(19) United States
(12) Patent Application Publication
(10) Pub. No.: US 2026/0190601 A1
(43) Pub. Date: Jul. 2, 2026

(54) ORGANIC ELECTROLUMINESCENT COMPOUND, A PLURALITY OF HOST MATERIALS, AND ORGANIC ELECTROLUMINESCENT DEVICE COMPRISING THE SAME

(71) Applicant: DuPont Specialty Materials Korea Ltd., Chungcheongnam-do (KR)

(72) Inventors: So-Young JUNG, Gyeonggi-do (KR); Hee-Ryong KANG, Gyeonggi-do (KR); Tae-Jun HAN, Gyeonggi-do (KR); Hyun-Ju KANG, Gyeonggi-do (KR); Sang-Hee CHO, Gyeonggi-do (KR); Hyo-Jung LEE, Gyeonggi-do (KR); Ji-Song JUN, Gyeonggi-do (KR); Bitnari KIM, Gyeonggi-do (KR); Mi-Ran SEO, Gyeonggi-do (KR); Du-Yong PARK, Gyeonggi-do (KR); So-Mi PARK, Gyeonggi-do (KR)

(21) Appl. No.: 19/416,369

(22) Filed: Dec. 11, 2025

(30) Foreign Application Priority Data
Dec. 27, 2024 (KR) 10-2024-0198840
Nov. 12, 2025 (KR) 10-2025-0170667

(51) Int. Cl. H10K 50/11; C07B 59/00; C09K 11/06; H10K 85/30; H10K 85/40; H10K 85/60; H10K 101/00

(52) U.S. Cl. CPC H10K 50/11; C07B 59/004; C09K 11/06; H10K 85/342; H10K 85/40; H10K 85/622; H10K 85/626; H10K 85/633; H10K 85/636; H10K 85/654; H10K 85/656; H10K 85/6572; H10K 85/6574; H10K 85/6576; C07B 2200/05; C09K 2211/1074; H10K 2101/90

(57) ABSTRACT

The present disclosure relates to an organic electroluminescent compound, a plurality of host materials, and an organic electroluminescent device comprising the same. By comprising the organic electroluminescent compound and the plurality of host materials, an organic electroluminescent device can be provided which has improved luminous efficiency characteristics and/or lifetime properties compared to the conventional organic electroluminescent devices.

### TECHNICAL FIELD

The present disclosure relates to an organic electroluminescent compound, a plurality of host materials, and an organic electroluminescent device comprising the same.

### BACKGROUND ART

The TPD/Alq3 bilayer small-molecule organic electroluminescent device (OLED) with green emission, which is constituted with a light-emitting layer and a charge transport layer, was first developed by Tang et al. of Eastman Kodak in 1987.

Thereafter, studies on organic electroluminescent devices have proceeded rapidly, and OLEDs have since been commercialized. At present, OLEDs primarily use phosphorescent materials having excellent luminous efficiency in panel implementation. For long-term use of displays and high resolution, OLEDs with low driving voltage, high luminous efficiency, and/or long lifetime are required.

Korean Patent Application Laid-Open Nos. 10-2022-0161620, 10-2023-0057737, and 10-2023-0157860 disclose a plurality of host materials, but do not specifically disclose a plurality of host materials of a specific combination and organic electroluminescent compounds claimed in the present disclosure. In addition, there is a continuous need to develop host materials that exhibit improved device characteristics compared to previously disclosed host materials.

### DISCLOSURE OF INVENTION

### Technical Problem

The objective of the present disclosure is, first, to provide a plurality of host materials and organic electroluminescent compounds that are effective for providing an organic electroluminescent device with low driving voltage, high luminous efficiency, and/or long lifetime, and second, to provide organic electroluminescent materials or an organic electroluminescent device comprising these plurality of host materials or organic electroluminescent compounds.

### Solution to Problem

As a result of intensive studies to solve the technical problems, the present inventors found that the above objective can be achieved by a plurality of host materials comprising a first host material comprising a compound represented by the following Formula 1 and a second host material comprising a compound represented by the following Formula 2, wherein at least one of the first host material and the second host material comprises a cyano, or an organic electroluminescent compound represented by the following Formula 3.

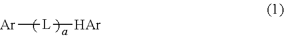

In Formula 1,
Ar represents a substituted or unsubstituted (C₆-C₃₀)aryl, a substituted or unsubstituted (3- to 30-membered)heteroaryl, or a substituted or unsubstituted (C₃-C₃₀)cycloalkyl;
L represents a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
a represents an integer of 1 to 3, where if a is an integer of 2 or 3, each L may be the same as or different from each other; and
HAr is represented b the following Formula 1-a or 1-b:

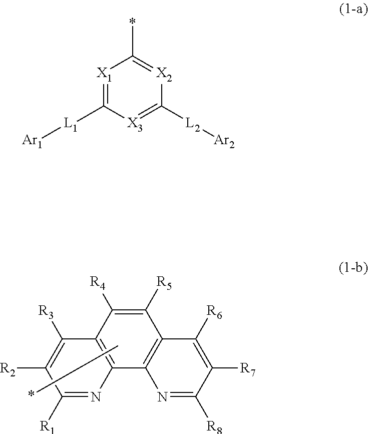

In Formulas 1-a and 1-b,
* represents a site linked to L, and in Formula 1-b, any one of R₁ to R₅ is linked to L;
X₁ to X₃ each independently represent N or CR₉; with the proviso that at least one of X₁ to X₃ is N;
Ar₁ and Ar₂ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, or a substituted or unsubstituted fused ring group of a (C₃-C₃₀)aliphatic ring(s) and a (C₆-C₃₀)aromatic ring(s);
R₆ to R₉ and those of R₁ to R₅ that are not linked to L each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s); and
L₁ and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
with the proviso that when HAr is represented by Formula 1-a, cases where Ar, Ar₁, or Ar₂ comprises a tri(C₆-C₃₀)arylsilyl or a tri(C₆-C₃₀)arylmethyl are excluded, and the carbon atoms of the aryl in the tri(C₆-C₃₀)arylsilyl and the tri(C₆-C₃₀)arylmethyl may be replaced with any one of N, S, or O.

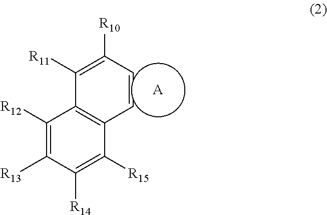

In Formula 2,
ring A is represented by the following Formula 2-a or 2-b;
R₁₀ to R₁₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring group of a (C₃-C₃₀)aliphatic ring(s) and a (C₆-C₃₀)aromatic ring(s), or

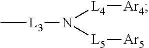

or may be linked to an adjacent substituent(s) to form a ring(s);
L₃ to L₅ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene; and
Ar₄ and Ar₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl.

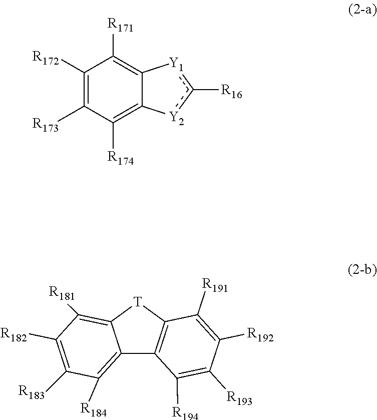

In Formulas 2-a and 2-b,
Y₁ and Y₂ each independently represent —N═, —NRₐ—, —O—, or —S—, with the proviso that one of Y₁ and Y₂ is —N═, and the other of Y₁ and Y₂ is —NRₐ—, —O—, or —S—;
T represents O or S; and
an adjacent pair among R₁₇₁ to R₁₇₄, R₁₈₁ to R₁₈₄, and R₁₉₁ to R₁₉₄ represents a fused position to the naphthalene in Formula 2, and R₁₇₁ to R₁₇₄, R₁₈₁ to R₁₈₄, R₁₉₁ to R₁₉₄, Rₐ and R₁₆ which are not fused positions each independently have the same definitions as R₁₀ to R₁₅;
with the proviso that when the ring A is represented by Formula 2-a, any one of R₁₀ to R₁₆ and R₁₇₁ to R₁₇₄ is

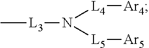

and when the ring A is represented by Formula 2-b, at least one of R₁₀ to R₁₅, R₁₈₁ to R₁₈₄, and R₁₉₁ to R₁₉₄ is L₅-Ar₅; and

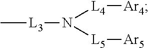

with the proviso that when Ar₄ and Ar₅ are substituted (C₆-C₃₀)aryl, cases where the substituents of the substituted aryl comprise a carbazole or an amino are excluded.

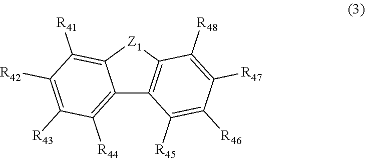

In Formula 3,
Z₁ represents O, S, Se, NR_{b}, or CR_{c}R_{d}; and
R₄₁ to R₄₈ and R_{b} to R_{d} each independently represent the following Formula 3-a, or hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl;
with the proviso that at least one of R₄₁ to R₄₈ and R_{b} to R_{d} is represented by the following Formula 3-a:

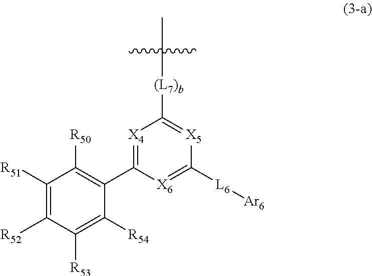

In Formula 3-a,
X₄ to X₆ each independently represent N or CRₑ; with the proviso that at least one of X₄ to X₆ is N;
L₆ and L₇ each independently represent a single bond, a substituted or unsubstituted (C₆-C₃₀)arylene, or a substituted or unsubstituted (3- to 30-membered)heteroarylene, or a substituted or unsubstituted (C₃-C₃₀)cycloalkylene;
b represents an integer of 1 or 2, where if b is an integer of 2, each L₇ may be the same as or different from each other;
R₅₀ to R₅₄ and Rₑ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s), a substituted or unsubstituted (C₆-C₃₀)aryl; with the proviso that at least one of R₅₀ to R₅₄ is cyano; and
Ar₆ represents a substituted or unsubstituted phenyl, a substituted or unsubstituted biphenyl, a substituted or unsubstituted terphenyl, a substituted or unsubstituted naphthyl, a substituted or unsubstituted binaphthyl, a substituted or unsubstituted phenylnaphthyl, a substituted or unsubstituted naphthylphenyl, a substituted or unsubstituted phenanthrenyl, a substituted or unsubstituted anthracenyl, a substituted or unsubstituted chrysenyl, a substituted or unsubstituted dibenzofuranyl, a substituted or unsubstituted dibenzothiophenyl, a substituted or unsubstituted naphthobenzothiophenyl, a substituted or unsubstituted carbazolyl, or a substituted or unsubstituted benzocarbazolyl.

### Advantageous Effects of Invention

By comprising an organic electroluminescent compound and a plurality of host materials according to the present disclosure, it is possible to provide an organic electroluminescent device exhibiting low driving voltage, high luminous efficiency and/or improved lifetime characteristics. In particular, an organic electroluminescent device comprising an organic electroluminescent compound or a plurality of host materials according to the present disclosure can exhibit long-lifetime characteristics while having a low driving voltage and/or high luminous efficiency.

### MODE FOR INVENTION

Hereinafter, the present disclosure will be described in detail. However, the following description is intended to explain the present disclosure, and is not meant in any way to restrict the scope of the present disclosure.

The “organic electroluminescent compound” in the present disclosure is a compound that may be used in an organic electroluminescent device, and may be comprised in any layer constituting an organic electroluminescent device, as necessary.

The “organic electroluminescent material” in the present disclosure is a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron-blocking material, a light-emitting material (including a host material and a dopant material), an electron buffer material, a hole-blocking material, an electron transport material, an electron injection material, etc.

The “plurality of host materials” in the present disclosure means a host material comprising a combination of two or more, or three or more compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of two or more, or three or more of host materials, and may selectively further comprise conventional materials comprised in an organic electroluminescent material. Two or more compounds comprised in the plurality of host materials of the present disclosure may be comprised together in one light-emitting layer or may respectively be comprised in different light-emitting layers. For example, the two or more, or three or more host materials may be mixture-evaporated or co-evaporated, or may be individually evaporated.

Herein, the term “(C₁-C₃₀)alkyl” is meant to refer to a linear or branched alkyl having 1 to 30 carbon atoms constituting a chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. The term “(C₂-C₃₀)alkenyl” in the present disclosure is meant to refer to a linear or branched alkenyl having 2 to 30 carbon atoms constituting the chain, in which the number of carbon atoms is preferably 2 to 20, and more preferably 2 to 10. The above alkenyl may include vinyl, 1-propenyl, 2-propenyl, 1-butenyl, 2-butenyl, 3-butenyl, 2-methylbut-2-enyl, etc. The term “(C₂-C₃₀)alkynyl” in the present disclosure is meant to refer to a linear or branched alkynyl having 2 to 30 carbon atoms constituting the chain, in which the number of carbon atoms is preferably 2 to 20, and more preferably 2 to 10. The above alkynyl may include ethynyl, 1-propynyl, 2-propynyl, 1-butynyl, 2-butynyl, 3-butynyl, 1-methylpent-2-ynyl, etc. The term “(C₃-C₃₀)cycloalkyl” or “(C₃-C₃₀)cycloalkylene” are meant to refer to a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The term “(3- to 7-membered)heterocycloalkyl” in the present disclosure is meant to refer to a cycloalkyl having 3 to 7, preferably 5 to 7 ring backbone atoms, and including at least one heteroatom selected from the group consisting of B, N, O, S, Si, P, Te, Se, and Ge, preferably at least one heteroatom selected from O, S, N, and Se. For example, the above heterocycloalkyl may include tetrahydrofuran, pyrrolidine, thiolane, tetrahydropyran, etc. The “(C₆-C₃₀)aryl” or “(C₆-C₃₀)arylene” in the present disclosure refer to a monocyclic or fused ring radical derived from an aromatic hydrocarbon having 6 to 30 ring backbone carbon atoms, and may be partially saturated. The above aryl may comprise a spiro structure. The above aryl may include phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluorene]yl, spiro[cyclopentene-fluorene]yl, spiro[dihydroindene-fluorene]yl, azulenyl, tetramethyl-dihydrophenanthrenyl, etc. Specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenyl, 3-biphenyl, 4-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, o-quaterphenyl, m-quaterphenyl, p-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The “(3- to 30-membered)heteroaryl” or “(3- to 30-membered)heteroarylene” in the present disclosure refer to an aryl group or arylene group having 3 to 30 ring backbone atoms and including at least one heteroatom(s) selected from the group consisting of B, N, O, S, Si, P, Te, Se, and Ge. The number of heteroatoms is preferably 1 to 4. The above heteroaryl or heteroarylene may be a monocyclic ring or a fused ring condensed with at least one benzene ring, and may be partially saturated. In addition, the above heteroaryl or heteroarylene may be one formed by linking at least one heteroaryl or aryl group to a heteroaryl group via a single bond(s), and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, benzofuroquinolinyl, benzofuroquinazolinyl, benzofuronaphthyridinyl, benzofuropyrimidinyl, naphthofuropyrimidinyl, naphthofuropyrimidinyl, benzothienoquinolinyl, benzothienoquinazolinyl, naphthyridinyl, benzothienonaphthyrdinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzimidazolyl, benzothiazolyl, benzisothiazolyl, benzisoxazolyl, benzoxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolyl, phenazinyl, imidazopyridinyl, chromenoquinazolyl, thiochromenoquinazolyl, dimethylbenzopyrimidinyl, indolocarbazolyl, indenocarbazolyl, etc. More specifically, the heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-trazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthrdinyl, 2-phenanthrdinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho[1,2-b]benzofuranyl, 2-naphtho[1,2-b]benzofuranyl, 3-naphtho[1,2-b]benzofuranyl, 4-naphtho[1,2-b]benzofuranyl, 5-naphtho[1,2-b]benzofuranyl, 6-naphtho[1,2-b]benzofuranyl, 7-naphtho[1,2-b]benzofuranyl, 8-naphtho[1,2-b]benzofuranyl, 9-naphtho[1,2-b]benzofuranyl, 10-naphtho[1,2-b]benzofuranyl, 1-naphtho[2,3-b]benzofuranyl, 2-naphtho[2,3-b]benzofuranyl, 3-naphtho[2,3-b]benzofuranyl, 4-naphtho[2,3-b]benzofuranyl, 5-naphtho[2,3-b]benzofuranyl, 6-naphtho[2,3-b]benzofuranyl, 7-naphtho[2,3-b]benzofuranyl, 8-naphtho[2,3-b]benzofuranyl, 9-naphtho[2,3-b]benzofuranyl, 10-naphtho[2,3-b]benzofuranyl, 1-naphtho[2,1-b]benzofuranyl, 2-naphtho[2,1-b]benzofuranyl, 3-naphtho[2,1-b]benzofuranyl, 4-naphtho[2,1-b]benzofuranyl, 5-naphtho[2,1-b]benzofuranyl, 6-naphtho[2,1-b]benzofuranyl, 7-naphtho[2,1-b]benzofuranyl, 8-naphtho[2,1-b]benzofuranyl, 9-naphtho[2,1-b]benzofuranyl, 10-naphtho[2,1-b]benzofuranyl, 1-naphtho[1,2-b]benzothiophenyl, 2-naphtho[1,2-b]benzothiophenyl, 3-naphtho[1,2-b]benzothiophenyl, 4-naphtho[1,2-b]benzothiophenyl, 5-naphtho[1,2-b]benzothiophenyl, 6-naphtho[1,2-b]benzothiophenyl, 7-naphtho[1,2-b]benzothiophenyl, 8-naphtho[1,2-b]benzothiophenyl, 9-naphtho[1,2-b]benzothiophenyl, 10-naphtho[1,2-b]benzothiophenyl, 1-naphtho[2,3-b]benzothiophenyl, 2-naphtho[2,3-b]benzothiophenyl, 3-naphtho[2,3-b]benzothiophenyl, 4-naphtho[2,3-b]benzothiophenyl, 5-naphtho[2,3-b]benzothiophenyl, 1-naphtho[2,1-b]benzothiophenyl, 2-naphtho[2,1-b]benzothiophenyl, 3-naphtho[2,1-b]benzothiophenyl, 4-naphtho[2,1-b]benzothiophenyl, 5-naphtho[2,1-b]benzothiophenyl, 6-naphtho[2,1-b]benzothiophenyl, 7-naphtho[2,1-b]benzothiophenyl, 8-naphtho[2,1-b]benzothiophenyl, 9-naphtho[2,1-b]benzothiophenyl, 10-naphtho[2,1-b]benzothiophenyl, 2-benzofuro[3,2-d]pyrimidinyl, 6-benzofuro[3,2-d]pyrimidinyl, 7-benzofuro[3,2-d]pyrmidinyl, 8-benzofuro[3,2-d]pyrimidinyl, 9-benzofuro[3,2-d]pyrmidinyl, 2-benzothio[3,2-d]pyrimidinyl, 6-benzothio[3,2-d]pyrimidinyl, 7-benzothio[3,2-d]pyrmidinyl, 8-benzothio[3,2-d]pyrimidinyl, 9-benzothio[3,2-d]pyrmidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “heteroaryl(ene)” can be classified into a heteroaryl(ene) with electronic properties and a heteroaryl(ene) with hole properties. A heteroaryl(ene) with electronic properties is a substituent that is relatively rich in electrons in the parent nucleus, for example, a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc.

A heteroaryl(ene) with hole properties is a substituent that is relatively electron-deficient in the parent nucleus, for example, a substituted or unsubstituted carbazolyl, a substituted or unsubstituted dibenzofuranyl, a substituted or unsubstituted dibenzothiophenyl, etc.

Herein, “a fused ring group of a (C₃-C₃₀)aliphatic ring(s) and a (C₆-C₃₀)aromatic ring(s)” is meant to be a functional group of a ring in which at least one aliphatic ring having 3 to 30 ring backbone carbon atoms, preferably 3 to 25 ring backbone carbon atoms, and more preferably 3 to 18 ring backbone carbon atoms, is fused with at least one aromatic ring having 6 to 30 ring backbone carbon atoms, preferably 6 to 25 ring backbone carbon atoms, and more preferably 6 to 18 ring backbone carbon atoms. Specific examples of the fused ring group include a fused ring group of one or more benzene and one or more cyclohexane, or a fused ring group of one or more naphthalene and one or more cyclopentane, etc. Herein, the carbon atom of the fused ring group of a (C₃-C₃₀)aliphatic ring(s) and a (C₆-C₃₀)aromatic ring(s) may be replaced with one or more heteroatoms selected from B, N, O, S, Si, P, Te, Se, and Ge, preferably one or more heteroatoms selected from N, O, S and Se. Herein, “halogen” includes F, Cl, Br, and I.

In addition, “ortho-” (“o-”), “meta-” (“m-”), and “para” (“p-”) are prefixes which each represent the relative positions of substituents. The prefix “ortho-” indicates that two substituents are adjacent to each other, and for example, when two substituents in a benzene derivative occupy positions 1 and 2, this is called an “ortho-” configuration. The prefix “meta-” indicates that two substituents are at positions 1 and 3, and for example, when two substituents in a benzene derivative occupy positions 1 and 3, this is called a “meta-” configuration. The prefix “para-” indicates that two substituents are at positions 1 and 4, and for example, when two substituents in a benzene derivative occupy positions 1 and 4, this is called a “para-” configuration.

Herein, “a ring formed by being linked to an adjacent substituent(s)” means that at least two adjacent substituents are linked to or fused with each other to form a substituted or unsubstituted, mono- or polycyclic, (3- to 30-membered) alicyclic or aromatic ring, or a combination thereof, and the ring may form a spiro ring.

Preferably, the ring may be a substituted or unsubstituted, mono- or polycyclic, (5- to 26-membered)alicyclic or aromatic ring, or a combination thereof, and more preferably, the ring may be a mono- or polycyclic, (5- to 25-membered)aromatic ring substituted or unsubstituted with one or more of (C₁-C₆)alkyl, (C₆-C₁₈)aryl, and (3- to 20-membered)heteroaryl. In addition, the ring may contain at least one heteroatom selected from B, N, O, S, Si, P, Te, Se, and Ge, preferably, at least one heteroatom selected from B, N, O, S, and Se. For example, the ring may a benzene ring, etc.

In the present disclosure, heteroaryl, heteroarylene, and heterocycloalkyl may each independently comprise at least one heteroatom selected from B, N, O, S, Si, P, Te, and Se. In addition, the heteroatom may be bonded to at least one selected from the group consisting of hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, and a substituted or unsubstituted (C₆-C₃₀)aryl(3- to 30-membered)heteroarylamino.

Herein, “substituted” in the expression “substituted or unsubstituted” means that a hydrogen atom in a certain functional group is replaced with another atom or another functional group, i.e., a substituent. Unless otherwise specified, the substituent may replace hydrogen at a position where the substituent can be substituted without limitation, and when two or more hydrogen atoms in a certain functional group are each replaced with a substituent, each substituent may be the same as or different from each other. The maximum number of substituents that can be substituted for a certain functional group may be the total number of valences that can be substituted for each atom forming the functional group. Herein, the substituted alkyl, the substituted aryl(ene), the substituted heteroaryl(ene), the substituted cycloalkyl(ene), the substituted heterocycloalkyl, the substituted alkoxy, the substituted trialkylsilyl, the substituted dialkylarylsilyl, the substituted alkyldiarylsilyl, the substituted triarylsilyl, the substituted mono- or dialkylamino, the substituted mono- or dialkenylamino, the substituted alkylalkenylamino, the substituted mono- or diarylamino, the substituted alkylarylamino, the substituted mono- or diheteroarylamino, the substituted alkylheteroarylamino, the substituted alkenylarylamino, the substituted alkenylheteroarylamino, the substituted arylheteroarylamino, and the substituted fused ring group of an aliphatic ring(s) and an aromatic ring(s) each independently may be substituted with at least one selected from the group consisting of deuterium, a halogen, a cyano, a carboxyl, a nitro, a hydroxyl, a (C₁-C₃₀)alkyl, a halo(C₁-C₃₀)alkyl, a (C₂-C₃₀)alkenyl, a (C₂-C₃₀)alkynyl, a (C₁-C₃₀)alkoxy, a (C₁-C₃₀)alkylthio, a (C₃-C₃₀)cycloalkyl, a (C₃-C₃₀)cycloalkenyl, a (3- to 7-membered)heterocycloalkyl, a (C₆-C₃₀)aryloxy, a (C₆-C₃₀)arylthio, a (3- to 30-membered)heteroaryl, a (C₆-C₃₀)aryl, a tri(C₁-C₃₀)alkylsilyl, a tri(C₆-C₃₀)arylsilyl, a di(C₁-C₃₀)alkyl(C₆-C₃₀)arylsilyl, a (C₁-C₃₀)alkyldi(C₆-C₃₀)arylsilyl, a fused ring group of a (C₃-C₃₀)aliphatic ring(s) and a (C₆-C₃₀)aromatic ring(s), an amino, a mono- or di(C₁-C₃₀)alkylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₆-C₃₀)aryl(3- to 30-membered)heteroarylamino, a (C₁-C₃₀)alkylcarbonyl, a (C₁-C₃₀)alkoxycarbonyl, a (C₆-C₃₀)arylcarbonyl, a (C₆-C₃₀)arylphosphinyl, a di(C₆-C₃₀)arylboronyl, a di(C₁-C₃₀)alkylboronyl, a (C₁-C₃₀)alkyl(C₆-C₃₀)arylboronyl, a (C₆-C₃₀)aryl(C₁-C₃₀)alkyl, a (C₁-C₃₀)alkyl(C₆-C₃₀)aryl, and a combination thereof. According to one embodiment of the present disclosure, the group consists of deuterium, a cyano, a (C₁-C₂₀)alkyl, a (C₆-C₂₅)aryl, a (5- to 25-membered)heteroaryl, a di(C₆-C₂₅)arylamino, a (C₆-C₂₅)aryl(5- to 25-membered)heteroarylamino, and a combination thereof. According to another embodiment of the present disclosure, the group consists of deuterium, a cyano, a (C₁-C₁₀)alkyl, a (C₆-C₁₈)aryl, a (5- to 20-membered)heteroaryl, a di(C₆-C₁₈)arylamino, a (C₆-C₁₈)aryl(5- to 20-membered)heteroarylamino, and a combination thereof. For example, the group may consist of deuterium; a cyano; a methyl; a tert-butyl; a phenyl unsubstituted or substituted with a cyano, or pyridyl; a biphenyl unsubstituted or substituted with a cyano; a naphthyl unsubstituted or substituted with a cyano; a phenanthrenyl; an anthracenyl; a fluoranthenyl; a terphenyl; a naphthylphenyl unsubstituted or substituted with a cyano; a phenylnaphthyl unsubstituted or substituted with a cyano; a pyridyl unsubstituted or substituted with a phenyl; a dibenzofuranyl; a dibenzothiophenyl; a carbazolyl; a phenoxazinyl; a diphenylamino; a phenyldibenzofuranylamino, etc., and these may be further substituted with deuterium.

In the present disclosure, if a substituent is not indicated in the chemical formula or compound structure, it may mean that all possible positions for the substituent are hydrogen or deuterium. That is, in the case of deuterium, it is an isotope of hydrogen, and some hydrogen atoms may be the isotope deuterium, and in this case, the content of deuterium may be 0% to 100%. In the present disclosure, in cases where a substituent is not indicated in the chemical formula or compound structure, if the substituent is not explicitly excluded, such as 0% deuterium, 100% hydrogen, and all substituents are hydrogen, etc., hydrogen and deuterium may be used intermixed in a compound. Deuterium is one of the isotopes of hydrogen and an element with a deuteron consisting of one proton and one neutron as its nucleus.

It can be represented as hydrogen-2, whose element symbol can also be written as D or ²H. Isotopes are atoms with the same atomic number (Z) but different mass numbers (A), and can also be interpreted as elements with the same number of protons but different numbers of neutrons.

In the present disclosure, “a combination thereof” refers to a combination of one or more elements from the corresponding list to form a known or chemically stable arrangement that can be envisioned by a person skilled in the art from the corresponding list. For example, alkyl and deuterium can be combined to form a partially or fully deuterated alkyl group, a halogen and alkyl can be combined to form a halogenated alkyl substituent, and a halogen, alkyl, and aryl can be combined to form a halogenated arylalkyl. For example, a preferred combination of substituents includes up to 50 atoms that are not hydrogen or deuterium, or up to 40 atoms that are not hydrogen or deuterium, or up to 30 atoms that are not hydrogen or deuterium, or in many cases, a preferred combination of substituents may comprise up to 20 atoms that are not hydrogen or deuterium.

In the formulas of the present disclosure, when there are multiple substituents represented by the same symbol, each substituent represented by the same symbol may be the same as or different from each other.

In Formula 1, Ar represents a substituted or unsubstituted (C₆-C₃₀)aryl, a substituted or unsubstituted (3- to 30-membered)heteroaryl, or a substituted or unsubstituted (C₃-C₃₀)cycloalkyl. According to one embodiment of the present disclosure, Ar represents a substituted or unsubstituted (C₆-C₂₅)aryl, a substituted or unsubstituted (5- to 25-membered)heteroaryl, or a substituted or unsubstituted (C₃-C₂₅)cycloalkyl. According to another embodiment of the present disclosure, Ar represents a substituted or unsubstituted (C₁₀-C₂₀)aryl, a substituted or unsubstituted (13- to 17-membered)heteroaryl, or a substituted or unsubstituted (C₆-C₁₂)cycloalkyl. Herein, an aryl, a heteroaryl, and a cycloalkyl may be substituted with at least one selected from the group consisting of deuterium, a cyano, a (C₁-C₃₀)alkyl, a (C₆-C₃₀)aryl, a (3- to 30-membered)heteroaryl, and a combination thereof. Preferably, the group consists of deuterium, a cyano, a (C₁-C₁₀)alkyl, a (C₆-C₁₈)aryl, a (5- to 10-membered)heteroaryl, and a combination thereof. For example, Ar may be a substituted or unsubstituted, phenyl, biphenyl, terphenyl, naphthyl, binaphthyl, phenylnaphthyl, naphthylphenyl, phenanthrenyl, adamantyl, fluorenyl, dimethylfluorenyl, diphenylfluorenyl, methylphenylfluorenyl, phenylfluorenyl, benzofluorenyl, spiro[fluorene-fluorene]yl, dibenzofuranyl, naphthobenzofuranyl, dibenzothiophenyl, naphthobenzothiophenyl, dibenzoselenophenyl, carbazolyl, or benzocarbazolyl, and these may be substituted with at least one of deuterium, a cyano, a phenyl, a phenyl substituted with a cyano, a phenyl substituted with a pyridyl, a biphenyl, a biphenyl substituted with a cyano, a naphthyl, a naphthyl substituted with a cyano, a phenanthrenyl, a terphenyl, a naphthylphenyl, a naphthylphenyl substituted with a cyano, a phenylnaphthyl, and a phenylnaphthyl substituted with a cyano, and these may be further substituted with deuterium.

In Formula 1, L represents a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L represents a single bond, a substituted or unsubstituted (C₆-C₂₅)arylene, or a substituted or unsubstituted (5- to 20-membered)heteroarylene. According to another embodiment of the present disclosure, L represents a single bond, a substituted or unsubstituted (C₆-C₁₈)arylene, or a substituted or unsubstituted (6- to 17-membered)heteroarylene. For example, L may be a single bond, a phenylene unsubstituted or substituted with a cyano, a biphenylene, a naphthylene, a phenylenenaphthylene, a naphthylenephenylene, or a pyridylene, etc., and these may be further substituted with deuterium.

In Formula 1, a represents an integer of 1 to 3, where if a is an integer of 2 or 3, each L may be the same as or different from each other.

In Formula 1-a, X₁ to X₃ each independently represent N or CR₉; with the proviso that at least one of X₁ to X₃ is N. According to one embodiment of the present disclosure, at least two of X₁ to X₃ are N. According to another embodiment of the present disclosure, all of X₁ to X₃ are N.

In Formula 1-a, Ar₁ and Ar₂ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₆-C₃₀)arylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s). According to one embodiment of the present disclosure, Ar₁ and Ar₂ each independently represent a cyano, a substituted or unsubstituted (C₁-C₂₀)alkyl, a substituted or unsubstituted (C₆-C₂₅)aryl, or a substituted or unsubstituted (5- to 25-membered)heteroaryl. According to another embodiment of the present disclosure, Ar₁ and Ar₂ each independently represent a cyano, a substituted or unsubstituted (C₁-C₁₀)alkyl, a substituted or unsubstituted (C₆-C₂₄)aryl, or a substituted or unsubstituted (6- to 20-membered)heteroaryl. Herein, an alkyl, an aryl, or a heteroaryl may be substituted with at least one selected from the group consisting of deuterium, a cyano, a (C₁-C₃₀)alkyl, a (C₆-C₃₀)aryl, and a combination thereof. Preferably, the group consists of deuterium, a cyano, a (C₁-C₁₀)alkyl, (C₆-C₁₈)aryl, and a combination thereof. For example, Ar₁ and Ar₂ may each independently be a cyano, a tert-butyl, a phenyl, a naphthyl, a phenylnaphthyl, a binaphthyl, a naphthylphenyl, a biphenyl, a phenanthrenyl, a fluoranthenyl, a chrysenyl, a benzo[c]phenanthrenyl, a triphenylenyl, a quaterphenyl, a terphenyl, a dimethylfluorenyl, a methylphenylfluorenyl, a pyridyl, a quinolyl, dibenzofuranyl, dibenzothiophenyl, carbazolyl, phenylcarbazolyl, naphthobenzofuranyl, naphthobenzothiophenyl, or benzocarbazolyl, etc., and these may be substituted with deuterium, a cyano, a phenyl, a phenyl substituted with a cyano, a naphthyl, a biphenyl, a biphenyl substituted with a cyano, etc., and these may be further substituted with deuterium.

In Formulas 1-a and 1-b, R₆ to R₉ and those of R₁ to R₅ that are not linked to L each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s). According to one embodiment of the present disclosure, any one of R₁ to R₅ is linked to L, and R₁ to R₅ and R₆ to R₉ that are not linked to L each independently represent hydrogen, deuterium, a cyano, or a substituted or unsubstituted (C₆-C₂₅)aryl. According to another embodiment of the present disclosure, R₁ to R₅ and R₆ to R₉ that are not linked to L each independently represent hydrogen, deuterium, a cyano, or a (C₆-C₁₈)aryl unsubstituted or substituted with a cyano. For example, R₁ to R₅ and R₆ to R₈ that are not linked to L may each independently be hydrogen, deuterium, a cyano, a phenyl unsubstituted or substituted with a cyano, or a biphenyl unsubstituted or substituted with a cyano, etc., and these may be further substituted with deuterium.

In Formula 1-a, L₁ and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L₁ and L₂ each independently represent a single bond, a substituted or unsubstituted (C₆-C₂₅)arylene, or a substituted or unsubstituted (5- to 25-membered)heteroarylene. According to another embodiment of the present disclosure, L₁ and L₂ each independently represent a single bond, a substituted or unsubstituted (C₆-Cia)arylene, or a substituted or unsubstituted (5- to 20-membered)heteroarylene. Herein, an arylene, a heteroarylene, or a cycloalkylene may be substituted with at least one selected from the group consisting of deuterium, a cyano, a (C₁-C₃₀)alkyl, a (C₆-C₃₀)aryl, and a combination thereof. Preferably, the group consists of deuterium, a cyano, a (C₁-C₁₀)alkyl, (C₆-C₁₈)aryl, and a combination thereof. For example, L₁ and L₂ may each independently be a single bond, a phenylene unsubstituted or substituted with a phenyl, a naphthylene unsubstituted or substituted with a phenyl, a biphenylene unsubstituted or substituted with a cyano, or a methyl, a phenanthrenylene, a carbazolylene substituted with a phenyl, or a dibenzofuranylene, and these may be further substituted with deuterium;
with the proviso that when HAr is represented by Formula 1-a, cases where Ar, Ar₁, or Ar₂ comprises a tri(C₆-C₃₀)arylsilyl or a tri(C₆-C₃₀)arylmethyl are excluded, and the carbon atoms of the aryl in the tri(C₆-C₃₀)arylsilyl and the tri(C₆-C₃₀)arylmethyl may be replaced with any one of N, S, or O.

Formula 1 may be represented by any one of the following Formulas 1-1 to 1-9.

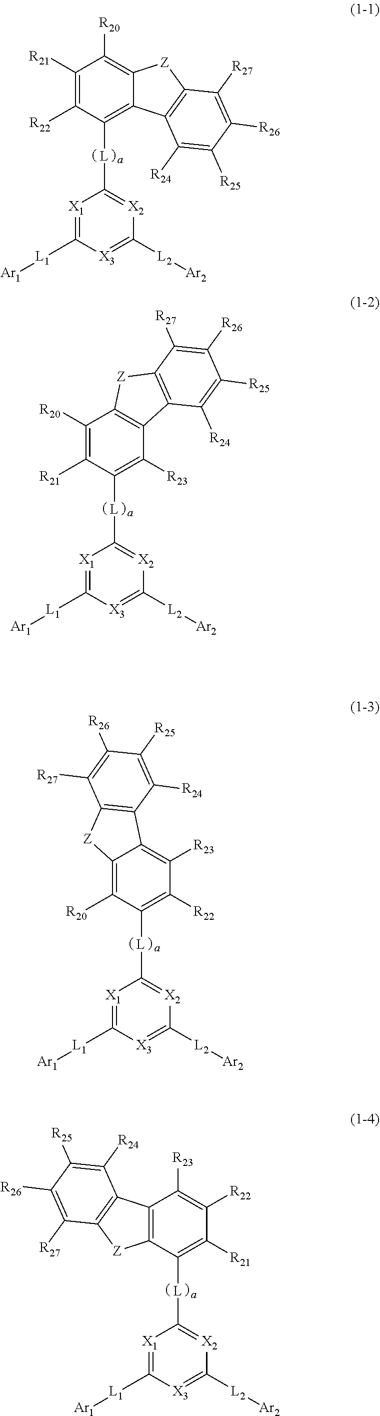

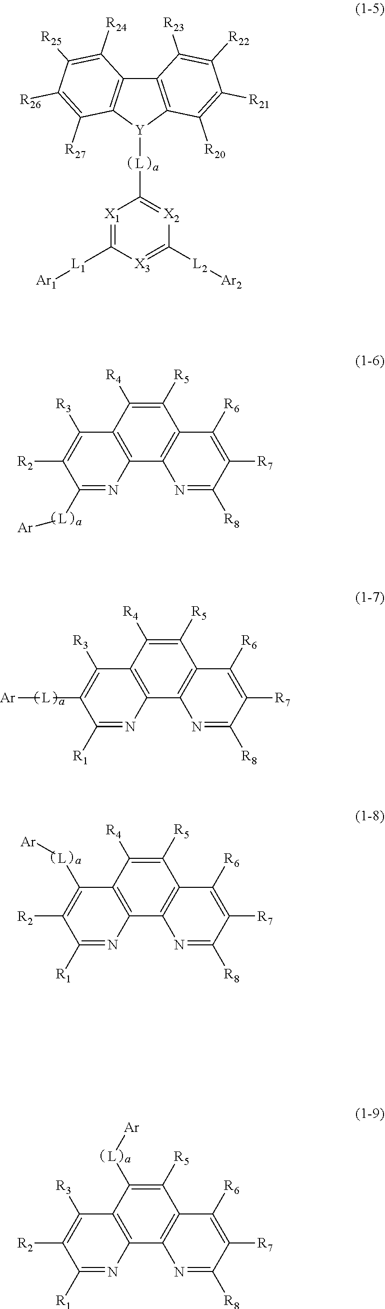

In Formulas 1-1 to 1-9,
Z represents O, S, Se, NR₂₈, or CR₂₉R₃₀;
Y represents N or CR₃₁;
R₂₀ to R₃₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl; or may be linked to an adjacent substituent(s) to form a ring(s); and
X₁ to X₃, L, L₁, L₂, Ar, Ar₁, Ar₂, a, and R₁ to R₈ are as defined in Formula 1.

According to one embodiment of the present disclosure, Z represents O, S, NR₂₈, or CR₂₉R₃₀.

According to one embodiment of the present disclosure, R₂₀ to R₂₇ each independently represent hydrogen, deuterium, a cyano, or a substituted or unsubstituted (C₆-C₃₀)aryl; or may be linked to an adjacent substituent(s) to form a substituted or unsubstituted fused ring(s) of a (C₃-C₃₀)aliphatic ring(s) and a (C₆-C₃₀)aromatic ring(s). According to another embodiment of the present disclosure, R₂₀ to R₂₇ each independently represent hydrogen, deuterium, a cyano, or a substituted or unsubstituted (C₁-C₁₈)aryl; or may be linked to an adjacent substituent(s) to form a substituted or unsubstituted (C₆-C₃₀)aromatic ring(s). Herein, an aryl, or a fused ring of a aliphatic ring(s) and a aromatic ring(s) may be substituted with at least one selected from the group consisting of deuterium, a cyano, a (C₆-C₃₀)aryl, a (3- to 30-membered)heteroaryl and a combination thereof. Preferably, the group consists of deuterium, a cyano, a (C₁-C₁₈)aryl, a (5- to 20-membered)heteroaryl, and a combination thereof. For example, R₂₀ to R₂₇ may each independently be hydrogen, deuterium, a cyano, a phenyl unsubstituted or substituted with a pyridyl, a biphenyl, a naphthyl, a phenanthrenyl, a terphenyl, a phenylnaphthyl, a naphthylphenyl, etc., or may be linked to an adjacent substituent(s) to form a benzene ring, and these may be further substituted with at least one of deuterium and a cyano.

According to one embodiment of the present disclosure, R₂₀ represent a substituted or unsubstituted (C₆-C₂₅)aryl. According to another embodiment of the present disclosure, R₂₈ represent a substituted or unsubstituted (C₆-C₁₈)aryl. For example, R₂₈ may be a phenyl unsubstituted or substituted with deuterium or a cyano.

According to one embodiment of the present disclosure, R₂₉ and R₃₀ each independently represent a substituted or unsubstituted (C₁-C₂₀)alkyl, or a substituted or unsubstituted (C₆-C₂₅)aryl; or may be linked to an adjacent substituent(s) to form a ring(s) of a (C₃-C₃₀)aliphatic ring(s) and a (C₆-C₃₀)aromatic ring(s). According to another embodiment of the present disclosure, each independently represent a substituted or unsubstituted (C₁-C₁₀)alkyl, or a substituted or unsubstituted (C₆-C₁₈)aryl; or R₂₉ and R₃₀ may be linked to each other to form a ring(s) of a (C₃-C₁₀)aliphatic ring(s) and a (C₁-C₁₈)aromatic ring(s). For example, R₂₉ and R₃₀ may each independently be a methyl or a phenyl, etc., or R₂₉ and R₃₀ may be linked to each other to form a spirofluorene ring, and these may be further substituted with at least one of deuterium and a cyano.

According to one embodiment of the present disclosure, the first host material comprising a compound represented by Formula 1 comprises a cyano. According to another embodiment of the present disclosure, at least one of Ar, L, Ar₁, and Ar₂ in Formula 1 may be substituted with a cyano, a (C₁-C₃₀)alkyl substituted with a cyano, a (C₆-C₃₀)aryl substituted with a cyano, or a (3- to 30-membered)heteroaryl substituted with a cyano. According to one embodiment of the present disclosure, at least one of R₂₀ to R₂₇, Ar₁, and Ar₂ in Formulas 1-1 to 1-5 is substituted with a cyano, a (C₁-C₃₀)alkyl substituted with a cyano, a (C₆-C₃₀)aryl substituted with a cyano, or a (3- to 30-membered)heteroaryl substituted with a cyano. According to one embodiment of the present disclosure, at least one of R₁ to R₈ and Ar in Formulas 1-6 to 1-9 is substituted with a cyano, a (C₁-C₃₀)alkyl substituted with a cyano, a (C₆-C₃₀)aryl substituted with a cyano, or a (3- to 30-membered)heteroaryl substituted with a cyano.

The compound represented by Formula 1 may be selected from the following compounds, but is not limited to thereto.

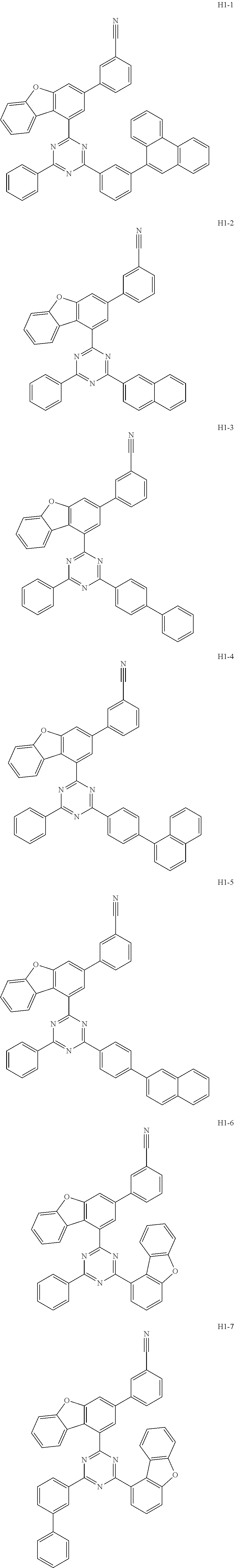

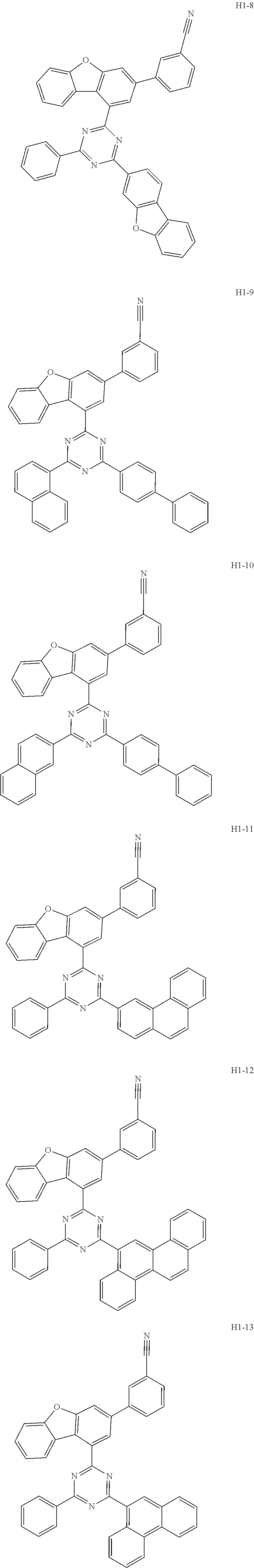

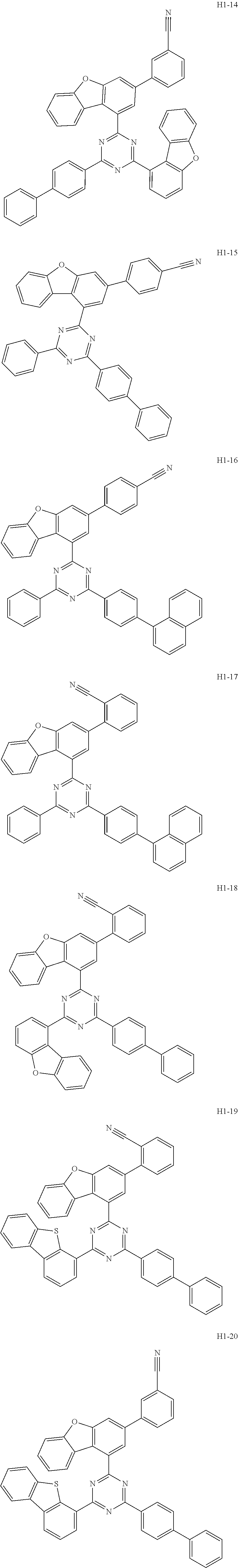

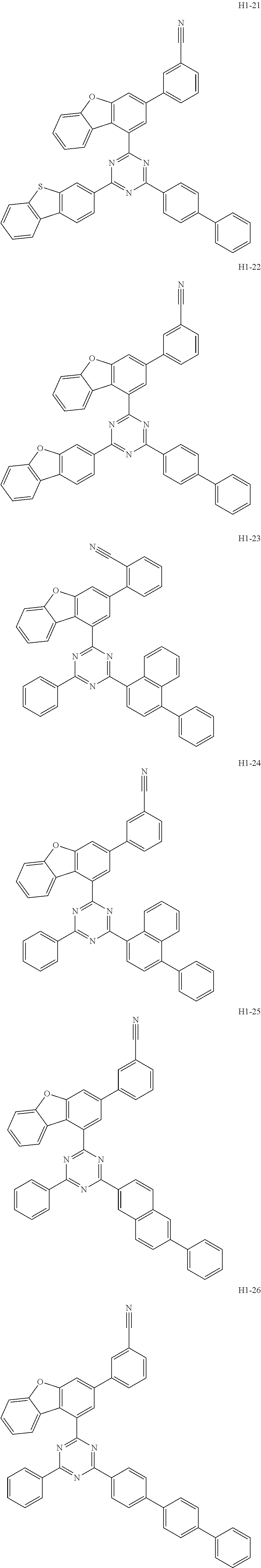

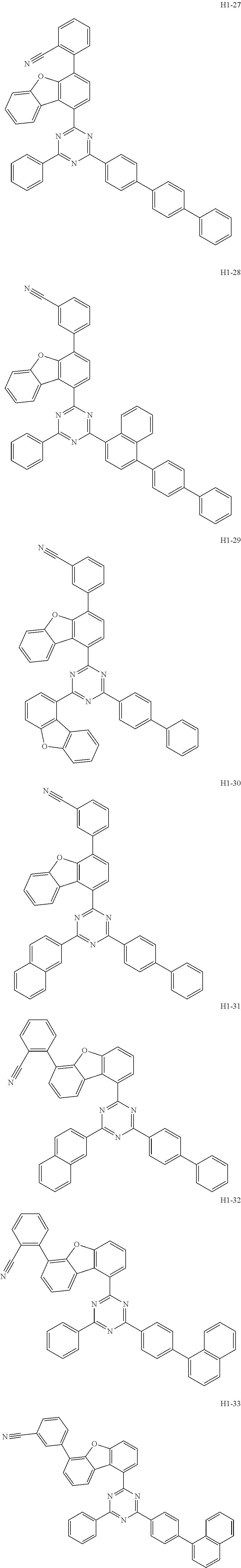

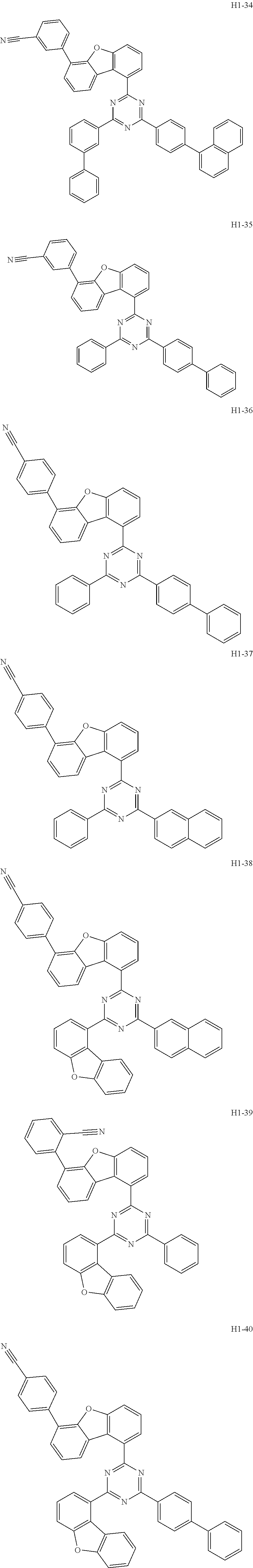

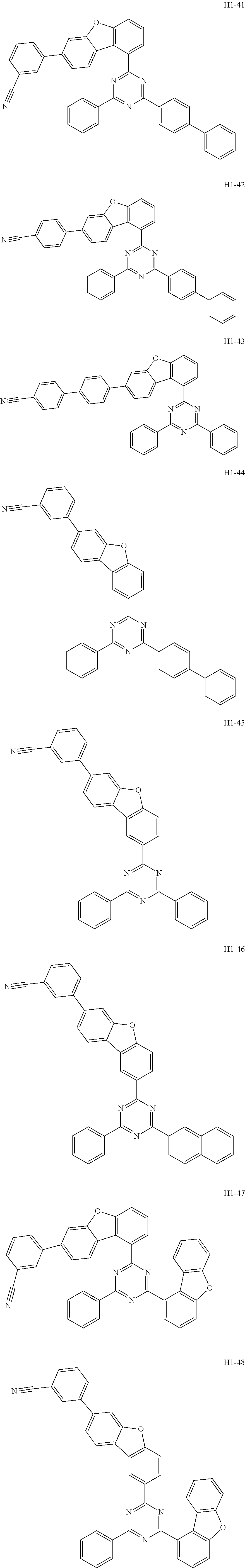

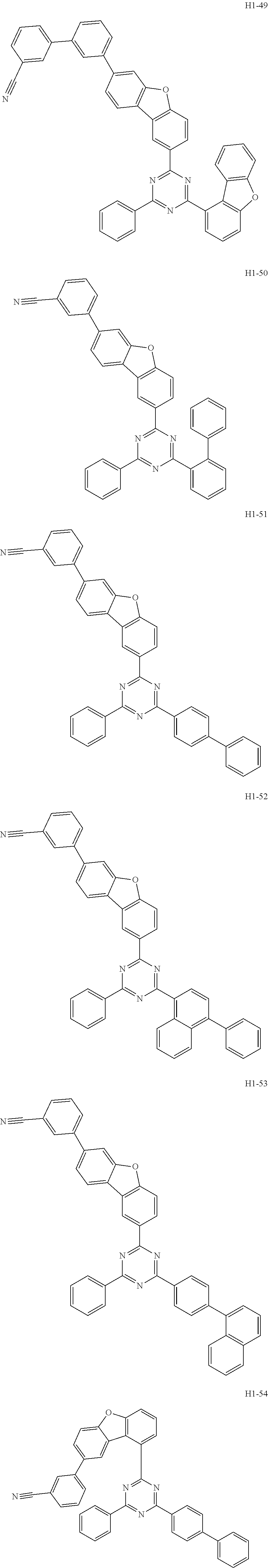

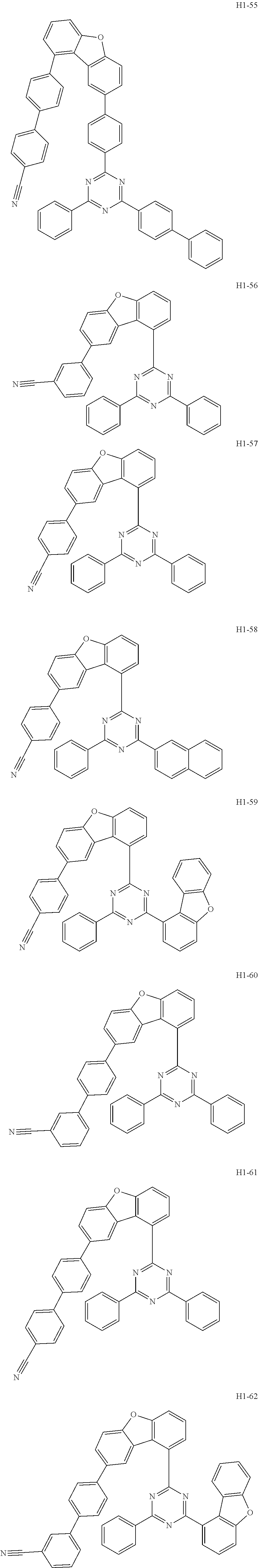

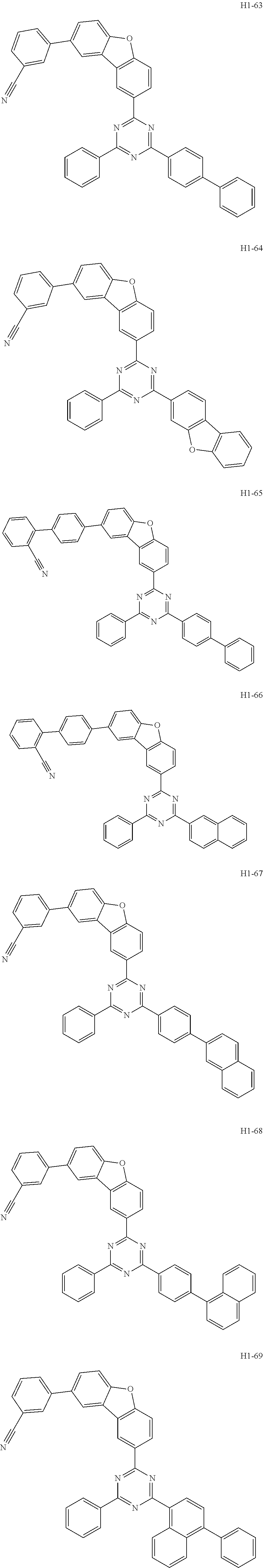

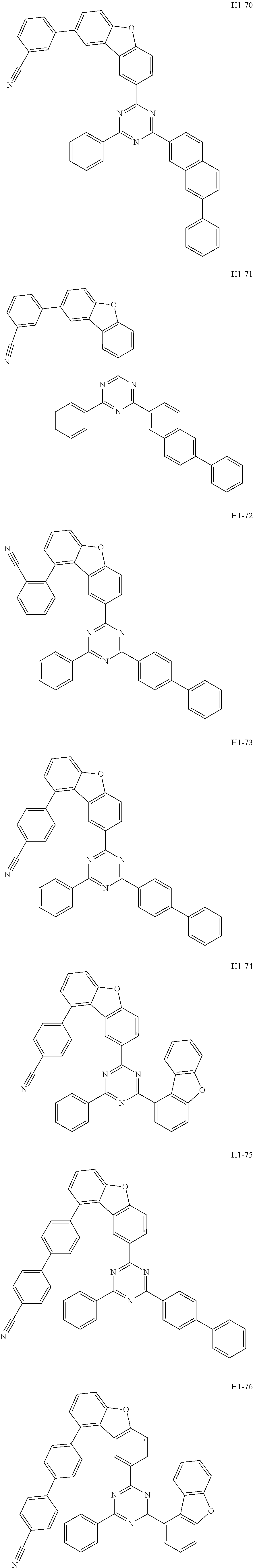

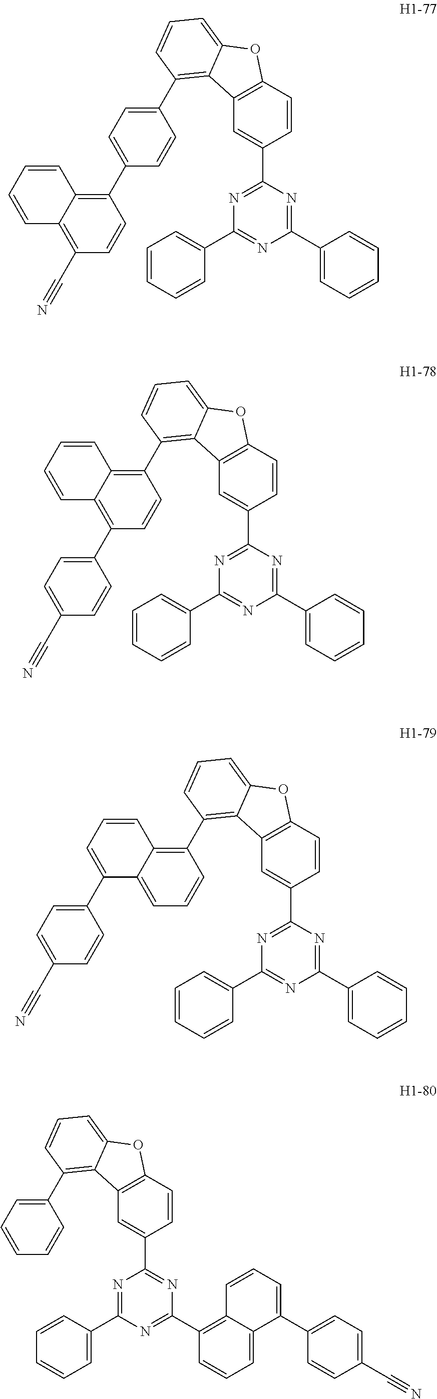 [SMILES: N#Cc1ccc(-c2ccc(-c3cccc4oc5ccc(-c6nc(-c7ccccc7)nc(-c7ccccc7)n6)cc5c34)cc2)c2ccccc12 ; N#Cc1ccc(-c2ccc(-c3cccc4oc5ccc(-c6nc(-c7ccccc7)nc(-c7ccccc7)n6)cc5c34)c3ccccc23)cc1 ; N#Cc1ccc(-c2cccc3c(-c4cccc5oc6ccc(-c7nc(-c8ccccc8)nc(-c8ccccc8)n7)cc6c45)cccc23)cc1 ; N#Cc1ccc(-c2cccc3c(-c4nc(-c5ccccc5)nc(-c5ccc6oc7cccc(-c8ccccc8)c7c6c5)n4)cccc23)cc1]

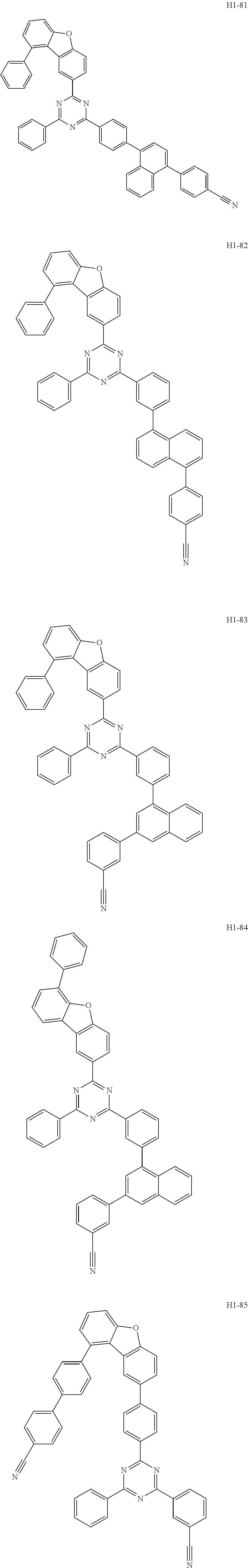 [SMILES: N#Cc1ccc(-c2ccc(-c3ccc(-c4nc(-c5ccccc5)nc(-c5ccc6oc7cccc(-c8ccccc8)c7c6c5)n4)cc3)c3ccccc23)cc1 ; N#Cc1ccc(-c2cccc3c(-c4cccc(-c5nc(-c6ccccc6)nc(-c6ccc7oc8cccc(-c9ccccc9)c8c7c6)n5)c4)cccc23)cc1 ; N#Cc1cccc(-c2cc(-c3cccc(-c4nc(-c5ccccc5)nc(-c5ccc6oc7cccc(-c8ccccc8)c7c6c5)n4)c3)c3ccccc3c2)c1 ; N#Cc1cccc(-c2cc(-c3cccc(-c4nc(-c5ccccc5)nc(-c5ccc6oc7c(-c8ccccc8)cccc7c6c5)n4)c3)c3ccccc3c2)c1 ; N#Cc1ccc(-c2ccc(-c3cccc4oc5ccc(-c6ccc(-c7nc(-c8ccccc8)nc(-c8cccc(C#N)c8)n7)cc6)cc5c34)cc2)cc1]

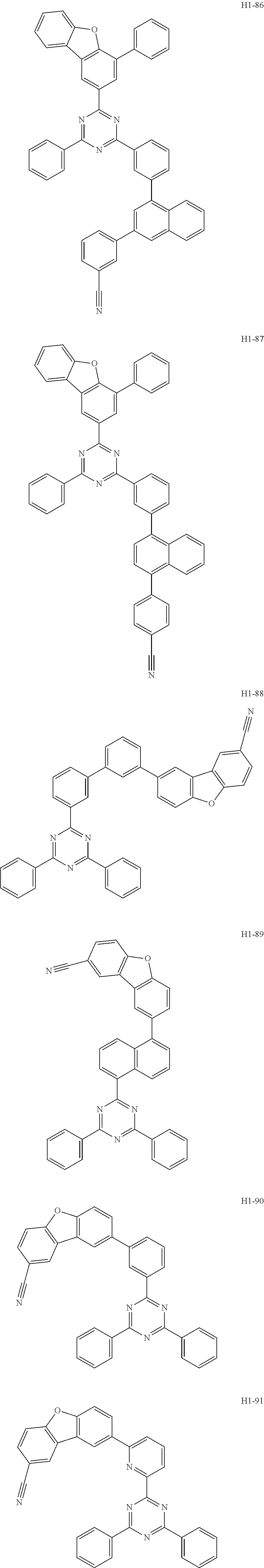 [SMILES: N#Cc1cccc(-c2cc(-c3cccc(-c4nc(-c5ccccc5)nc(-c5cc(-c6ccccc6)c6oc7ccccc7c6c5)n4)c3)c3ccccc3c2)c1 ; N#Cc1ccc(-c2ccc(-c3cccc(-c4nc(-c5ccccc5)nc(-c5cc(-c6ccccc6)c6oc7ccccc7c6c5)n4)c3)c3ccccc23)cc1 ; N#Cc1ccc2oc3ccc(-c4cccc(-c5cccc(-c6nc(-c7ccccc7)nc(-c7ccccc7)n6)c5)c4)cc3c2c1 ; N#Cc1ccc2oc3ccc(-c4cccc5c(-c6nc(-c7ccccc7)nc(-c7ccccc7)n6)cccc45)cc3c2c1 ; N#Cc1ccc2oc3ccc(-c4cccc(-c5nc(-c6ccccc6)nc(-c6ccccc6)n5)c4)cc3c2c1 ; N#Cc1ccc2oc3ccc(-c4cccc(-c5nc(-c6ccccc6)nc(-c6ccccc6)n5)n4)cc3c2c1]

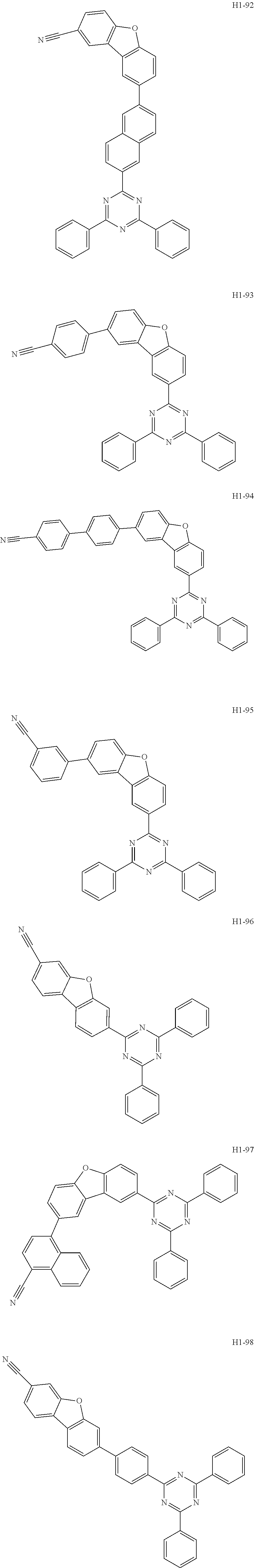

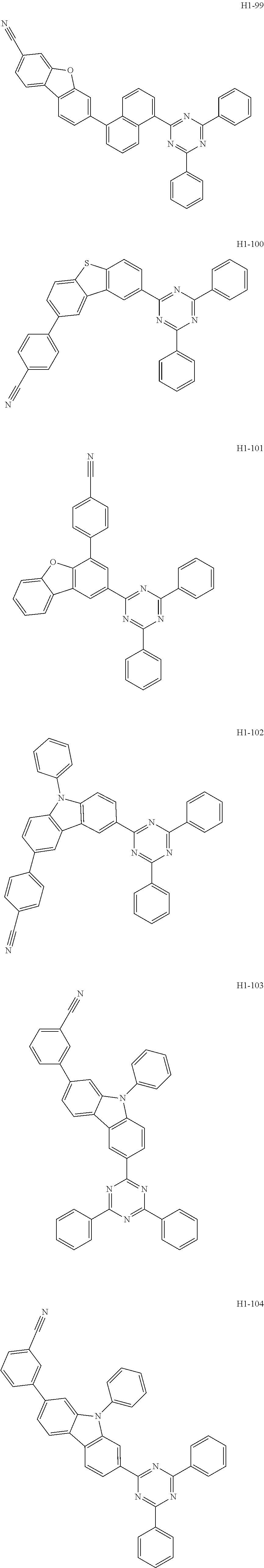 [SMILES: N#Cc1ccc2c(c1)oc1cc(-c3cccc4c(-c5nc(-c6ccccc6)nc(-c6ccccc6)n5)cccc34)ccc12 ; N#Cc1ccc(-c2ccc3sc4ccc(-c5nc(-c6ccccc6)nc(-c6ccccc6)n5)cc4c3c2)cc1 ; N#Cc1ccc(-c2cc(-c3nc(-c4ccccc4)nc(-c4ccccc4)n3)cc3c2oc2ccccc23)cc1 ; N#Cc1ccc(-c2ccc3c(c2)c2cc(-c4nc(-c5ccccc5)nc(-c5ccccc5)n4)ccc2n3-c2ccccc2)cc1 ; N#Cc1cccc(-c2ccc3c4cc(-c5nc(-c6ccccc6)nc(-c6ccccc6)n5)ccc4n(-c4ccccc4)c3c2)c1 ; N#Cc1cccc(-c2ccc3c4ccc(-c5nc(-c6ccccc6)nc(-c6ccccc6)n5)cc4n(-c4ccccc4)c3c2)c1]

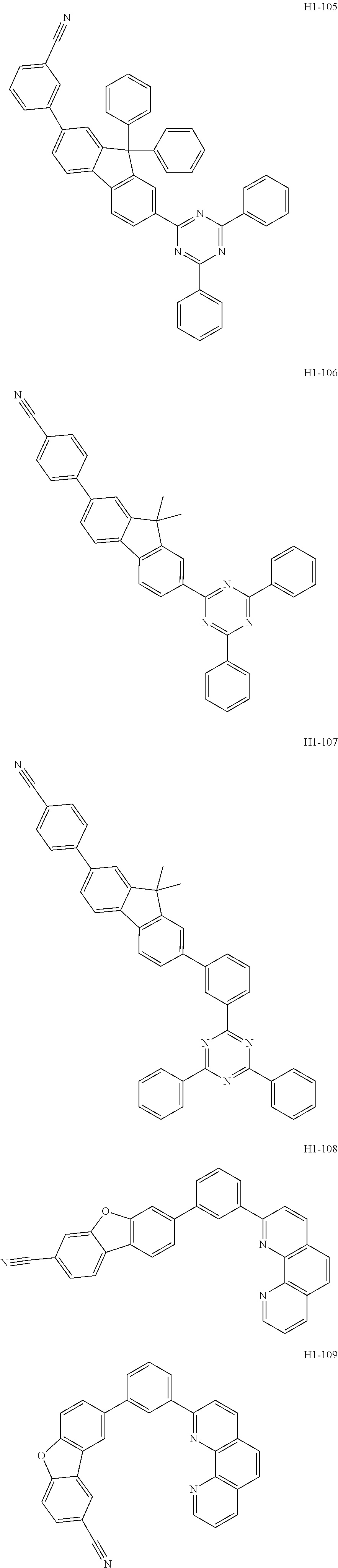 [SMILES: N#Cc1cccc(-c2ccc3c(c2)C(c2ccccc2)(c2ccccc2)c2cc(-c4nc(-c5ccccc5)nc(-c5ccccc5)n4)ccc2-3)c1 ; CC1(C)c2cc(-c3ccc(C#N)cc3)ccc2-c2ccc(-c3nc(-c4ccccc4)nc(-c4ccccc4)n3)cc21 ; CC1(C)c2cc(-c3ccc(C#N)cc3)ccc2-c2ccc(-c3cccc(-c4nc(-c5ccccc5)nc(-c5ccccc5)n4)c3)cc21 ; N#Cc1ccc2c(c1)oc1cc(-c3cccc(-c4ccc5ccc6cccnc6c5n4)c3)ccc12 ; N#Cc1ccc2oc3ccc(-c4cccc(-c5ccc6ccc7cccnc7c6n5)c4)cc3c2c1]

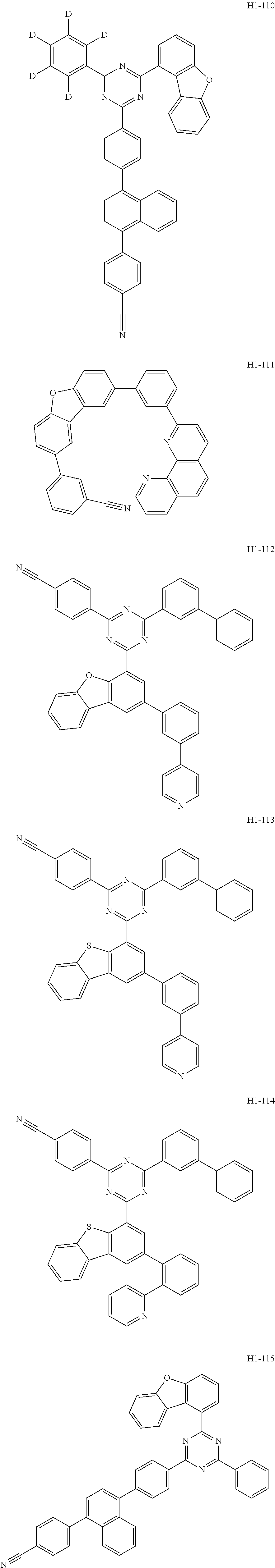

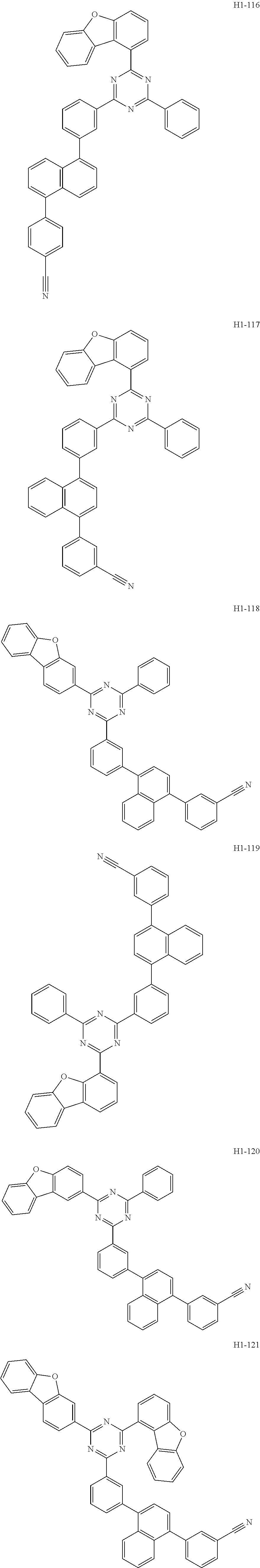

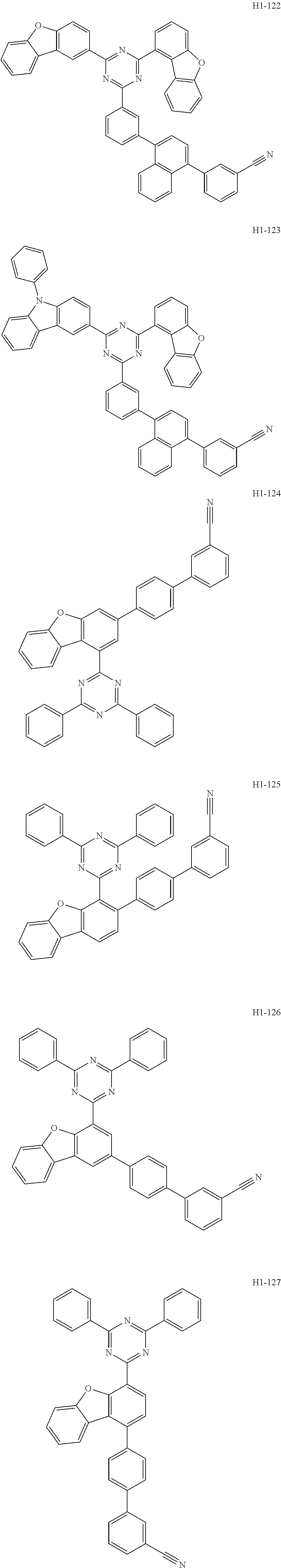

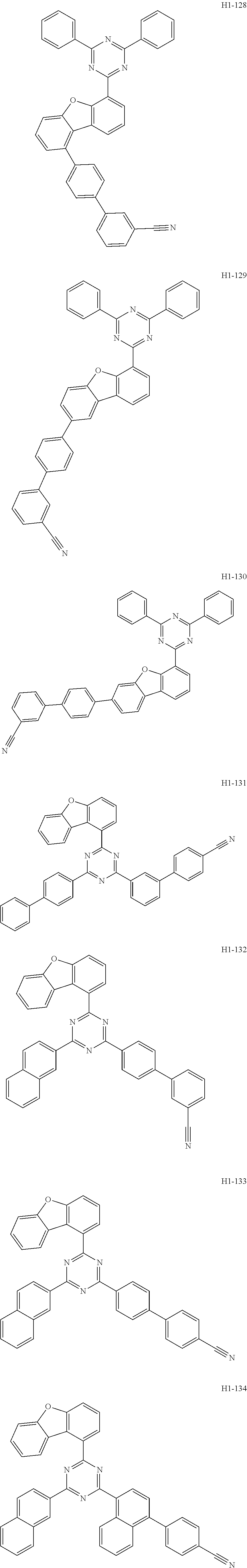

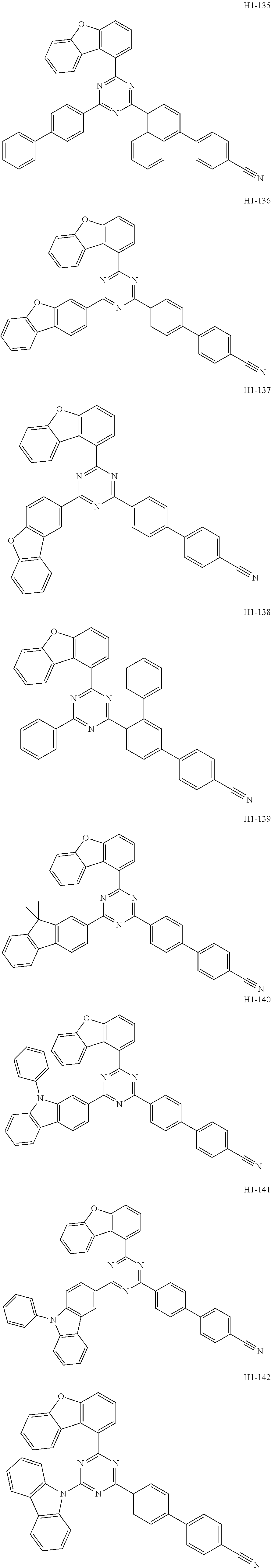

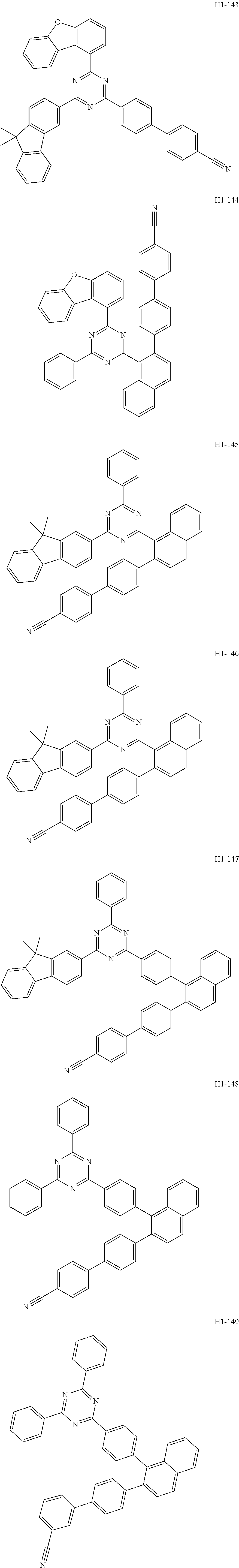

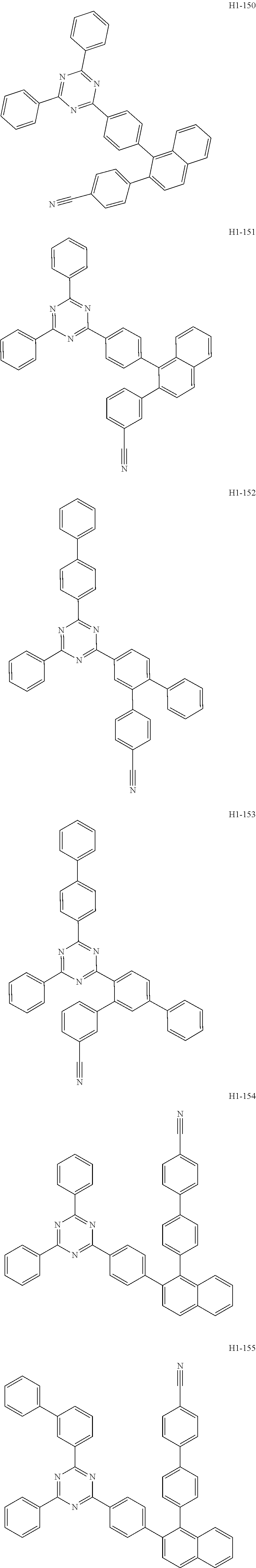 [SMILES: N#Cc1ccc(-c2ccc3ccccc3c2-c2ccc(-c3nc(-c4ccccc4)nc(-c4ccccc4)n3)cc2)cc1 ; N#Cc1cccc(-c2ccc3ccccc3c2-c2ccc(-c3nc(-c4ccccc4)nc(-c4ccccc4)n3)cc2)c1 ; N#Cc1ccc(-c2cc(-c3nc(-c4ccccc4)nc(-c4ccc(-c5ccccc5)cc4)n3)ccc2-c2ccccc2)cc1 ; N#Cc1cccc(-c2cc(-c3ccccc3)ccc2-c2nc(-c3ccccc3)nc(-c3ccc(-c4ccccc4)cc3)n2)c1 ; N#Cc1ccc(-c2ccc(-c3c(-c4ccc(-c5nc(-c6ccccc6)nc(-c6ccccc6)n5)cc4)ccc4ccccc34)cc2)cc1 ; N#Cc1ccc(-c2ccc(-c3c(-c4ccc(-c5nc(-c6ccccc6)nc(-c6cccc(-c7ccccc7)c6)n5)cc4)ccc4ccccc34)cc2)cc1]

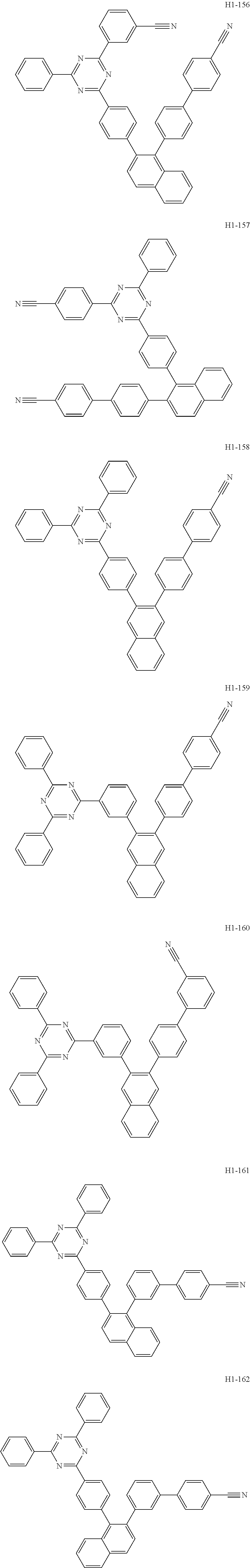

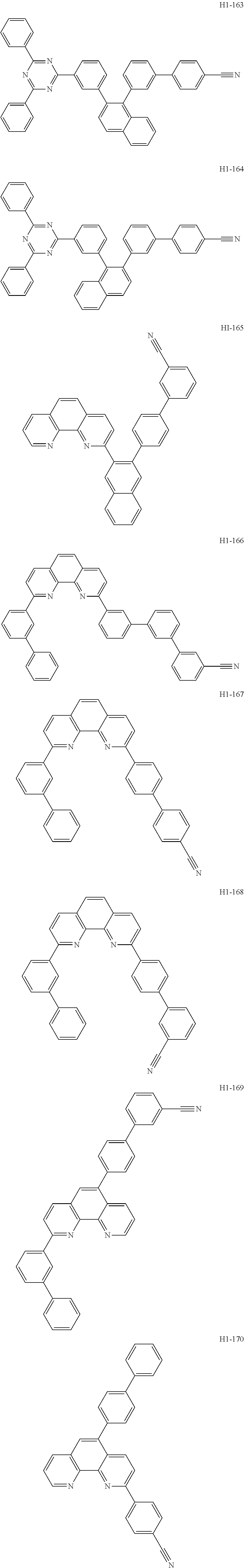

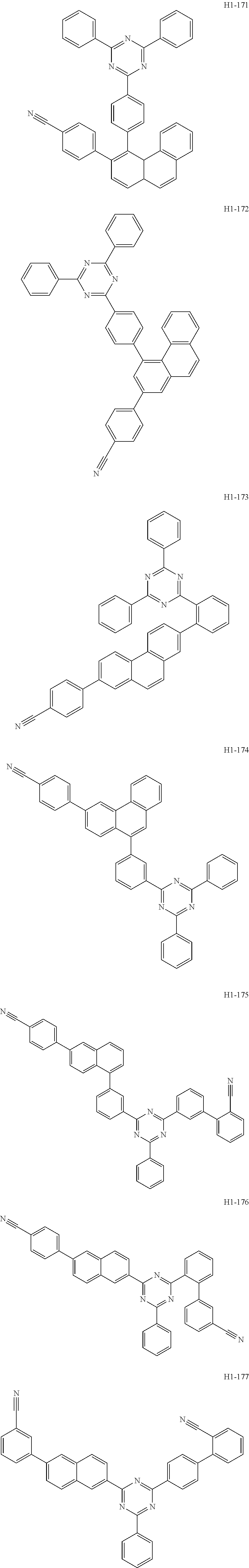

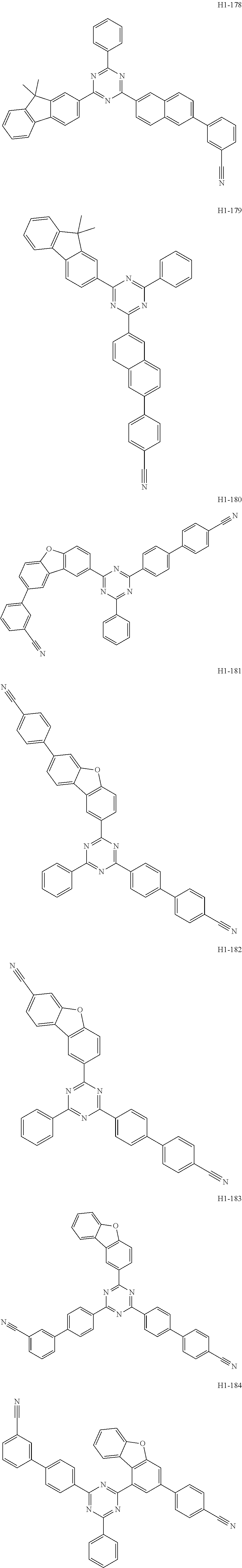

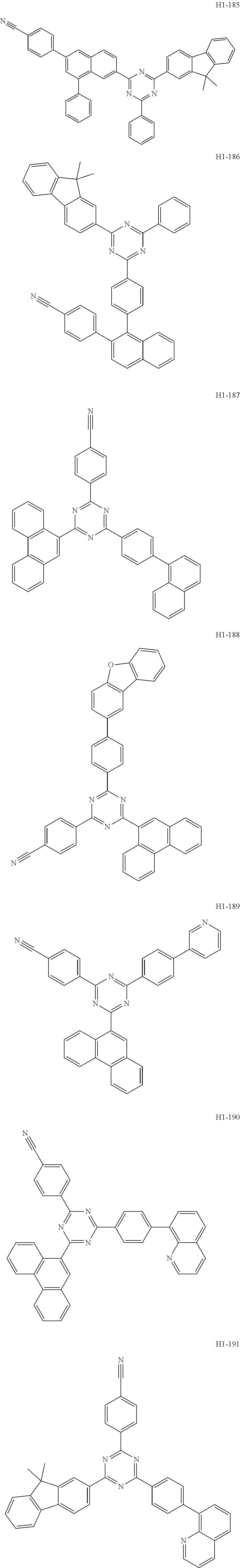

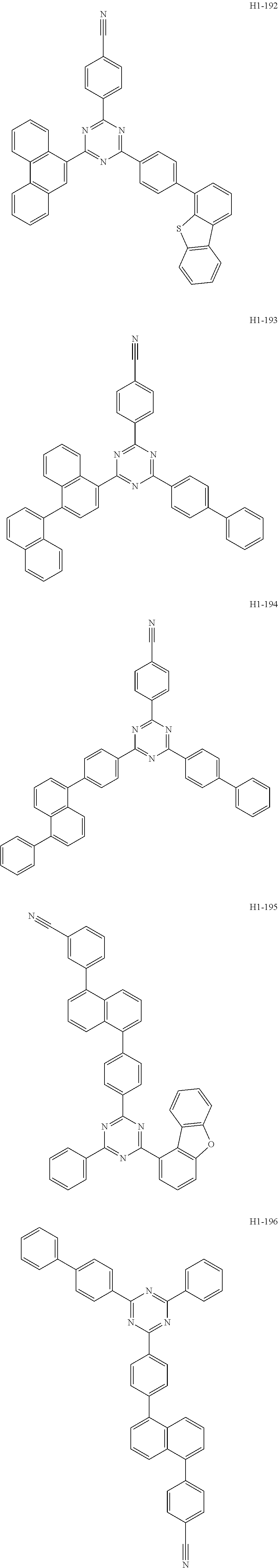 [SMILES: N#Cc1ccc(-c2nc(-c3ccc(-c4cccc5c4sc4ccccc45)cc3)nc(-c3cc4ccccc4c4ccccc34)n2)cc1 ; N#Cc1ccc(-c2nc(-c3ccc(-c4ccccc4)cc3)nc(-c3ccc(-c4cccc5ccccc45)c4ccccc34)n2)cc1 ; N#Cc1ccc(-c2nc(-c3ccc(-c4ccccc4)cc3)nc(-c3ccc(-c4cccc5c(-c6ccccc6)cccc45)cc3)n2)cc1 ; N#Cc1cccc(-c2cccc3c(-c4ccc(-c5nc(-c6ccccc6)nc(-c6cccc7oc8ccccc8c67)n5)cc4)cccc23)c1 ; N#Cc1ccc(-c2cccc3c(-c4ccc(-c5nc(-c6ccccc6)nc(-c6ccc(-c7ccccc7)cc6)n5)cc4)cccc23)cc1]

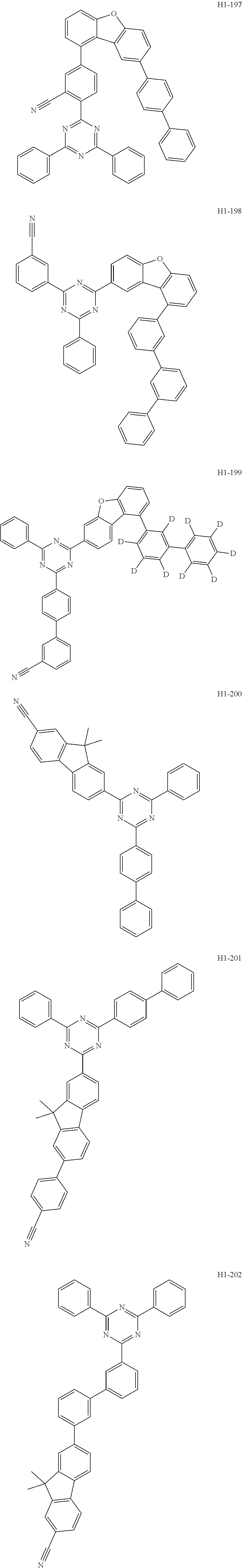

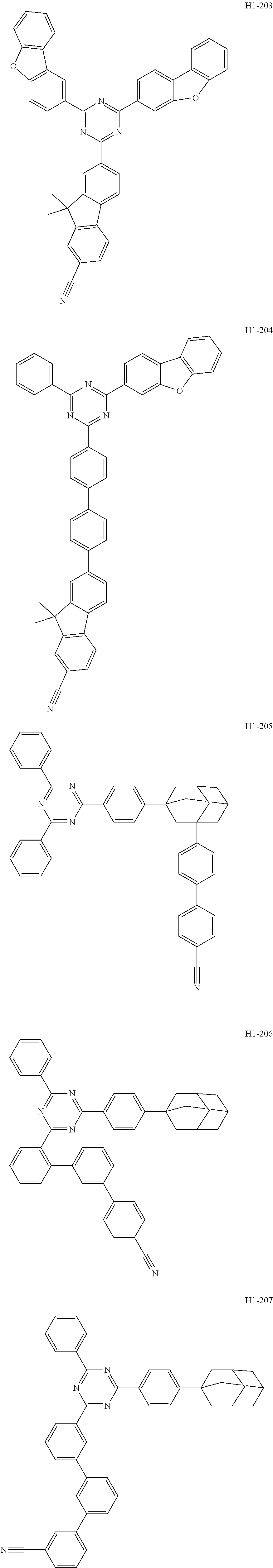

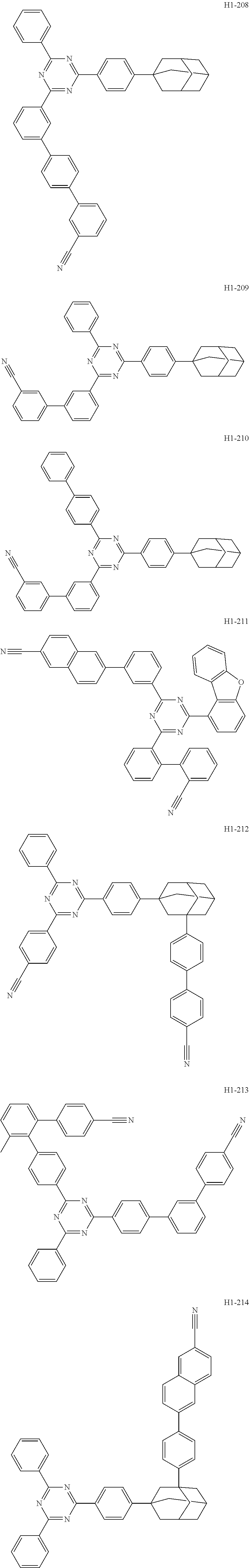

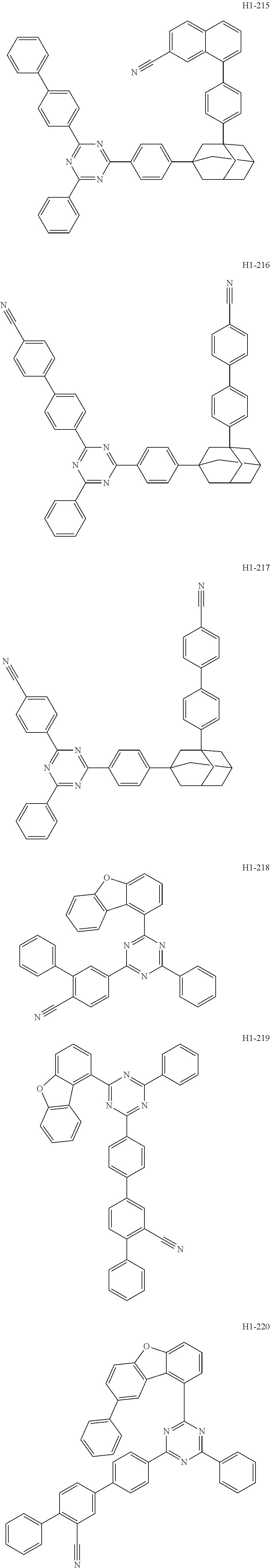

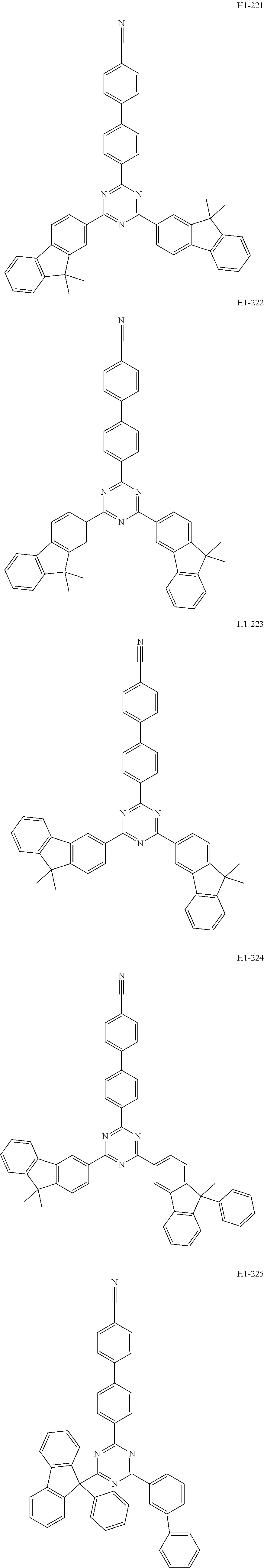 [SMILES: CC1(C)c2ccccc2-c2ccc(-c3nc(-c4ccc(-c5ccc(C#N)cc5)cc4)nc(-c4ccc5c(c4)C(C)(C)c4ccccc4-5)n3)cc21 ; CC1(C)c2ccccc2-c2cc(-c3nc(-c4ccc(-c5ccc(C#N)cc5)cc4)nc(-c4ccc5c(c4)C(C)(C)c4ccccc4-5)n3)ccc21 ; CC1(C)c2ccccc2-c2cc(-c3nc(-c4ccc(-c5ccc(C#N)cc5)cc4)nc(-c4ccc5c(c4)-c4ccccc4C5(C)C)n3)ccc21 ; CC1(C)c2ccccc2-c2cc(-c3nc(-c4ccc(-c5ccc(C#N)cc5)cc4)nc(-c4ccc5c(c4)-c4ccccc4C5(C)c4ccccc4)n3)ccc21 ; N#Cc1ccc(-c2ccc(-c3nc(-c4cccc(-c5ccccc5)c4)nc(C4(c5ccccc5)c5ccccc5-c5ccccc54)n3)cc2)cc1]

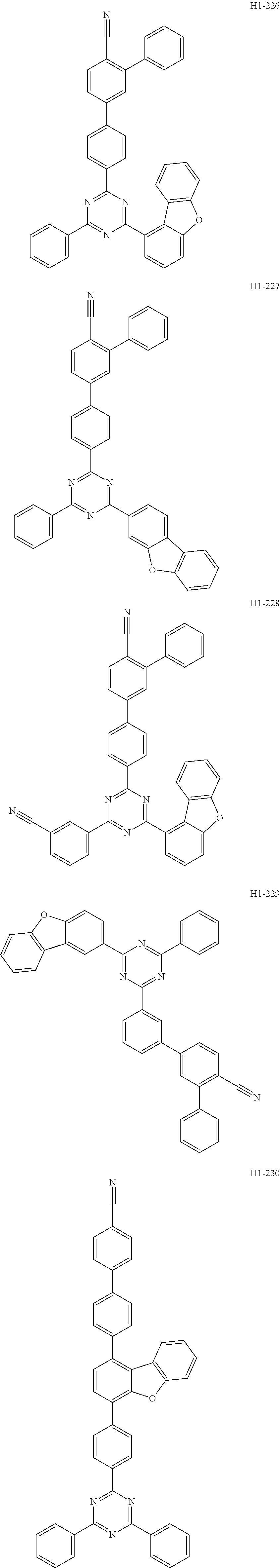 [SMILES: N#Cc1ccc(-c2ccc(-c3nc(-c4ccccc4)nc(-c4cccc5oc6ccccc6c45)n3)cc2)cc1-c1ccccc1 ; N#Cc1ccc(-c2ccc(-c3nc(-c4ccccc4)nc(-c4ccc5c(c4)oc4ccccc45)n3)cc2)cc1-c1ccccc1 ; N#Cc1cccc(-c2nc(-c3ccc(-c4ccc(C#N)c(-c5ccccc5)c4)cc3)nc(-c3cccc4oc5ccccc5c34)n2)c1 ; N#Cc1ccc(-c2cccc(-c3nc(-c4ccccc4)nc(-c4ccc5oc6ccccc6c5c4)n3)c2)cc1-c1ccccc1 ; N#Cc1ccc(-c2ccc(-c3ccc(-c4ccc(-c5nc(-c6ccccc6)nc(-c6ccccc6)n5)cc4)c4oc5ccccc5c34)cc2)cc1]

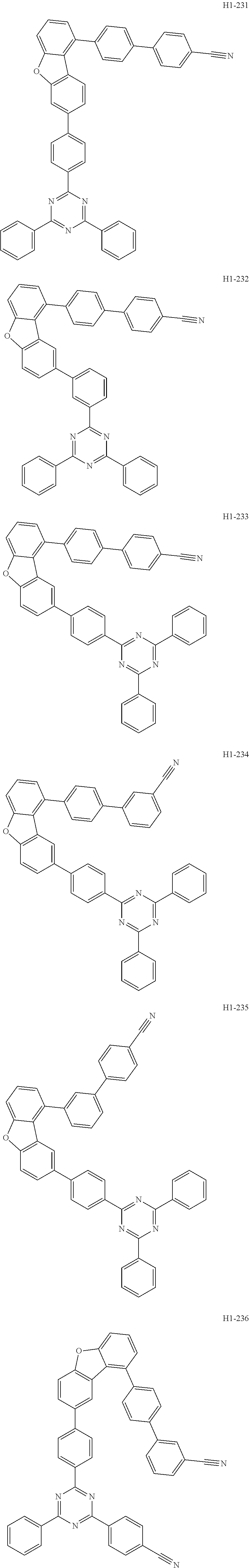

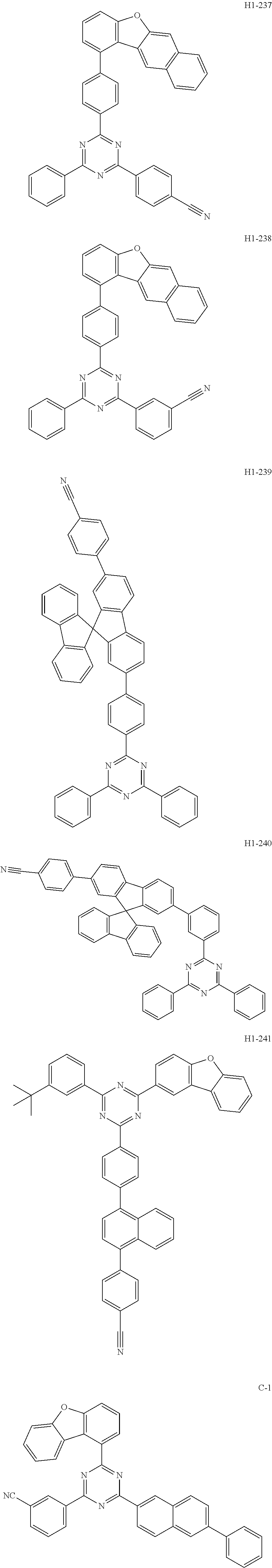

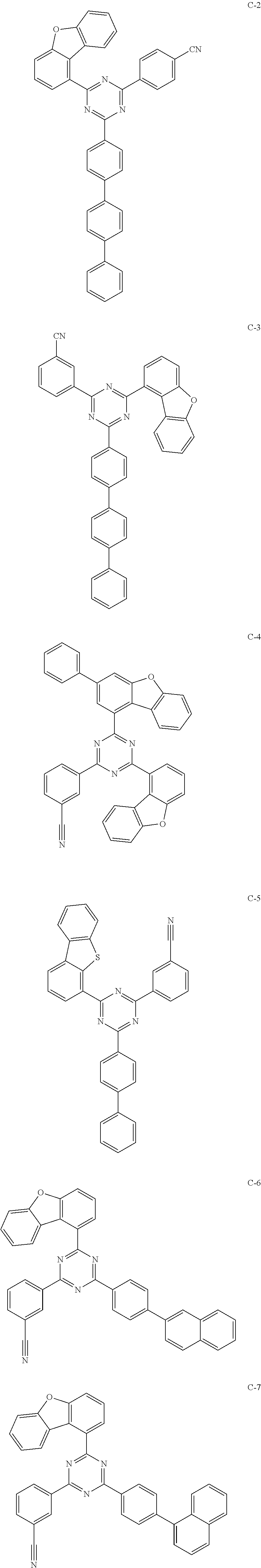 [SMILES: N#Cc1ccc(-c2nc(-c3ccc(-c4ccc(-c5ccccc5)cc4)cc3)nc(-c3cccc4oc5ccccc5c34)n2)cc1 ; N#Cc1cccc(-c2nc(-c3ccc(-c4ccc(-c5ccccc5)cc4)cc3)nc(-c3cccc4oc5ccccc5c34)n2)c1 ; N#Cc1cccc(-c2nc(-c3cccc4oc5ccccc5c34)nc(-c3cc(-c4ccccc4)cc4oc5ccccc5c34)n2)c1 ; N#Cc1cccc(-c2nc(-c3ccc(-c4ccccc4)cc3)nc(-c3cccc4c3sc3ccccc34)n2)c1 ; N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4cccc5ccccc45)cc3)nc(-c3cccc4oc5ccccc5c34)n2)c1]

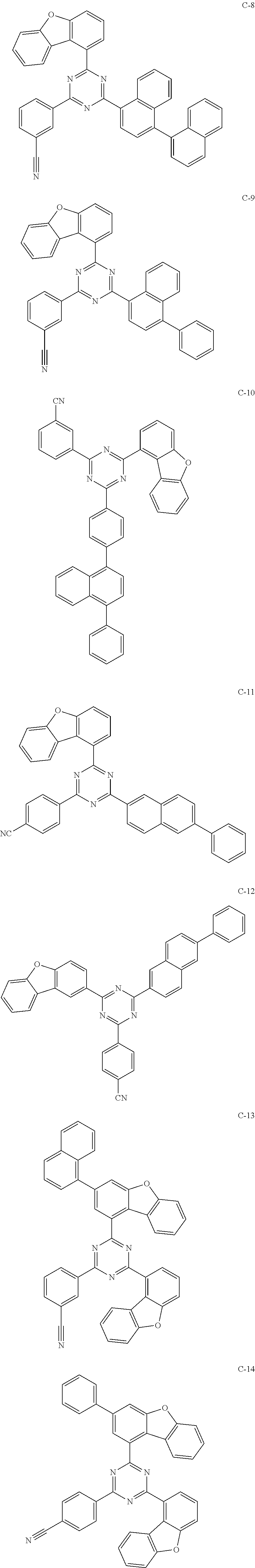

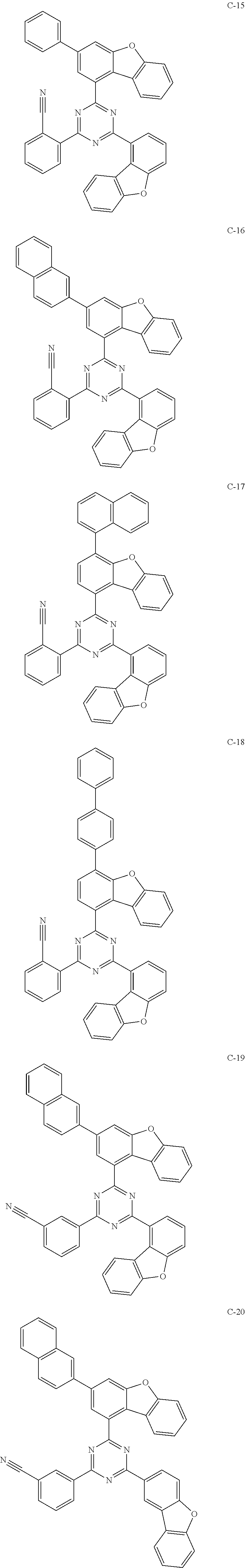

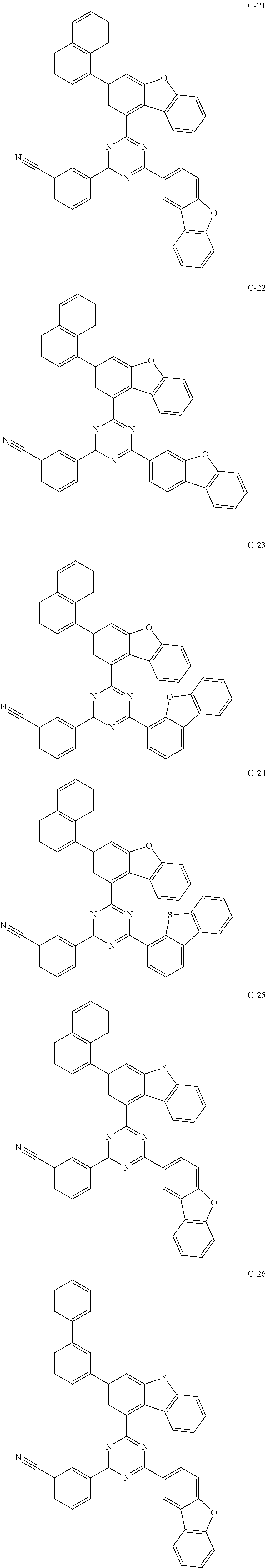

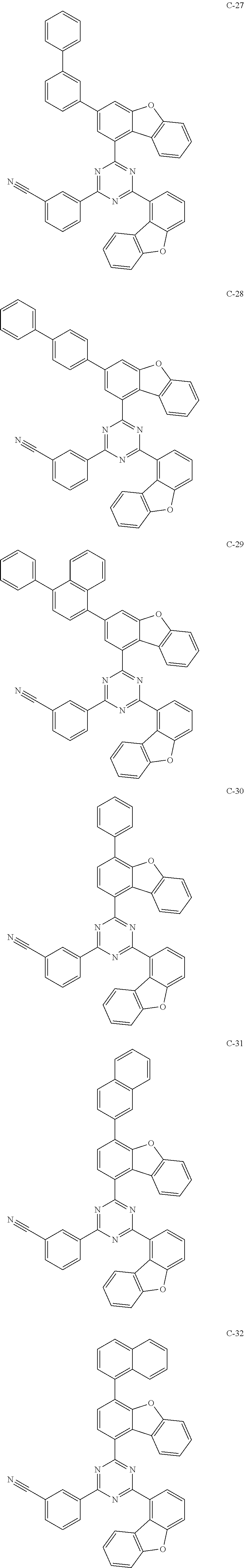

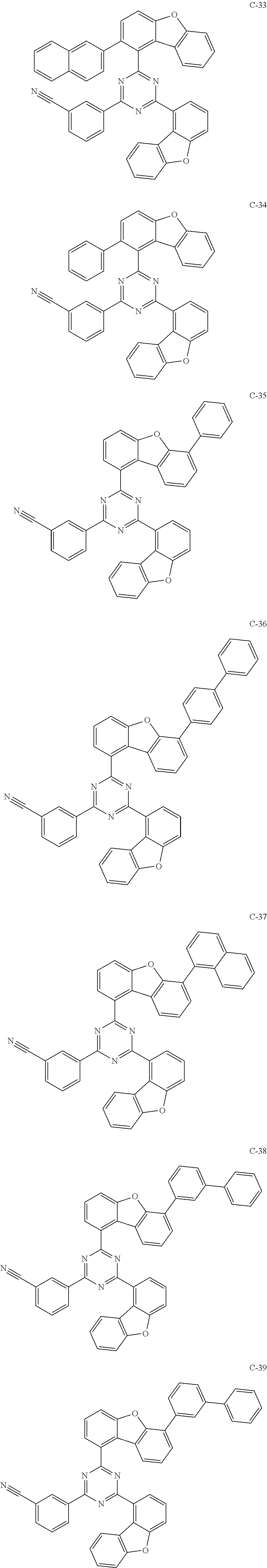

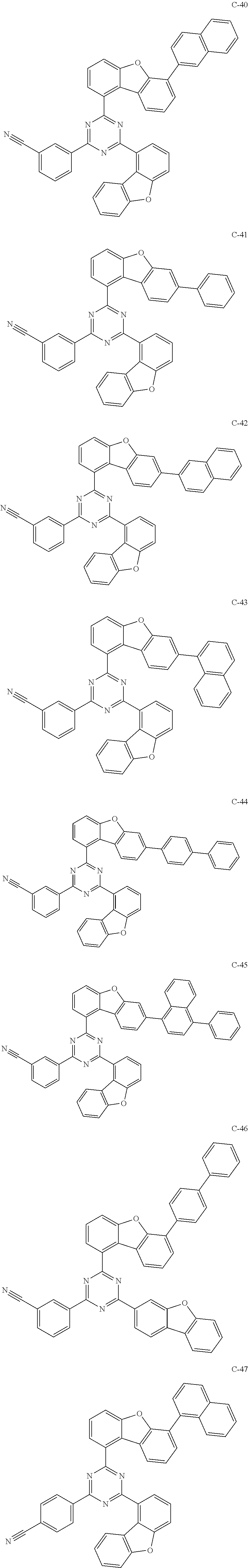

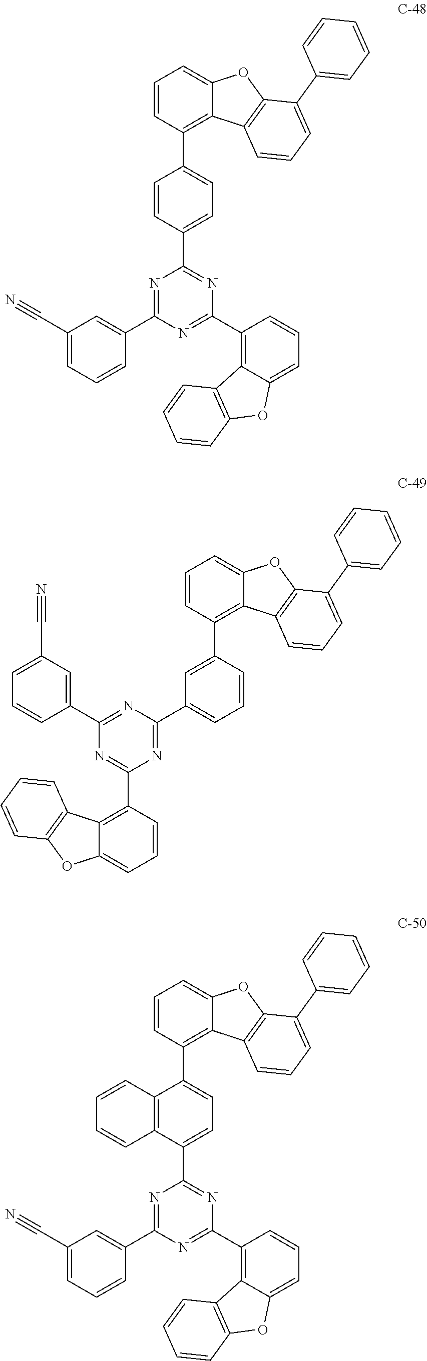 [SMILES: N#Cc1cccc(-c2nc(-c3ccc(-c4cccc5oc6c(-c7ccccc7)cccc6c45)cc3)nc(-c3cccc4oc5ccccc5c34)n2)c1 ; N#Cc1cccc(-c2nc(-c3cccc(-c4cccc5oc6c(-c7ccccc7)cccc6c45)c3)nc(-c3cccc4oc5ccccc5c34)n2)c1 ; N#Cc1cccc(-c2nc(-c3ccc(-c4cccc5oc6c(-c7ccccc7)cccc6c45)c4ccccc34)nc(-c3cccc4oc5ccccc5c34)n2)c1]

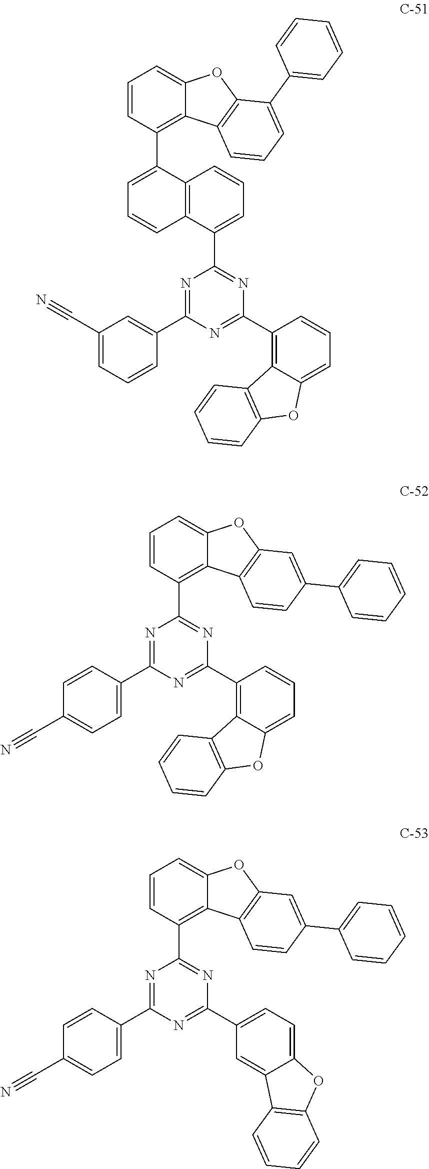 [SMILES: N#Cc1cccc(-c2nc(-c3cccc4c(-c5cccc6oc7c(-c8ccccc8)cccc7c56)cccc34)nc(-c3cccc4oc5ccccc5c34)n2)c1 ; N#Cc1ccc(-c2nc(-c3cccc4oc5ccccc5c34)nc(-c3cccc4oc5cc(-c6ccccc6)ccc5c34)n2)cc1 ; N#Cc1ccc(-c2nc(-c3ccc4oc5ccccc5c4c3)nc(-c3cccc4oc5cc(-c6ccccc6)ccc5c34)n2)cc1]

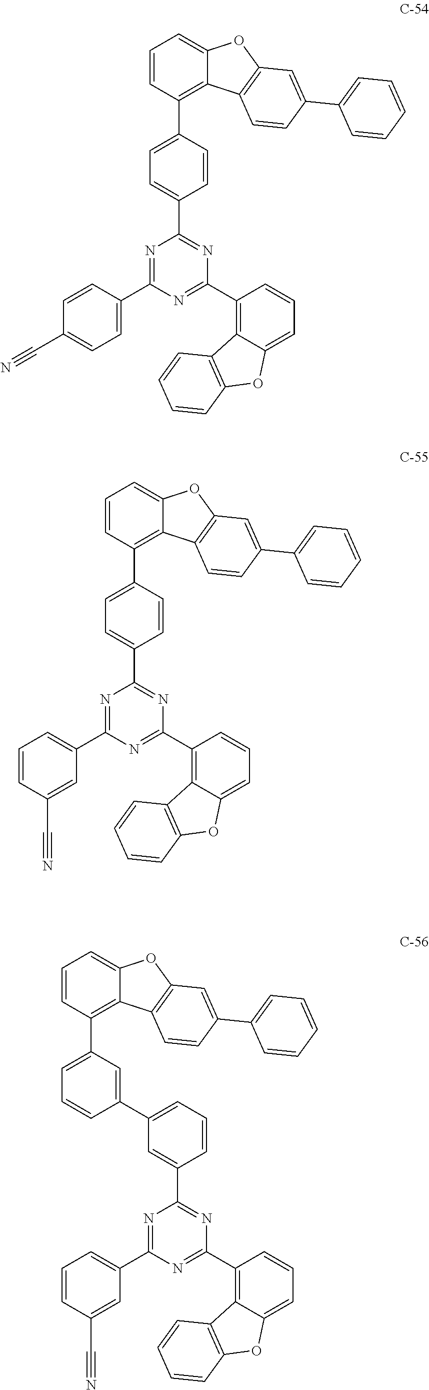 [SMILES: N#Cc1ccc(-c2nc(-c3ccc(-c4cccc5oc6cc(-c7ccccc7)ccc6c45)cc3)nc(-c3cccc4oc5ccccc5c34)n2)cc1 ; N#Cc1cccc(-c2nc(-c3ccc(-c4cccc5oc6cc(-c7ccccc7)ccc6c45)cc3)nc(-c3cccc4oc5ccccc5c34)n2)c1 ; N#Cc1cccc(-c2nc(-c3cccc(-c4cccc(-c5cccc6oc7cc(-c8ccccc8)ccc7c56)c4)c3)nc(-c3cccc4oc5ccccc5c34)n2)c1]

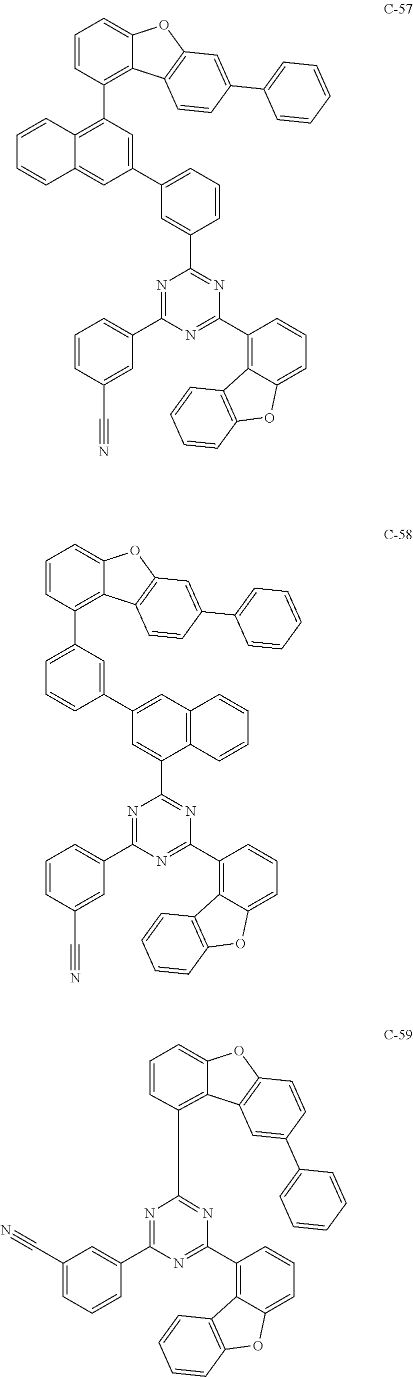 [SMILES: N#Cc1cccc(-c2nc(-c3cccc(-c4cc(-c5cccc6oc7cc(-c8ccccc8)ccc7c56)c5ccccc5c4)c3)nc(-c3cccc4oc5ccccc5c34)n2)c1 ; N#Cc1cccc(-c2nc(-c3cc(-c4cccc(-c5cccc6oc7cc(-c8ccccc8)ccc7c56)c4)cc4ccccc34)nc(-c3cccc4oc5ccccc5c34)n2)c1 ; N#Cc1cccc(-c2nc(-c3cccc4oc5ccccc5c34)nc(-c3cccc4oc5ccc(-c6ccccc6)cc5c34)n2)c1]

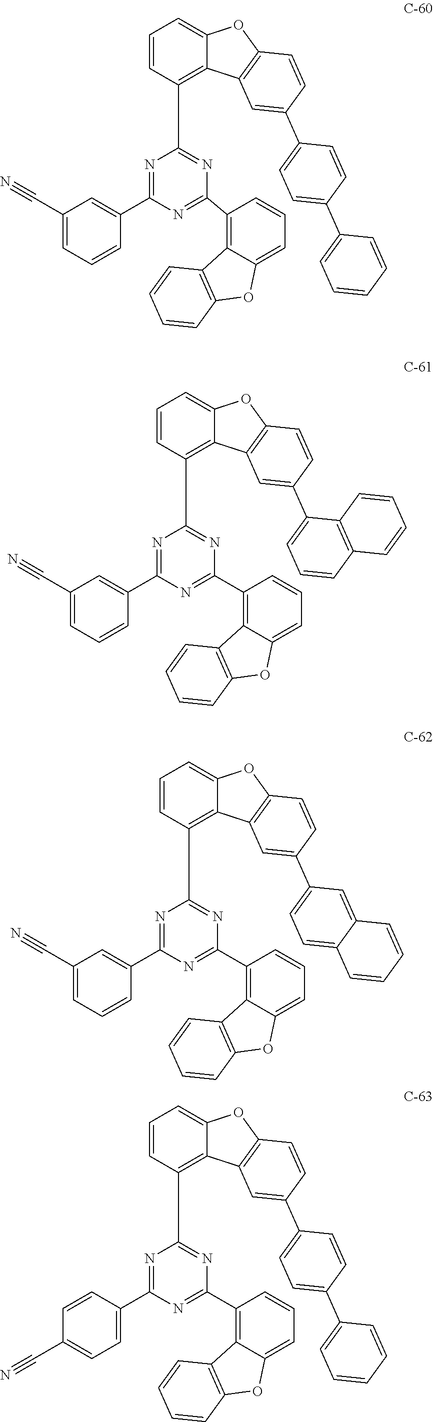

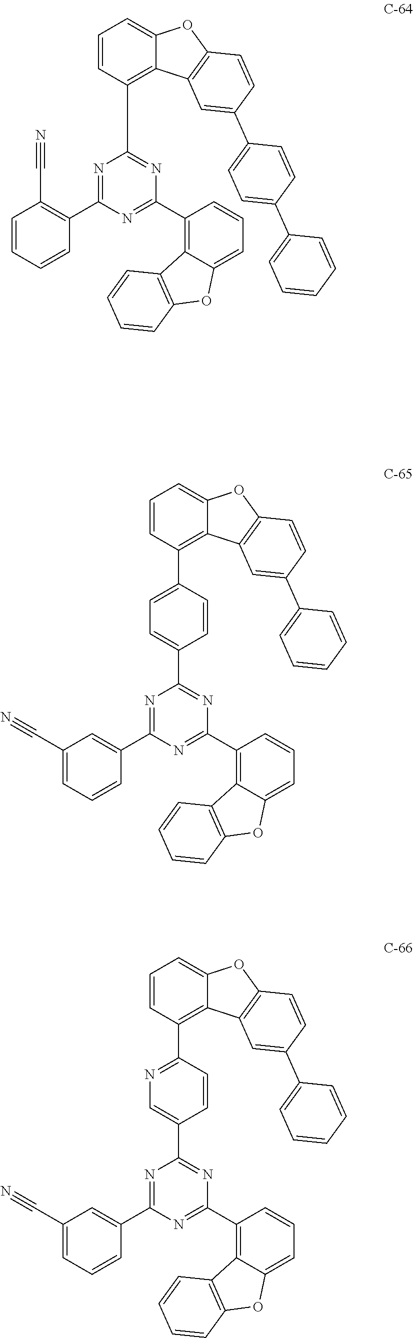 [SMILES: N#Cc1ccccc1-c1nc(-c2cccc3oc4ccccc4c23)nc(-c2cccc3oc4ccc(-c5ccc(-c6ccccc6)cc5)cc4c23)n1 ; N#Cc1cccc(-c2nc(-c3ccc(-c4cccc5oc6ccc(-c7ccccc7)cc6c45)cc3)nc(-c3cccc4oc5ccccc5c34)n2)c1 ; N#Cc1cccc(-c2nc(-c3ccc(-c4cccc5oc6ccc(-c7ccccc7)cc6c45)nc3)nc(-c3cccc4oc5ccccc5c34)n2)c1]

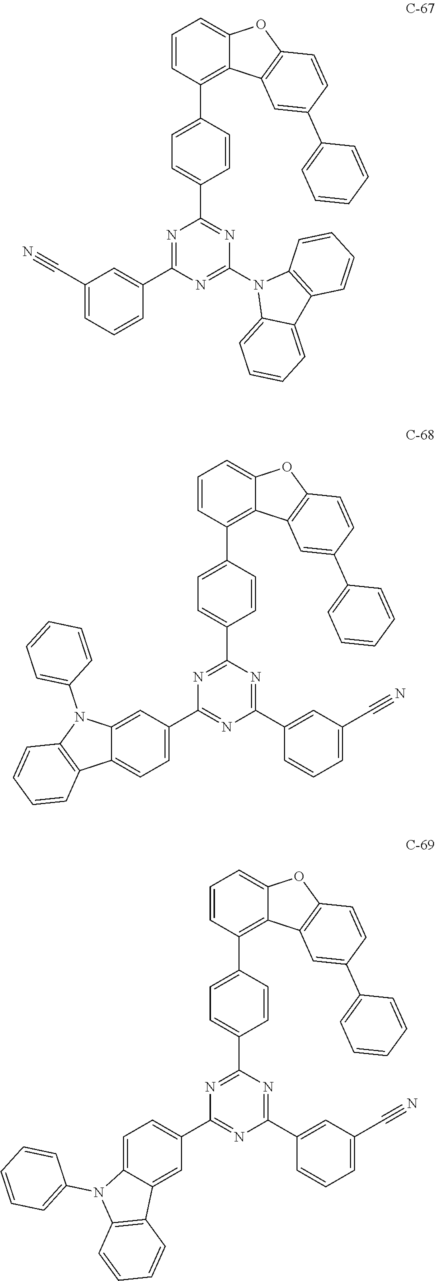 [SMILES: N#Cc1cccc(-c2nc(-c3ccc(-c4cccc5oc6ccc(-c7ccccc7)cc6c45)cc3)nc(-n3c4ccccc4c4ccccc43)n2)c1 ; N#Cc1cccc(-c2nc(-c3ccc(-c4cccc5oc6ccc(-c7ccccc7)cc6c45)cc3)nc(-c3ccc4c5ccccc5n(-c5ccccc5)c4c3)n2)c1 ; N#Cc1cccc(-c2nc(-c3ccc(-c4cccc5oc6ccc(-c7ccccc7)cc6c45)cc3)nc(-c3ccc4c(c3)c3ccccc3n4-c3ccccc3)n2)c1]

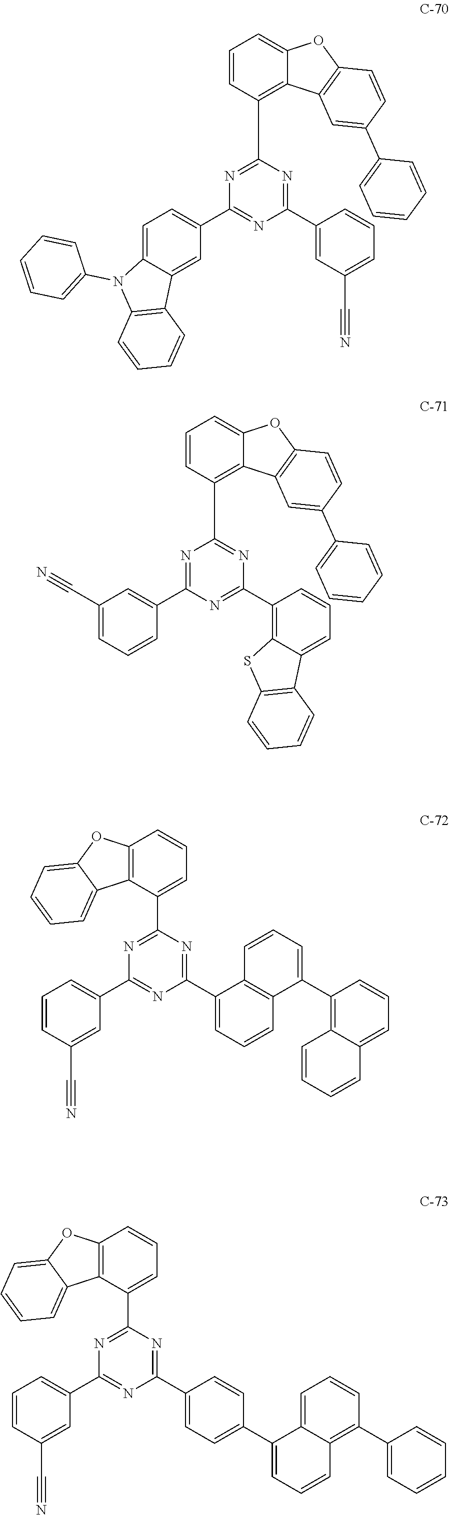 [SMILES: N#Cc1cccc(-c2nc(-c3ccc4c(c3)c3ccccc3n4-c3ccccc3)nc(-c3cccc4oc5ccc(-c6ccccc6)cc5c34)n2)c1 ; N#Cc1cccc(-c2nc(-c3cccc4c3sc3ccccc34)nc(-c3cccc4oc5ccc(-c6ccccc6)cc5c34)n2)c1 ; N#Cc1cccc(-c2nc(-c3cccc4c(-c5cccc6ccccc56)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1]

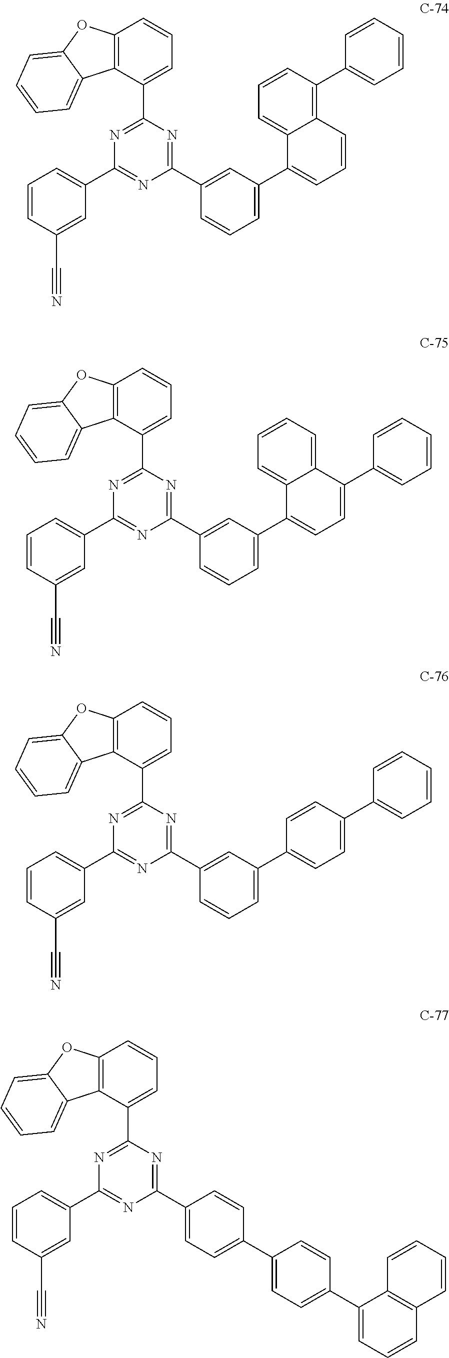 [SMILES: N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1 ; N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3ccc(-c4ccc(-c5cccc6ccccc56)cc4)cc3)nc(-c3cccc4oc5ccccc5c34)n2)c1]

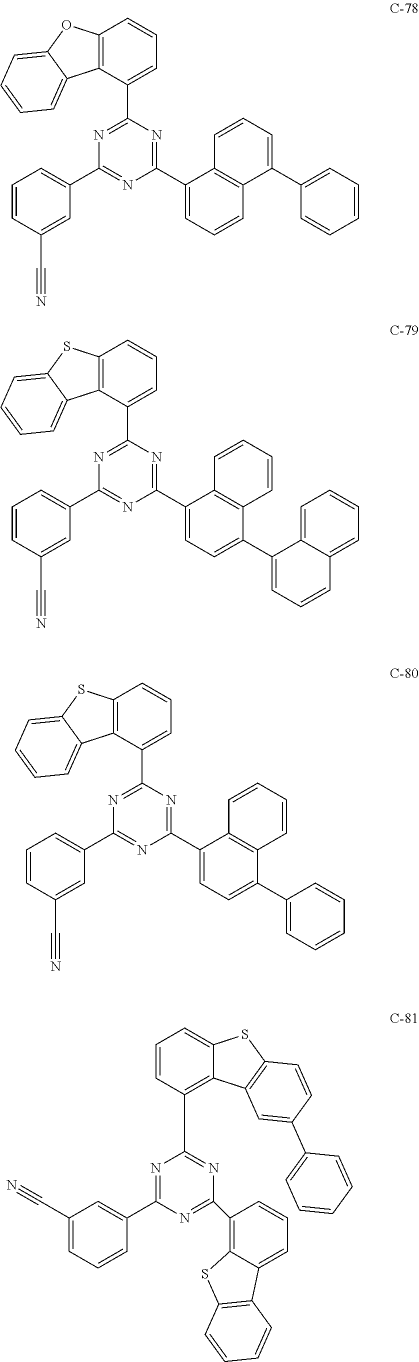 [SMILES: N#Cc1cccc(-c2nc(-c3cccc4c(-c5ccccc5)cccc34)nc(-c3cccc4oc5ccccc5c34)n2)c1 ; N#Cc1cccc(-c2nc(-c3ccc(-c4cccc5ccccc45)c4ccccc34)nc(-c3cccc4sc5ccccc5c34)n2)c1 ; N#Cc1cccc(-c2nc(-c3ccc(-c4ccccc4)c4ccccc34)nc(-c3cccc4sc5ccccc5c34)n2)c1 ; N#Cc1cccc(-c2nc(-c3cccc4c3sc3ccccc34)nc(-c3cccc4sc5ccc(-c6ccccc6)cc5c34)n2)c1]

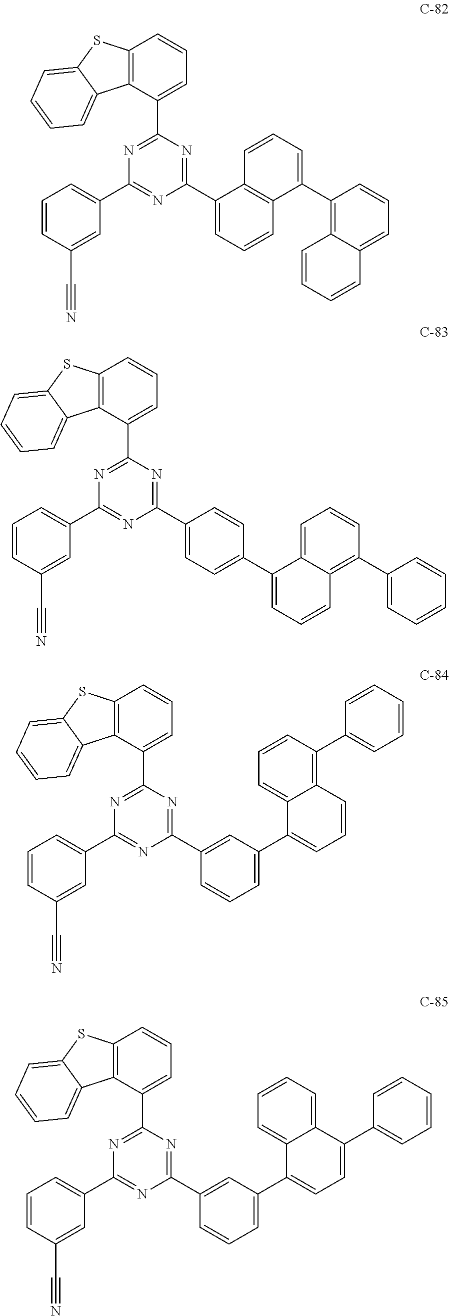

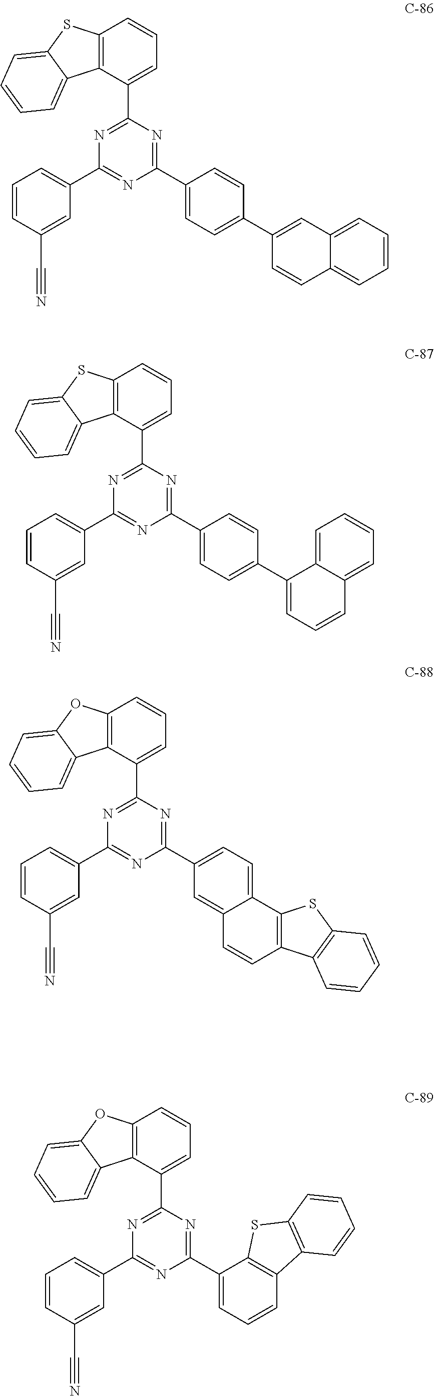 [SMILES: N#Cc1cccc(-c2nc(-c3ccc(-c4ccc5ccccc5c4)cc3)nc(-c3cccc4sc5ccccc5c34)n2)c1 ; N#Cc1cccc(-c2nc(-c3ccc(-c4cccc5ccccc45)cc3)nc(-c3cccc4sc5ccccc5c34)n2)c1 ; N#Cc1cccc(-c2nc(-c3ccc4c(ccc5c6ccccc6sc45)c3)nc(-c3cccc4oc5ccccc5c34)n2)c1 ; N#Cc1cccc(-c2nc(-c3cccc4c3sc3ccccc34)nc(-c3cccc4oc5ccccc5c34)n2)c1]

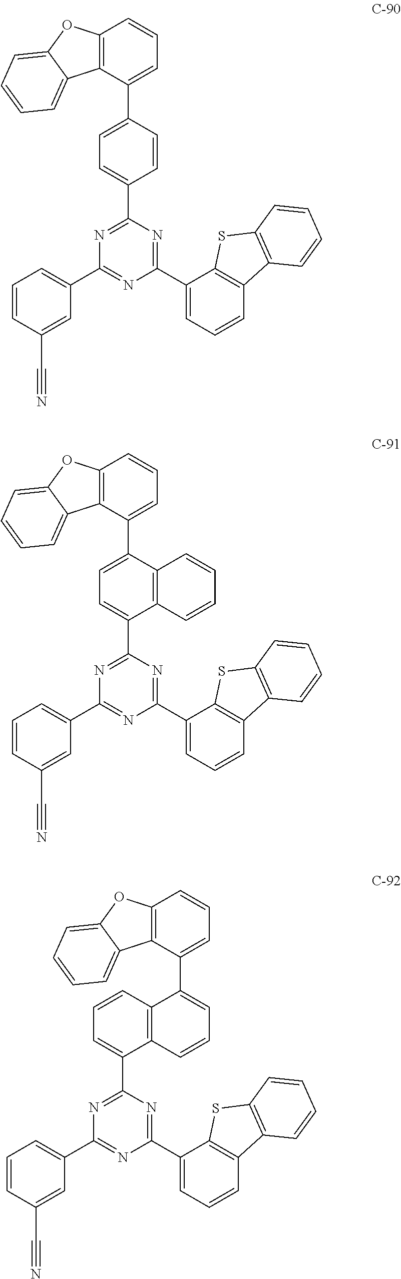 [SMILES: N#Cc1cccc(-c2nc(-c3ccc(-c4cccc5oc6ccccc6c45)cc3)nc(-c3cccc4c3sc3ccccc34)n2)c1 ; N#Cc1cccc(-c2nc(-c3ccc(-c4cccc5oc6ccccc6c45)c4ccccc34)nc(-c3cccc4c3sc3ccccc34)n2)c1 ; N#Cc1cccc(-c2nc(-c3cccc4c(-c5cccc6oc7ccccc7c56)cccc34)nc(-c3cccc4c3sc3ccccc34)n2)c1]

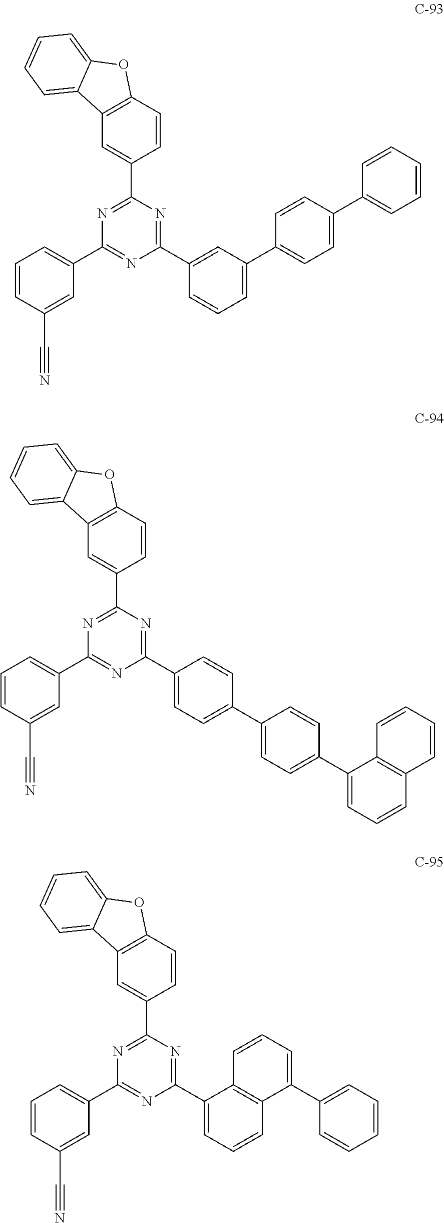 [SMILES: N#Cc1cccc(-c2nc(-c3cccc(-c4ccc(-c5ccccc5)cc4)c3)nc(-c3ccc4oc5ccccc5c4c3)n2)c1 ; N#Cc1cccc(-c2nc(-c3ccc(-c4ccc(-c5cccc6ccccc56)cc4)cc3)nc(-c3ccc4oc5ccccc5c4c3)n2)c1 ; N#Cc1cccc(-c2nc(-c3ccc4oc5ccccc5c4c3)nc(-c3cccc4c(-c5ccccc5)cccc34)n2)c1]

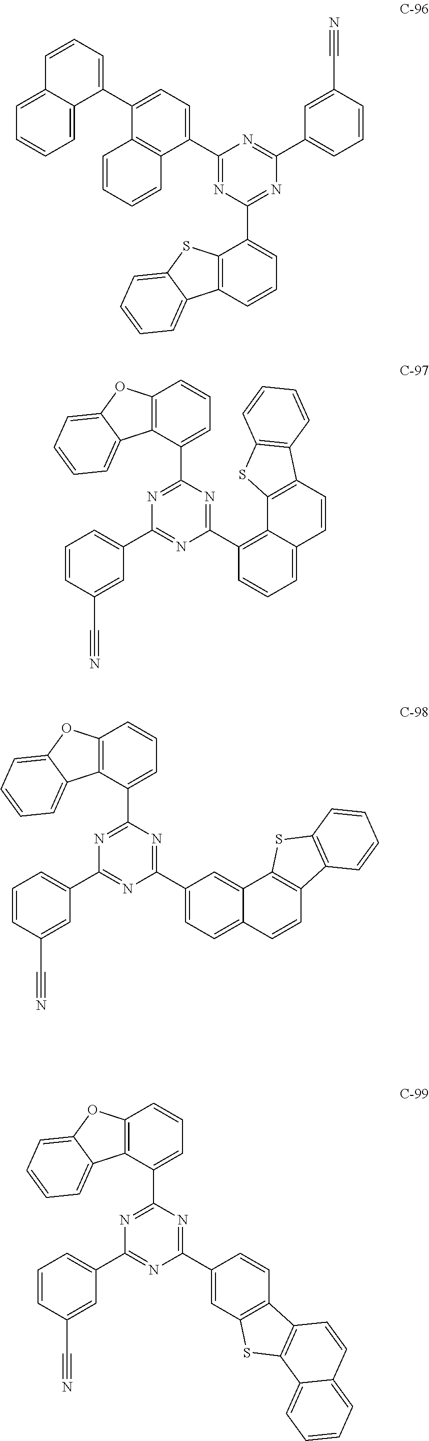 [SMILES: N#Cc1cccc(-c2nc(-c3ccc(-c4cccc5ccccc45)c4ccccc34)nc(-c3cccc4c3sc3ccccc34)n2)c1 ; N#Cc1cccc(-c2nc(-c3cccc4oc5ccccc5c34)nc(-c3cccc4ccc5c6ccccc6sc5c34)n2)c1 ; N#Cc1cccc(-c2nc(-c3ccc4ccc5c6ccccc6sc5c4c3)nc(-c3cccc4oc5ccccc5c34)n2)c1 ; N#Cc1cccc(-c2nc(-c3ccc4c(c3)sc3c5ccccc5ccc43)nc(-c3cccc4oc5ccccc5c34)n2)c1]

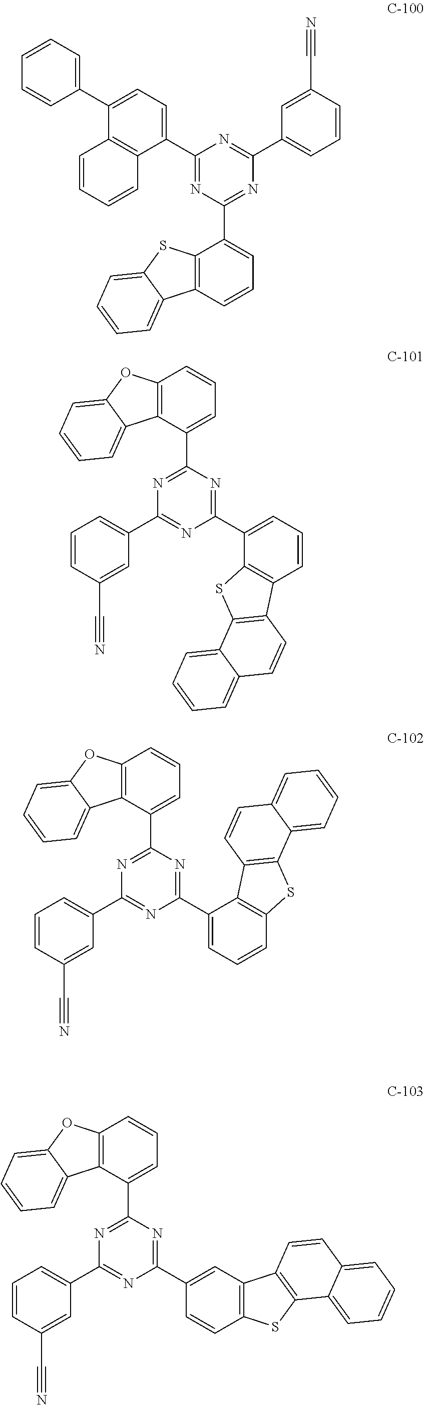

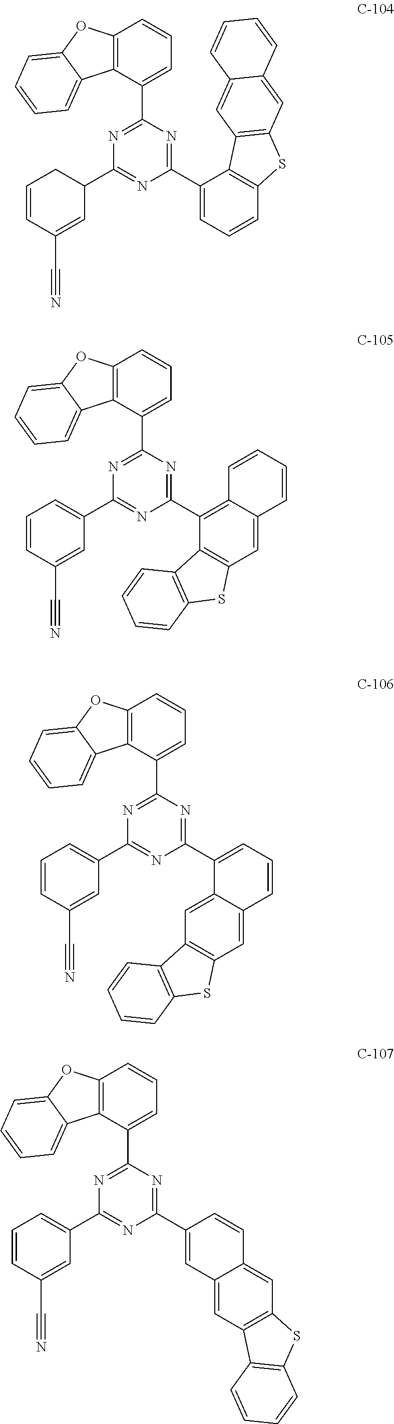

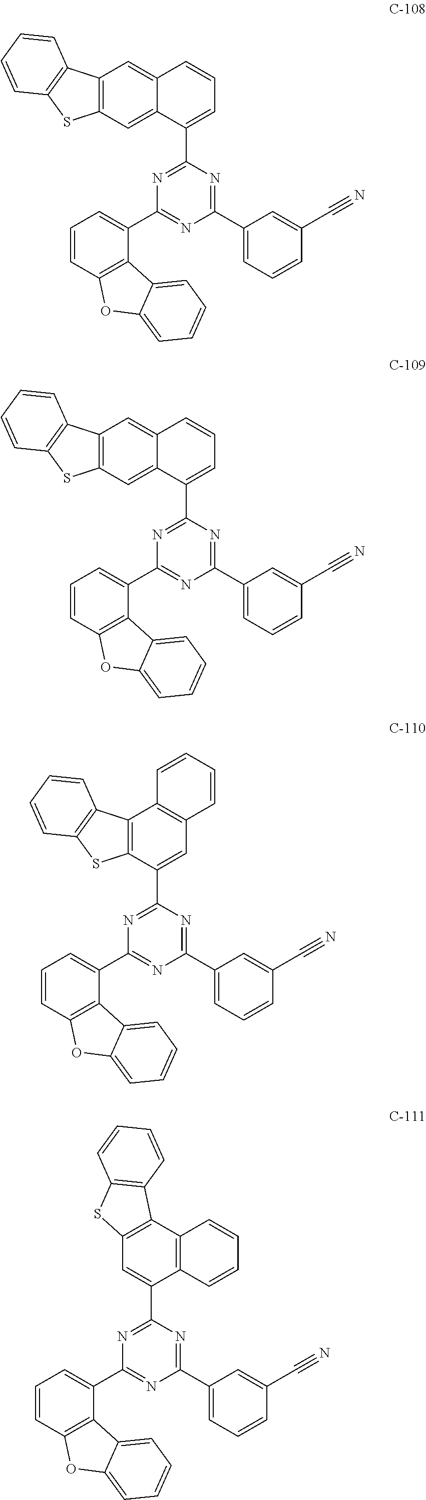

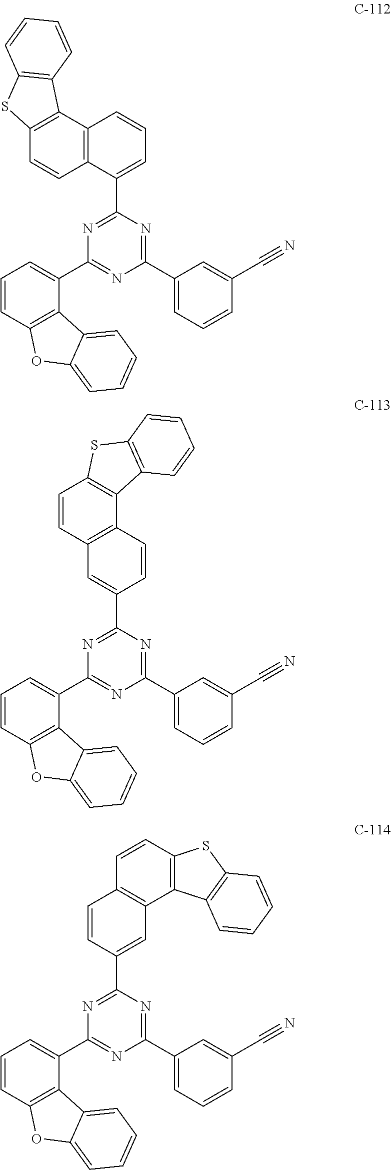

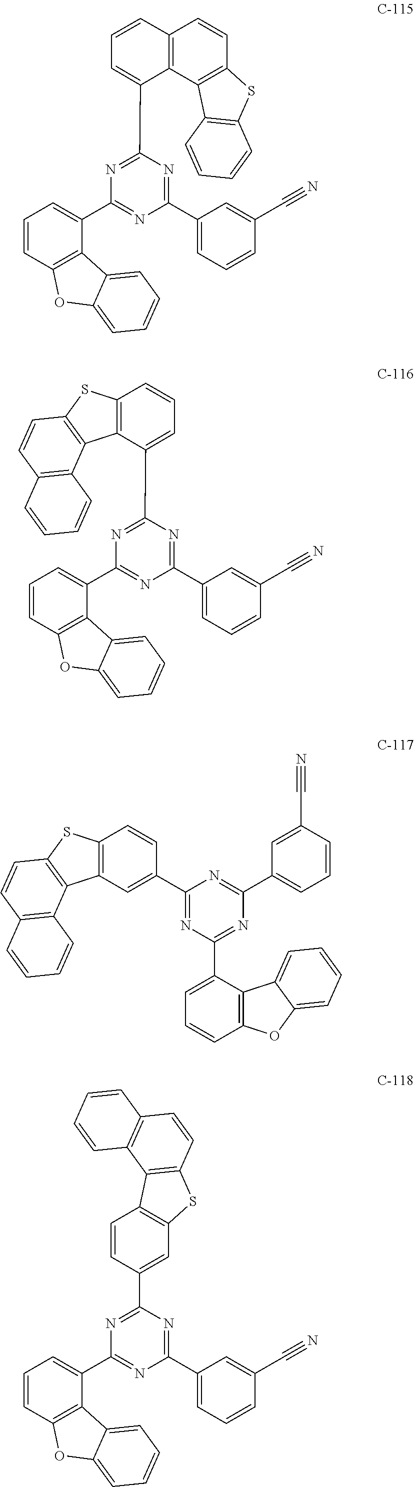 [SMILES: N#Cc1cccc(-c2nc(-c3cccc4oc5ccccc5c34)nc(-c3cccc4ccc5sc6ccccc6c5c34)n2)c1 ; N#Cc1cccc(-c2nc(-c3cccc4oc5ccccc5c34)nc(-c3cccc4sc5ccc6ccccc6c5c34)n2)c1 ; N#Cc1cccc(-c2nc(-c3ccc4sc5ccc6ccccc6c5c4c3)nc(-c3cccc4oc5ccccc5c34)n2)c1 ; N#Cc1cccc(-c2nc(-c3ccc4c(c3)sc3ccc5ccccc5c34)nc(-c3cccc4oc5ccccc5c34)n2)c1]

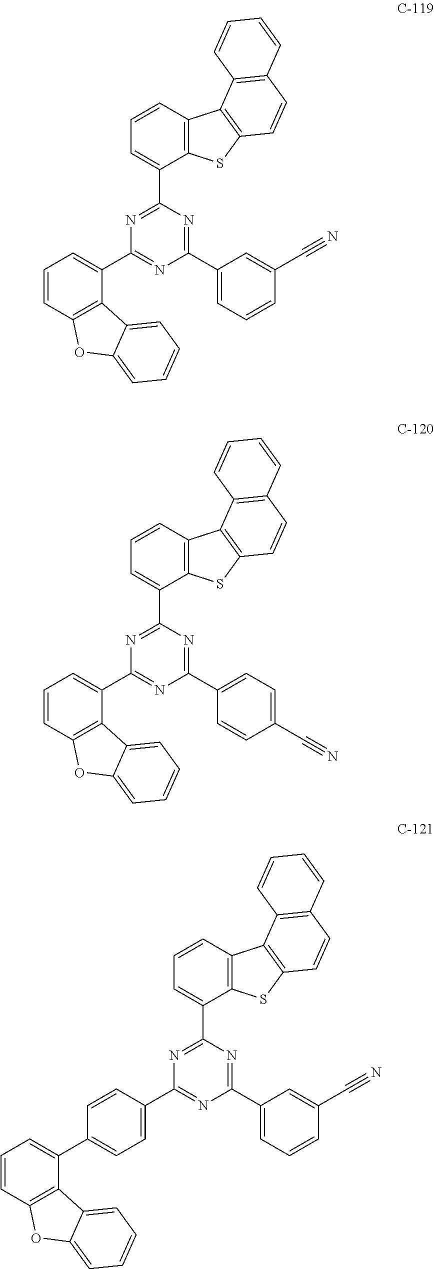 [SMILES: N#Cc1cccc(-c2nc(-c3cccc4c3sc3ccc5ccccc5c34)nc(-c3cccc4oc5ccccc5c34)n2)c1 ; N#Cc1ccc(-c2nc(-c3cccc4c3sc3ccc5ccccc5c34)nc(-c3cccc4oc5ccccc5c34)n2)cc1 ; N#Cc1cccc(-c2nc(-c3ccc(-c4cccc5oc6ccccc6c45)cc3)nc(-c3cccc4c3sc3ccc5ccccc5c34)n2)c1]

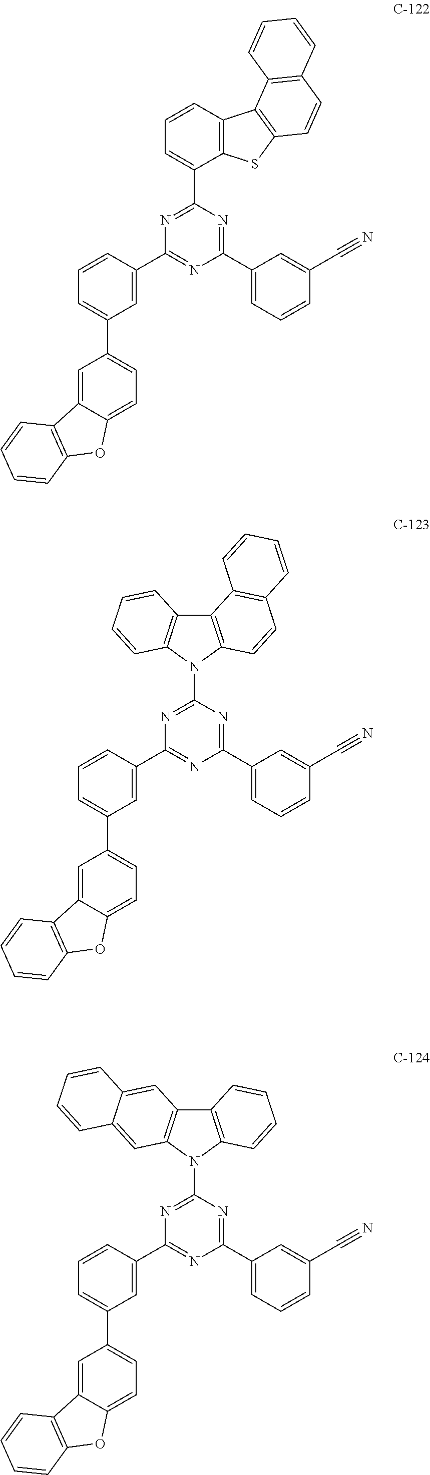 [SMILES: N#Cc1cccc(-c2nc(-c3cccc(-c4ccc5oc6ccccc6c5c4)c3)nc(-c3cccc4c3sc3ccc5ccccc5c34)n2)c1 ; N#Cc1cccc(-c2nc(-c3cccc(-c4ccc5oc6ccccc6c5c4)c3)nc(-n3c4ccccc4c4c5ccccc5ccc43)n2)c1 ; N#Cc1cccc(-c2nc(-c3cccc(-c4ccc5oc6ccccc6c5c4)c3)nc(-n3c4ccccc4c4cc5ccccc5cc43)n2)c1]

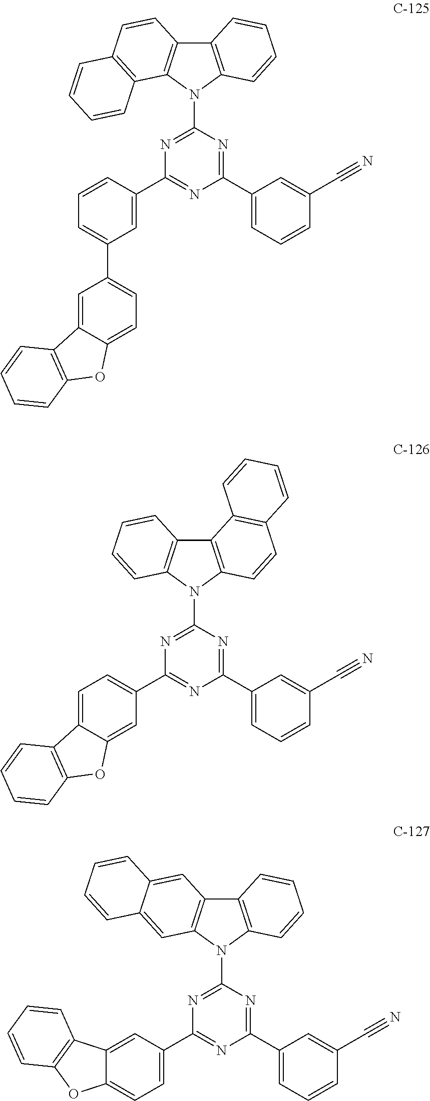 [SMILES: N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4c(c3)oc3ccccc34)nc(-n3c4ccccc4c4c5ccccc5ccc43)n2)c1 ; N#Cc1cccc(-c2nc(-c3ccc4oc5ccccc5c4c3)nc(-n3c4ccccc4c4cc5ccccc5cc43)n2)c1]

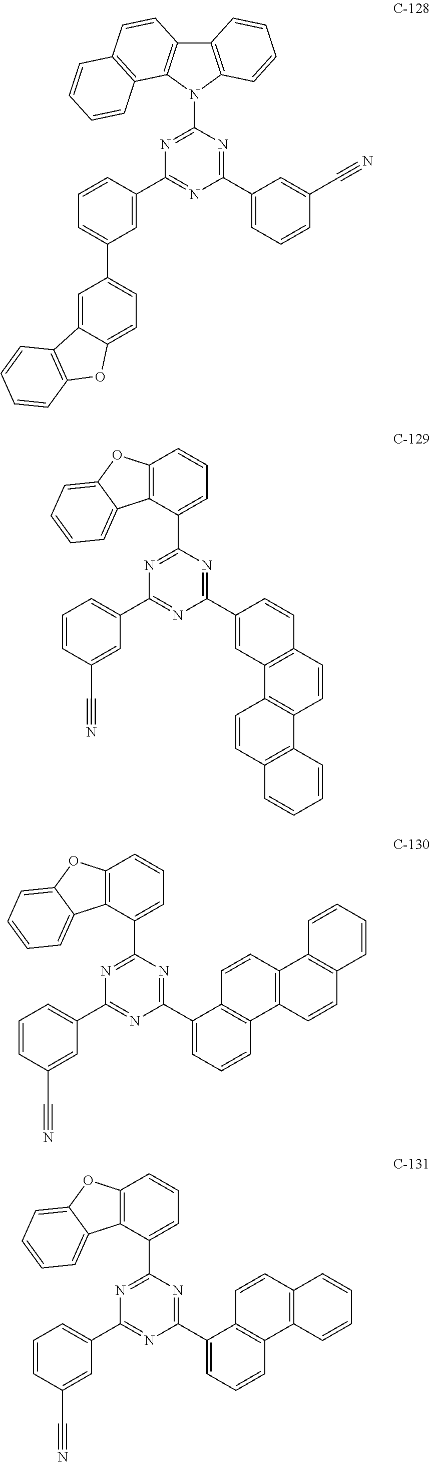 [SMILES: N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4ccc5c6ccccc6ccc5c4c3)nc(-c3cccc4oc5ccccc5c34)n2)c1 ; N#Cc1cccc(-c2nc(-c3cccc4c3ccc3c5ccccc5ccc43)nc(-c3cccc4oc5ccccc5c34)n2)c1 ; N#Cc1cccc(-c2nc(-c3cccc4c3ccc3ccccc34)nc(-c3cccc4oc5ccccc5c34)n2)c1]

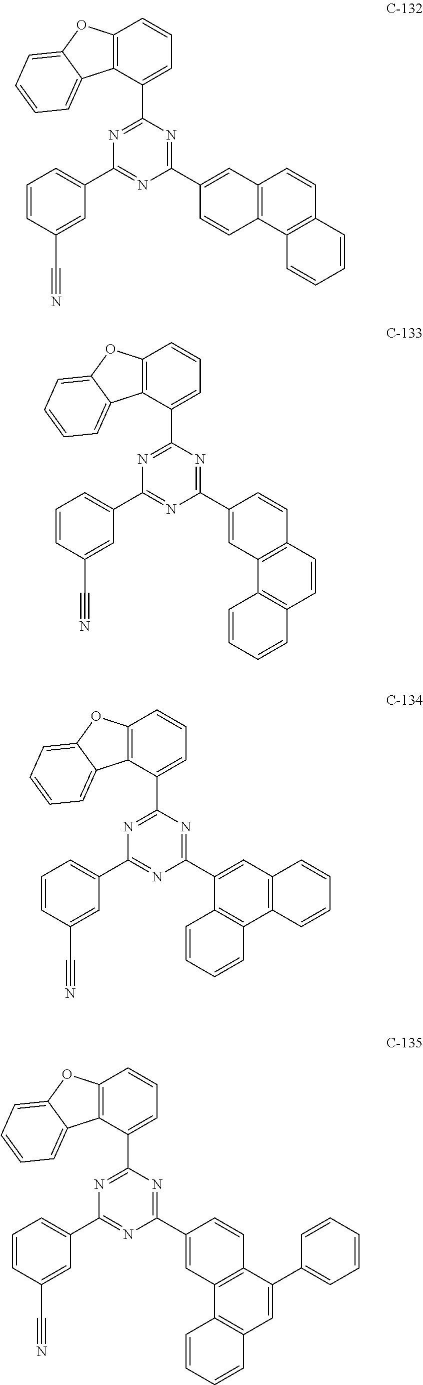 [SMILES: N#Cc1cccc(-c2nc(-c3ccc4c(ccc5ccccc54)c3)nc(-c3cccc4oc5ccccc5c34)n2)c1 ; N#Cc1cccc(-c2nc(-c3ccc4ccc5ccccc5c4c3)nc(-c3cccc4oc5ccccc5c34)n2)c1 ; N#Cc1cccc(-c2nc(-c3cc4ccccc4c4ccccc34)nc(-c3cccc4oc5ccccc5c34)n2)c1 ; N#Cc1cccc(-c2nc(-c3ccc4c(-c5ccccc5)cc5ccccc5c4c3)nc(-c3cccc4oc5ccccc5c34)n2)c1]

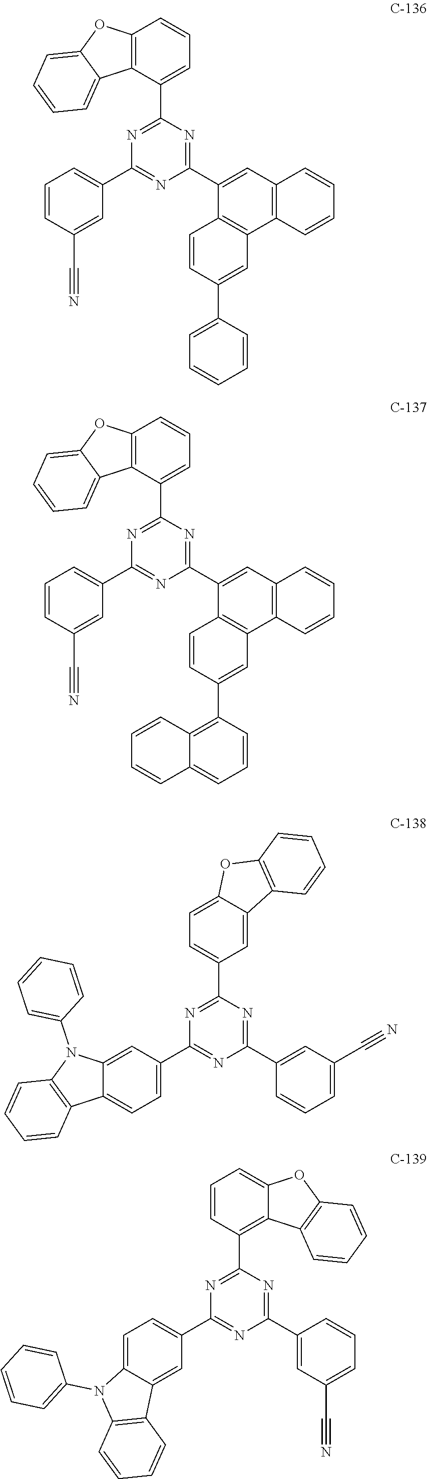 [SMILES: N#Cc1cccc(-c2nc(-c3cc4ccccc4c4cc(-c5ccccc5)ccc34)nc(-c3cccc4oc5ccccc5c34)n2)c1 ; N#Cc1cccc(-c2nc(-c3cc4ccccc4c4cc(-c5cccc6ccccc56)ccc34)nc(-c3cccc4oc5ccccc5c34)n2)c1 ; N#Cc1cccc(-c2nc(-c3ccc4oc5ccccc5c4c3)nc(-c3ccc4c5ccccc5n(-c5ccccc5)c4c3)n2)c1 ; N#Cc1cccc(-c2nc(-c3ccc4c(c3)c3ccccc3n4-c3ccccc3)nc(-c3cccc4oc5ccccc5c34)n2)c1]

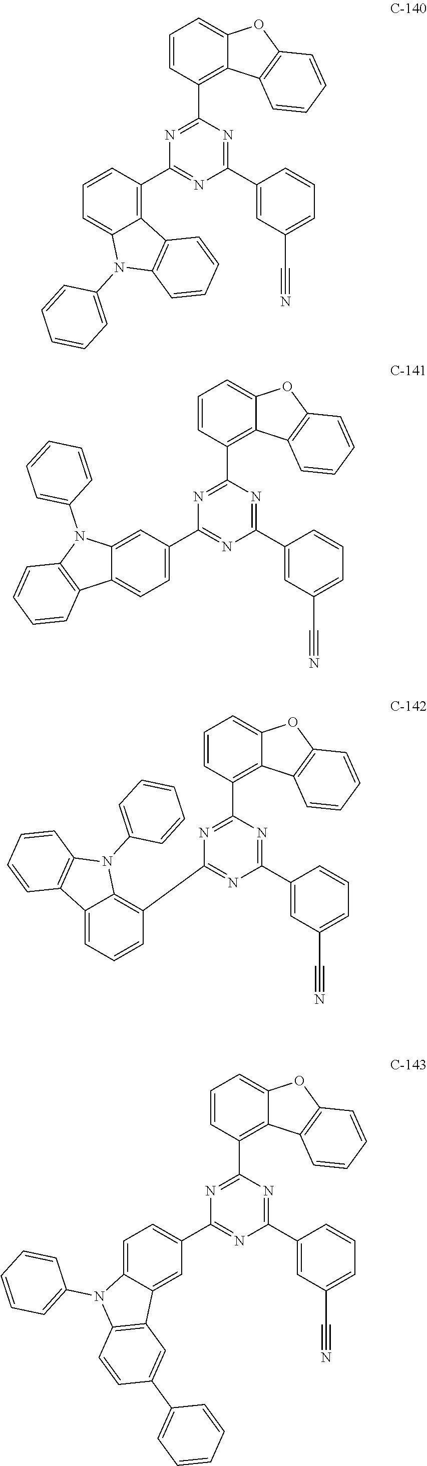 [SMILES: N#Cc1cccc(-c2nc(-c3cccc4oc5ccccc5c34)nc(-c3cccc4c3c3ccccc3n4-c3ccccc3)n2)c1 ; N#Cc1cccc(-c2nc(-c3ccc4c5ccccc5n(-c5ccccc5)c4c3)nc(-c3cccc4oc5ccccc5c34)n2)c1 ; N#Cc1cccc(-c2nc(-c3cccc4oc5ccccc5c34)nc(-c3cccc4c5ccccc5n(-c5ccccc5)c34)n2)c1 ; N#Cc1cccc(-c2nc(-c3ccc4c(c3)c3cc(-c5ccccc5)ccc3n4-c3ccccc3)nc(-c3cccc4oc5ccccc5c34)n2)c1]

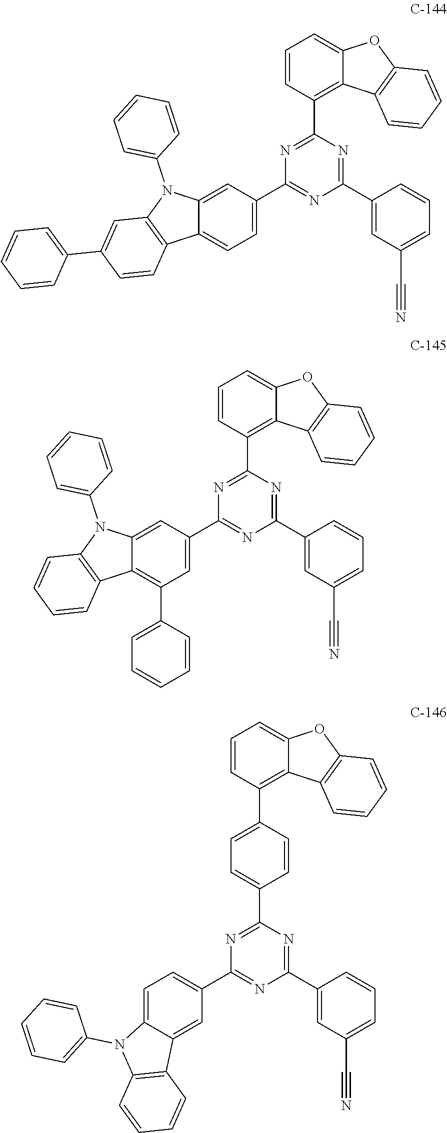 [SMILES: N#Cc1cccc(-c2nc(-c3ccc4c5ccc(-c6ccccc6)cc5n(-c5ccccc5)c4c3)nc(-c3cccc4oc5ccccc5c34)n2)c1 ; N#Cc1cccc(-c2nc(-c3cc(-c4ccccc4)c4c5ccccc5n(-c5ccccc5)c4c3)nc(-c3cccc4oc5ccccc5c34)n2)c1 ; N#Cc1cccc(-c2nc(-c3ccc(-c4cccc5oc6ccccc6c45)cc3)nc(-c3ccc4c(c3)c3ccccc3n4-c3ccccc3)n2)c1]

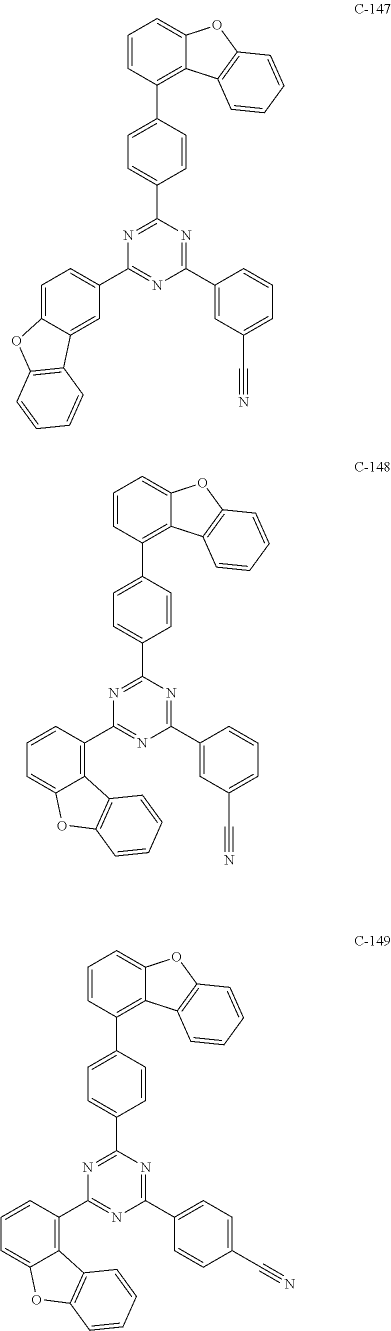 [SMILES: N#Cc1cccc(-c2nc(-c3ccc(-c4cccc5oc6ccccc6c45)cc3)nc(-c3ccc4oc5ccccc5c4c3)n2)c1 ; N#Cc1cccc(-c2nc(-c3ccc(-c4cccc5oc6ccccc6c45)cc3)nc(-c3cccc4oc5ccccc5c34)n2)c1 ; N#Cc1ccc(-c2nc(-c3ccc(-c4cccc5oc6ccccc6c45)cc3)nc(-c3cccc4oc5ccccc5c34)n2)cc1]

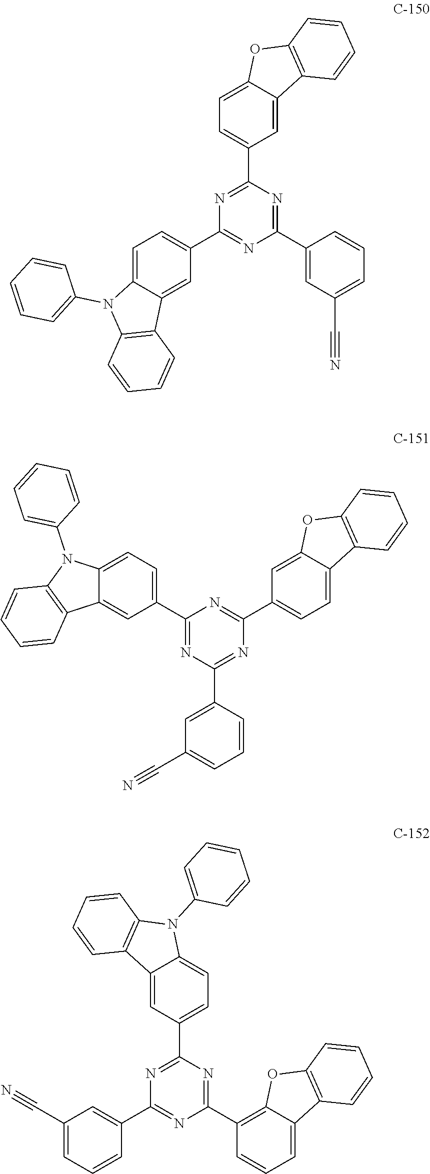 [SMILES: N#Cc1cccc(-c2nc(-c3ccc4oc5ccccc5c4c3)nc(-c3ccc4c(c3)c3ccccc3n4-c3ccccc3)n2)c1 ; N#Cc1cccc(-c2nc(-c3ccc4c(c3)oc3ccccc34)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4c3oc3ccccc34)n2)c1]

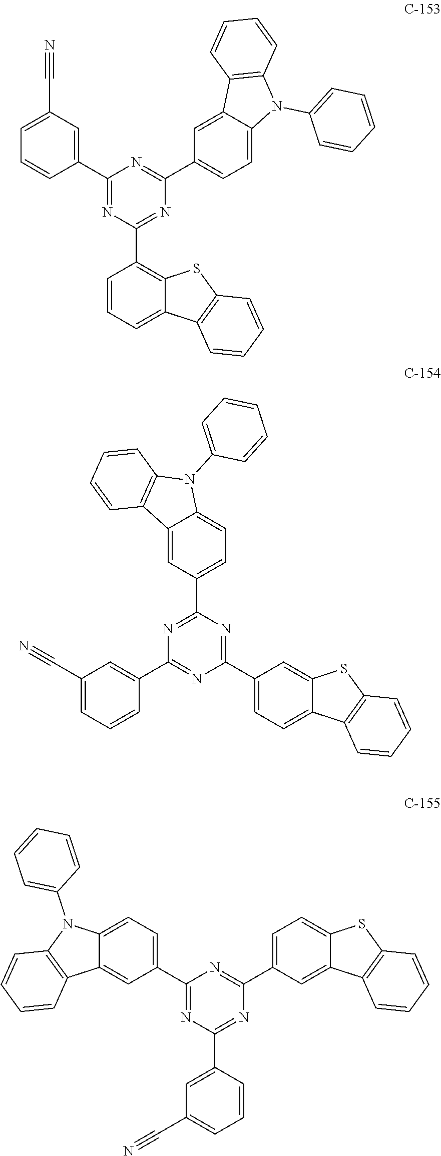

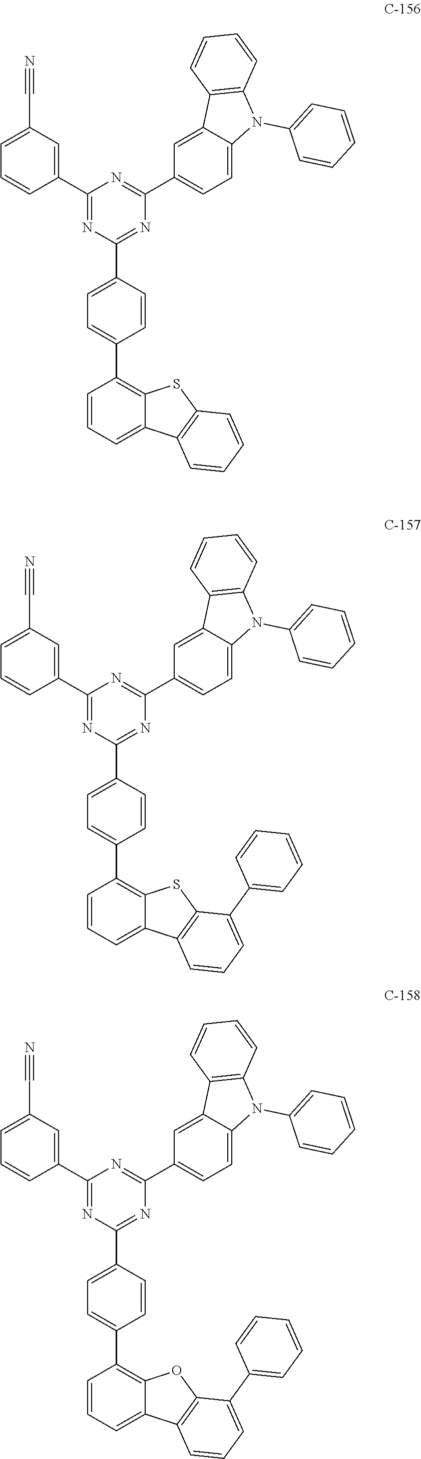 [SMILES: N#Cc1cccc(-c2nc(-c3ccc(-c4cccc5c4sc4ccccc45)cc3)nc(-c3ccc4c(c3)c3ccccc3n4-c3ccccc3)n2)c1 ; N#Cc1cccc(-c2nc(-c3ccc(-c4cccc5c4sc4c(-c6ccccc6)cccc45)cc3)nc(-c3ccc4c(c3)c3ccccc3n4-c3ccccc3)n2)c1 ; N#Cc1cccc(-c2nc(-c3ccc(-c4cccc5c4oc4c(-c6ccccc6)cccc45)cc3)nc(-c3ccc4c(c3)c3ccccc3n4-c3ccccc3)n2)c1]

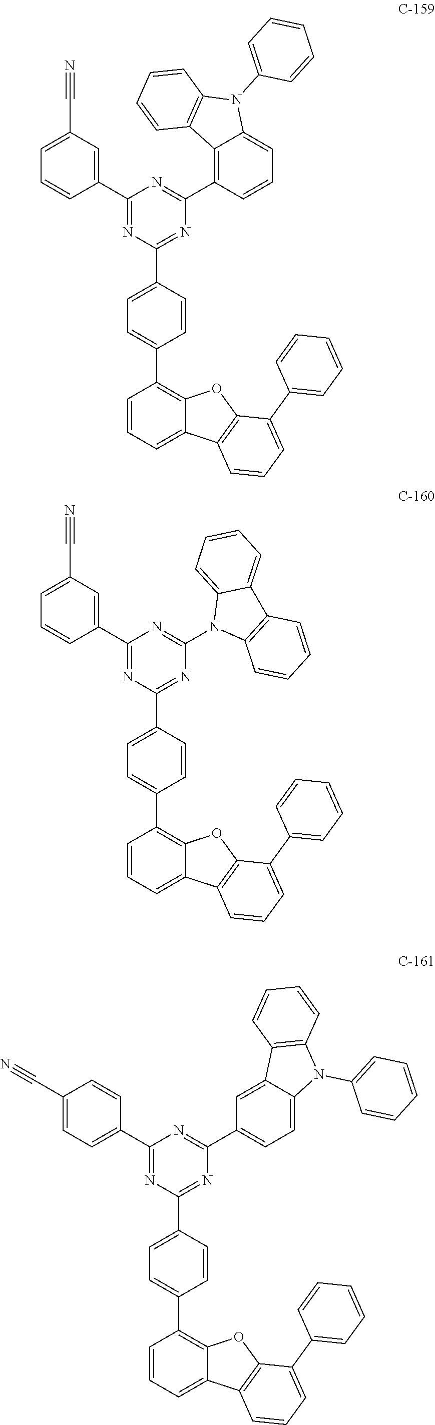 [SMILES: N#Cc1cccc(-c2nc(-c3ccc(-c4cccc5c4oc4c(-c6ccccc6)cccc45)cc3)nc(-c3cccc4c3c3ccccc3n4-c3ccccc3)n2)c1 ; N#Cc1cccc(-c2nc(-c3ccc(-c4cccc5c4oc4c(-c6ccccc6)cccc45)cc3)nc(-n3c4ccccc4c4ccccc43)n2)c1 ; N#Cc1ccc(-c2nc(-c3ccc(-c4cccc5c4oc4c(-c6ccccc6)cccc45)cc3)nc(-c3ccc4c(c3)c3ccccc3n4-c3ccccc3)n2)cc1]

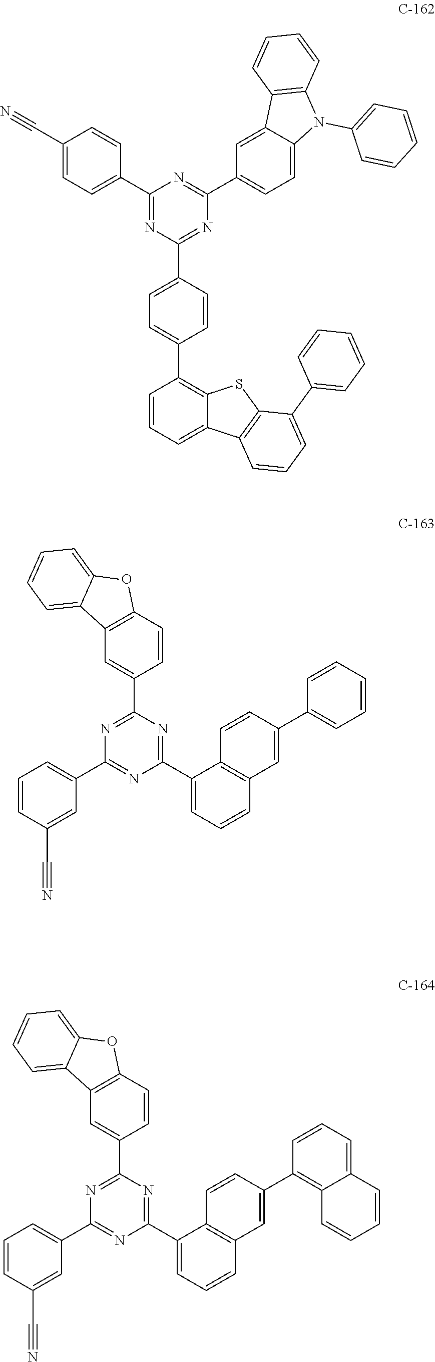 [SMILES: N#Cc1ccc(-c2nc(-c3ccc(-c4cccc5c4sc4c(-c6ccccc6)cccc45)cc3)nc(-c3ccc4c(c3)c3ccccc3n4-c3ccccc3)n2)cc1 ; N#Cc1cccc(-c2nc(-c3ccc4oc5ccccc5c4c3)nc(-c3cccc4cc(-c5ccccc5)ccc34)n2)c1 ; N#Cc1cccc(-c2nc(-c3ccc4oc5ccccc5c4c3)nc(-c3cccc4cc(-c5cccc6ccccc56)ccc34)n2)c1]

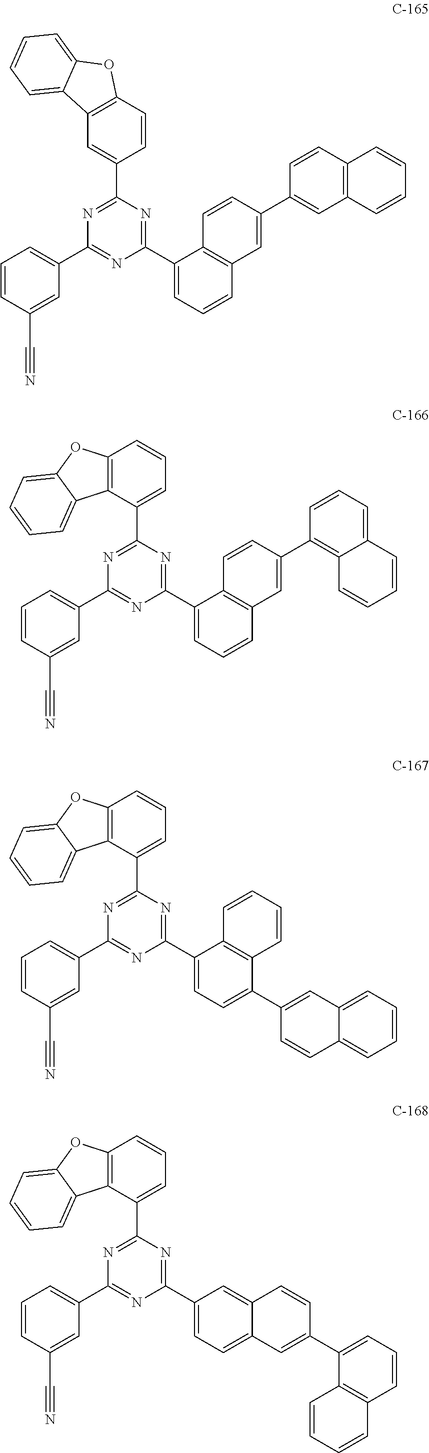 [SMILES: N#Cc1cccc(-c2nc(-c3ccc4oc5ccccc5c4c3)nc(-c3cccc4cc(-c5ccc6ccccc6c5)ccc34)n2)c1 ; N#Cc1cccc(-c2nc(-c3cccc4cc(-c5cccc6ccccc56)ccc34)nc(-c3cccc4oc5ccccc5c34)n2)c1 ; N#Cc1cccc(-c2nc(-c3ccc(-c4ccc5ccccc5c4)c4ccccc34)nc(-c3cccc4oc5ccccc5c34)n2)c1 ; N#Cc1cccc(-c2nc(-c3ccc4cc(-c5cccc6ccccc56)ccc4c3)nc(-c3cccc4oc5ccccc5c34)n2)c1]

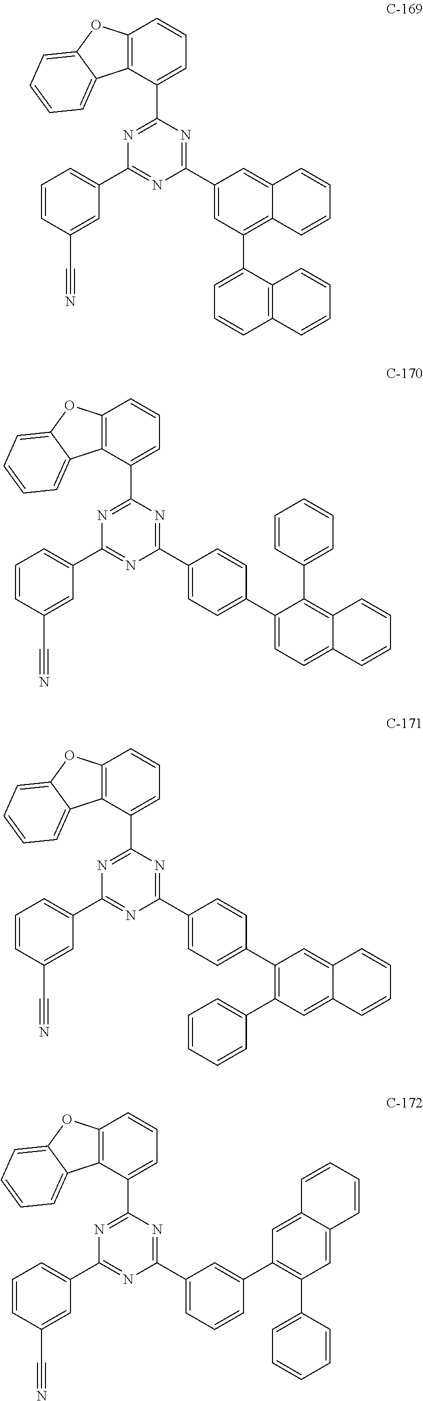 [SMILES: N#Cc1cccc(-c2nc(-c3cc(-c4cccc5ccccc45)c4ccccc4c3)nc(-c3cccc4oc5ccccc5c34)n2)c1 ; N#Cc1cccc(-c2nc(-c3ccc(-c4ccc5ccccc5c4-c4ccccc4)cc3)nc(-c3cccc4oc5ccccc5c34)n2)c1 ; N#Cc1cccc(-c2nc(-c3ccc(-c4cc5ccccc5cc4-c4ccccc4)cc3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1]

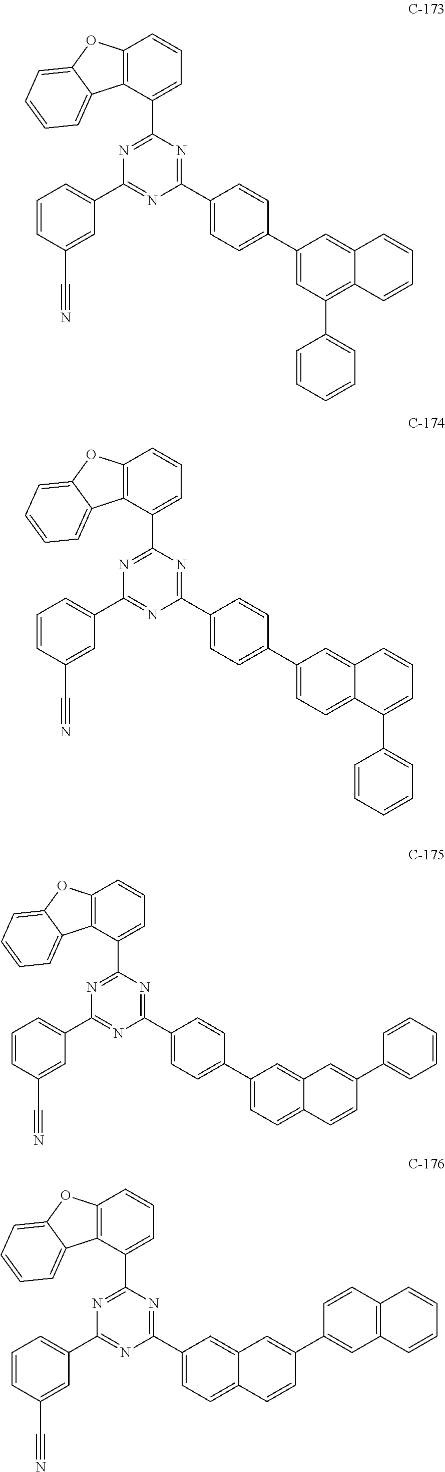 [SMILES: N#Cc1cccc(-c2nc(-c3ccc(-c4cc(-c5ccccc5)c5ccccc5c4)cc3)nc(-c3cccc4oc5ccccc5c34)n2)c1 ; N#Cc1cccc(-c2nc(-c3ccc(-c4ccc5c(-c6ccccc6)cccc5c4)cc3)nc(-c3cccc4oc5ccccc5c34)n2)c1 ; N#Cc1cccc(-c2nc(-c3ccc(-c4ccc5ccc(-c6ccccc6)cc5c4)cc3)nc(-c3cccc4oc5ccccc5c34)n2)c1 ; N#Cc1cccc(-c2nc(-c3ccc4ccc(-c5ccc6ccccc6c5)cc4c3)nc(-c3cccc4oc5ccccc5c34)n2)c1]

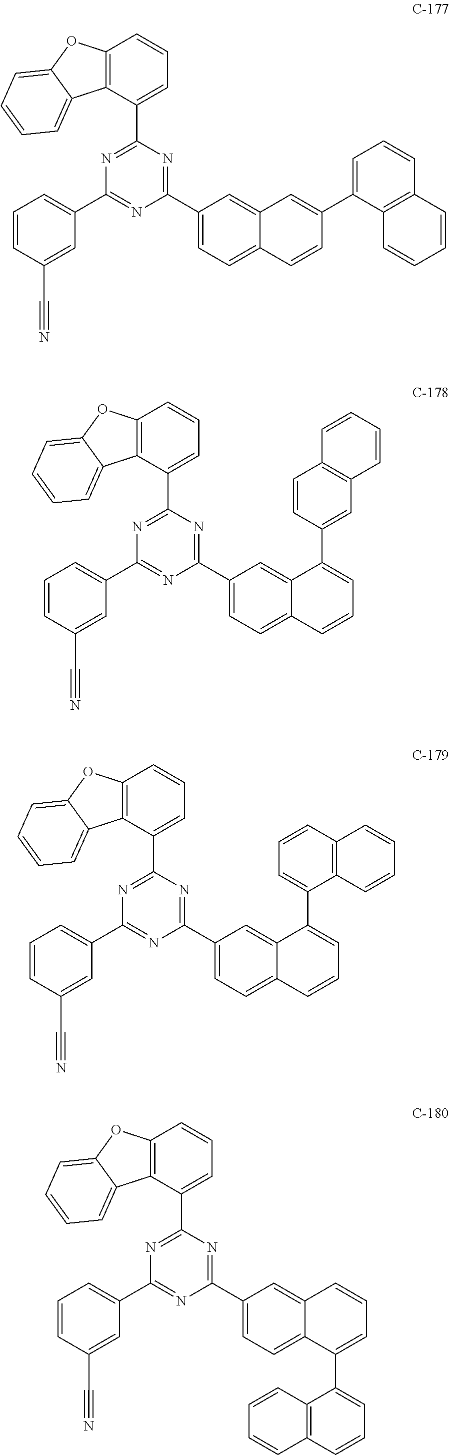 [SMILES: N#Cc1cccc(-c2nc(-c3ccc4ccc(-c5cccc6ccccc56)cc4c3)nc(-c3cccc4oc5ccccc5c34)n2)c1 ; N#Cc1cccc(-c2nc(-c3ccc4cccc(-c5ccc6ccccc6c5)c4c3)nc(-c3cccc4oc5ccccc5c34)n2)c1 ; N#Cc1cccc(-c2nc(-c3ccc4cccc(-c5cccc6ccccc56)c4c3)nc(-c3cccc4oc5ccccc5c34)n2)c1 ; N#Cc1cccc(-c2nc(-c3ccc4c(-c5cccc6ccccc56)cccc4c3)nc(-c3cccc4oc5ccccc5c34)n2)c1]

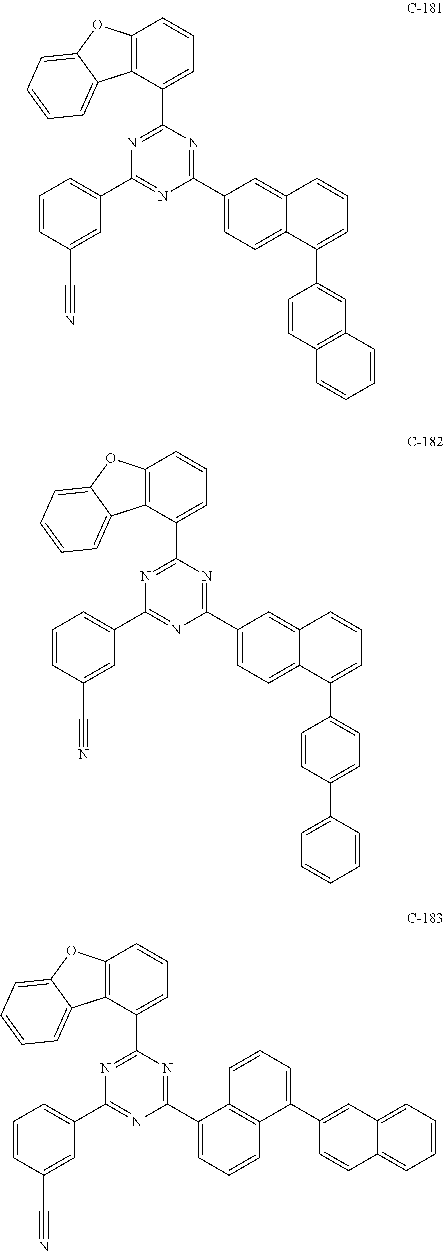 [SMILES: N#Cc1cccc(-c2nc(-c3ccc4c(-c5ccc6ccccc6c5)cccc4c3)nc(-c3cccc4oc5ccccc5c34)n2)c1 ; N#Cc1cccc(-c2nc(-c3ccc4c(-c5ccc(-c6ccccc6)cc5)cccc4c3)nc(-c3cccc4oc5ccccc5c34)n2)c1 ; N#Cc1cccc(-c2nc(-c3cccc4c(-c5ccc6ccccc6c5)cccc34)nc(-c3cccc4oc5ccccc5c34)n2)c1]

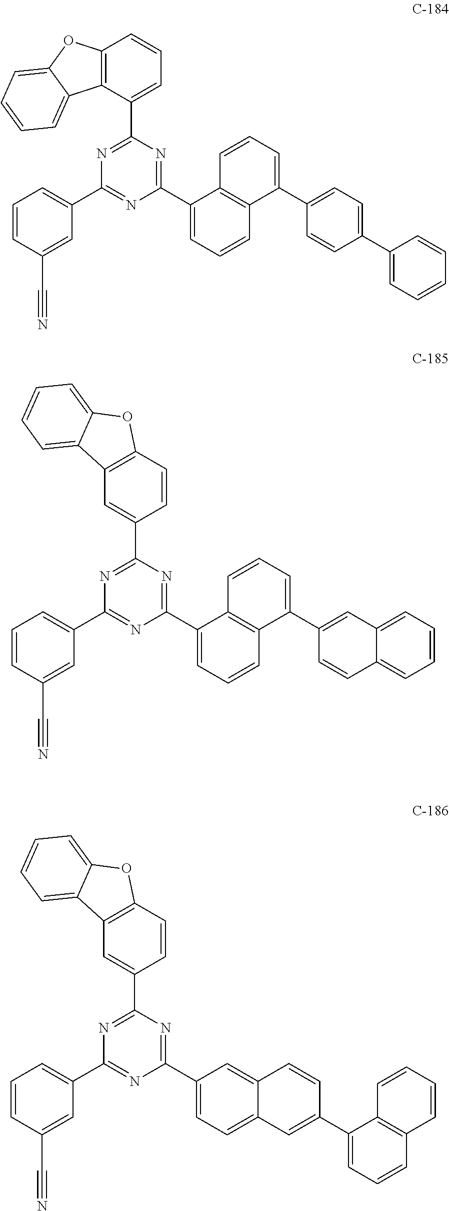 [SMILES: N#Cc1cccc(-c2nc(-c3cccc4c(-c5ccc(-c6ccccc6)cc5)cccc34)nc(-c3cccc4oc5ccccc5c34)n2)c1 ; N#Cc1cccc(-c2nc(-c3ccc4oc5ccccc5c4c3)nc(-c3cccc4c(-c5ccc6ccccc6c5)cccc34)n2)c1 ; N#Cc1cccc(-c2nc(-c3ccc4cc(-c5cccc6ccccc56)ccc4c3)nc(-c3ccc4oc5ccccc5c4c3)n2)c1]

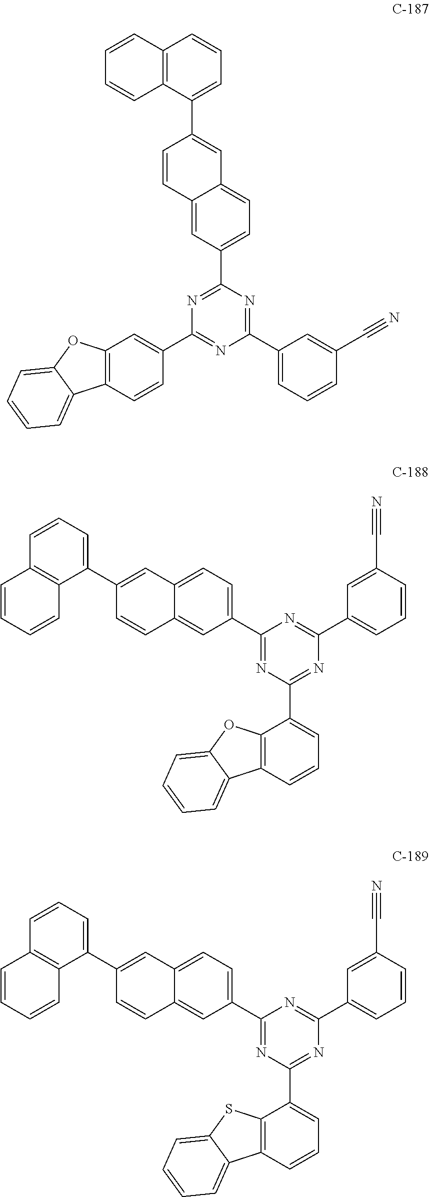 [SMILES: N#Cc1cccc(-c2nc(-c3ccc4cc(-c5cccc6ccccc56)ccc4c3)nc(-c3ccc4c(c3)oc3ccccc34)n2)c1 ; N#Cc1cccc(-c2nc(-c3ccc4cc(-c5cccc6ccccc56)ccc4c3)nc(-c3cccc4c3oc3ccccc34)n2)c1 ; N#Cc1cccc(-c2nc(-c3ccc4cc(-c5cccc6ccccc56)ccc4c3)nc(-c3cccc4c3sc3ccccc34)n2)c1]

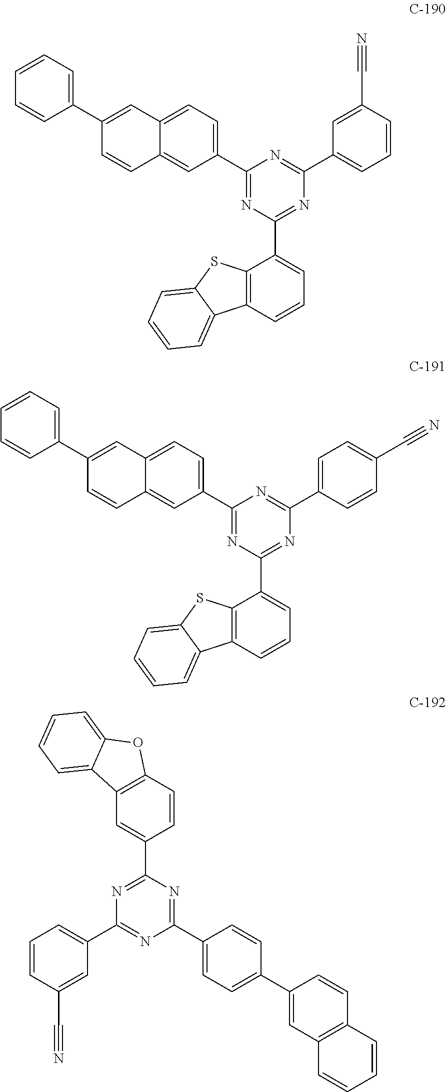 [SMILES: N#Cc1cccc(-c2nc(-c3ccc4cc(-c5ccccc5)ccc4c3)nc(-c3cccc4c3sc3ccccc34)n2)c1 ; N#Cc1ccc(-c2nc(-c3ccc4cc(-c5ccccc5)ccc4c3)nc(-c3cccc4c3sc3ccccc34)n2)cc1 ; N#Cc1cccc(-c2nc(-c3ccc(-c4ccc5ccccc5c4)cc3)nc(-c3ccc4oc5ccccc5c4c3)n2)c1]

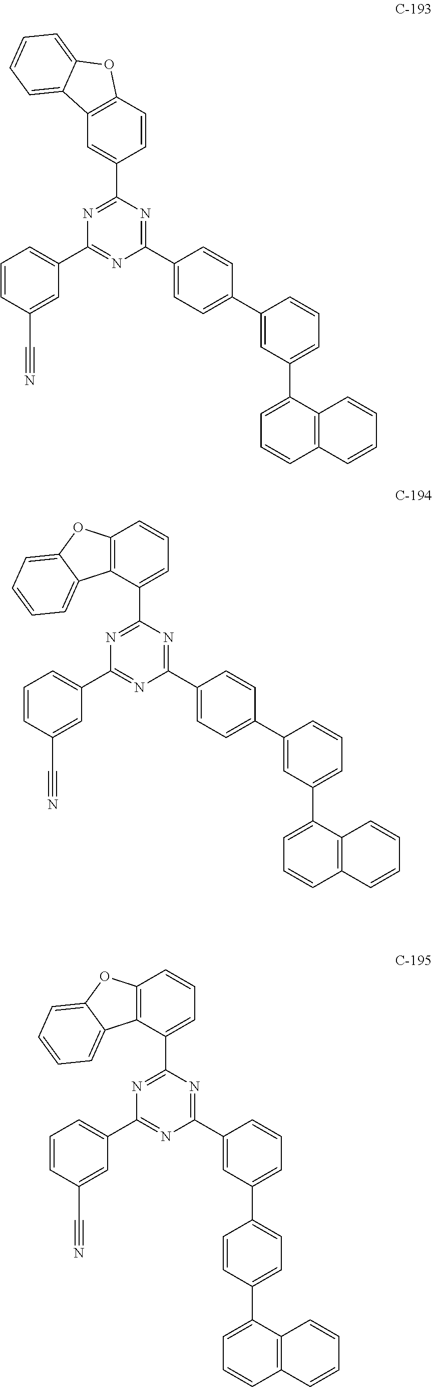 [SMILES: N#Cc1cccc(-c2nc(-c3ccc(-c4cccc(-c5cccc6ccccc56)c4)cc3)nc(-c3ccc4oc5ccccc5c4c3)n2)c1 ; N#Cc1cccc(-c2nc(-c3ccc(-c4cccc(-c5cccc6ccccc56)c4)cc3)nc(-c3cccc4oc5ccccc5c34)n2)c1 ; N#Cc1cccc(-c2nc(-c3cccc(-c4ccc(-c5cccc6ccccc56)cc4)c3)nc(-c3cccc4oc5ccccc5c34)n2)c1]

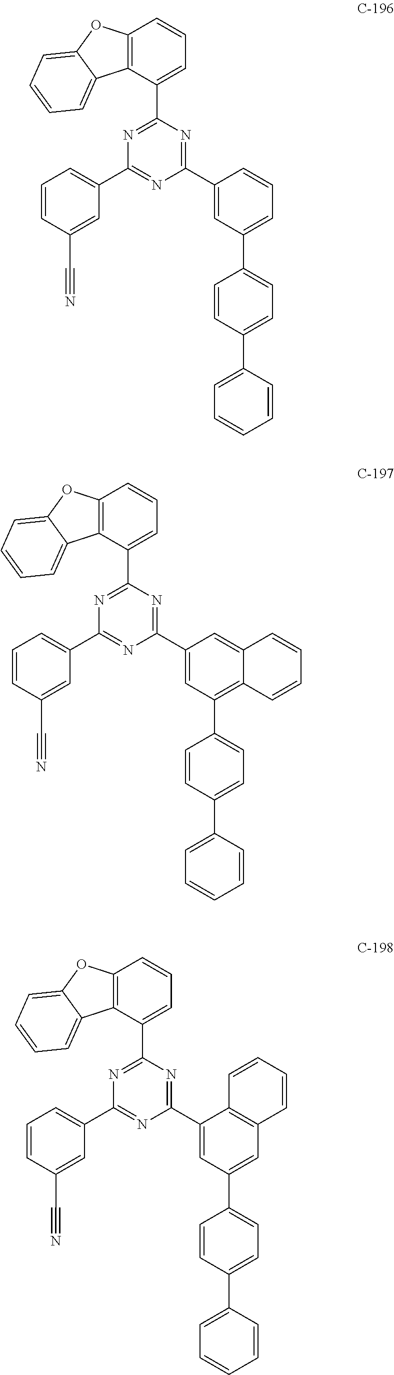 [SMILES: N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3cc(-c4ccc(-c5ccccc5)cc4)c4ccccc4c3)nc(-c3cccc4oc5ccccc5c34)n2)c1 ; N#Cc1cccc(-c2nc(-c3cc(-c4ccc(-c5ccccc5)cc4)cc4ccccc34)nc(-c3cccc4oc5ccccc5c34)n2)c1]

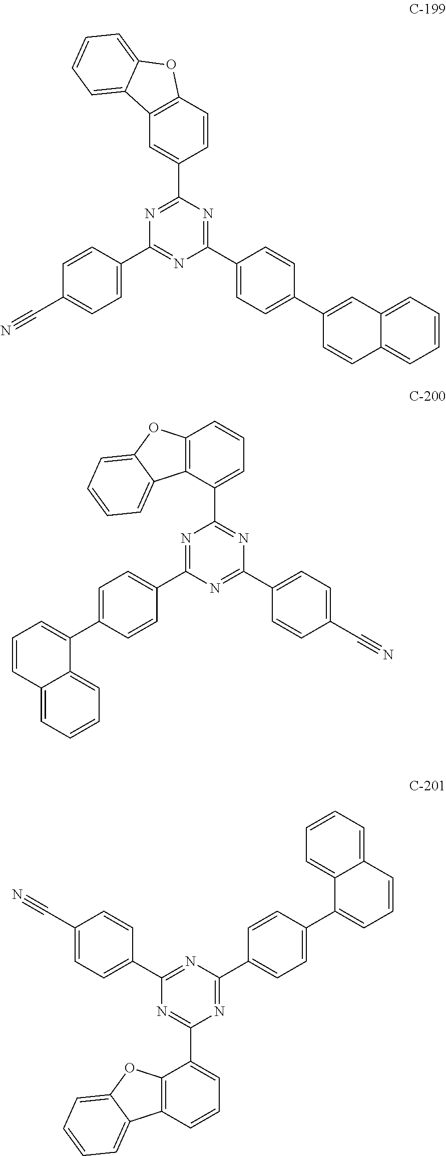 [SMILES: N#Cc1ccc(-c2nc(-c3ccc(-c4ccc5ccccc5c4)cc3)nc(-c3ccc4oc5ccccc5c4c3)n2)cc1 ; N#Cc1ccc(-c2nc(-c3ccc(-c4cccc5ccccc45)cc3)nc(-c3cccc4oc5ccccc5c34)n2)cc1 ; N#Cc1ccc(-c2nc(-c3ccc(-c4cccc5ccccc45)cc3)nc(-c3cccc4c3oc3ccccc34)n2)cc1]

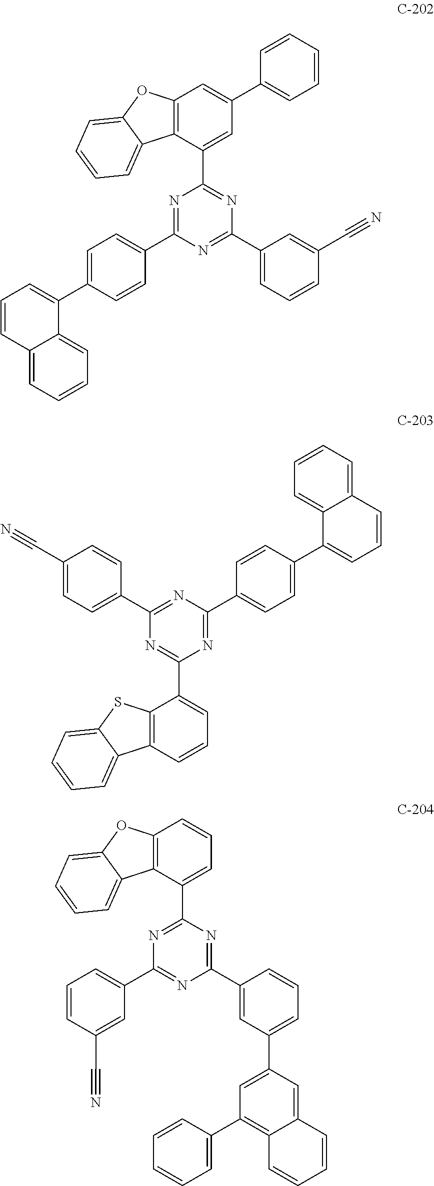

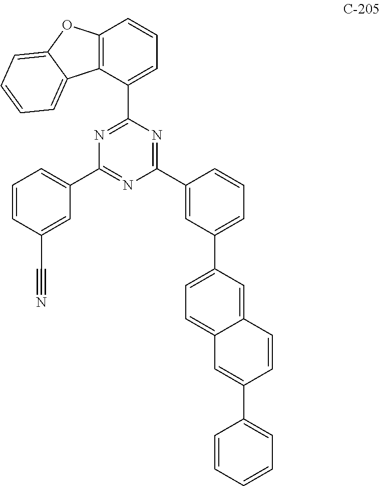 [SMILES: N#Cc1cccc(-c2nc(-c3cccc(-c4ccc5cc(-c6ccccc6)ccc5c4)c3)nc(-c3cccc4oc5ccccc5c34)n2)c1]

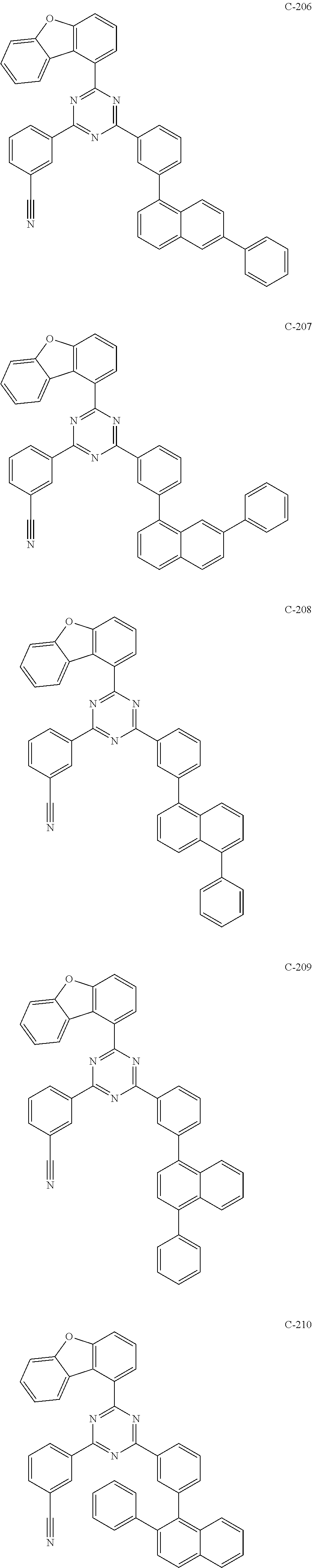 [SMILES: N#Cc1cccc(-c2nc(-c3cccc(-c4cccc5cc(-c6ccccc6)ccc45)c3)nc(-c3cccc4oc5ccccc5c34)n2)c1 ; N#Cc1cccc(-c2nc(-c3cccc(-c4cccc5ccc(-c6ccccc6)cc45)c3)nc(-c3cccc4oc5ccccc5c34)n2)c1 ; N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1 ; N#Cc1cccc(-c2nc(-c3cccc(-c4c(-c5ccccc5)ccc5ccccc45)c3)nc(-c3cccc4oc5ccccc5c34)n2)c1]

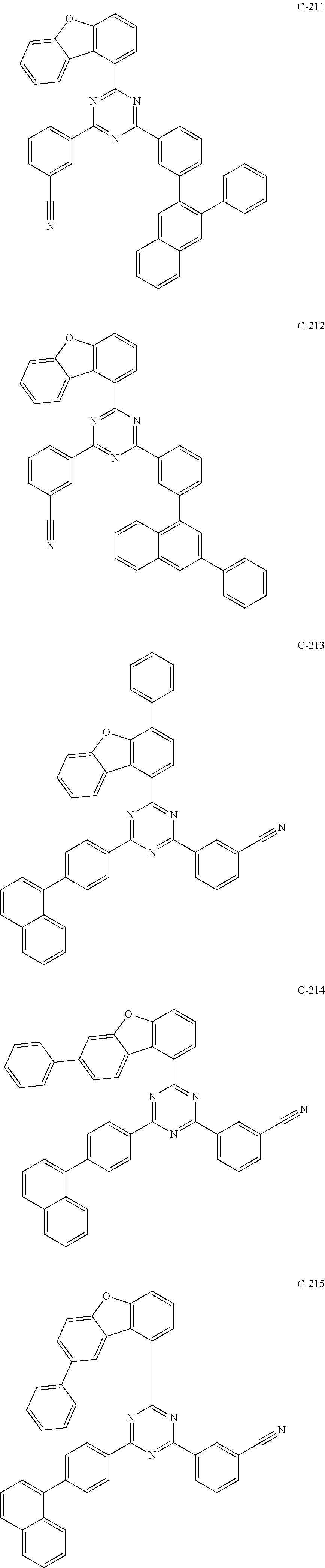 [SMILES: N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3cccc(-c4cc(-c5ccccc5)cc5ccccc45)c3)nc(-c3cccc4oc5ccccc5c34)n2)c1 ; N#Cc1cccc(-c2nc(-c3ccc(-c4cccc5ccccc45)cc3)nc(-c3ccc(-c4ccccc4)c4oc5ccccc5c34)n2)c1 ; N#Cc1cccc(-c2nc(-c3ccc(-c4cccc5ccccc45)cc3)nc(-c3cccc4oc5cc(-c6ccccc6)ccc5c34)n2)c1 ; N#Cc1cccc(-c2nc(-c3ccc(-c4cccc5ccccc45)cc3)nc(-c3cccc4oc5ccc(-c6ccccc6)cc5c34)n2)c1]

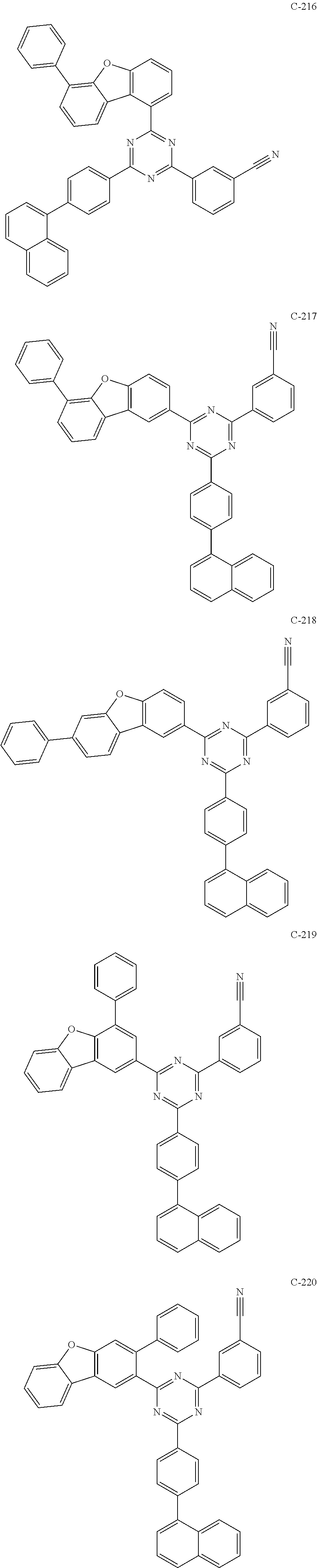 [SMILES: N#Cc1cccc(-c2nc(-c3ccc(-c4cccc5ccccc45)cc3)nc(-c3cccc4oc5c(-c6ccccc6)cccc5c34)n2)c1 ; N#Cc1cccc(-c2nc(-c3ccc(-c4cccc5ccccc45)cc3)nc(-c3ccc4oc5c(-c6ccccc6)cccc5c4c3)n2)c1 ; N#Cc1cccc(-c2nc(-c3ccc(-c4cccc5ccccc45)cc3)nc(-c3ccc4oc5cc(-c6ccccc6)ccc5c4c3)n2)c1 ; N#Cc1cccc(-c2nc(-c3ccc(-c4cccc5ccccc45)cc3)nc(-c3cc(-c4ccccc4)c4oc5ccccc5c4c3)n2)c1 ; N#Cc1cccc(-c2nc(-c3ccc(-c4cccc5ccccc45)cc3)nc(-c3cc4c(cc3-c3ccccc3)oc3ccccc34)n2)c1]

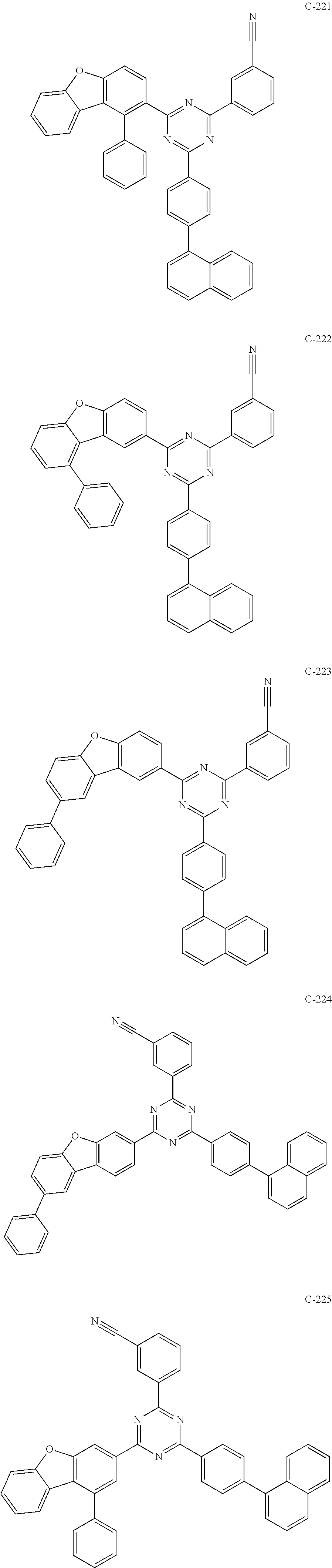 [SMILES: N#Cc1cccc(-c2nc(-c3ccc(-c4cccc5ccccc45)cc3)nc(-c3ccc4oc5ccccc5c4c3-c3ccccc3)n2)c1 ; N#Cc1cccc(-c2nc(-c3ccc(-c4cccc5ccccc45)cc3)nc(-c3ccc4oc5cccc(-c6ccccc6)c5c4c3)n2)c1 ; N#Cc1cccc(-c2nc(-c3ccc(-c4cccc5ccccc45)cc3)nc(-c3ccc4oc5ccc(-c6ccccc6)cc5c4c3)n2)c1 ; N#Cc1cccc(-c2nc(-c3ccc(-c4cccc5ccccc45)cc3)nc(-c3ccc4c(c3)oc3ccc(-c5ccccc5)cc34)n2)c1 ; N#Cc1cccc(-c2nc(-c3ccc(-c4cccc5ccccc45)cc3)nc(-c3cc(-c4ccccc4)c4c(c3)oc3ccccc34)n2)c1]

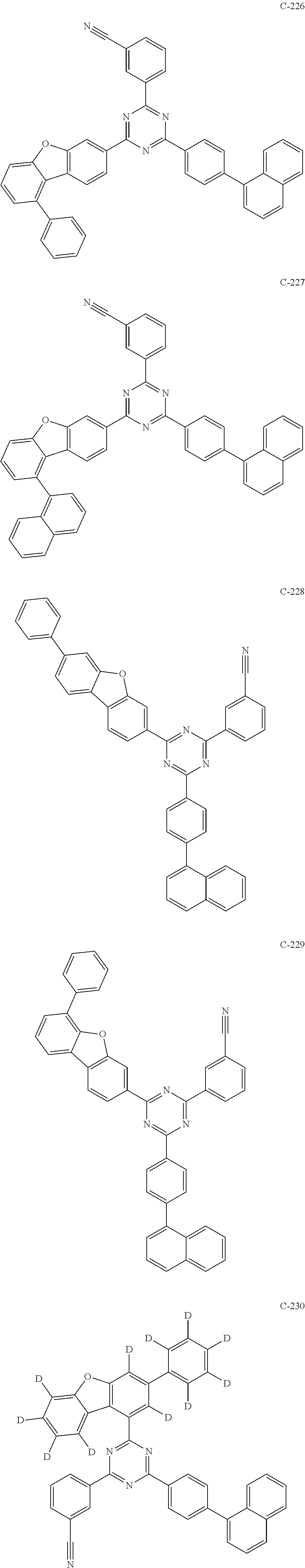

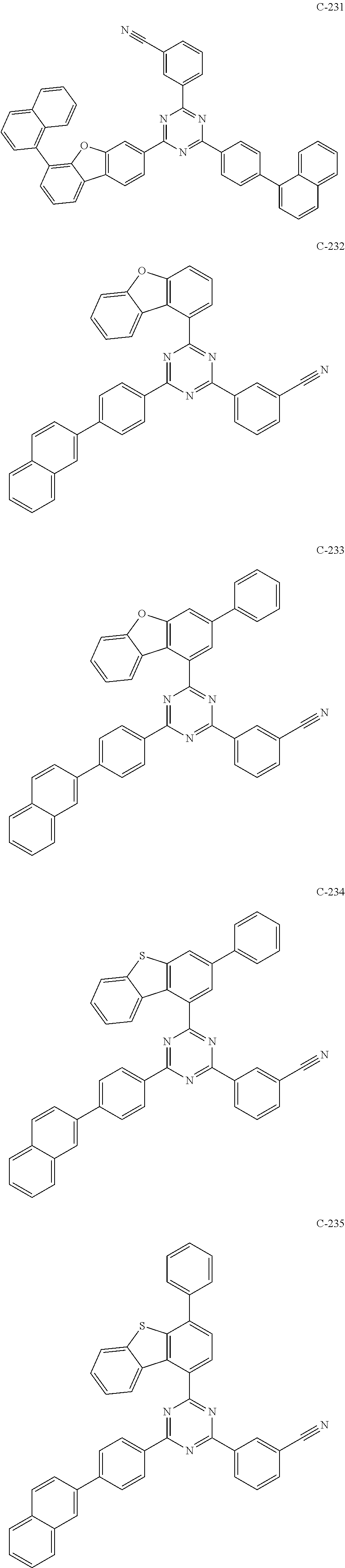 [SMILES: N#Cc1cccc(-c2nc(-c3ccc(-c4cccc5ccccc45)cc3)nc(-c3ccc4c(c3)oc3c(-c5cccc6ccccc56)cccc34)n2)c1 ; N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4ccc5ccccc5c4)cc3)nc(-c3cc(-c4ccccc4)cc4oc5ccccc5c34)n2)c1 ; N#Cc1cccc(-c2nc(-c3ccc(-c4ccc5ccccc5c4)cc3)nc(-c3cc(-c4ccccc4)cc4sc5ccccc5c34)n2)c1 ; N#Cc1cccc(-c2nc(-c3ccc(-c4ccc5ccccc5c4)cc3)nc(-c3ccc(-c4ccccc4)c4sc5ccccc5c34)n2)c1]

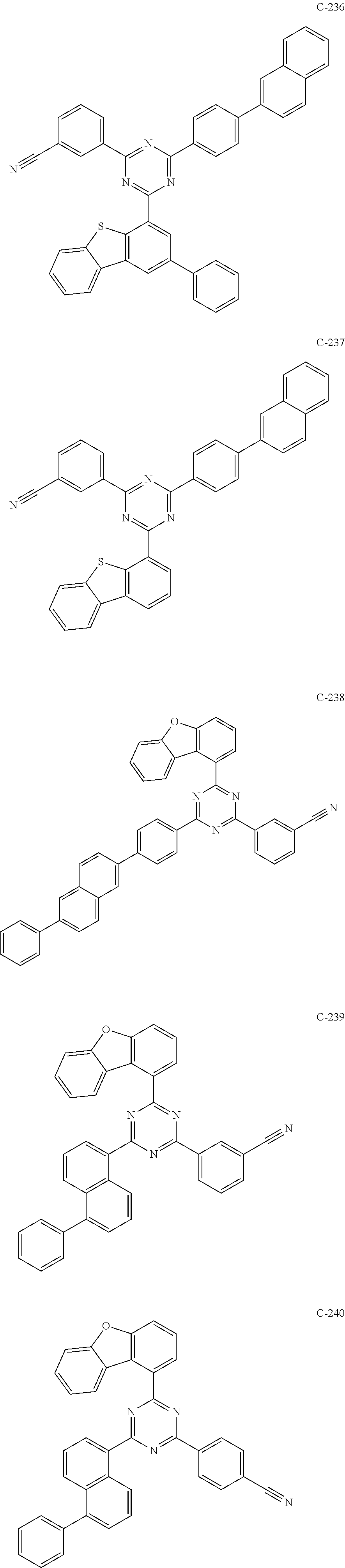 [SMILES: N#Cc1cccc(-c2nc(-c3ccc(-c4ccc5ccccc5c4)cc3)nc(-c3cc(-c4ccccc4)cc4c3sc3ccccc34)n2)c1 ; N#Cc1cccc(-c2nc(-c3ccc(-c4ccc5ccccc5c4)cc3)nc(-c3cccc4c3sc3ccccc34)n2)c1 ; N#Cc1cccc(-c2nc(-c3ccc(-c4ccc5cc(-c6ccccc6)ccc5c4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1 ; N#Cc1ccc(-c2nc(-c3cccc4c(-c5ccccc5)cccc34)nc(-c3cccc4oc5ccccc5c34)n2)cc1]

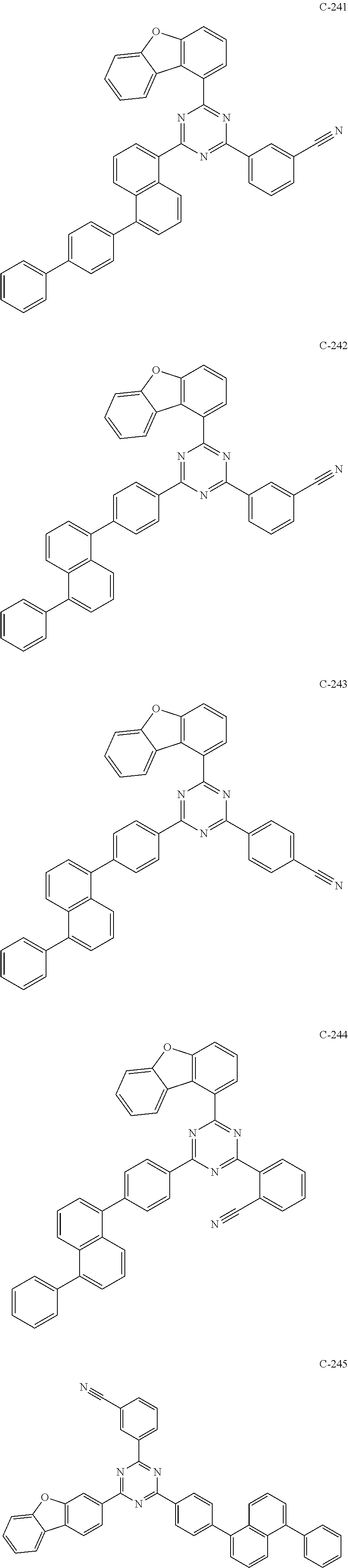 [SMILES: N#Cc1cccc(-c2nc(-c3cccc4c(-c5ccc(-c6ccccc6)cc5)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1 ; N#Cc1ccc(-c2nc(-c3ccc(-c4cccc5c(-c6ccccc6)cccc45)cc3)nc(-c3cccc4oc5ccccc5c34)n2)cc1 ; N#Cc1ccccc1-c1nc(-c2ccc(-c3cccc4c(-c5ccccc5)cccc34)cc2)nc(-c2cccc3oc4ccccc4c23)n1 ; N#Cc1cccc(-c2nc(-c3ccc(-c4cccc5c(-c6ccccc6)cccc45)cc3)nc(-c3ccc4c(c3)oc3ccccc34)n2)c1]

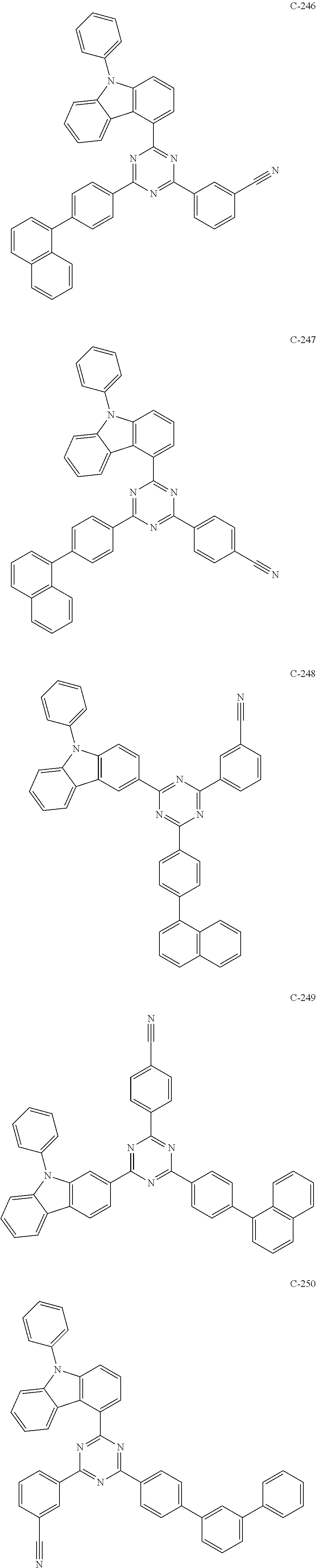 [SMILES: N#Cc1cccc(-c2nc(-c3ccc(-c4cccc5ccccc45)cc3)nc(-c3cccc4c3c3ccccc3n4-c3ccccc3)n2)c1 ; N#Cc1ccc(-c2nc(-c3ccc(-c4cccc5ccccc45)cc3)nc(-c3cccc4c3c3ccccc3n4-c3ccccc3)n2)cc1 ; N#Cc1cccc(-c2nc(-c3ccc(-c4cccc5ccccc45)cc3)nc(-c3ccc4c(c3)c3ccccc3n4-c3ccccc3)n2)c1 ; N#Cc1ccc(-c2nc(-c3ccc(-c4cccc5ccccc45)cc3)nc(-c3ccc4c5ccccc5n(-c5ccccc5)c4c3)n2)cc1 ; N#Cc1cccc(-c2nc(-c3ccc(-c4cccc(-c5ccccc5)c4)cc3)nc(-c3cccc4c3c3ccccc3n4-c3ccccc3)n2)c1]

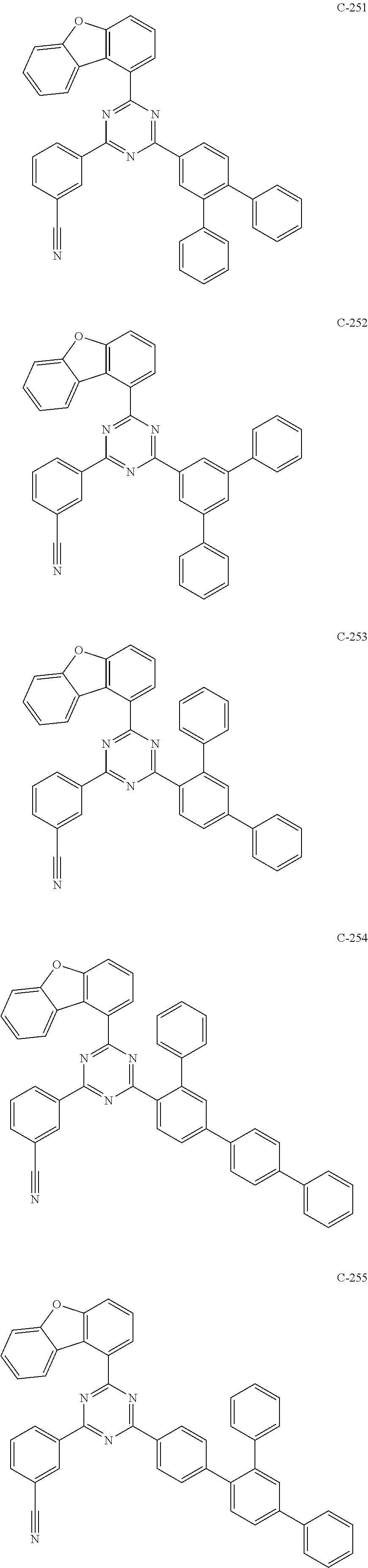 [SMILES: N#Cc1cccc(-c2nc(-c3ccc(-c4ccccc4)c(-c4ccccc4)c3)nc(-c3cccc4oc5ccccc5c34)n2)c1 ; N#Cc1cccc(-c2nc(-c3cc(-c4ccccc4)cc(-c4ccccc4)c3)nc(-c3cccc4oc5ccccc5c34)n2)c1 ; N#Cc1cccc(-c2nc(-c3ccc(-c4ccccc4)cc3-c3ccccc3)nc(-c3cccc4oc5ccccc5c34)n2)c1 ; N#Cc1cccc(-c2nc(-c3ccc(-c4ccc(-c5ccccc5)cc4)cc3-c3ccccc3)nc(-c3cccc4oc5ccccc5c34)n2)c1 ; N#Cc1cccc(-c2nc(-c3ccc(-c4ccc(-c5ccccc5)cc4-c4ccccc4)cc3)nc(-c3cccc4oc5ccccc5c34)n2)c1]

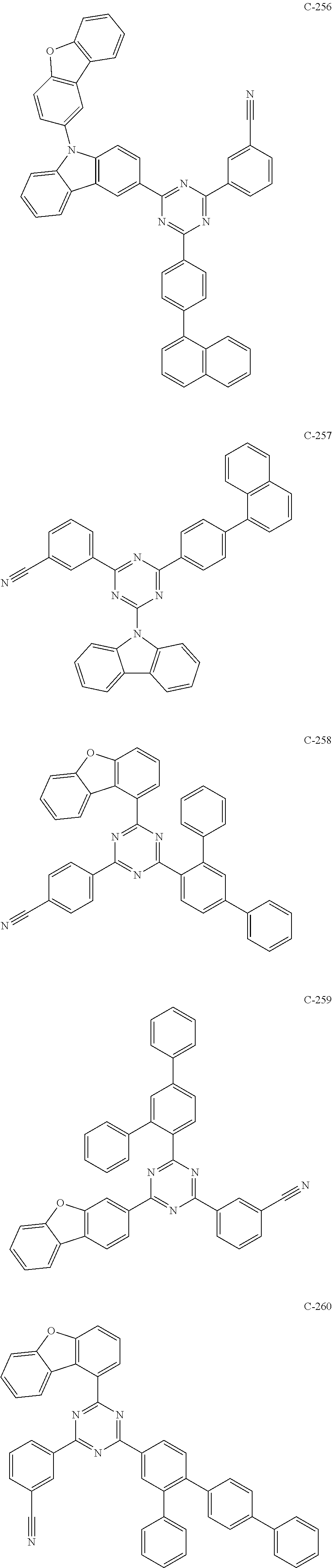 [SMILES: N#Cc1cccc(-c2nc(-c3ccc(-c4cccc5ccccc45)cc3)nc(-c3ccc4c(c3)c3ccccc3n4-c3ccc4oc5ccccc5c4c3)n2)c1 ; N#Cc1cccc(-c2nc(-c3ccc(-c4cccc5ccccc45)cc3)nc(-n3c4ccccc4c4ccccc43)n2)c1 ; N#Cc1ccc(-c2nc(-c3ccc(-c4ccccc4)cc3-c3ccccc3)nc(-c3cccc4oc5ccccc5c34)n2)cc1 ; N#Cc1cccc(-c2nc(-c3ccc4c(c3)oc3ccccc34)nc(-c3ccc(-c4ccccc4)cc3-c3ccccc3)n2)c1 ; N#Cc1cccc(-c2nc(-c3ccc(-c4ccc(-c5ccccc5)cc4)c(-c4ccccc4)c3)nc(-c3cccc4oc5ccccc5c34)n2)c1]

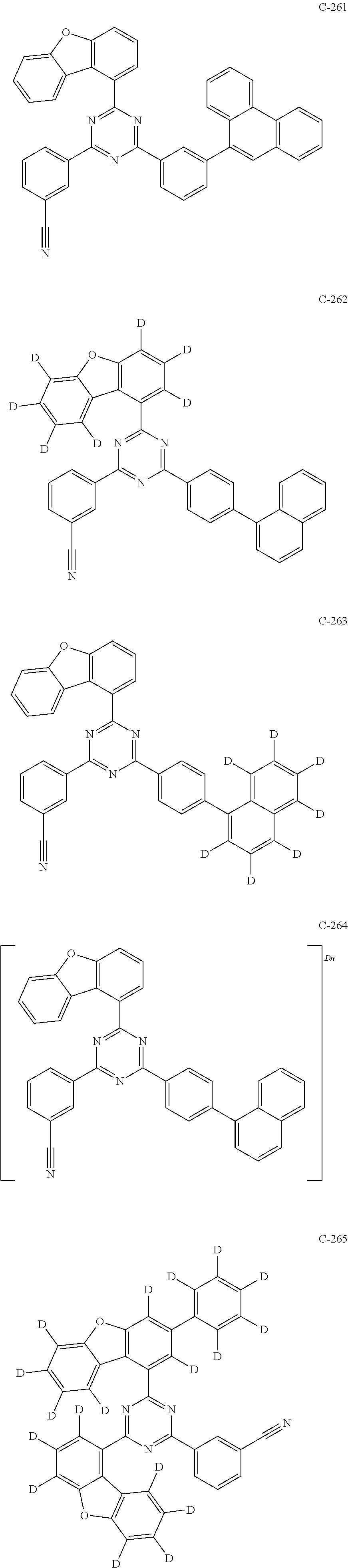

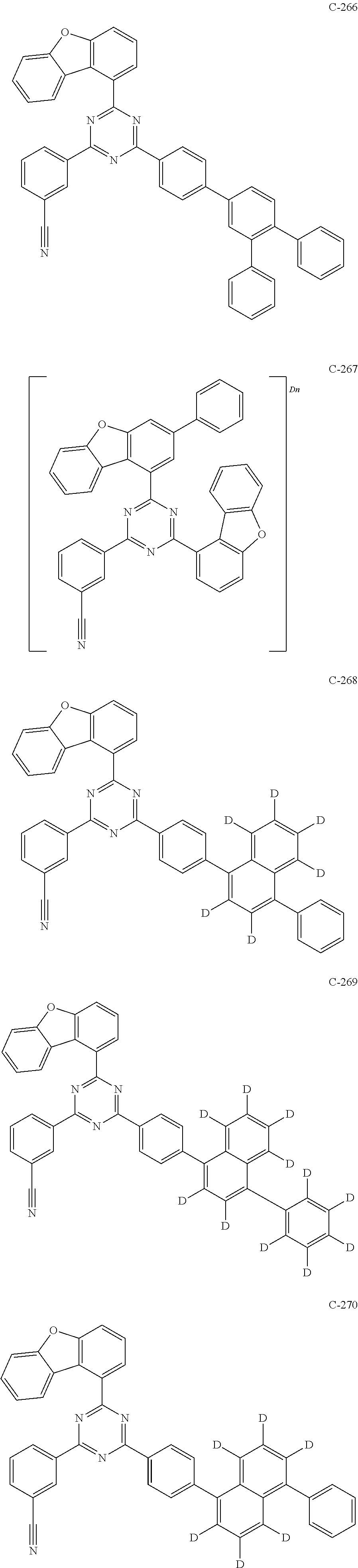

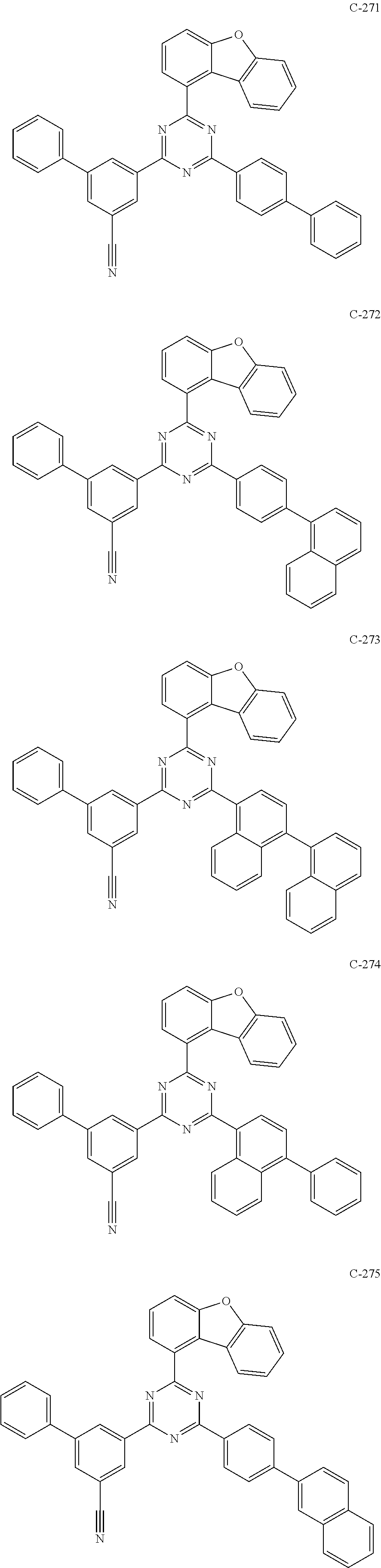 [SMILES: N#Cc1cc(-c2ccccc2)cc(-c2nc(-c3ccc(-c4ccccc4)cc3)nc(-c3cccc4oc5ccccc5c34)n2)c1 ; N#Cc1cc(-c2ccccc2)cc(-c2nc(-c3ccc(-c4cccc5ccccc45)cc3)nc(-c3cccc4oc5ccccc5c34)n2)c1 ; N#Cc1cc(-c2ccccc2)cc(-c2nc(-c3ccc(-c4cccc5ccccc45)c4ccccc34)nc(-c3cccc4oc5ccccc5c34)n2)c1 ; N#Cc1cc(-c2ccccc2)cc(-c2nc(-c3ccc(-c4ccccc4)c4ccccc34)nc(-c3cccc4oc5ccccc5c34)n2)c1 ; N#Cc1cc(-c2ccccc2)cc(-c2nc(-c3ccc(-c4ccc5ccccc5c4)cc3)nc(-c3cccc4oc5ccccc5c34)n2)c1]

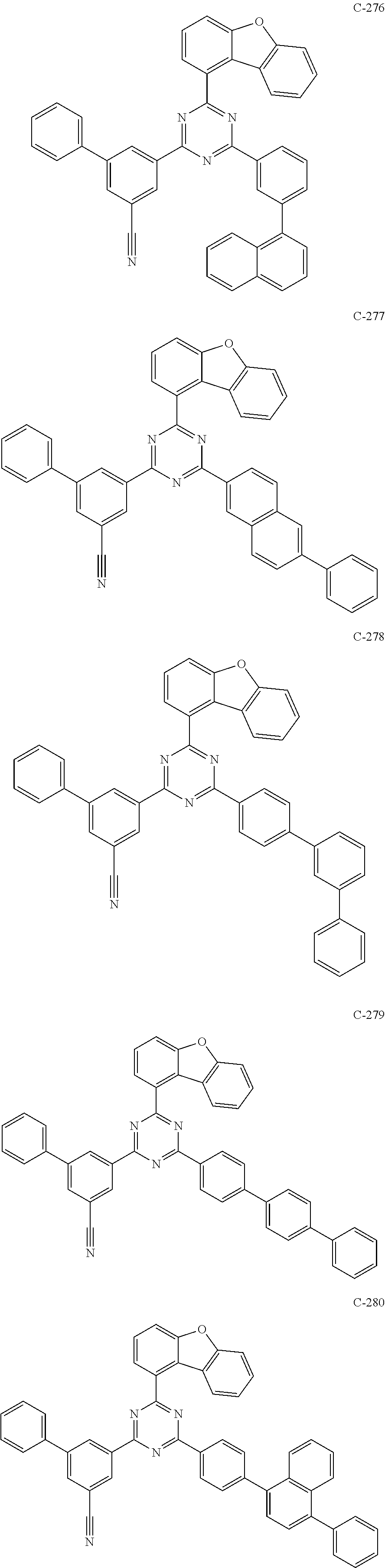 [SMILES: N#Cc1cc(-c2ccccc2)cc(-c2nc(-c3cccc(-c4cccc5ccccc45)c3)nc(-c3cccc4oc5ccccc5c34)n2)c1 ; N#Cc1cc(-c2ccccc2)cc(-c2nc(-c3ccc4cc(-c5ccccc5)ccc4c3)nc(-c3cccc4oc5ccccc5c34)n2)c1 ; N#Cc1cc(-c2ccccc2)cc(-c2nc(-c3ccc(-c4cccc(-c5ccccc5)c4)cc3)nc(-c3cccc4oc5ccccc5c34)n2)c1 ; N#Cc1cc(-c2ccccc2)cc(-c2nc(-c3ccc(-c4ccc(-c5ccccc5)cc4)cc3)nc(-c3cccc4oc5ccccc5c34)n2)c1 ; N#Cc1cc(-c2ccccc2)cc(-c2nc(-c3ccc(-c4ccc(-c5ccccc5)c5ccccc45)cc3)nc(-c3cccc4oc5ccccc5c34)n2)c1]

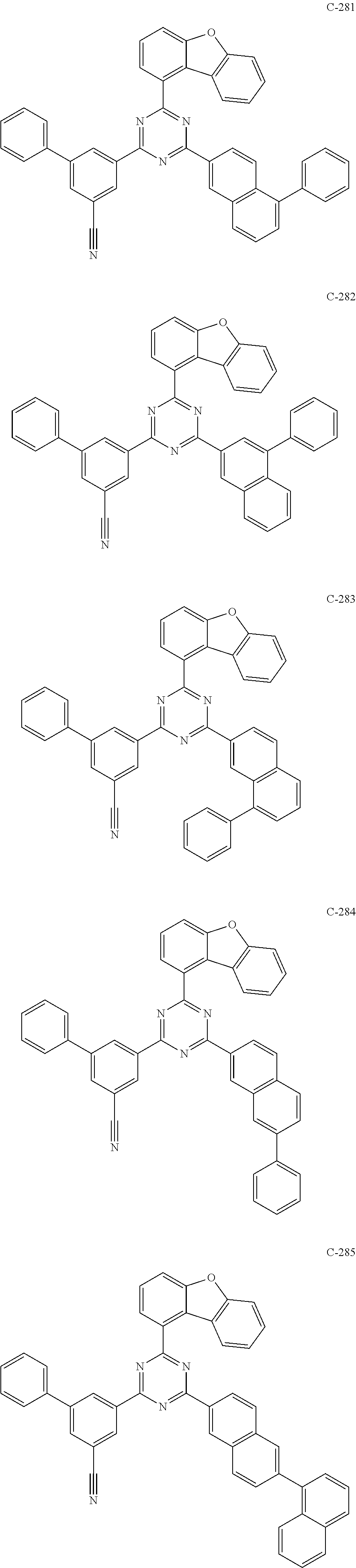 [SMILES: N#Cc1cc(-c2ccccc2)cc(-c2nc(-c3ccc4c(-c5ccccc5)cccc4c3)nc(-c3cccc4oc5ccccc5c34)n2)c1 ; N#Cc1cc(-c2ccccc2)cc(-c2nc(-c3cc(-c4ccccc4)c4ccccc4c3)nc(-c3cccc4oc5ccccc5c34)n2)c1 ; N#Cc1cc(-c2ccccc2)cc(-c2nc(-c3ccc4cccc(-c5ccccc5)c4c3)nc(-c3cccc4oc5ccccc5c34)n2)c1 ; N#Cc1cc(-c2ccccc2)cc(-c2nc(-c3ccc4ccc(-c5ccccc5)cc4c3)nc(-c3cccc4oc5ccccc5c34)n2)c1 ; N#Cc1cc(-c2ccccc2)cc(-c2nc(-c3ccc4cc(-c5cccc6ccccc56)ccc4c3)nc(-c3cccc4oc5ccccc5c34)n2)c1]

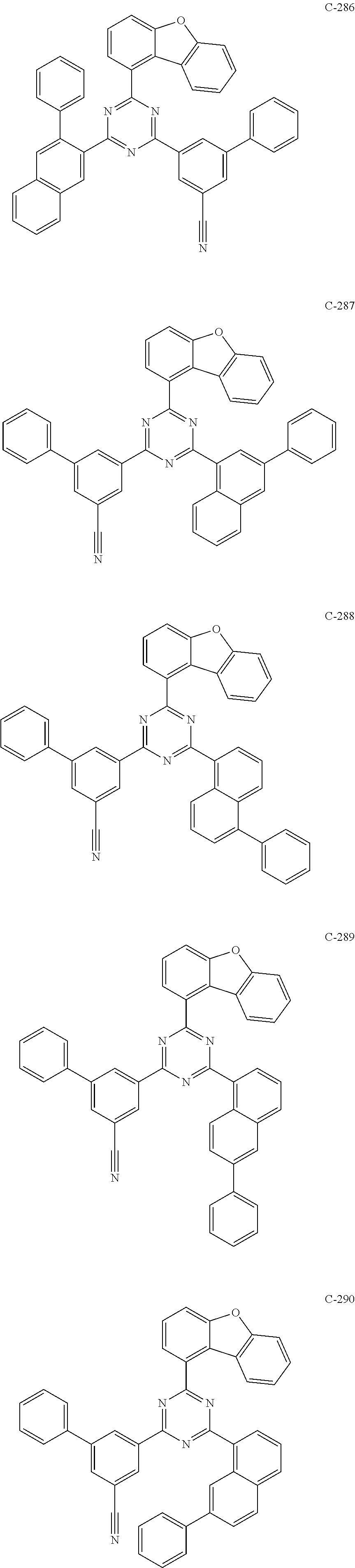 [SMILES: N#Cc1cc(-c2ccccc2)cc(-c2nc(-c3cc4ccccc4cc3-c3ccccc3)nc(-c3cccc4oc5ccccc5c34)n2)c1 ; N#Cc1cc(-c2ccccc2)cc(-c2nc(-c3cc(-c4ccccc4)cc4ccccc34)nc(-c3cccc4oc5ccccc5c34)n2)c1 ; N#Cc1cc(-c2ccccc2)cc(-c2nc(-c3cccc4c(-c5ccccc5)cccc34)nc(-c3cccc4oc5ccccc5c34)n2)c1 ; N#Cc1cc(-c2ccccc2)cc(-c2nc(-c3cccc4cc(-c5ccccc5)ccc34)nc(-c3cccc4oc5ccccc5c34)n2)c1 ; N#Cc1cc(-c2ccccc2)cc(-c2nc(-c3cccc4ccc(-c5ccccc5)cc34)nc(-c3cccc4oc5ccccc5c34)n2)c1]

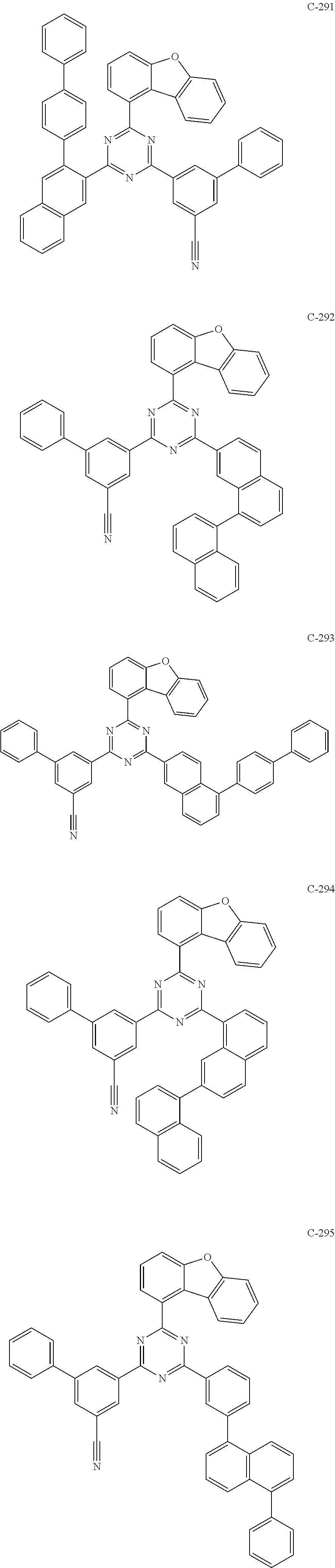 [SMILES: N#Cc1cc(-c2ccccc2)cc(-c2nc(-c3cc4ccccc4cc3-c3ccc(-c4ccccc4)cc3)nc(-c3cccc4oc5ccccc5c34)n2)c1 ; N#Cc1cc(-c2ccccc2)cc(-c2nc(-c3ccc4cccc(-c5cccc6ccccc56)c4c3)nc(-c3cccc4oc5ccccc5c34)n2)c1 ; N#Cc1cc(-c2ccccc2)cc(-c2nc(-c3ccc4c(-c5ccc(-c6ccccc6)cc5)cccc4c3)nc(-c3cccc4oc5ccccc5c34)n2)c1 ; N#Cc1cc(-c2ccccc2)cc(-c2nc(-c3cccc4ccc(-c5cccc6ccccc56)cc34)nc(-c3cccc4oc5ccccc5c34)n2)c1 ; N#Cc1cc(-c2ccccc2)cc(-c2nc(-c3cccc(-c4cccc5c(-c6ccccc6)cccc45)c3)nc(-c3cccc4oc5ccccc5c34)n2)c1]

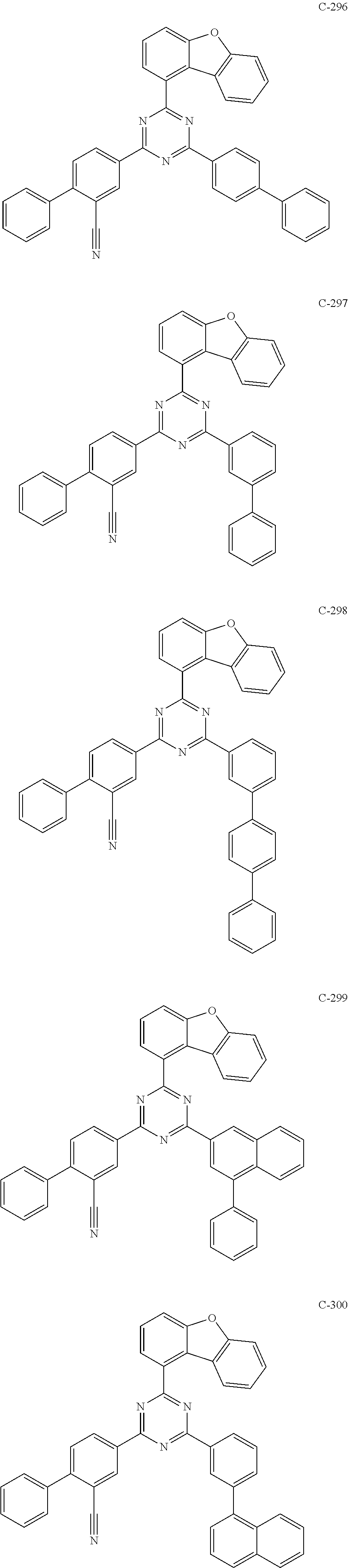 [SMILES: N#Cc1cc(-c2nc(-c3ccc(-c4ccccc4)cc3)nc(-c3cccc4oc5ccccc5c34)n2)ccc1-c1ccccc1 ; N#Cc1cc(-c2nc(-c3cccc(-c4ccccc4)c3)nc(-c3cccc4oc5ccccc5c34)n2)ccc1-c1ccccc1 ; N#Cc1cc(-c2nc(-c3cccc(-c4ccc(-c5ccccc5)cc4)c3)nc(-c3cccc4oc5ccccc5c34)n2)ccc1-c1ccccc1 ; N#Cc1cc(-c2nc(-c3cc(-c4ccccc4)c4ccccc4c3)nc(-c3cccc4oc5ccccc5c34)n2)ccc1-c1ccccc1 ; N#Cc1cc(-c2nc(-c3cccc(-c4cccc5ccccc45)c3)nc(-c3cccc4oc5ccccc5c34)n2)ccc1-c1ccccc1]

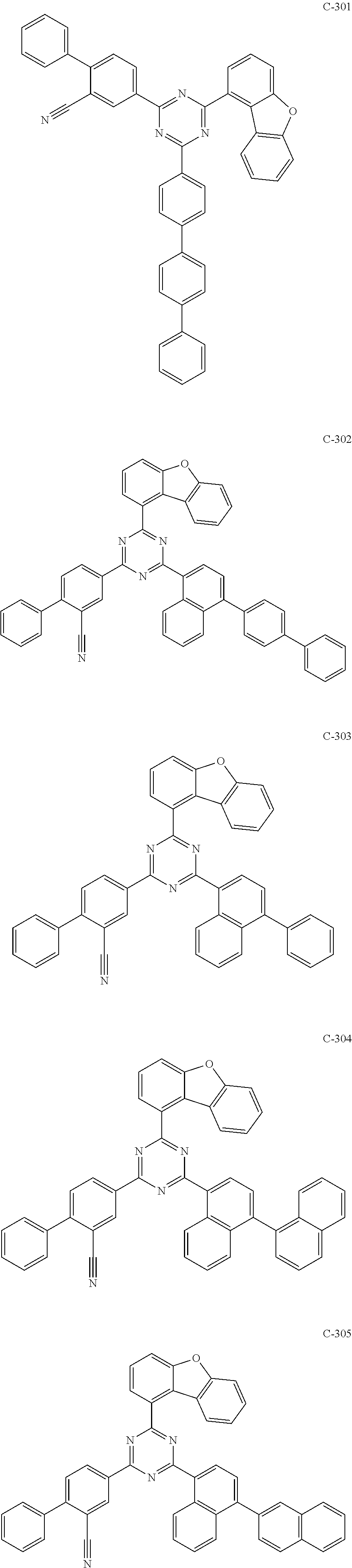 [SMILES: N#Cc1cc(-c2nc(-c3ccc(-c4ccc(-c5ccccc5)cc4)cc3)nc(-c3cccc4oc5ccccc5c34)n2)ccc1-c1ccccc1 ; N#Cc1cc(-c2nc(-c3ccc(-c4ccc(-c5ccccc5)cc4)c4ccccc34)nc(-c3cccc4oc5ccccc5c34)n2)ccc1-c1ccccc1 ; N#Cc1cc(-c2nc(-c3ccc(-c4ccccc4)c4ccccc34)nc(-c3cccc4oc5ccccc5c34)n2)ccc1-c1ccccc1 ; N#Cc1cc(-c2nc(-c3ccc(-c4cccc5ccccc45)c4ccccc34)nc(-c3cccc4oc5ccccc5c34)n2)ccc1-c1ccccc1 ; N#Cc1cc(-c2nc(-c3ccc(-c4ccc5ccccc5c4)c4ccccc34)nc(-c3cccc4oc5ccccc5c34)n2)ccc1-c1ccccc1]

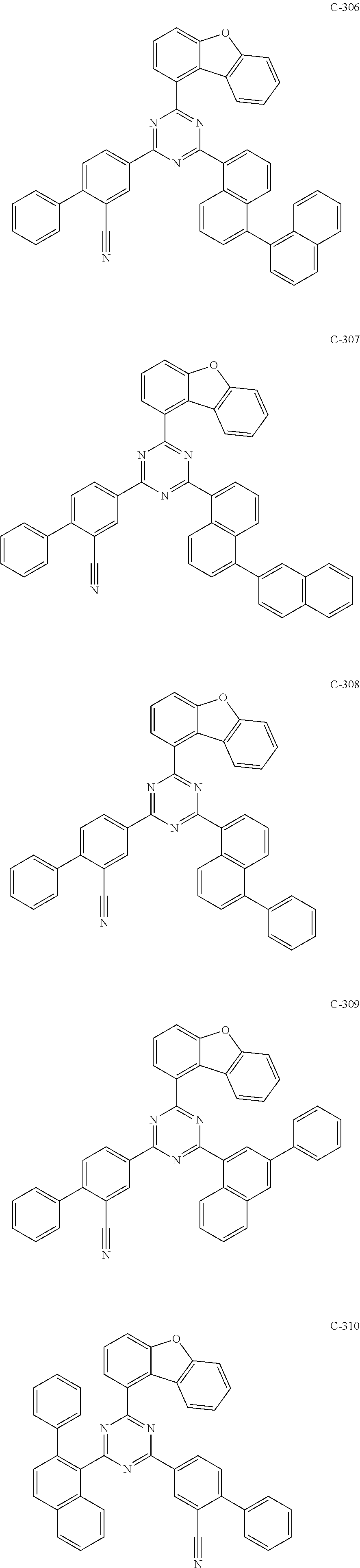 [SMILES: N#Cc1cc(-c2nc(-c3cccc4c(-c5cccc6ccccc56)cccc34)nc(-c3cccc4oc5ccccc5c34)n2)ccc1-c1ccccc1 ; N#Cc1cc(-c2nc(-c3cccc4c(-c5ccc6ccccc6c5)cccc34)nc(-c3cccc4oc5ccccc5c34)n2)ccc1-c1ccccc1 ; N#Cc1cc(-c2nc(-c3cccc4c(-c5ccccc5)cccc34)nc(-c3cccc4oc5ccccc5c34)n2)ccc1-c1ccccc1 ; N#Cc1cc(-c2nc(-c3cc(-c4ccccc4)cc4ccccc34)nc(-c3cccc4oc5ccccc5c34)n2)ccc1-c1ccccc1 ; N#Cc1cc(-c2nc(-c3c(-c4ccccc4)ccc4ccccc34)nc(-c3cccc4oc5ccccc5c34)n2)ccc1-c1ccccc1]

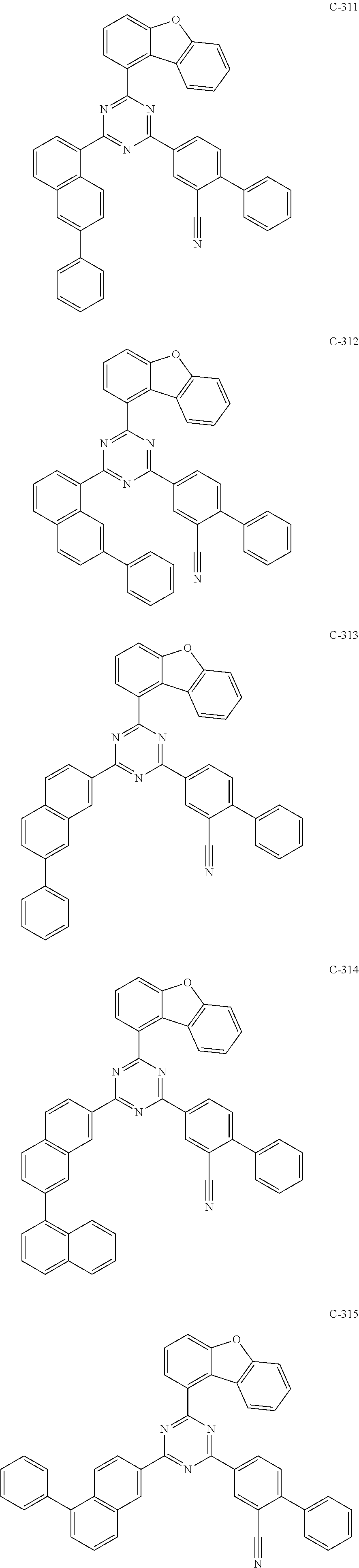 [SMILES: N#Cc1cc(-c2nc(-c3cccc4cc(-c5ccccc5)ccc34)nc(-c3cccc4oc5ccccc5c34)n2)ccc1-c1ccccc1 ; N#Cc1cc(-c2nc(-c3cccc4ccc(-c5ccccc5)cc34)nc(-c3cccc4oc5ccccc5c34)n2)ccc1-c1ccccc1 ; N#Cc1cc(-c2nc(-c3ccc4ccc(-c5ccccc5)cc4c3)nc(-c3cccc4oc5ccccc5c34)n2)ccc1-c1ccccc1 ; N#Cc1cc(-c2nc(-c3ccc4ccc(-c5cccc6ccccc56)cc4c3)nc(-c3cccc4oc5ccccc5c34)n2)ccc1-c1ccccc1 ; N#Cc1cc(-c2nc(-c3ccc4c(-c5ccccc5)cccc4c3)nc(-c3cccc4oc5ccccc5c34)n2)ccc1-c1ccccc1]

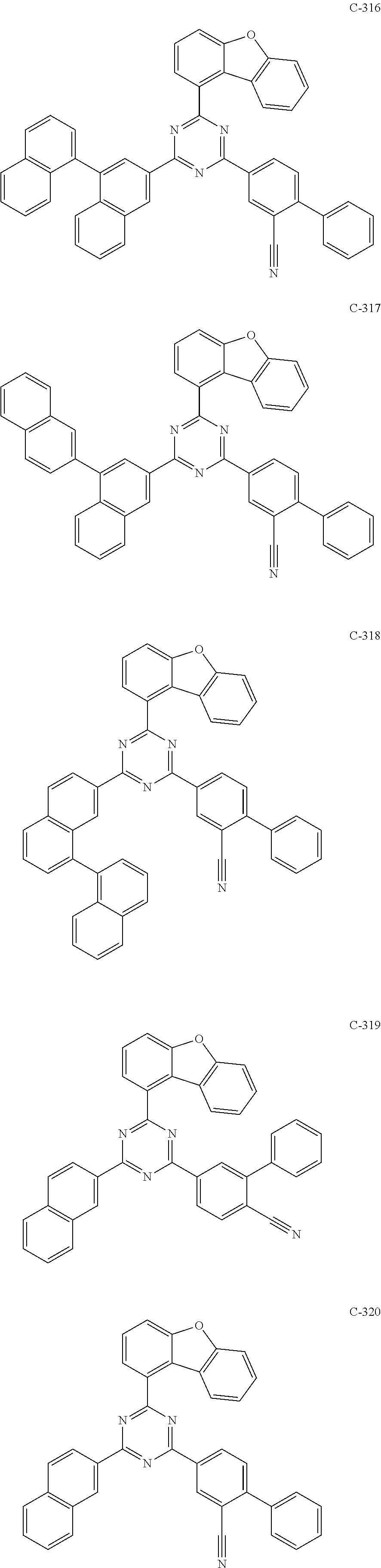 [SMILES: N#Cc1cc(-c2nc(-c3cc(-c4cccc5ccccc45)c4ccccc4c3)nc(-c3cccc4oc5ccccc5c34)n2)ccc1-c1ccccc1 ; N#Cc1cc(-c2nc(-c3cc(-c4ccc5ccccc5c4)c4ccccc4c3)nc(-c3cccc4oc5ccccc5c34)n2)ccc1-c1ccccc1 ; N#Cc1cc(-c2nc(-c3ccc4cccc(-c5cccc6ccccc56)c4c3)nc(-c3cccc4oc5ccccc5c34)n2)ccc1-c1ccccc1 ; N#Cc1ccc(-c2nc(-c3ccc4ccccc4c3)nc(-c3cccc4oc5ccccc5c34)n2)cc1-c1ccccc1 ; N#Cc1cc(-c2nc(-c3ccc4ccccc4c3)nc(-c3cccc4oc5ccccc5c34)n2)ccc1-c1ccccc1]

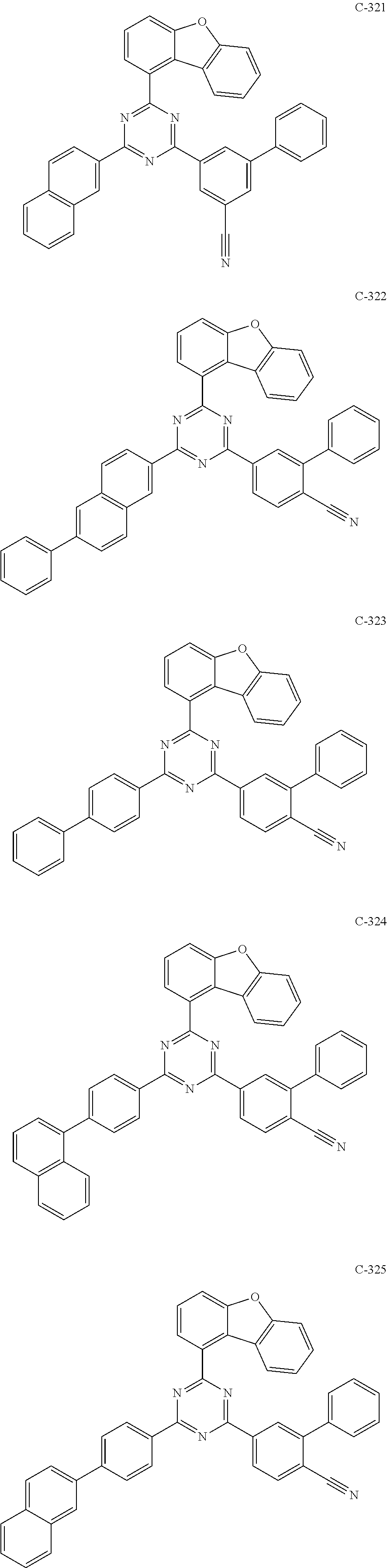 [SMILES: N#Cc1cc(-c2ccccc2)cc(-c2nc(-c3ccc4ccccc4c3)nc(-c3cccc4oc5ccccc5c34)n2)c1 ; N#Cc1ccc(-c2nc(-c3ccc4cc(-c5ccccc5)ccc4c3)nc(-c3cccc4oc5ccccc5c34)n2)cc1-c1ccccc1 ; N#Cc1ccc(-c2nc(-c3ccc(-c4ccccc4)cc3)nc(-c3cccc4oc5ccccc5c34)n2)cc1-c1ccccc1 ; N#Cc1ccc(-c2nc(-c3ccc(-c4cccc5ccccc45)cc3)nc(-c3cccc4oc5ccccc5c34)n2)cc1-c1ccccc1 ; N#Cc1ccc(-c2nc(-c3ccc(-c4ccc5ccccc5c4)cc3)nc(-c3cccc4oc5ccccc5c34)n2)cc1-c1ccccc1]

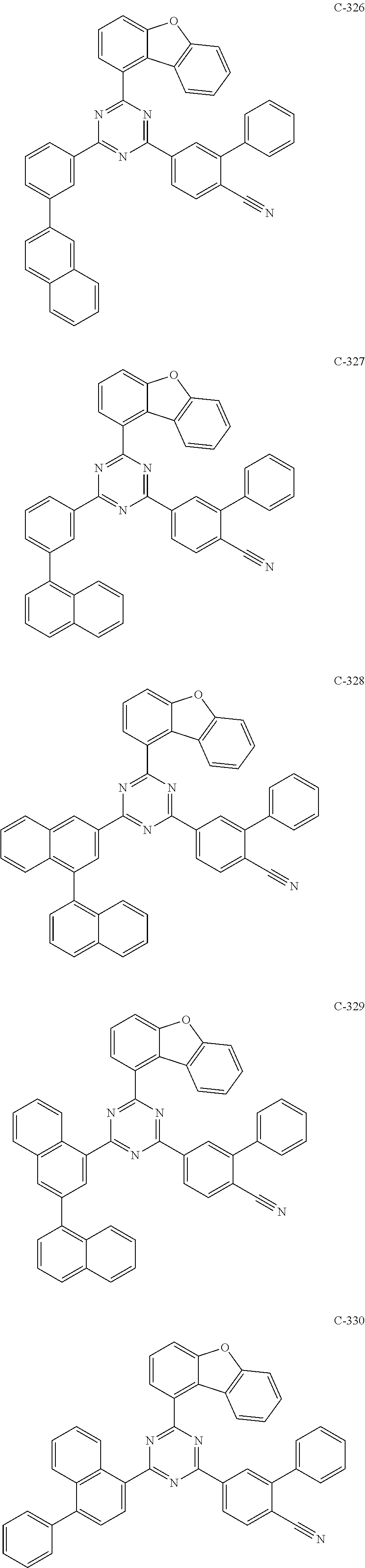 [SMILES: N#Cc1ccc(-c2nc(-c3cccc(-c4ccc5ccccc5c4)c3)nc(-c3cccc4oc5ccccc5c34)n2)cc1-c1ccccc1 ; N#Cc1ccc(-c2nc(-c3cccc(-c4cccc5ccccc45)c3)nc(-c3cccc4oc5ccccc5c34)n2)cc1-c1ccccc1 ; N#Cc1ccc(-c2nc(-c3cc(-c4cccc5ccccc45)c4ccccc4c3)nc(-c3cccc4oc5ccccc5c34)n2)cc1-c1ccccc1 ; N#Cc1ccc(-c2nc(-c3cc(-c4cccc5ccccc45)cc4ccccc34)nc(-c3cccc4oc5ccccc5c34)n2)cc1-c1ccccc1 ; N#Cc1ccc(-c2nc(-c3ccc(-c4ccccc4)c4ccccc34)nc(-c3cccc4oc5ccccc5c34)n2)cc1-c1ccccc1]

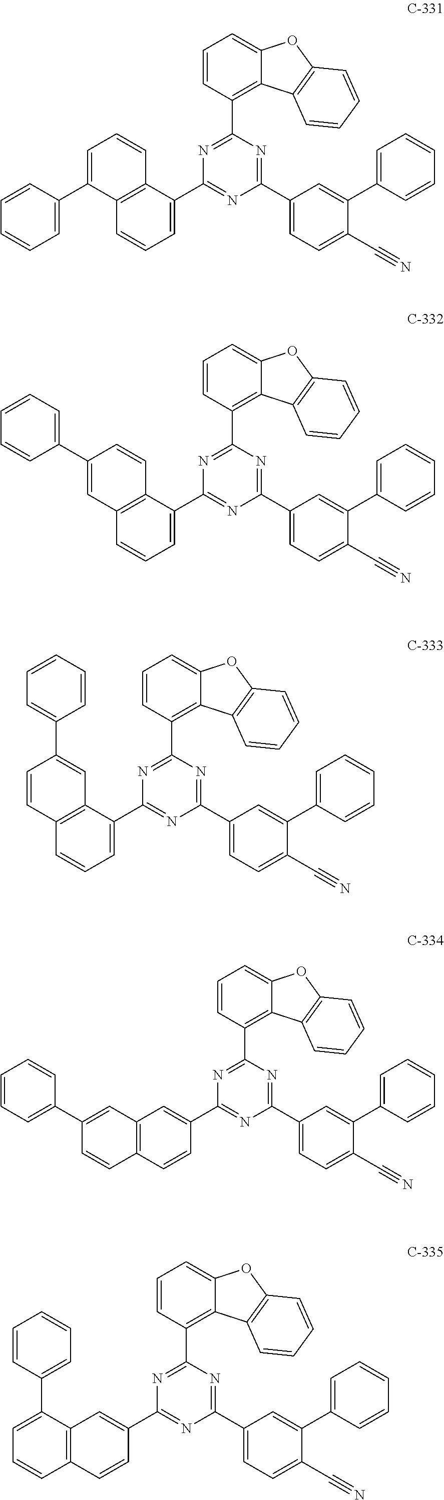 [SMILES: N#Cc1ccc(-c2nc(-c3cccc4c(-c5ccccc5)cccc34)nc(-c3cccc4oc5ccccc5c34)n2)cc1-c1ccccc1 ; N#Cc1ccc(-c2nc(-c3cccc4cc(-c5ccccc5)ccc34)nc(-c3cccc4oc5ccccc5c34)n2)cc1-c1ccccc1 ; N#Cc1ccc(-c2nc(-c3cccc4ccc(-c5ccccc5)cc34)nc(-c3cccc4oc5ccccc5c34)n2)cc1-c1ccccc1 ; N#Cc1ccc(-c2nc(-c3ccc4ccc(-c5ccccc5)cc4c3)nc(-c3cccc4oc5ccccc5c34)n2)cc1-c1ccccc1 ; N#Cc1ccc(-c2nc(-c3ccc4cccc(-c5ccccc5)c4c3)nc(-c3cccc4oc5ccccc5c34)n2)cc1-c1ccccc1]

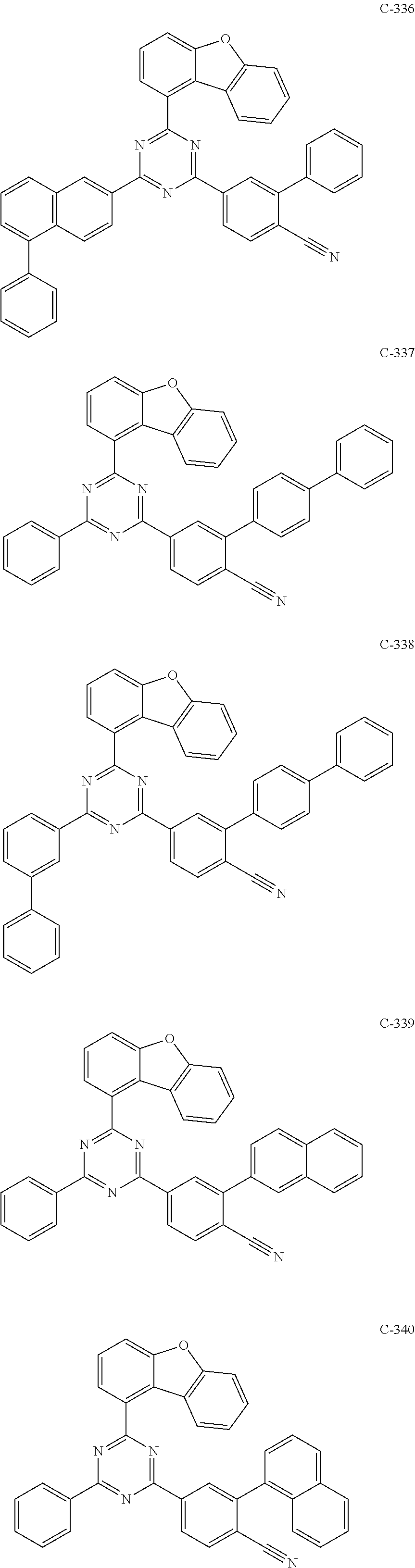 [SMILES: N#Cc1ccc(-c2nc(-c3ccc4c(-c5ccccc5)cccc4c3)nc(-c3cccc4oc5ccccc5c34)n2)cc1-c1ccccc1 ; N#Cc1ccc(-c2nc(-c3ccccc3)nc(-c3cccc4oc5ccccc5c34)n2)cc1-c1ccc(-c2ccccc2)cc1 ; N#Cc1ccc(-c2nc(-c3cccc(-c4ccccc4)c3)nc(-c3cccc4oc5ccccc5c34)n2)cc1-c1ccc(-c2ccccc2)cc1 ; N#Cc1ccc(-c2nc(-c3ccccc3)nc(-c3cccc4oc5ccccc5c34)n2)cc1-c1ccc2ccccc2c1 ; N#Cc1ccc(-c2nc(-c3ccccc3)nc(-c3cccc4oc5ccccc5c34)n2)cc1-c1cccc2ccccc12]

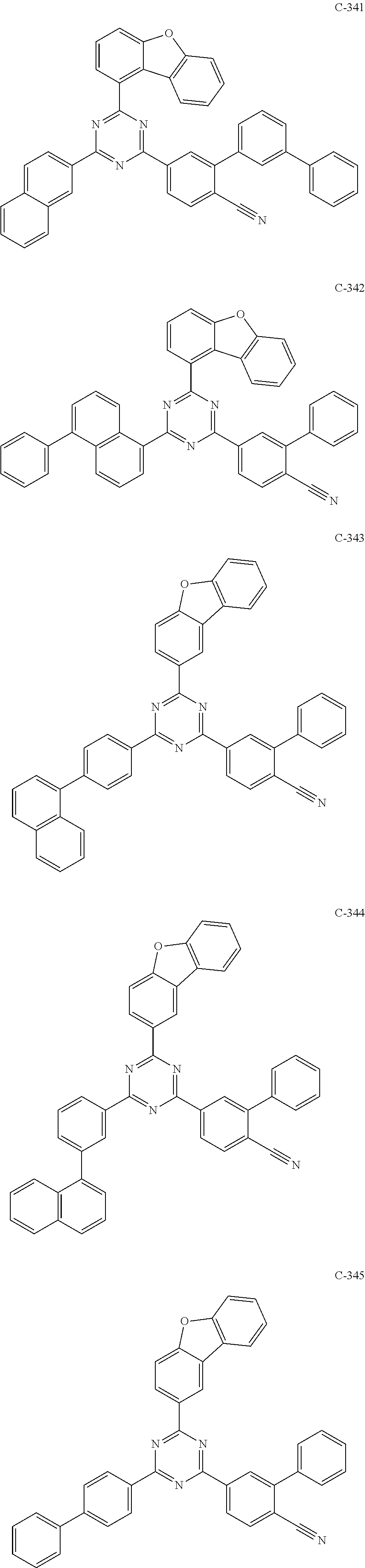 [SMILES: N#Cc1ccc(-c2nc(-c3ccc4ccccc4c3)nc(-c3cccc4oc5ccccc5c34)n2)cc1-c1cccc(-c2ccccc2)c1 ; N#Cc1ccc(-c2nc(-c3cccc4c(-c5ccccc5)cccc34)nc(-c3cccc4oc5ccccc5c34)n2)cc1-c1ccccc1 ; N#Cc1ccc(-c2nc(-c3ccc(-c4cccc5ccccc45)cc3)nc(-c3ccc4oc5ccccc5c4c3)n2)cc1-c1ccccc1 ; N#Cc1ccc(-c2nc(-c3cccc(-c4cccc5ccccc45)c3)nc(-c3ccc4oc5ccccc5c4c3)n2)cc1-c1ccccc1 ; N#Cc1ccc(-c2nc(-c3ccc(-c4ccccc4)cc3)nc(-c3ccc4oc5ccccc5c4c3)n2)cc1-c1ccccc1]

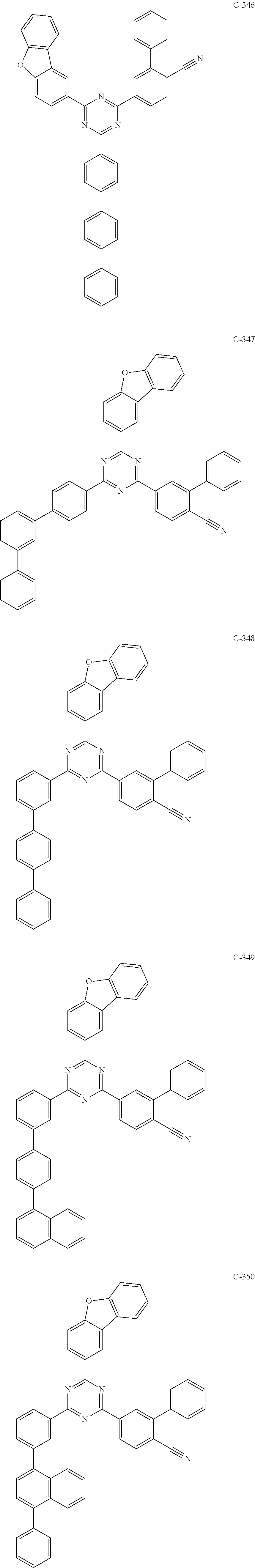 [SMILES: N#Cc1ccc(-c2nc(-c3ccc(-c4ccc(-c5ccccc5)cc4)cc3)nc(-c3ccc4oc5ccccc5c4c3)n2)cc1-c1ccccc1 ; N#Cc1ccc(-c2nc(-c3ccc(-c4cccc(-c5ccccc5)c4)cc3)nc(-c3ccc4oc5ccccc5c4c3)n2)cc1-c1ccccc1 ; N#Cc1ccc(-c2nc(-c3cccc(-c4ccc(-c5ccccc5)cc4)c3)nc(-c3ccc4oc5ccccc5c4c3)n2)cc1-c1ccccc1 ; N#Cc1ccc(-c2nc(-c3cccc(-c4ccc(-c5cccc6ccccc56)cc4)c3)nc(-c3ccc4oc5ccccc5c4c3)n2)cc1-c1ccccc1 ; N#Cc1ccc(-c2nc(-c3cccc(-c4ccc(-c5ccccc5)c5ccccc45)c3)nc(-c3ccc4oc5ccccc5c4c3)n2)cc1-c1ccccc1]

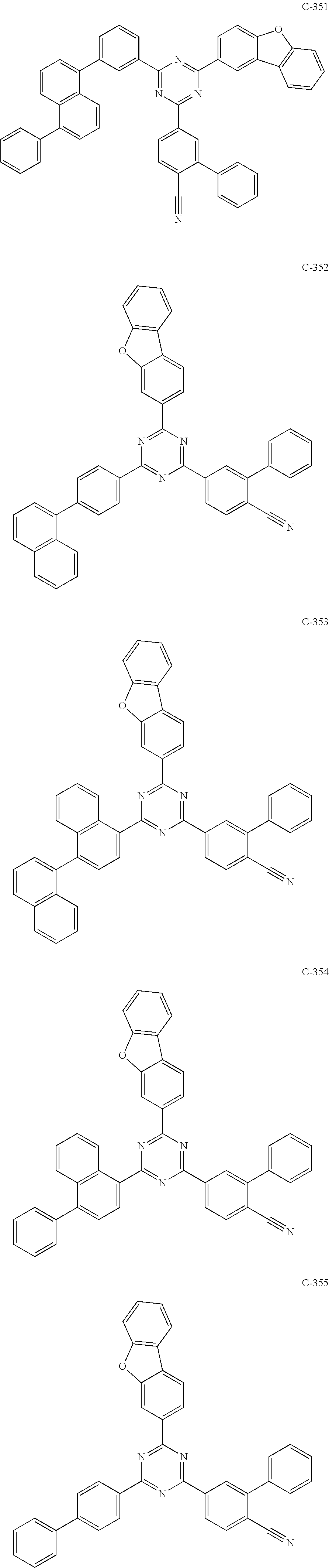 [SMILES: N#Cc1ccc(-c2nc(-c3cccc(-c4cccc5c(-c6ccccc6)cccc45)c3)nc(-c3ccc4oc5ccccc5c4c3)n2)cc1-c1ccccc1 ; N#Cc1ccc(-c2nc(-c3ccc(-c4cccc5ccccc45)cc3)nc(-c3ccc4c(c3)oc3ccccc34)n2)cc1-c1ccccc1 ; N#Cc1ccc(-c2nc(-c3ccc4c(c3)oc3ccccc34)nc(-c3ccc(-c4cccc5ccccc45)c4ccccc34)n2)cc1-c1ccccc1 ; N#Cc1ccc(-c2nc(-c3ccc4c(c3)oc3ccccc34)nc(-c3ccc(-c4ccccc4)c4ccccc34)n2)cc1-c1ccccc1 ; N#Cc1ccc(-c2nc(-c3ccc(-c4ccccc4)cc3)nc(-c3ccc4c(c3)oc3ccccc34)n2)cc1-c1ccccc1]

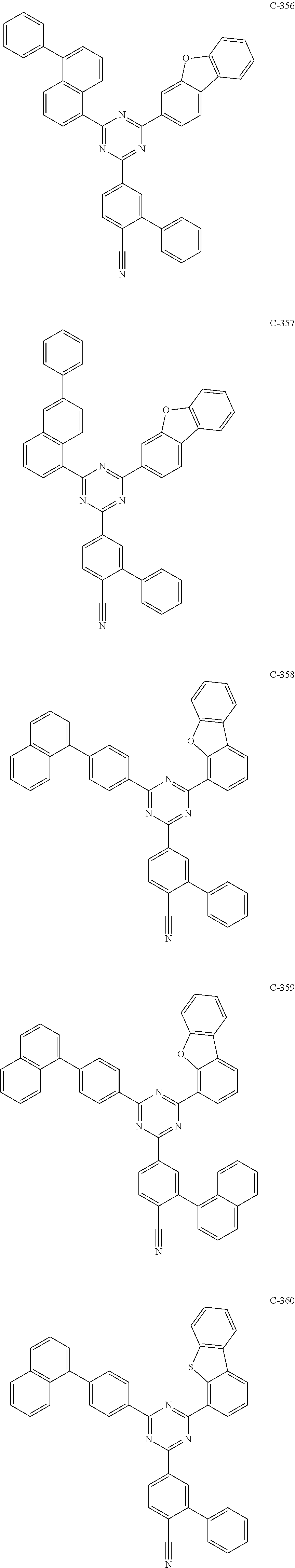 [SMILES: N#Cc1ccc(-c2nc(-c3ccc4c(c3)oc3ccccc34)nc(-c3cccc4c(-c5ccccc5)cccc34)n2)cc1-c1ccccc1 ; N#Cc1ccc(-c2nc(-c3ccc4c(c3)oc3ccccc34)nc(-c3cccc4cc(-c5ccccc5)ccc34)n2)cc1-c1ccccc1 ; N#Cc1ccc(-c2nc(-c3ccc(-c4cccc5ccccc45)cc3)nc(-c3cccc4c3oc3ccccc34)n2)cc1-c1ccccc1 ; N#Cc1ccc(-c2nc(-c3ccc(-c4cccc5ccccc45)cc3)nc(-c3cccc4c3oc3ccccc34)n2)cc1-c1cccc2ccccc12 ; N#Cc1ccc(-c2nc(-c3ccc(-c4cccc5ccccc45)cc3)nc(-c3cccc4c3sc3ccccc34)n2)cc1-c1ccccc1]

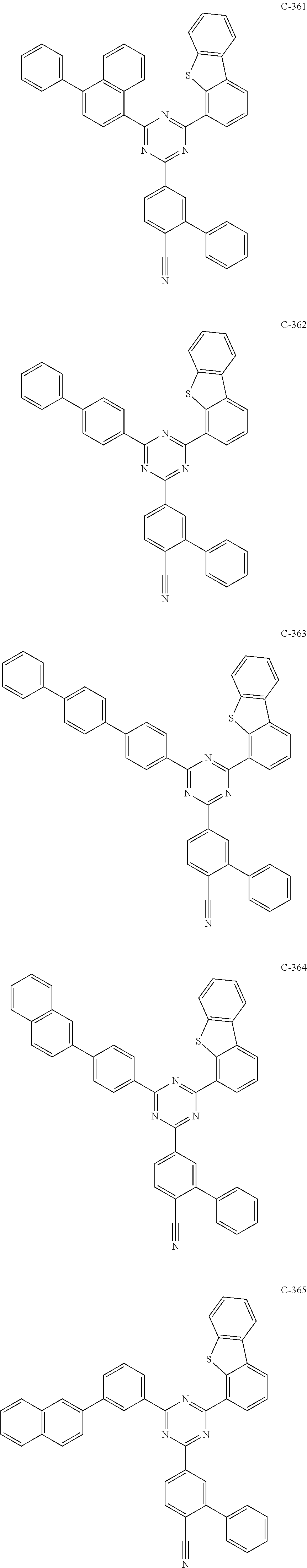 [SMILES: N#Cc1ccc(-c2nc(-c3ccc(-c4ccccc4)c4ccccc34)nc(-c3cccc4c3sc3ccccc34)n2)cc1-c1ccccc1 ; N#Cc1ccc(-c2nc(-c3ccc(-c4ccccc4)cc3)nc(-c3cccc4c3sc3ccccc34)n2)cc1-c1ccccc1 ; N#Cc1ccc(-c2nc(-c3ccc(-c4ccc(-c5ccccc5)cc4)cc3)nc(-c3cccc4c3sc3ccccc34)n2)cc1-c1ccccc1 ; N#Cc1ccc(-c2nc(-c3ccc(-c4ccc5ccccc5c4)cc3)nc(-c3cccc4c3sc3ccccc34)n2)cc1-c1ccccc1 ; N#Cc1ccc(-c2nc(-c3cccc(-c4ccc5ccccc5c4)c3)nc(-c3cccc4c3sc3ccccc34)n2)cc1-c1ccccc1]

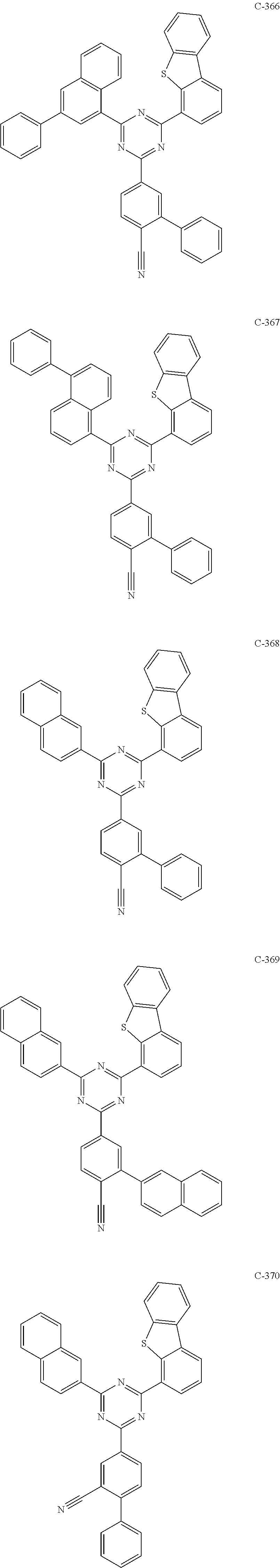 [SMILES: N#Cc1ccc(-c2nc(-c3cc(-c4ccccc4)cc4ccccc34)nc(-c3cccc4c3sc3ccccc34)n2)cc1-c1ccccc1 ; N#Cc1ccc(-c2nc(-c3cccc4c(-c5ccccc5)cccc34)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccc2ccccc2c1 ; N#Cc1cc(-c2nc(-c3ccc4ccccc4c3)nc(-c3cccc4c3sc3ccccc34)n2)ccc1-c1ccccc1]

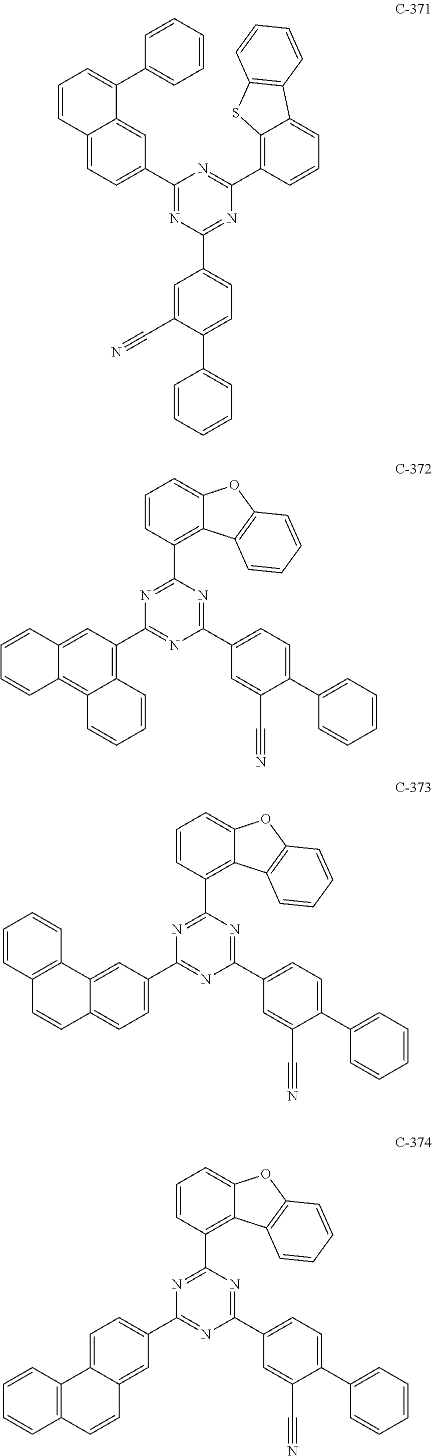 [SMILES: N#Cc1cc(-c2nc(-c3ccc4cccc(-c5ccccc5)c4c3)nc(-c3cccc4c3sc3ccccc34)n2)ccc1-c1ccccc1 ; N#Cc1cc(-c2nc(-c3cc4ccccc4c4ccccc34)nc(-c3cccc4oc5ccccc5c34)n2)ccc1-c1ccccc1 ; N#Cc1cc(-c2nc(-c3ccc4ccc5ccccc5c4c3)nc(-c3cccc4oc5ccccc5c34)n2)ccc1-c1ccccc1 ; N#Cc1cc(-c2nc(-c3ccc4c(ccc5ccccc54)c3)nc(-c3cccc4oc5ccccc5c34)n2)ccc1-c1ccccc1]

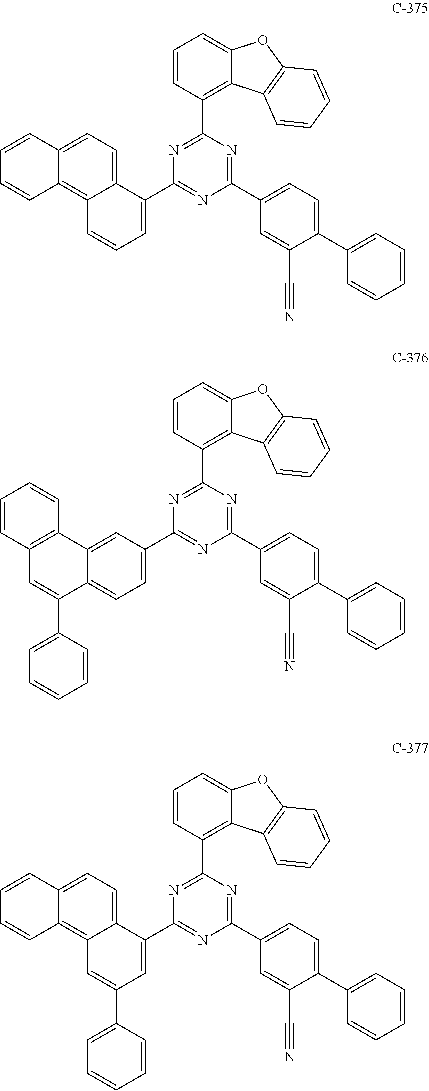 [SMILES: N#Cc1cc(-c2nc(-c3cccc4c3ccc3ccccc34)nc(-c3cccc4oc5ccccc5c34)n2)ccc1-c1ccccc1 ; N#Cc1cc(-c2nc(-c3ccc4c(-c5ccccc5)cc5ccccc5c4c3)nc(-c3cccc4oc5ccccc5c34)n2)ccc1-c1ccccc1 ; N#Cc1cc(-c2nc(-c3cc(-c4ccccc4)cc4c3ccc3ccccc34)nc(-c3cccc4oc5ccccc5c34)n2)ccc1-c1ccccc1]

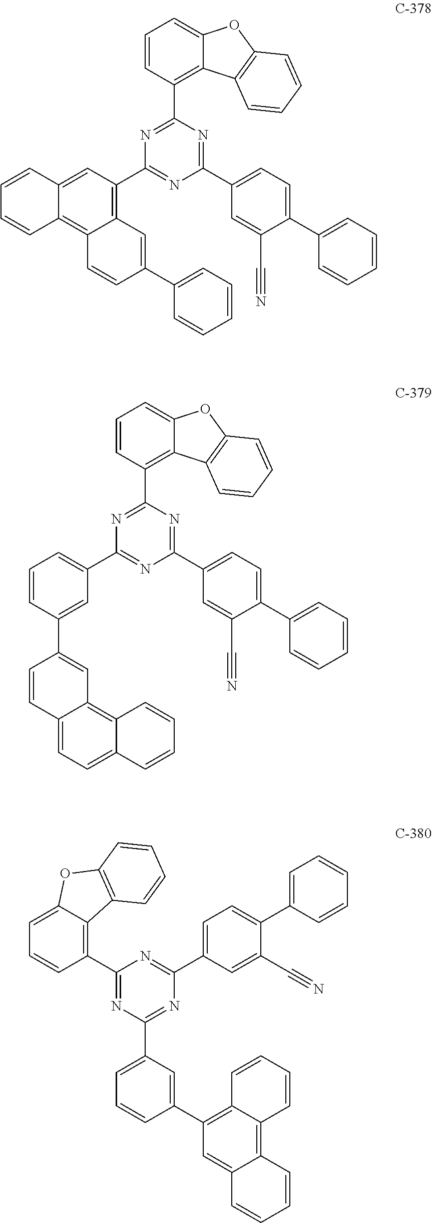 [SMILES: N#Cc1cc(-c2nc(-c3cc4ccccc4c4ccc(-c5ccccc5)cc34)nc(-c3cccc4oc5ccccc5c34)n2)ccc1-c1ccccc1 ; N#Cc1cc(-c2nc(-c3cccc(-c4ccc5ccc6ccccc6c5c4)c3)nc(-c3cccc4oc5ccccc5c34)n2)ccc1-c1ccccc1 ; N#Cc1cc(-c2nc(-c3cccc(-c4cc5ccccc5c5ccccc45)c3)nc(-c3cccc4oc5ccccc5c34)n2)ccc1-c1ccccc1]

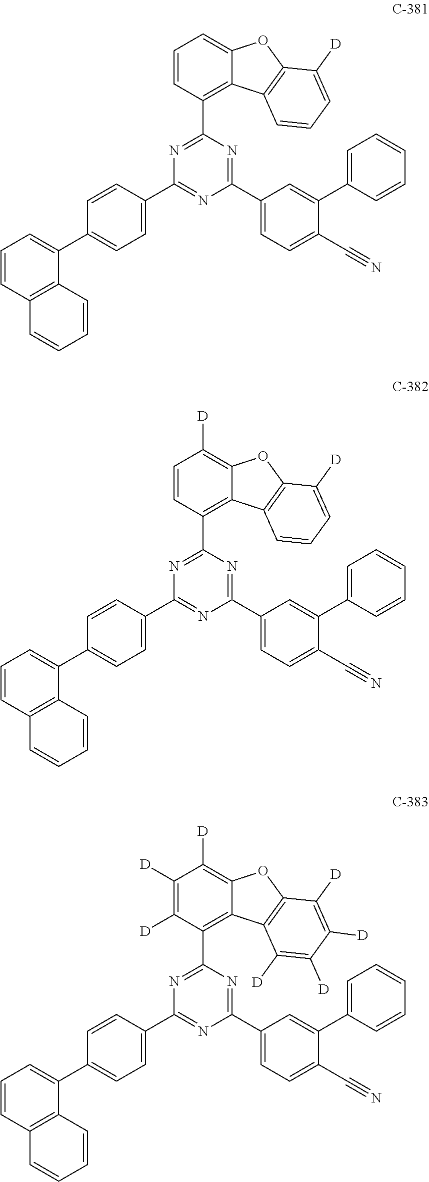 [SMILES: [2H]c1cccc2c1oc1cccc(-c3nc(-c4ccc(-c5cccc6ccccc56)cc4)nc(-c4ccc(C#N)c(-c5ccccc5)c4)n3)c12 ; [2H]c1cccc2c1oc1c([2H])ccc(-c3nc(-c4ccc(-c5cccc6ccccc56)cc4)nc(-c4ccc(C#N)c(-c5ccccc5)c4)n3)c12 ; [2H]c1c([2H])c([2H])c2c(oc3c([2H])c([2H])c([2H])c(-c4nc(-c5ccc(-c6cccc7ccccc67)cc5)nc(-c5ccc(C#N)c(-c6ccccc6)c5)n4)c32)c1[2H]]

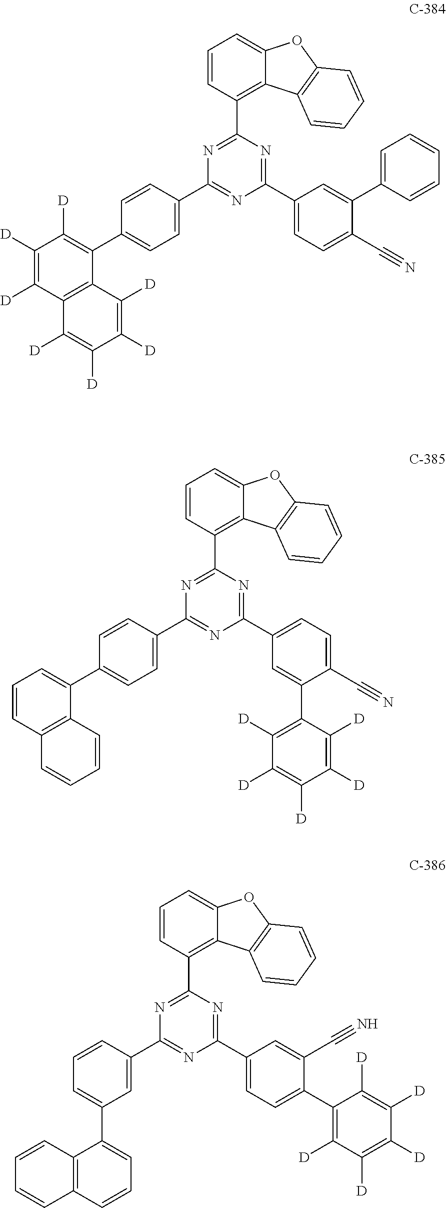 [SMILES: [2H]c1c([2H])c([2H])c2c(-c3ccc(-c4nc(-c5ccc(C#N)c(-c6ccccc6)c5)nc(-c5cccc6oc7ccccc7c56)n4)cc3)c([2H])c([2H])c([2H])c2c1[2H] ; [2H]c1c([2H])c([2H])c(-c2cc(-c3nc(-c4ccc(-c5cccc6ccccc56)cc4)nc(-c4cccc5oc6ccccc6c45)n3)ccc2C#N)c([2H])c1[2H] ; [2H]c1c([2H])c([2H])c(-c2ccc(-c3nc(-c4cccc(-c5cccc6ccccc56)c4)nc(-c4cccc5oc6ccccc6c45)n3)cc2C#N)c([2H])c1[2H]]

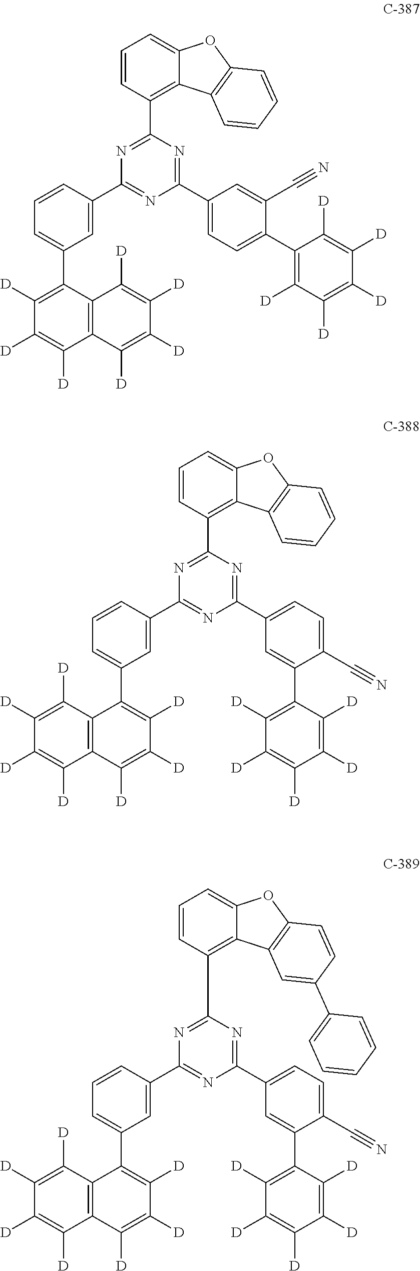 [SMILES: [2H]c1c([2H])c([2H])c(-c2ccc(-c3nc(-c4cccc(-c5c([2H])c([2H])c([2H])c6c([2H])c([2H])c([2H])c([2H])c56)c4)nc(-c4cccc5oc6ccccc6c45)n3)cc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccccc6c45)n3)ccc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccc(-c7ccccc7)cc6c45)n3)ccc2C#N)c([2H])c1[2H]]

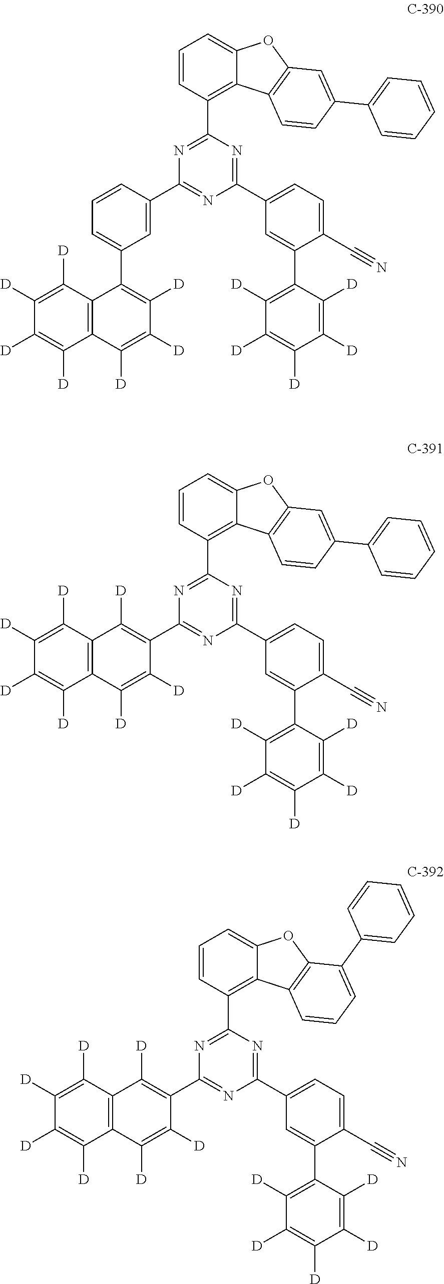 [SMILES: [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6cc(-c7ccccc7)ccc6c45)n3)ccc2C#N)c([2H])c1[2H] ; [2H]c1c([2H])c([2H])c(-c2cc(-c3nc(-c4c([2H])c([2H])c5c([2H])c([2H])c([2H])c([2H])c5c4[2H])nc(-c4cccc5oc6cc(-c7ccccc7)ccc6c45)n3)ccc2C#N)c([2H])c1[2H] ; [2H]c1c([2H])c([2H])c(-c2cc(-c3nc(-c4c([2H])c([2H])c5c([2H])c([2H])c([2H])c([2H])c5c4[2H])nc(-c4cccc5oc6c(-c7ccccc7)cccc6c45)n3)ccc2C#N)c([2H])c1[2H]]

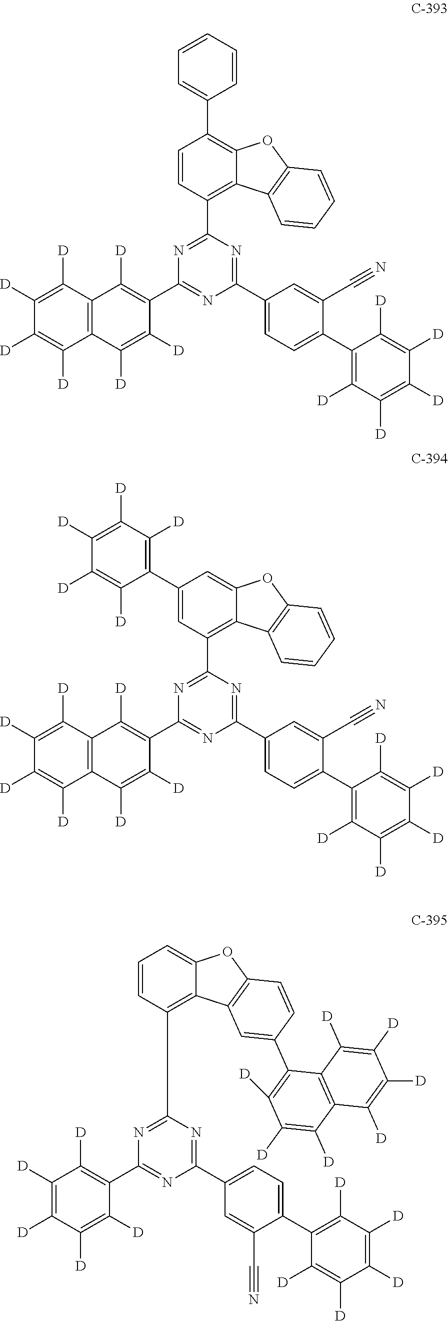

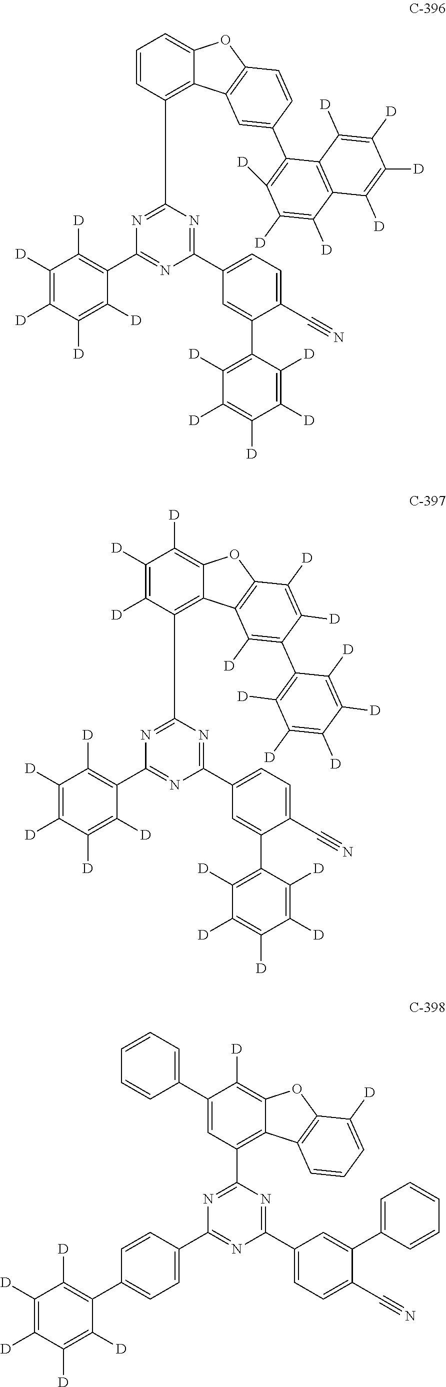

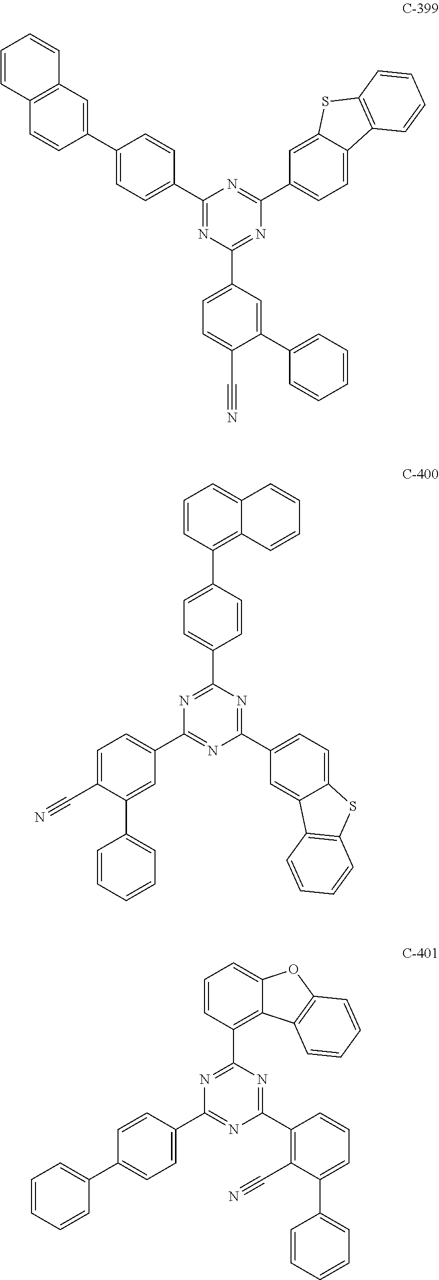 [SMILES: N#Cc1ccc(-c2nc(-c3ccc(-c4ccc5ccccc5c4)cc3)nc(-c3ccc4c(c3)sc3ccccc34)n2)cc1-c1ccccc1 ; N#Cc1ccc(-c2nc(-c3ccc(-c4cccc5ccccc45)cc3)nc(-c3ccc4sc5ccccc5c4c3)n2)cc1-c1ccccc1 ; N#Cc1c(-c2ccccc2)cccc1-c1nc(-c2ccc(-c3ccccc3)cc2)nc(-c2cccc3oc4ccccc4c23)n1]

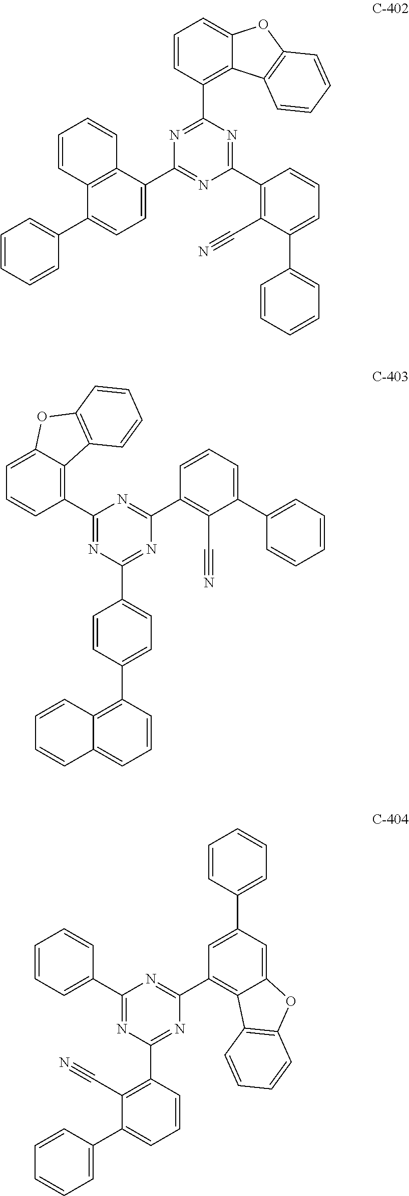 [SMILES: N#Cc1c(-c2ccccc2)cccc1-c1nc(-c2ccc(-c3ccccc3)c3ccccc23)nc(-c2cccc3oc4ccccc4c23)n1 ; N#Cc1c(-c2ccccc2)cccc1-c1nc(-c2ccc(-c3cccc4ccccc34)cc2)nc(-c2cccc3oc4ccccc4c23)n1 ; N#Cc1c(-c2ccccc2)cccc1-c1nc(-c2ccccc2)nc(-c2cc(-c3ccccc3)cc3oc4ccccc4c23)n1]

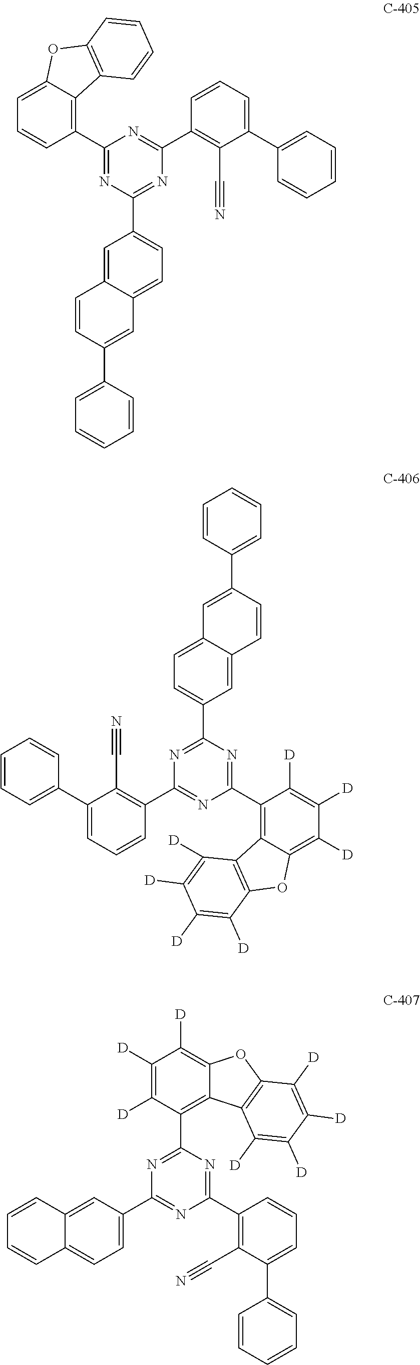 [SMILES: N#Cc1c(-c2ccccc2)cccc1-c1nc(-c2ccc3cc(-c4ccccc4)ccc3c2)nc(-c2cccc3oc4ccccc4c23)n1 ; [2H]c1c([2H])c([2H])c2c(oc3c([2H])c([2H])c([2H])c(-c4nc(-c5ccc6cc(-c7ccccc7)ccc6c5)nc(-c5cccc(-c6ccccc6)c5C#N)n4)c32)c1[2H] ; [2H]c1c([2H])c([2H])c2c(oc3c([2H])c([2H])c([2H])c(-c4nc(-c5ccc6ccccc6c5)nc(-c5cccc(-c6ccccc6)c5C#N)n4)c32)c1[2H]]

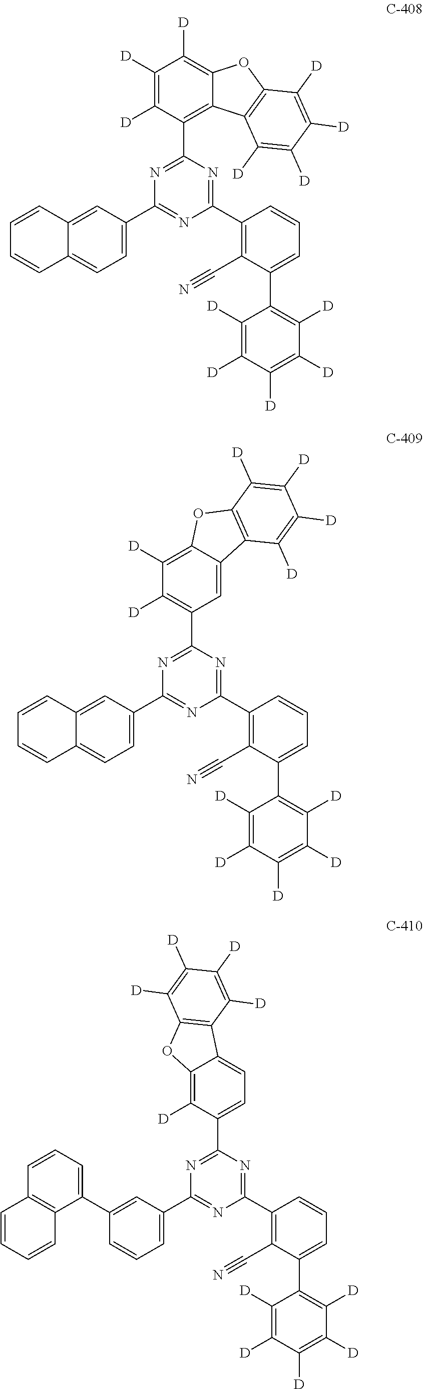 [SMILES: [2H]c1c([2H])c([2H])c(-c2cccc(-c3nc(-c4ccc5ccccc5c4)nc(-c4c([2H])c([2H])c([2H])c5oc6c([2H])c([2H])c([2H])c([2H])c6c45)n3)c2C#N)c([2H])c1[2H] ; [2H]c1c([2H])c([2H])c(-c2cccc(-c3nc(-c4ccc5ccccc5c4)nc(-c4cc5c(oc6c([2H])c([2H])c([2H])c([2H])c65)c([2H])c4[2H])n3)c2C#N)c([2H])c1[2H] ; [2H]c1c([2H])c([2H])c(-c2cccc(-c3nc(-c4cccc(-c5cccc6ccccc56)c4)nc(-c4ccc5c(oc6c([2H])c([2H])c([2H])c([2H])c65)c4[2H])n3)c2C#N)c([2H])c1[2H]]

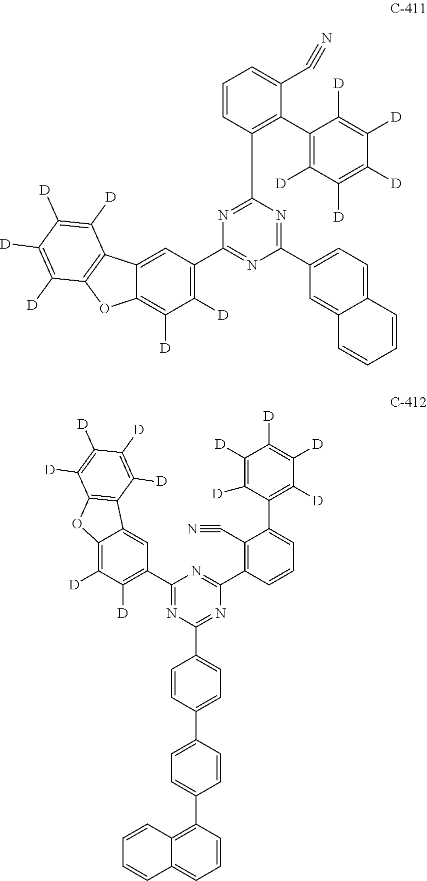 [SMILES: [2H]c1c([2H])c([2H])c(-c2c(C#N)cccc2-c2nc(-c3ccc4ccccc4c3)nc(-c3cc4c(oc5c([2H])c([2H])c([2H])c([2H])c54)c([2H])c3[2H])n2)c([2H])c1[2H] ; [2H]c1c([2H])c([2H])c(-c2cccc(-c3nc(-c4ccc(-c5ccc(-c6cccc7ccccc67)cc5)cc4)nc(-c4cc5c(oc6c([2H])c([2H])c([2H])c([2H])c65)c([2H])c4[2H])n3)c2C#N)c([2H])c1[2H]]

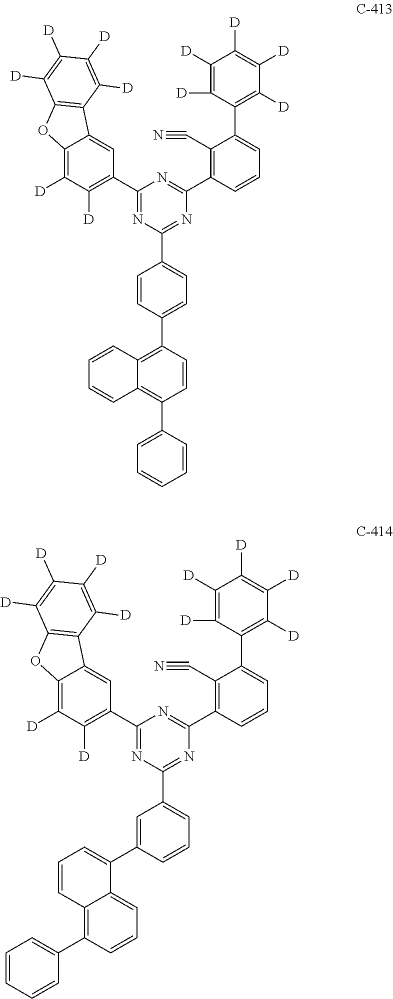 [SMILES: [2H]c1c([2H])c([2H])c(-c2cccc(-c3nc(-c4ccc(-c5ccc(-c6ccccc6)c6ccccc56)cc4)nc(-c4cc5c(oc6c([2H])c([2H])c([2H])c([2H])c65)c([2H])c4[2H])n3)c2C#N)c([2H])c1[2H] ; [2H]c1c([2H])c([2H])c(-c2cccc(-c3nc(-c4cccc(-c5cccc6c(-c7ccccc7)cccc56)c4)nc(-c4cc5c(oc6c([2H])c([2H])c([2H])c([2H])c65)c([2H])c4[2H])n3)c2C#N)c([2H])c1[2H]]

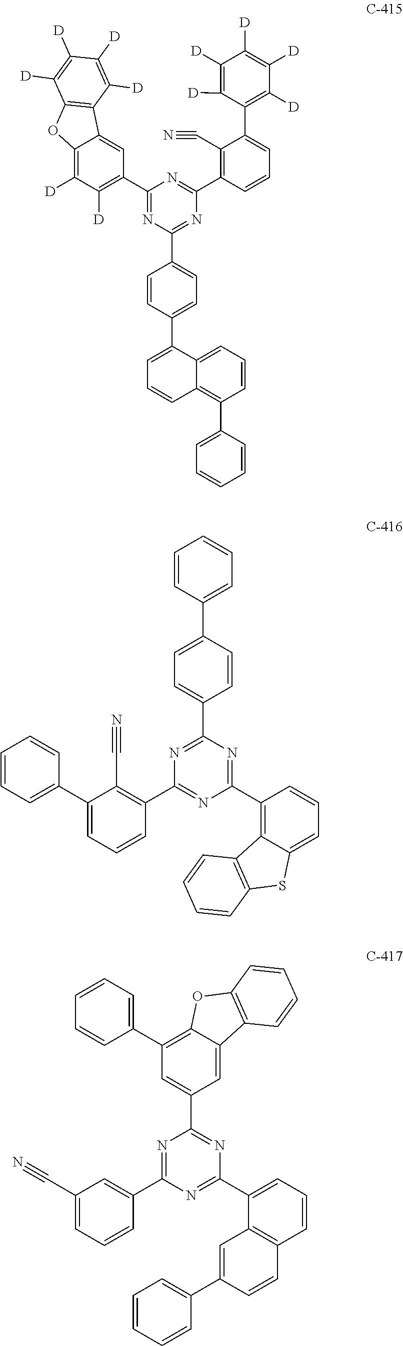 [SMILES: [2H]c1c([2H])c([2H])c(-c2cccc(-c3nc(-c4ccc(-c5cccc6c(-c7ccccc7)cccc56)cc4)nc(-c4cc5c(oc6c([2H])c([2H])c([2H])c([2H])c65)c([2H])c4[2H])n3)c2C#N)c([2H])c1[2H] ; N#Cc1c(-c2ccccc2)cccc1-c1nc(-c2ccc(-c3ccccc3)cc2)nc(-c2cccc3sc4ccccc4c23)n1 ; N#Cc1cccc(-c2nc(-c3cc(-c4ccccc4)c4oc5ccccc5c4c3)nc(-c3cccc4ccc(-c5ccccc5)cc34)n2)c1]

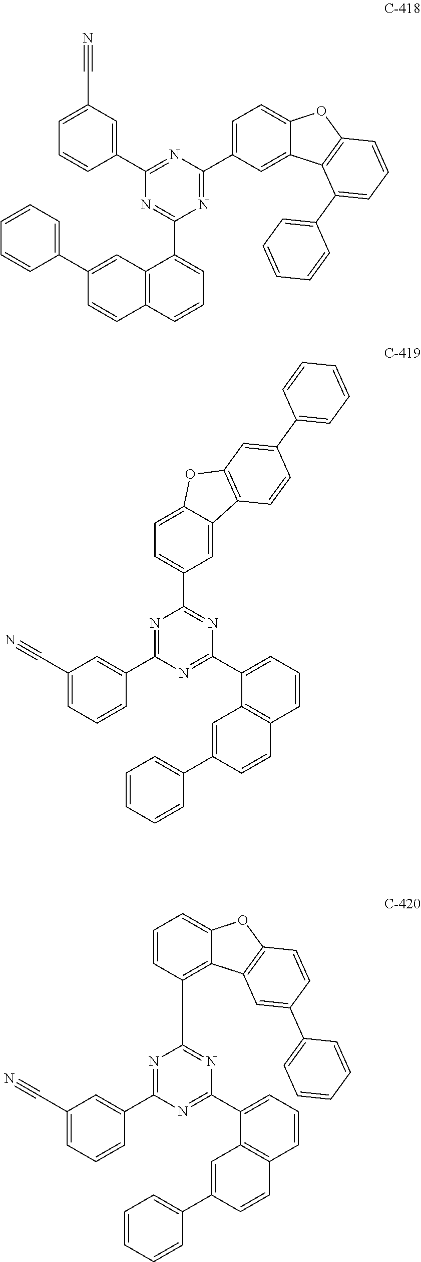 [SMILES: N#Cc1cccc(-c2nc(-c3ccc4oc5cccc(-c6ccccc6)c5c4c3)nc(-c3cccc4ccc(-c5ccccc5)cc34)n2)c1 ; N#Cc1cccc(-c2nc(-c3ccc4oc5cc(-c6ccccc6)ccc5c4c3)nc(-c3cccc4ccc(-c5ccccc5)cc34)n2)c1 ; N#Cc1cccc(-c2nc(-c3cccc4ccc(-c5ccccc5)cc34)nc(-c3cccc4oc5ccc(-c6ccccc6)cc5c34)n2)c1]

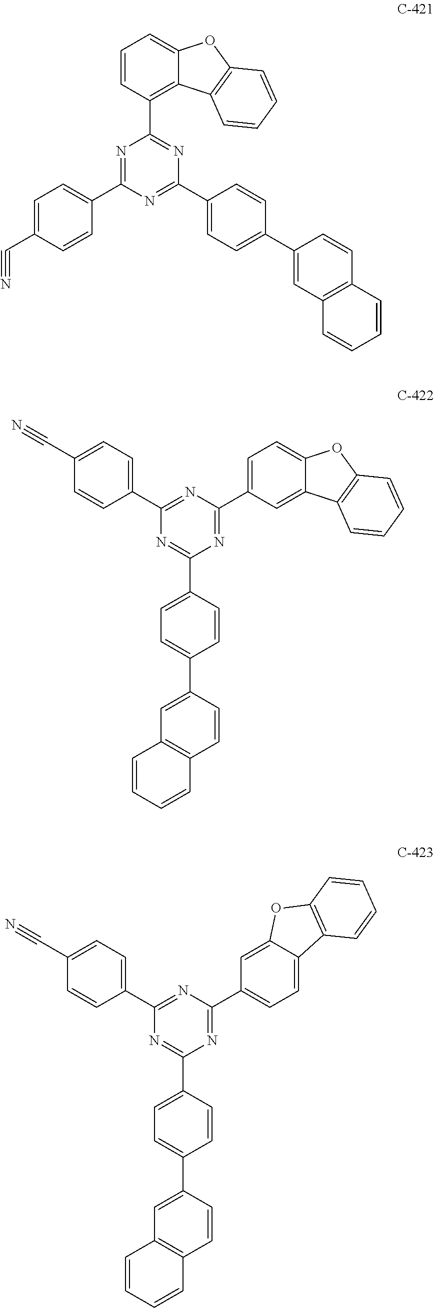 [SMILES: N#Cc1ccc(-c2nc(-c3ccc(-c4ccc5ccccc5c4)cc3)nc(-c3cccc4oc5ccccc5c34)n2)cc1 ; N#Cc1ccc(-c2nc(-c3ccc(-c4ccc5ccccc5c4)cc3)nc(-c3ccc4oc5ccccc5c4c3)n2)cc1 ; N#Cc1ccc(-c2nc(-c3ccc(-c4ccc5ccccc5c4)cc3)nc(-c3ccc4c(c3)oc3ccccc34)n2)cc1]

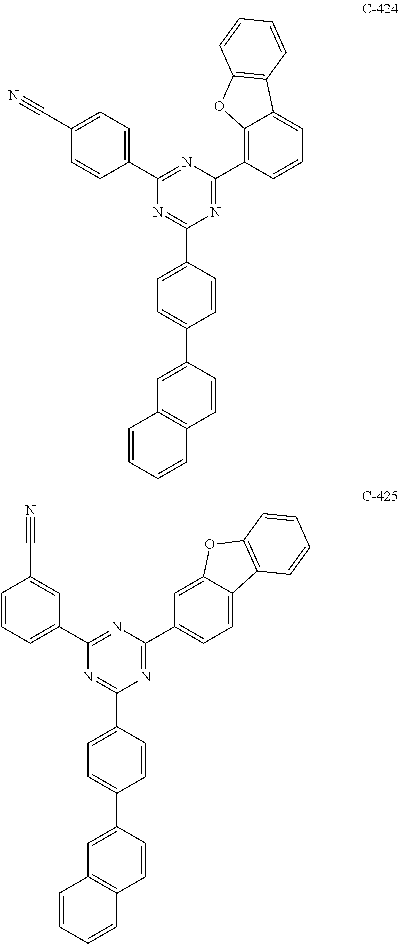 [SMILES: N#Cc1ccc(-c2nc(-c3ccc(-c4ccc5ccccc5c4)cc3)nc(-c3cccc4c3oc3ccccc34)n2)cc1 ; N#Cc1cccc(-c2nc(-c3ccc(-c4ccc5ccccc5c4)cc3)nc(-c3ccc4c(c3)oc3ccccc34)n2)c1]

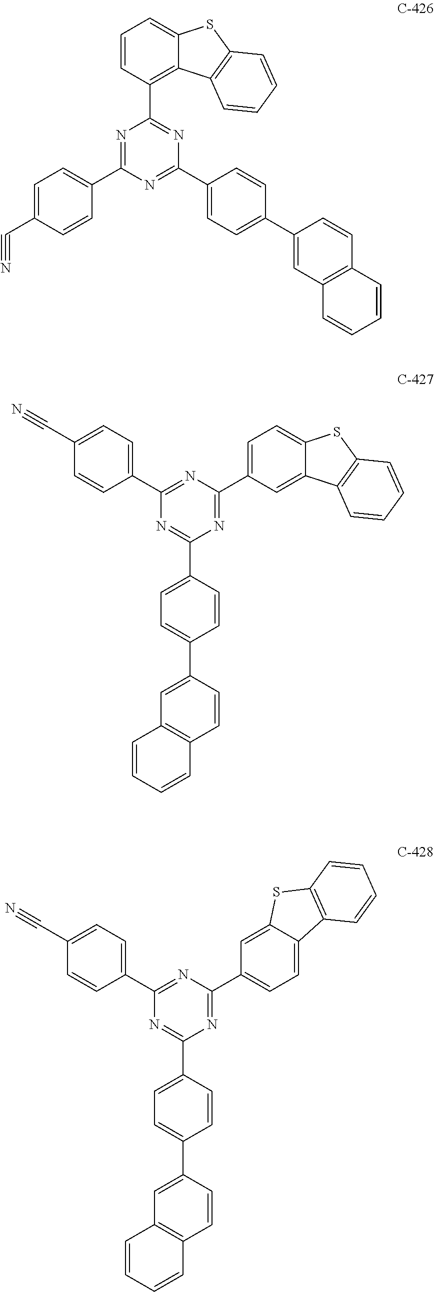 [SMILES: N#Cc1ccc(-c2nc(-c3ccc(-c4ccc5ccccc5c4)cc3)nc(-c3cccc4sc5ccccc5c34)n2)cc1 ; N#Cc1ccc(-c2nc(-c3ccc(-c4ccc5ccccc5c4)cc3)nc(-c3ccc4sc5ccccc5c4c3)n2)cc1 ; N#Cc1ccc(-c2nc(-c3ccc(-c4ccc5ccccc5c4)cc3)nc(-c3ccc4c(c3)sc3ccccc34)n2)cc1]

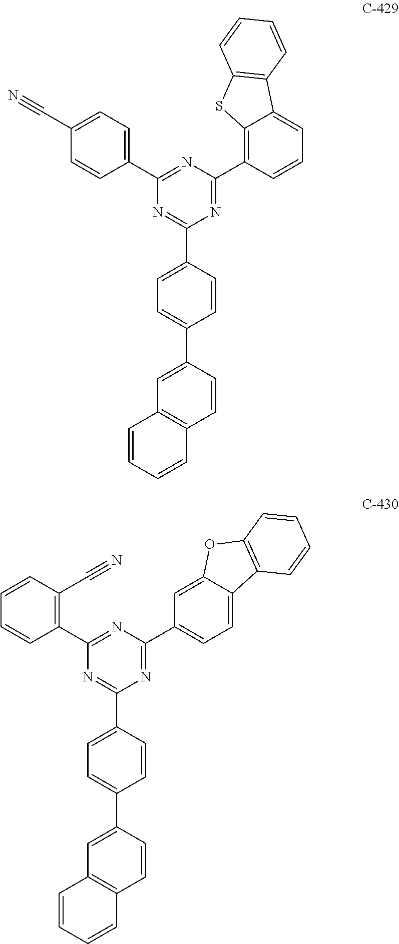 [SMILES: N#Cc1ccc(-c2nc(-c3ccc(-c4ccc5ccccc5c4)cc3)nc(-c3cccc4c3sc3ccccc34)n2)cc1 ; N#Cc1ccccc1-c1nc(-c2ccc(-c3ccc4ccccc4c3)cc2)nc(-c2ccc3c(c2)oc2ccccc23)n1]

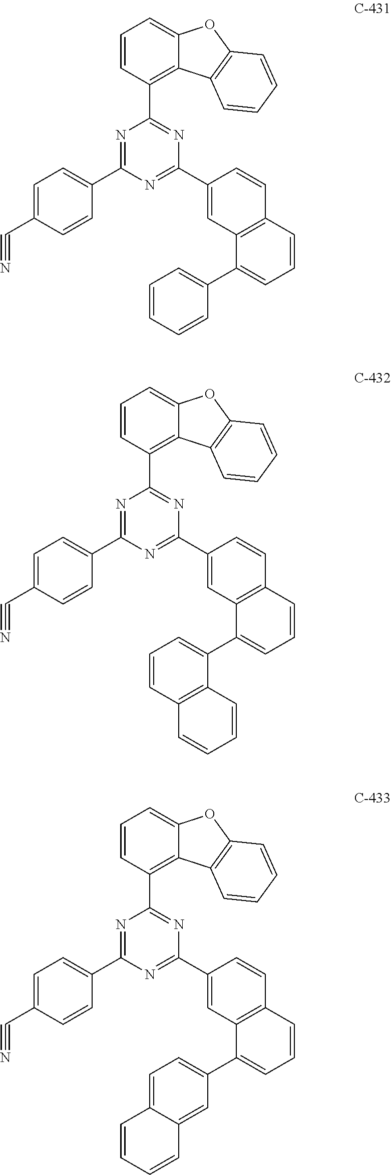 [SMILES: N#Cc1ccc(-c2nc(-c3ccc4cccc(-c5ccccc5)c4c3)nc(-c3cccc4oc5ccccc5c34)n2)cc1 ; N#Cc1ccc(-c2nc(-c3ccc4cccc(-c5cccc6ccccc56)c4c3)nc(-c3cccc4oc5ccccc5c34)n2)cc1 ; N#Cc1ccc(-c2nc(-c3ccc4cccc(-c5ccc6ccccc6c5)c4c3)nc(-c3cccc4oc5ccccc5c34)n2)cc1]

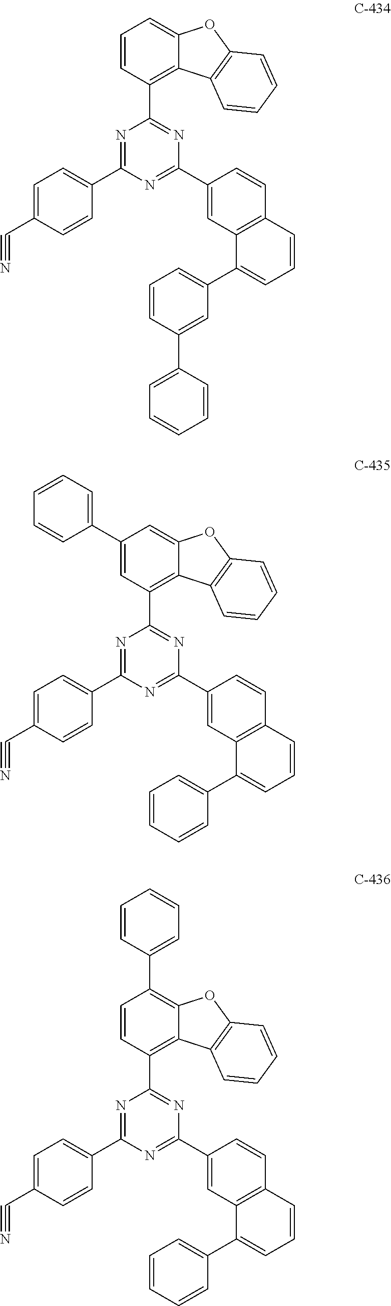 [SMILES: N#Cc1ccc(-c2nc(-c3ccc4cccc(-c5cccc(-c6ccccc6)c5)c4c3)nc(-c3cccc4oc5ccccc5c34)n2)cc1 ; N#Cc1ccc(-c2nc(-c3ccc4cccc(-c5ccccc5)c4c3)nc(-c3cc(-c4ccccc4)cc4oc5ccccc5c34)n2)cc1 ; N#Cc1ccc(-c2nc(-c3ccc4cccc(-c5ccccc5)c4c3)nc(-c3ccc(-c4ccccc4)c4oc5ccccc5c34)n2)cc1]

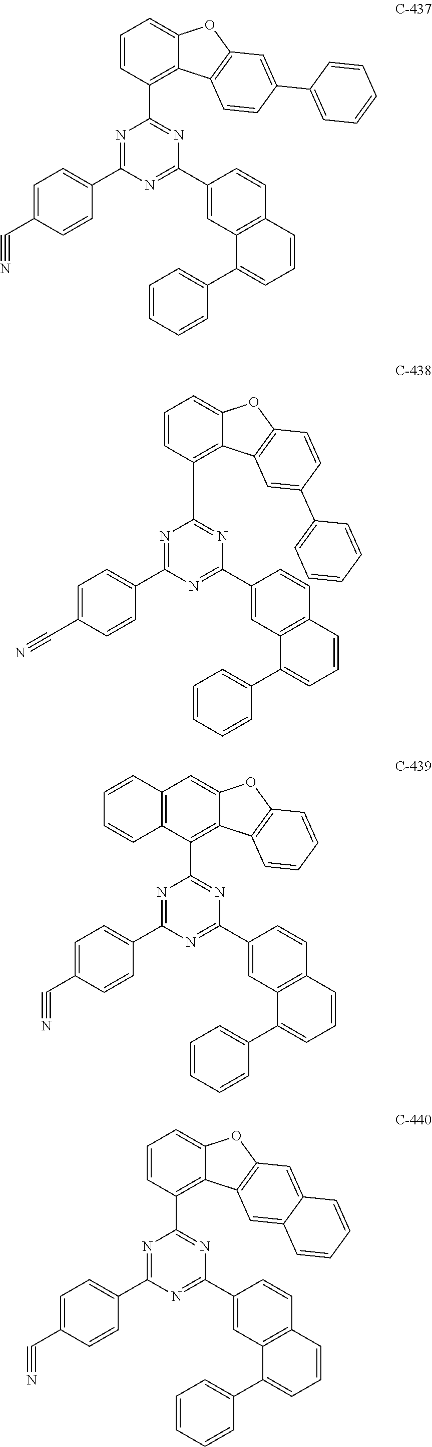 [SMILES: N#Cc1ccc(-c2nc(-c3ccc4cccc(-c5ccccc5)c4c3)nc(-c3cccc4oc5cc(-c6ccccc6)ccc5c34)n2)cc1 ; N#Cc1ccc(-c2nc(-c3ccc4cccc(-c5ccccc5)c4c3)nc(-c3cccc4oc5ccc(-c6ccccc6)cc5c34)n2)cc1 ; N#Cc1ccc(-c2nc(-c3ccc4cccc(-c5ccccc5)c4c3)nc(-c3c4ccccc4cc4oc5ccccc5c34)n2)cc1 ; N#Cc1ccc(-c2nc(-c3ccc4cccc(-c5ccccc5)c4c3)nc(-c3cccc4oc5cc6ccccc6cc5c34)n2)cc1]

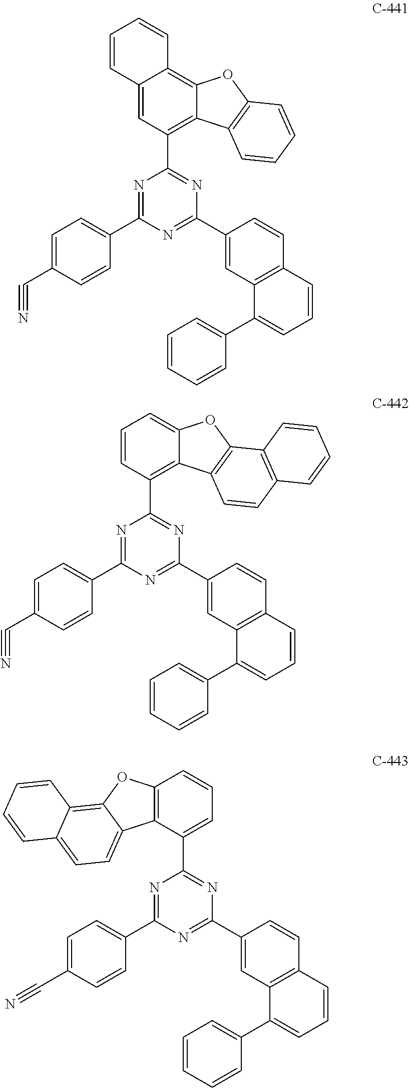

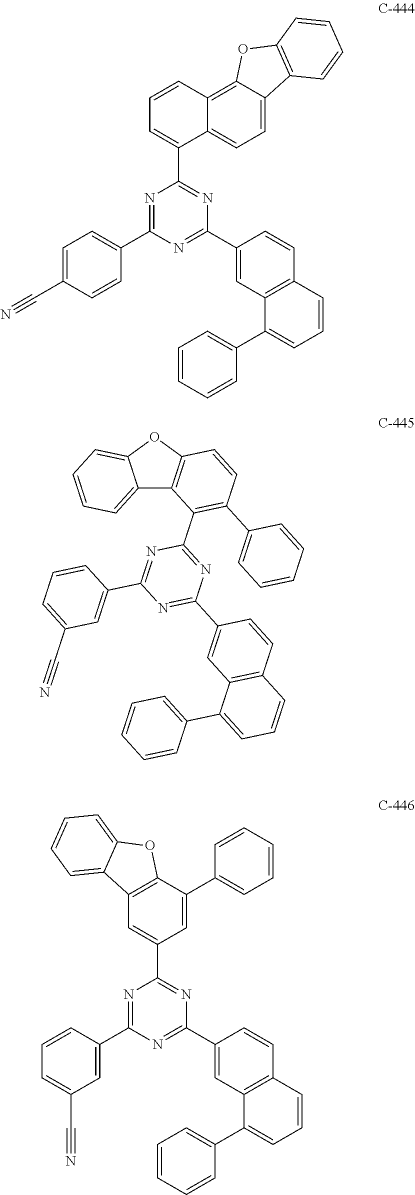 [SMILES: N#Cc1ccc(-c2nc(-c3ccc4cccc(-c5ccccc5)c4c3)nc(-c3cccc4c3ccc3c5ccccc5oc43)n2)cc1 ; N#Cc1cccc(-c2nc(-c3ccc4cccc(-c5ccccc5)c4c3)nc(-c3c(-c4ccccc4)ccc4oc5ccccc5c34)n2)c1 ; N#Cc1cccc(-c2nc(-c3ccc4cccc(-c5ccccc5)c4c3)nc(-c3cc(-c4ccccc4)c4oc5ccccc5c4c3)n2)c1]

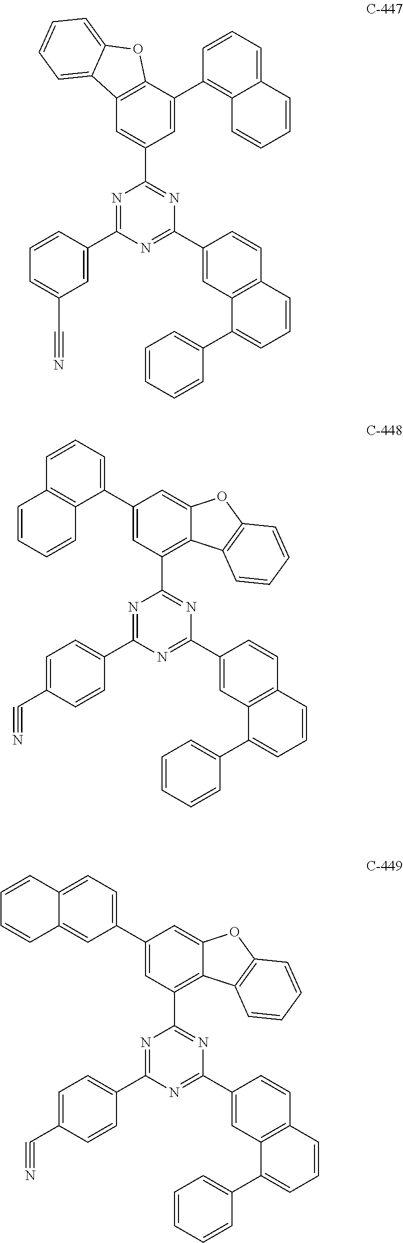 [SMILES: N#Cc1cccc(-c2nc(-c3ccc4cccc(-c5ccccc5)c4c3)nc(-c3cc(-c4cccc5ccccc45)c4oc5ccccc5c4c3)n2)c1 ; N#Cc1ccc(-c2nc(-c3ccc4cccc(-c5ccccc5)c4c3)nc(-c3cc(-c4cccc5ccccc45)cc4oc5ccccc5c34)n2)cc1 ; N#Cc1ccc(-c2nc(-c3ccc4cccc(-c5ccccc5)c4c3)nc(-c3cc(-c4ccc5ccccc5c4)cc4oc5ccccc5c34)n2)cc1]

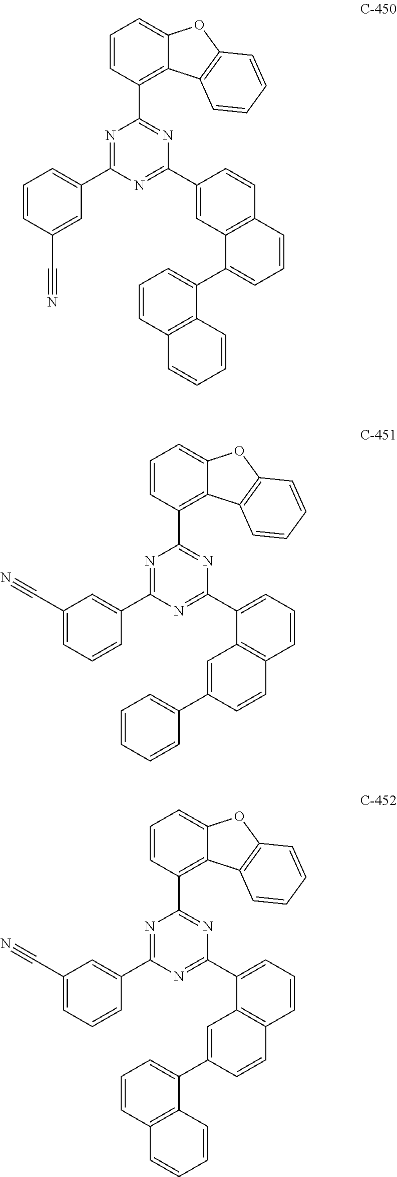 [SMILES: N#Cc1cccc(-c2nc(-c3ccc4cccc(-c5cccc6ccccc56)c4c3)nc(-c3cccc4oc5ccccc5c34)n2)c1 ; N#Cc1cccc(-c2nc(-c3cccc4ccc(-c5ccccc5)cc34)nc(-c3cccc4oc5ccccc5c34)n2)c1 ; N#Cc1cccc(-c2nc(-c3cccc4ccc(-c5cccc6ccccc56)cc34)nc(-c3cccc4oc5ccccc5c34)n2)c1]

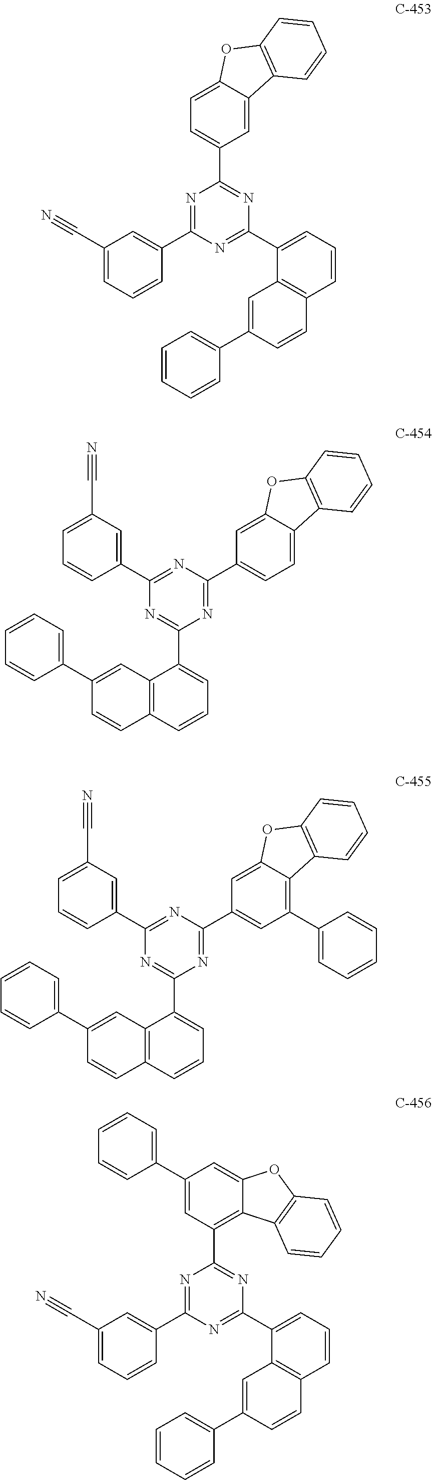

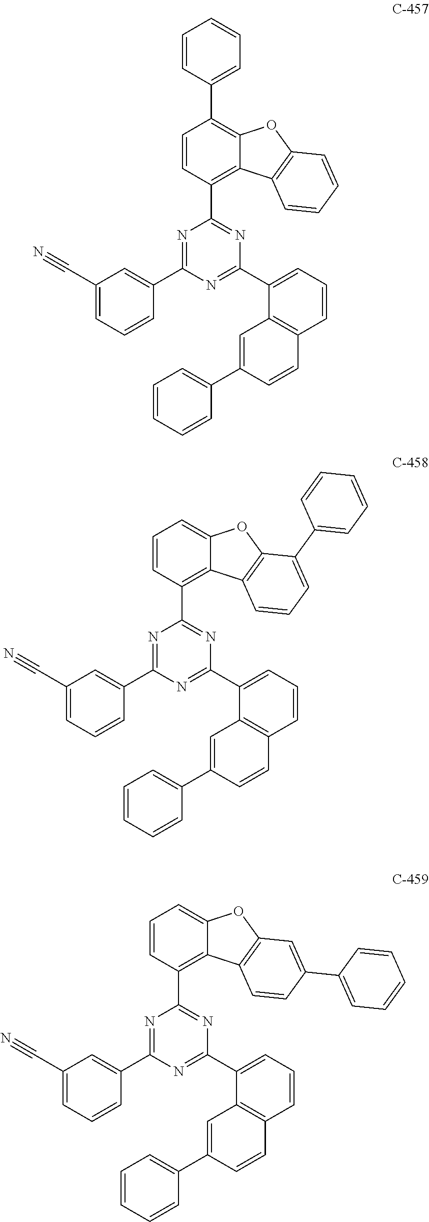 [SMILES: N#Cc1cccc(-c2nc(-c3cccc4ccc(-c5ccccc5)cc34)nc(-c3ccc(-c4ccccc4)c4oc5ccccc5c34)n2)c1 ; N#Cc1cccc(-c2nc(-c3cccc4ccc(-c5ccccc5)cc34)nc(-c3cccc4oc5c(-c6ccccc6)cccc5c34)n2)c1 ; N#Cc1cccc(-c2nc(-c3cccc4ccc(-c5ccccc5)cc34)nc(-c3cccc4oc5cc(-c6ccccc6)ccc5c34)n2)c1]

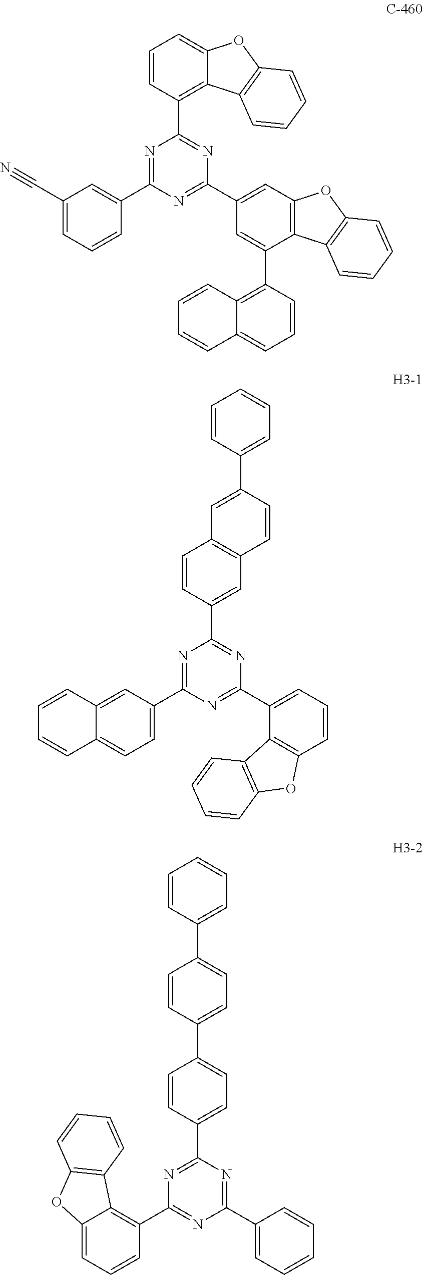

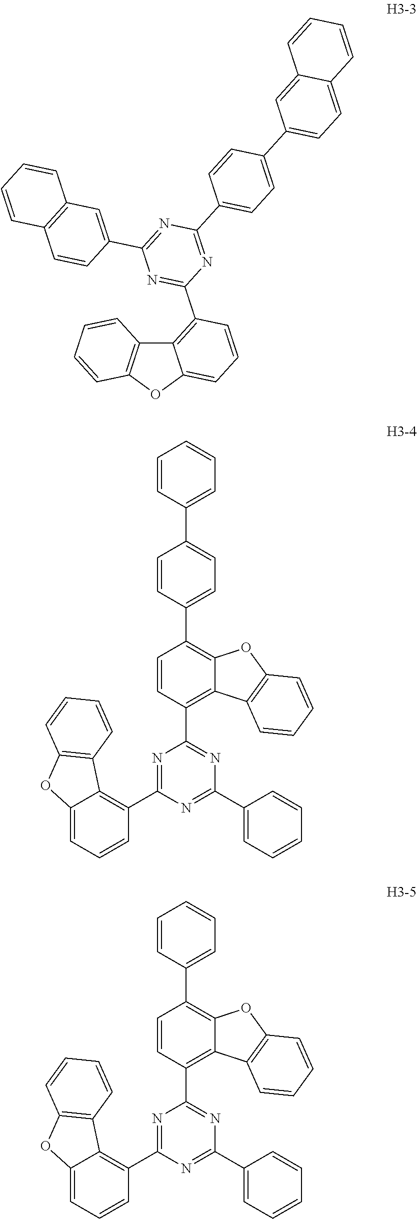 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3ccc(-c4nc(-c5ccccc5)nc(-c5cccc6oc7ccccc7c56)n4)c4c3oc3ccccc34)cc2)cc1 ; c1ccc(-c2nc(-c3cccc4oc5ccccc5c34)nc(-c3ccc(-c4ccccc4)c4oc5ccccc5c34)n2)cc1]

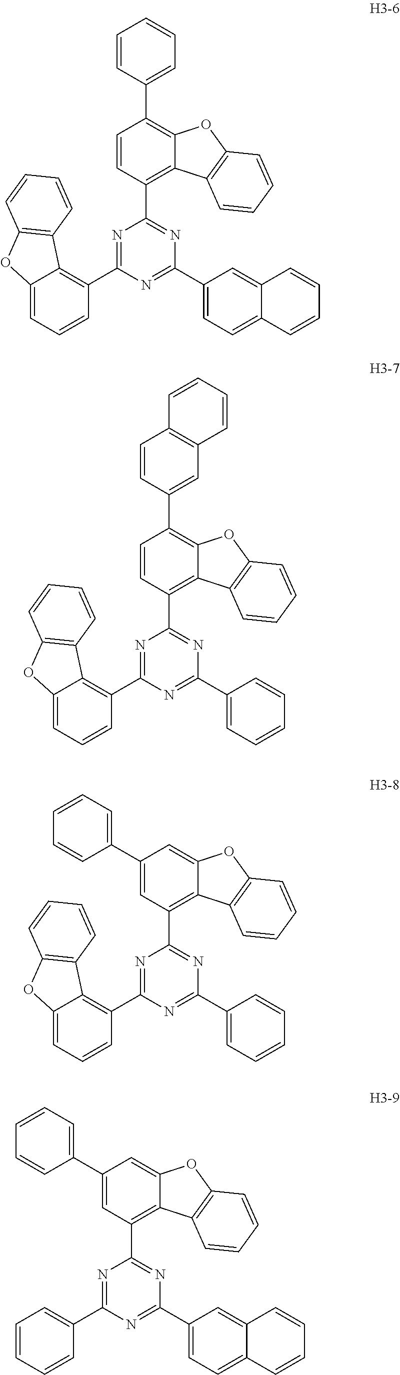 [SMILES: c1ccc(-c2ccc(-c3nc(-c4ccc5ccccc5c4)nc(-c4cccc5oc6ccccc6c45)n3)c3c2oc2ccccc23)cc1 ; c1ccc(-c2nc(-c3cccc4oc5ccccc5c34)nc(-c3ccc(-c4ccc5ccccc5c4)c4oc5ccccc5c34)n2)cc1 ; c1ccc(-c2cc(-c3nc(-c4ccccc4)nc(-c4cccc5oc6ccccc6c45)n3)c3c(c2)oc2ccccc23)cc1 ; c1ccc(-c2cc(-c3nc(-c4ccccc4)nc(-c4ccc5ccccc5c4)n3)c3c(c2)oc2ccccc23)cc1]

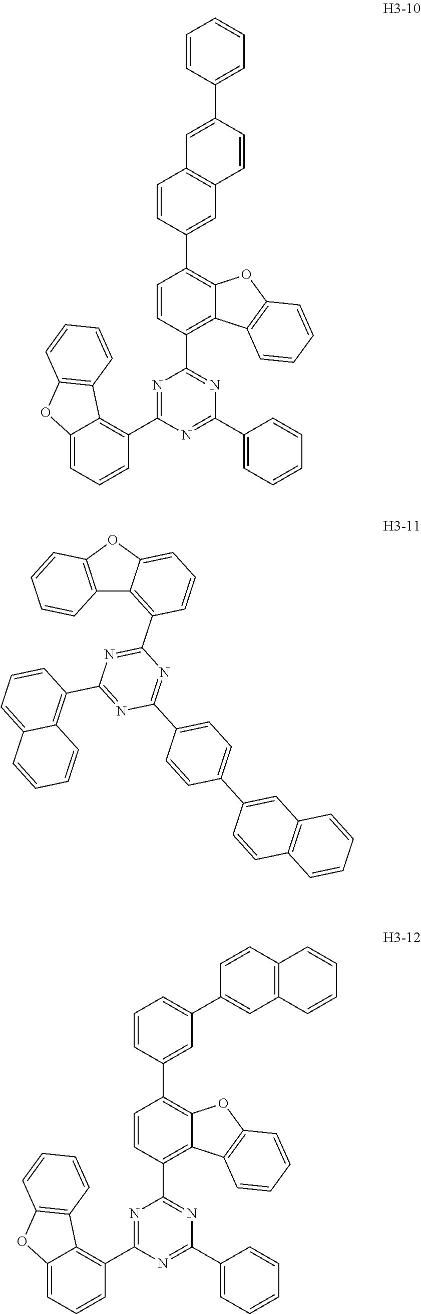 [SMILES: c1ccc(-c2ccc3cc(-c4ccc(-c5nc(-c6ccccc6)nc(-c6cccc7oc8ccccc8c67)n5)c5c4oc4ccccc45)ccc3c2)cc1 ; c1ccc2cc(-c3ccc(-c4nc(-c5cccc6ccccc56)nc(-c5cccc6oc7ccccc7c56)n4)cc3)ccc2c1 ; c1ccc(-c2nc(-c3cccc4oc5ccccc5c34)nc(-c3ccc(-c4cccc(-c5ccc6ccccc6c5)c4)c4oc5ccccc5c34)n2)cc1]

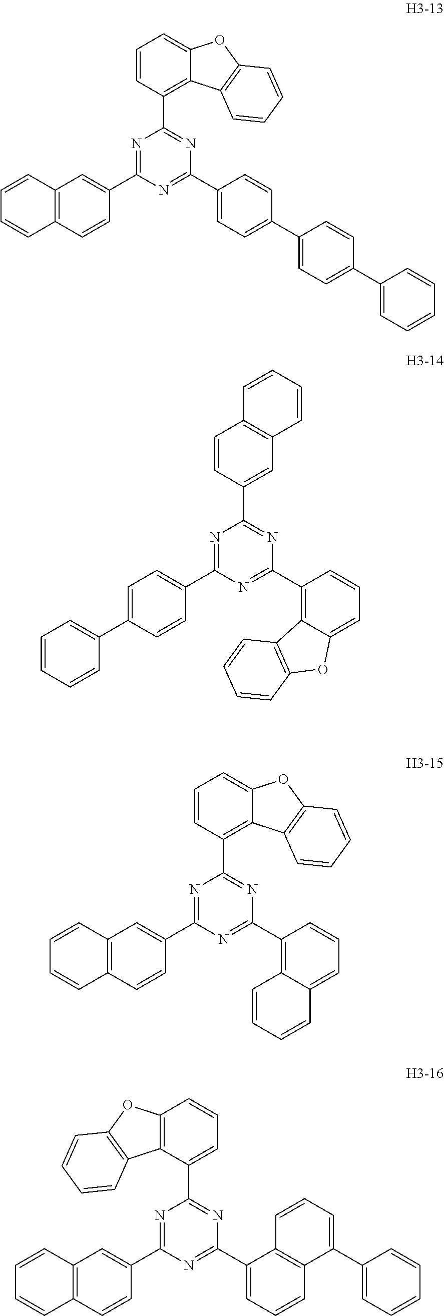 [SMILES: c1ccc(-c2ccc(-c3ccc(-c4nc(-c5ccc6ccccc6c5)nc(-c5cccc6oc7ccccc7c56)n4)cc3)cc2)cc1 ; c1ccc(-c2ccc(-c3nc(-c4ccc5ccccc5c4)nc(-c4cccc5oc6ccccc6c45)n3)cc2)cc1 ; c1ccc2cc(-c3nc(-c4cccc5ccccc45)nc(-c4cccc5oc6ccccc6c45)n3)ccc2c1 ; c1ccc(-c2cccc3c(-c4nc(-c5ccc6ccccc6c5)nc(-c5cccc6oc7ccccc7c56)n4)cccc23)cc1]

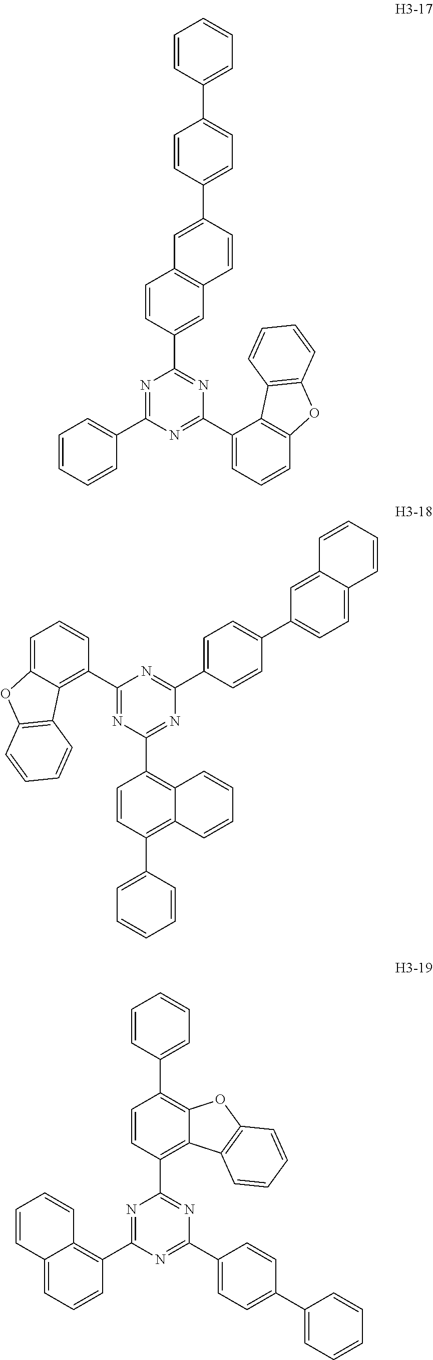 [SMILES: c1ccc(-c2ccc(-c3ccc4cc(-c5nc(-c6ccccc6)nc(-c6cccc7oc8ccccc8c67)n5)ccc4c3)cc2)cc1 ; c1ccc(-c2ccc(-c3nc(-c4ccc(-c5ccc6ccccc6c5)cc4)nc(-c4cccc5oc6ccccc6c45)n3)c3ccccc23)cc1 ; c1ccc(-c2ccc(-c3nc(-c4cccc5ccccc45)nc(-c4ccc(-c5ccccc5)c5oc6ccccc6c45)n3)cc2)cc1]

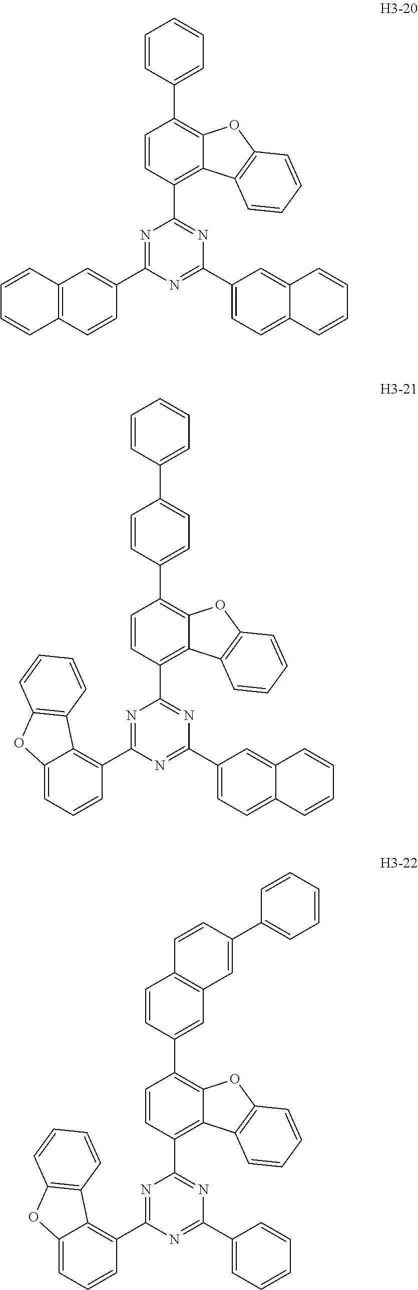 [SMILES: c1ccc(-c2ccc(-c3nc(-c4ccc5ccccc5c4)nc(-c4ccc5ccccc5c4)n3)c3c2oc2ccccc23)cc1 ; c1ccc(-c2ccc(-c3ccc(-c4nc(-c5ccc6ccccc6c5)nc(-c5cccc6oc7ccccc7c56)n4)c4c3oc3ccccc34)cc2)cc1 ; c1ccc(-c2ccc3ccc(-c4ccc(-c5nc(-c6ccccc6)nc(-c6cccc7oc8ccccc8c67)n5)c5c4oc4ccccc45)cc3c2)cc1]

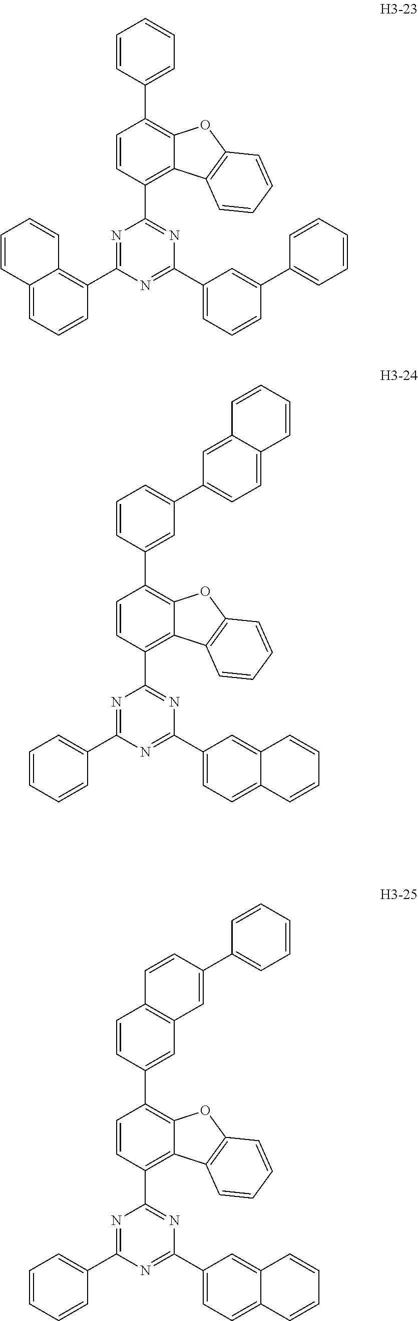 [SMILES: c1ccc(-c2cccc(-c3nc(-c4cccc5ccccc45)nc(-c4ccc(-c5ccccc5)c5oc6ccccc6c45)n3)c2)cc1 ; c1ccc(-c2nc(-c3ccc4ccccc4c3)nc(-c3ccc(-c4cccc(-c5ccc6ccccc6c5)c4)c4oc5ccccc5c34)n2)cc1 ; c1ccc(-c2ccc3ccc(-c4ccc(-c5nc(-c6ccccc6)nc(-c6ccc7ccccc7c6)n5)c5c4oc4ccccc45)cc3c2)cc1]

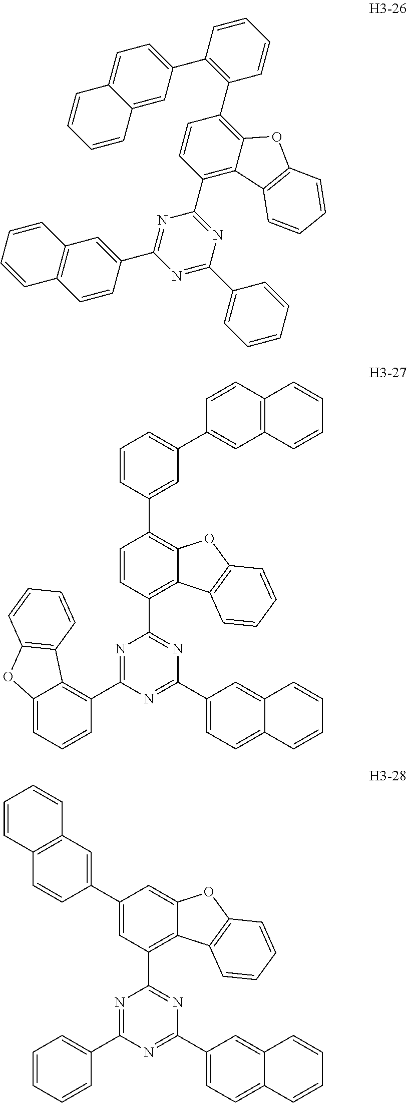

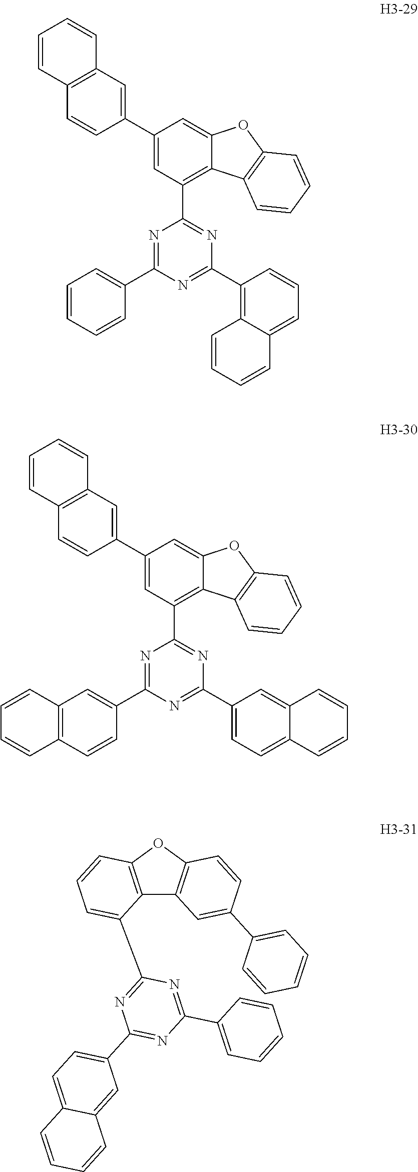 [SMILES: c1ccc(-c2nc(-c3cccc4ccccc34)nc(-c3cc(-c4ccc5ccccc5c4)cc4oc5ccccc5c34)n2)cc1 ; c1ccc2cc(-c3cc(-c4nc(-c5ccc6ccccc6c5)nc(-c5ccc6ccccc6c5)n4)c4c(c3)oc3ccccc34)ccc2c1 ; c1ccc(-c2ccc3oc4cccc(-c5nc(-c6ccccc6)nc(-c6ccc7ccccc7c6)n5)c4c3c2)cc1]

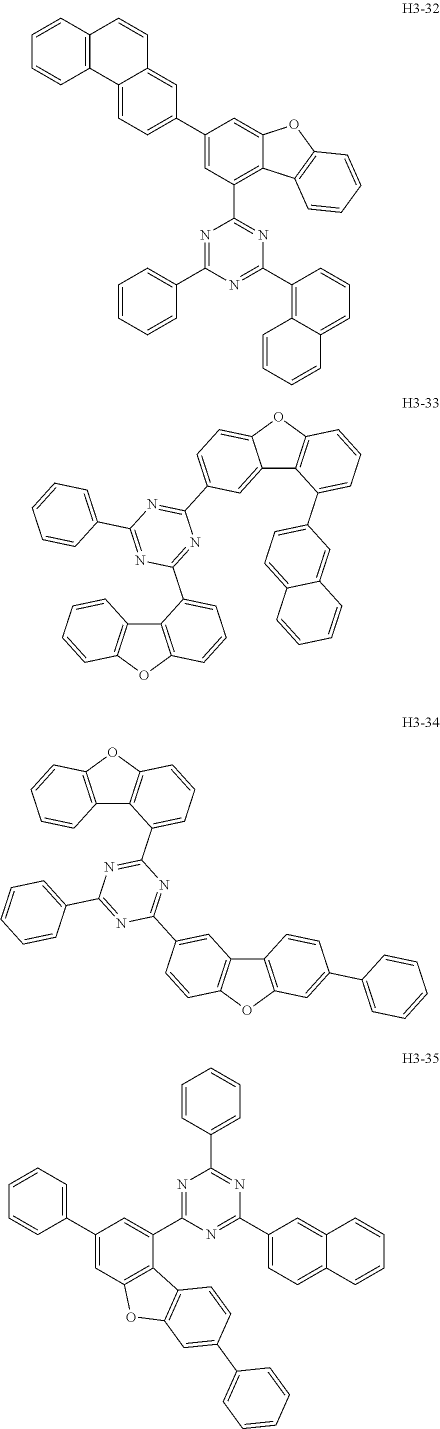

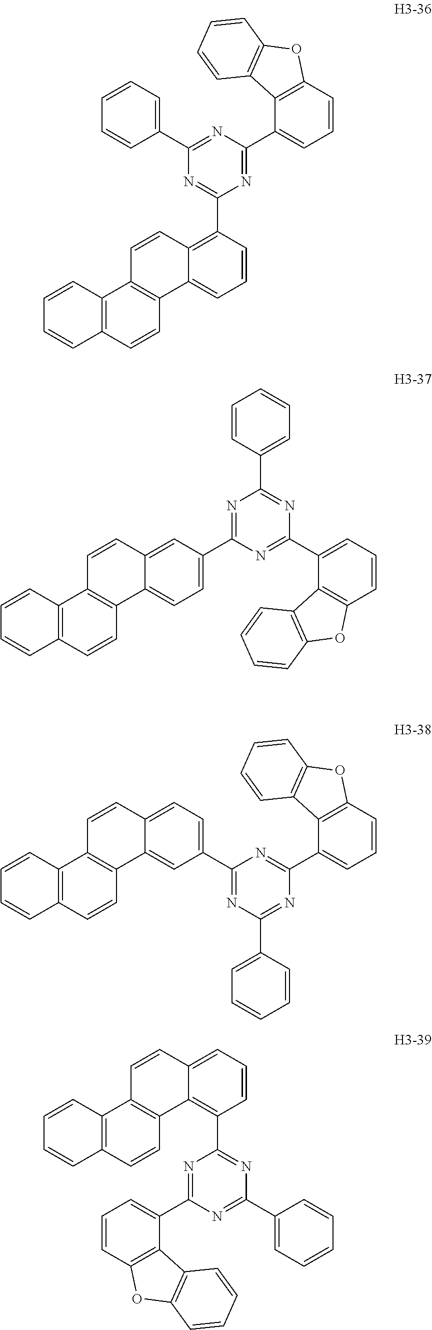 [SMILES: c1ccc(-c2nc(-c3cccc4c3ccc3c5ccccc5ccc43)nc(-c3cccc4oc5ccccc5c34)n2)cc1 ; c1ccc(-c2nc(-c3ccc4c(ccc5c6ccccc6ccc45)c3)nc(-c3cccc4oc5ccccc5c34)n2)cc1 ; c1ccc(-c2nc(-c3ccc4ccc5c6ccccc6ccc5c4c3)nc(-c3cccc4oc5ccccc5c34)n2)cc1 ; c1ccc(-c2nc(-c3cccc4ccc5c6ccccc6ccc5c34)nc(-c3cccc4oc5ccccc5c34)n2)cc1]

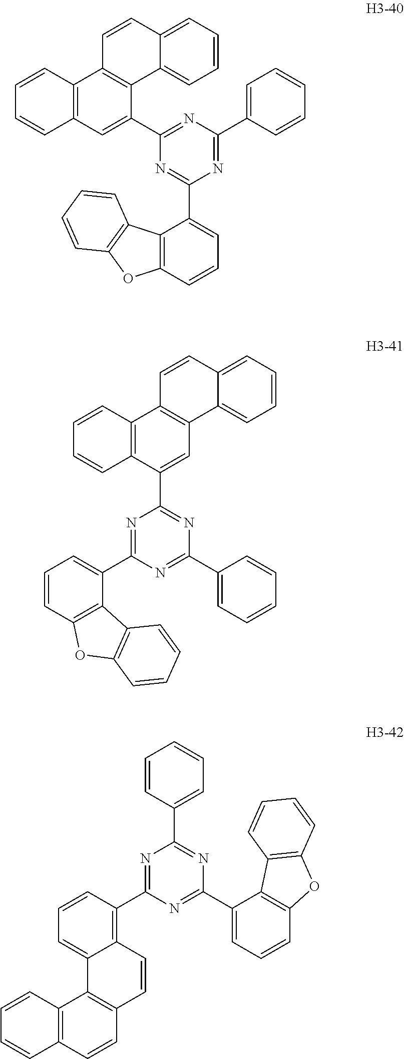 [SMILES: c1ccc(-c2nc(-c3cccc4oc5ccccc5c34)nc(-c3cc4ccccc4c4ccc5ccccc5c34)n2)cc1 ; c1ccc(-c2nc(-c3cc4c5ccccc5ccc4c4ccccc34)nc(-c3cccc4oc5ccccc5c34)n2)cc1 ; c1ccc(-c2nc(-c3cccc4c3ccc3ccc5ccccc5c34)nc(-c3cccc4oc5ccccc5c34)n2)cc1]

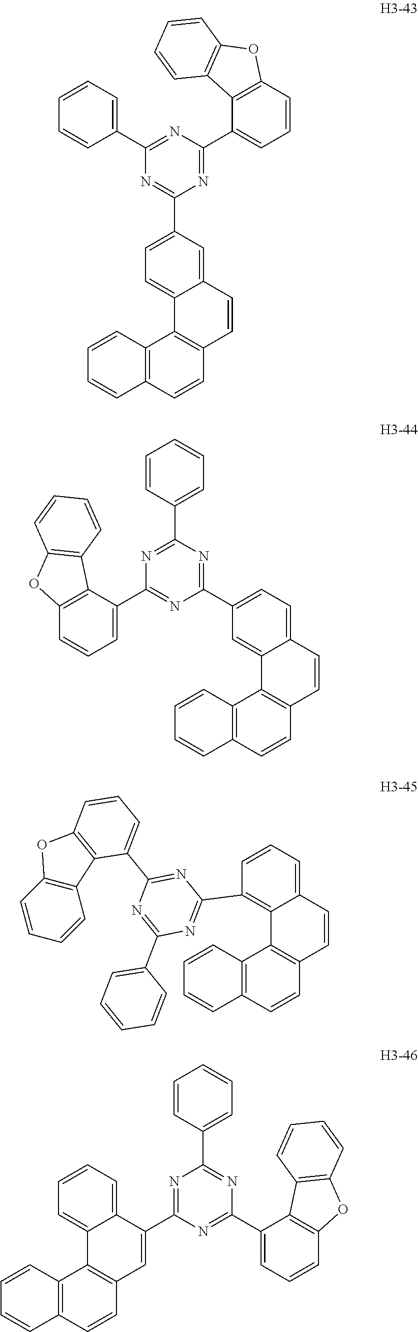

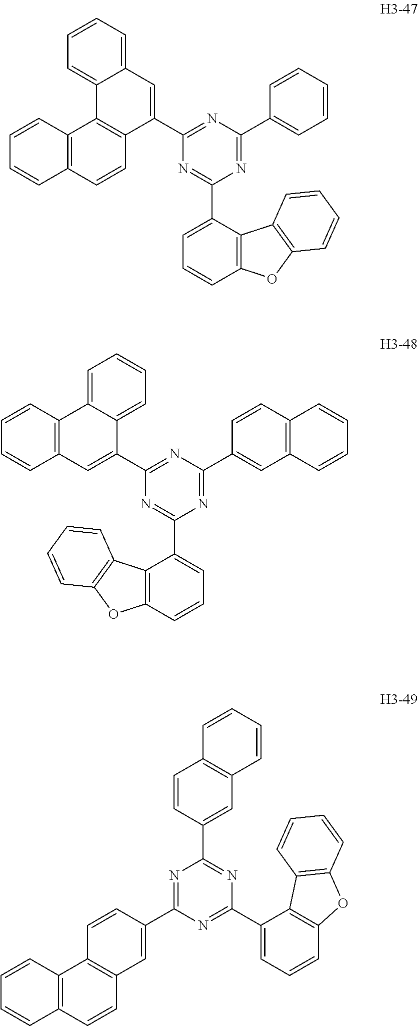 [SMILES: c1ccc(-c2nc(-c3cc4ccccc4c4c3ccc3ccccc34)nc(-c3cccc4oc5ccccc5c34)n2)cc1 ; c1ccc2cc(-c3nc(-c4cc5ccccc5c5ccccc45)nc(-c4cccc5oc6ccccc6c45)n3)ccc2c1 ; c1ccc2cc(-c3nc(-c4ccc5c(ccc6ccccc65)c4)nc(-c4cccc5oc6ccccc6c45)n3)ccc2c1]

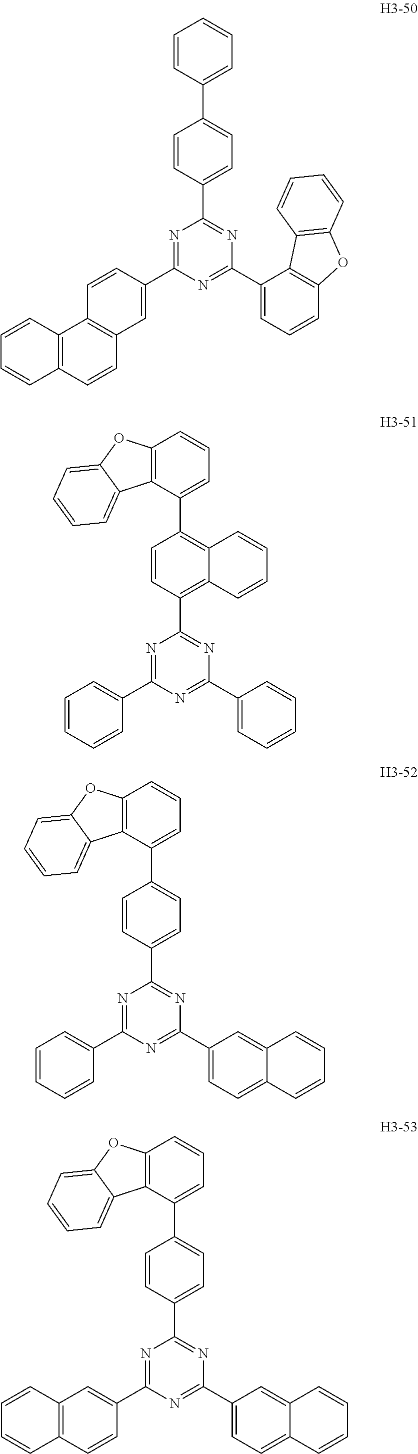

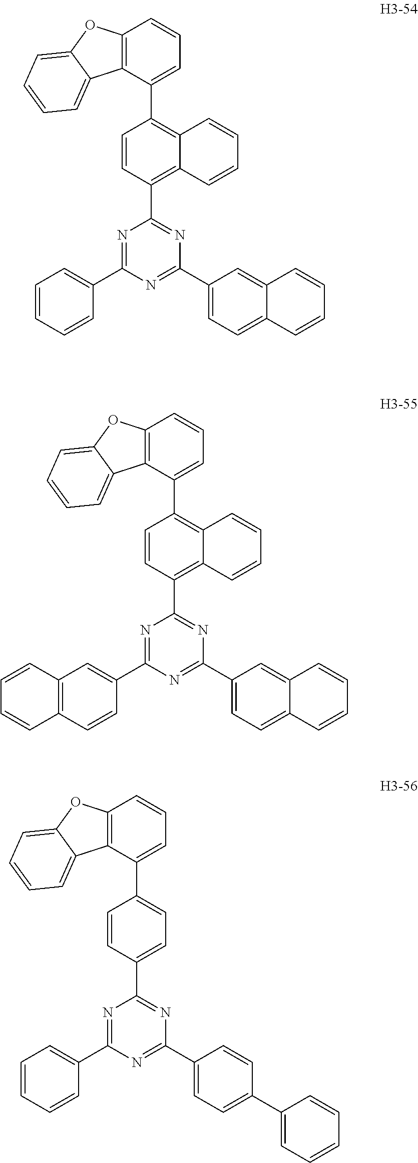 [SMILES: c1ccc(-c2nc(-c3ccc4ccccc4c3)nc(-c3ccc(-c4cccc5oc6ccccc6c45)c4ccccc34)n2)cc1 ; c1ccc2cc(-c3nc(-c4ccc5ccccc5c4)nc(-c4ccc(-c5cccc6oc7ccccc7c56)c5ccccc45)n3)ccc2c1 ; c1ccc(-c2ccc(-c3nc(-c4ccccc4)nc(-c4ccc(-c5cccc6oc7ccccc7c56)cc4)n3)cc2)cc1]

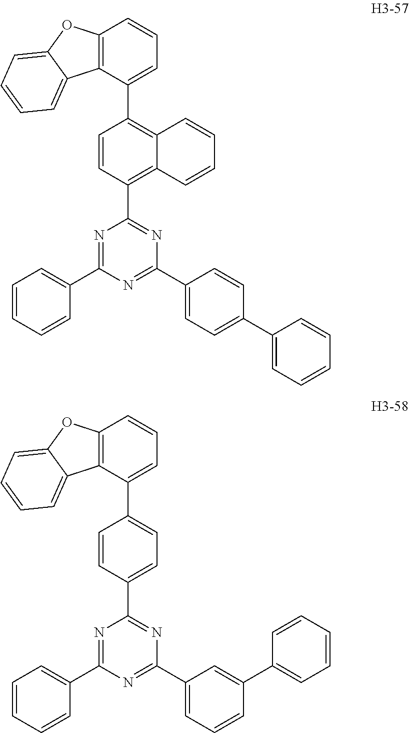 [SMILES: c1ccc(-c2ccc(-c3nc(-c4ccccc4)nc(-c4ccc(-c5cccc6oc7ccccc7c56)c5ccccc45)n3)cc2)cc1 ; c1ccc(-c2cccc(-c3nc(-c4ccccc4)nc(-c4ccc(-c5cccc6oc7ccccc7c56)cc4)n3)c2)cc1]

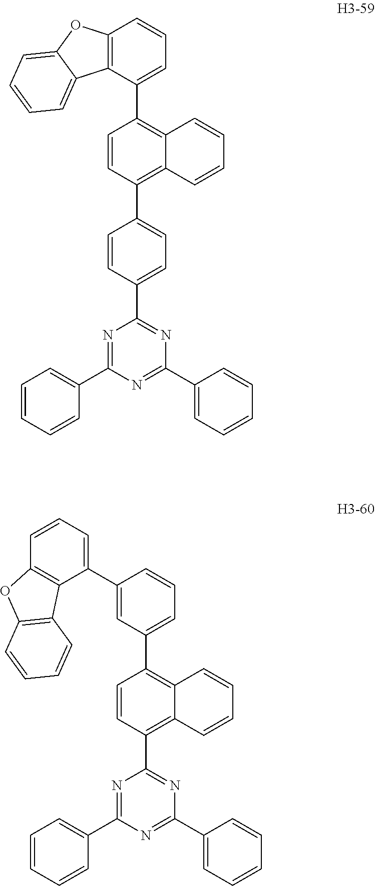 [SMILES: c1ccc(-c2nc(-c3ccccc3)nc(-c3ccc(-c4ccc(-c5cccc6oc7ccccc7c56)c5ccccc45)cc3)n2)cc1 ; c1ccc(-c2nc(-c3ccccc3)nc(-c3ccc(-c4cccc(-c5cccc6oc7ccccc7c56)c4)c4ccccc34)n2)cc1]

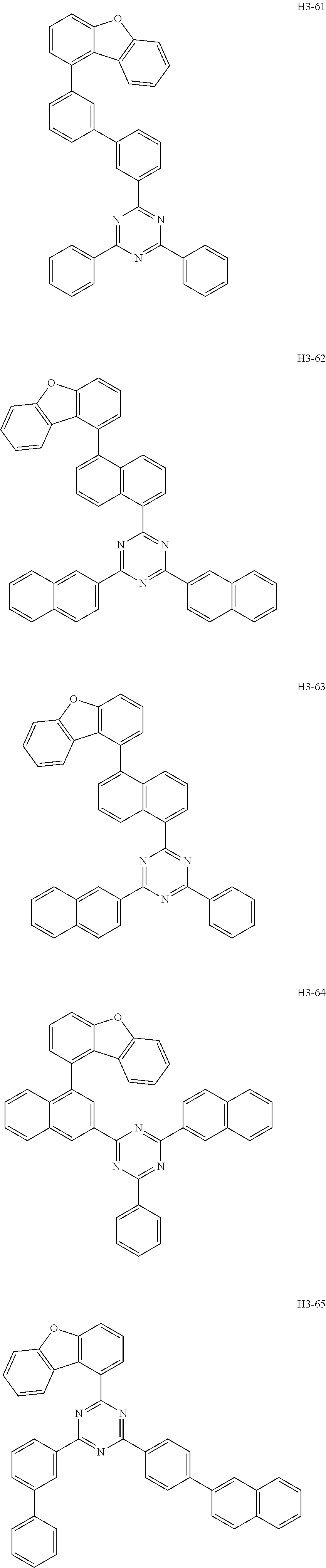 [SMILES: c1ccc(-c2nc(-c3ccccc3)nc(-c3cccc(-c4cccc(-c5cccc6oc7ccccc7c56)c4)c3)n2)cc1 ; c1ccc2cc(-c3nc(-c4ccc5ccccc5c4)nc(-c4cccc5c(-c6cccc7oc8ccccc8c67)cccc45)n3)ccc2c1 ; c1ccc(-c2nc(-c3ccc4ccccc4c3)nc(-c3cccc4c(-c5cccc6oc7ccccc7c56)cccc34)n2)cc1 ; c1ccc(-c2nc(-c3ccc4ccccc4c3)nc(-c3cc(-c4cccc5oc6ccccc6c45)c4ccccc4c3)n2)cc1 ; c1ccc(-c2cccc(-c3nc(-c4ccc(-c5ccc6ccccc6c5)cc4)nc(-c4cccc5oc6ccccc6c45)n3)c2)cc1]

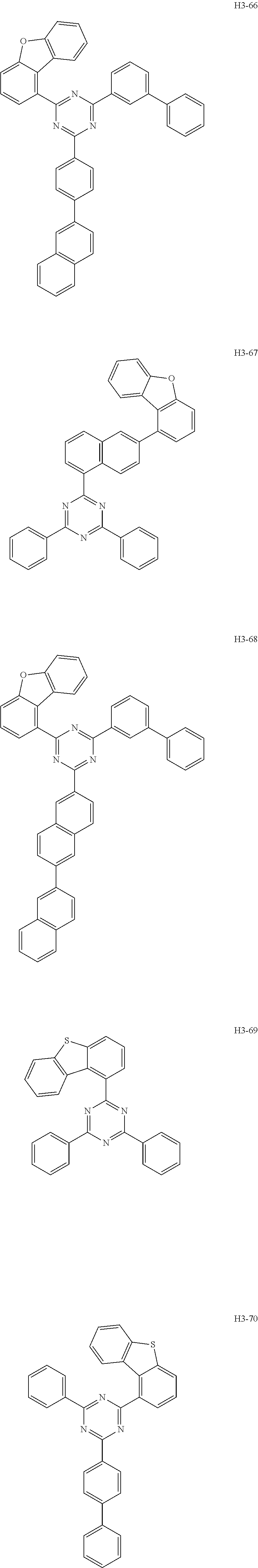 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2nc(-c3ccccc3)nc(-c3cccc4cc(-c5cccc6oc7ccccc7c56)ccc34)n2)cc1 ; c1ccc(-c2cccc(-c3nc(-c4ccc5cc(-c6ccc7ccccc7c6)ccc5c4)nc(-c4cccc5oc6ccccc6c45)n3)c2)cc1 ; c1ccc(-c2nc(-c3ccccc3)nc(-c3cccc4sc5ccccc5c34)n2)cc1 ; c1ccc(-c2ccc(-c3nc(-c4ccccc4)nc(-c4cccc5sc6ccccc6c45)n3)cc2)cc1]

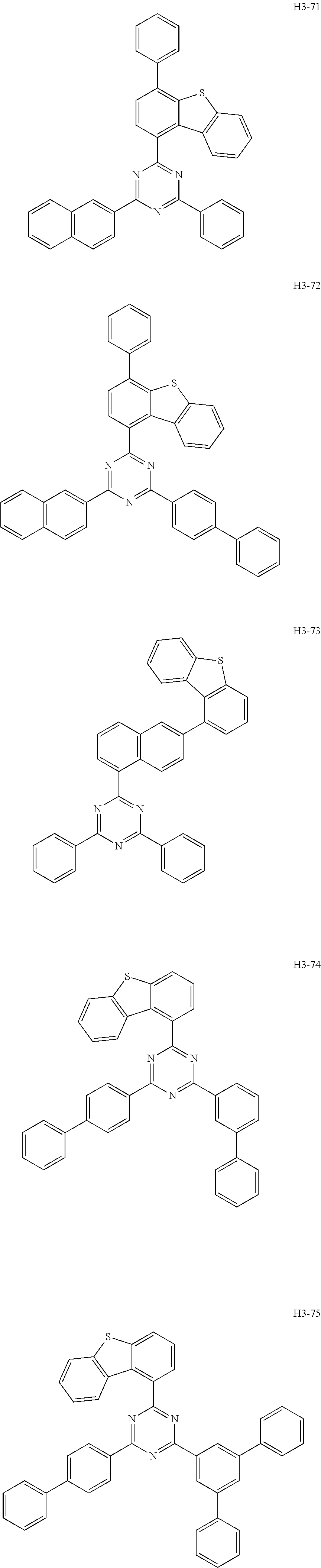 [SMILES: c1ccc(-c2nc(-c3ccc4ccccc4c3)nc(-c3ccc(-c4ccccc4)c4sc5ccccc5c34)n2)cc1 ; c1ccc(-c2ccc(-c3nc(-c4ccc5ccccc5c4)nc(-c4ccc(-c5ccccc5)c5sc6ccccc6c45)n3)cc2)cc1 ; c1ccc(-c2nc(-c3ccccc3)nc(-c3cccc4cc(-c5cccc6sc7ccccc7c56)ccc34)n2)cc1 ; c1ccc(-c2ccc(-c3nc(-c4cccc(-c5ccccc5)c4)nc(-c4cccc5sc6ccccc6c45)n3)cc2)cc1 ; c1ccc(-c2ccc(-c3nc(-c4cc(-c5ccccc5)cc(-c5ccccc5)c4)nc(-c4cccc5sc6ccccc6c45)n3)cc2)cc1]

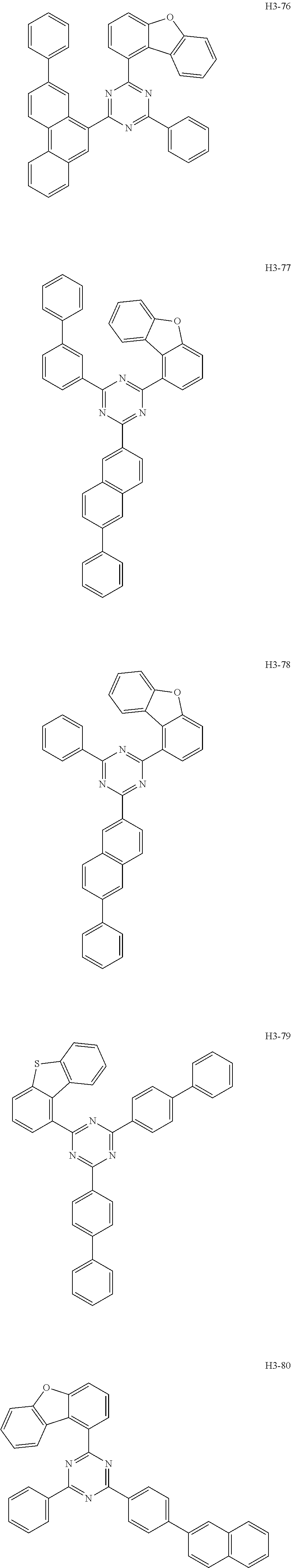 [SMILES: c1ccc(-c2ccc3c(c2)c(-c2nc(-c4ccccc4)nc(-c4cccc5oc6ccccc6c45)n2)cc2ccccc23)cc1 ; c1ccc(-c2cccc(-c3nc(-c4ccc5cc(-c6ccccc6)ccc5c4)nc(-c4cccc5oc6ccccc6c45)n3)c2)cc1 ; c1ccc(-c2ccc3cc(-c4nc(-c5ccccc5)nc(-c5cccc6oc7ccccc7c56)n4)ccc3c2)cc1 ; c1ccc(-c2ccc(-c3nc(-c4ccc(-c5ccccc5)cc4)nc(-c4cccc5sc6ccccc6c45)n3)cc2)cc1 ; c1ccc(-c2nc(-c3ccc(-c4ccc5ccccc5c4)cc3)nc(-c3cccc4oc5ccccc5c34)n2)cc1]

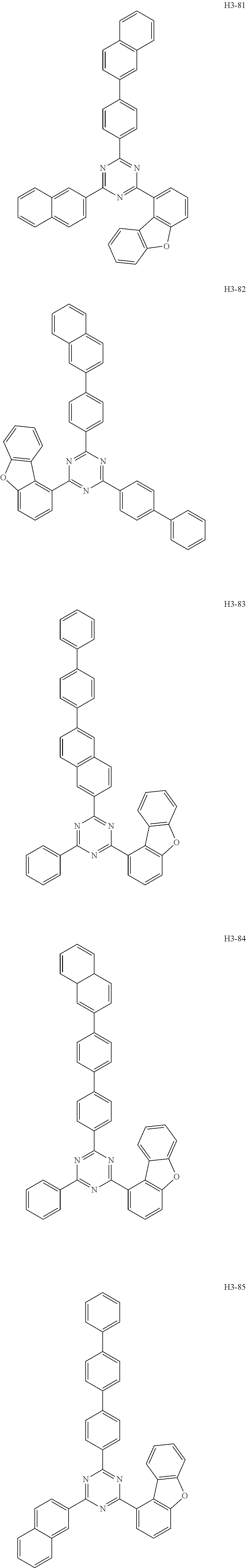 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3ccc4cc(-c5nc(-c6ccccc6)nc(-c6cccc7oc8ccccc8c67)n5)ccc4c3)cc2)cc1 ; C1=CC2C=CC(c3ccc(-c4ccc(-c5nc(-c6ccccc6)nc(-c6cccc7oc8ccccc8c67)n5)cc4)cc3)=CC2C=C1 ; c1ccc(-c2ccc(-c3ccc(-c4nc(-c5ccc6ccccc6c5)nc(-c5cccc6oc7ccccc7c56)n4)cc3)cc2)cc1]

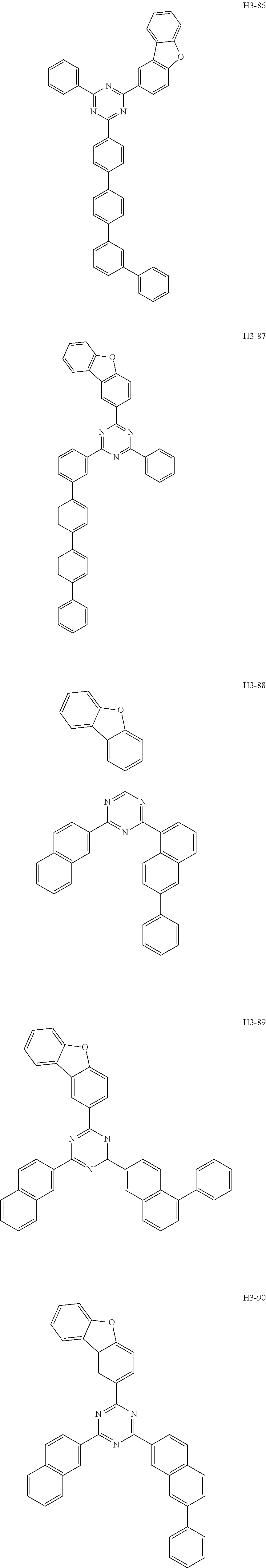 [SMILES: c1ccc(-c2cccc(-c3ccc(-c4ccc(-c5nc(-c6ccccc6)nc(-c6ccc7oc8ccccc8c7c6)n5)cc4)cc3)c2)cc1 ; c1ccc(-c2ccc(-c3ccc(-c4cccc(-c5nc(-c6ccccc6)nc(-c6ccc7oc8ccccc8c7c6)n5)c4)cc3)cc2)cc1 ; c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1]

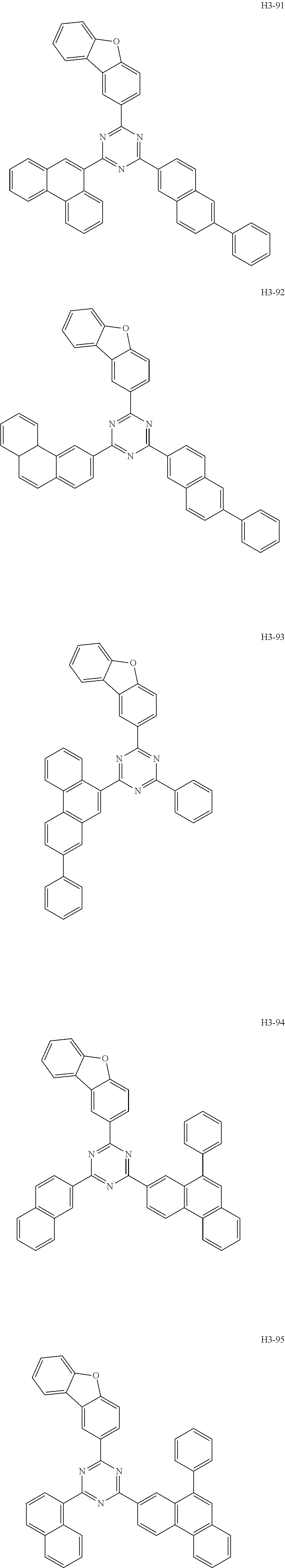 [SMILES: c1ccc(-c2ccc3cc(-c4nc(-c5ccc6oc7ccccc7c6c5)nc(-c5cc6ccccc6c6ccccc56)n4)ccc3c2)cc1 ; C1=CC2C=Cc3ccc(-c4nc(-c5ccc6cc(-c7ccccc7)ccc6c5)nc(-c5ccc6oc7ccccc7c6c5)n4)cc3C2C=C1 ; c1ccc(-c2ccc3c(c2)cc(-c2nc(-c4ccccc4)nc(-c4ccc5oc6ccccc6c5c4)n2)c2ccccc23)cc1 ; c1ccc(-c2cc3ccccc3c3ccc(-c4nc(-c5ccc6ccccc6c5)nc(-c5ccc6oc7ccccc7c6c5)n4)cc23)cc1 ; c1ccc(-c2cc3ccccc3c3ccc(-c4nc(-c5ccc6oc7ccccc7c6c5)nc(-c5cccc6ccccc56)n4)cc23)cc1]

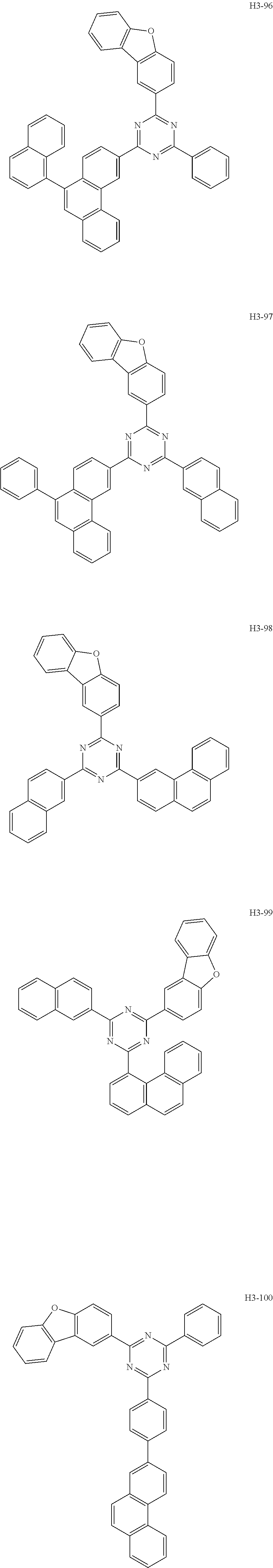 [SMILES: c1ccc(-c2nc(-c3ccc4oc5ccccc5c4c3)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6oc7ccccc7c6c5)n4)ccc23)cc1 ; c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4oc5ccccc5c4c3)n2)cc1]

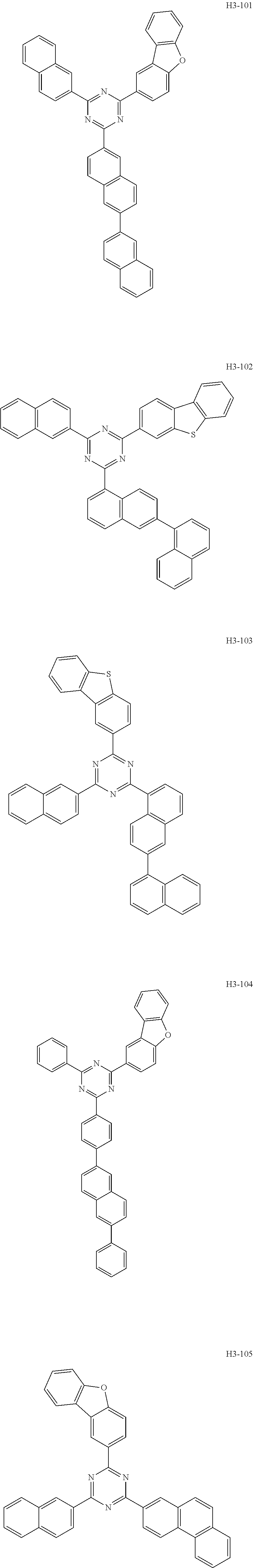 [SMILES: c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6ccc7oc8ccccc8c7c6)n5)cc4)ccc3c2)cc1 ; c1ccc2cc(-c3nc(-c4ccc5c(ccc6ccccc65)c4)nc(-c4ccc5oc6ccccc6c5c4)n3)ccc2c1]

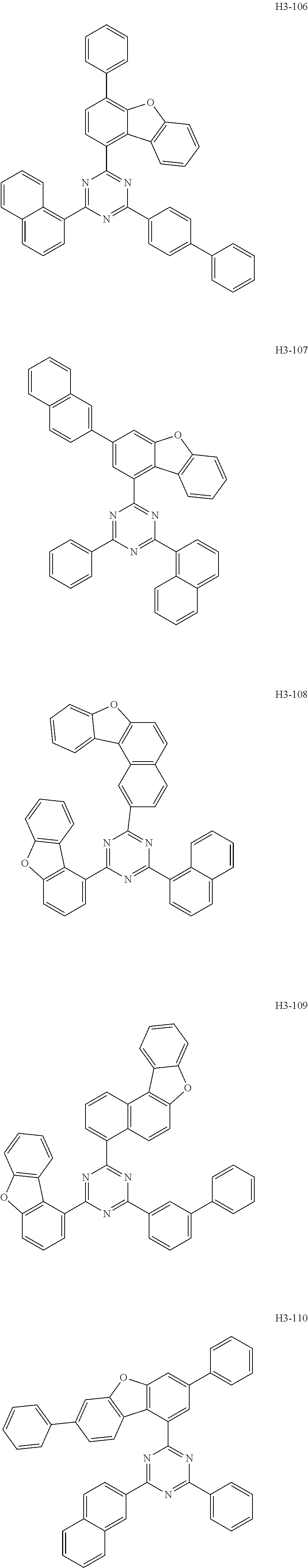 [SMILES: c1ccc(-c2ccc(-c3nc(-c4cccc5ccccc45)nc(-c4ccc(-c5ccccc5)c5oc6ccccc6c45)n3)cc2)cc1 ; c1ccc(-c2nc(-c3cccc4ccccc34)nc(-c3cc(-c4ccc5ccccc5c4)cc4oc5ccccc5c34)n2)cc1 ; c1ccc2c(-c3nc(-c4ccc5ccc6oc7ccccc7c6c5c4)nc(-c4cccc5oc6ccccc6c45)n3)cccc2c1 ; c1ccc(-c2cccc(-c3nc(-c4cccc5c4ccc4oc6ccccc6c45)nc(-c4cccc5oc6ccccc6c45)n3)c2)cc1 ; c1ccc(-c2ccc3c(c2)oc2cc(-c4ccccc4)cc(-c4nc(-c5ccccc5)nc(-c5ccc6ccccc6c5)n4)c23)cc1]

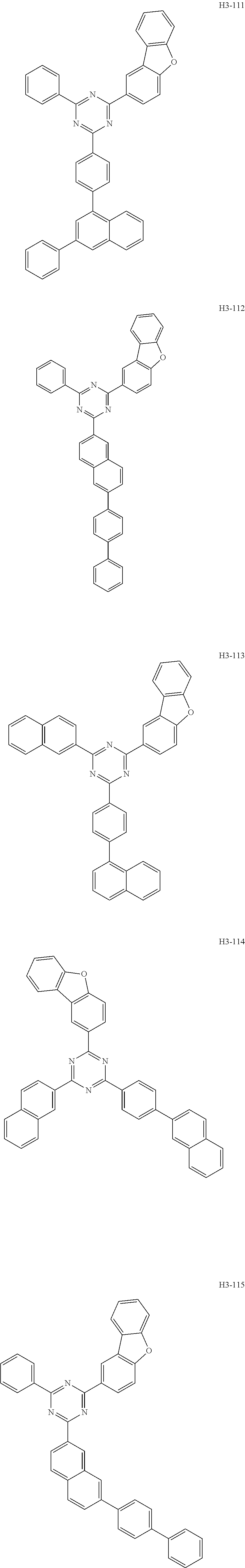 [SMILES: c1ccc(-c2cc(-c3ccc(-c4nc(-c5ccccc5)nc(-c5ccc6oc7ccccc7c6c5)n4)cc3)c3ccccc3c2)cc1 ; c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1 ; c1ccc(-c2ccc(-c3ccc4ccc(-c5nc(-c6ccccc6)nc(-c6ccc7oc8ccccc8c7c6)n5)cc4c3)cc2)cc1]

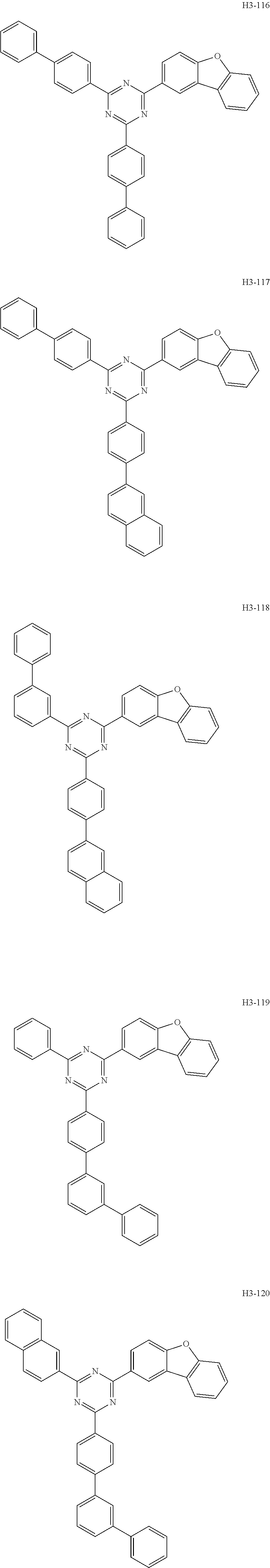 [SMILES: c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1 ; c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1]

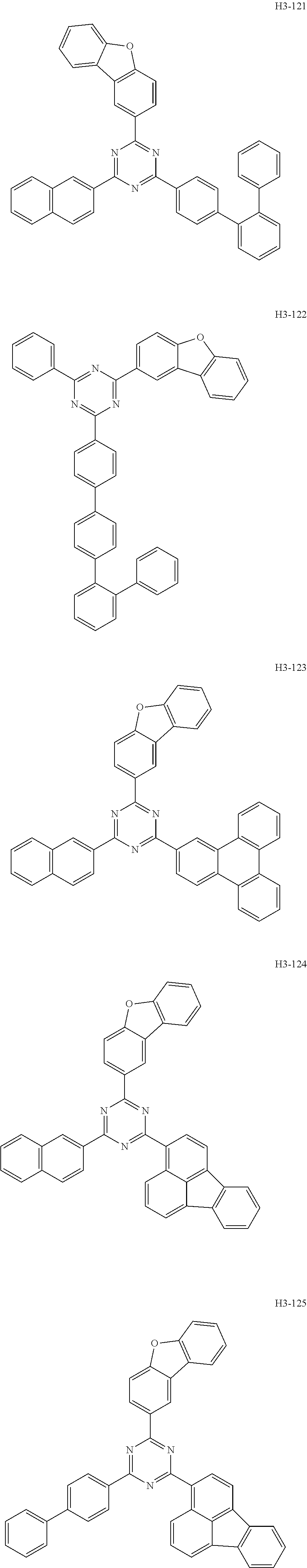 [SMILES: c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1]

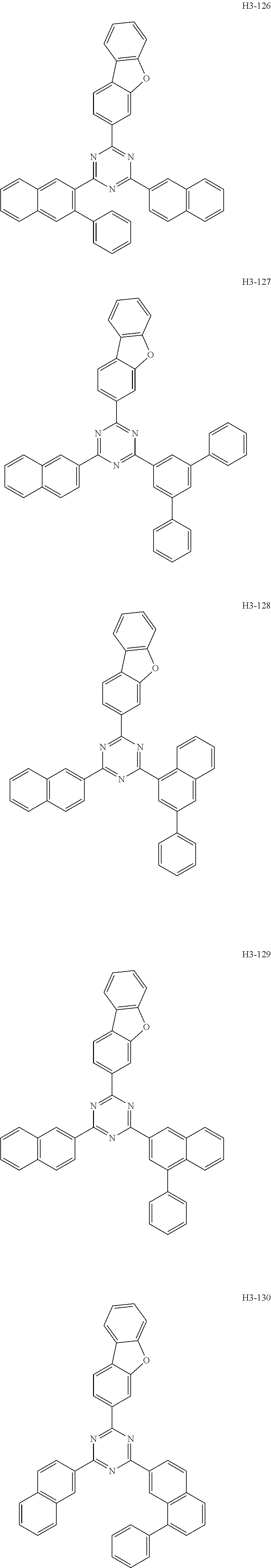 [SMILES: c1ccc(-c2cc3ccccc3cc2-c2nc(-c3ccc4ccccc4c3)nc(-c3ccc4c(c3)oc3ccccc34)n2)cc1 ; c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1 ; c1ccc(-c2cccc3ccc(-c4nc(-c5ccc6ccccc6c5)nc(-c5ccc6c(c5)oc5ccccc56)n4)cc23)cc1]

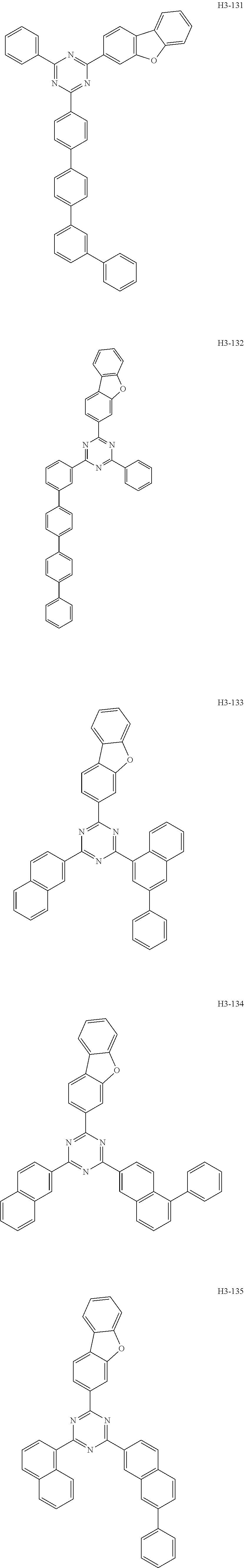 [SMILES: c1ccc(-c2cccc(-c3ccc(-c4ccc(-c5nc(-c6ccccc6)nc(-c6ccc7c(c6)oc6ccccc67)n5)cc4)cc3)c2)cc1 ; c1ccc(-c2ccc(-c3ccc(-c4cccc(-c5nc(-c6ccccc6)nc(-c6ccc7c(c6)oc6ccccc67)n5)c4)cc3)cc2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6c(c5)oc5ccccc56)nc(-c5cccc6ccccc56)n4)cc3c2)cc1]

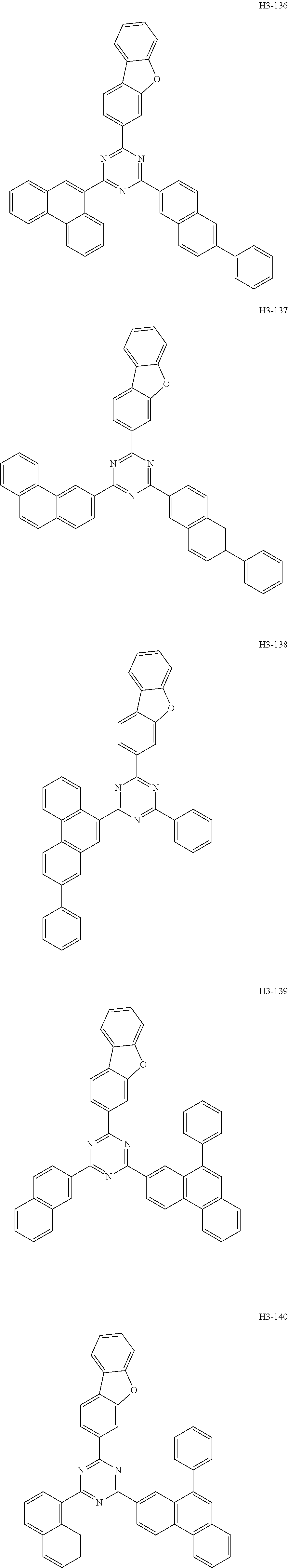 [SMILES: c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1 ; c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1]

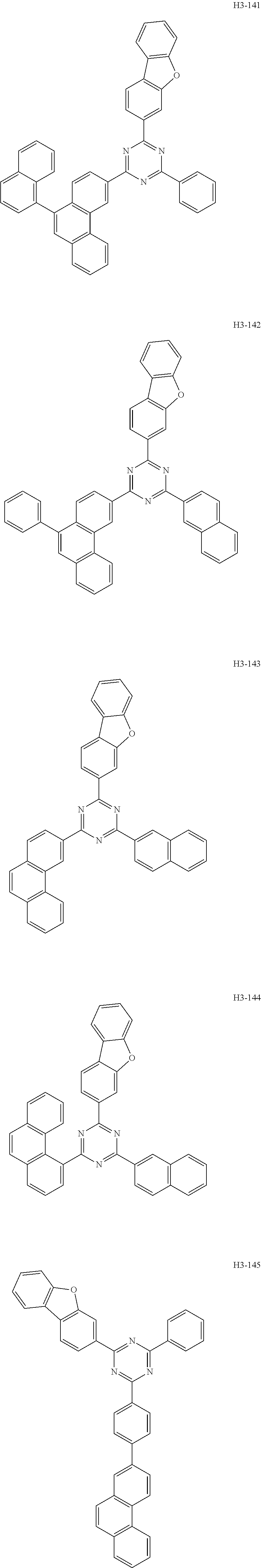 [SMILES: c1ccc(-c2nc(-c3ccc4c(c3)oc3ccccc34)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4c(c3)oc3ccccc34)n2)cc1]

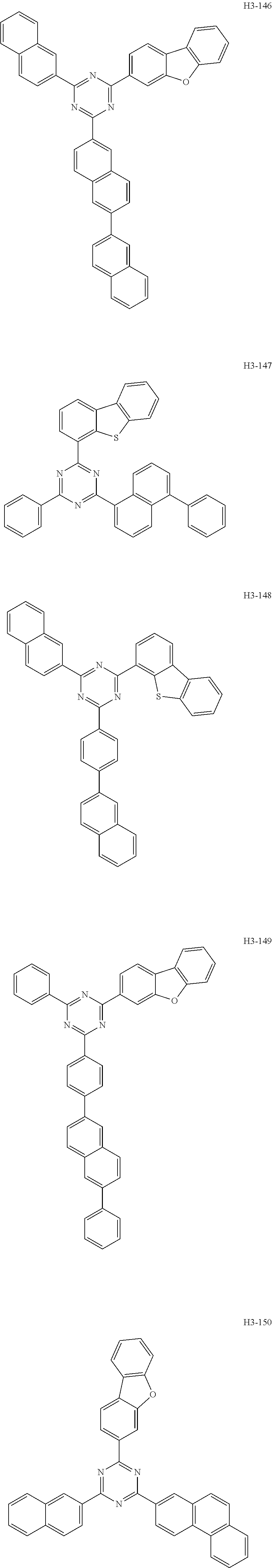 [SMILES: c1ccc2cc(-c3ccc4cc(-c5nc(-c6ccc7ccccc7c6)nc(-c6ccc7c(c6)oc6ccccc67)n5)ccc4c3)ccc2c1 ; c1ccc(-c2nc(-c3cccc4c(-c5ccccc5)cccc34)nc(-c3cccc4c3sc3ccccc34)n2)cc1 ; c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1 ; c1ccc2cc(-c3nc(-c4ccc5c(ccc6ccccc65)c4)nc(-c4ccc5c(c4)oc4ccccc45)n3)ccc2c1]

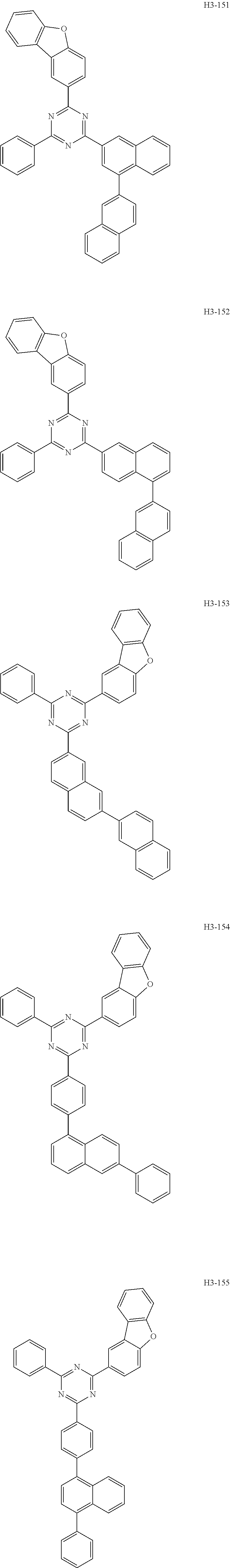 [SMILES: c1ccc(-c2nc(-c3cc(-c4ccc5ccccc5c4)c4ccccc4c3)nc(-c3ccc4oc5ccccc5c4c3)n2)cc1 ; c1ccc(-c2nc(-c3ccc4c(-c5ccc6ccccc6c5)cccc4c3)nc(-c3ccc4oc5ccccc5c4c3)n2)cc1 ; c1ccc(-c2nc(-c3ccc4ccc(-c5ccc6ccccc6c5)cc4c3)nc(-c3ccc4oc5ccccc5c4c3)n2)cc1 ; c1ccc(-c2ccc3c(-c4ccc(-c5nc(-c6ccccc6)nc(-c6ccc7oc8ccccc8c7c6)n5)cc4)cccc3c2)cc1 ; c1ccc(-c2nc(-c3ccc(-c4ccc(-c5ccccc5)c5ccccc45)cc3)nc(-c3ccc4oc5ccccc5c4c3)n2)cc1]

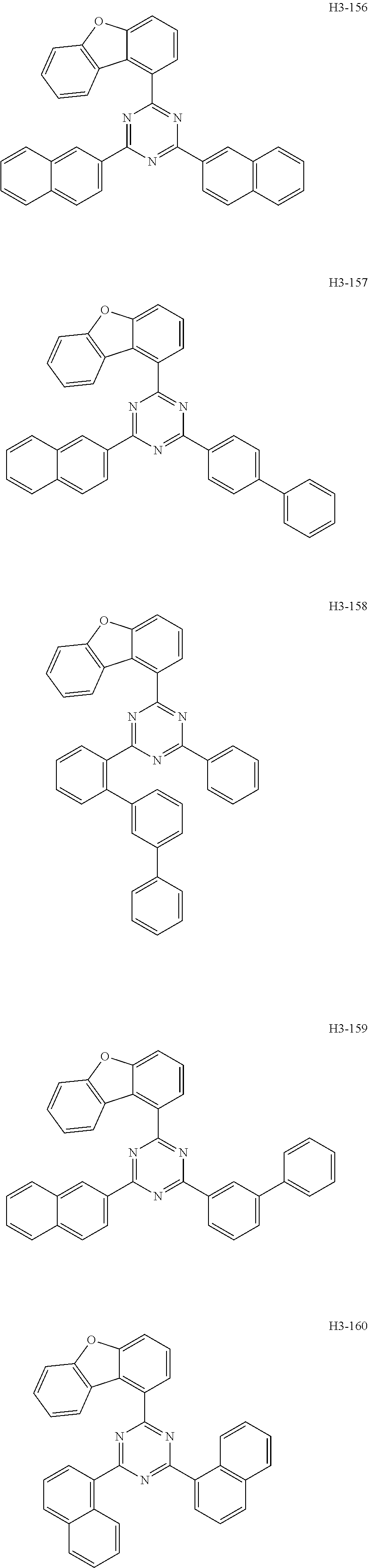 [SMILES: c1ccc2cc(-c3nc(-c4ccc5ccccc5c4)nc(-c4cccc5oc6ccccc6c45)n3)ccc2c1 ; c1ccc(-c2ccc(-c3nc(-c4ccc5ccccc5c4)nc(-c4cccc5oc6ccccc6c45)n3)cc2)cc1 ; c1ccc(-c2cccc(-c3ccccc3-c3nc(-c4ccccc4)nc(-c4cccc5oc6ccccc6c45)n3)c2)cc1 ; c1ccc(-c2cccc(-c3nc(-c4ccc5ccccc5c4)nc(-c4cccc5oc6ccccc6c45)n3)c2)cc1 ; c1ccc2c(-c3nc(-c4cccc5ccccc45)nc(-c4cccc5oc6ccccc6c45)n3)cccc2c1]

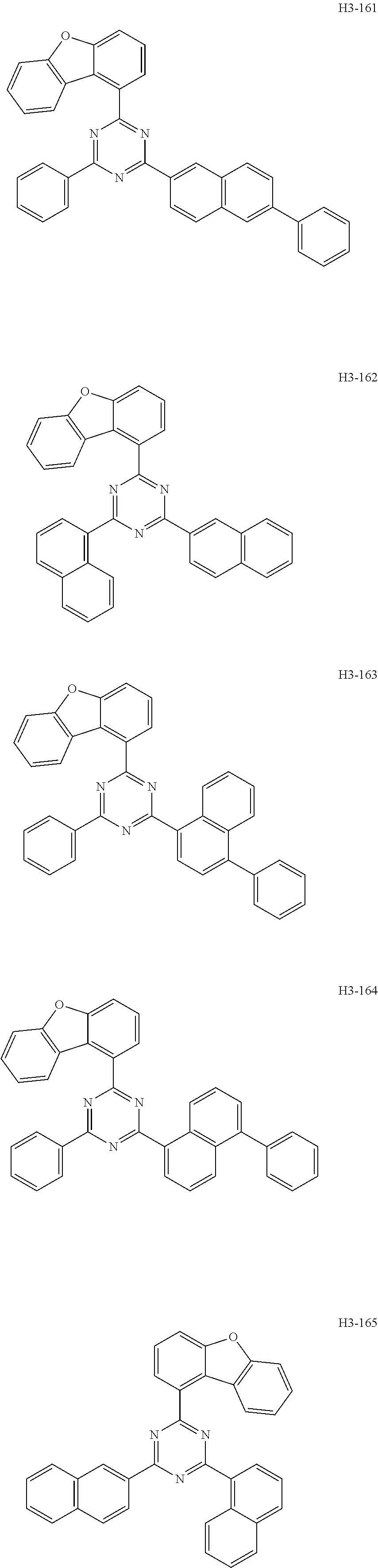 [SMILES: c1ccc(-c2ccc3cc(-c4nc(-c5ccccc5)nc(-c5cccc6oc7ccccc7c56)n4)ccc3c2)cc1 ; c1ccc2cc(-c3nc(-c4cccc5ccccc45)nc(-c4cccc5oc6ccccc6c45)n3)ccc2c1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1 ; c1ccc2cc(-c3nc(-c4cccc5ccccc45)nc(-c4cccc5oc6ccccc6c45)n3)ccc2c1]

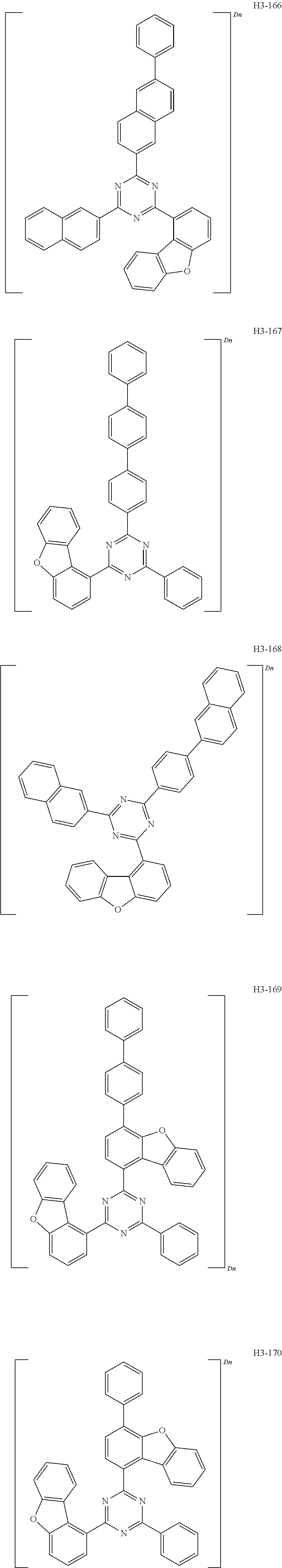

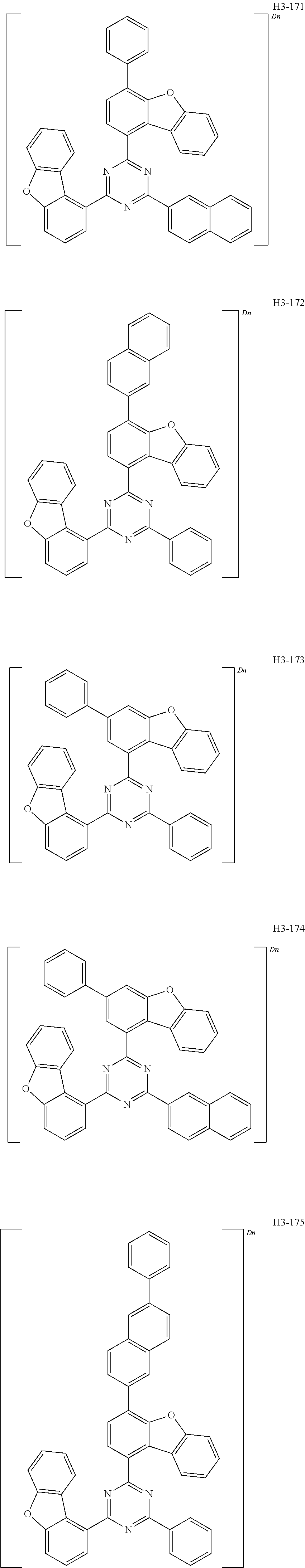

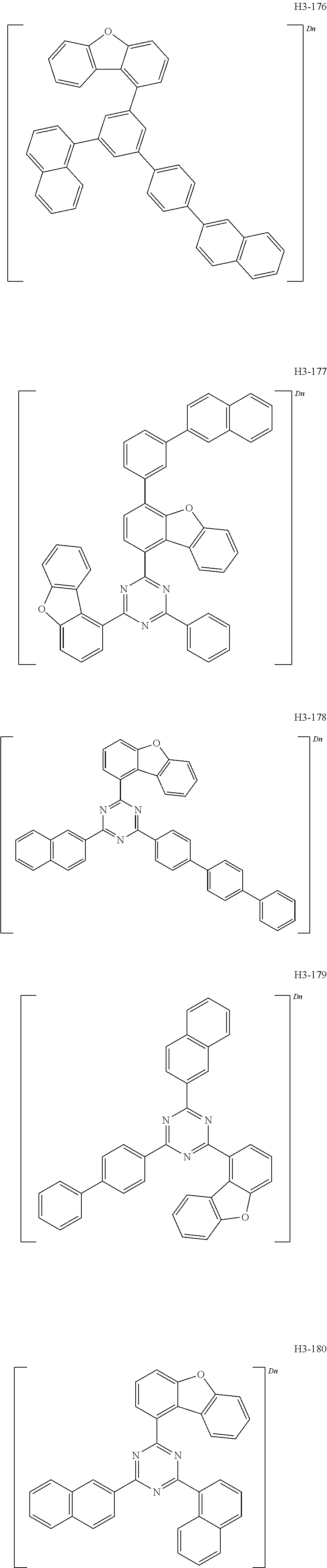

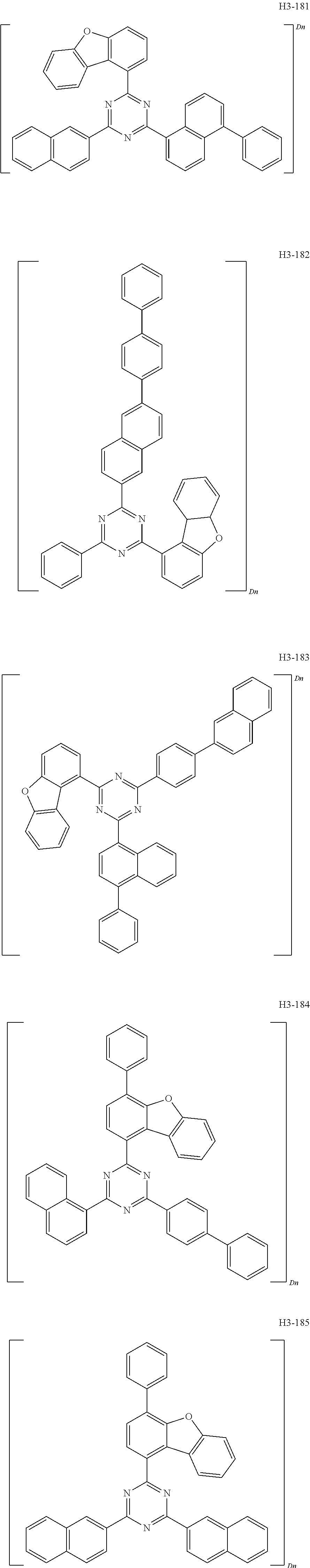

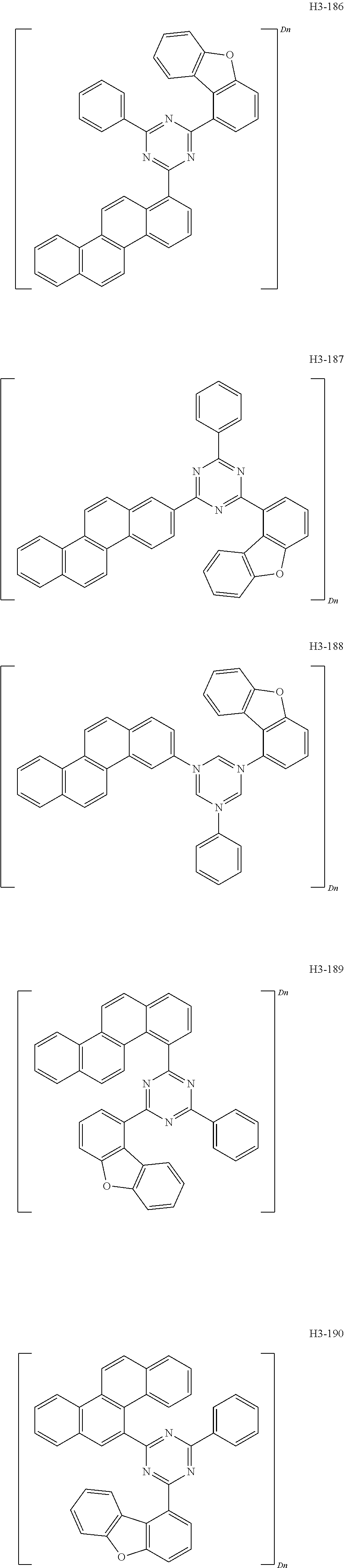

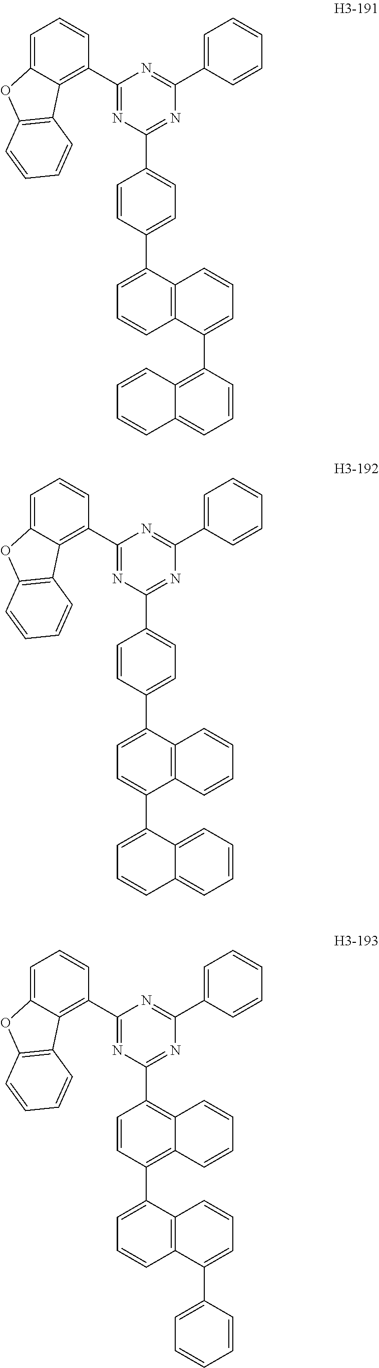 [SMILES: c1ccc(-c2nc(-c3ccc(-c4cccc5c(-c6cccc7ccccc67)cccc45)cc3)nc(-c3cccc4oc5ccccc5c34)n2)cc1 ; c1ccc(-c2nc(-c3ccc(-c4ccc(-c5cccc6ccccc56)c5ccccc45)cc3)nc(-c3cccc4oc5ccccc5c34)n2)cc1 ; c1ccc(-c2nc(-c3ccc(-c4cccc5c(-c6ccccc6)cccc45)c4ccccc34)nc(-c3cccc4oc5ccccc5c34)n2)cc1]

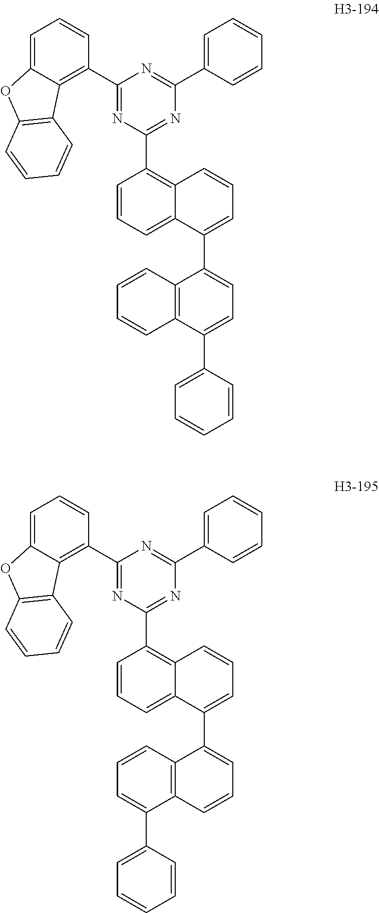 [SMILES: c1ccc(-c2nc(-c3cccc4c(-c5ccc(-c6ccccc6)c6ccccc56)cccc34)nc(-c3cccc4oc5ccccc5c34)n2)cc1 ; c1ccc(-c2nc(-c3cccc4c(-c5cccc6c(-c7ccccc7)cccc56)cccc34)nc(-c3cccc4oc5ccccc5c34)n2)cc1]

In the compounds above, Dₙ represents that n number of hydrogens are replaced with deuterium, and n represents an integer of 1 or more, which is an integer of 1 to the maximum number of hydrogens in the compound.

In Formula 2, R₁₀ to R₁₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring group of a (C₃-C₃₀)aliphatic ring(s) and a (C₆-C₃₀)aromatic ring(s), or

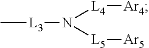

or may be linked to an adjacent substituent(s) to form a ring(s). According to one embodiment of the present disclosure, R₁₀ to R₁₅ each independently represent hydrogen, deuterium, a cyano, a substituted or unsubstituted (C₃-C₃₀)aryl, or

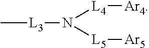

For example, R₁₀ to R₁₅ may each independently be hydrogen, deuterium, a cyano, a phenyl unsubstituted or substituted with a cyano, or

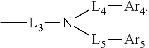

L₃ to L₅ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L₃ to L₅ each independently represent a single bond, a substituted or unsubstituted (C₆-C₂₅)arylene, or a substituted or unsubstituted (5- to 25-membered)heteroarylene. According to another embodiment of the present disclosure, L₃ to L₅ each independently represent a single bond, a substituted or unsubstituted (C₆-C₁₈)arylene, or a substituted or unsubstituted (6- to 13-membered)heteroarylene. Herein, an arylene, a heteroarylene, and a cycloalkylene may be substituted with at least one selected from the group consisting of deuterium, a cyano, and a (C₆-C₃₀)aryl. For example, L₃ to L₅ may each independently be a single bond, a phenylene unsubstituted or substituted with a phenyl or a naphthyl, a naphthylene, a biphenylene, a phenanthrenylene, a dibenzofuranylene, a dibenzothiophenylene, a carbazolylene, etc., and these may be further substituted with at least one of deuterium and a cyano.

Ar₄ and Ar₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl. According to one embodiment of the present disclosure, Ar₄ and Ar₅ each independently represent a cyano, a substituted or unsubstituted (C₆-C₂₅)aryl, or a substituted or unsubstituted (5- to 20-membered)heteroaryl. According to another embodiment of the present disclosure, Ar₄ and Ar₅ each independently represent a cyano, a substituted or unsubstituted (C₆-C₂₄)aryl, or a substituted or unsubstituted (6- to 17-membered)heteroaryl. Herein, an alkyl, an aryl, a heteroaryl, and a cycloalkyl may be substituted with at least one selected from the group consisting of deuterium, a cyano, a (C₁-C₃₀)alkyl, a (C₆-C₃₀)aryl, a (3- to 30-membered)heteroaryl, a di(C₆-C₃₀)arylamino, a (C₆-C₃₀)aryl(3- to 30-membered)heteroarylamino, and a combination thereof. Preferably, the group consists of deuterium, a cyano, a (C₁-C₄)alkyl, (C₆-C₁₈)aryl, a (6- to 14-membered)heteroaryl, a di(C₆-C₁₈)arylamino, a (C₆-C₁₈)aryl(6- to 13-membered)heteroarylamino and a combination thereof. For example, Ar₄ and Ar₅ may each independently be a cyano, a phenyl, a naphthyl, a naphthylphenyl, a phenylnaphthyl, a biphenyl, a phenanthrenyl, a chrysenyl, a terphenyl, a dimethylfluorenyl, a dimethylbenzofluorenyl, a C₂₂ aryl, a quaterphenyl, a pyridyl, a benzofuranyl, a dibenzofuranyl, a dibenzothiophenyl, a carbazolyl, a phenylcarbazolyl, a biphenylcarbazolyl, a naphthobenzofuranyl, a naphthobenzothiophenyl, or a benzoxazolyl, etc., and these may be substituted with at least one selected from the group consisting of deuterium, a cyano, a methyl, a propyl, a tert-butyl, a phenyl substituted with a cyano, a naphthyl, a biphenyl, an anthracenyl, a fluoranthenyl, a benzofuranyl, a dibenzofuranyl, a dibenzothiophenyl, a carbazolyl, a phenoxazinyl, a pyridyl substituted with a phenyl, a diphenylamino, a phenyldibenzofuranylamino, and a combination thereof.

In Formula 2-a, Y₁ and Y₂ each independently represent —N═, —NRₐ—, —O—, or —S—, with the proviso that one of Y₁ and Y₂ is —N═, and the other of Y₁ and Y₂ is —NRₐ—, —O—, or —S—. According to one embodiment of the present disclosure, one of Y₁ and Y₂ is —N═, and the other of Y₁ and Y₂ is —O— or —S—.

In Formula 2-b, T represents O or S.

In Formulas 2-a and 2-b, an adjacent pair among R₁₇₁ to R₁₇₄, R₁₈₁ to R₁₈₄, and R₁₉₁ to R₁₉₄ represents a fused position to the naphthalene in Formula 2, and R₁₇₁ to R₁₇₄, R₁₈₁ to R₁₈₄, R₁₉₁ to R₁₉₄, Rₐ, and R₁₆ which are not fused positions each independently have the same definitions as R₁₀ to R₁₅.

According to one embodiment of the present disclosure, R₁₆ represents a substituted or unsubstituted (C₆-C₃₀)aryl, a substituted or unsubstituted (3- to 30-membered)heteroaryl, or a substituted or unsubstituted (C₃-C₃₀)cycloalkyl, and these may be substituted with at least one of deuterium and a cyano. According to another embodiment of the present disclosure, R₁₆ represents a substituted or unsubstituted (C₁-C₁₈)aryl. For example, R₁₆ may be a phenyl, a naphthyl, or a biphenyl, etc., and these may be substituted with at least one of deuterium and a cyano.

In Formulas 2, when the ring A is represented by Formula 2-a, any one of R₁₀ to R₁₆ and R₁₇₁ to R₁₇₄ is

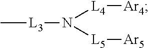

and when the ring A is represented by Formula 2-b, at least one of R₁₀ to R₁₅, R₁₈₁ to R₁₈₄, and R₁₉₁ to R₁₉₄ is

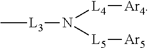

For example, when the ring A is represented by Formula 2-a, any one of R₁₀ to R₁₅ and R₁₇₁ to R₁₇₄ is

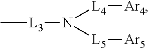

Ar₅, and when the ring A is represented b Formula 2-b, any one or any two of R₁₀ to R₁₅, R₁₈₁ to R₁₈₄, and R₁₉₁ to R₁₉₄ is

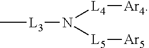

In Formula 2, when Ar₄ and Arm are substituted (C₆-C₃₀)aryl, cases where the substituents of the substituted aryl comprise a carbazole or an amino are excluded.

Formula 2 may be represented by any one of the following Formulas 2-1 to 2-4.

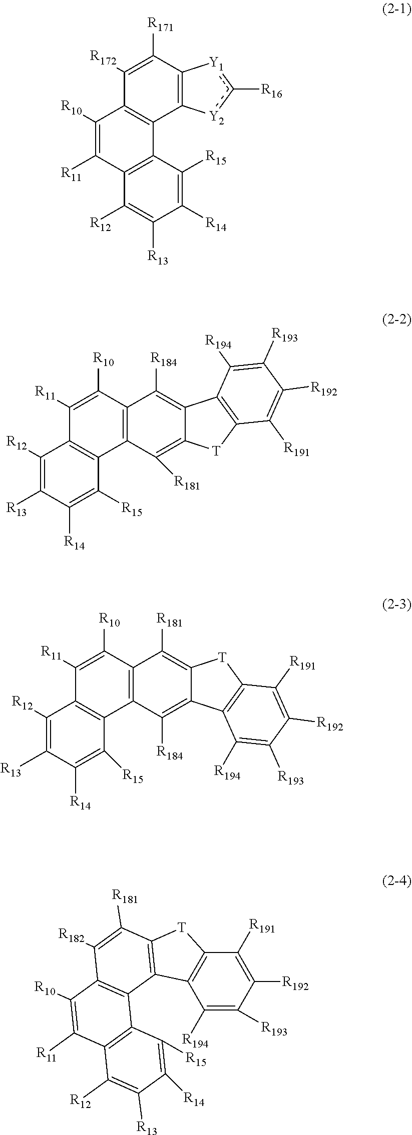

In Formulas 2-1 to 2-4, Y₁, Y₂, T, R₁₀ to R₁₆, R₁₇₁, R₁₇₂, R₁₈₁, R₁₈₂, R₁₈₄, and R₁₉₁ to R₁₉₄ are as defined in Formula 2.

According to one embodiment of the present disclosure, the second host material comprising a compound represented by Formula 2 comprises a cyano. According to one embodiment of the present disclosure, in Formula 2-1, any one of R₁₀ to R₁₆, R₁₇₁, and R₁₇₂ is

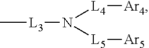

and at least one of R₁₀ to R₁₆, R₁₇₁, R₁₇₂, Ar₄, and Ar₅ is substituted with a cyano, a (C₁-C₃₀)alkyl unsubstituted or substituted with a cyano, a (C₆-C₃₀)aryl unsubstituted or substituted with a cyano, or a (3- to 30-membered)heteroaryl unsubstituted or substituted with a cyano. According to one embodiment of the present disclosure, in any one of Formulas 2-2 to 2-4, at least one of R₁₀ to R₁₅, R₁₈₁, R₁₈₂, R₁₈₄, and R₁₉₁ to R₁₉₄ is

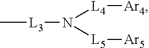

and at least one of R₁₀ to R₁₅, R₁₈₁, R₁₈₂, R₁₈₄, R₁₉₁ to R₁₉₄, Ar₄, and Ar₅ is substituted with a cyano, a (C₁-C₃₀)alkyl unsubstituted or substituted with a cyano, a (C₆-C₃₀)aryl unsubstituted or substituted with a cyano, or a (3- to 30-membered)heteroaryl unsubstituted or substituted with a cyano.

The compound represented by Formula 2 may be selected from the following compounds, but is not limited to thereto.

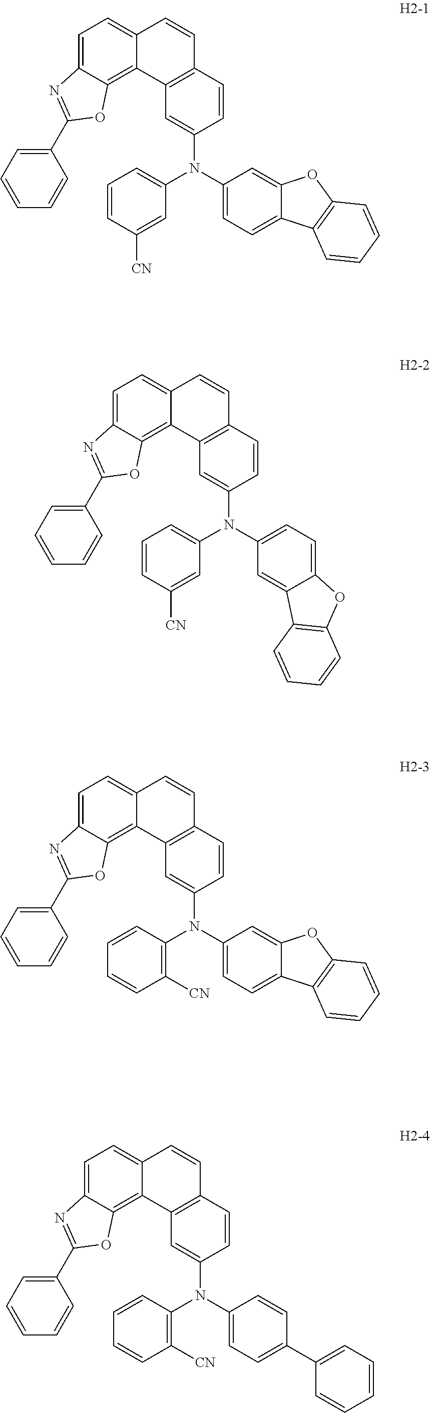 [SMILES: N#Cc1cccc(N(c2ccc3c(c2)oc2ccccc23)c2ccc3ccc4ccc5nc(-c6ccccc6)oc5c4c3c2)c1 ; N#Cc1cccc(N(c2ccc3oc4ccccc4c3c2)c2ccc3ccc4ccc5nc(-c6ccccc6)oc5c4c3c2)c1 ; N#Cc1ccccc1N(c1ccc2c(c1)oc1ccccc12)c1ccc2ccc3ccc4nc(-c5ccccc5)oc4c3c2c1 ; N#Cc1ccccc1N(c1ccc(-c2ccccc2)cc1)c1ccc2ccc3ccc4nc(-c5ccccc5)oc4c3c2c1]

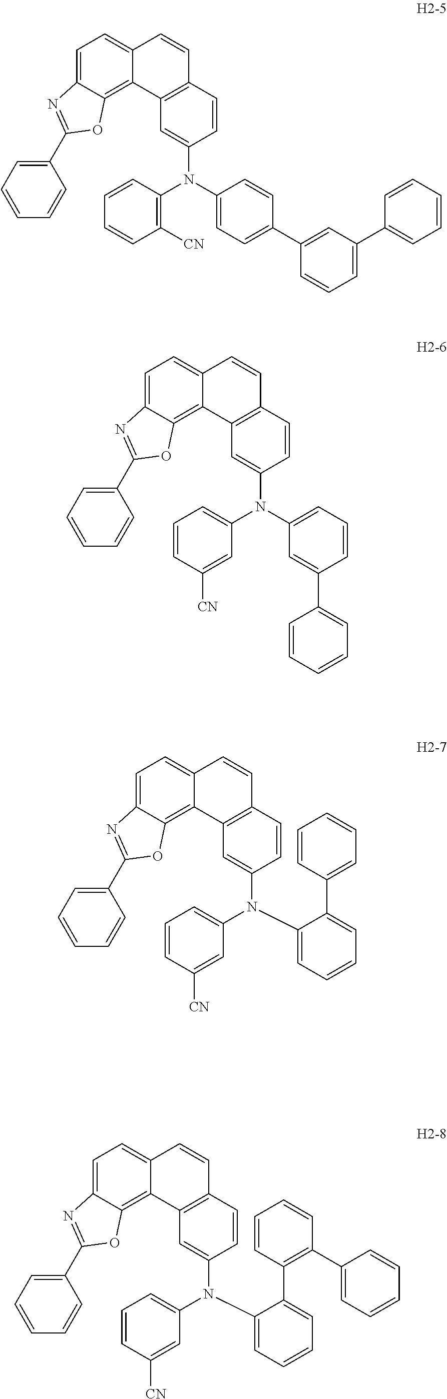 [SMILES: N#Cc1ccccc1N(c1ccc(-c2cccc(-c3ccccc3)c2)cc1)c1ccc2ccc3ccc4nc(-c5ccccc5)oc4c3c2c1 ; N#Cc1cccc(N(c2cccc(-c3ccccc3)c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2ccccc2-c2ccccc2)c1 ; N#Cc1cccc(N(c2ccc3ccc4ccc5nc(-c6ccccc6)oc5c4c3c2)c2ccccc2-c2ccccc2-c2ccccc2)c1]

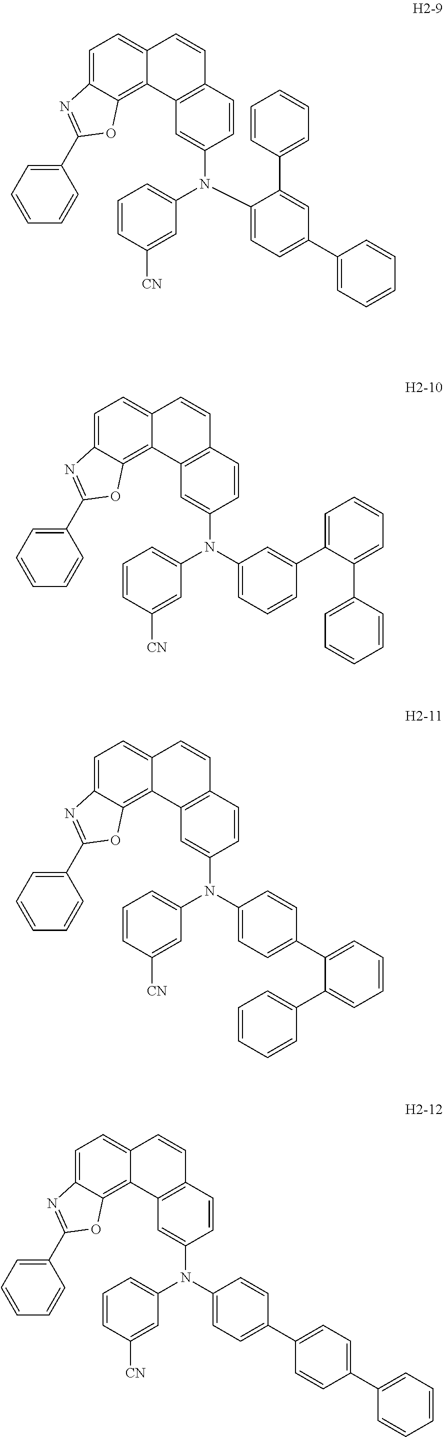 [SMILES: N#Cc1cccc(N(c2ccc3ccc4ccc5nc(-c6ccccc6)oc5c4c3c2)c2ccc(-c3ccccc3)cc2-c2ccccc2)c1 ; N#Cc1cccc(N(c2cccc(-c3ccccc3-c3ccccc3)c2)c2ccc3ccc4ccc5nc(-c6ccccc6)oc5c4c3c2)c1 ; N#Cc1cccc(N(c2ccc(-c3ccccc3-c3ccccc3)cc2)c2ccc3ccc4ccc5nc(-c6ccccc6)oc5c4c3c2)c1 ; N#Cc1cccc(N(c2ccc(-c3ccc(-c4ccccc4)cc3)cc2)c2ccc3ccc4ccc5nc(-c6ccccc6)oc5c4c3c2)c1]

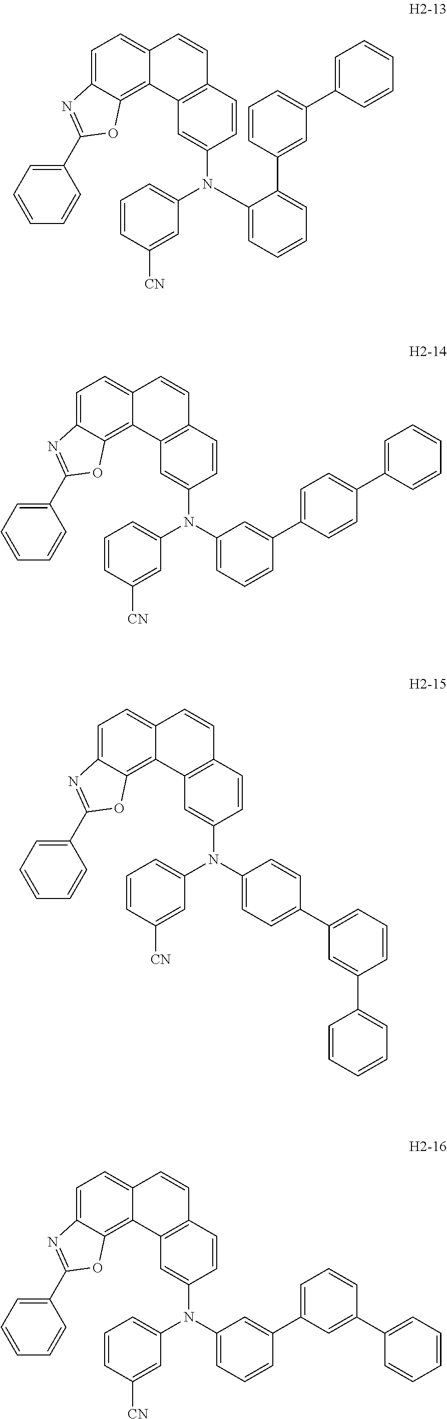 [SMILES: N#Cc1cccc(N(c2ccc3ccc4ccc5nc(-c6ccccc6)oc5c4c3c2)c2ccccc2-c2cccc(-c3ccccc3)c2)c1 ; N#Cc1cccc(N(c2cccc(-c3ccc(-c4ccccc4)cc3)c2)c2ccc3ccc4ccc5nc(-c6ccccc6)oc5c4c3c2)c1 ; N#Cc1cccc(N(c2ccc(-c3cccc(-c4ccccc4)c3)cc2)c2ccc3ccc4ccc5nc(-c6ccccc6)oc5c4c3c2)c1 ; N#Cc1cccc(N(c2cccc(-c3cccc(-c4ccccc4)c3)c2)c2ccc3ccc4ccc5nc(-c6ccccc6)oc5c4c3c2)c1]

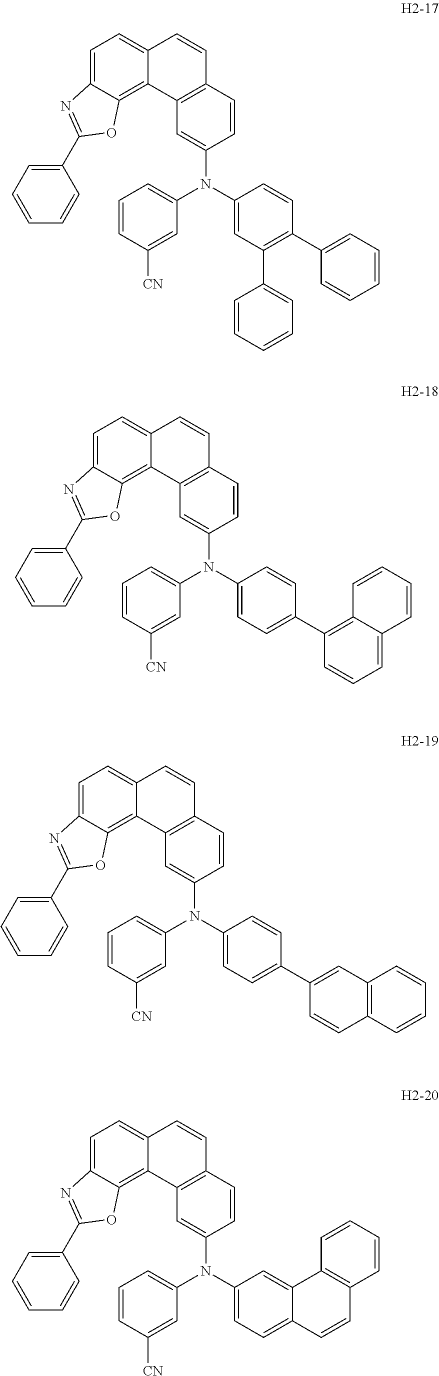 [SMILES: N#Cc1cccc(N(c2ccc(-c3ccccc3)c(-c3ccccc3)c2)c2ccc3ccc4ccc5nc(-c6ccccc6)oc5c4c3c2)c1 ; N#Cc1cccc(N(c2ccc(-c3cccc4ccccc34)cc2)c2ccc3ccc4ccc5nc(-c6ccccc6)oc5c4c3c2)c1 ; N#Cc1cccc(N(c2ccc(-c3ccc4ccccc4c3)cc2)c2ccc3ccc4ccc5nc(-c6ccccc6)oc5c4c3c2)c1 ; N#Cc1cccc(N(c2ccc3ccc4ccccc4c3c2)c2ccc3ccc4ccc5nc(-c6ccccc6)oc5c4c3c2)c1]

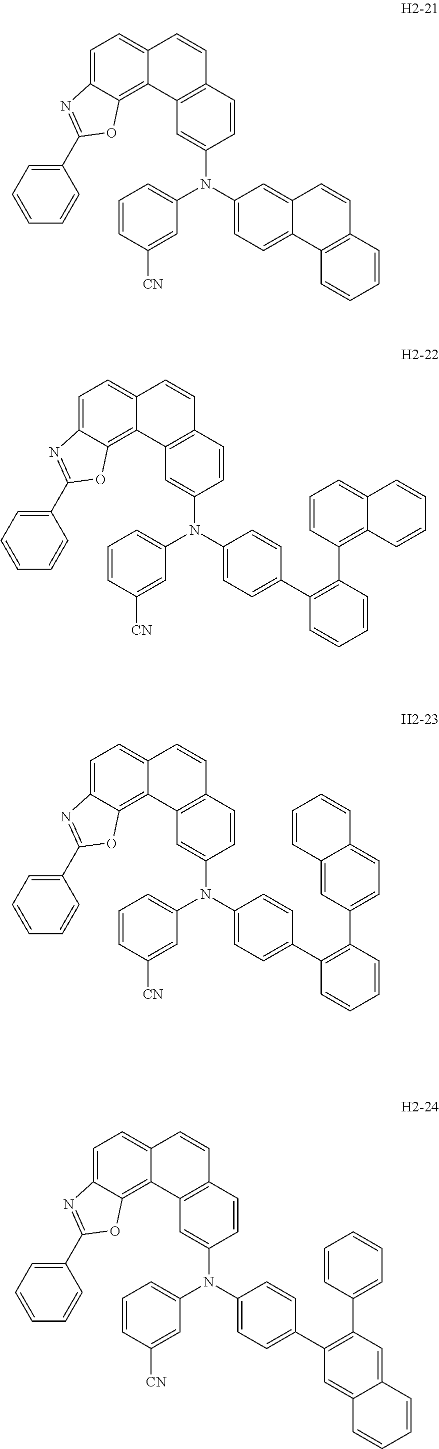 [SMILES: N#Cc1cccc(N(c2ccc3c(ccc4ccccc43)c2)c2ccc3ccc4ccc5nc(-c6ccccc6)oc5c4c3c2)c1 ; N#Cc1cccc(N(c2ccc(-c3ccccc3-c3cccc4ccccc34)cc2)c2ccc3ccc4ccc5nc(-c6ccccc6)oc5c4c3c2)c1 ; N#Cc1cccc(N(c2ccc(-c3ccccc3-c3ccc4ccccc4c3)cc2)c2ccc3ccc4ccc5nc(-c6ccccc6)oc5c4c3c2)c1 ; N#Cc1cccc(N(c2ccc(-c3cc4ccccc4cc3-c3ccccc3)cc2)c2ccc3ccc4ccc5nc(-c6ccccc6)oc5c4c3c2)c1]

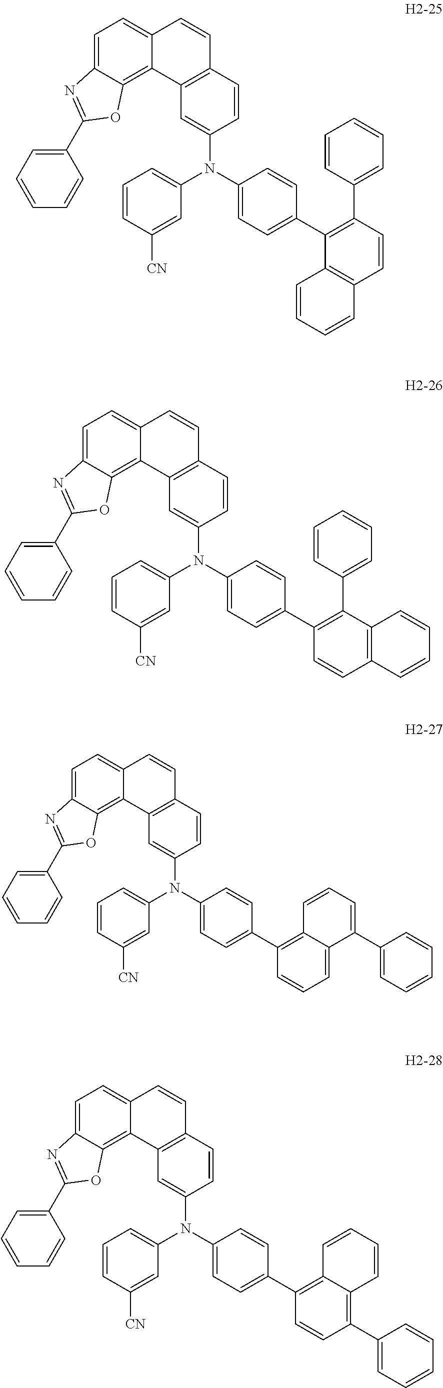 [SMILES: N#Cc1cccc(N(c2ccc(-c3c(-c4ccccc4)ccc4ccccc34)cc2)c2ccc3ccc4ccc5nc(-c6ccccc6)oc5c4c3c2)c1 ; N#Cc1cccc(N(c2ccc(-c3ccc4ccccc4c3-c3ccccc3)cc2)c2ccc3ccc4ccc5nc(-c6ccccc6)oc5c4c3c2)c1 ; N#Cc1cccc(N(c2ccc(-c3cccc4c(-c5ccccc5)cccc34)cc2)c2ccc3ccc4ccc5nc(-c6ccccc6)oc5c4c3c2)c1 ; N#Cc1cccc(N(c2ccc(-c3ccc(-c4ccccc4)c4ccccc34)cc2)c2ccc3ccc4ccc5nc(-c6ccccc6)oc5c4c3c2)c1]

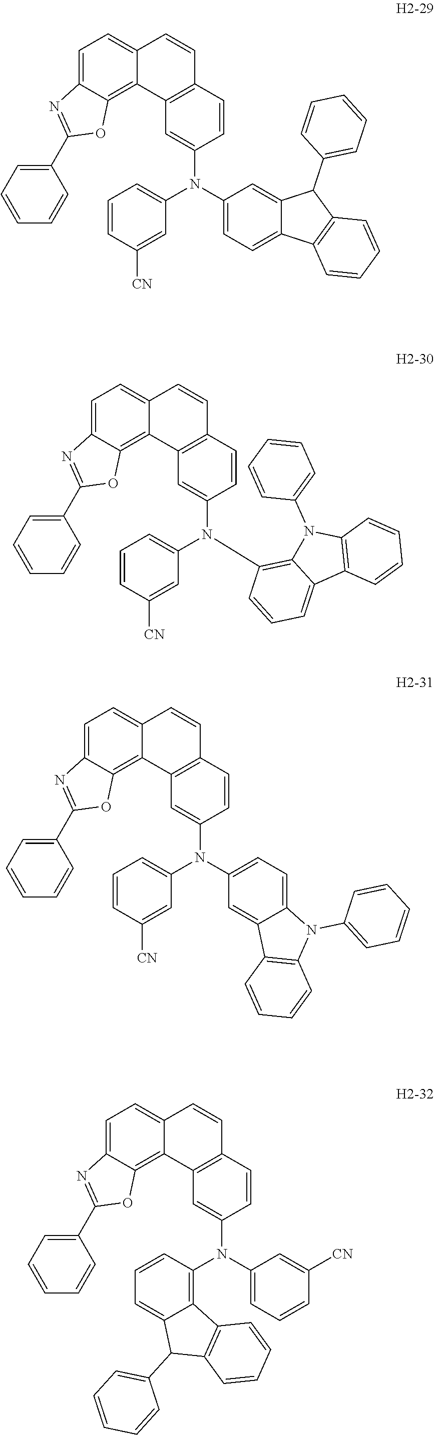 [SMILES: N#Cc1cccc(N(c2ccc3c(c2)C(c2ccccc2)c2ccccc2-3)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c4ccccc4n(-c4ccccc4)c23)c1 ; N#Cc1cccc(N(c2ccc3ccc4ccc5nc(-c6ccccc6)oc5c4c3c2)c2ccc3c(c2)c2ccccc2n3-c2ccccc2)c1 ; N#Cc1cccc(N(c2ccc3ccc4ccc5nc(-c6ccccc6)oc5c4c3c2)c2cccc3c2-c2ccccc2C3c2ccccc2)c1]

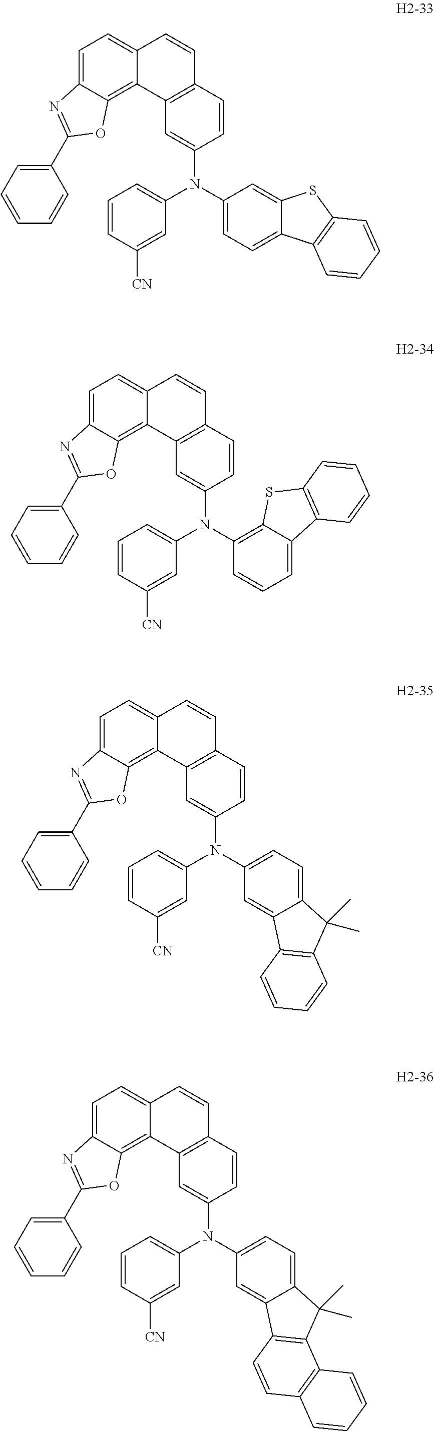 [SMILES: N#Cc1cccc(N(c2ccc3c(c2)sc2ccccc23)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c2sc2ccccc23)c1 ; CC1(C)c2ccccc2-c2cc(N(c3cccc(C#N)c3)c3ccc4ccc5ccc6nc(-c7ccccc7)oc6c5c4c3)ccc21 ; CC1(C)c2ccc(N(c3cccc(C#N)c3)c3ccc4ccc5ccc6nc(-c7ccccc7)oc6c5c4c3)cc2-c2ccc3ccccc3c21]

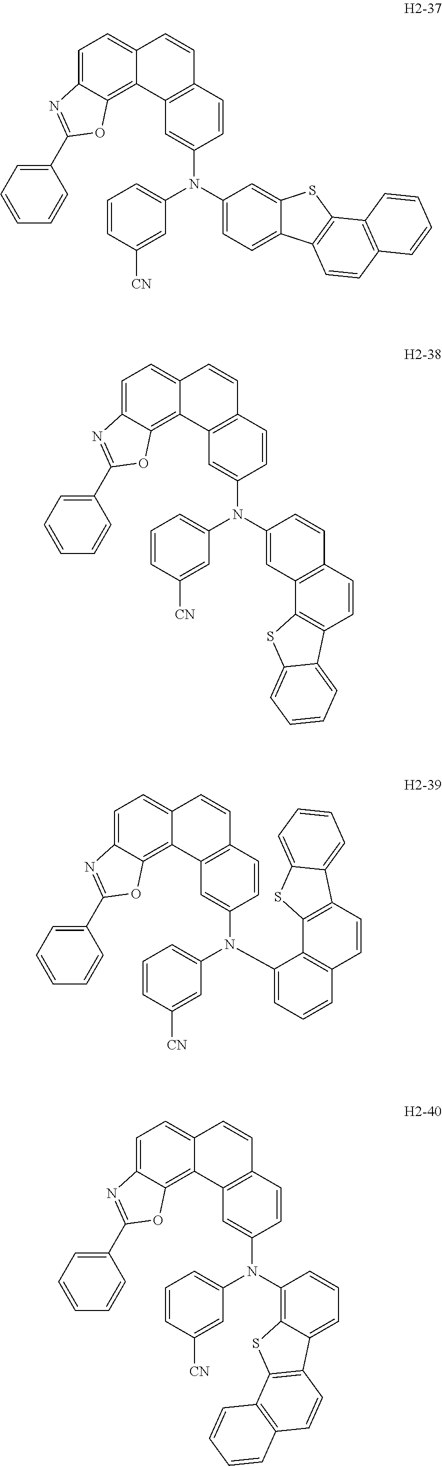 [SMILES: N#Cc1cccc(N(c2ccc3c(c2)sc2c4ccccc4ccc32)c2ccc3ccc4ccc5nc(-c6ccccc6)oc5c4c3c2)c1 ; N#Cc1cccc(N(c2ccc3ccc4c5ccccc5sc4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3ccc4c5ccccc5sc4c23)c1 ; N#Cc1cccc(N(c2ccc3ccc4ccc5nc(-c6ccccc6)oc5c4c3c2)c2cccc3c2sc2c4ccccc4ccc32)c1]

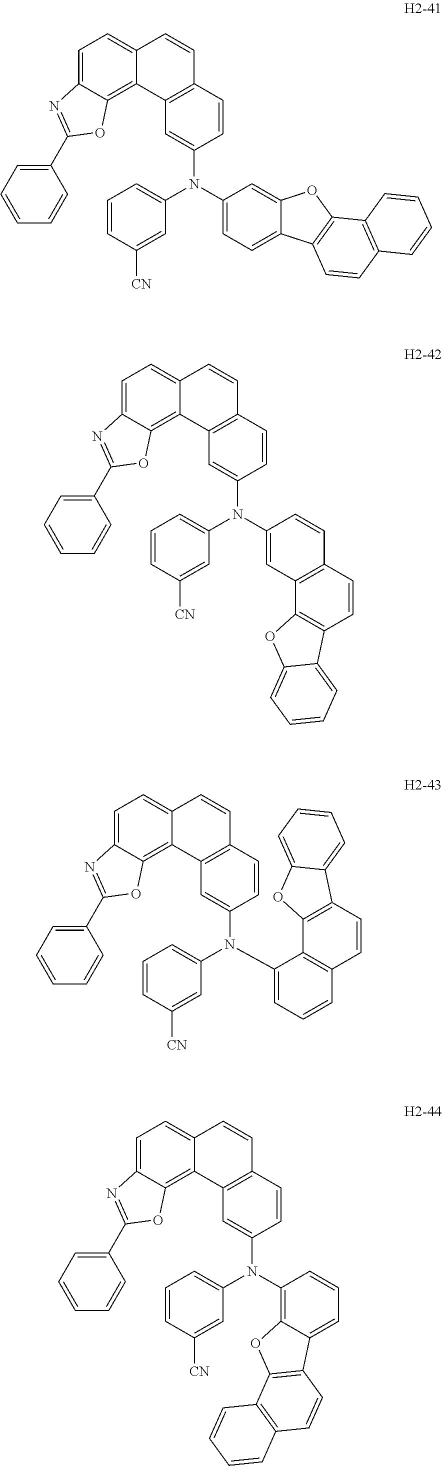 [SMILES: N#Cc1cccc(N(c2ccc3c(c2)oc2c4ccccc4ccc32)c2ccc3ccc4ccc5nc(-c6ccccc6)oc5c4c3c2)c1 ; N#Cc1cccc(N(c2ccc3ccc4c5ccccc5oc4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3ccc4c5ccccc5oc4c23)c1 ; N#Cc1cccc(N(c2ccc3ccc4ccc5nc(-c6ccccc6)oc5c4c3c2)c2cccc3c2oc2c4ccccc4ccc32)c1]

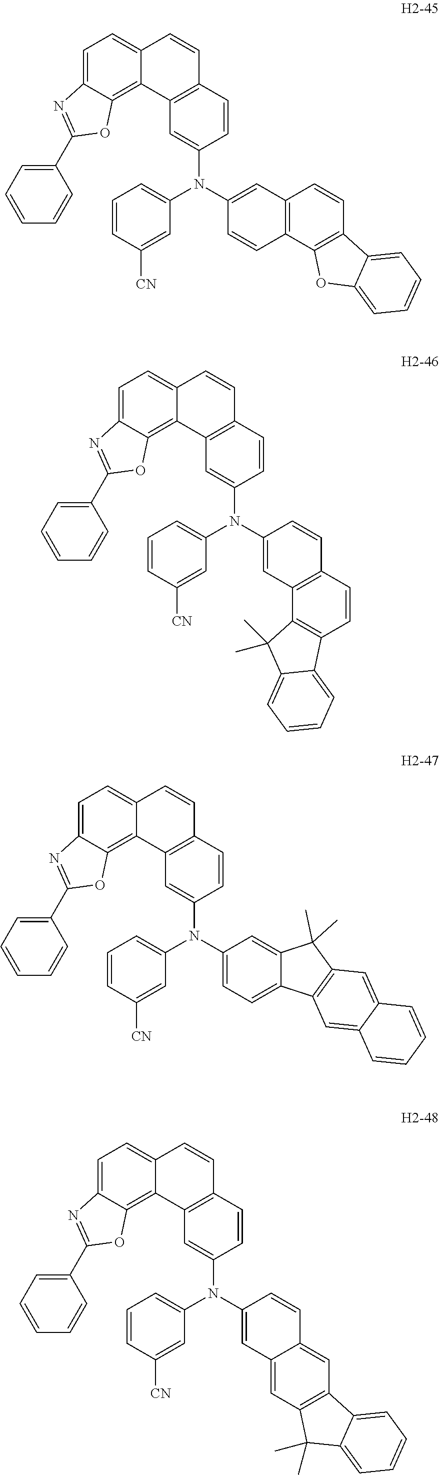 [SMILES: N#Cc1cccc(N(c2ccc3c(ccc4c5ccccc5oc34)c2)c2ccc3ccc4ccc5nc(-c6ccccc6)oc5c4c3c2)c1 ; CC1(C)c2ccccc2-c2ccc3ccc(N(c4cccc(C#N)c4)c4ccc5ccc6ccc7nc(-c8ccccc8)oc7c6c5c4)cc3c21 ; CC1(C)c2cc(N(c3cccc(C#N)c3)c3ccc4ccc5ccc6nc(-c7ccccc7)oc6c5c4c3)ccc2-c2cc3ccccc3cc21 ; CC1(C)c2ccccc2-c2cc3ccc(N(c4cccc(C#N)c4)c4ccc5ccc6ccc7nc(-c8ccccc8)oc7c6c5c4)cc3cc21]

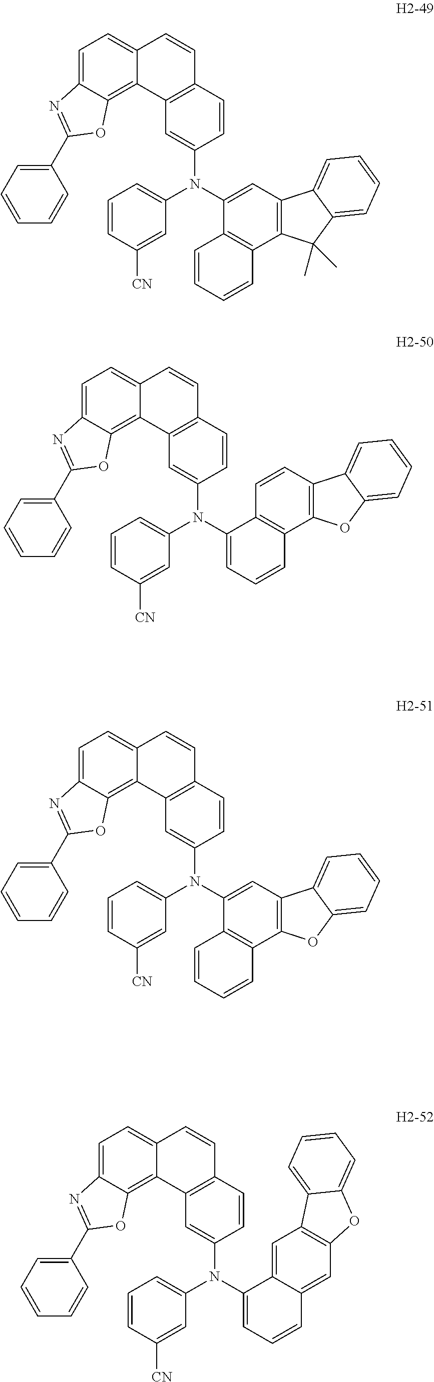 [SMILES: CC1(C)c2ccccc2-c2cc(N(c3cccc(C#N)c3)c3ccc4ccc5ccc6nc(-c7ccccc7)oc6c5c4c3)c3ccccc3c21 ; N#Cc1cccc(N(c2ccc3ccc4ccc5nc(-c6ccccc6)oc5c4c3c2)c2cccc3c2ccc2c4ccccc4oc32)c1 ; N#Cc1cccc(N(c2ccc3ccc4ccc5nc(-c6ccccc6)oc5c4c3c2)c2cc3c4ccccc4oc3c3ccccc23)c1 ; N#Cc1cccc(N(c2ccc3ccc4ccc5nc(-c6ccccc6)oc5c4c3c2)c2cccc3cc4oc5ccccc5c4cc23)c1]

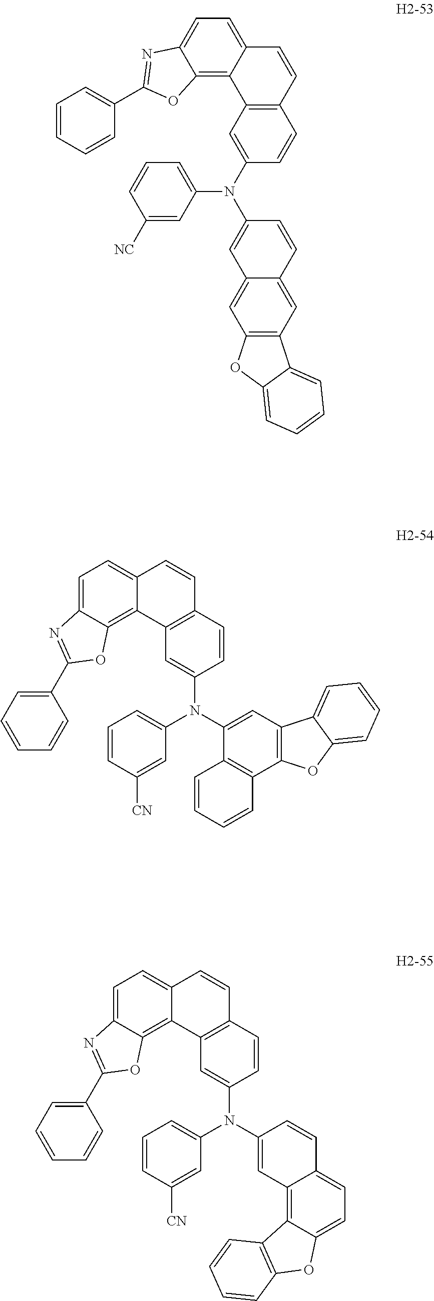 [SMILES: N#Cc1cccc(N(c2ccc3cc4c(cc3c2)oc2ccccc24)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cc3c4ccccc4oc3c3ccccc23)c1 ; N#Cc1cccc(N(c2ccc3ccc4oc5ccccc5c4c3c2)c2ccc3ccc4ccc5nc(-c6ccccc6)oc5c4c3c2)c1]

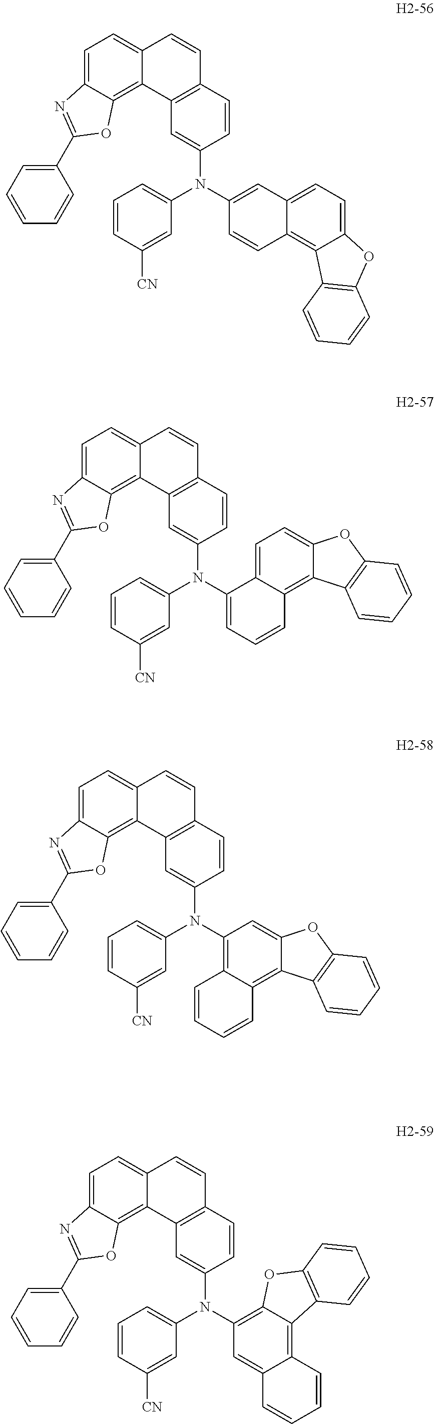 [SMILES: N#Cc1cccc(N(c2ccc3c(ccc4oc5ccccc5c43)c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c2ccc2oc4ccccc4c23)c1 ; N#Cc1cccc(N(c2ccc3ccc4ccc5nc(-c6ccccc6)oc5c4c3c2)c2cc3oc4ccccc4c3c3ccccc23)c1 ; N#Cc1cccc(N(c2ccc3ccc4ccc5nc(-c6ccccc6)oc5c4c3c2)c2cc3ccccc3c3c2oc2ccccc23)c1]

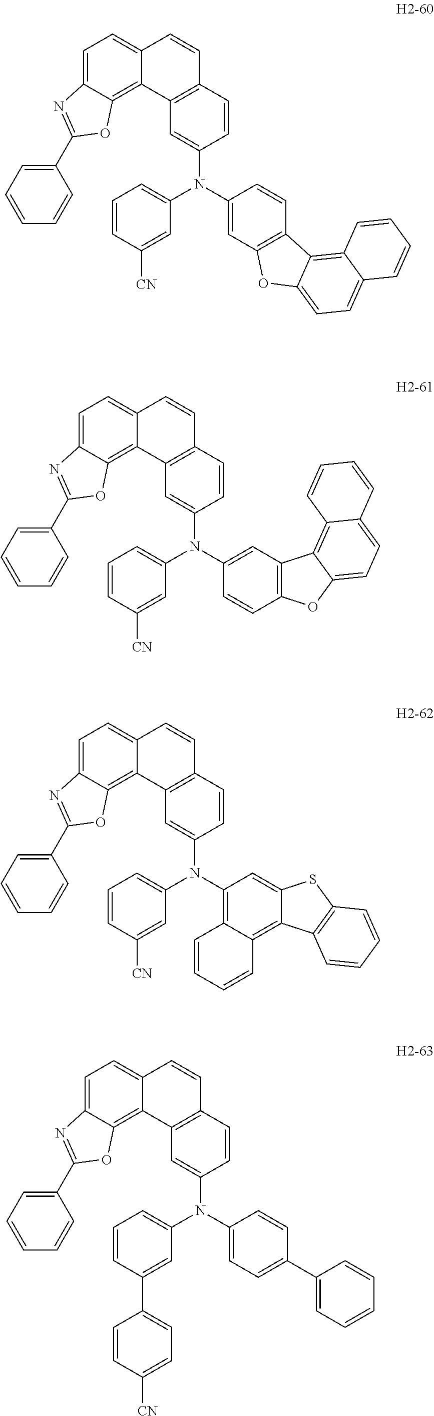 [SMILES: N#Cc1cccc(N(c2ccc3c(c2)oc2ccc4ccccc4c23)c2ccc3ccc4ccc5nc(-c6ccccc6)oc5c4c3c2)c1 ; N#Cc1cccc(N(c2ccc3oc4ccc5ccccc5c4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cc3sc4ccccc4c3c3ccccc23)c1 ; N#Cc1ccc(-c2cccc(N(c3ccc(-c4ccccc4)cc3)c3ccc4ccc5ccc6nc(-c7ccccc7)oc6c5c4c3)c2)cc1]

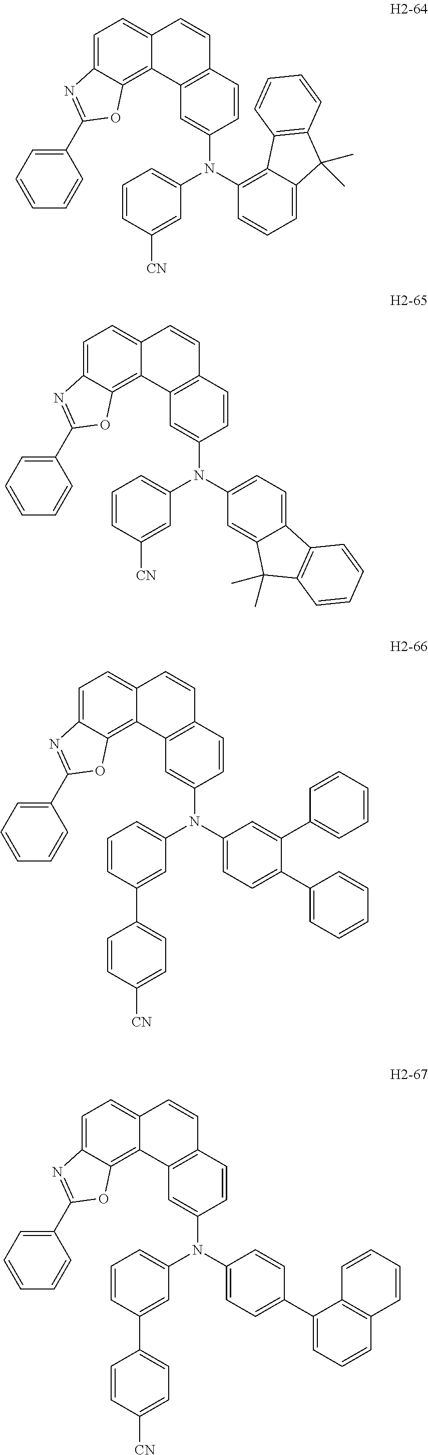 [SMILES: CC1(C)c2ccccc2-c2c(N(c3cccc(C#N)c3)c3ccc4ccc5ccc6nc(-c7ccccc7)oc6c5c4c3)cccc21 ; CC1(C)c2ccccc2-c2ccc(N(c3cccc(C#N)c3)c3ccc4ccc5ccc6nc(-c7ccccc7)oc6c5c4c3)cc21 ; N#Cc1ccc(-c2cccc(N(c3ccc(-c4ccccc4)c(-c4ccccc4)c3)c3ccc4ccc5ccc6nc(-c7ccccc7)oc6c5c4c3)c2)cc1 ; N#Cc1ccc(-c2cccc(N(c3ccc(-c4cccc5ccccc45)cc3)c3ccc4ccc5ccc6nc(-c7ccccc7)oc6c5c4c3)c2)cc1]

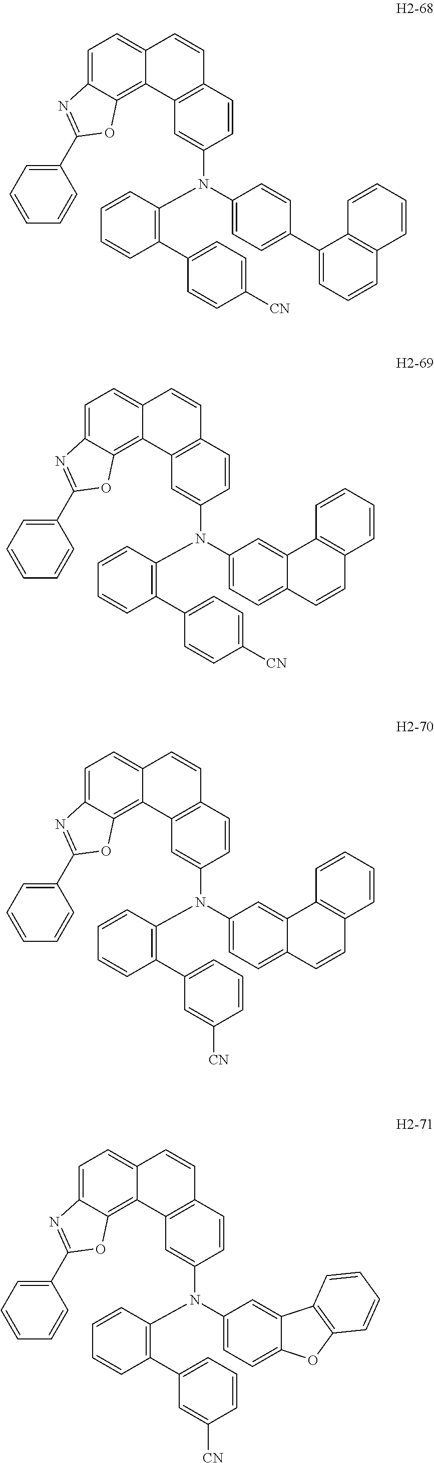 [SMILES: N#Cc1ccc(-c2ccccc2N(c2ccc(-c3cccc4ccccc34)cc2)c2ccc3ccc4ccc5nc(-c6ccccc6)oc5c4c3c2)cc1 ; N#Cc1ccc(-c2ccccc2N(c2ccc3ccc4ccccc4c3c2)c2ccc3ccc4ccc5nc(-c6ccccc6)oc5c4c3c2)cc1 ; N#Cc1cccc(-c2ccccc2N(c2ccc3ccc4ccccc4c3c2)c2ccc3ccc4ccc5nc(-c6ccccc6)oc5c4c3c2)c1 ; N#Cc1cccc(-c2ccccc2N(c2ccc3oc4ccccc4c3c2)c2ccc3ccc4ccc5nc(-c6ccccc6)oc5c4c3c2)c1]

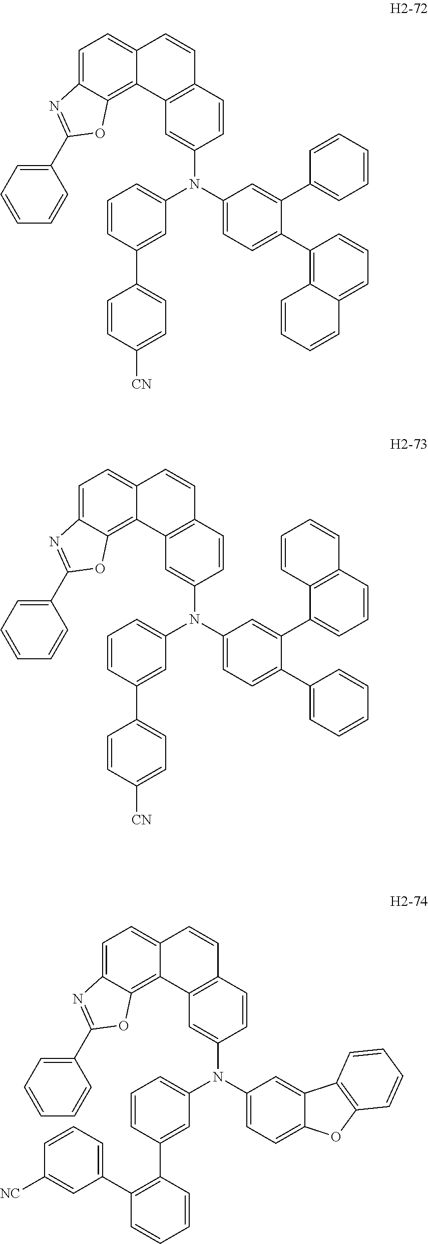 [SMILES: N#Cc1ccc(-c2cccc(N(c3ccc(-c4cccc5ccccc45)c(-c4ccccc4)c3)c3ccc4ccc5ccc6nc(-c7ccccc7)oc6c5c4c3)c2)cc1 ; N#Cc1ccc(-c2cccc(N(c3ccc(-c4ccccc4)c(-c4cccc5ccccc45)c3)c3ccc4ccc5ccc6nc(-c7ccccc7)oc6c5c4c3)c2)cc1 ; N#Cc1cccc(-c2ccccc2-c2cccc(N(c3ccc4oc5ccccc5c4c3)c3ccc4ccc5ccc6nc(-c7ccccc7)oc6c5c4c3)c2)c1]

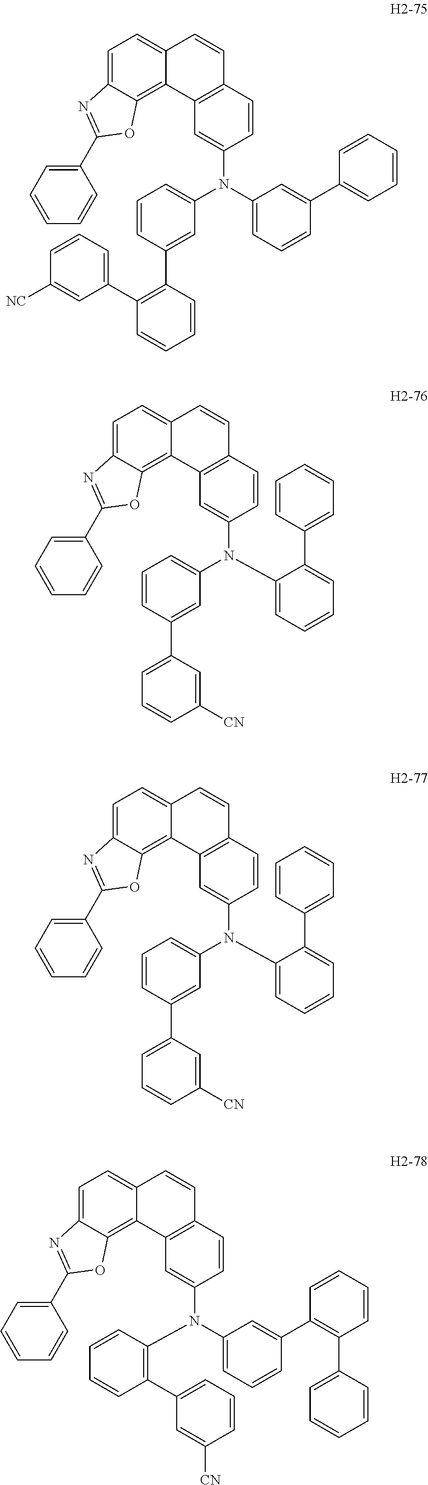 [SMILES: N#Cc1cccc(-c2ccccc2-c2cccc(N(c3cccc(-c4ccccc4)c3)c3ccc4ccc5ccc6nc(-c7ccccc7)oc6c5c4c3)c2)c1 ; N#Cc1cccc(-c2cccc(N(c3ccc4ccc5ccc6nc(-c7ccccc7)oc6c5c4c3)c3ccccc3-c3ccccc3)c2)c1 ; N#Cc1cccc(-c2cccc(N(c3ccc4ccc5ccc6nc(-c7ccccc7)oc6c5c4c3)c3ccccc3-c3ccccc3)c2)c1 ; N#Cc1cccc(-c2ccccc2N(c2cccc(-c3ccccc3-c3ccccc3)c2)c2ccc3ccc4ccc5nc(-c6ccccc6)oc5c4c3c2)c1]

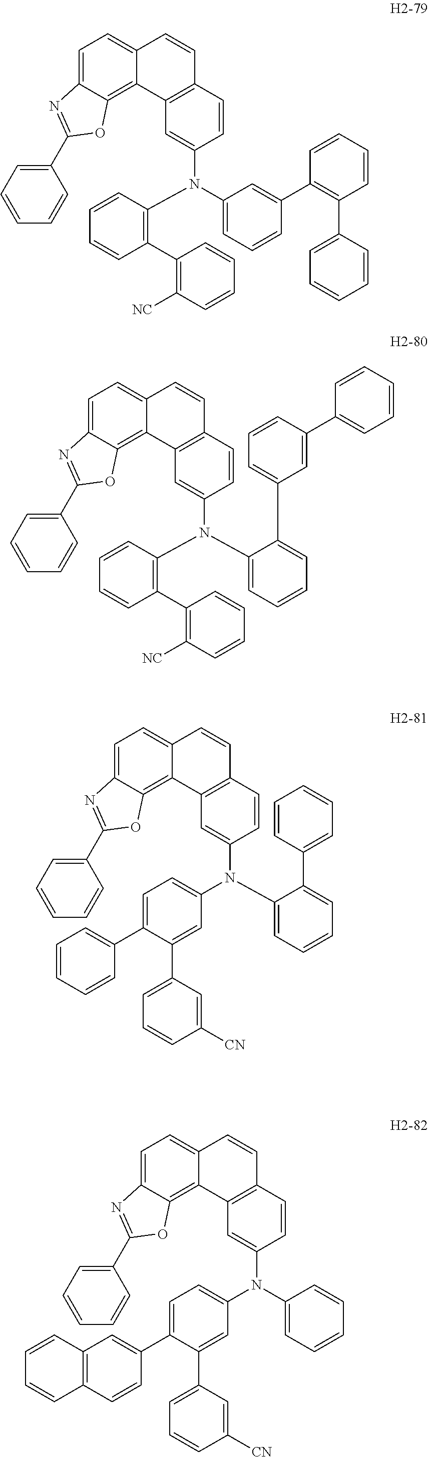 [SMILES: N#Cc1ccccc1-c1ccccc1N(c1cccc(-c2ccccc2-c2ccccc2)c1)c1ccc2ccc3ccc4nc(-c5ccccc5)oc4c3c2c1 ; N#Cc1ccccc1-c1ccccc1N(c1ccc2ccc3ccc4nc(-c5ccccc5)oc4c3c2c1)c1ccccc1-c1cccc(-c2ccccc2)c1 ; N#Cc1cccc(-c2cc(N(c3ccc4ccc5ccc6nc(-c7ccccc7)oc6c5c4c3)c3ccccc3-c3ccccc3)ccc2-c2ccccc2)c1 ; N#Cc1cccc(-c2cc(N(c3ccccc3)c3ccc4ccc5ccc6nc(-c7ccccc7)oc6c5c4c3)ccc2-c2ccc3ccccc3c2)c1]

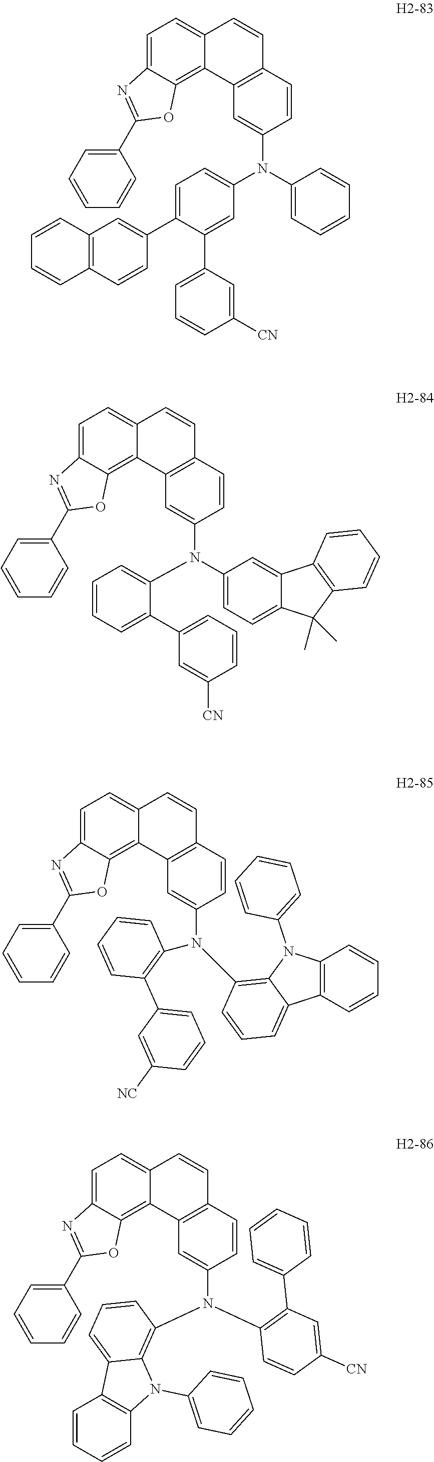 [SMILES: N#Cc1cccc(-c2cc(N(c3ccccc3)c3ccc4ccc5ccc6nc(-c7ccccc7)oc6c5c4c3)ccc2-c2ccc3ccccc3c2)c1 ; CC1(C)c2ccccc2-c2cc(N(c3ccc4ccc5ccc6nc(-c7ccccc7)oc6c5c4c3)c3ccccc3-c3cccc(C#N)c3)ccc21 ; N#Cc1cccc(-c2ccccc2N(c2ccc3ccc4ccc5nc(-c6ccccc6)oc5c4c3c2)c2cccc3c4ccccc4n(-c4ccccc4)c23)c1 ; N#Cc1ccc(N(c2ccc3ccc4ccc5nc(-c6ccccc6)oc5c4c3c2)c2cccc3c4ccccc4n(-c4ccccc4)c23)c(-c2ccccc2)c1]

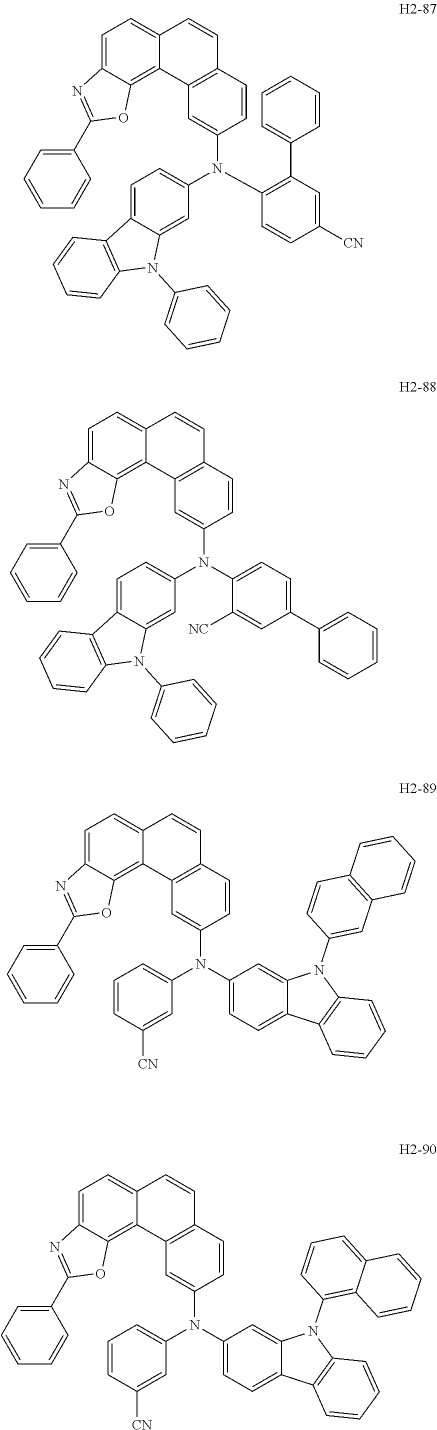 [SMILES: N#Cc1ccc(N(c2ccc3ccc4ccc5nc(-c6ccccc6)oc5c4c3c2)c2ccc3c4ccccc4n(-c4ccccc4)c3c2)c(-c2ccccc2)c1 ; N#Cc1cc(-c2ccccc2)ccc1N(c1ccc2ccc3ccc4nc(-c5ccccc5)oc4c3c2c1)c1ccc2c3ccccc3n(-c3ccccc3)c2c1 ; N#Cc1cccc(N(c2ccc3ccc4ccc5nc(-c6ccccc6)oc5c4c3c2)c2ccc3c4ccccc4n(-c4ccc5ccccc5c4)c3c2)c1 ; N#Cc1cccc(N(c2ccc3ccc4ccc5nc(-c6ccccc6)oc5c4c3c2)c2ccc3c4ccccc4n(-c4cccc5ccccc45)c3c2)c1]

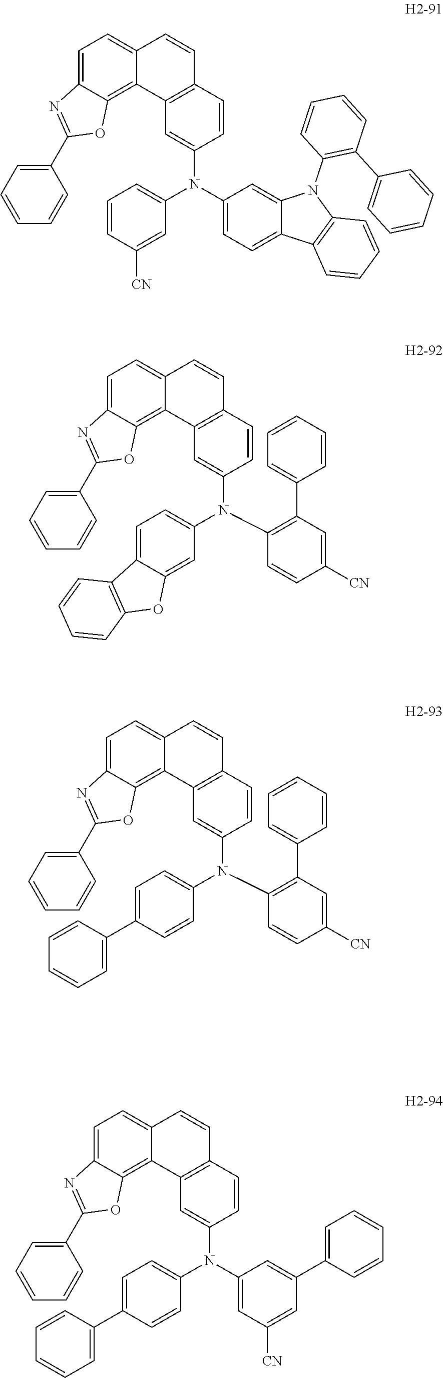 [SMILES: N#Cc1cccc(N(c2ccc3ccc4ccc5nc(-c6ccccc6)oc5c4c3c2)c2ccc3c4ccccc4n(-c4ccccc4-c4ccccc4)c3c2)c1 ; N#Cc1ccc(N(c2ccc3c(c2)oc2ccccc23)c2ccc3ccc4ccc5nc(-c6ccccc6)oc5c4c3c2)c(-c2ccccc2)c1 ; N#Cc1ccc(N(c2ccc(-c3ccccc3)cc2)c2ccc3ccc4ccc5nc(-c6ccccc6)oc5c4c3c2)c(-c2ccccc2)c1 ; N#Cc1cc(-c2ccccc2)cc(N(c2ccc(-c3ccccc3)cc2)c2ccc3ccc4ccc5nc(-c6ccccc6)oc5c4c3c2)c1]

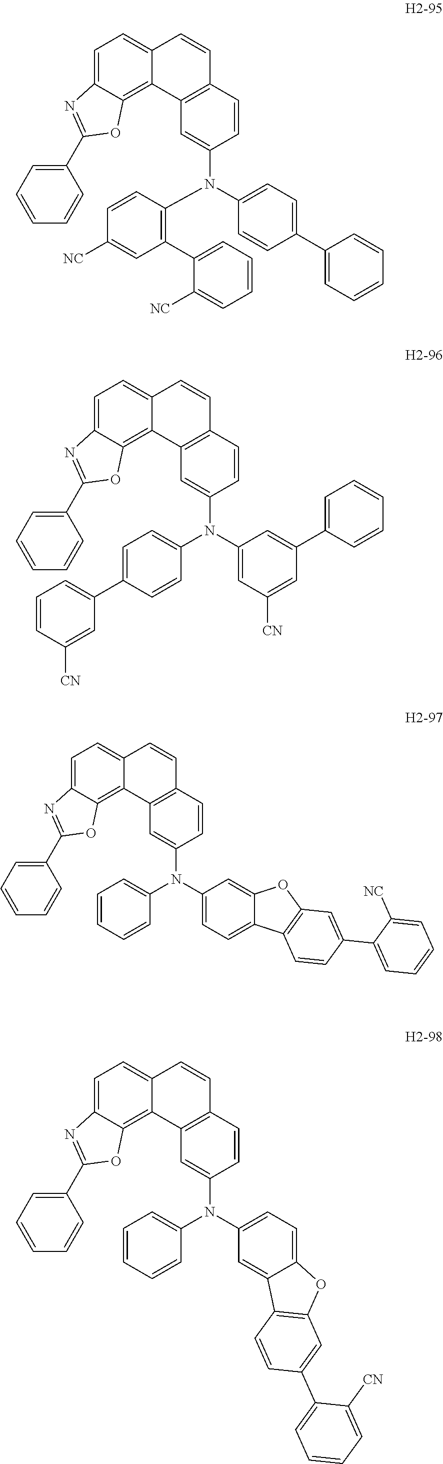 [SMILES: N#Cc1ccc(N(c2ccc(-c3ccccc3)cc2)c2ccc3ccc4ccc5nc(-c6ccccc6)oc5c4c3c2)c(-c2ccccc2C#N)c1 ; N#Cc1cccc(-c2ccc(N(c3cc(C#N)cc(-c4ccccc4)c3)c3ccc4ccc5ccc6nc(-c7ccccc7)oc6c5c4c3)cc2)c1 ; N#Cc1ccccc1-c1ccc2c(c1)oc1cc(N(c3ccccc3)c3ccc4ccc5ccc6nc(-c7ccccc7)oc6c5c4c3)ccc12 ; N#Cc1ccccc1-c1ccc2c(c1)oc1ccc(N(c3ccccc3)c3ccc4ccc5ccc6nc(-c7ccccc7)oc6c5c4c3)cc12]

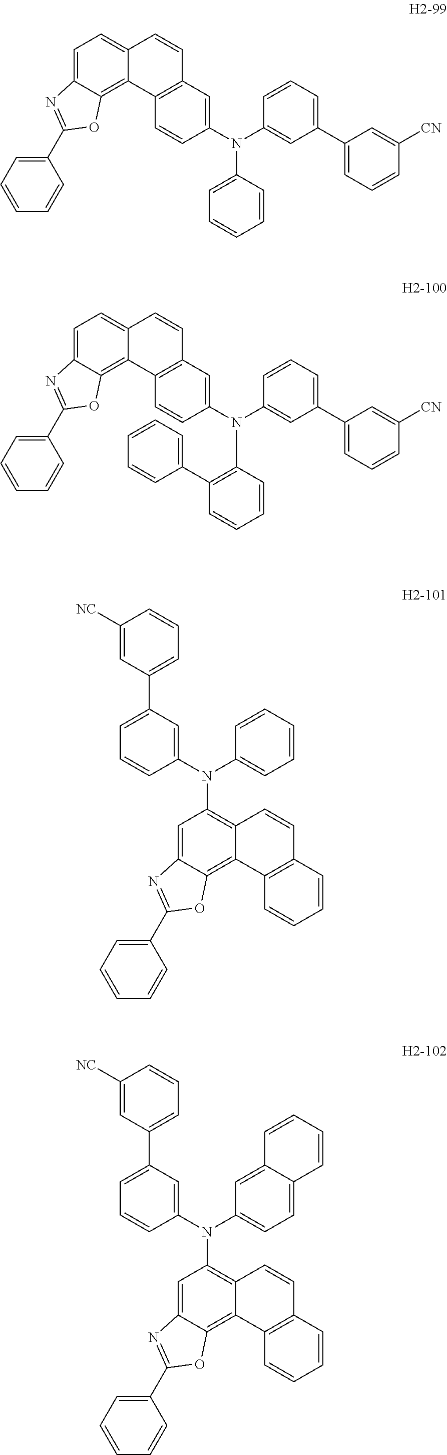 [SMILES: N#Cc1cccc(-c2cccc(N(c3ccccc3)c3ccc4c(ccc5ccc6nc(-c7ccccc7)oc6c54)c3)c2)c1 ; N#Cc1cccc(-c2cccc(N(c3ccc4c(ccc5ccc6nc(-c7ccccc7)oc6c54)c3)c3ccccc3-c3ccccc3)c2)c1 ; N#Cc1cccc(-c2cccc(N(c3ccccc3)c3cc4nc(-c5ccccc5)oc4c4c3ccc3ccccc34)c2)c1 ; N#Cc1cccc(-c2cccc(N(c3ccc4ccccc4c3)c3cc4nc(-c5ccccc5)oc4c4c3ccc3ccccc34)c2)c1]

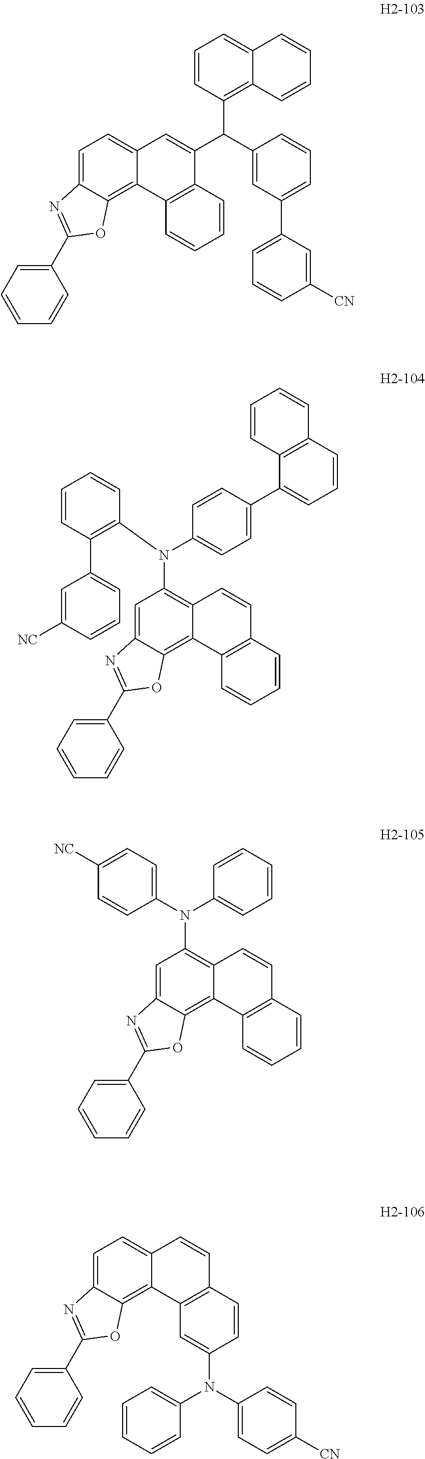 [SMILES: N#Cc1cccc(-c2cccc(C(c3cccc4ccccc34)c3cc4ccc5nc(-c6ccccc6)oc5c4c4ccccc34)c2)c1 ; N#Cc1cccc(-c2ccccc2N(c2ccc(-c3cccc4ccccc34)cc2)c2cc3nc(-c4ccccc4)oc3c3c2ccc2ccccc23)c1 ; N#Cc1ccc(N(c2ccccc2)c2cc3nc(-c4ccccc4)oc3c3c2ccc2ccccc23)cc1 ; N#Cc1ccc(N(c2ccccc2)c2ccc3ccc4ccc5nc(-c6ccccc6)oc5c4c3c2)cc1]

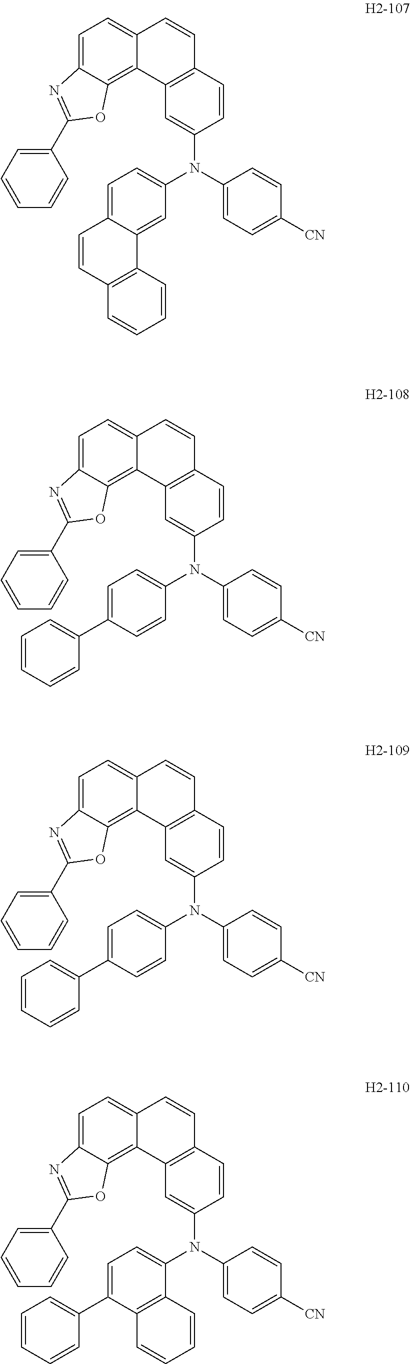 [SMILES: N#Cc1ccc(N(c2ccc3ccc4ccccc4c3c2)c2ccc3ccc4ccc5nc(-c6ccccc6)oc5c4c3c2)cc1 ; N#Cc1ccc(N(c2ccc(-c3ccccc3)cc2)c2ccc3ccc4ccc5nc(-c6ccccc6)oc5c4c3c2)cc1 ; N#Cc1ccc(N(c2ccc(-c3ccccc3)cc2)c2ccc3ccc4ccc5nc(-c6ccccc6)oc5c4c3c2)cc1 ; N#Cc1ccc(N(c2ccc3ccc4ccc5nc(-c6ccccc6)oc5c4c3c2)c2ccc(-c3ccccc3)c3ccccc23)cc1]

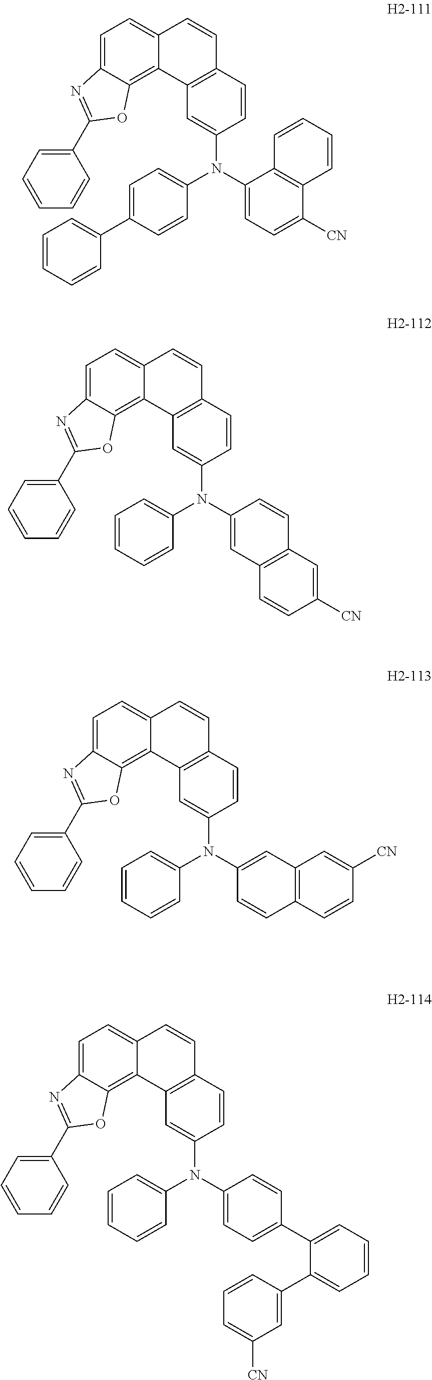 [SMILES: N#Cc1ccc(N(c2ccc(-c3ccccc3)cc2)c2ccc3ccc4ccc5nc(-c6ccccc6)oc5c4c3c2)c2ccccc12 ; N#Cc1ccc2cc(N(c3ccccc3)c3ccc4ccc5ccc6nc(-c7ccccc7)oc6c5c4c3)ccc2c1 ; N#Cc1ccc2ccc(N(c3ccccc3)c3ccc4ccc5ccc6nc(-c7ccccc7)oc6c5c4c3)cc2c1 ; N#Cc1cccc(-c2ccccc2-c2ccc(N(c3ccccc3)c3ccc4ccc5ccc6nc(-c7ccccc7)oc6c5c4c3)cc2)c1]

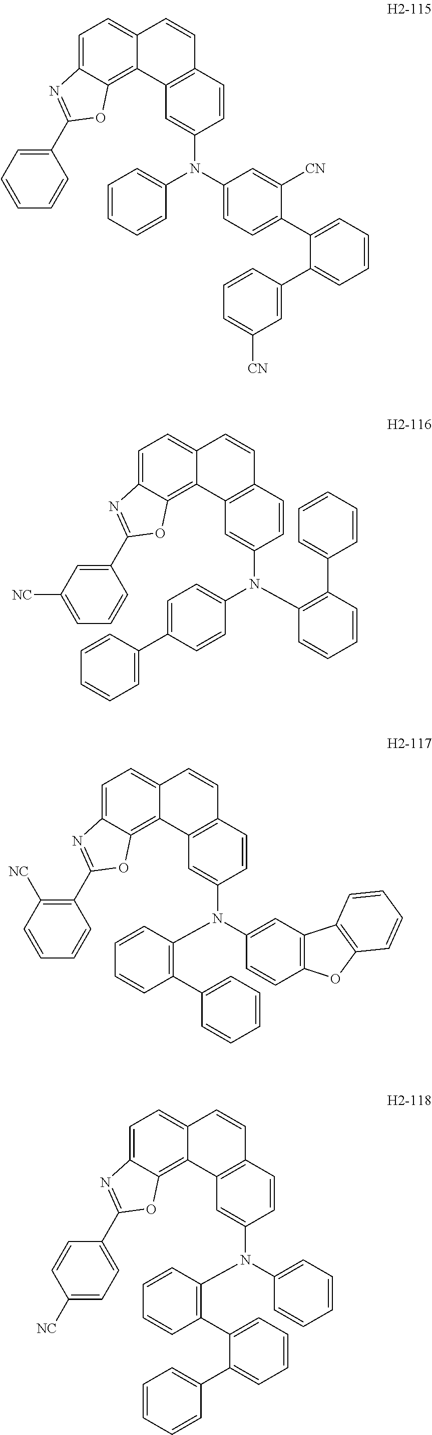 [SMILES: N#Cc1cccc(-c2ccccc2-c2ccc(N(c3ccccc3)c3ccc4ccc5ccc6nc(-c7ccccc7)oc6c5c4c3)cc2C#N)c1 ; N#Cc1cccc(-c2nc3ccc4ccc5ccc(N(c6ccc(-c7ccccc7)cc6)c6ccccc6-c6ccccc6)cc5c4c3o2)c1 ; N#Cc1ccccc1-c1nc2ccc3ccc4ccc(N(c5ccc6oc7ccccc7c6c5)c5ccccc5-c5ccccc5)cc4c3c2o1 ; N#Cc1ccc(-c2nc3ccc4ccc5ccc(N(c6ccccc6)c6ccccc6-c6ccccc6-c6ccccc6)cc5c4c3o2)cc1]

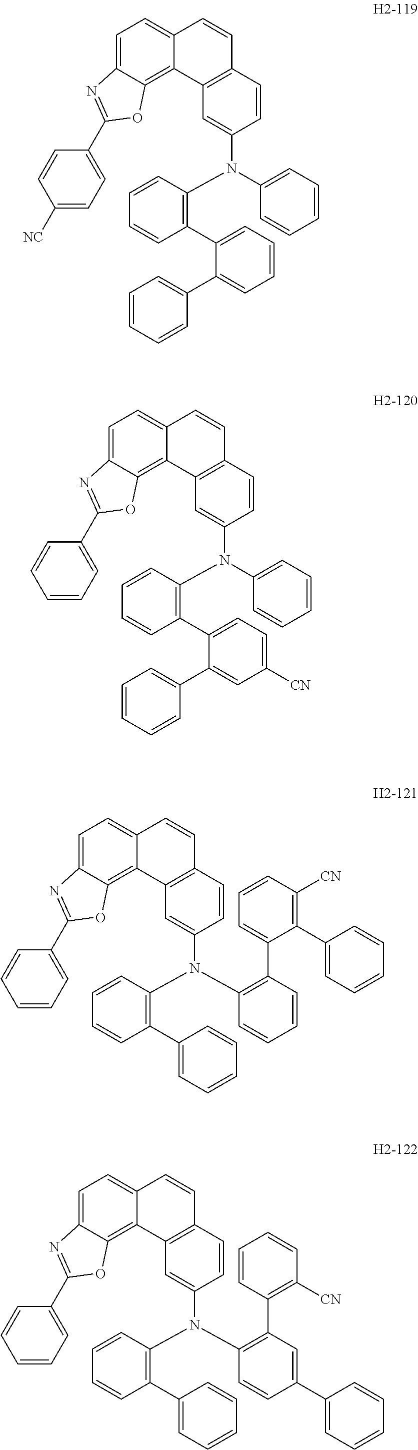 [SMILES: N#Cc1ccc(-c2nc3ccc4ccc5ccc(N(c6ccccc6)c6ccccc6-c6ccccc6-c6ccccc6)cc5c4c3o2)cc1 ; N#Cc1ccc(-c2ccccc2N(c2ccccc2)c2ccc3ccc4ccc5nc(-c6ccccc6)oc5c4c3c2)c(-c2ccccc2)c1 ; N#Cc1cccc(-c2ccccc2N(c2ccc3ccc4ccc5nc(-c6ccccc6)oc5c4c3c2)c2ccccc2-c2ccccc2)c1-c1ccccc1 ; N#Cc1ccccc1-c1cc(-c2ccccc2)ccc1N(c1ccc2ccc3ccc4nc(-c5ccccc5)oc4c3c2c1)c1ccccc1-c1ccccc1]

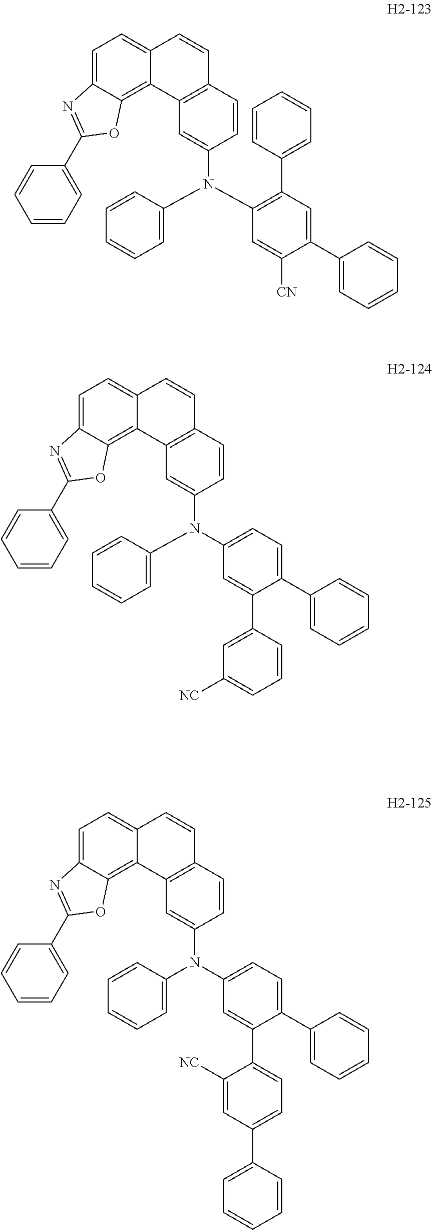 [SMILES: N#Cc1cc(N(c2ccccc2)c2ccc3ccc4ccc5nc(-c6ccccc6)oc5c4c3c2)c(-c2ccccc2)cc1-c1ccccc1 ; N#Cc1cccc(-c2cc(N(c3ccccc3)c3ccc4ccc5ccc6nc(-c7ccccc7)oc6c5c4c3)ccc2-c2ccccc2)c1 ; N#Cc1cc(-c2ccccc2)ccc1-c1cc(N(c2ccccc2)c2ccc3ccc4ccc5nc(-c6ccccc6)oc5c4c3c2)ccc1-c1ccccc1]

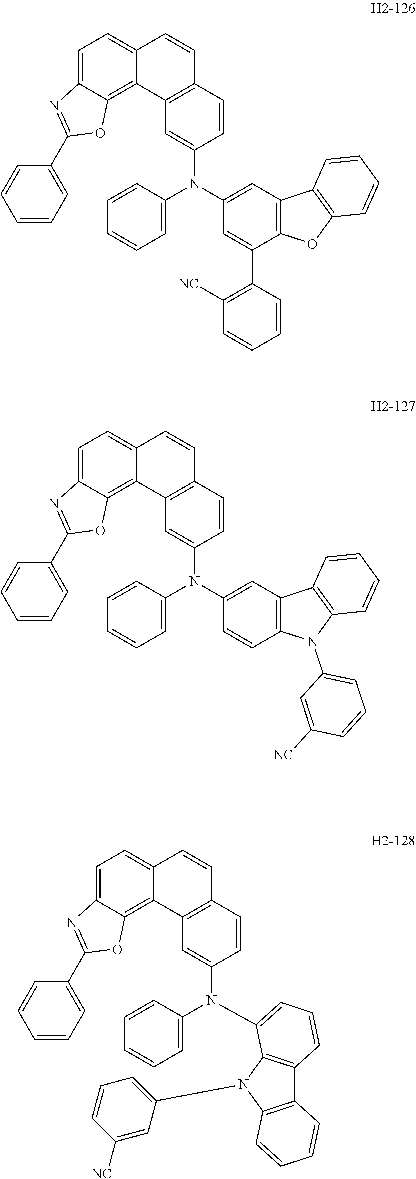 [SMILES: N#Cc1ccccc1-c1cc(N(c2ccccc2)c2ccc3ccc4ccc5nc(-c6ccccc6)oc5c4c3c2)cc2c1oc1ccccc12 ; N#Cc1cccc(-n2c3ccccc3c3cc(N(c4ccccc4)c4ccc5ccc6ccc7nc(-c8ccccc8)oc7c6c5c4)ccc32)c1 ; N#Cc1cccc(-n2c3ccccc3c3cccc(N(c4ccccc4)c4ccc5ccc6ccc7nc(-c8ccccc8)oc7c6c5c4)c32)c1]

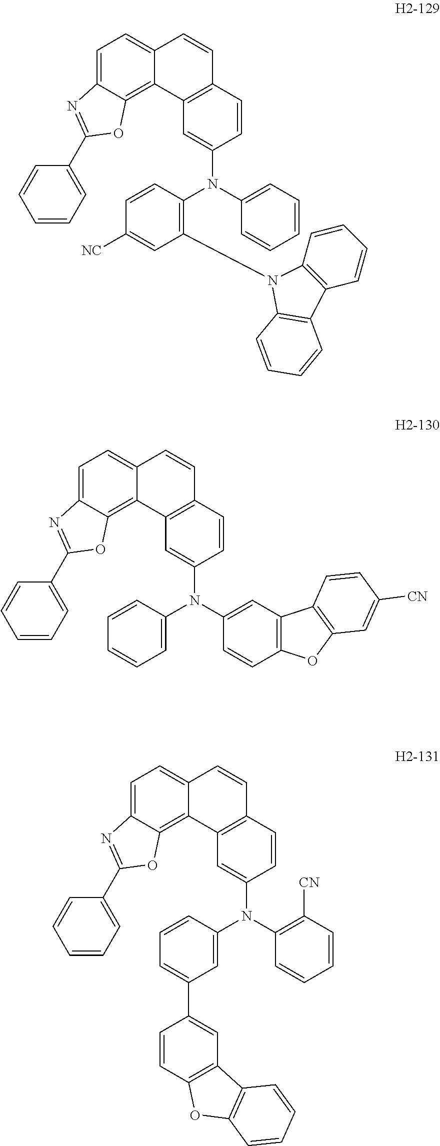 [SMILES: N#Cc1ccc(N(c2ccccc2)c2ccc3ccc4ccc5nc(-c6ccccc6)oc5c4c3c2)c(-n2c3ccccc3c3ccccc32)c1 ; N#Cc1ccc2c(c1)oc1ccc(N(c3ccccc3)c3ccc4ccc5ccc6nc(-c7ccccc7)oc6c5c4c3)cc12 ; N#Cc1ccccc1N(c1cccc(-c2ccc3oc4ccccc4c3c2)c1)c1ccc2ccc3ccc4nc(-c5ccccc5)oc4c3c2c1]

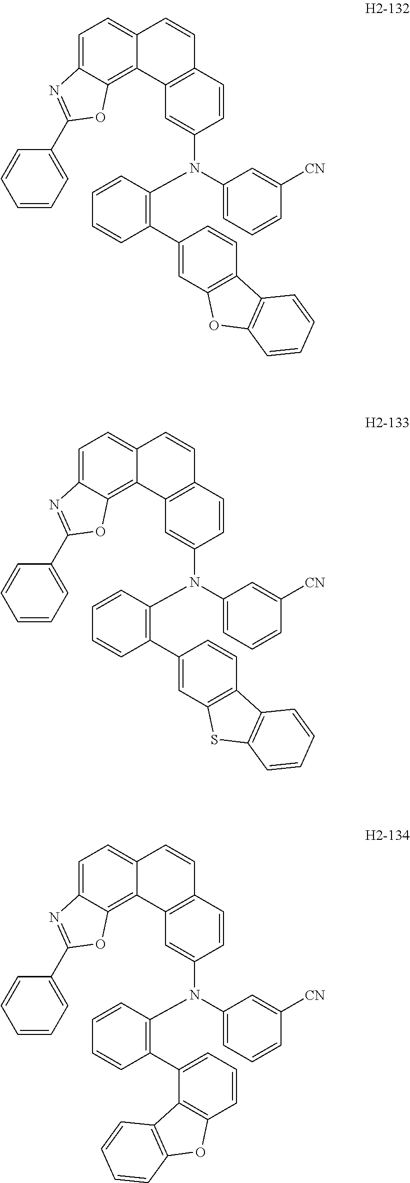 [SMILES: N#Cc1cccc(N(c2ccc3ccc4ccc5nc(-c6ccccc6)oc5c4c3c2)c2ccccc2-c2ccc3c(c2)oc2ccccc23)c1 ; N#Cc1cccc(N(c2ccc3ccc4ccc5nc(-c6ccccc6)oc5c4c3c2)c2ccccc2-c2ccc3c(c2)sc2ccccc23)c1 ; N#Cc1cccc(N(c2ccc3ccc4ccc5nc(-c6ccccc6)oc5c4c3c2)c2ccccc2-c2cccc3oc4ccccc4c23)c1]

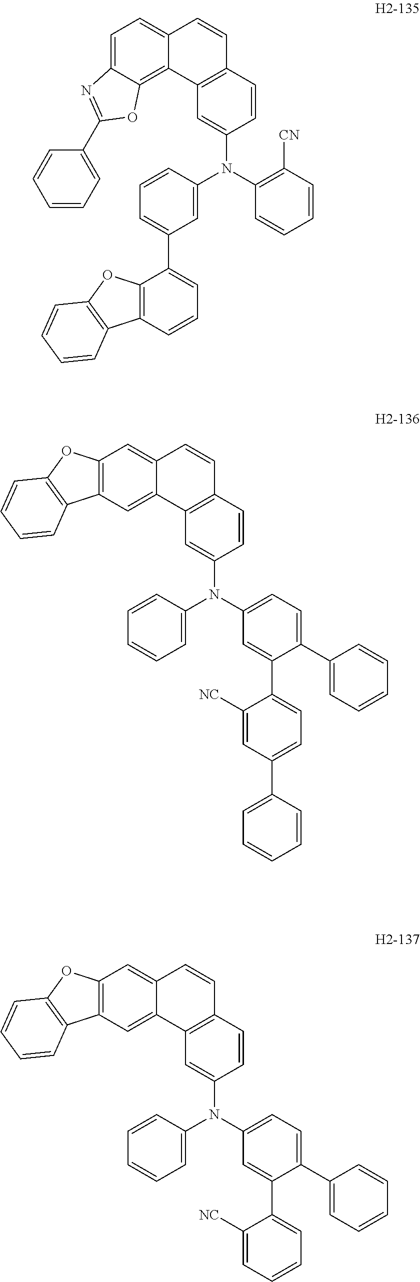 [SMILES: N#Cc1ccccc1N(c1cccc(-c2cccc3c2oc2ccccc23)c1)c1ccc2ccc3ccc4nc(-c5ccccc5)oc4c3c2c1 ; N#Cc1cc(-c2ccccc2)ccc1-c1cc(N(c2ccccc2)c2ccc3ccc4cc5oc6ccccc6c5cc4c3c2)ccc1-c1ccccc1 ; N#Cc1ccccc1-c1cc(N(c2ccccc2)c2ccc3ccc4cc5oc6ccccc6c5cc4c3c2)ccc1-c1ccccc1]

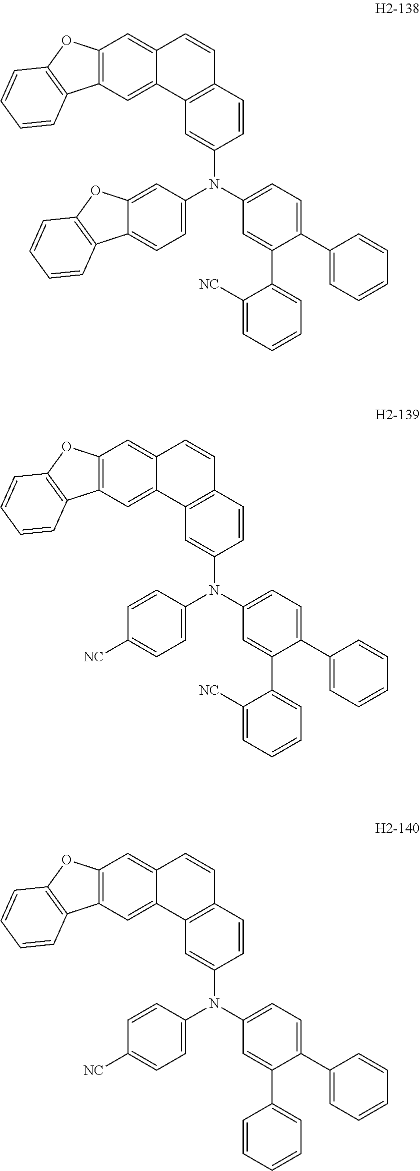 [SMILES: N#Cc1ccccc1-c1cc(N(c2ccc3c(c2)oc2ccccc23)c2ccc3ccc4cc5oc6ccccc6c5cc4c3c2)ccc1-c1ccccc1 ; N#Cc1ccc(N(c2ccc(-c3ccccc3)c(-c3ccccc3C#N)c2)c2ccc3ccc4cc5oc6ccccc6c5cc4c3c2)cc1 ; N#Cc1ccc(N(c2ccc(-c3ccccc3)c(-c3ccccc3)c2)c2ccc3ccc4cc5oc6ccccc6c5cc4c3c2)cc1]

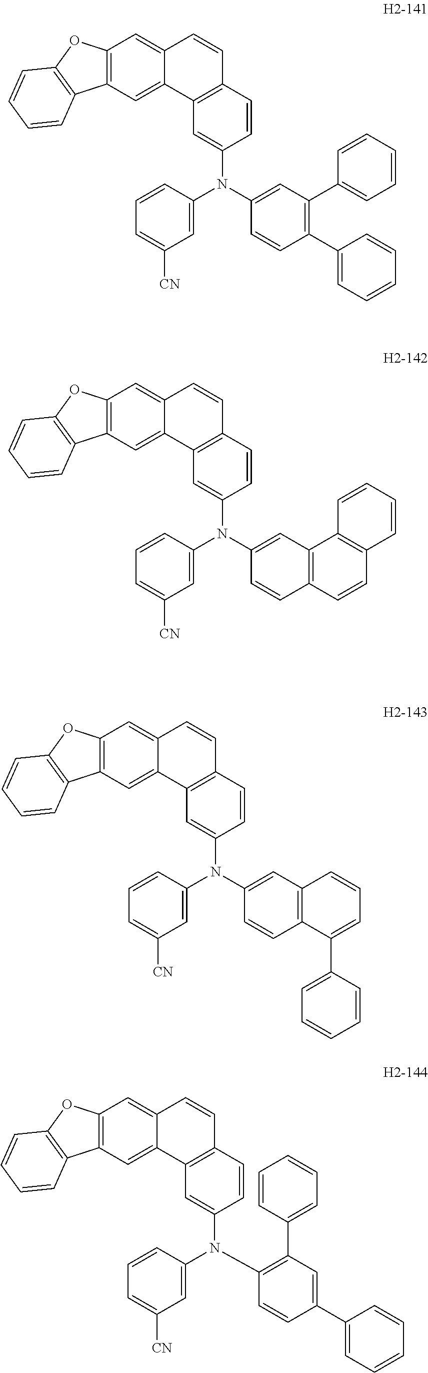 [SMILES: N#Cc1cccc(N(c2ccc(-c3ccccc3)c(-c3ccccc3)c2)c2ccc3ccc4cc5oc6ccccc6c5cc4c3c2)c1 ; N#Cc1cccc(N(c2ccc3ccc4ccccc4c3c2)c2ccc3ccc4cc5oc6ccccc6c5cc4c3c2)c1 ; N#Cc1cccc(N(c2ccc3c(-c4ccccc4)cccc3c2)c2ccc3ccc4cc5oc6ccccc6c5cc4c3c2)c1 ; N#Cc1cccc(N(c2ccc3ccc4cc5oc6ccccc6c5cc4c3c2)c2ccc(-c3ccccc3)cc2-c2ccccc2)c1]

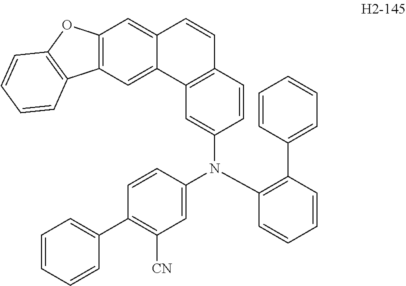 [SMILES: N#Cc1cc(N(c2ccc3ccc4cc5oc6ccccc6c5cc4c3c2)c2ccccc2-c2ccccc2)ccc1-c1ccccc1]

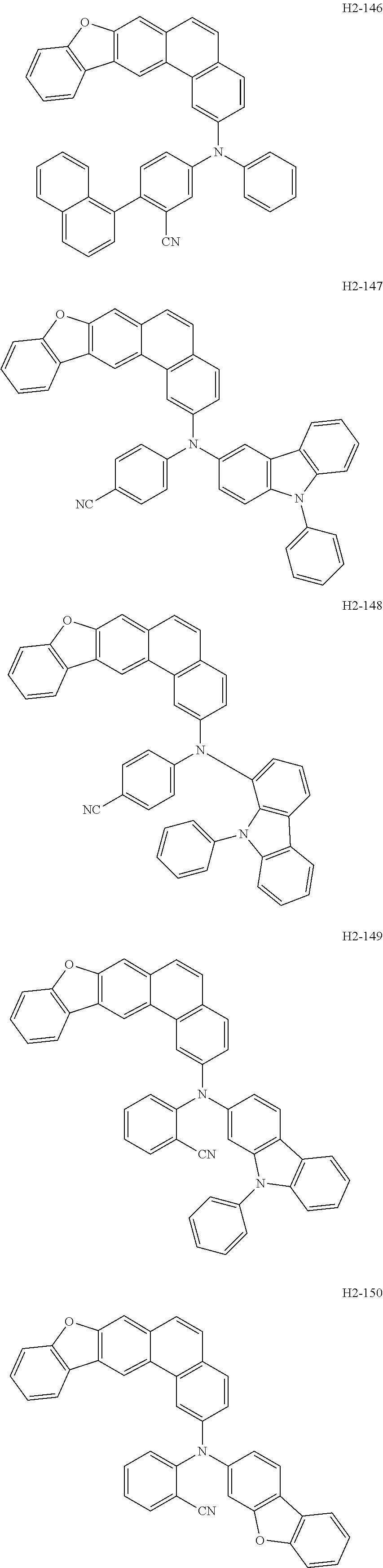 [SMILES: N#Cc1cc(N(c2ccccc2)c2ccc3ccc4cc5oc6ccccc6c5cc4c3c2)ccc1-c1cccc2ccccc12 ; N#Cc1ccc(N(c2ccc3ccc4cc5oc6ccccc6c5cc4c3c2)c2ccc3c(c2)c2ccccc2n3-c2ccccc2)cc1 ; N#Cc1ccc(N(Cc2cccc3c4ccccc4n(-c4ccccc4)c23)c2ccc3ccc4cc5oc6ccccc6c5cc4c3c2)cc1 ; N#Cc1ccccc1N(c1ccc2ccc3cc4oc5ccccc5c4cc3c2c1)c1ccc2c3ccccc3n(-c3ccccc3)c2c1 ; N#Cc1ccccc1N(c1ccc2c(c1)oc1ccccc12)c1ccc2ccc3cc4oc5ccccc5c4cc3c2c1]

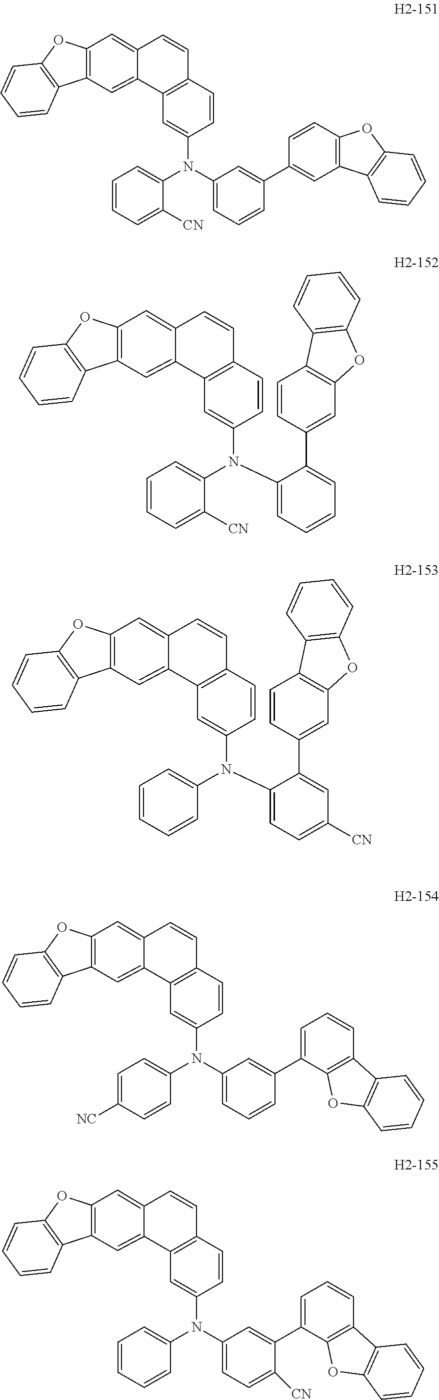 [SMILES: N#Cc1ccccc1N(c1cccc(-c2ccc3oc4ccccc4c3c2)c1)c1ccc2ccc3cc4oc5ccccc5c4cc3c2c1 ; N#Cc1ccccc1N(c1ccc2ccc3cc4oc5ccccc5c4cc3c2c1)c1ccccc1-c1ccc2c(c1)oc1ccccc12 ; N#Cc1ccc(N(c2ccccc2)c2ccc3ccc4cc5oc6ccccc6c5cc4c3c2)c(-c2ccc3c(c2)oc2ccccc23)c1 ; N#Cc1ccc(N(c2cccc(-c3cccc4c3oc3ccccc34)c2)c2ccc3ccc4cc5oc6ccccc6c5cc4c3c2)cc1 ; N#Cc1ccc(N(c2ccccc2)c2ccc3ccc4cc5oc6ccccc6c5cc4c3c2)cc1-c1cccc2c1oc1ccccc12]

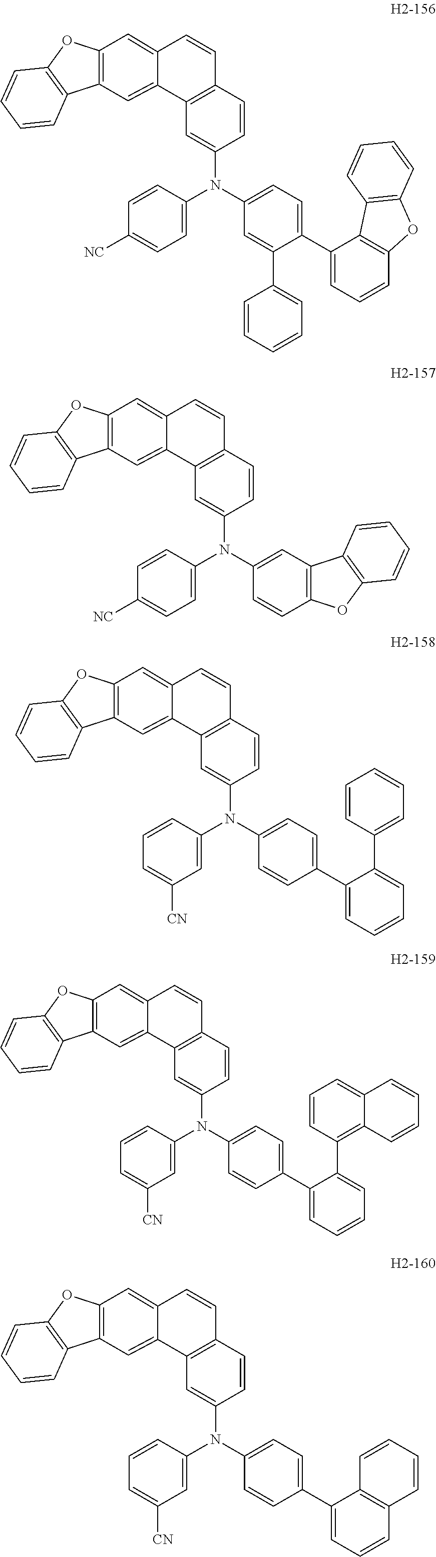 [SMILES: N#Cc1ccc(N(c2ccc(-c3cccc4oc5ccccc5c34)c(-c3ccccc3)c2)c2ccc3ccc4cc5oc6ccccc6c5cc4c3c2)cc1 ; N#Cc1ccc(N(c2ccc3ccc4cc5oc6ccccc6c5cc4c3c2)c2ccc3oc4ccccc4c3c2)cc1 ; N#Cc1cccc(N(c2ccc(-c3ccccc3-c3ccccc3)cc2)c2ccc3ccc4cc5oc6ccccc6c5cc4c3c2)c1 ; N#Cc1cccc(N(c2ccc(-c3ccccc3-c3cccc4ccccc34)cc2)c2ccc3ccc4cc5oc6ccccc6c5cc4c3c2)c1 ; N#Cc1cccc(N(c2ccc(-c3cccc4ccccc34)cc2)c2ccc3ccc4cc5oc6ccccc6c5cc4c3c2)c1]

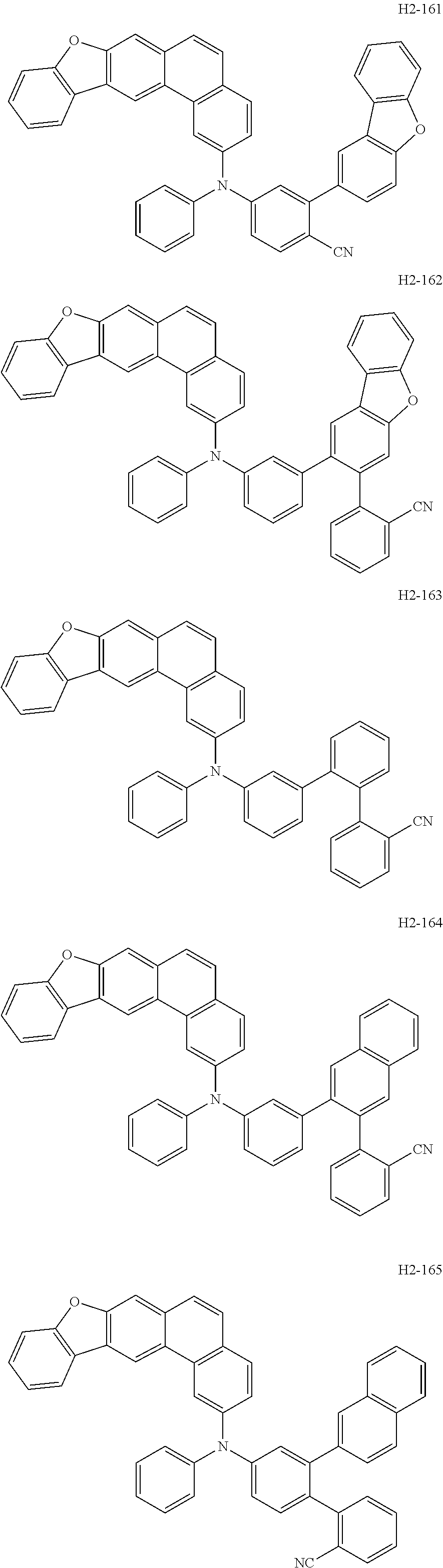 [SMILES: N#Cc1ccc(N(c2ccccc2)c2ccc3ccc4cc5oc6ccccc6c5cc4c3c2)cc1-c1ccc2oc3ccccc3c2c1 ; N#Cc1ccccc1-c1cc2oc3ccccc3c2cc1-c1cccc(N(c2ccccc2)c2ccc3ccc4cc5oc6ccccc6c5cc4c3c2)c1 ; N#Cc1ccccc1-c1ccccc1-c1cccc(N(c2ccccc2)c2ccc3ccc4cc5oc6ccccc6c5cc4c3c2)c1 ; N#Cc1ccccc1-c1cc2ccccc2cc1-c1cccc(N(c2ccccc2)c2ccc3ccc4cc5oc6ccccc6c5cc4c3c2)c1 ; N#Cc1ccccc1-c1ccc(N(c2ccccc2)c2ccc3ccc4cc5oc6ccccc6c5cc4c3c2)cc1-c1ccc2ccccc2c1]

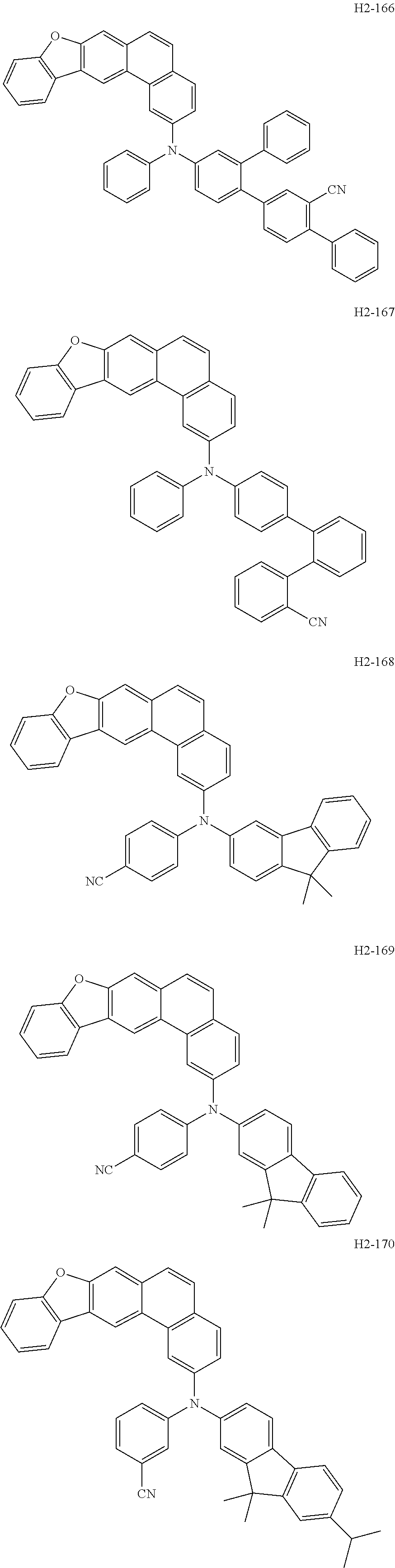 [SMILES: N#Cc1cc(-c2ccc(N(c3ccccc3)c3ccc4ccc5cc6oc7ccccc7c6cc5c4c3)cc2-c2ccccc2)ccc1-c1ccccc1 ; N#Cc1ccccc1-c1ccccc1-c1ccc(N(c2ccccc2)c2ccc3ccc4cc5oc6ccccc6c5cc4c3c2)cc1 ; CC1(C)c2ccccc2-c2cc(N(c3ccc(C#N)cc3)c3ccc4ccc5cc6oc7ccccc7c6cc5c4c3)ccc21 ; CC1(C)c2ccccc2-c2ccc(N(c3ccc(C#N)cc3)c3ccc4ccc5cc6oc7ccccc7c6cc5c4c3)cc21 ; CC(C)c1ccc2c(c1)C(C)(C)c1cc(N(c3cccc(C#N)c3)c3ccc4ccc5cc6oc7ccccc7c6cc5c4c3)ccc1-2]

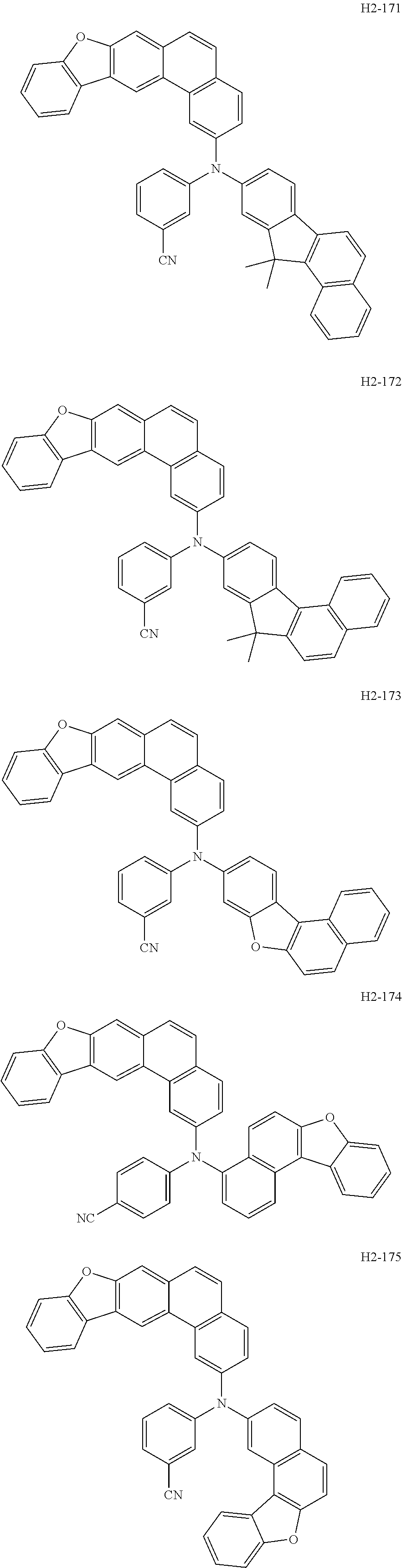 [SMILES: CC1(C)c2cc(N(c3cccc(C#N)c3)c3ccc4ccc5cc6oc7ccccc7c6cc5c4c3)ccc2-c2ccc3ccccc3c21 ; CC1(C)c2cc(N(c3cccc(C#N)c3)c3ccc4ccc5cc6oc7ccccc7c6cc5c4c3)ccc2-c2c1ccc1ccccc21 ; N#Cc1cccc(N(c2ccc3c(c2)oc2ccc4ccccc4c23)c2ccc3ccc4cc5oc6ccccc6c5cc4c3c2)c1 ; N#Cc1ccc(N(c2ccc3ccc4cc5oc6ccccc6c5cc4c3c2)c2cccc3c2ccc2oc4ccccc4c23)cc1 ; N#Cc1cccc(N(c2ccc3ccc4cc5oc6ccccc6c5cc4c3c2)c2ccc3ccc4oc5ccccc5c4c3c2)c1]

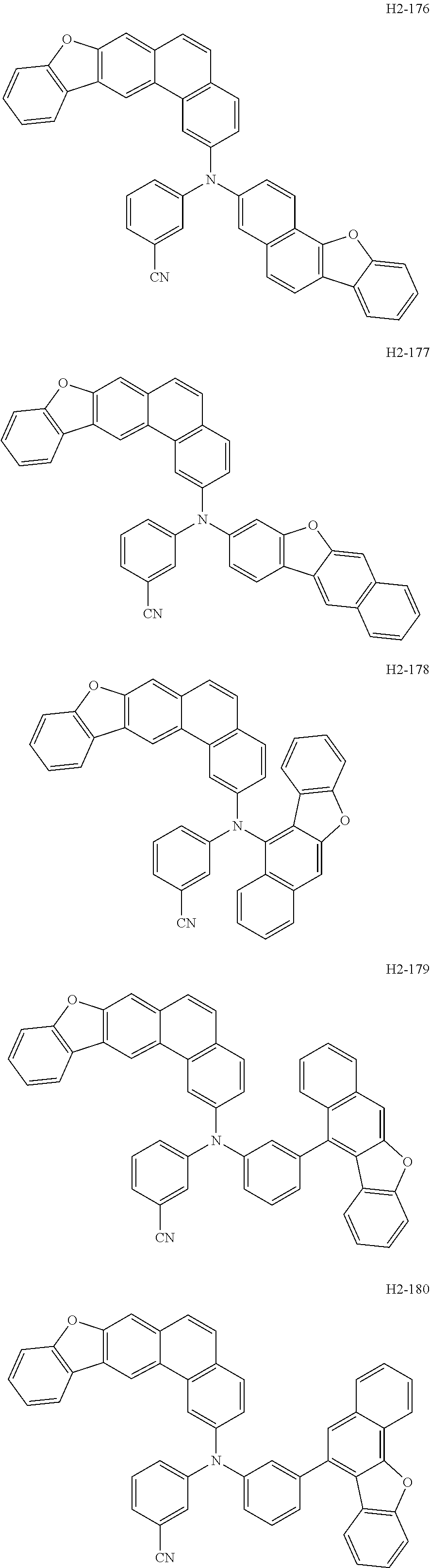 [SMILES: N#Cc1cccc(N(c2ccc3c(ccc4c5ccccc5oc34)c2)c2ccc3ccc4cc5oc6ccccc6c5cc4c3c2)c1 ; N#Cc1cccc(N(c2ccc3c(c2)oc2cc4ccccc4cc23)c2ccc3ccc4cc5oc6ccccc6c5cc4c3c2)c1 ; N#Cc1cccc(N(c2ccc3ccc4cc5oc6ccccc6c5cc4c3c2)c2c3ccccc3cc3oc4ccccc4c23)c1 ; N#Cc1cccc(N(c2cccc(-c3c4ccccc4cc4oc5ccccc5c34)c2)c2ccc3ccc4cc5oc6ccccc6c5cc4c3c2)c1 ; N#Cc1cccc(N(c2cccc(-c3cc4ccccc4c4oc5ccccc5c34)c2)c2ccc3ccc4cc5oc6ccccc6c5cc4c3c2)c1]

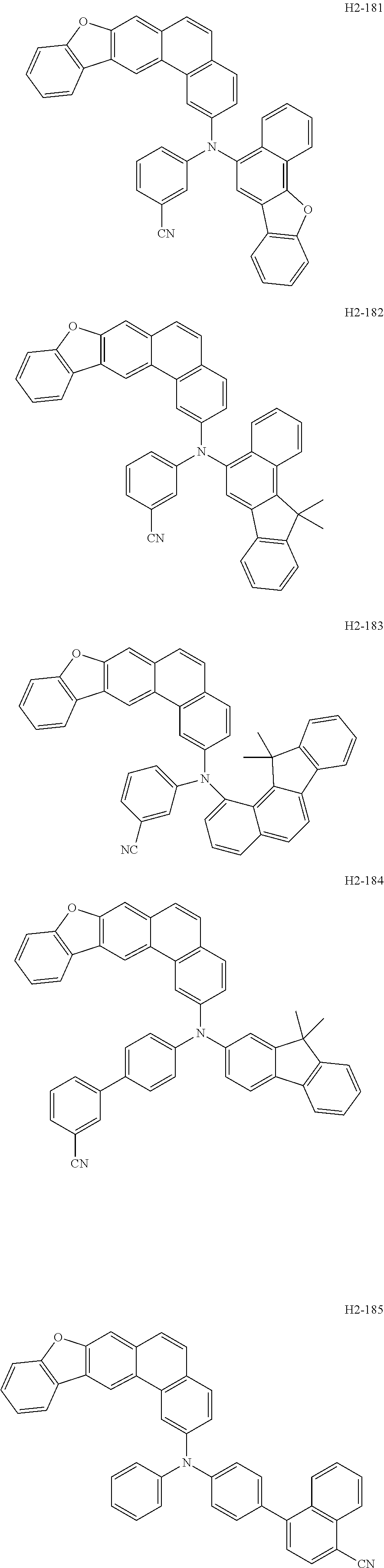 [SMILES: N#Cc1cccc(N(c2ccc3ccc4cc5oc6ccccc6c5cc4c3c2)c2cc3c4ccccc4oc3c3ccccc23)c1 ; CC1(C)c2ccccc2-c2cc(N(c3cccc(C#N)c3)c3ccc4ccc5cc6oc7ccccc7c6cc5c4c3)c3ccccc3c21 ; CC1(C)c2ccccc2-c2ccc3cccc(N(c4cccc(C#N)c4)c4ccc5ccc6cc7oc8ccccc8c7cc6c5c4)c3c21 ; CC1(C)c2ccccc2-c2ccc(N(c3ccc(-c4cccc(C#N)c4)cc3)c3ccc4ccc5cc6oc7ccccc7c6cc5c4c3)cc21 ; N#Cc1ccc(-c2ccc(N(c3ccccc3)c3ccc4ccc5cc6oc7ccccc7c6cc5c4c3)cc2)c2ccccc12]

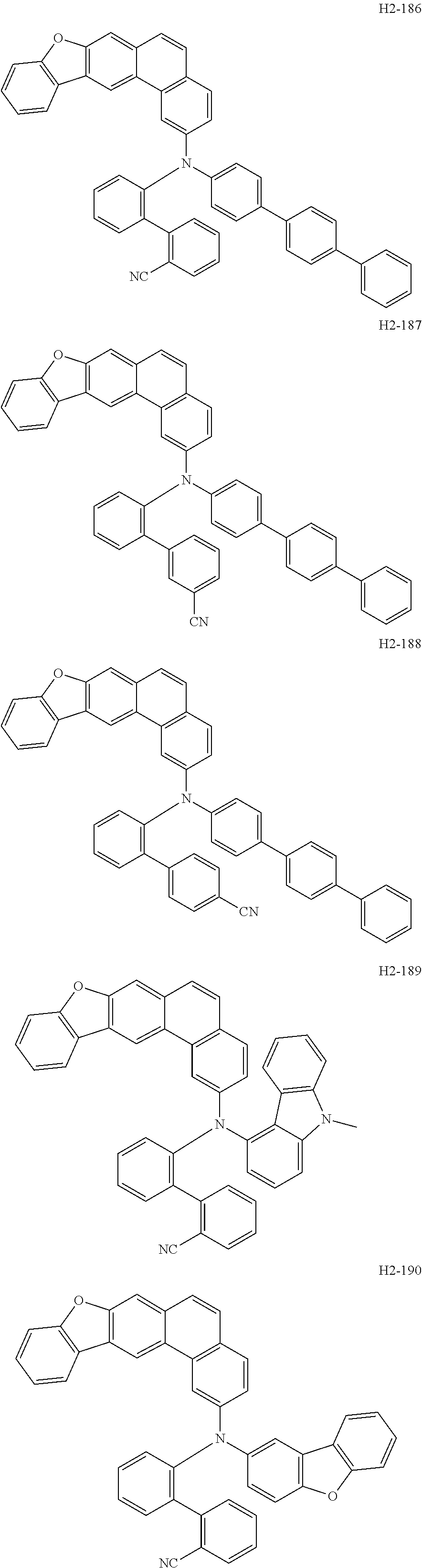 [SMILES: N#Cc1ccccc1-c1ccccc1N(c1ccc(-c2ccc(-c3ccccc3)cc2)cc1)c1ccc2ccc3cc4oc5ccccc5c4cc3c2c1 ; N#Cc1cccc(-c2ccccc2N(c2ccc(-c3ccc(-c4ccccc4)cc3)cc2)c2ccc3ccc4cc5oc6ccccc6c5cc4c3c2)c1 ; N#Cc1ccc(-c2ccccc2N(c2ccc(-c3ccc(-c4ccccc4)cc3)cc2)c2ccc3ccc4cc5oc6ccccc6c5cc4c3c2)cc1 ; Cn1c2ccccc2c2c(N(c3ccc4ccc5cc6oc7ccccc7c6cc5c4c3)c3ccccc3-c3ccccc3C#N)cccc21 ; N#Cc1ccccc1-c1ccccc1N(c1ccc2ccc3cc4oc5ccccc5c4cc3c2c1)c1ccc2oc3ccccc3c2c1]

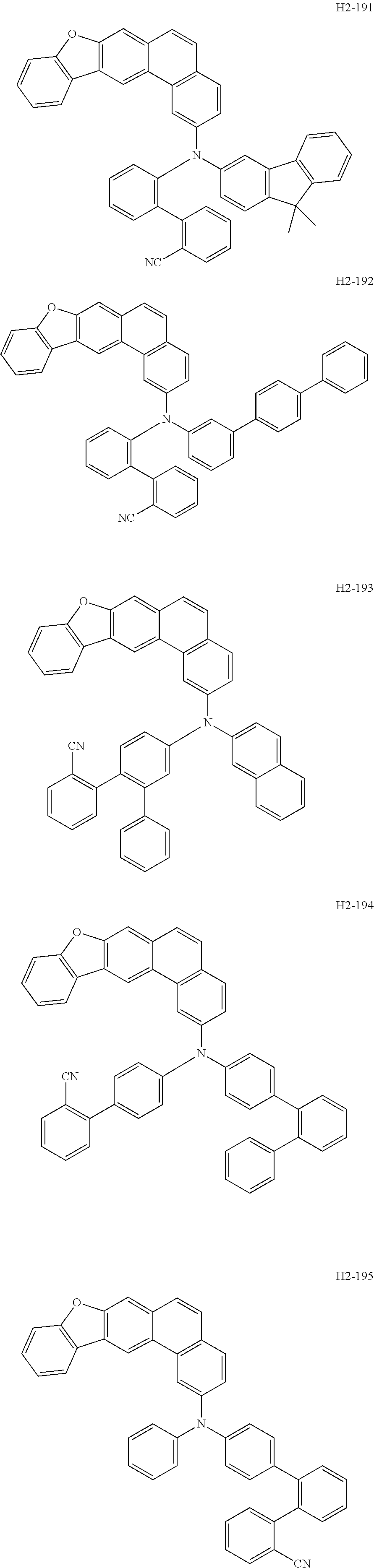 [SMILES: CC1(C)c2ccccc2-c2cc(N(c3ccc4ccc5cc6oc7ccccc7c6cc5c4c3)c3ccccc3-c3ccccc3C#N)ccc21 ; N#Cc1ccccc1-c1ccccc1N(c1cccc(-c2ccc(-c3ccccc3)cc2)c1)c1ccc2ccc3cc4oc5ccccc5c4cc3c2c1 ; N#Cc1ccccc1-c1ccc(N(c2ccc3ccccc3c2)c2ccc3ccc4cc5oc6ccccc6c5cc4c3c2)cc1-c1ccccc1 ; N#Cc1ccccc1-c1ccc(N(c2ccc(-c3ccccc3-c3ccccc3)cc2)c2ccc3ccc4cc5oc6ccccc6c5cc4c3c2)cc1 ; N#Cc1ccccc1-c1ccccc1-c1ccc(N(c2ccccc2)c2ccc3ccc4cc5oc6ccccc6c5cc4c3c2)cc1]

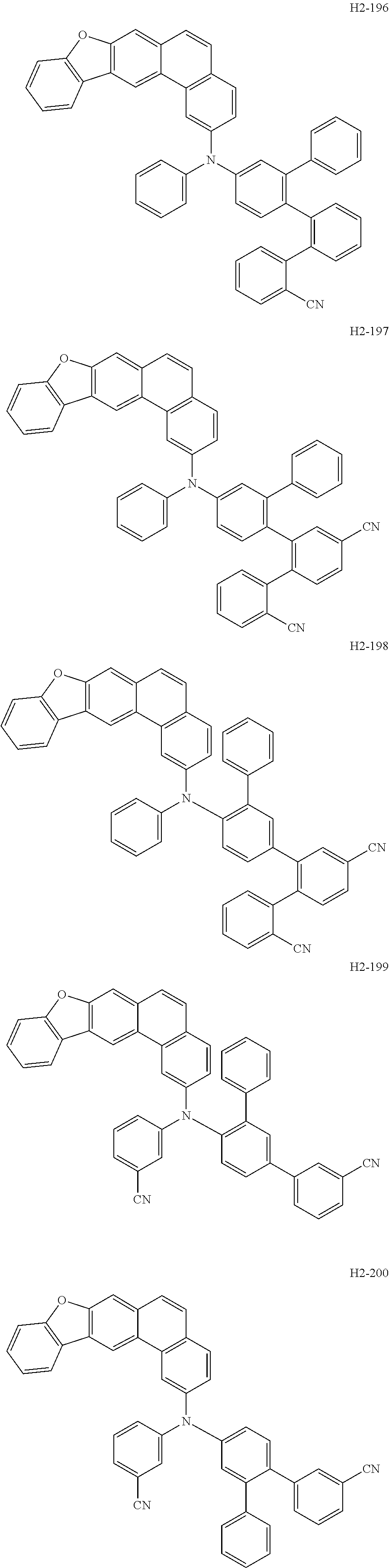 [SMILES: N#Cc1ccccc1-c1ccccc1-c1ccc(N(c2ccccc2)c2ccc3ccc4cc5oc6ccccc6c5cc4c3c2)cc1-c1ccccc1 ; N#Cc1ccc(-c2ccccc2C#N)c(-c2ccc(N(c3ccccc3)c3ccc4ccc5cc6oc7ccccc7c6cc5c4c3)cc2-c2ccccc2)c1 ; N#Cc1ccc(-c2ccccc2C#N)c(-c2ccc(N(c3ccccc3)c3ccc4ccc5cc6oc7ccccc7c6cc5c4c3)c(-c3ccccc3)c2)c1 ; N#Cc1cccc(-c2ccc(N(c3cccc(C#N)c3)c3ccc4ccc5cc6oc7ccccc7c6cc5c4c3)c(-c3ccccc3)c2)c1 ; N#Cc1cccc(-c2ccc(N(c3cccc(C#N)c3)c3ccc4ccc5cc6oc7ccccc7c6cc5c4c3)cc2-c2ccccc2)c1]

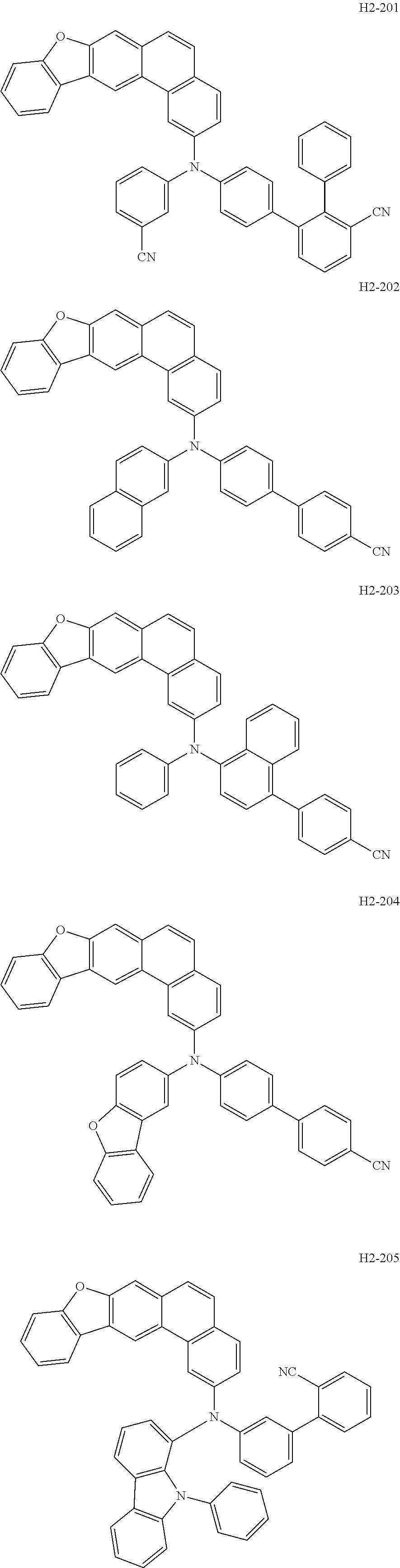 [SMILES: N#Cc1cccc(N(c2ccc(-c3cccc(C#N)c3-c3ccccc3)cc2)c2ccc3ccc4cc5oc6ccccc6c5cc4c3c2)c1 ; N#Cc1ccc(-c2ccc(N(c3ccc4ccccc4c3)c3ccc4ccc5cc6oc7ccccc7c6cc5c4c3)cc2)cc1 ; N#Cc1ccc(-c2ccc(N(c3ccccc3)c3ccc4ccc5cc6oc7ccccc7c6cc5c4c3)c3ccccc23)cc1 ; N#Cc1ccc(-c2ccc(N(c3ccc4ccc5cc6oc7ccccc7c6cc5c4c3)c3ccc4oc5ccccc5c4c3)cc2)cc1 ; N#Cc1ccccc1-c1cccc(N(c2ccc3ccc4cc5oc6ccccc6c5cc4c3c2)c2cccc3c4ccccc4n(-c4ccccc4)c23)c1]

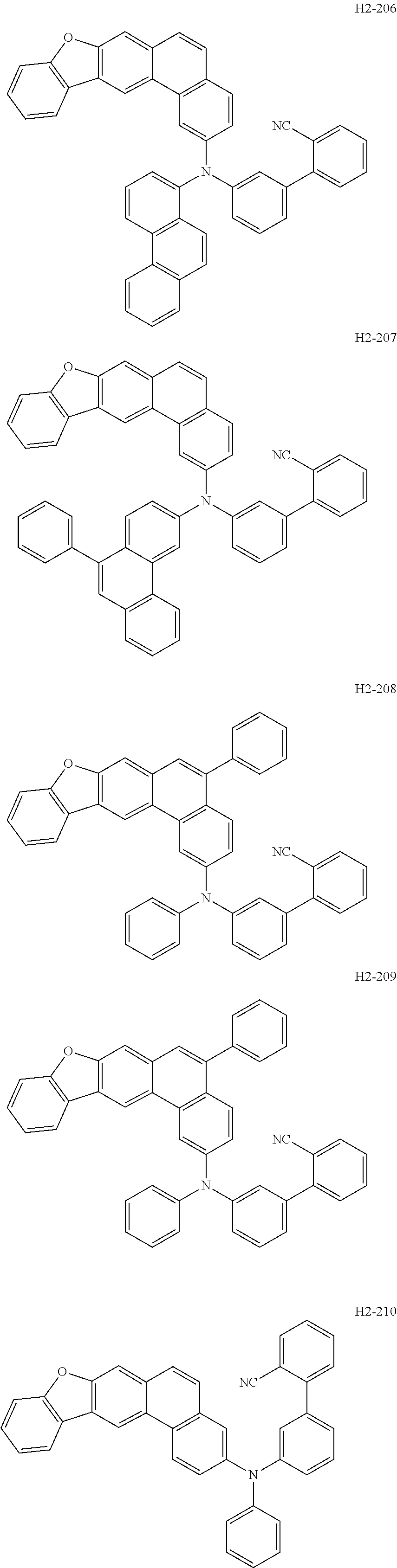

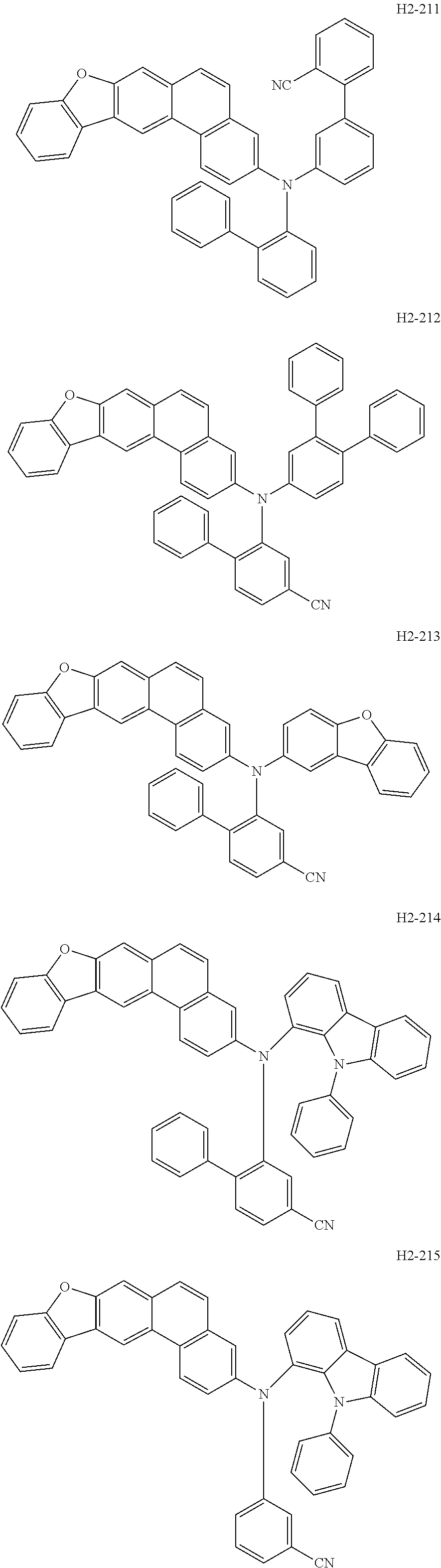 [SMILES: N#Cc1ccccc1-c1cccc(N(c2ccc3c(ccc4cc5oc6ccccc6c5cc43)c2)c2ccccc2-c2ccccc2)c1 ; N#Cc1ccc(-c2ccccc2)c(N(c2ccc(-c3ccccc3)c(-c3ccccc3)c2)c2ccc3c(ccc4cc5oc6ccccc6c5cc43)c2)c1 ; N#Cc1ccc(-c2ccccc2)c(N(c2ccc3c(ccc4cc5oc6ccccc6c5cc43)c2)c2ccc3oc4ccccc4c3c2)c1 ; N#Cc1ccc(-c2ccccc2)c(N(c2ccc3c(ccc4cc5oc6ccccc6c5cc43)c2)c2cccc3c4ccccc4n(-c4ccccc4)c23)c1 ; N#Cc1cccc(N(c2ccc3c(ccc4cc5oc6ccccc6c5cc43)c2)c2cccc3c4ccccc4n(-c4ccccc4)c23)c1]

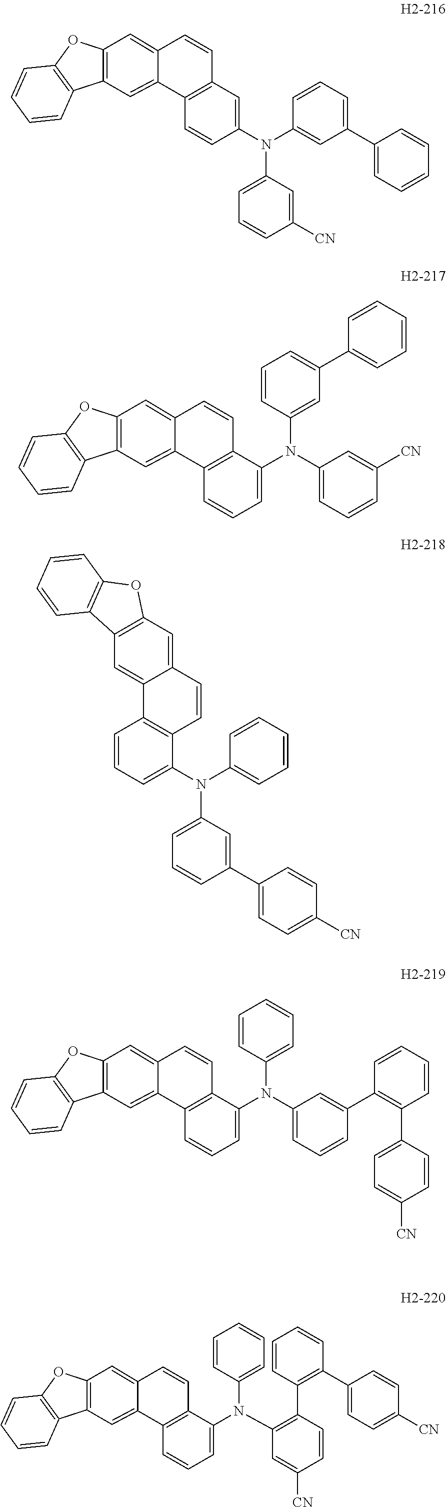 [SMILES: N#Cc1cccc(N(c2cccc(-c3ccccc3)c2)c2ccc3c(ccc4cc5oc6ccccc6c5cc43)c2)c1 ; N#Cc1cccc(N(c2cccc(-c3ccccc3)c2)c2cccc3c2ccc2cc4oc5ccccc5c4cc23)c1 ; N#Cc1ccc(-c2cccc(N(c3ccccc3)c3cccc4c3ccc3cc5oc6ccccc6c5cc34)c2)cc1 ; N#Cc1ccc(-c2ccccc2-c2cccc(N(c3ccccc3)c3cccc4c3ccc3cc5oc6ccccc6c5cc34)c2)cc1 ; N#Cc1ccc(-c2ccccc2-c2ccc(C#N)cc2N(c2ccccc2)c2cccc3c2ccc2cc4oc5ccccc5c4cc23)cc1]

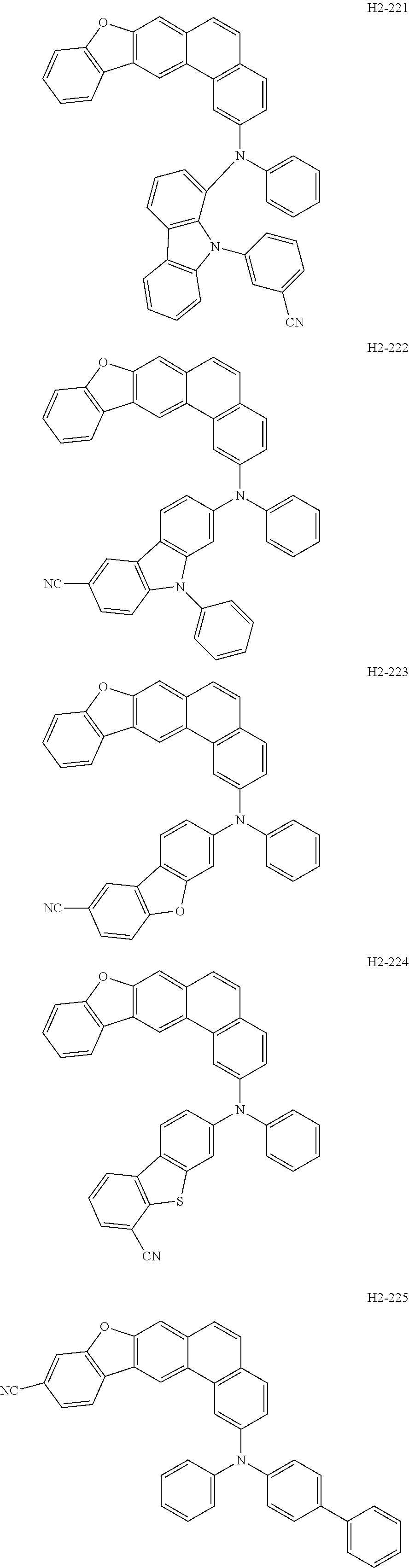

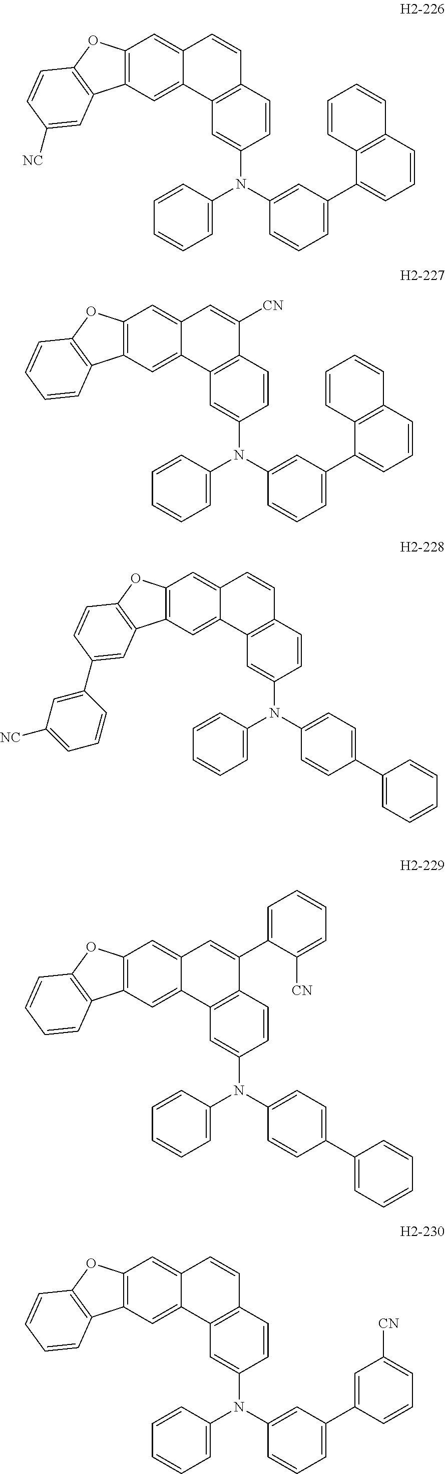 [SMILES: N#Cc1ccc2oc3cc4ccc5ccc(N(c6ccccc6)c6cccc(-c7cccc8ccccc78)c6)cc5c4cc3c2c1 ; N#Cc1cc2cc3oc4ccccc4c3cc2c2cc(N(c3ccccc3)c3cccc(-c4cccc5ccccc45)c3)ccc12 ; N#Cc1cccc(-c2ccc3oc4cc5ccc6ccc(N(c7ccccc7)c7ccc(-c8ccccc8)cc7)cc6c5cc4c3c2)c1 ; N#Cc1ccccc1-c1cc2cc3oc4ccccc4c3cc2c2cc(N(c3ccccc3)c3ccc(-c4ccccc4)cc3)ccc12 ; N#Cc1cccc(-c2cccc(N(c3ccccc3)c3ccc4ccc5cc6oc7ccccc7c6cc5c4c3)c2)c1]

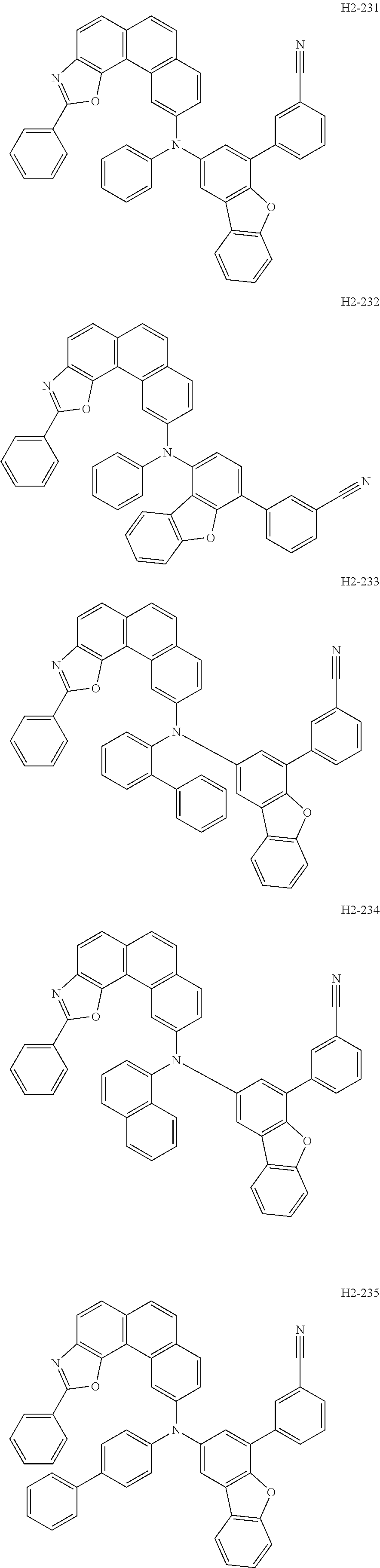 [SMILES: N#Cc1cccc(-c2cc(N(c3ccccc3)c3ccc4ccc5ccc6nc(-c7ccccc7)oc6c5c4c3)cc3c2oc2ccccc23)c1 ; N#Cc1cccc(-c2ccc(N(c3ccccc3)c3ccc4ccc5ccc6nc(-c7ccccc7)oc6c5c4c3)c3c2oc2ccccc23)c1 ; N#Cc1cccc(-c2cc(N(c3ccc4ccc5ccc6nc(-c7ccccc7)oc6c5c4c3)c3ccccc3-c3ccccc3)cc3c2oc2ccccc23)c1 ; N#Cc1cccc(-c2cc(N(c3ccc4ccc5ccc6nc(-c7ccccc7)oc6c5c4c3)c3cccc4ccccc34)cc3c2oc2ccccc23)c1 ; N#Cc1cccc(-c2cc(N(c3ccc(-c4ccccc4)cc3)c3ccc4ccc5ccc6nc(-c7ccccc7)oc6c5c4c3)cc3c2oc2ccccc23)c1]

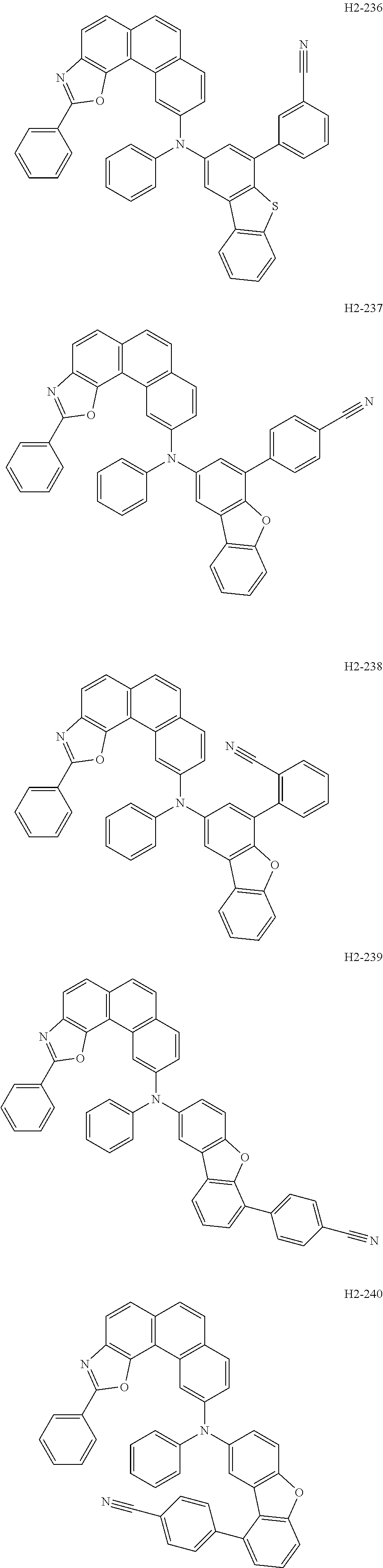 [SMILES: N#Cc1cccc(-c2cc(N(c3ccccc3)c3ccc4ccc5ccc6nc(-c7ccccc7)oc6c5c4c3)cc3c2sc2ccccc23)c1 ; N#Cc1ccc(-c2cc(N(c3ccccc3)c3ccc4ccc5ccc6nc(-c7ccccc7)oc6c5c4c3)cc3c2oc2ccccc23)cc1 ; N#Cc1ccccc1-c1cc(N(c2ccccc2)c2ccc3ccc4ccc5nc(-c6ccccc6)oc5c4c3c2)cc2c1oc1ccccc12 ; N#Cc1ccc(-c2cccc3c2oc2ccc(N(c4ccccc4)c4ccc5ccc6ccc7nc(-c8ccccc8)oc7c6c5c4)cc23)cc1 ; N#Cc1ccc(-c2cccc3oc4ccc(N(c5ccccc5)c5ccc6ccc7ccc8nc(-c9ccccc9)oc8c7c6c5)cc4c23)cc1]

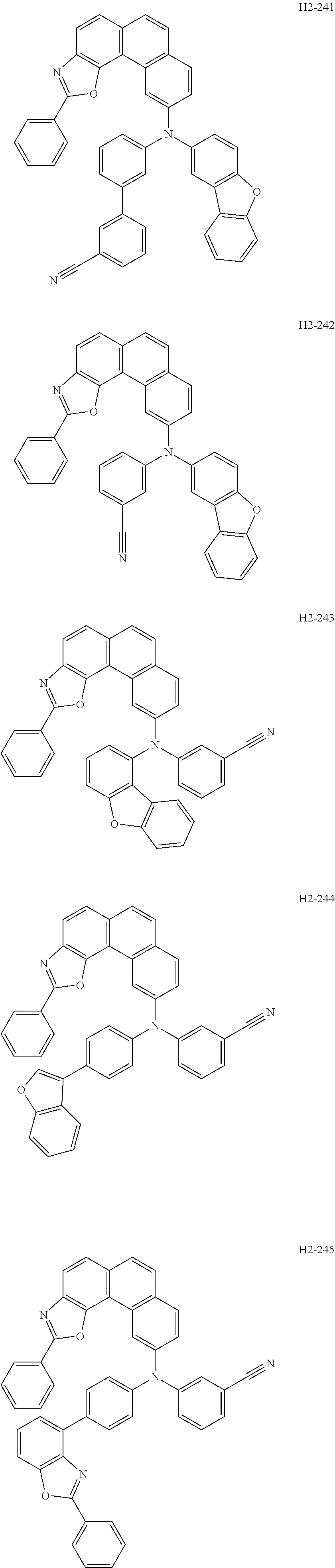 [SMILES: N#Cc1cccc(-c2cccc(N(c3ccc4oc5ccccc5c4c3)c3ccc4ccc5ccc6nc(-c7ccccc7)oc6c5c4c3)c2)c1 ; N#Cc1cccc(N(c2ccc3oc4ccccc4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3oc4ccccc4c23)c1 ; N#Cc1cccc(N(c2ccc(-c3coc4ccccc34)cc2)c2ccc3ccc4ccc5nc(-c6ccccc6)oc5c4c3c2)c1 ; N#Cc1cccc(N(c2ccc(-c3cccc4oc(-c5ccccc5)nc34)cc2)c2ccc3ccc4ccc5nc(-c6ccccc6)oc5c4c3c2)c1]

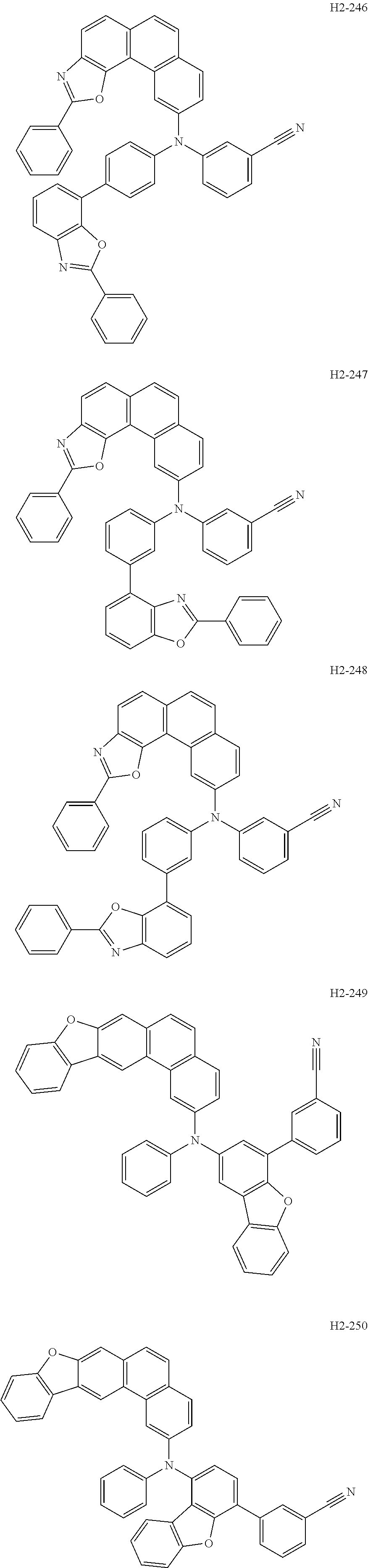 [SMILES: N#Cc1cccc(N(c2ccc(-c3cccc4nc(-c5ccccc5)oc34)cc2)c2ccc3ccc4ccc5nc(-c6ccccc6)oc5c4c3c2)c1 ; N#Cc1cccc(N(c2cccc(-c3cccc4oc(-c5ccccc5)nc34)c2)c2ccc3ccc4ccc5nc(-c6ccccc6)oc5c4c3c2)c1 ; N#Cc1cccc(N(c2cccc(-c3cccc4nc(-c5ccccc5)oc34)c2)c2ccc3ccc4ccc5nc(-c6ccccc6)oc5c4c3c2)c1 ; N#Cc1cccc(-c2cc(N(c3ccccc3)c3ccc4ccc5cc6oc7ccccc7c6cc5c4c3)cc3c2oc2ccccc23)c1 ; N#Cc1cccc(-c2ccc(N(c3ccccc3)c3ccc4ccc5cc6oc7ccccc7c6cc5c4c3)c3c2oc2ccccc23)c1]

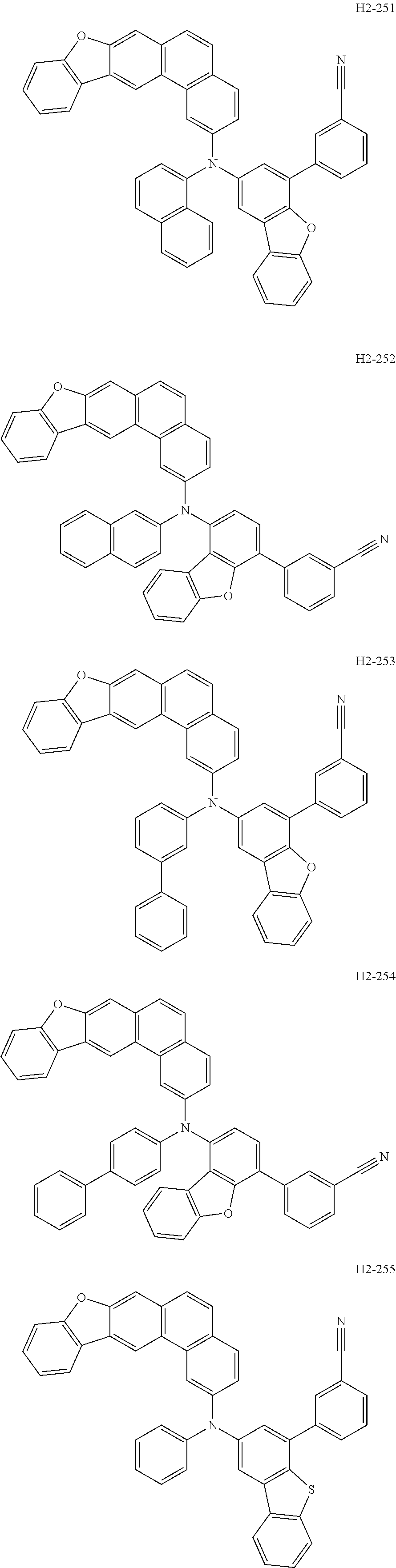 [SMILES: N#Cc1cccc(-c2cc(N(c3ccc4ccc5cc6oc7ccccc7c6cc5c4c3)c3cccc4ccccc34)cc3c2oc2ccccc23)c1 ; N#Cc1cccc(-c2ccc(N(c3ccc4ccccc4c3)c3ccc4ccc5cc6oc7ccccc7c6cc5c4c3)c3c2oc2ccccc23)c1 ; N#Cc1cccc(-c2cc(N(c3cccc(-c4ccccc4)c3)c3ccc4ccc5cc6oc7ccccc7c6cc5c4c3)cc3c2oc2ccccc23)c1 ; N#Cc1cccc(-c2ccc(N(c3ccc(-c4ccccc4)cc3)c3ccc4ccc5cc6oc7ccccc7c6cc5c4c3)c3c2oc2ccccc23)c1 ; N#Cc1cccc(-c2cc(N(c3ccccc3)c3ccc4ccc5cc6oc7ccccc7c6cc5c4c3)cc3c2sc2ccccc23)c1]

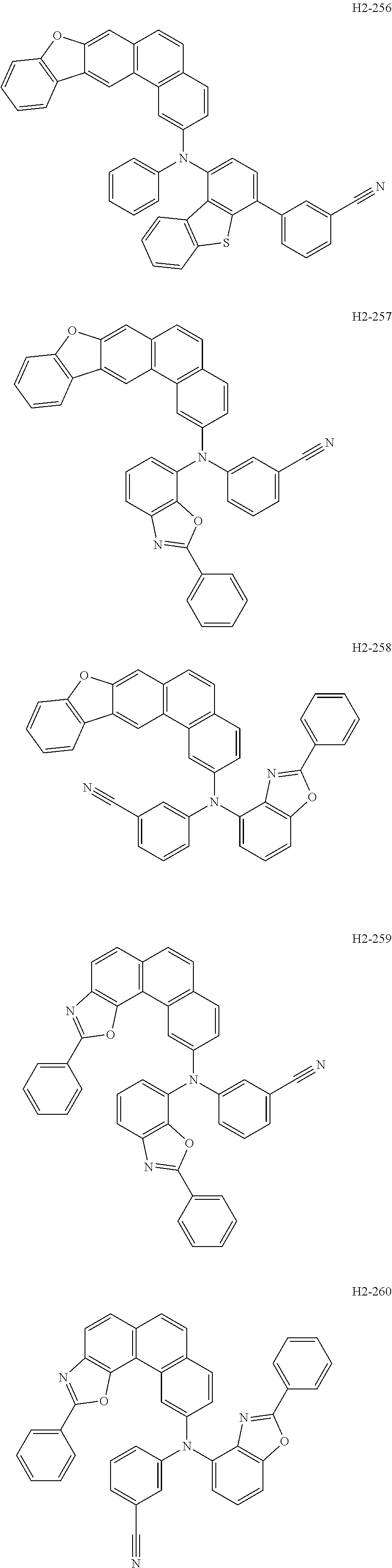 [SMILES: N#Cc1cccc(-c2ccc(N(c3ccccc3)c3ccc4ccc5cc6oc7ccccc7c6cc5c4c3)c3c2sc2ccccc23)c1 ; N#Cc1cccc(N(c2ccc3ccc4cc5oc6ccccc6c5cc4c3c2)c2cccc3nc(-c4ccccc4)oc23)c1 ; N#Cc1cccc(N(c2ccc3ccc4cc5oc6ccccc6c5cc4c3c2)c2cccc3oc(-c4ccccc4)nc23)c1 ; N#Cc1cccc(N(c2ccc3ccc4ccc5nc(-c6ccccc6)oc5c4c3c2)c2cccc3nc(-c4ccccc4)oc23)c1 ; N#Cc1cccc(N(c2ccc3ccc4ccc5nc(-c6ccccc6)oc5c4c3c2)c2cccc3oc(-c4ccccc4)nc23)c1]

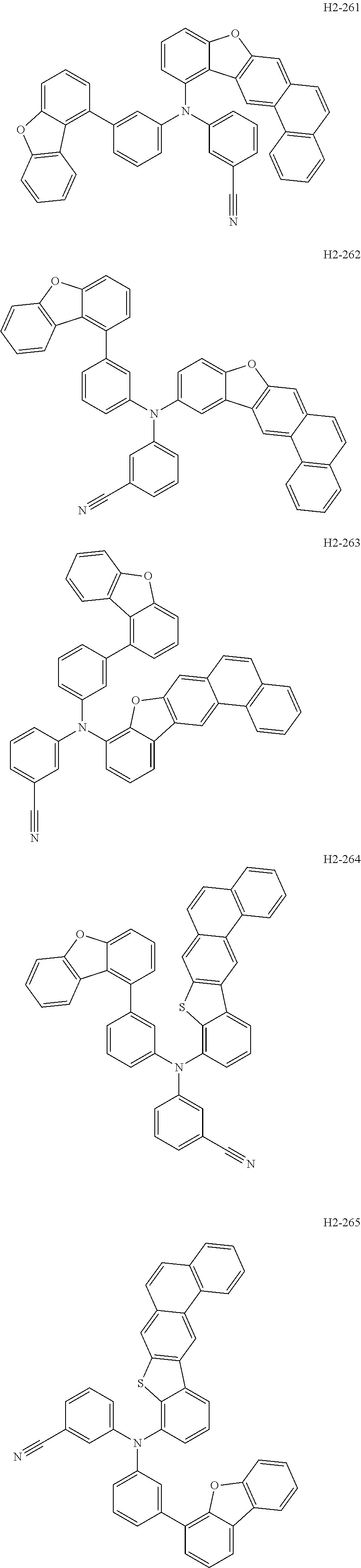 [SMILES: N#Cc1cccc(N(c2cccc(-c3cccc4oc5ccccc5c34)c2)c2cccc3oc4cc5ccc6ccccc6c5cc4c23)c1 ; N#Cc1cccc(N(c2cccc(-c3cccc4oc5ccccc5c34)c2)c2ccc3oc4cc5ccc6ccccc6c5cc4c3c2)c1 ; N#Cc1cccc(N(c2cccc(-c3cccc4oc5ccccc5c34)c2)c2cccc3c2oc2cc4ccc5ccccc5c4cc23)c1 ; N#Cc1cccc(N(c2cccc(-c3cccc4oc5ccccc5c34)c2)c2cccc3c2sc2cc4ccc5ccccc5c4cc23)c1 ; N#Cc1cccc(N(c2cccc(-c3cccc4c3oc3ccccc34)c2)c2cccc3c2sc2cc4ccc5ccccc5c4cc23)c1]

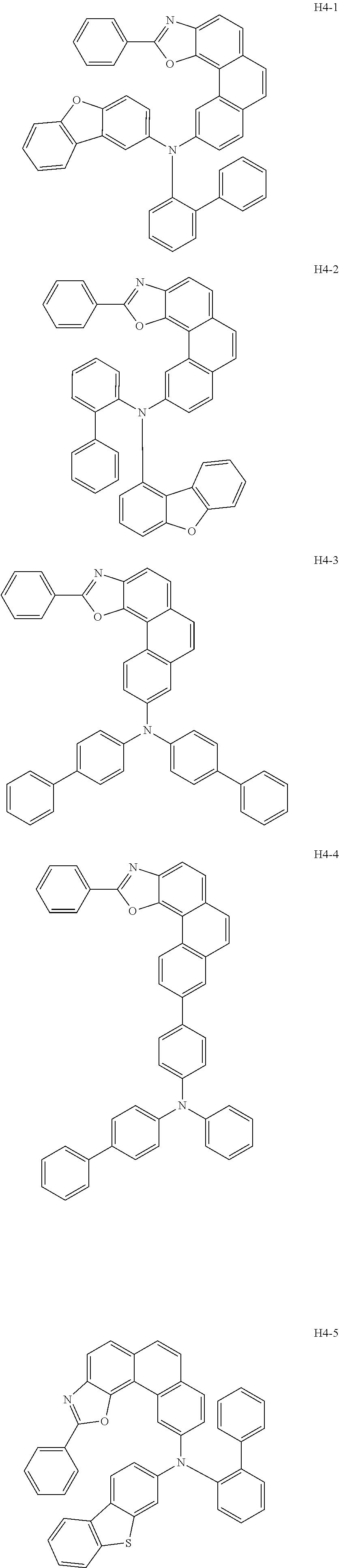

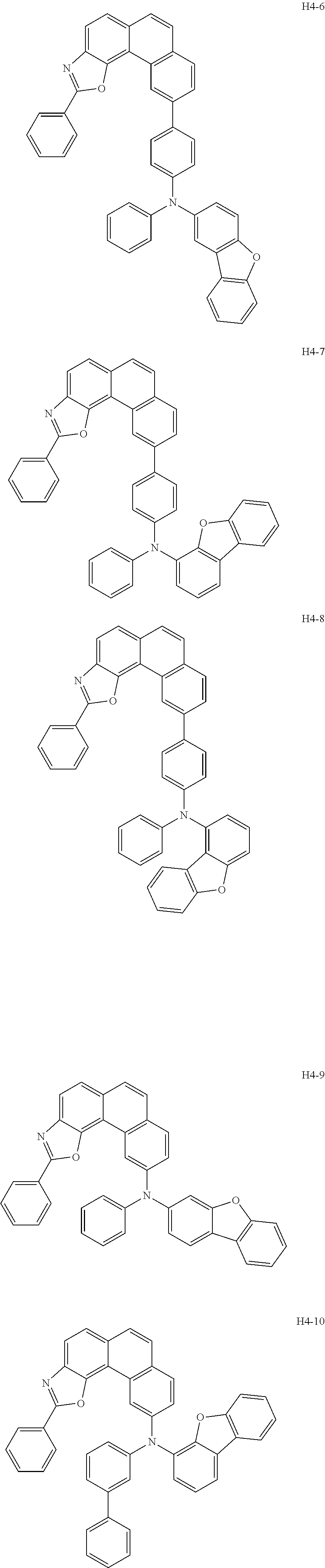

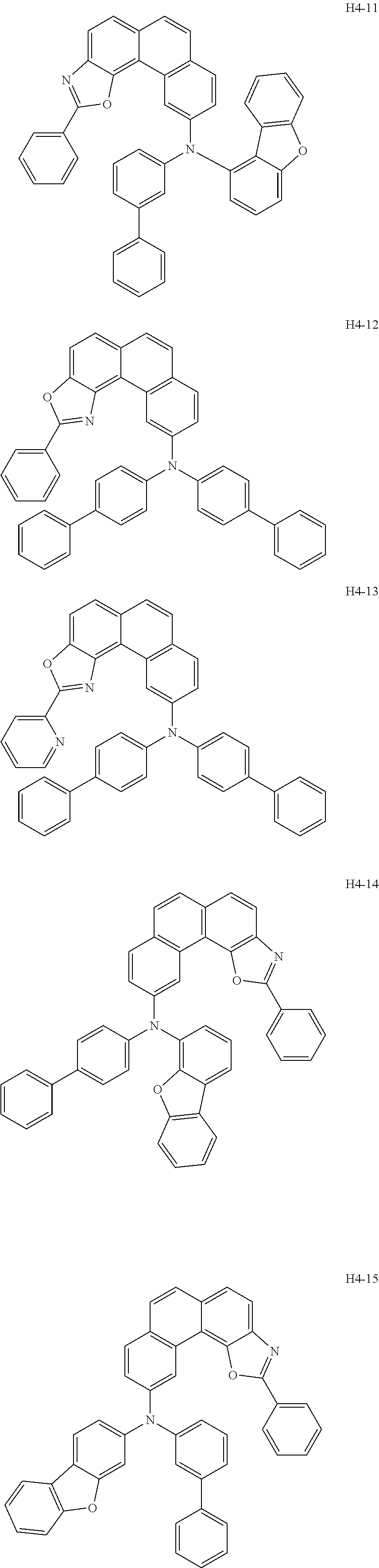

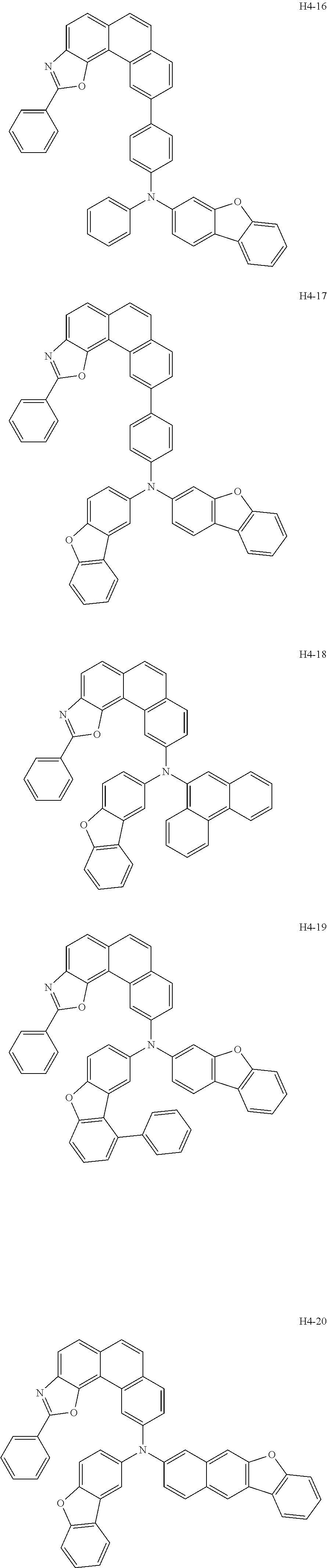 [SMILES: c1ccc(-c2nc3ccc4ccc5ccc(-c6ccc(N(c7ccccc7)c7ccc8c(c7)oc7ccccc78)cc6)cc5c4c3o2)cc1 ; c1ccc(-c2nc3ccc4ccc5ccc(-c6ccc(N(c7ccc8c(c7)oc7ccccc78)c7ccc8oc9ccccc9c8c7)cc6)cc5c4c3o2)cc1 ; c1ccc(-c2nc3ccc4ccc5ccc(N(c6ccc7oc8ccccc8c7c6)c6cc7ccccc7c7ccccc67)cc5c4c3o2)cc1 ; c1ccc(-c2nc3ccc4ccc5ccc(N(c6ccc7c(c6)oc6ccccc67)c6ccc7oc8cccc(-c9ccccc9)c8c7c6)cc5c4c3o2)cc1 ; C/C=C(\C=C/c1ccc2oc3ccccc3c2c1)N(c1ccc2oc3ccccc3c2c1)c1ccc2ccc3ccc4nc(-c5ccccc5)oc4c3c2c1]

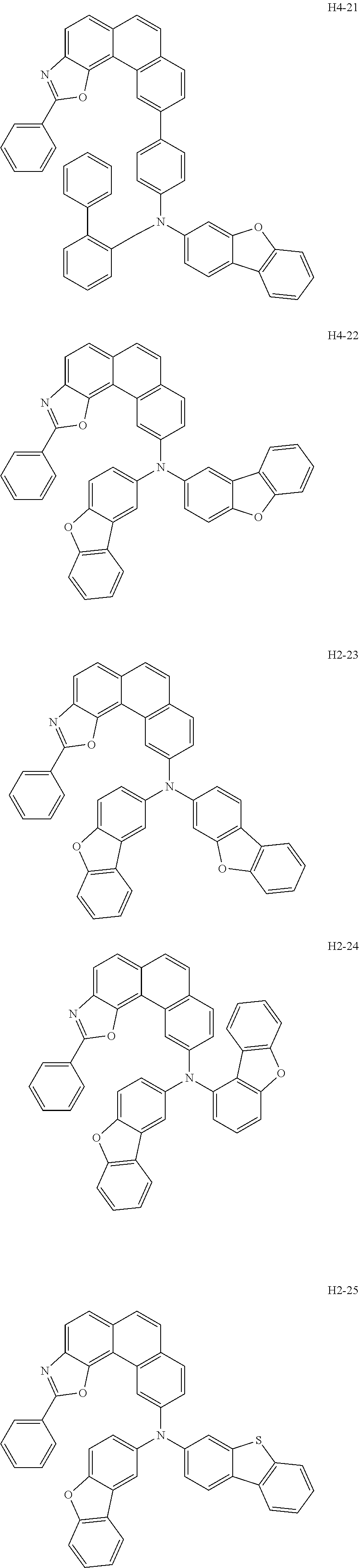

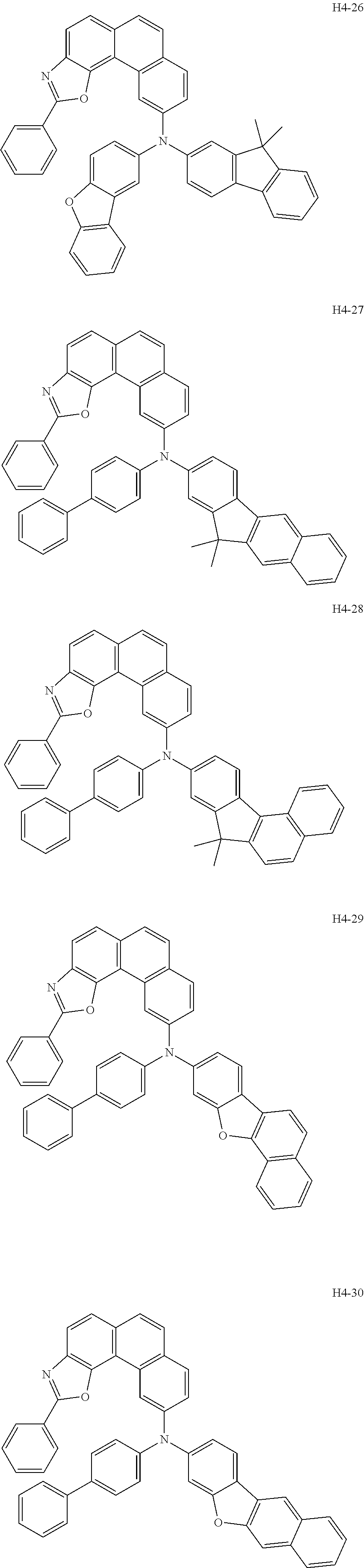 [SMILES: C/C=C(\C=C/C1=CC(C)(C)c2ccccc21)N(c1ccc2oc3ccccc3c2c1)c1ccc2ccc3ccc4nc(-c5ccccc5)oc4c3c2c1 ; C=C1/C(=C\C(=C/C)N(c2ccc(-c3ccccc3)cc2)c2ccc3ccc4ccc5nc(-c6ccccc6)oc5c4c3c2)C(C)(C)c2cc3ccccc3cc21 ; C=C1/C(=C\C(=C/C)N(c2ccc(-c3ccccc3)cc2)c2ccc3ccc4ccc5nc(-c6ccccc6)oc5c4c3c2)C(C)(C)c2ccc3ccccc3c21 ; C=c1/c(=C\C(=C/C)N(c2ccc(-c3ccccc3)cc2)c2ccc3ccc4ccc5nc(-c6ccccc6)oc5c4c3c2)oc2c1ccc1ccccc12 ; C=c1/c(=C\C(=C/C)N(c2ccc(-c3ccccc3)cc2)c2ccc3ccc4ccc5nc(-c6ccccc6)oc5c4c3c2)oc2cc3ccccc3cc12]

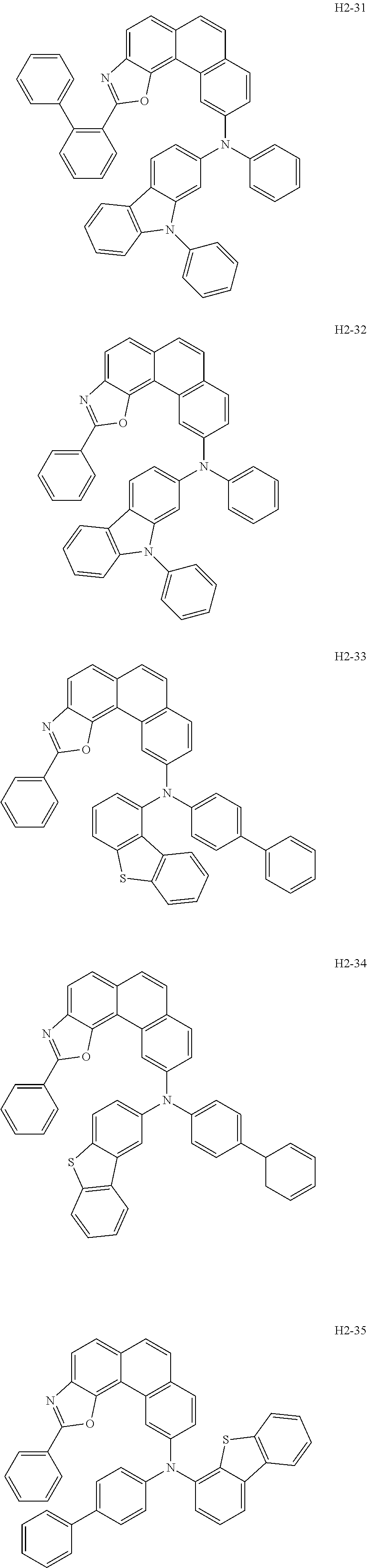

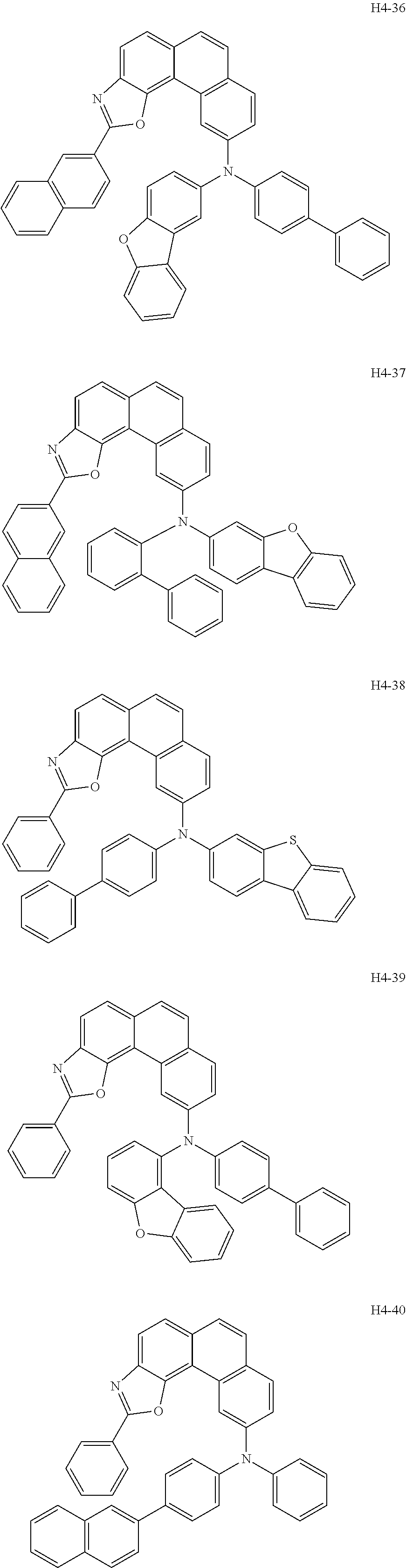 [SMILES: C=C/C(=C\C=C(/C)c1ccccc1)N(c1ccc2oc3ccccc3c2c1)c1ccc2ccc3ccc4nc(-c5ccc6ccccc6c5)oc4c3c2c1 ; C=C/C(=C\C=C1/COc2ccccc21)N(c1ccc2ccc3ccc4nc(-c5ccc6ccccc6c5)oc4c3c2c1)c1ccccc1-c1ccccc1 ; C=C/C(=C\C=C1/CSc2ccccc21)N(c1ccc(-c2ccccc2)cc1)c1ccc2ccc3ccc4nc(-c5ccccc5)oc4c3c2c1 ; C=C/C(=C\C=C(/C)c1ccccc1)N(c1ccc2ccc3ccc4nc(-c5ccccc5)oc4c3c2c1)c1cccc2oc3ccccc3c12 ; C=C/C(=C\C=C/C)N(c1ccc(-c2ccc3ccccc3c2)cc1)c1ccc2ccc3ccc4nc(-c5ccccc5)oc4c3c2c1]

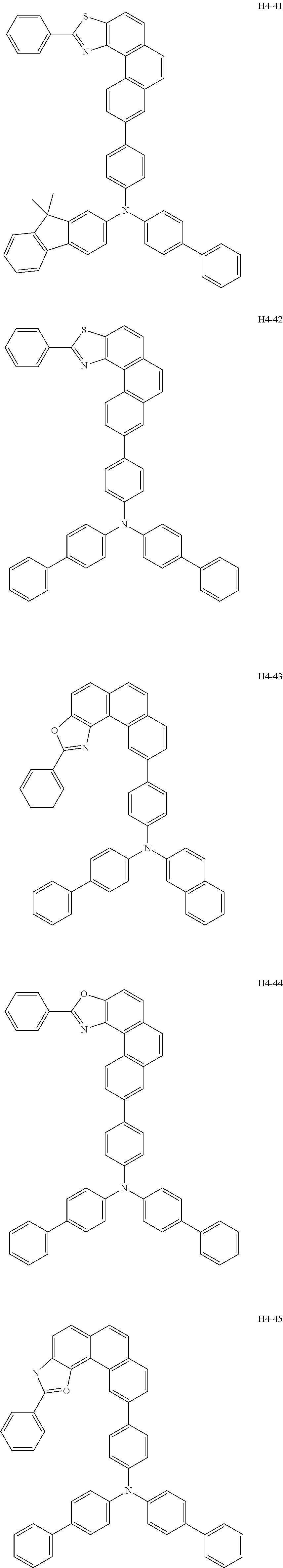

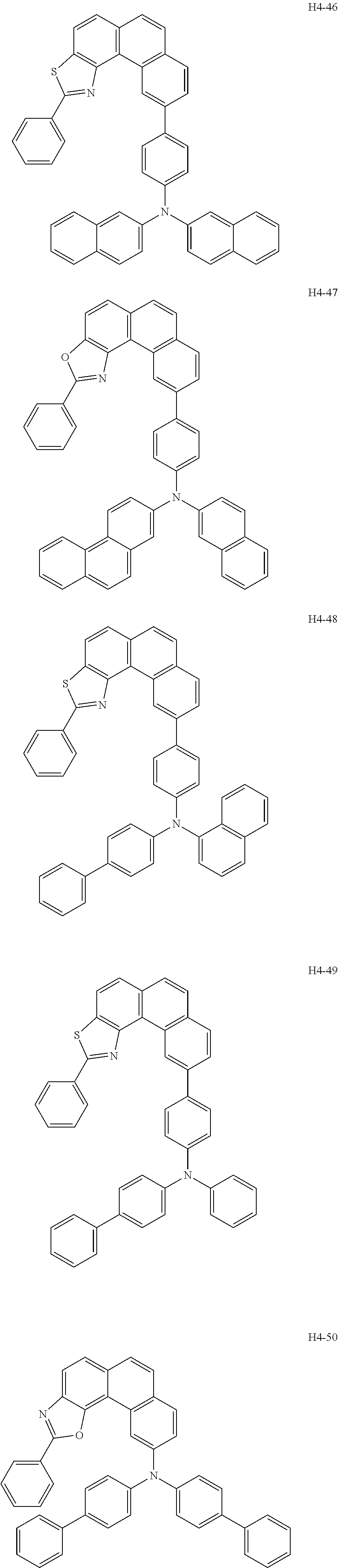 [SMILES: c1ccc(-c2nc3c(ccc4ccc5ccc(-c6ccc(N(c7ccc8ccccc8c7)c7ccc8ccccc8c7)cc6)cc5c43)s2)cc1 ; c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2ccc(N(c3ccc(-c4ccc5ccc6ccc7sc(-c8ccccc8)nc7c6c5c4)cc3)c3cccc4ccccc34)cc2)cc1 ; c1ccc(-c2ccc(N(c3ccccc3)c3ccc(-c4ccc5ccc6ccc7sc(-c8ccccc8)nc7c6c5c4)cc3)cc2)cc1 ; c1ccc(-c2ccc(N(c3ccc(-c4ccccc4)cc3)c3ccc4ccc5ccc6nc(-c7ccccc7)oc6c5c4c3)cc2)cc1]

[chemical structure]

[chemical structure]

[chemical structure]

[chemical structure]

[chemical structure]

[chemical structure]

[chemical structure]

[chemical structure]

[chemical structure]

[chemical structure]

[chemical structure]

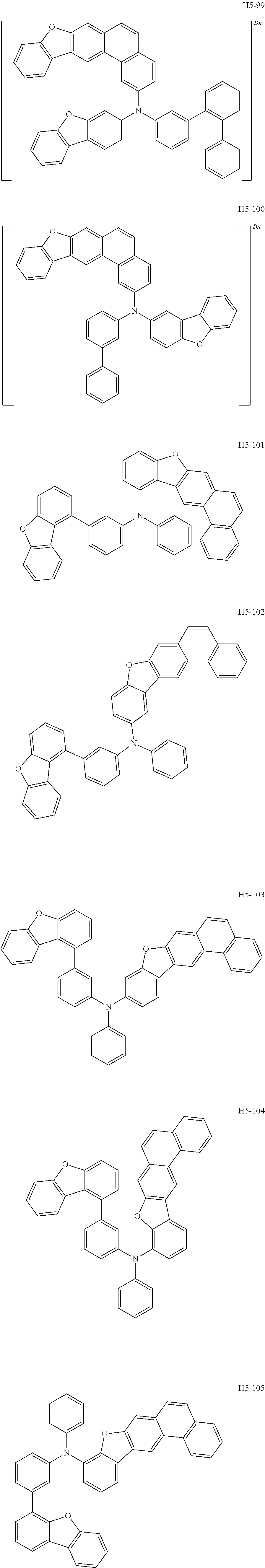

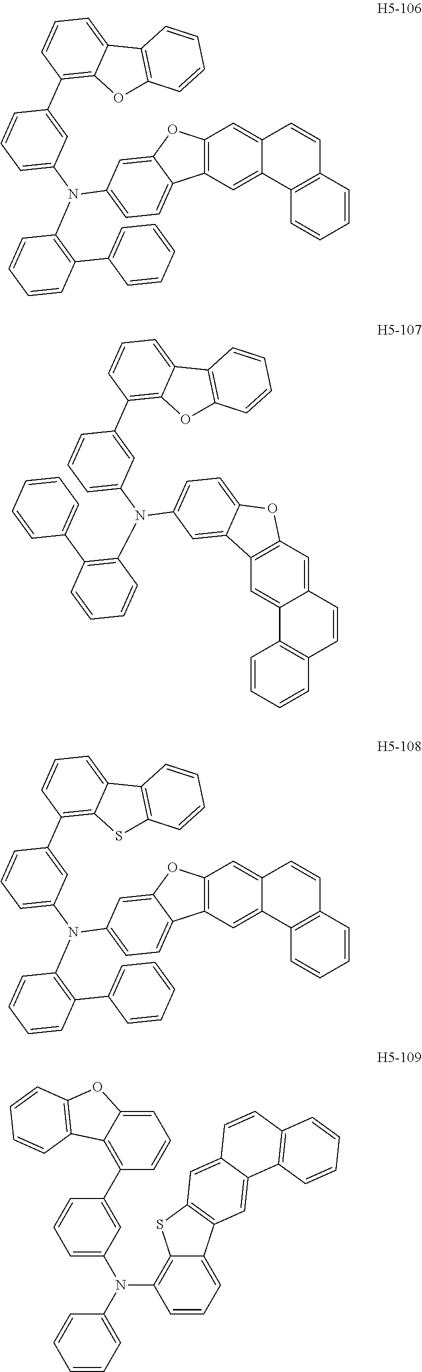 [SMILES: c1ccc(-c2ccccc2N(c2cccc(-c3cccc4c3oc3ccccc34)c2)c2ccc3c(c2)oc2cc4ccc5ccccc5c4cc23)cc1 ; c1ccc(-c2ccccc2N(c2cccc(-c3cccc4c3oc3ccccc34)c2)c2ccc3oc4cc5ccc6ccccc6c5cc4c3c2)cc1 ; c1ccc(-c2ccccc2N(c2cccc(-c3cccc4c3sc3ccccc34)c2)c2ccc3c(c2)oc2cc4ccc5ccccc5c4cc23)cc1 ; c1ccc(N(c2cccc(-c3cccc4oc5ccccc5c34)c2)c2cccc3c2sc2cc4ccc5ccccc5c4cc23)cc1]

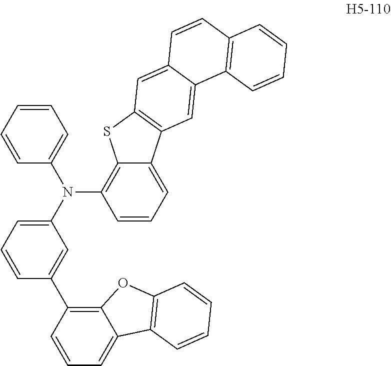 [SMILES: c1ccc(N(c2cccc(-c3cccc4c3oc3ccccc34)c2)c2cccc3c2sc2cc4ccc5ccccc5c4cc23)cc1]

In the compounds above, Dₙ represents that n number of hydrogens are replaced with deuterium, and n represents an integer of 1 or more, which is an integer of 1 to the maximum number of hydrogens in the compound.

The plurality of host materials according to the present disclosure further comprises a third host material. According to one embodiment of the present disclosure, the third host material comprises a compound with electronic properties by comprising a substituent that is relatively rich in electrons in a parent nucleus. For example, the compound with electronic properties by comprising a substituent that is relatively rich in electrons in a parent nucleus may be a compound represented by Formula 1. According to another embodiment of the present disclosure, the third host material comprises a compound with hole properties by comprising a substituent that is relatively deficient in electrons on a parent nucleus. For example, the compound with hole properties by comprising a substituent that is relatively deficient in electrons on a parent nucleus may be a compound represented by Formula 2.

The present disclosure provides an organic electroluminescent compound represented by the following Formula 3, an organic electroluminescent material, and an organic electroluminescent device comprising the same.

In Formula 3, Z₁ represents O, S, Se, NR_{b}, or CR_{c}R_{d}. According to one embodiment of the present disclosure, Z₁ may be O, S, or NR_{b}.

In Formula 3, R₄₁ to R₄₈ and R_{b} to R_{d} each independently represent the above Formula 3-a, hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl; with the proviso that at least one of R₄₁ to R₄₈ and R_{b} to R_{d} is represented by the above Formula 3-a.

According to one embodiment of the present disclosure, R₄₁ to R₄₈ each independently represent the above Formula 3-a, hydrogen, deuterium, or a substituted or unsubstituted (C₆-C₂₅)aryl. According to another embodiment of the present disclosure, R₄₁ to R₄₈ each independently represent the above Formula 3-a, hydrogen, deuterium, or a substituted or unsubstituted (C₆-C₁₈)aryl unsubstituted or substituted with deuterium and/or a (C₆-C₃₀)aryl. For example, R₄₁ to R₄₈ may each independently be the above Formula 3-a, hydrogen, deuterium, a phenyl, a biphenyl, a naphthyl, a phenylnaphthyl, or a naphthylphenyl, etc., and these may be further substituted with deuterium. According to one embodiment of the present disclosure, at least one of R₄₁ to R₄₈ may be a substituted or unsubstituted phenyl, a substituted or unsubstituted biphenyl, a substituted or unsubstituted naphthyl, a substituted or unsubstituted phenylnaphthyl, or a substituted or unsubstituted naphthylphenyl.

According to one embodiment of the present disclosure, R_{b} represents the above Formula 3-a, a substituted or unsubstituted (C₆-C₂₅)aryl, or a substituted or unsubstituted (3- to 20-membered)heteroaryl. According to another embodiment of the present disclosure, R_{b} represents the above Formula 3-a, a (C₆-C₁₈)aryl unsubstituted or substituted with deuterium, or a (13-membered)heteroaryl unsubstituted or substituted with deuterium. For example, R_{b} may be the above Formula 3-a, a phenyl, or a dibenzofuranyl, etc., and these may be substituted with deuterium.

In Formula 3-a, X₄ to X₆ each independently represent N or CRₑ; with the proviso that at least one of X₄ to X₆ is N. According to one embodiment of the present disclosure, at least two of X₄ to X₆ are N. According to another embodiment of the present disclosure, all of X₄ to X₆ are N.

In Formula 3-a, L₆ and L₇ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene. According to one embodiment of the present disclosure, L₆ and L₇ each independently represent a single bond, a substituted or unsubstituted (C₆-C₂₅)arylene, or a substituted or unsubstituted (5- to 25-membered)heteroarylene. According to another embodiment of the present disclosure, L₆ and L₇ each independently represent a single bond, a (C₆-C₁₈)arylene unsubstituted or substituted with deuterium or a (C₆-C₃₀)aryl, or a (5- to 20-membered)heteroarylene unsubstituted or substituted with deuterium. For example, L₆ and L₇ may each independently be a single bond, a phenylene unsubstituted or substituted with a phenyl, a naphthylene, a biphenylene, a pyridylene, a dibenzofuranylene, etc., and these may be substituted with deuterium.

In Formula 3-a, b represents an integer of 1 or 2, where if b is an integer of 2, each L₇ may be the same as or different from each other.

In Formula 3-a, R₅₀ to R₅₄ and Rₑ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s); with the proviso that at least one of R₅₀ to R₅₄ is cyano. According to one embodiment of the present disclosure, R₅₀ to R₅₄ each independently represent hydrogen, deuterium, a cyano, or a substituted or unsubstituted (C₆-C₃₀)aryl, and at least one of R₅₀ to R₅₄ is cyano. For example, at least one of R₅₀ to R₅₄ is cyano, the others each represent hydrogen, deuterium, a phenyl, a naphthyl, a biphenyl, etc., and these may be substituted with deuterium.

According to one embodiment of the present disclosure, at least one of R₅₀ to R₅₄ is a cyano, and one of the remainder is a substituted or unsubstituted (C₆-C₃₀)aryl. For example, at least one of R₅₀ to R₅₄ is a cyano, and one of the remainder may be a phenyl, a naphthyl, or a biphenyl, etc., and these may be substituted with deuterium. According to one embodiment of the present disclosure, at least one of R₅₀ to R₅₄ is a cyano, and the remainder are hydrogen, deuterium, or a phenyl.

In Formula 3-a, Ar₆ represents a substituted or unsubstituted phenyl, a substituted or unsubstituted biphenyl, a substituted or unsubstituted terphenyl, a substituted or unsubstituted naphthyl, a substituted or unsubstituted binaphthyl, a substituted or unsubstituted phenylnaphthyl, a substituted or unsubstituted naphthylphenyl, a substituted or unsubstituted phenanthrenyl, a substituted or unsubstituted anthracenyl, a substituted or unsubstituted chrysenyl, a substituted or unsubstituted dibenzofuranyl, a substituted or unsubstituted dibenzothiophenyl, a substituted or unsubstituted naphthobenzothiophenyl, a substituted or unsubstituted carbazolyl, or a substituted or unsubstituted benzocarbazolyl. Herein, a phenyl, a biphenyl, a terphenyl, a naphthyl, a binaphthyl, a phenylnaphthyl, a naphthylphenyl, a phenanthrenyl, a anthracenyl, a chrysenyl, a dibenzofuranyl, a dibenzothiophenyl, a naphthobenzothiophenyl, a carbazolyl, or a benzocarbazolyl may be substituted with at least one selected from the group consisting of deuterium, a (C₃-C₃₀)aryl, and a combination thereof. The group may consist of deuterium, a phenyl unsubstituted or substituted with deuterium, a naphthyl unsubstituted or substituted with deuterium, an unsubstituted biphenyl, and a combination thereof.

The compound represented by Formula 3 may be selected from the following compounds, but is not limited to thereto.

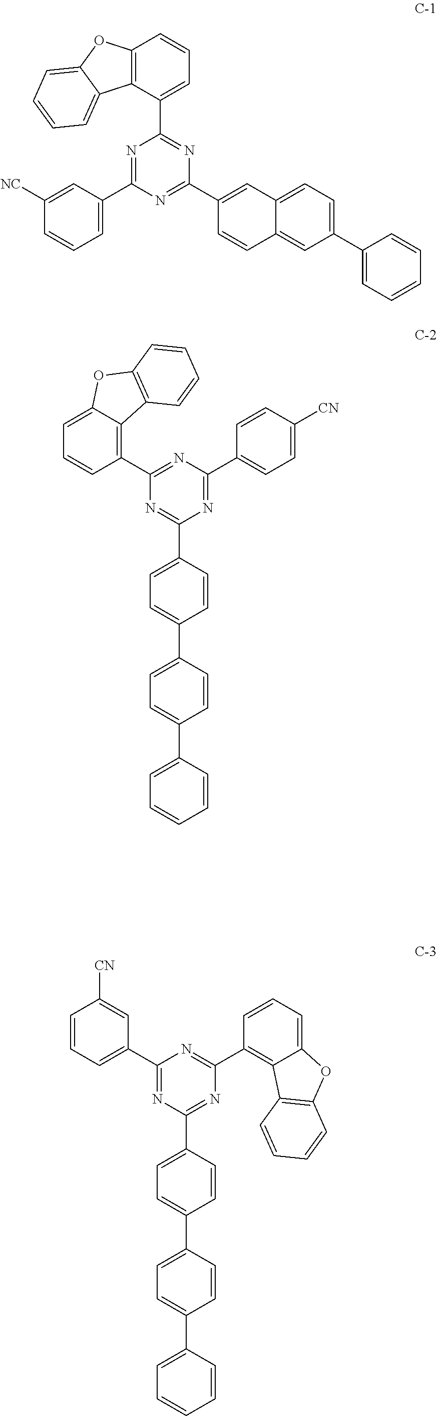 [SMILES: N#Cc1cccc(-c2nc(-c3ccc4cc(-c5ccccc5)ccc4c3)nc(-c3cccc4oc5ccccc5c34)n2)c1 ; N#Cc1ccc(-c2nc(-c3ccc(-c4ccc(-c5ccccc5)cc4)cc3)nc(-c3cccc4oc5ccccc5c34)n2)cc1 ; N#Cc1cccc(-c2nc(-c3ccc(-c4ccc(-c5ccccc5)cc4)cc3)nc(-c3cccc4oc5ccccc5c34)n2)c1]

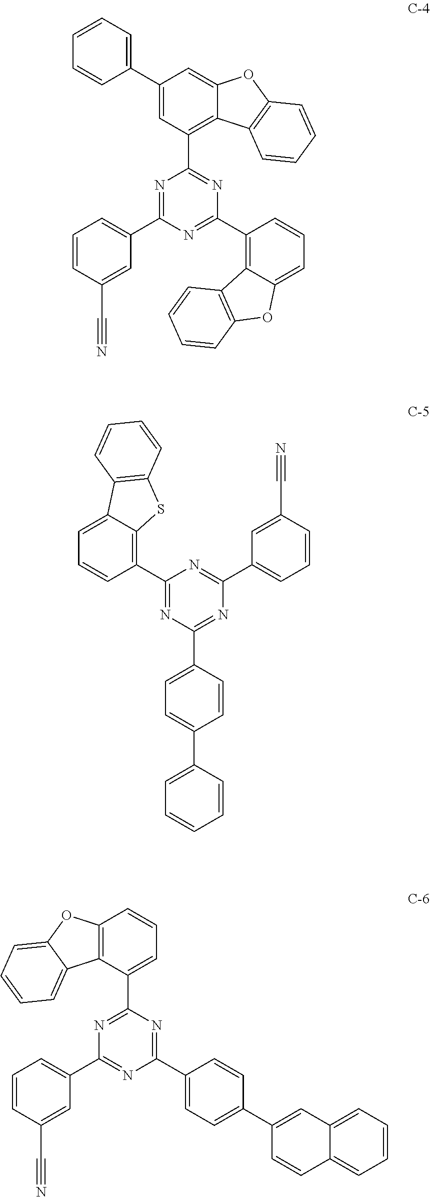 [SMILES: N#Cc1cccc(-c2nc(-c3cccc4oc5ccccc5c34)nc(-c3cc(-c4ccccc4)cc4oc5ccccc5c34)n2)c1 ; N#Cc1cccc(-c2nc(-c3ccc(-c4ccccc4)cc3)nc(-c3cccc4c3sc3ccccc34)n2)c1 ; N#Cc1cccc(-c2nc(-c3ccc(-c4ccc5ccccc5c4)cc3)nc(-c3cccc4oc5ccccc5c34)n2)c1]

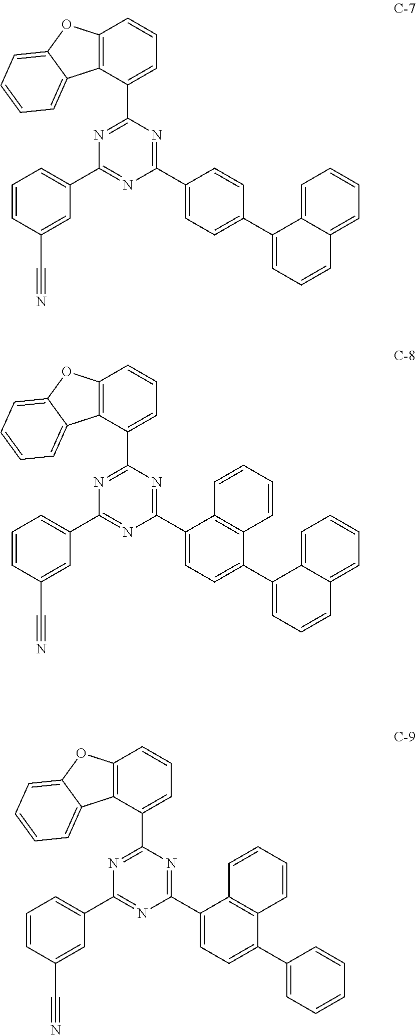 [SMILES: N#Cc1cccc(-c2nc(-c3ccc(-c4cccc5ccccc45)cc3)nc(-c3cccc4oc5ccccc5c34)n2)c1 ; N#Cc1cccc(-c2nc(-c3ccc(-c4cccc5ccccc45)c4ccccc34)nc(-c3cccc4oc5ccccc5c34)n2)c1 ; N#Cc1cccc(-c2nc(-c3ccc(-c4ccccc4)c4ccccc34)nc(-c3cccc4oc5ccccc5c34)n2)c1]

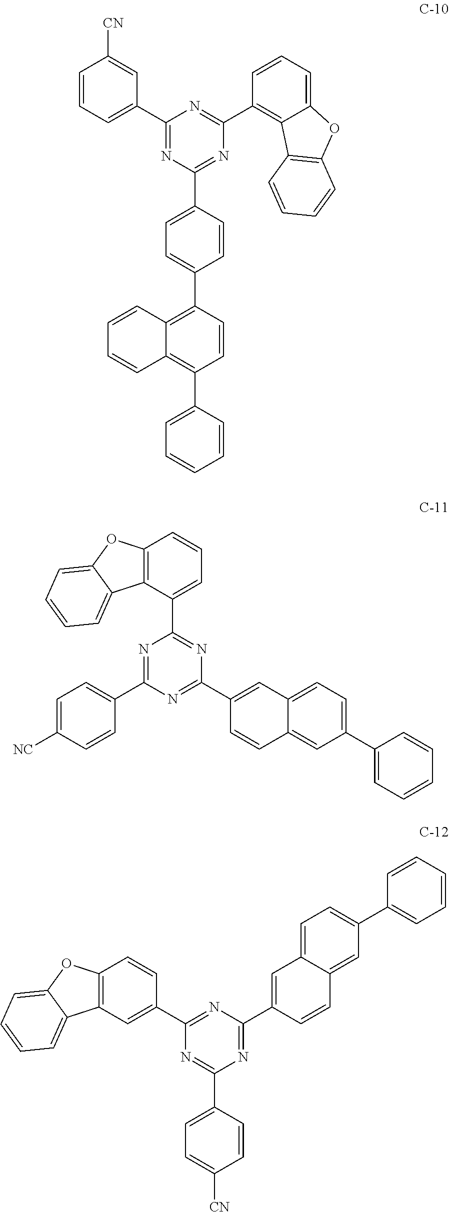 [SMILES: N#Cc1cccc(-c2nc(-c3ccc(-c4ccc(-c5ccccc5)c5ccccc45)cc3)nc(-c3cccc4oc5ccccc5c34)n2)c1 ; N#Cc1ccc(-c2nc(-c3ccc4cc(-c5ccccc5)ccc4c3)nc(-c3cccc4oc5ccccc5c34)n2)cc1 ; N#Cc1ccc(-c2nc(-c3ccc4cc(-c5ccccc5)ccc4c3)nc(-c3ccc4oc5ccccc5c4c3)n2)cc1]

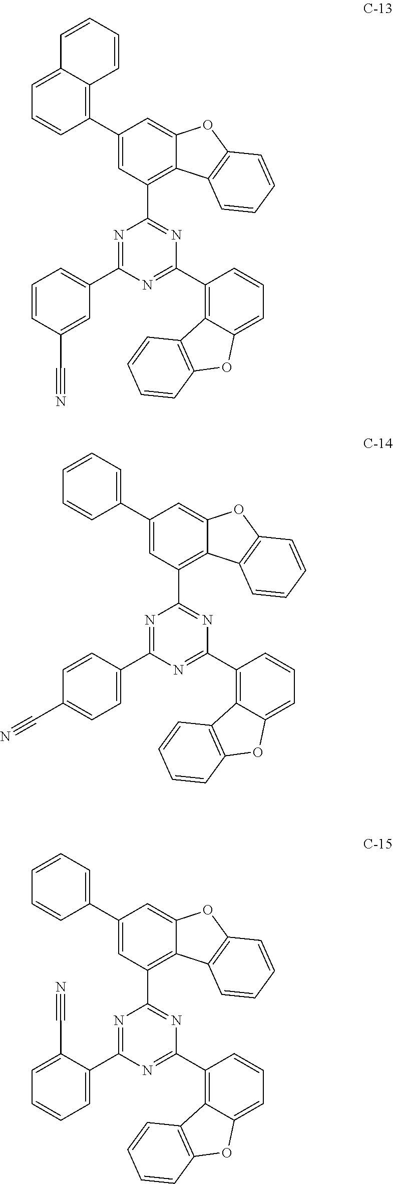 [SMILES: N#Cc1cccc(-c2nc(-c3cccc4oc5ccccc5c34)nc(-c3cc(-c4cccc5ccccc45)cc4oc5ccccc5c34)n2)c1 ; N#Cc1ccc(-c2nc(-c3cccc4oc5ccccc5c34)nc(-c3cc(-c4ccccc4)cc4oc5ccccc5c34)n2)cc1 ; N#Cc1ccccc1-c1nc(-c2cccc3oc4ccccc4c23)nc(-c2cc(-c3ccccc3)cc3oc4ccccc4c23)n1]

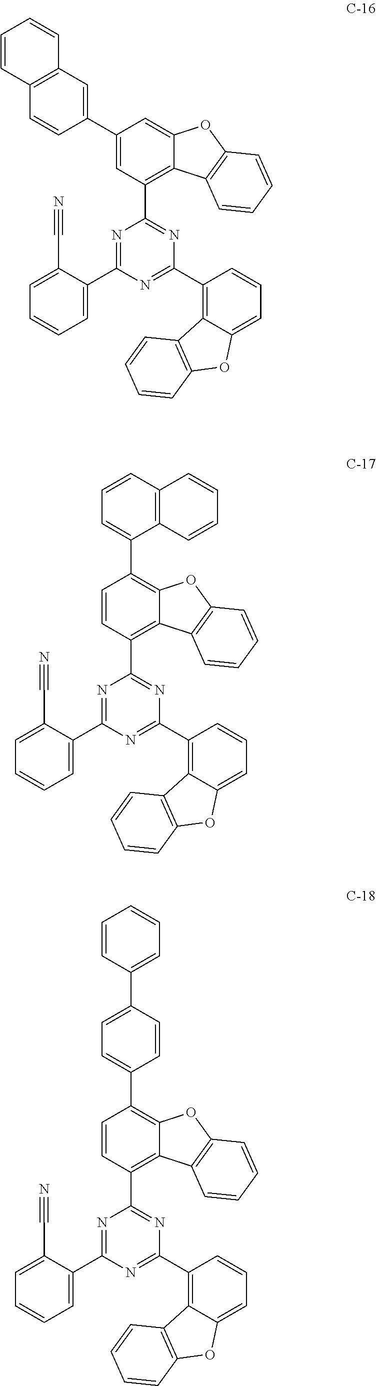 [SMILES: N#Cc1ccccc1-c1nc(-c2cccc3oc4ccccc4c23)nc(-c2cc(-c3ccc4ccccc4c3)cc3oc4ccccc4c23)n1 ; N#Cc1ccccc1-c1nc(-c2cccc3oc4ccccc4c23)nc(-c2ccc(-c3cccc4ccccc34)c3oc4ccccc4c23)n1 ; N#Cc1ccccc1-c1nc(-c2cccc3oc4ccccc4c23)nc(-c2ccc(-c3ccc(-c4ccccc4)cc3)c3oc4ccccc4c23)n1]

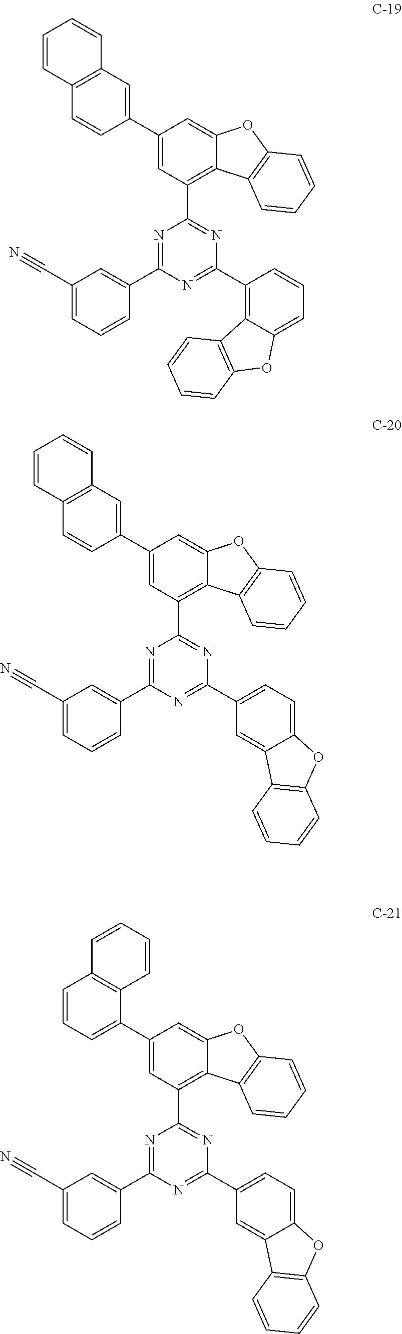 [SMILES: N#Cc1cccc(-c2nc(-c3cccc4oc5ccccc5c34)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4cccc5ccccc45)cc4oc5ccccc5c34)n2)c1]

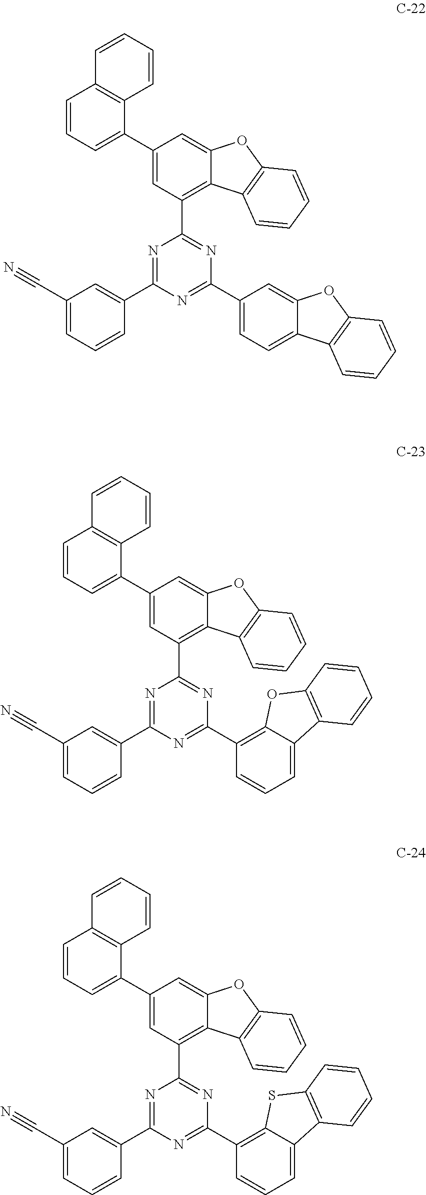 [SMILES: N#Cc1cccc(-c2nc(-c3ccc4c(c3)oc3ccccc34)nc(-c3cc(-c4cccc5ccccc45)cc4oc5ccccc5c34)n2)c1 ; N#Cc1cccc(-c2nc(-c3cccc4c3oc3ccccc34)nc(-c3cc(-c4cccc5ccccc45)cc4oc5ccccc5c34)n2)c1 ; N#Cc1cccc(-c2nc(-c3cccc4c3sc3ccccc34)nc(-c3cc(-c4cccc5ccccc45)cc4oc5ccccc5c34)n2)c1]

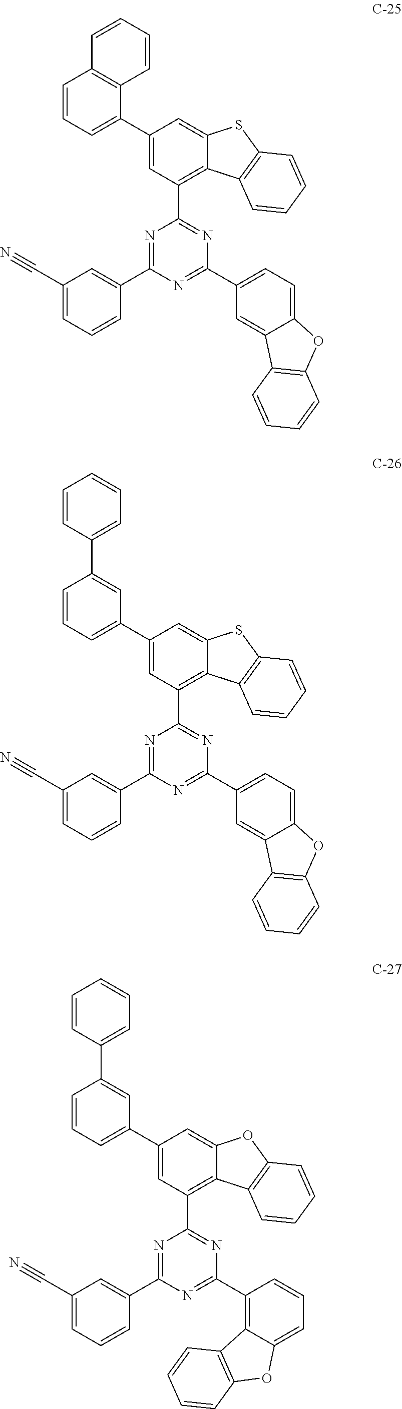 [SMILES: N#Cc1cccc(-c2nc(-c3ccc4oc5ccccc5c4c3)nc(-c3cc(-c4cccc5ccccc45)cc4sc5ccccc5c34)n2)c1 ; N#Cc1cccc(-c2nc(-c3ccc4oc5ccccc5c4c3)nc(-c3cc(-c4cccc(-c5ccccc5)c4)cc4sc5ccccc5c34)n2)c1 ; N#Cc1cccc(-c2nc(-c3cccc4oc5ccccc5c34)nc(-c3cc(-c4cccc(-c5ccccc5)c4)cc4oc5ccccc5c34)n2)c1]

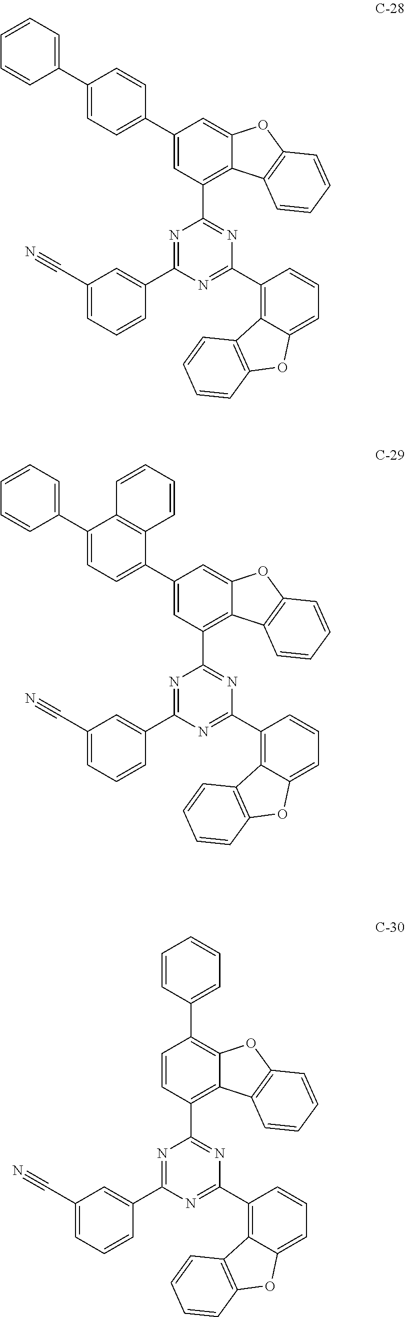 [SMILES: N#Cc1cccc(-c2nc(-c3cccc4oc5ccccc5c34)nc(-c3cc(-c4ccc(-c5ccccc5)cc4)cc4oc5ccccc5c34)n2)c1 ; N#Cc1cccc(-c2nc(-c3cccc4oc5ccccc5c34)nc(-c3cc(-c4ccc(-c5ccccc5)c5ccccc45)cc4oc5ccccc5c34)n2)c1 ; N#Cc1cccc(-c2nc(-c3cccc4oc5ccccc5c34)nc(-c3ccc(-c4ccccc4)c4oc5ccccc5c34)n2)c1]

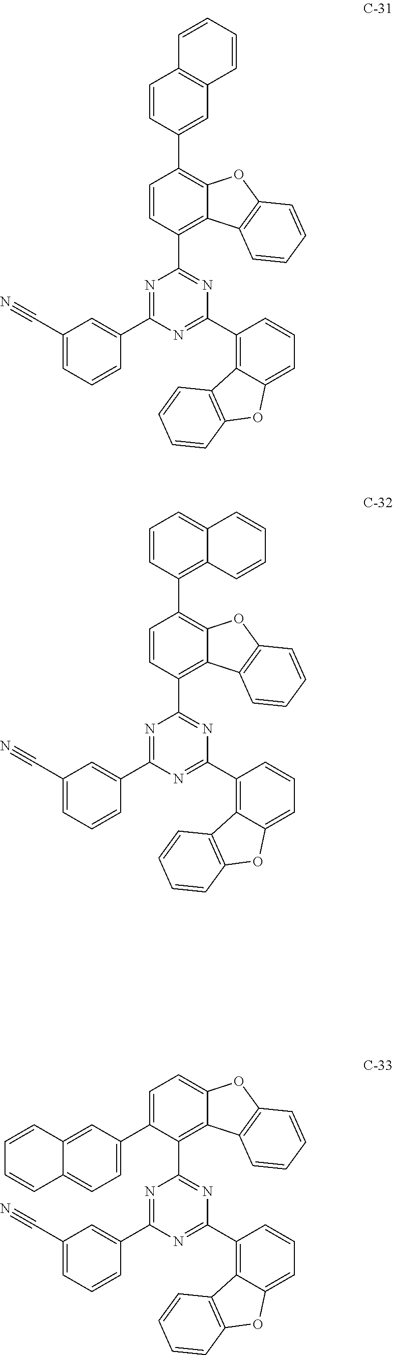 [SMILES: N#Cc1cccc(-c2nc(-c3cccc4oc5ccccc5c34)nc(-c3ccc(-c4ccc5ccccc5c4)c4oc5ccccc5c34)n2)c1 ; N#Cc1cccc(-c2nc(-c3cccc4oc5ccccc5c34)nc(-c3ccc(-c4cccc5ccccc45)c4oc5ccccc5c34)n2)c1 ; N#Cc1cccc(-c2nc(-c3cccc4oc5ccccc5c34)nc(-c3c(-c4ccc5ccccc5c4)ccc4oc5ccccc5c34)n2)c1]

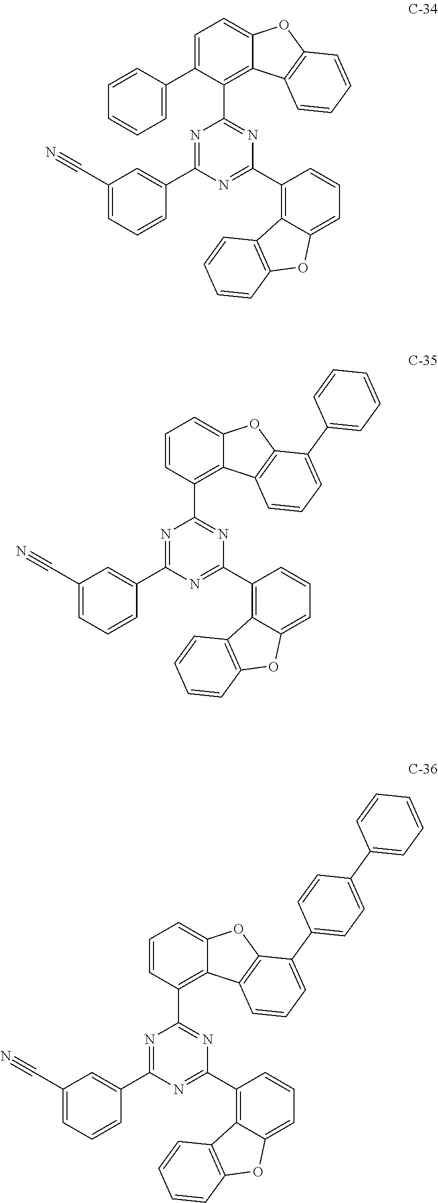 [SMILES: N#Cc1cccc(-c2nc(-c3cccc4oc5ccccc5c34)nc(-c3c(-c4ccccc4)ccc4oc5ccccc5c34)n2)c1 ; N#Cc1cccc(-c2nc(-c3cccc4oc5ccccc5c34)nc(-c3cccc4oc5c(-c6ccccc6)cccc5c34)n2)c1 ; N#Cc1cccc(-c2nc(-c3cccc4oc5ccccc5c34)nc(-c3cccc4oc5c(-c6ccc(-c7ccccc7)cc6)cccc5c34)n2)c1]

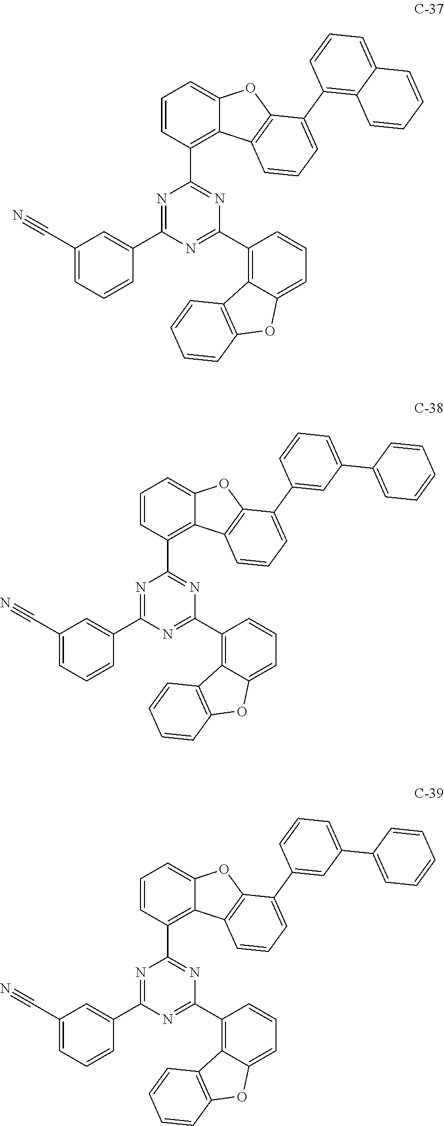 [SMILES: N#Cc1cccc(-c2nc(-c3cccc4oc5ccccc5c34)nc(-c3cccc4oc5c(-c6cccc7ccccc67)cccc5c34)n2)c1 ; N#Cc1cccc(-c2nc(-c3cccc4oc5ccccc5c34)nc(-c3cccc4oc5c(-c6cccc(-c7ccccc7)c6)cccc5c34)n2)c1 ; N#Cc1cccc(-c2nc(-c3cccc4oc5ccccc5c34)nc(-c3cccc4oc5c(-c6cccc(-c7ccccc7)c6)cccc5c34)n2)c1]

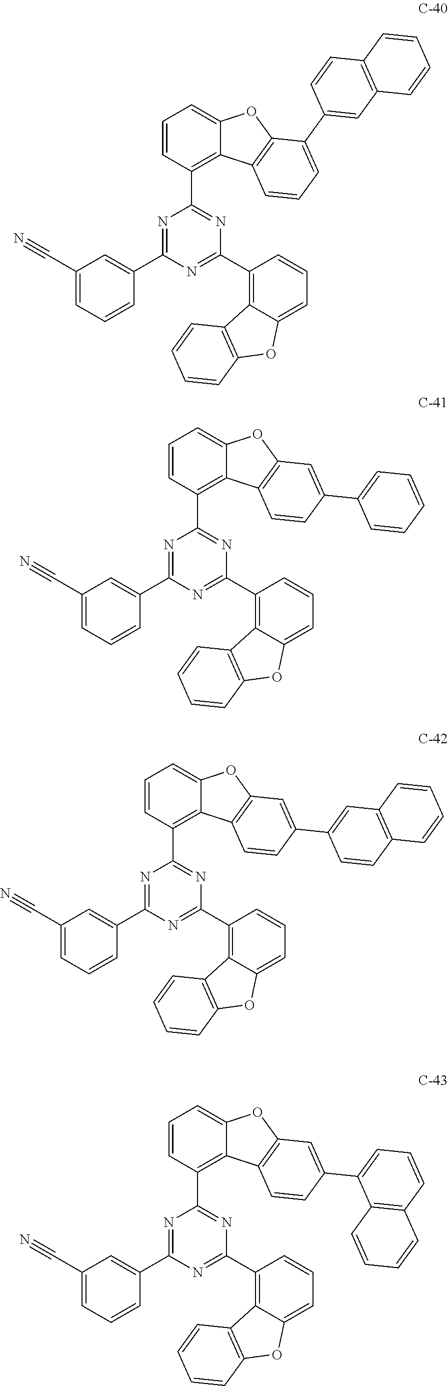 [SMILES: N#Cc1cccc(-c2nc(-c3cccc4oc5ccccc5c34)nc(-c3cccc4oc5c(-c6ccc7ccccc7c6)cccc5c34)n2)c1 ; N#Cc1cccc(-c2nc(-c3cccc4oc5ccccc5c34)nc(-c3cccc4oc5cc(-c6ccccc6)ccc5c34)n2)c1 ; N#Cc1cccc(-c2nc(-c3cccc4oc5ccccc5c34)nc(-c3cccc4oc5cc(-c6ccc7ccccc7c6)ccc5c34)n2)c1 ; N#Cc1cccc(-c2nc(-c3cccc4oc5ccccc5c34)nc(-c3cccc4oc5cc(-c6cccc7ccccc67)ccc5c34)n2)c1]

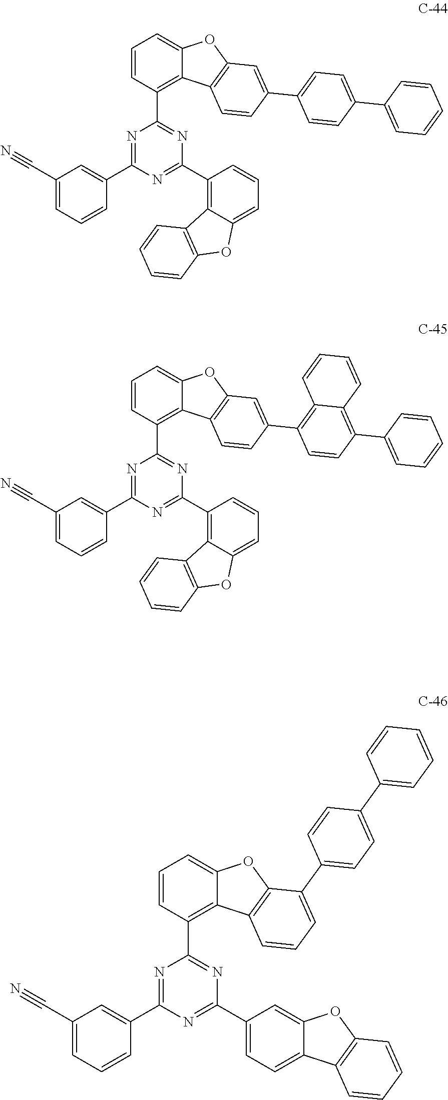 [SMILES: N#Cc1cccc(-c2nc(-c3cccc4oc5ccccc5c34)nc(-c3cccc4oc5cc(-c6ccc(-c7ccccc7)cc6)ccc5c34)n2)c1 ; N#Cc1cccc(-c2nc(-c3cccc4oc5ccccc5c34)nc(-c3cccc4oc5cc(-c6ccc(-c7ccccc7)c7ccccc67)ccc5c34)n2)c1 ; N#Cc1cccc(-c2nc(-c3ccc4c(c3)oc3ccccc34)nc(-c3cccc4oc5c(-c6ccc(-c7ccccc7)cc6)cccc5c34)n2)c1]

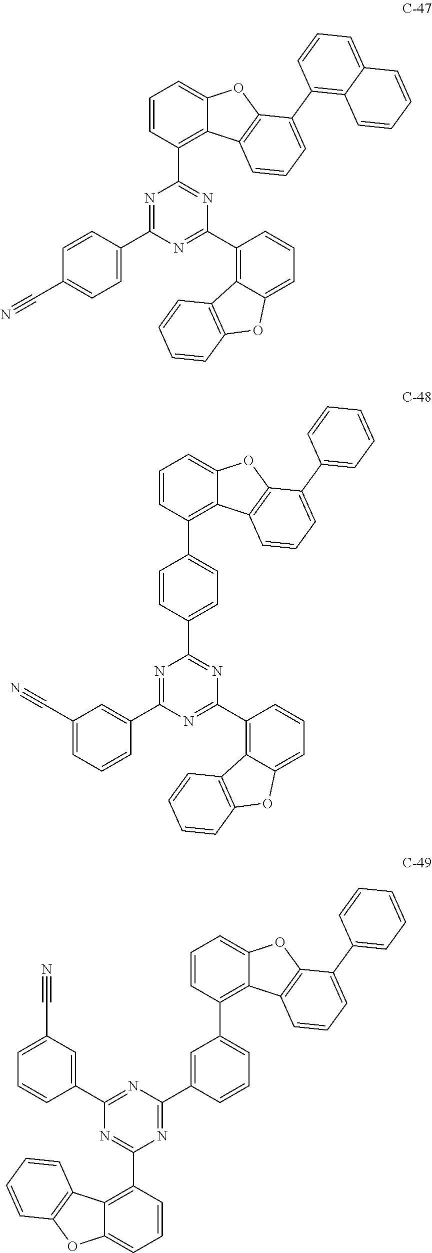 [SMILES: N#Cc1ccc(-c2nc(-c3cccc4oc5ccccc5c34)nc(-c3cccc4oc5c(-c6cccc7ccccc67)cccc5c34)n2)cc1 ; N#Cc1cccc(-c2nc(-c3ccc(-c4cccc5oc6c(-c7ccccc7)cccc6c45)cc3)nc(-c3cccc4oc5ccccc5c34)n2)c1 ; N#Cc1cccc(-c2nc(-c3cccc(-c4cccc5oc6c(-c7ccccc7)cccc6c45)c3)nc(-c3cccc4oc5ccccc5c34)n2)c1]

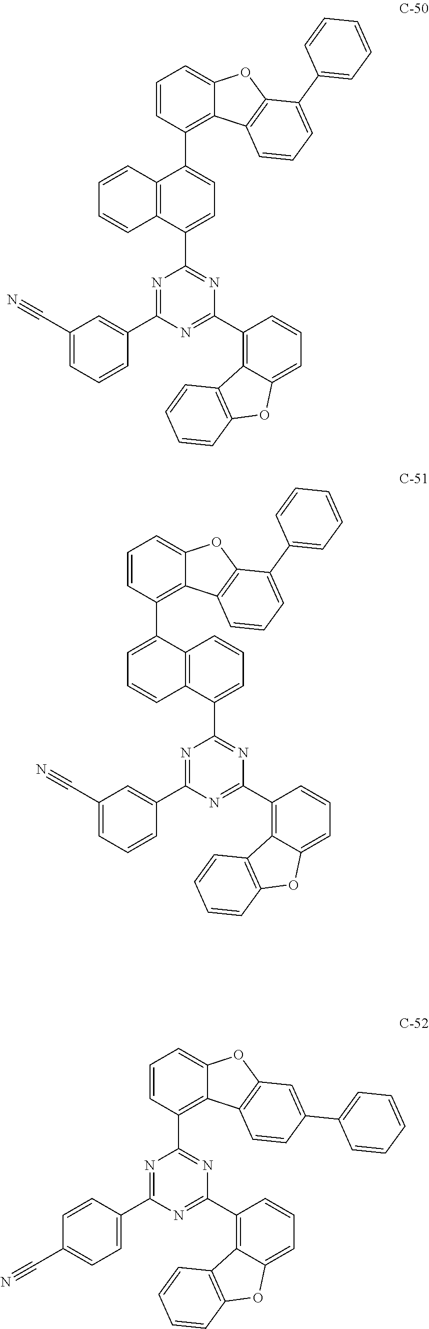 [SMILES: N#Cc1cccc(-c2nc(-c3ccc(-c4cccc5oc6c(-c7ccccc7)cccc6c45)c4ccccc34)nc(-c3cccc4oc5ccccc5c34)n2)c1 ; N#Cc1cccc(-c2nc(-c3cccc4c(-c5cccc6oc7c(-c8ccccc8)cccc7c56)cccc34)nc(-c3cccc4oc5ccccc5c34)n2)c1 ; N#Cc1ccc(-c2nc(-c3cccc4oc5ccccc5c34)nc(-c3cccc4oc5cc(-c6ccccc6)ccc5c34)n2)cc1]

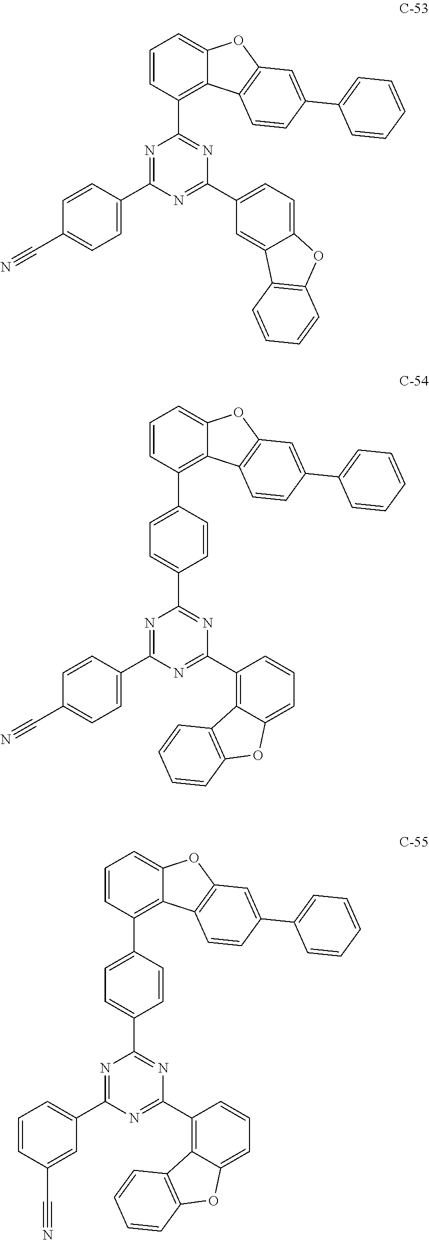 [SMILES: N#Cc1ccc(-c2nc(-c3ccc4oc5ccccc5c4c3)nc(-c3cccc4oc5cc(-c6ccccc6)ccc5c34)n2)cc1 ; N#Cc1ccc(-c2nc(-c3ccc(-c4cccc5oc6cc(-c7ccccc7)ccc6c45)cc3)nc(-c3cccc4oc5ccccc5c34)n2)cc1 ; N#Cc1cccc(-c2nc(-c3ccc(-c4cccc5oc6cc(-c7ccccc7)ccc6c45)cc3)nc(-c3cccc4oc5ccccc5c34)n2)c1]

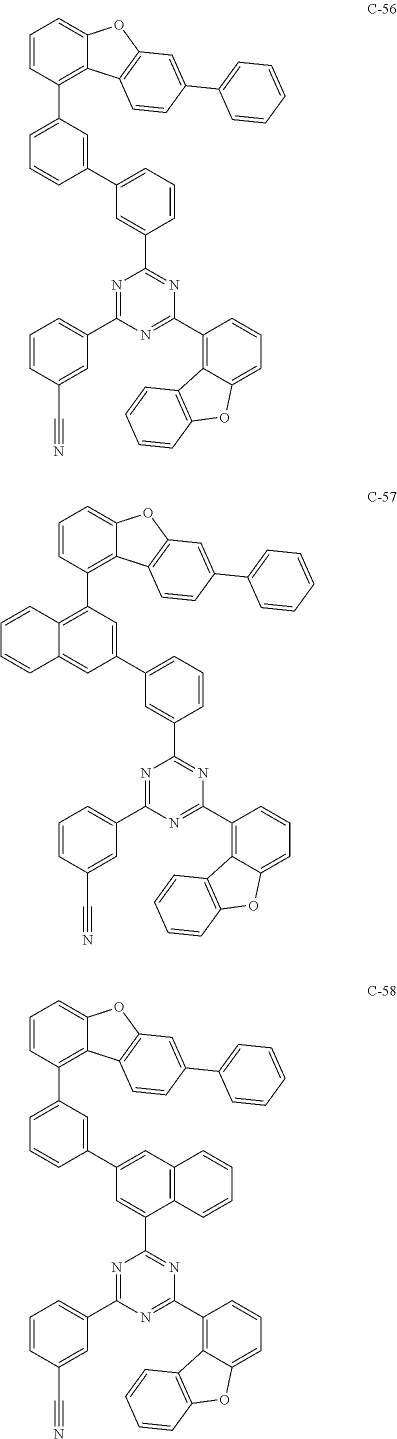 [SMILES: N#Cc1cccc(-c2nc(-c3cccc(-c4cccc(-c5cccc6oc7cc(-c8ccccc8)ccc7c56)c4)c3)nc(-c3cccc4oc5ccccc5c34)n2)c1 ; N#Cc1cccc(-c2nc(-c3cccc(-c4cc(-c5cccc6oc7cc(-c8ccccc8)ccc7c56)c5ccccc5c4)c3)nc(-c3cccc4oc5ccccc5c34)n2)c1 ; N#Cc1cccc(-c2nc(-c3cc(-c4cccc(-c5cccc6oc7cc(-c8ccccc8)ccc7c56)c4)cc4ccccc34)nc(-c3cccc4oc5ccccc5c34)n2)c1]

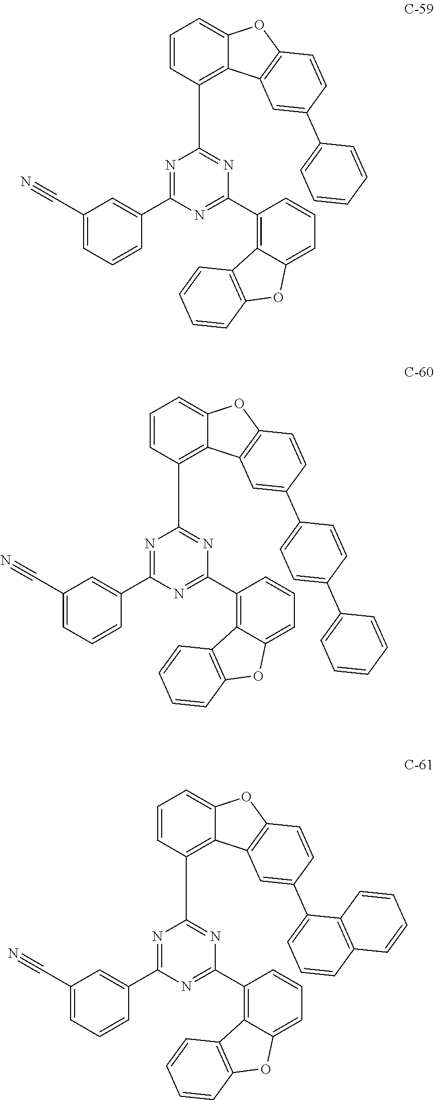 [SMILES: N#Cc1cccc(-c2nc(-c3cccc4oc5ccccc5c34)nc(-c3cccc4oc5ccc(-c6ccccc6)cc5c34)n2)c1 ; N#Cc1cccc(-c2nc(-c3cccc4oc5ccccc5c34)nc(-c3cccc4oc5ccc(-c6ccc(-c7ccccc7)cc6)cc5c34)n2)c1 ; N#Cc1cccc(-c2nc(-c3cccc4oc5ccccc5c34)nc(-c3cccc4oc5ccc(-c6cccc7ccccc67)cc5c34)n2)c1]

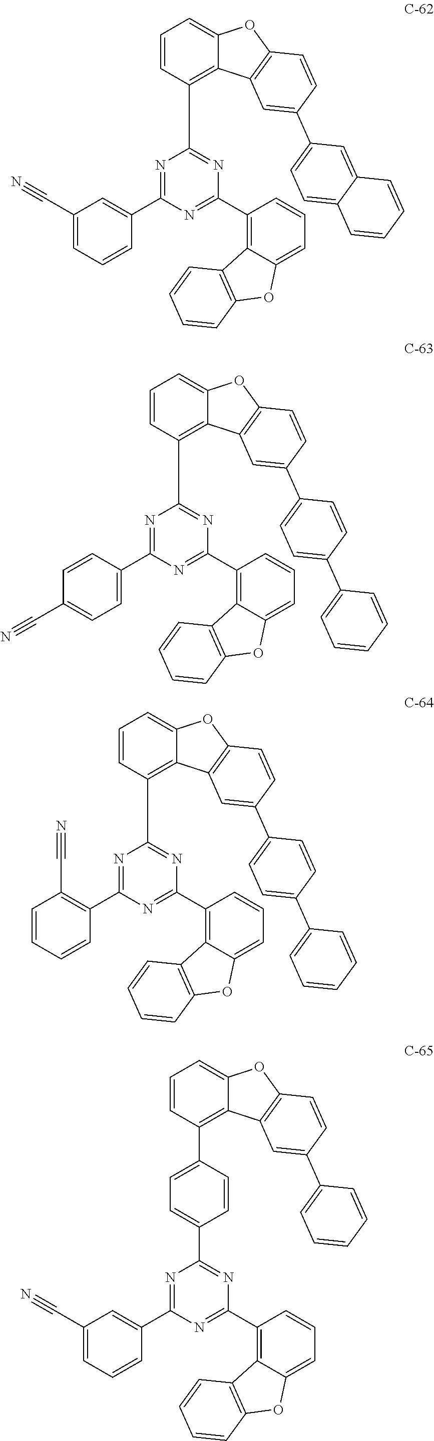

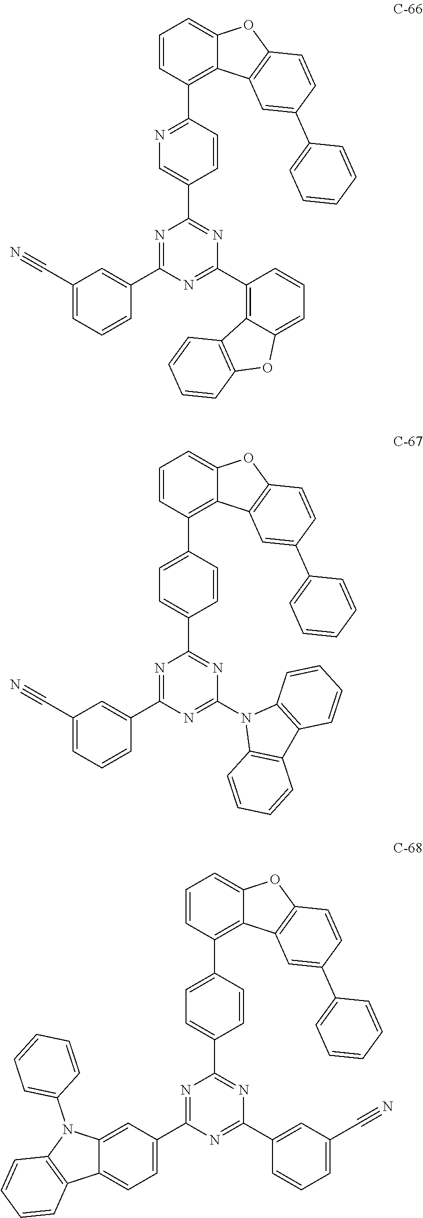 [SMILES: N#Cc1cccc(-c2nc(-c3ccc(-c4cccc5oc6ccc(-c7ccccc7)cc6c45)nc3)nc(-c3cccc4oc5ccccc5c34)n2)c1 ; N#Cc1cccc(-c2nc(-c3ccc(-c4cccc5oc6ccc(-c7ccccc7)cc6c45)cc3)nc(-n3c4ccccc4c4ccccc43)n2)c1 ; N#Cc1cccc(-c2nc(-c3ccc(-c4cccc5oc6ccc(-c7ccccc7)cc6c45)cc3)nc(-c3ccc4c5ccccc5n(-c5ccccc5)c4c3)n2)c1]

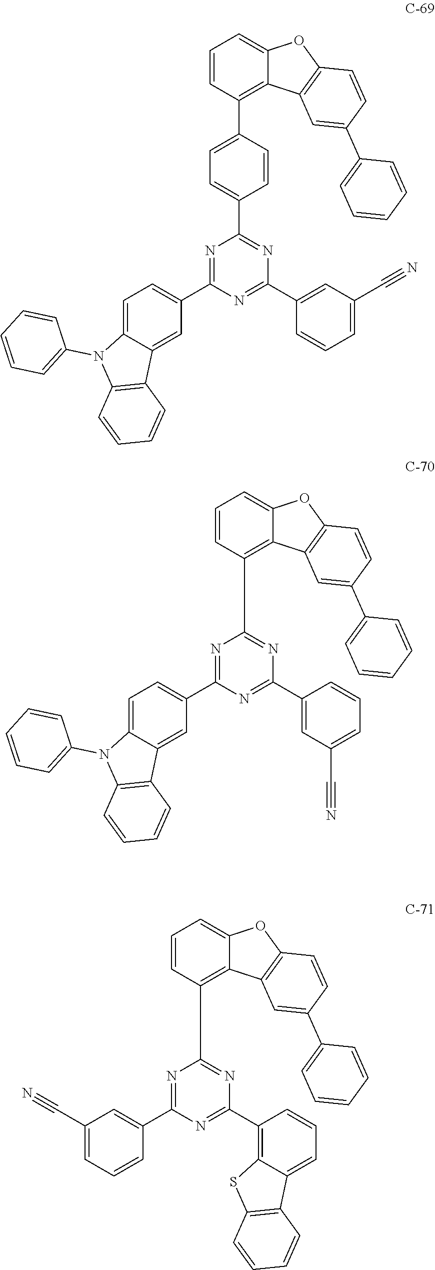 [SMILES: N#Cc1cccc(-c2nc(-c3ccc(-c4cccc5oc6ccc(-c7ccccc7)cc6c45)cc3)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4oc5ccc(-c6ccccc6)cc5c34)n2)c1 ; N#Cc1cccc(-c2nc(-c3cccc4c3sc3ccccc34)nc(-c3cccc4oc5ccc(-c6ccccc6)cc5c34)n2)c1]

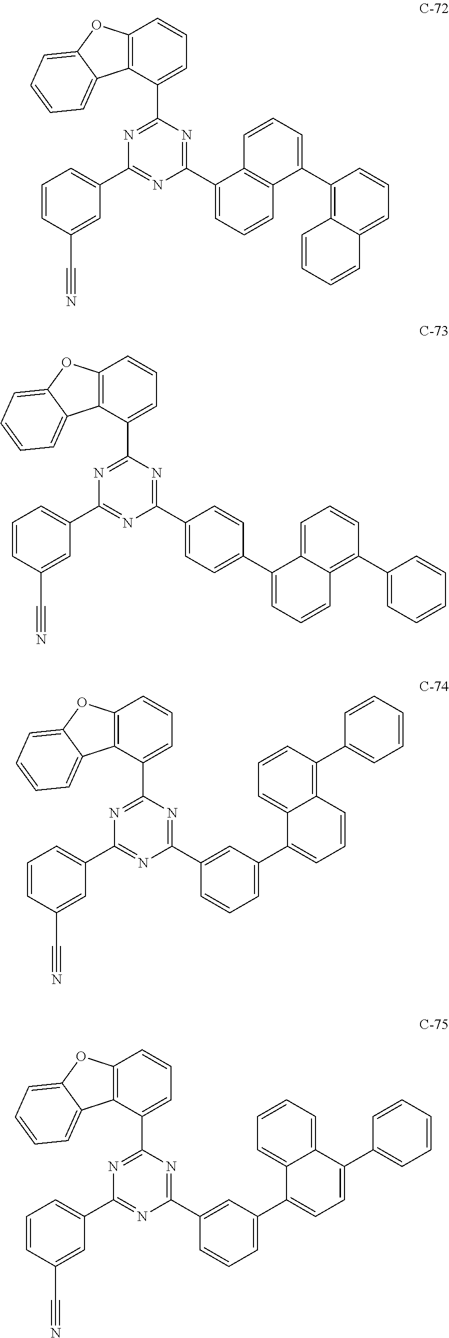 [SMILES: N#Cc1cccc(-c2nc(-c3cccc4c(-c5cccc6ccccc56)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1 ; N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1]

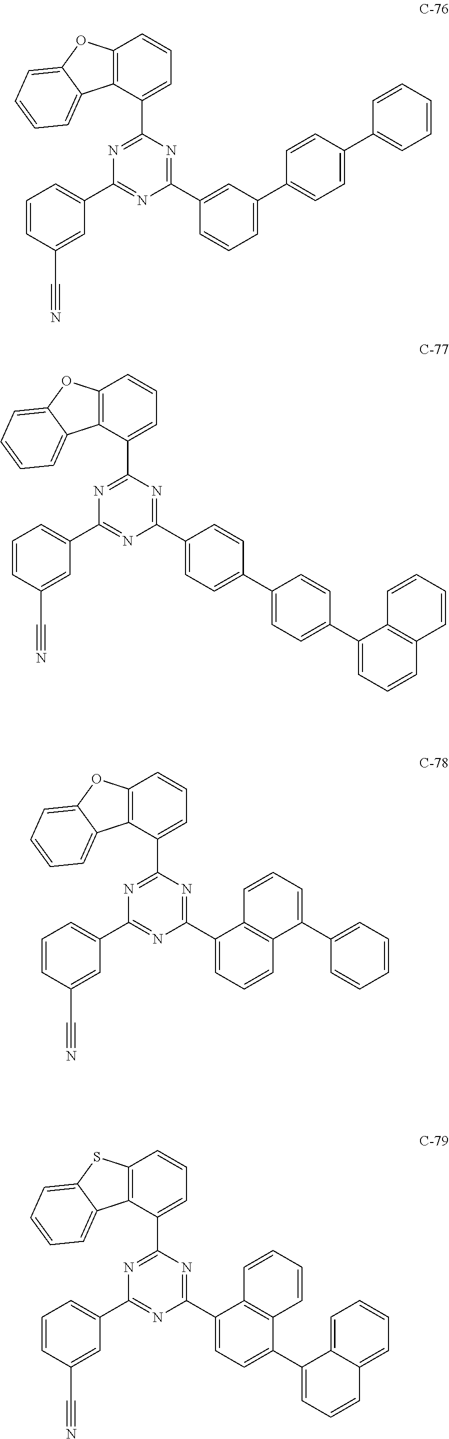 [SMILES: N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3ccc(-c4ccc(-c5cccc6ccccc56)cc4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1 ; N#Cc1cccc(-c2nc(-c3ccc(-c4cccc5ccccc45)c4ccccc34)nc(-c3cccc4sc5ccccc5c34)n2)c1]

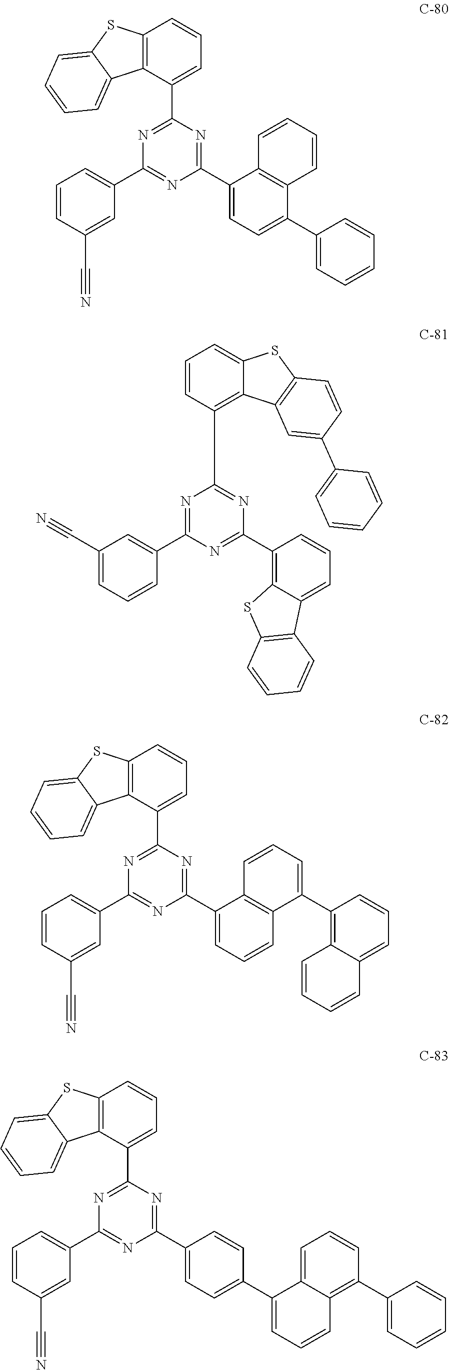 [SMILES: N#Cc1cccc(-c2nc(-c3ccc(-c4ccccc4)c4ccccc34)nc(-c3cccc4sc5ccccc5c34)n2)c1 ; N#Cc1cccc(-c2nc(-c3cccc4c3sc3ccccc34)nc(-c3cccc4sc5ccc(-c6ccccc6)cc5c34)n2)c1 ; N#Cc1cccc(-c2nc(-c3cccc4c(-c5cccc6ccccc56)cccc34)nc(-c3cccc4sc5ccccc5c34)n2)c1 ; N#Cc1cccc(-c2nc(-c3ccc(-c4cccc5c(-c6ccccc6)cccc45)cc3)nc(-c3cccc4sc5ccccc5c34)n2)c1]

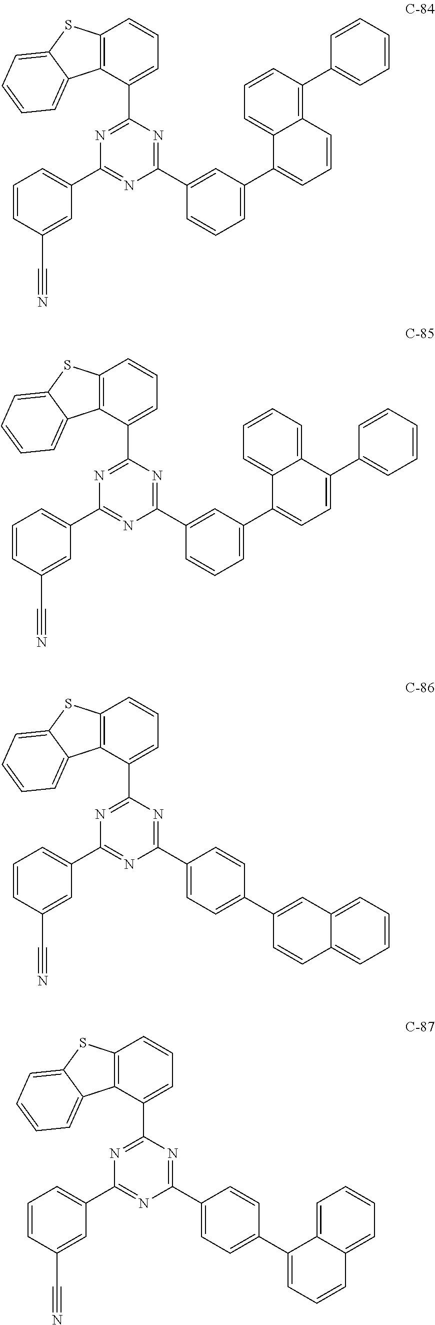 [SMILES: N#Cc1cccc(-c2nc(-c3cccc(-c4cccc5c(-c6ccccc6)cccc45)c3)nc(-c3cccc4sc5ccccc5c34)n2)c1 ; N#Cc1cccc(-c2nc(-c3cccc(-c4ccc(-c5ccccc5)c5ccccc45)c3)nc(-c3cccc4sc5ccccc5c34)n2)c1 ; N#Cc1cccc(-c2nc(-c3ccc(-c4ccc5ccccc5c4)cc3)nc(-c3cccc4sc5ccccc5c34)n2)c1 ; N#Cc1cccc(-c2nc(-c3ccc(-c4cccc5ccccc45)cc3)nc(-c3cccc4sc5ccccc5c34)n2)c1]

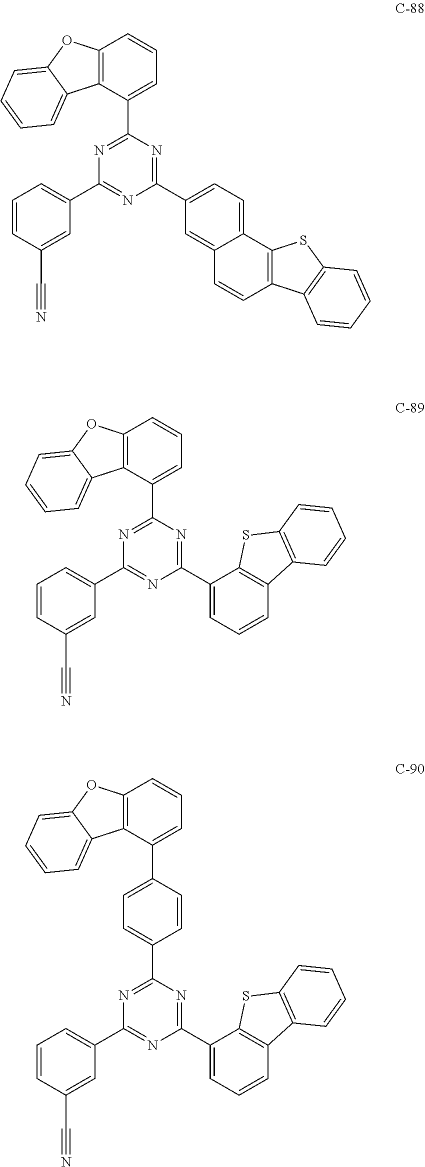 [SMILES: N#Cc1cccc(-c2nc(-c3ccc4c(ccc5c6ccccc6sc45)c3)nc(-c3cccc4oc5ccccc5c34)n2)c1 ; N#Cc1cccc(-c2nc(-c3cccc4c3sc3ccccc34)nc(-c3cccc4oc5ccccc5c34)n2)c1 ; N#Cc1cccc(-c2nc(-c3ccc(-c4cccc5oc6ccccc6c45)cc3)nc(-c3cccc4c3sc3ccccc34)n2)c1]

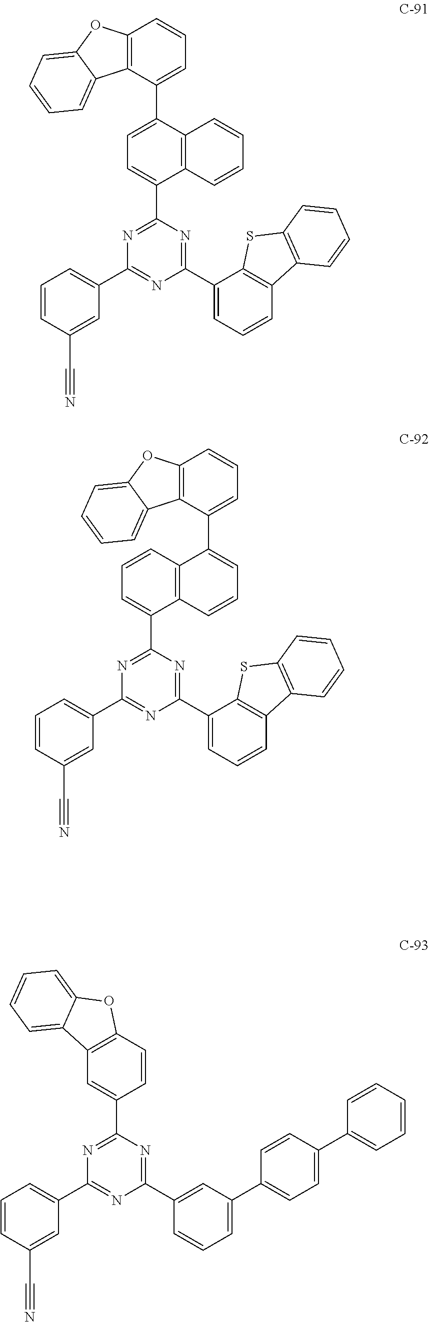 [SMILES: N#Cc1cccc(-c2nc(-c3ccc(-c4cccc5oc6ccccc6c45)c4ccccc34)nc(-c3cccc4c3sc3ccccc34)n2)c1 ; N#Cc1cccc(-c2nc(-c3cccc4c(-c5cccc6oc7ccccc7c56)cccc34)nc(-c3cccc4c3sc3ccccc34)n2)c1 ; N#Cc1cccc(-c2nc(-c3cccc(-c4ccc(-c5ccccc5)cc4)c3)nc(-c3ccc4oc5ccccc5c4c3)n2)c1]

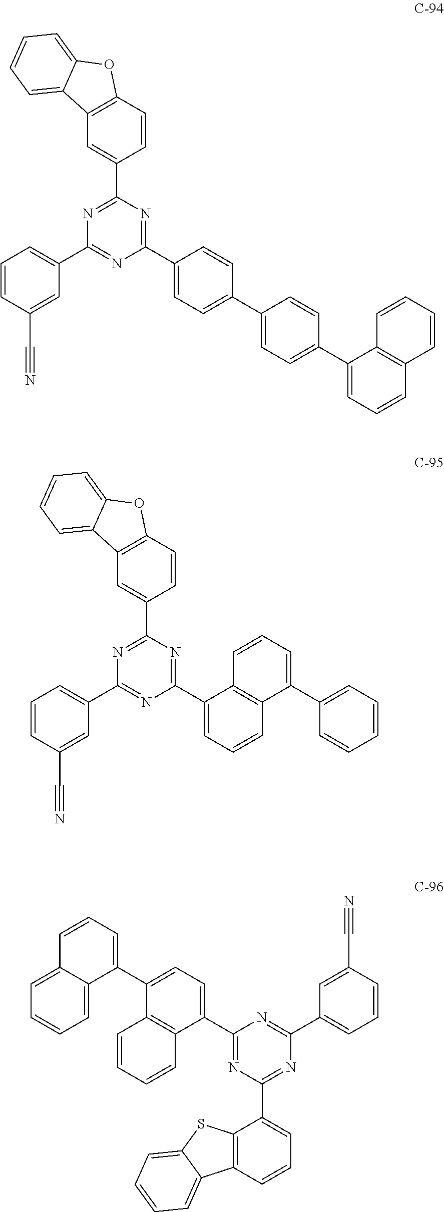 [SMILES: N#Cc1cccc(-c2nc(-c3ccc(-c4ccc(-c5cccc6ccccc56)cc4)cc3)nc(-c3ccc4oc5ccccc5c4c3)n2)c1 ; N#Cc1cccc(-c2nc(-c3ccc4oc5ccccc5c4c3)nc(-c3cccc4c(-c5ccccc5)cccc34)n2)c1 ; N#Cc1cccc(-c2nc(-c3ccc(-c4cccc5ccccc45)c4ccccc34)nc(-c3cccc4c3sc3ccccc34)n2)c1]

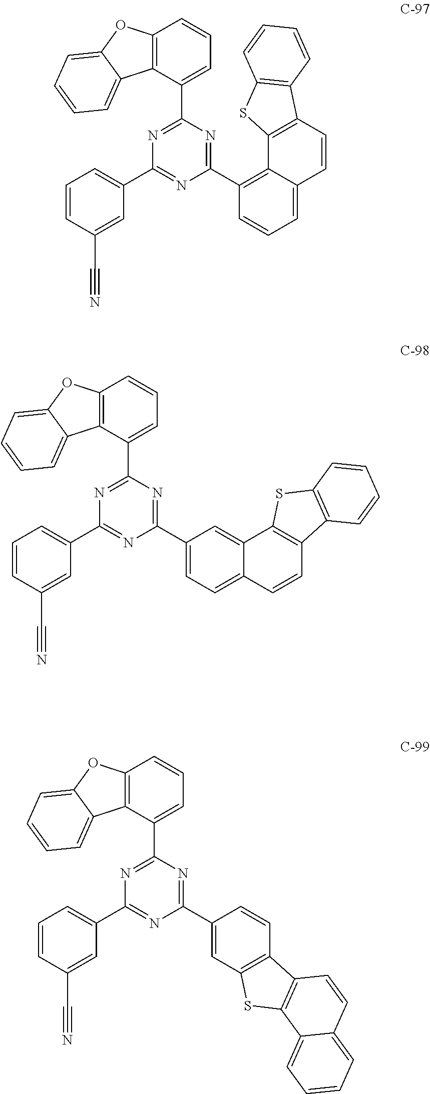 [SMILES: N#Cc1cccc(-c2nc(-c3cccc4oc5ccccc5c34)nc(-c3cccc4ccc5c6ccccc6sc5c34)n2)c1 ; N#Cc1cccc(-c2nc(-c3ccc4ccc5c6ccccc6sc5c4c3)nc(-c3cccc4oc5ccccc5c34)n2)c1 ; N#Cc1cccc(-c2nc(-c3ccc4c(c3)sc3c5ccccc5ccc43)nc(-c3cccc4oc5ccccc5c34)n2)c1]

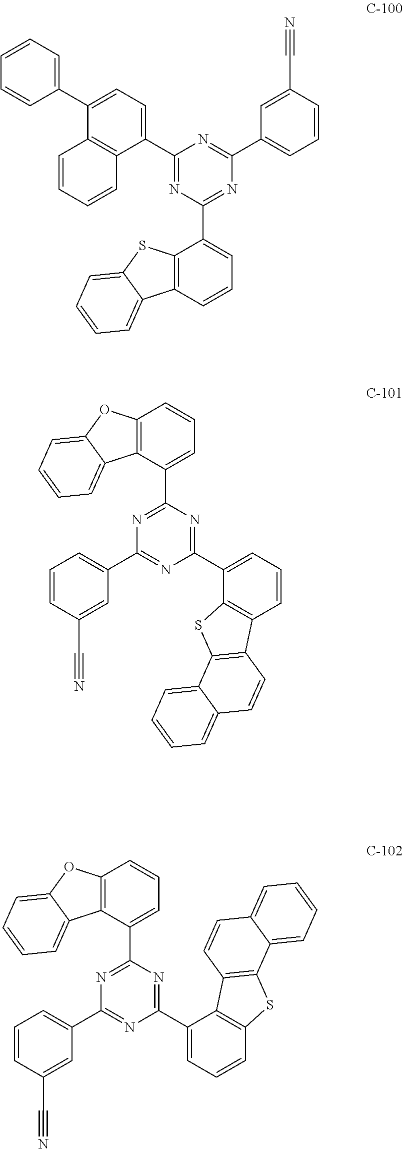 [SMILES: N#Cc1cccc(-c2nc(-c3ccc(-c4ccccc4)c4ccccc34)nc(-c3cccc4c3sc3ccccc34)n2)c1 ; N#Cc1cccc(-c2nc(-c3cccc4c3sc3c5ccccc5ccc43)nc(-c3cccc4oc5ccccc5c34)n2)c1 ; N#Cc1cccc(-c2nc(-c3cccc4oc5ccccc5c34)nc(-c3cccc4sc5c6ccccc6ccc5c34)n2)c1]

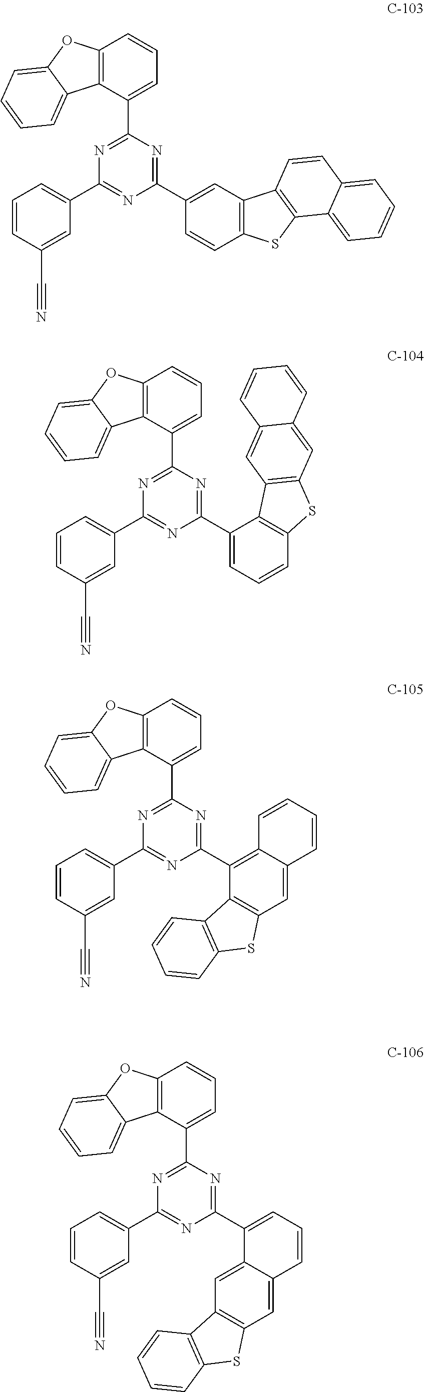 [SMILES: N#Cc1cccc(-c2nc(-c3ccc4sc5c6ccccc6ccc5c4c3)nc(-c3cccc4oc5ccccc5c34)n2)c1 ; N#Cc1cccc(-c2nc(-c3cccc4oc5ccccc5c34)nc(-c3cccc4sc5cc6ccccc6cc5c34)n2)c1 ; N#Cc1cccc(-c2nc(-c3cccc4oc5ccccc5c34)nc(-c3c4ccccc4cc4sc5ccccc5c34)n2)c1 ; N#Cc1cccc(-c2nc(-c3cccc4cc5sc6ccccc6c5cc34)nc(-c3cccc4oc5ccccc5c34)n2)c1]

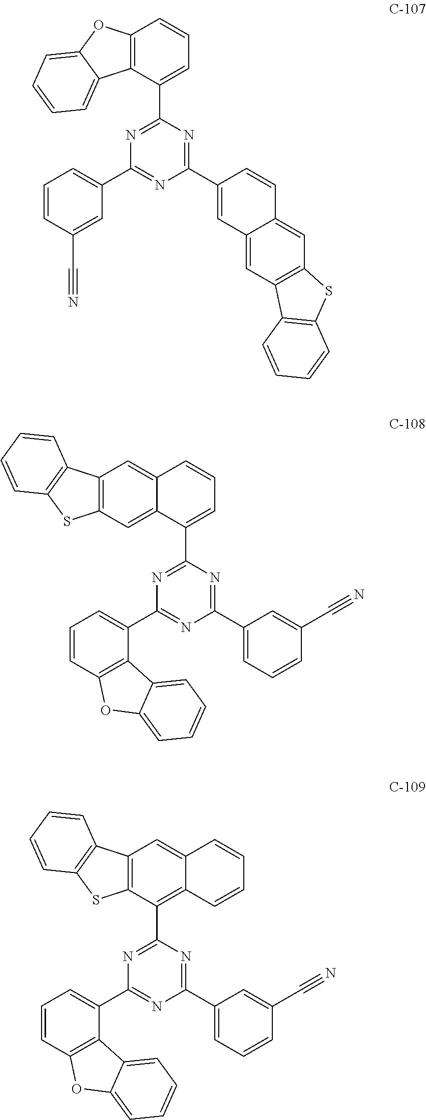 [SMILES: N#Cc1cccc(-c2nc(-c3ccc4cc5sc6ccccc6c5cc4c3)nc(-c3cccc4oc5ccccc5c34)n2)c1 ; N#Cc1cccc(-c2nc(-c3cccc4cc5c(cc34)sc3ccccc35)nc(-c3cccc4oc5ccccc5c34)n2)c1 ; N#Cc1cccc(-c2nc(-c3c4ccccc4cc4c3sc3ccccc34)nc(-c3cccc4oc5ccccc5c34)n2)c1]

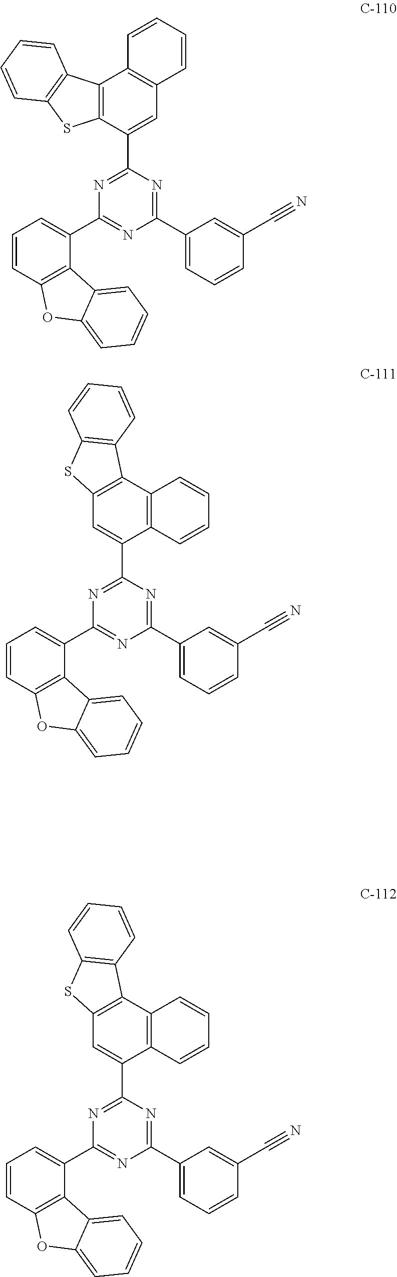

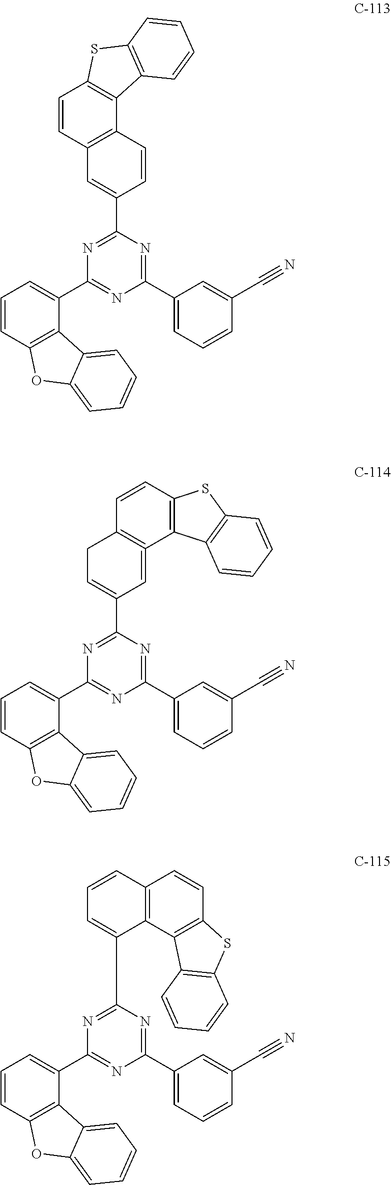

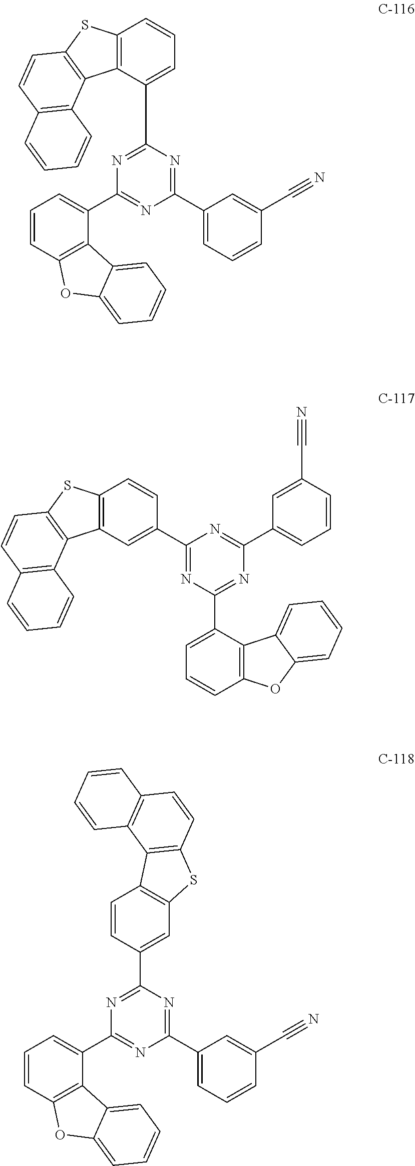 [SMILES: N#Cc1cccc(-c2nc(-c3cccc4oc5ccccc5c34)nc(-c3cccc4sc5ccc6ccccc6c5c34)n2)c1 ; N#Cc1cccc(-c2nc(-c3ccc4sc5ccc6ccccc6c5c4c3)nc(-c3cccc4oc5ccccc5c34)n2)c1 ; N#Cc1cccc(-c2nc(-c3ccc4c(c3)sc3ccc5ccccc5c34)nc(-c3cccc4oc5ccccc5c34)n2)c1]

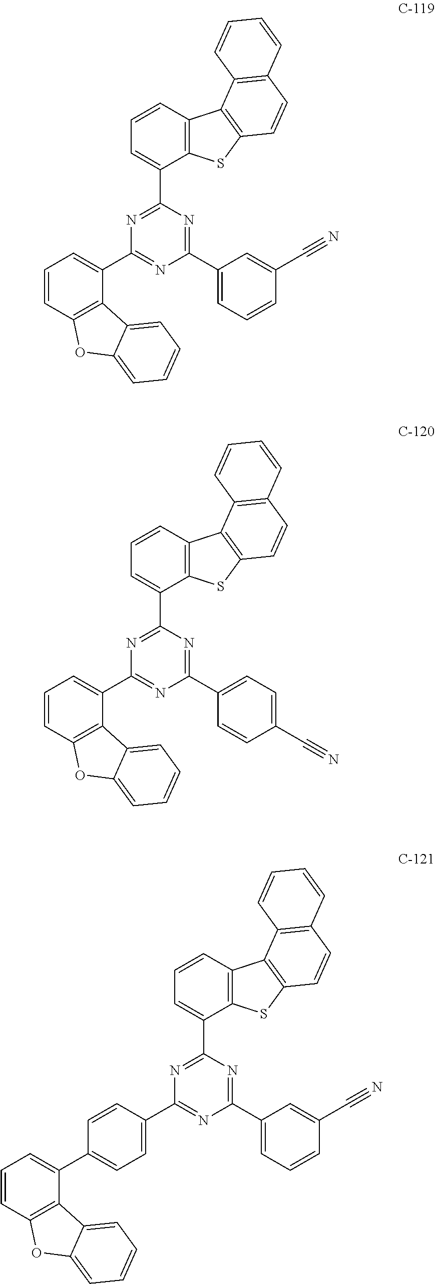 [SMILES: N#Cc1cccc(-c2nc(-c3cccc4c3sc3ccc5ccccc5c34)nc(-c3cccc4oc5ccccc5c34)n2)c1 ; N#Cc1ccc(-c2nc(-c3cccc4c3sc3ccc5ccccc5c34)nc(-c3cccc4oc5ccccc5c34)n2)cc1 ; N#Cc1cccc(-c2nc(-c3ccc(-c4cccc5oc6ccccc6c45)cc3)nc(-c3cccc4c3sc3ccc5ccccc5c34)n2)c1]

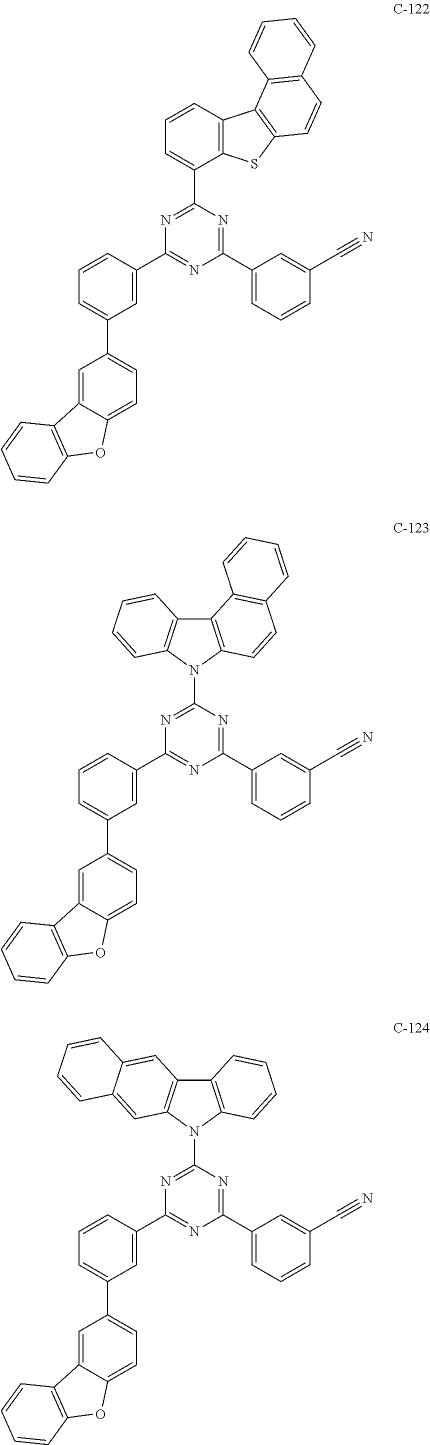 [SMILES: N#Cc1cccc(-c2nc(-c3cccc(-c4ccc5oc6ccccc6c5c4)c3)nc(-c3cccc4c3sc3ccc5ccccc5c34)n2)c1 ; N#Cc1cccc(-c2nc(-c3cccc(-c4ccc5oc6ccccc6c5c4)c3)nc(-n3c4ccccc4c4c5ccccc5ccc43)n2)c1 ; N#Cc1cccc(-c2nc(-c3cccc(-c4ccc5oc6ccccc6c5c4)c3)nc(-n3c4ccccc4c4cc5ccccc5cc43)n2)c1]

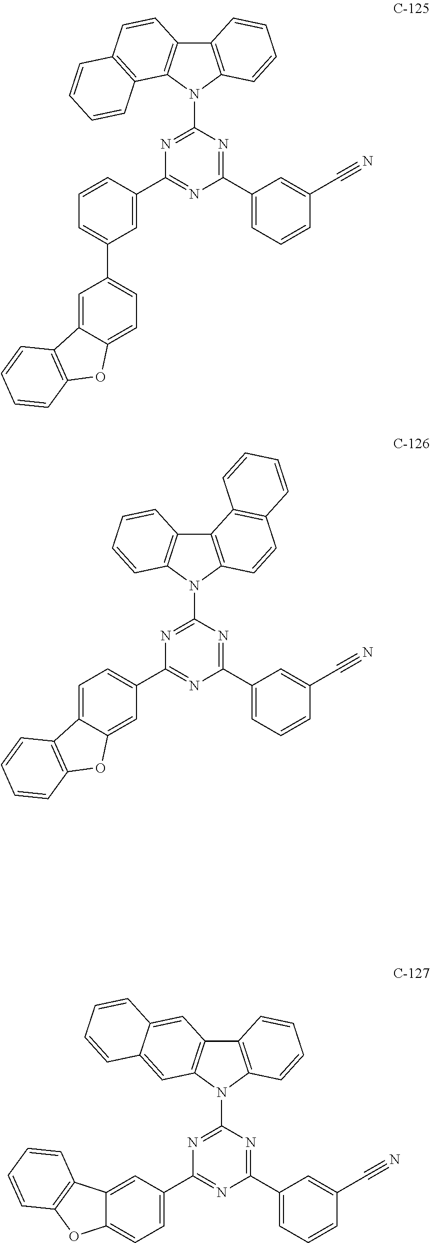 [SMILES: N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4c(c3)oc3ccccc34)nc(-n3c4ccccc4c4c5ccccc5ccc43)n2)c1 ; N#Cc1cccc(-c2nc(-c3ccc4oc5ccccc5c4c3)nc(-n3c4ccccc4c4cc5ccccc5cc43)n2)c1]

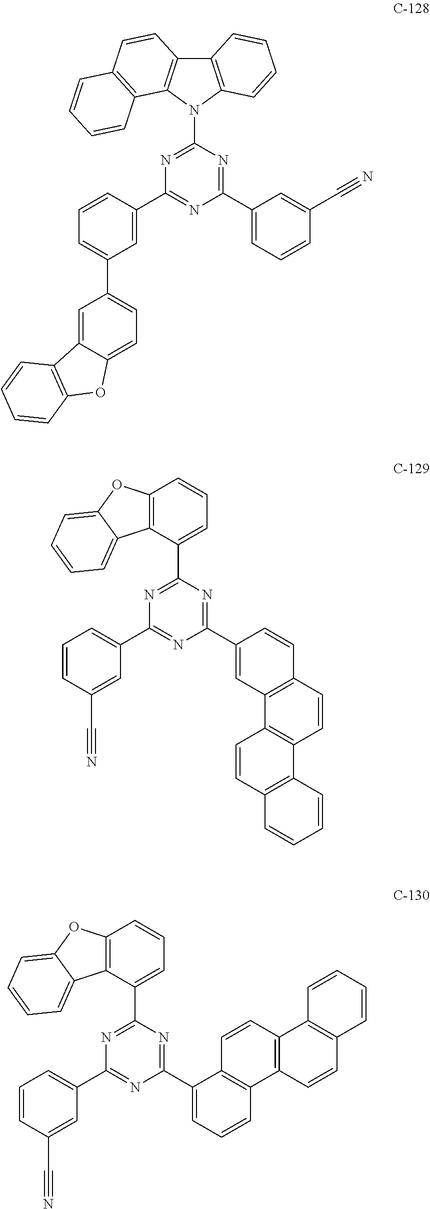 [SMILES: N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4ccc5c6ccccc6ccc5c4c3)nc(-c3cccc4oc5ccccc5c34)n2)c1 ; N#Cc1cccc(-c2nc(-c3cccc4c3ccc3c5ccccc5ccc43)nc(-c3cccc4oc5ccccc5c34)n2)c1]

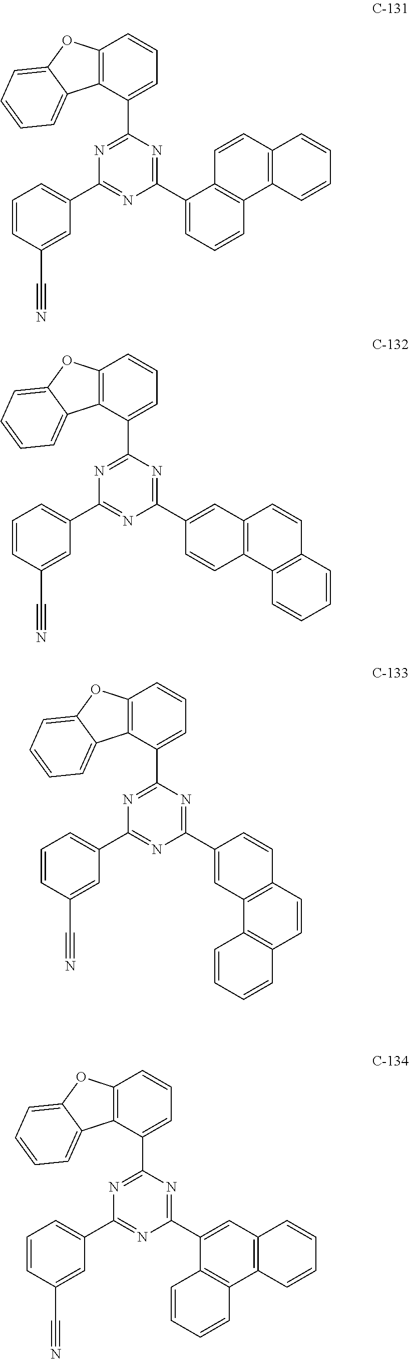 [SMILES: N#Cc1cccc(-c2nc(-c3cccc4c3ccc3ccccc34)nc(-c3cccc4oc5ccccc5c34)n2)c1 ; N#Cc1cccc(-c2nc(-c3ccc4c(ccc5ccccc54)c3)nc(-c3cccc4oc5ccccc5c34)n2)c1 ; N#Cc1cccc(-c2nc(-c3ccc4ccc5ccccc5c4c3)nc(-c3cccc4oc5ccccc5c34)n2)c1 ; N#Cc1cccc(-c2nc(-c3cc4ccccc4c4ccccc34)nc(-c3cccc4oc5ccccc5c34)n2)c1]

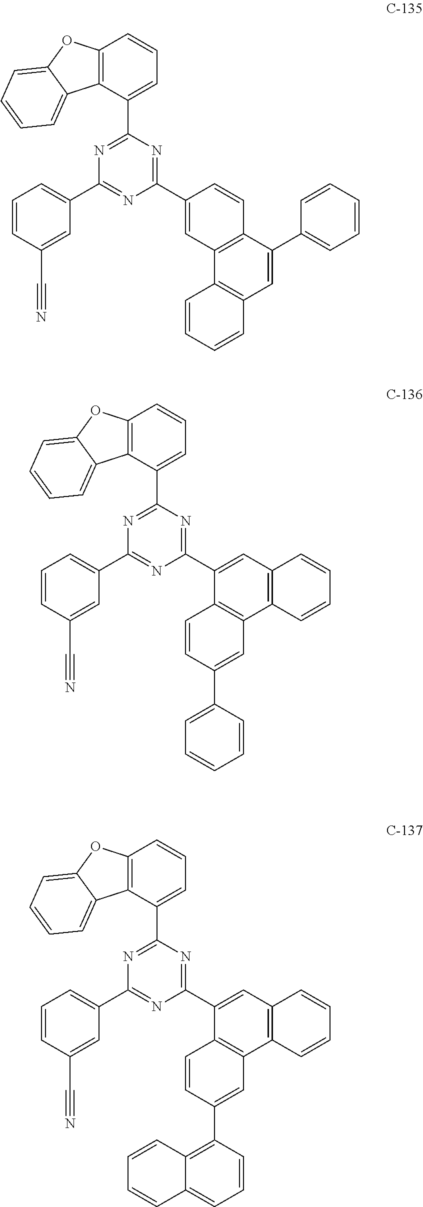 [SMILES: N#Cc1cccc(-c2nc(-c3ccc4c(-c5ccccc5)cc5ccccc5c4c3)nc(-c3cccc4oc5ccccc5c34)n2)c1 ; N#Cc1cccc(-c2nc(-c3cc4ccccc4c4cc(-c5ccccc5)ccc34)nc(-c3cccc4oc5ccccc5c34)n2)c1 ; N#Cc1cccc(-c2nc(-c3cc4ccccc4c4cc(-c5cccc6ccccc56)ccc34)nc(-c3cccc4oc5ccccc5c34)n2)c1]

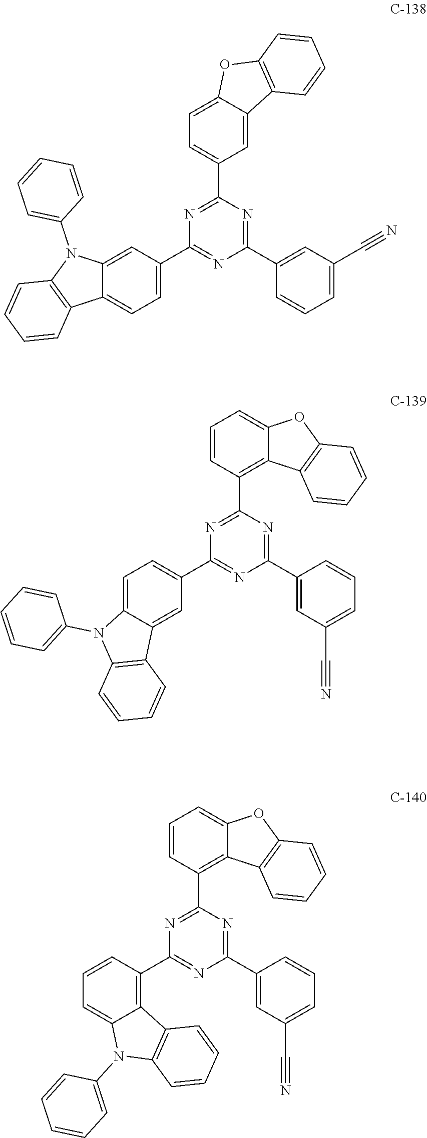 [SMILES: N#Cc1cccc(-c2nc(-c3ccc4oc5ccccc5c4c3)nc(-c3ccc4c5ccccc5n(-c5ccccc5)c4c3)n2)c1 ; N#Cc1cccc(-c2nc(-c3ccc4c(c3)c3ccccc3n4-c3ccccc3)nc(-c3cccc4oc5ccccc5c34)n2)c1 ; N#Cc1cccc(-c2nc(-c3cccc4oc5ccccc5c34)nc(-c3cccc4c3c3ccccc3n4-c3ccccc3)n2)c1]

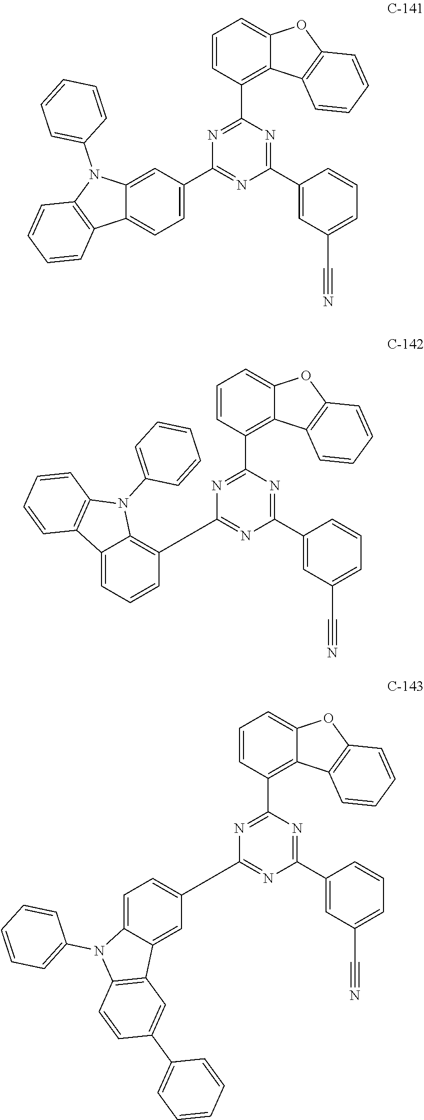 [SMILES: N#Cc1cccc(-c2nc(-c3ccc4c5ccccc5n(-c5ccccc5)c4c3)nc(-c3cccc4oc5ccccc5c34)n2)c1 ; N#Cc1cccc(-c2nc(Cc3cccc4c5ccccc5n(-c5ccccc5)c34)nc(-c3cccc4oc5ccccc5c34)n2)c1 ; N#Cc1cccc(-c2nc(Cc3ccc4c(c3)c3cc(-c5ccccc5)ccc3n4-c3ccccc3)nc(-c3cccc4oc5ccccc5c34)n2)c1]

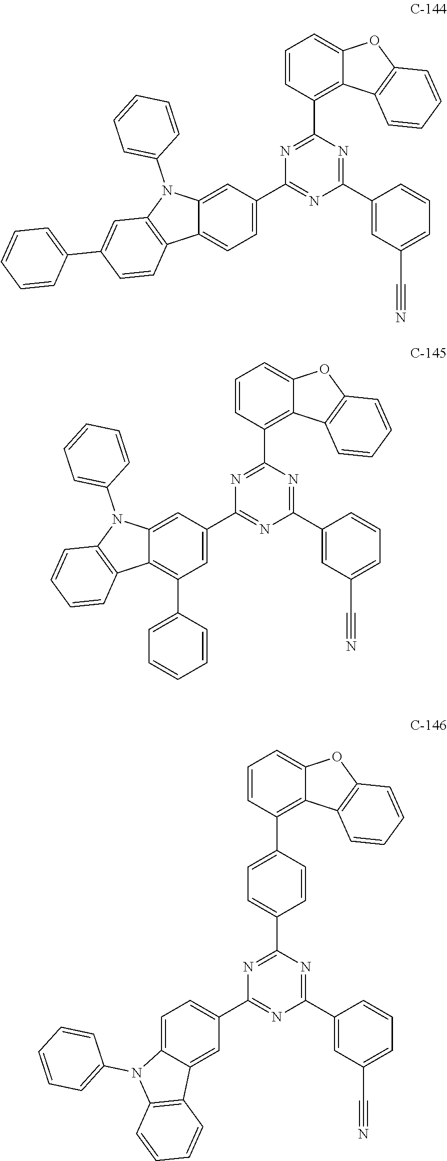 [SMILES: N#Cc1cccc(-c2nc(-c3ccc4c5ccc(-c6ccccc6)cc5n(-c5ccccc5)c4c3)nc(-c3cccc4oc5ccccc5c34)n2)c1 ; N#Cc1cccc(-c2nc(-c3cc(-c4ccccc4)c4c5ccccc5n(-c5ccccc5)c4c3)nc(-c3cccc4oc5ccccc5c34)n2)c1 ; N#Cc1cccc(-c2nc(-c3ccc(-c4cccc5oc6ccccc6c45)cc3)nc(-c3ccc4c(c3)c3ccccc3n4-c3ccccc3)n2)c1]

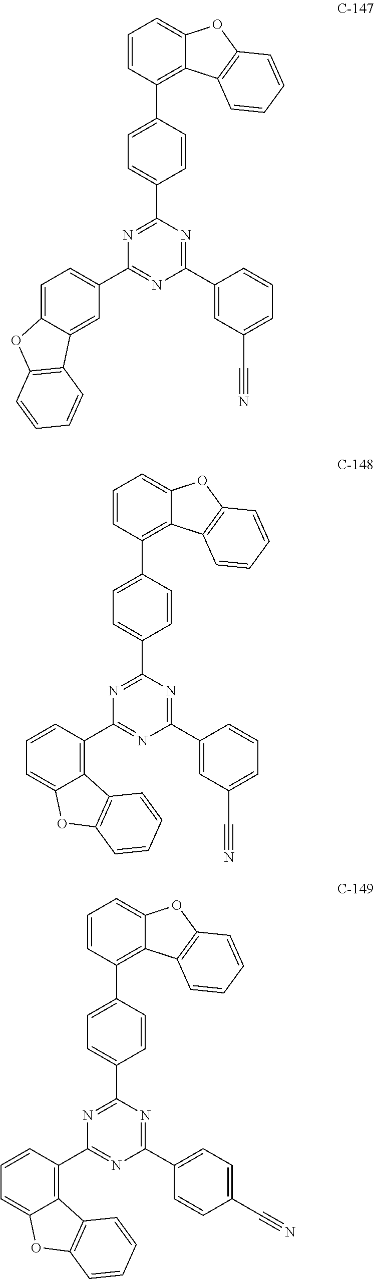

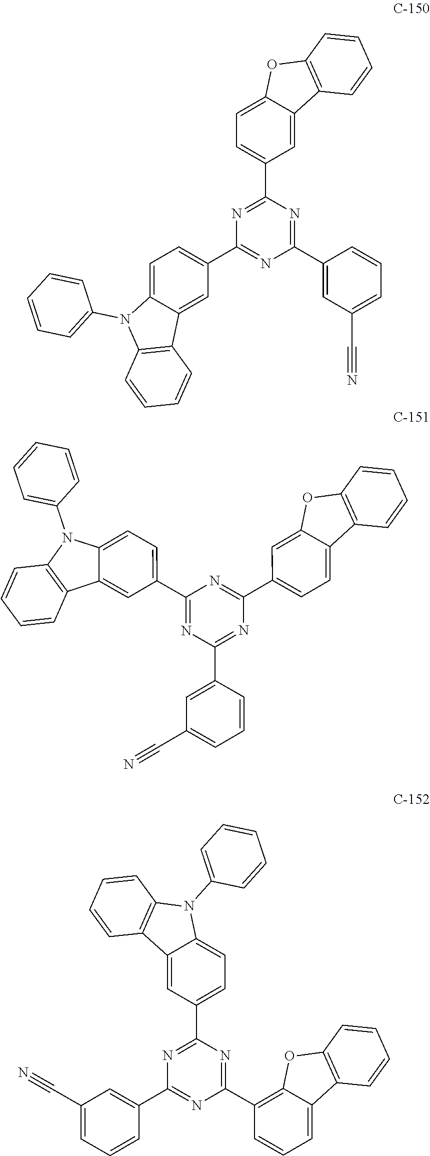 [SMILES: N#Cc1cccc(-c2nc(-c3ccc4oc5ccccc5c4c3)nc(-c3ccc4c(c3)c3ccccc3n4-c3ccccc3)n2)c1 ; N#Cc1cccc(-c2nc(-c3ccc4c(c3)oc3ccccc34)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4c3oc3ccccc34)n2)c1]

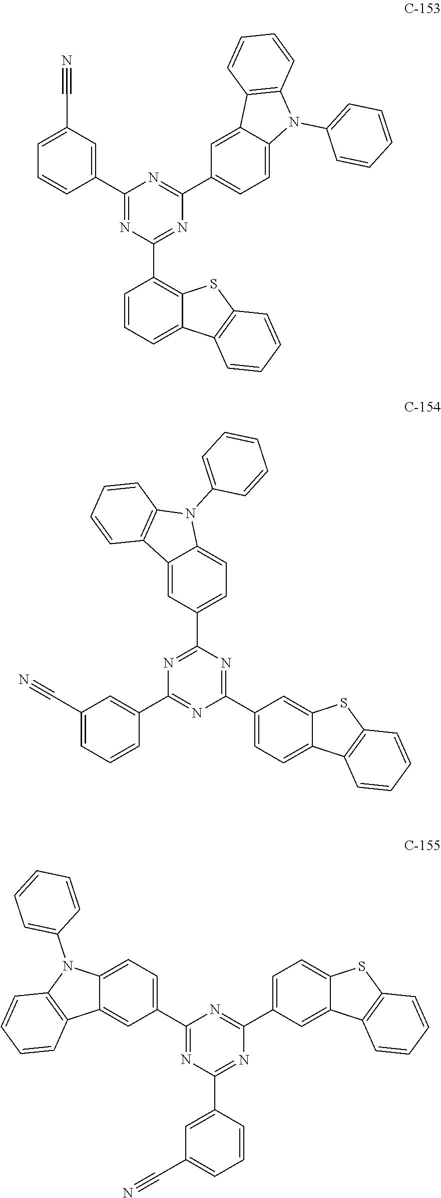 [SMILES: N#Cc1cccc(-c2nc(-c3ccc4c(c3)c3ccccc3n4-c3ccccc3)nc(-c3cccc4c3sc3ccccc34)n2)c1 ; N#Cc1cccc(-c2nc(-c3ccc4c(c3)sc3ccccc34)nc(-c3ccc4c(c3)c3ccccc3n4-c3ccccc3)n2)c1 ; N#Cc1cccc(-c2nc(-c3ccc4sc5ccccc5c4c3)nc(-c3ccc4c(c3)c3ccccc3n4-c3ccccc3)n2)c1]

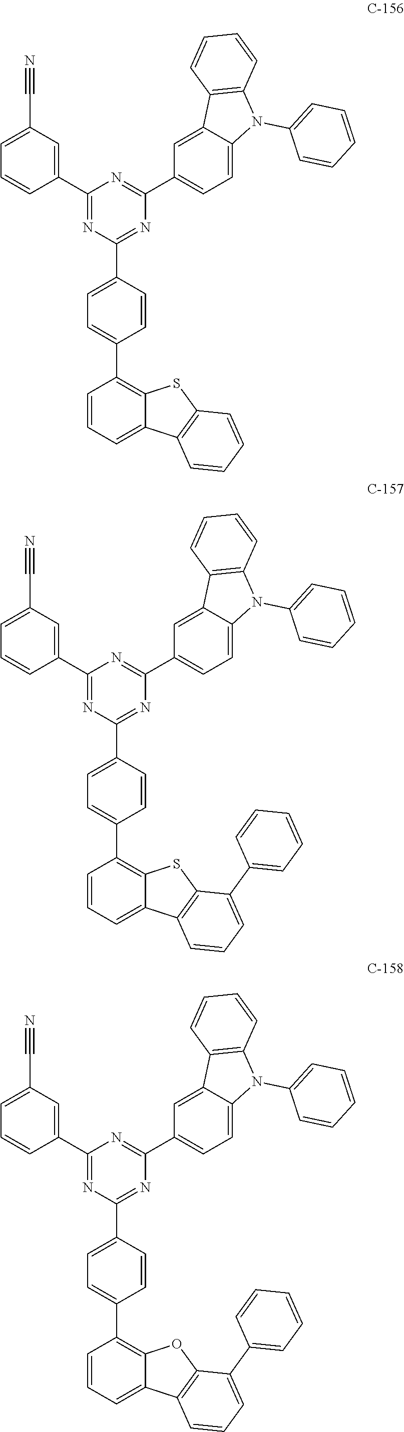

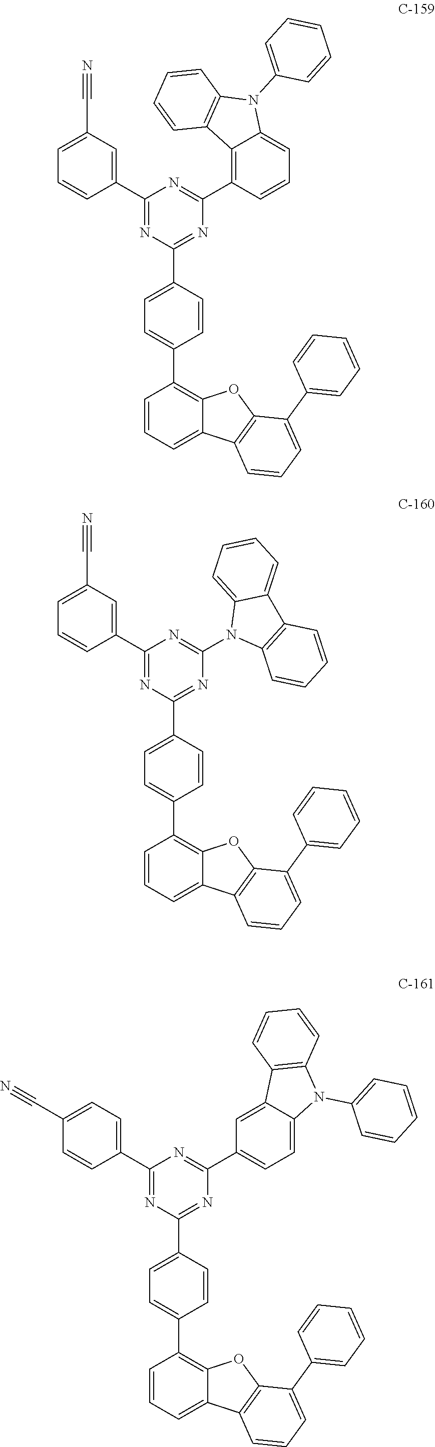 [SMILES: N#Cc1cccc(-c2nc(-c3ccc(-c4cccc5c4oc4c(-c6ccccc6)cccc45)cc3)nc(-c3cccc4c3c3ccccc3n4-c3ccccc3)n2)c1 ; N#Cc1cccc(-c2nc(-c3ccc(-c4cccc5c4oc4c(-c6ccccc6)cccc45)cc3)nc(-n3c4ccccc4c4ccccc43)n2)c1 ; N#Cc1ccc(-c2nc(-c3ccc(-c4cccc5c4oc4c(-c6ccccc6)cccc45)cc3)nc(-c3ccc4c(c3)c3ccccc3n4-c3ccccc3)n2)cc1]

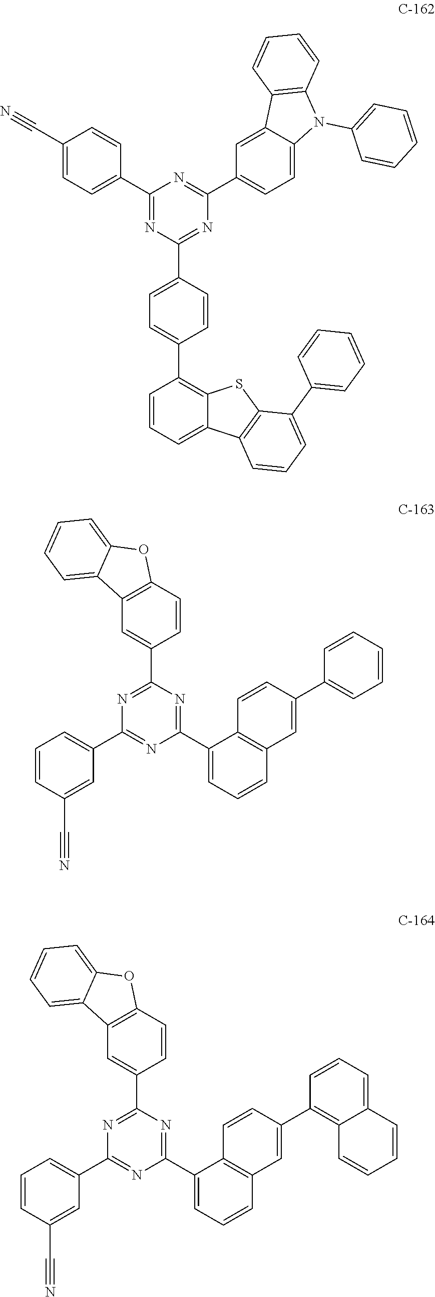 [SMILES: N#Cc1ccc(-c2nc(-c3ccc(-c4cccc5c4sc4c(-c6ccccc6)cccc45)cc3)nc(-c3ccc4c(c3)c3ccccc3n4-c3ccccc3)n2)cc1 ; N#Cc1cccc(-c2nc(-c3ccc4oc5ccccc5c4c3)nc(-c3cccc4cc(-c5ccccc5)ccc34)n2)c1 ; N#Cc1cccc(-c2nc(-c3ccc4oc5ccccc5c4c3)nc(-c3cccc4cc(-c5cccc6ccccc56)ccc34)n2)c1]

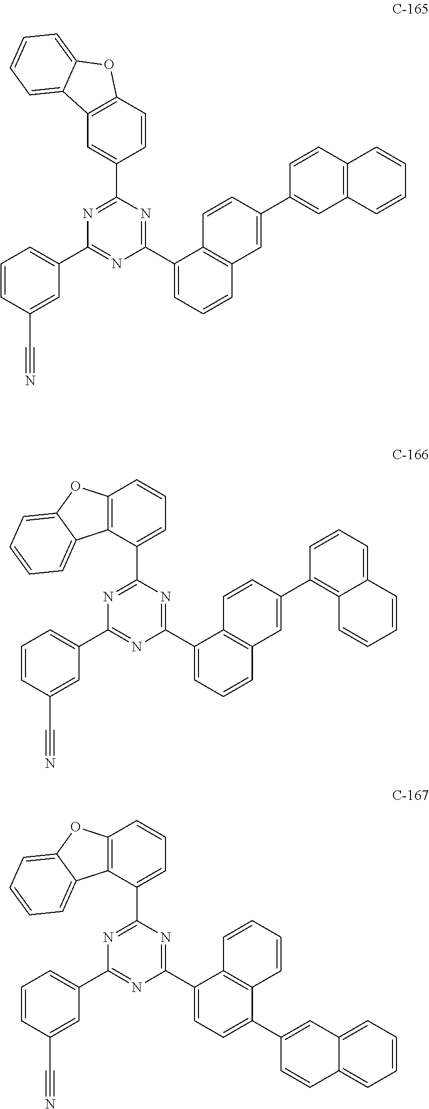 [SMILES: N#Cc1cccc(-c2nc(-c3ccc4oc5ccccc5c4c3)nc(-c3cccc4cc(-c5ccc6ccccc6c5)ccc34)n2)c1 ; N#Cc1cccc(-c2nc(-c3cccc4cc(-c5cccc6ccccc56)ccc34)nc(-c3cccc4oc5ccccc5c34)n2)c1 ; N#Cc1cccc(-c2nc(-c3ccc(-c4ccc5ccccc5c4)c4ccccc34)nc(-c3cccc4oc5ccccc5c34)n2)c1]

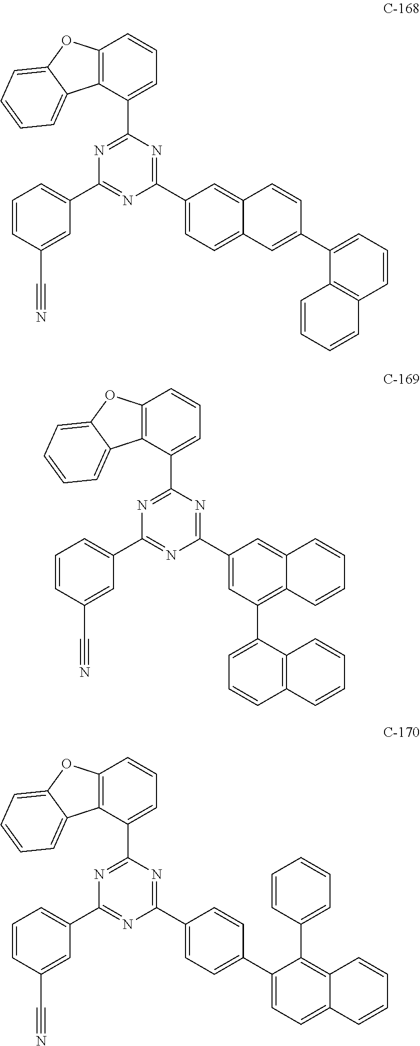 [SMILES: N#Cc1cccc(-c2nc(-c3ccc4cc(-c5cccc6ccccc56)ccc4c3)nc(-c3cccc4oc5ccccc5c34)n2)c1 ; N#Cc1cccc(-c2nc(-c3cc(-c4cccc5ccccc45)c4ccccc4c3)nc(-c3cccc4oc5ccccc5c34)n2)c1 ; N#Cc1cccc(-c2nc(-c3ccc(-c4ccc5ccccc5c4-c4ccccc4)cc3)nc(-c3cccc4oc5ccccc5c34)n2)c1]

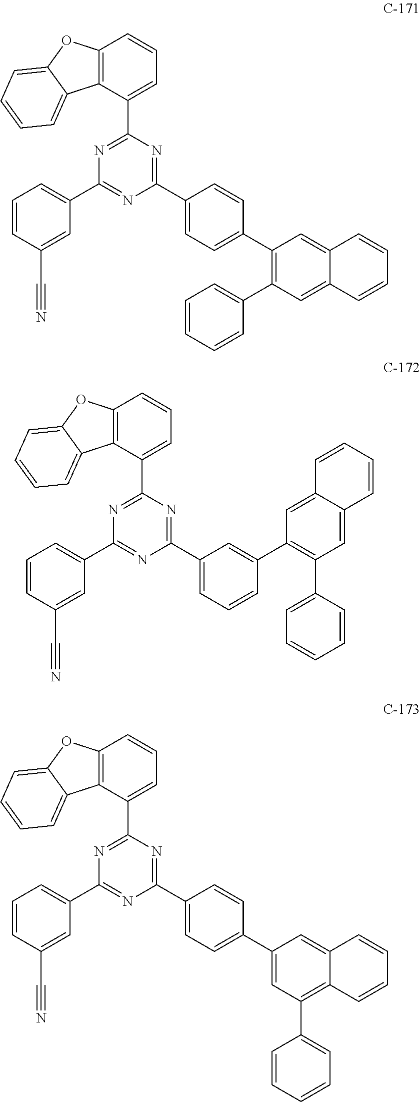 [SMILES: N#Cc1cccc(-c2nc(-c3ccc(-c4cc5ccccc5cc4-c4ccccc4)cc3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3ccc(-c4cc(-c5ccccc5)c5ccccc5c4)cc3)nc(-c3cccc4oc5ccccc5c34)n2)c1]

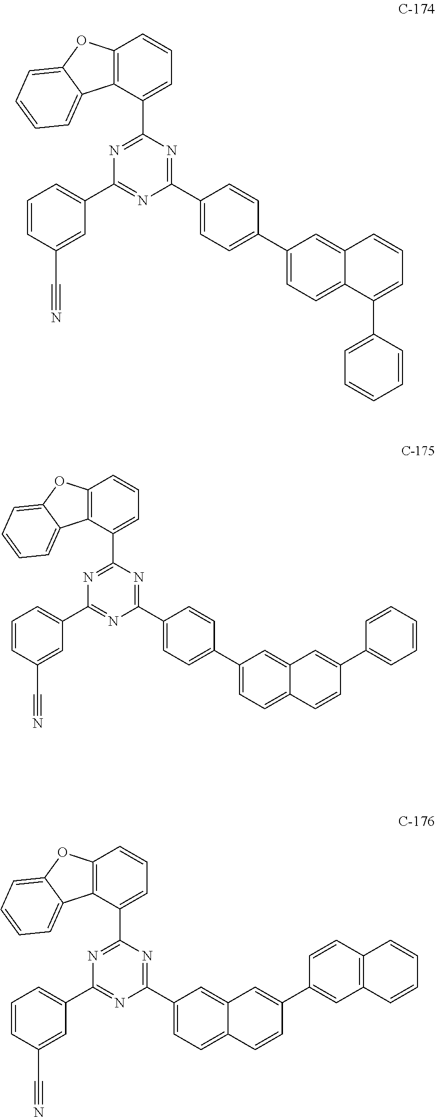 [SMILES: N#Cc1cccc(-c2nc(-c3ccc(-c4ccc5c(-c6ccccc6)cccc5c4)cc3)nc(-c3cccc4oc5ccccc5c34)n2)c1 ; N#Cc1cccc(-c2nc(-c3ccc(-c4ccc5ccc(-c6ccccc6)cc5c4)cc3)nc(-c3cccc4oc5ccccc5c34)n2)c1 ; N#Cc1cccc(-c2nc(-c3ccc4ccc(-c5ccc6ccccc6c5)cc4c3)nc(-c3cccc4oc5ccccc5c34)n2)c1]

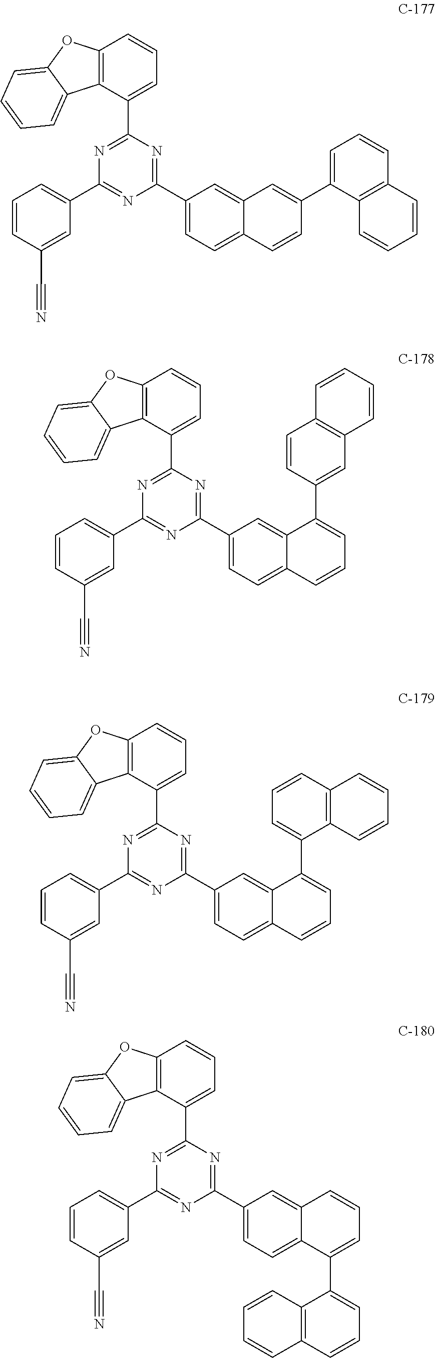 [SMILES: N#Cc1cccc(-c2nc(-c3ccc4ccc(-c5cccc6ccccc56)cc4c3)nc(-c3cccc4oc5ccccc5c34)n2)c1 ; N#Cc1cccc(-c2nc(-c3ccc4cccc(-c5ccc6ccccc6c5)c4c3)nc(-c3cccc4oc5ccccc5c34)n2)c1 ; N#Cc1cccc(-c2nc(-c3ccc4cccc(-c5cccc6ccccc56)c4c3)nc(-c3cccc4oc5ccccc5c34)n2)c1 ; N#Cc1cccc(-c2nc(-c3ccc4c(-c5cccc6ccccc56)cccc4c3)nc(-c3cccc4oc5ccccc5c34)n2)c1]

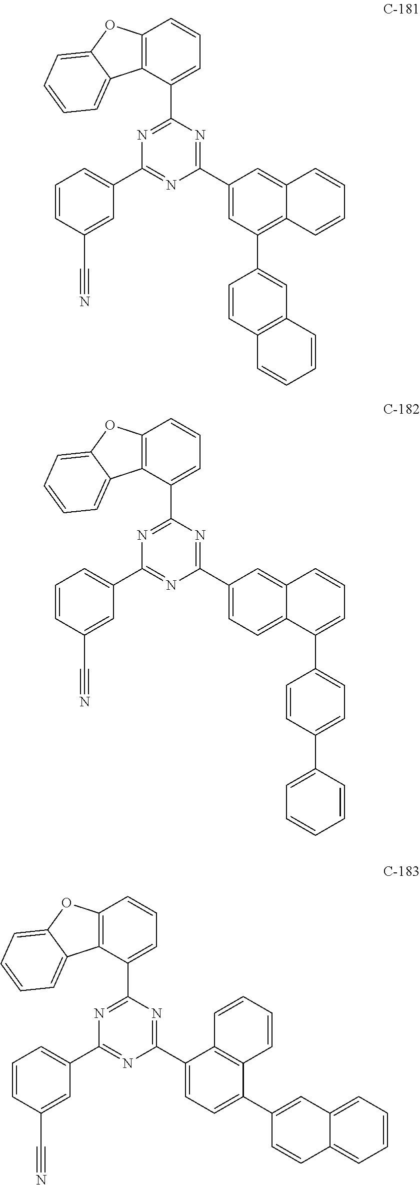 [SMILES: N#Cc1cccc(-c2nc(-c3cc(-c4ccc5ccccc5c4)c4ccccc4c3)nc(-c3cccc4oc5ccccc5c34)n2)c1 ; N#Cc1cccc(-c2nc(-c3ccc4c(-c5ccc(-c6ccccc6)cc5)cccc4c3)nc(-c3cccc4oc5ccccc5c34)n2)c1 ; N#Cc1cccc(-c2nc(-c3ccc(-c4ccc5ccccc5c4)c4ccccc34)nc(-c3cccc4oc5ccccc5c34)n2)c1]

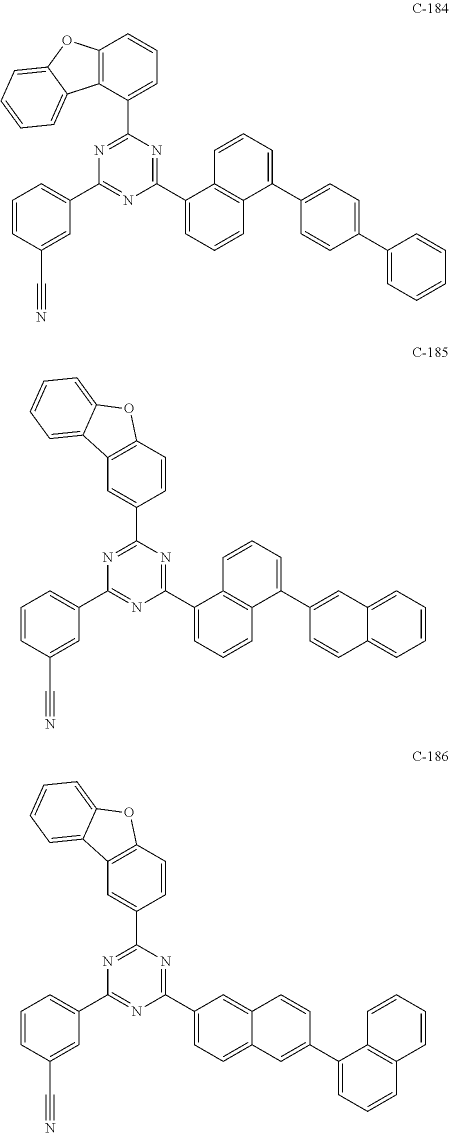 [SMILES: N#Cc1cccc(-c2nc(-c3cccc4c(-c5ccc(-c6ccccc6)cc5)cccc34)nc(-c3cccc4oc5ccccc5c34)n2)c1 ; N#Cc1cccc(-c2nc(-c3ccc4oc5ccccc5c4c3)nc(-c3cccc4c(-c5ccc6ccccc6c5)cccc34)n2)c1 ; N#Cc1cccc(-c2nc(-c3ccc4cc(-c5cccc6ccccc56)ccc4c3)nc(-c3ccc4oc5ccccc5c4c3)n2)c1]

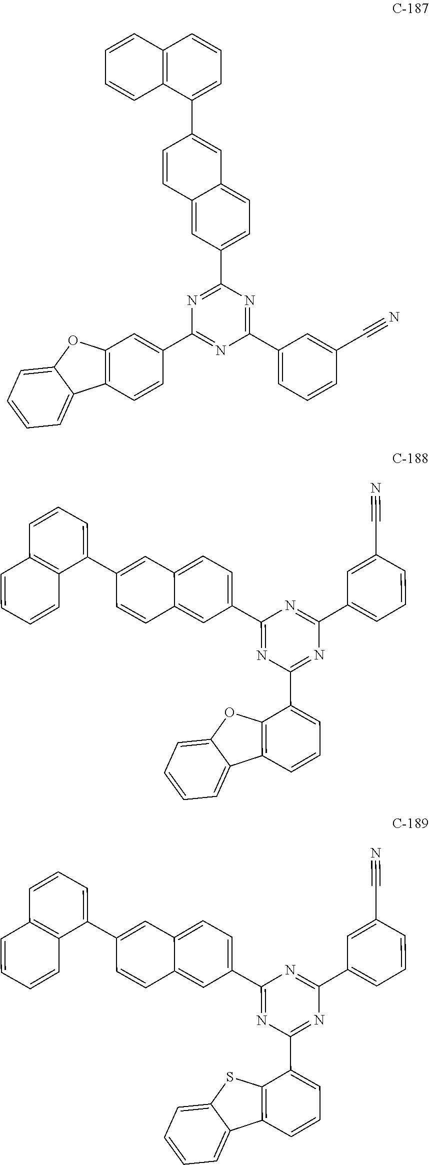 [SMILES: N#Cc1cccc(-c2nc(-c3ccc4cc(-c5cccc6ccccc56)ccc4c3)nc(-c3ccc4c(c3)oc3ccccc34)n2)c1 ; N#Cc1cccc(-c2nc(-c3ccc4cc(-c5cccc6ccccc56)ccc4c3)nc(-c3cccc4c3oc3ccccc34)n2)c1 ; N#Cc1cccc(-c2nc(-c3ccc4cc(-c5cccc6ccccc56)ccc4c3)nc(-c3cccc4c3sc3ccccc34)n2)c1]

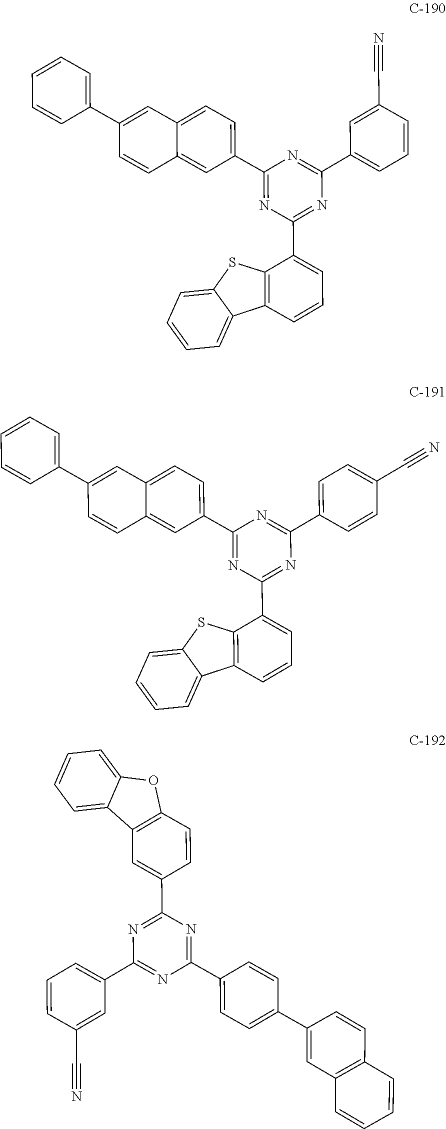 [SMILES: N#Cc1cccc(-c2nc(-c3ccc4cc(-c5ccccc5)ccc4c3)nc(-c3cccc4c3sc3ccccc34)n2)c1 ; N#Cc1ccc(-c2nc(-c3ccc4cc(-c5ccccc5)ccc4c3)nc(-c3cccc4c3sc3ccccc34)n2)cc1 ; N#Cc1cccc(-c2nc(-c3ccc(-c4ccc5ccccc5c4)cc3)nc(-c3ccc4oc5ccccc5c4c3)n2)c1]

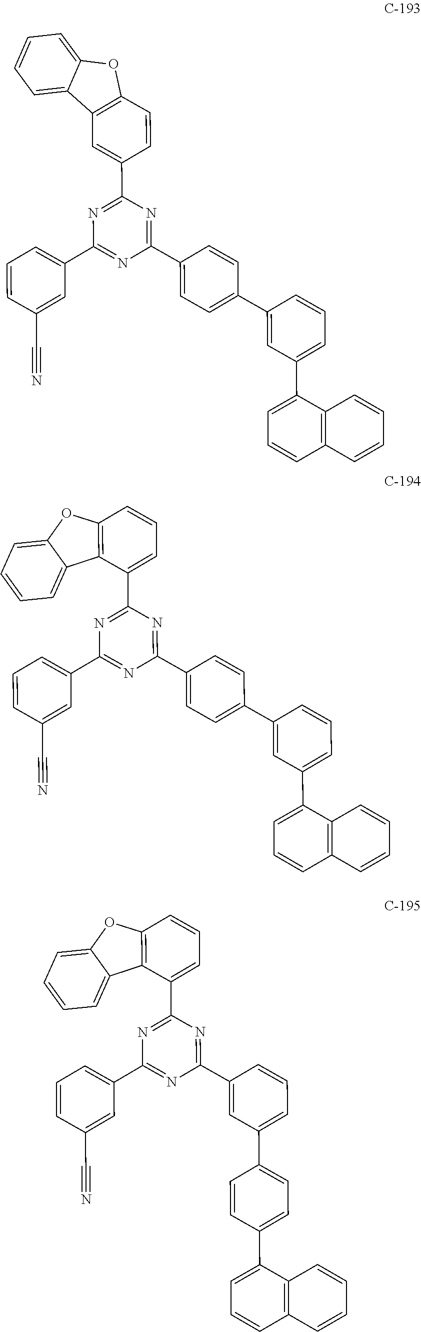 [SMILES: N#Cc1cccc(-c2nc(-c3ccc(-c4cccc(-c5cccc6ccccc56)c4)cc3)nc(-c3ccc4oc5ccccc5c4c3)n2)c1 ; N#Cc1cccc(-c2nc(-c3ccc(-c4cccc(-c5cccc6ccccc56)c4)cc3)nc(-c3cccc4oc5ccccc5c34)n2)c1 ; N#Cc1cccc(-c2nc(-c3cccc(-c4ccc(-c5cccc6ccccc56)cc4)c3)nc(-c3cccc4oc5ccccc5c34)n2)c1]

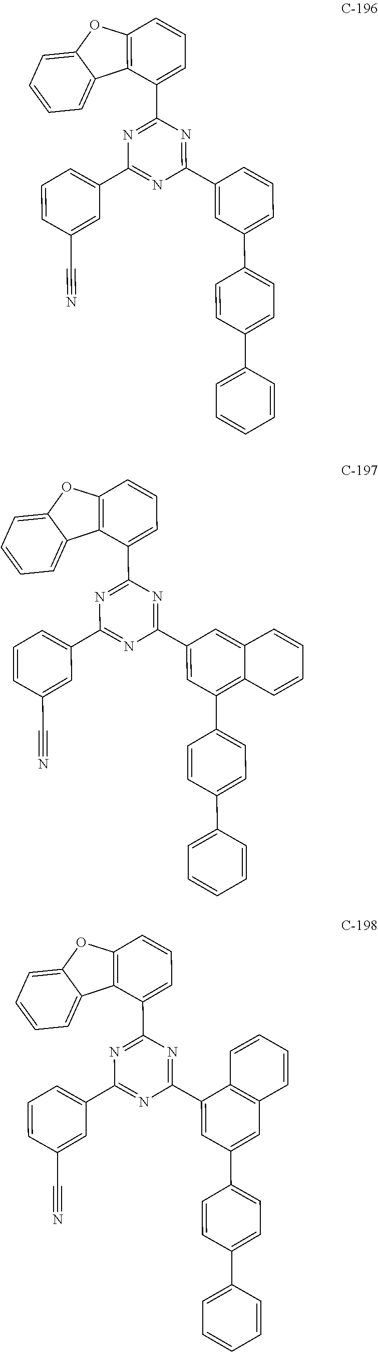 [SMILES: N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3cc(-c4ccc(-c5ccccc5)cc4)c4ccccc4c3)nc(-c3cccc4oc5ccccc5c34)n2)c1 ; N#Cc1cccc(-c2nc(-c3cc(-c4ccc(-c5ccccc5)cc4)cc4ccccc34)nc(-c3cccc4oc5ccccc5c34)n2)c1]

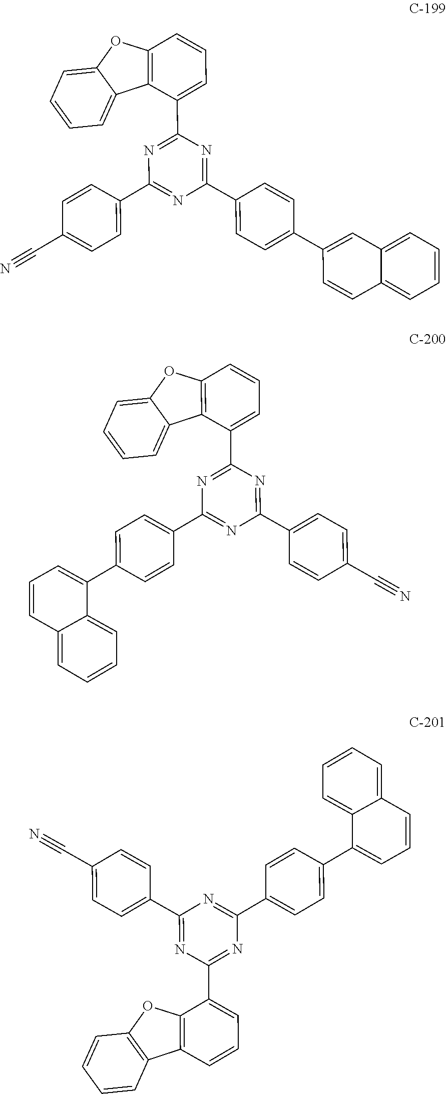 [SMILES: N#Cc1ccc(-c2nc(-c3ccc(-c4ccc5ccccc5c4)cc3)nc(-c3cccc4oc5ccccc5c34)n2)cc1 ; N#Cc1ccc(-c2nc(-c3ccc(-c4cccc5ccccc45)cc3)nc(-c3cccc4oc5ccccc5c34)n2)cc1 ; N#Cc1ccc(-c2nc(-c3ccc(-c4cccc5ccccc45)cc3)nc(-c3cccc4c3oc3ccccc34)n2)cc1]

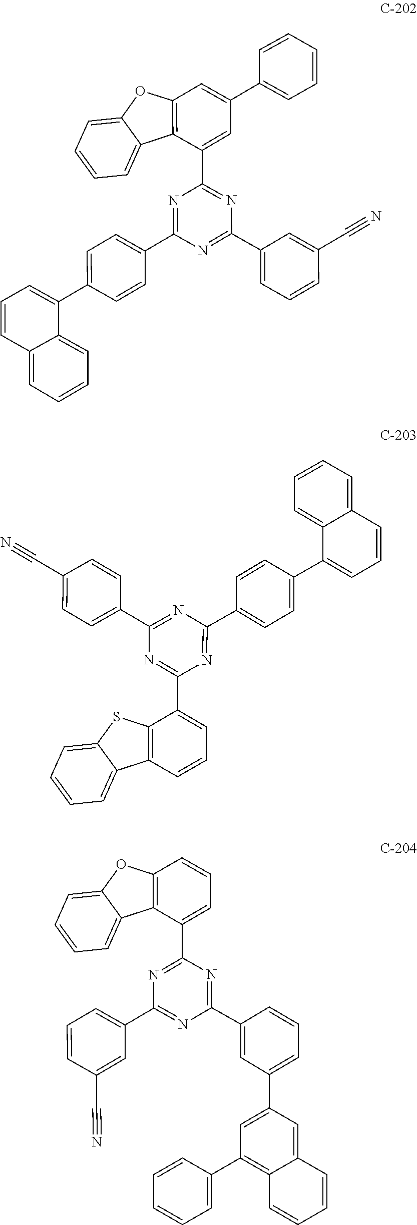 [SMILES: N#Cc1cccc(-c2nc(-c3ccc(-c4cccc5ccccc45)cc3)nc(-c3cc(-c4ccccc4)cc4oc5ccccc5c34)n2)c1 ; N#Cc1ccc(-c2nc(-c3ccc(-c4cccc5ccccc45)cc3)nc(-c3cccc4c3sc3ccccc34)n2)cc1 ; N#Cc1cccc(-c2nc(-c3cccc(-c4cc(-c5ccccc5)c5ccccc5c4)c3)nc(-c3cccc4oc5ccccc5c34)n2)c1]

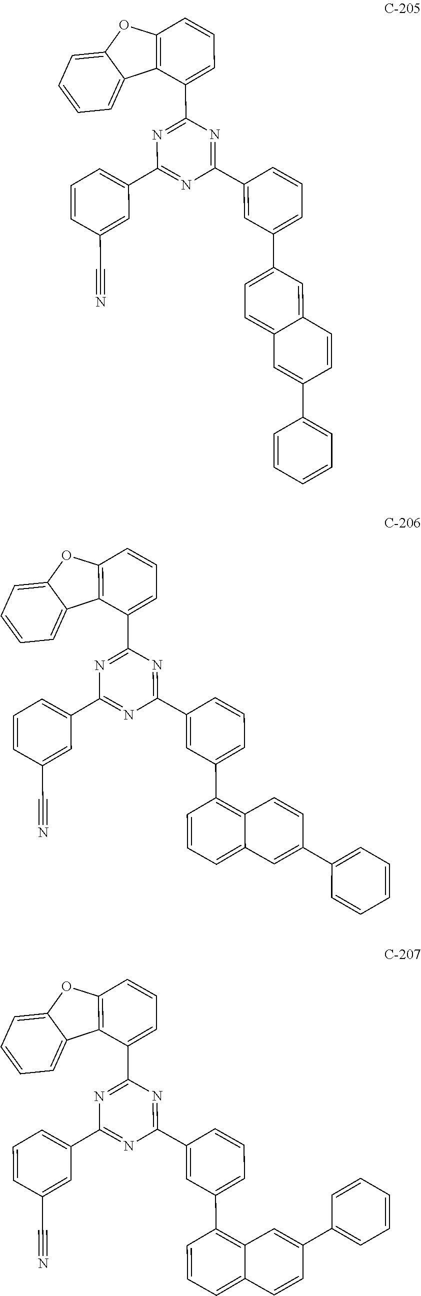 [SMILES: N#Cc1cccc(-c2nc(-c3cccc(-c4ccc5cc(-c6ccccc6)ccc5c4)c3)nc(-c3cccc4oc5ccccc5c34)n2)c1 ; N#Cc1cccc(-c2nc(-c3cccc(-c4cccc5cc(-c6ccccc6)ccc45)c3)nc(-c3cccc4oc5ccccc5c34)n2)c1 ; N#Cc1cccc(-c2nc(-c3cccc(-c4cccc5ccc(-c6ccccc6)cc45)c3)nc(-c3cccc4oc5ccccc5c34)n2)c1]

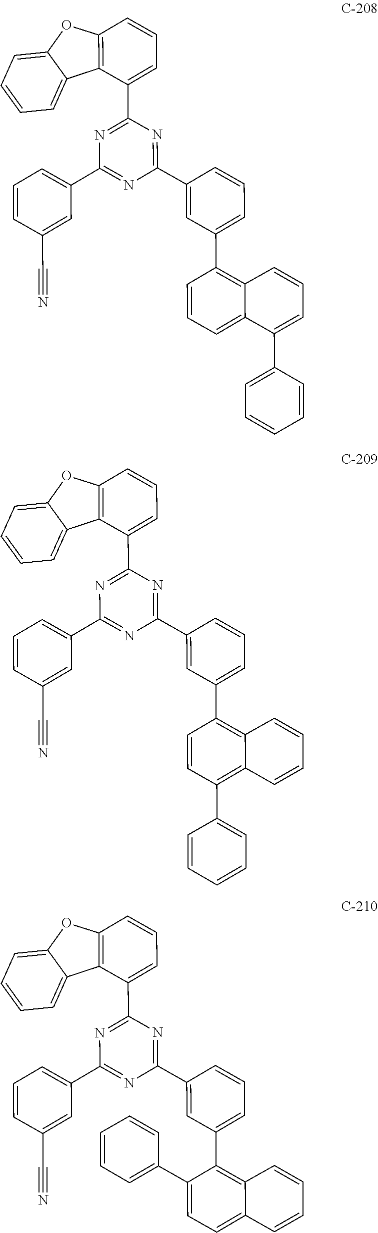 [SMILES: N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1 ; N#Cc1cccc(-c2nc(-c3cccc(-c4c(-c5ccccc5)ccc5ccccc45)c3)nc(-c3cccc4oc5ccccc5c34)n2)c1]

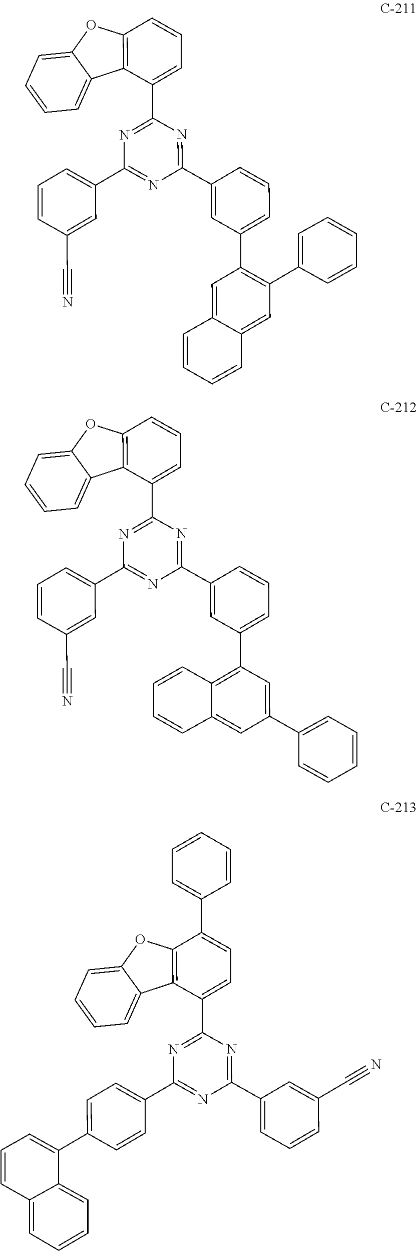 [SMILES: N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3cccc(-c4cc(-c5ccccc5)cc5ccccc45)c3)nc(-c3cccc4oc5ccccc5c34)n2)c1 ; N#Cc1cccc(-c2nc(-c3ccc(-c4cccc5ccccc45)cc3)nc(-c3ccc(-c4ccccc4)c4oc5ccccc5c34)n2)c1]

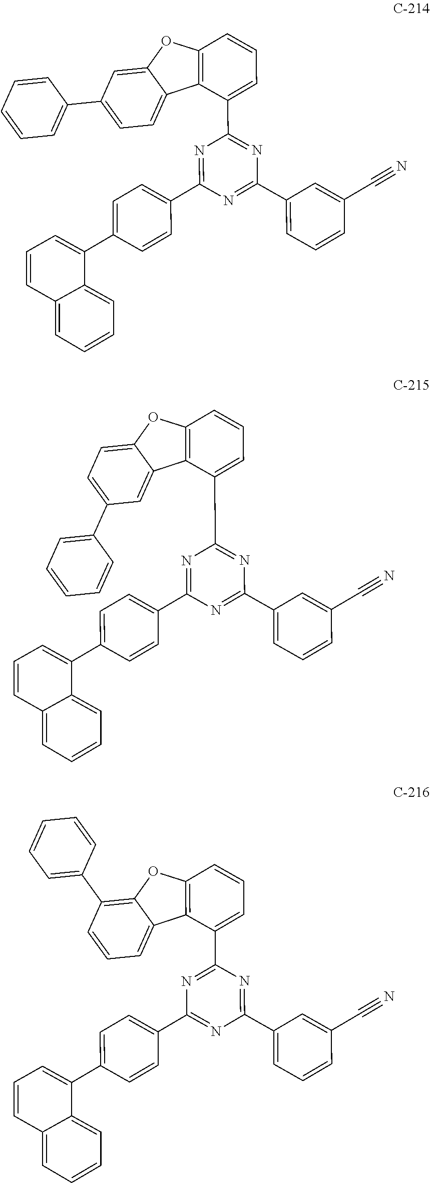 [SMILES: N#Cc1cccc(-c2nc(-c3ccc(-c4cccc5ccccc45)cc3)nc(-c3cccc4oc5cc(-c6ccccc6)ccc5c34)n2)c1 ; N#Cc1cccc(-c2nc(Cc3cccc4oc5ccc(-c6ccccc6)cc5c34)nc(-c3ccc(-c4cccc5ccccc45)cc3)n2)c1 ; N#Cc1cccc(-c2nc(-c3ccc(-c4cccc5ccccc45)cc3)nc(-c3cccc4oc5c(-c6ccccc6)cccc5c34)n2)c1]

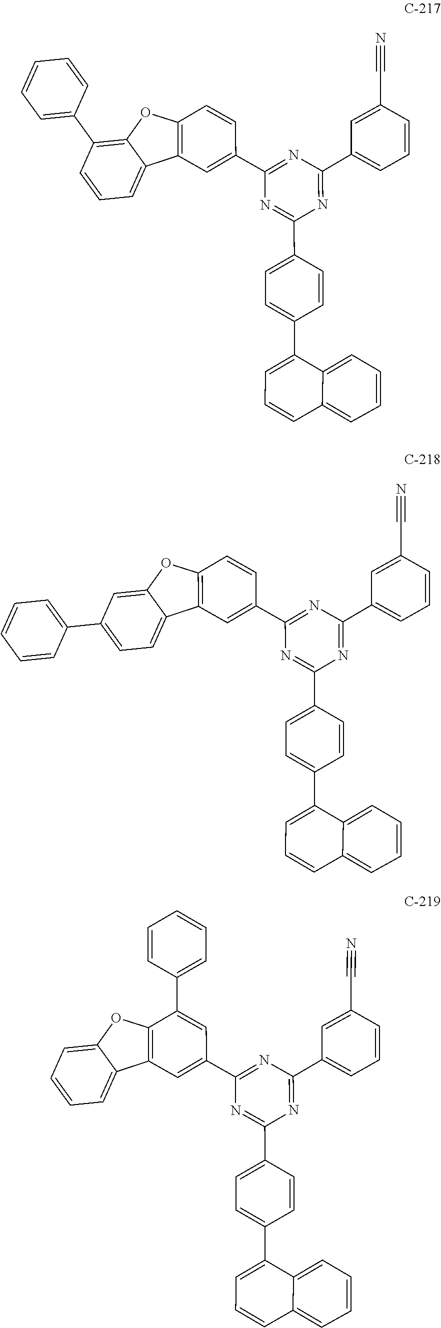 [SMILES: N#Cc1cccc(-c2nc(-c3ccc(-c4cccc5ccccc45)cc3)nc(-c3ccc4oc5c(-c6ccccc6)cccc5c4c3)n2)c1 ; N#Cc1cccc(-c2nc(-c3ccc(-c4cccc5ccccc45)cc3)nc(-c3ccc4oc5cc(-c6ccccc6)ccc5c4c3)n2)c1 ; N#Cc1cccc(-c2nc(-c3ccc(-c4cccc5ccccc45)cc3)nc(-c3cc(-c4ccccc4)c4oc5ccccc5c4c3)n2)c1]

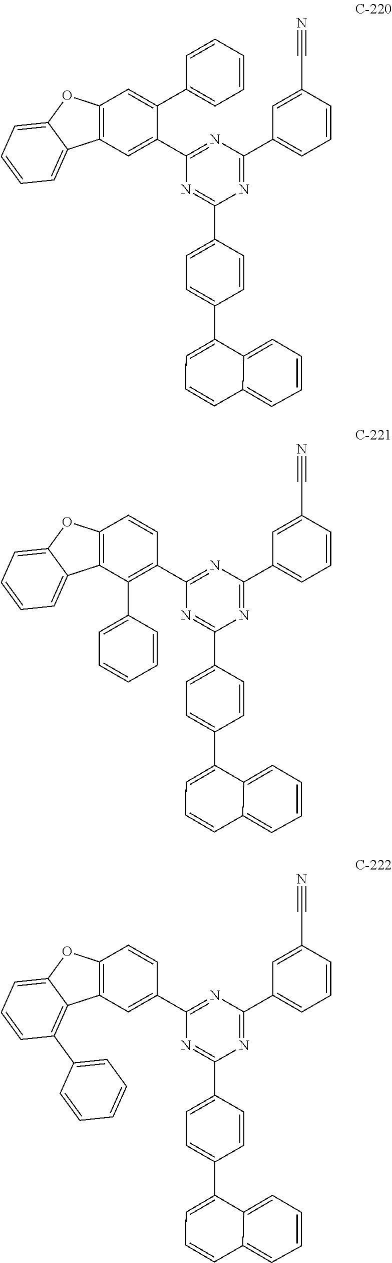 [SMILES: N#Cc1cccc(-c2nc(-c3ccc(-c4cccc5ccccc45)cc3)nc(-c3cc4c(cc3-c3ccccc3)oc3ccccc34)n2)c1 ; N#Cc1cccc(-c2nc(-c3ccc(-c4cccc5ccccc45)cc3)nc(-c3ccc4oc5ccccc5c4c3-c3ccccc3)n2)c1 ; N#Cc1cccc(-c2nc(-c3ccc(-c4cccc5ccccc45)cc3)nc(-c3ccc4oc5cccc(-c6ccccc6)c5c4c3)n2)c1]

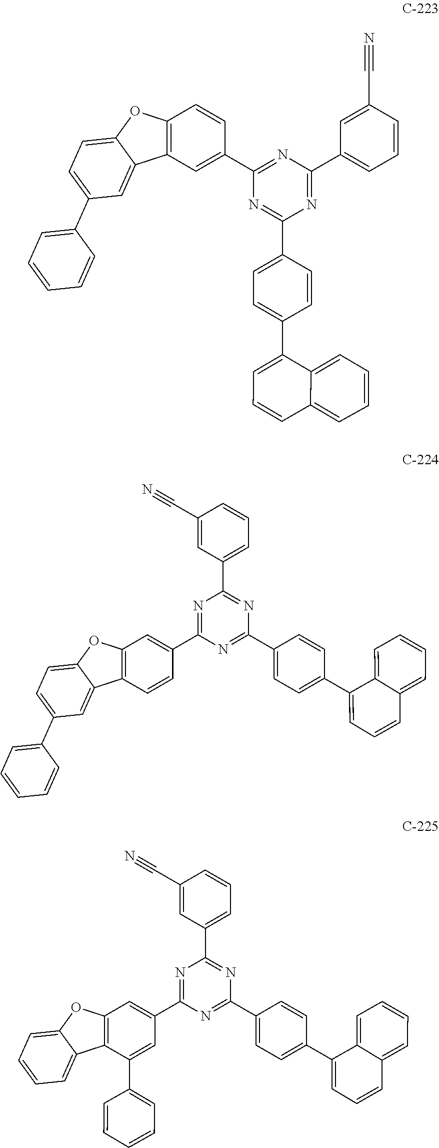 [SMILES: N#Cc1cccc(-c2nc(-c3ccc(-c4cccc5ccccc45)cc3)nc(-c3ccc4oc5ccc(-c6ccccc6)cc5c4c3)n2)c1 ; N#Cc1cccc(-c2nc(-c3ccc(-c4cccc5ccccc45)cc3)nc(-c3ccc4c(c3)oc3ccc(-c5ccccc5)cc34)n2)c1 ; N#Cc1cccc(-c2nc(-c3ccc(-c4cccc5ccccc45)cc3)nc(-c3cc(-c4ccccc4)c4c(c3)oc3ccccc34)n2)c1]

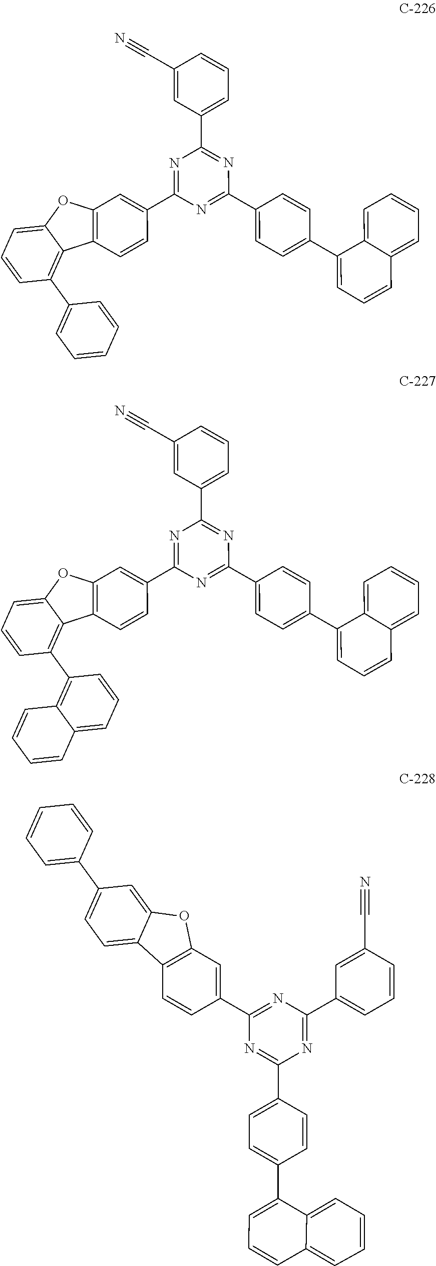 [SMILES: N#Cc1cccc(-c2nc(-c3ccc(-c4cccc5ccccc45)cc3)nc(-c3ccc4c(c3)oc3cccc(-c5ccccc5)c34)n2)c1 ; N#Cc1cccc(-c2nc(-c3ccc(-c4cccc5ccccc45)cc3)nc(-c3ccc4c(c3)oc3cccc(-c5cccc6ccccc56)c34)n2)c1 ; N#Cc1cccc(-c2nc(-c3ccc(-c4cccc5ccccc45)cc3)nc(-c3ccc4c(c3)oc3cc(-c5ccccc5)ccc34)n2)c1]

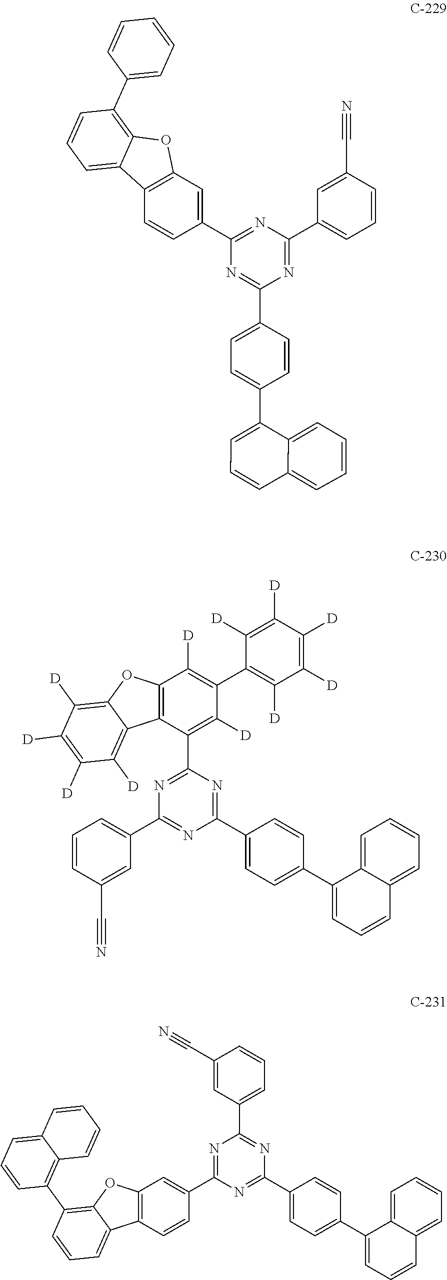 [SMILES: N#Cc1cccc(-c2nc(-c3ccc(-c4cccc5ccccc45)cc3)nc(-c3ccc4c(c3)oc3c(-c5ccccc5)cccc34)n2)c1 ; [2H]c1c([2H])c([2H])c(-c2c([2H])c(-c3nc(-c4ccc(-c5cccc6ccccc56)cc4)nc(-c4cccc(C#N)c4)n3)c3c(oc4c([2H])c([2H])c([2H])c([2H])c43)c2[2H])c([2H])c1[2H] ; N#Cc1cccc(-c2nc(-c3ccc(-c4cccc5ccccc45)cc3)nc(-c3ccc4c(c3)oc3c(-c5cccc6ccccc56)cccc34)n2)c1]

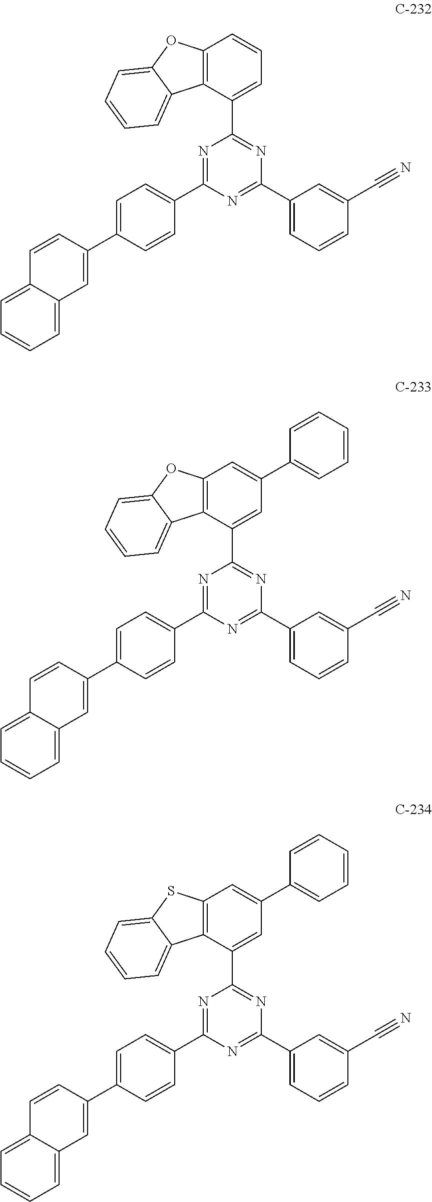 [SMILES: N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4ccc5ccccc5c4)cc3)nc(-c3cc(-c4ccccc4)cc4oc5ccccc5c34)n2)c1 ; N#Cc1cccc(-c2nc(-c3ccc(-c4ccc5ccccc5c4)cc3)nc(-c3cc(-c4ccccc4)cc4sc5ccccc5c34)n2)c1]

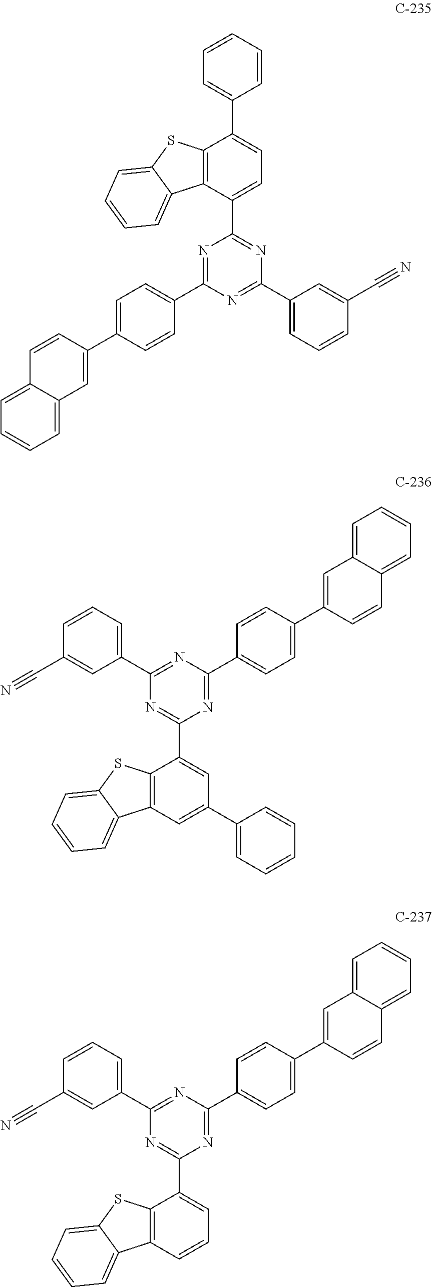 [SMILES: N#Cc1cccc(-c2nc(-c3ccc(-c4ccc5ccccc5c4)cc3)nc(-c3ccc(-c4ccccc4)c4sc5ccccc5c34)n2)c1 ; N#Cc1cccc(-c2nc(-c3ccc(-c4ccc5ccccc5c4)cc3)nc(-c3cc(-c4ccccc4)cc4c3sc3ccccc34)n2)c1 ; N#Cc1cccc(-c2nc(-c3ccc(-c4ccc5ccccc5c4)cc3)nc(-c3cccc4c3sc3ccccc34)n2)c1]

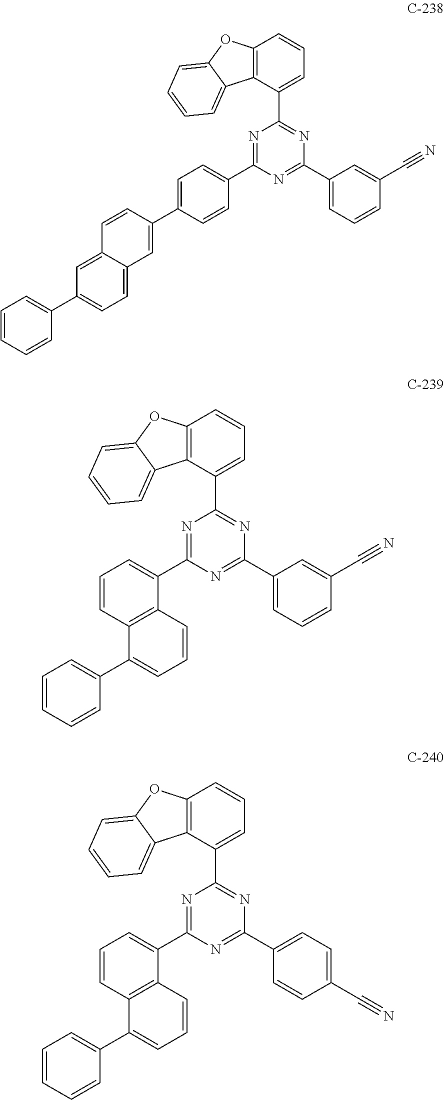 [SMILES: N#Cc1cccc(-c2nc(-c3ccc(-c4ccc5cc(-c6ccccc6)ccc5c4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1 ; N#Cc1ccc(-c2nc(-c3cccc4c(-c5ccccc5)cccc34)nc(-c3cccc4oc5ccccc5c34)n2)cc1]

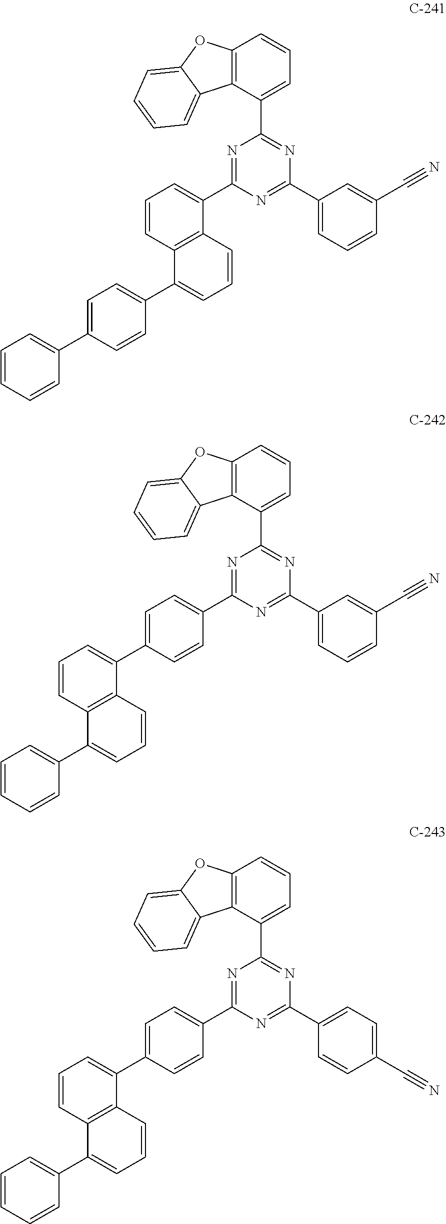 [SMILES: N#Cc1cccc(-c2nc(-c3cccc4c(-c5ccc(-c6ccccc6)cc5)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1 ; N#Cc1ccc(-c2nc(-c3ccc(-c4cccc5c(-c6ccccc6)cccc45)cc3)nc(-c3cccc4oc5ccccc5c34)n2)cc1]

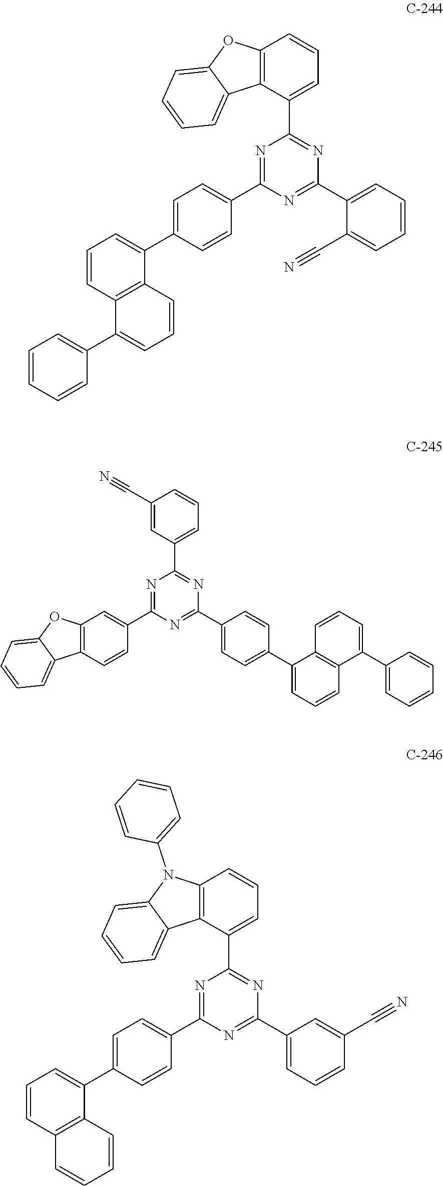 [SMILES: N#Cc1ccccc1-c1nc(-c2ccc(-c3cccc4c(-c5ccccc5)cccc34)cc2)nc(-c2cccc3oc4ccccc4c23)n1 ; N#Cc1cccc(-c2nc(-c3ccc(-c4cccc5c(-c6ccccc6)cccc45)cc3)nc(-c3ccc4c(c3)oc3ccccc34)n2)c1 ; N#Cc1cccc(-c2nc(-c3ccc(-c4cccc5ccccc45)cc3)nc(-c3cccc4c3c3ccccc3n4-c3ccccc3)n2)c1]

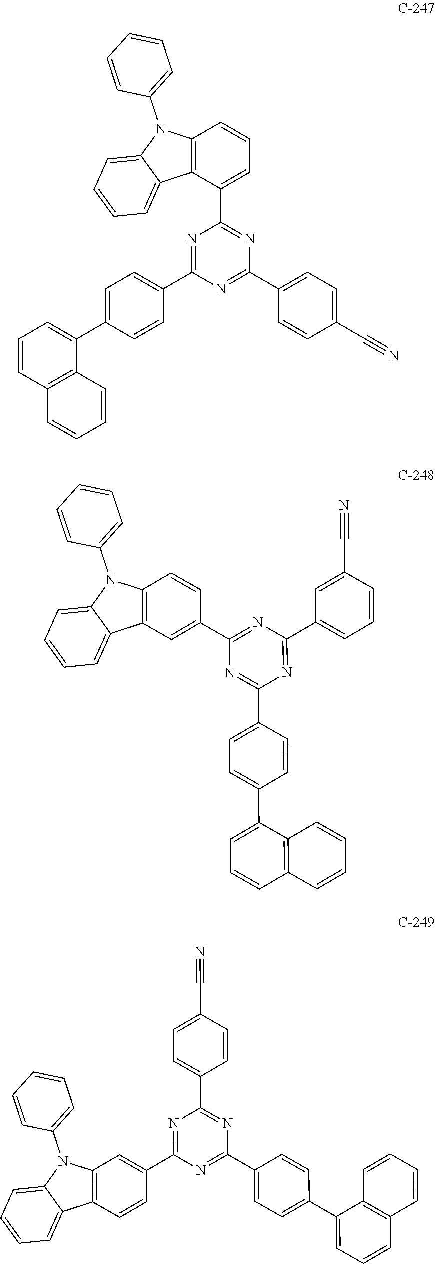

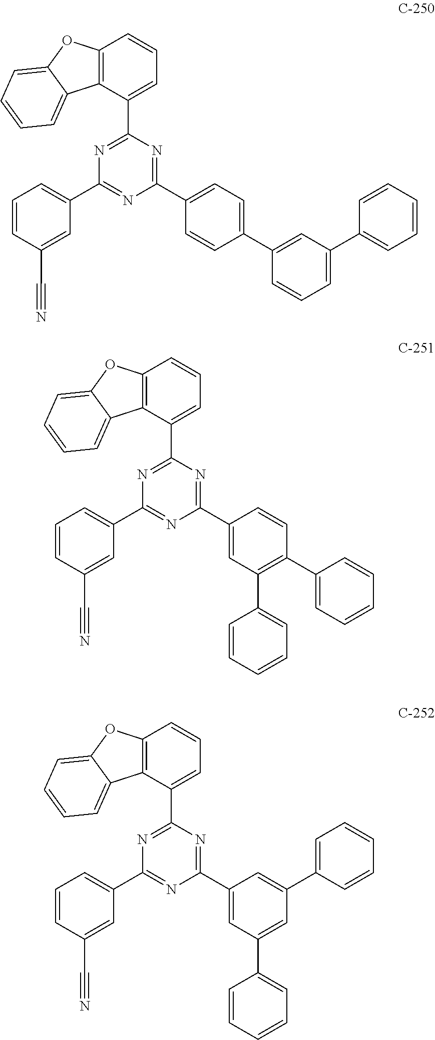 [SMILES: N#Cc1cccc(-c2nc(-c3ccc(-c4cccc(-c5ccccc5)c4)cc3)nc(-c3cccc4oc5ccccc5c34)n2)c1 ; N#Cc1cccc(-c2nc(-c3ccc(-c4ccccc4)c(-c4ccccc4)c3)nc(-c3cccc4oc5ccccc5c34)n2)c1 ; N#Cc1cccc(-c2nc(-c3cc(-c4ccccc4)cc(-c4ccccc4)c3)nc(-c3cccc4oc5ccccc5c34)n2)c1]

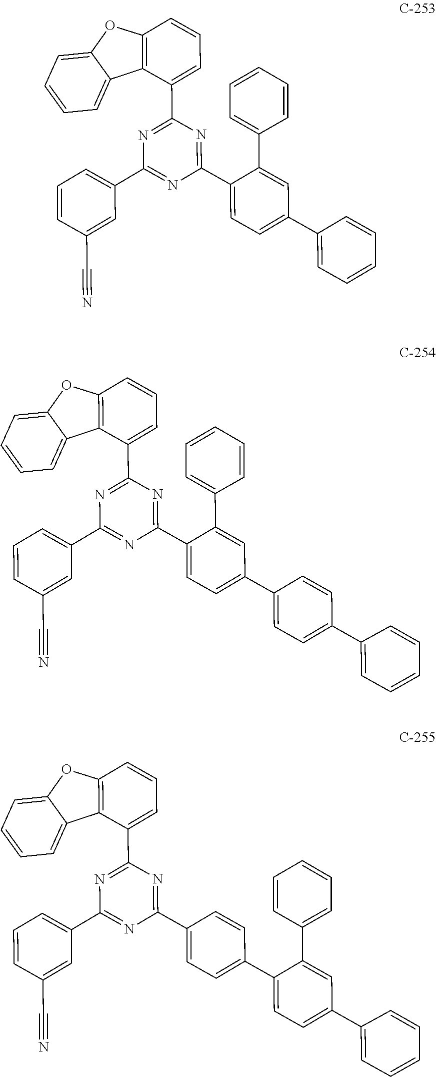 [SMILES: N#Cc1cccc(-c2nc(-c3ccc(-c4ccccc4)cc3-c3ccccc3)nc(-c3cccc4oc5ccccc5c34)n2)c1 ; N#Cc1cccc(-c2nc(-c3ccc(-c4ccc(-c5ccccc5)cc4)cc3-c3ccccc3)nc(-c3cccc4oc5ccccc5c34)n2)c1 ; N#Cc1cccc(-c2nc(-c3ccc(-c4ccc(-c5ccccc5)cc4-c4ccccc4)cc3)nc(-c3cccc4oc5ccccc5c34)n2)c1]

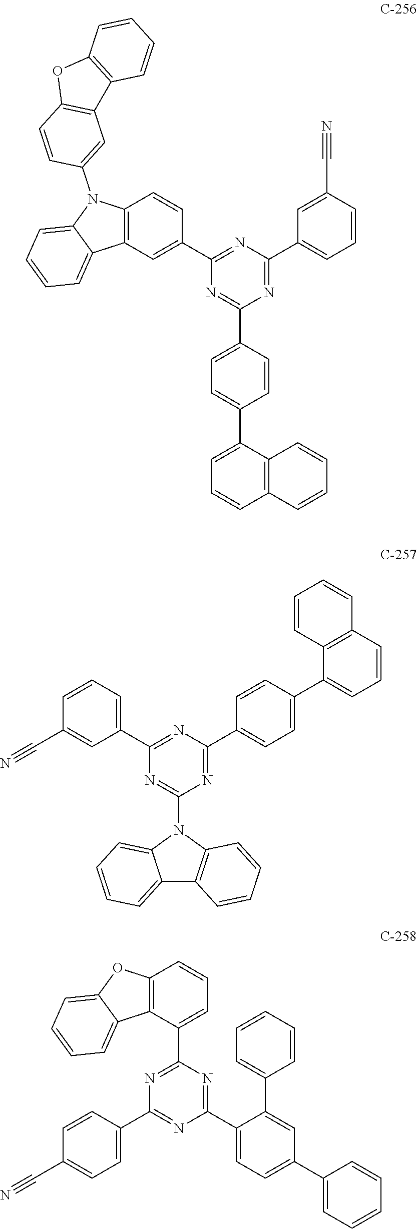 [SMILES: N#Cc1cccc(-c2nc(-c3ccc(-c4cccc5ccccc45)cc3)nc(-c3ccc4c(c3)c3ccccc3n4-c3ccc4oc5ccccc5c4c3)n2)c1 ; N#Cc1cccc(-c2nc(-c3ccc(-c4cccc5ccccc45)cc3)nc(-n3c4ccccc4c4ccccc43)n2)c1 ; N#Cc1ccc(-c2nc(-c3ccc(-c4ccccc4)cc3-c3ccccc3)nc(-c3cccc4oc5ccccc5c34)n2)cc1]

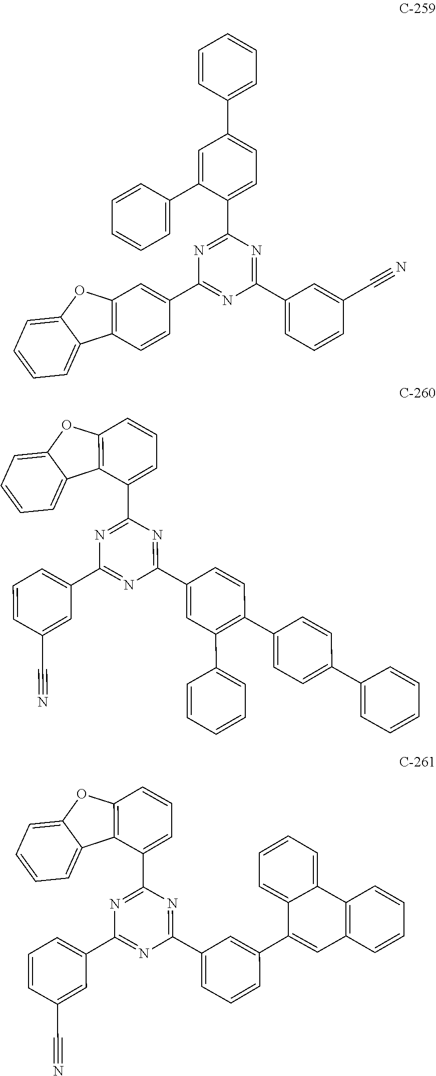 [SMILES: N#Cc1cccc(-c2nc(-c3ccc4c(c3)oc3ccccc34)nc(-c3ccc(-c4ccccc4)cc3-c3ccccc3)n2)c1 ; N#Cc1cccc(-c2nc(-c3ccc(-c4ccc(-c5ccccc5)cc4)c(-c4ccccc4)c3)nc(-c3cccc4oc5ccccc5c34)n2)c1 ; N#Cc1cccc(-c2nc(-c3cccc(-c4cc5ccccc5c5ccccc45)c3)nc(-c3cccc4oc5ccccc5c34)n2)c1]

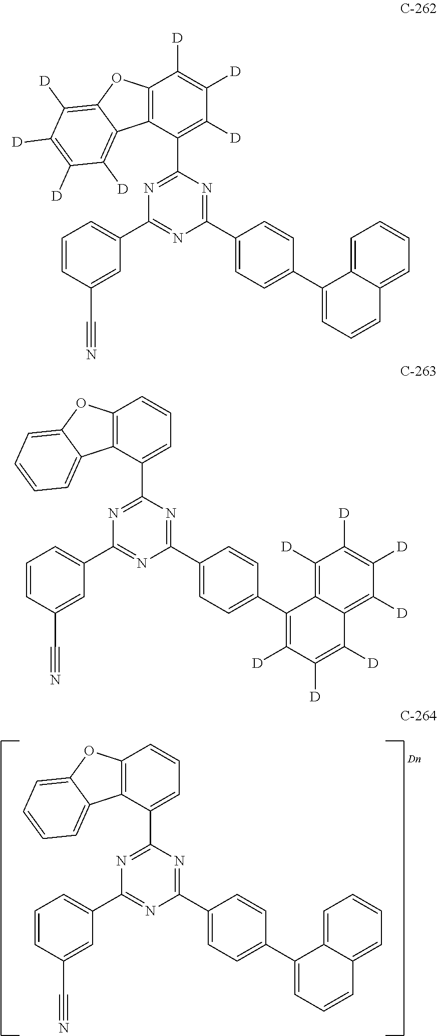

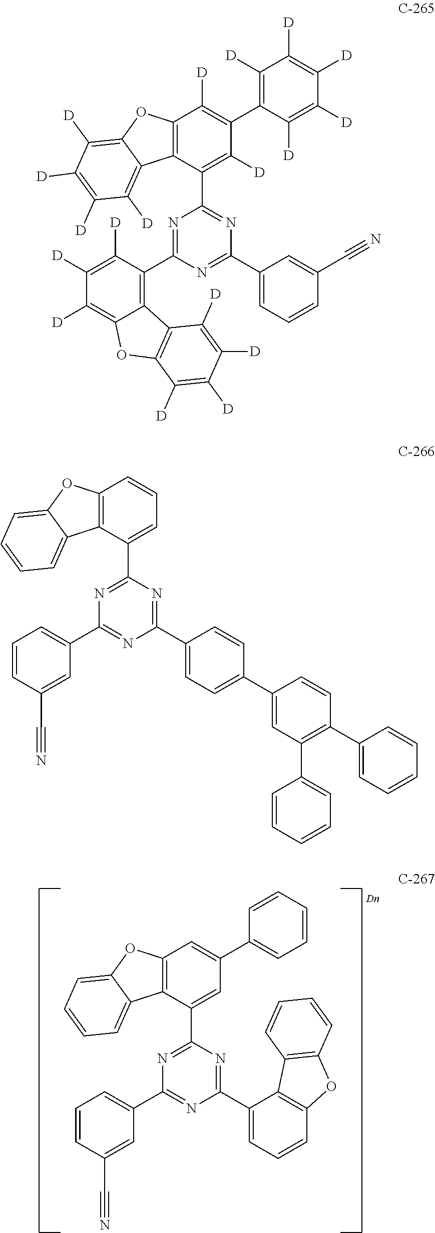

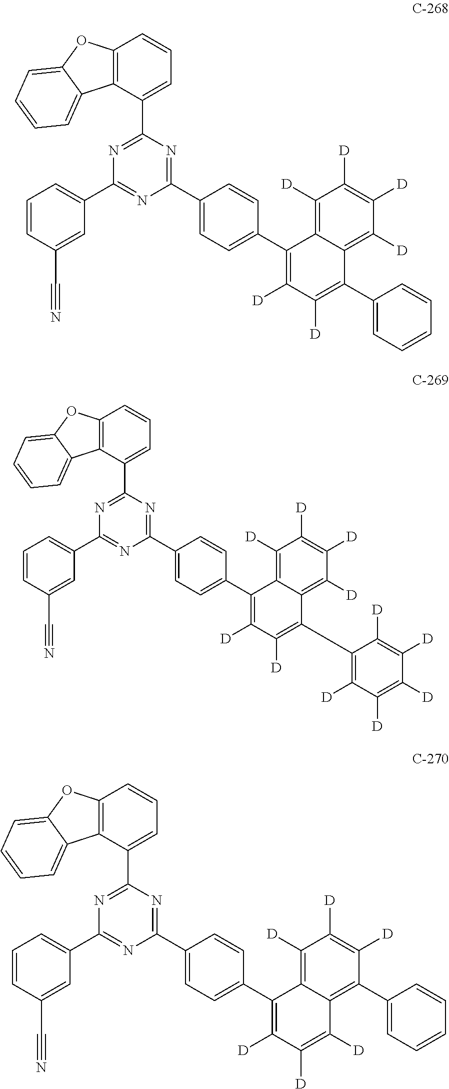 [SMILES: [2H]c1c([2H])c([2H])c2c(-c3ccc(-c4nc(-c5cccc(C#N)c5)nc(-c5cccc6oc7ccccc7c56)n4)cc3)c([2H])c([2H])c(-c3ccccc3)c2c1[2H] ; [2H]c1c([2H])c([2H])c(Cc2c([2H])c([2H])c(-c3ccc(-c4nc(-c5cccc(C#N)c5)nc(-c5cccc6oc7ccccc7c56)n4)cc3)c3c([2H])c([2H])c([2H])c([2H])c23)c([2H])c1[2H] ; [2H]c1c([2H])c(-c2ccc(-c3nc(-c4cccc(C#N)c4)nc(-c4cccc5oc6ccccc6c45)n3)cc2)c2c([2H])c([2H])c([2H])c(-c3ccccc3)c2c1[2H]]

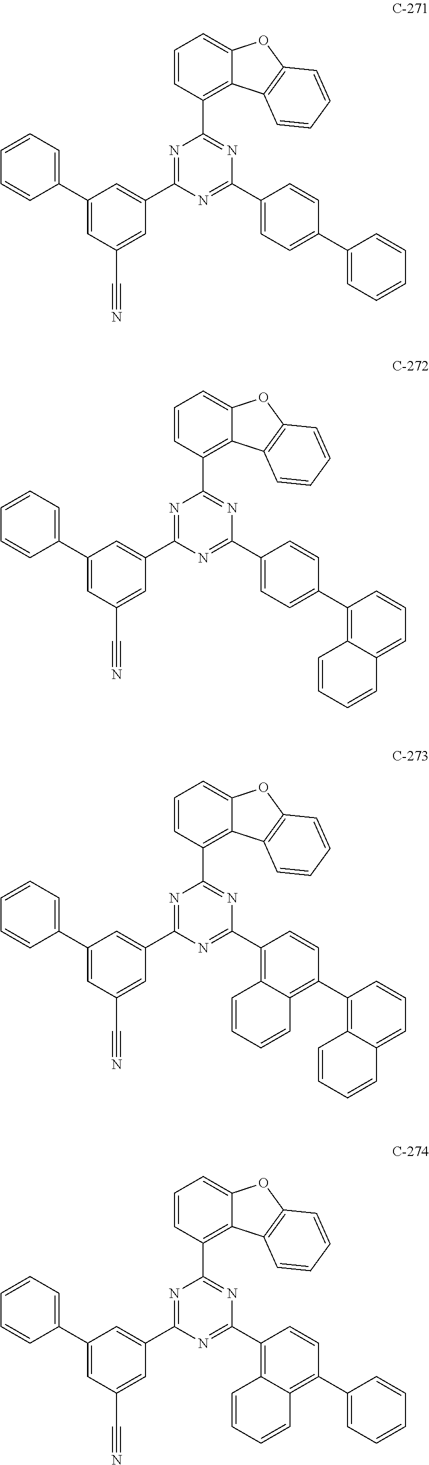 [SMILES: N#Cc1cc(-c2ccccc2)cc(-c2nc(-c3ccc(-c4ccccc4)cc3)nc(-c3cccc4oc5ccccc5c34)n2)c1 ; N#Cc1cc(-c2ccccc2)cc(-c2nc(-c3ccc(-c4cccc5ccccc45)cc3)nc(-c3cccc4oc5ccccc5c34)n2)c1 ; N#Cc1cc(-c2ccccc2)cc(-c2nc(-c3ccc(-c4cccc5ccccc45)c4ccccc34)nc(-c3cccc4oc5ccccc5c34)n2)c1 ; N#Cc1cc(-c2ccccc2)cc(-c2nc(-c3ccc(-c4ccccc4)c4ccccc34)nc(-c3cccc4oc5ccccc5c34)n2)c1]

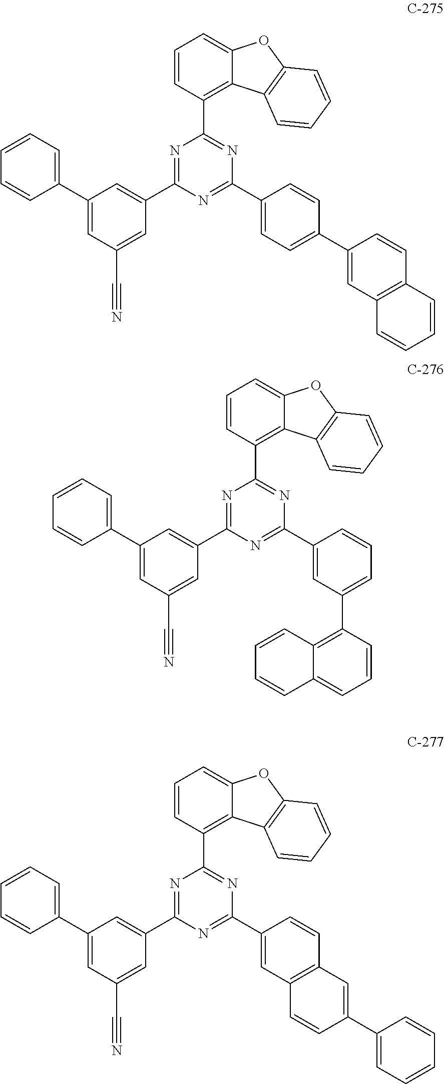 [SMILES: N#Cc1cc(-c2ccccc2)cc(-c2nc(-c3ccc(-c4ccc5ccccc5c4)cc3)nc(-c3cccc4oc5ccccc5c34)n2)c1 ; N#Cc1cc(-c2ccccc2)cc(-c2nc(-c3cccc(-c4cccc5ccccc45)c3)nc(-c3cccc4oc5ccccc5c34)n2)c1 ; N#Cc1cc(-c2ccccc2)cc(-c2nc(-c3ccc4cc(-c5ccccc5)ccc4c3)nc(-c3cccc4oc5ccccc5c34)n2)c1]

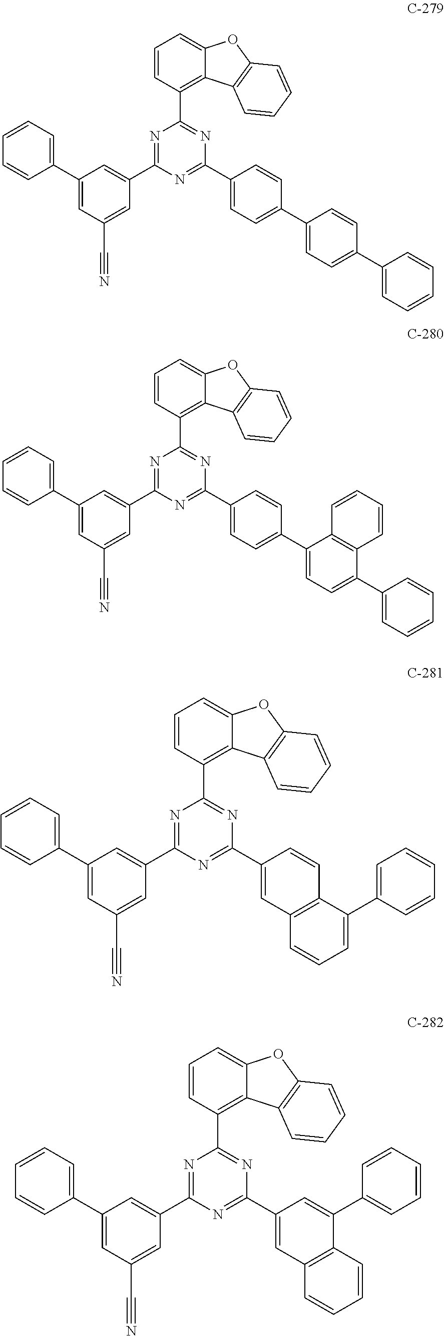 [SMILES: N#Cc1cc(-c2ccccc2)cc(-c2nc(-c3ccc(-c4ccc(-c5ccccc5)cc4)cc3)nc(-c3cccc4oc5ccccc5c34)n2)c1 ; N#Cc1cc(-c2ccccc2)cc(-c2nc(-c3ccc(-c4ccc(-c5ccccc5)c5ccccc45)cc3)nc(-c3cccc4oc5ccccc5c34)n2)c1 ; N#Cc1cc(-c2ccccc2)cc(-c2nc(-c3ccc4c(-c5ccccc5)cccc4c3)nc(-c3cccc4oc5ccccc5c34)n2)c1 ; N#Cc1cc(-c2ccccc2)cc(-c2nc(-c3cc(-c4ccccc4)c4ccccc4c3)nc(-c3cccc4oc5ccccc5c34)n2)c1]

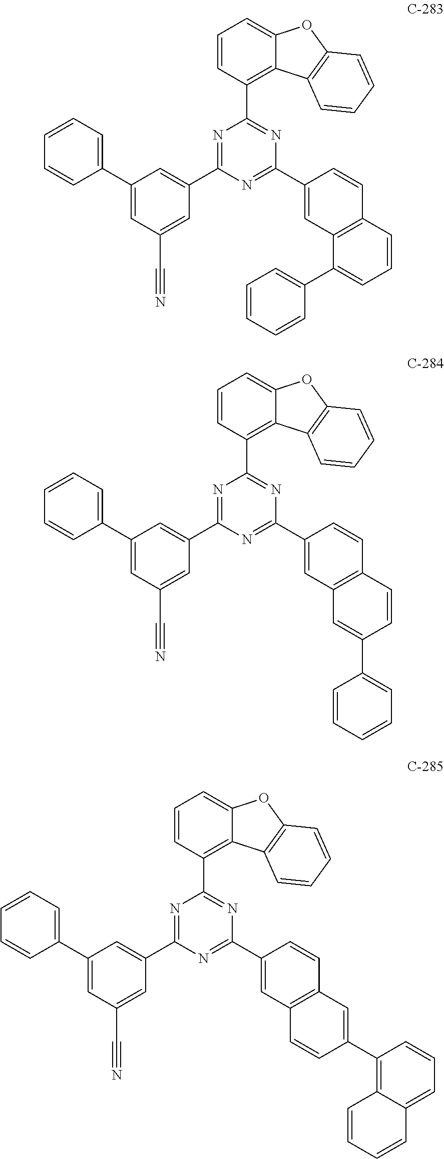 [SMILES: N#Cc1cc(-c2ccccc2)cc(-c2nc(-c3ccc4cccc(-c5ccccc5)c4c3)nc(-c3cccc4oc5ccccc5c34)n2)c1 ; N#Cc1cc(-c2ccccc2)cc(-c2nc(-c3ccc4ccc(-c5ccccc5)cc4c3)nc(-c3cccc4oc5ccccc5c34)n2)c1 ; N#Cc1cc(-c2ccccc2)cc(-c2nc(-c3ccc4cc(-c5cccc6ccccc56)ccc4c3)nc(-c3cccc4oc5ccccc5c34)n2)c1]

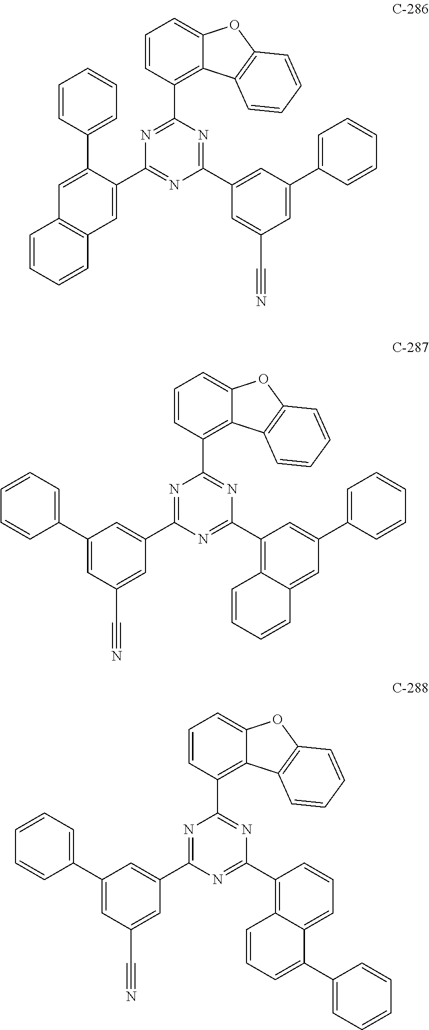 [SMILES: N#Cc1cc(-c2ccccc2)cc(-c2nc(-c3cc4ccccc4cc3-c3ccccc3)nc(-c3cccc4oc5ccccc5c34)n2)c1 ; N#Cc1cc(-c2ccccc2)cc(-c2nc(-c3cc(-c4ccccc4)cc4ccccc34)nc(-c3cccc4oc5ccccc5c34)n2)c1 ; N#Cc1cc(-c2ccccc2)cc(-c2nc(-c3cccc4c(-c5ccccc5)cccc34)nc(-c3cccc4oc5ccccc5c34)n2)c1]

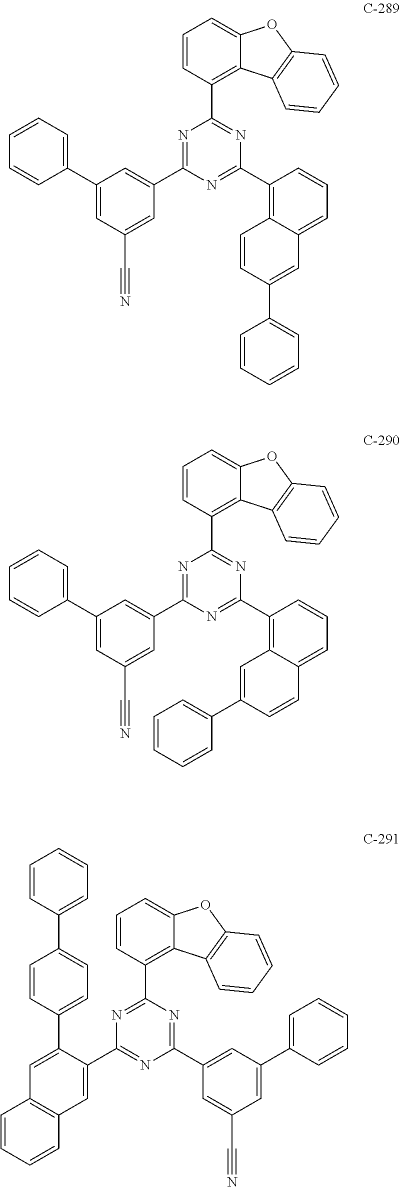 [SMILES: N#Cc1cc(-c2ccccc2)cc(-c2nc(-c3cccc4cc(-c5ccccc5)ccc34)nc(-c3cccc4oc5ccccc5c34)n2)c1 ; N#Cc1cc(-c2ccccc2)cc(-c2nc(-c3cccc4ccc(-c5ccccc5)cc34)nc(-c3cccc4oc5ccccc5c34)n2)c1 ; N#Cc1cc(-c2ccccc2)cc(-c2nc(-c3cc4ccccc4cc3-c3ccc(-c4ccccc4)cc3)nc(-c3cccc4oc5ccccc5c34)n2)c1]

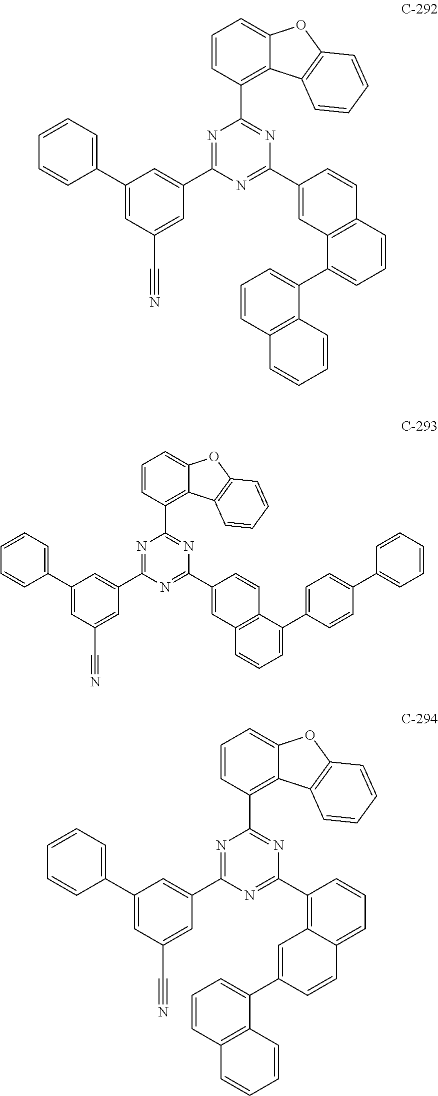 [SMILES: N#Cc1cc(-c2ccccc2)cc(-c2nc(-c3ccc4cccc(-c5cccc6ccccc56)c4c3)nc(-c3cccc4oc5ccccc5c34)n2)c1 ; N#Cc1cc(-c2ccccc2)cc(-c2nc(-c3ccc4c(-c5ccc(-c6ccccc6)cc5)cccc4c3)nc(-c3cccc4oc5ccccc5c34)n2)c1 ; N#Cc1cc(-c2ccccc2)cc(-c2nc(-c3cccc4ccc(-c5cccc6ccccc56)cc34)nc(-c3cccc4oc5ccccc5c34)n2)c1]

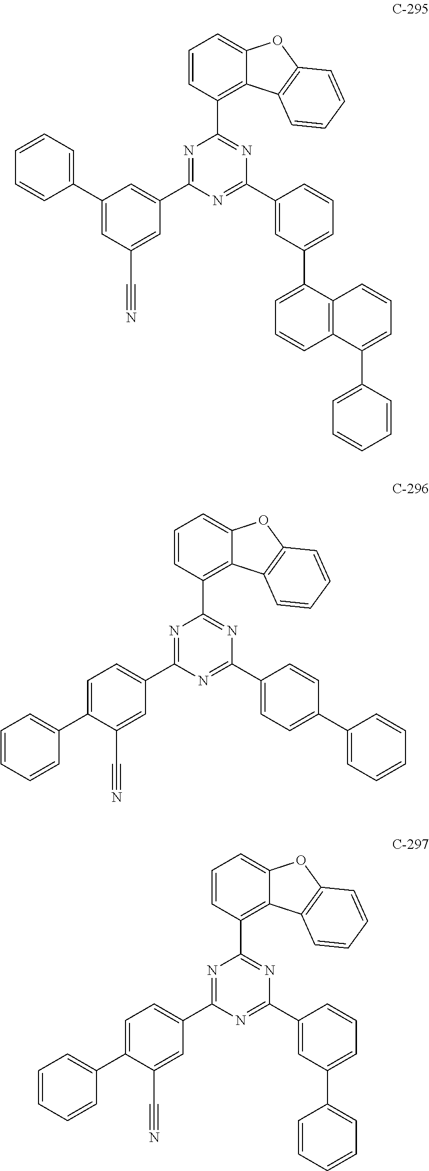 [SMILES: N#Cc1cc(-c2ccccc2)cc(-c2nc(-c3cccc(-c4cccc5c(-c6ccccc6)cccc45)c3)nc(-c3cccc4oc5ccccc5c34)n2)c1 ; N#Cc1cc(-c2nc(-c3ccc(-c4ccccc4)cc3)nc(-c3cccc4oc5ccccc5c34)n2)ccc1-c1ccccc1 ; N#Cc1cc(-c2nc(-c3cccc(-c4ccccc4)c3)nc(-c3cccc4oc5ccccc5c34)n2)ccc1-c1ccccc1]

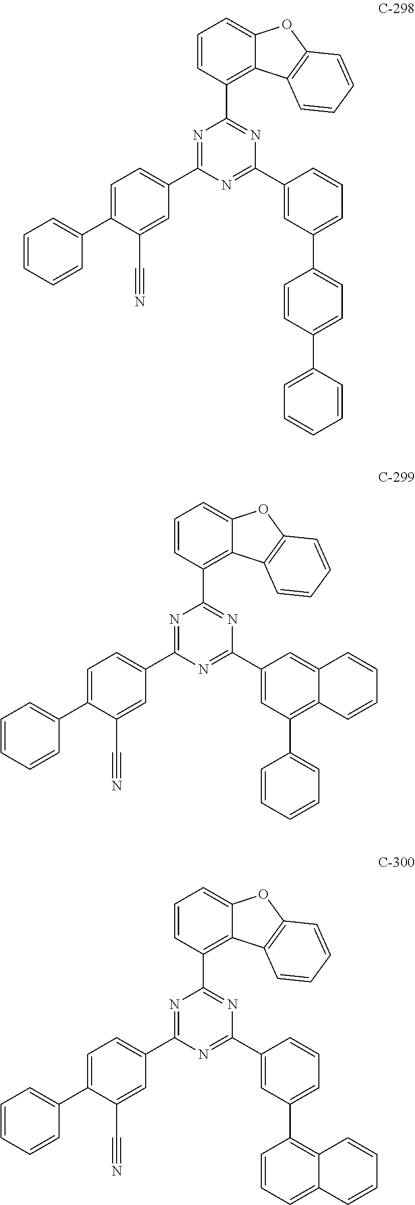 [SMILES: N#Cc1cc(-c2nc(-c3cccc(-c4ccc(-c5ccccc5)cc4)c3)nc(-c3cccc4oc5ccccc5c34)n2)ccc1-c1ccccc1 ; N#Cc1cc(-c2nc(-c3cc(-c4ccccc4)c4ccccc4c3)nc(-c3cccc4oc5ccccc5c34)n2)ccc1-c1ccccc1 ; N#Cc1cc(-c2nc(-c3cccc(-c4cccc5ccccc45)c3)nc(-c3cccc4oc5ccccc5c34)n2)ccc1-c1ccccc1]

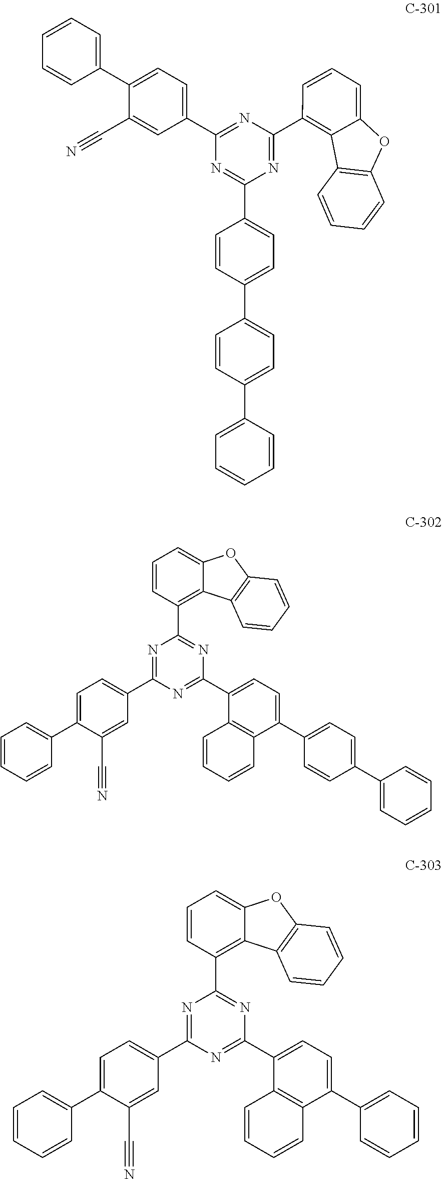 [SMILES: N#Cc1cc(-c2nc(-c3ccc(-c4ccc(-c5ccccc5)cc4)cc3)nc(-c3cccc4oc5ccccc5c34)n2)ccc1-c1ccccc1 ; N#Cc1cc(-c2nc(-c3ccc(-c4ccc(-c5ccccc5)cc4)c4ccccc34)nc(-c3cccc4oc5ccccc5c34)n2)ccc1-c1ccccc1 ; N#Cc1cc(-c2nc(-c3ccc(-c4ccccc4)c4ccccc34)nc(-c3cccc4oc5ccccc5c34)n2)ccc1-c1ccccc1]

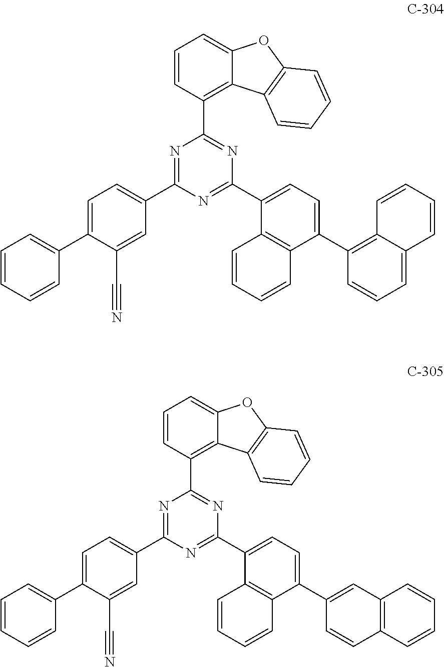 [SMILES: N#Cc1cc(-c2nc(-c3ccc(-c4cccc5ccccc45)c4ccccc34)nc(-c3cccc4oc5ccccc5c34)n2)ccc1-c1ccccc1 ; N#Cc1cc(-c2nc(-c3ccc(-c4ccc5ccccc5c4)c4ccccc34)nc(-c3cccc4oc5ccccc5c34)n2)ccc1-c1ccccc1]

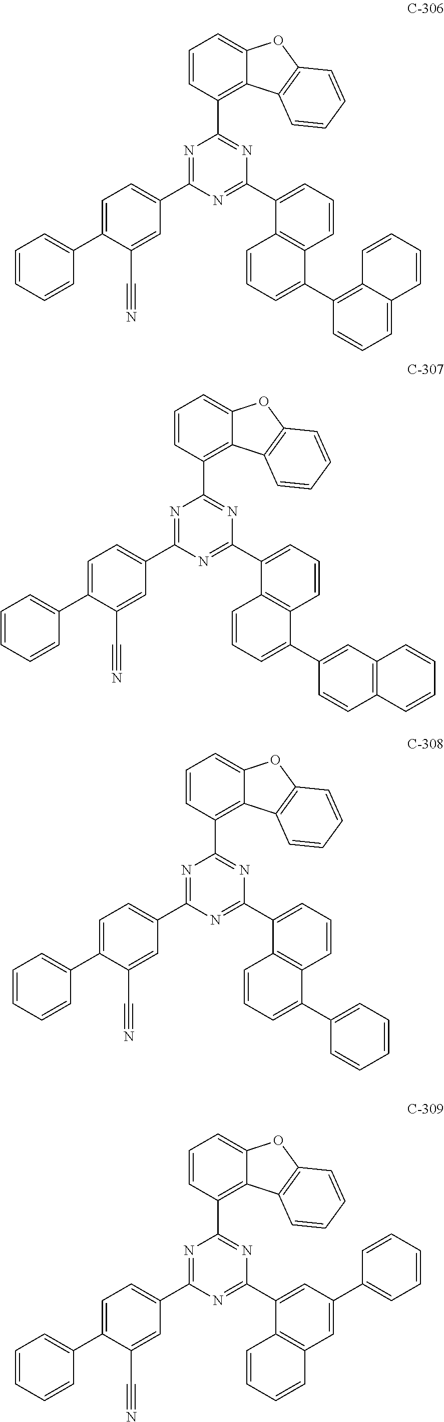 [SMILES: N#Cc1cc(-c2nc(-c3cccc4c(-c5cccc6ccccc56)cccc34)nc(-c3cccc4oc5ccccc5c34)n2)ccc1-c1ccccc1 ; N#Cc1cc(-c2nc(-c3cccc4c(-c5ccc6ccccc6c5)cccc34)nc(-c3cccc4oc5ccccc5c34)n2)ccc1-c1ccccc1 ; N#Cc1cc(-c2nc(-c3cccc4c(-c5ccccc5)cccc34)nc(-c3cccc4oc5ccccc5c34)n2)ccc1-c1ccccc1 ; N#Cc1cc(-c2nc(-c3cc(-c4ccccc4)cc4ccccc34)nc(-c3cccc4oc5ccccc5c34)n2)ccc1-c1ccccc1]

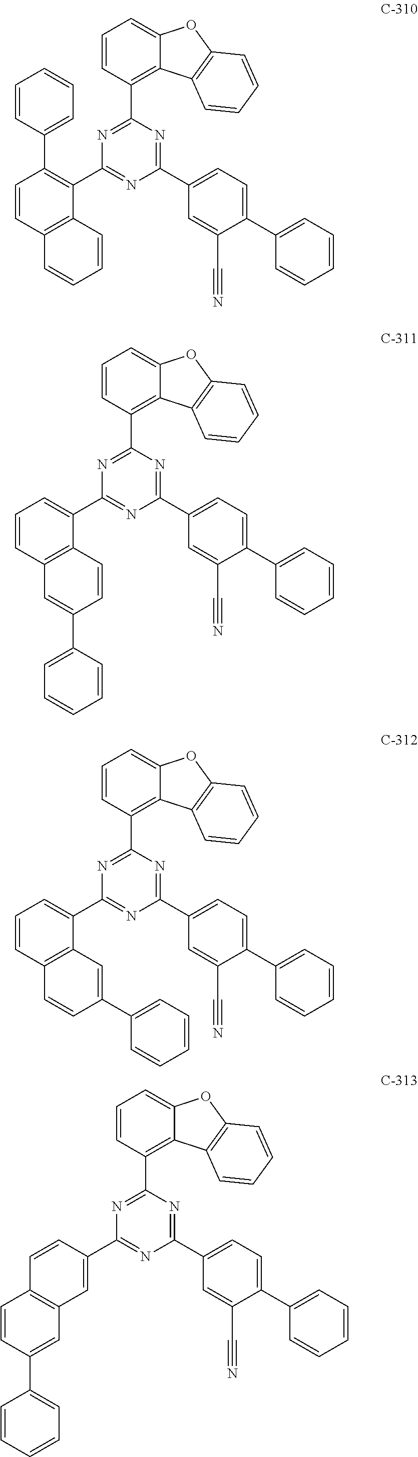

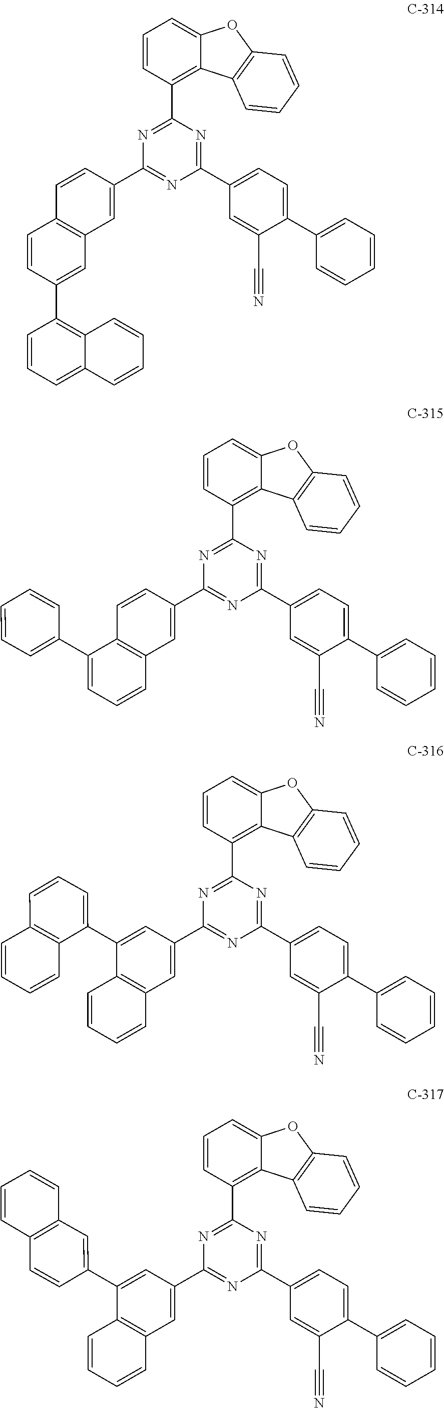 [SMILES: N#Cc1cc(-c2nc(-c3ccc4ccc(-c5cccc6ccccc56)cc4c3)nc(-c3cccc4oc5ccccc5c34)n2)ccc1-c1ccccc1 ; N#Cc1cc(-c2nc(-c3ccc4c(-c5ccccc5)cccc4c3)nc(-c3cccc4oc5ccccc5c34)n2)ccc1-c1ccccc1 ; N#Cc1cc(-c2nc(-c3cc(-c4cccc5ccccc45)c4ccccc4c3)nc(-c3cccc4oc5ccccc5c34)n2)ccc1-c1ccccc1 ; N#Cc1cc(-c2nc(-c3cc(-c4ccc5ccccc5c4)c4ccccc4c3)nc(-c3cccc4oc5ccccc5c34)n2)ccc1-c1ccccc1]

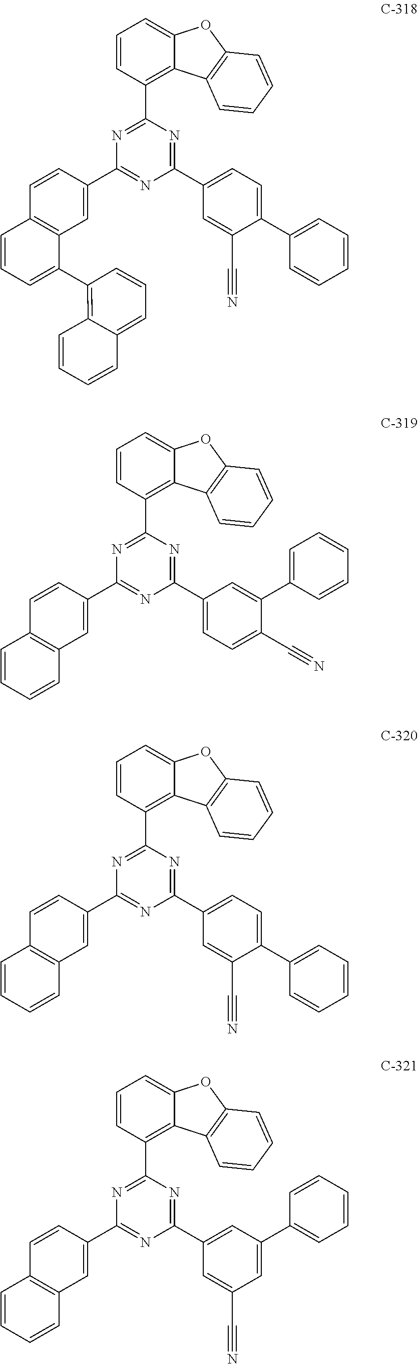 [SMILES: N#Cc1cc(-c2nc(-c3ccc4cccc(-c5cccc6ccccc56)c4c3)nc(-c3cccc4oc5ccccc5c34)n2)ccc1-c1ccccc1 ; N#Cc1ccc(-c2nc(-c3ccc4ccccc4c3)nc(-c3cccc4oc5ccccc5c34)n2)cc1-c1ccccc1 ; N#Cc1cc(-c2nc(-c3ccc4ccccc4c3)nc(-c3cccc4oc5ccccc5c34)n2)ccc1-c1ccccc1 ; N#Cc1cc(-c2ccccc2)cc(-c2nc(-c3ccc4ccccc4c3)nc(-c3cccc4oc5ccccc5c34)n2)c1]

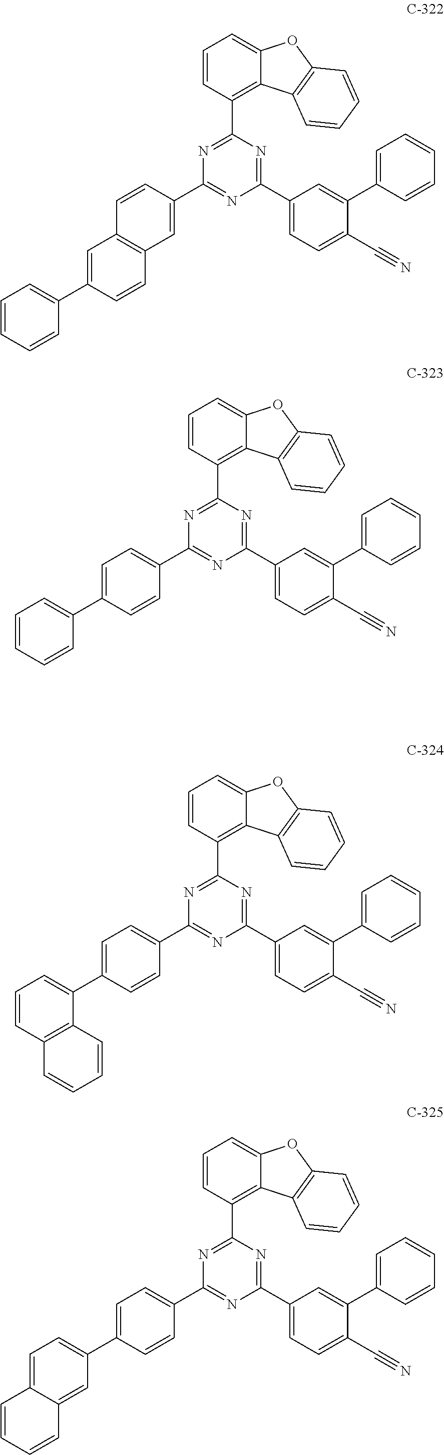 [SMILES: N#Cc1ccc(-c2nc(-c3ccc4cc(-c5ccccc5)ccc4c3)nc(-c3cccc4oc5ccccc5c34)n2)cc1-c1ccccc1 ; N#Cc1ccc(-c2nc(-c3ccc(-c4ccccc4)cc3)nc(-c3cccc4oc5ccccc5c34)n2)cc1-c1ccccc1 ; N#Cc1ccc(-c2nc(-c3ccc(-c4cccc5ccccc45)cc3)nc(-c3cccc4oc5ccccc5c34)n2)cc1-c1ccccc1 ; N#Cc1ccc(-c2nc(-c3ccc(-c4ccc5ccccc5c4)cc3)nc(-c3cccc4oc5ccccc5c34)n2)cc1-c1ccccc1]

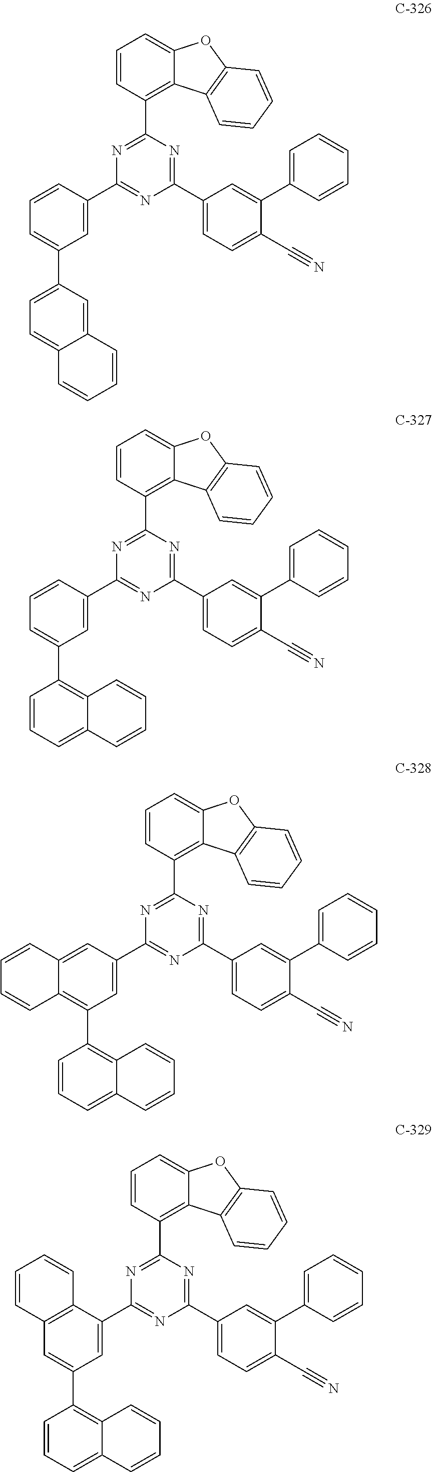 [SMILES: N#Cc1ccc(-c2nc(-c3cccc(-c4ccc5ccccc5c4)c3)nc(-c3cccc4oc5ccccc5c34)n2)cc1-c1ccccc1 ; N#Cc1ccc(-c2nc(-c3cccc(-c4cccc5ccccc45)c3)nc(-c3cccc4oc5ccccc5c34)n2)cc1-c1ccccc1 ; N#Cc1ccc(-c2nc(-c3cc(-c4cccc5ccccc45)c4ccccc4c3)nc(-c3cccc4oc5ccccc5c34)n2)cc1-c1ccccc1 ; N#Cc1ccc(-c2nc(-c3cc(-c4cccc5ccccc45)cc4ccccc34)nc(-c3cccc4oc5ccccc5c34)n2)cc1-c1ccccc1]

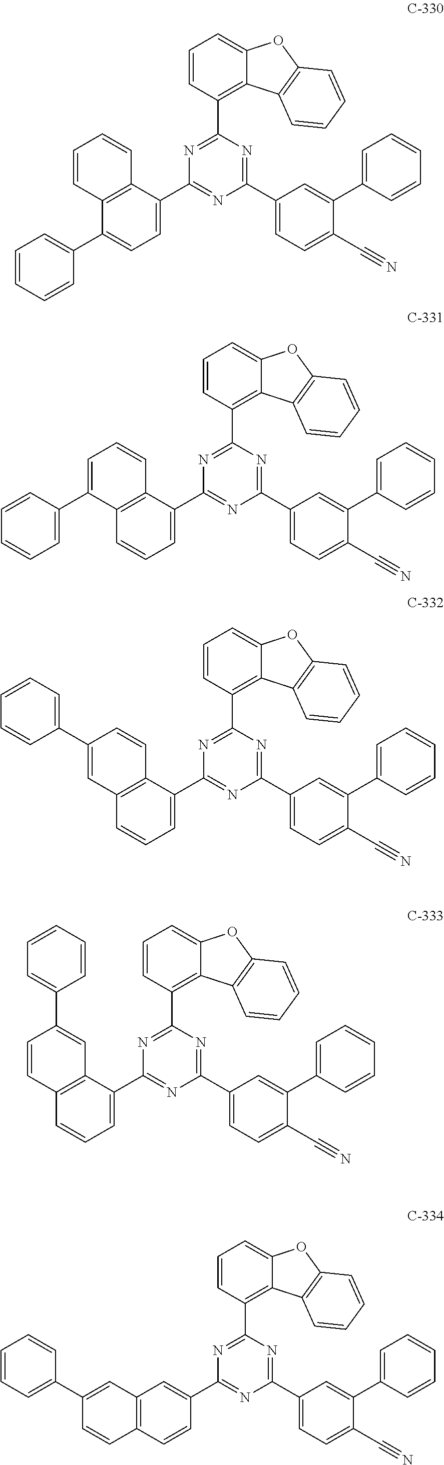 [SMILES: N#Cc1ccc(-c2nc(-c3ccc(-c4ccccc4)c4ccccc34)nc(-c3cccc4oc5ccccc5c34)n2)cc1-c1ccccc1 ; N#Cc1ccc(-c2nc(-c3cccc4c(-c5ccccc5)cccc34)nc(-c3cccc4oc5ccccc5c34)n2)cc1-c1ccccc1 ; N#Cc1ccc(-c2nc(-c3cccc4cc(-c5ccccc5)ccc34)nc(-c3cccc4oc5ccccc5c34)n2)cc1-c1ccccc1 ; N#Cc1ccc(-c2nc(-c3cccc4ccc(-c5ccccc5)cc34)nc(-c3cccc4oc5ccccc5c34)n2)cc1-c1ccccc1 ; N#Cc1ccc(-c2nc(-c3ccc4ccc(-c5ccccc5)cc4c3)nc(-c3cccc4oc5ccccc5c34)n2)cc1-c1ccccc1]

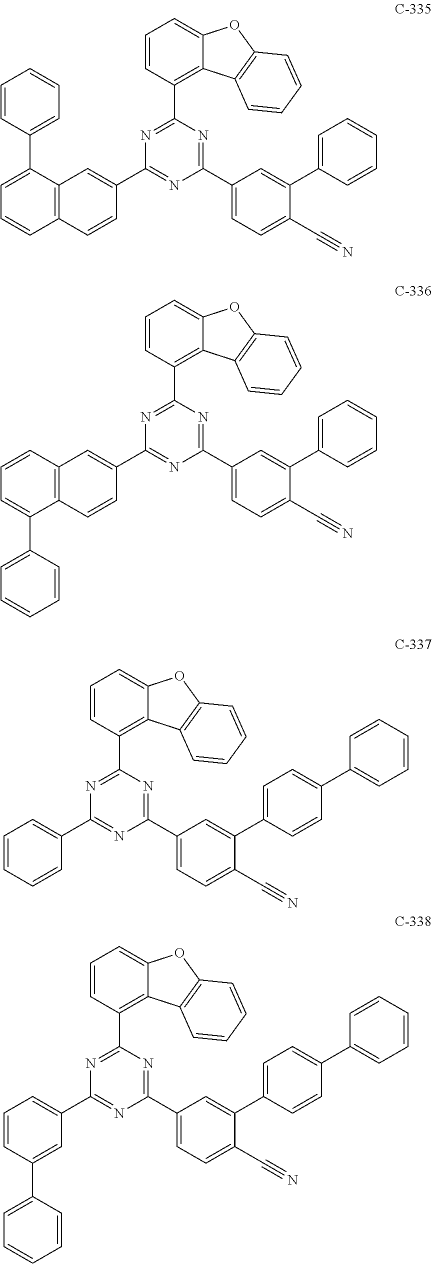 [SMILES: N#Cc1ccc(-c2nc(-c3ccc4cccc(-c5ccccc5)c4c3)nc(-c3cccc4oc5ccccc5c34)n2)cc1-c1ccccc1 ; N#Cc1ccc(-c2nc(-c3ccc4c(-c5ccccc5)cccc4c3)nc(-c3cccc4oc5ccccc5c34)n2)cc1-c1ccccc1 ; N#Cc1ccc(-c2nc(-c3ccccc3)nc(-c3cccc4oc5ccccc5c34)n2)cc1-c1ccc(-c2ccccc2)cc1 ; N#Cc1ccc(-c2nc(-c3cccc(-c4ccccc4)c3)nc(-c3cccc4oc5ccccc5c34)n2)cc1-c1ccc(-c2ccccc2)cc1]

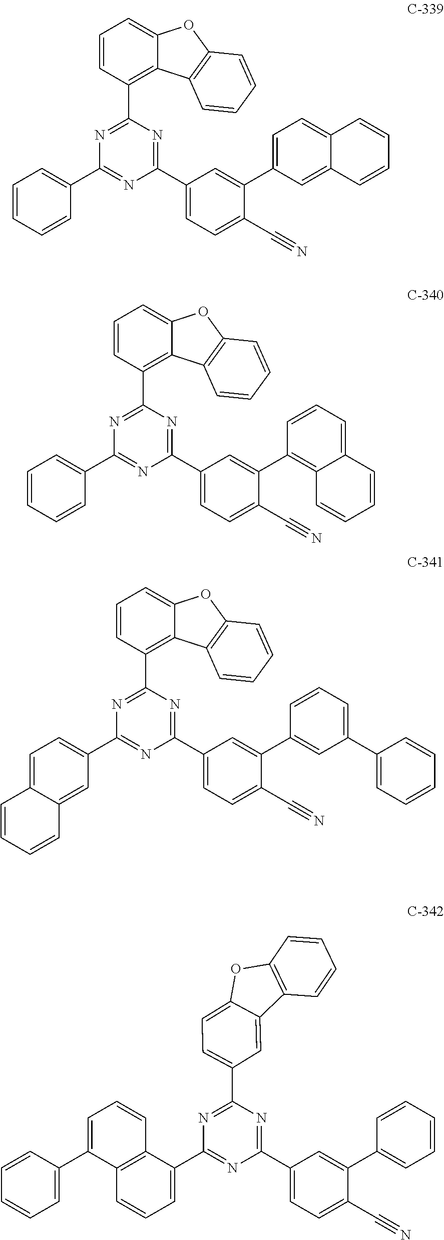 [SMILES: N#Cc1ccc(-c2nc(-c3ccccc3)nc(-c3cccc4oc5ccccc5c34)n2)cc1-c1ccc2ccccc2c1 ; N#Cc1ccc(-c2nc(-c3ccccc3)nc(-c3cccc4oc5ccccc5c34)n2)cc1-c1cccc2ccccc12 ; N#Cc1ccc(-c2nc(-c3ccc4ccccc4c3)nc(-c3cccc4oc5ccccc5c34)n2)cc1-c1cccc(-c2ccccc2)c1 ; N#Cc1ccc(-c2nc(-c3ccc4oc5ccccc5c4c3)nc(-c3cccc4c(-c5ccccc5)cccc34)n2)cc1-c1ccccc1]

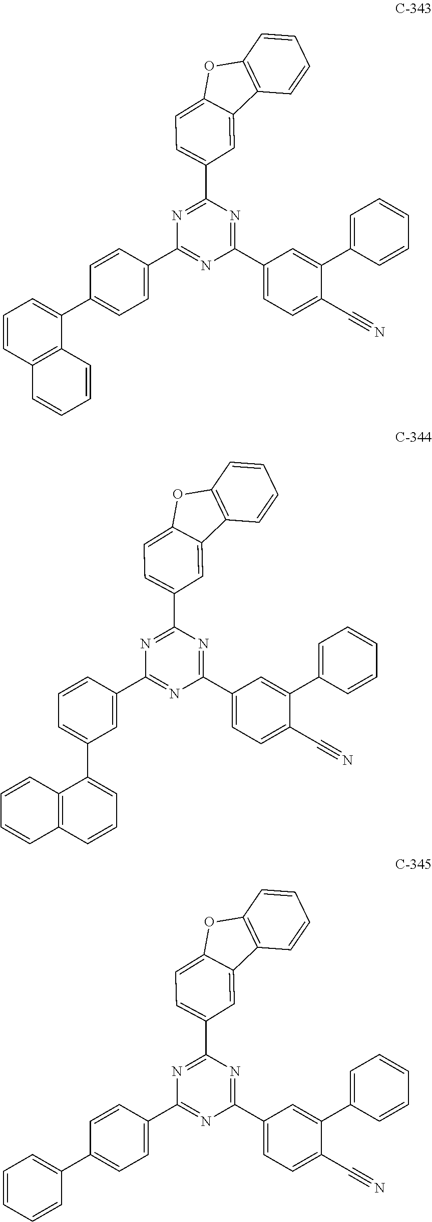 [SMILES: N#Cc1ccc(-c2nc(-c3ccc(-c4cccc5ccccc45)cc3)nc(-c3ccc4oc5ccccc5c4c3)n2)cc1-c1ccccc1 ; N#Cc1ccc(-c2nc(-c3cccc(-c4cccc5ccccc45)c3)nc(-c3ccc4oc5ccccc5c4c3)n2)cc1-c1ccccc1 ; N#Cc1ccc(-c2nc(-c3ccc(-c4ccccc4)cc3)nc(-c3ccc4oc5ccccc5c4c3)n2)cc1-c1ccccc1]

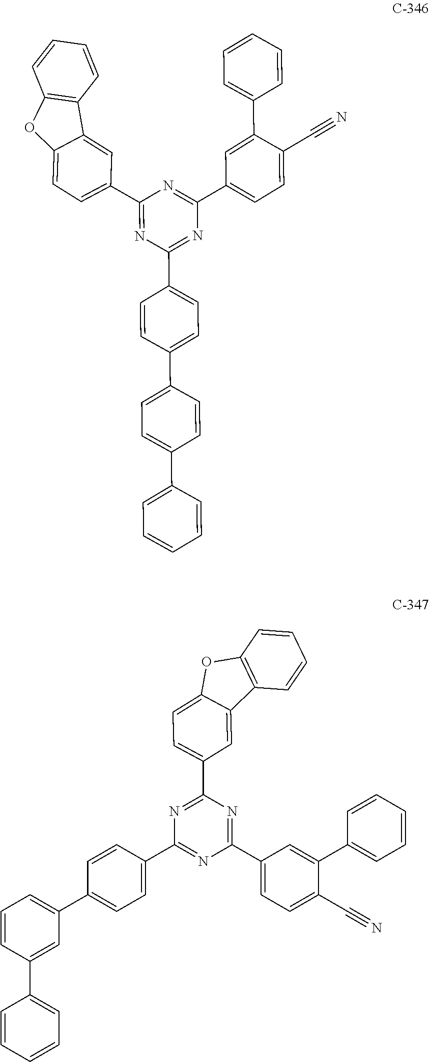 [SMILES: N#Cc1ccc(-c2nc(-c3ccc(-c4ccc(-c5ccccc5)cc4)cc3)nc(-c3ccc4oc5ccccc5c4c3)n2)cc1-c1ccccc1 ; N#Cc1ccc(-c2nc(-c3ccc(-c4cccc(-c5ccccc5)c4)cc3)nc(-c3ccc4oc5ccccc5c4c3)n2)cc1-c1ccccc1]

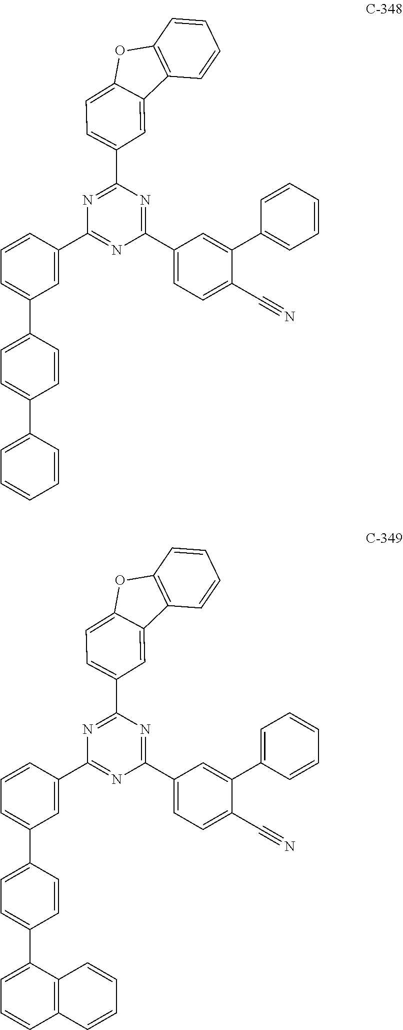 [SMILES: N#Cc1ccc(-c2nc(-c3cccc(-c4ccc(-c5ccccc5)cc4)c3)nc(-c3ccc4oc5ccccc5c4c3)n2)cc1-c1ccccc1 ; N#Cc1ccc(-c2nc(-c3cccc(-c4ccc(-c5cccc6ccccc56)cc4)c3)nc(-c3ccc4oc5ccccc5c4c3)n2)cc1-c1ccccc1]

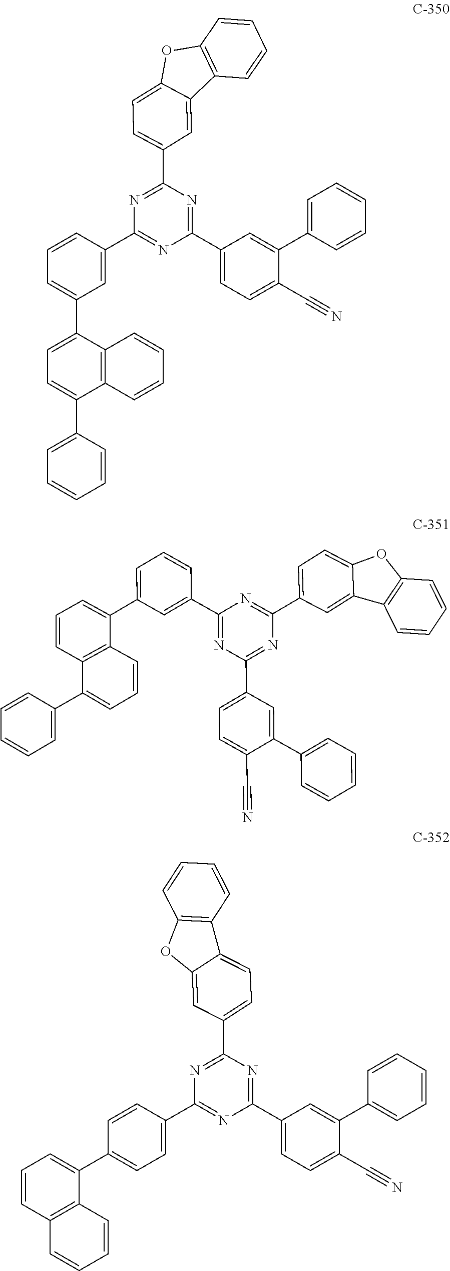 [SMILES: N#Cc1ccc(-c2nc(-c3cccc(-c4ccc(-c5ccccc5)c5ccccc45)c3)nc(-c3ccc4oc5ccccc5c4c3)n2)cc1-c1ccccc1 ; N#Cc1ccc(-c2nc(-c3cccc(-c4cccc5c(-c6ccccc6)cccc45)c3)nc(-c3ccc4oc5ccccc5c4c3)n2)cc1-c1ccccc1 ; N#Cc1ccc(-c2nc(-c3ccc(-c4cccc5ccccc45)cc3)nc(-c3ccc4c(c3)oc3ccccc34)n2)cc1-c1ccccc1]

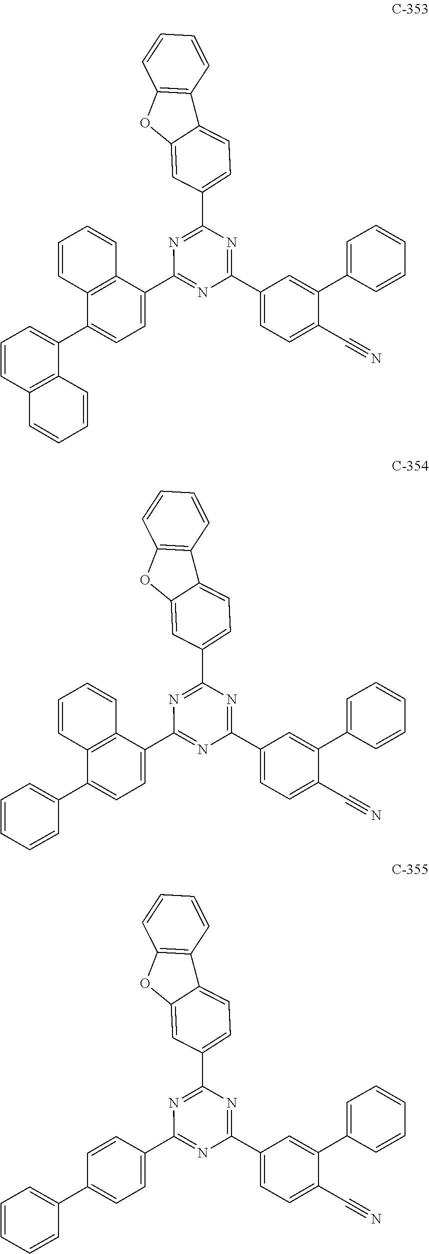 [SMILES: N#Cc1ccc(-c2nc(-c3ccc4c(c3)oc3ccccc34)nc(-c3ccc(-c4cccc5ccccc45)c4ccccc34)n2)cc1-c1ccccc1 ; N#Cc1ccc(-c2nc(-c3ccc4c(c3)oc3ccccc34)nc(-c3ccc(-c4ccccc4)c4ccccc34)n2)cc1-c1ccccc1 ; N#Cc1ccc(-c2nc(-c3ccc(-c4ccccc4)cc3)nc(-c3ccc4c(c3)oc3ccccc34)n2)cc1-c1ccccc1]

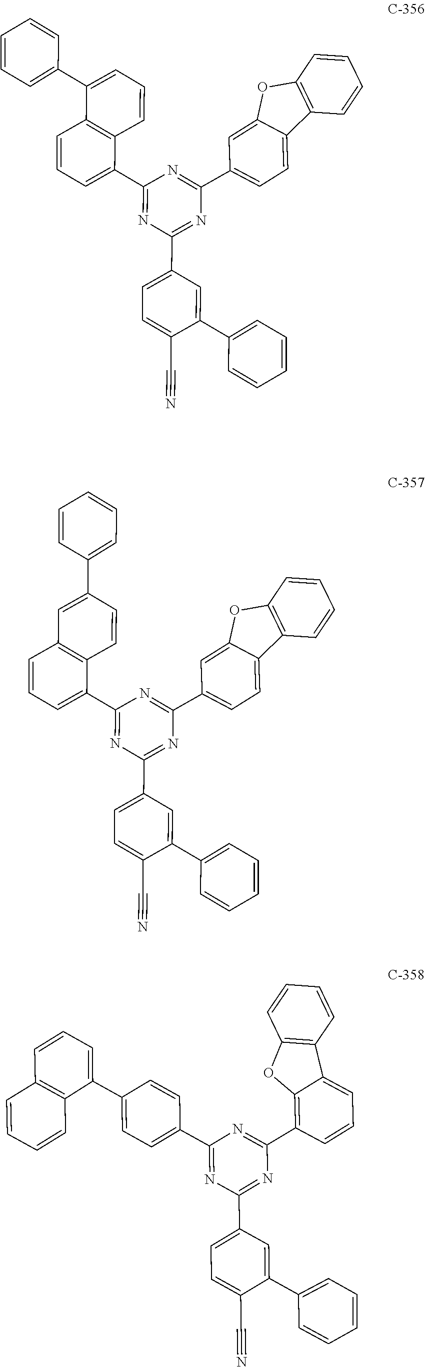 [SMILES: N#Cc1ccc(-c2nc(-c3ccc4c(c3)oc3ccccc34)nc(-c3cccc4c(-c5ccccc5)cccc34)n2)cc1-c1ccccc1 ; N#Cc1ccc(-c2nc(-c3ccc4c(c3)oc3ccccc34)nc(-c3cccc4cc(-c5ccccc5)ccc34)n2)cc1-c1ccccc1 ; N#Cc1ccc(-c2nc(-c3ccc(-c4cccc5ccccc45)cc3)nc(-c3cccc4c3oc3ccccc34)n2)cc1-c1ccccc1]

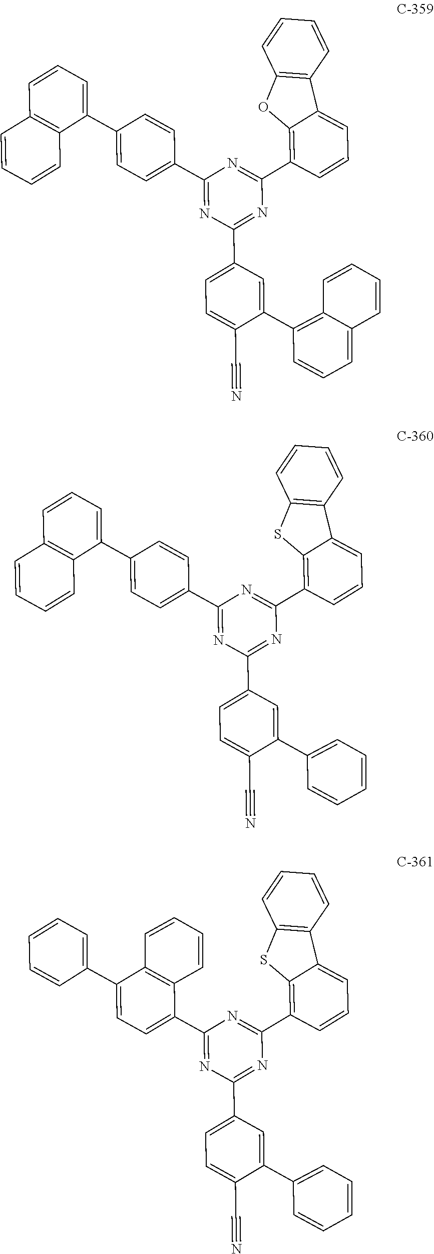 [SMILES: N#Cc1ccc(-c2nc(-c3ccc(-c4cccc5ccccc45)cc3)nc(-c3cccc4c3oc3ccccc34)n2)cc1-c1cccc2ccccc12 ; N#Cc1ccc(-c2nc(-c3ccc(-c4cccc5ccccc45)cc3)nc(-c3cccc4c3sc3ccccc34)n2)cc1-c1ccccc1 ; N#Cc1ccc(-c2nc(-c3ccc(-c4ccccc4)c4ccccc34)nc(-c3cccc4c3sc3ccccc34)n2)cc1-c1ccccc1]

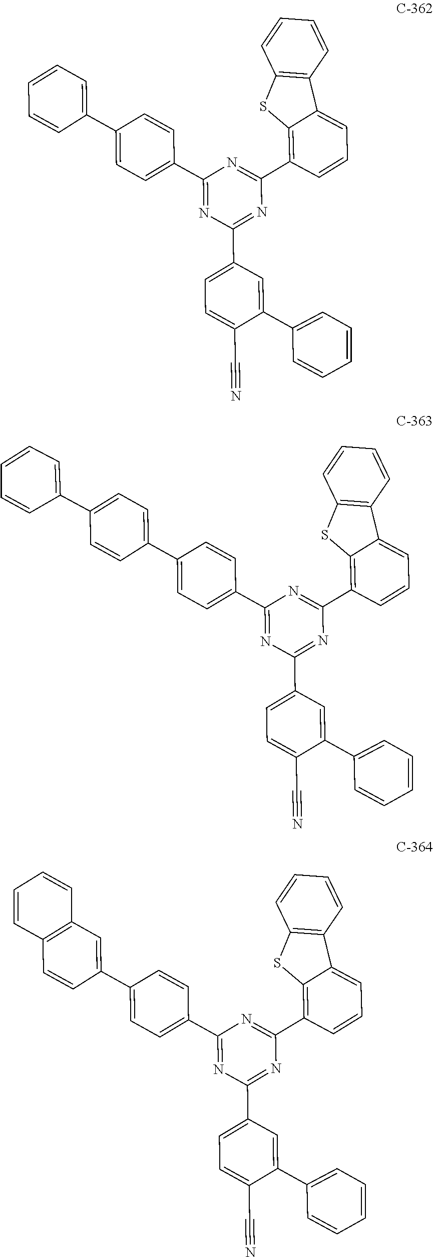 [SMILES: N#Cc1ccc(-c2nc(-c3ccc(-c4ccccc4)cc3)nc(-c3cccc4c3sc3ccccc34)n2)cc1-c1ccccc1 ; N#Cc1ccc(-c2nc(-c3ccc(-c4ccc(-c5ccccc5)cc4)cc3)nc(-c3cccc4c3sc3ccccc34)n2)cc1-c1ccccc1 ; N#Cc1ccc(-c2nc(-c3ccc(-c4ccc5ccccc5c4)cc3)nc(-c3cccc4c3sc3ccccc34)n2)cc1-c1ccccc1]

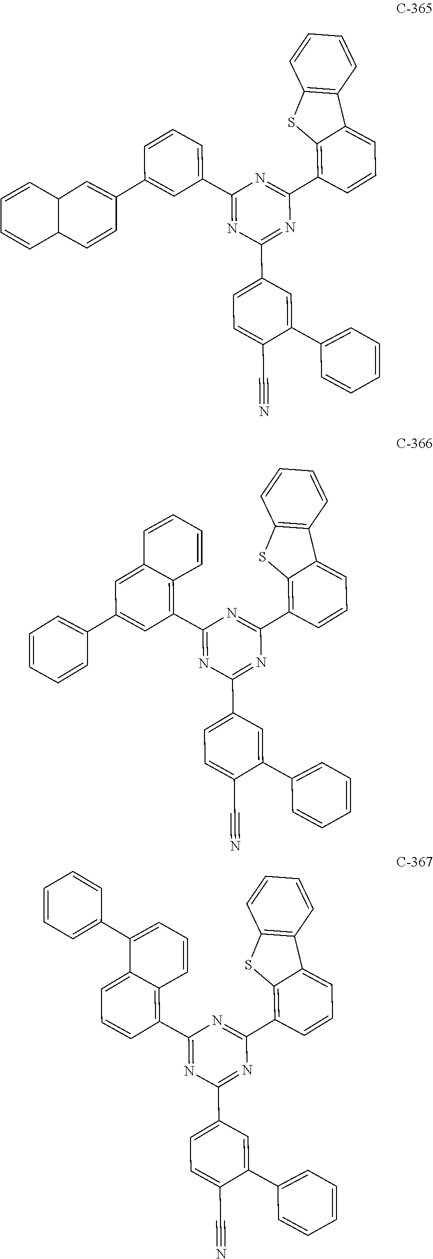

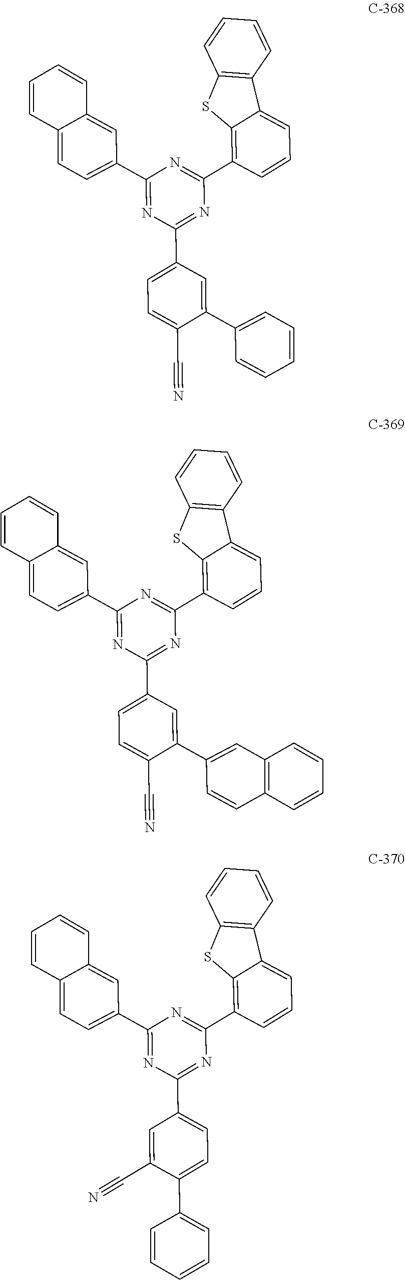 [SMILES: N#Cc1ccc(-c2nc(-c3ccc4ccccc4c3)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccc2ccccc2c1 ; N#Cc1cc(-c2nc(-c3ccc4ccccc4c3)nc(-c3cccc4c3sc3ccccc34)n2)ccc1-c1ccccc1]

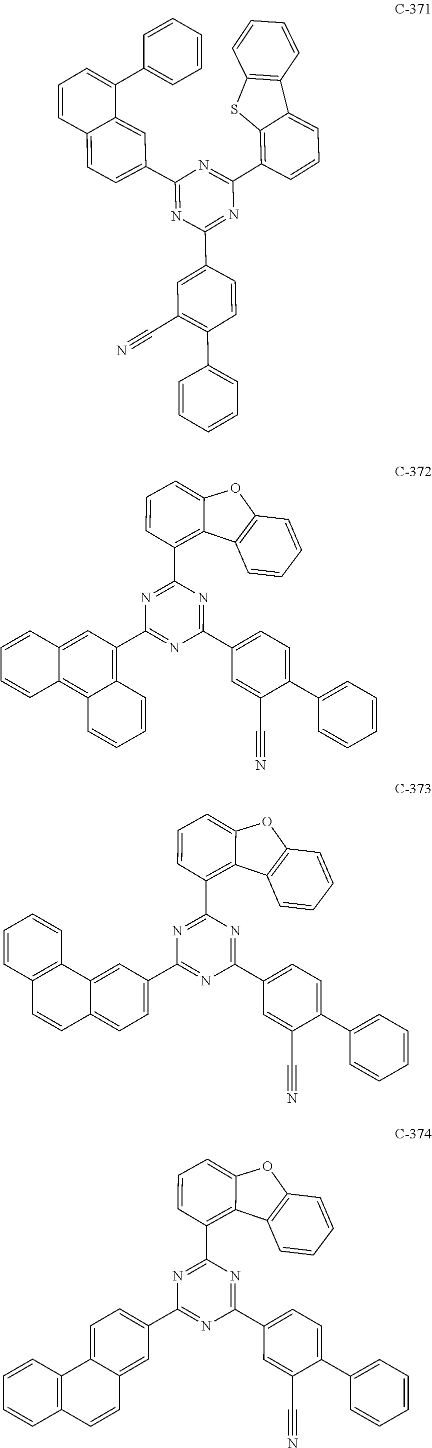 [SMILES: N#Cc1cc(-c2nc(-c3ccc4cccc(-c5ccccc5)c4c3)nc(-c3cccc4c3sc3ccccc34)n2)ccc1-c1ccccc1 ; N#Cc1cc(-c2nc(-c3cc4ccccc4c4ccccc34)nc(-c3cccc4oc5ccccc5c34)n2)ccc1-c1ccccc1 ; N#Cc1cc(-c2nc(-c3ccc4ccc5ccccc5c4c3)nc(-c3cccc4oc5ccccc5c34)n2)ccc1-c1ccccc1 ; N#Cc1cc(-c2nc(-c3ccc4c(ccc5ccccc54)c3)nc(-c3cccc4oc5ccccc5c34)n2)ccc1-c1ccccc1]

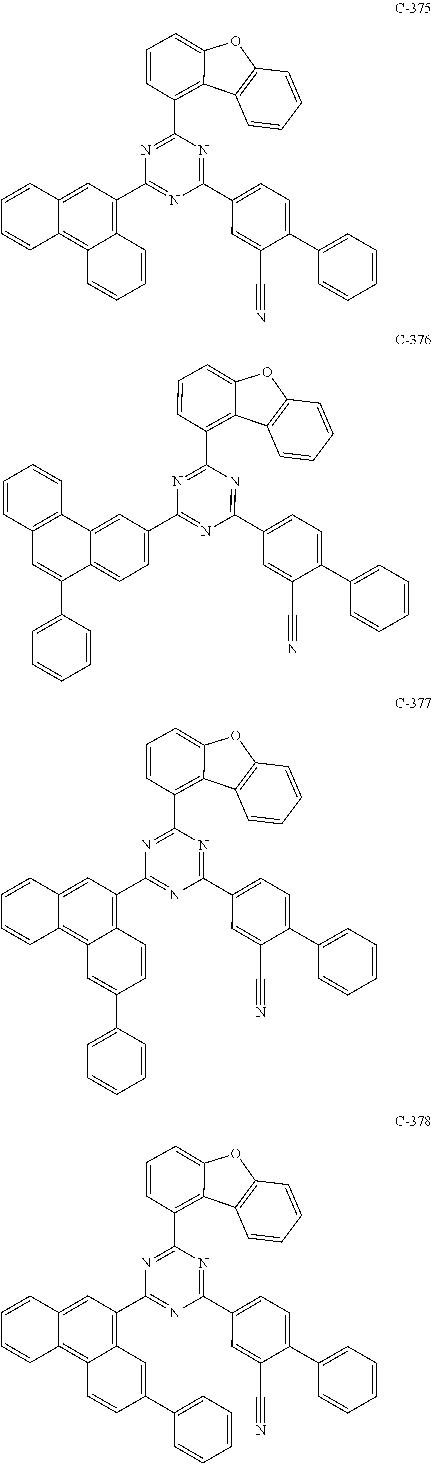 [SMILES: N#Cc1cc(-c2nc(-c3cc4ccccc4c4ccccc34)nc(-c3cccc4oc5ccccc5c34)n2)ccc1-c1ccccc1 ; N#Cc1cc(-c2nc(-c3ccc4c(-c5ccccc5)cc5ccccc5c4c3)nc(-c3cccc4oc5ccccc5c34)n2)ccc1-c1ccccc1 ; N#Cc1cc(-c2nc(-c3cc4ccccc4c4cc(-c5ccccc5)ccc34)nc(-c3cccc4oc5ccccc5c34)n2)ccc1-c1ccccc1 ; N#Cc1cc(-c2nc(-c3cc4ccccc4c4ccc(-c5ccccc5)cc34)nc(-c3cccc4oc5ccccc5c34)n2)ccc1-c1ccccc1]

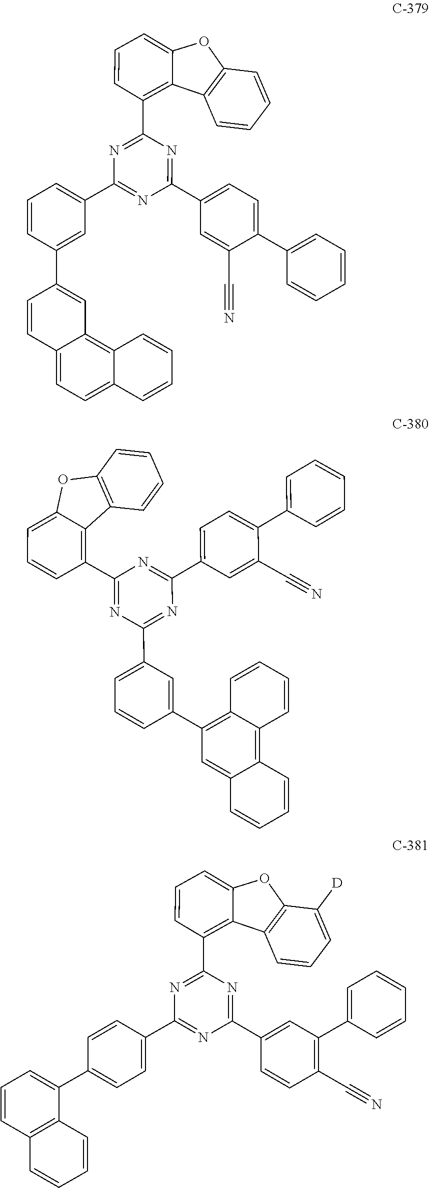 [SMILES: N#Cc1cc(-c2nc(-c3cccc(-c4ccc5ccc6ccccc6c5c4)c3)nc(-c3cccc4oc5ccccc5c34)n2)ccc1-c1ccccc1 ; N#Cc1cc(-c2nc(-c3cccc(-c4cc5ccccc5c5ccccc45)c3)nc(-c3cccc4oc5ccccc5c34)n2)ccc1-c1ccccc1 ; [2H]c1cccc2c1oc1cccc(-c3nc(-c4ccc(-c5cccc6ccccc56)cc4)nc(-c4ccc(C#N)c(-c5ccccc5)c4)n3)c12]

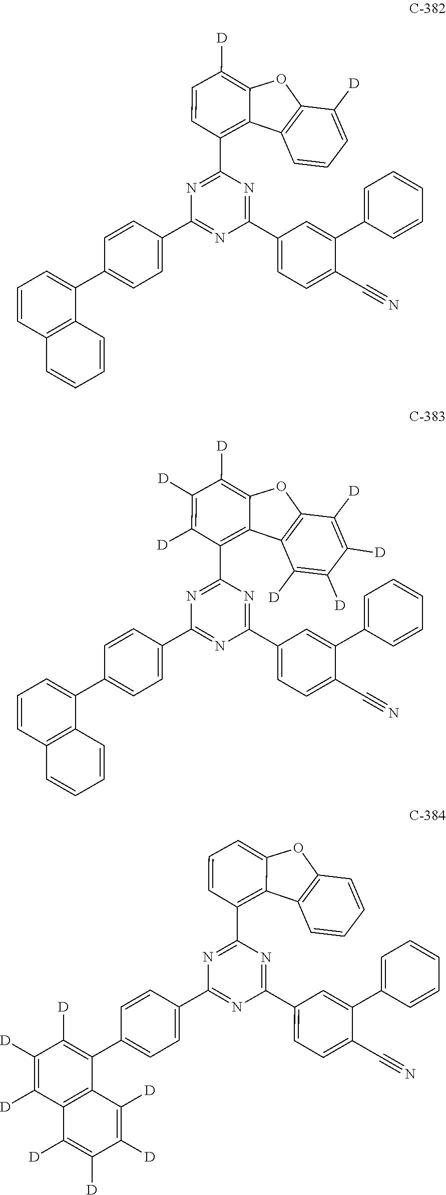 [SMILES: [2H]c1cccc2c1oc1c([2H])ccc(-c3nc(-c4ccc(-c5cccc6ccccc56)cc4)nc(-c4ccc(C#N)c(-c5ccccc5)c4)n3)c12 ; [2H]c1c([2H])c([2H])c2c(oc3c([2H])c([2H])c([2H])c(-c4nc(-c5ccc(-c6cccc7ccccc67)cc5)nc(-c5ccc(C#N)c(-c6ccccc6)c5)n4)c32)c1[2H] ; [2H]c1c([2H])c([2H])c2c(-c3ccc(-c4nc(-c5ccc(C#N)c(-c6ccccc6)c5)nc(-c5cccc6oc7ccccc7c56)n4)cc3)c([2H])c([2H])c([2H])c2c1[2H]]

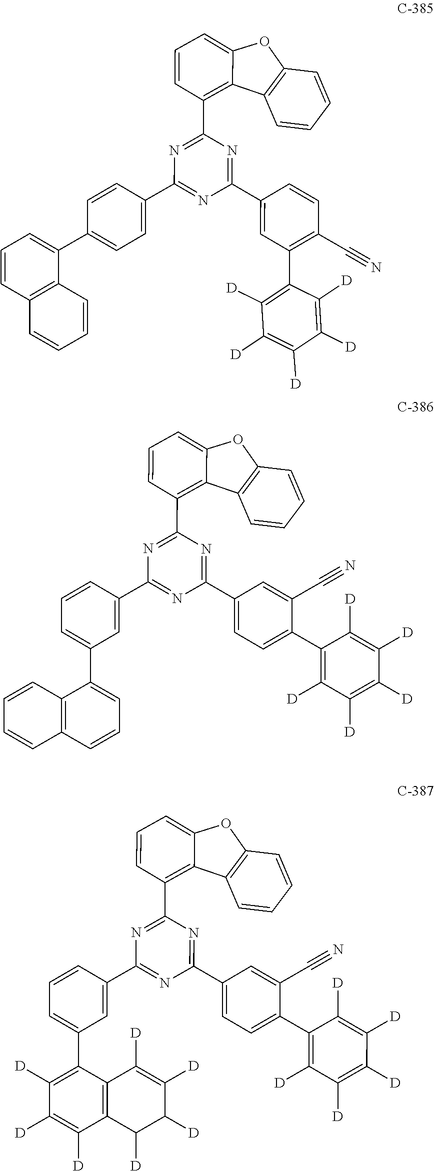 [SMILES: [2H]c1c([2H])c([2H])c(-c2cc(-c3nc(-c4ccc(-c5cccc6ccccc56)cc4)nc(-c4cccc5oc6ccccc6c45)n3)ccc2C#N)c([2H])c1[2H] ; [2H]c1c([2H])c([2H])c(-c2ccc(-c3nc(-c4cccc(-c5cccc6ccccc56)c4)nc(-c4cccc5oc6ccccc6c45)n3)cc2C#N)c([2H])c1[2H] ; [2H]C1=C([2H])C([2H])C([2H])c2c([2H])c([2H])c([2H])c(-c3cccc(-c4nc(-c5ccc(-c6c([2H])c([2H])c([2H])c([2H])c6[2H])c(C#N)c5)nc(-c5cccc6oc7ccccc7c56)n4)c3)c21]

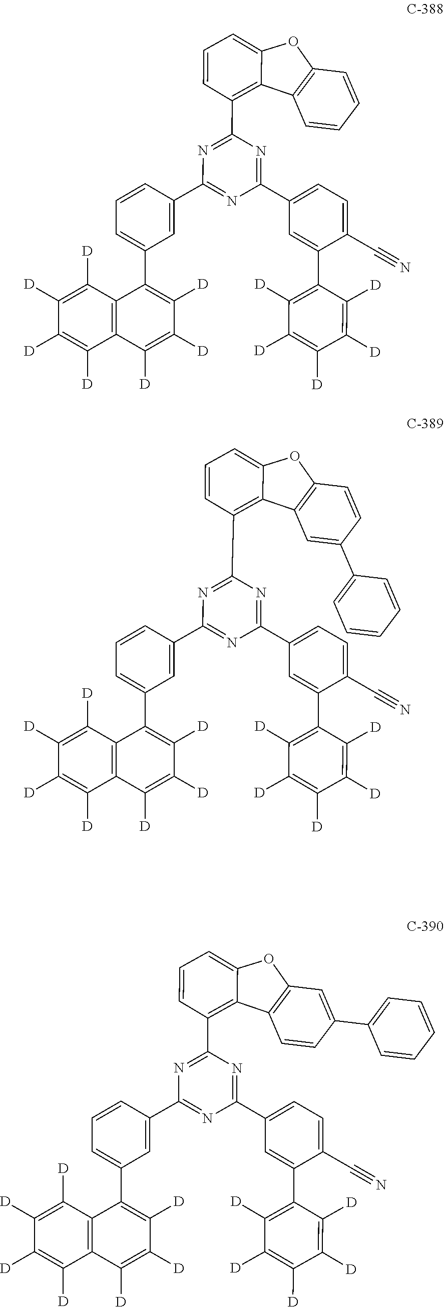 [SMILES: [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccccc6c45)n3)ccc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccc(-c7ccccc7)cc6c45)n3)ccc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6cc(-c7ccccc7)ccc6c45)n3)ccc2C#N)c([2H])c1[2H]]

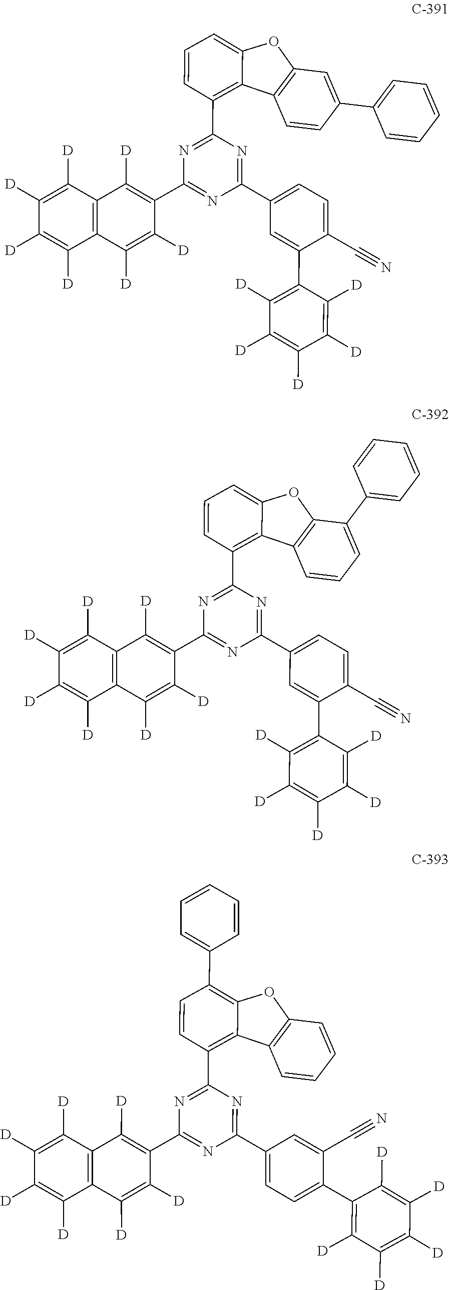 [SMILES: [2H]c1c([2H])c([2H])c(-c2cc(-c3nc(-c4c([2H])c([2H])c5c([2H])c([2H])c([2H])c([2H])c5c4[2H])nc(-c4cccc5oc6cc(-c7ccccc7)ccc6c45)n3)ccc2C#N)c([2H])c1[2H] ; [2H]c1c([2H])c([2H])c(-c2cc(-c3nc(-c4c([2H])c([2H])c5c([2H])c([2H])c([2H])c([2H])c5c4[2H])nc(-c4cccc5oc6c(-c7ccccc7)cccc6c45)n3)ccc2C#N)c([2H])c1[2H] ; [2H]c1c([2H])c([2H])c(-c2ccc(-c3nc(-c4c([2H])c([2H])c5c([2H])c([2H])c([2H])c([2H])c5c4[2H])nc(-c4ccc(-c5ccccc5)c5oc6ccccc6c45)n3)cc2C#N)c([2H])c1[2H]]

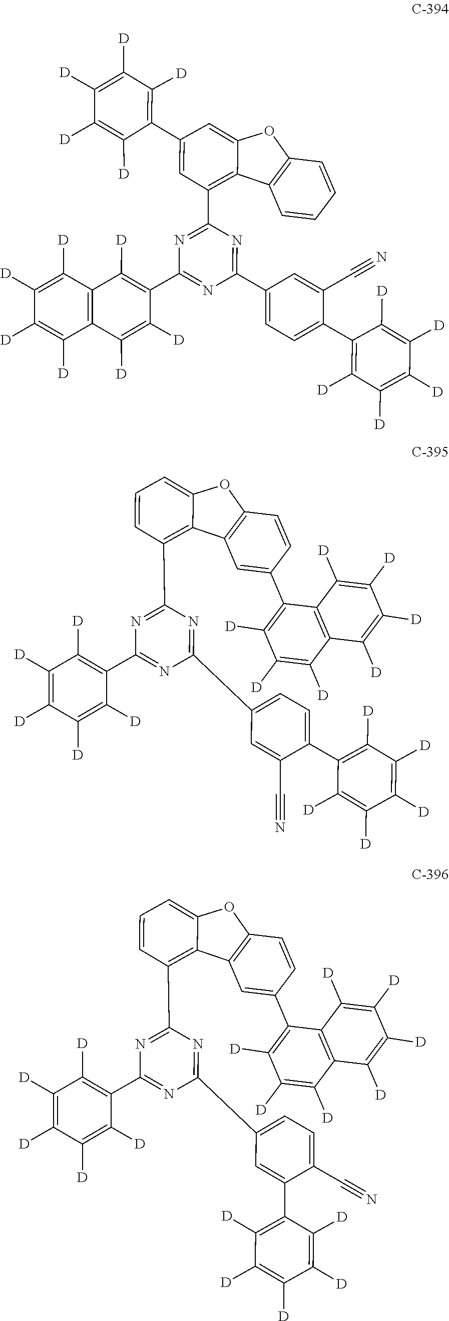

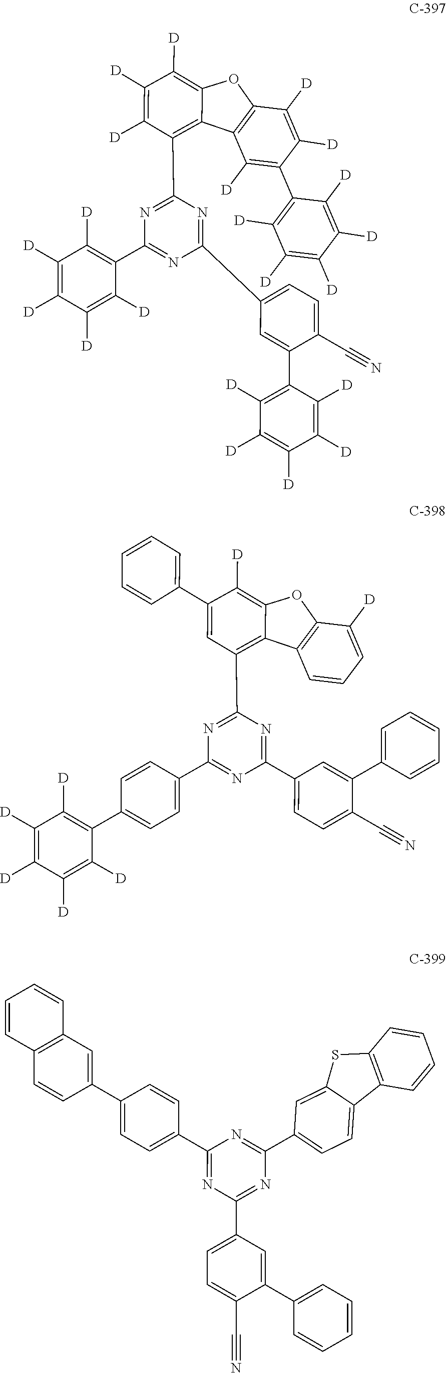 [SMILES: [2H]c1c([2H])c([2H])c(-c2nc(-c3ccc(C#N)c(-c4c([2H])c([2H])c([2H])c([2H])c4[2H])c3)nc(-c3c([2H])c([2H])c([2H])c4oc5c([2H])c([2H])c(-c6c([2H])c([2H])c([2H])c([2H])c6[2H])c([2H])c5c34)n2)c([2H])c1[2H] ; [2H]c1c([2H])c([2H])c(-c2ccc(-c3nc(-c4ccc(C#N)c(-c5ccccc5)c4)nc(-c4cc(-c5ccccc5)c([2H])c5oc6c([2H])cccc6c45)n3)cc2)c([2H])c1[2H] ; N#Cc1ccc(-c2nc(-c3ccc(-c4ccc5ccccc5c4)cc3)nc(-c3ccc4c(c3)sc3ccccc34)n2)cc1-c1ccccc1]

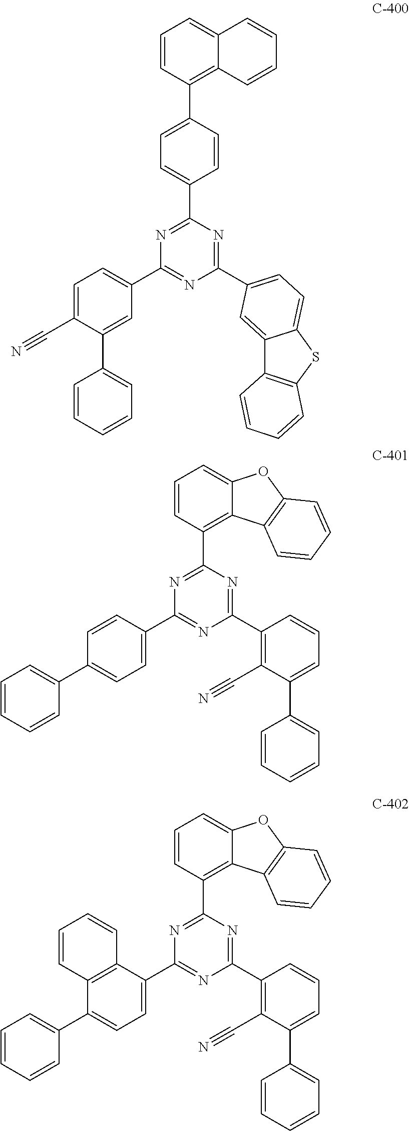

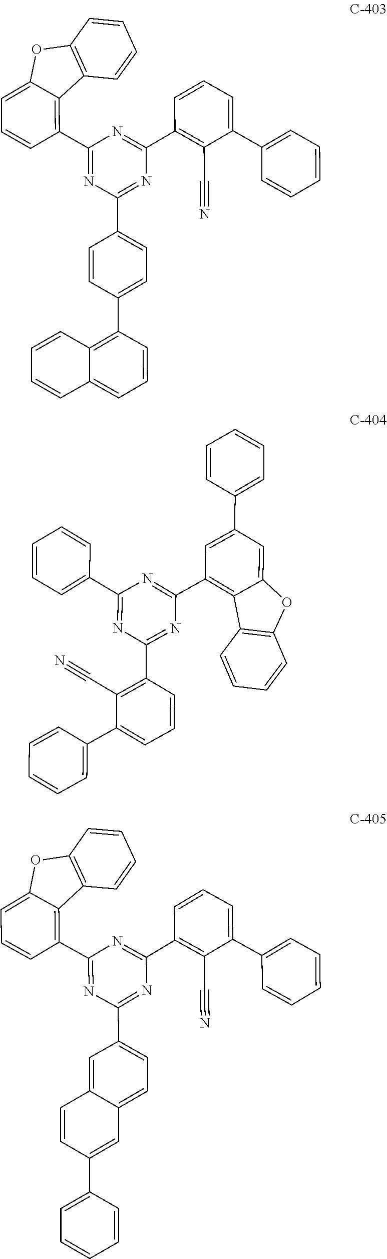

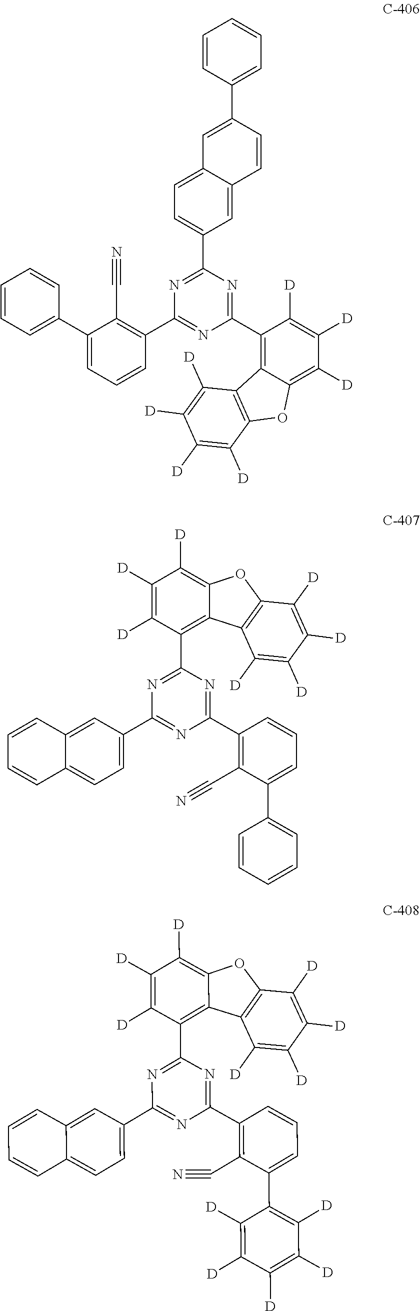 [SMILES: [2H]c1c([2H])c([2H])c2c(oc3c([2H])c([2H])c([2H])c(-c4nc(-c5ccc6cc(-c7ccccc7)ccc6c5)nc(-c5cccc(-c6ccccc6)c5C#N)n4)c32)c1[2H] ; [2H]c1c([2H])c([2H])c2c(oc3c([2H])c([2H])c([2H])c(-c4nc(-c5ccc6ccccc6c5)nc(-c5cccc(-c6ccccc6)c5C#N)n4)c32)c1[2H] ; [2H]c1c([2H])c([2H])c(-c2cccc(-c3nc(-c4ccc5ccccc5c4)nc(-c4c([2H])c([2H])c([2H])c5oc6c([2H])c([2H])c([2H])c([2H])c6c45)n3)c2C#N)c([2H])c1[2H]]

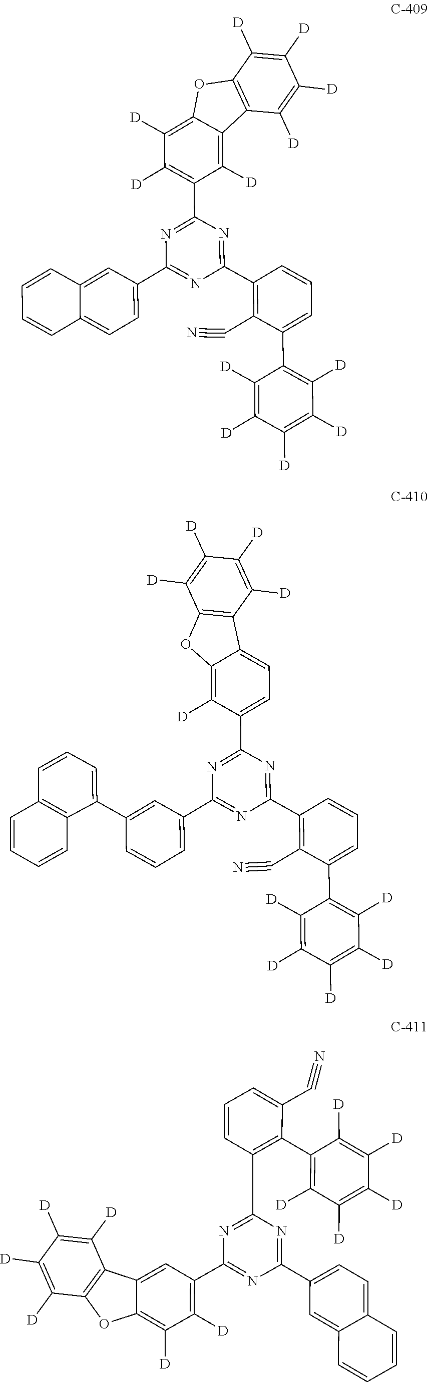 [SMILES: [2H]c1c([2H])c([2H])c(-c2cccc(-c3nc(-c4ccc5ccccc5c4)nc(-c4c([2H])c([2H])c5oc6c([2H])c([2H])c([2H])c([2H])c6c5c4[2H])n3)c2C#N)c([2H])c1[2H] ; [2H]c1c([2H])c([2H])c(-c2cccc(-c3nc(-c4cccc(-c5cccc6ccccc56)c4)nc(-c4ccc5c(oc6c([2H])c([2H])c([2H])c([2H])c65)c4[2H])n3)c2C#N)c([2H])c1[2H] ; [2H]c1c([2H])c([2H])c(-c2c(C#N)cccc2-c2nc(-c3ccc4ccccc4c3)nc(-c3cc4c(oc5c([2H])c([2H])c([2H])c([2H])c54)c([2H])c3[2H])n2)c([2H])c1[2H]]

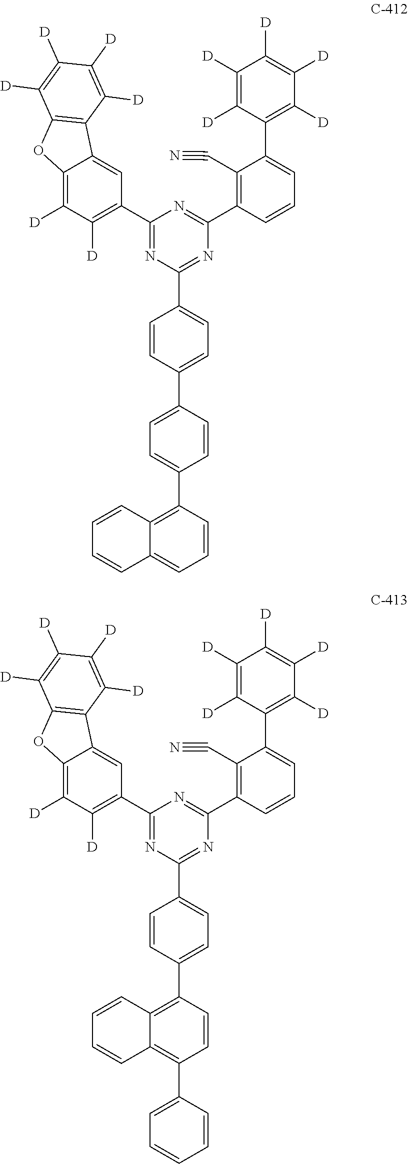 [SMILES: [2H]c1c([2H])c([2H])c(-c2cccc(-c3nc(-c4ccc(-c5ccc(-c6cccc7ccccc67)cc5)cc4)nc(-c4cc5c(oc6c([2H])c([2H])c([2H])c([2H])c65)c([2H])c4[2H])n3)c2C#N)c([2H])c1[2H] ; [2H]c1c([2H])c([2H])c(-c2cccc(-c3nc(-c4ccc(-c5ccc(-c6ccccc6)c6ccccc56)cc4)nc(-c4cc5c(oc6c([2H])c([2H])c([2H])c([2H])c65)c([2H])c4[2H])n3)c2C#N)c([2H])c1[2H]]

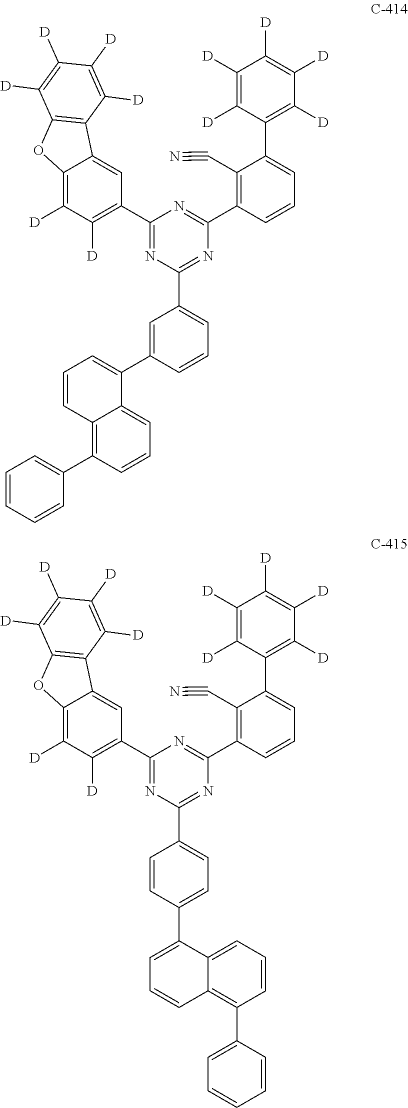

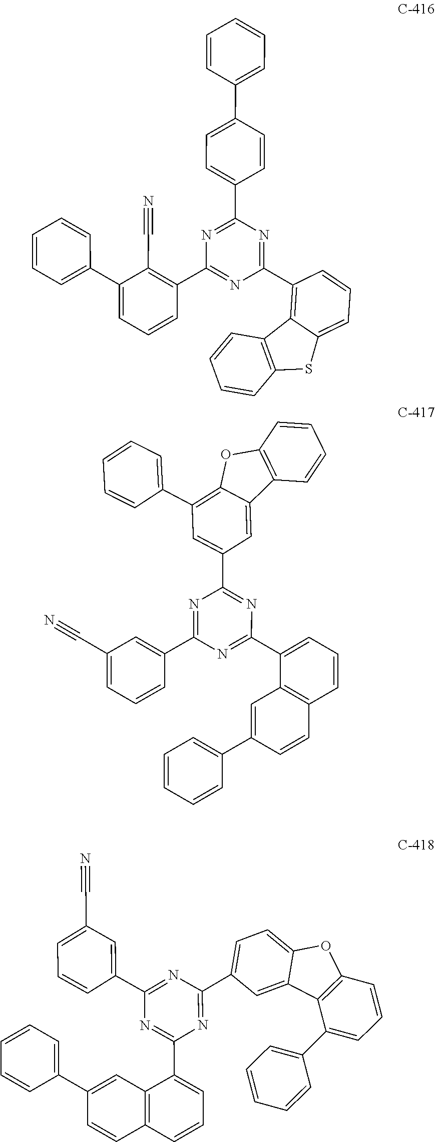

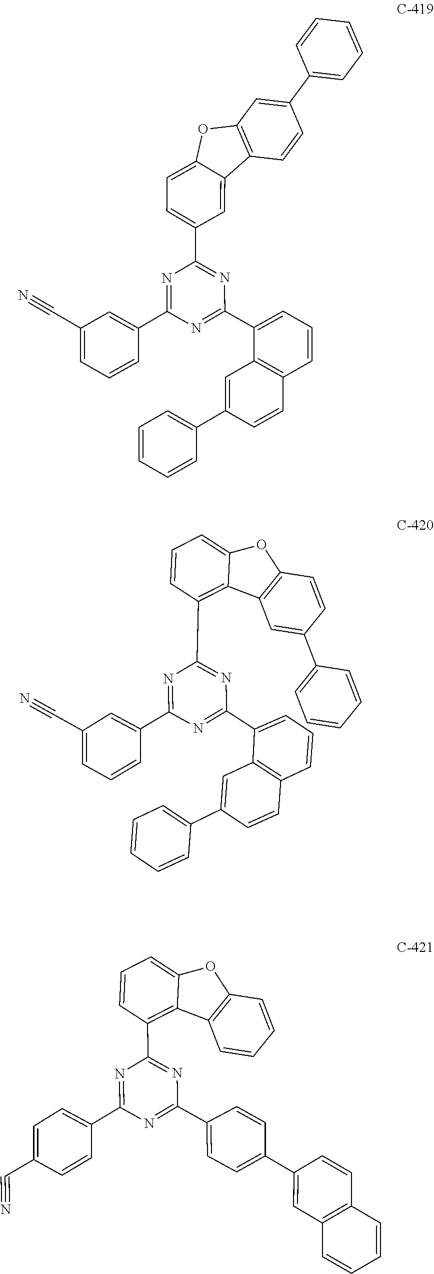 [SMILES: N#Cc1cccc(-c2nc(-c3ccc4oc5cc(-c6ccccc6)ccc5c4c3)nc(-c3cccc4ccc(-c5ccccc5)cc34)n2)c1 ; N#Cc1cccc(-c2nc(-c3cccc4ccc(-c5ccccc5)cc34)nc(-c3cccc4oc5ccc(-c6ccccc6)cc5c34)n2)c1 ; N#Cc1ccc(-c2nc(-c3ccc(-c4ccc5ccccc5c4)cc3)nc(-c3cccc4oc5ccccc5c34)n2)cc1]

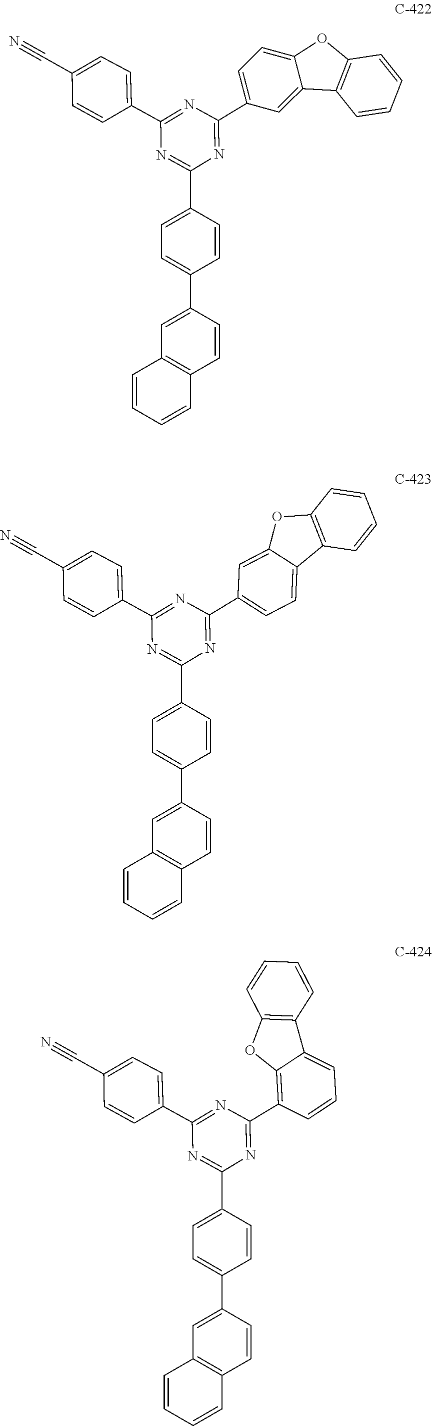 [SMILES: N#Cc1ccc(-c2nc(-c3ccc(-c4ccc5ccccc5c4)cc3)nc(-c3ccc4oc5ccccc5c4c3)n2)cc1 ; N#Cc1ccc(-c2nc(-c3ccc(-c4ccc5ccccc5c4)cc3)nc(-c3ccc4c(c3)oc3ccccc34)n2)cc1 ; N#Cc1ccc(-c2nc(-c3ccc(-c4ccc5ccccc5c4)cc3)nc(-c3cccc4c3oc3ccccc34)n2)cc1]

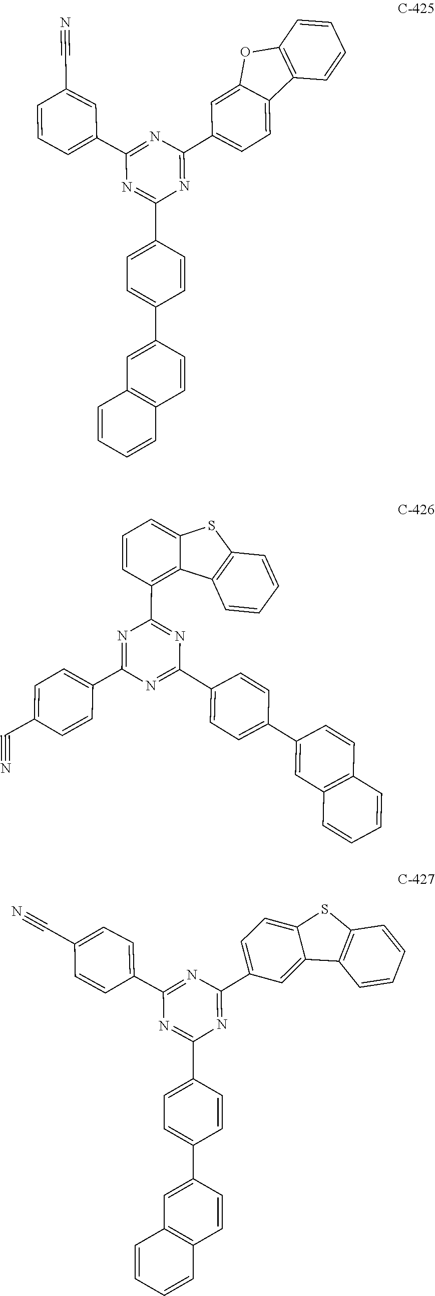 [SMILES: N#Cc1cccc(-c2nc(-c3ccc(-c4ccc5ccccc5c4)cc3)nc(-c3ccc4c(c3)oc3ccccc34)n2)c1 ; N#Cc1ccc(-c2nc(-c3ccc(-c4ccc5ccccc5c4)cc3)nc(-c3cccc4sc5ccccc5c34)n2)cc1 ; N#Cc1ccc(-c2nc(-c3ccc(-c4ccc5ccccc5c4)cc3)nc(-c3ccc4sc5ccccc5c4c3)n2)cc1]

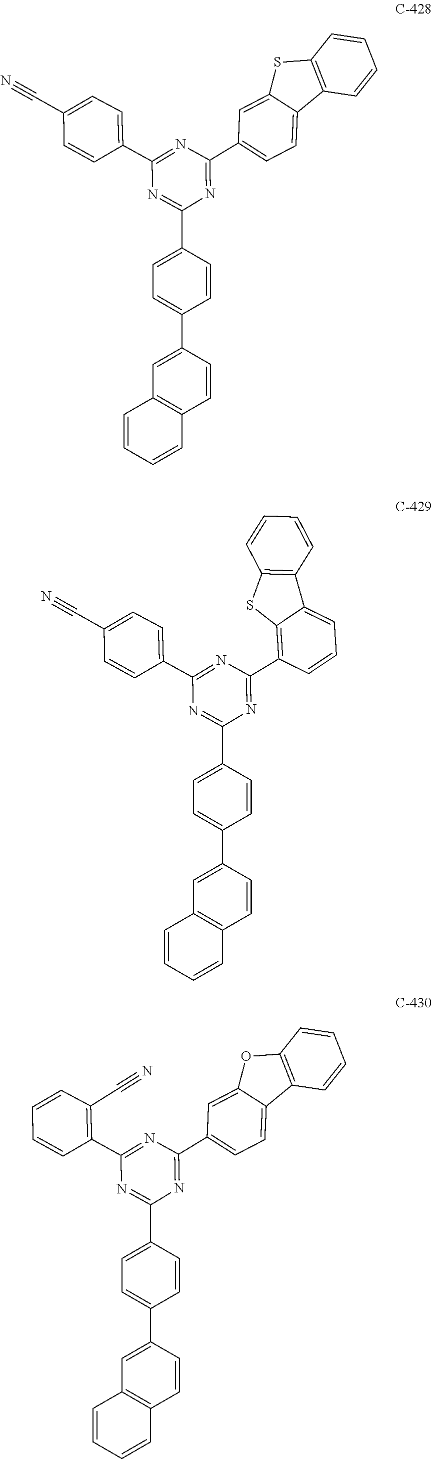 [SMILES: N#Cc1ccc(-c2nc(-c3ccc(-c4ccc5ccccc5c4)cc3)nc(-c3ccc4c(c3)sc3ccccc34)n2)cc1 ; N#Cc1ccc(-c2nc(-c3ccc(-c4ccc5ccccc5c4)cc3)nc(-c3cccc4c3sc3ccccc34)n2)cc1 ; N#Cc1ccccc1-c1nc(-c2ccc(-c3ccc4ccccc4c3)cc2)nc(-c2ccc3c(c2)oc2ccccc23)n1]

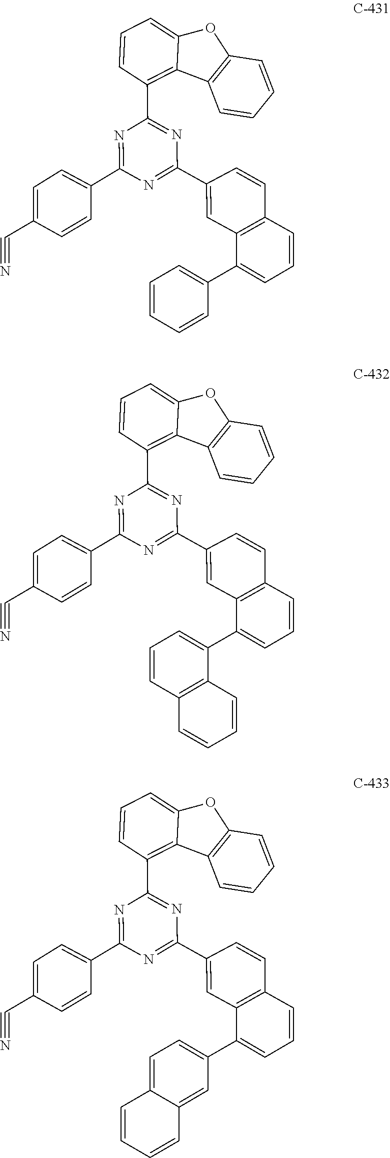 [SMILES: N#Cc1ccc(-c2nc(-c3ccc4cccc(-c5ccccc5)c4c3)nc(-c3cccc4oc5ccccc5c34)n2)cc1 ; N#Cc1ccc(-c2nc(-c3ccc4cccc(-c5cccc6ccccc56)c4c3)nc(-c3cccc4oc5ccccc5c34)n2)cc1 ; N#Cc1ccc(-c2nc(-c3ccc4cccc(-c5ccc6ccccc6c5)c4c3)nc(-c3cccc4oc5ccccc5c34)n2)cc1]

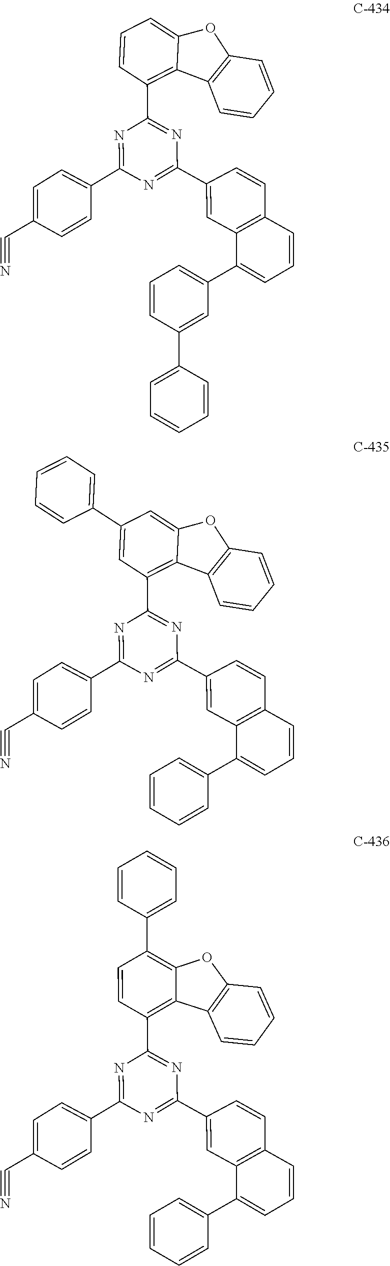

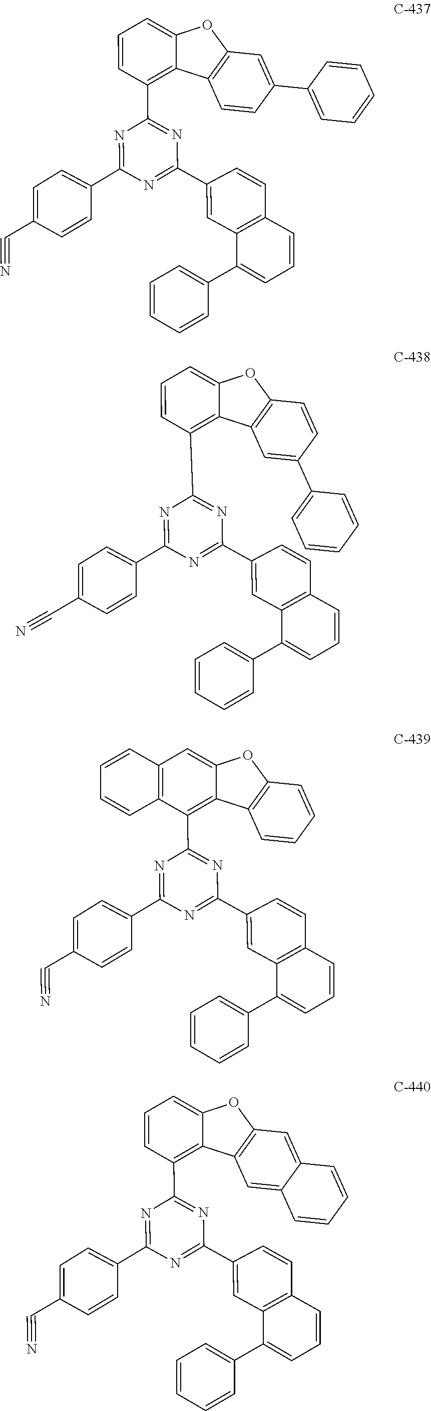

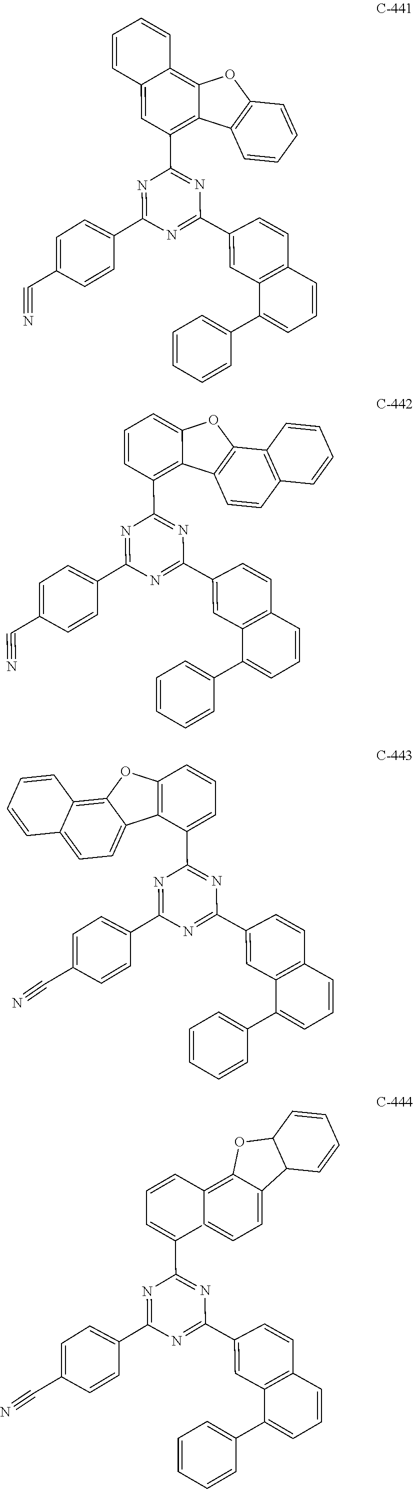

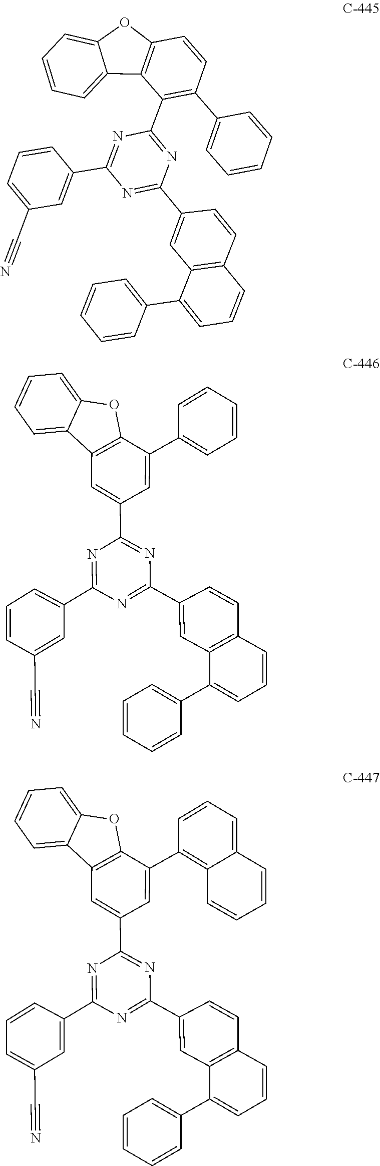 [SMILES: N#Cc1cccc(-c2nc(-c3ccc4cccc(-c5ccccc5)c4c3)nc(-c3c(-c4ccccc4)ccc4oc5ccccc5c34)n2)c1 ; N#Cc1cccc(-c2nc(-c3ccc4cccc(-c5ccccc5)c4c3)nc(-c3cc(-c4ccccc4)c4oc5ccccc5c4c3)n2)c1 ; N#Cc1cccc(-c2nc(-c3ccc4cccc(-c5ccccc5)c4c3)nc(-c3cc(-c4cccc5ccccc45)c4oc5ccccc5c4c3)n2)c1]

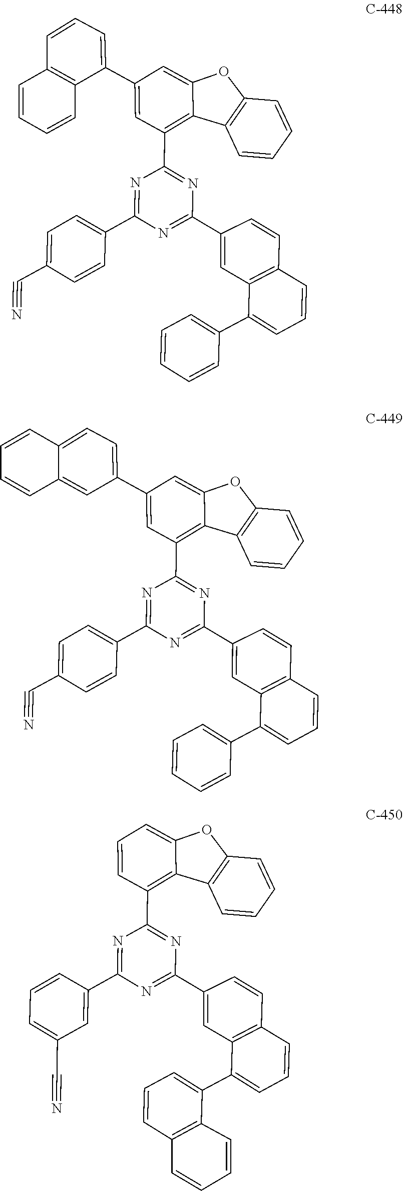

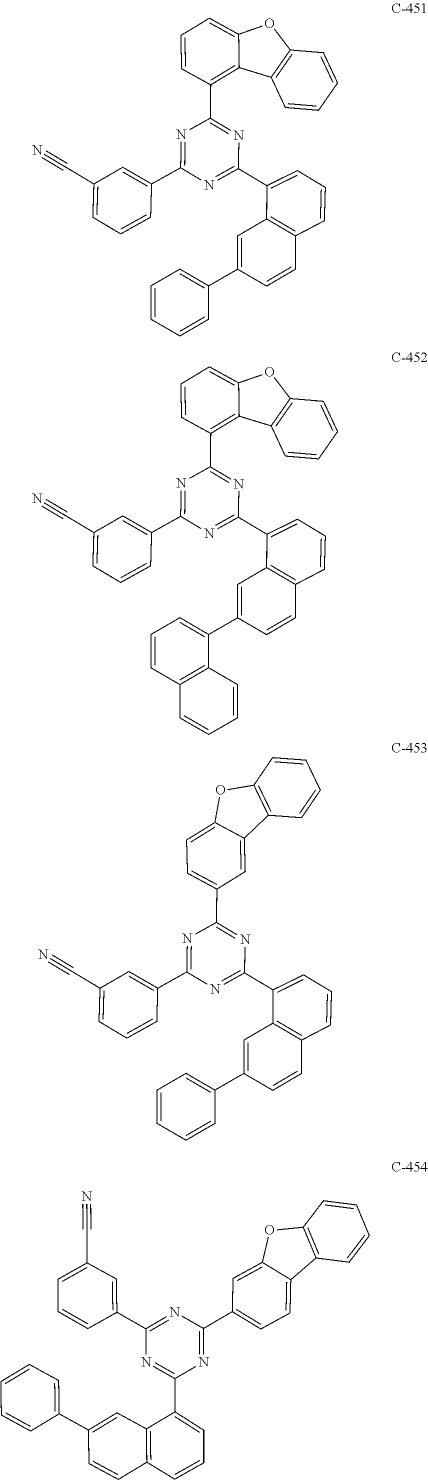

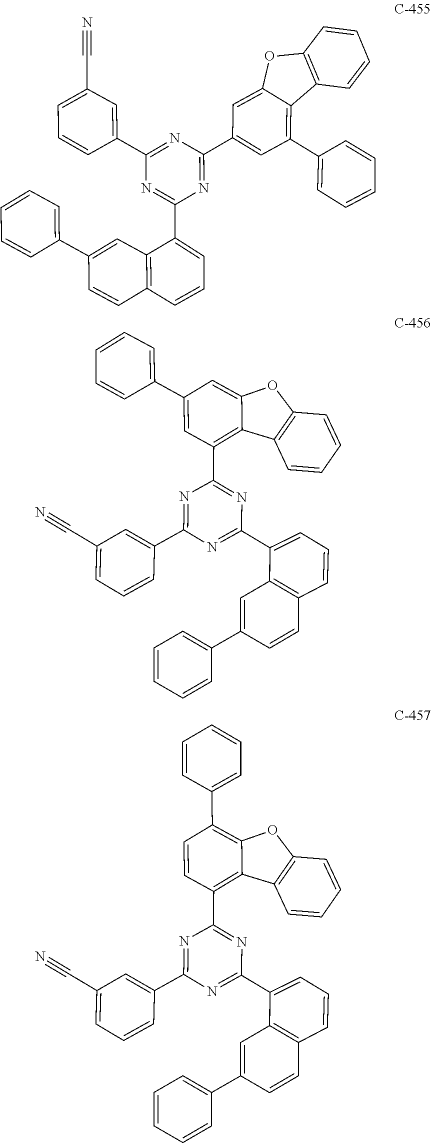

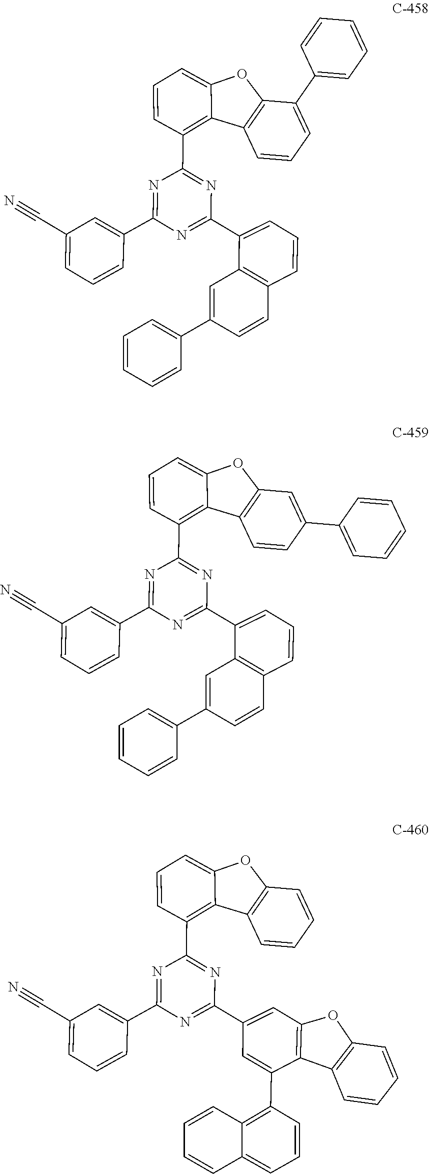 [SMILES: N#Cc1cccc(-c2nc(-c3cccc4ccc(-c5ccccc5)cc34)nc(-c3cccc4oc5c(-c6ccccc6)cccc5c34)n2)c1 ; N#Cc1cccc(-c2nc(-c3cccc4ccc(-c5ccccc5)cc34)nc(-c3cccc4oc5cc(-c6ccccc6)ccc5c34)n2)c1 ; N#Cc1cccc(-c2nc(-c3cc(-c4cccc5ccccc45)c4c(c3)oc3ccccc34)nc(-c3cccc4oc5ccccc5c34)n2)c1]

In the compounds above, Dₙ represents that n number of hydrogens are replaced with deuterium, and n represents an integer of 1 or more, which is an integer of 1 to the maximum number of hydrogens in the compound.

The compounds represented by Formulas 1 to 3 according to the present disclosure may be produced by synthetic methods known to one skilled in the art. For example, the compounds of the present disclosure may be synthesized by referring to the Korean Patent Application Laid-Open Nos. 10-2022-0161620 (Dec. 7, 2022), 10-2023-0057737 (May 2, 2023), and 10-2023-0157860 (Nov. 17, 2023), but are not limited thereto. In addition, the compounds represented by Formula 3 according to the present disclosure may be produced as shown in the following reaction schemes, but are not limited thereto.

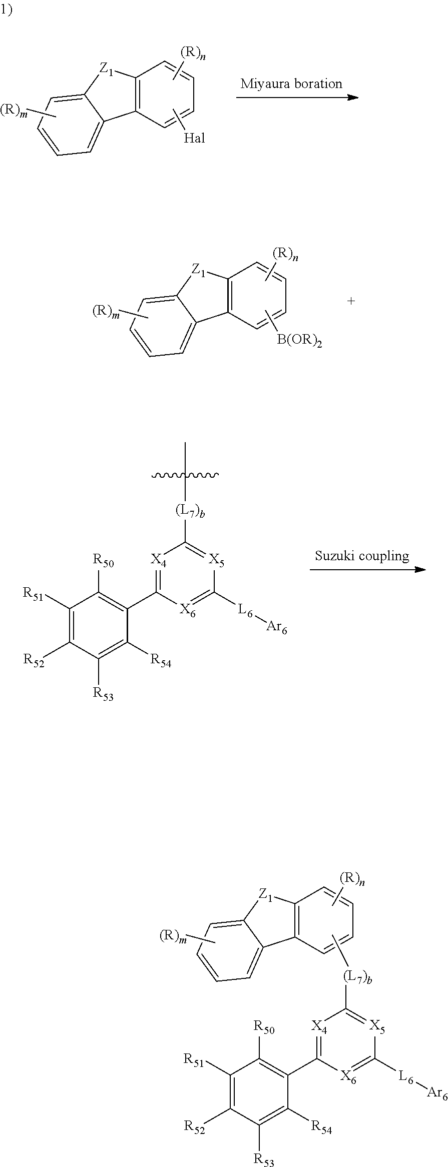

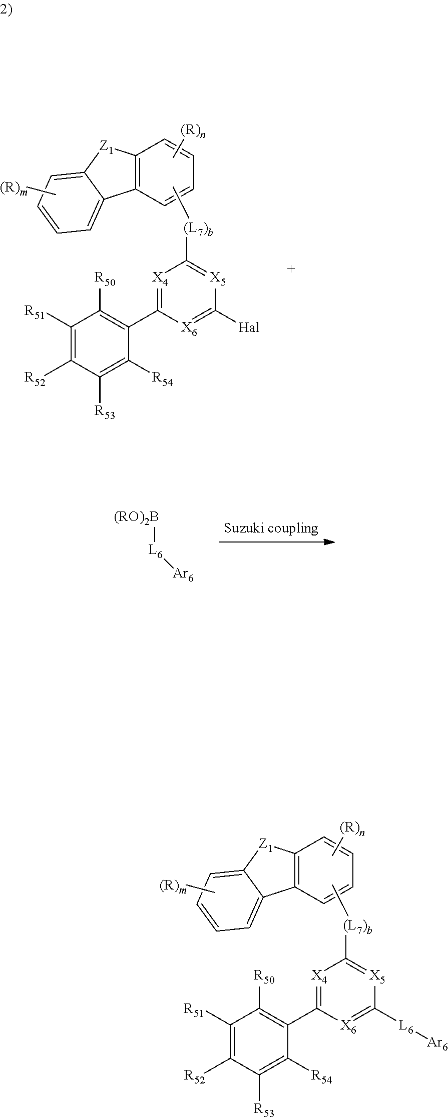

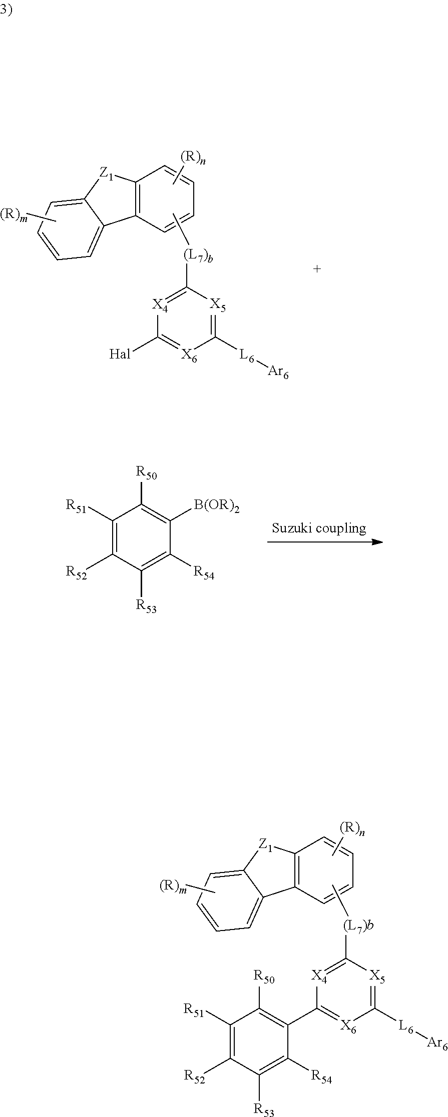

In the above reaction schemes, Z₁, X₄ to X₆, Are, and R₅₀ to R₅₄ have the same definitions as in Formula 3, R has the same definition as R₄₁ to R₄₈ in Formula 3, Hal means a halogen, m is an integer of 1 to 4, n is an integer of 1 to 3, and when m and n are integers of 2 or more, each R may be the same as or different from each other.

The present disclosure provides an organic electroluminescent device comprising a first electrode; a second electrode; and at least one light-emitting layer disposed between the first electrode and the second electrode, wherein the at least one light-emitting layer comprises the plurality of host materials according to the present disclosure.

An organic electroluminescent device according to one embodiment of the present disclosure comprises a first electrode; a second electrode; and one or more of organic layers positioned between the first electrode and the second electrode, wherein the organic layers comprise a hole injection layer, a hole transport layer, a light-emitting layer, a hole auxiliary layer, an electron transport layer, an electron-blocking layer, an electron injection layer, and an emission auxiliary layer. According to one example, the light-emitting layer may comprise an organic electroluminescent compound represented by Formula 3.

One of the first and second electrodes may be an anode, and the other may be a cathode. In this case, each of the first electrode and the second electrode may be formed of a transparent conductive material or a transflective or reflective conductive material. Depending on the type of material forming the first electrode and the second electrode, the organic electroluminescent device may be a top light-emitting type, a bottom light-emitting type, or a double side light-emitting type.

The light-emitting layer comprises at least one host and at least one dopant. The dopant comprised in the organic electroluminescent device of the present disclosure may be at least one phosphorescent or fluorescent dopant, and is preferably a fluorescent dopant.

The dopant comprised in the organic electroluminescent device of the present disclosure may be a compound represented by the following Formula 101 or 102, but is not limited thereto.

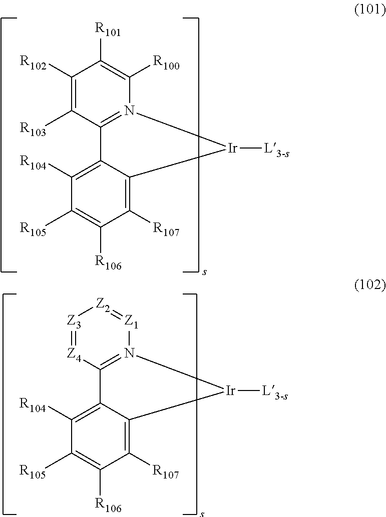

In Formulas 101 and 102,
L′ is any one selected from the following Structures 1 to 3:

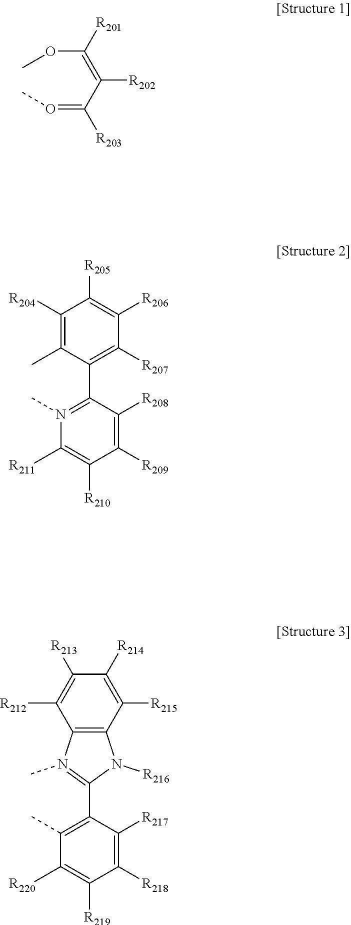

R₁₀₀ to R₁₀₃ each independently represent hydrogen, deuterium, a halogen, a (C₁-C₃₀)alkyl unsubstituted or substituted with deuterium and/or a halogen(s), a substituted or unsubstituted (C₃-C₃₀)cycloalkyl, a substituted or unsubstituted (C₆-C₃₀)aryl, a cyano, a substituted or unsubstituted (3- to 30-membered)heteroaryl, or a substituted or unsubstituted (C₁-C₃₀)alkoxy; or may be linked to an adjacent substituent(s) to form a ring(s), for example, to form a ring(s) with a pyridine, e.g., a substituted or unsubstituted quinoline, a substituted or unsubstituted isoquinoline, a substituted or unsubstituted thienopyridine, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;
R₁₀₄ to R₁₀₇ each independently represent, hydrogen, deuterium, halogen, deuterium- and/or halogen-substituted or unsubstituted (C₁-C₃₀)alkyl, a substituted or unsubstituted (C₃-C₃₀)cycloalkyl, a substituted or unsubstituted (C₃-C₃₀)aryl, a substituted or unsubstituted (3- to 30-membered)heteroaryl, cyano, a substituted or unsubstituted (C₁-C₃₀)alkoxy, or a substituted or unsubstituted di(C₁-C₃₀)alkylamino; or may be linked to an adjacent substituent(s) to form a ring(s), for example, to form a ring(s) with a benzene, e.g., a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;
R₂₀₁ to R₂₂₀ each independently represent, hydrogen, deuterium, halogen, deuterium- and/or halogen-substituted or unsubstituted (C₁-C₃₀)alkyl, a substituted or unsubstituted (C₃-C₃₀)cycloalkyl, a substituted or unsubstituted (C₆-C₃₀)aryl, a substituted or unsubstituted (C₁-C₃₀)alkoxy, or a substituted or unsubstituted di(C₁-C₃₀)alkylamino; or may be linked to an adjacent substituent(s) to form a ring(s); for example, to form a substituted or unsubstituted benzene, a substituted or unsubstituted fluorene, a substituted or unsubstituted benzofuran, a substituted or unsubstituted benzothiophene, a substituted or unsubstituted dibenzofuran, a substituted or unsubstituted dibenzothiophene, a substituted or unsubstituted furopyridine, or a substituted or unsubstituted thiophene;
Z₁ to Z₄ each independently represent N or CK₁;
K₁ each independently represent hydrogen, deuterium, halogen, deuterium- and/or halogen-substituted or unsubstituted (C₁-C₃₀)alkyl, a substituted or unsubstituted (C₃-C₃₀)cycloalkyl, a substituted or unsubstituted (C₆-C₃₀)aryl, cyano, a substituted or unsubstituted (3- to 30-membered)heteroaryl, or a substituted or unsubstituted (C₁-C₃₀)alkoxy; or may be linked to an adjacent substituent(s) to form a ring(s); for example, to form a substituted or unsubstituted benzene, a substituted or unsubstituted naphthalene, a substituted or unsubstituted thiophene, a substituted or unsubstituted benzothiophene, a substituted or unsubstituted fluorene, a substituted or unsubstituted dibenzofuran, or a substituted or unsubstituted dibenzothiophene; and
s represents an integer of 1 to 3.

Specifically, the specific examples of the dopant compound include the following, but are not limited thereto.

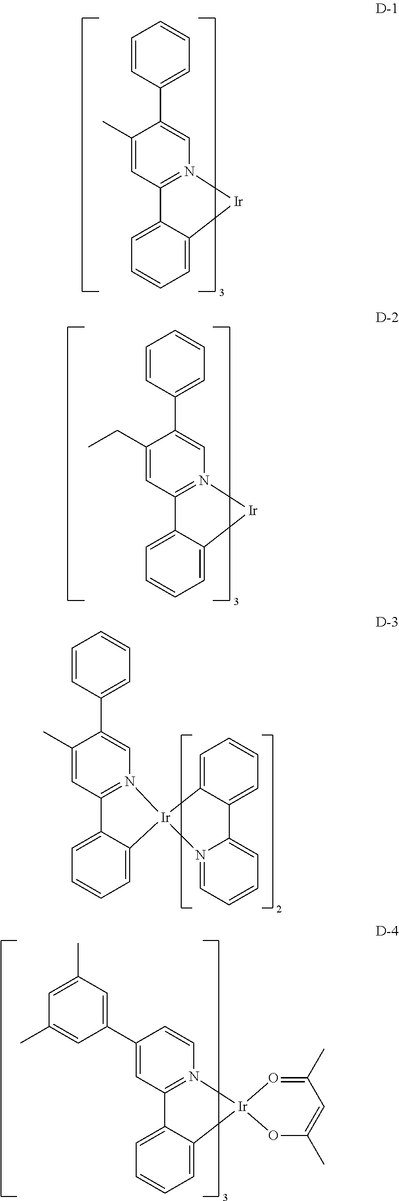

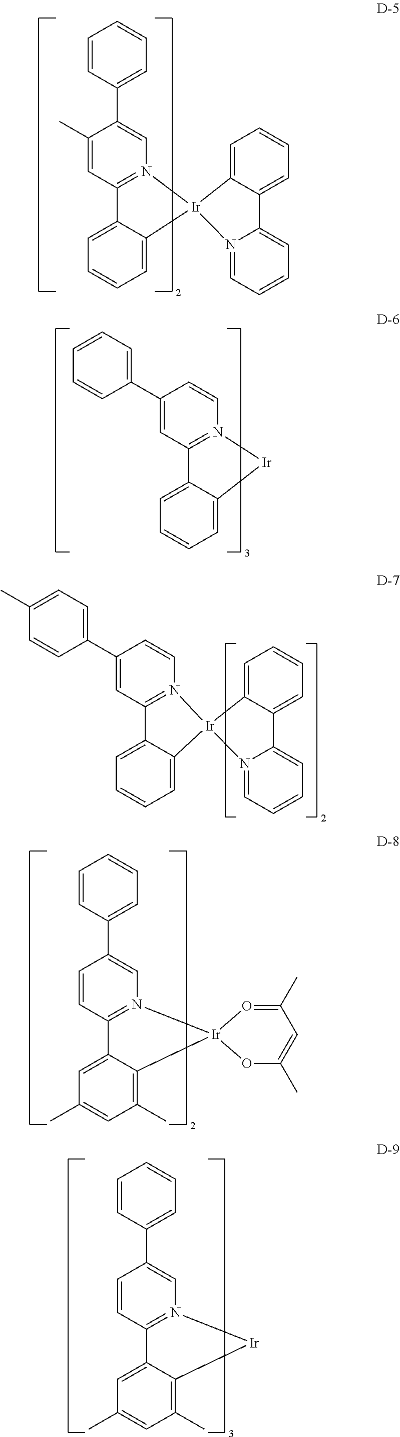

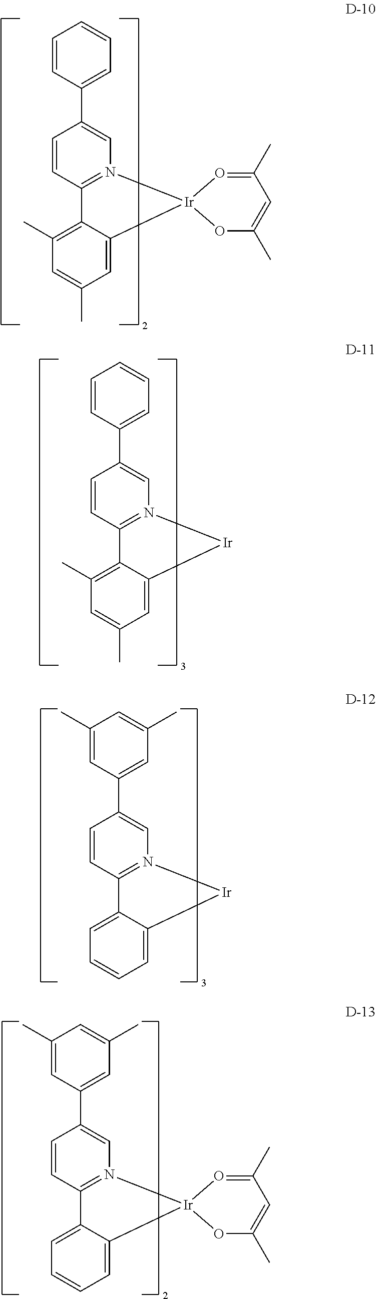

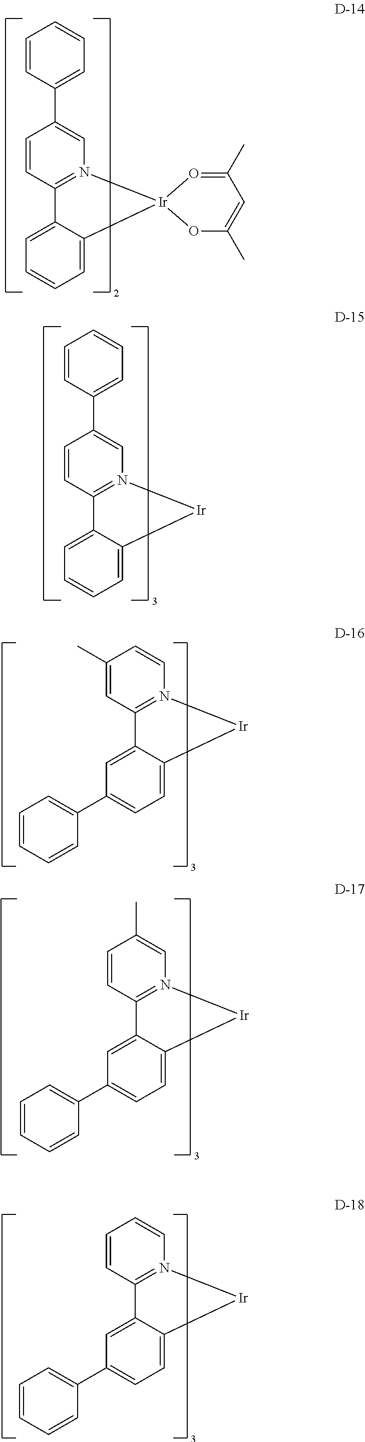

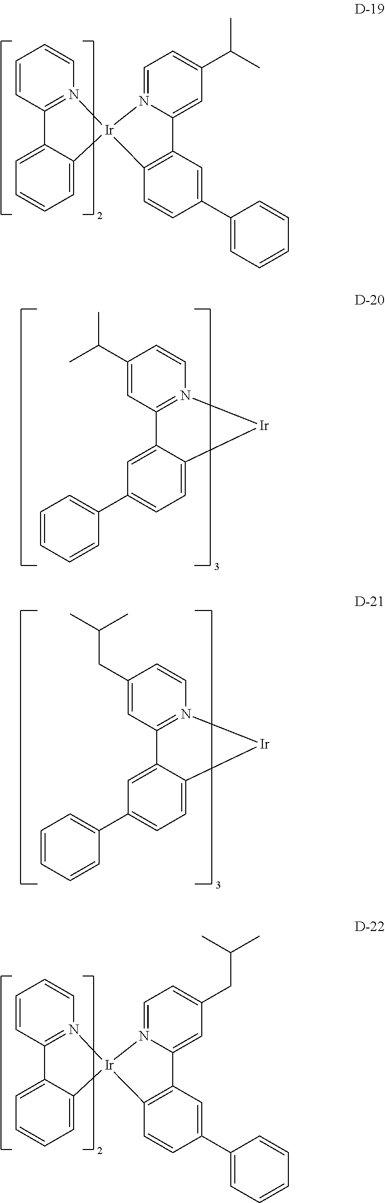

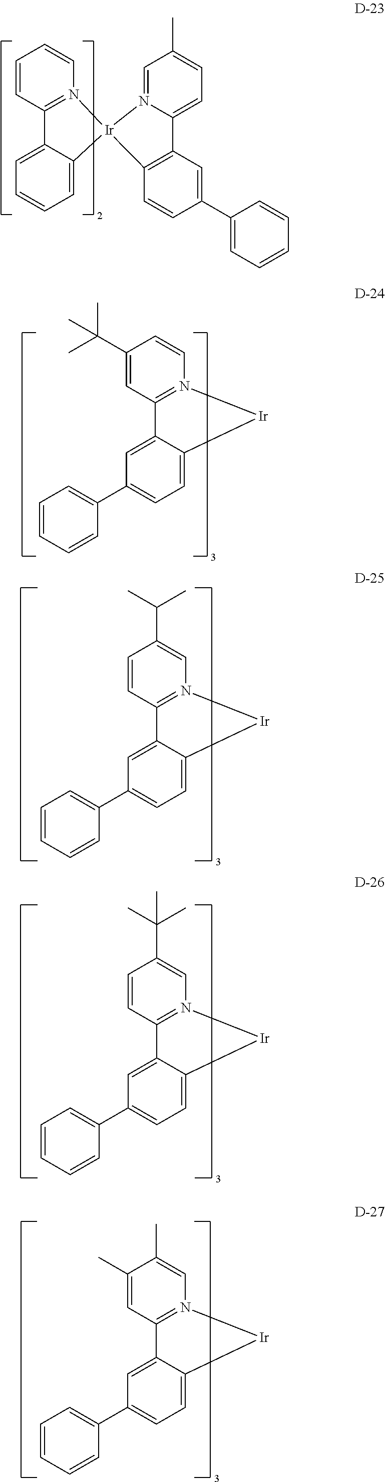

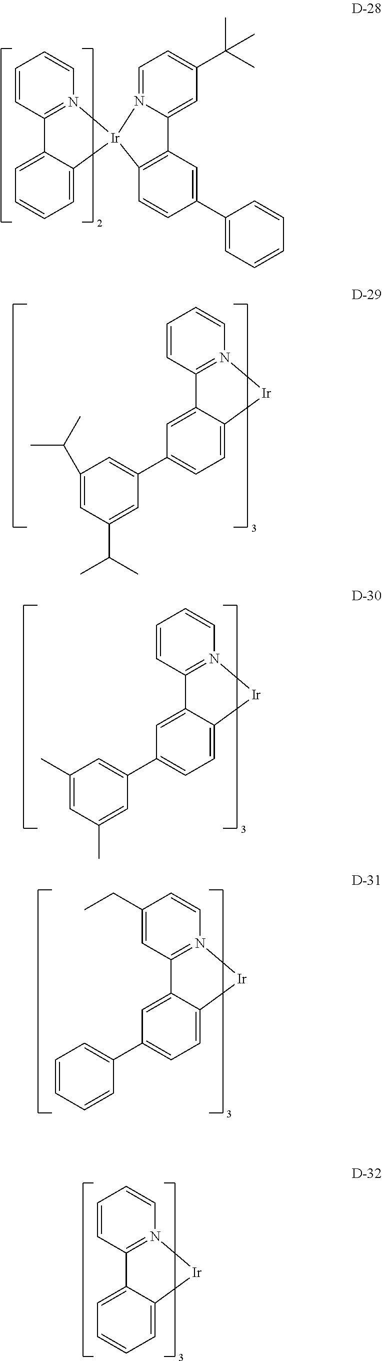

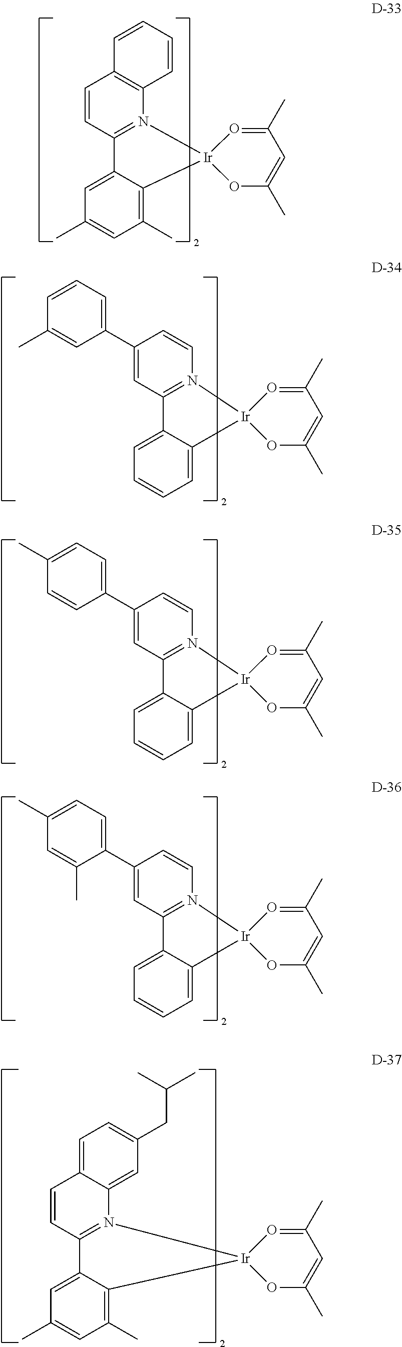

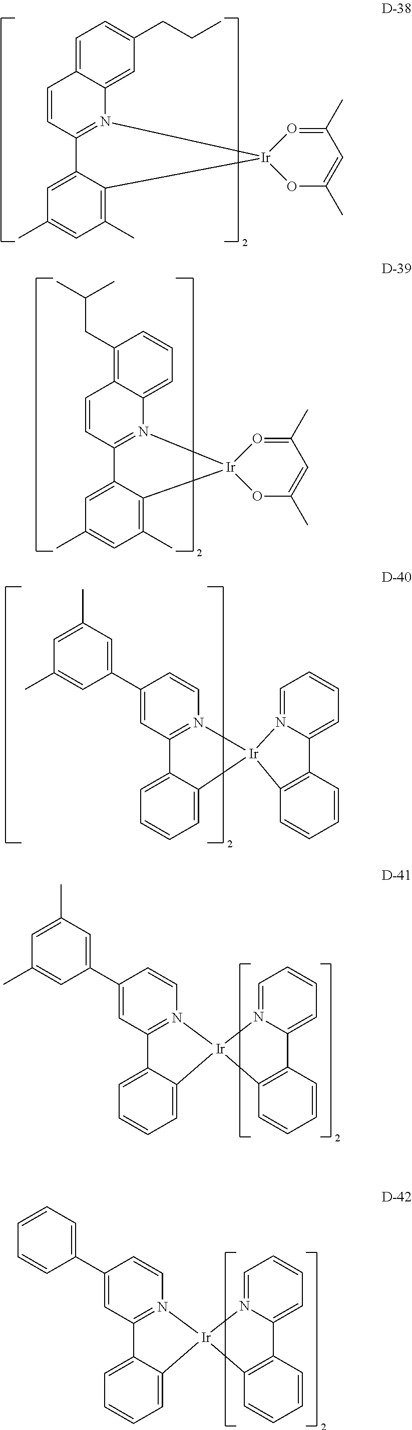

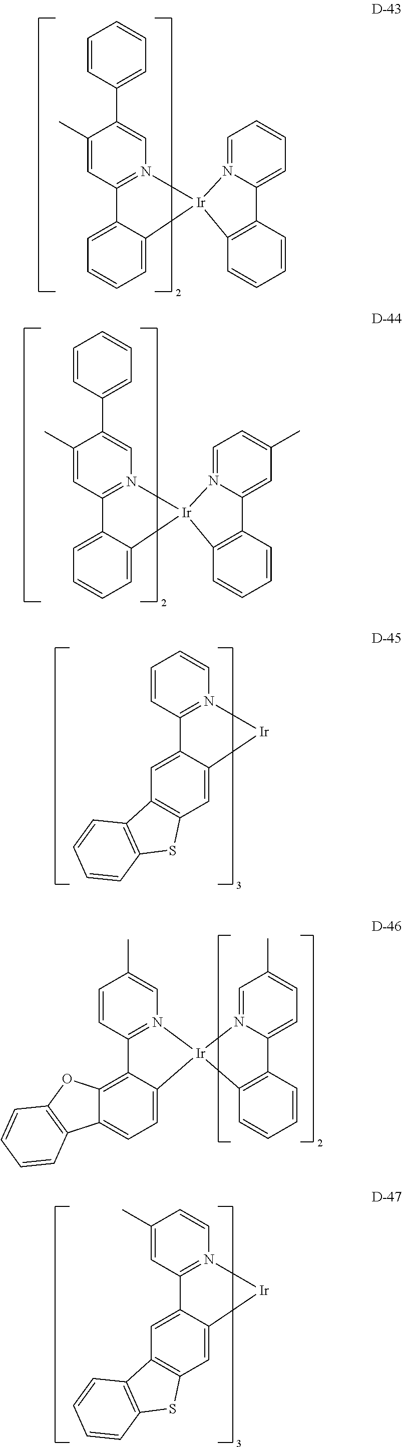

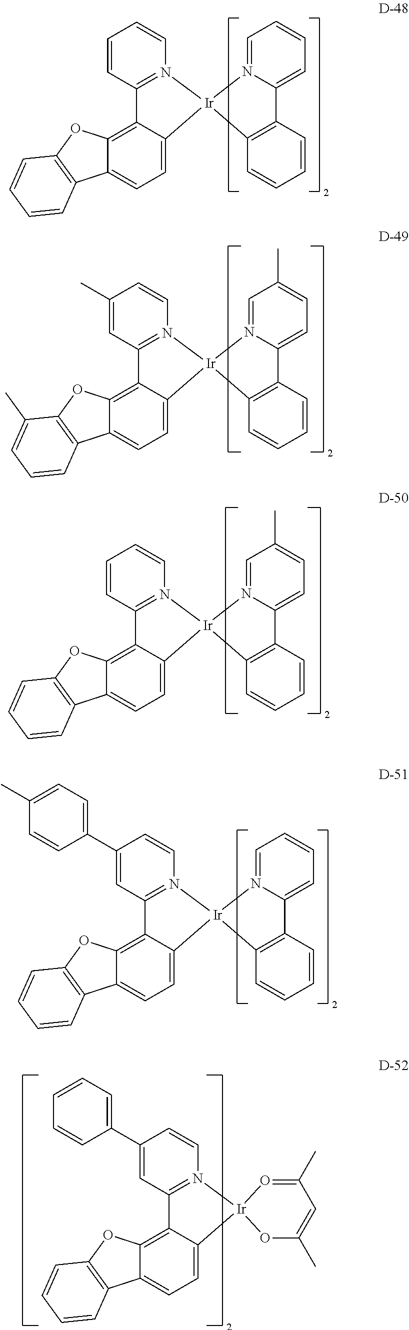

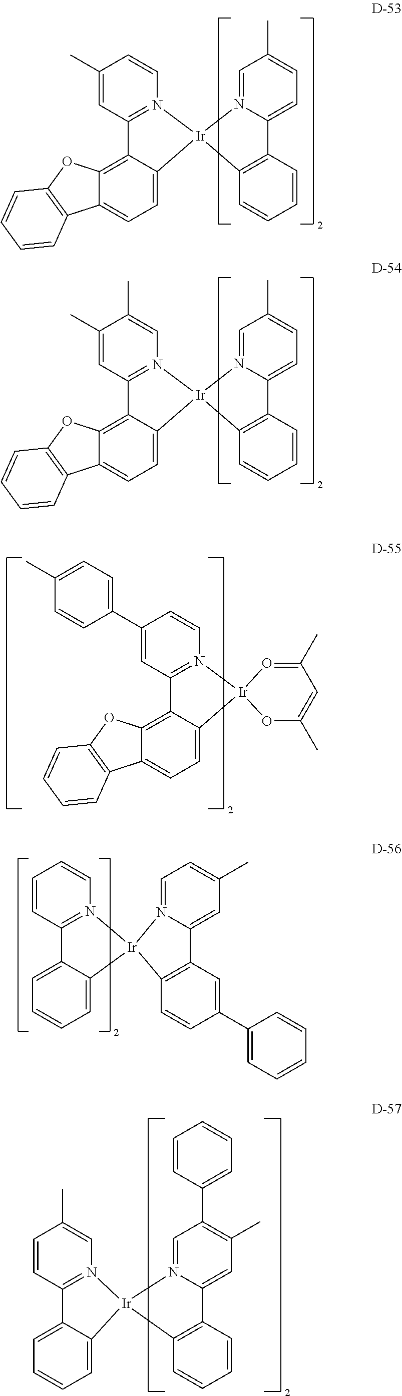

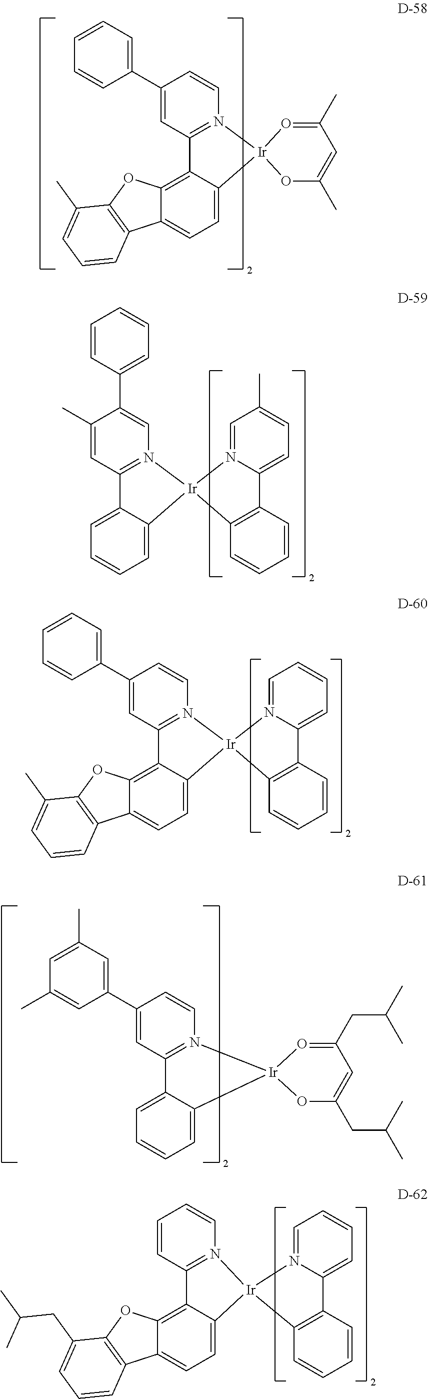

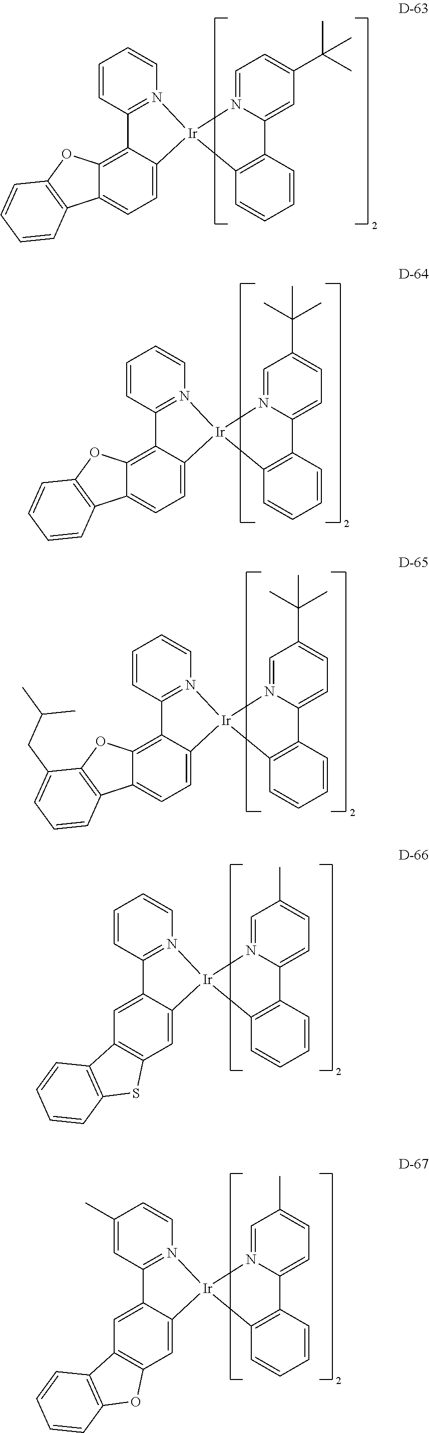

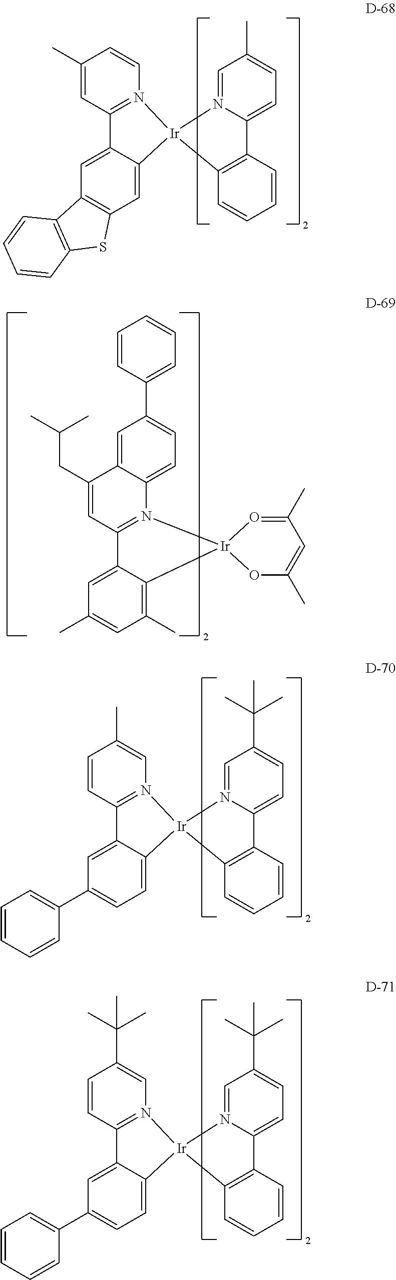

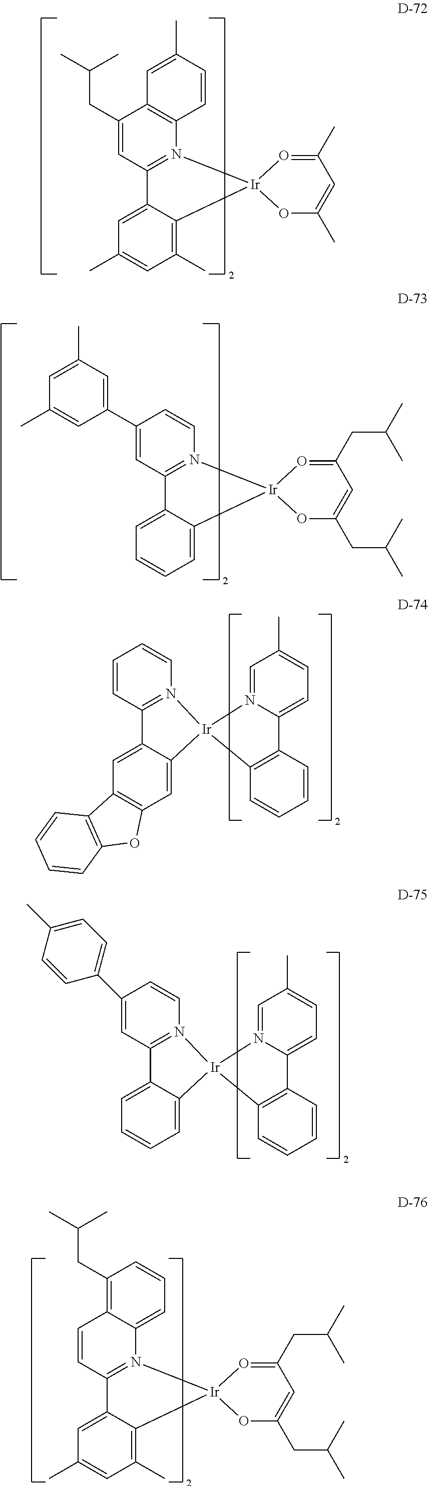

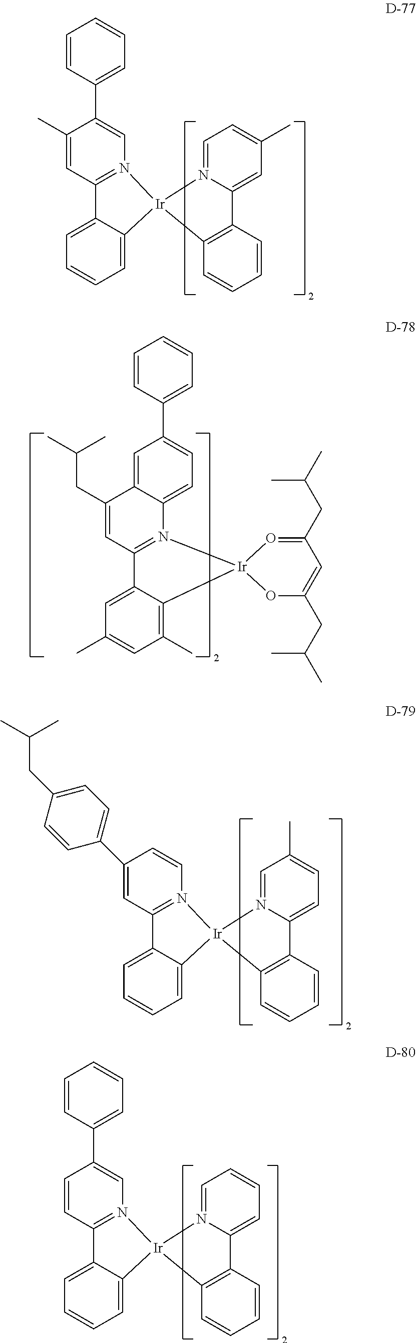

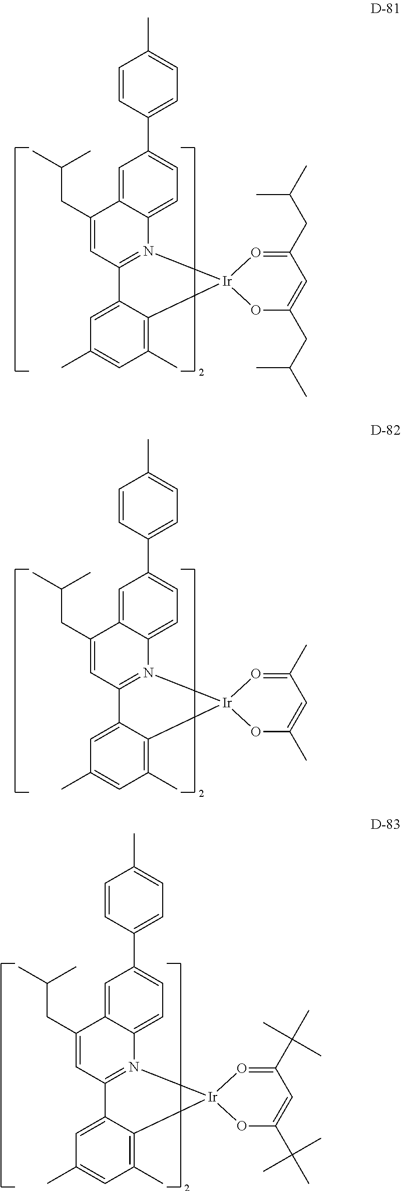

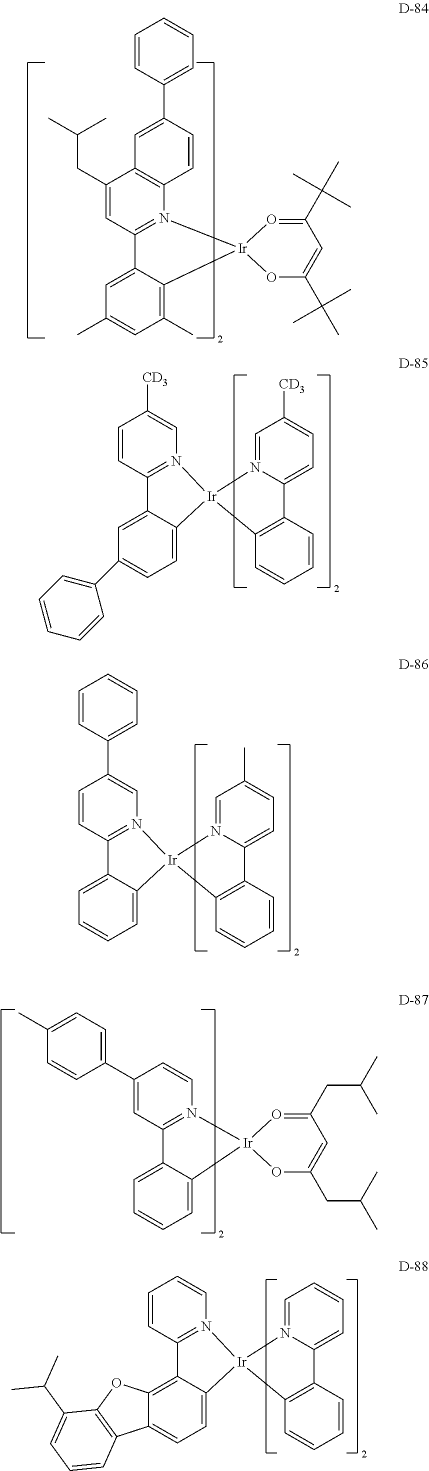

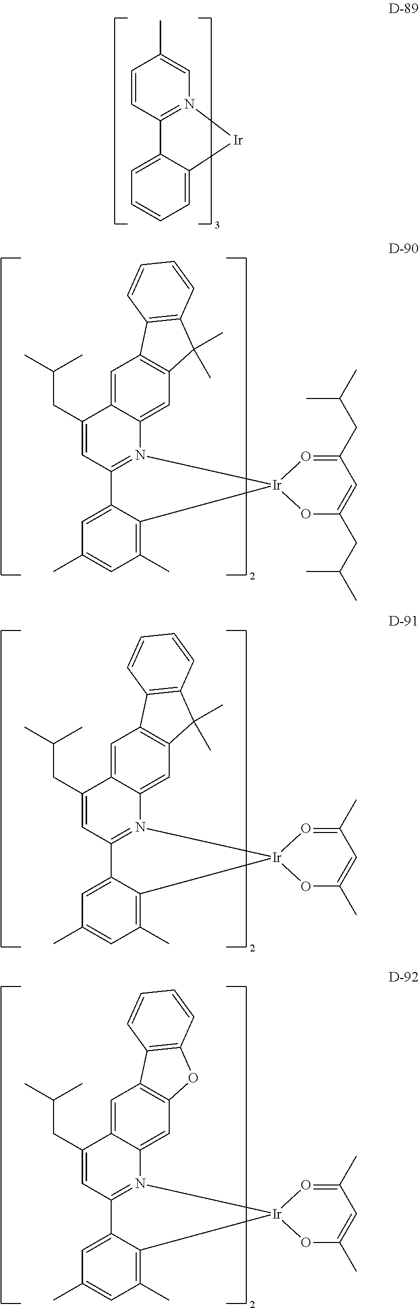

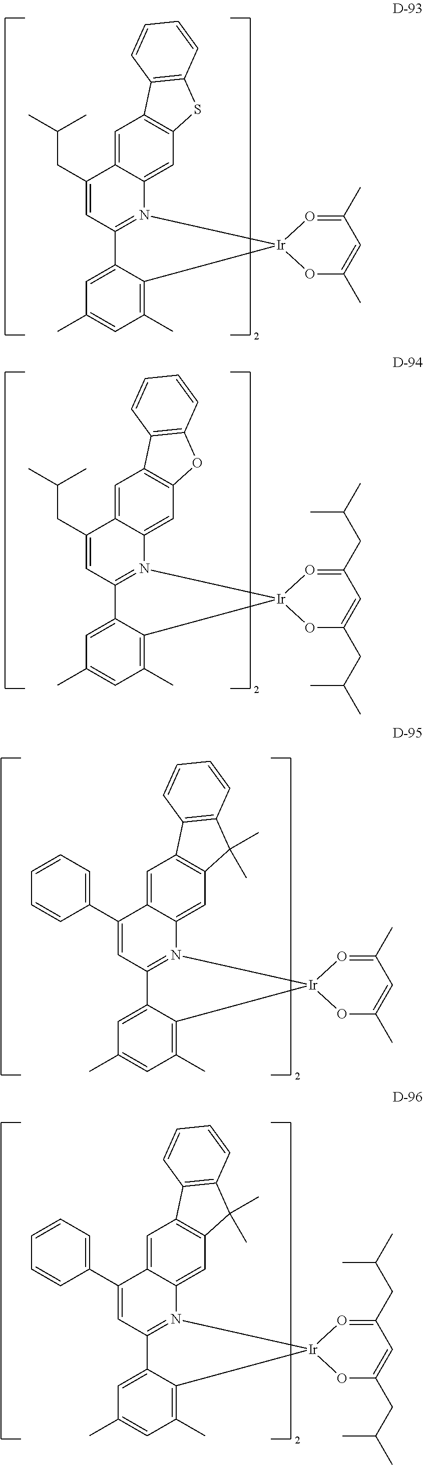

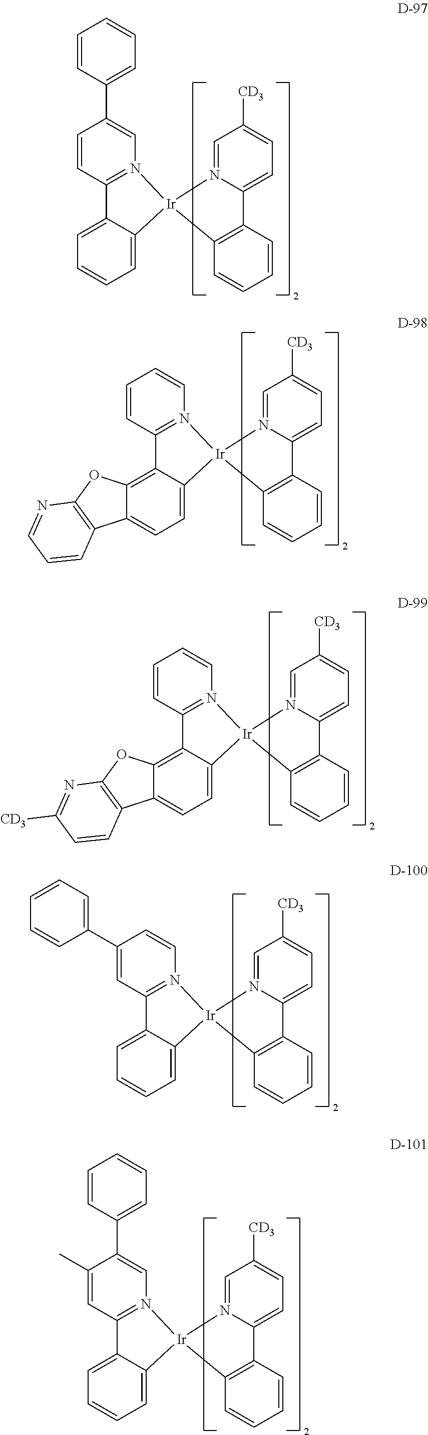

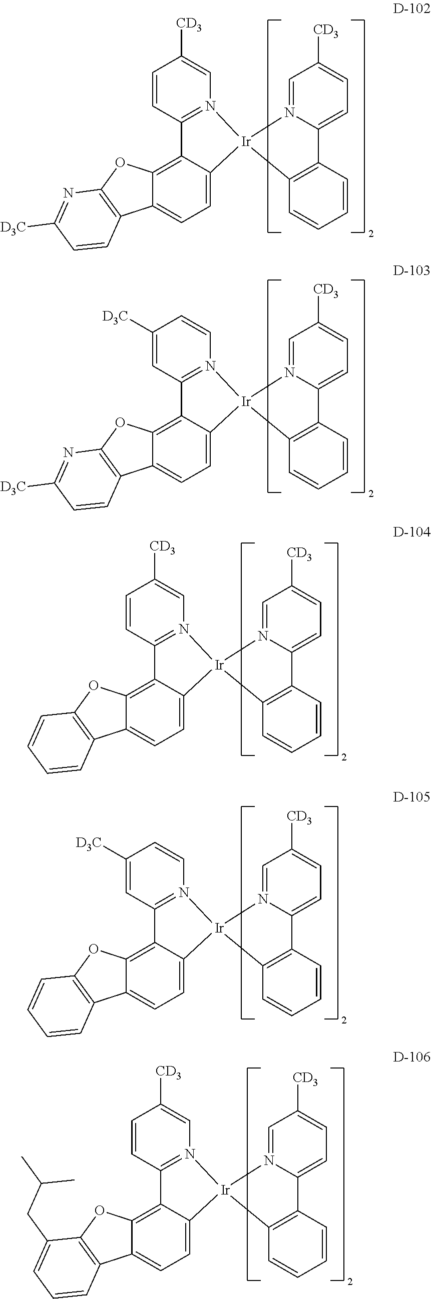

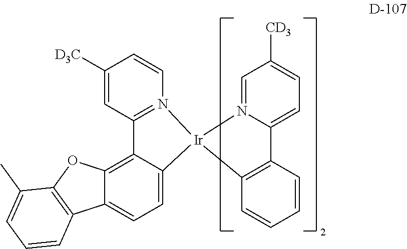

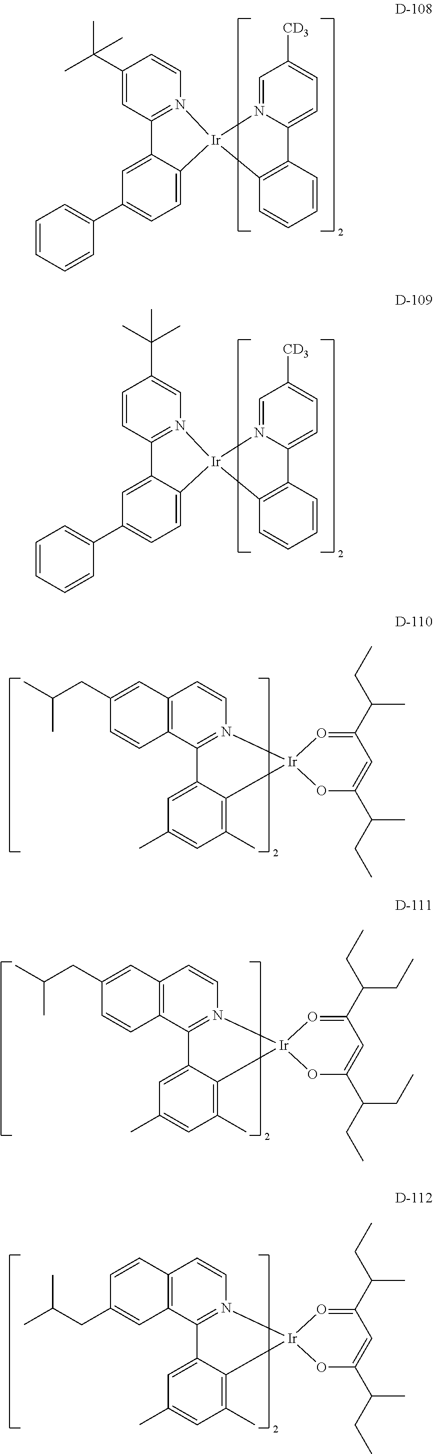

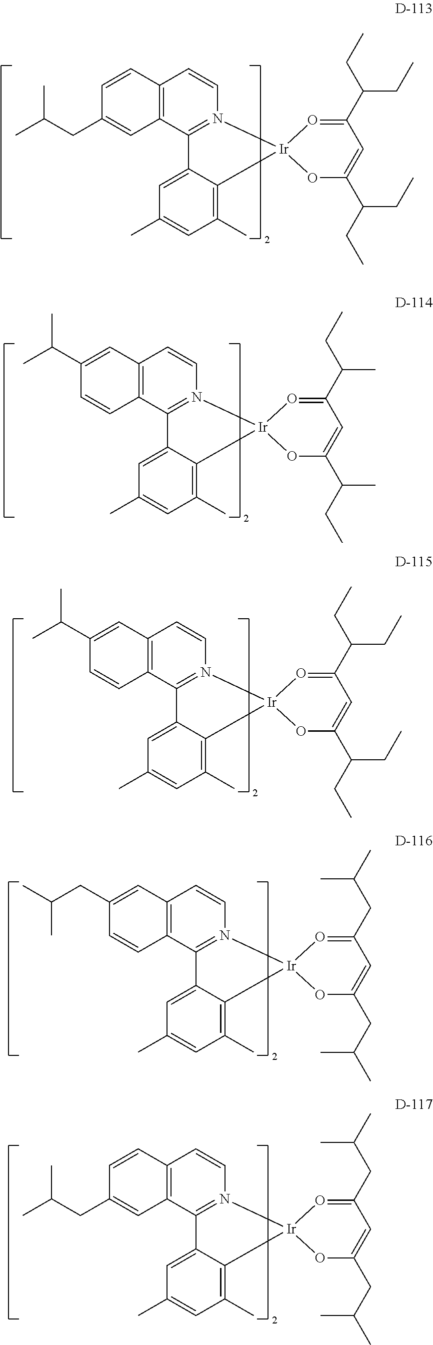

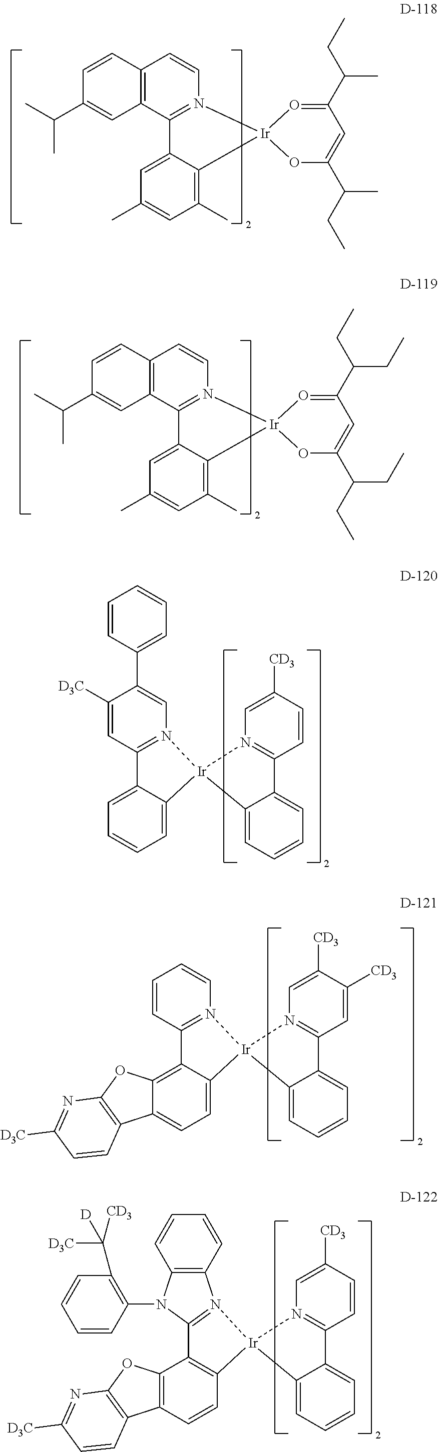

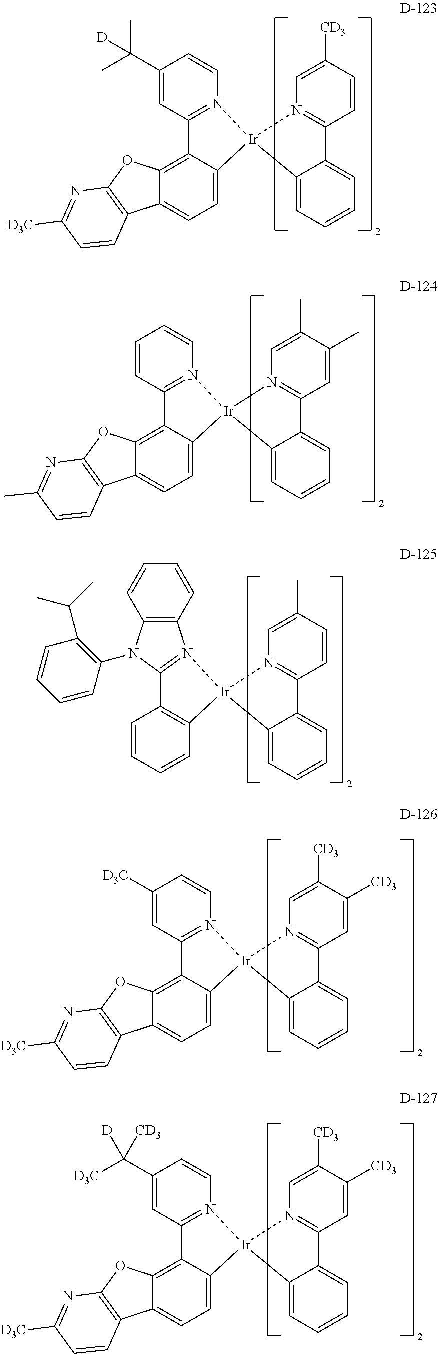

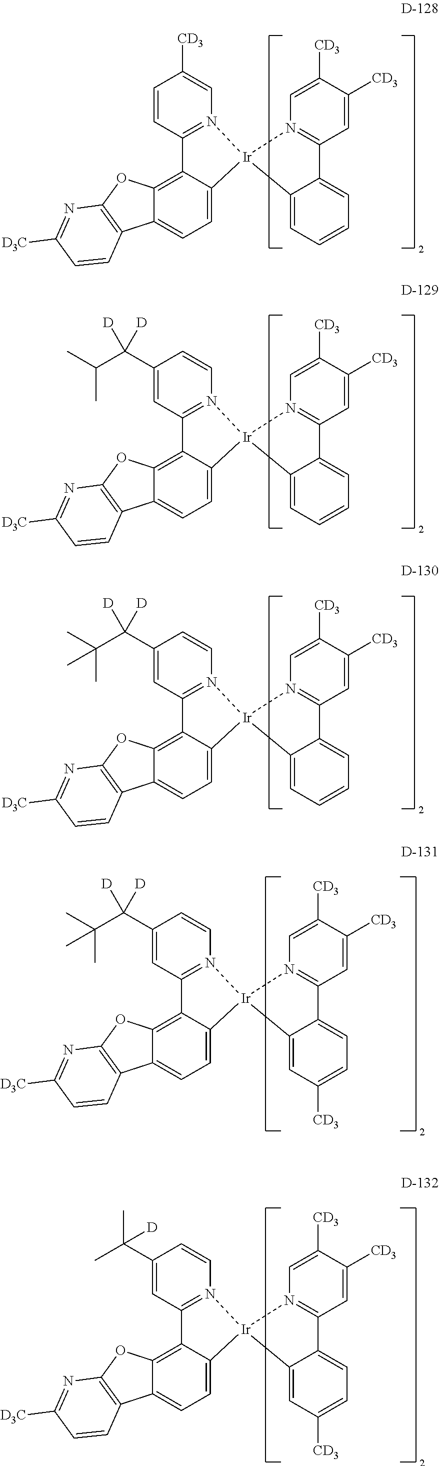

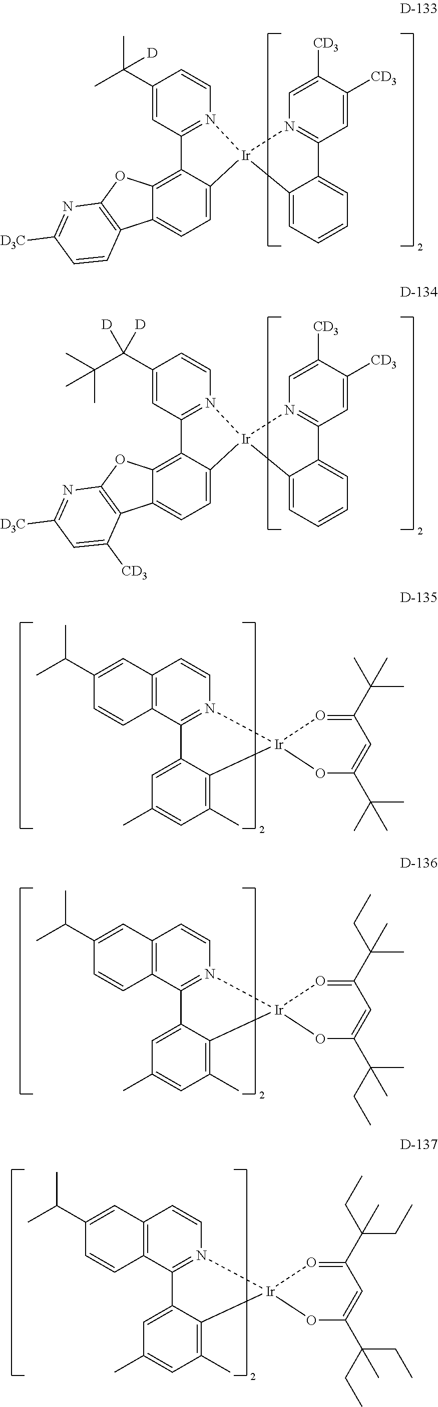

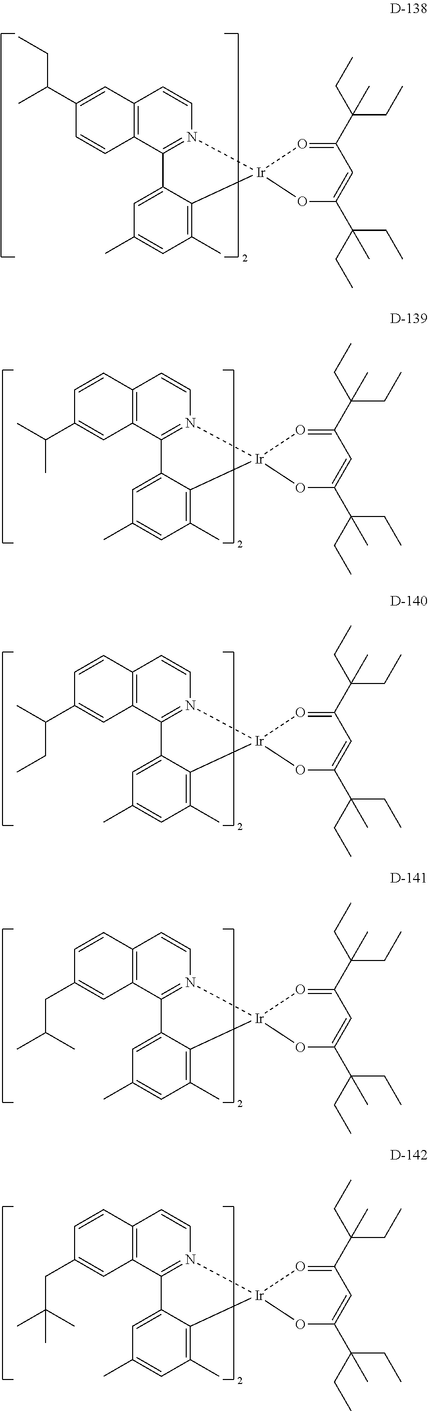

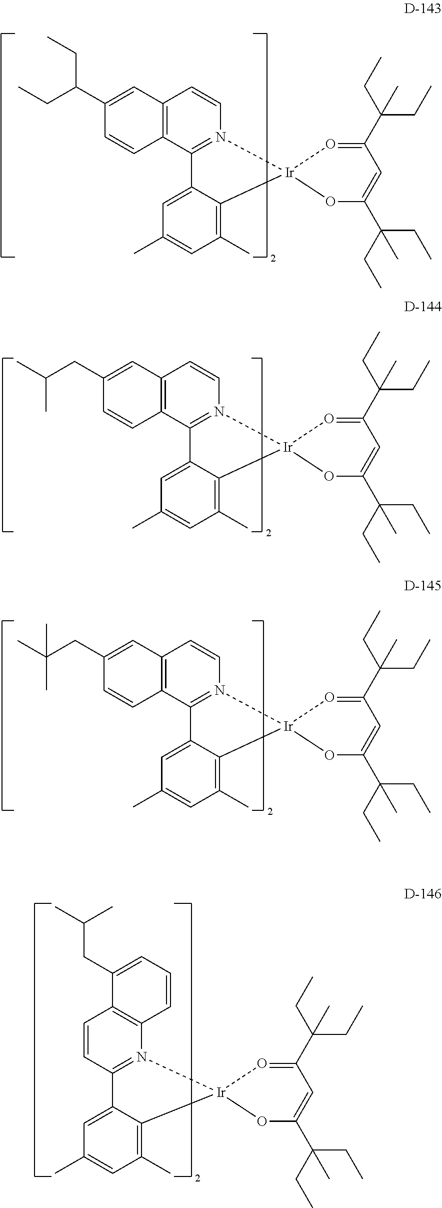

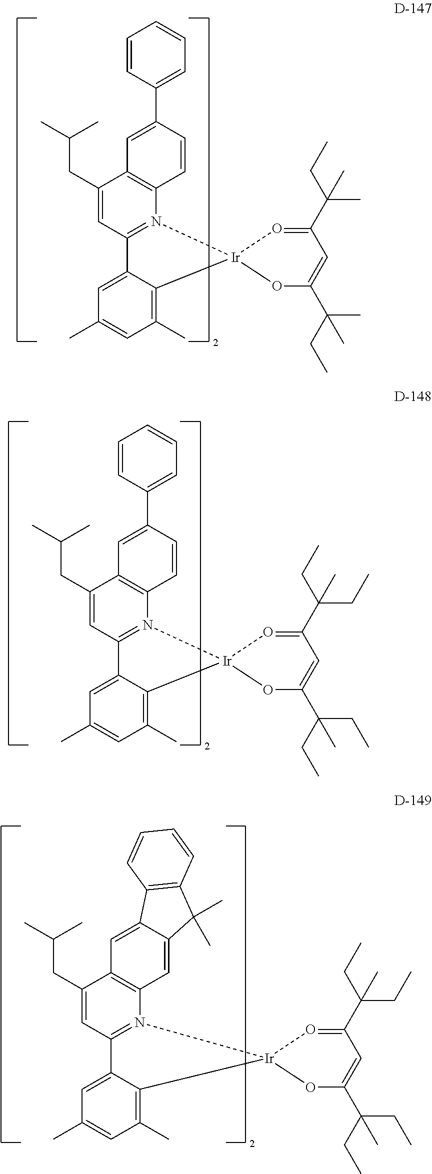

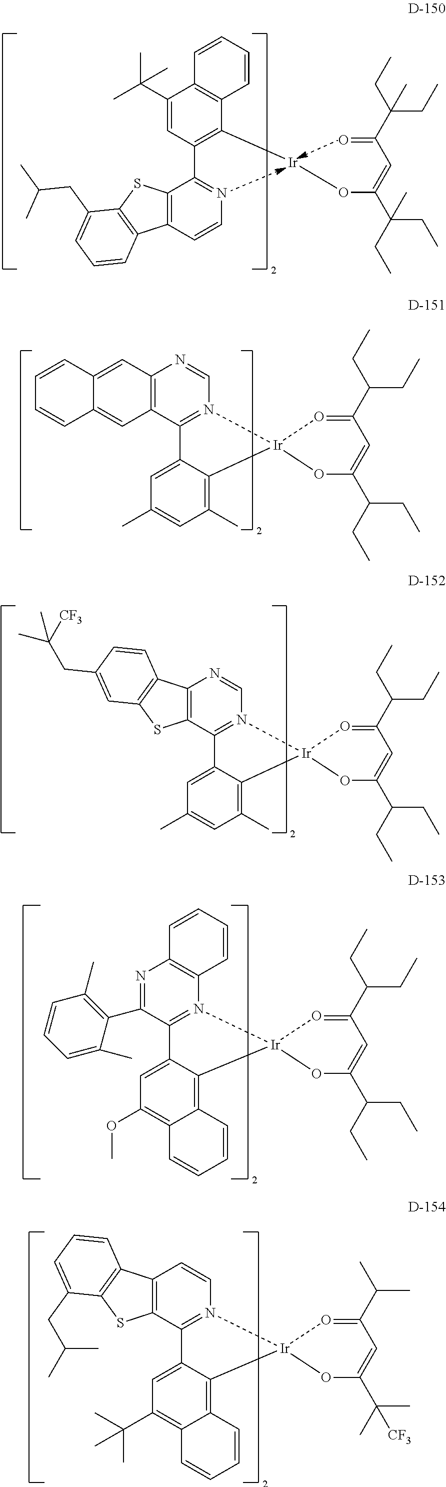

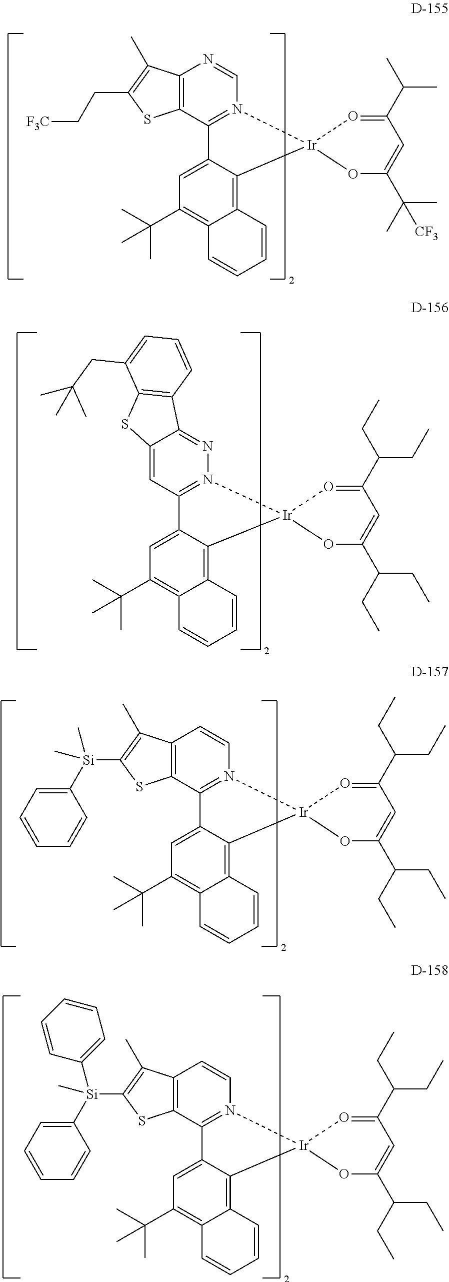

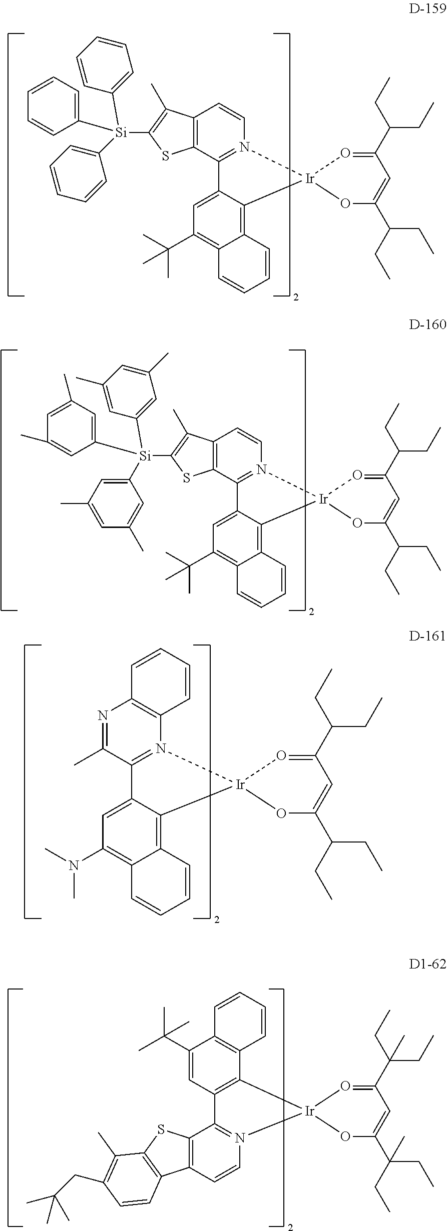

The manufacturing method of the organic electroluminescent device of the present disclosure is not limited, and the manufacturing method of the Device Examples as described below is only an example and is not limited thereto. One skilled in the art can reasonably modify the manufacturing method of the Device Examples as described below by relying on existing technology. For example, there is no particular limitation on the mixing ratio of the first host compound and the second host compound, and thus one skilled in the art can reasonably select this within a certain range by depending on existing technology. For example, based on the total weight of the light-emitting layer material, the total weight of the first host compound and the second host compound accounts for 99.5% to 80.0% of the total weight of the light-emitting layer, the weight ratio of the first host compound and the second host compound may be between 1:99 and 99:1, between 20:80 and 99:1, or between 50:50 and 90:10. In the manufacture of devices, when forming a light-emitting layer by co-depositing two or more host materials and a light-emitting material, the two or more host materials and the light-emitting material may each be placed in different evaporation sources and co-deposited to form a light-emitting layer, or a pre-mixed mixture of two or more host materials may be placed on the same evaporation source and then co-deposited with a light-emitting material placed on another evaporation source to form a light-emitting layer. This premixing method can further save evaporation sources. According to one embodiment, the first host compound, the second host compound, and the light-emitting material of the present disclosure may each be placed in different evaporation sources and co-deposited to form a light-emitting layer, or a pre-mixed mixture of the first host compound and the second host compound may be placed in the same evaporation source and then co-deposited with a light-emitting material placed in another evaporation source to form a light-emitting layer.

Hereinafter, the preparation method of the compounds according to the present disclosure, the properties thereof, and the properties of the OLED comprising the organic electroluminescent compound according to the present disclosure will be explained in detail with reference to the representative compounds of the present disclosure. The following examples only describe the properties of the compound and the OLED comprising the same according to the present disclosure, but the present disclosure is not limited to the following examples.

### Example 1: Preparation of Compound C-1

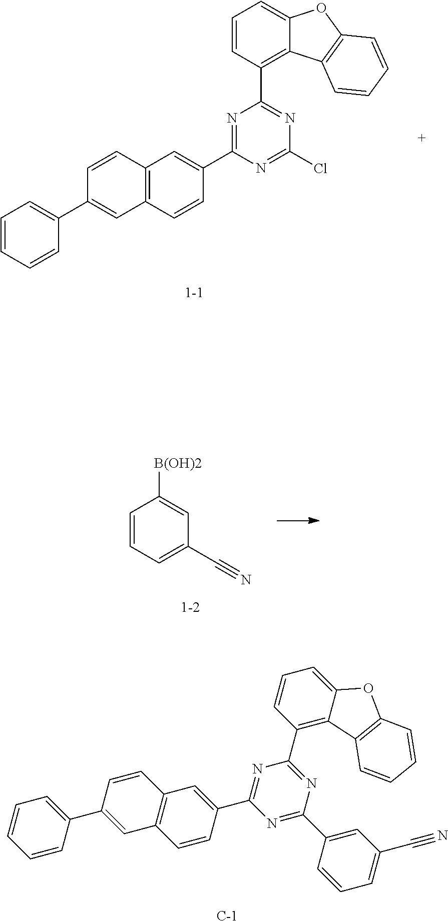

In a flask, Compound 1-1 (15 g, 31.03 mmol), Compound 1-2 (5.0 g, 34.14 mmol), tetrakis(tiphenylphosphine)palladium(0) (1.8 g, 1.551 mmol), and 2 M potassium carbonate (8.5 g, 62.06 mmol) were dissolved in 155 mL of toluene and 77 mL of ethanol, and the mixture was stirred under reflux at 120° C. for 4 hours. After completion of the reaction, the organic layer was extracted, and the remaining moisture was removed with magnesium sulfate. Thereafter, the organic layer was separated by column chromatography to obtain Compound C-1 (9.8 g, yield: 57%).

| | MW | M.P. |
|---|---|---|
| C-1 | 550.62 | 233.6° C. |

### Example 2: Preparation of Compound C-5

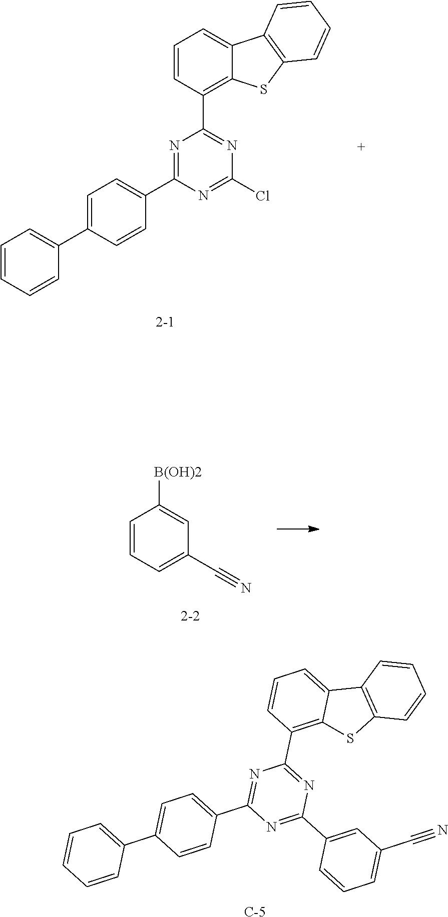

In a flask, Compound 2-1 (7 g, 15.56 mmol), Compound 2-2 (2.5 g, 17.11 mmol), tetrakis(tiphenylphosphine)palladium(0) (0.89 g, 0.778 mmol), and 2 M potassium carbonate (4.3 g, 31.12 mmol) were dissolved in 78 mL of toluene and 19 mL of ethanol, and the mixture was stirred under reflux at 120° C. for 4 hours. After completion of the reaction, the organic layer was extracted with ethyl acetate, and the remaining moisture was removed with magnesium sulfate. Thereafter, the organic layer was separated by column chromatography to obtain Compound C-5 (2.1 g, yield: 26).

| | MW | M.P. |
|---|---|---|
| C-5 | 516.62 | 264.1° C. |

### Example 3: Preparation of Compound C-3

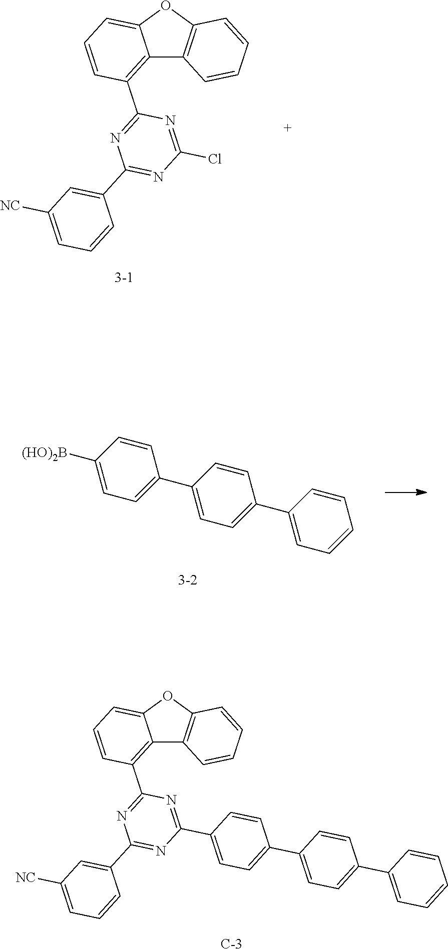

In a flask, Compound 3-1 (4.5 g, 11.7 mmol), Compound 3-2 (3.2 g, 11.7 mmol), tetrakis(tiphenylphosphine)palladium(0) (0.67 g, 0.58 mmol), and potassium carbonate (4.1 g, 29.3 mmol) were dissolved in 60 mL of toluene, 15 mL of ethanol, and 15 mL of distilled water, and the mixture was stirred under reflux for 3 hours. After completion of the reaction, the resulting solid was filtered, washed with distilled water and methanol, and dried. Thereafter, the organic layer was separated by column chromatography to obtain Compound C-3 (4.9 g, yield: 72%).

| | MW | M.P. |
|---|---|---|
| C-3 | 576.66 | 226° C. |

### Example 4: Preparation of Compound C-2

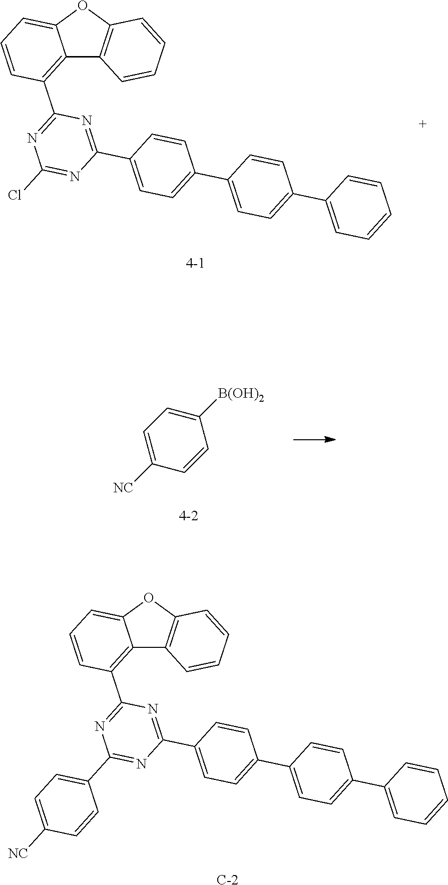

In a flask, Compound 4-1 (10 g, 19.6 mmol), Compound 4-2 (3.0 g, 20.5 mmol), tetrakis(triphenylphosphine)palladium(0) (1.13 g, 0.98 mmol), and potassium carbonate (6.7 g, 49.0 mmol) were dissolved in 100 mL of toluene, 25 mL of ethanol, and 25 mL of distilled water, and the mixture was stirred under reflux for 4 hours.

After completion of the reaction, the resulting solid was filtered, washed with distilled water and methanol, and dried. Thereafter, the organic layer was separated by column chromatography to obtain Compound C-2 (9.0 yield: 80%).

| | MW | M.P. |
|---|---|---|
| C-2 | 576.66 | 285° C. |

### Example 5: Preparation of Compound C-9

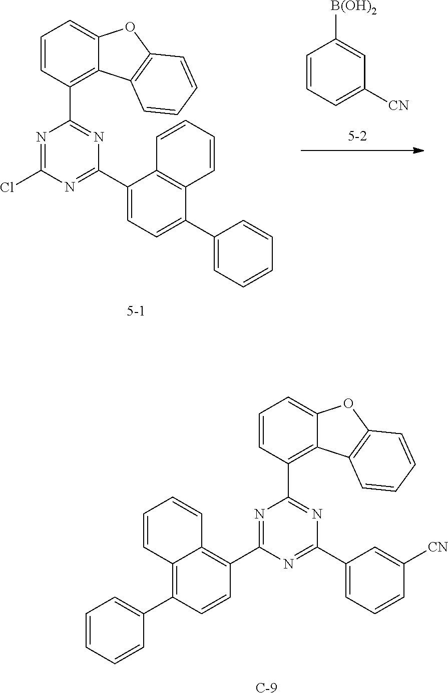

In a flask, Compound 5-1 (5.7 g, 11.77 mmol), Compound 5-2 (1.9 g, 12.95 mmol), tetrakis(triphenylphosphine)palladium(0) (0.68 g, 0.588 mmol), and potassium carbonate (4.9 g, 35.33 mmol) were dissolved in 80 mL of toluene, 20 mL of ethanol, and 20 mL of distilled water, and the mixture was stirred under reflux at 140° C. for 4 hours. After completion of the reaction, the mixture was cooled to room temperature, methanol was added, and the solid was filtered and then dissolved in CHCl₃. Thereafter, Compound C-9 (5.5 g, yield: 84%) was obtained by separation using a silica filter.

| | MW | M.P. |
|---|---|---|
| C-9 | 550.6 | 253.4° C. |

### Example 6: Preparation of Compound C-4

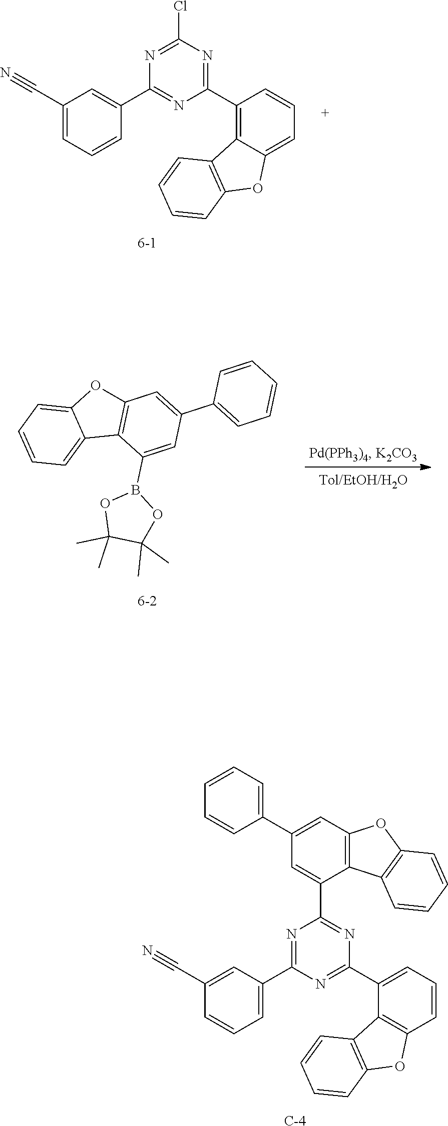

In a flask, Compound 6-1 (7 g, 18.28 mmol), Compound 6-2 (6.77 g, 18.28 mmol), tetrakis(triphenylphosphine)palladium(0) (1.06 g, 0.91 mmol), and potassium carbonate (3.76 g, 27.42 mmol) were dissolved in 90 mL of toluene, 45 mL of ethanol, and 45 mL of distilled water, and the mixture was stirred under reflux at 130° C. for 3 hours. After completion of the reaction, the mixture was cooled to room temperature, and distilled water was added to the resulting solid, followed by stirring for 30 minutes. Thereafter, Compound C-4 (4.1 g, yield: 46%) was obtained by separation using a silica filter and recrystallization.

| | MW | M.P. |
|---|---|---|
| C-4 | 590.64 | 215.2° C. |

### Example 7: Preparation of Compound C-30

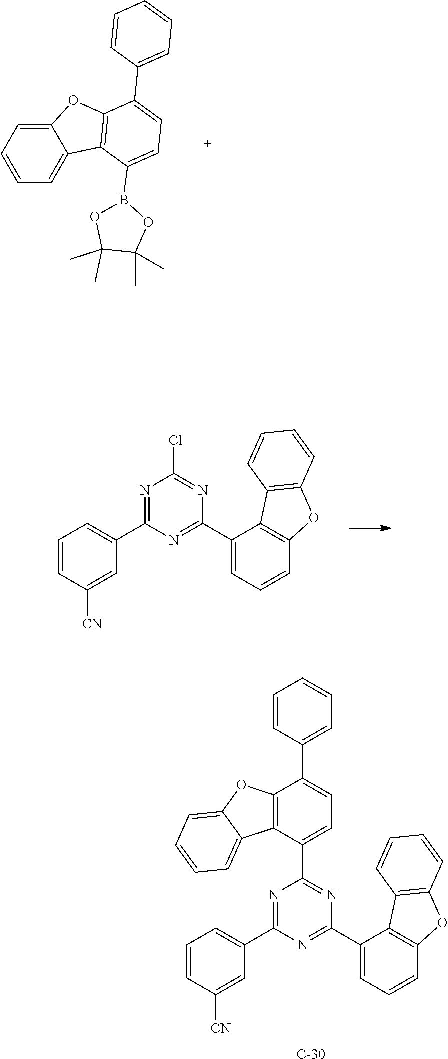

In a flask, 4,4,5,5-tetramethyl-2-(4-phenyldibenzo[b,d]furan-1-yl)-1,3,2-dioxaborolane (8.1 g, 21.8 mmol), 3-(4-chloro-6-(dibenzo[b,d]furan-1-yl)-1,3,5-triazin-2-yl)benzonitrile (7 g, 18.2 mmol), tetrakis(triphenylphosphine)palladium(0) (1 g, 0.8 mmol), and potassium carbonate (7.6 g, 54.9 mmol) were dissolved in 82 mL of toluene, 27 mL of ethanol, and 27 mL of distilled water, and the mixture was stirred under reflux at 120° C. for 3 hours. After completion of the reaction, the resulting solid was filtered, washed with methanol, and dried. Thereafter, Compound C-30 (8.5 g, yield: 78.7%) was obtained by purification through column chromatography.

| | MW | M.P. |
|---|---|---|
| C-30 | 590.64 | 301° C. |

### Example 8: Preparation of Compound C-7

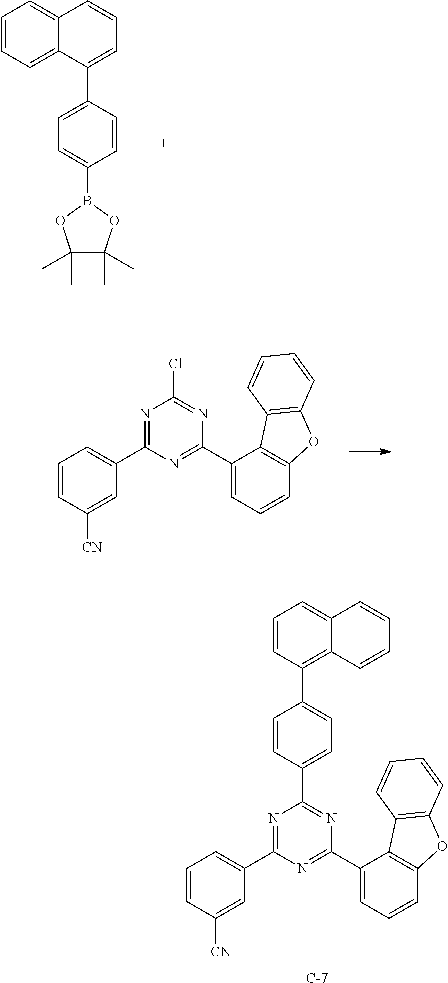

In a flask, 4,4,5,5-tetramethyl-2-(4-(naphthalen-1-yl)phenyl)-1,3,2-dioxaborolane (9.5 g, 28.7 mmol), 3-(4-chloro-6-(dibenzo[b,d]furan-1-yl)-1,3,5-triazin-2-yl)benzonitrile (10 g, 26.1 mmol), tetrakis(triphenylphosphine)palladium(0) (1.5 g, 1.2 mmol), and potassium carbonate (10.8 g, 78.1 mmol) were dissolved in 120 mL of toluene, 39 mL of ethanol, and 39 mL of distilled water, and the mixture was stirred under reflux at 120° C. for 3 hours. After completion of the reaction, the organic layer was extracted, and the remaining moisture was removed with magnesium sulfate. Thereafter, the organic layer was separated by column chromatography to obtain Compound C-7 (6.9 g, yield: 48%).

| | MW | M.P. |
|---|---|---|
| C-7 | 550.62 | 229.8° C. |

### Example 9: Preparation of Compound C-8

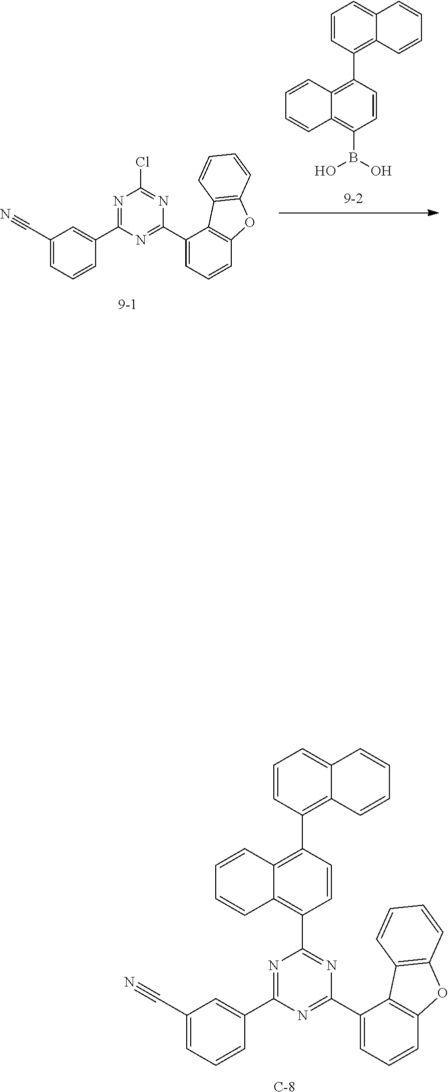

In a flask, Compound 9-1 (10 g, 33 mmol), [1,1′-binaphthalen]4-ylboronic acid (14 g, 35 mmol), potassium carbonate (9.3 g, 66 mmol), and tetrakis(tiphenylphosphine)palladium(0) (2 g, 1.6 mmol) were dissolved in 300 mL of tetrahydrofuran (THF) and 70 mL of distilled water, and the mixture was stirred under reflux at 120° C. for 5 hours. After completion of the reaction, the organic layer was extracted with ethyl acetate, the remaining moisture was removed with magnesium sulfate, and the resultant was dried. Thereafter, the organic layer was separated by column chromatography to obtain Compound C-8 (11 g, yield: 54%).

| | MW | M.P. |
|---|---|---|
| C-8 | 600.20 | 204° C. |

### Example 10: Preparation of Compound H1-2

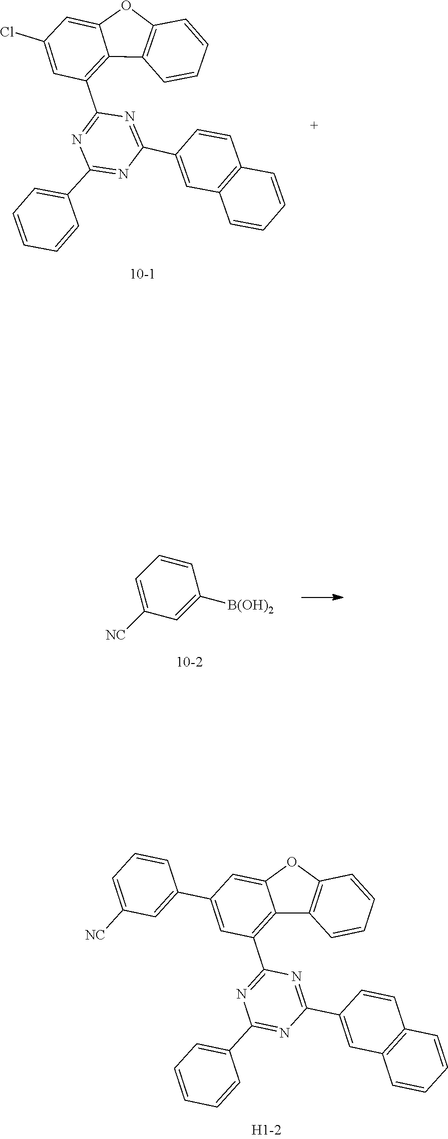 [SMILES: Clc1cc(-c2nc(-c3ccccc3)nc(-c3ccc4ccccc4c3)n2)c2c(c1)oc1ccccc12 ; N#Cc1cccc(B(O)O)c1 ; N#Cc1cccc(-c2cc(-c3nc(-c4ccccc4)nc(-c4ccc5ccccc5c4)n3)c3c(c2)oc2ccccc23)c1]

In a flask, Compound 10-1 (7 g, 14.5 mmol), Compound 10-2 (4.2 g, 28.9 mmol), tris(dibenzylideneacetone)dipalladium (1.32 g, 1.45 mmol), 2-dichlorohexylphosphino-2′,6′-dimethoxybiphenyl (1.18 g, 2.89 mmol), and tripotassium phosphate (9.2 g, 43.3 mmol) were dissolved in 80 mL of o-xylene and 20 mL of 1,4-dioxane, and the mixture was stirred under reflux for 15 hours. After completion of the reaction, the resulting solid was filtered, washed with distilled water and methanol, and dried. Thereafter, the organic layer was separated by column chromatography to obtain Compound H1-2 (3.5 g, yield: 44%).

| | MW | M.P. |
|---|---|---|
| H1-2 | 550.62 | 301° C. |

### Example 11: Preparation of Compound H1-3

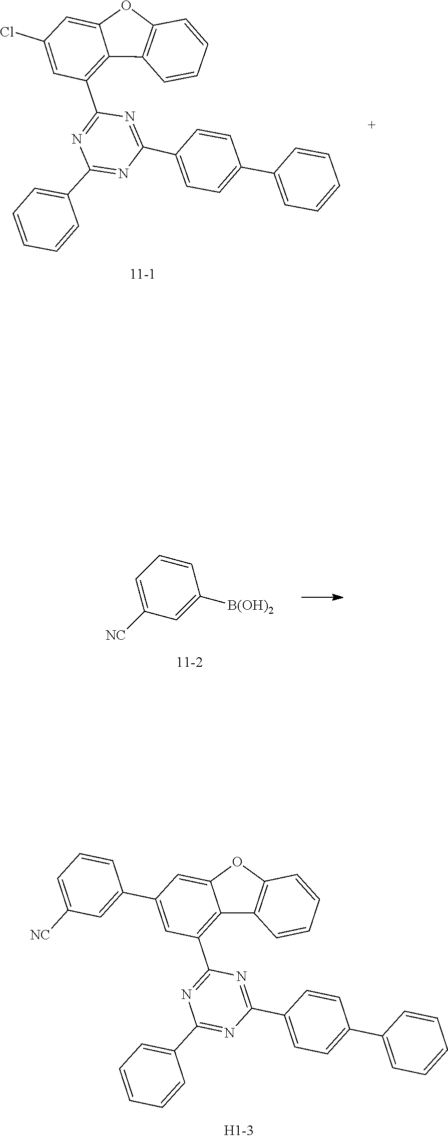 [SMILES: Clc1cc(-c2nc(-c3ccccc3)nc(-c3ccc(-c4ccccc4)cc3)n2)c2c(c1)oc1ccccc12 ; N#Cc1cccc(B(O)O)c1 ; N#Cc1cccc(-c2cc(-c3nc(-c4ccccc4)nc(-c4ccc(-c5ccccc5)cc4)n3)c3c(c2)oc2ccccc23)c1]

In a flask, Compound 11-1 (5.6 g, 10.9 mmol), Compound 11-2 (3.2 g, 21.8 mmol), tris(dibenzylideneacetone)dipalladium (1.0 g, 1.09 mmol), 2-dichlorohexylphosphino-2′,6′-dimethoxybiphenyl (0.9 g, 2.18 mmol), and tripotassium phosphate (9.3 g, 43.7 mmol) were dissolved in 80 mL of o-xylene and 20 mL of 1,4-dioxane, and the mixture was stirred under reflux for 5 hours. After completion of the reaction, the resulting solid was filtered, washed with distilled water and methanol, and dried. Thereafter, the organic layer was separated by column chromatography to obtain Compound H1-3 (3.5 g, yield: 55%).

| | MW | M.P. |
|---|---|---|
| H1-3 | 576.66 | 270° C. |

### Example 12: Preparation of Compound H2-231

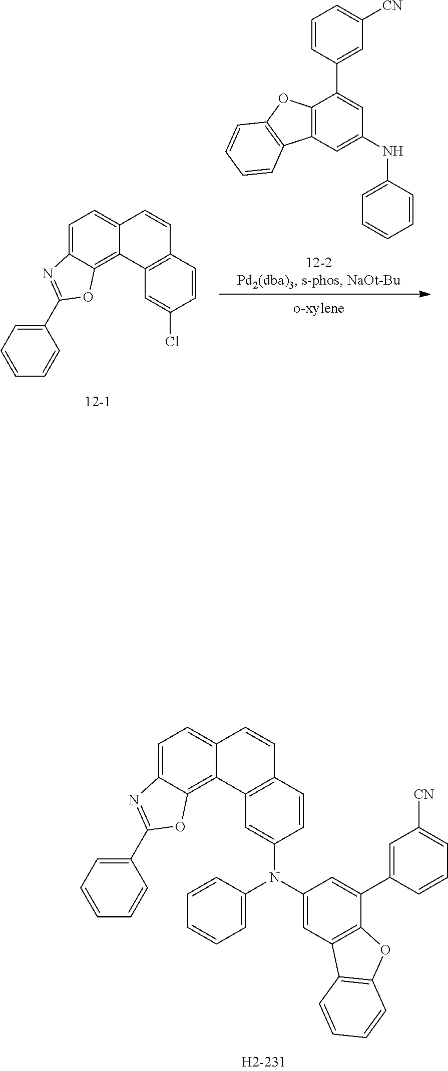 [SMILES: Clc1ccc2ccc3ccc4nc(-c5ccccc5)oc4c3c2c1 ; N#Cc1cccc(-c2cc(Nc3ccccc3)cc3c2oc2ccccc23)c1 ; N#Cc1cccc(-c2cc(N(c3ccccc3)c3ccc4ccc5ccc6nc(-c7ccccc7)oc6c5c4c3)cc3c2oc2ccccc23)c1]

In a flask, Compound 12-1 (5.7 g, 17.57 mmol), Compound 12-2 (6.6 g, 18.45 mmol), tris(dibenzylideneacetone)dipalladium (0.8 g, 0.878 mmol), 2-dichlorohexylphosphino-2′,6′-dimethoxybiphenyl (0.72 g, 1.757 mmol), NaOtBu (4.2 g, 43.92 mmol), and 90 mL of o-xylene were added, and the mixture was stirred under reflux at 130° C. for 3 hours. After completion of the reaction, the mixture was cooled to room temperature, the organic layer was extracted with ethyl acetate, the remaining moisture was removed with magnesium sulfate, and the resultant was dried. Thereafter, the organic layer was separated by column chromatography to obtain Compound H2-231 (1.9, yield: 16%).

| | MW | M.P. |
|---|---|---|
| H2-231 | 653.7 | 256° C. |

### Example 13: Preparation of Compound C-6

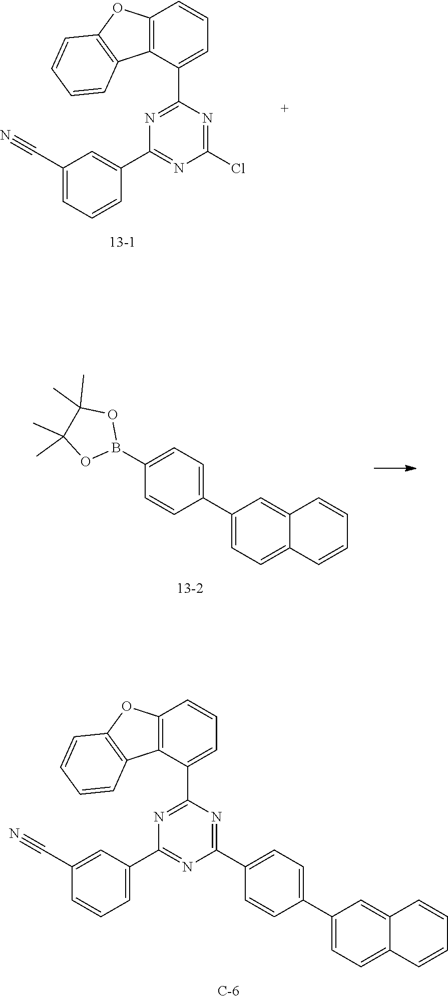

In a flask, Compound 13-1 (10.5 g, 27.530 mmol), Compound 13-2 (10 g, 30.282 mmol), tetrakis(triphenylphosphine)palladium(0) (1.5 g, 1.376 mmol), and potassium carbonate (9.5 g, 68.25 mmol) were dissolved in 140 mL of toluene, 70 mL of ethanol, and 70 mL of distilled water, and the mixture was stirred under reflux at 120° C. for 4 hours. After completion of the reaction, the organic layer was extracted with ethyl acetate, the remaining moisture was removed with magnesium sulfate, and the resultant was dried. Thereafter, the organic layer was separated by column chromatography to obtain Compound C-6 (5.9 g, yield: 26%).

| | MW | M.P. |
|---|---|---|
| C-6 | 550.62 | 228.5° C. |

### Example 14: Preparation of Compound C-421

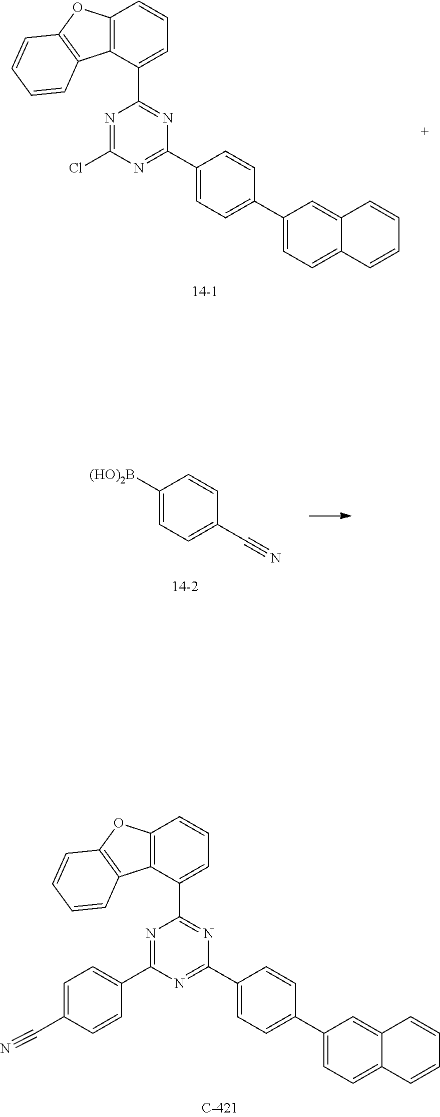 [SMILES: Clc1nc(-c2ccc(-c3ccc4ccccc4c3)cc2)nc(-c2cccc3oc4ccccc4c23)n1 ; N#Cc1ccc(B(O)O)cc1 ; N#Cc1ccc(-c2nc(-c3ccc(-c4ccc5ccccc5c4)cc3)nc(-c3cccc4oc5ccccc5c34)n2)cc1]

In a flask, Compound 14-1 (8.0 g, 16.6 mmol), Compound 14-2 (2.6 g, 17.3 mmol), tetrakis(triphenylphosphine)palladium(0) (0.95 g, 0.83 mmol), and potassium carbonate (3.44 g, 24.9 mmol) were dissolved in 80 mL of toluene, 40 mL of ethanol, and 40 mL of distilled water, and the mixture was stirred under reflux at 120° C. for one day. After completion of the reaction, the organic layer was extracted with ethyl acetate, the remaining moisture was removed with magnesium sulfate, and the resultant was dried. Thereafter, the organic layer was separated by column chromatography to obtain Compound C-421 (3.0 g, yield: 33%).

| | MW | M.P. |
|---|---|---|
| C-421 | 550.18 | 269.7° C. |

### Device Examples 1 to 4: Producing OLEDs in which a Compound According to the Present Disclosure is Deposited as a Host

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI-1 of Table 4 was introduced into a cell of the vacuum vapor deposition apparatus, and Compound HT-1 was introduced into another cell. The two materials were evaporated at different rates, and Compound HI-1 was deposited in a doping amount of 3 wt % based to the total amount of Compound HI-1 and Compound HT-1 to form a hole injection layer with a thickness of 10 nm. Subsequently, Compound HT-1 was deposited on the hole injection layer to form a first hole transport layer with a thickness of 80 nm. Then Compound HT-2 was introduced into another cell of the vacuum vapor deposition apparatus and was then evaporated by applying an electric current to the cell to thereby deposit a second hole transport layer with a thickness of 60 nm on the first hole transport layer. After formation of the hole injection layer and the hole transport layers, a light-emitting layer was deposited thereon as follows. After compounds listed in Table 1 below as hosts and Compound D-39 as a dopant were introduced into two cells of the vacuum vapor deposition apparatus, the host material and the dopant material were simultaneously evaporated at different rates, and the dopant was deposited in a doping amount of 3 wt % based on the total amount of the hosts and the dopant to form a light-emitting layer with a thickness of 40 nm on the third hole transport layer. Next, an electron transport layer was deposited to a thickness of 35 nm on the light-emitting layer using a 50:50 weight ratio mixture of Compound ET-1 and Compound EI-1 as the electron transport materials. After Compound EI-1 was deposited as an electron injection layer with a thickness of 2 nm on the electron transport layer, an Al cathode was deposited with a thickness of 80 nm on the electron injection layer using another vacuum vapor deposition apparatus to manufacture an OLED. All of the materials used for producing the OLED were purified by vacuum sublimation at 10⁻⁶ Torr.

### Comparative Examples 1 and 2: Producing OLEDs Comprising Comparative Compounds as Hosts

OLEDs were produced in the same manner as in Device Example 1, except that the compounds listed as hosts in Table 1 below were used as hosts of the light-emitting layer.

The driving voltage, the power efficiency, the luminous color at a luminance of 1,000 nit, and the time taken for luminance to decrease from 100% to 95% at a luminance of 10,000 nit (lifetime: T₉₅) of the OLEDs of Device Examples 1 to 4 and Comparative Examples 1 and 2 prepared as described above were measured, and the results thereof are shown in Table 1 below.

TABLE 1

| | | Driving | Power | | |
|---|---|---|---|---|---|
| | | Voltage | Efficiency | Luminous | Lifetime |
| | Host | (V) | (lm/W) | Color | (T₉₅, hr) |
| Device | C-4 | 3.3 | 26.7 | Red | 22 |
| Example 1 | | | | | |
| Device | C-30 | 3.5 | 26.3 | Red | 26 |
| Example 2 | | | | | |
| Device | C-7 | 3.2 | 25.6 | Red | 15 |
| Example 3 | | | | | |
| Device | C-6 | 3.0 | 26.4 | Red | 18 |
| Example 4 | | | | | |
| Comparative | A-1 | 3.6 | 24.5 | Red | 4 |
| Example 1 | | | | | |
| Comparative | A-2 | 4.1 | 6.4 | Red | 11 |
| Example 2 | | | | | |

From Table 1 above, it can be confirmed that the OLEDs comprising the organic electroluminescent compound according to the present disclosure as a host material exhibit lower driving voltage and higher power efficiency, while exhibiting improved lifetime characteristics compared to the Comparative Examples using a conventional compound.

### Device Examples 5 to 13: Producing OLEDs in which a First Host Material and a Second Host Material According to the Present Disclosure are Co-Deposited

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI-1 of Table 4 was introduced into a cell of the vacuum vapor deposition apparatus, and Compound HT-3 was introduced into another cell. The two materials were evaporated at different rates, and Compound HI-1 was deposited in a doping amount of 3 wt % based to the total amount of Compound HI-1 and Compound HT-3 to form a hole injection layer with a thickness of 10 nm. Subsequently, Compound HT-3 was deposited on the hole injection layer to form a first hole transport layer with a thickness of 80 nm. Then Compound HT-4 was introduced into another cell of the vacuum vapor deposition apparatus and was then evaporated by applying an electric current to the cell to thereby deposit a second hole transport layer with a thickness of 55 nm on the first hole transport layer. Subsequently, Compound HT-5 was introduced into another cell of the vacuum vapor deposition apparatus and was then evaporated by applying an electric current to the cell to thereby deposit a third hole transport layer with a thickness of 5 nm on the second hole transport layer. After formation of the hole injection layer and the hole transport layers, a light-emitting layer was deposited thereon as follows. After respective compounds listed in Table 2 below as the first host and the second host were introduced into two cells of the vacuum vapor deposition apparatus, and Compound D-39 was introduced into another cell as a dopant, the two host materials were evaporated at a ratio of 1:1, and the dopant material was simultaneously evaporated at a different rate, thereby depositing the dopant in a doping amount of 3 wt % based on the total amount of the hosts and the dopant to form a light-emitting layer with a thickness of 40 nm on the third hole transport layer. Next, an electron transport layer was deposited to a thickness of 35 nm on the light-emitting layer using a 50:50 weight ratio mixture of Compound ET-2 and Compound EI-1 as the electron transport materials. After Compound EI-1 was deposited as an electron injection layer with a thickness of 2 nm on the electron transport layer, an Al cathode was deposited with a thickness of 80 nm on the electron injection layer using another vacuum vapor deposition apparatus to manufacture an OLED. All of the materials used for producing the OLED were purified by vacuum sublimation at 10⁻⁶ Torr.

### Comparative Example 3: Producing an OLED Comprising a Comparative Compound as a Host

An OLED was produced in the same manner as in Device Example 5, except that the compounds listed as a second host in Table 2 below were used as a host of the light-emitting layer.

The driving voltage, the luminous color at a luminance of 1,000 nit, and the time taken for luminance to decrease from 100% to 95% at a luminance of 10,000 nit (lifetime: T₉₅) of the OLEDs of Device Examples 5 to 13 and Comparative Example 3 prepared as described above were measured, and the results thereof are shown in Table 2 below.

TABLE 2

| | | | Driving | | |
|---|---|---|---|---|---|
| | First | Second | Voltage | Luminous | Lifetime |
| | Host | Host | (V) | Color | (T₉₅, hr) |
| Device | C-3 | H4-69 | 3.0 | Red | 223 |
| Example 5 | | | | | |
| Device | C-9 | H4-69 | 3.0 | Red | 258 |
| Example 6 | | | | | |
| Device | C-8 | H4-69 | 3.1 | Red | 135 |
| Example 7 | | | | | |
| Device | H1-3 | H4-69 | 2.9 | Red | 204 |
| Example 8 | | | | | |
| Device | H1-2 | H4-69 | 3.0 | Red | 232 |
| Example 9 | | | | | |
| Device | C-2 | H4-69 | 3.1 | Red | 334 |
| Example 10 | | | | | |
| Device | C-4 | H4-69 | 3.1 | Red | 132 |
| Example 11 | | | | | |
| Device | C-30 | H4-69 | 3.1 | Red | 132 |
| Example 12 | | | | | |
| Device | C-7 | H4-69 | 3.0 | Red | 166 |
| Example 13 | | | | | |
| Comparative | A-1 | H4-69 | 3.2 | Red | 54 |
| Example 3 | | | | | |

From Table 2 above, it can be confirmed that the OLEDs comprising the plurality of host materials according to the present disclosure exhibit lower driving voltage while exhibiting improved lifetime characteristics compared to the Comparative Example using a conventional compound.

### Device Examples 14 to 17: Producing OLEDs in which a First Host Material and a Second Host Material According to the Present Disclosure are Co-Deposited

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI-1 of Table 4 was introduced into a cell of the vacuum vapor deposition apparatus, and Compound HT-3 was introduced into another cell. The two materials were evaporated at different rates, and Compound HI-1 was deposited in a doping amount of 3 wt % based to the total amount of Compound HI-1 and Compound HT-3 to form a hole injection layer with a thickness of 10 nm. Subsequently, Compound HT-3 was deposited on the hole injection layer to form a first hole transport layer with a thickness of 80 nm. Then Compound HT-6 was introduced into another cell of the vacuum vapor deposition apparatus and was then evaporated by applying an electric current to the cell to thereby deposit a second hole transport layer with a thickness of 55 nm on the first hole transport layer. Subsequently, Compound HT-7 was introduced into another cell of the vacuum vapor deposition apparatus and was then evaporated by applying an electric current to the cell to thereby deposit a third hole transport layer with a thickness of 5 nm on the second hole transport layer. After formation of the hole injection layer and the hole transport layers, a light-emitting layer was deposited thereon as follows.

After compounds as hosts listed in Table 3 below were introduced into two cells of the vacuum vapor deposition apparatus, and Compound D-162 was introduced into another cell as a dopant, the two host materials were evaporated at a ratio of 1:1, and the dopant material was simultaneously evaporated at a different rate, thereby depositing the dopant in a doping amount of 3 wt % based on the total amount of the hosts and the dopant to form a light-emitting layer with a thickness of 40 nm on the third hole transport layer. Then an electron buffer layer with a thickness of 5 nm was deposited on the light-emitting layer using Compound ET-3, and an electron transport layer was deposited to a thickness of 30 nm on the electron buffer layer using a 50:50 weight ratio mixture of Compound ET-4 and Compound EI-1. After Compound EI-1 was deposited as an electron injection layer with a thickness of 2 nm on the electron transport layer, an Al cathode was deposited with a thickness of 80 nm on the electron injection layer using another vacuum vapor deposition apparatus to manufacture an OLED. All of the materials used for producing the OLED were purified by vacuum sublimation at 10⁻⁶ Torr.

The driving voltage, the luminous color at a luminance of 1,000 nit, and the time taken for luminance to decrease from 100% to 95% at a luminance of 10,000 nit (lifetime: T₉₅) of the OLEDs of Device Examples 14 to 17 prepared as described above were measured, and the results thereof are shown in Table 3 below.

TABLE 3

| | | | Driving | | |
|---|---|---|---|---|---|
| | First | Second | Voltage | Luminous | Lifetime |
| | Host | Host | (V) | Color | (T₉₅, hr) |
| Device | C-6 | H4-69 | 3.0 | Red | 233 |
| Example 14 | | | | | |
| Device | C-460 | H4-69 | 2.9 | Red | 115 |
| Example 15 | | | | | |
| Device | C-321 | H4-69 | 2.8 | Red | 231 |
| Example 16 | | | | | |
| Device | C-75 | H4-69 | 3.1 | Red | 145 |
| Example 17 | | | | | |

From Table 3 above, it can be confirmed that the OLEDs comprising the plurality of host materials according to the present disclosure exhibit lower driving voltage while exhibiting improved lifetime characteristics.

The compounds used in the Device Examples and Comparative Examples are shown in Table 4 below.

TABLE 4

| | | |
|---|---|---|
| Hole Injection Layer/Hole Transport Layer | 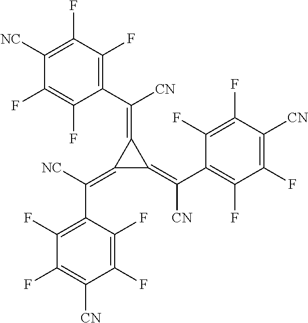 | HI-1 |
| | 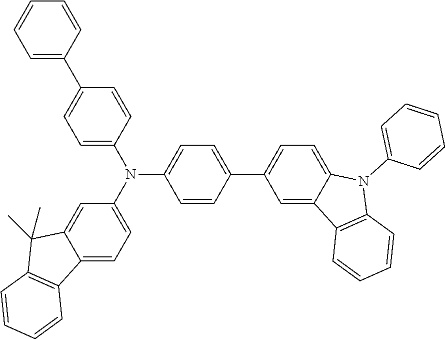 | HT-1 |
| | 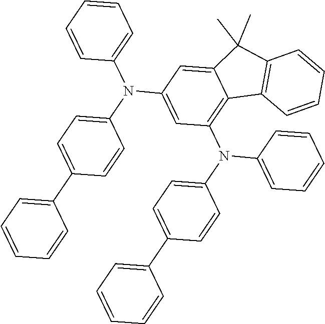 | HT-2 |
| | 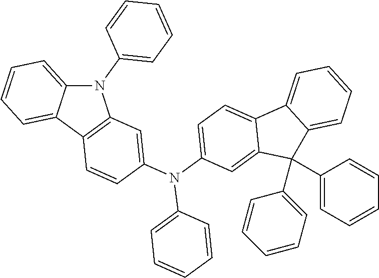 | HT-3 |
| | 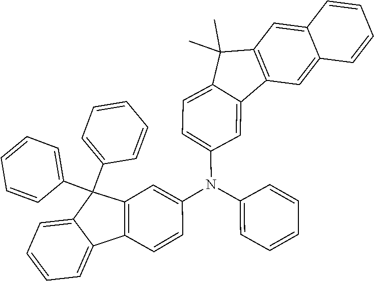 | HT-4 |
| | 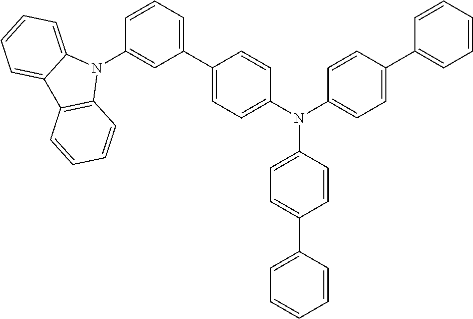 | HT-5 |
| | 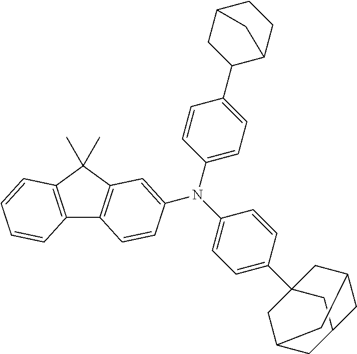 | HT-6 |
| | 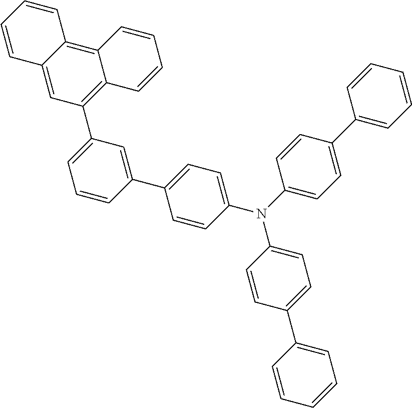 | HT-7 |
| Light-Emitting Layer | 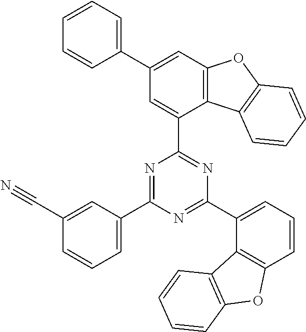 | C-4 |
| | 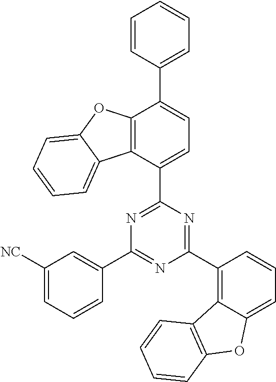 | C-30 |
| | 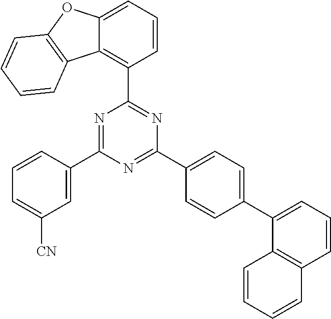 | C-7 |
| | 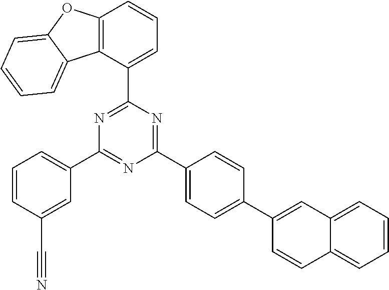 | C-6 |
| | 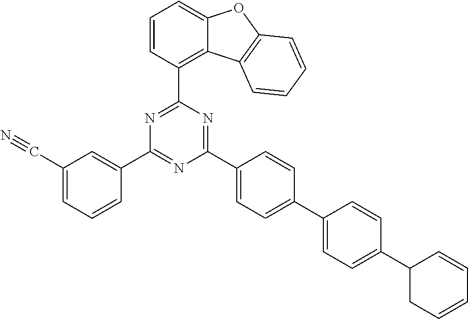 | C-3 |
| | 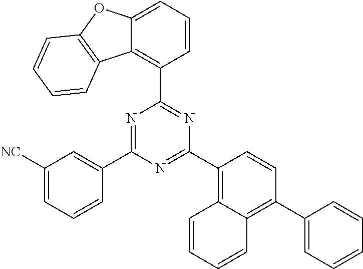 | C-9 |
| | 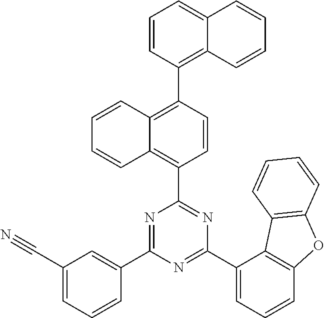 | C-8 |
| | 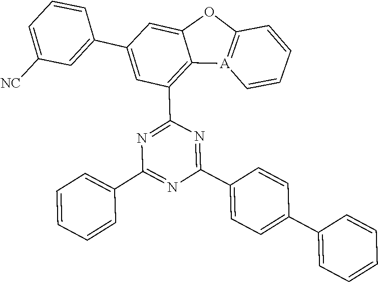 | H1-3 |
| | 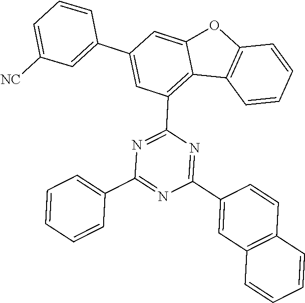 | H1-2 |
| | 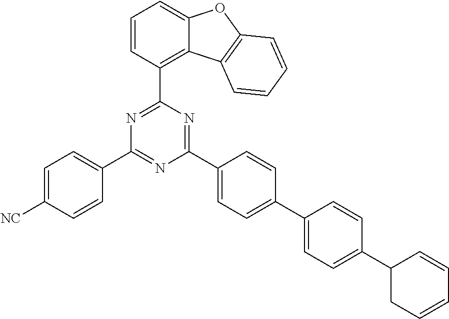 | C-2 |
| | 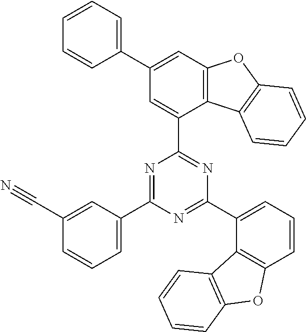 | C-4 |
| | 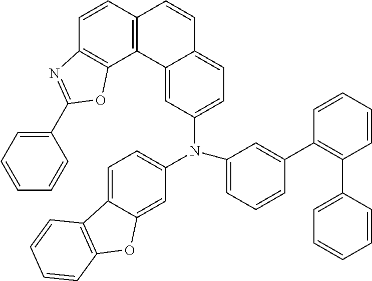 | H4-69 |
| | 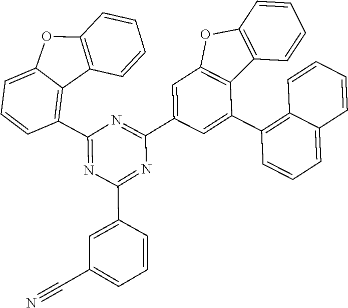 | C-460 |
| | 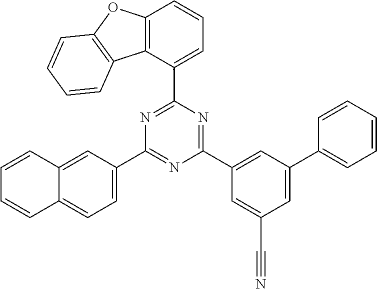 | C-321 |
| | 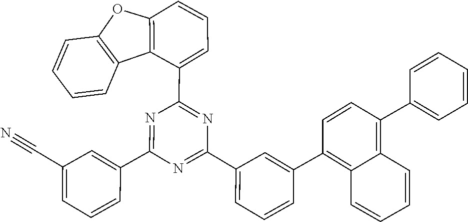 | C-75 |
| | 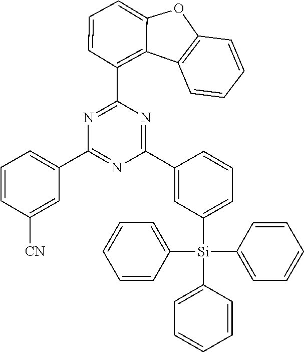 | A-1 |
| | 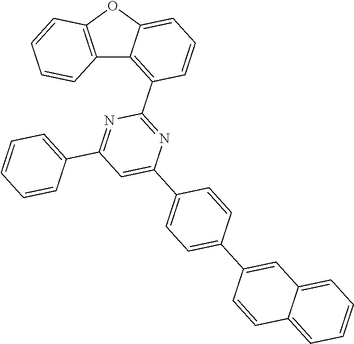 | A-2 |
| | 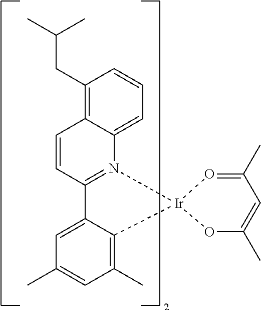 | D-39 |
| | 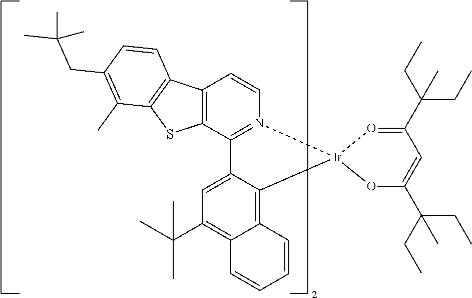 | D-162 |
| Electron Transport Layer/ Electron Injection Layer | 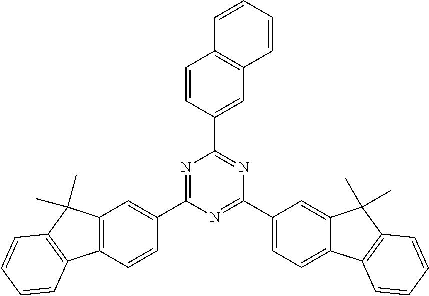 | ET-1 |
| | 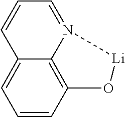 | EI-1 |
| | 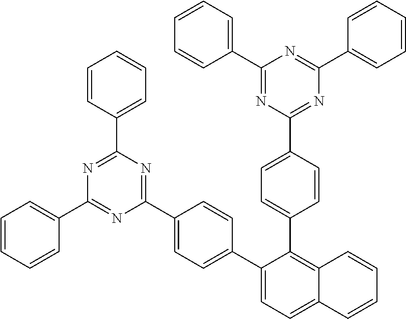 | ET-2 |
| | 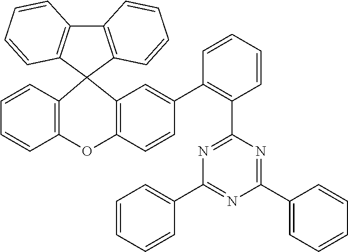 | ET-3 |
| | 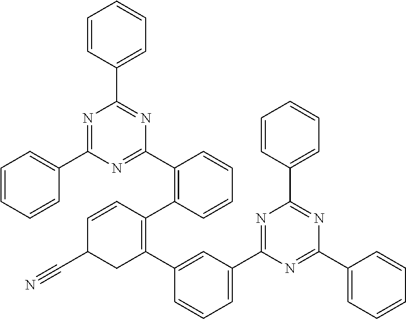 | ET-4 |

1. A plurality of host materials comprising a first host material comprising a compound represented by the following Formula 1 and a second host material comprising a compound represented by the following Formula 2, wherein at least one of the first host material and the second host material comprises a cyano: 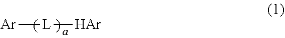
wherein in Formula 1,
Ar represents a substituted or unsubstituted (C₆-C₃₀)aryl, a substituted or unsubstituted (3- to 30-membered)heteroaryl, or a substituted or unsubstituted (C₃-C₃₀)cycloalkyl;
L represents a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
a represents an integer of 1 to 3, where if a is an integer of 2 or 3, each L may be the same as or different from each other;
HAr is represented by the following Formula 1-a or 1-b: 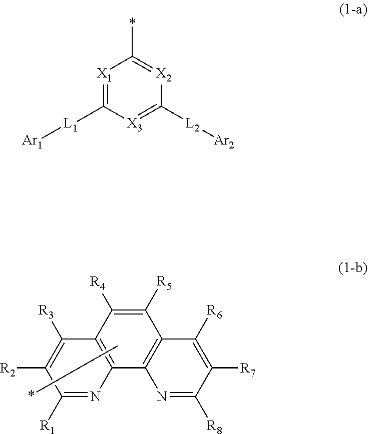
wherein in Formulas 1-a and 1-b,
* represents a site linked to L, and in Formula 1-b, any one of R₁ to R₅ is linked to L;
X₁ to X₃ each independently represent N or CR₉; with the proviso that at least one of X₁ to X₃ is N;
Ar₁ and Ar₂ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, or a substituted or unsubstituted fused ring group of a (C₃-C₃₀)aliphatic ring(s) and a (C₆-C₃₀)aromatic ring(s);
R₆ to R₉ and those of R₁ to R₅ that are not linked to L each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s); and
L₁ and L₂ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
with the proviso that when HAr is represented by Formula 1-a, cases where Ar, Ar₁, or Ar₂ comprises a tri(C₆-C₃₀)arylsilyl or a tri(C₆-C₃₀)arylmethyl are excluded, and the carbon atoms of the aryl in the tri(C₆-C₃₀)arylsilyl and the tri(C₆-C₃₀)arylmethyl may be replaced with any one of N, S, or O; 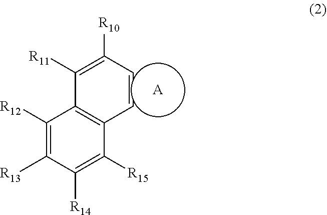
wherein in Formula 2,
ring A is represented by the following Formula 2-a or 2-b;
R₁₀ to R₁₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring group of a (C₃-C₃₀)aliphatic ring(s) and a (C₆-C₃₀)aromatic ring(s), or 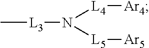
or may be linked to an adjacent substituent(s) to form a ring(s);
L₃ to L₅ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
Ar₄ and Ar₅ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, or a substituted or unsubstituted (C₃-C₃₀)cycloalkyl; 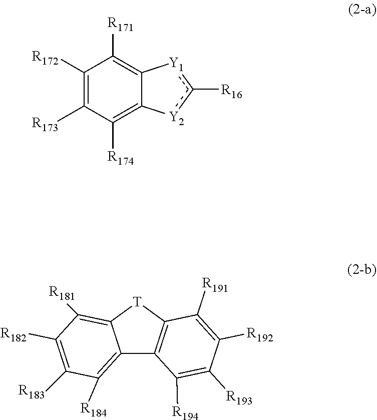
wherein in Formulas 2-a and 2-b,
Y₁ and Y₂ each independently represent —N═, —NRₐ—, —O—, or —S—, with the proviso that one of Y₁ and Y₂ is —N═, and the other of Y₁ and Y₂ is —NRₐ—, —O—, or —S—;
T represents O or S; and
an adjacent pair among R₁₇₁ to R₁₇₄, R₁₈₁ to R₁₈₄, and R₁₉₁ to R₁₉₄ represents a fused position to the naphthalene in Formula 2, and R₁₇₁ to R₁₇₄, R₁₈₁ to R₁₈₄, R₁₉₁ to R₁₉₄, Rₐ, and R₁₆ which are not fused positions each independently have the same definitions as R₁₀ to R₁₅;
with the proviso that when the ring A is represented by Formula 2-a, any one of R₁₀ to R₁₆ and R₁₇₁ to R₁₇₄ is 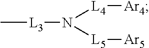
and when the ring A is represented by Formula 2-b, at least one of R₁₀ to R₁₅, R₁₈₁ to R₁₈₄, and R₁₉₁ to R₁₉₄ is 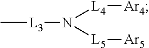
and
with the proviso that when Ar₄ and Ar₅ are substituted (C₆-C₃₀)aryl, cases where the substituents of the substituted aryl comprise a carbazole or an amino are excluded.

2. The plurality of host materials according to claim 1, wherein the substituted alkyl, the substituted aryl(ene), the substituted heteroaryl(ene), the substituted cycloalkyl(ene), the substituted heterocycloalkyl, the substituted alkoxy, the substituted trialkylsilyl, the substituted dialkylarylsilyl, the substituted alkyldiarylsilyl, the substituted triarylsilyl, and the fused ring group of the substituted aliphatic ring(s) and aromatic ring(s) each independently are substituted with at least one selected from the group consisting of deuterium, a halogen, a cyano, a carboxyl, a nitro, a hydroxy, a (C₁-C₃₀)alkyl, a halo(C₁-C₃₀)alkyl, a (C₂-C₃₀)alkenyl, a (C₂-C₃₀)alkynyl, a (C₁-C₃₀)alkoxy, a (C₁-C₃₀)alkylthio, a (C₃-C₃₀)cycloalkyl, a (C₃-C₃₀)cycloalkenyl, a (3- to 7-membered)heterocycloalkyl, a (C₆-C₃₀)aryloxy, a (C₆-C₃₀)arylthio, a (3- to 30-membered)heteroaryl, a (C₆-C₃₀)aryl, a tri(C₁-C₃₀)alkylsilyl, a tri(C₆-C₃₀)arylsilyl, a di(C₁-C₃₀)alkyl(C₆-C₃₀)arylsilyl, a (C₁-C₃₀)alkyldi(C₆-C₃₀)arylsilyl, a fused ring group of a (C₃-C₃₀)aliphatic ring(s) and a (C₆-C₃₀)aromatic ring(s), an amino, a mono- or di(C₁-C₃₀)alkylamino, a mono- or di(C₆-C₃₀)arylamino, a (C₁-C₃₀)alkyl(C₆-C₃₀)arylamino, a mono- or di(3- to 30-membered)heteroarylamino, a (C₁-C₃₀)alkyl(3- to 30-membered)heteroarylamino, a (C₆-C₃₀)aryl(3- to 30-membered)heteroarylamino, a (C₁-C₃₀)alkylcarbonyl, a (C₁-C₃₀)alkoxycarbonyl, a (C₆-C₃₀)arylcarbonyl, a (C₆-C₃₀)arylphosphinyl, a di(C₆-C₃₀)arylboronyl, a di(C₁-C₃₀)alkylboronyl, a (C₁-C₃₀)alkyl(C₆-C₃₀)arylboronyl, a (C₆-C₃₀)aryl(C₁-C₃₀)alkyl, a (C₁-C₃₀)alkyl(C₆-C₃₀)aryl, and combinations thereof.

3. The plurality of host materials according to claim 1, wherein Ar of Formula 1 is a substituted or unsubstituted biphenyl, a substituted or unsubstituted terphenyl, a substituted or unsubstituted naphthyl, a substituted or unsubstituted binaphthyl, a substituted or unsubstituted phenylnaphthyl, a substituted or unsubstituted naphthylphenyl, a substituted or unsubstituted phenanthrenyl, a substituted or unsubstituted adamantyl, a substituted or unsubstituted fluorenyl, a substituted or unsubstituted dimethylfluorenyl, a substituted or unsubstituted diphenylfluorenyl, a substituted or unsubstituted methylphenylfluorenyl, a substituted or unsubstituted phenylfluorenyl, a substituted or unsubstituted benzofluorenyl, a substituted or unsubstituted spiro[fluorene-fluorene]yl, a substituted or unsubstituted dibenzofuranyl, a substituted or unsubstituted naphthobenzofuranyl, a substituted or unsubstituted dibenzothiophenyl, a substituted or unsubstituted naphthobenzothiophenyl, a substituted or unsubstituted dibenzoselenophenyl, a substituted or unsubstituted carbazolyl, or a substituted or unsubstituted benzocarbazolyl.

4. The plurality of host materials according to claim 1, wherein Formula 1 is represented by any one of the following Formulas 1-1 to 1-9: 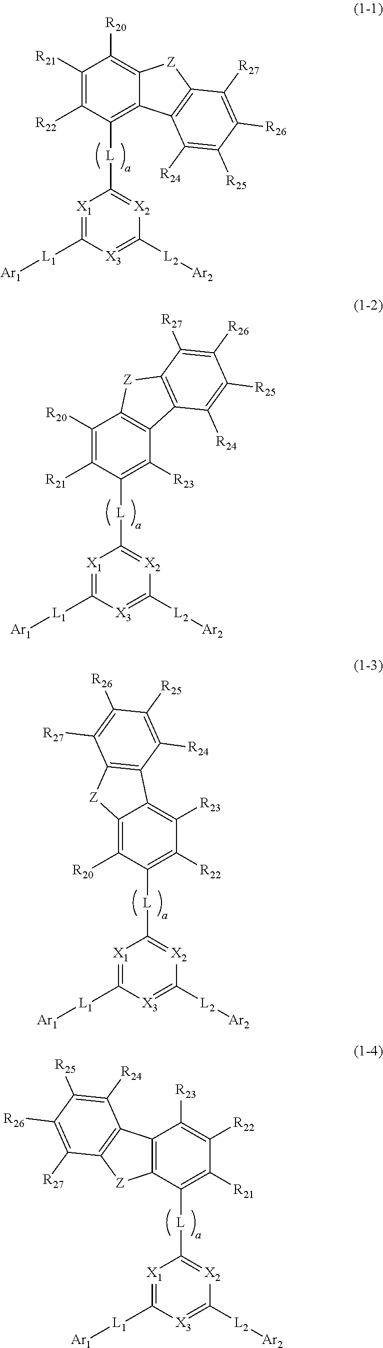 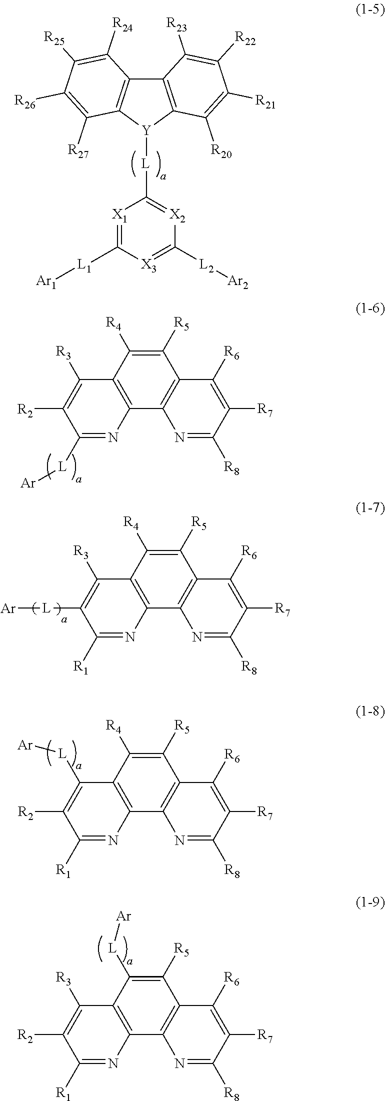
wherein in Formulas 1-1 to 1-9,
Z represents O, S, Se, NR₂₈, or CR₂₉R₃₀;
Y represents N or CR₃₁;
R₂ to R₃₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl; or may be linked to an adjacent substituent(s) to form a ring(s); and
X₁ to X₃, L, L₁, L₂, Ar, Ar₁, Ar₂, a, and R₁ to R₈ are as defined in claim 1.

5. The plurality of host materials according to claim 1, wherein the first host material comprising a compound represented by Formula 1 comprises a cyano.

6. The plurality of host materials according to claim 1, wherein at least one of Ar, L, Ar₁, and Ar₂ in Formula 1 is substituted with a cyano, a (C₁-C₃₀)alkyl substituted with a cyano, a (C₆-C₃₀)aryl substituted with a cyano, or a (3- to 30-membered)heteroaryl substituted with a cyano.

7. The plurality of host materials according to claim 4, wherein at least one of R₂₀ to R₂₇, Ar₁, and Ar₂ in Formulas 1-1 to 1-5 is substituted with a cyano, a (C₁-C₃₀)alkyl substituted with a cyano, a (C₆-C₃₀)aryl substituted with a cyano, or a (3- to 30-membered)heteroaryl substituted with a cyano.

8. The plurality of host materials according to claim 4, wherein at least one of R₁ to R₈ and Ar in Formulas 1-6 to 1-9 is substituted with a cyano, a (C₁-C₃₀)alkyl substituted with a cyano, a (C₆-C₃₀)aryl substituted with a cyano, or a (3- to 30-membered)heteroaryl substituted with a cyano.

9. The plurality of host materials according to claim 1, wherein Formula 2 is represented by any one of the following Formulas 2-1 to 2-4: 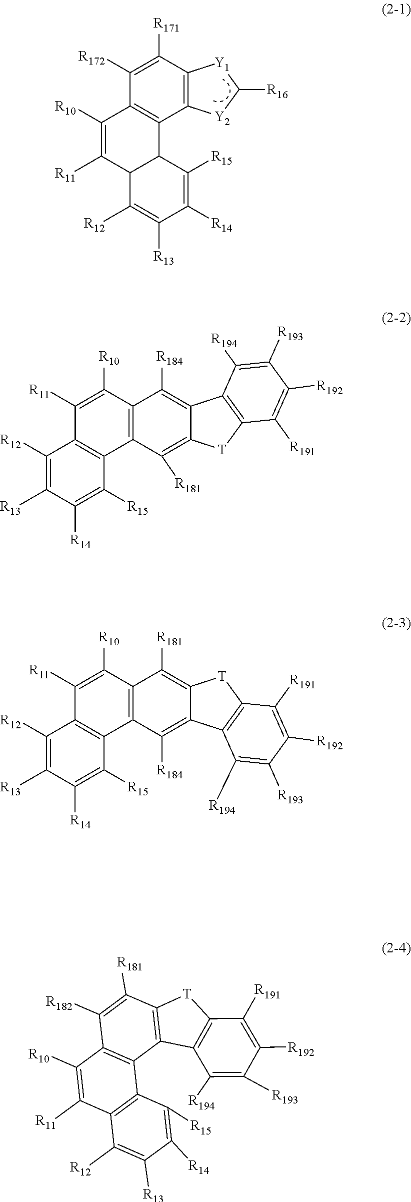
wherein in Formulas 2-1 to 2-4,
Y₁, Y₂, T, R₁₀ to R₁₆, R₁₇₁, R₁₇, R₁₈₁, R₁₈₂, R₁₈₄, and R₁₉₁ to R₁₉ are as defined in claim 1.

10. The plurality of host materials according to claim 1, wherein the second host material comprising a compound represented by Formula 2 comprises a cyano.

11. The plurality of host materials according to claim 9, wherein in Formula 2-1, any one of R₁₀ to R₁₆, R₁₇₁, and R₁₇₂ is 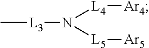
and
at least one of R₁₀ to R₁₆, R₁₇₁, R₁₇₂, Ar₄, and Ar₅ is substituted with a cyano, a (C₁-C₃₀)alkyl substituted with a cyano, a (C₆-C₃₀)aryl substituted with a cyano, or a (3- to 30-membered)heteroaryl substituted with a cyano.

12. The plurality of host materials according to claim 9, wherein in any one of Formulas 2-2 to 2-4, at least one of R₁₀ to R₁₅, R₁₈₁, R₁₈₂, R₁₈₄, and R₁₉₁ to R₁₉₄ is 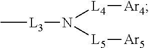
at least one of R₁₀ to R₁₅, R₁₈₁, R₁₈₂, R₁₈₄, R₁₉₁ to R₁₉₄, Ar₄, and Ar₅ is substituted with a cyano, a (C₁-C₃₀)alkyl substituted with a cyano, a (C₆-C₃₀)aryl substituted with a cyano, or a (3- to 30-membered)heteroaryl substituted with a cyano.

13. The plurality of host materials according to claim 1, wherein the compound represented by Formula 1 is selected from the following compounds: 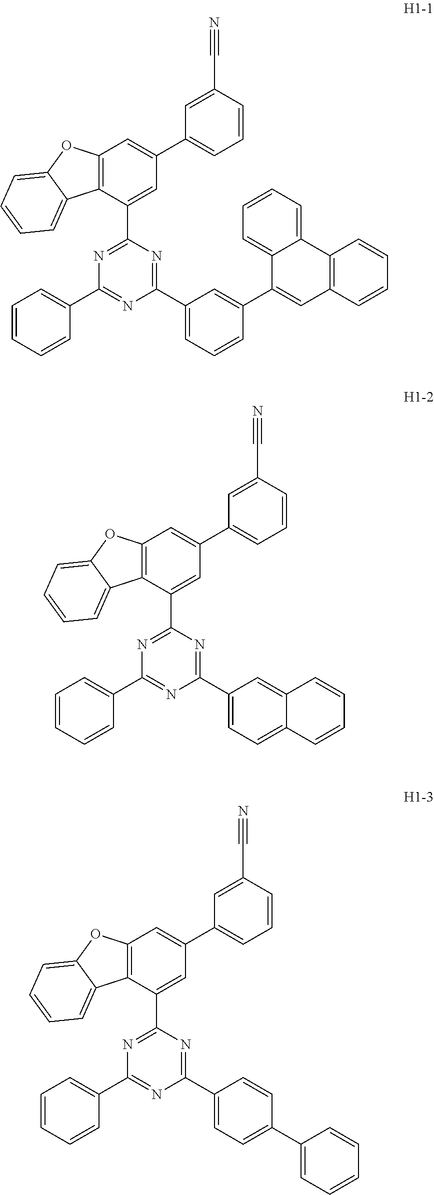 [SMILES: N#Cc1cccc(-c2cc(-c3nc(-c4ccccc4)nc(-c4cccc(-c5cc6ccccc6c6ccccc56)c4)n3)c3c(c2)oc2ccccc23)c1 ; N#Cc1cccc(-c2cc(-c3nc(-c4ccccc4)nc(-c4ccc5ccccc5c4)n3)c3c(c2)oc2ccccc23)c1 ; N#Cc1cccc(-c2cc(-c3nc(-c4ccccc4)nc(-c4ccc(-c5ccccc5)cc4)n3)c3c(c2)oc2ccccc23)c1] 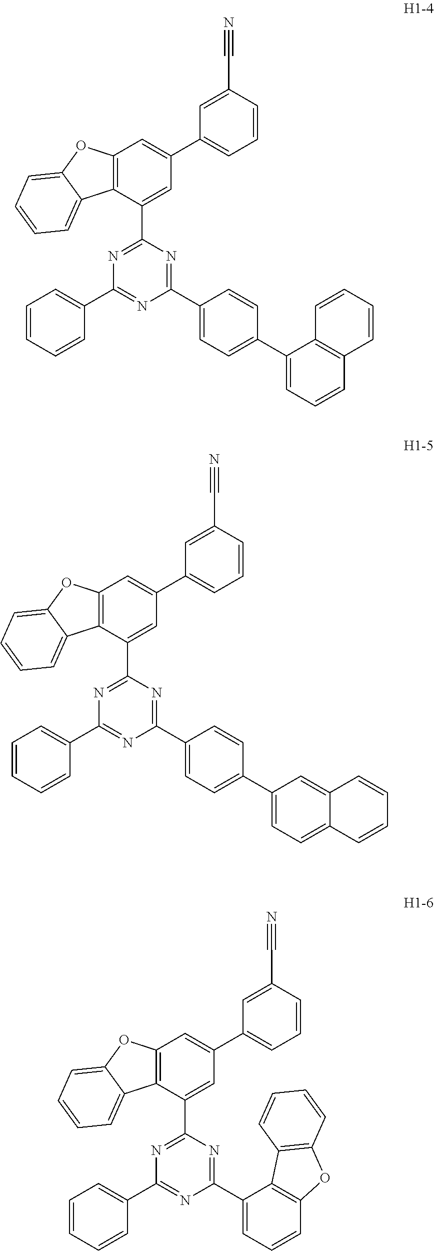 [SMILES: N#Cc1cccc(-c2cc(-c3nc(-c4ccccc4)nc(-c4ccc(-c5cccc6ccccc56)cc4)n3)c3c(c2)oc2ccccc23)c1 ; N#Cc1cccc(-c2cc(-c3nc(-c4ccccc4)nc(-c4ccc(-c5ccc6ccccc6c5)cc4)n3)c3c(c2)oc2ccccc23)c1 ; N#Cc1cccc(-c2cc(-c3nc(-c4ccccc4)nc(-c4cccc5oc6ccccc6c45)n3)c3c(c2)oc2ccccc23)c1] 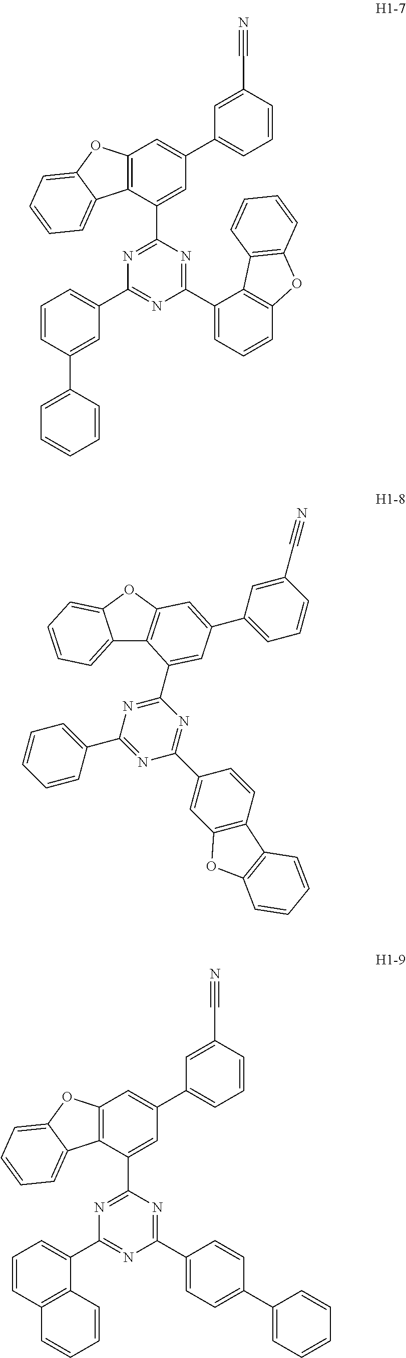 [SMILES: N#Cc1cccc(-c2cc(-c3nc(-c4cccc(-c5ccccc5)c4)nc(-c4cccc5oc6ccccc6c45)n3)c3c(c2)oc2ccccc23)c1 ; N#Cc1cccc(-c2cc(-c3nc(-c4ccccc4)nc(-c4ccc5c(c4)oc4ccccc45)n3)c3c(c2)oc2ccccc23)c1 ; N#Cc1cccc(-c2cc(-c3nc(-c4ccc(-c5ccccc5)cc4)nc(-c4cccc5ccccc45)n3)c3c(c2)oc2ccccc23)c1] 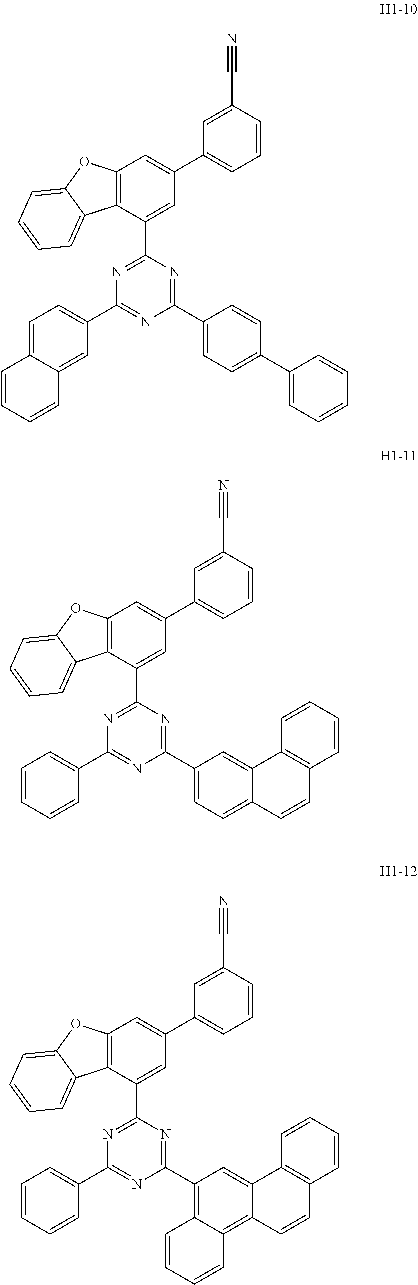 [SMILES: N#Cc1cccc(-c2cc(-c3nc(-c4ccc(-c5ccccc5)cc4)nc(-c4ccc5ccccc5c4)n3)c3c(c2)oc2ccccc23)c1 ; N#Cc1cccc(-c2cc(-c3nc(-c4ccccc4)nc(-c4ccc5ccc6ccccc6c5c4)n3)c3c(c2)oc2ccccc23)c1 ; N#Cc1cccc(-c2cc(-c3nc(-c4ccccc4)nc(-c4cc5c6ccccc6ccc5c5ccccc45)n3)c3c(c2)oc2ccccc23)c1] 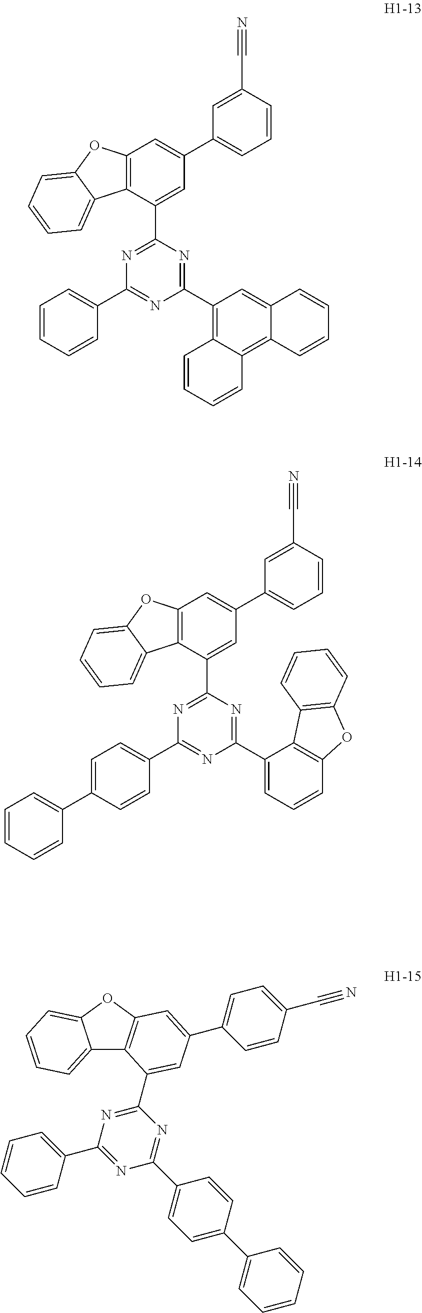 [SMILES: N#Cc1cccc(-c2cc(-c3nc(-c4ccccc4)nc(-c4cc5ccccc5c5ccccc45)n3)c3c(c2)oc2ccccc23)c1 ; N#Cc1cccc(-c2cc(-c3nc(-c4ccc(-c5ccccc5)cc4)nc(-c4cccc5oc6ccccc6c45)n3)c3c(c2)oc2ccccc23)c1 ; N#Cc1ccc(-c2cc(-c3nc(-c4ccccc4)nc(-c4ccc(-c5ccccc5)cc4)n3)c3c(c2)oc2ccccc23)cc1] 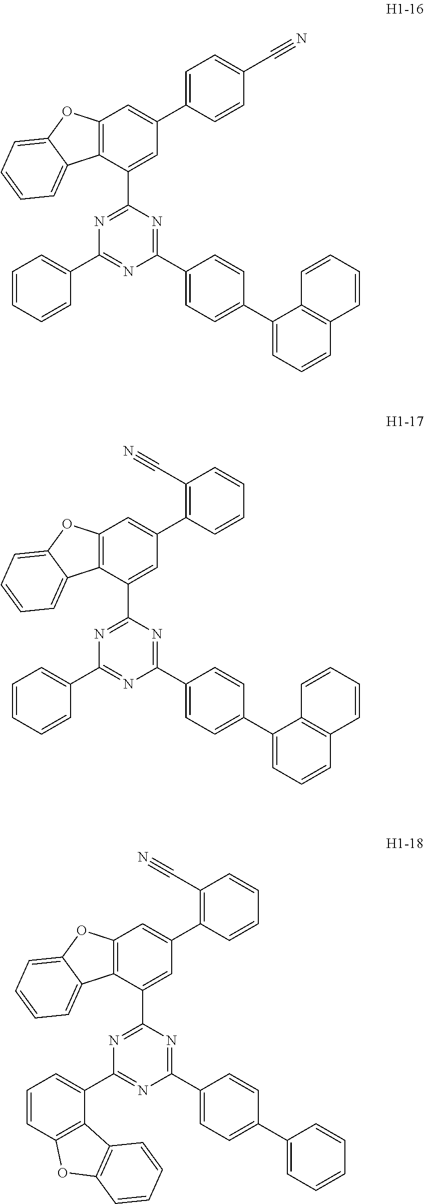 [SMILES: N#Cc1ccc(-c2cc(-c3nc(-c4ccccc4)nc(-c4ccc(-c5cccc6ccccc56)cc4)n3)c3c(c2)oc2ccccc23)cc1 ; N#Cc1ccccc1-c1cc(-c2nc(-c3ccccc3)nc(-c3ccc(-c4cccc5ccccc45)cc3)n2)c2c(c1)oc1ccccc12 ; N#Cc1ccccc1-c1cc(-c2nc(-c3ccc(-c4ccccc4)cc3)nc(-c3cccc4oc5ccccc5c34)n2)c2c(c1)oc1ccccc12] 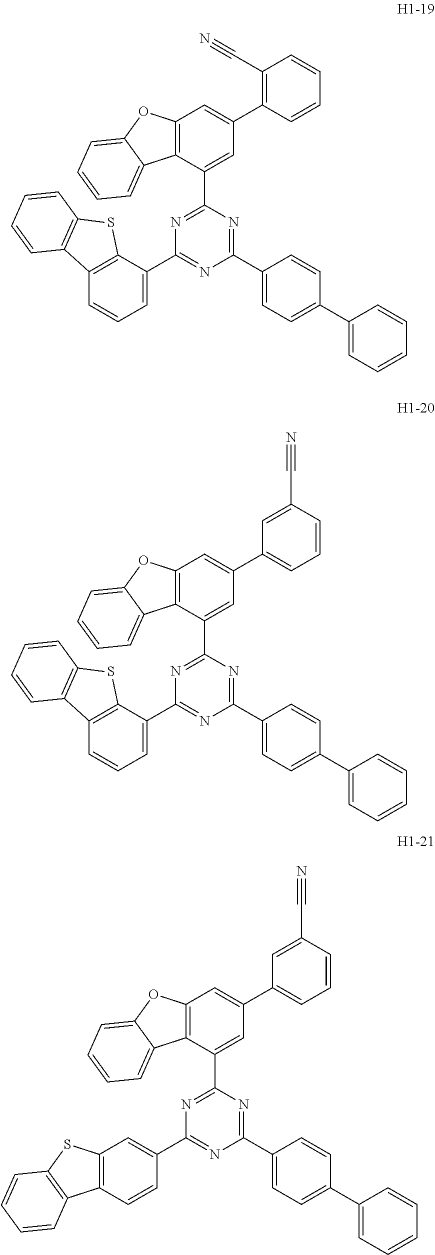 [SMILES: N#Cc1ccccc1-c1cc(-c2nc(-c3ccc(-c4ccccc4)cc3)nc(-c3cccc4c3sc3ccccc34)n2)c2c(c1)oc1ccccc12 ; N#Cc1cccc(-c2cc(-c3nc(-c4ccc(-c5ccccc5)cc4)nc(-c4cccc5c4sc4ccccc45)n3)c3c(c2)oc2ccccc23)c1 ; N#Cc1cccc(-c2cc(-c3nc(-c4ccc(-c5ccccc5)cc4)nc(-c4ccc5c(c4)sc4ccccc45)n3)c3c(c2)oc2ccccc23)c1] 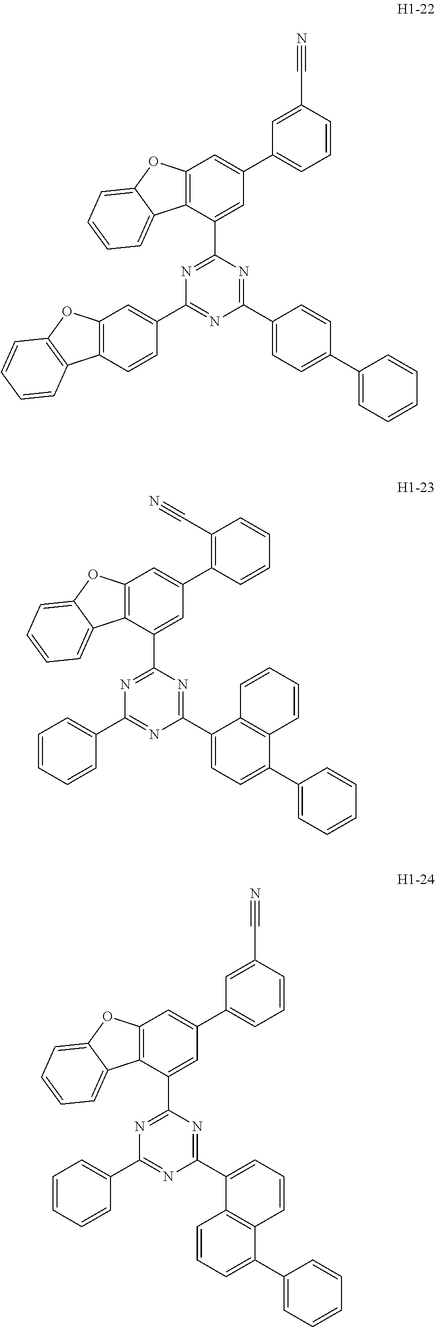 [SMILES: N#Cc1cccc(-c2cc(-c3nc(-c4ccc(-c5ccccc5)cc4)nc(-c4ccc5c(c4)oc4ccccc45)n3)c3c(c2)oc2ccccc23)c1 ; N#Cc1ccccc1-c1cc(-c2nc(-c3ccccc3)nc(-c3ccc(-c4ccccc4)c4ccccc34)n2)c2c(c1)oc1ccccc12 ; N#Cc1cccc(-c2cc(-c3nc(-c4ccccc4)nc(-c4cccc5c(-c6ccccc6)cccc45)n3)c3c(c2)oc2ccccc23)c1] 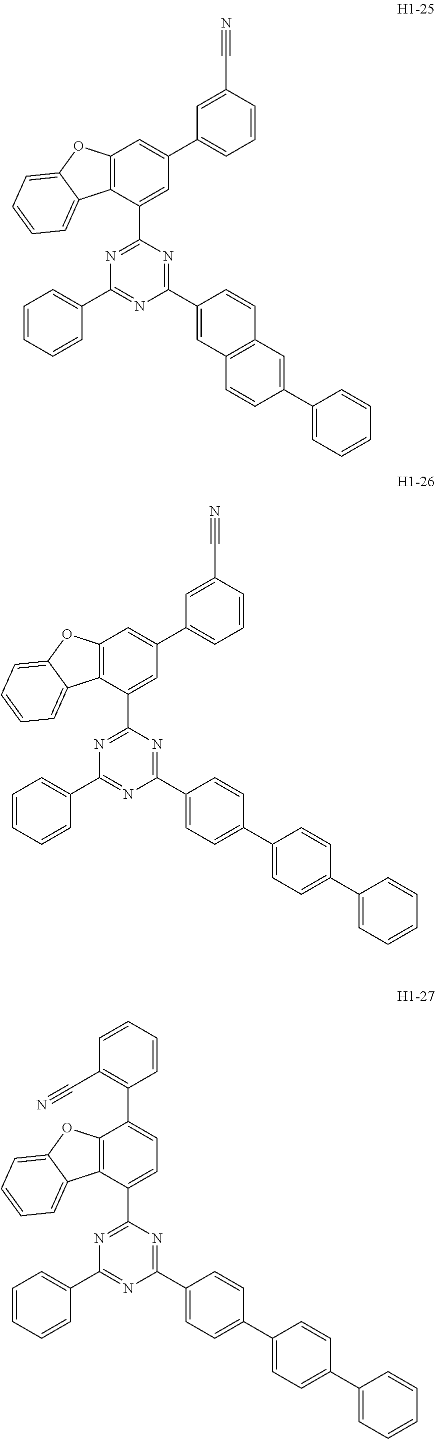 [SMILES: N#Cc1cccc(-c2cc(-c3nc(-c4ccccc4)nc(-c4ccc5cc(-c6ccccc6)ccc5c4)n3)c3c(c2)oc2ccccc23)c1 ; N#Cc1cccc(-c2cc(-c3nc(-c4ccccc4)nc(-c4ccc(-c5ccc(-c6ccccc6)cc5)cc4)n3)c3c(c2)oc2ccccc23)c1 ; N#Cc1ccccc1-c1ccc(-c2nc(-c3ccccc3)nc(-c3ccc(-c4ccc(-c5ccccc5)cc4)cc3)n2)c2c1oc1ccccc12] 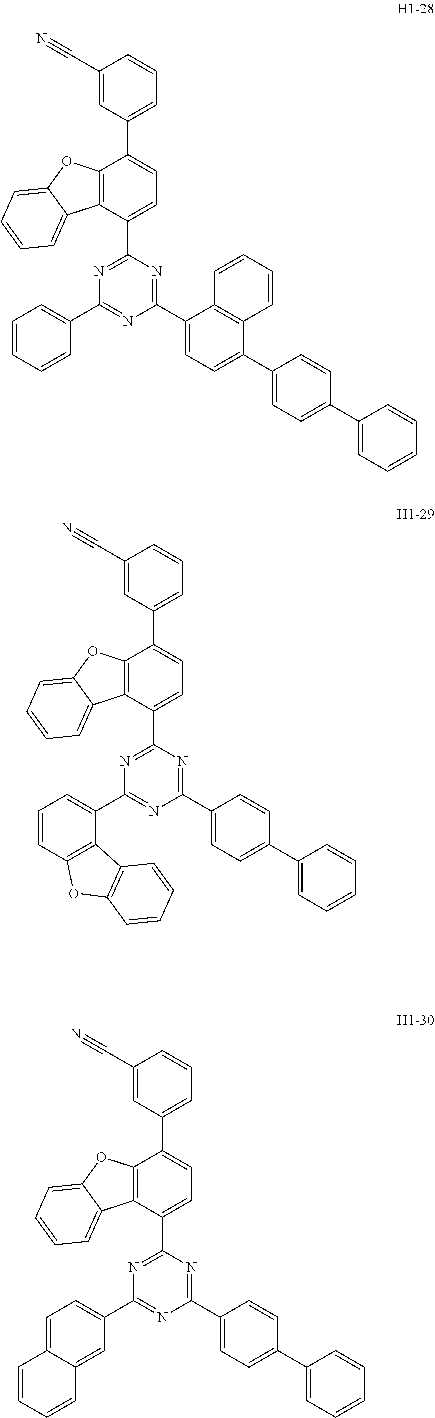 [SMILES: N#Cc1cccc(-c2ccc(-c3nc(-c4ccccc4)nc(-c4ccc(-c5ccc(-c6ccccc6)cc5)c5ccccc45)n3)c3c2oc2ccccc23)c1 ; N#Cc1cccc(-c2ccc(-c3nc(-c4ccc(-c5ccccc5)cc4)nc(-c4cccc5oc6ccccc6c45)n3)c3c2oc2ccccc23)c1 ; N#Cc1cccc(-c2ccc(-c3nc(-c4ccc(-c5ccccc5)cc4)nc(-c4ccc5ccccc5c4)n3)c3c2oc2ccccc23)c1] 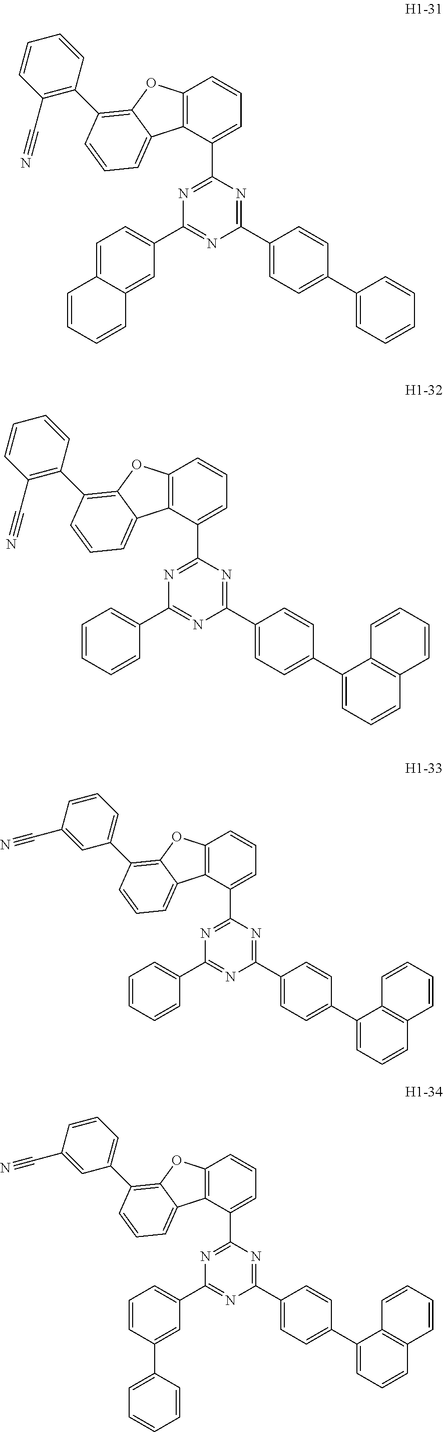 [SMILES: N#Cc1ccccc1-c1cccc2c1oc1cccc(-c3nc(-c4ccc(-c5ccccc5)cc4)nc(-c4ccc5ccccc5c4)n3)c12 ; N#Cc1ccccc1-c1cccc2c1oc1cccc(-c3nc(-c4ccccc4)nc(-c4ccc(-c5cccc6ccccc56)cc4)n3)c12 ; N#Cc1cccc(-c2cccc3c2oc2cccc(-c4nc(-c5ccccc5)nc(-c5ccc(-c6cccc7ccccc67)cc5)n4)c23)c1 ; N#Cc1cccc(-c2cccc3c2oc2cccc(-c4nc(-c5ccc(-c6cccc7ccccc67)cc5)nc(-c5cccc(-c6ccccc6)c5)n4)c23)c1] 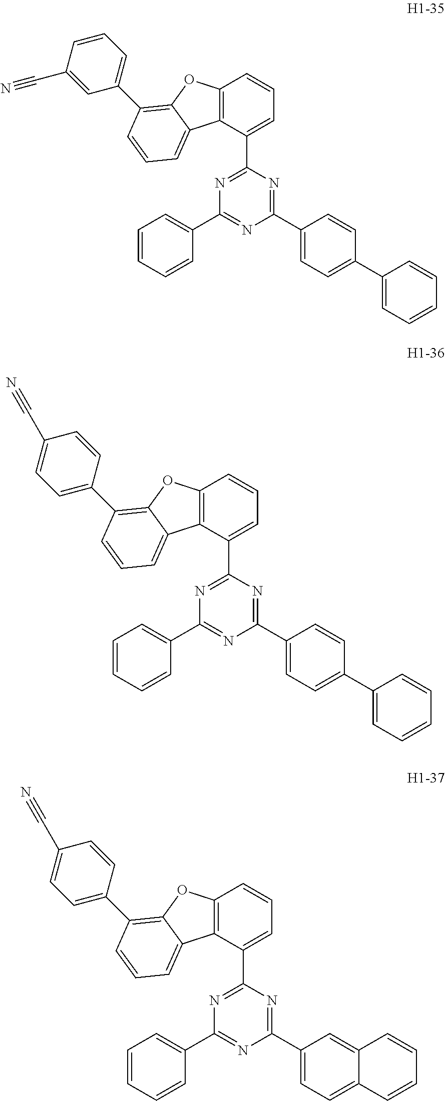 [SMILES: N#Cc1cccc(-c2cccc3c2oc2cccc(-c4nc(-c5ccccc5)nc(-c5ccc(-c6ccccc6)cc5)n4)c23)c1 ; N#Cc1ccc(-c2cccc3c2oc2cccc(-c4nc(-c5ccccc5)nc(-c5ccc(-c6ccccc6)cc5)n4)c23)cc1 ; N#Cc1ccc(-c2cccc3c2oc2cccc(-c4nc(-c5ccccc5)nc(-c5ccc6ccccc6c5)n4)c23)cc1] 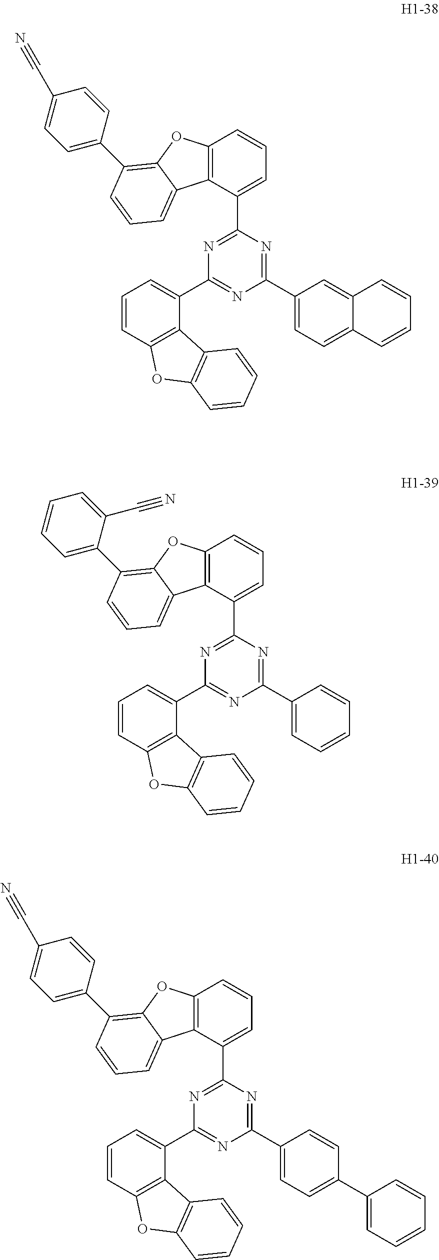 [SMILES: N#Cc1ccc(-c2cccc3c2oc2cccc(-c4nc(-c5ccc6ccccc6c5)nc(-c5cccc6oc7ccccc7c56)n4)c23)cc1 ; N#Cc1ccccc1-c1cccc2c1oc1cccc(-c3nc(-c4ccccc4)nc(-c4cccc5oc6ccccc6c45)n3)c12 ; N#Cc1ccc(-c2cccc3c2oc2cccc(-c4nc(-c5ccc(-c6ccccc6)cc5)nc(-c5cccc6oc7ccccc7c56)n4)c23)cc1] 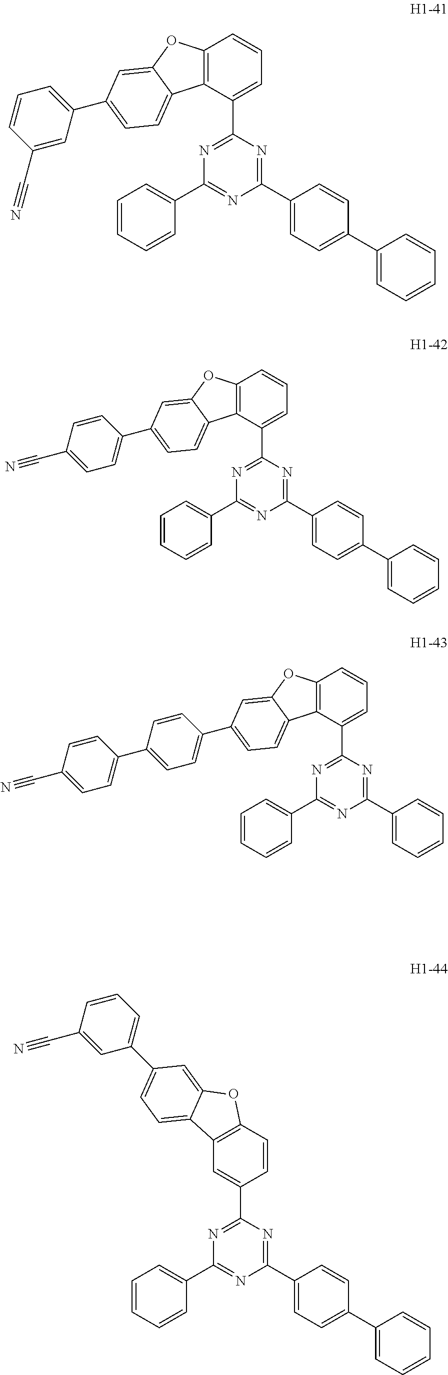 [SMILES: N#Cc1cccc(-c2ccc3c(c2)oc2cccc(-c4nc(-c5ccccc5)nc(-c5ccc(-c6ccccc6)cc5)n4)c23)c1 ; N#Cc1ccc(-c2ccc3c(c2)oc2cccc(-c4nc(-c5ccccc5)nc(-c5ccc(-c6ccccc6)cc5)n4)c23)cc1 ; N#Cc1ccc(-c2ccc(-c3ccc4c(c3)oc3cccc(-c5nc(-c6ccccc6)nc(-c6ccccc6)n5)c34)cc2)cc1 ; N#Cc1cccc(-c2ccc3c(c2)oc2ccc(-c4nc(-c5ccccc5)nc(-c5ccc(-c6ccccc6)cc5)n4)cc23)c1] 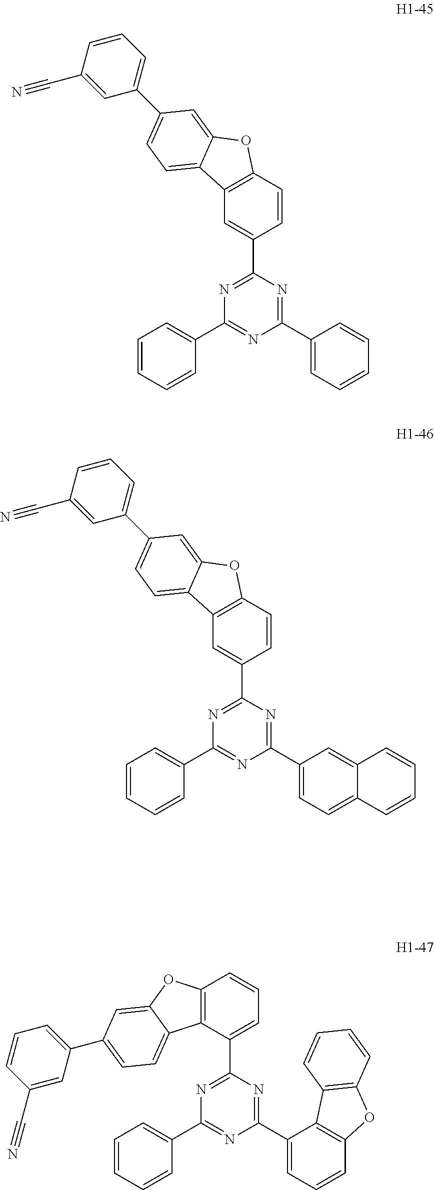 [SMILES: N#Cc1cccc(-c2ccc3c(c2)oc2ccc(-c4nc(-c5ccccc5)nc(-c5ccccc5)n4)cc23)c1 ; N#Cc1cccc(-c2ccc3c(c2)oc2ccc(-c4nc(-c5ccccc5)nc(-c5ccc6ccccc6c5)n4)cc23)c1 ; N#Cc1cccc(-c2ccc3c(c2)oc2cccc(-c4nc(-c5ccccc5)nc(-c5cccc6oc7ccccc7c56)n4)c23)c1] 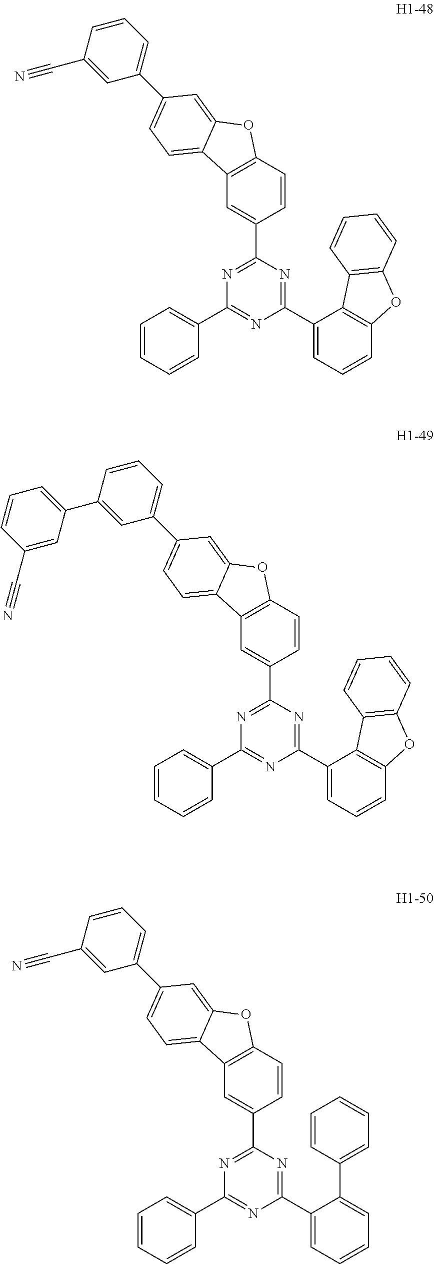 [SMILES: N#Cc1cccc(-c2ccc3c(c2)oc2ccc(-c4nc(-c5ccccc5)nc(-c5cccc6oc7ccccc7c56)n4)cc23)c1 ; N#Cc1cccc(-c2cccc(-c3ccc4c(c3)oc3ccc(-c5nc(-c6ccccc6)nc(-c6cccc7oc8ccccc8c67)n5)cc34)c2)c1 ; N#Cc1cccc(-c2ccc3c(c2)oc2ccc(-c4nc(-c5ccccc5)nc(-c5ccccc5-c5ccccc5)n4)cc23)c1] 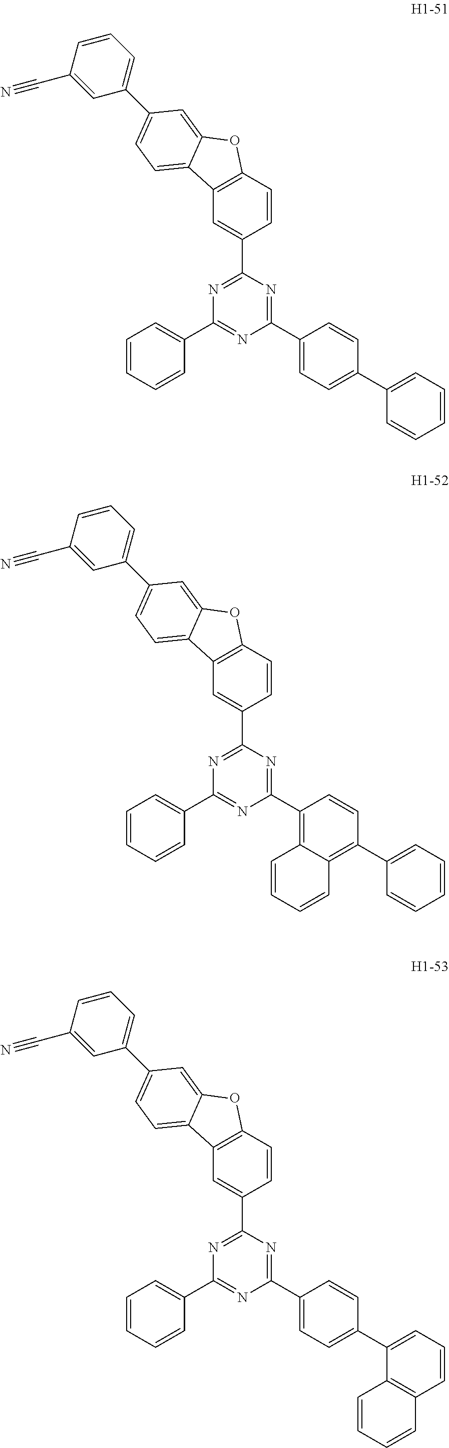 [SMILES: N#Cc1cccc(-c2ccc3c(c2)oc2ccc(-c4nc(-c5ccccc5)nc(-c5ccc(-c6ccccc6)cc5)n4)cc23)c1 ; N#Cc1cccc(-c2ccc3c(c2)oc2ccc(-c4nc(-c5ccccc5)nc(-c5ccc(-c6ccccc6)c6ccccc56)n4)cc23)c1 ; N#Cc1cccc(-c2ccc3c(c2)oc2ccc(-c4nc(-c5ccccc5)nc(-c5ccc(-c6cccc7ccccc67)cc5)n4)cc23)c1] 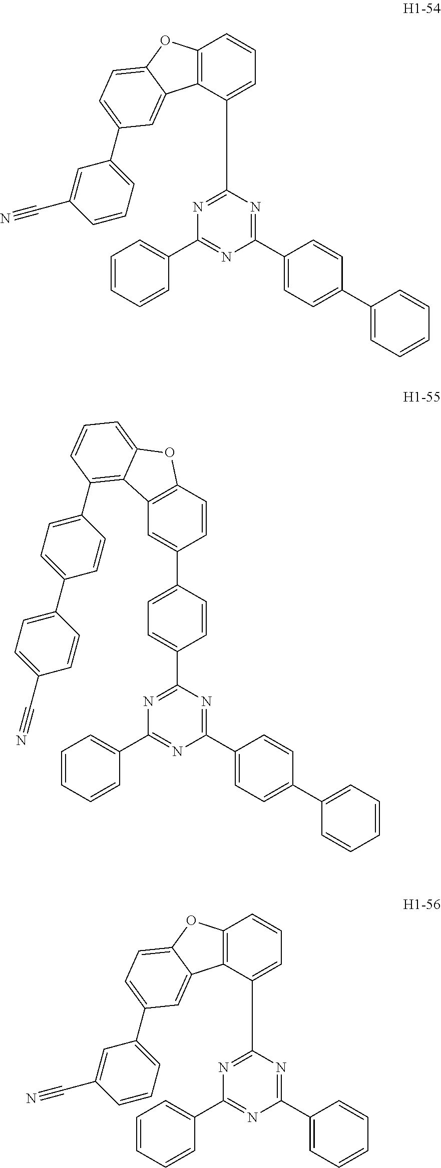 [SMILES: N#Cc1cccc(-c2ccc3oc4cccc(-c5nc(-c6ccccc6)nc(-c6ccc(-c7ccccc7)cc6)n5)c4c3c2)c1 ; N#Cc1ccc(-c2ccc(-c3cccc4oc5ccc(-c6ccc(-c7nc(-c8ccccc8)nc(-c8ccc(-c9ccccc9)cc8)n7)cc6)cc5c34)cc2)cc1 ; N#Cc1cccc(-c2ccc3oc4cccc(-c5nc(-c6ccccc6)nc(-c6ccccc6)n5)c4c3c2)c1] 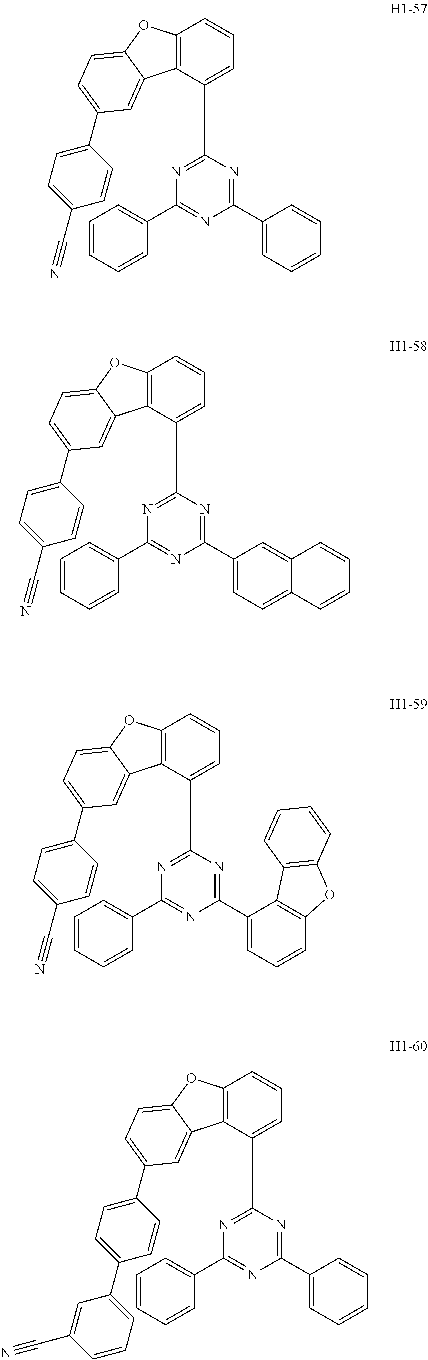 [SMILES: N#Cc1ccc(-c2ccc3oc4cccc(-c5nc(-c6ccccc6)nc(-c6ccccc6)n5)c4c3c2)cc1 ; N#Cc1ccc(-c2ccc3oc4cccc(-c5nc(-c6ccccc6)nc(-c6ccc7ccccc7c6)n5)c4c3c2)cc1 ; N#Cc1ccc(-c2ccc3oc4cccc(-c5nc(-c6ccccc6)nc(-c6cccc7oc8ccccc8c67)n5)c4c3c2)cc1 ; N#Cc1cccc(-c2ccc(-c3ccc4oc5cccc(-c6nc(-c7ccccc7)nc(-c7ccccc7)n6)c5c4c3)cc2)c1] 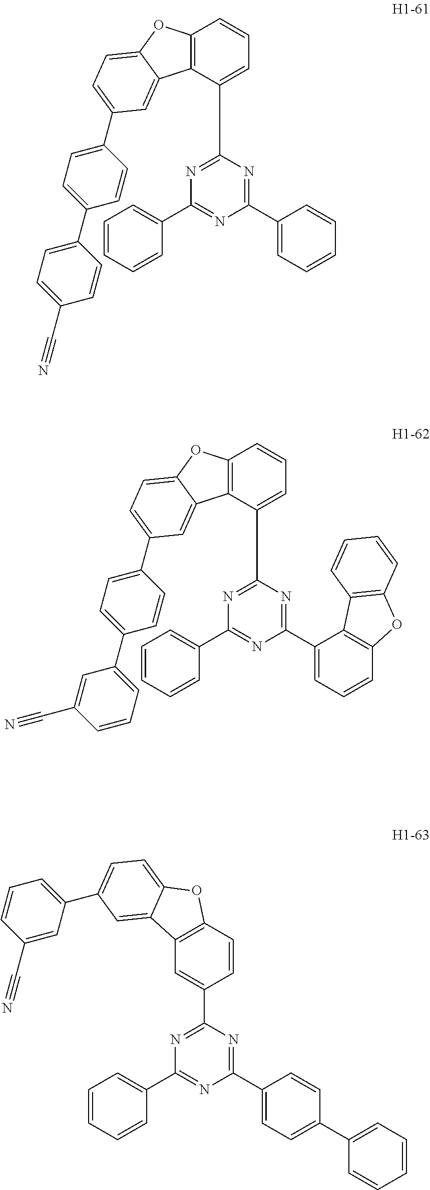 [SMILES: N#Cc1ccc(-c2ccc(-c3ccc4oc5cccc(-c6nc(-c7ccccc7)nc(-c7ccccc7)n6)c5c4c3)cc2)cc1 ; N#Cc1cccc(-c2ccc(-c3ccc4oc5cccc(-c6nc(-c7ccccc7)nc(-c7cccc8oc9ccccc9c78)n6)c5c4c3)cc2)c1 ; N#Cc1cccc(-c2ccc3oc4ccc(-c5nc(-c6ccccc6)nc(-c6ccc(-c7ccccc7)cc6)n5)cc4c3c2)c1] 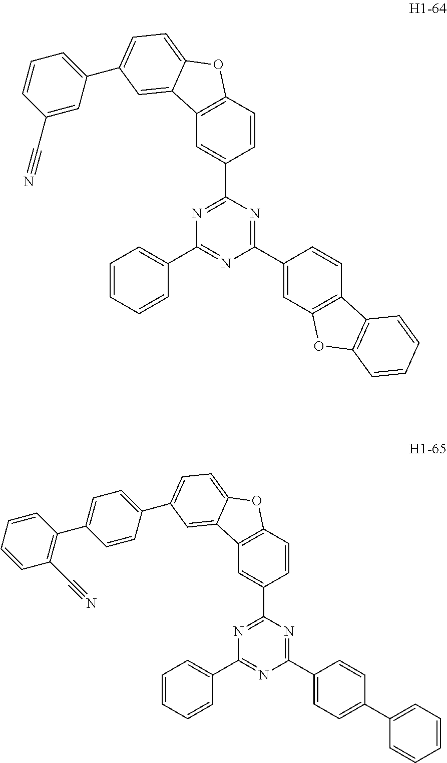 [SMILES: N#Cc1cccc(-c2ccc3oc4ccc(-c5nc(-c6ccccc6)nc(-c6ccc7c(c6)oc6ccccc67)n5)cc4c3c2)c1 ; N#Cc1ccccc1-c1ccc(-c2ccc3oc4ccc(-c5nc(-c6ccccc6)nc(-c6ccc(-c7ccccc7)cc6)n5)cc4c3c2)cc1] 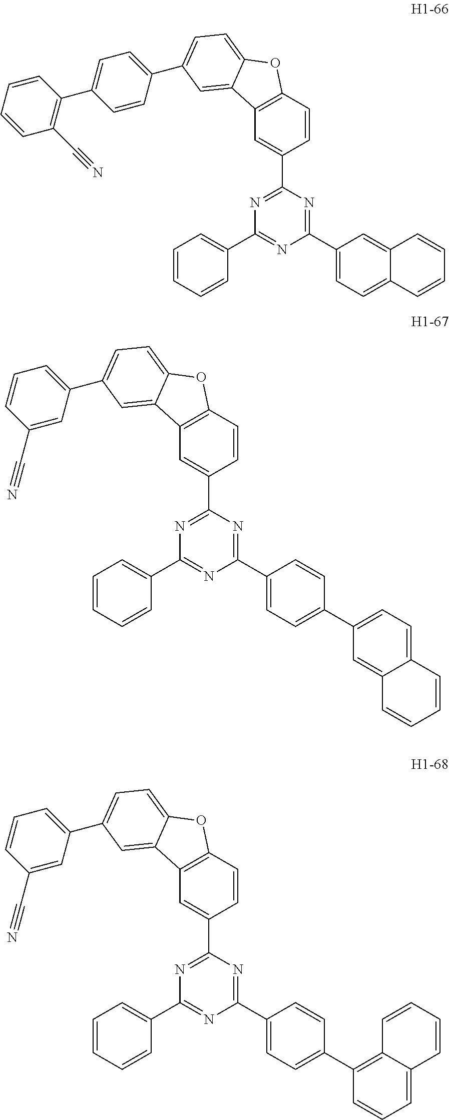 [SMILES: N#Cc1ccccc1-c1ccc(-c2ccc3oc4ccc(-c5nc(-c6ccccc6)nc(-c6ccc7ccccc7c6)n5)cc4c3c2)cc1 ; N#Cc1cccc(-c2ccc3oc4ccc(-c5nc(-c6ccccc6)nc(-c6ccc(-c7ccc8ccccc8c7)cc6)n5)cc4c3c2)c1 ; N#Cc1cccc(-c2ccc3oc4ccc(-c5nc(-c6ccccc6)nc(-c6ccc(-c7cccc8ccccc78)cc6)n5)cc4c3c2)c1] 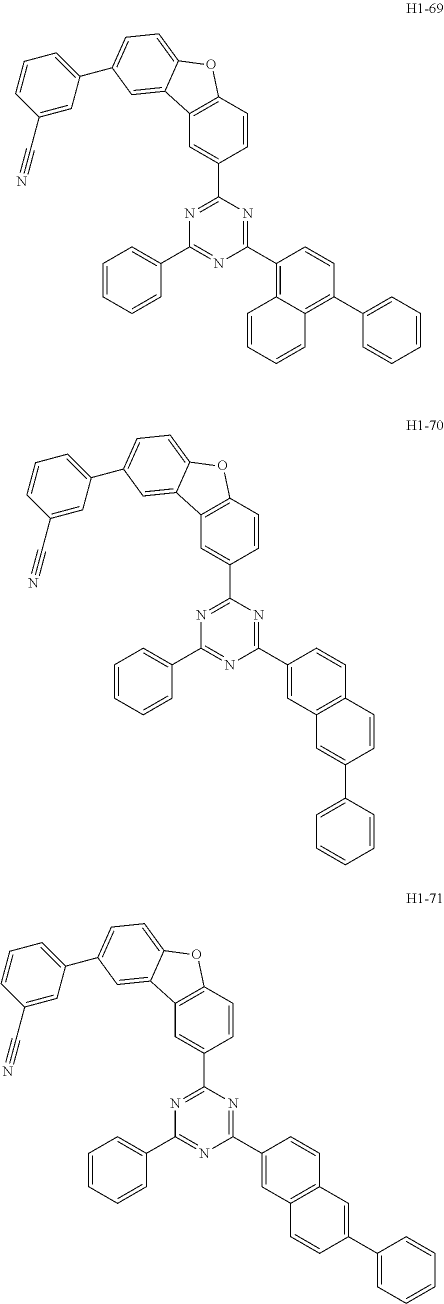 [SMILES: N#Cc1cccc(-c2ccc3oc4ccc(-c5nc(-c6ccccc6)nc(-c6ccc(-c7ccccc7)c7ccccc67)n5)cc4c3c2)c1 ; N#Cc1cccc(-c2ccc3oc4ccc(-c5nc(-c6ccccc6)nc(-c6ccc7ccc(-c8ccccc8)cc7c6)n5)cc4c3c2)c1 ; N#Cc1cccc(-c2ccc3oc4ccc(-c5nc(-c6ccccc6)nc(-c6ccc7cc(-c8ccccc8)ccc7c6)n5)cc4c3c2)c1] 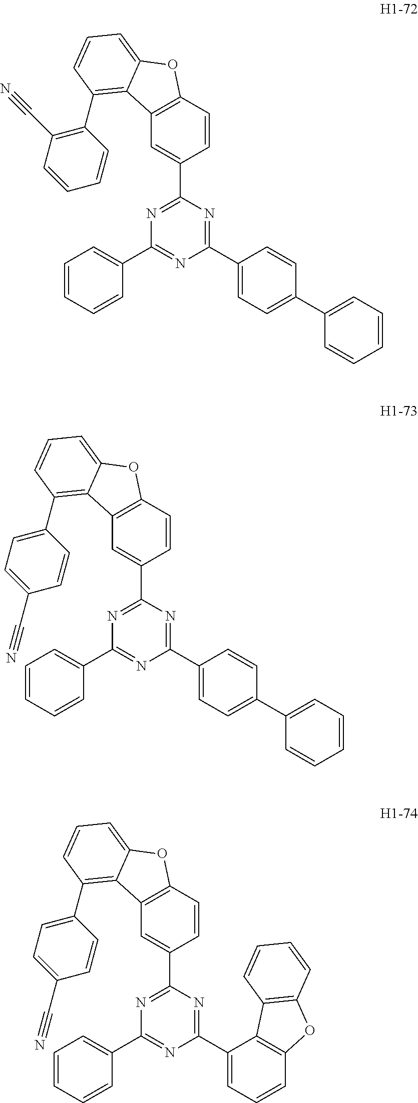 [SMILES: N#Cc1ccccc1-c1cccc2oc3ccc(-c4nc(-c5ccccc5)nc(-c5ccc(-c6ccccc6)cc5)n4)cc3c12 ; N#Cc1ccc(-c2cccc3oc4ccc(-c5nc(-c6ccccc6)nc(-c6ccc(-c7ccccc7)cc6)n5)cc4c23)cc1 ; N#Cc1ccc(-c2cccc3oc4ccc(-c5nc(-c6ccccc6)nc(-c6cccc7oc8ccccc8c67)n5)cc4c23)cc1] 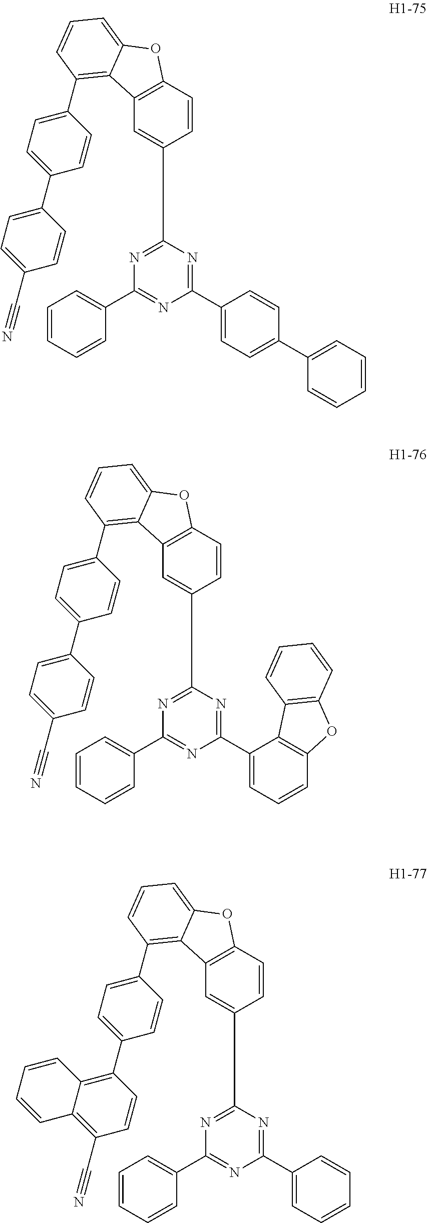 [SMILES: N#Cc1ccc(-c2ccc(-c3cccc4oc5ccc(-c6nc(-c7ccccc7)nc(-c7ccc(-c8ccccc8)cc7)n6)cc5c34)cc2)cc1 ; N#Cc1ccc(-c2ccc(-c3cccc4oc5ccc(-c6nc(-c7ccccc7)nc(-c7cccc8oc9ccccc9c78)n6)cc5c34)cc2)cc1 ; N#Cc1ccc(-c2ccc(-c3cccc4oc5ccc(-c6nc(-c7ccccc7)nc(-c7ccccc7)n6)cc5c34)cc2)c2ccccc12] 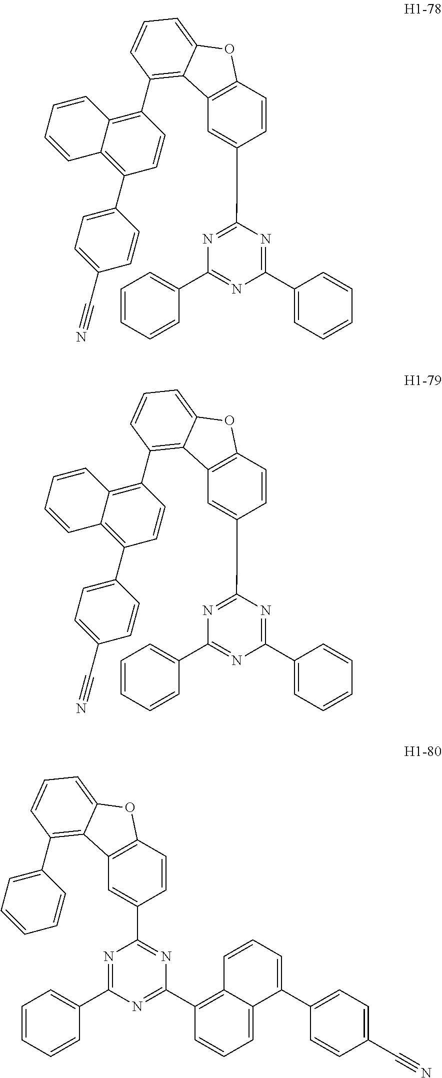 [SMILES: N#Cc1ccc(-c2ccc(-c3cccc4oc5ccc(-c6nc(-c7ccccc7)nc(-c7ccccc7)n6)cc5c34)c3ccccc23)cc1 ; N#Cc1ccc(-c2ccc(-c3cccc4oc5ccc(-c6nc(-c7ccccc7)nc(-c7ccccc7)n6)cc5c34)c3ccccc23)cc1 ; N#Cc1ccc(-c2cccc3c(-c4nc(-c5ccccc5)nc(-c5ccc6oc7cccc(-c8ccccc8)c7c6c5)n4)cccc23)cc1] 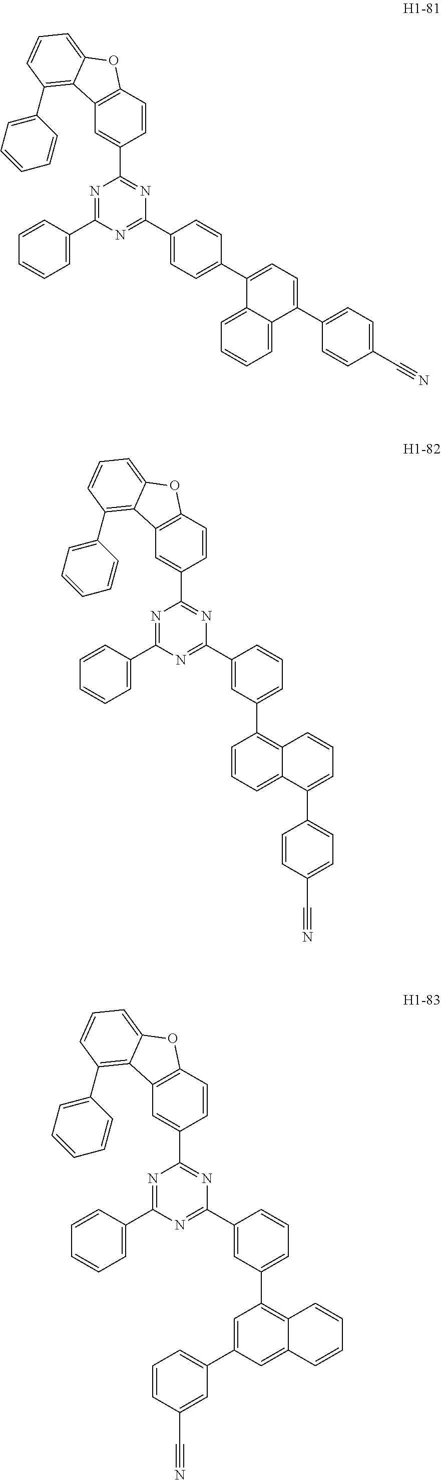 [SMILES: N#Cc1ccc(-c2ccc(-c3ccc(-c4nc(-c5ccccc5)nc(-c5ccc6oc7cccc(-c8ccccc8)c7c6c5)n4)cc3)c3ccccc23)cc1 ; N#Cc1ccc(-c2cccc3c(-c4cccc(-c5nc(-c6ccccc6)nc(-c6ccc7oc8cccc(-c9ccccc9)c8c7c6)n5)c4)cccc23)cc1 ; N#Cc1cccc(-c2cc(-c3cccc(-c4nc(-c5ccccc5)nc(-c5ccc6oc7cccc(-c8ccccc8)c7c6c5)n4)c3)c3ccccc3c2)c1] 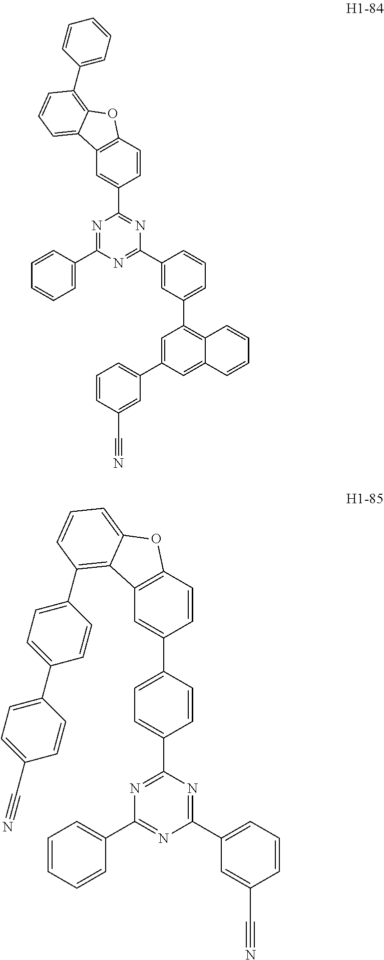 [SMILES: N#Cc1cccc(-c2cc(-c3cccc(-c4nc(-c5ccccc5)nc(-c5ccc6oc7c(-c8ccccc8)cccc7c6c5)n4)c3)c3ccccc3c2)c1 ; N#Cc1ccc(-c2ccc(-c3cccc4oc5ccc(-c6ccc(-c7nc(-c8ccccc8)nc(-c8cccc(C#N)c8)n7)cc6)cc5c34)cc2)cc1] 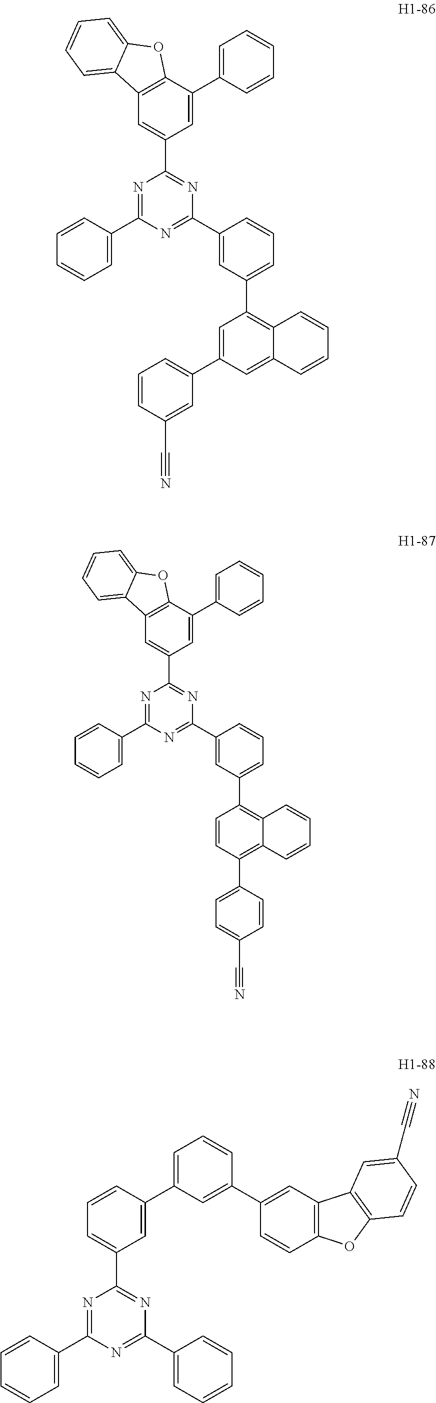 [SMILES: N#Cc1cccc(-c2cc(-c3cccc(-c4nc(-c5ccccc5)nc(-c5cc(-c6ccccc6)c6oc7ccccc7c6c5)n4)c3)c3ccccc3c2)c1 ; N#Cc1ccc(-c2ccc(-c3cccc(-c4nc(-c5ccccc5)nc(-c5cc(-c6ccccc6)c6oc7ccccc7c6c5)n4)c3)c3ccccc23)cc1 ; N#Cc1ccc2oc3ccc(-c4cccc(-c5cccc(-c6nc(-c7ccccc7)nc(-c7ccccc7)n6)c5)c4)cc3c2c1] 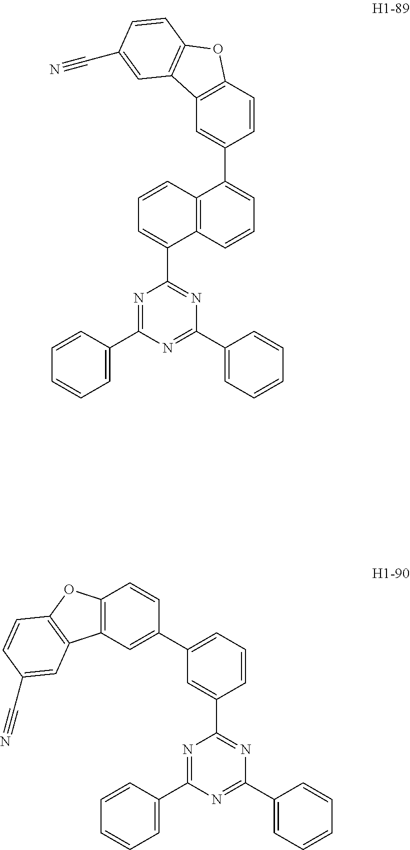 [SMILES: N#Cc1ccc2oc3ccc(-c4cccc5c(-c6nc(-c7ccccc7)nc(-c7ccccc7)n6)cccc45)cc3c2c1 ; N#Cc1ccc2oc3ccc(-c4cccc(-c5nc(-c6ccccc6)nc(-c6ccccc6)n5)c4)cc3c2c1] 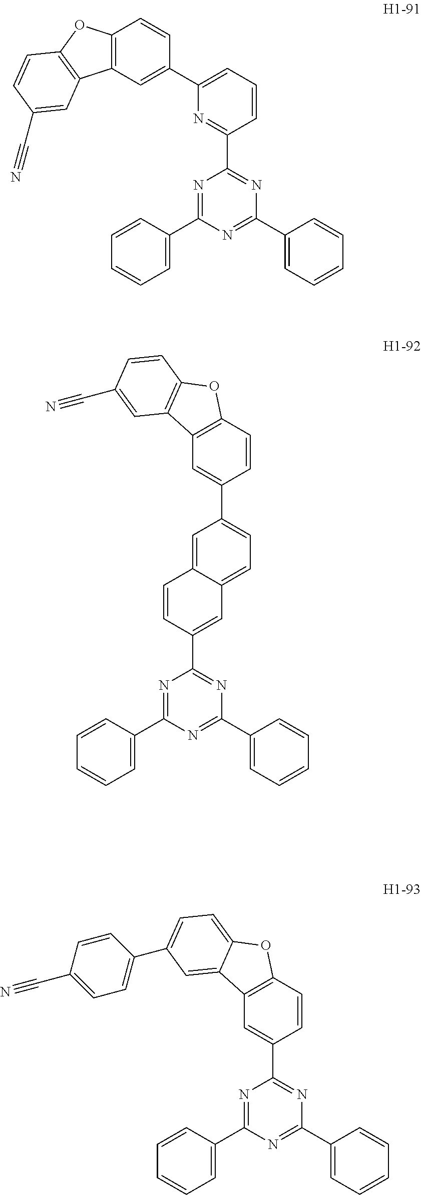 [SMILES: N#Cc1ccc2oc3ccc(-c4cccc(-c5nc(-c6ccccc6)nc(-c6ccccc6)n5)n4)cc3c2c1 ; N#Cc1ccc2oc3ccc(-c4ccc5cc(-c6nc(-c7ccccc7)nc(-c7ccccc7)n6)ccc5c4)cc3c2c1 ; N#Cc1ccc(-c2ccc3oc4ccc(-c5nc(-c6ccccc6)nc(-c6ccccc6)n5)cc4c3c2)cc1] 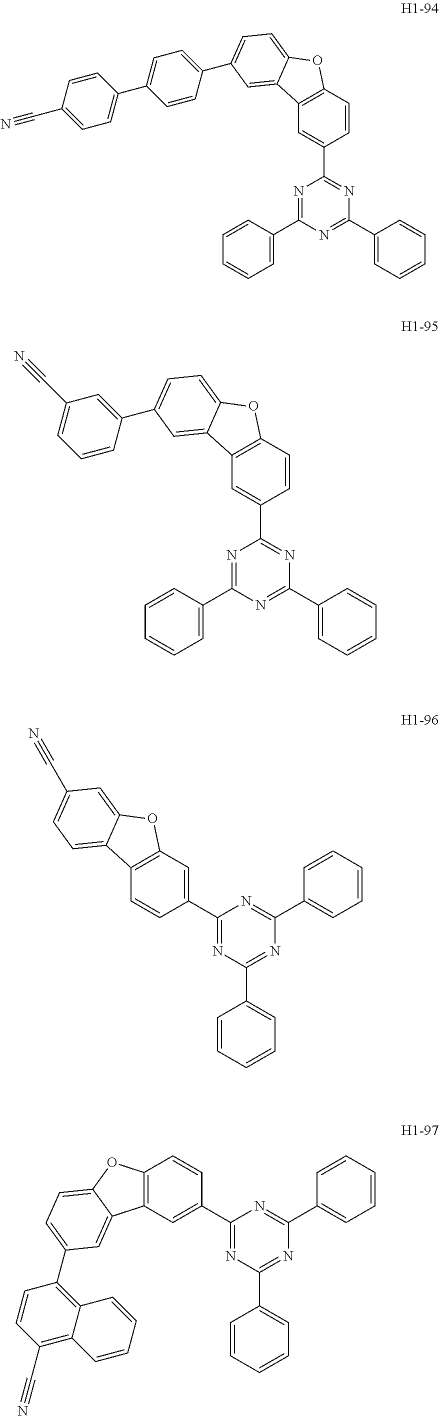 [SMILES: N#Cc1ccc(-c2ccc(-c3ccc4oc5ccc(-c6nc(-c7ccccc7)nc(-c7ccccc7)n6)cc5c4c3)cc2)cc1 ; N#Cc1cccc(-c2ccc3oc4ccc(-c5nc(-c6ccccc6)nc(-c6ccccc6)n5)cc4c3c2)c1 ; N#Cc1ccc2c(c1)oc1cc(-c3nc(-c4ccccc4)nc(-c4ccccc4)n3)ccc12 ; N#Cc1ccc(-c2ccc3oc4ccc(-c5nc(-c6ccccc6)nc(-c6ccccc6)n5)cc4c3c2)c2ccccc12] 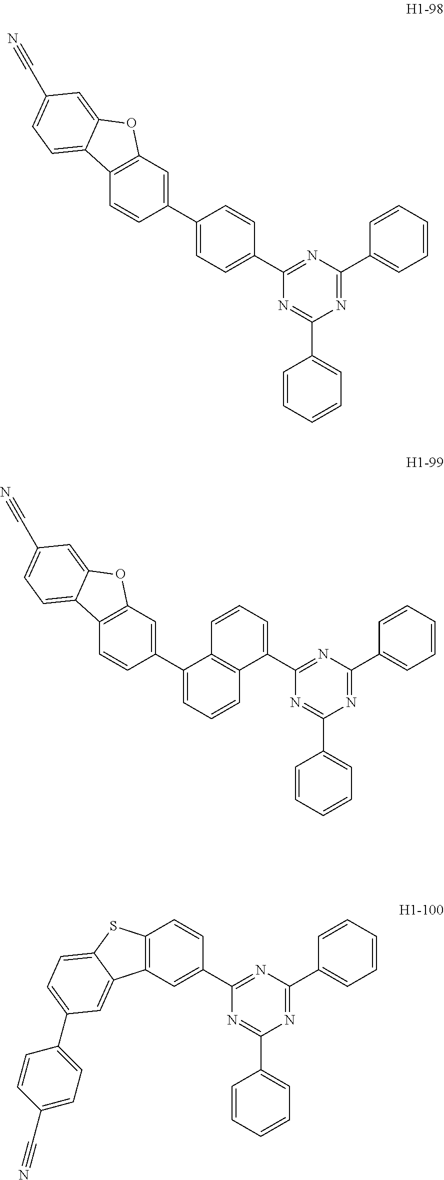 [SMILES: N#Cc1ccc2c(c1)oc1cc(-c3ccc(-c4nc(-c5ccccc5)nc(-c5ccccc5)n4)cc3)ccc12 ; N#Cc1ccc2c(c1)oc1cc(-c3cccc4c(-c5nc(-c6ccccc6)nc(-c6ccccc6)n5)cccc34)ccc12 ; N#Cc1ccc(-c2ccc3sc4ccc(-c5nc(-c6ccccc6)nc(-c6ccccc6)n5)cc4c3c2)cc1] 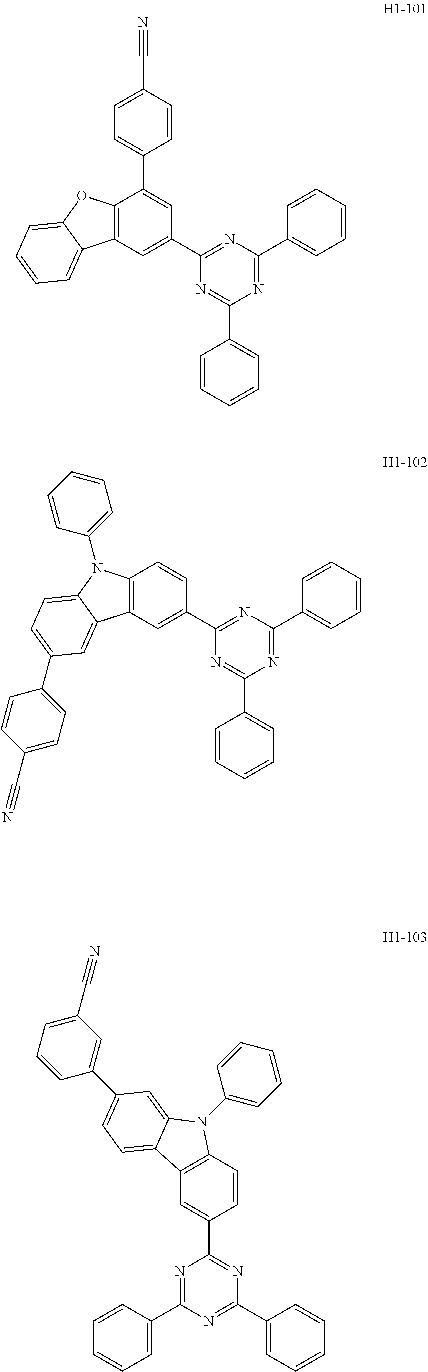 [SMILES: N#Cc1ccc(-c2cc(-c3nc(-c4ccccc4)nc(-c4ccccc4)n3)cc3c2oc2ccccc23)cc1 ; N#Cc1ccc(-c2ccc3c(c2)c2cc(-c4nc(-c5ccccc5)nc(-c5ccccc5)n4)ccc2n3-c2ccccc2)cc1 ; N#Cc1cccc(-c2ccc3c4cc(-c5nc(-c6ccccc6)nc(-c6ccccc6)n5)ccc4n(-c4ccccc4)c3c2)c1] 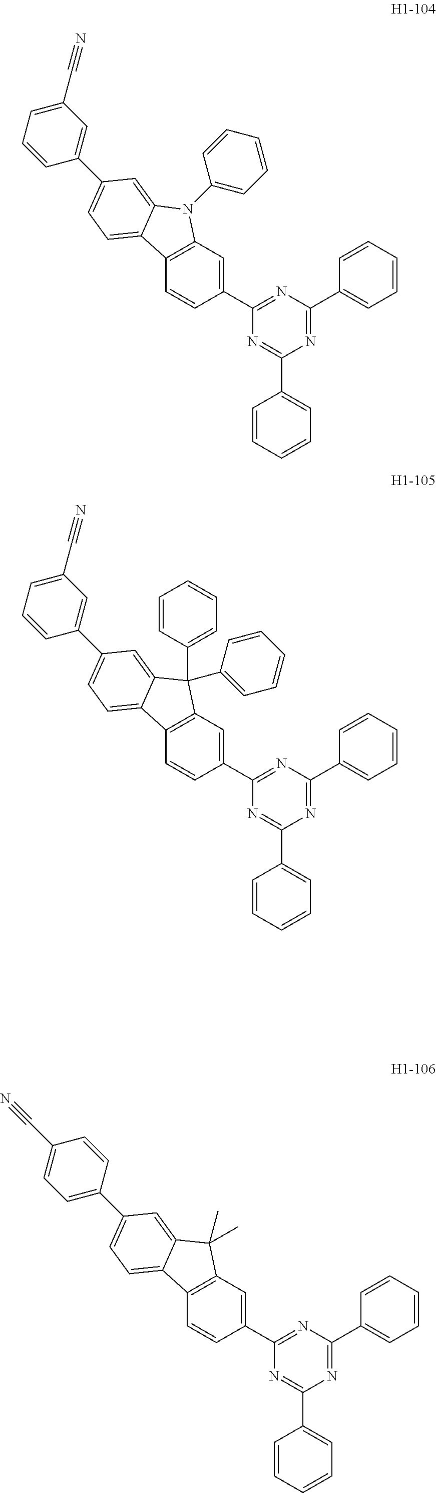 [SMILES: N#Cc1cccc(-c2ccc3c4ccc(-c5nc(-c6ccccc6)nc(-c6ccccc6)n5)cc4n(-c4ccccc4)c3c2)c1 ; N#Cc1cccc(-c2ccc3c(c2)C(c2ccccc2)(c2ccccc2)c2cc(-c4nc(-c5ccccc5)nc(-c5ccccc5)n4)ccc2-3)c1 ; CC1(C)c2cc(-c3ccc(C#N)cc3)ccc2-c2ccc(-c3nc(-c4ccccc4)nc(-c4ccccc4)n3)cc21] 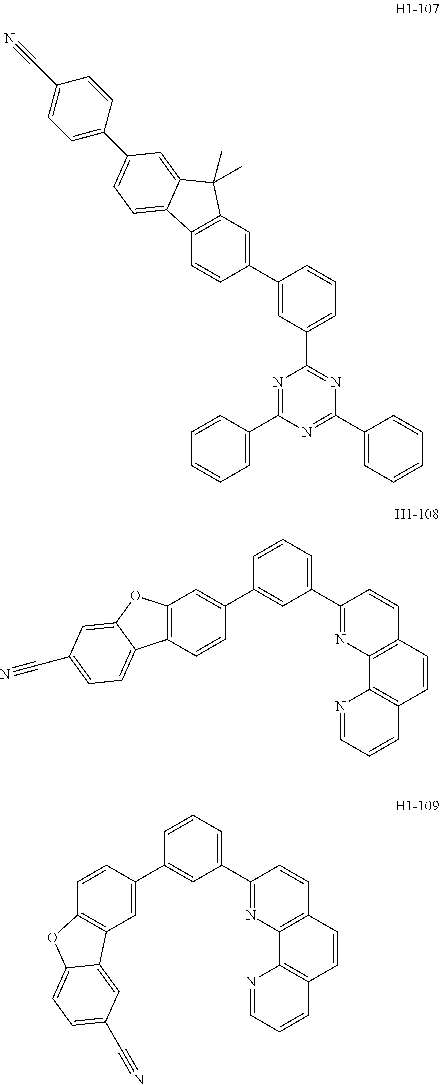 [SMILES: CC1(C)c2cc(-c3ccc(C#N)cc3)ccc2-c2ccc(-c3cccc(-c4nc(-c5ccccc5)nc(-c5ccccc5)n4)c3)cc21 ; N#Cc1ccc2c(c1)oc1cc(-c3cccc(-c4ccc5ccc6cccnc6c5n4)c3)ccc12 ; N#Cc1ccc2oc3ccc(-c4cccc(-c5ccc6ccc7cccnc7c6n5)c4)cc3c2c1] 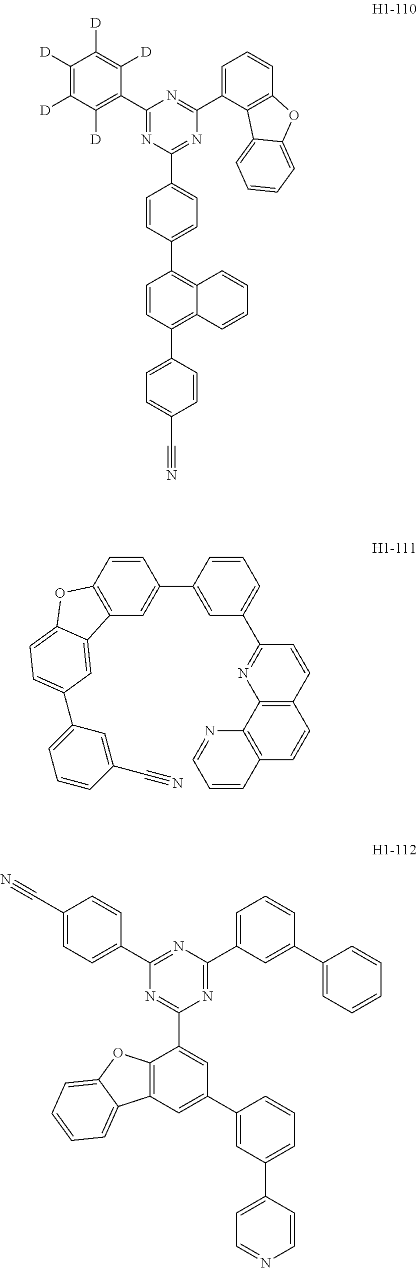 [SMILES: [2H]c1c([2H])c([2H])c(-c2nc(-c3ccc(-c4ccc(-c5ccc(C#N)cc5)c5ccccc45)cc3)nc(-c3cccc4oc5ccccc5c34)n2)c([2H])c1[2H] ; N#Cc1cccc(-c2ccc3oc4ccc(-c5cccc(-c6ccc7ccc8cccnc8c7n6)c5)cc4c3c2)c1 ; N#Cc1ccc(-c2nc(-c3cccc(-c4ccccc4)c3)nc(-c3cc(-c4cccc(-c5ccncc5)c4)cc4c3oc3ccccc34)n2)cc1] 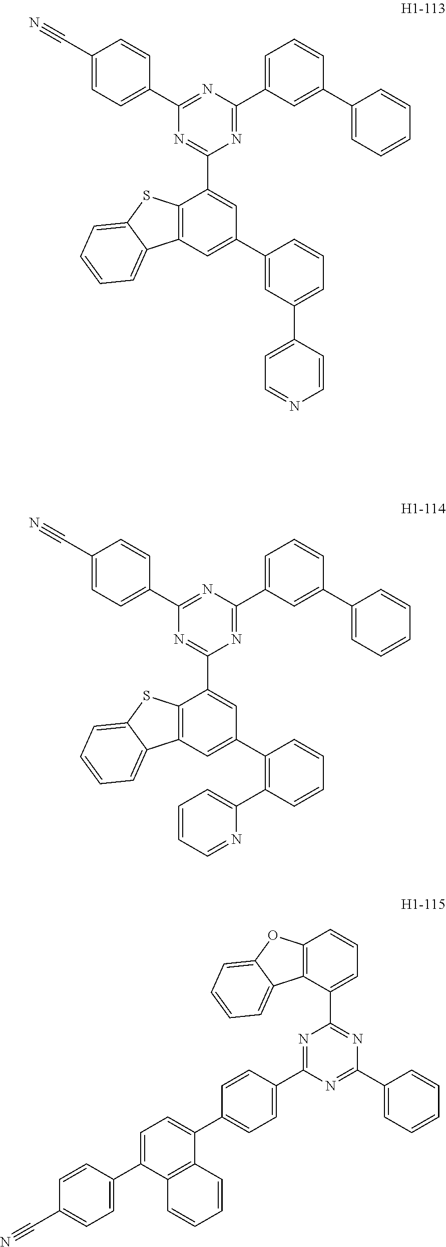 [SMILES: N#Cc1ccc(-c2nc(-c3cccc(-c4ccccc4)c3)nc(-c3cc(-c4cccc(-c5ccncc5)c4)cc4c3sc3ccccc34)n2)cc1 ; N#Cc1ccc(-c2nc(-c3cccc(-c4ccccc4)c3)nc(-c3cc(-c4ccccc4-c4ccccn4)cc4c3sc3ccccc34)n2)cc1 ; N#Cc1ccc(-c2ccc(-c3ccc(-c4nc(-c5ccccc5)nc(-c5cccc6oc7ccccc7c56)n4)cc3)c3ccccc23)cc1] 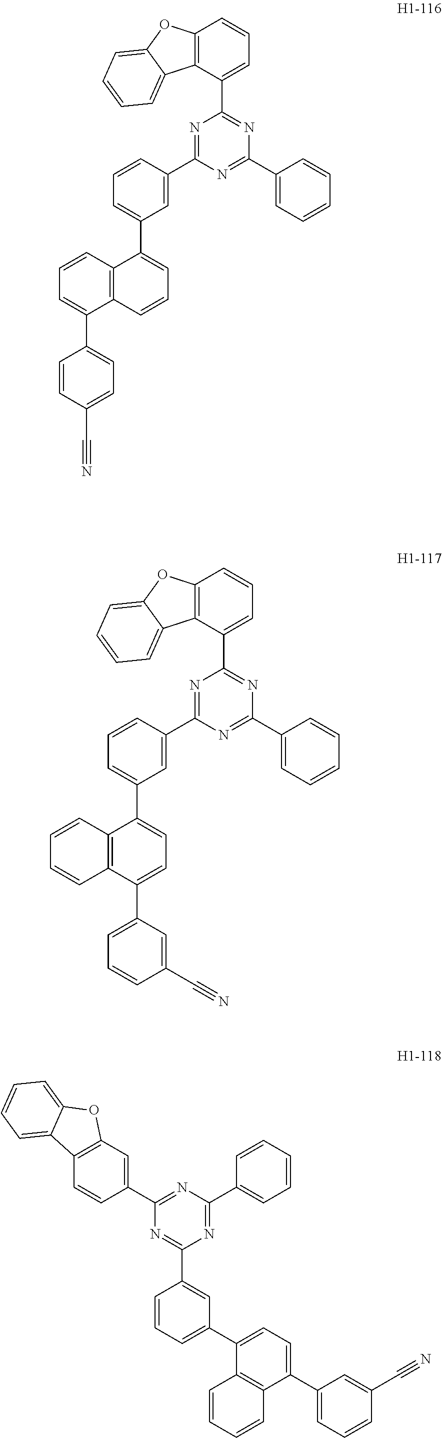 [SMILES: N#Cc1ccc(-c2cccc3c(-c4cccc(-c5nc(-c6ccccc6)nc(-c6cccc7oc8ccccc8c67)n5)c4)cccc23)cc1 ; N#Cc1cccc(-c2ccc(-c3cccc(-c4nc(-c5ccccc5)nc(-c5cccc6oc7ccccc7c56)n4)c3)c3ccccc23)c1 ; N#Cc1cccc(-c2ccc(-c3cccc(-c4nc(-c5ccccc5)nc(-c5ccc6c(c5)oc5ccccc56)n4)c3)c3ccccc23)c1] 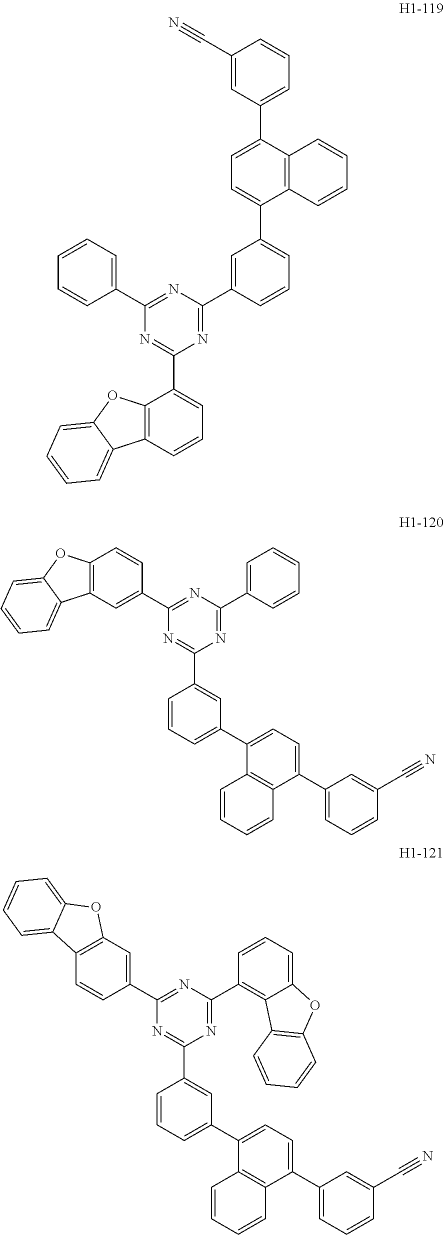 [SMILES: N#Cc1cccc(-c2ccc(-c3cccc(-c4nc(-c5ccccc5)nc(-c5cccc6c5oc5ccccc56)n4)c3)c3ccccc23)c1 ; N#Cc1cccc(-c2ccc(-c3cccc(-c4nc(-c5ccccc5)nc(-c5ccc6oc7ccccc7c6c5)n4)c3)c3ccccc23)c1 ; N#Cc1cccc(-c2ccc(-c3cccc(-c4nc(-c5ccc6c(c5)oc5ccccc56)nc(-c5cccc6oc7ccccc7c56)n4)c3)c3ccccc23)c1] 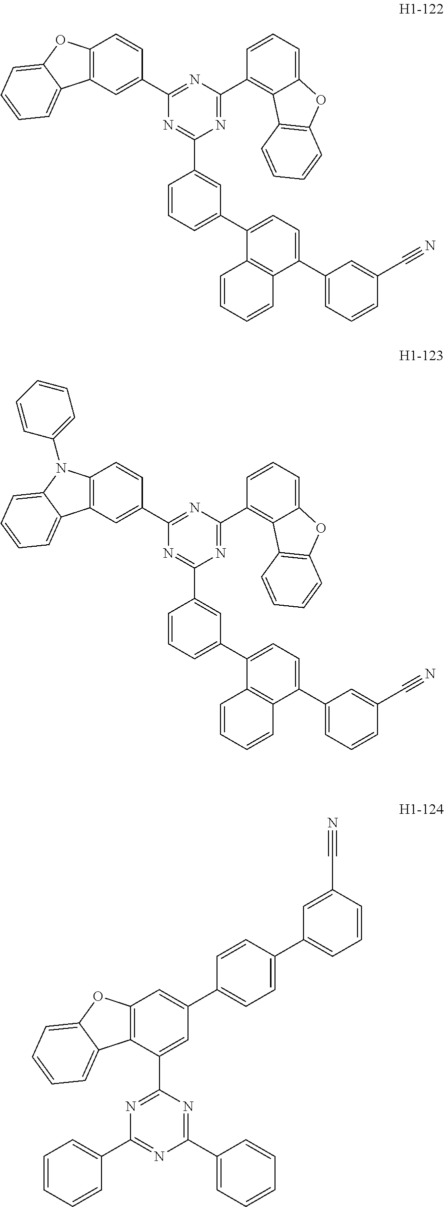 [SMILES: N#Cc1cccc(-c2ccc(-c3cccc(-c4nc(-c5ccc6oc7ccccc7c6c5)nc(-c5cccc6oc7ccccc7c56)n4)c3)c3ccccc23)c1 ; N#Cc1cccc(-c2ccc(-c3cccc(-c4nc(-c5ccc6c(c5)c5ccccc5n6-c5ccccc5)nc(-c5cccc6oc7ccccc7c56)n4)c3)c3ccccc23)c1 ; N#Cc1cccc(-c2ccc(-c3cc(-c4nc(-c5ccccc5)nc(-c5ccccc5)n4)c4c(c3)oc3ccccc34)cc2)c1] 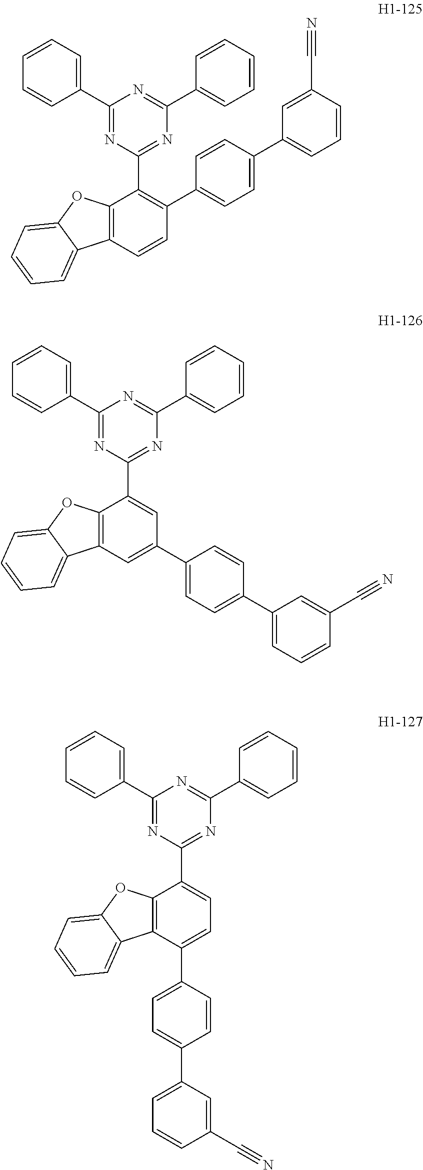 [SMILES: N#Cc1cccc(-c2ccc(-c3ccc4c(oc5ccccc54)c3-c3nc(-c4ccccc4)nc(-c4ccccc4)n3)cc2)c1 ; N#Cc1cccc(-c2ccc(-c3cc(-c4nc(-c5ccccc5)nc(-c5ccccc5)n4)c4oc5ccccc5c4c3)cc2)c1 ; N#Cc1cccc(-c2ccc(-c3ccc(-c4nc(-c5ccccc5)nc(-c5ccccc5)n4)c4oc5ccccc5c34)cc2)c1] 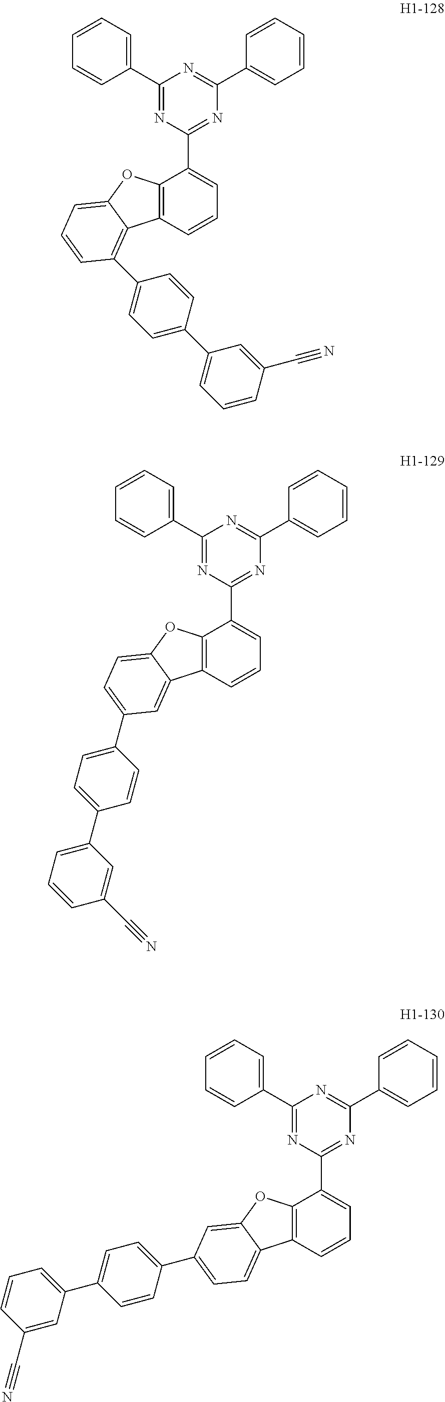 [SMILES: N#Cc1cccc(-c2ccc(-c3cccc4oc5c(-c6nc(-c7ccccc7)nc(-c7ccccc7)n6)cccc5c34)cc2)c1 ; N#Cc1cccc(-c2ccc(-c3ccc4oc5c(-c6nc(-c7ccccc7)nc(-c7ccccc7)n6)cccc5c4c3)cc2)c1 ; N#Cc1cccc(-c2ccc(-c3ccc4c(c3)oc3c(-c5nc(-c6ccccc6)nc(-c6ccccc6)n5)cccc34)cc2)c1] 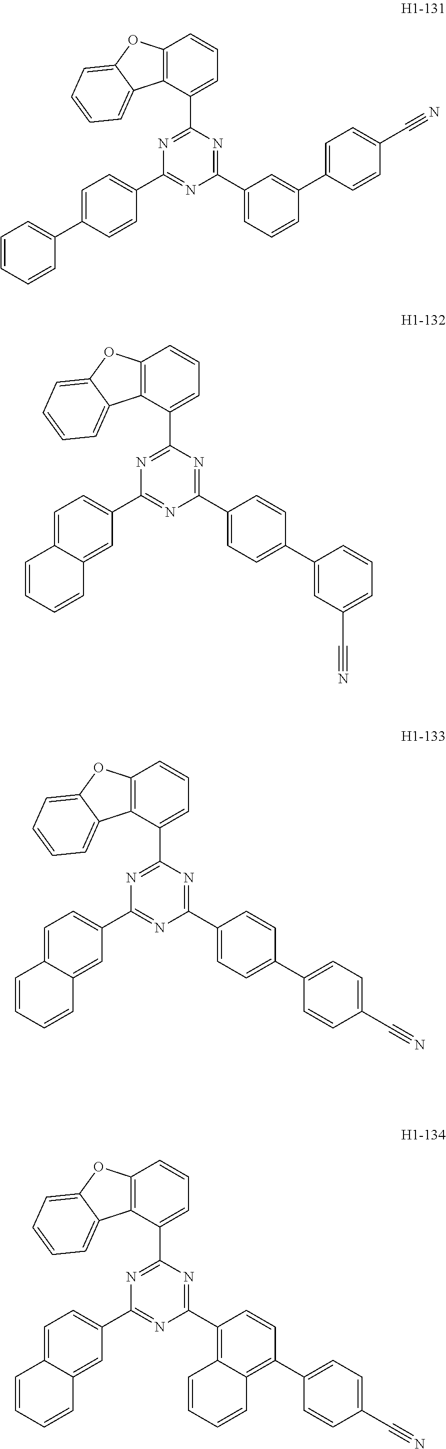 [SMILES: N#Cc1ccc(-c2cccc(-c3nc(-c4ccc(-c5ccccc5)cc4)nc(-c4cccc5oc6ccccc6c45)n3)c2)cc1 ; N#Cc1cccc(-c2ccc(-c3nc(-c4ccc5ccccc5c4)nc(-c4cccc5oc6ccccc6c45)n3)cc2)c1 ; N#Cc1ccc(-c2ccc(-c3nc(-c4ccc5ccccc5c4)nc(-c4cccc5oc6ccccc6c45)n3)cc2)cc1 ; N#Cc1ccc(-c2ccc(-c3nc(-c4ccc5ccccc5c4)nc(-c4cccc5oc6ccccc6c45)n3)c3ccccc23)cc1] 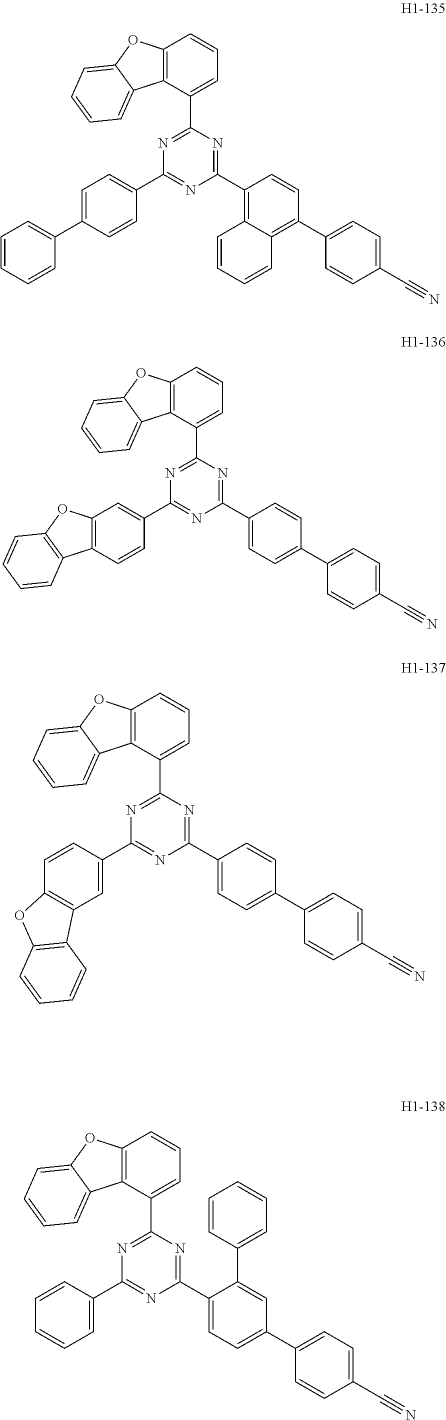 [SMILES: N#Cc1ccc(-c2ccc(-c3nc(-c4ccc(-c5ccccc5)cc4)nc(-c4cccc5oc6ccccc6c45)n3)c3ccccc23)cc1 ; N#Cc1ccc(-c2ccc(-c3nc(-c4ccc5c(c4)oc4ccccc45)nc(-c4cccc5oc6ccccc6c45)n3)cc2)cc1 ; N#Cc1ccc(-c2ccc(-c3nc(-c4ccc5oc6ccccc6c5c4)nc(-c4cccc5oc6ccccc6c45)n3)cc2)cc1 ; N#Cc1ccc(-c2ccc(-c3nc(-c4ccccc4)nc(-c4cccc5oc6ccccc6c45)n3)c(-c3ccccc3)c2)cc1] 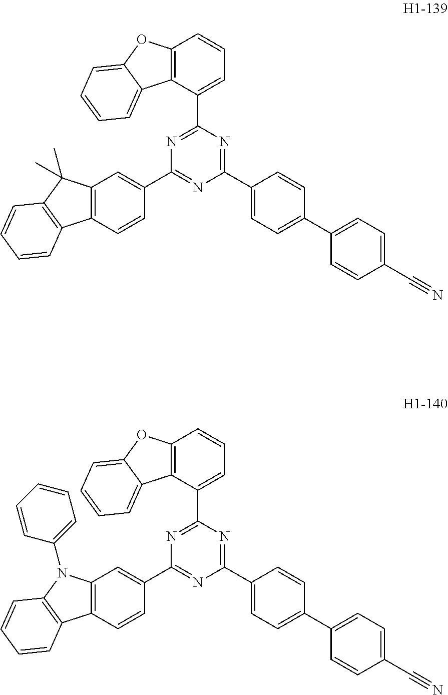 [SMILES: CC1(C)c2ccccc2-c2ccc(-c3nc(-c4ccc(-c5ccc(C#N)cc5)cc4)nc(-c4cccc5oc6ccccc6c45)n3)cc21 ; N#Cc1ccc(-c2ccc(-c3nc(-c4ccc5c6ccccc6n(-c6ccccc6)c5c4)nc(-c4cccc5oc6ccccc6c45)n3)cc2)cc1] 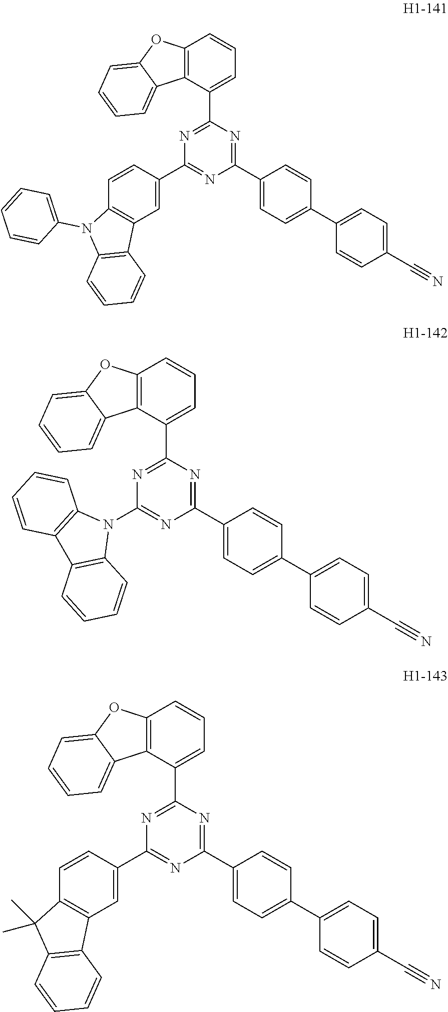 [SMILES: N#Cc1ccc(-c2ccc(-c3nc(-c4ccc5c(c4)c4ccccc4n5-c4ccccc4)nc(-c4cccc5oc6ccccc6c45)n3)cc2)cc1 ; N#Cc1ccc(-c2ccc(-c3nc(-c4cccc5oc6ccccc6c45)nc(-n4c5ccccc5c5ccccc54)n3)cc2)cc1 ; CC1(C)c2ccccc2-c2cc(-c3nc(-c4ccc(-c5ccc(C#N)cc5)cc4)nc(-c4cccc5oc6ccccc6c45)n3)ccc21] 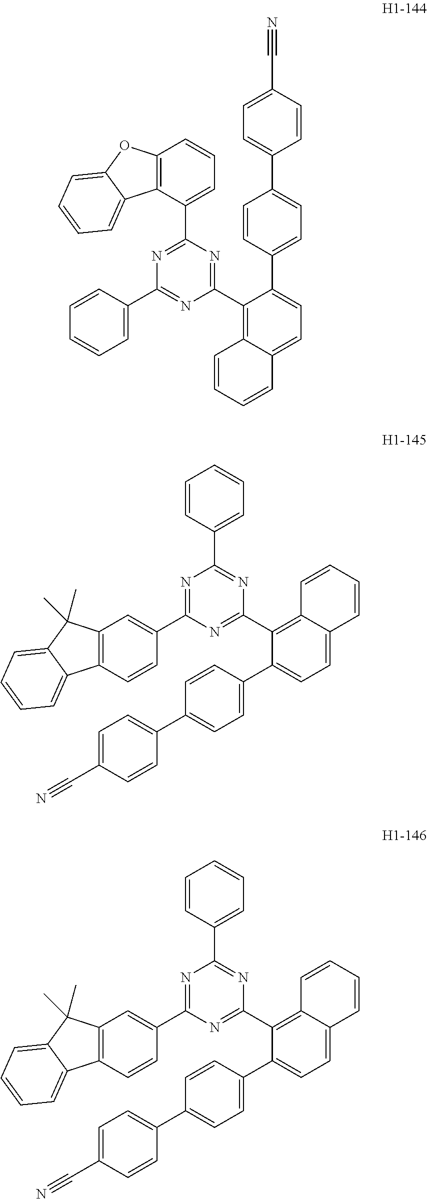 [SMILES: N#Cc1ccc(-c2ccc(-c3ccc4ccccc4c3-c3nc(-c4ccccc4)nc(-c4cccc5oc6ccccc6c45)n3)cc2)cc1 ; CC1(C)c2ccccc2-c2ccc(-c3nc(-c4ccccc4)nc(-c4c(-c5ccc(-c6ccc(C#N)cc6)cc5)ccc5ccccc45)n3)cc21 ; CC1(C)c2ccccc2-c2ccc(-c3nc(-c4ccccc4)nc(-c4c(-c5ccc(-c6ccc(C#N)cc6)cc5)ccc5ccccc45)n3)cc21] 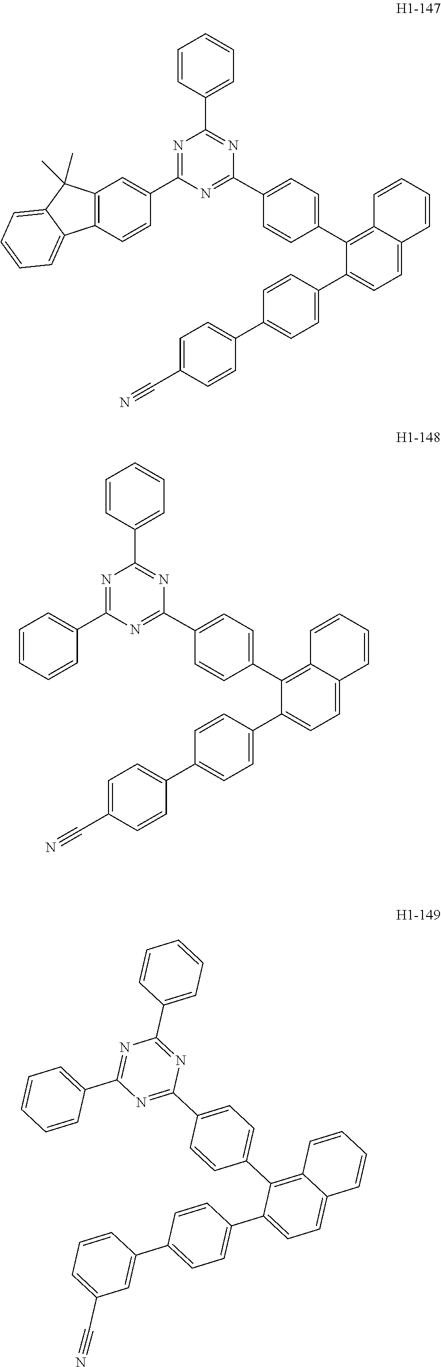 [SMILES: CC1(C)c2ccccc2-c2ccc(-c3nc(-c4ccccc4)nc(-c4ccc(-c5c(-c6ccc(-c7ccc(C#N)cc7)cc6)ccc6ccccc56)cc4)n3)cc21 ; N#Cc1ccc(-c2ccc(-c3ccc4ccccc4c3-c3ccc(-c4nc(-c5ccccc5)nc(-c5ccccc5)n4)cc3)cc2)cc1 ; N#Cc1cccc(-c2ccc(-c3ccc4ccccc4c3-c3ccc(-c4nc(-c5ccccc5)nc(-c5ccccc5)n4)cc3)cc2)c1] 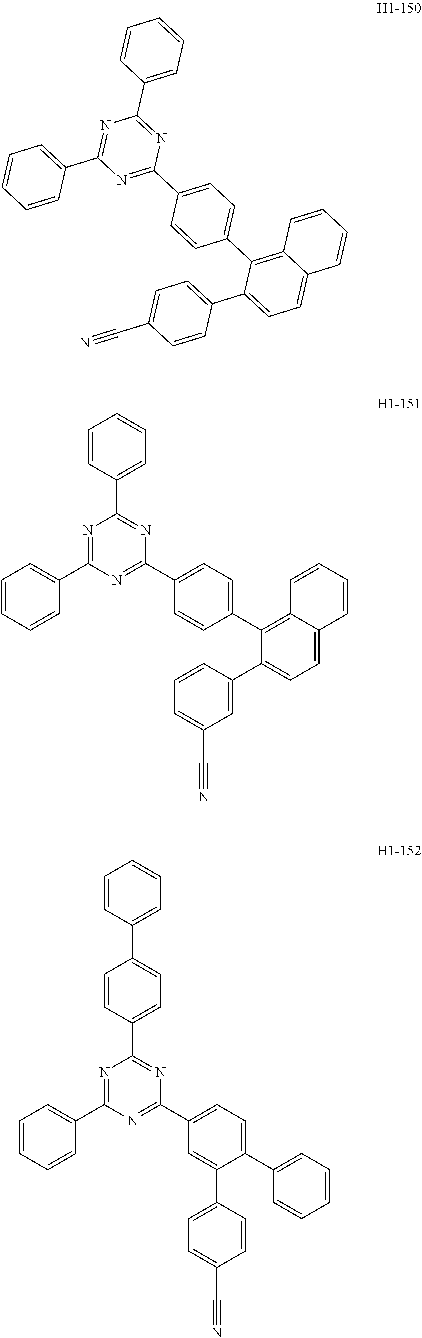 [SMILES: N#Cc1ccc(-c2ccc3ccccc3c2-c2ccc(-c3nc(-c4ccccc4)nc(-c4ccccc4)n3)cc2)cc1 ; N#Cc1cccc(-c2ccc3ccccc3c2-c2ccc(-c3nc(-c4ccccc4)nc(-c4ccccc4)n3)cc2)c1 ; N#Cc1ccc(-c2cc(-c3nc(-c4ccccc4)nc(-c4ccc(-c5ccccc5)cc4)n3)ccc2-c2ccccc2)cc1] 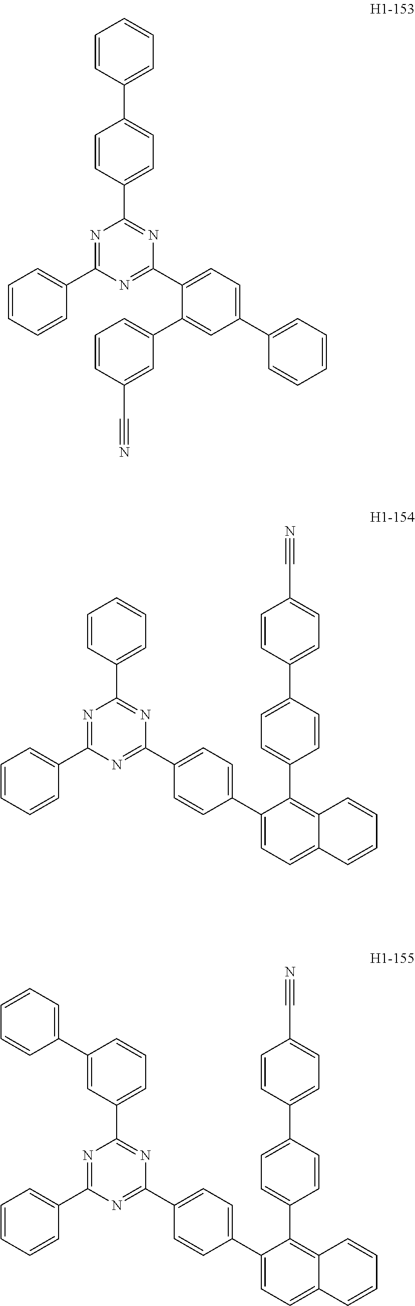 [SMILES: N#Cc1cccc(-c2cc(-c3ccccc3)ccc2-c2nc(-c3ccccc3)nc(-c3ccc(-c4ccccc4)cc3)n2)c1 ; N#Cc1ccc(-c2ccc(-c3c(-c4ccc(-c5nc(-c6ccccc6)nc(-c6ccccc6)n5)cc4)ccc4ccccc34)cc2)cc1 ; N#Cc1ccc(-c2ccc(-c3c(-c4ccc(-c5nc(-c6ccccc6)nc(-c6cccc(-c7ccccc7)c6)n5)cc4)ccc4ccccc34)cc2)cc1] 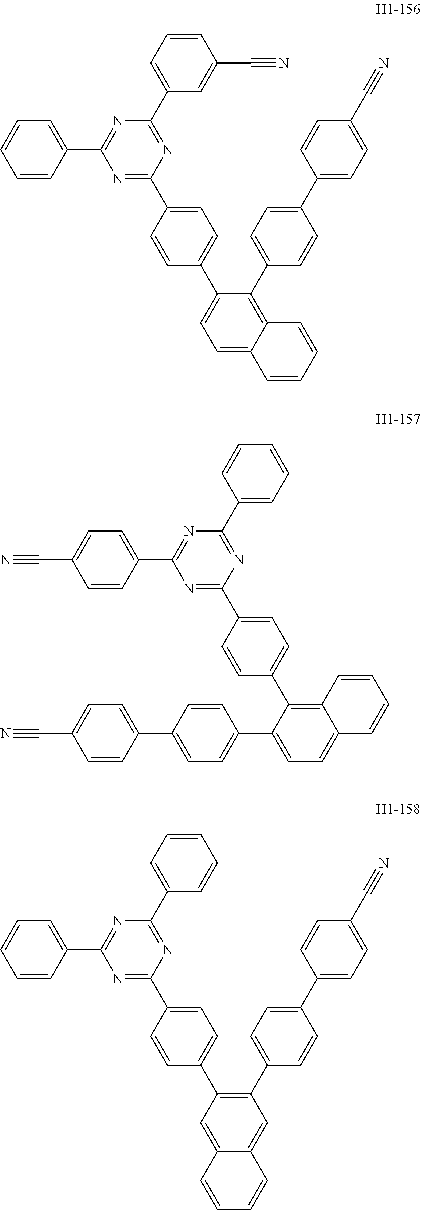 [SMILES: N#Cc1ccc(-c2ccc(-c3c(-c4ccc(-c5nc(-c6ccccc6)nc(-c6cccc(C#N)c6)n5)cc4)ccc4ccccc34)cc2)cc1 ; N#Cc1ccc(-c2ccc(-c3ccc4ccccc4c3-c3ccc(-c4nc(-c5ccccc5)nc(-c5ccc(C#N)cc5)n4)cc3)cc2)cc1 ; N#Cc1ccc(-c2ccc(-c3cc4ccccc4cc3-c3ccc(-c4nc(-c5ccccc5)nc(-c5ccccc5)n4)cc3)cc2)cc1] 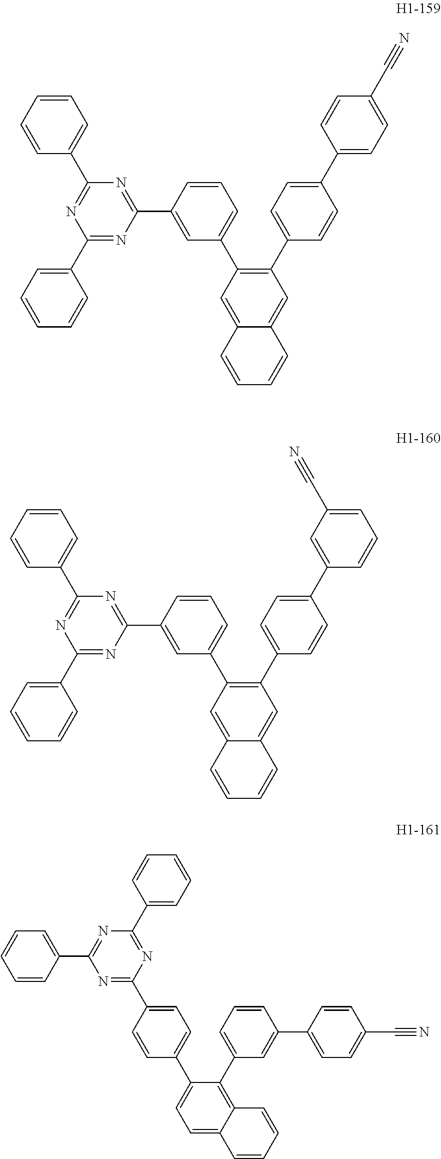 [SMILES: N#Cc1ccc(-c2ccc(-c3cc4ccccc4cc3-c3cccc(-c4nc(-c5ccccc5)nc(-c5ccccc5)n4)c3)cc2)cc1 ; N#Cc1cccc(-c2ccc(-c3cc4ccccc4cc3-c3cccc(-c4nc(-c5ccccc5)nc(-c5ccccc5)n4)c3)cc2)c1 ; N#Cc1ccc(-c2cccc(-c3c(-c4ccc(-c5nc(-c6ccccc6)nc(-c6ccccc6)n5)cc4)ccc4ccccc34)c2)cc1] 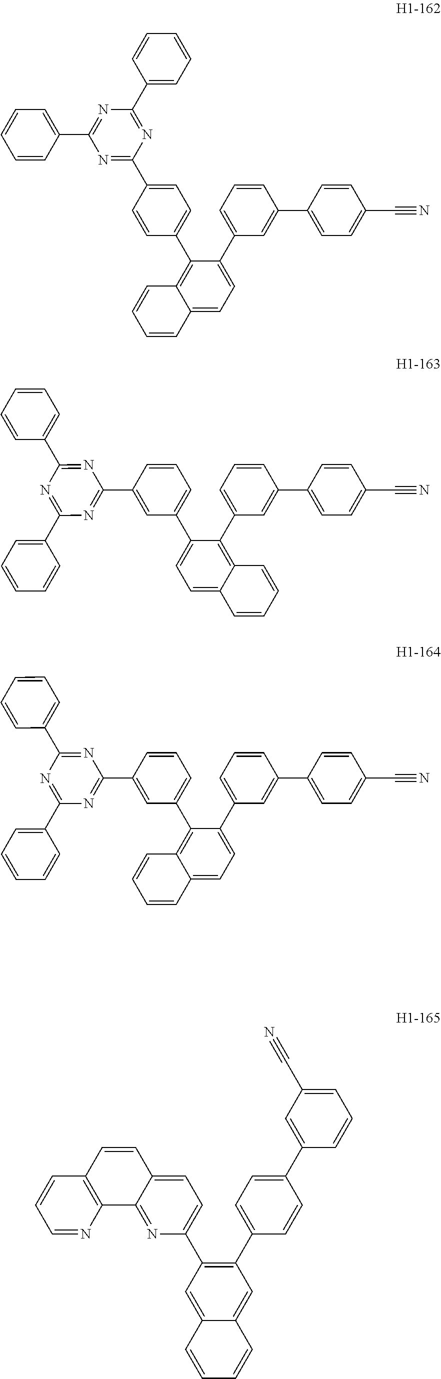 [SMILES: N#Cc1ccc(-c2cccc(-c3ccc4ccccc4c3-c3ccc(-c4nc(-c5ccccc5)nc(-c5ccccc5)n4)cc3)c2)cc1 ; N#Cc1ccc(-c2cccc(-c3c(-c4cccc(-c5nc(-c6ccccc6)nc(-c6ccccc6)n5)c4)ccc4ccccc34)c2)cc1 ; N#Cc1ccc(-c2cccc(-c3ccc4ccccc4c3-c3cccc(-c4nc(-c5ccccc5)nc(-c5ccccc5)n4)c3)c2)cc1 ; N#Cc1cccc(-c2ccc(-c3cc4ccccc4cc3-c3ccc4ccc5cccnc5c4n3)cc2)c1] 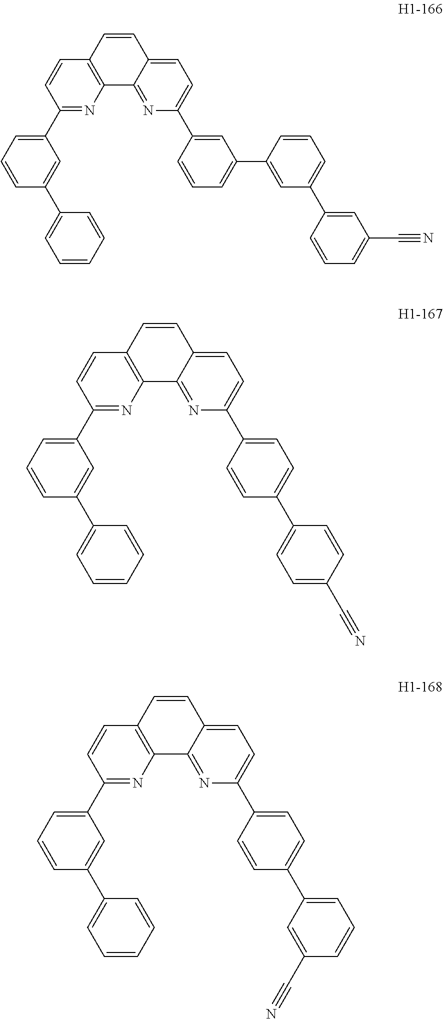 [SMILES: N#Cc1cccc(-c2cccc(-c3cccc(-c4ccc5ccc6ccc(-c7cccc(-c8ccccc8)c7)nc6c5n4)c3)c2)c1 ; N#Cc1ccc(-c2ccc(-c3ccc4ccc5ccc(-c6cccc(-c7ccccc7)c6)nc5c4n3)cc2)cc1 ; N#Cc1cccc(-c2ccc(-c3ccc4ccc5ccc(-c6cccc(-c7ccccc7)c6)nc5c4n3)cc2)c1] 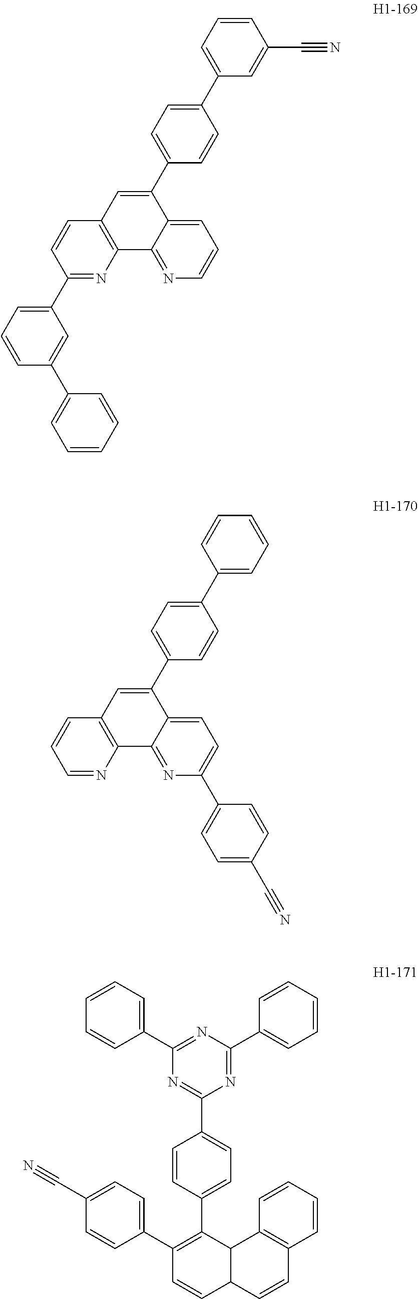 [SMILES: N#Cc1cccc(-c2ccc(-c3cc4ccc(-c5cccc(-c6ccccc6)c5)nc4c4ncccc34)cc2)c1 ; N#Cc1ccc(-c2ccc3c(-c4ccc(-c5ccccc5)cc4)cc4cccnc4c3n2)cc1 ; N#Cc1ccc(C2=C(c3ccc(-c4nc(-c5ccccc5)nc(-c5ccccc5)n4)cc3)C3c4ccccc4C=CC3C=C2)cc1] 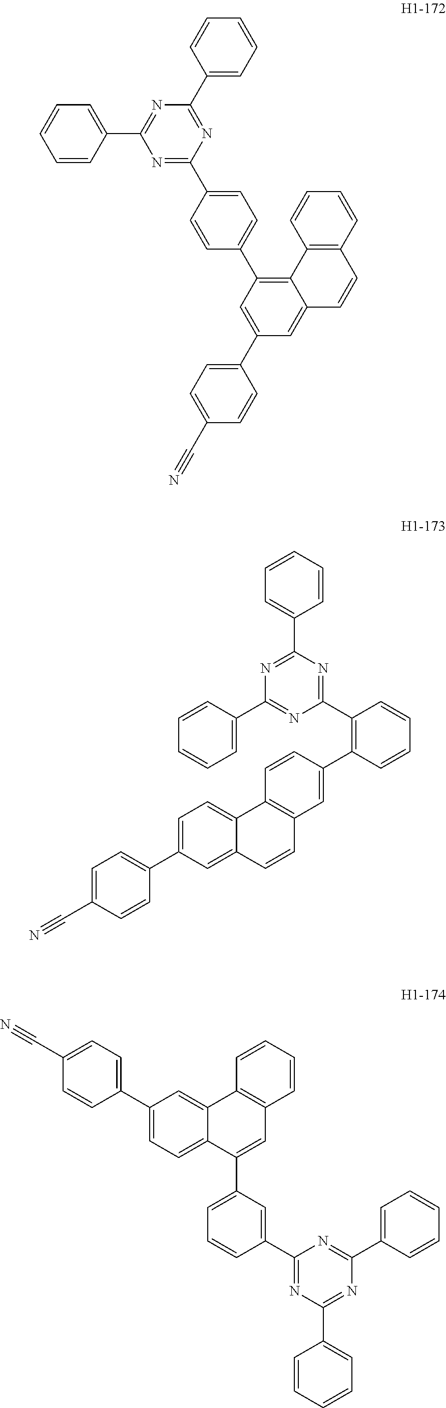 [SMILES: N#Cc1ccc(-c2cc(-c3ccc(-c4nc(-c5ccccc5)nc(-c5ccccc5)n4)cc3)c3c(ccc4ccccc43)c2)cc1 ; N#Cc1ccc(-c2ccc3c(ccc4cc(-c5ccccc5-c5nc(-c6ccccc6)nc(-c6ccccc6)n5)ccc43)c2)cc1 ; N#Cc1ccc(-c2ccc3c(-c4cccc(-c5nc(-c6ccccc6)nc(-c6ccccc6)n5)c4)cc4ccccc4c3c2)cc1] 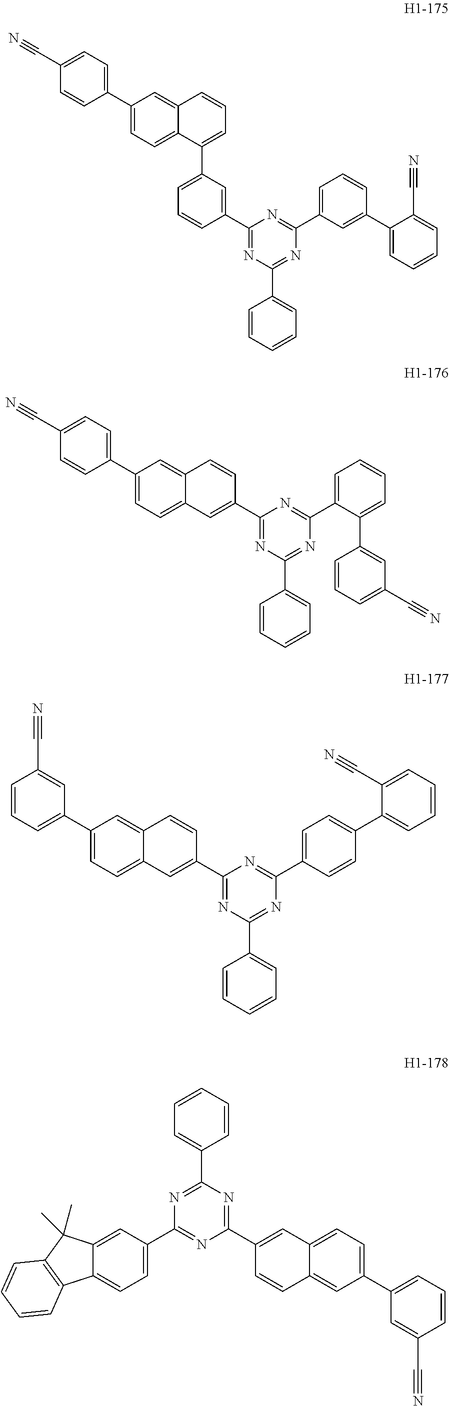 [SMILES: N#Cc1ccc(-c2ccc3c(-c4cccc(-c5nc(-c6ccccc6)nc(-c6cccc(-c7ccccc7C#N)c6)n5)c4)cccc3c2)cc1 ; N#Cc1ccc(-c2ccc3cc(-c4nc(-c5ccccc5)nc(-c5ccccc5-c5cccc(C#N)c5)n4)ccc3c2)cc1 ; N#Cc1cccc(-c2ccc3cc(-c4nc(-c5ccccc5)nc(-c5ccc(-c6ccccc6C#N)cc5)n4)ccc3c2)c1 ; CC1(C)c2ccccc2-c2ccc(-c3nc(-c4ccccc4)nc(-c4ccc5cc(-c6cccc(C#N)c6)ccc5c4)n3)cc21] 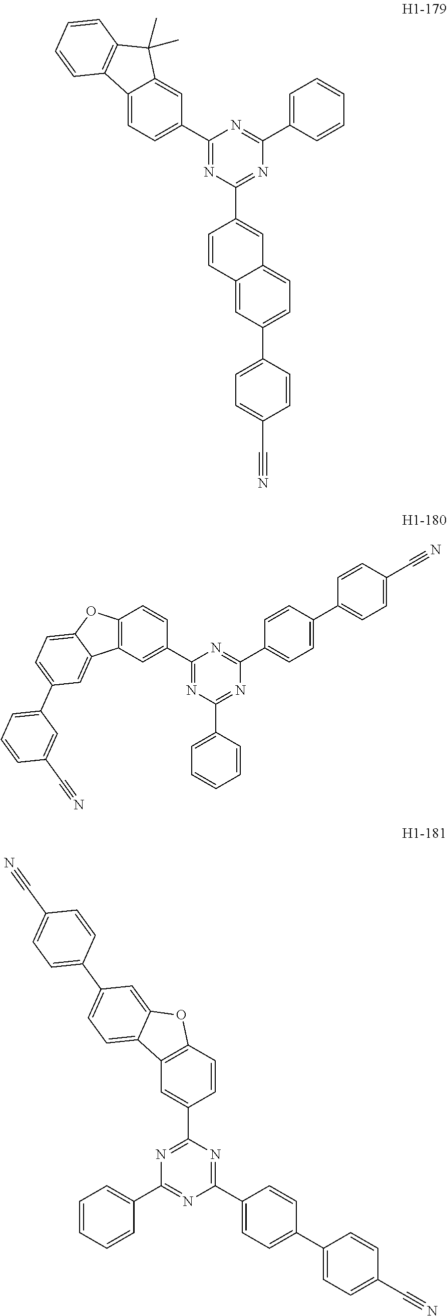 [SMILES: CC1(C)c2ccccc2-c2ccc(-c3nc(-c4ccccc4)nc(-c4ccc5cc(-c6ccc(C#N)cc6)ccc5c4)n3)cc21 ; N#Cc1ccc(-c2ccc(-c3nc(-c4ccccc4)nc(-c4ccc5oc6ccc(-c7cccc(C#N)c7)cc6c5c4)n3)cc2)cc1 ; N#Cc1ccc(-c2ccc(-c3nc(-c4ccccc4)nc(-c4ccc5oc6cc(-c7ccc(C#N)cc7)ccc6c5c4)n3)cc2)cc1] 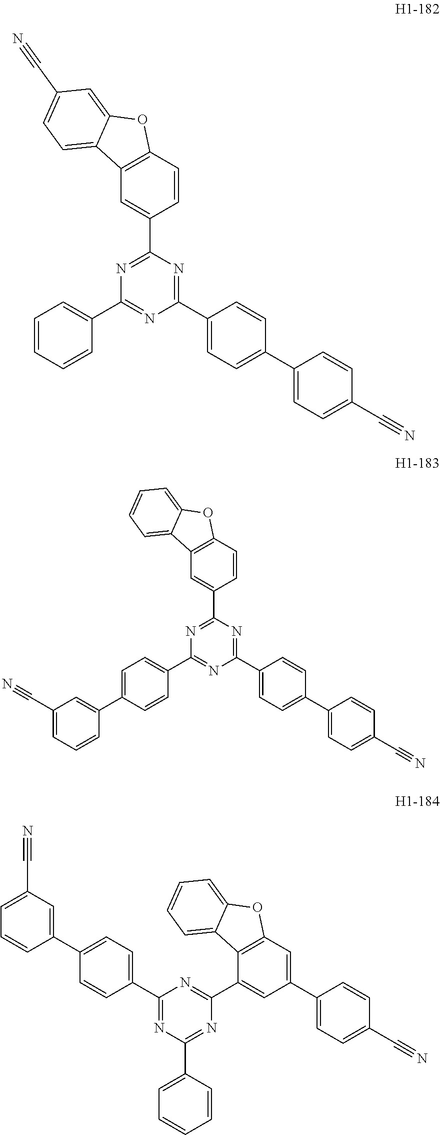 [SMILES: N#Cc1ccc(-c2ccc(-c3nc(-c4ccccc4)nc(-c4ccc5oc6cc(C#N)ccc6c5c4)n3)cc2)cc1 ; N#Cc1ccc(-c2ccc(-c3nc(-c4ccc(-c5cccc(C#N)c5)cc4)nc(-c4ccc5oc6ccccc6c5c4)n3)cc2)cc1 ; N#Cc1ccc(-c2cc(-c3nc(-c4ccccc4)nc(-c4ccc(-c5cccc(C#N)c5)cc4)n3)c3c(c2)oc2ccccc23)cc1] 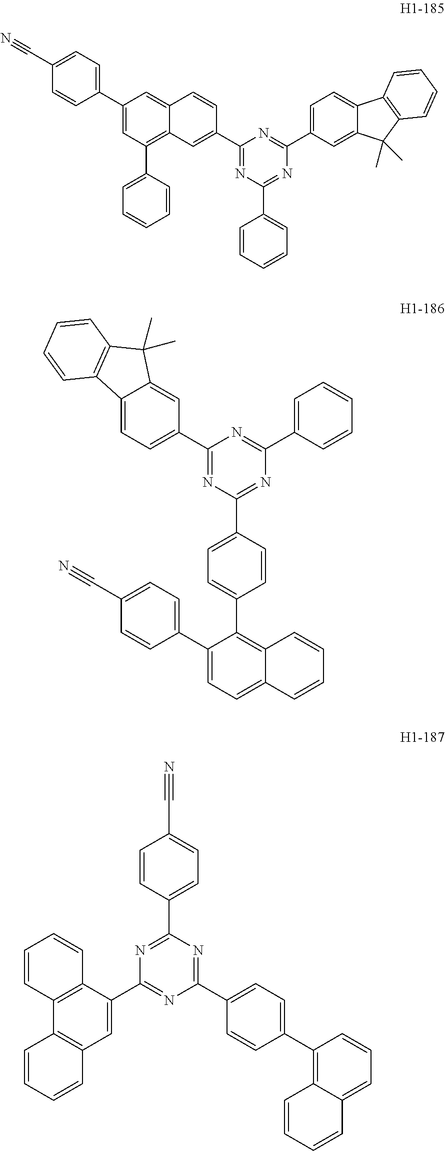 [SMILES: CC1(C)c2ccccc2-c2ccc(-c3nc(-c4ccccc4)nc(-c4ccc5cc(-c6ccc(C#N)cc6)cc(-c6ccccc6)c5c4)n3)cc21 ; CC1(C)c2ccccc2-c2ccc(-c3nc(-c4ccccc4)nc(-c4ccc(-c5c(-c6ccc(C#N)cc6)ccc6ccccc56)cc4)n3)cc21 ; N#Cc1ccc(-c2nc(-c3ccc(-c4cccc5ccccc45)cc3)nc(-c3cc4ccccc4c4ccccc34)n2)cc1] 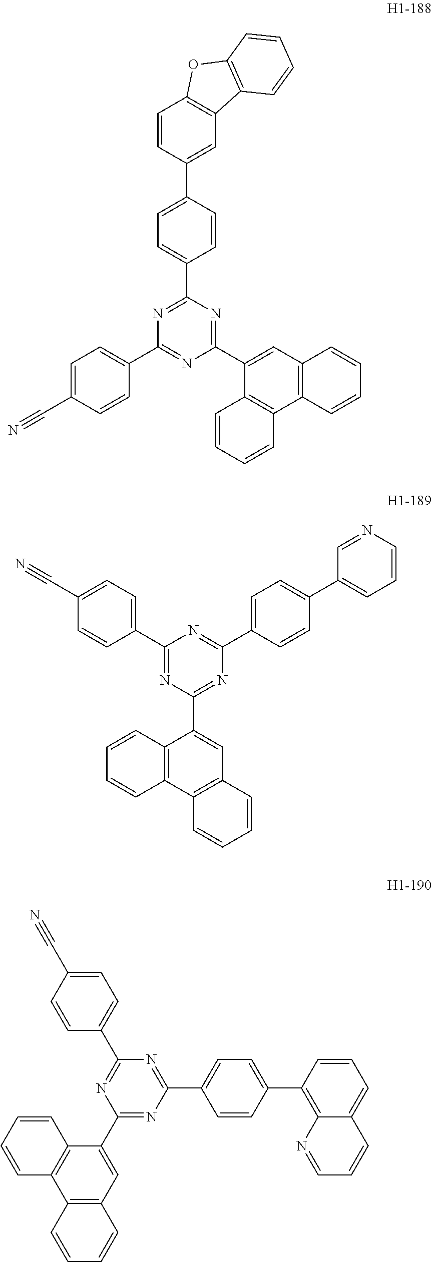 [SMILES: N#Cc1ccc(-c2nc(-c3ccc(-c4ccc5oc6ccccc6c5c4)cc3)nc(-c3cc4ccccc4c4ccccc34)n2)cc1 ; N#Cc1ccc(-c2nc(-c3ccc(-c4cccnc4)cc3)nc(-c3cc4ccccc4c4ccccc34)n2)cc1 ; N#Cc1ccc(-c2nc(-c3ccc(-c4cccc5cccnc45)cc3)nc(-c3cc4ccccc4c4ccccc34)n2)cc1] 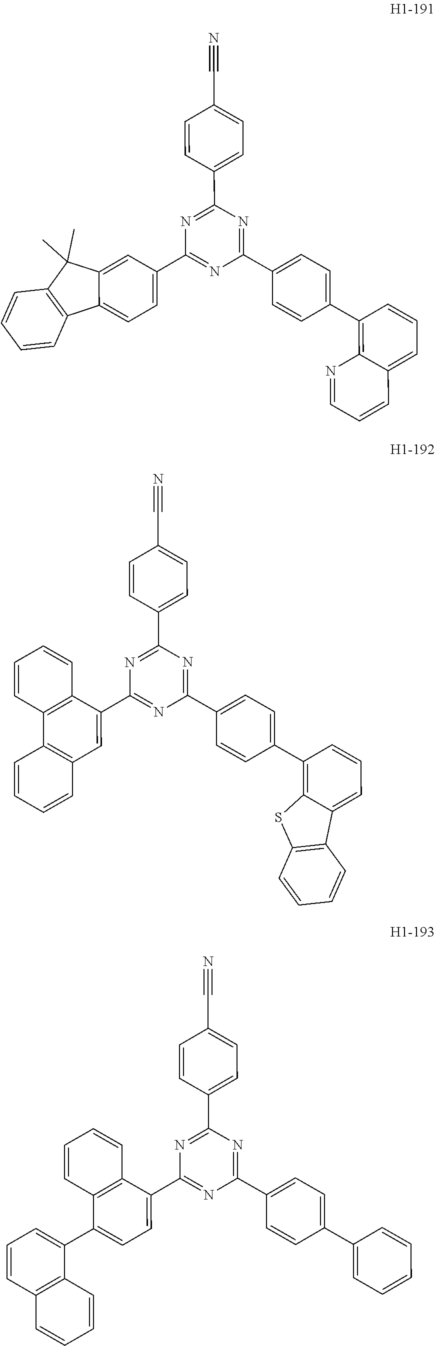 [SMILES: CC1(C)c2ccccc2-c2ccc(-c3nc(-c4ccc(C#N)cc4)nc(-c4ccc(-c5cccc6cccnc56)cc4)n3)cc21 ; N#Cc1ccc(-c2nc(-c3ccc(-c4cccc5c4sc4ccccc45)cc3)nc(-c3cc4ccccc4c4ccccc34)n2)cc1 ; N#Cc1ccc(-c2nc(-c3ccc(-c4ccccc4)cc3)nc(-c3ccc(-c4cccc5ccccc45)c4ccccc34)n2)cc1] 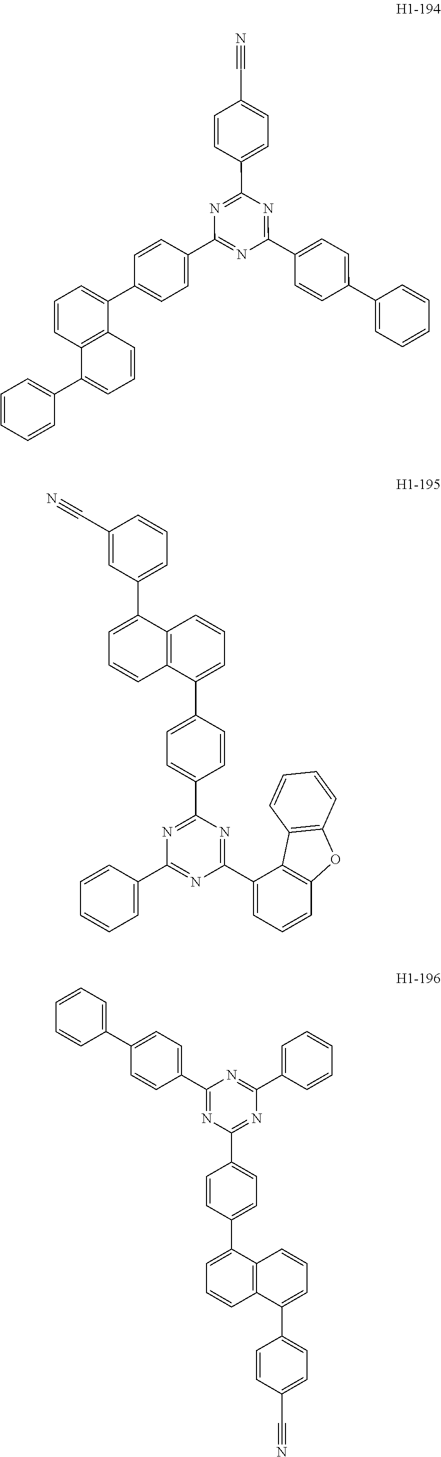 [SMILES: N#Cc1ccc(-c2nc(-c3ccc(-c4ccccc4)cc3)nc(-c3ccc(-c4cccc5c(-c6ccccc6)cccc45)cc3)n2)cc1 ; N#Cc1cccc(-c2cccc3c(-c4ccc(-c5nc(-c6ccccc6)nc(-c6cccc7oc8ccccc8c67)n5)cc4)cccc23)c1 ; N#Cc1ccc(-c2cccc3c(-c4ccc(-c5nc(-c6ccccc6)nc(-c6ccc(-c7ccccc7)cc6)n5)cc4)cccc23)cc1] 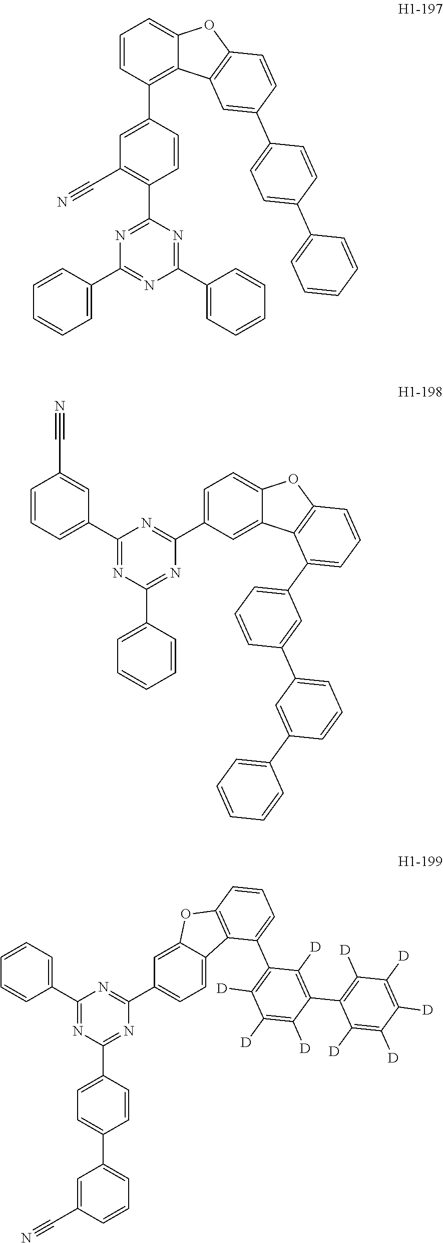 [SMILES: N#Cc1cc(-c2cccc3oc4ccc(-c5ccc(-c6ccccc6)cc5)cc4c23)ccc1-c1nc(-c2ccccc2)nc(-c2ccccc2)n1 ; N#Cc1cccc(-c2nc(-c3ccccc3)nc(-c3ccc4oc5cccc(-c6cccc(-c7cccc(-c8ccccc8)c7)c6)c5c4c3)n2)c1 ; [2H]c1c([2H])c([2H])c(-c2c([2H])c([2H])c([2H])c(-c3cccc4oc5cc(-c6nc(-c7ccccc7)nc(-c7ccc(-c8cccc(C#N)c8)cc7)n6)ccc5c34)c2[2H])c([2H])c1[2H]] 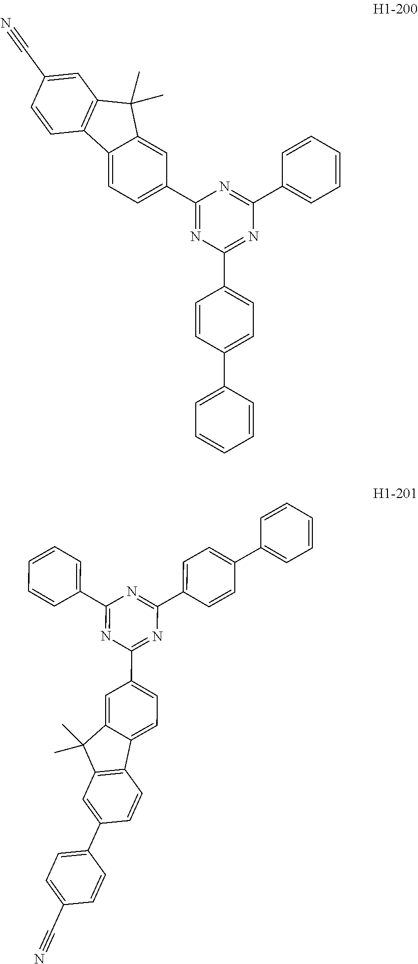 [SMILES: CC1(C)c2cc(C#N)ccc2-c2ccc(-c3nc(-c4ccccc4)nc(-c4ccc(-c5ccccc5)cc4)n3)cc21 ; CC1(C)c2cc(-c3ccc(C#N)cc3)ccc2-c2ccc(-c3nc(-c4ccccc4)nc(-c4ccc(-c5ccccc5)cc4)n3)cc21] 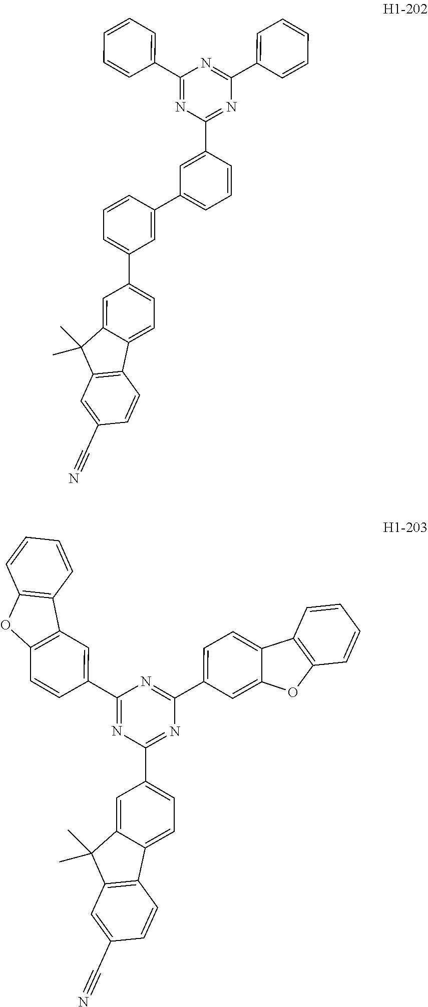 [SMILES: CC1(C)c2cc(C#N)ccc2-c2ccc(-c3cccc(-c4cccc(-c5nc(-c6ccccc6)nc(-c6ccccc6)n5)c4)c3)cc21 ; CC1(C)c2cc(C#N)ccc2-c2ccc(-c3nc(-c4ccc5c(c4)oc4ccccc45)nc(-c4ccc5oc6ccccc6c5c4)n3)cc21] 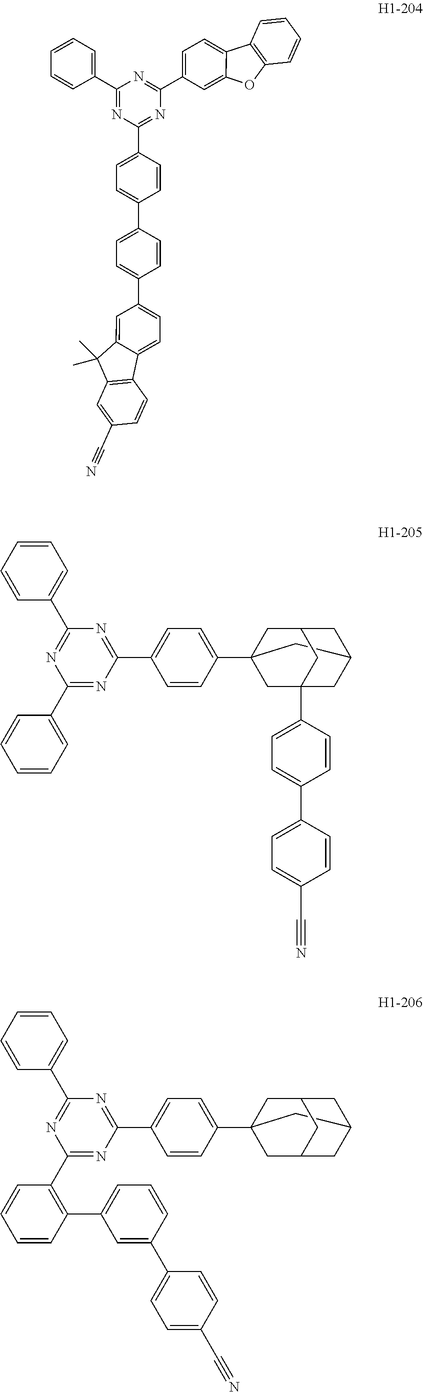 [SMILES: CC1(C)c2cc(C#N)ccc2-c2ccc(-c3ccc(-c4ccc(-c5nc(-c6ccccc6)nc(-c6ccc7c(c6)oc6ccccc67)n5)cc4)cc3)cc21 ; N#Cc1ccc(-c2ccc(C34CC5CC(C3)CC(c3ccc(-c6nc(-c7ccccc7)nc(-c7ccccc7)n6)cc3)(C5)C4)cc2)cc1 ; N#Cc1ccc(-c2cccc(-c3ccccc3-c3nc(-c4ccccc4)nc(-c4ccc(C56CC7CC(CC(C7)C5)C6)cc4)n3)c2)cc1] 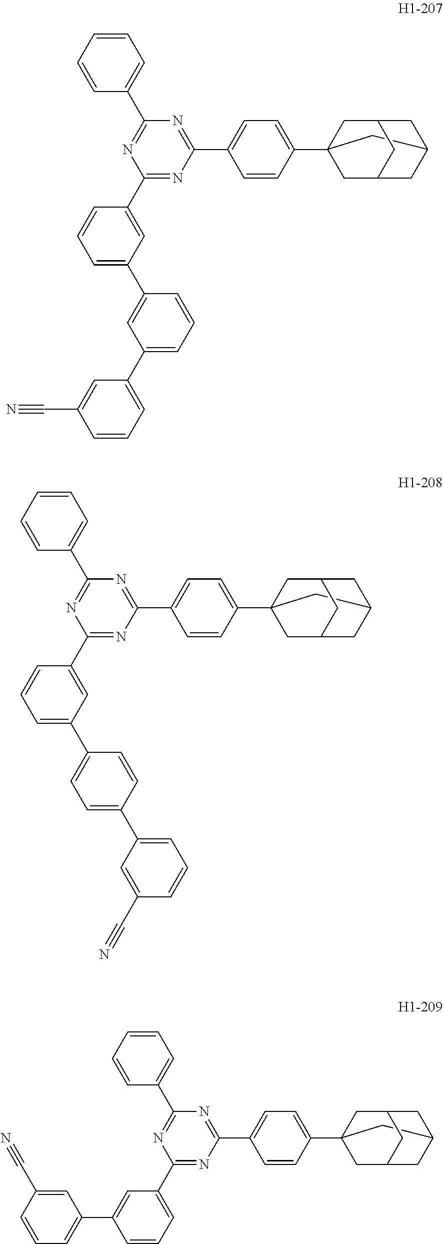 [SMILES: N#Cc1cccc(-c2cccc(-c3cccc(-c4nc(-c5ccccc5)nc(-c5ccc(C67CC8CC(CC(C8)C6)C7)cc5)n4)c3)c2)c1 ; N#Cc1cccc(-c2ccc(-c3cccc(-c4nc(-c5ccccc5)nc(-c5ccc(C67CC8CC(CC(C8)C6)C7)cc5)n4)c3)cc2)c1 ; N#Cc1cccc(-c2cccc(-c3nc(-c4ccccc4)nc(-c4ccc(C56CC7CC(CC(C7)C5)C6)cc4)n3)c2)c1] 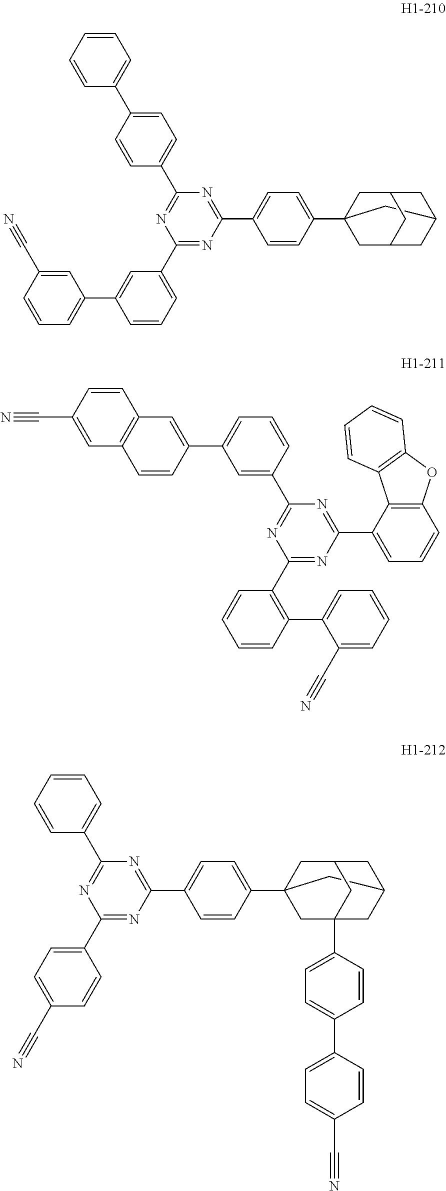 [SMILES: N#Cc1cccc(-c2cccc(-c3nc(-c4ccc(-c5ccccc5)cc4)nc(-c4ccc(C56CC7CC(CC(C7)C5)C6)cc4)n3)c2)c1 ; N#Cc1ccc2cc(-c3cccc(-c4nc(-c5ccccc5-c5ccccc5C#N)nc(-c5cccc6oc7ccccc7c56)n4)c3)ccc2c1 ; N#Cc1ccc(-c2ccc(C34CC5CC(C3)CC(c3ccc(-c6nc(-c7ccccc7)nc(-c7ccc(C#N)cc7)n6)cc3)(C5)C4)cc2)cc1] 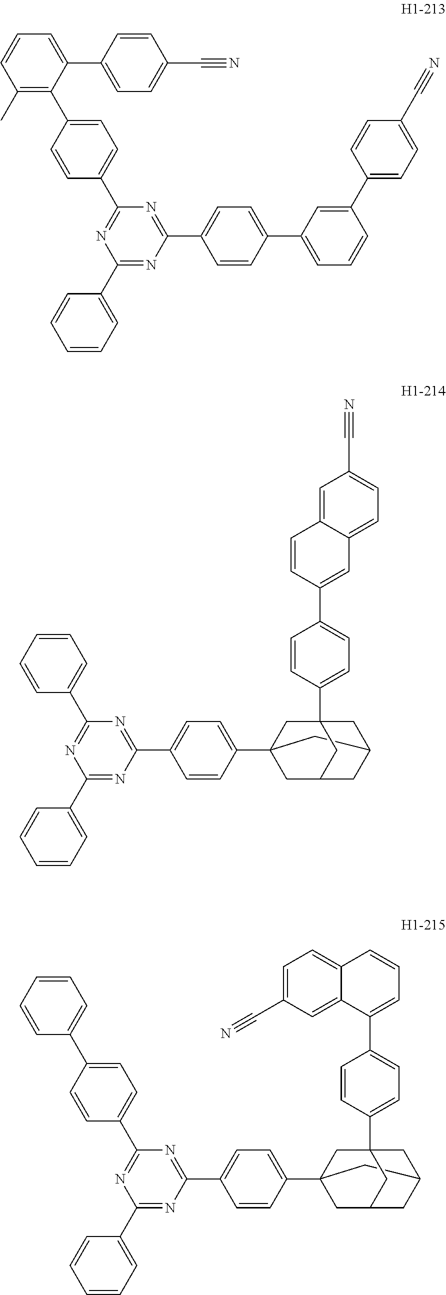 [SMILES: Cc1cccc(-c2ccc(C#N)cc2)c1-c1ccc(-c2nc(-c3ccccc3)nc(-c3ccc(-c4cccc(-c5ccc(C#N)cc5)c4)cc3)n2)cc1 ; N#Cc1ccc2cc(-c3ccc(C45CC6CC(C4)CC(c4ccc(-c7nc(-c8ccccc8)nc(-c8ccccc8)n7)cc4)(C6)C5)cc3)ccc2c1 ; N#Cc1ccc2cccc(-c3ccc(C45CC6CC(CC(c7ccc(-c8nc(-c9ccccc9)nc(-c9ccc(-c%10ccccc%10)cc9)n8)cc7)(C6)C4)C5)cc3)c2c1] 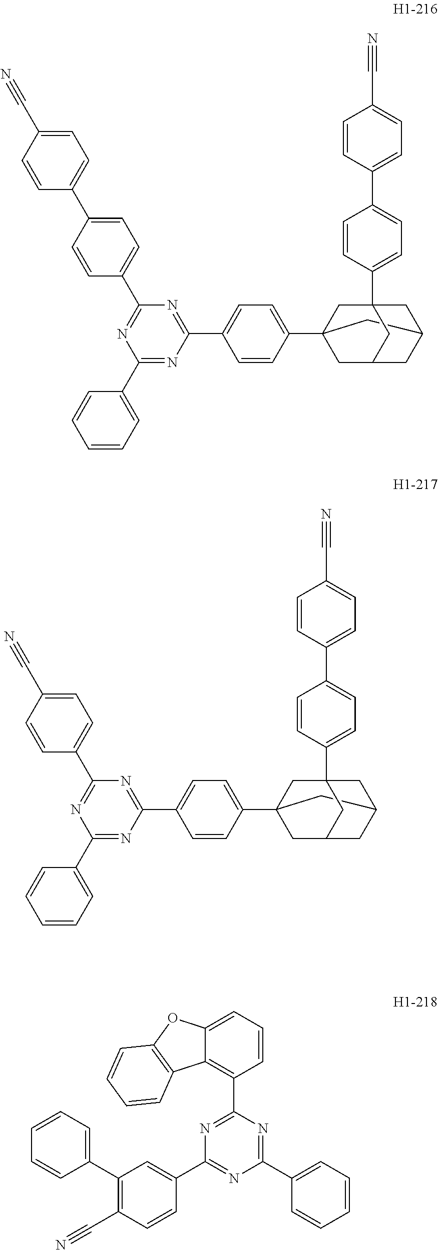 [SMILES: N#Cc1ccc(-c2ccc(-c3nc(-c4ccccc4)nc(-c4ccc(C56CC7CC(CC(c8ccc(-c9ccc(C#N)cc9)cc8)(C7)C5)C6)cc4)n3)cc2)cc1 ; N#Cc1ccc(-c2ccc(C34CC5CC(C3)CC(c3ccc(-c6nc(-c7ccccc7)nc(-c7ccc(C#N)cc7)n6)cc3)(C5)C4)cc2)cc1 ; N#Cc1ccc(-c2nc(-c3ccccc3)nc(-c3cccc4oc5ccccc5c34)n2)cc1-c1ccccc1] 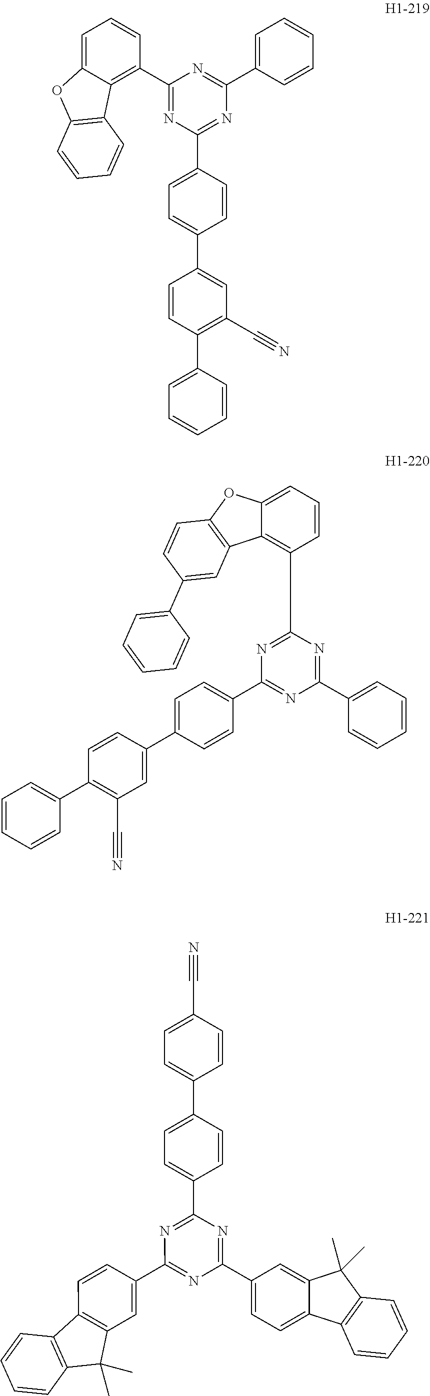 [SMILES: N#Cc1cc(-c2ccc(-c3nc(-c4ccccc4)nc(-c4cccc5oc6ccccc6c45)n3)cc2)ccc1-c1ccccc1 ; N#Cc1cc(-c2ccc(-c3nc(-c4ccccc4)nc(-c4cccc5oc6ccc(-c7ccccc7)cc6c45)n3)cc2)ccc1-c1ccccc1 ; CC1(C)c2ccccc2-c2ccc(-c3nc(-c4ccc(-c5ccc(C#N)cc5)cc4)nc(-c4ccc5c(c4)C(C)(C)c4ccccc4-5)n3)cc21] 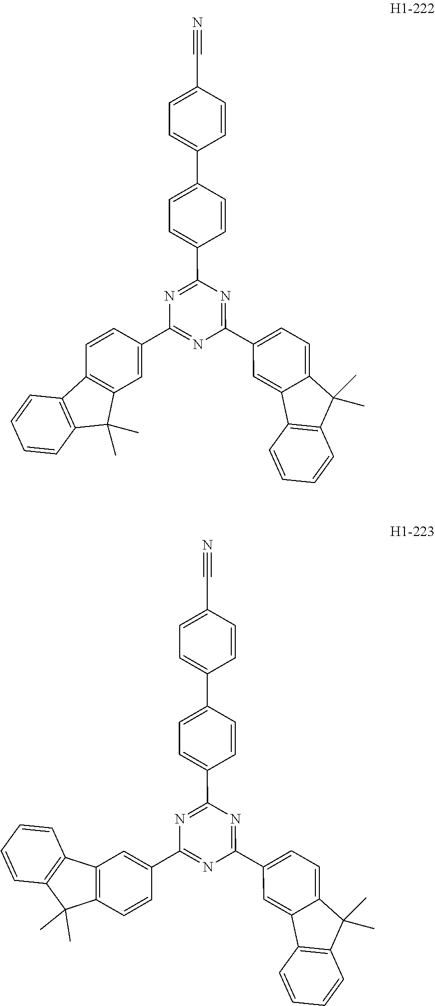 [SMILES: CC1(C)c2ccccc2-c2cc(-c3nc(-c4ccc(-c5ccc(C#N)cc5)cc4)nc(-c4ccc5c(c4)C(C)(C)c4ccccc4-5)n3)ccc21 ; CC1(C)c2ccccc2-c2cc(-c3nc(-c4ccc(-c5ccc(C#N)cc5)cc4)nc(-c4ccc5c(c4)-c4ccccc4C5(C)C)n3)ccc21] 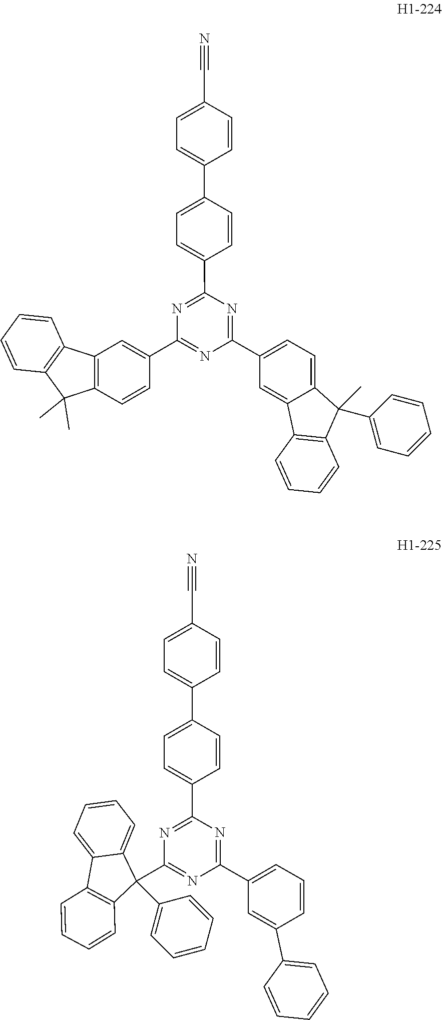 [SMILES: CC1(C)c2ccccc2-c2cc(-c3nc(-c4ccc(-c5ccc(C#N)cc5)cc4)nc(-c4ccc5c(c4)-c4ccccc4C5(C)c4ccccc4)n3)ccc21 ; N#Cc1ccc(-c2ccc(-c3nc(-c4cccc(-c5ccccc5)c4)nc(C4(c5ccccc5)c5ccccc5-c5ccccc54)n3)cc2)cc1] 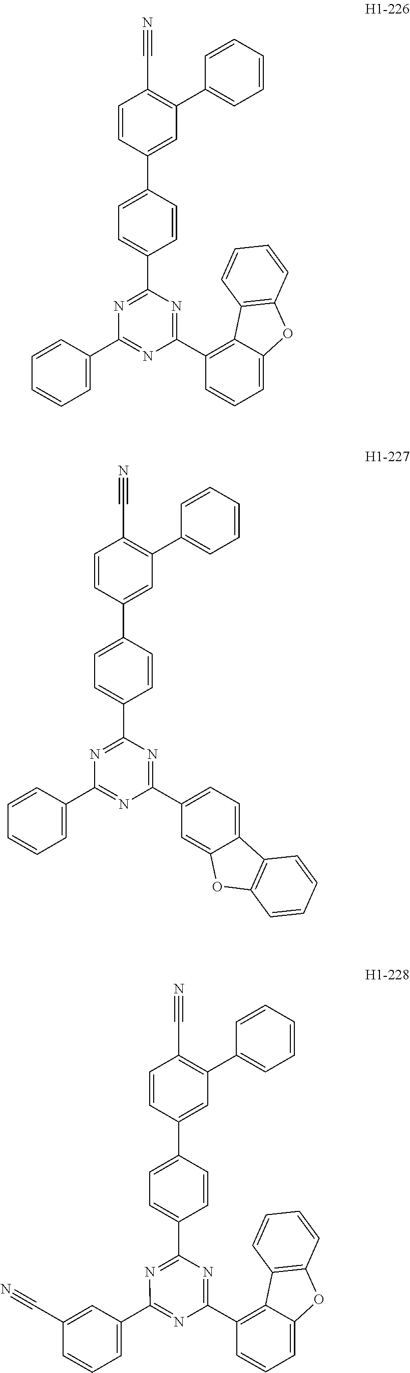 [SMILES: N#Cc1ccc(-c2ccc(-c3nc(-c4ccccc4)nc(-c4cccc5oc6ccccc6c45)n3)cc2)cc1-c1ccccc1 ; N#Cc1ccc(-c2ccc(-c3nc(-c4ccccc4)nc(-c4ccc5c(c4)oc4ccccc45)n3)cc2)cc1-c1ccccc1 ; N#Cc1cccc(-c2nc(-c3ccc(-c4ccc(C#N)c(-c5ccccc5)c4)cc3)nc(-c3cccc4oc5ccccc5c34)n2)c1] 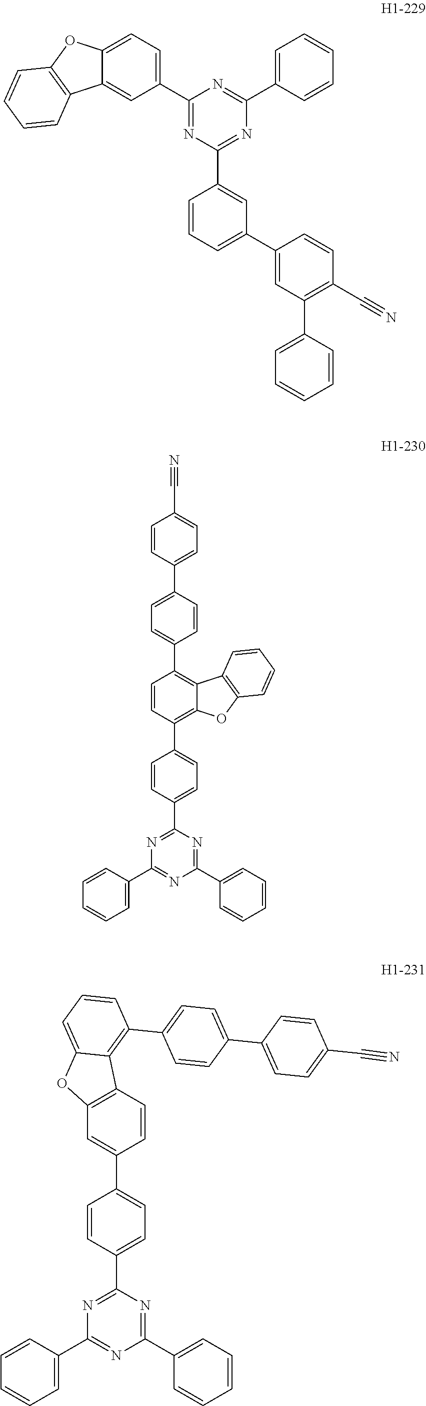 [SMILES: N#Cc1ccc(-c2cccc(-c3nc(-c4ccccc4)nc(-c4ccc5oc6ccccc6c5c4)n3)c2)cc1-c1ccccc1 ; N#Cc1ccc(-c2ccc(-c3ccc(-c4ccc(-c5nc(-c6ccccc6)nc(-c6ccccc6)n5)cc4)c4oc5ccccc5c34)cc2)cc1 ; N#Cc1ccc(-c2ccc(-c3cccc4oc5cc(-c6ccc(-c7nc(-c8ccccc8)nc(-c8ccccc8)n7)cc6)ccc5c34)cc2)cc1] 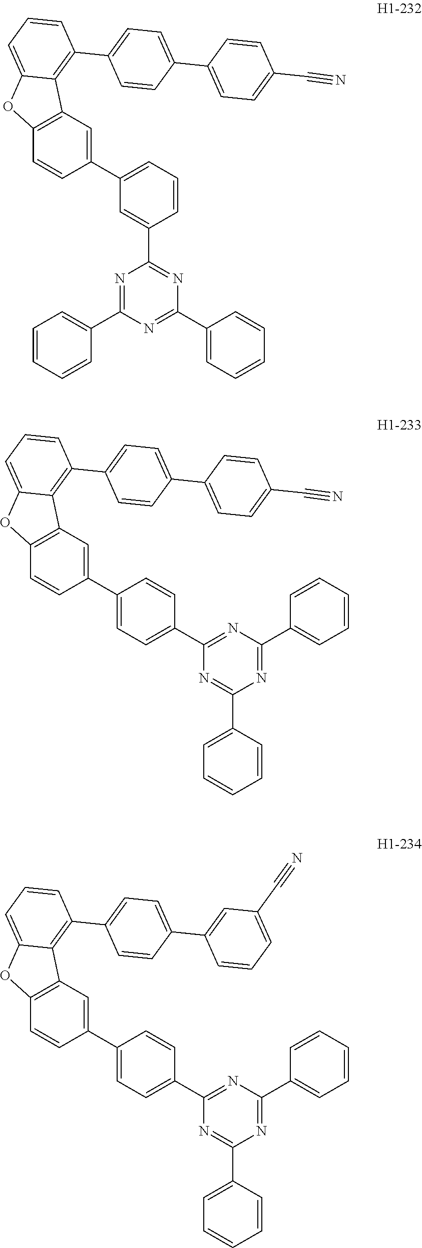 [SMILES: N#Cc1ccc(-c2ccc(-c3cccc4oc5ccc(-c6cccc(-c7nc(-c8ccccc8)nc(-c8ccccc8)n7)c6)cc5c34)cc2)cc1 ; N#Cc1ccc(-c2ccc(-c3cccc4oc5ccc(-c6ccc(-c7nc(-c8ccccc8)nc(-c8ccccc8)n7)cc6)cc5c34)cc2)cc1 ; N#Cc1cccc(-c2ccc(-c3cccc4oc5ccc(-c6ccc(-c7nc(-c8ccccc8)nc(-c8ccccc8)n7)cc6)cc5c34)cc2)c1] 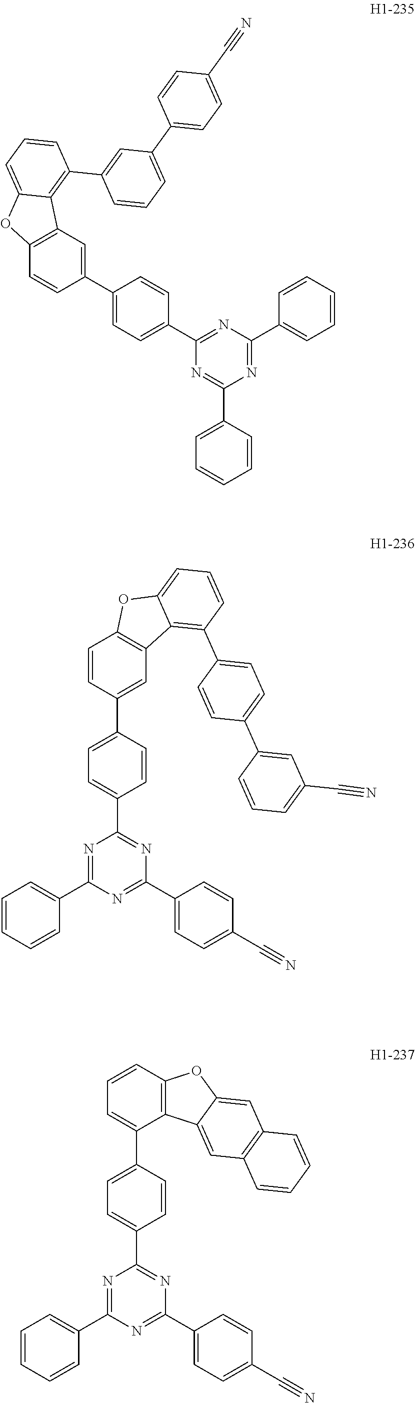 [SMILES: N#Cc1ccc(-c2cccc(-c3cccc4oc5ccc(-c6ccc(-c7nc(-c8ccccc8)nc(-c8ccccc8)n7)cc6)cc5c34)c2)cc1 ; N#Cc1ccc(-c2nc(-c3ccccc3)nc(-c3ccc(-c4ccc5oc6cccc(-c7ccc(-c8cccc(C#N)c8)cc7)c6c5c4)cc3)n2)cc1 ; N#Cc1ccc(-c2nc(-c3ccccc3)nc(-c3ccc(-c4cccc5oc6cc7ccccc7cc6c45)cc3)n2)cc1] 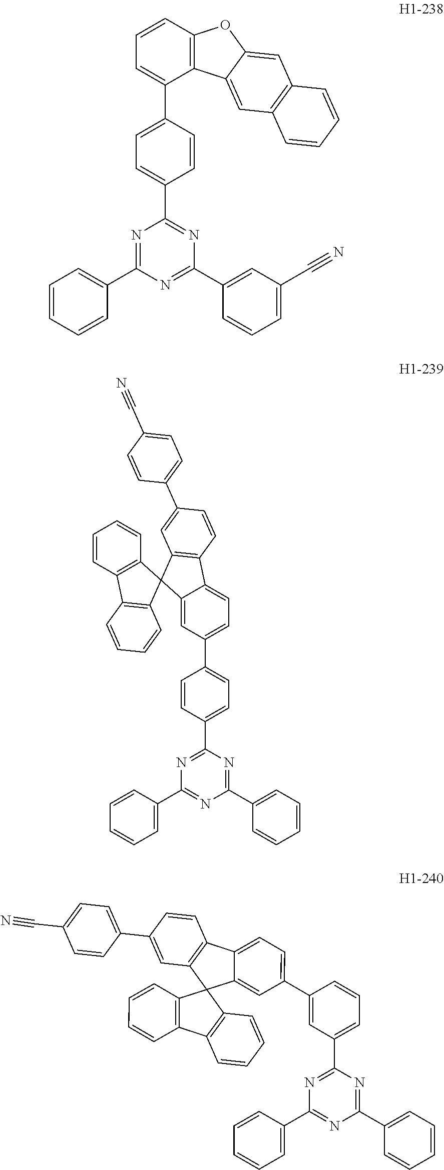 [SMILES: N#Cc1cccc(-c2nc(-c3ccccc3)nc(-c3ccc(-c4cccc5oc6cc7ccccc7cc6c45)cc3)n2)c1 ; N#Cc1ccc(-c2ccc3c(c2)C2(c4ccccc4-c4ccccc42)c2cc(-c4ccc(-c5nc(-c6ccccc6)nc(-c6ccccc6)n5)cc4)ccc2-3)cc1 ; N#Cc1ccc(-c2ccc3c(c2)C2(c4ccccc4-c4ccccc42)c2cc(-c4cccc(-c5nc(-c6ccccc6)nc(-c6ccccc6)n5)c4)ccc2-3)cc1] 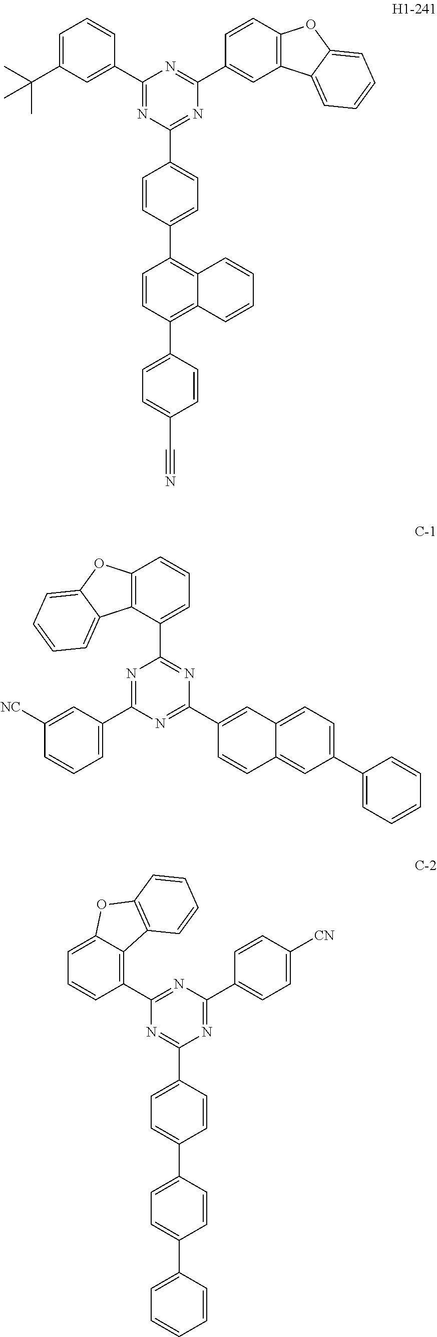 [SMILES: CC(C)(C)c1cccc(-c2nc(-c3ccc(-c4ccc(-c5ccc(C#N)cc5)c5ccccc45)cc3)nc(-c3ccc4oc5ccccc5c4c3)n2)c1 ; N#Cc1cccc(-c2nc(-c3ccc4cc(-c5ccccc5)ccc4c3)nc(-c3cccc4oc5ccccc5c34)n2)c1 ; N#Cc1ccc(-c2nc(-c3ccc(-c4ccc(-c5ccccc5)cc4)cc3)nc(-c3cccc4oc5ccccc5c34)n2)cc1] 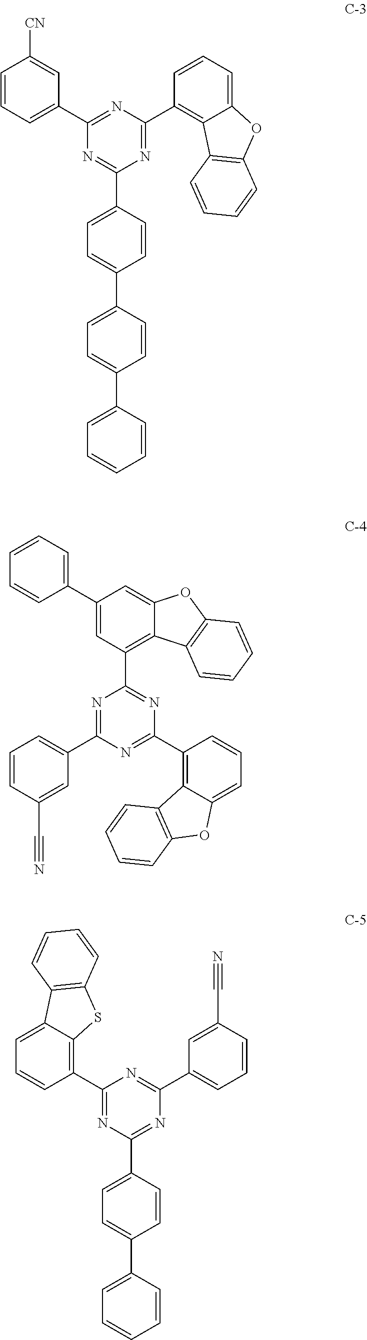 [SMILES: N#Cc1cccc(-c2nc(-c3ccc(-c4ccc(-c5ccccc5)cc4)cc3)nc(-c3cccc4oc5ccccc5c34)n2)c1 ; N#Cc1cccc(-c2nc(-c3cccc4oc5ccccc5c34)nc(-c3cc(-c4ccccc4)cc4oc5ccccc5c34)n2)c1 ; N#Cc1cccc(-c2nc(-c3ccc(-c4ccccc4)cc3)nc(-c3cccc4c3sc3ccccc34)n2)c1] 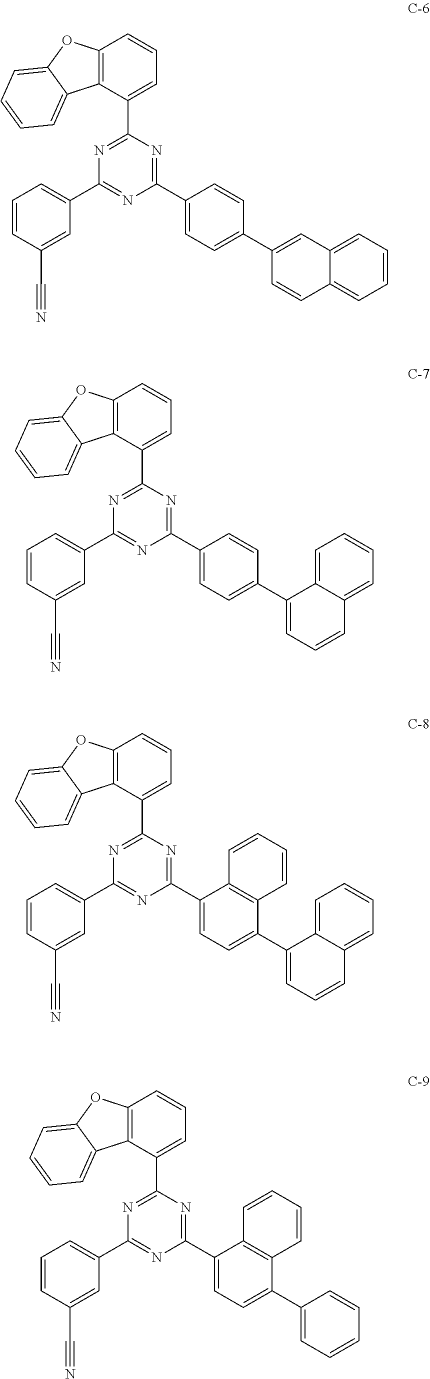 [SMILES: N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4cccc5ccccc45)cc3)nc(-c3cccc4oc5ccccc5c34)n2)c1 ; N#Cc1cccc(-c2nc(-c3ccc(-c4cccc5ccccc45)c4ccccc34)nc(-c3cccc4oc5ccccc5c34)n2)c1 ; N#Cc1cccc(-c2nc(-c3ccc(-c4ccccc4)c4ccccc34)nc(-c3cccc4oc5ccccc5c34)n2)c1] 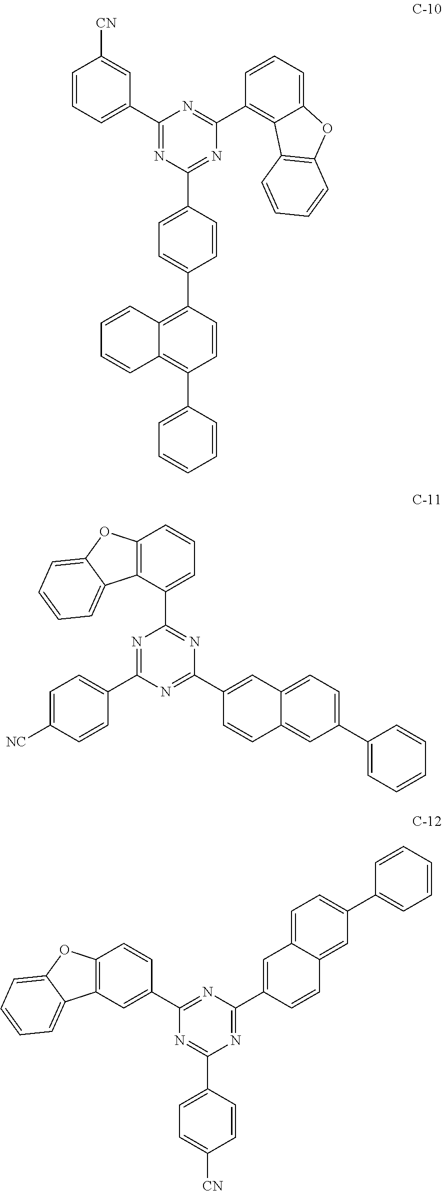 [SMILES: N#Cc1cccc(-c2nc(-c3ccc(-c4ccc(-c5ccccc5)c5ccccc45)cc3)nc(-c3cccc4oc5ccccc5c34)n2)c1 ; N#Cc1ccc(-c2nc(-c3ccc4cc(-c5ccccc5)ccc4c3)nc(-c3cccc4oc5ccccc5c34)n2)cc1 ; N#Cc1ccc(-c2nc(-c3ccc4cc(-c5ccccc5)ccc4c3)nc(-c3ccc4oc5ccccc5c4c3)n2)cc1] 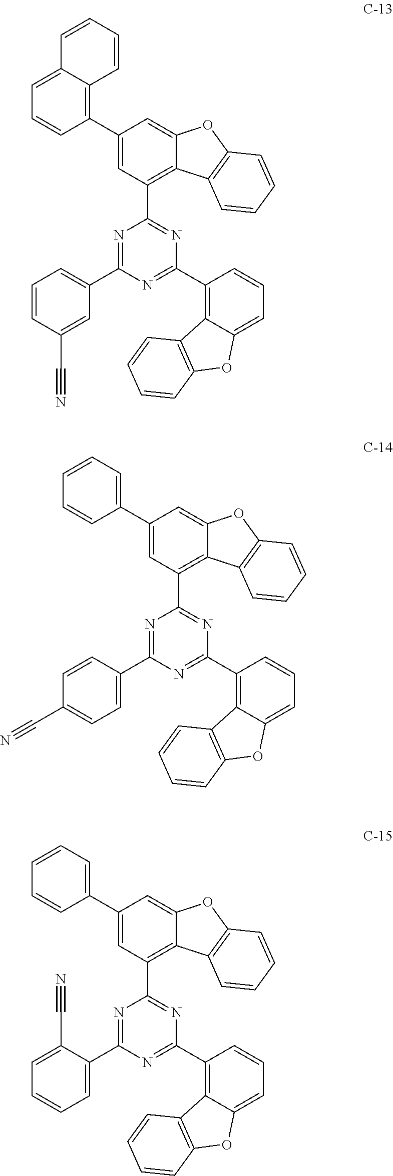 [SMILES: N#Cc1cccc(-c2nc(-c3cccc4oc5ccccc5c34)nc(-c3cc(-c4cccc5ccccc45)cc4oc5ccccc5c34)n2)c1 ; N#Cc1ccc(-c2nc(-c3cccc4oc5ccccc5c34)nc(-c3cc(-c4ccccc4)cc4oc5ccccc5c34)n2)cc1 ; N#Cc1ccccc1-c1nc(-c2cccc3oc4ccccc4c23)nc(-c2cc(-c3ccccc3)cc3oc4ccccc4c23)n1] 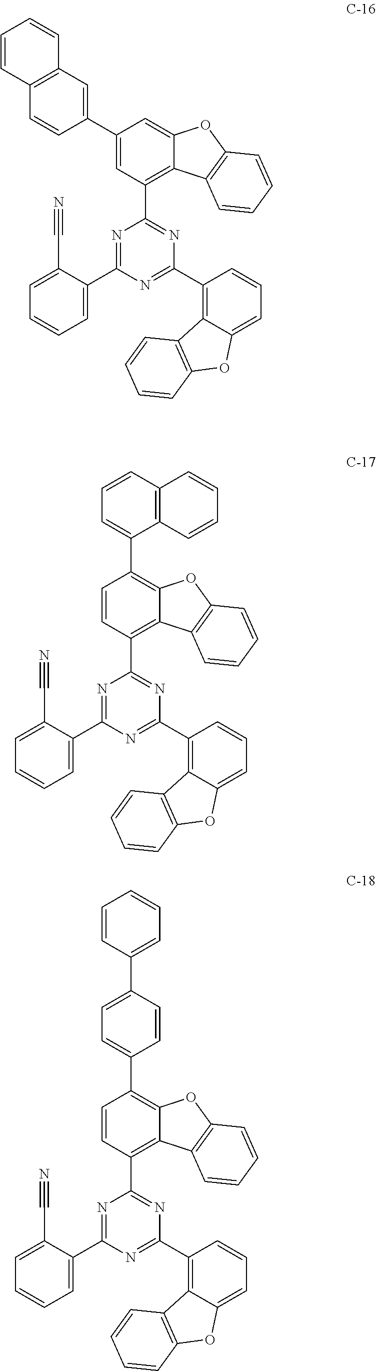 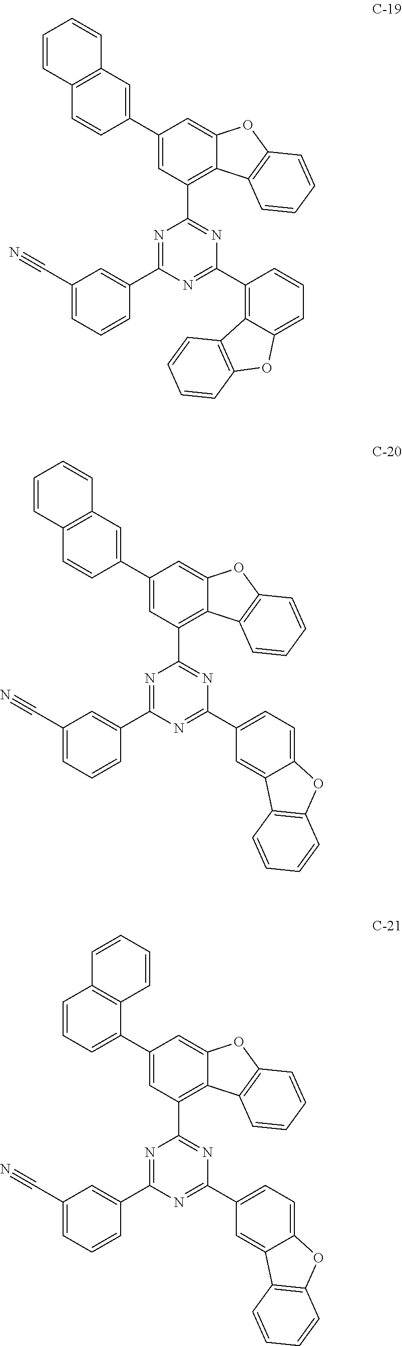 [SMILES: N#Cc1cccc(-c2nc(-c3cccc4oc5ccccc5c34)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4cccc5ccccc45)cc4oc5ccccc5c34)n2)c1] 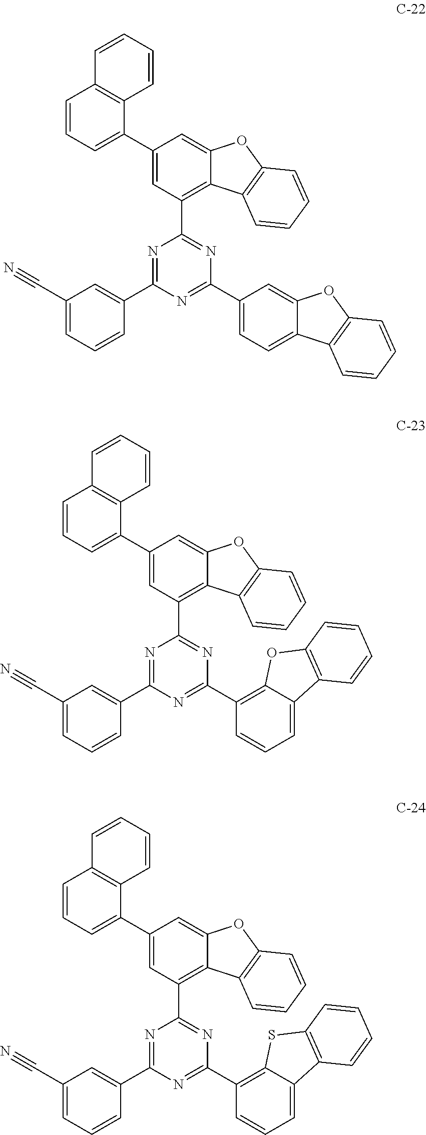 [SMILES: N#Cc1cccc(-c2nc(-c3ccc4c(c3)oc3ccccc34)nc(-c3cc(-c4cccc5ccccc45)cc4oc5ccccc5c34)n2)c1 ; N#Cc1cccc(-c2nc(-c3cccc4c3oc3ccccc34)nc(-c3cc(-c4cccc5ccccc45)cc4oc5ccccc5c34)n2)c1 ; N#Cc1cccc(-c2nc(-c3cccc4c3sc3ccccc34)nc(-c3cc(-c4cccc5ccccc45)cc4oc5ccccc5c34)n2)c1] 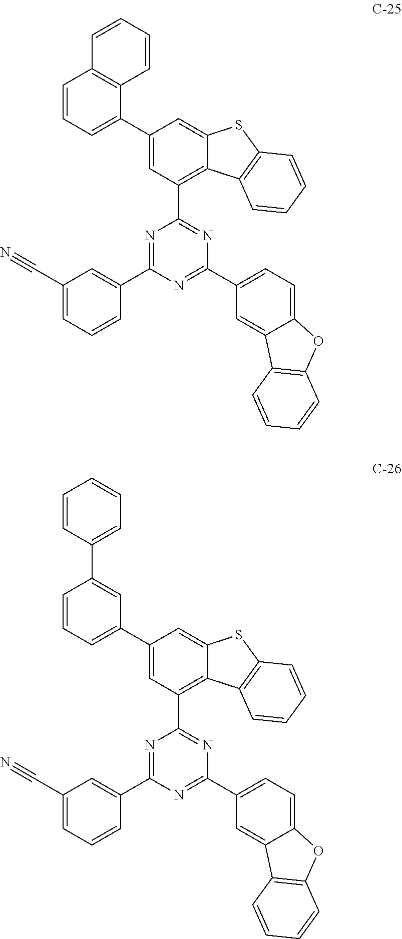 [SMILES: N#Cc1cccc(-c2nc(-c3ccc4oc5ccccc5c4c3)nc(-c3cc(-c4cccc5ccccc45)cc4sc5ccccc5c34)n2)c1 ; N#Cc1cccc(-c2nc(-c3ccc4oc5ccccc5c4c3)nc(-c3cc(-c4cccc(-c5ccccc5)c4)cc4sc5ccccc5c34)n2)c1] 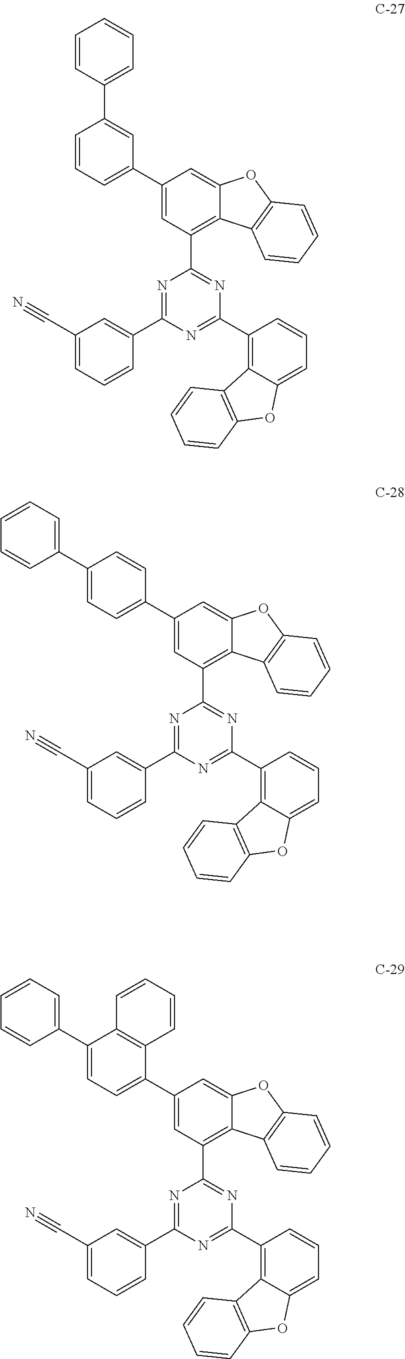 [SMILES: N#Cc1cccc(-c2nc(-c3cccc4oc5ccccc5c34)nc(-c3cc(-c4cccc(-c5ccccc5)c4)cc4oc5ccccc5c34)n2)c1 ; N#Cc1cccc(-c2nc(-c3cccc4oc5ccccc5c34)nc(-c3cc(-c4ccc(-c5ccccc5)cc4)cc4oc5ccccc5c34)n2)c1 ; N#Cc1cccc(-c2nc(-c3cccc4oc5ccccc5c34)nc(-c3cc(-c4ccc(-c5ccccc5)c5ccccc45)cc4oc5ccccc5c34)n2)c1] 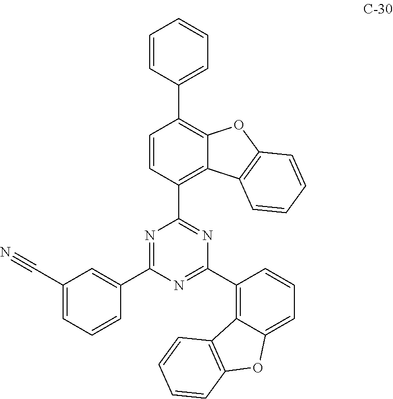 [SMILES: N#Cc1cccc(-c2nc(-c3cccc4oc5ccccc5c34)nc(-c3ccc(-c4ccccc4)c4oc5ccccc5c34)n2)c1] 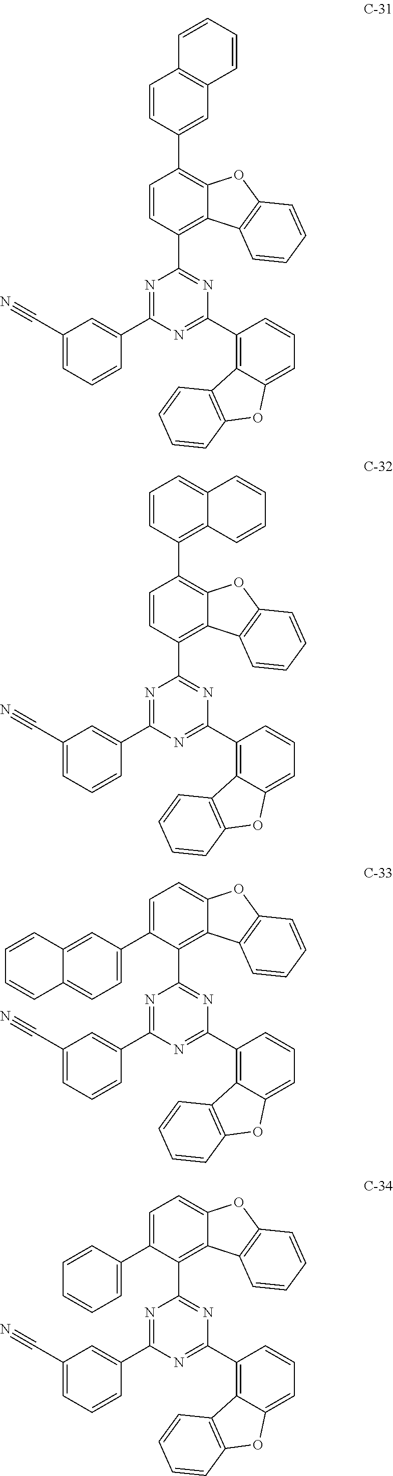 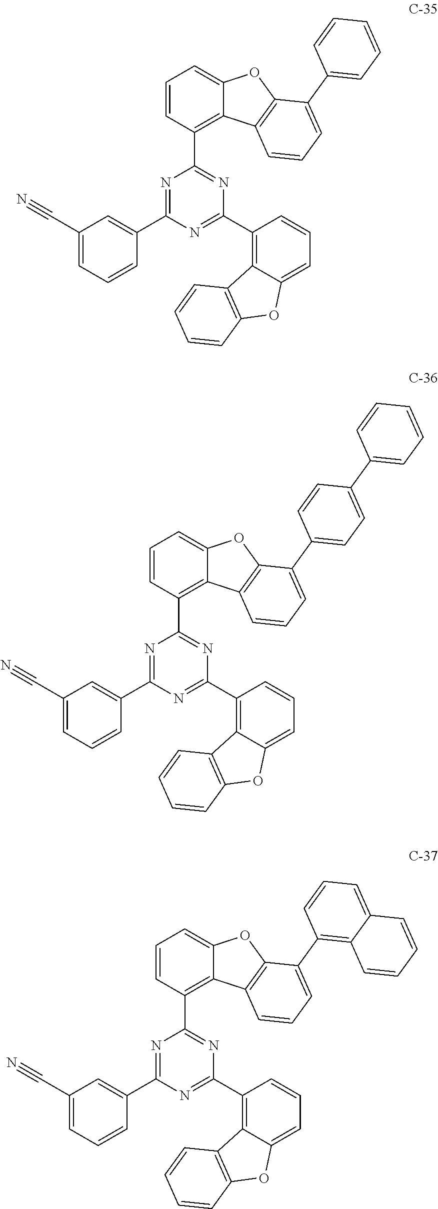 [SMILES: N#Cc1cccc(-c2nc(-c3cccc4oc5ccccc5c34)nc(-c3cccc4oc5c(-c6ccccc6)cccc5c34)n2)c1 ; N#Cc1cccc(-c2nc(-c3cccc4oc5ccccc5c34)nc(-c3cccc4oc5c(-c6ccc(-c7ccccc7)cc6)cccc5c34)n2)c1 ; N#Cc1cccc(-c2nc(-c3cccc4oc5ccccc5c34)nc(-c3cccc4oc5c(-c6cccc7ccccc67)cccc5c34)n2)c1] 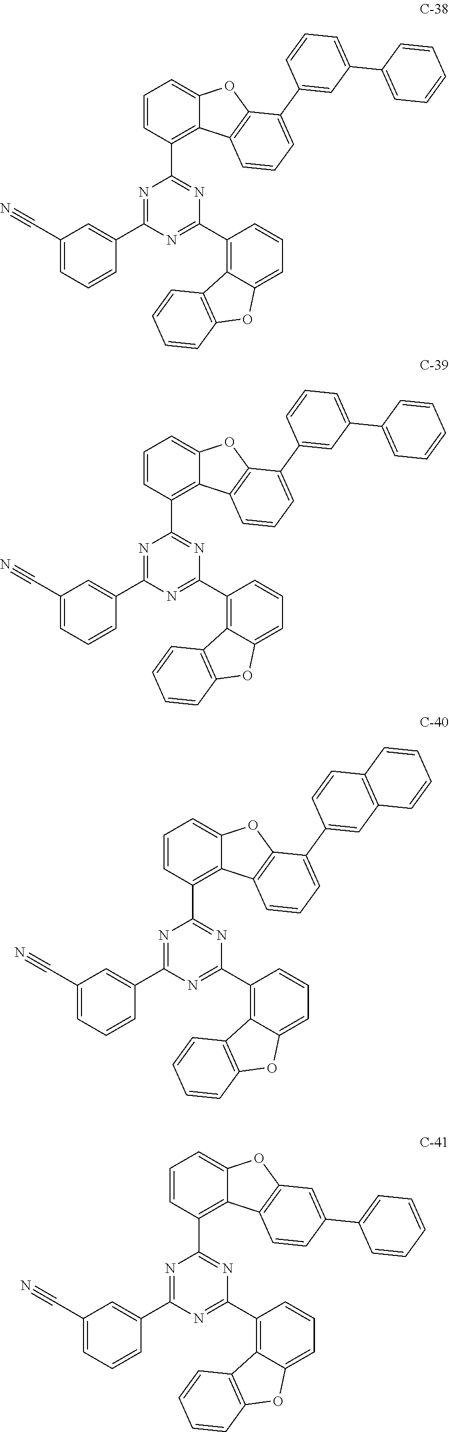 [SMILES: N#Cc1cccc(-c2nc(-c3cccc4oc5ccccc5c34)nc(-c3cccc4oc5c(-c6cccc(-c7ccccc7)c6)cccc5c34)n2)c1 ; N#Cc1cccc(-c2nc(-c3cccc4oc5ccccc5c34)nc(-c3cccc4oc5c(-c6cccc(-c7ccccc7)c6)cccc5c34)n2)c1 ; N#Cc1cccc(-c2nc(-c3cccc4oc5ccccc5c34)nc(-c3cccc4oc5c(-c6ccc7ccccc7c6)cccc5c34)n2)c1 ; N#Cc1cccc(-c2nc(-c3cccc4oc5ccccc5c34)nc(-c3cccc4oc5cc(-c6ccccc6)ccc5c34)n2)c1] 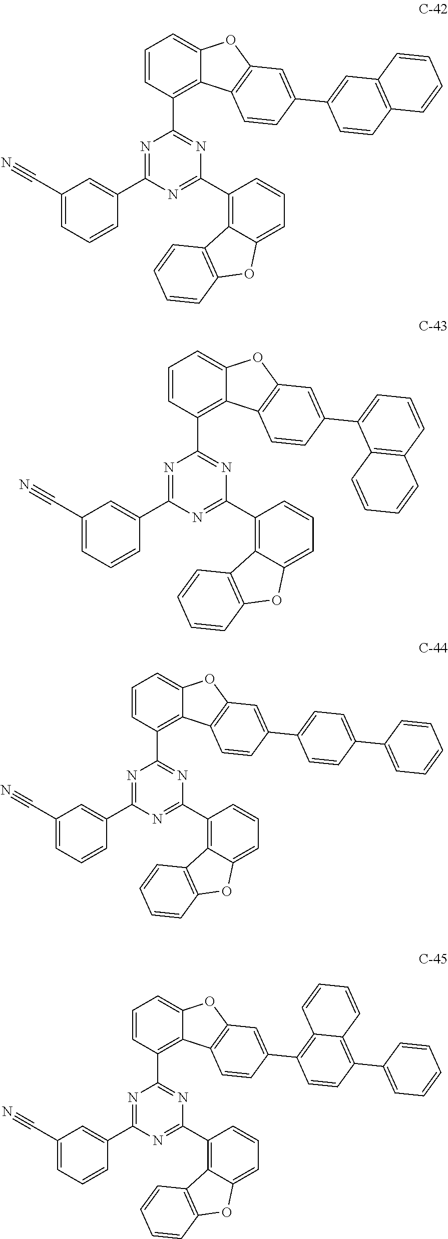 [SMILES: N#Cc1cccc(-c2nc(-c3cccc4oc5ccccc5c34)nc(-c3cccc4oc5cc(-c6ccc7ccccc7c6)ccc5c34)n2)c1 ; N#Cc1cccc(-c2nc(-c3cccc4oc5ccccc5c34)nc(-c3cccc4oc5cc(-c6cccc7ccccc67)ccc5c34)n2)c1 ; N#Cc1cccc(-c2nc(-c3cccc4oc5ccccc5c34)nc(-c3cccc4oc5cc(-c6ccc(-c7ccccc7)cc6)ccc5c34)n2)c1 ; N#Cc1cccc(-c2nc(-c3cccc4oc5ccccc5c34)nc(-c3cccc4oc5cc(-c6ccc(-c7ccccc7)c7ccccc67)ccc5c34)n2)c1] 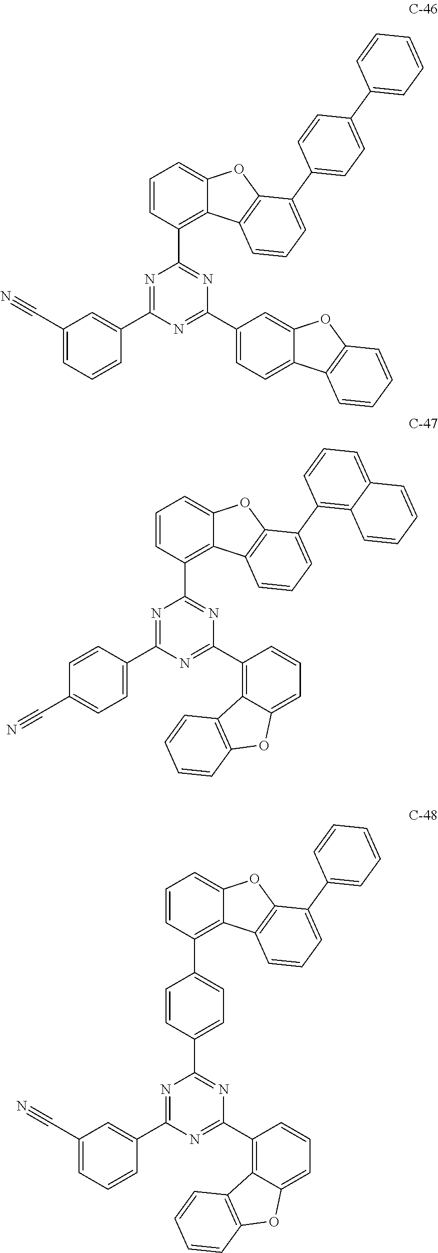 [SMILES: N#Cc1cccc(-c2nc(-c3ccc4c(c3)oc3ccccc34)nc(-c3cccc4oc5c(-c6ccc(-c7ccccc7)cc6)cccc5c34)n2)c1 ; N#Cc1ccc(-c2nc(-c3cccc4oc5ccccc5c34)nc(-c3cccc4oc5c(-c6cccc7ccccc67)cccc5c34)n2)cc1 ; N#Cc1cccc(-c2nc(-c3ccc(-c4cccc5oc6c(-c7ccccc7)cccc6c45)cc3)nc(-c3cccc4oc5ccccc5c34)n2)c1] 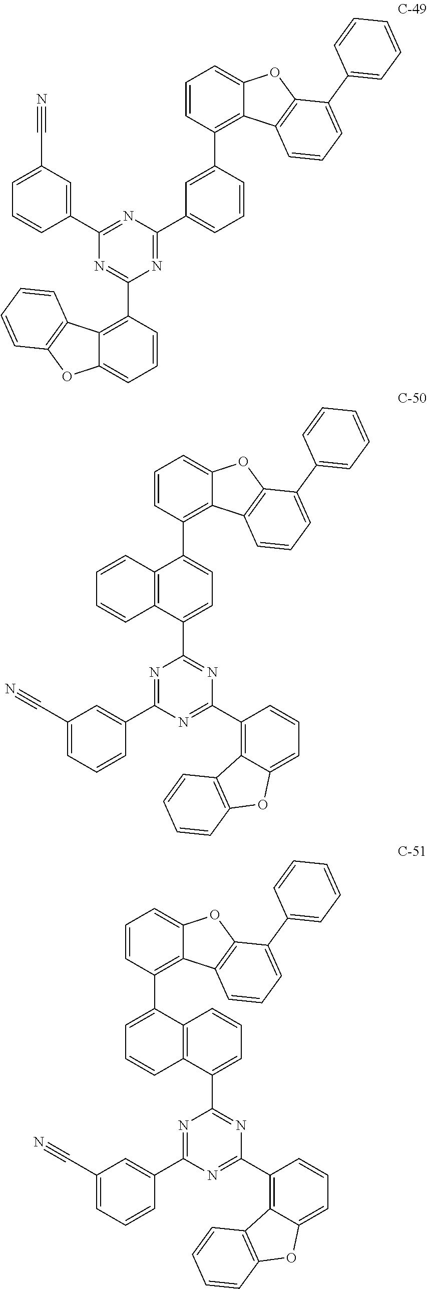 [SMILES: N#Cc1cccc(-c2nc(-c3cccc(-c4cccc5oc6c(-c7ccccc7)cccc6c45)c3)nc(-c3cccc4oc5ccccc5c34)n2)c1 ; N#Cc1cccc(-c2nc(-c3ccc(-c4cccc5oc6c(-c7ccccc7)cccc6c45)c4ccccc34)nc(-c3cccc4oc5ccccc5c34)n2)c1 ; N#Cc1cccc(-c2nc(-c3cccc4c(-c5cccc6oc7c(-c8ccccc8)cccc7c56)cccc34)nc(-c3cccc4oc5ccccc5c34)n2)c1] 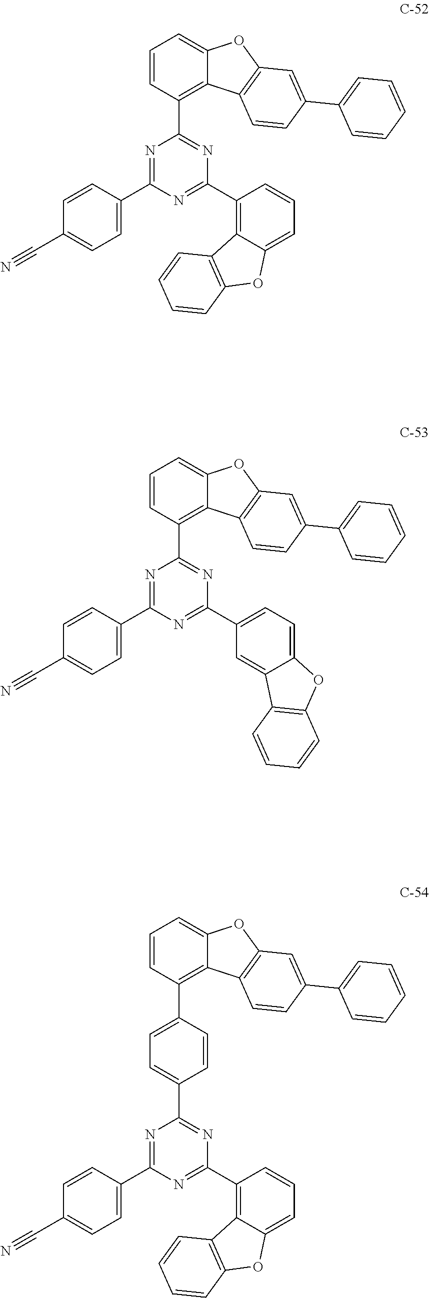 [SMILES: N#Cc1ccc(-c2nc(-c3cccc4oc5ccccc5c34)nc(-c3cccc4oc5cc(-c6ccccc6)ccc5c34)n2)cc1 ; N#Cc1ccc(-c2nc(-c3ccc4oc5ccccc5c4c3)nc(-c3cccc4oc5cc(-c6ccccc6)ccc5c34)n2)cc1 ; N#Cc1ccc(-c2nc(-c3ccc(-c4cccc5oc6cc(-c7ccccc7)ccc6c45)cc3)nc(-c3cccc4oc5ccccc5c34)n2)cc1] 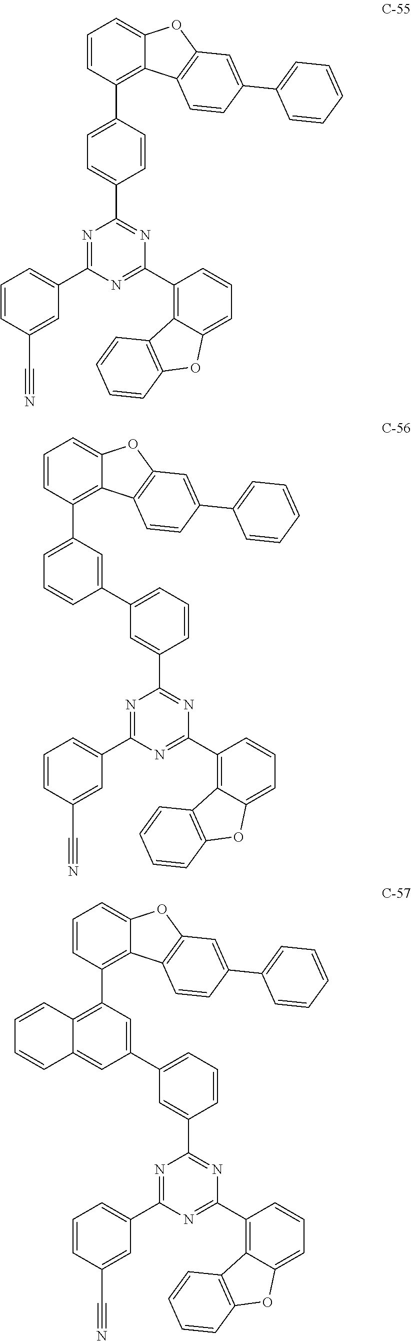 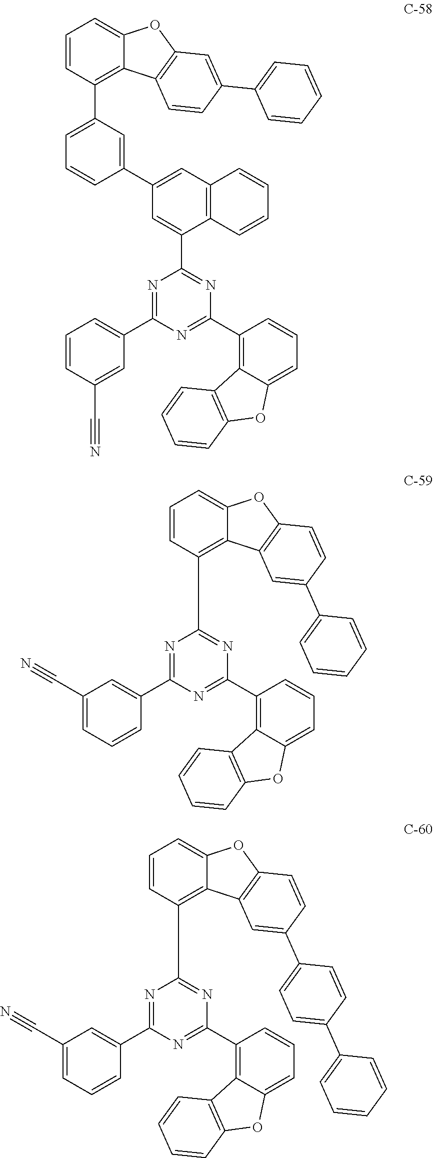 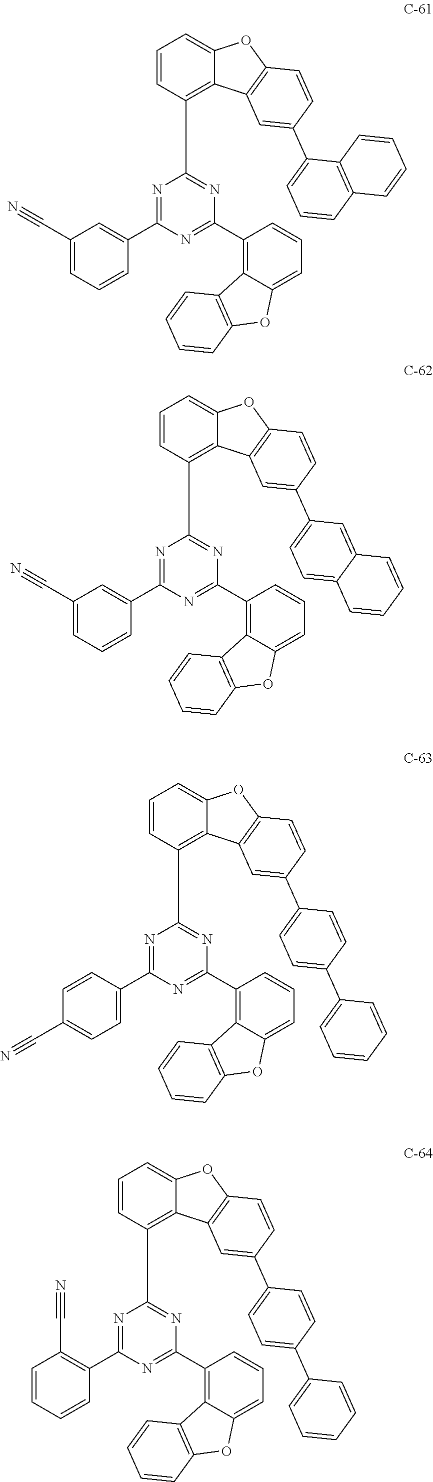 [SMILES: N#Cc1cccc(-c2nc(-c3cccc4oc5ccccc5c34)nc(-c3cccc4oc5ccc(-c6cccc7ccccc67)cc5c34)n2)c1 ; N#Cc1cccc(-c2nc(-c3cccc4oc5ccccc5c34)nc(-c3cccc4oc5ccc(-c6ccc7ccccc7c6)cc5c34)n2)c1 ; N#Cc1ccc(-c2nc(-c3cccc4oc5ccccc5c34)nc(-c3cccc4oc5ccc(-c6ccc(-c7ccccc7)cc6)cc5c34)n2)cc1 ; N#Cc1ccccc1-c1nc(-c2cccc3oc4ccccc4c23)nc(-c2cccc3oc4ccc(-c5ccc(-c6ccccc6)cc5)cc4c23)n1] 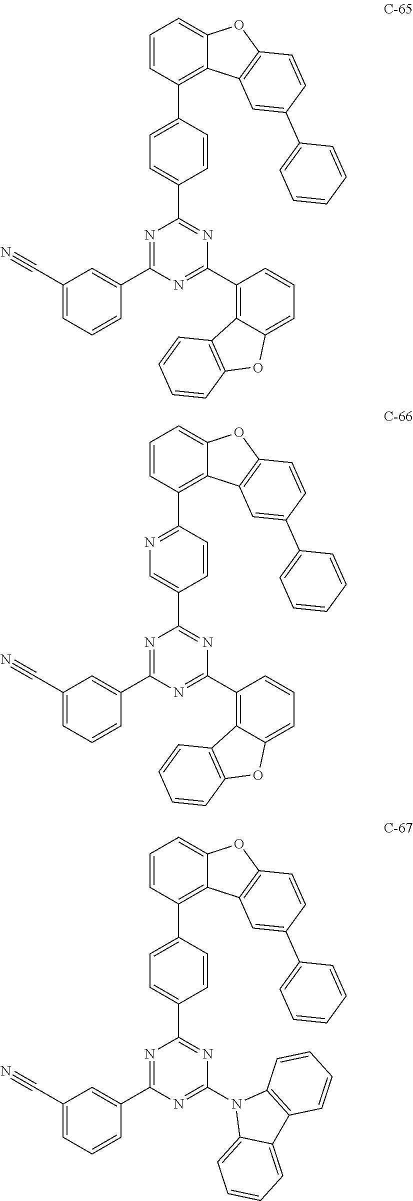 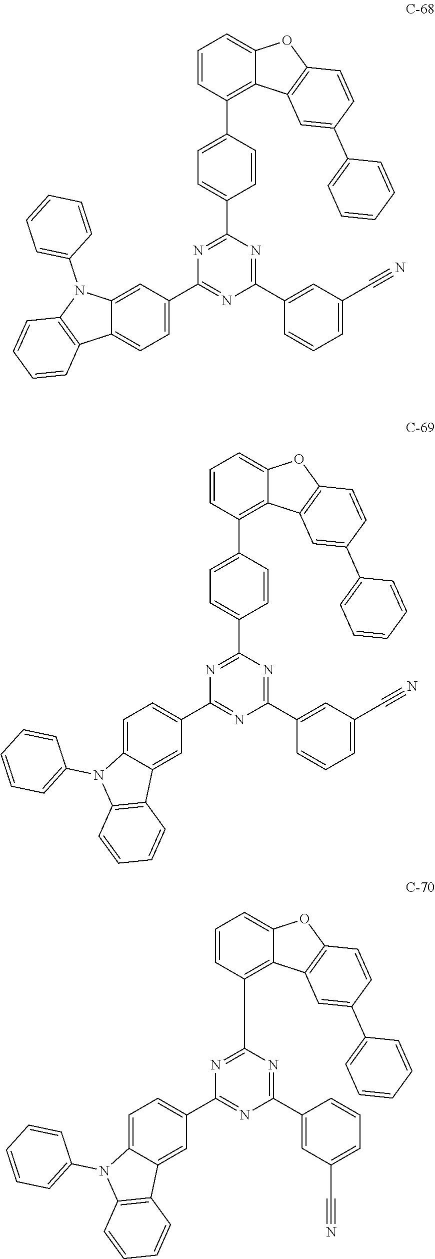 [SMILES: N#Cc1cccc(-c2nc(-c3ccc(-c4cccc5oc6ccc(-c7ccccc7)cc6c45)cc3)nc(-c3ccc4c5ccccc5n(-c5ccccc5)c4c3)n2)c1 ; N#Cc1cccc(-c2nc(-c3ccc(-c4cccc5oc6ccc(-c7ccccc7)cc6c45)cc3)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4oc5ccc(-c6ccccc6)cc5c34)n2)c1] 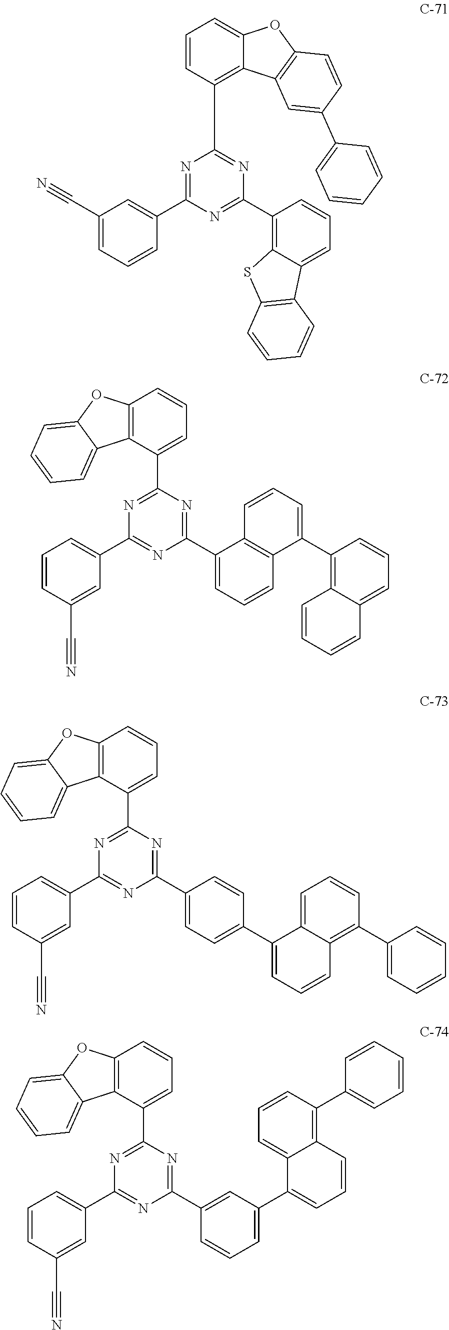 [SMILES: N#Cc1cccc(-c2nc(-c3cccc4c3sc3ccccc34)nc(-c3cccc4oc5ccc(-c6ccccc6)cc5c34)n2)c1 ; N#Cc1cccc(-c2nc(-c3cccc4c(-c5cccc6ccccc56)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1 ; N#Cc1cccc(-c2nc(-c3cccc(-c4cccc5c(-c6ccccc6)cccc45)c3)nc(-c3cccc4oc5ccccc5c34)n2)c1] 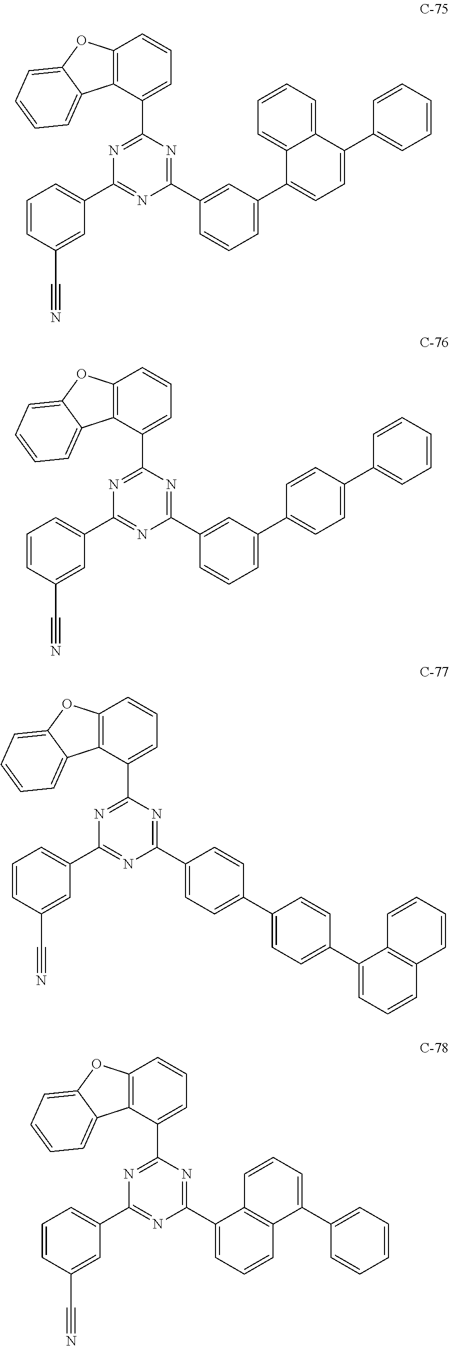 [SMILES: N#Cc1cccc(-c2nc(-c3cccc(-c4ccc(-c5ccccc5)c5ccccc45)c3)nc(-c3cccc4oc5ccccc5c34)n2)c1 ; N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3ccc(-c4ccc(-c5cccc6ccccc56)cc4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1] 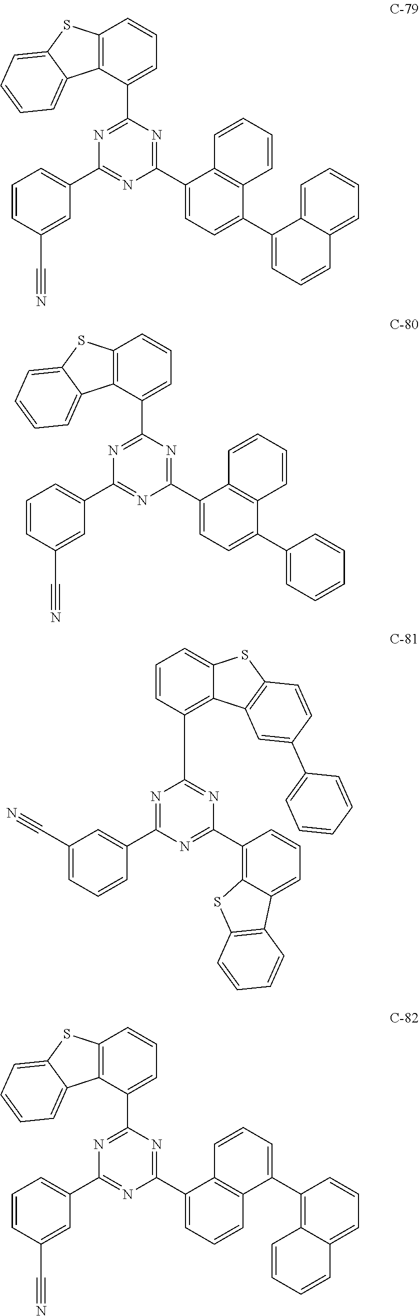 [SMILES: N#Cc1cccc(-c2nc(-c3ccc(-c4cccc5ccccc45)c4ccccc34)nc(-c3cccc4sc5ccccc5c34)n2)c1 ; N#Cc1cccc(-c2nc(-c3ccc(-c4ccccc4)c4ccccc34)nc(-c3cccc4sc5ccccc5c34)n2)c1 ; N#Cc1cccc(-c2nc(-c3cccc4c3sc3ccccc34)nc(-c3cccc4sc5ccc(-c6ccccc6)cc5c34)n2)c1 ; N#Cc1cccc(-c2nc(-c3cccc4c(-c5cccc6ccccc56)cccc34)nc(-c3cccc4sc5ccccc5c34)n2)c1] 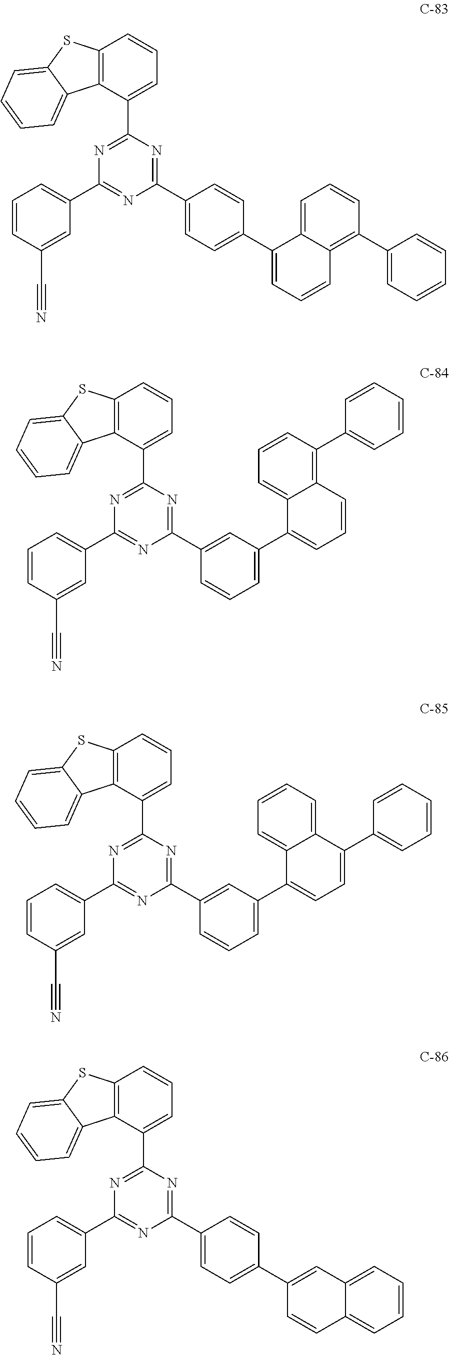 [SMILES: N#Cc1cccc(-c2nc(-c3ccc(-c4cccc5c(-c6ccccc6)cccc45)cc3)nc(-c3cccc4sc5ccccc5c34)n2)c1 ; N#Cc1cccc(-c2nc(-c3cccc(-c4cccc5c(-c6ccccc6)cccc45)c3)nc(-c3cccc4sc5ccccc5c34)n2)c1 ; N#Cc1cccc(-c2nc(-c3cccc(-c4ccc(-c5ccccc5)c5ccccc45)c3)nc(-c3cccc4sc5ccccc5c34)n2)c1 ; N#Cc1cccc(-c2nc(-c3ccc(-c4ccc5ccccc5c4)cc3)nc(-c3cccc4sc5ccccc5c34)n2)c1] 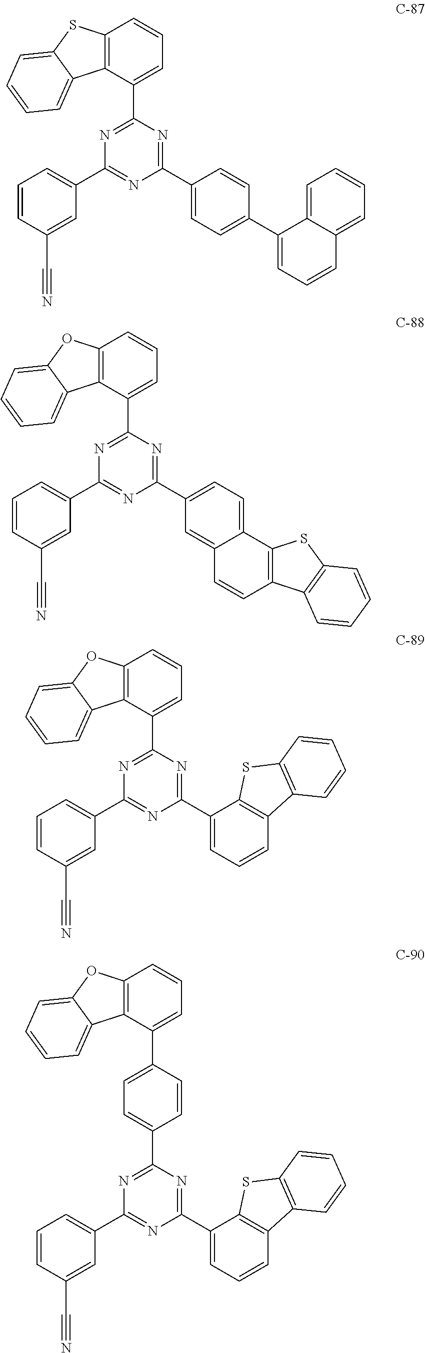 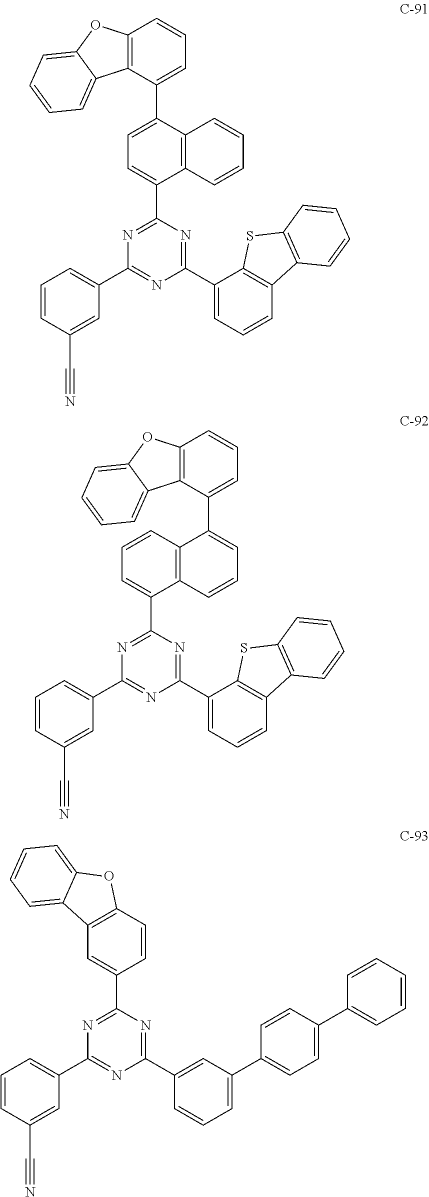 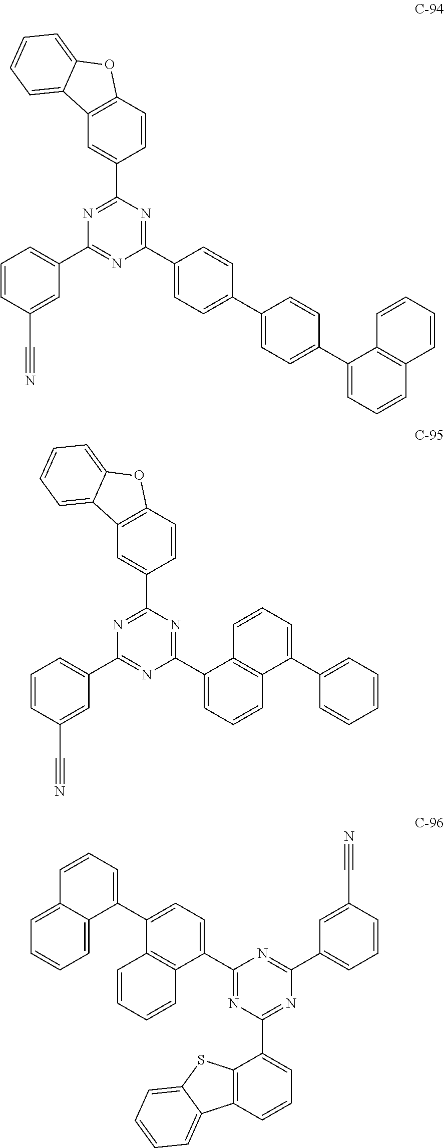 [SMILES: N#Cc1cccc(-c2nc(-c3ccc(-c4ccc(-c5cccc6ccccc56)cc4)cc3)nc(-c3ccc4oc5ccccc5c4c3)n2)c1 ; N#Cc1cccc(-c2nc(-c3ccc4oc5ccccc5c4c3)nc(-c3cccc4c(-c5ccccc5)cccc34)n2)c1 ; N#Cc1cccc(-c2nc(-c3ccc(-c4cccc5ccccc45)c4ccccc34)nc(-c3cccc4c3sc3ccccc34)n2)c1] 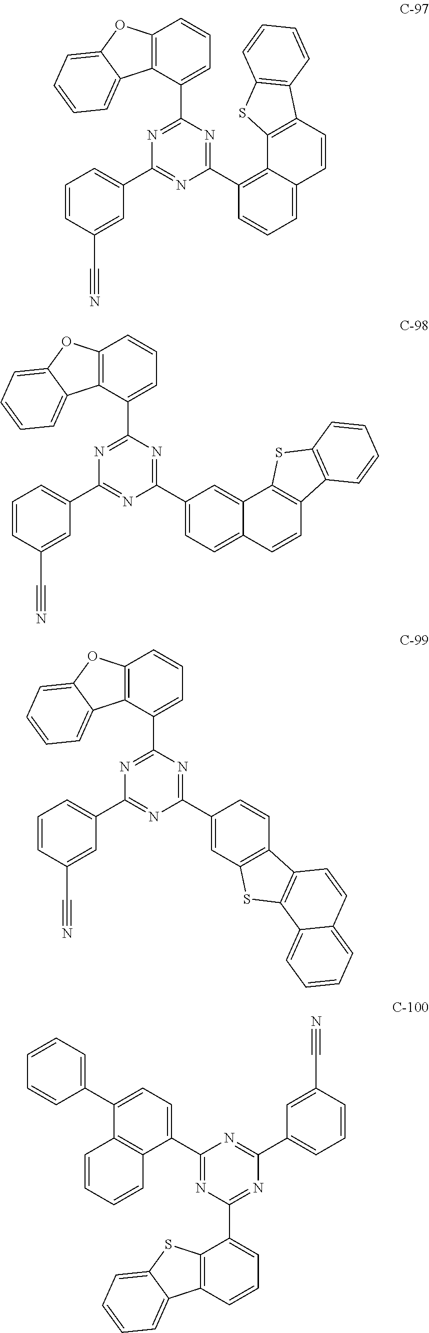 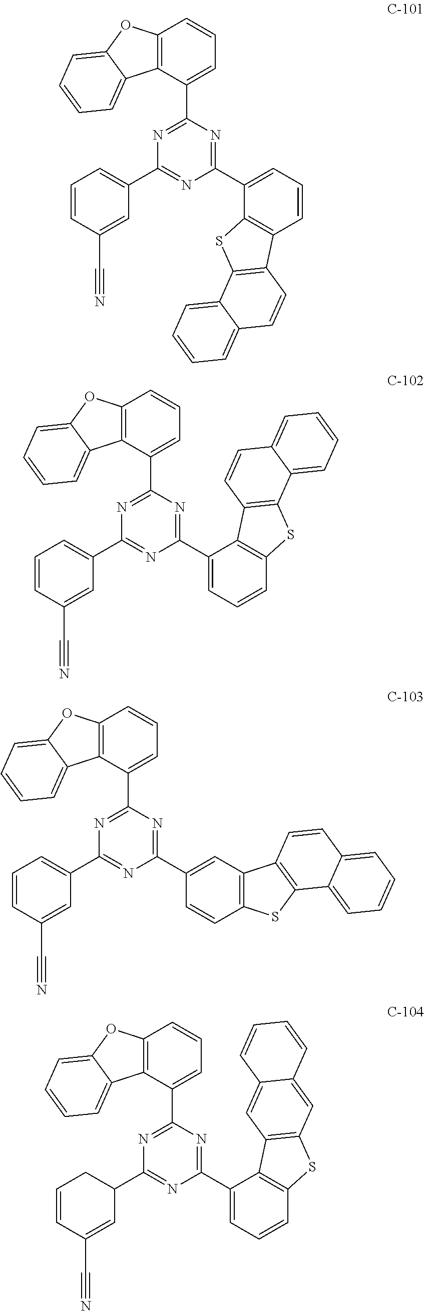 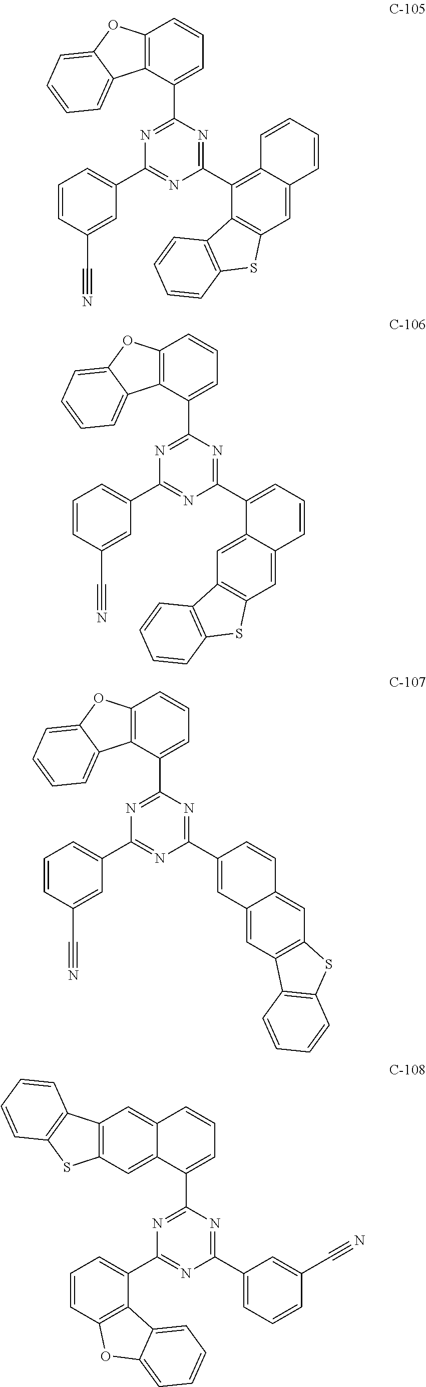 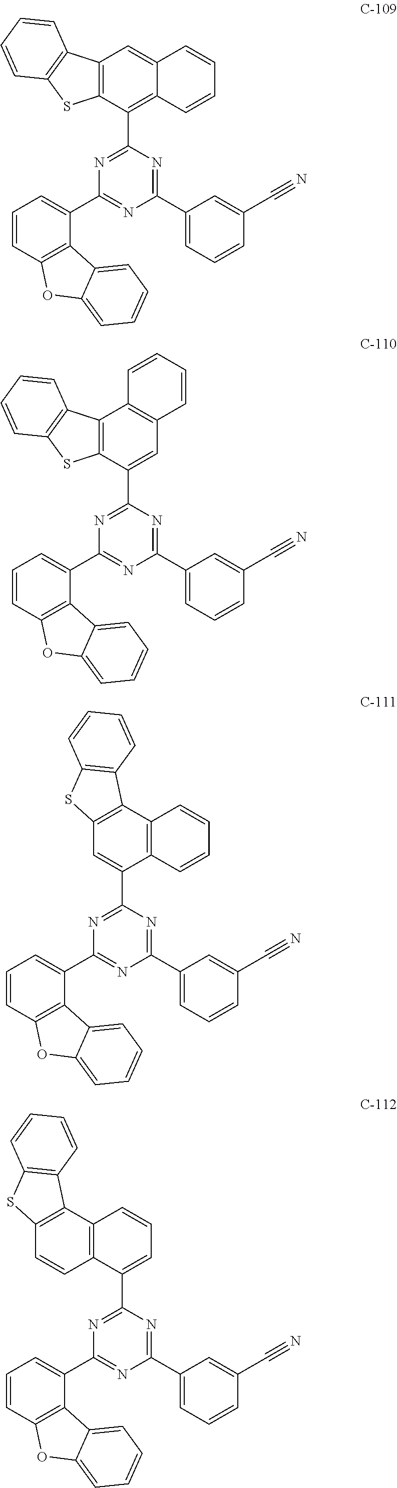 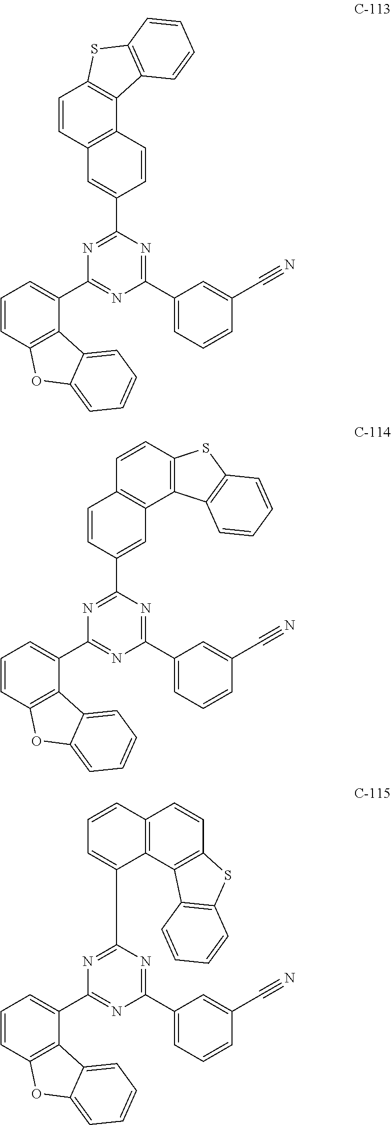 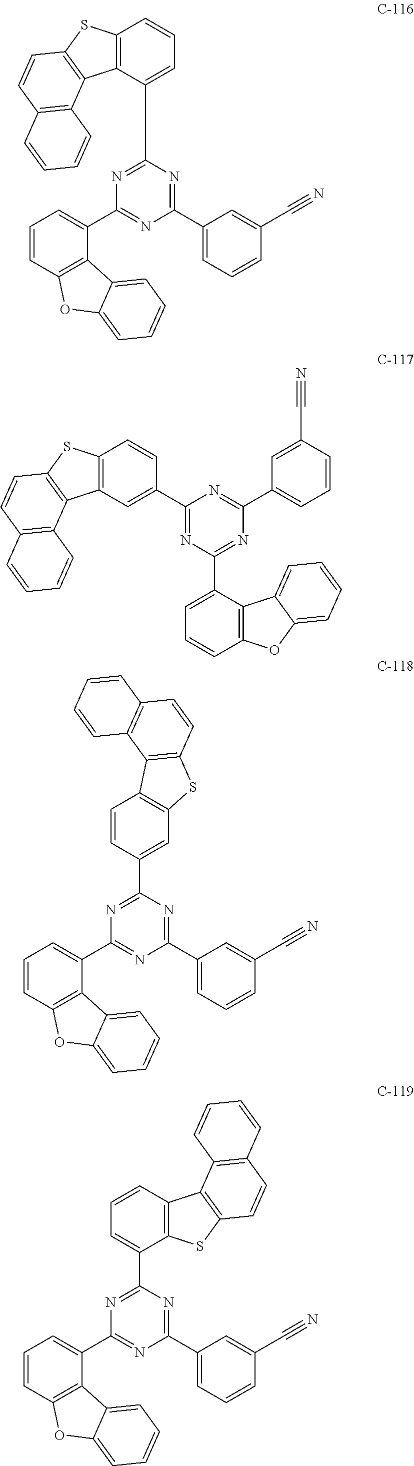 [SMILES: N#Cc1cccc(-c2nc(-c3cccc4oc5ccccc5c34)nc(-c3cccc4sc5ccc6ccccc6c5c34)n2)c1 ; N#Cc1cccc(-c2nc(-c3ccc4sc5ccc6ccccc6c5c4c3)nc(-c3cccc4oc5ccccc5c34)n2)c1 ; N#Cc1cccc(-c2nc(-c3ccc4c(c3)sc3ccc5ccccc5c34)nc(-c3cccc4oc5ccccc5c34)n2)c1 ; N#Cc1cccc(-c2nc(-c3cccc4c3sc3ccc5ccccc5c34)nc(-c3cccc4oc5ccccc5c34)n2)c1] 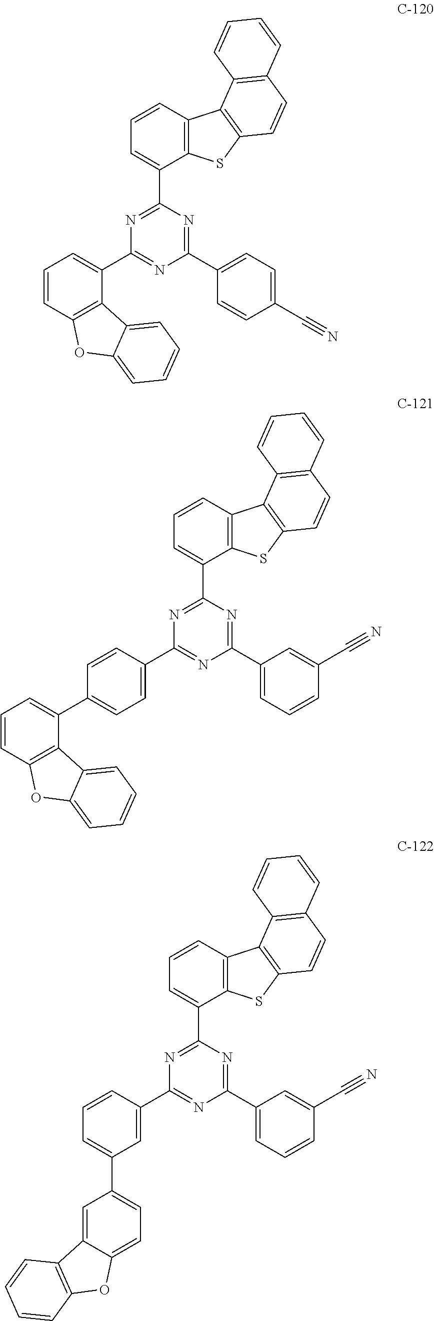 [SMILES: N#Cc1ccc(-c2nc(-c3cccc4c3sc3ccc5ccccc5c34)nc(-c3cccc4oc5ccccc5c34)n2)cc1 ; N#Cc1cccc(-c2nc(-c3ccc(-c4cccc5oc6ccccc6c45)cc3)nc(-c3cccc4c3sc3ccc5ccccc5c34)n2)c1 ; N#Cc1cccc(-c2nc(-c3cccc(-c4ccc5oc6ccccc6c5c4)c3)nc(-c3cccc4c3sc3ccc5ccccc5c34)n2)c1] 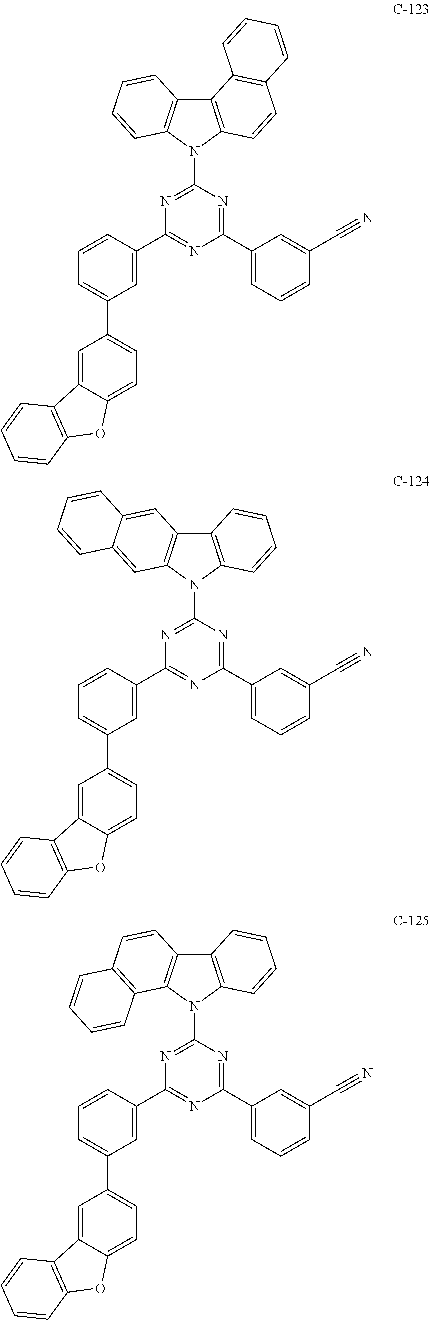 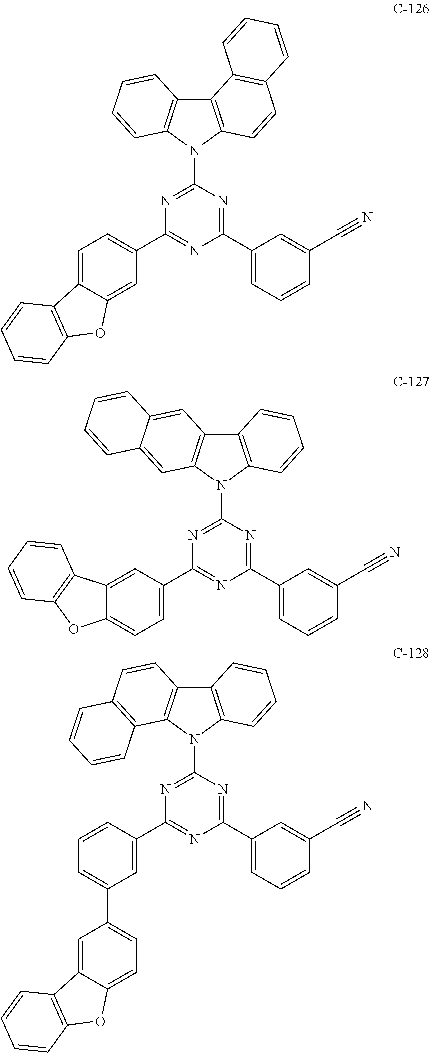 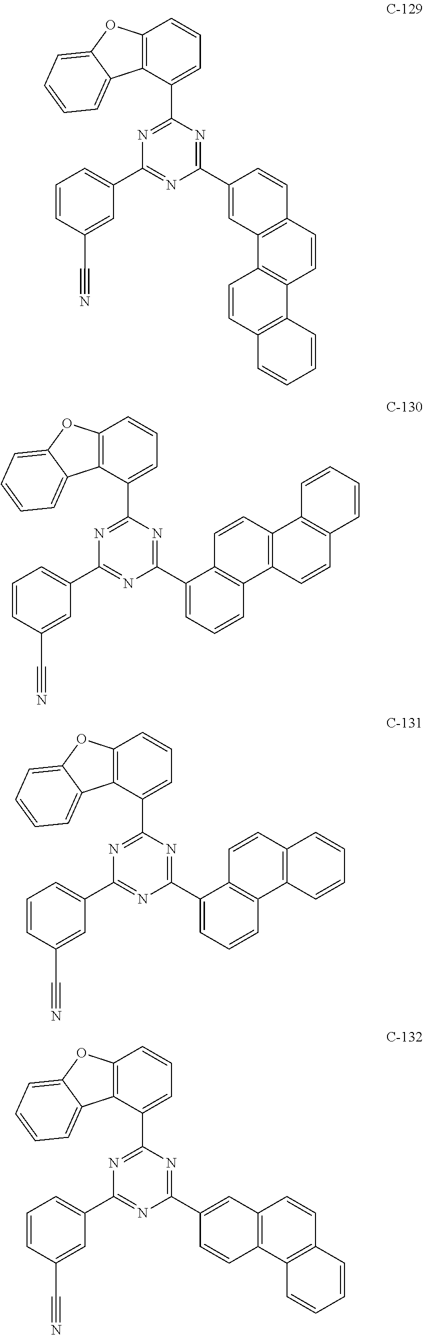 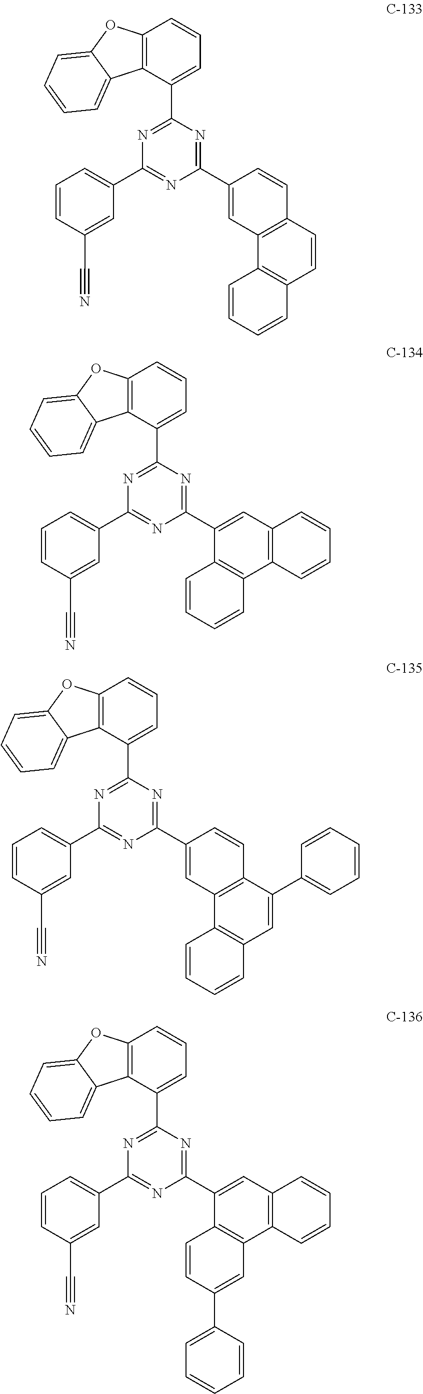 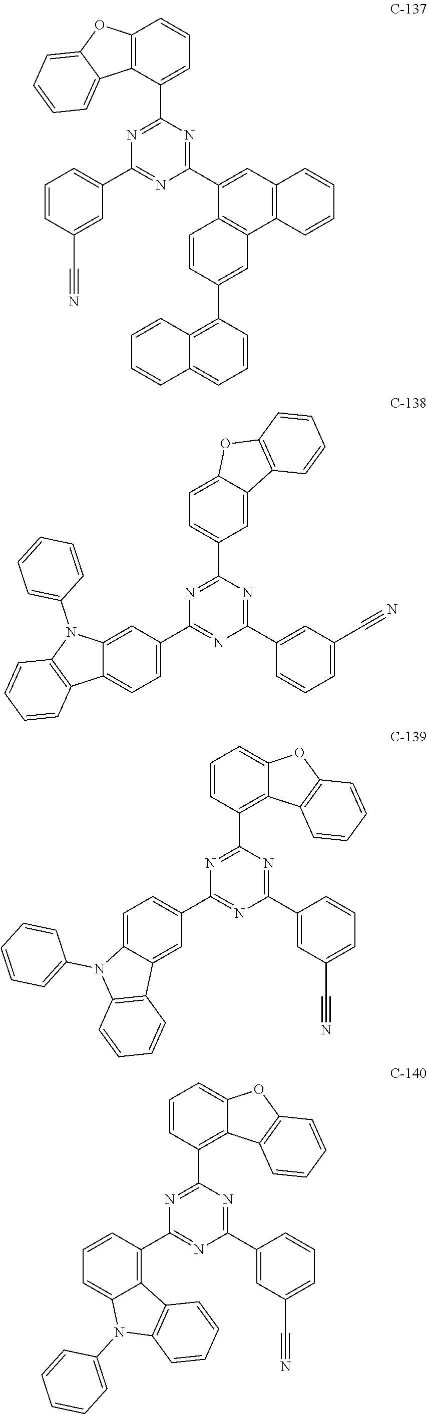 [SMILES: N#Cc1cccc(-c2nc(-c3cc4ccccc4c4cc(-c5cccc6ccccc56)ccc34)nc(-c3cccc4oc5ccccc5c34)n2)c1 ; N#Cc1cccc(-c2nc(-c3ccc4oc5ccccc5c4c3)nc(-c3ccc4c5ccccc5n(-c5ccccc5)c4c3)n2)c1 ; N#Cc1cccc(-c2nc(-c3ccc4c(c3)c3ccccc3n4-c3ccccc3)nc(-c3cccc4oc5ccccc5c34)n2)c1 ; N#Cc1cccc(-c2nc(-c3cccc4oc5ccccc5c34)nc(-c3cccc4c3c3ccccc3n4-c3ccccc3)n2)c1] 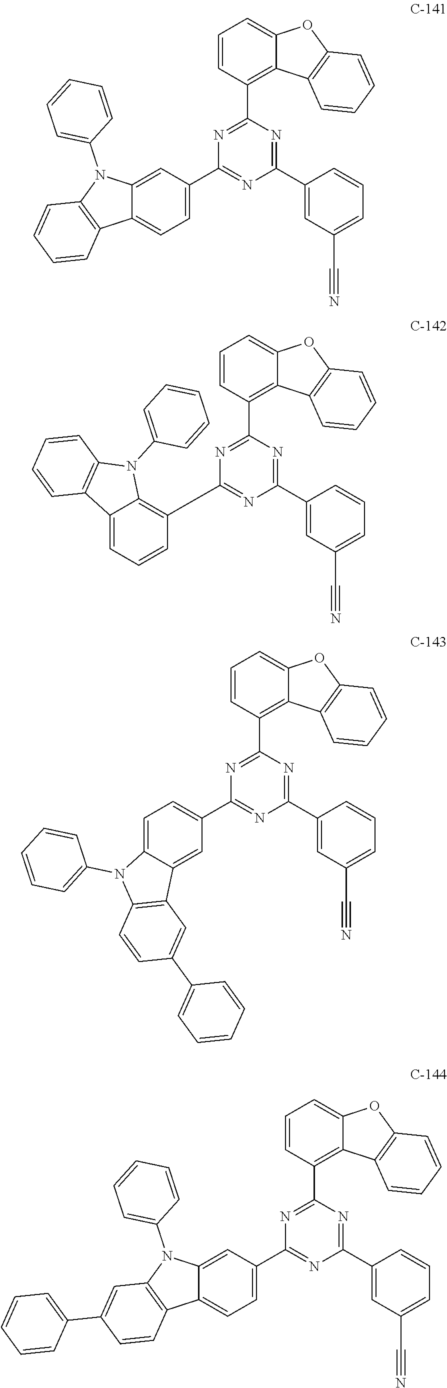 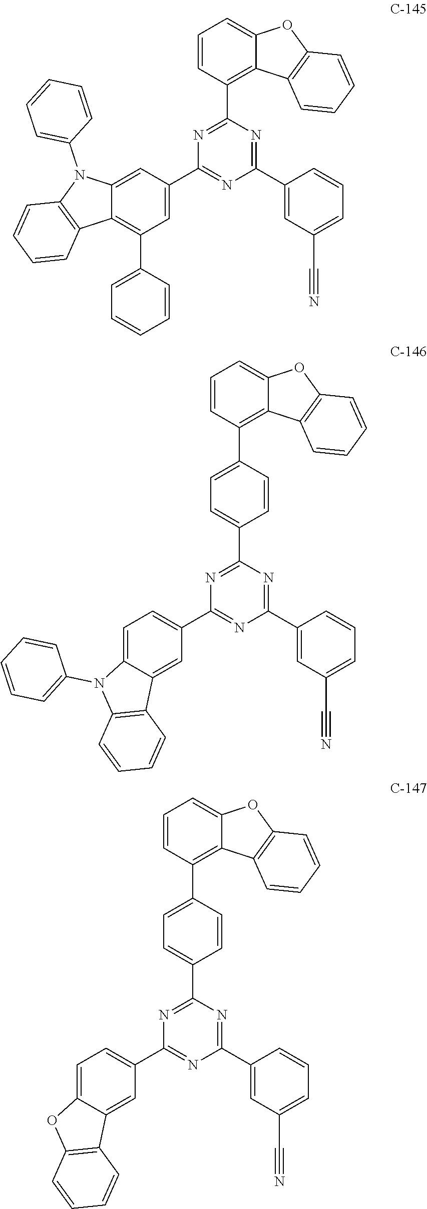 [SMILES: N#Cc1cccc(-c2nc(-c3cc(-c4ccccc4)c4c5ccccc5n(-c5ccccc5)c4c3)nc(-c3cccc4oc5ccccc5c34)n2)c1 ; N#Cc1cccc(-c2nc(-c3ccc(-c4cccc5oc6ccccc6c45)cc3)nc(-c3ccc4c(c3)c3ccccc3n4-c3ccccc3)n2)c1 ; N#Cc1cccc(-c2nc(-c3ccc(-c4cccc5oc6ccccc6c45)cc3)nc(-c3ccc4oc5ccccc5c4c3)n2)c1] 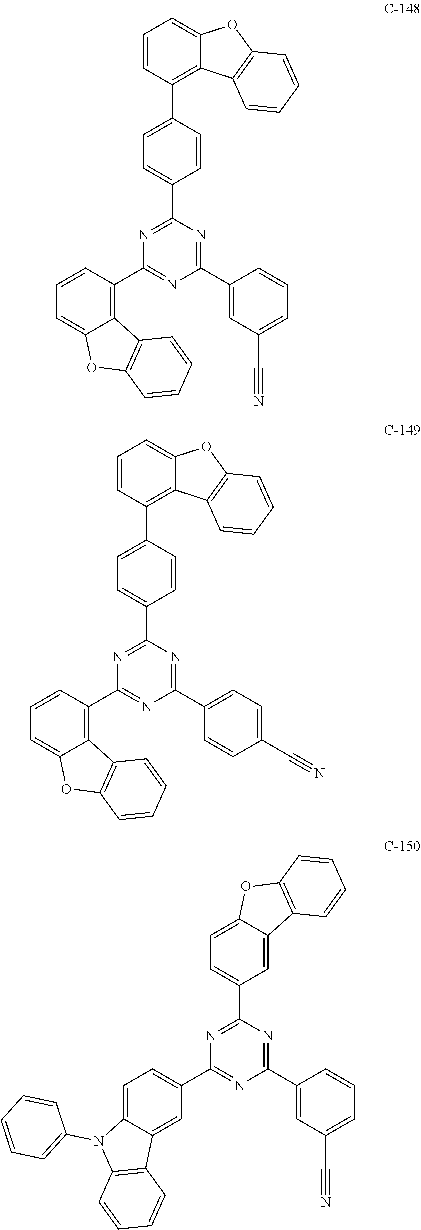 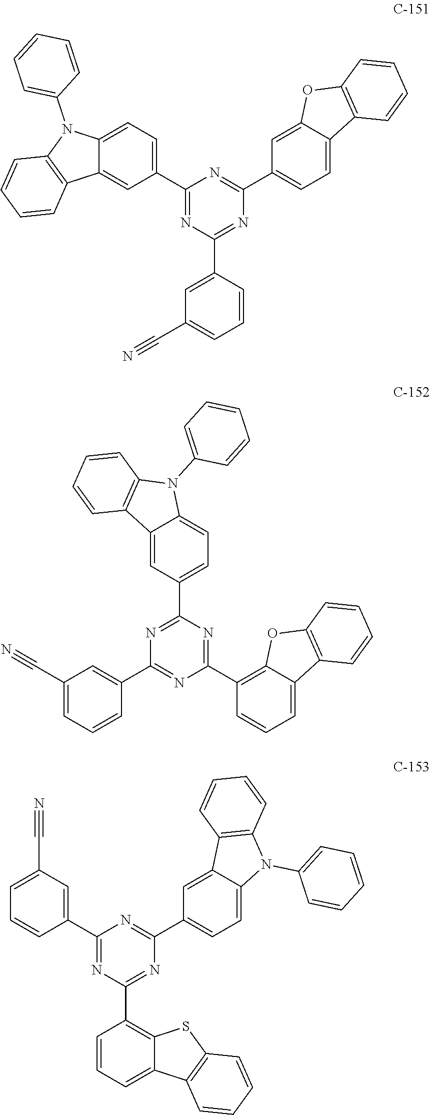 [SMILES: N#Cc1cccc(-c2nc(-c3ccc4c(c3)oc3ccccc34)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4c3oc3ccccc34)n2)c1 ; N#Cc1cccc(-c2nc(-c3ccc4c(c3)c3ccccc3n4-c3ccccc3)nc(-c3cccc4c3sc3ccccc34)n2)c1] 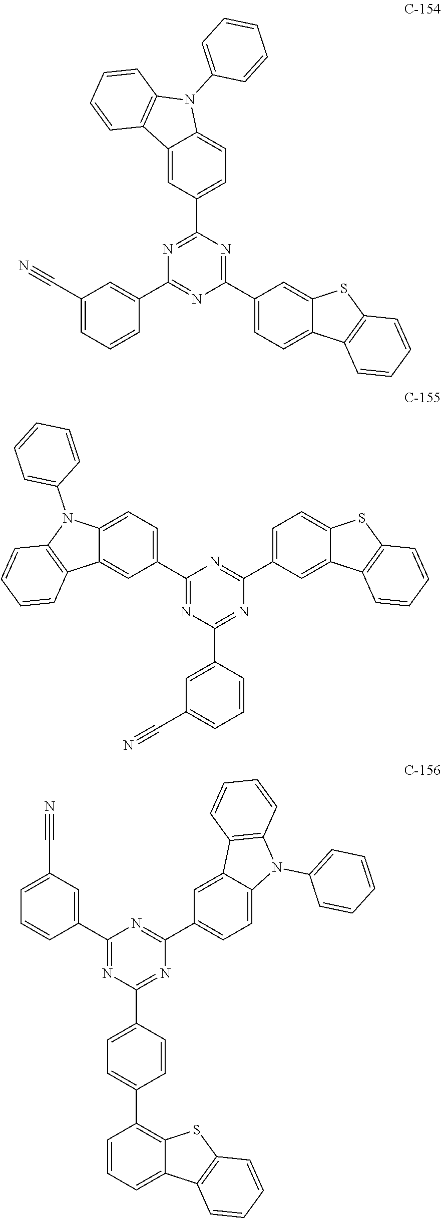 [SMILES: N#Cc1cccc(-c2nc(-c3ccc4c(c3)sc3ccccc34)nc(-c3ccc4c(c3)c3ccccc3n4-c3ccccc3)n2)c1 ; N#Cc1cccc(-c2nc(-c3ccc4sc5ccccc5c4c3)nc(-c3ccc4c(c3)c3ccccc3n4-c3ccccc3)n2)c1 ; N#Cc1cccc(-c2nc(-c3ccc(-c4cccc5c4sc4ccccc45)cc3)nc(-c3ccc4c(c3)c3ccccc3n4-c3ccccc3)n2)c1] 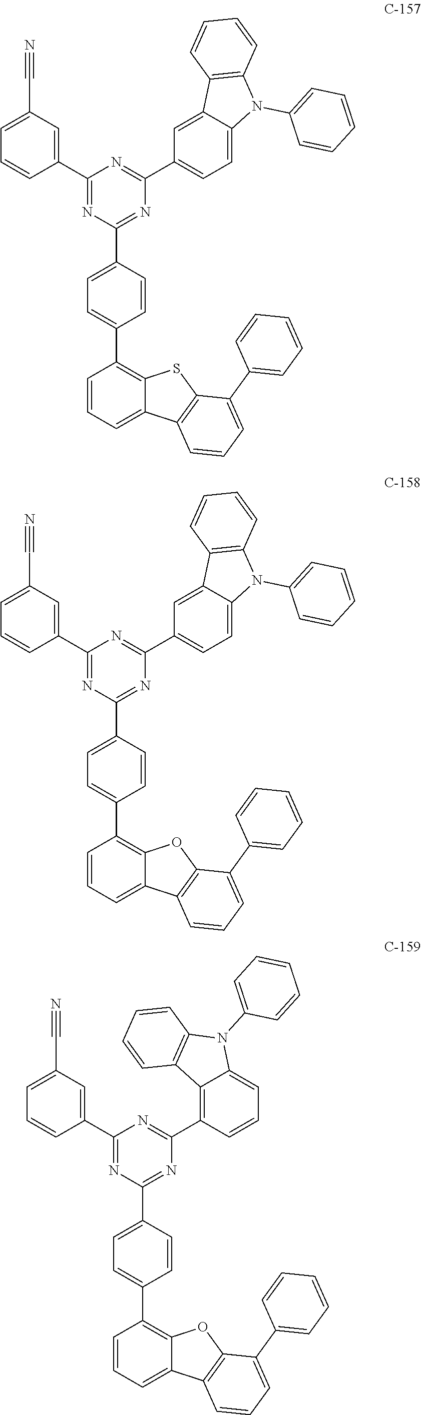 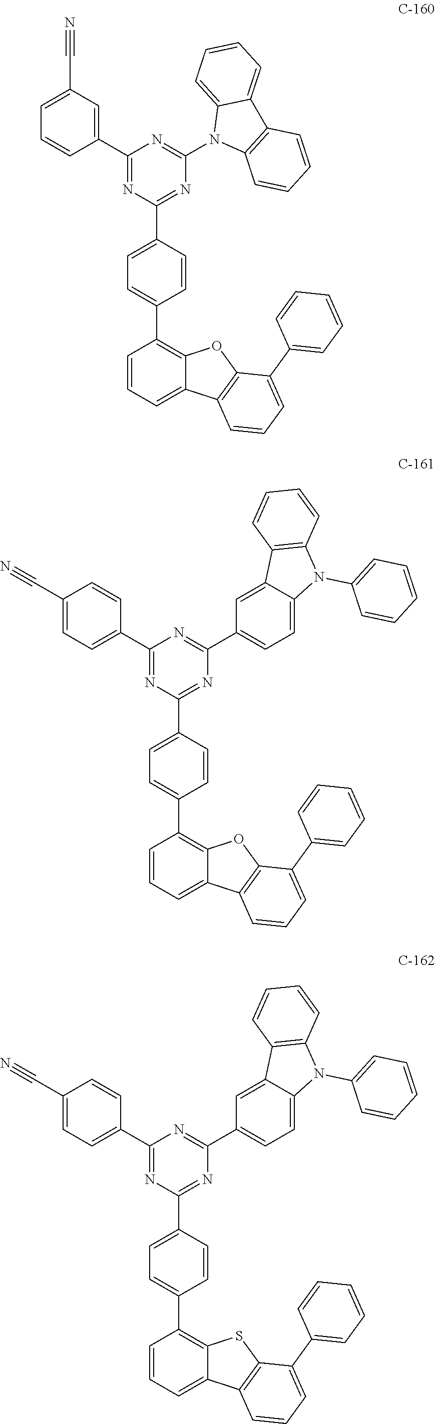 [SMILES: N#Cc1cccc(-c2nc(-c3ccc(-c4cccc5c4oc4c(-c6ccccc6)cccc45)cc3)nc(-n3c4ccccc4c4ccccc43)n2)c1 ; N#Cc1ccc(-c2nc(-c3ccc(-c4cccc5c4oc4c(-c6ccccc6)cccc45)cc3)nc(-c3ccc4c(c3)c3ccccc3n4-c3ccccc3)n2)cc1 ; N#Cc1ccc(-c2nc(-c3ccc(-c4cccc5c4sc4c(-c6ccccc6)cccc45)cc3)nc(-c3ccc4c(c3)c3ccccc3n4-c3ccccc3)n2)cc1] 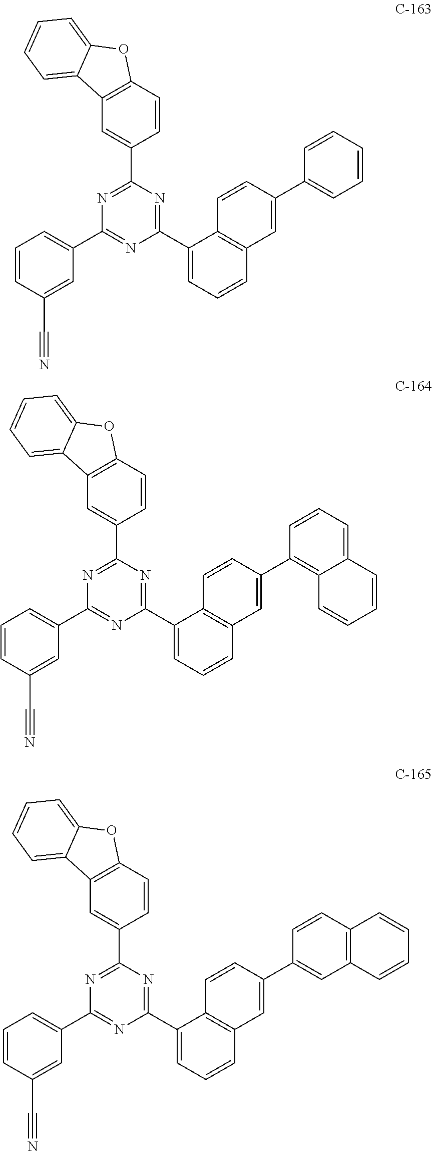 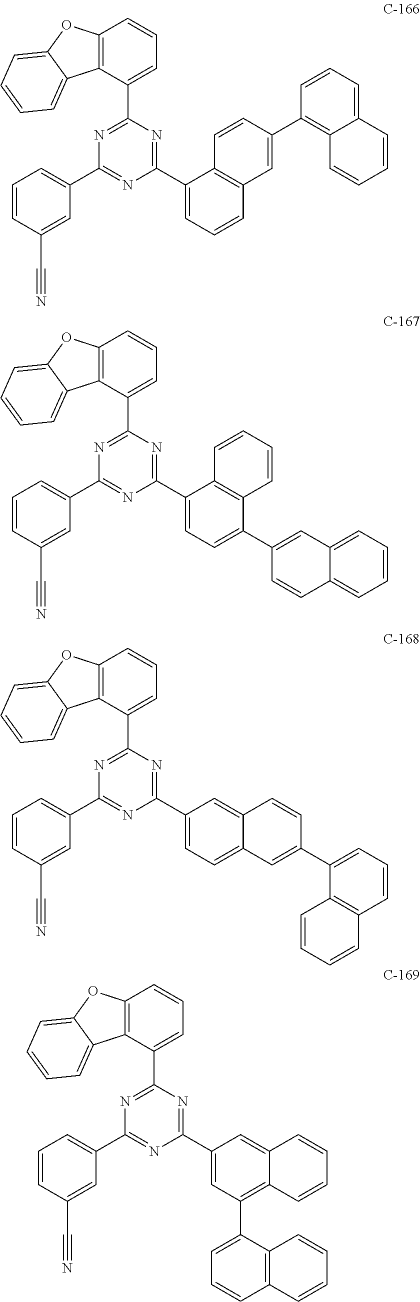 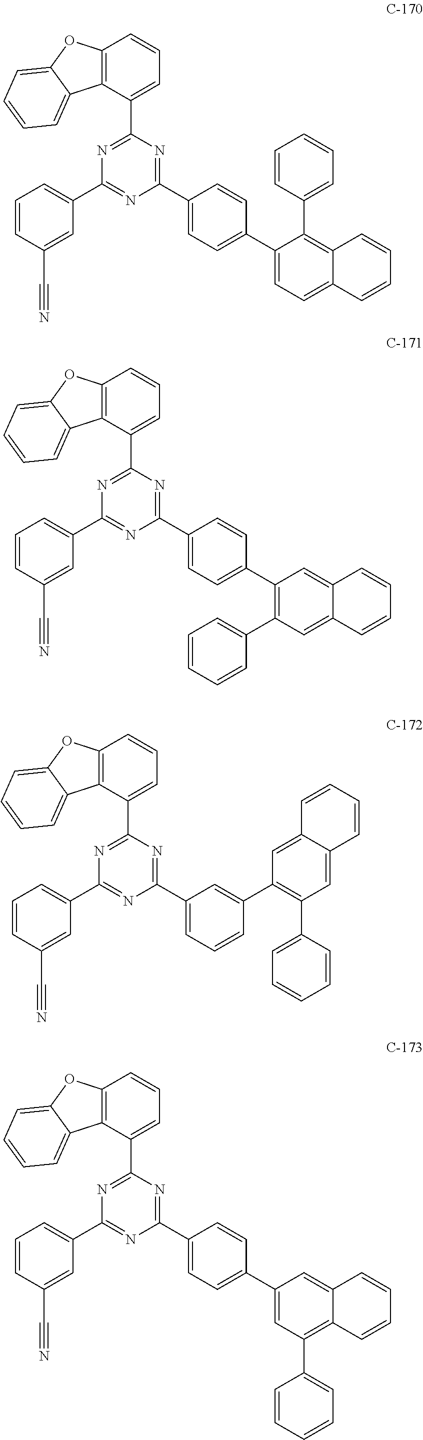 [SMILES: N#Cc1cccc(-c2nc(-c3ccc(-c4ccc5ccccc5c4-c4ccccc4)cc3)nc(-c3cccc4oc5ccccc5c34)n2)c1 ; N#Cc1cccc(-c2nc(-c3ccc(-c4cc5ccccc5cc4-c4ccccc4)cc3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3ccc(-c4cc(-c5ccccc5)c5ccccc5c4)cc3)nc(-c3cccc4oc5ccccc5c34)n2)c1] 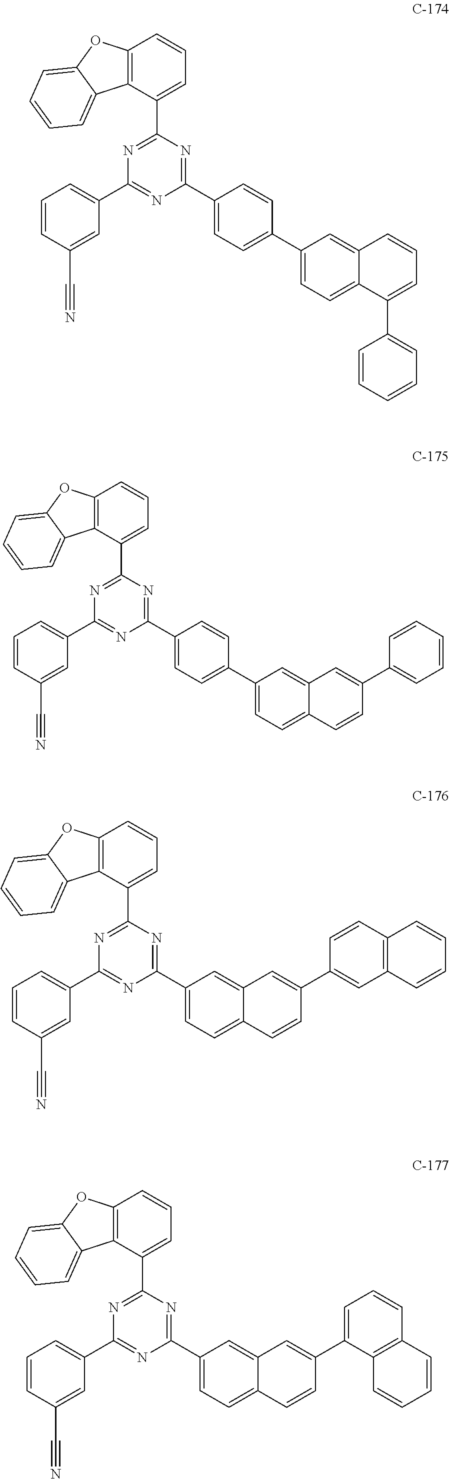 [SMILES: N#Cc1cccc(-c2nc(-c3ccc(-c4ccc5c(-c6ccccc6)cccc5c4)cc3)nc(-c3cccc4oc5ccccc5c34)n2)c1 ; N#Cc1cccc(-c2nc(-c3ccc(-c4ccc5ccc(-c6ccccc6)cc5c4)cc3)nc(-c3cccc4oc5ccccc5c34)n2)c1 ; N#Cc1cccc(-c2nc(-c3ccc4ccc(-c5ccc6ccccc6c5)cc4c3)nc(-c3cccc4oc5ccccc5c34)n2)c1 ; N#Cc1cccc(-c2nc(-c3ccc4ccc(-c5cccc6ccccc56)cc4c3)nc(-c3cccc4oc5ccccc5c34)n2)c1] 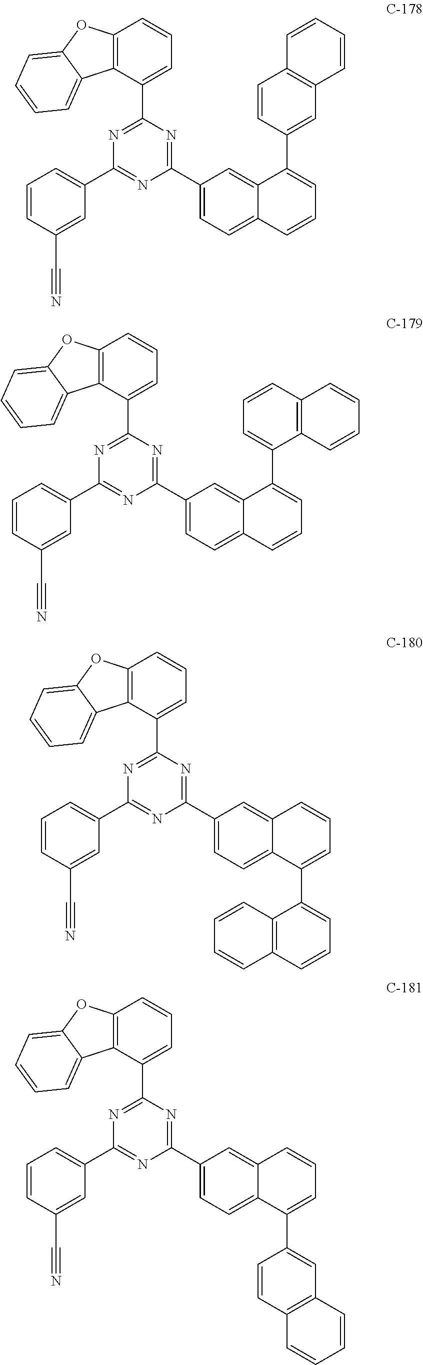 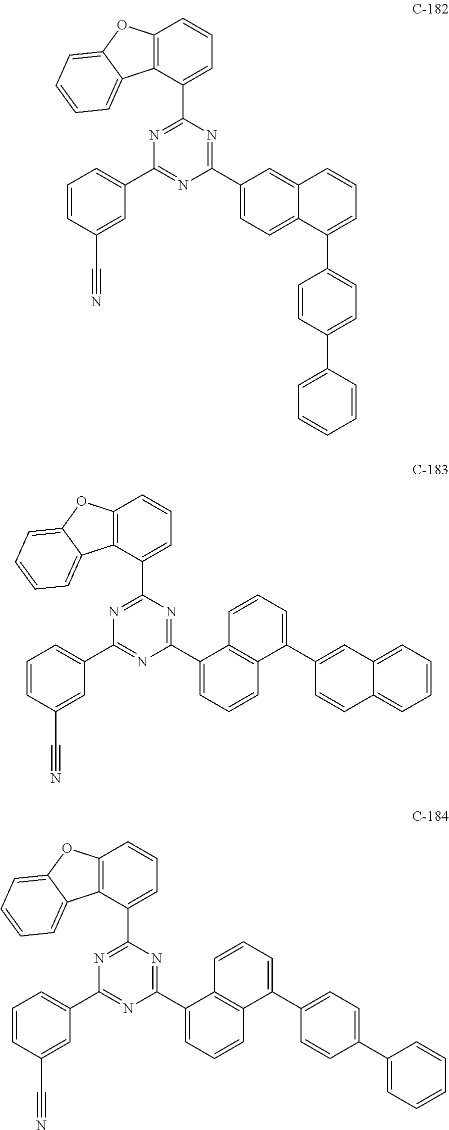 [SMILES: N#Cc1cccc(-c2nc(-c3ccc4c(-c5ccc(-c6ccccc6)cc5)cccc4c3)nc(-c3cccc4oc5ccccc5c34)n2)c1 ; N#Cc1cccc(-c2nc(-c3cccc4c(-c5ccc6ccccc6c5)cccc34)nc(-c3cccc4oc5ccccc5c34)n2)c1 ; N#Cc1cccc(-c2nc(-c3cccc4c(-c5ccc(-c6ccccc6)cc5)cccc34)nc(-c3cccc4oc5ccccc5c34)n2)c1] 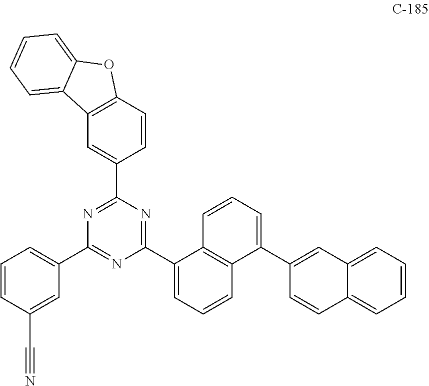 [SMILES: N#Cc1cccc(-c2nc(-c3ccc4oc5ccccc5c4c3)nc(-c3cccc4c(-c5ccc6ccccc6c5)cccc34)n2)c1] 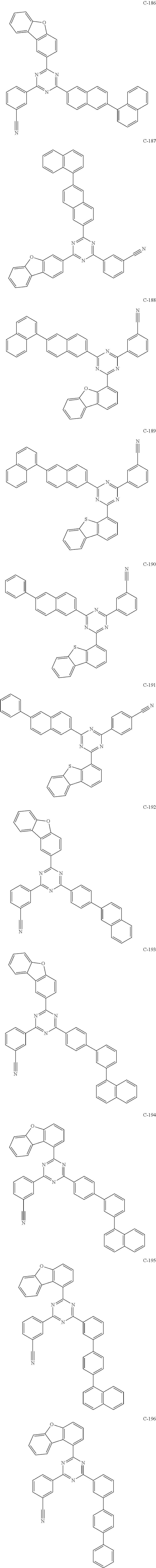 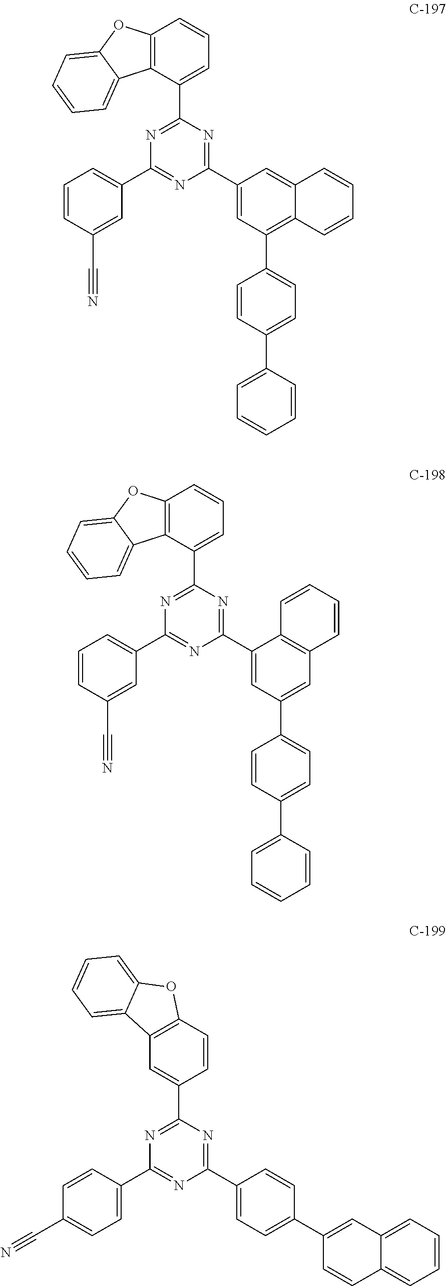 [SMILES: N#Cc1cccc(-c2nc(-c3cc(-c4ccc(-c5ccccc5)cc4)c4ccccc4c3)nc(-c3cccc4oc5ccccc5c34)n2)c1 ; N#Cc1cccc(-c2nc(-c3cc(-c4ccc(-c5ccccc5)cc4)cc4ccccc34)nc(-c3cccc4oc5ccccc5c34)n2)c1 ; N#Cc1ccc(-c2nc(-c3ccc(-c4ccc5ccccc5c4)cc3)nc(-c3ccc4oc5ccccc5c4c3)n2)cc1] 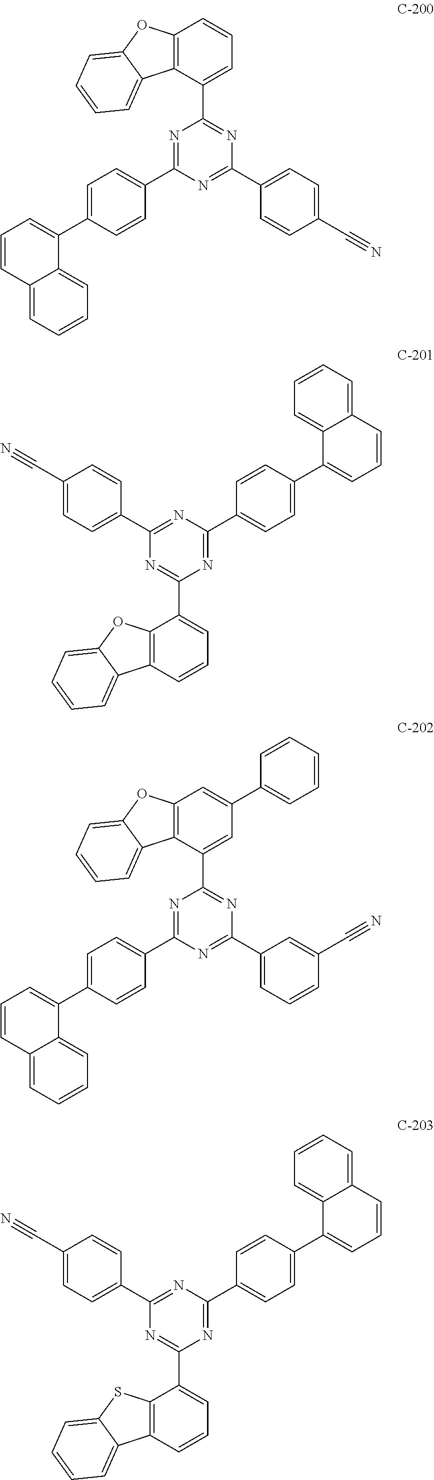 [SMILES: N#Cc1ccc(-c2nc(-c3ccc(-c4cccc5ccccc45)cc3)nc(-c3cccc4oc5ccccc5c34)n2)cc1 ; N#Cc1ccc(-c2nc(-c3ccc(-c4cccc5ccccc45)cc3)nc(-c3cccc4c3oc3ccccc34)n2)cc1 ; N#Cc1cccc(-c2nc(-c3ccc(-c4cccc5ccccc45)cc3)nc(-c3cc(-c4ccccc4)cc4oc5ccccc5c34)n2)c1 ; N#Cc1ccc(-c2nc(-c3ccc(-c4cccc5ccccc45)cc3)nc(-c3cccc4c3sc3ccccc34)n2)cc1] 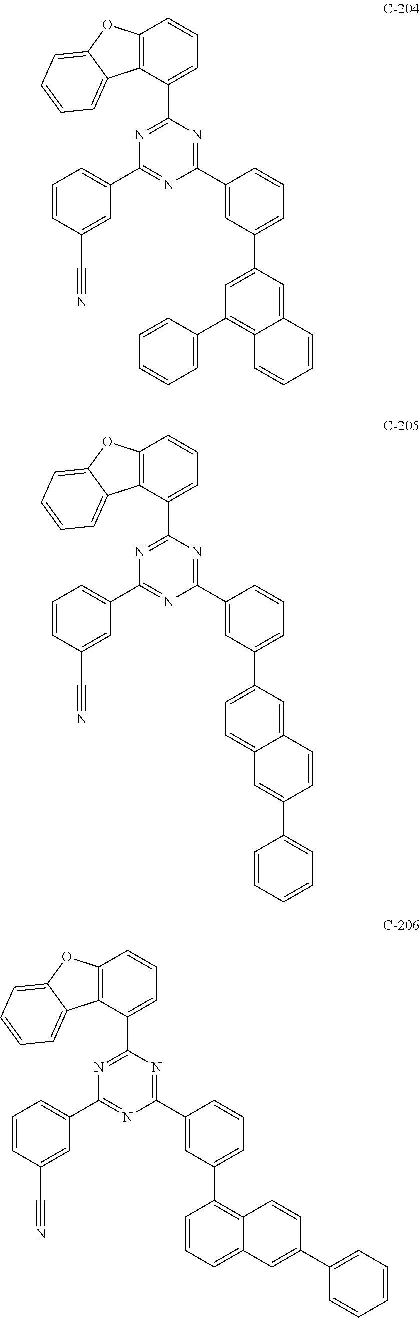 [SMILES: N#Cc1cccc(-c2nc(-c3cccc(-c4cc(-c5ccccc5)c5ccccc5c4)c3)nc(-c3cccc4oc5ccccc5c34)n2)c1 ; N#Cc1cccc(-c2nc(-c3cccc(-c4ccc5cc(-c6ccccc6)ccc5c4)c3)nc(-c3cccc4oc5ccccc5c34)n2)c1 ; N#Cc1cccc(-c2nc(-c3cccc(-c4cccc5cc(-c6ccccc6)ccc45)c3)nc(-c3cccc4oc5ccccc5c34)n2)c1] 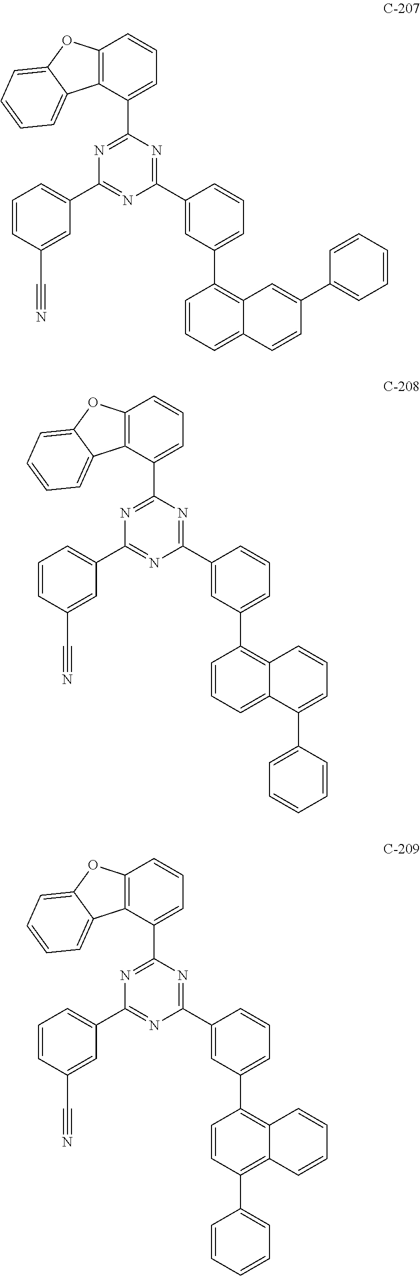 [SMILES: N#Cc1cccc(-c2nc(-c3cccc(-c4cccc5ccc(-c6ccccc6)cc45)c3)nc(-c3cccc4oc5ccccc5c34)n2)c1 ; N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1] 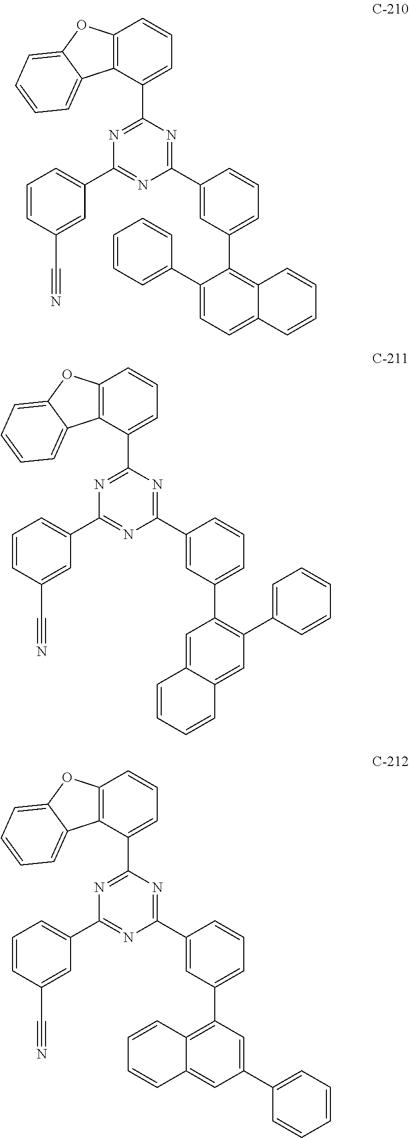 [SMILES: N#Cc1cccc(-c2nc(-c3cccc(-c4c(-c5ccccc5)ccc5ccccc45)c3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3cccc(-c4cc(-c5ccccc5)cc5ccccc45)c3)nc(-c3cccc4oc5ccccc5c34)n2)c1] 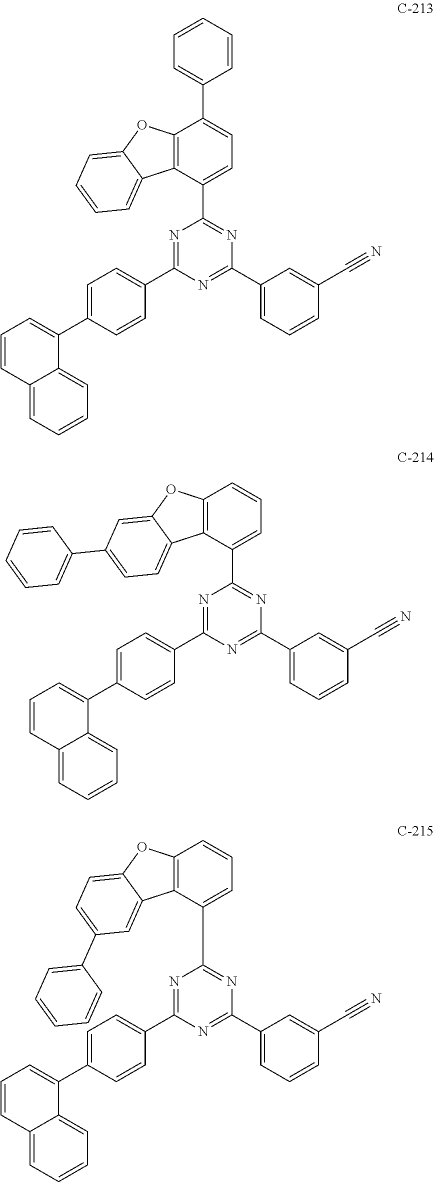 [SMILES: N#Cc1cccc(-c2nc(-c3ccc(-c4cccc5ccccc45)cc3)nc(-c3ccc(-c4ccccc4)c4oc5ccccc5c34)n2)c1 ; N#Cc1cccc(-c2nc(-c3ccc(-c4cccc5ccccc45)cc3)nc(-c3cccc4oc5cc(-c6ccccc6)ccc5c34)n2)c1 ; N#Cc1cccc(-c2nc(-c3ccc(-c4cccc5ccccc45)cc3)nc(-c3cccc4oc5ccc(-c6ccccc6)cc5c34)n2)c1] 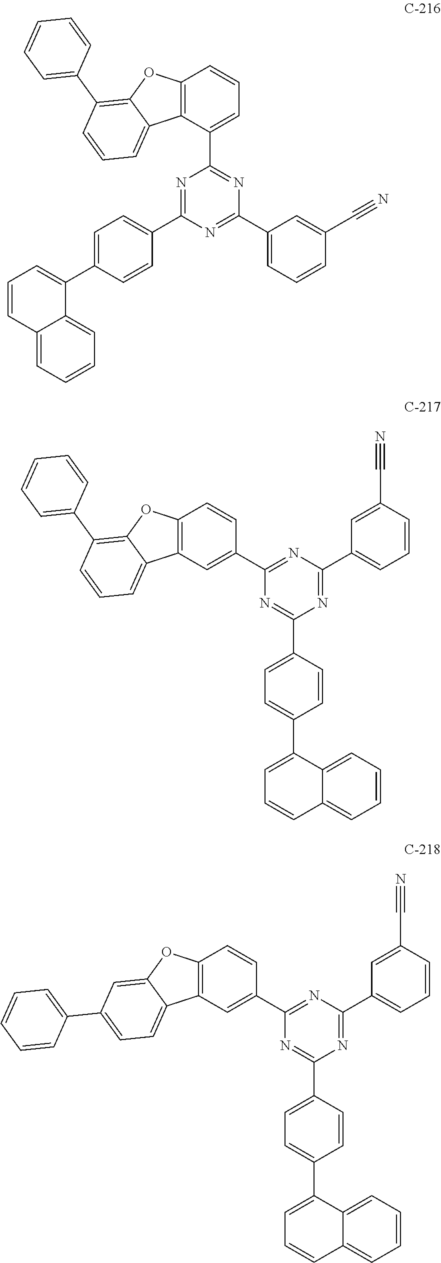 [SMILES: N#Cc1cccc(-c2nc(-c3ccc(-c4cccc5ccccc45)cc3)nc(-c3cccc4oc5c(-c6ccccc6)cccc5c34)n2)c1 ; N#Cc1cccc(-c2nc(-c3ccc(-c4cccc5ccccc45)cc3)nc(-c3ccc4oc5c(-c6ccccc6)cccc5c4c3)n2)c1 ; N#Cc1cccc(-c2nc(-c3ccc(-c4cccc5ccccc45)cc3)nc(-c3ccc4oc5cc(-c6ccccc6)ccc5c4c3)n2)c1] 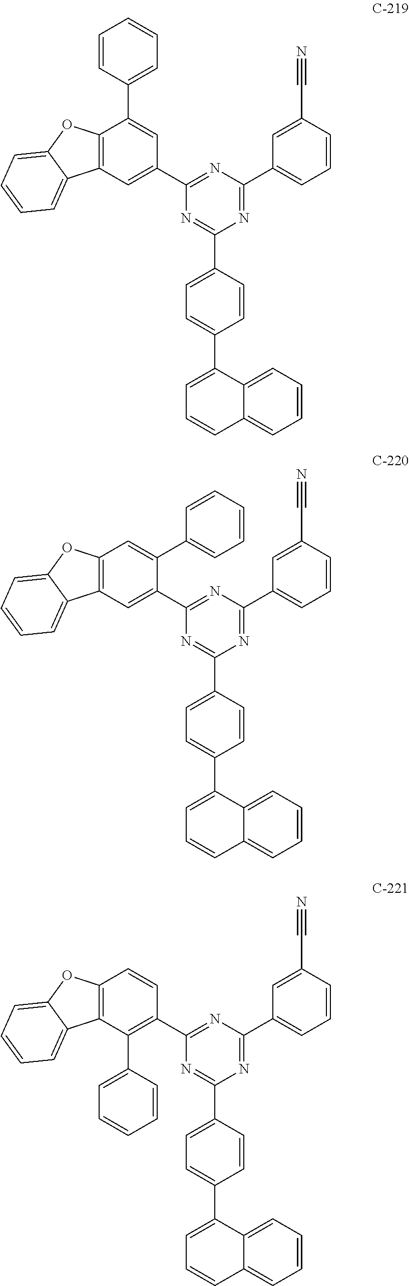 [SMILES: N#Cc1cccc(-c2nc(-c3ccc(-c4cccc5ccccc45)cc3)nc(-c3cc(-c4ccccc4)c4oc5ccccc5c4c3)n2)c1 ; N#Cc1cccc(-c2nc(-c3ccc(-c4cccc5ccccc45)cc3)nc(-c3cc4c(cc3-c3ccccc3)oc3ccccc34)n2)c1 ; N#Cc1cccc(-c2nc(-c3ccc(-c4cccc5ccccc45)cc3)nc(-c3ccc4oc5ccccc5c4c3-c3ccccc3)n2)c1] 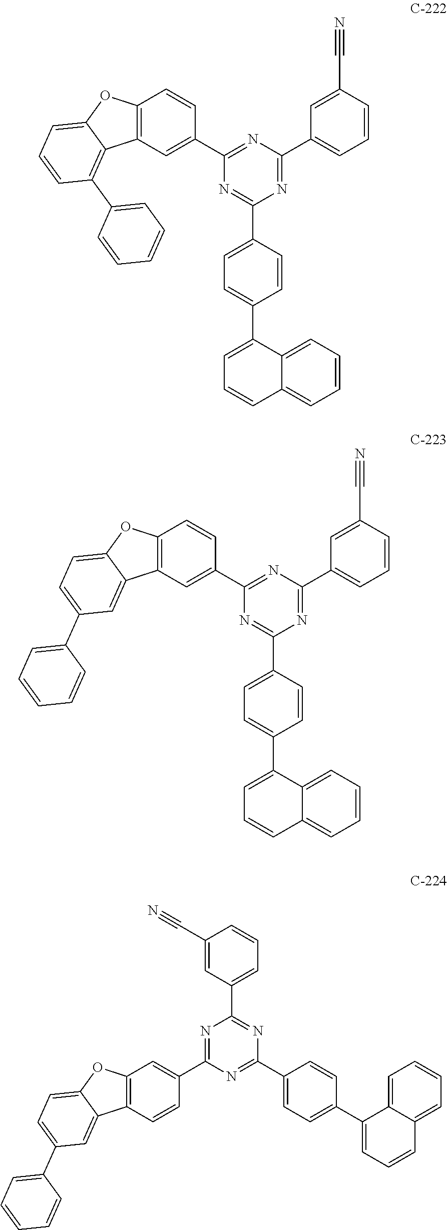 [SMILES: N#Cc1cccc(-c2nc(-c3ccc(-c4cccc5ccccc45)cc3)nc(-c3ccc4oc5cccc(-c6ccccc6)c5c4c3)n2)c1 ; N#Cc1cccc(-c2nc(-c3ccc(-c4cccc5ccccc45)cc3)nc(-c3ccc4oc5ccc(-c6ccccc6)cc5c4c3)n2)c1 ; N#Cc1cccc(-c2nc(-c3ccc(-c4cccc5ccccc45)cc3)nc(-c3ccc4c(c3)oc3ccc(-c5ccccc5)cc34)n2)c1] 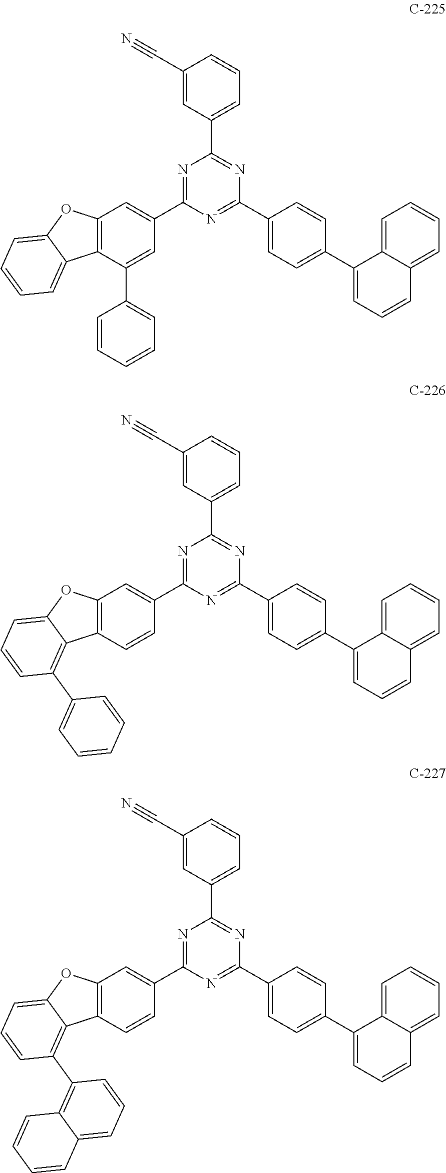 [SMILES: N#Cc1cccc(-c2nc(-c3ccc(-c4cccc5ccccc45)cc3)nc(-c3cc(-c4ccccc4)c4c(c3)oc3ccccc34)n2)c1 ; N#Cc1cccc(-c2nc(-c3ccc(-c4cccc5ccccc45)cc3)nc(-c3ccc4c(c3)oc3cccc(-c5ccccc5)c34)n2)c1 ; N#Cc1cccc(-c2nc(-c3ccc(-c4cccc5ccccc45)cc3)nc(-c3ccc4c(c3)oc3cccc(-c5cccc6ccccc56)c34)n2)c1] 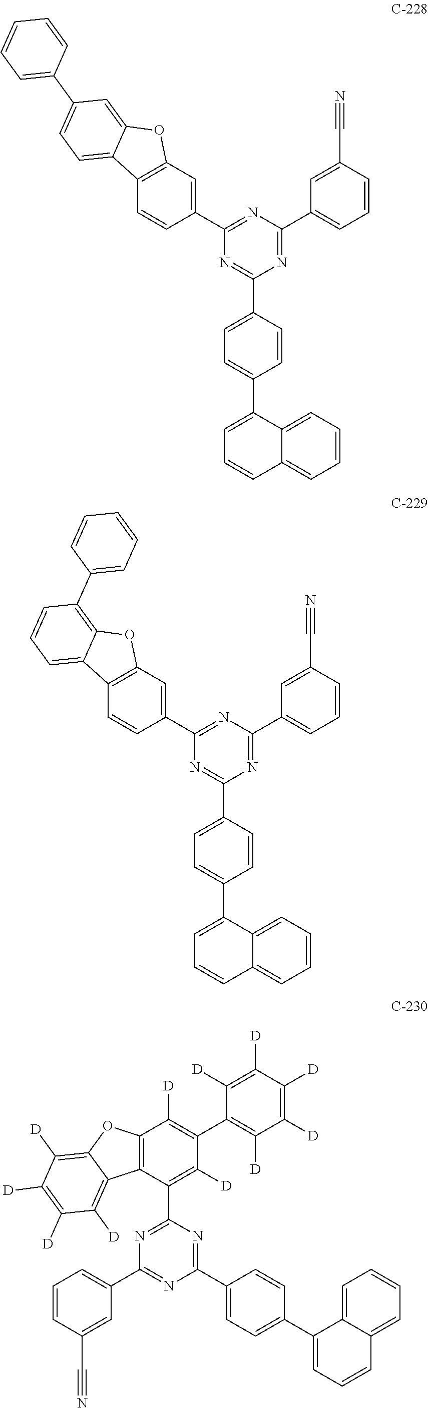 [SMILES: N#Cc1cccc(-c2nc(-c3ccc(-c4cccc5ccccc45)cc3)nc(-c3ccc4c(c3)oc3cc(-c5ccccc5)ccc34)n2)c1 ; N#Cc1cccc(-c2nc(-c3ccc(-c4cccc5ccccc45)cc3)nc(-c3ccc4c(c3)oc3c(-c5ccccc5)cccc34)n2)c1 ; [2H]c1c([2H])c([2H])c(-c2c([2H])c(-c3nc(-c4ccc(-c5cccc6ccccc56)cc4)nc(-c4cccc(C#N)c4)n3)c3c(oc4c([2H])c([2H])c([2H])c([2H])c43)c2[2H])c([2H])c1[2H]] 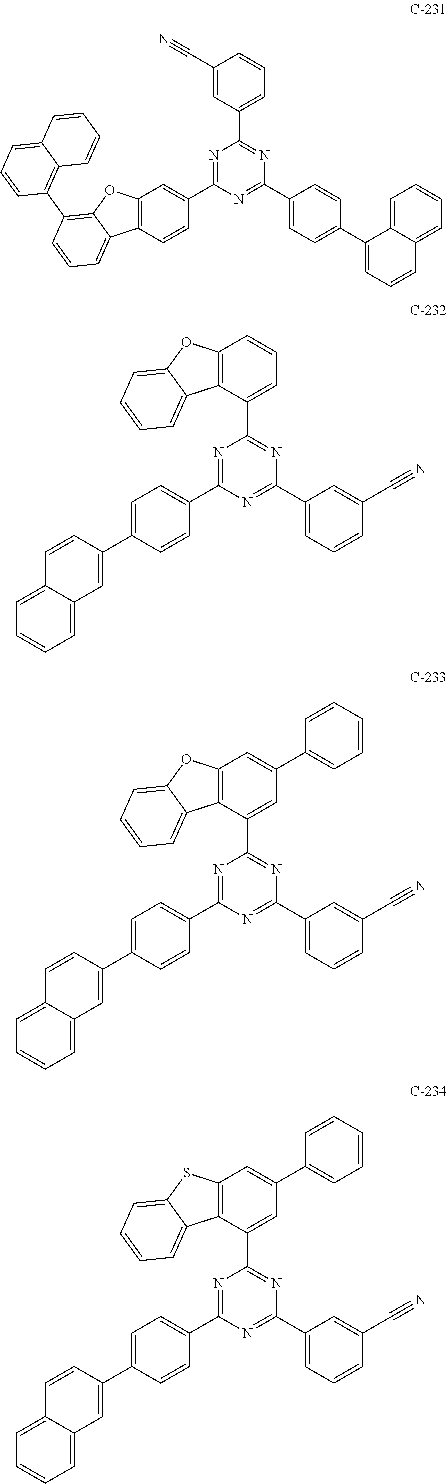 [SMILES: N#Cc1cccc(-c2nc(-c3ccc(-c4cccc5ccccc45)cc3)nc(-c3ccc4c(c3)oc3c(-c5cccc6ccccc56)cccc34)n2)c1 ; N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4ccc5ccccc5c4)cc3)nc(-c3cc(-c4ccccc4)cc4oc5ccccc5c34)n2)c1 ; N#Cc1cccc(-c2nc(-c3ccc(-c4ccc5ccccc5c4)cc3)nc(-c3cc(-c4ccccc4)cc4sc5ccccc5c34)n2)c1] 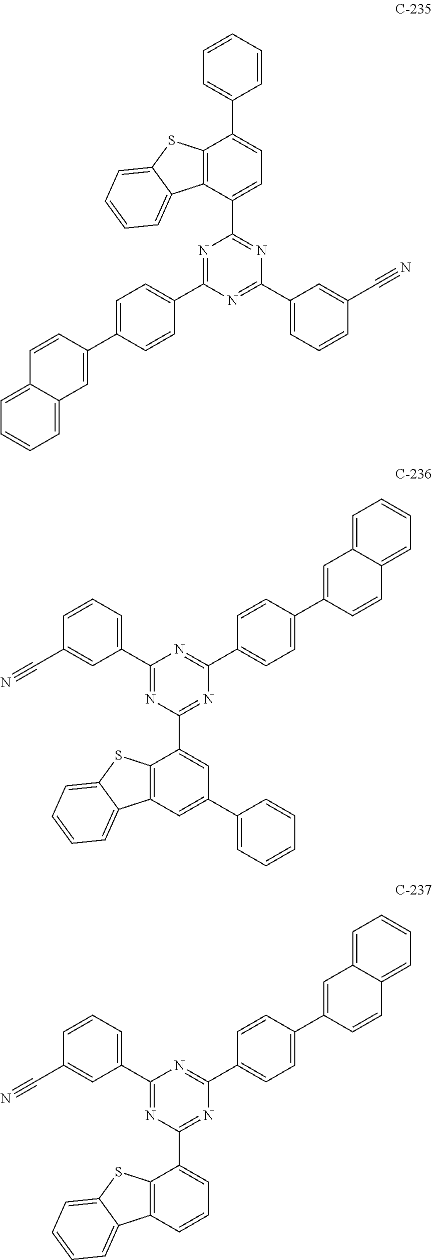 [SMILES: N#Cc1cccc(-c2nc(-c3ccc(-c4ccc5ccccc5c4)cc3)nc(-c3ccc(-c4ccccc4)c4sc5ccccc5c34)n2)c1 ; N#Cc1cccc(-c2nc(-c3ccc(-c4ccc5ccccc5c4)cc3)nc(-c3cc(-c4ccccc4)cc4c3sc3ccccc34)n2)c1 ; N#Cc1cccc(-c2nc(-c3ccc(-c4ccc5ccccc5c4)cc3)nc(-c3cccc4c3sc3ccccc34)n2)c1] 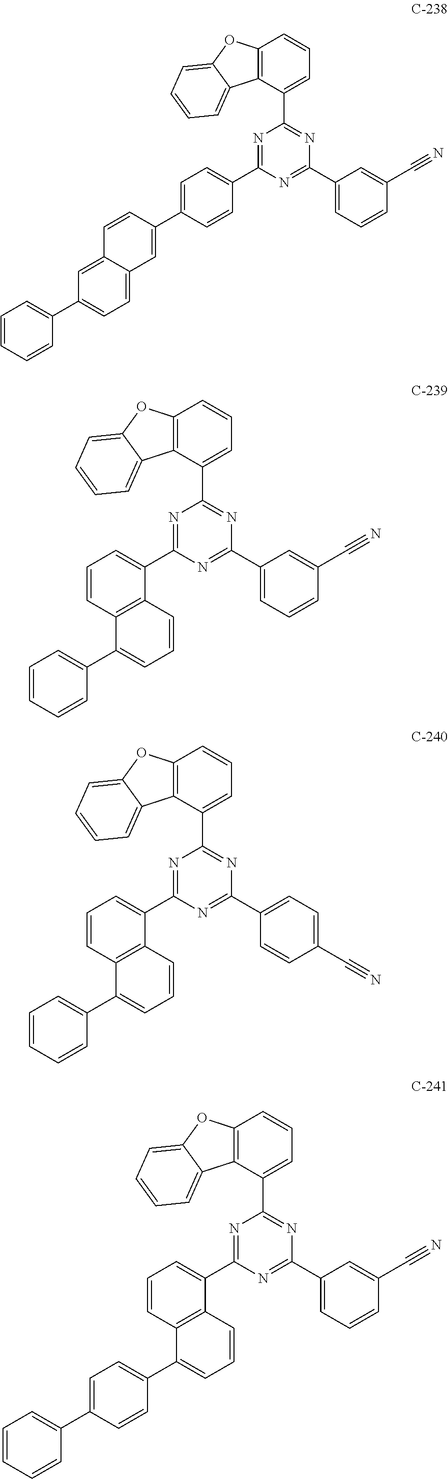 [SMILES: N#Cc1cccc(-c2nc(-c3ccc(-c4ccc5cc(-c6ccccc6)ccc5c4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1 ; N#Cc1ccc(-c2nc(-c3cccc4c(-c5ccccc5)cccc34)nc(-c3cccc4oc5ccccc5c34)n2)cc1 ; N#Cc1cccc(-c2nc(-c3cccc4c(-c5ccc(-c6ccccc6)cc5)cccc34)nc(-c3cccc4oc5ccccc5c34)n2)c1] 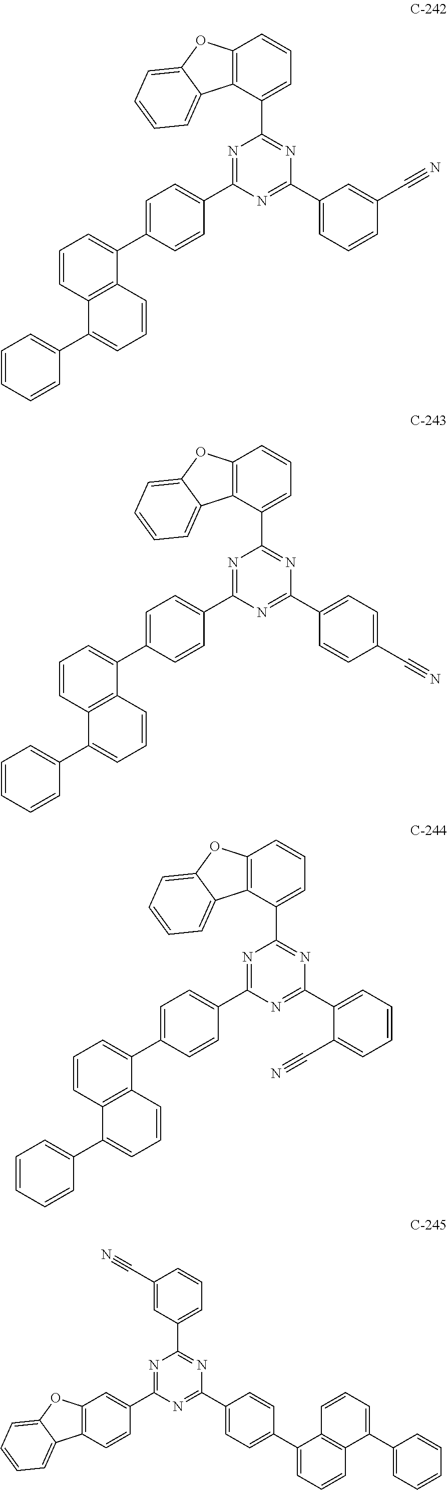 [SMILES: N#Cc1cccc(-c2nc(-c3ccc(-c4cccc5c(-c6ccccc6)cccc45)cc3)nc(-c3cccc4oc5ccccc5c34)n2)c1 ; N#Cc1ccc(-c2nc(-c3ccc(-c4cccc5c(-c6ccccc6)cccc45)cc3)nc(-c3cccc4oc5ccccc5c34)n2)cc1 ; N#Cc1ccccc1-c1nc(-c2ccc(-c3cccc4c(-c5ccccc5)cccc34)cc2)nc(-c2cccc3oc4ccccc4c23)n1 ; N#Cc1cccc(-c2nc(-c3ccc(-c4cccc5c(-c6ccccc6)cccc45)cc3)nc(-c3ccc4c(c3)oc3ccccc34)n2)c1] 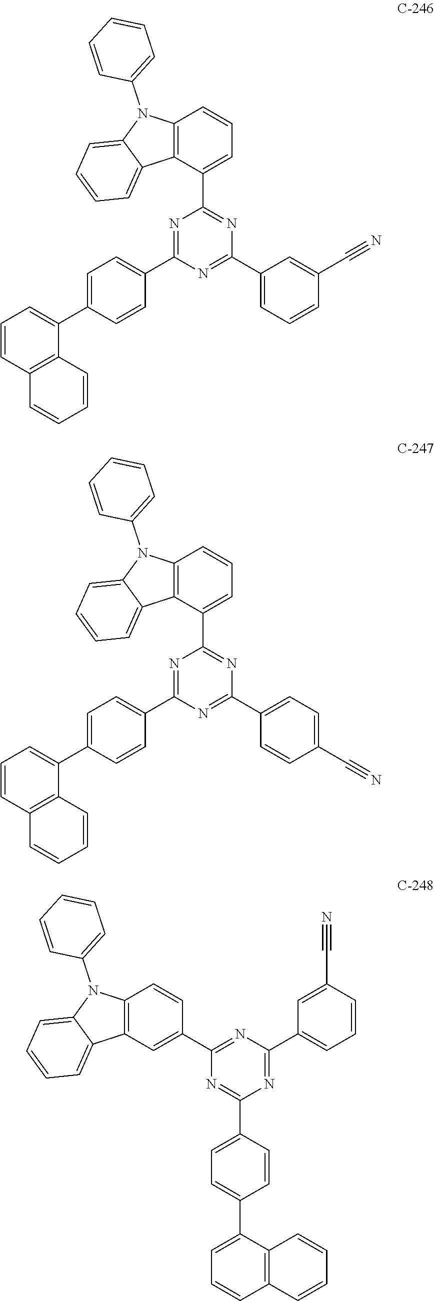 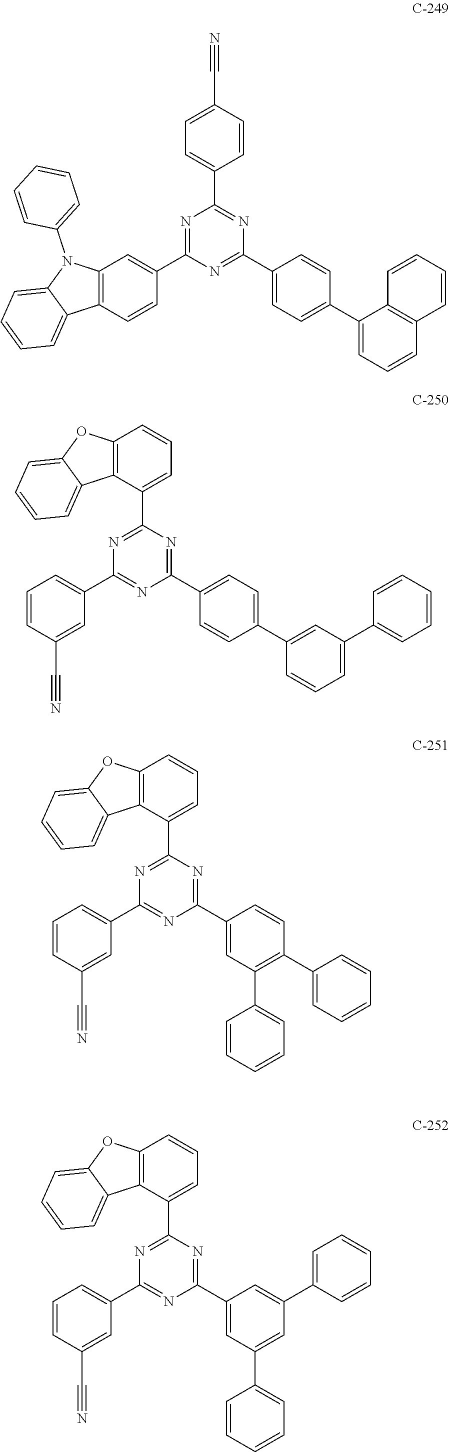 [SMILES: N#Cc1ccc(-c2nc(-c3ccc(-c4cccc5ccccc45)cc3)nc(-c3ccc4c5ccccc5n(-c5ccccc5)c4c3)n2)cc1 ; N#Cc1cccc(-c2nc(-c3ccc(-c4cccc(-c5ccccc5)c4)cc3)nc(-c3cccc4oc5ccccc5c34)n2)c1 ; N#Cc1cccc(-c2nc(-c3ccc(-c4ccccc4)c(-c4ccccc4)c3)nc(-c3cccc4oc5ccccc5c34)n2)c1 ; N#Cc1cccc(-c2nc(-c3cc(-c4ccccc4)cc(-c4ccccc4)c3)nc(-c3cccc4oc5ccccc5c34)n2)c1] 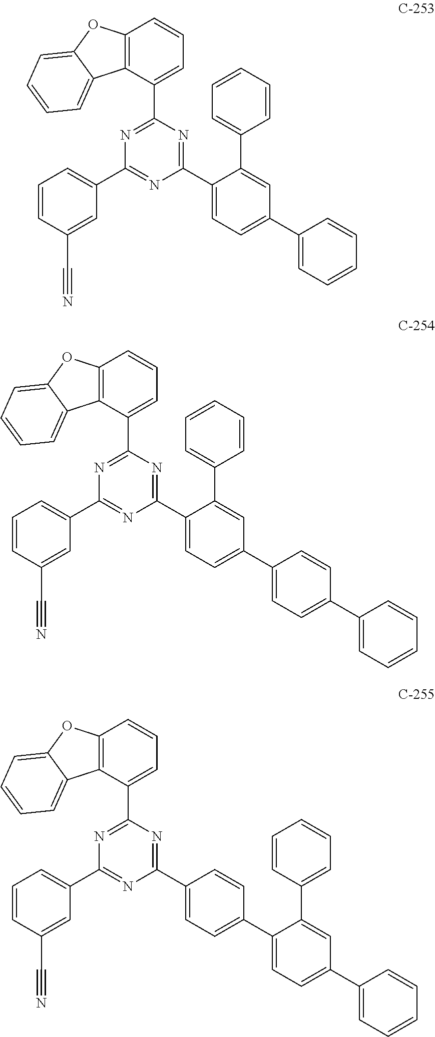 [SMILES: N#Cc1cccc(-c2nc(-c3ccc(-c4ccccc4)cc3-c3ccccc3)nc(-c3cccc4oc5ccccc5c34)n2)c1 ; N#Cc1cccc(-c2nc(-c3ccc(-c4ccc(-c5ccccc5)cc4)cc3-c3ccccc3)nc(-c3cccc4oc5ccccc5c34)n2)c1 ; N#Cc1cccc(-c2nc(-c3ccc(-c4ccc(-c5ccccc5)cc4-c4ccccc4)cc3)nc(-c3cccc4oc5ccccc5c34)n2)c1] 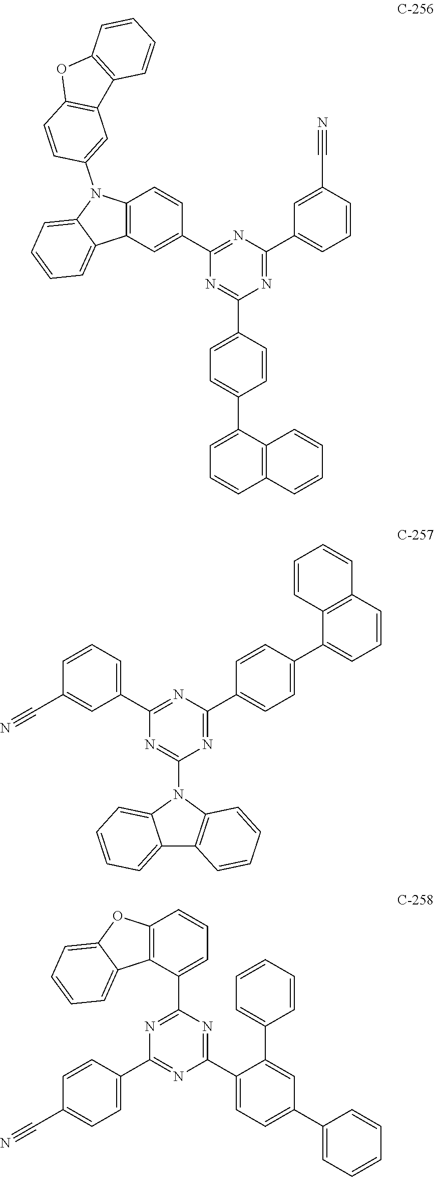 [SMILES: N#Cc1cccc(-c2nc(-c3ccc(-c4cccc5ccccc45)cc3)nc(-c3ccc4c(c3)c3ccccc3n4-c3ccc4oc5ccccc5c4c3)n2)c1 ; N#Cc1cccc(-c2nc(-c3ccc(-c4cccc5ccccc45)cc3)nc(-n3c4ccccc4c4ccccc43)n2)c1 ; N#Cc1ccc(-c2nc(-c3ccc(-c4ccccc4)cc3-c3ccccc3)nc(-c3cccc4oc5ccccc5c34)n2)cc1] 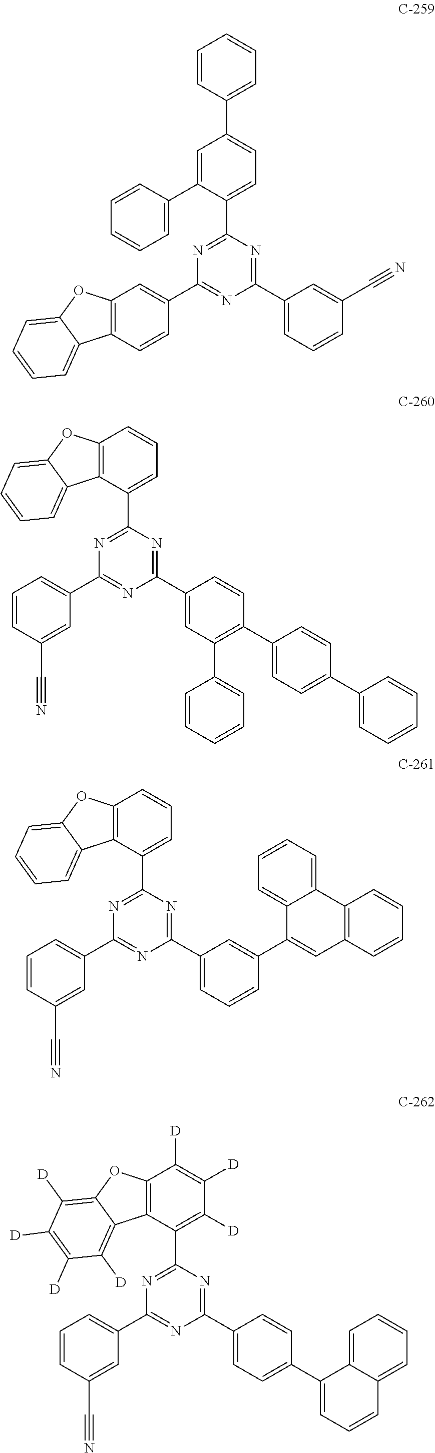 [SMILES: N#Cc1cccc(-c2nc(-c3ccc4c(c3)oc3ccccc34)nc(-c3ccc(-c4ccccc4)cc3-c3ccccc3)n2)c1 ; N#Cc1cccc(-c2nc(-c3ccc(-c4ccc(-c5ccccc5)cc4)c(-c4ccccc4)c3)nc(-c3cccc4oc5ccccc5c34)n2)c1 ; N#Cc1cccc(-c2nc(-c3cccc(-c4cc5ccccc5c5ccccc45)c3)nc(-c3cccc4oc5ccccc5c34)n2)c1 ; [2H]c1c([2H])c([2H])c2c(oc3c([2H])c([2H])c([2H])c(-c4nc(-c5ccc(-c6cccc7ccccc67)cc5)nc(-c5cccc(C#N)c5)n4)c32)c1[2H]] 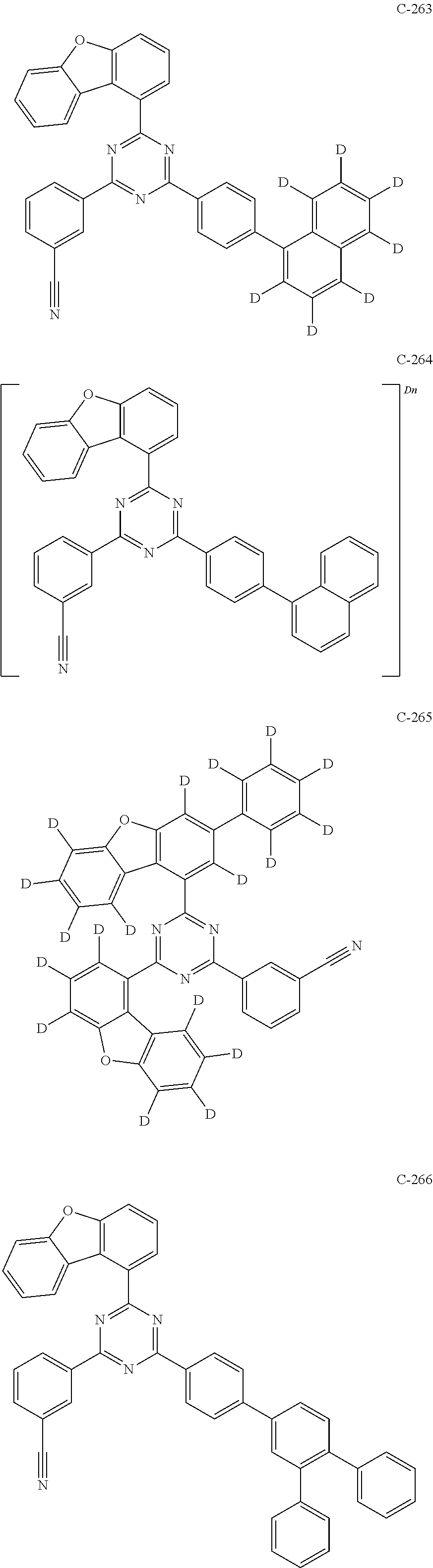 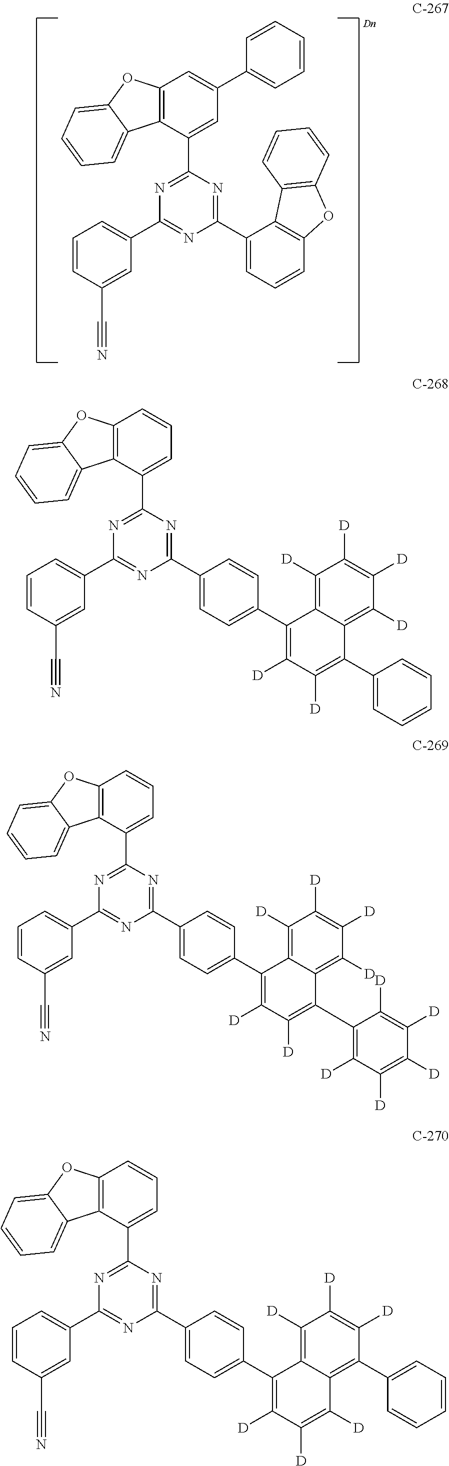 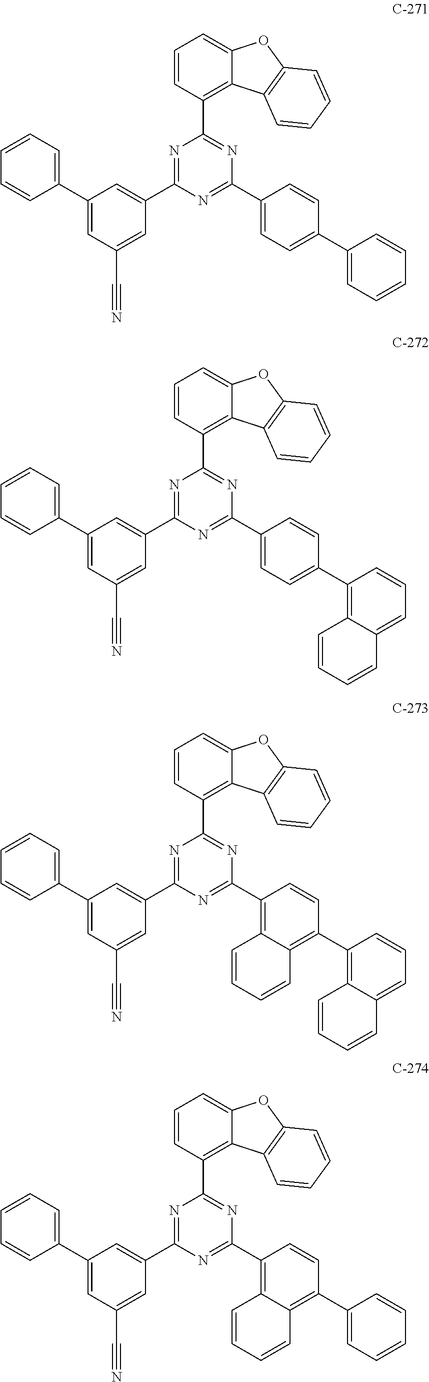 [SMILES: N#Cc1cc(-c2ccccc2)cc(-c2nc(-c3ccc(-c4ccccc4)cc3)nc(-c3cccc4oc5ccccc5c34)n2)c1 ; N#Cc1cc(-c2ccccc2)cc(-c2nc(-c3ccc(-c4cccc5ccccc45)cc3)nc(-c3cccc4oc5ccccc5c34)n2)c1 ; N#Cc1cc(-c2ccccc2)cc(-c2nc(-c3ccc(-c4cccc5ccccc45)c4ccccc34)nc(-c3cccc4oc5ccccc5c34)n2)c1 ; N#Cc1cc(-c2ccccc2)cc(-c2nc(-c3ccc(-c4ccccc4)c4ccccc34)nc(-c3cccc4oc5ccccc5c34)n2)c1] 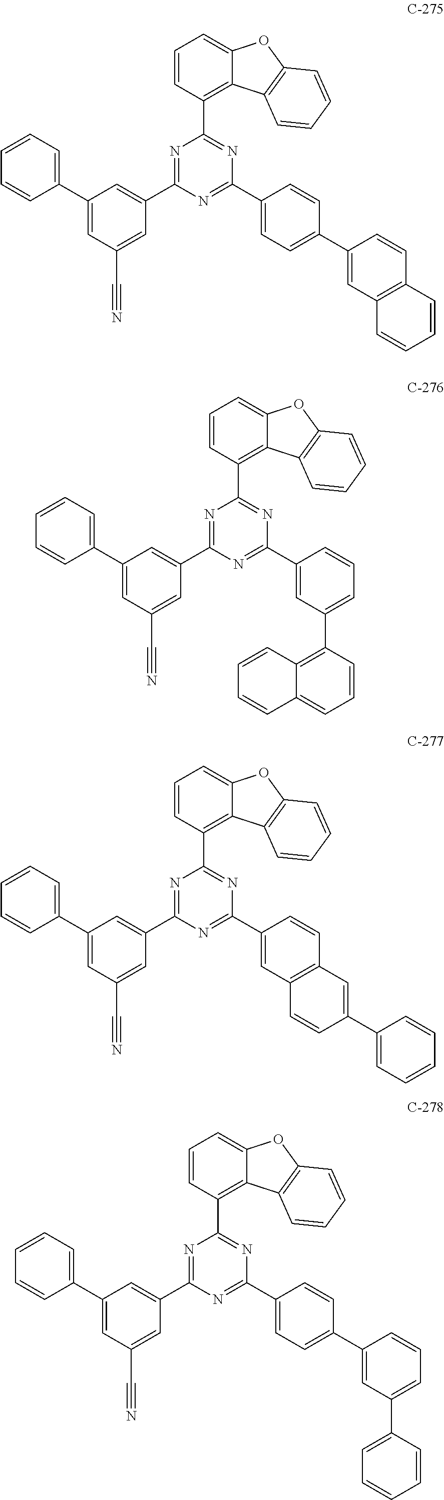 [SMILES: N#Cc1cc(-c2ccccc2)cc(-c2nc(-c3ccc(-c4ccc5ccccc5c4)cc3)nc(-c3cccc4oc5ccccc5c34)n2)c1 ; N#Cc1cc(-c2ccccc2)cc(-c2nc(-c3cccc(-c4cccc5ccccc45)c3)nc(-c3cccc4oc5ccccc5c34)n2)c1 ; N#Cc1cc(-c2ccccc2)cc(-c2nc(-c3ccc4cc(-c5ccccc5)ccc4c3)nc(-c3cccc4oc5ccccc5c34)n2)c1 ; N#Cc1cc(-c2ccccc2)cc(-c2nc(-c3ccc(-c4cccc(-c5ccccc5)c4)cc3)nc(-c3cccc4oc5ccccc5c34)n2)c1] 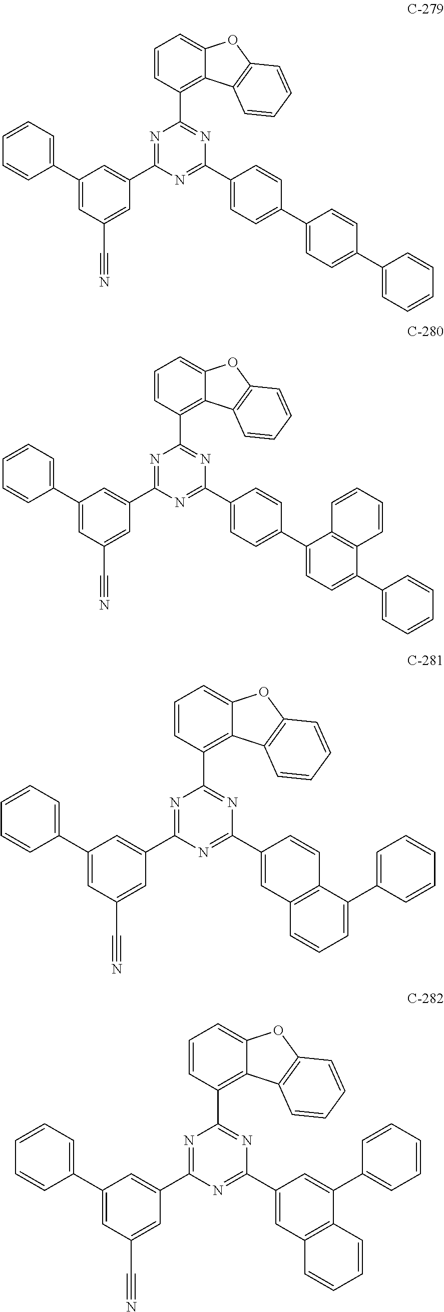 [SMILES: N#Cc1cc(-c2ccccc2)cc(-c2nc(-c3ccc(-c4ccc(-c5ccccc5)cc4)cc3)nc(-c3cccc4oc5ccccc5c34)n2)c1 ; N#Cc1cc(-c2ccccc2)cc(-c2nc(-c3ccc(-c4ccc(-c5ccccc5)c5ccccc45)cc3)nc(-c3cccc4oc5ccccc5c34)n2)c1 ; N#Cc1cc(-c2ccccc2)cc(-c2nc(-c3ccc4c(-c5ccccc5)cccc4c3)nc(-c3cccc4oc5ccccc5c34)n2)c1 ; N#Cc1cc(-c2ccccc2)cc(-c2nc(-c3cc(-c4ccccc4)c4ccccc4c3)nc(-c3cccc4oc5ccccc5c34)n2)c1] 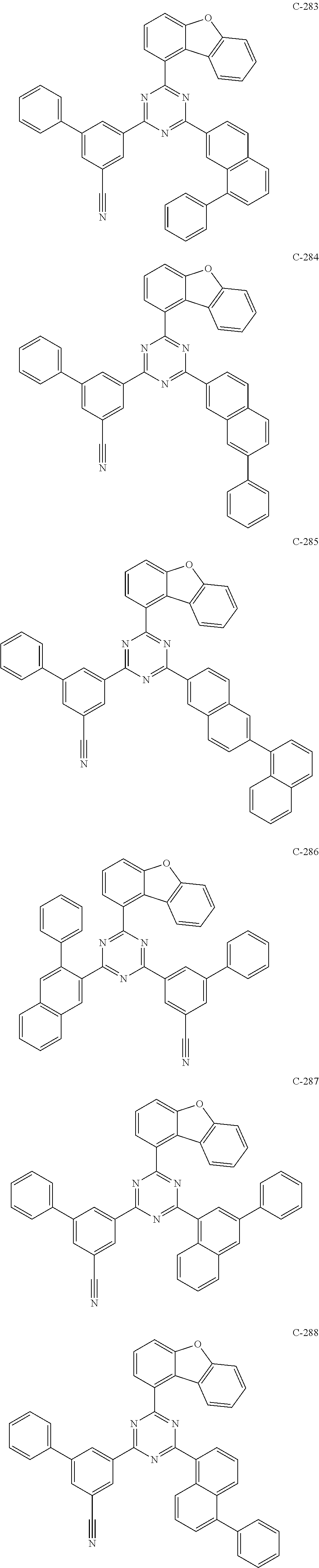 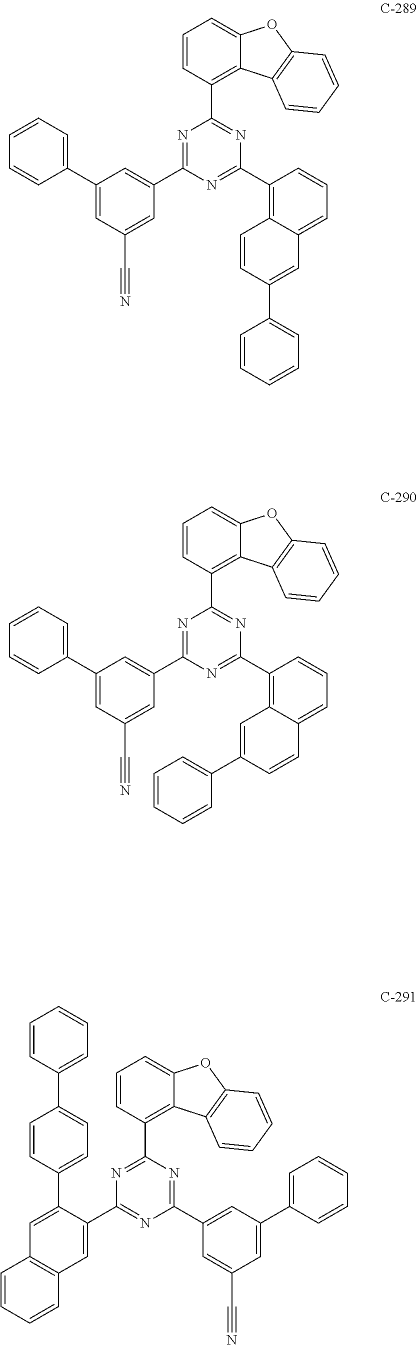 [SMILES: N#Cc1cc(-c2ccccc2)cc(-c2nc(-c3cccc4cc(-c5ccccc5)ccc34)nc(-c3cccc4oc5ccccc5c34)n2)c1 ; N#Cc1cc(-c2ccccc2)cc(-c2nc(-c3cccc4ccc(-c5ccccc5)cc34)nc(-c3cccc4oc5ccccc5c34)n2)c1 ; N#Cc1cc(-c2ccccc2)cc(-c2nc(-c3cc4ccccc4cc3-c3ccc(-c4ccccc4)cc3)nc(-c3cccc4oc5ccccc5c34)n2)c1] 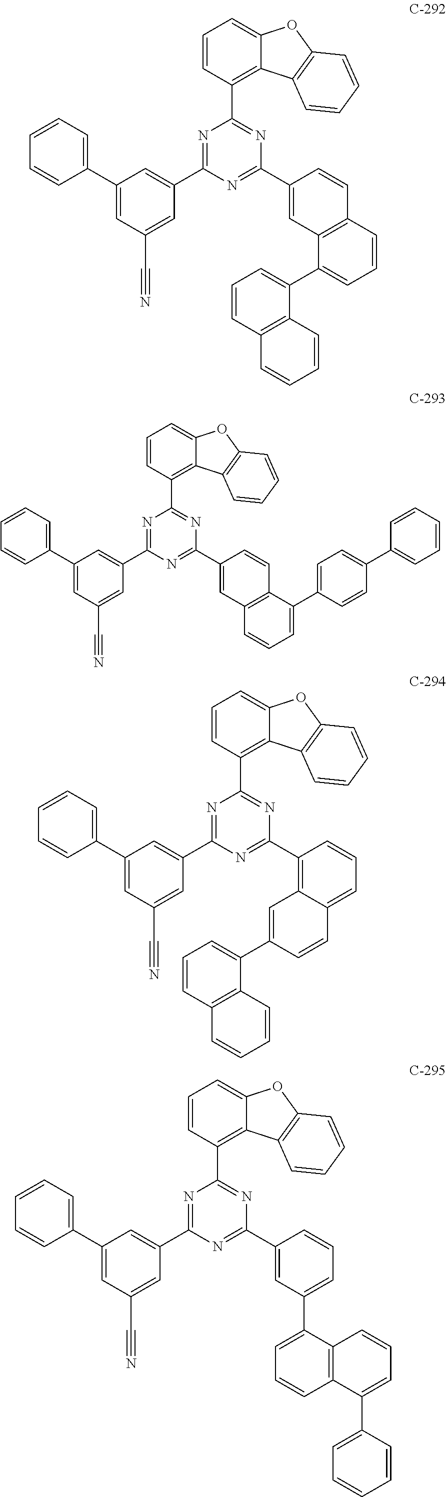 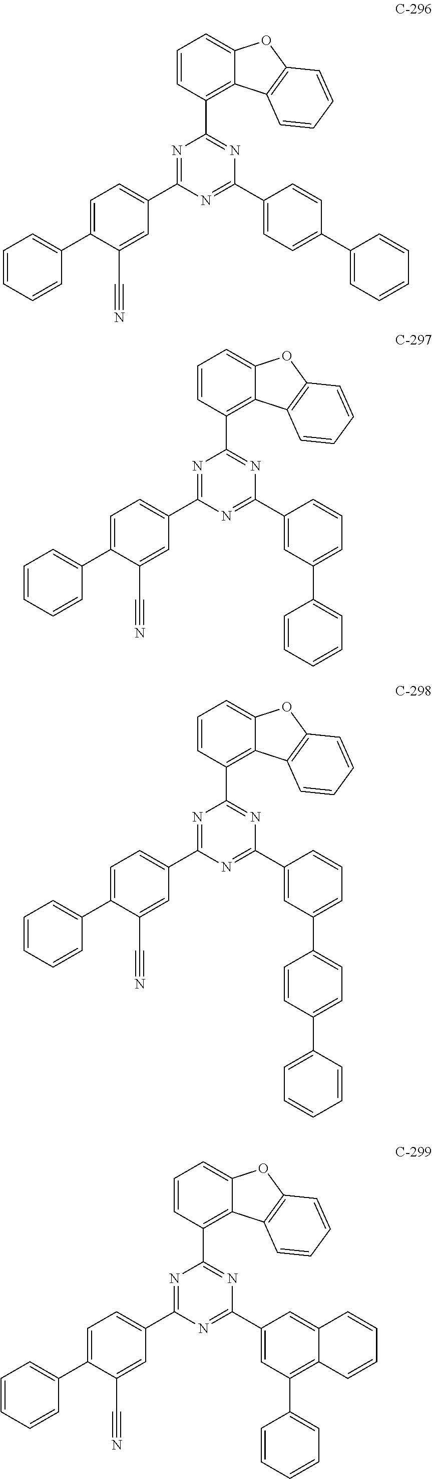 [SMILES: N#Cc1cc(-c2nc(-c3ccc(-c4ccccc4)cc3)nc(-c3cccc4oc5ccccc5c34)n2)ccc1-c1ccccc1 ; N#Cc1cc(-c2nc(-c3cccc(-c4ccccc4)c3)nc(-c3cccc4oc5ccccc5c34)n2)ccc1-c1ccccc1 ; N#Cc1cc(-c2nc(-c3cccc(-c4ccc(-c5ccccc5)cc4)c3)nc(-c3cccc4oc5ccccc5c34)n2)ccc1-c1ccccc1 ; N#Cc1cc(-c2nc(-c3cc(-c4ccccc4)c4ccccc4c3)nc(-c3cccc4oc5ccccc5c34)n2)ccc1-c1ccccc1] 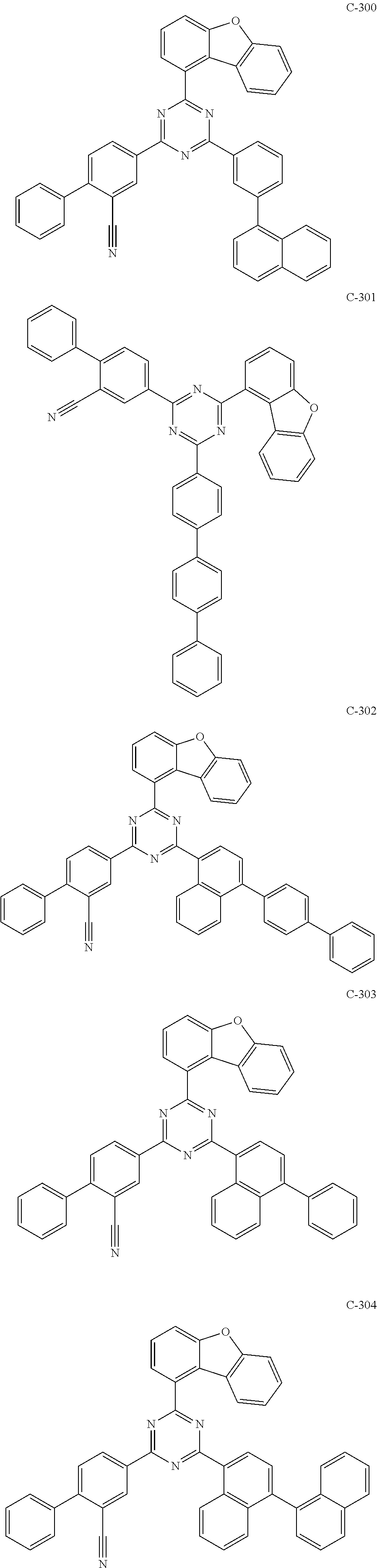 [SMILES: N#Cc1cc(-c2nc(-c3cccc(-c4cccc5ccccc45)c3)nc(-c3cccc4oc5ccccc5c34)n2)ccc1-c1ccccc1 ; N#Cc1cc(-c2nc(-c3ccc(-c4ccc(-c5ccccc5)cc4)cc3)nc(-c3cccc4oc5ccccc5c34)n2)ccc1-c1ccccc1 ; N#Cc1cc(-c2nc(-c3ccc(-c4ccc(-c5ccccc5)cc4)c4ccccc34)nc(-c3cccc4oc5ccccc5c34)n2)ccc1-c1ccccc1 ; N#Cc1cc(-c2nc(-c3ccc(-c4ccccc4)c4ccccc34)nc(-c3cccc4oc5ccccc5c34)n2)ccc1-c1ccccc1 ; N#Cc1cc(-c2nc(-c3ccc(-c4cccc5ccccc45)c4ccccc34)nc(-c3cccc4oc5ccccc5c34)n2)ccc1-c1ccccc1] 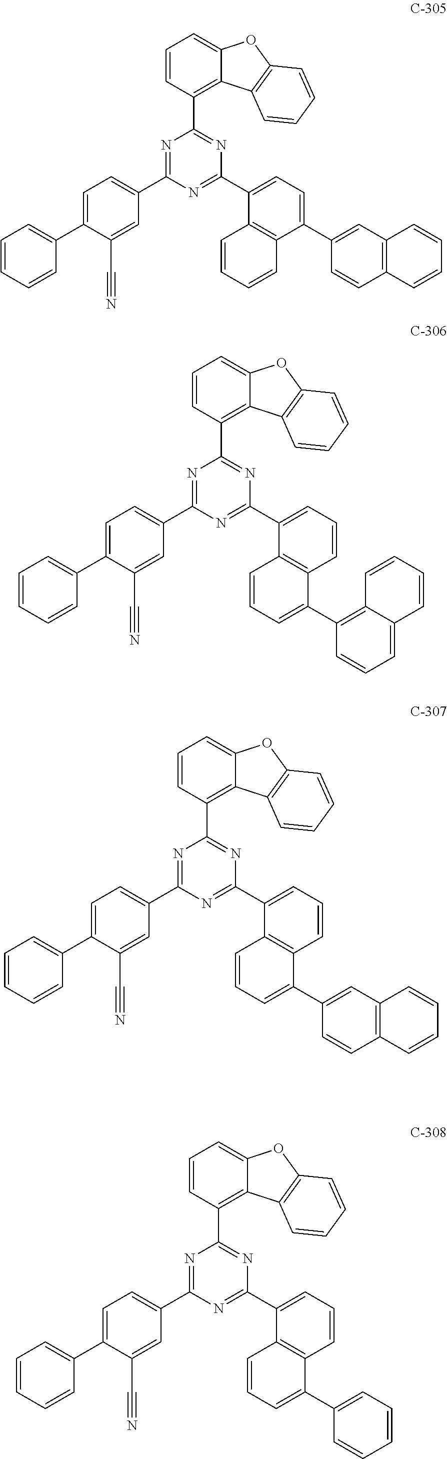 [SMILES: N#Cc1cc(-c2nc(-c3ccc(-c4ccc5ccccc5c4)c4ccccc34)nc(-c3cccc4oc5ccccc5c34)n2)ccc1-c1ccccc1 ; N#Cc1cc(-c2nc(-c3cccc4c(-c5cccc6ccccc56)cccc34)nc(-c3cccc4oc5ccccc5c34)n2)ccc1-c1ccccc1 ; N#Cc1cc(-c2nc(-c3cccc4c(-c5ccc6ccccc6c5)cccc34)nc(-c3cccc4oc5ccccc5c34)n2)ccc1-c1ccccc1 ; N#Cc1cc(-c2nc(-c3cccc4c(-c5ccccc5)cccc34)nc(-c3cccc4oc5ccccc5c34)n2)ccc1-c1ccccc1] 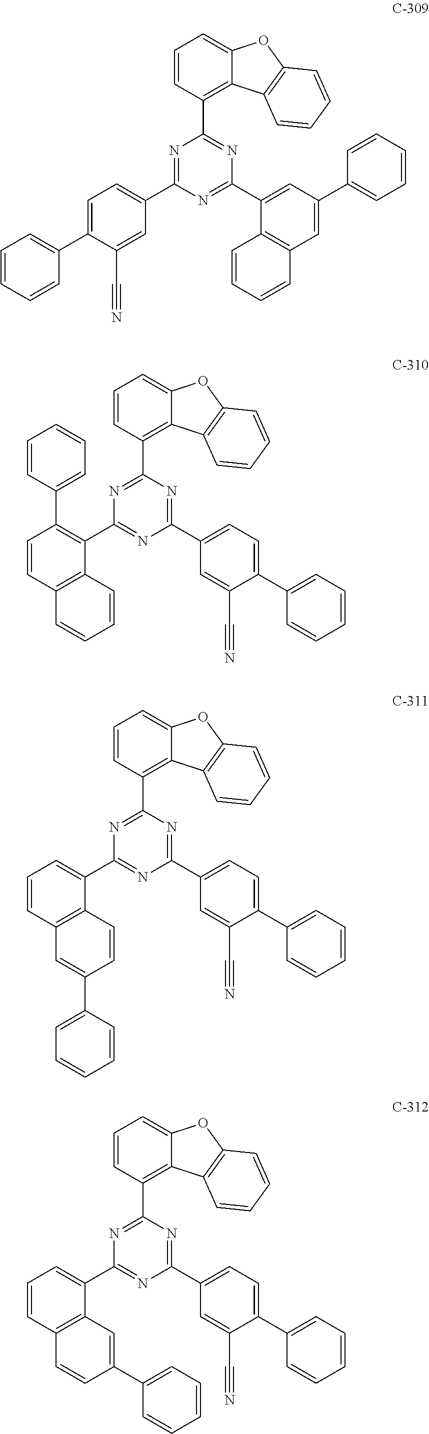 [SMILES: N#Cc1cc(-c2nc(-c3cc(-c4ccccc4)cc4ccccc34)nc(-c3cccc4oc5ccccc5c34)n2)ccc1-c1ccccc1 ; N#Cc1cc(-c2nc(-c3c(-c4ccccc4)ccc4ccccc34)nc(-c3cccc4oc5ccccc5c34)n2)ccc1-c1ccccc1 ; N#Cc1cc(-c2nc(-c3cccc4cc(-c5ccccc5)ccc34)nc(-c3cccc4oc5ccccc5c34)n2)ccc1-c1ccccc1 ; N#Cc1cc(-c2nc(-c3cccc4ccc(-c5ccccc5)cc34)nc(-c3cccc4oc5ccccc5c34)n2)ccc1-c1ccccc1] 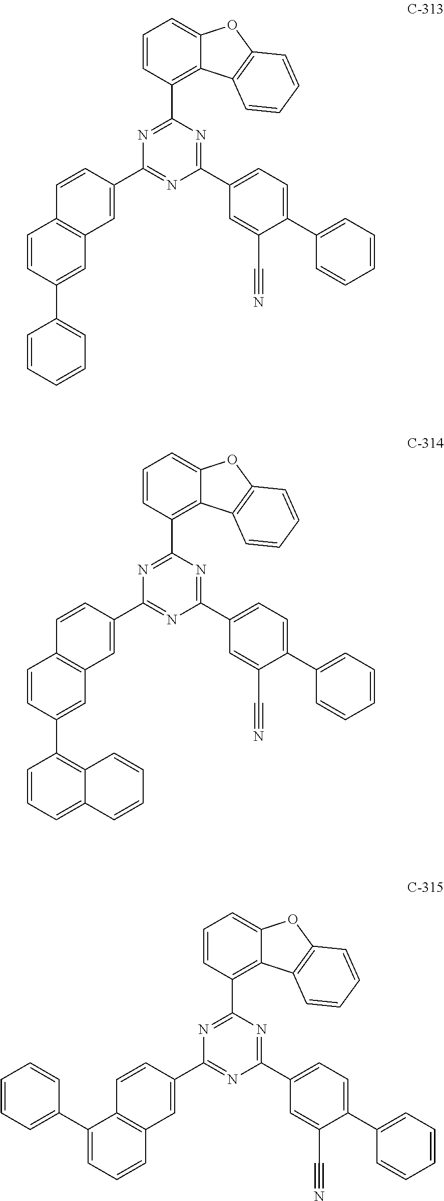 [SMILES: N#Cc1cc(-c2nc(-c3ccc4ccc(-c5ccccc5)cc4c3)nc(-c3cccc4oc5ccccc5c34)n2)ccc1-c1ccccc1 ; N#Cc1cc(-c2nc(-c3ccc4ccc(-c5cccc6ccccc56)cc4c3)nc(-c3cccc4oc5ccccc5c34)n2)ccc1-c1ccccc1 ; N#Cc1cc(-c2nc(-c3ccc4c(-c5ccccc5)cccc4c3)nc(-c3cccc4oc5ccccc5c34)n2)ccc1-c1ccccc1] 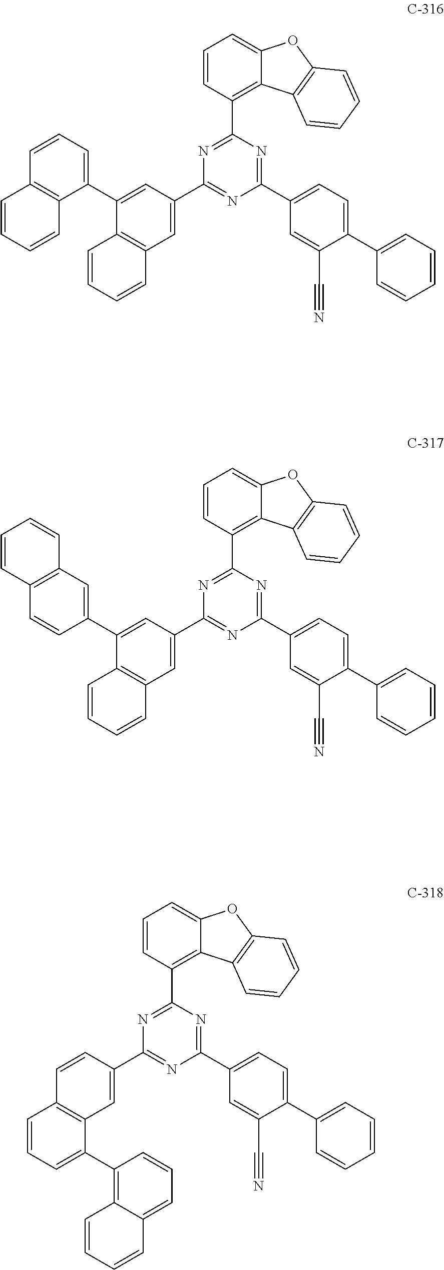 [SMILES: N#Cc1cc(-c2nc(-c3cc(-c4cccc5ccccc45)c4ccccc4c3)nc(-c3cccc4oc5ccccc5c34)n2)ccc1-c1ccccc1 ; N#Cc1cc(-c2nc(-c3cc(-c4ccc5ccccc5c4)c4ccccc4c3)nc(-c3cccc4oc5ccccc5c34)n2)ccc1-c1ccccc1 ; N#Cc1cc(-c2nc(-c3ccc4cccc(-c5cccc6ccccc56)c4c3)nc(-c3cccc4oc5ccccc5c34)n2)ccc1-c1ccccc1] 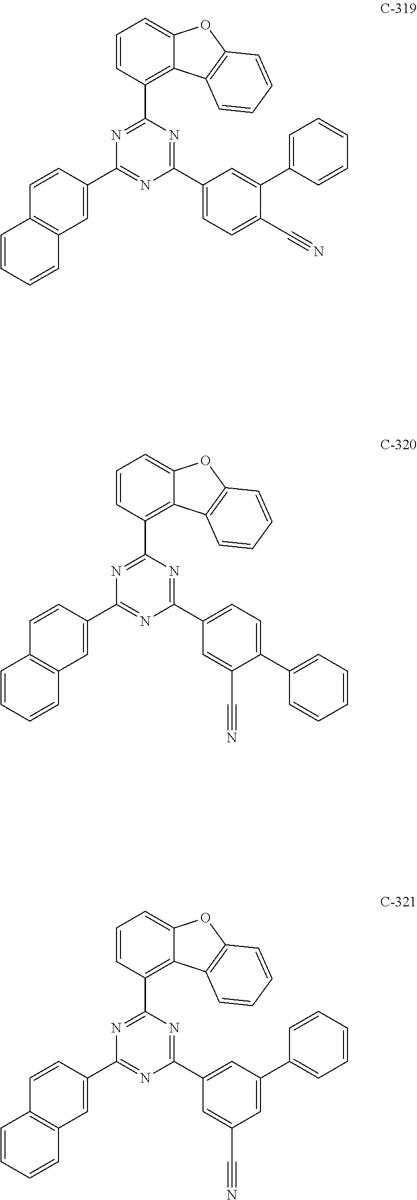 [SMILES: N#Cc1ccc(-c2nc(-c3ccc4ccccc4c3)nc(-c3cccc4oc5ccccc5c34)n2)cc1-c1ccccc1 ; N#Cc1cc(-c2nc(-c3ccc4ccccc4c3)nc(-c3cccc4oc5ccccc5c34)n2)ccc1-c1ccccc1 ; N#Cc1cc(-c2ccccc2)cc(-c2nc(-c3ccc4ccccc4c3)nc(-c3cccc4oc5ccccc5c34)n2)c1] 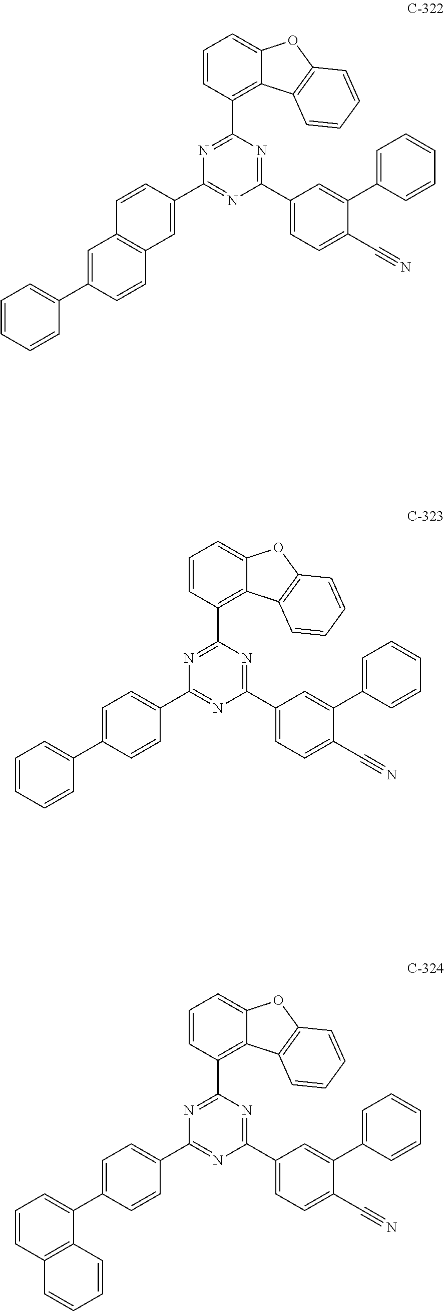 [SMILES: N#Cc1ccc(-c2nc(-c3ccc4cc(-c5ccccc5)ccc4c3)nc(-c3cccc4oc5ccccc5c34)n2)cc1-c1ccccc1 ; N#Cc1ccc(-c2nc(-c3ccc(-c4ccccc4)cc3)nc(-c3cccc4oc5ccccc5c34)n2)cc1-c1ccccc1 ; N#Cc1ccc(-c2nc(-c3ccc(-c4cccc5ccccc45)cc3)nc(-c3cccc4oc5ccccc5c34)n2)cc1-c1ccccc1] 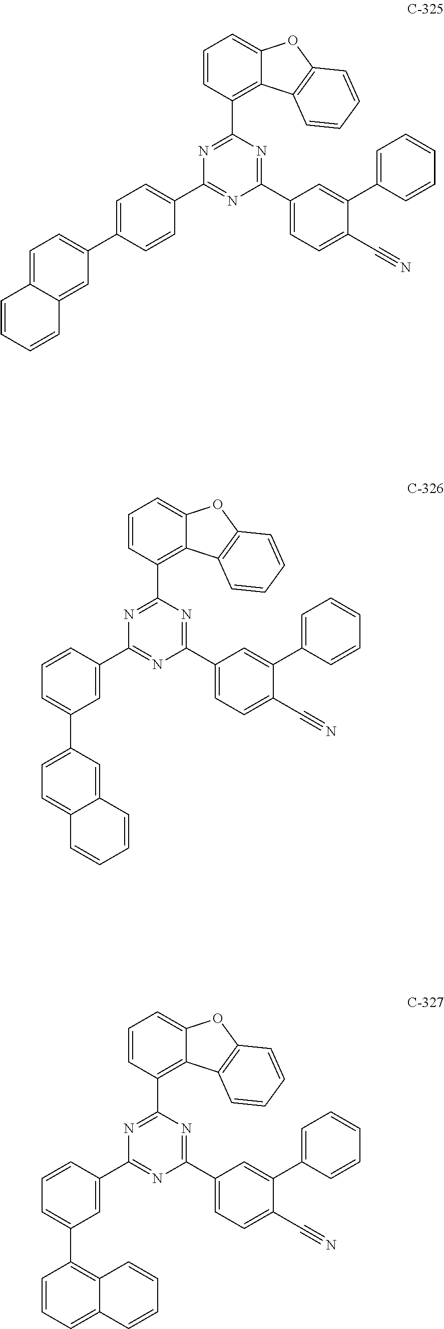 [SMILES: N#Cc1ccc(-c2nc(-c3ccc(-c4ccc5ccccc5c4)cc3)nc(-c3cccc4oc5ccccc5c34)n2)cc1-c1ccccc1 ; N#Cc1ccc(-c2nc(-c3cccc(-c4ccc5ccccc5c4)c3)nc(-c3cccc4oc5ccccc5c34)n2)cc1-c1ccccc1 ; N#Cc1ccc(-c2nc(-c3cccc(-c4cccc5ccccc45)c3)nc(-c3cccc4oc5ccccc5c34)n2)cc1-c1ccccc1] 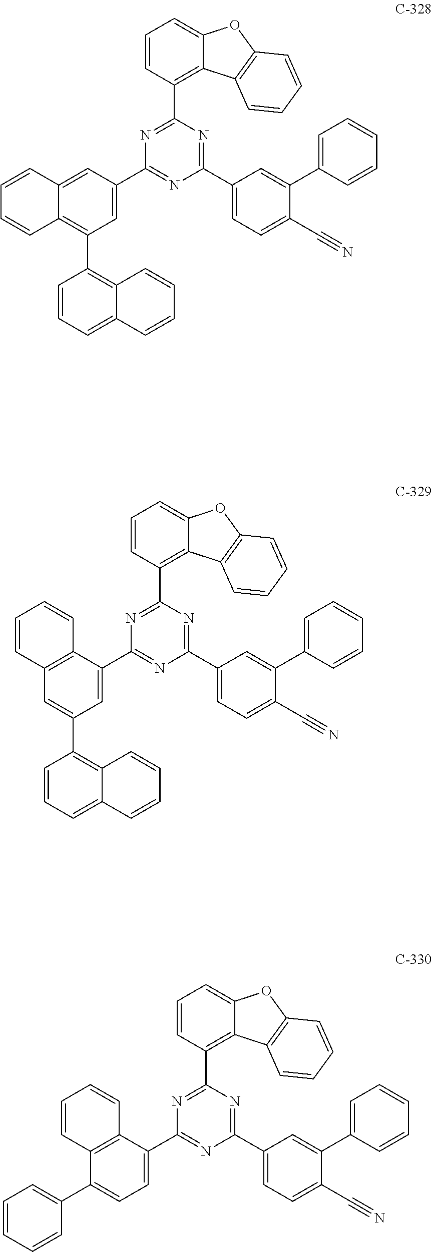 [SMILES: N#Cc1ccc(-c2nc(-c3cc(-c4cccc5ccccc45)c4ccccc4c3)nc(-c3cccc4oc5ccccc5c34)n2)cc1-c1ccccc1 ; N#Cc1ccc(-c2nc(-c3cc(-c4cccc5ccccc45)cc4ccccc34)nc(-c3cccc4oc5ccccc5c34)n2)cc1-c1ccccc1 ; N#Cc1ccc(-c2nc(-c3ccc(-c4ccccc4)c4ccccc34)nc(-c3cccc4oc5ccccc5c34)n2)cc1-c1ccccc1] 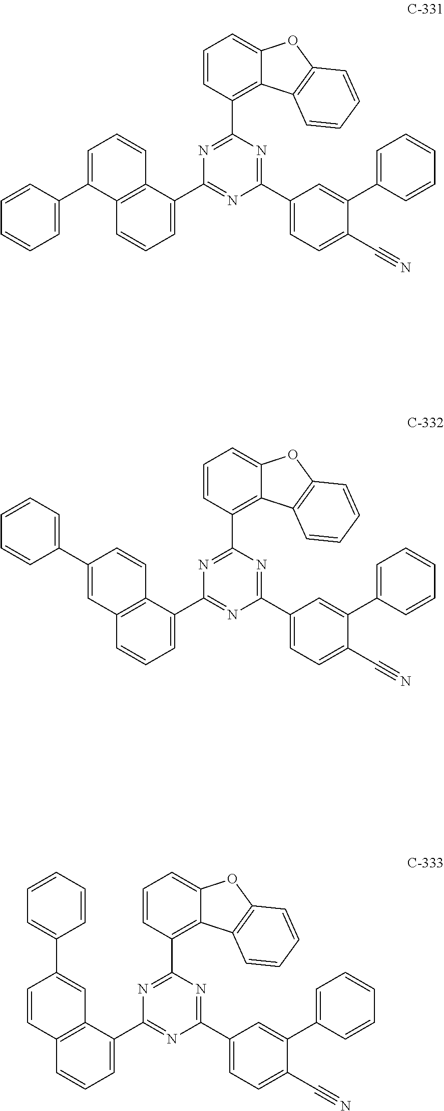 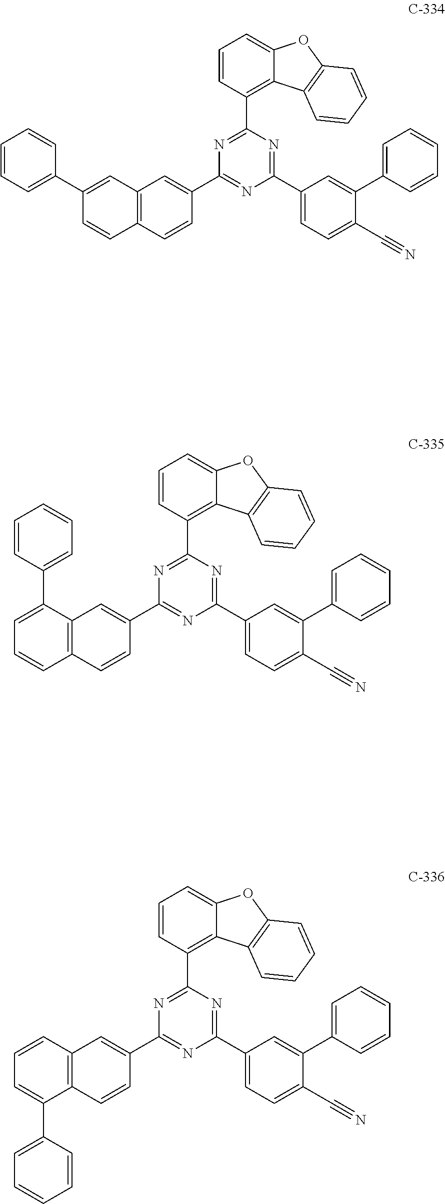 [SMILES: N#Cc1ccc(-c2nc(-c3ccc4ccc(-c5ccccc5)cc4c3)nc(-c3cccc4oc5ccccc5c34)n2)cc1-c1ccccc1 ; N#Cc1ccc(-c2nc(-c3ccc4cccc(-c5ccccc5)c4c3)nc(-c3cccc4oc5ccccc5c34)n2)cc1-c1ccccc1 ; N#Cc1ccc(-c2nc(-c3ccc4c(-c5ccccc5)cccc4c3)nc(-c3cccc4oc5ccccc5c34)n2)cc1-c1ccccc1] 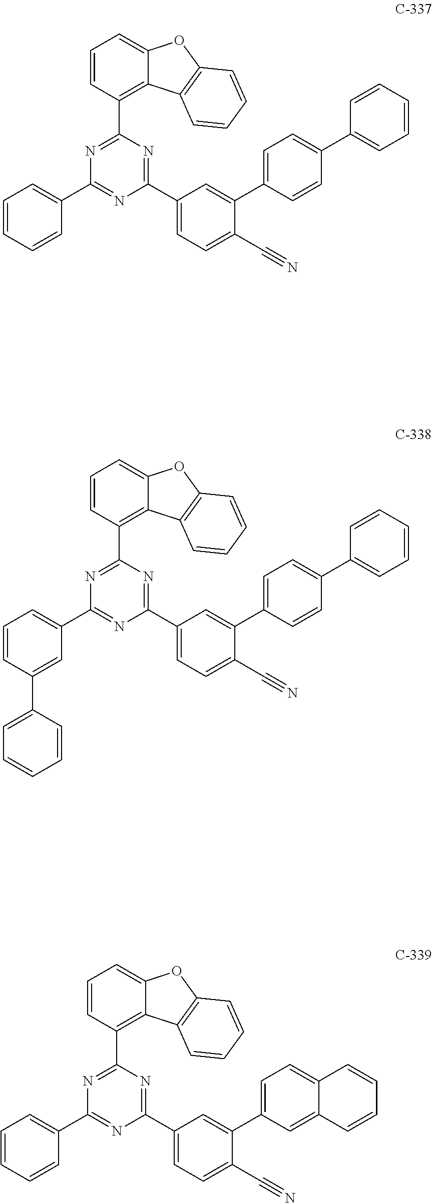 [SMILES: N#Cc1ccc(-c2nc(-c3ccccc3)nc(-c3cccc4oc5ccccc5c34)n2)cc1-c1ccc(-c2ccccc2)cc1 ; N#Cc1ccc(-c2nc(-c3cccc(-c4ccccc4)c3)nc(-c3cccc4oc5ccccc5c34)n2)cc1-c1ccc(-c2ccccc2)cc1 ; N#Cc1ccc(-c2nc(-c3ccccc3)nc(-c3cccc4oc5ccccc5c34)n2)cc1-c1ccc2ccccc2c1] 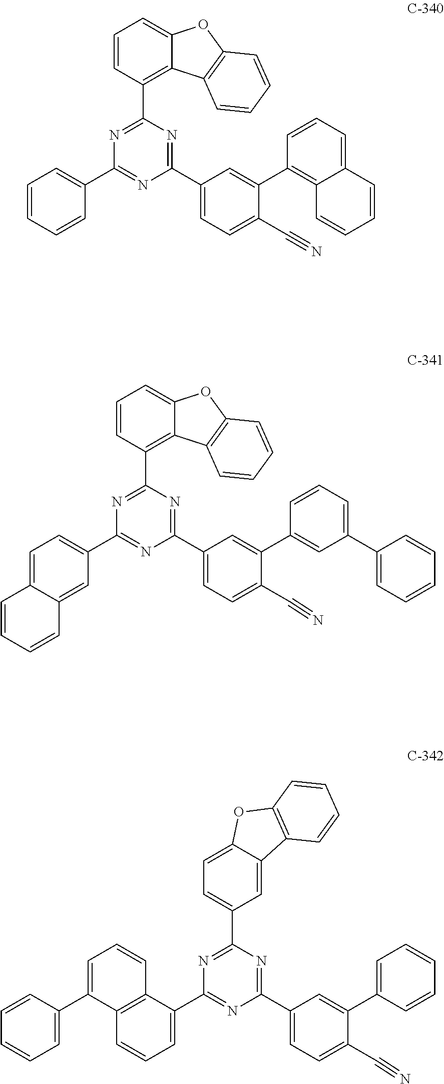 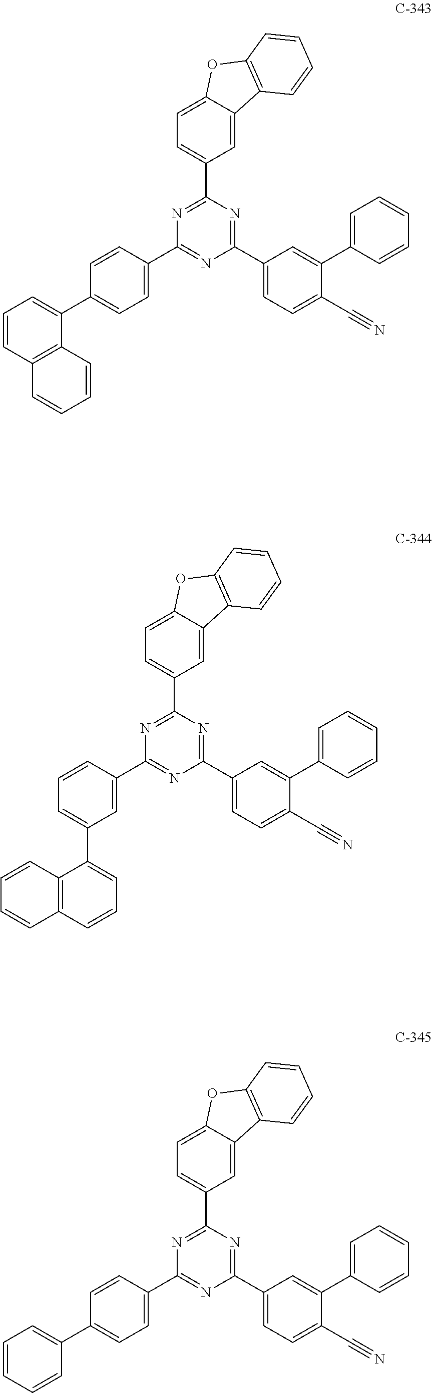 [SMILES: N#Cc1ccc(-c2nc(-c3ccc(-c4cccc5ccccc45)cc3)nc(-c3ccc4oc5ccccc5c4c3)n2)cc1-c1ccccc1 ; N#Cc1ccc(-c2nc(-c3cccc(-c4cccc5ccccc45)c3)nc(-c3ccc4oc5ccccc5c4c3)n2)cc1-c1ccccc1 ; N#Cc1ccc(-c2nc(-c3ccc(-c4ccccc4)cc3)nc(-c3ccc4oc5ccccc5c4c3)n2)cc1-c1ccccc1] 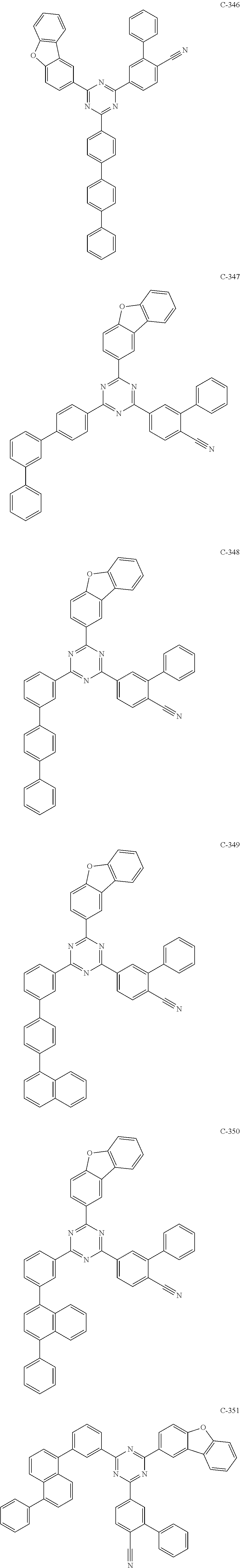 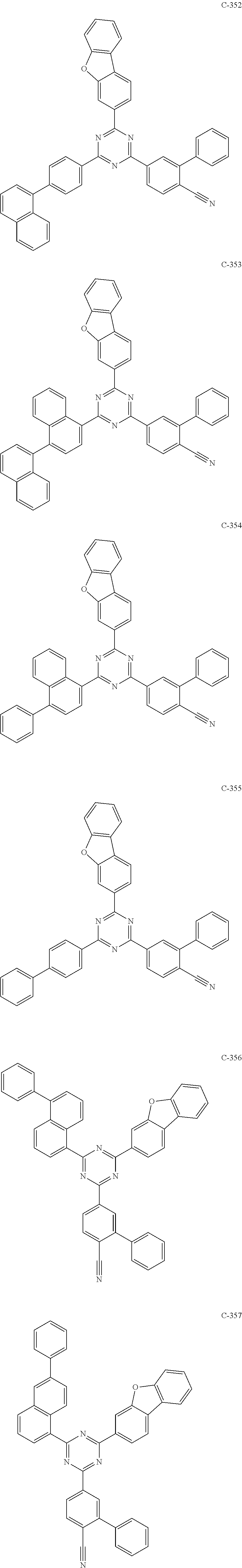 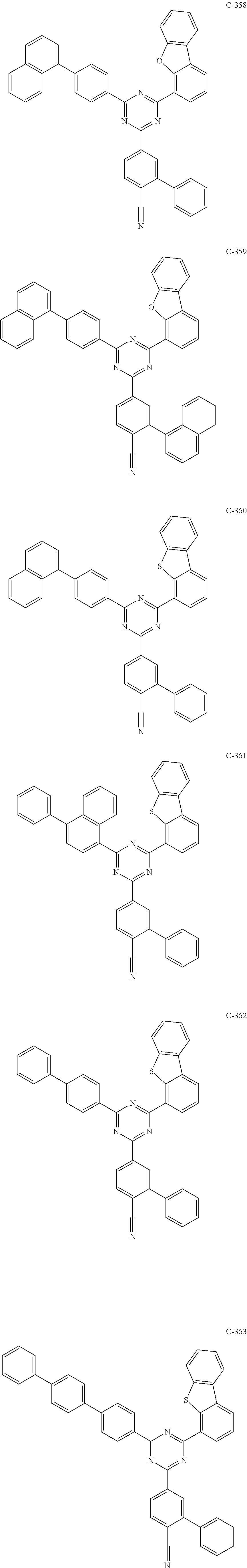 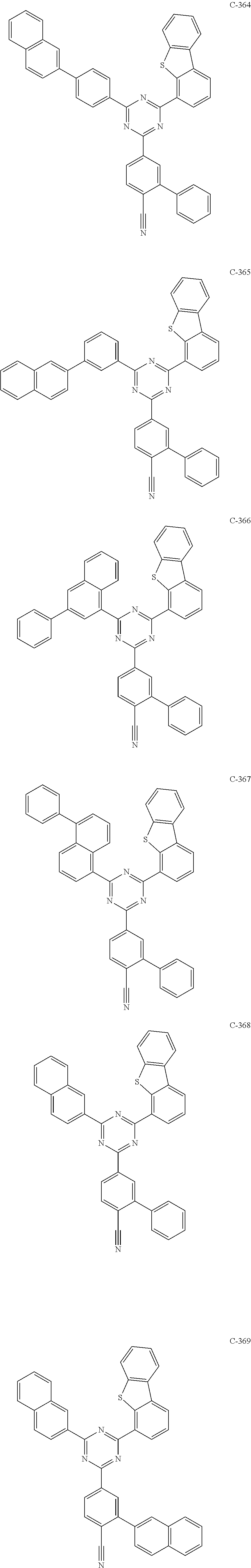 [SMILES: N#Cc1ccc(-c2nc(-c3ccc(-c4ccc5ccccc5c4)cc3)nc(-c3cccc4c3sc3ccccc34)n2)cc1-c1ccccc1 ; N#Cc1ccc(-c2nc(-c3cccc(-c4ccc5ccccc5c4)c3)nc(-c3cccc4c3sc3ccccc34)n2)cc1-c1ccccc1 ; N#Cc1ccc(-c2nc(-c3cc(-c4ccccc4)cc4ccccc34)nc(-c3cccc4c3sc3ccccc34)n2)cc1-c1ccccc1 ; N#Cc1ccc(-c2nc(-c3cccc4c(-c5ccccc5)cccc34)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccc2ccccc2c1] 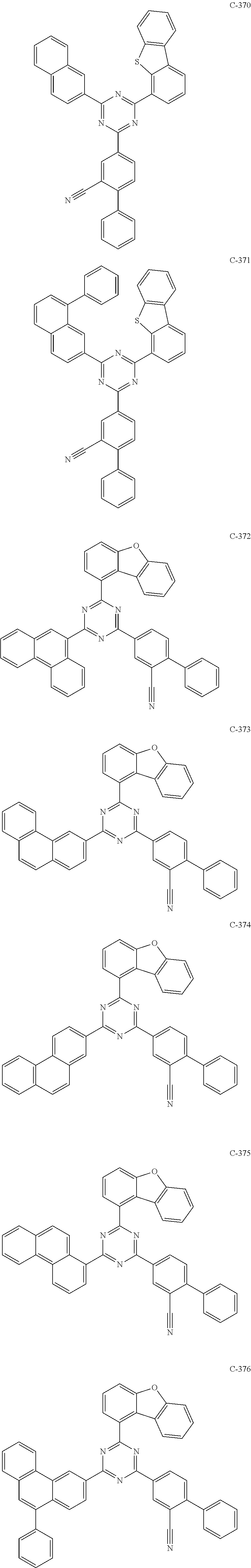 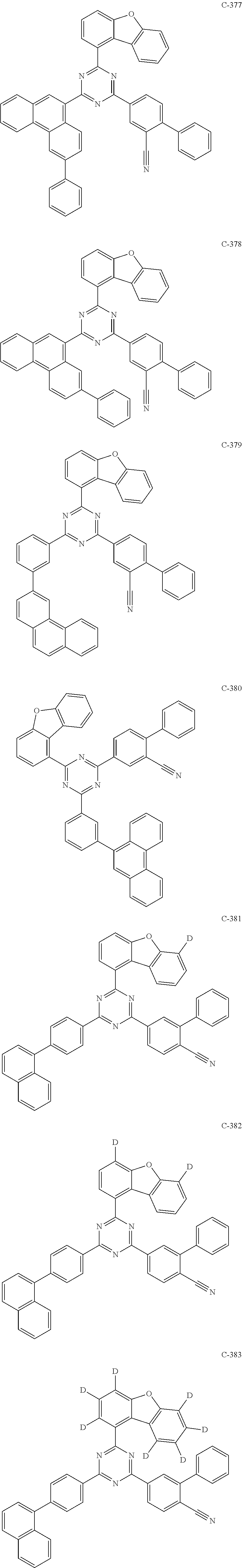 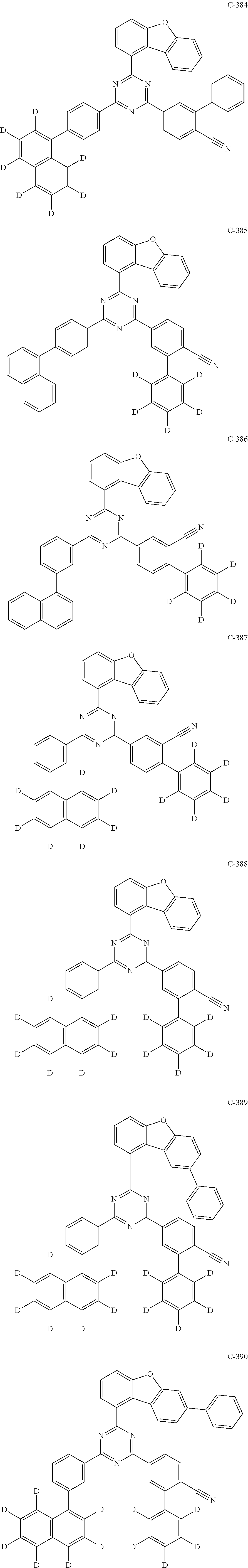 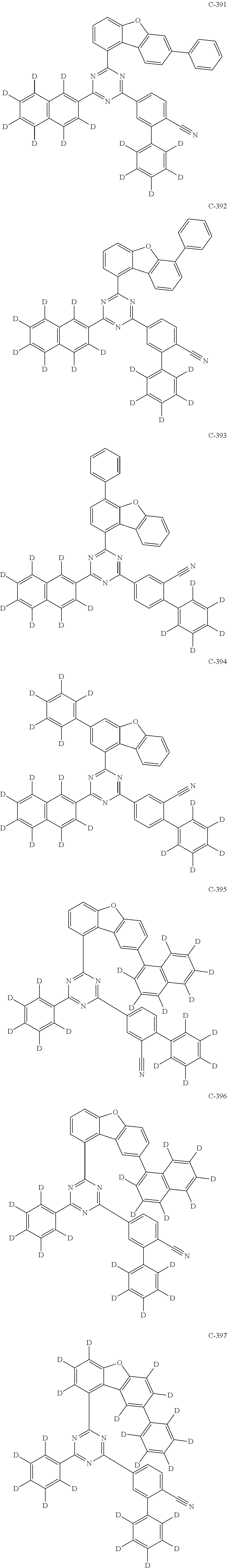 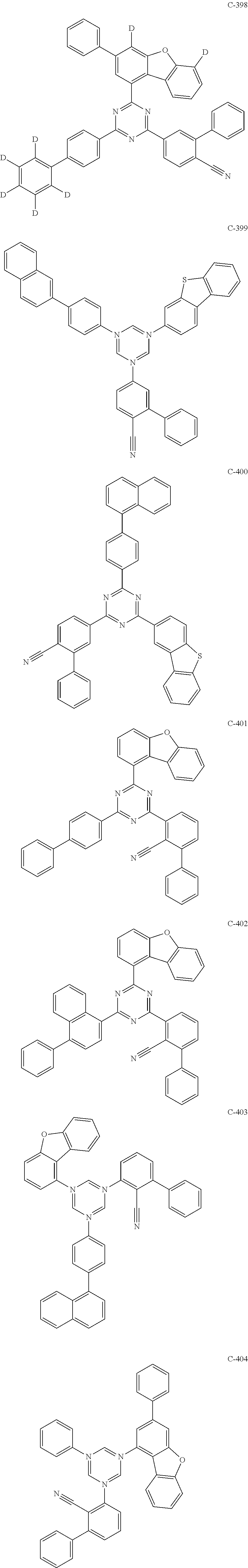 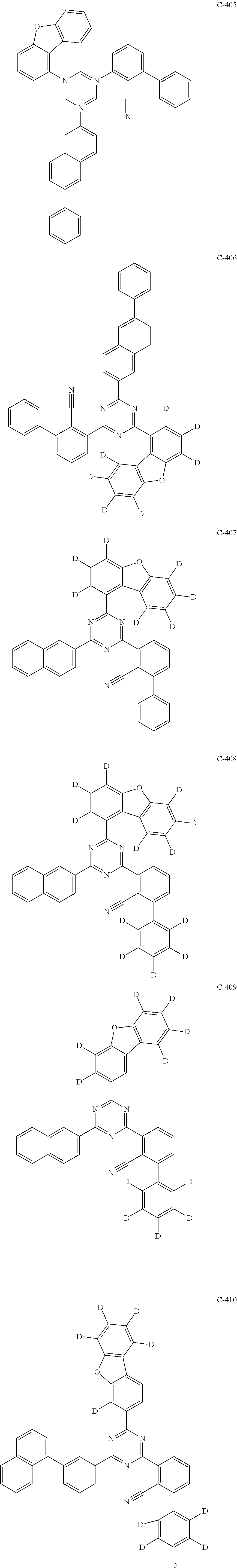 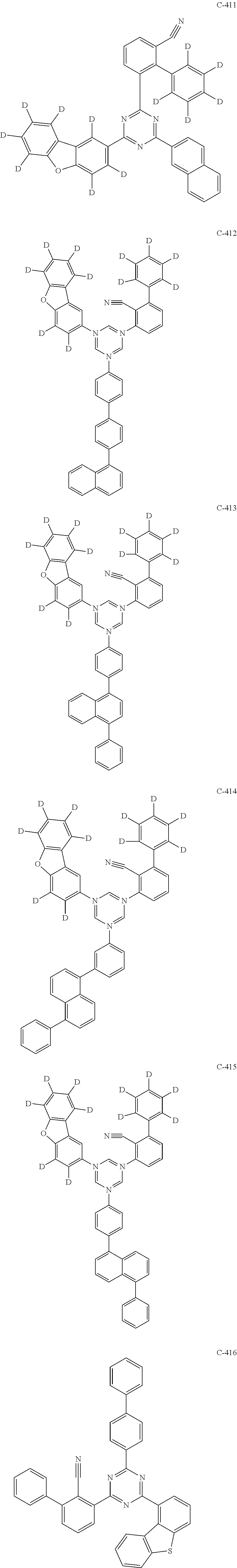 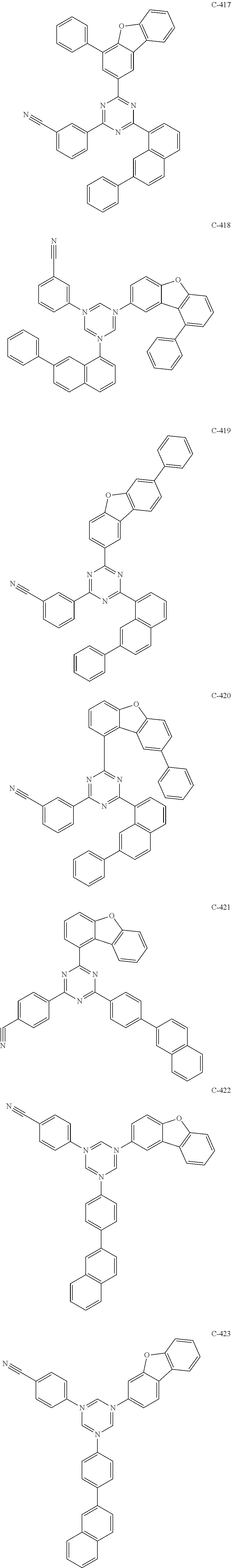 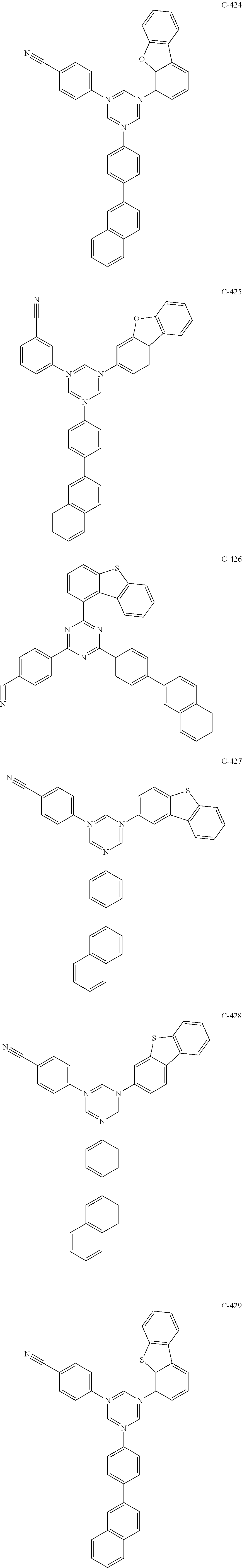 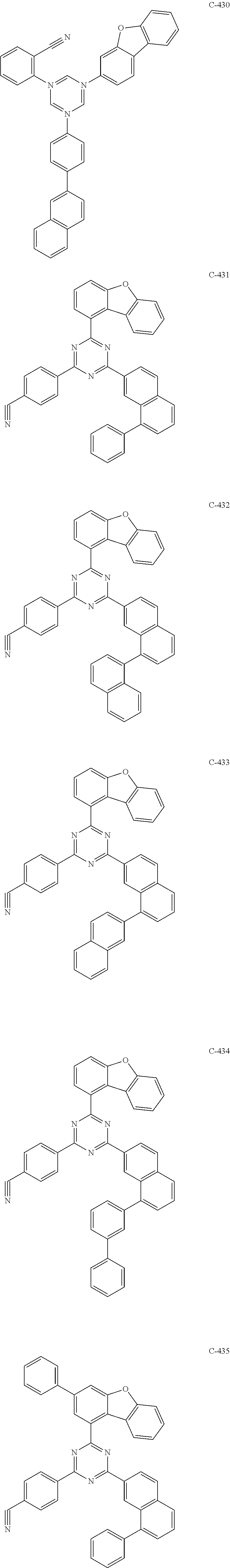 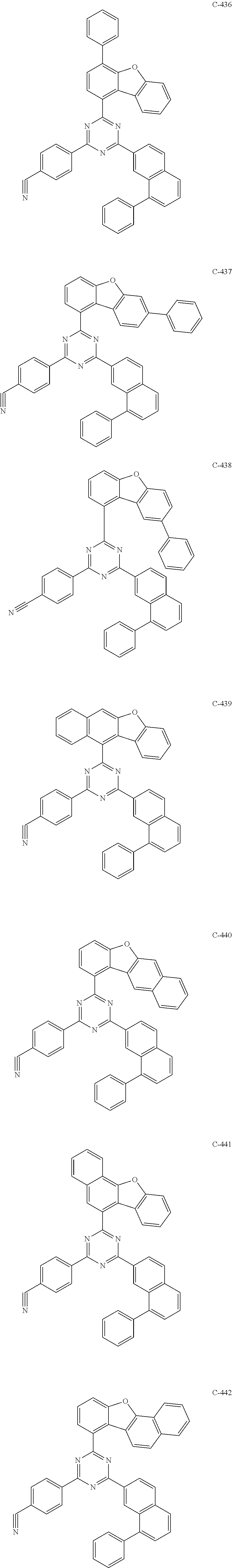 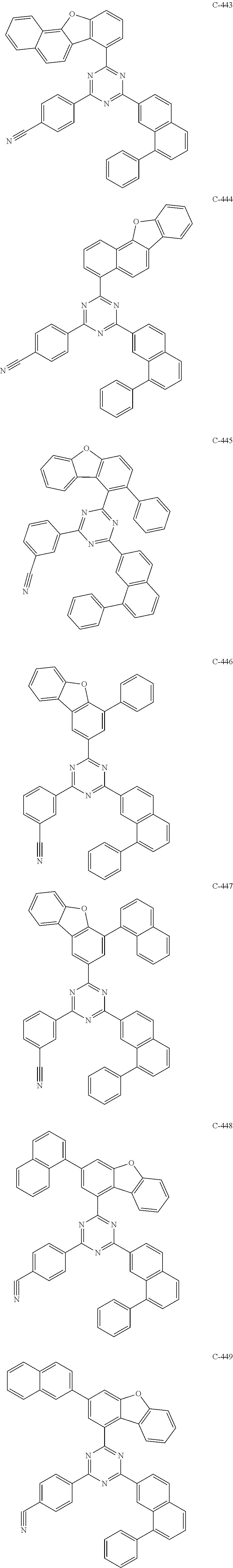 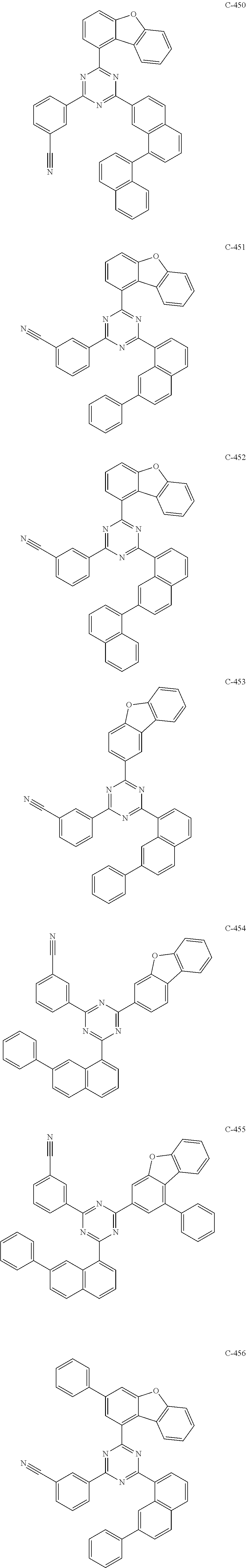 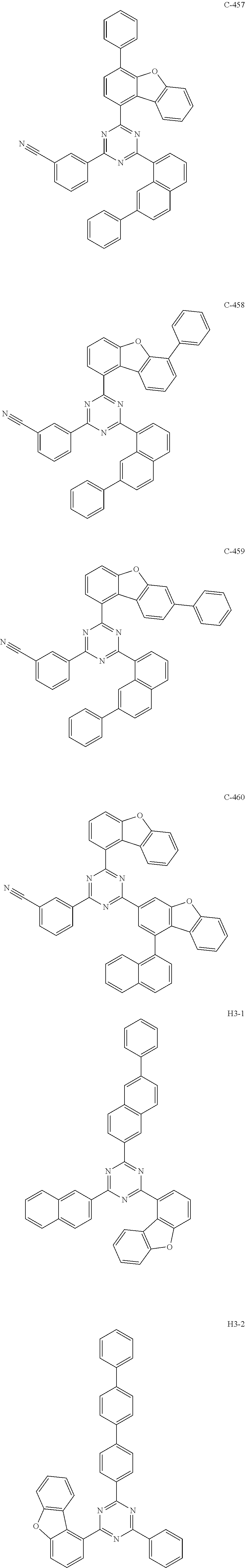 [SMILES: N#Cc1cccc(-c2nc(-c3cccc4ccc(-c5ccccc5)cc34)nc(-c3ccc(-c4ccccc4)c4oc5ccccc5c34)n2)c1 ; N#Cc1cccc(-c2nc(-c3cccc4ccc(-c5ccccc5)cc34)nc(-c3cccc4oc5c(-c6ccccc6)cccc5c34)n2)c1 ; N#Cc1cccc(-c2nc(-c3cccc4ccc(-c5ccccc5)cc34)nc(-c3cccc4oc5cc(-c6ccccc6)ccc5c34)n2)c1 ; N#Cc1cccc(-c2nc(-c3cc(-c4cccc5ccccc45)c4c(c3)oc3ccccc34)nc(-c3cccc4oc5ccccc5c34)n2)c1 ; c1ccc(-c2ccc3cc(-c4nc(-c5ccc6ccccc6c5)nc(-c5cccc6oc7ccccc7c56)n4)ccc3c2)cc1 ; c1ccc(-c2ccc(-c3ccc(-c4nc(-c5ccccc5)nc(-c5cccc6oc7ccccc7c56)n4)cc3)cc2)cc1] 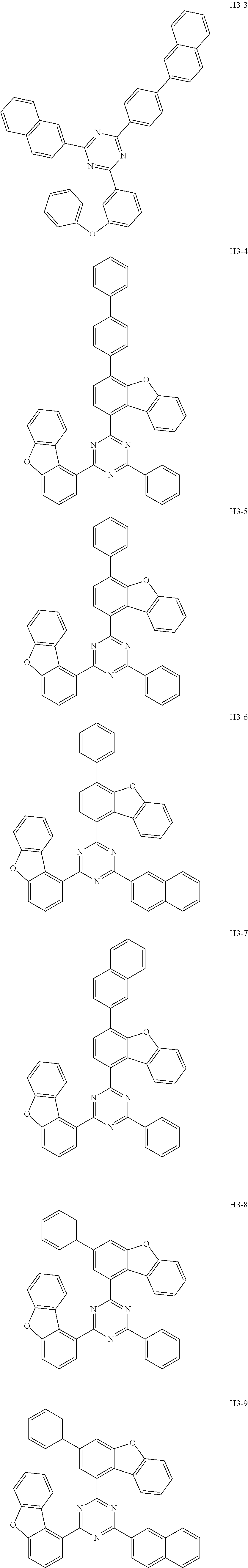 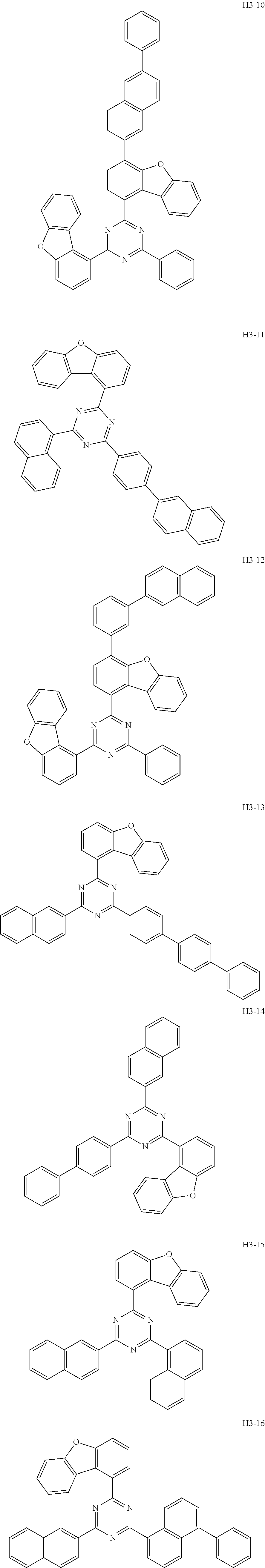 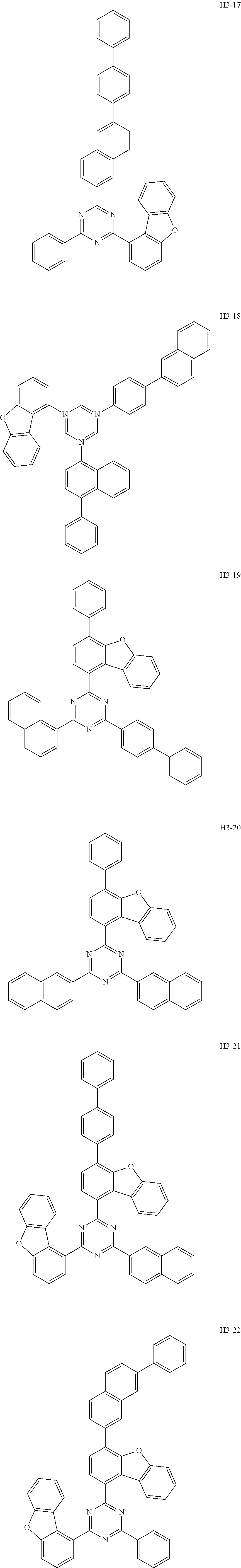 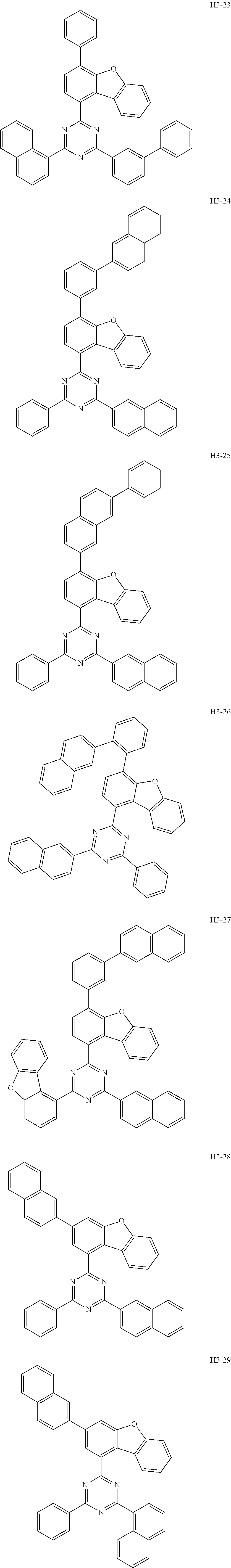 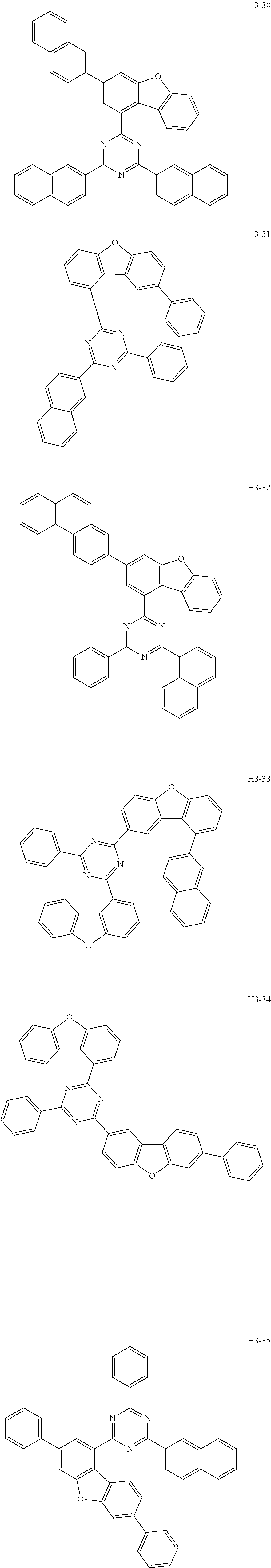 [SMILES: c1ccc2cc(-c3cc(-c4nc(-c5ccc6ccccc6c5)nc(-c5ccc6ccccc6c5)n4)c4c(c3)oc3ccccc34)ccc2c1 ; c1ccc(-c2ccc3oc4cccc(-c5nc(-c6ccccc6)nc(-c6ccc7ccccc7c6)n5)c4c3c2)cc1 ; c1ccc(-c2nc(-c3cccc4ccccc34)nc(-c3cc(-c4ccc5c(ccc6ccccc65)c4)cc4oc5ccccc5c34)n2)cc1 ; c1ccc(-c2nc(-c3ccc4oc5cccc(-c6ccc7ccccc7c6)c5c4c3)nc(-c3cccc4oc5ccccc5c34)n2)cc1 ; c1ccc(-c2ccc3c(c2)oc2ccc(-c4nc(-c5ccccc5)nc(-c5cccc6oc7ccccc7c56)n4)cc23)cc1 ; c1ccc(-c2ccc3c(c2)oc2cc(-c4ccccc4)cc(-c4nc(-c5ccccc5)nc(-c5ccc6ccccc6c5)n4)c23)cc1] 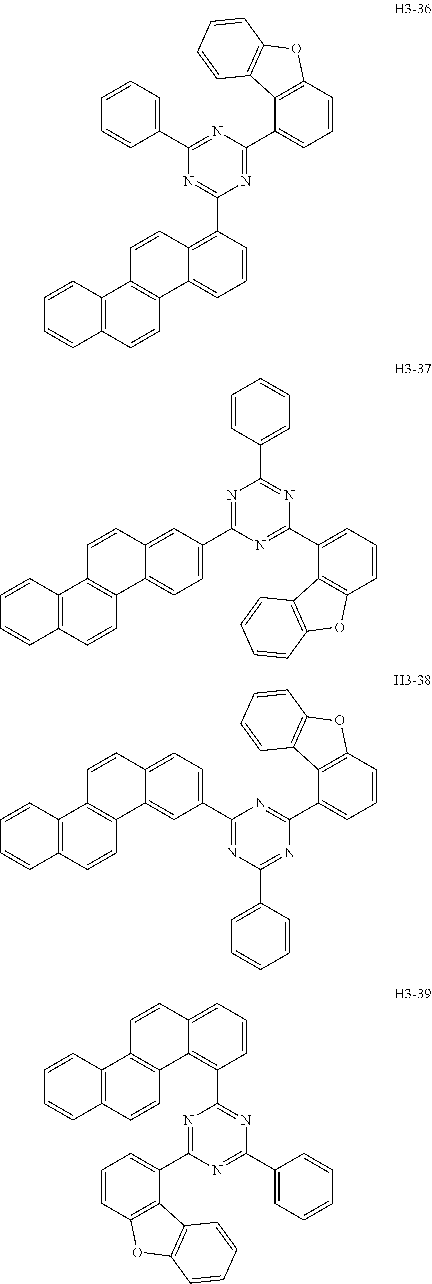 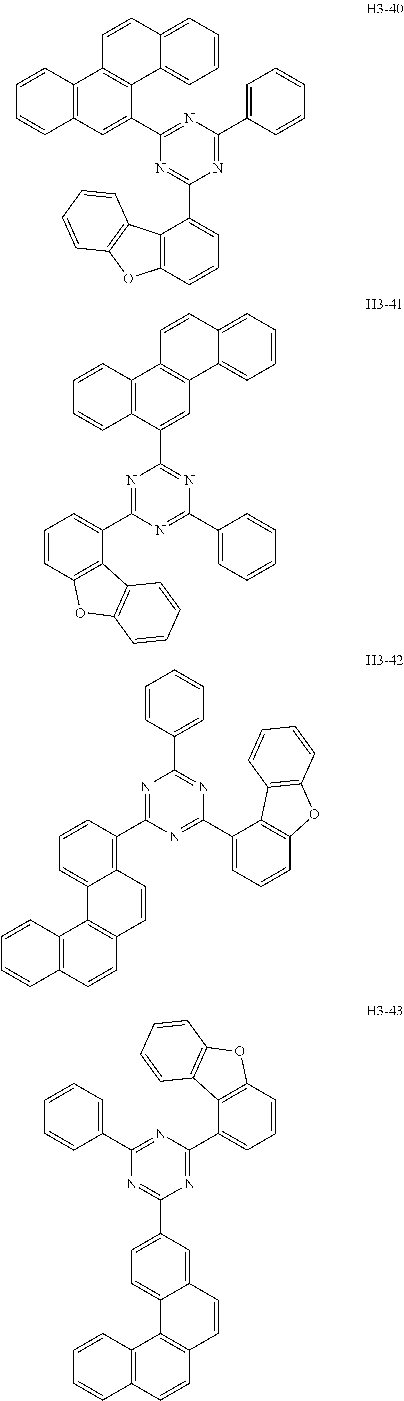 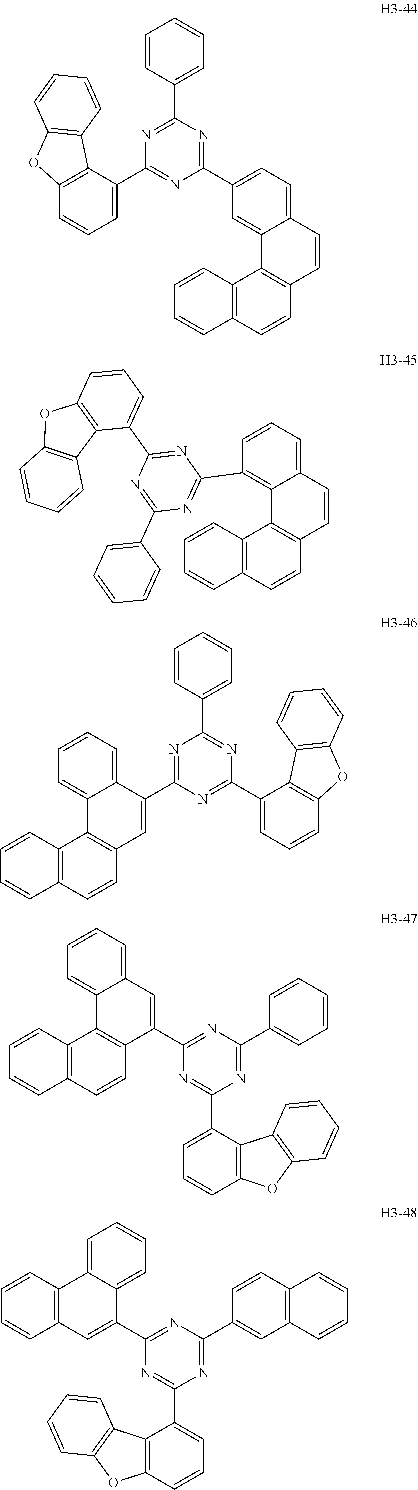 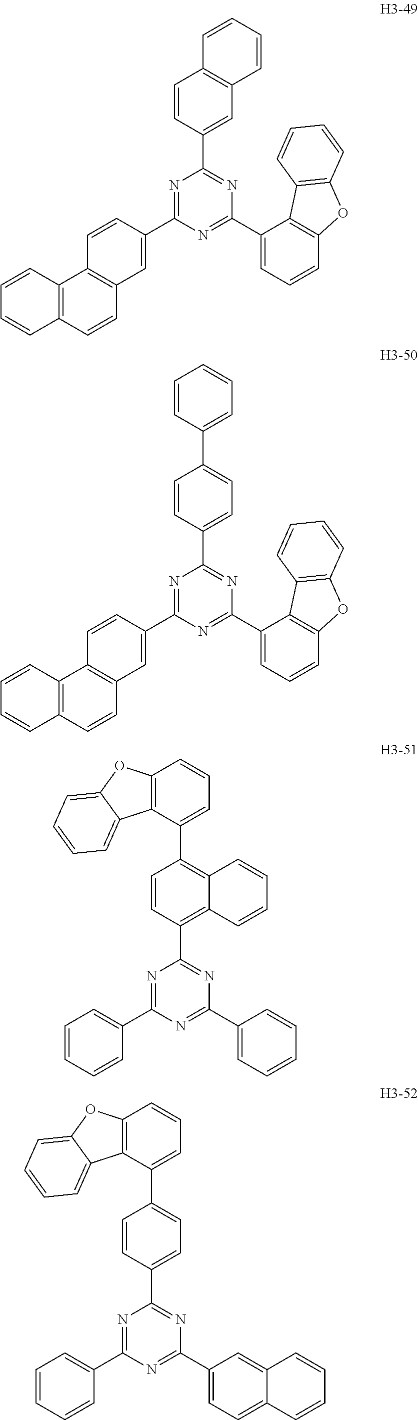 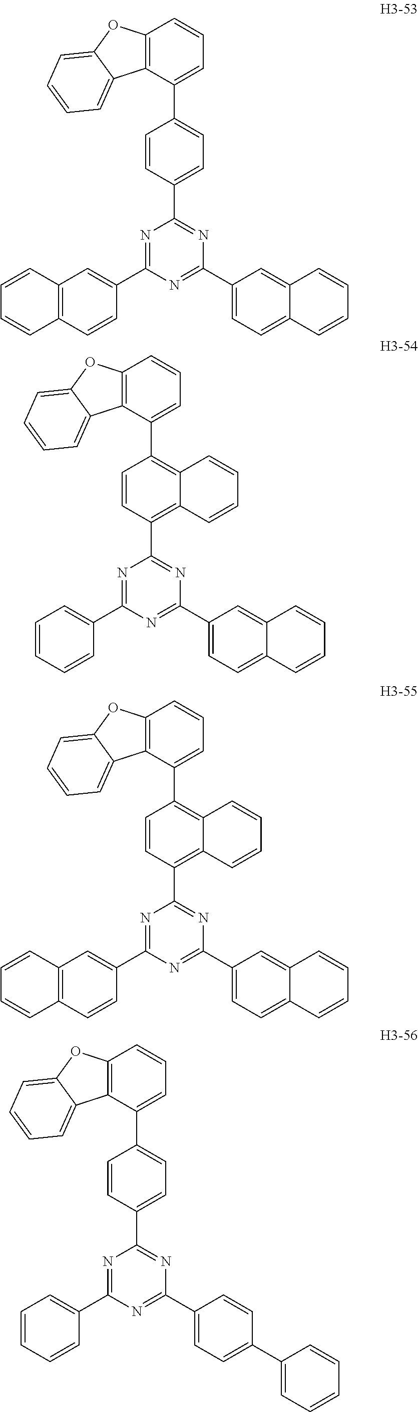 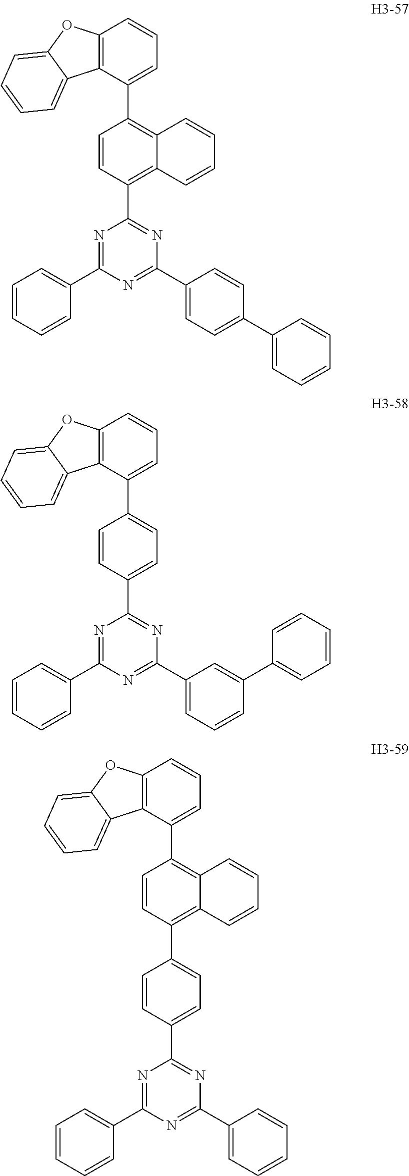 [SMILES: c1ccc(-c2ccc(-c3nc(-c4ccccc4)nc(-c4ccc(-c5cccc6oc7ccccc7c56)c5ccccc45)n3)cc2)cc1 ; c1ccc(-c2cccc(-c3nc(-c4ccccc4)nc(-c4ccc(-c5cccc6oc7ccccc7c56)cc4)n3)c2)cc1 ; c1ccc(-c2nc(-c3ccccc3)nc(-c3ccc(-c4ccc(-c5cccc6oc7ccccc7c56)c5ccccc45)cc3)n2)cc1] 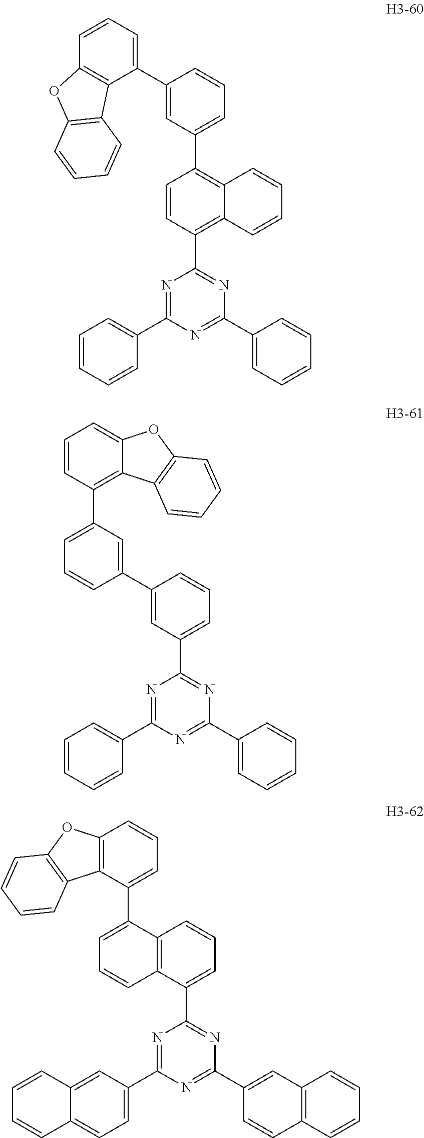 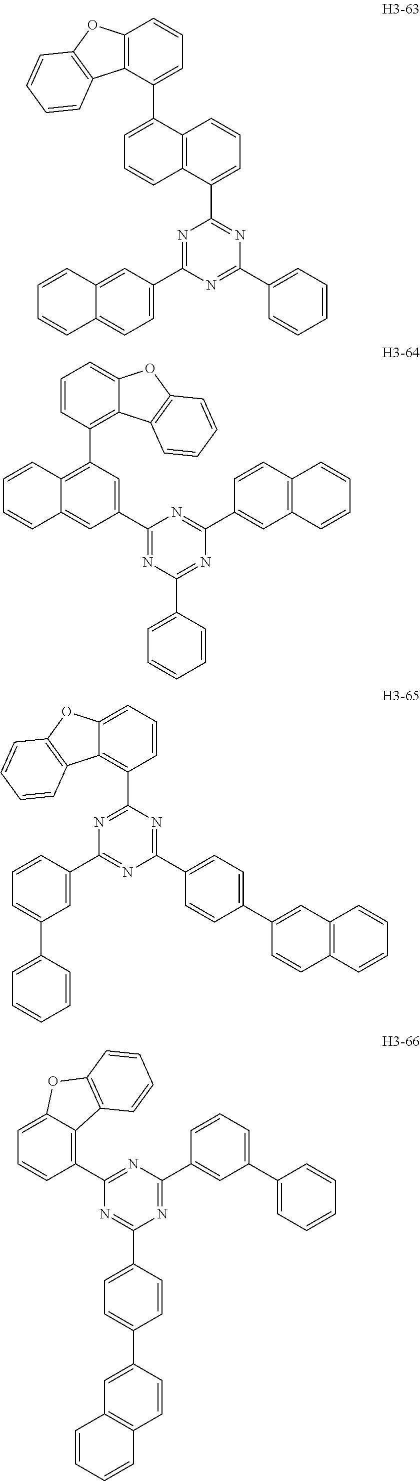 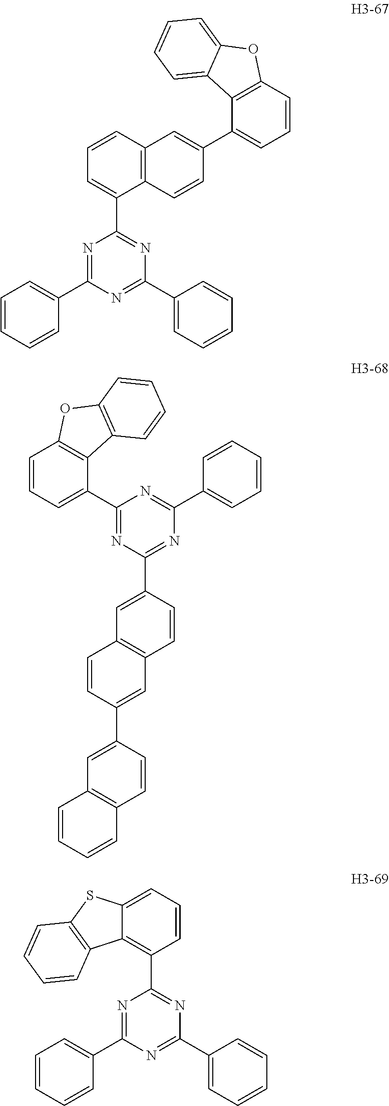 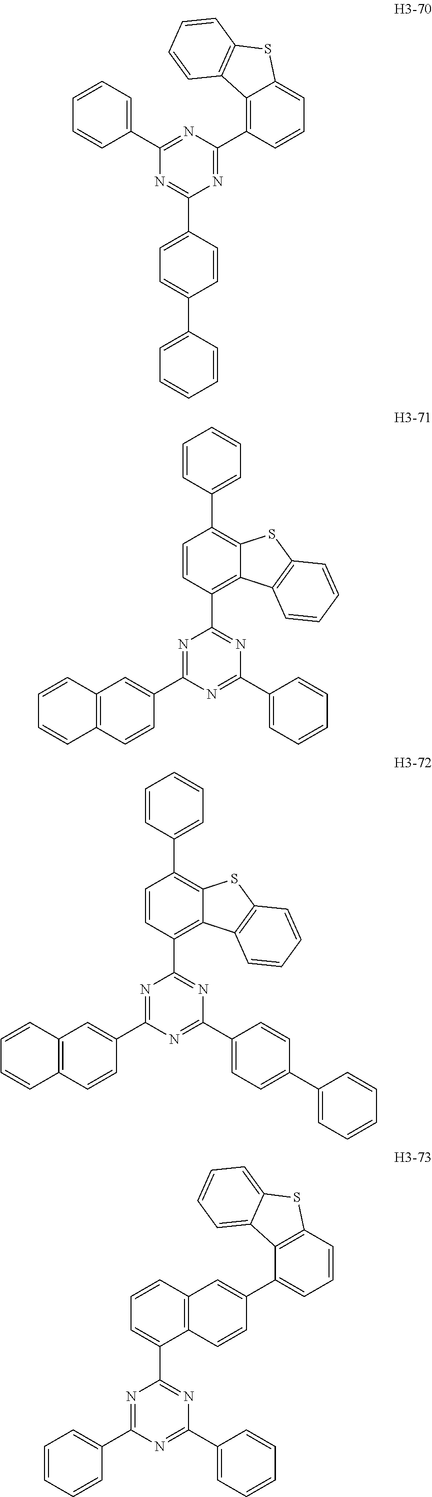 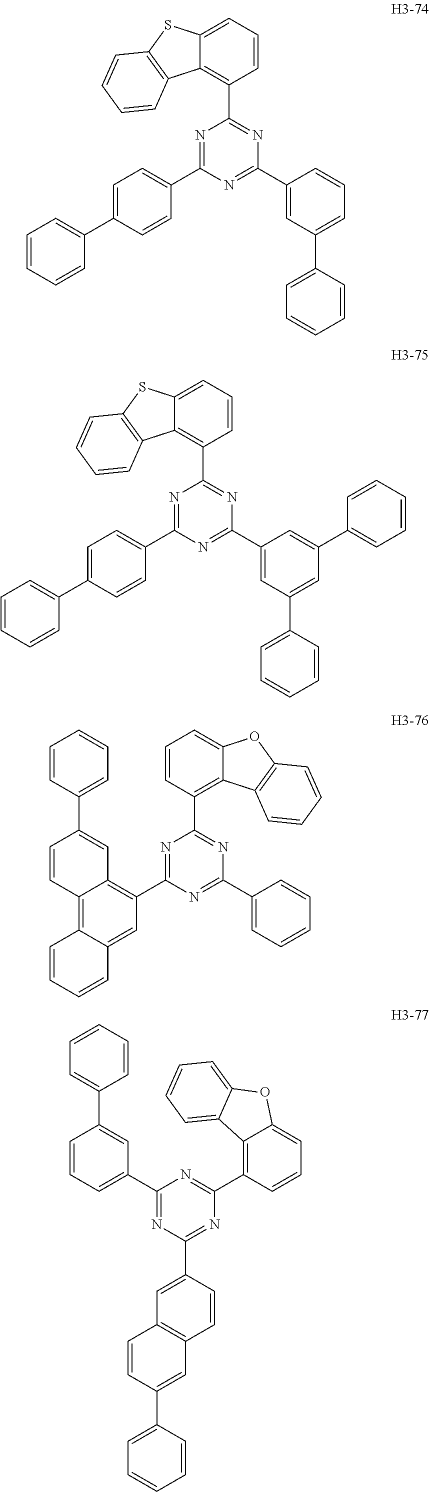 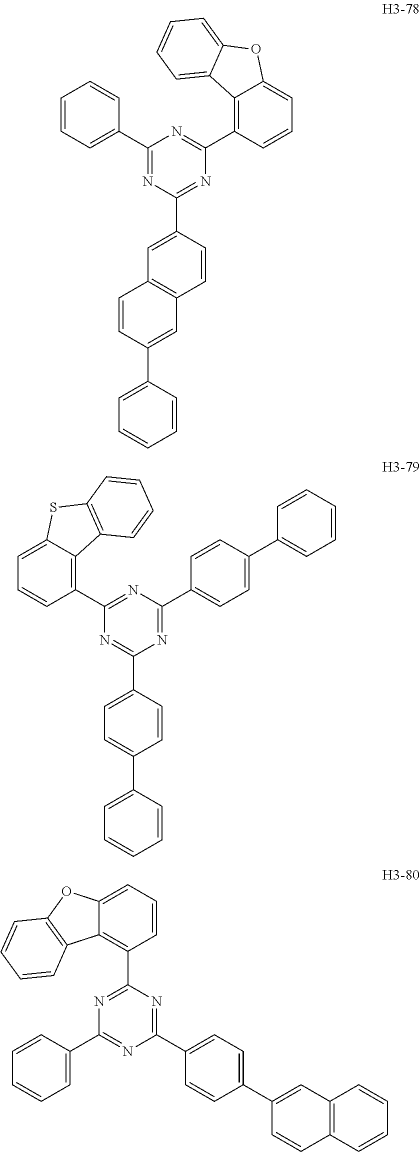 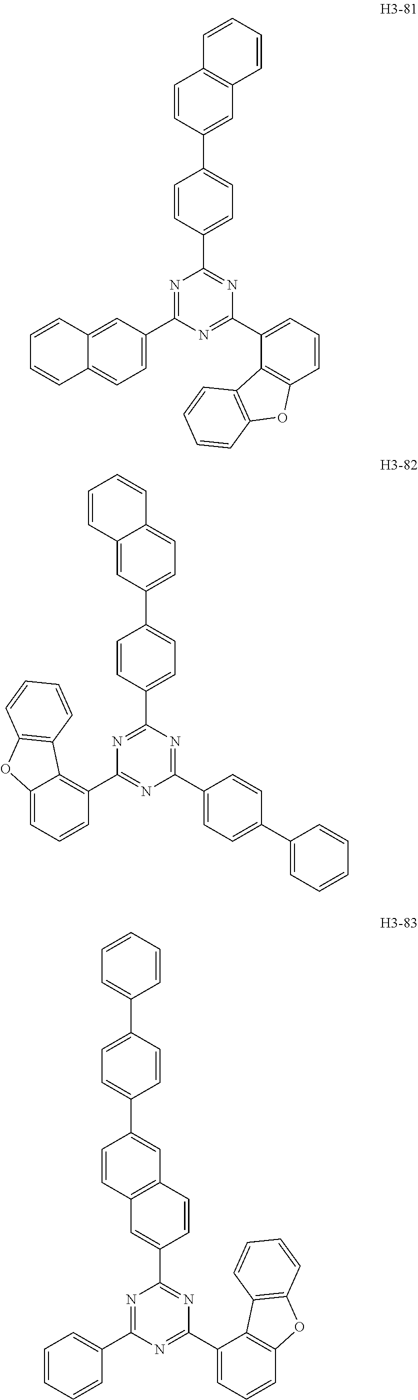 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3ccc4cc(-c5nc(-c6ccccc6)nc(-c6cccc7oc8ccccc8c67)n5)ccc4c3)cc2)cc1] 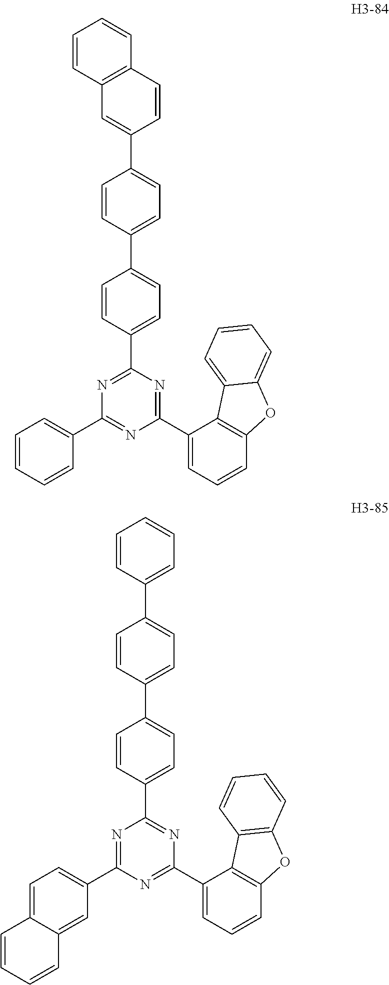 [SMILES: c1ccc(-c2nc(-c3ccc(-c4ccc(-c5ccc6ccccc6c5)cc4)cc3)nc(-c3cccc4oc5ccccc5c34)n2)cc1 ; c1ccc(-c2ccc(-c3ccc(-c4nc(-c5ccc6ccccc6c5)nc(-c5cccc6oc7ccccc7c56)n4)cc3)cc2)cc1] 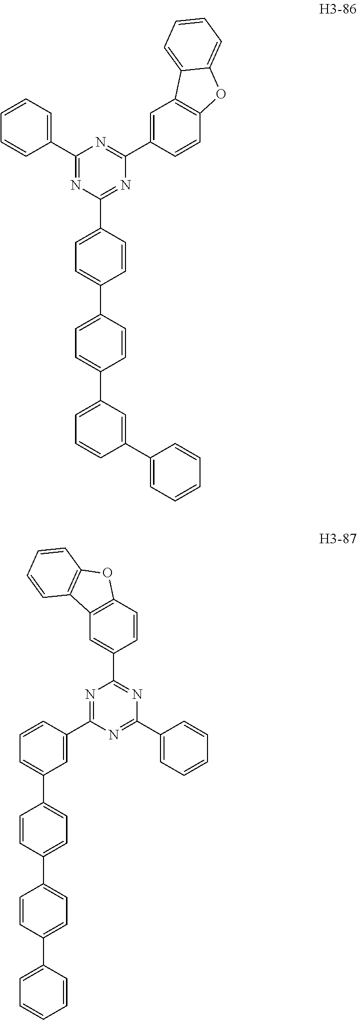 [SMILES: c1ccc(-c2cccc(-c3ccc(-c4ccc(-c5nc(-c6ccccc6)nc(-c6ccc7oc8ccccc8c7c6)n5)cc4)cc3)c2)cc1 ; c1ccc(-c2ccc(-c3ccc(-c4cccc(-c5nc(-c6ccccc6)nc(-c6ccc7oc8ccccc8c7c6)n5)c4)cc3)cc2)cc1] 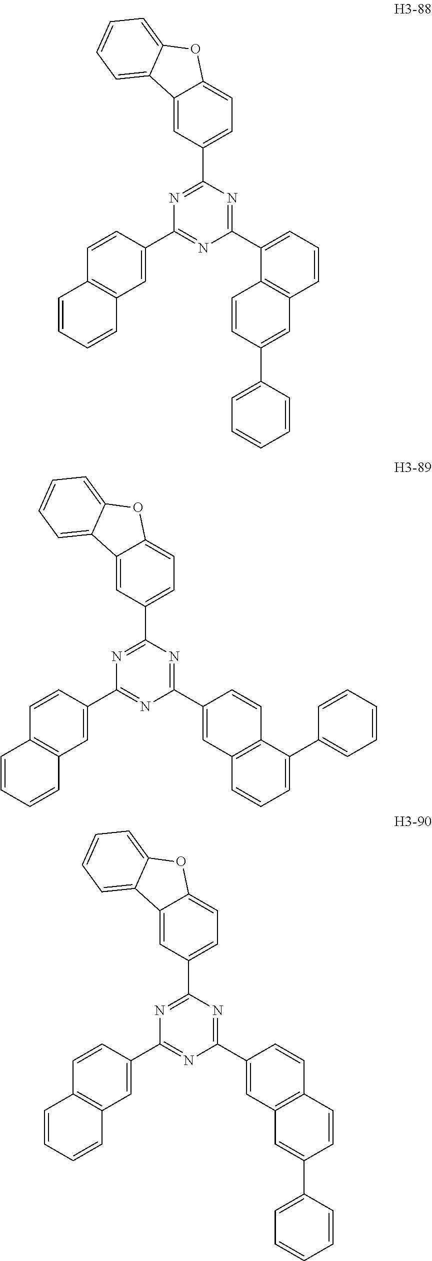 [SMILES: c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1] 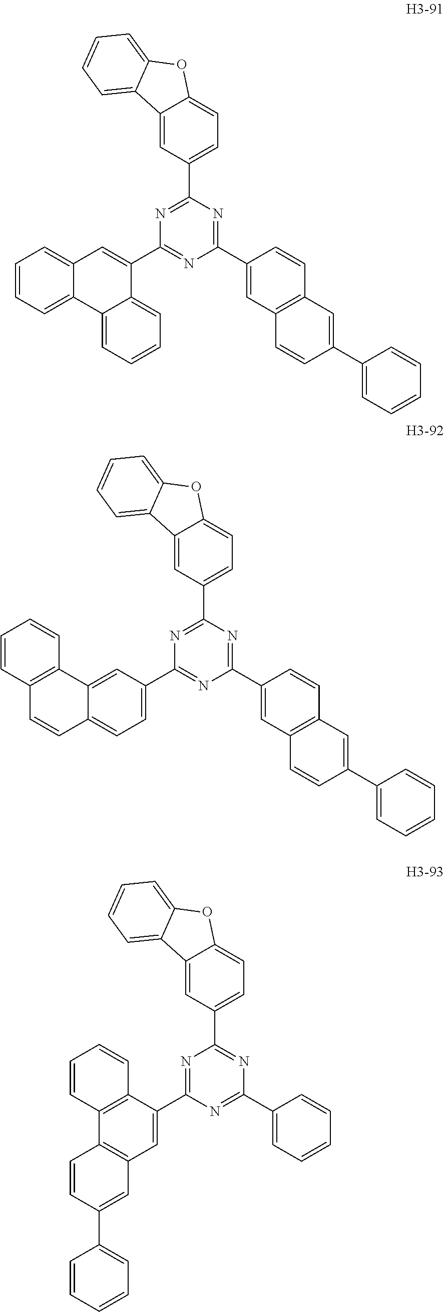 [SMILES: c1ccc(-c2ccc3cc(-c4nc(-c5ccc6oc7ccccc7c6c5)nc(-c5cc6ccccc6c6ccccc56)n4)ccc3c2)cc1 ; c1ccc(-c2ccc3cc(-c4nc(-c5ccc6ccc7ccccc7c6c5)nc(-c5ccc6oc7ccccc7c6c5)n4)ccc3c2)cc1 ; c1ccc(-c2ccc3c(c2)cc(-c2nc(-c4ccccc4)nc(-c4ccc5oc6ccccc6c5c4)n2)c2ccccc23)cc1] 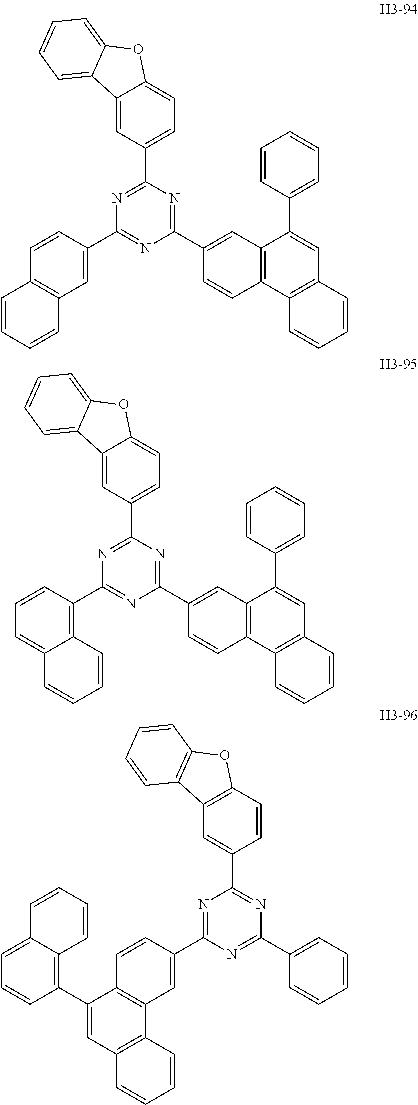 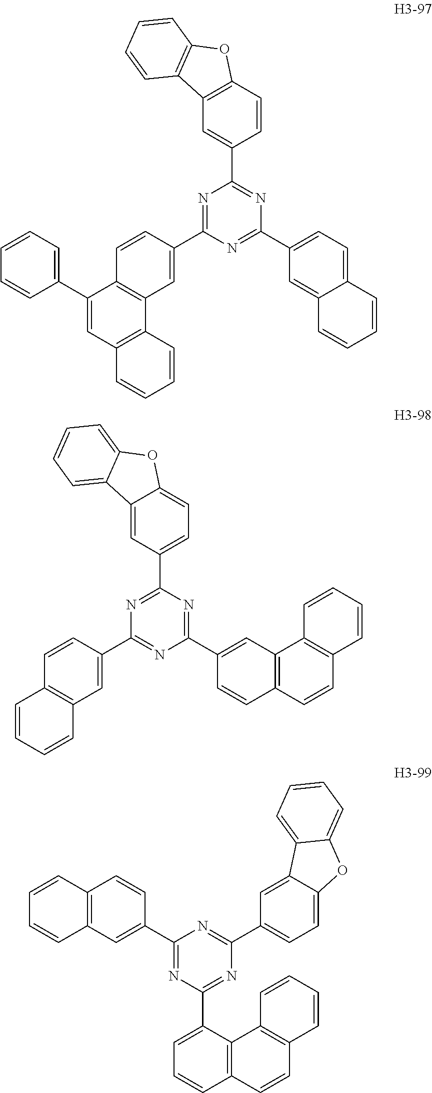 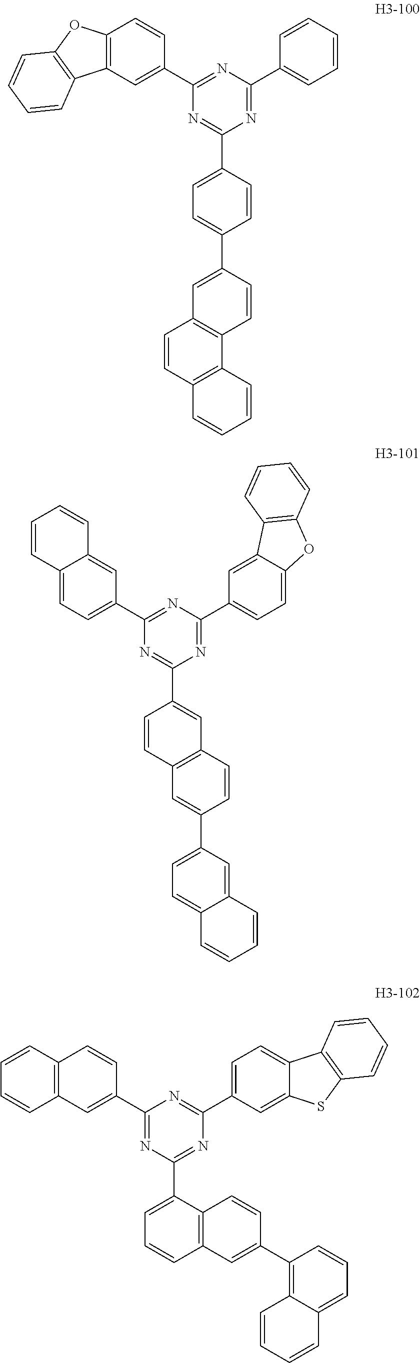 [SMILES: c1ccc(-c2nc(-c3ccc(-c4ccc5c(ccc6ccccc65)c4)cc3)nc(-c3ccc4oc5ccccc5c4c3)n2)cc1 ; c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1] 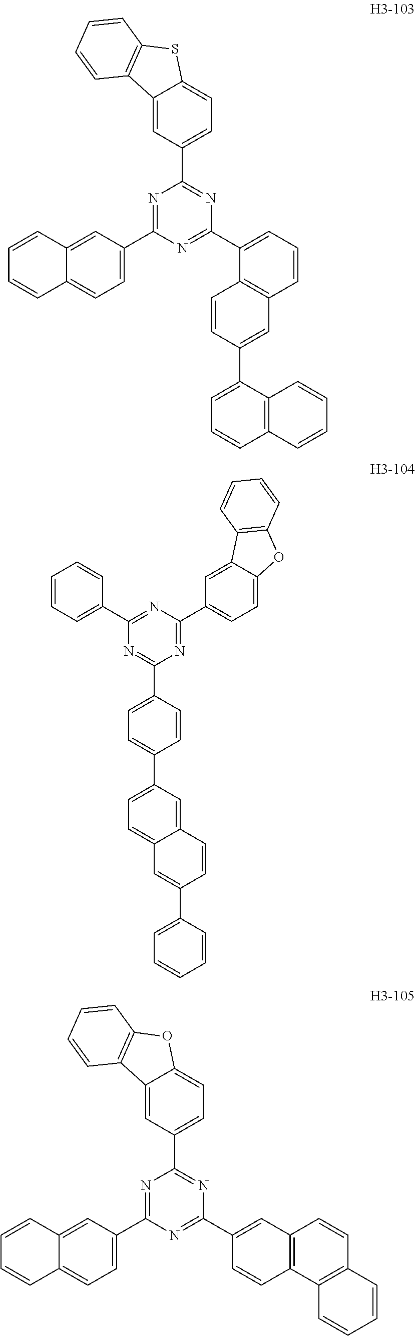 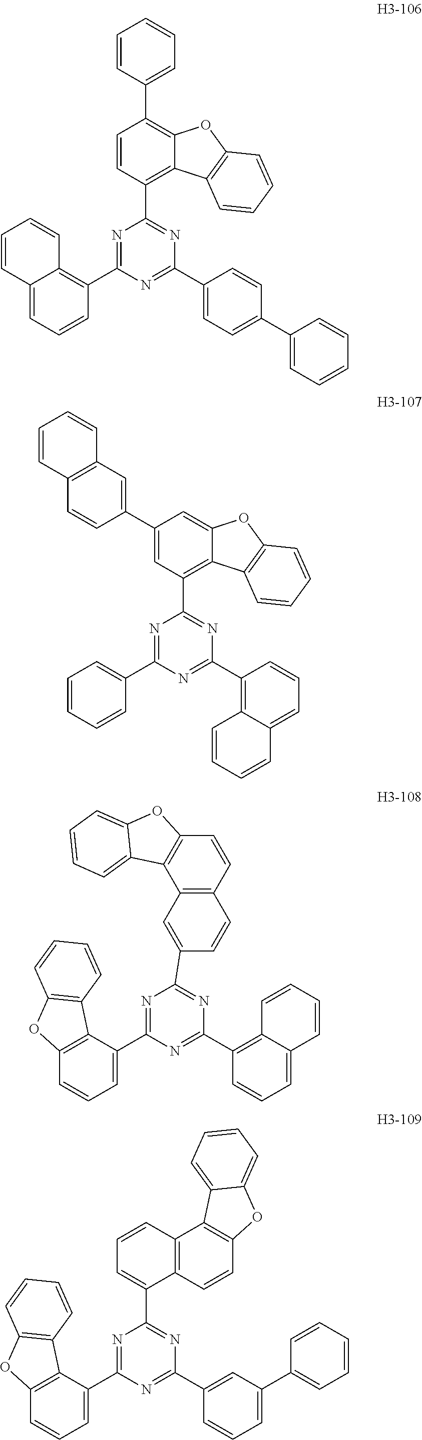 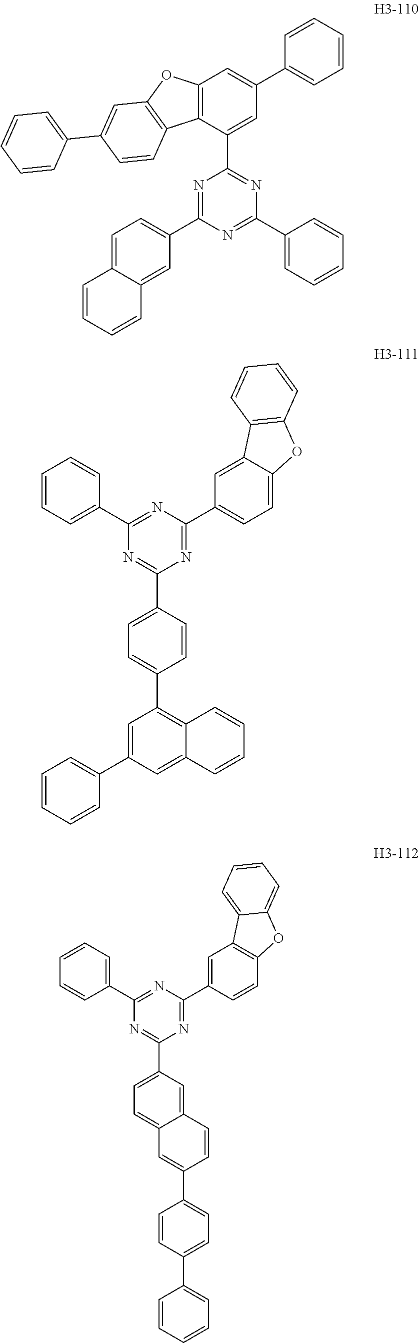 [SMILES: c1ccc(-c2ccc3c(c2)oc2cc(-c4ccccc4)cc(-c4nc(-c5ccccc5)nc(-c5ccc6ccccc6c5)n4)c23)cc1 ; c1ccc(-c2cc(-c3ccc(-c4nc(-c5ccccc5)nc(-c5ccc6oc7ccccc7c6c5)n4)cc3)c3ccccc3c2)cc1 ; c1ccc(-c2ccc(-c3ccc4cc(-c5nc(-c6ccccc6)nc(-c6ccc7oc8ccccc8c7c6)n5)ccc4c3)cc2)cc1] 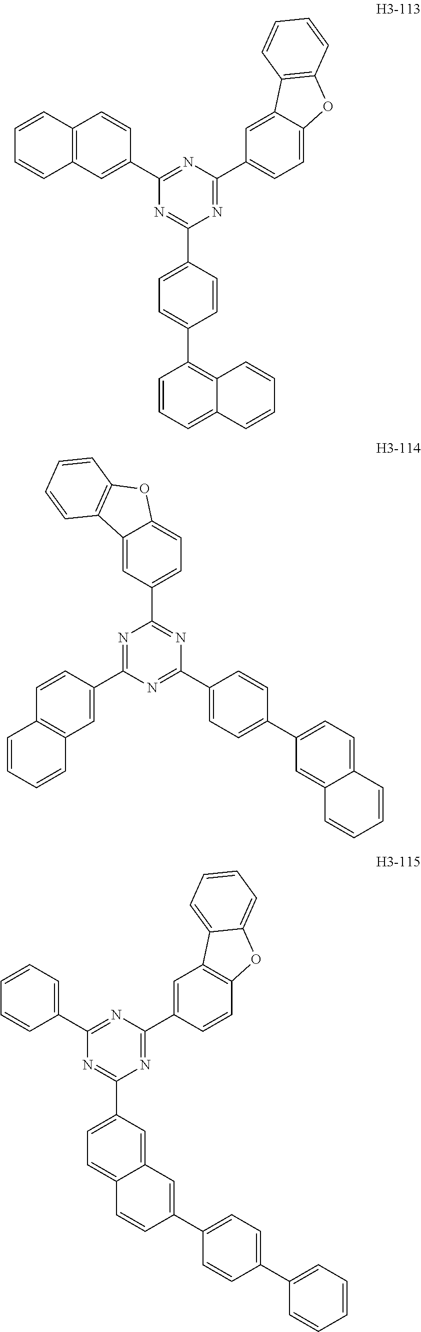 [SMILES: c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1 ; c1ccc(-c2ccc(-c3ccc4ccc(-c5nc(-c6ccccc6)nc(-c6ccc7oc8ccccc8c7c6)n5)cc4c3)cc2)cc1] 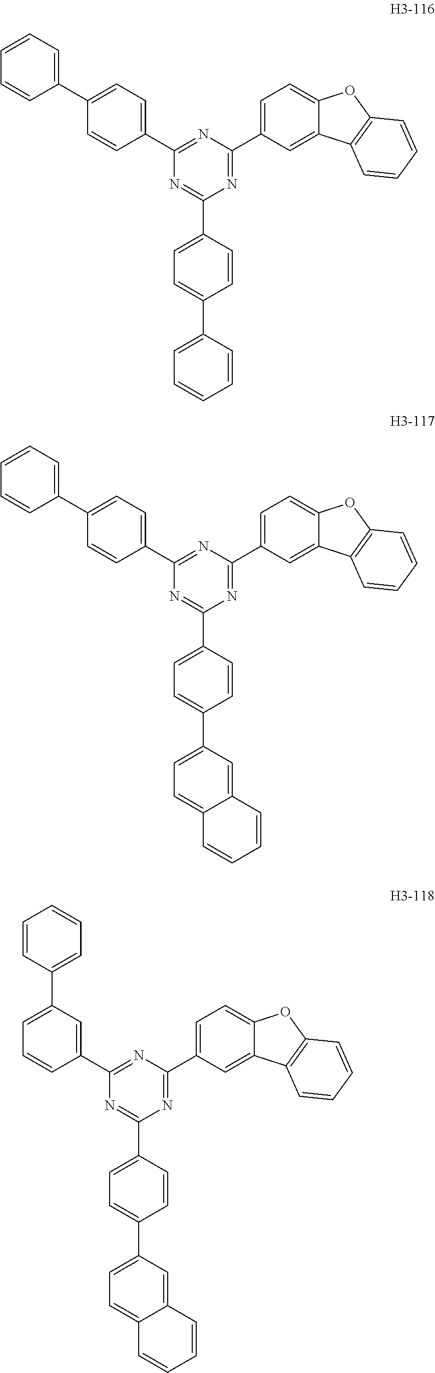 [SMILES: c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1 ; c1ccc(-c2cccc(-c3nc(-c4ccc(-c5ccc6ccccc6c5)cc4)nc(-c4ccc5oc6ccccc6c5c4)n3)c2)cc1] 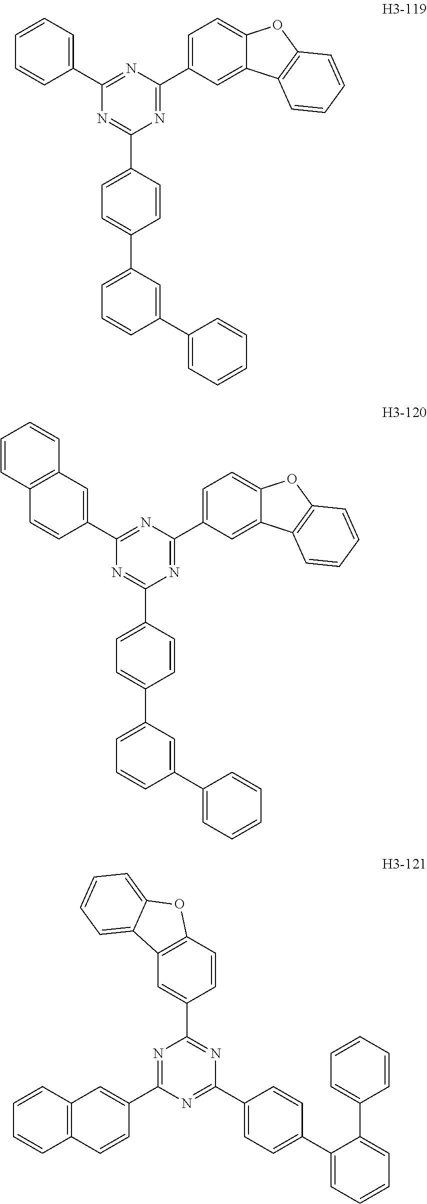 [SMILES: c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1 ; c1ccc(-c2ccccc2-c2ccc(-c3nc(-c4ccc5ccccc5c4)nc(-c4ccc5oc6ccccc6c5c4)n3)cc2)cc1] 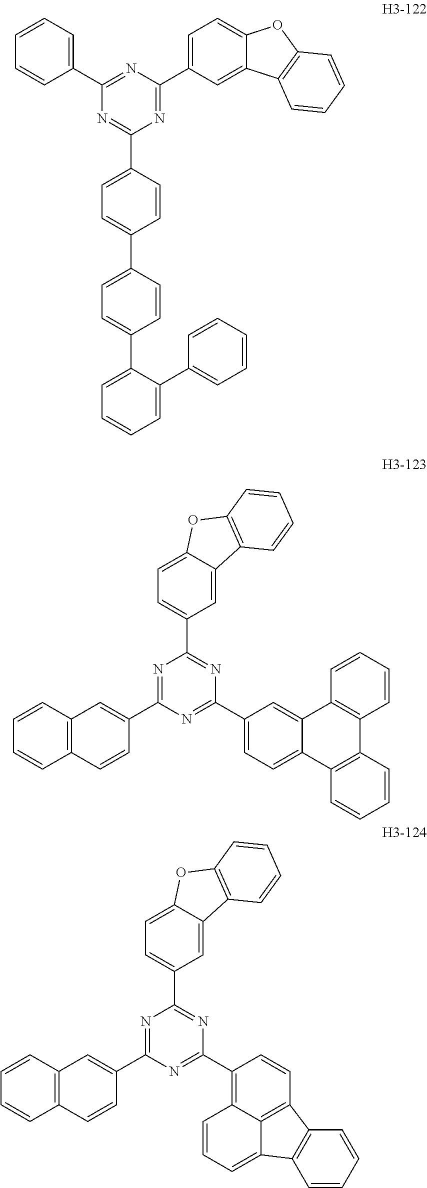 [SMILES: c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6oc7ccccc7c6c5)n4)ccc-2c13] 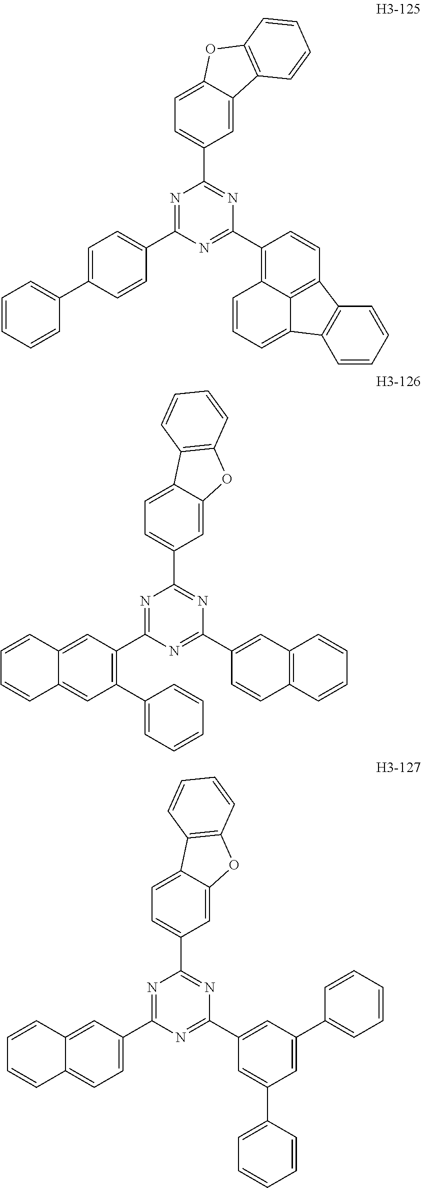 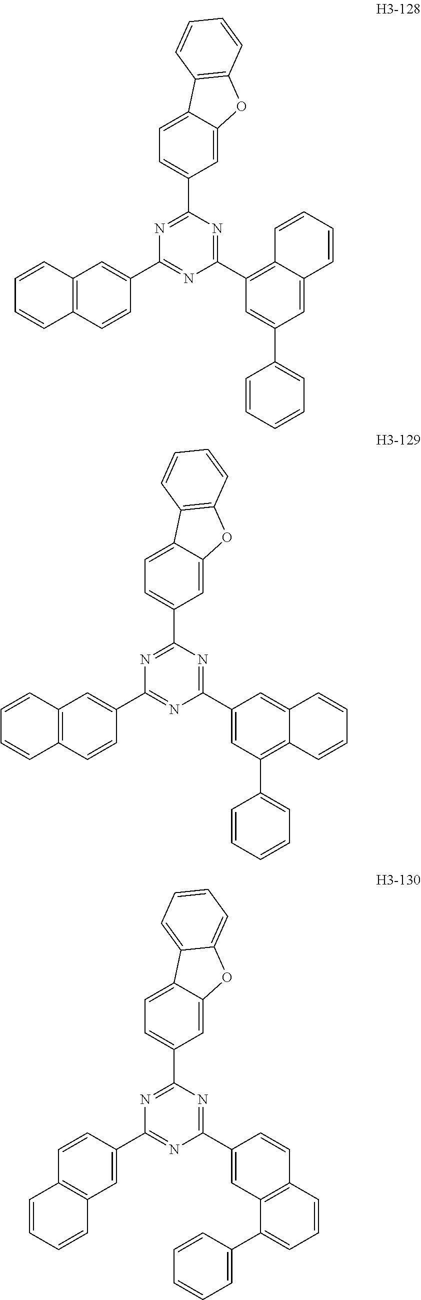 [SMILES: c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1 ; c1ccc(-c2cccc3ccc(-c4nc(-c5ccc6ccccc6c5)nc(-c5ccc6c(c5)oc5ccccc56)n4)cc23)cc1] 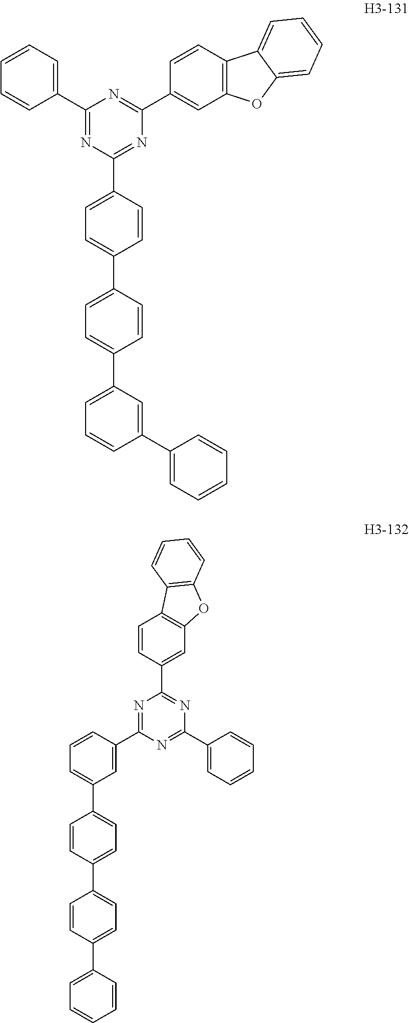 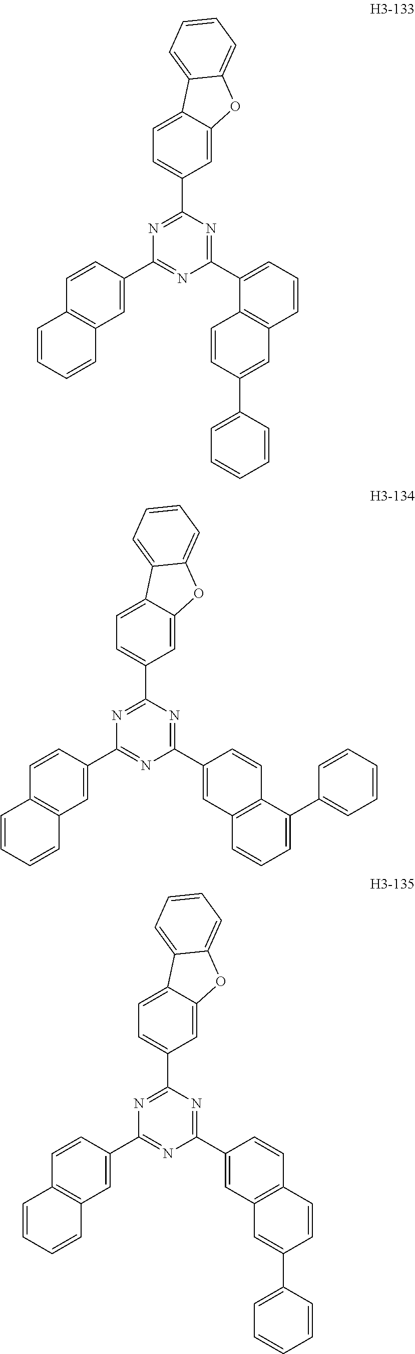 [SMILES: c1ccc(-c2ccc3c(-c4nc(-c5ccc6ccccc6c5)nc(-c5ccc6c(c5)oc5ccccc56)n4)cccc3c2)cc1 ; c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1] 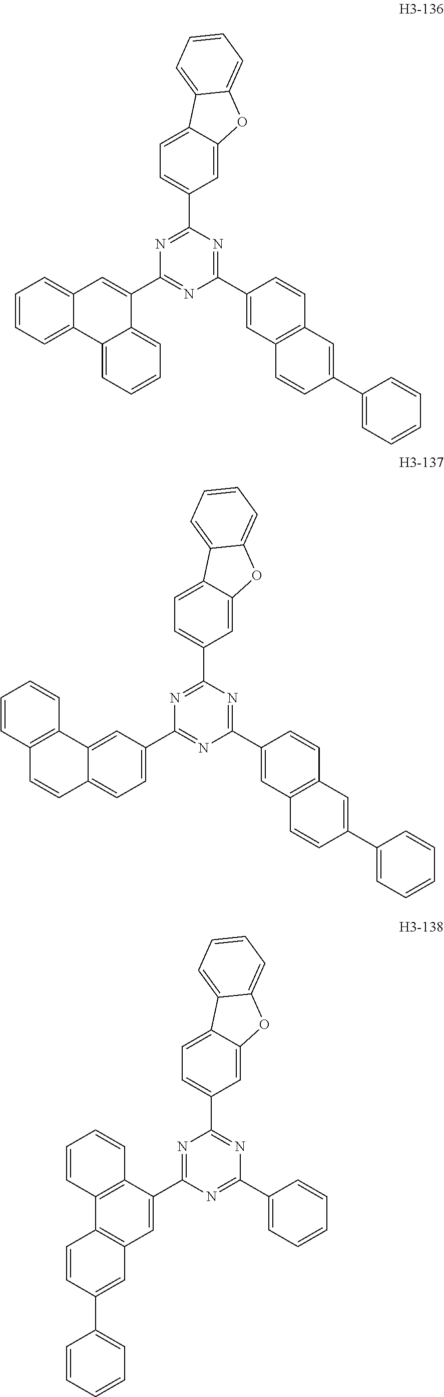 [SMILES: c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1] 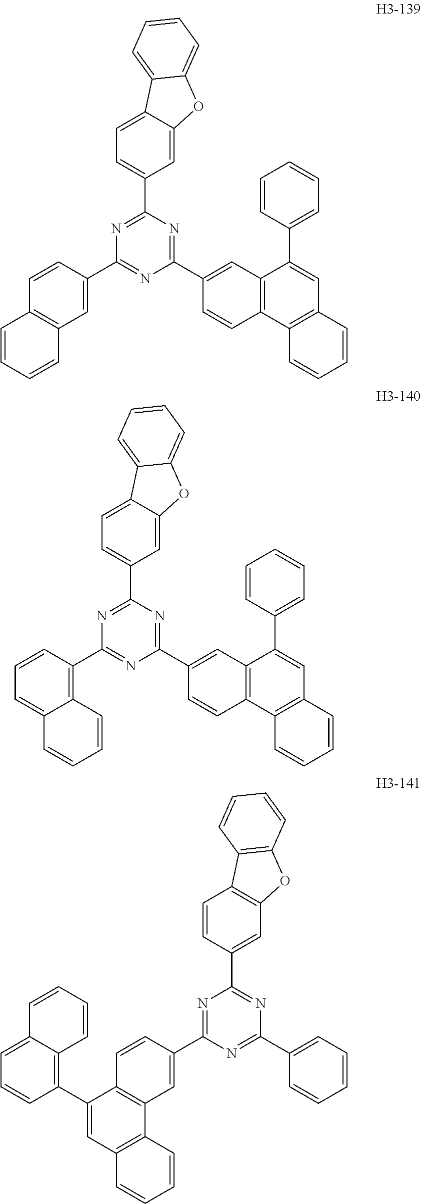 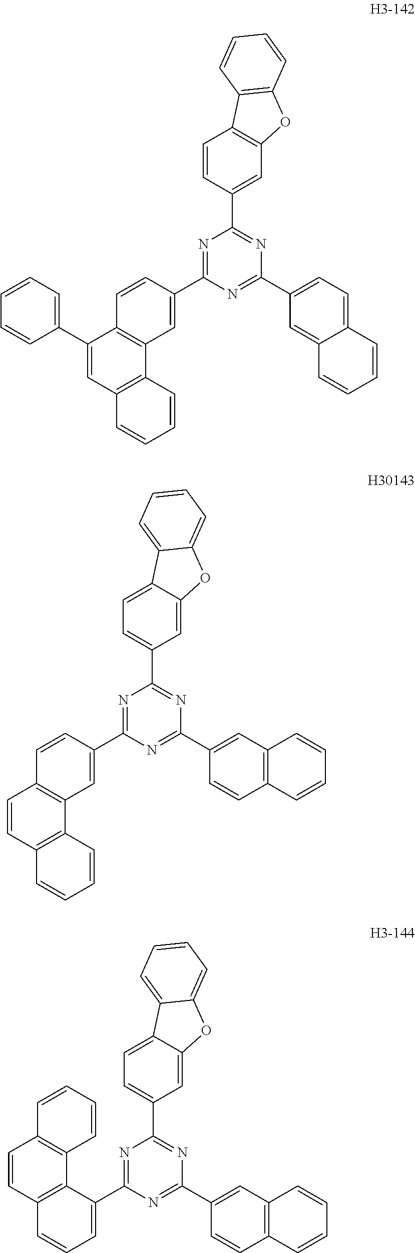 [SMILES: c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1] 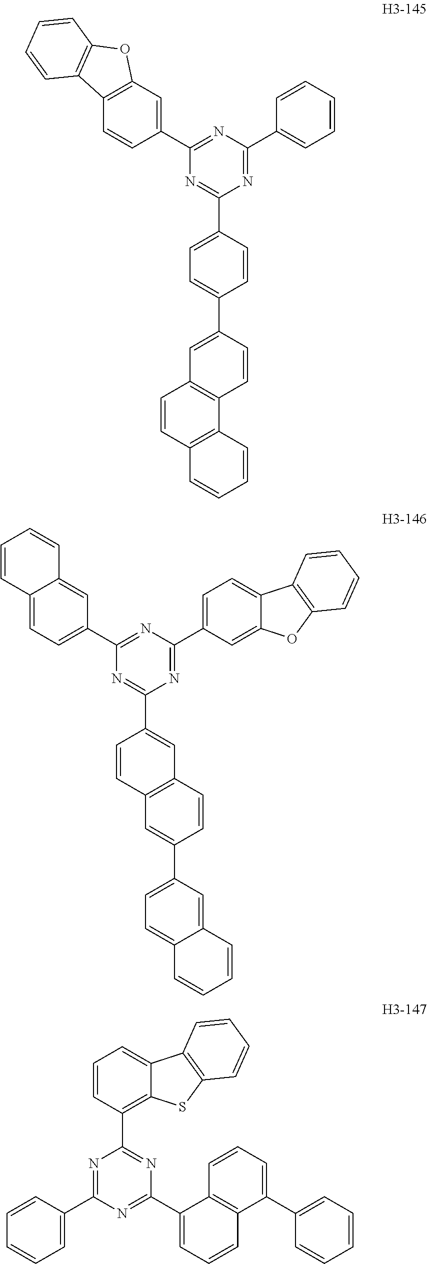 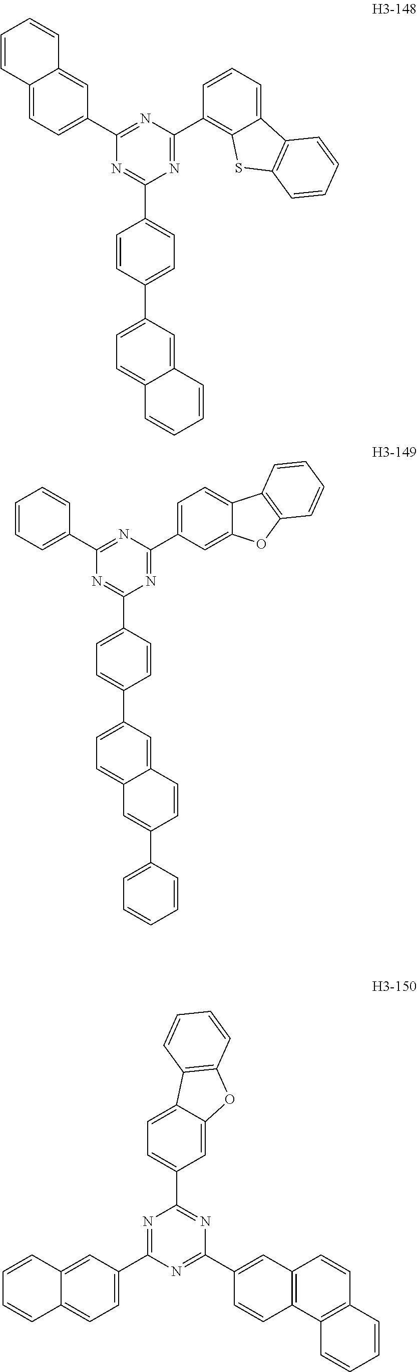 [SMILES: c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1 ; c1ccc2cc(-c3nc(-c4ccc5c(ccc6ccccc65)c4)nc(-c4ccc5c(c4)oc4ccccc45)n3)ccc2c1] 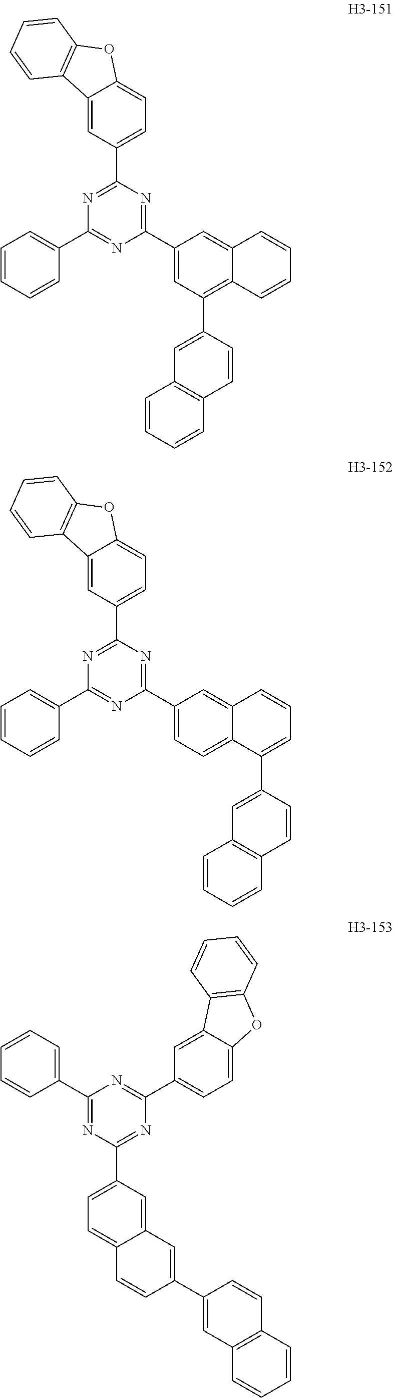 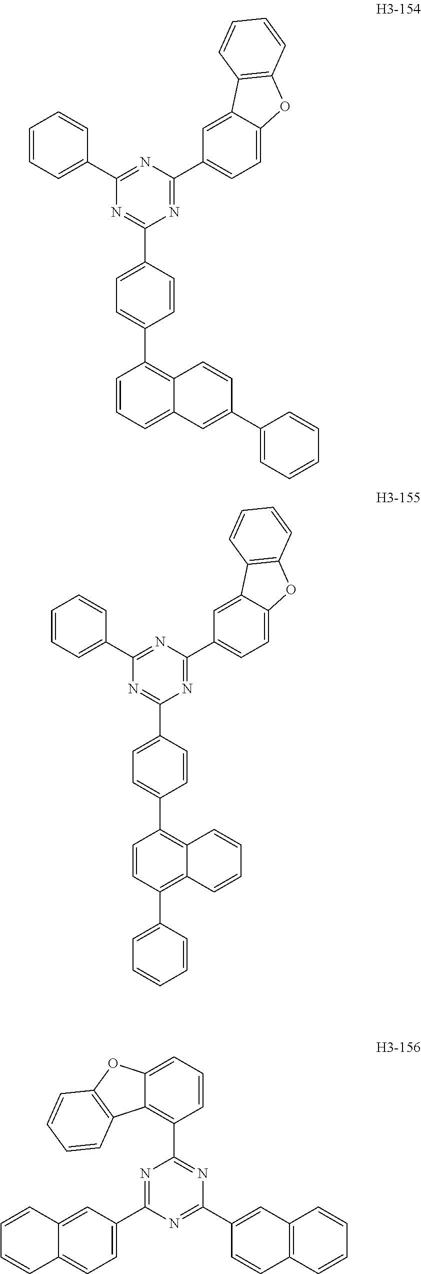 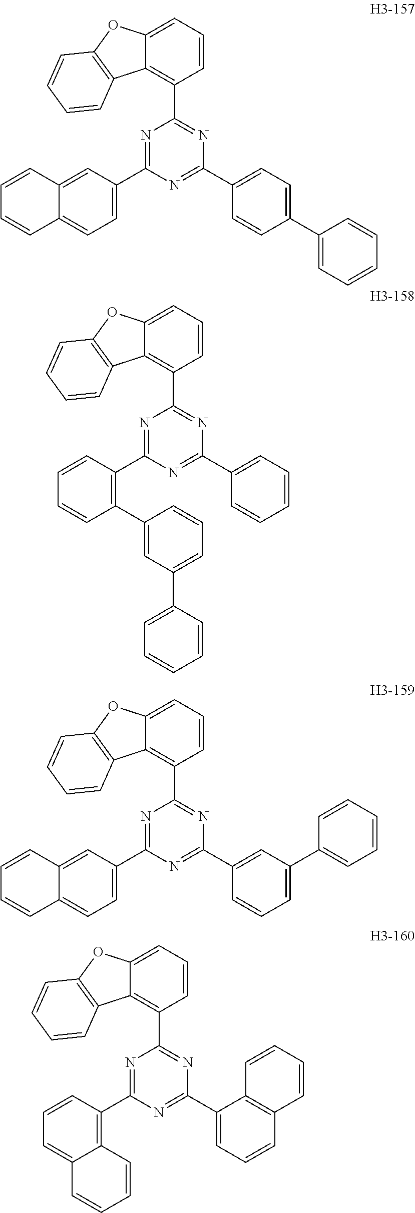 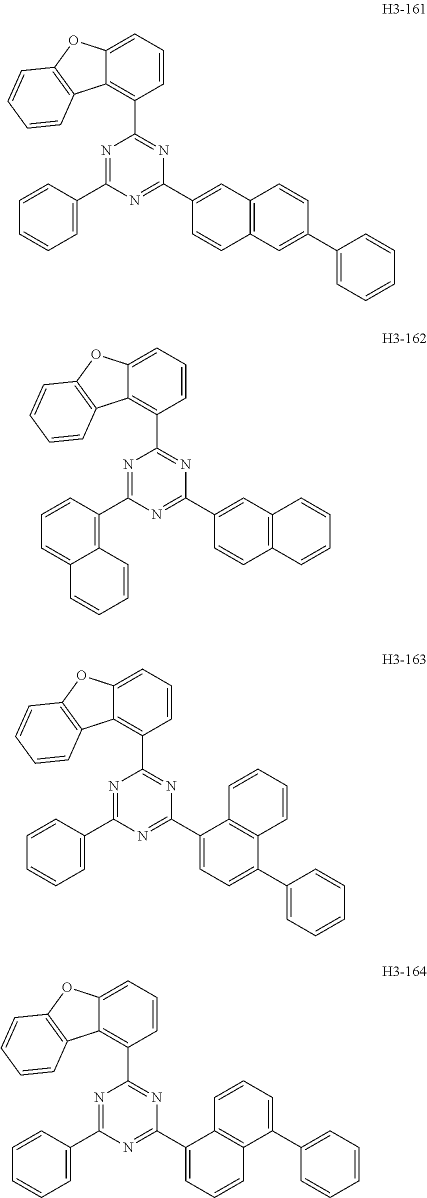 [SMILES: c1ccc(-c2ccc3cc(-c4nc(-c5ccccc5)nc(-c5cccc6oc7ccccc7c56)n4)ccc3c2)cc1 ; c1ccc2cc(-c3nc(-c4cccc5ccccc45)nc(-c4cccc5oc6ccccc6c45)n3)ccc2c1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1] 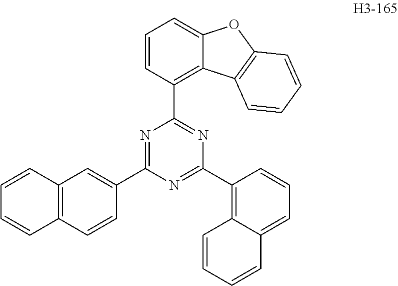 [SMILES: c1ccc2cc(-c3nc(-c4cccc5ccccc45)nc(-c4cccc5oc6ccccc6c45)n3)ccc2c1] 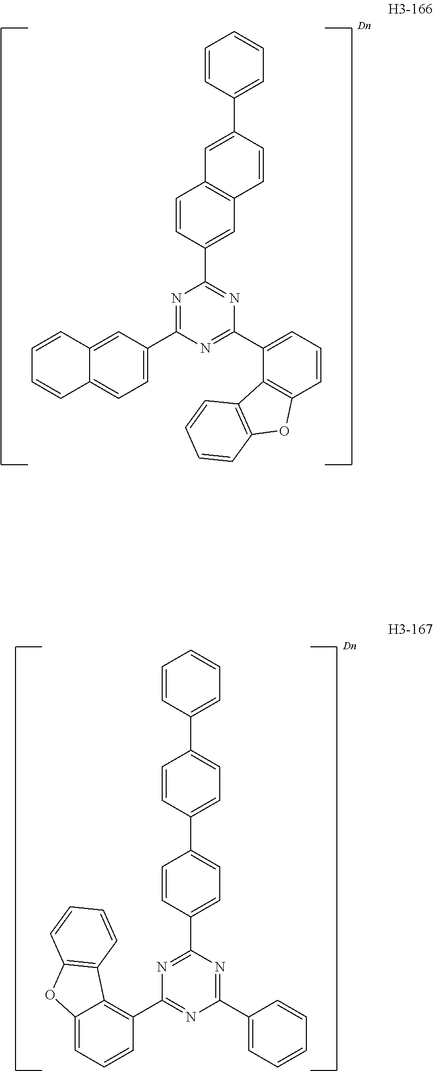 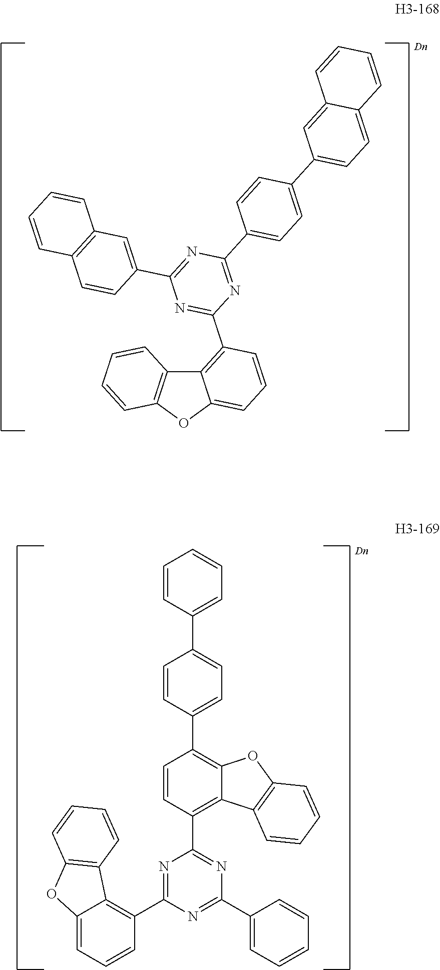 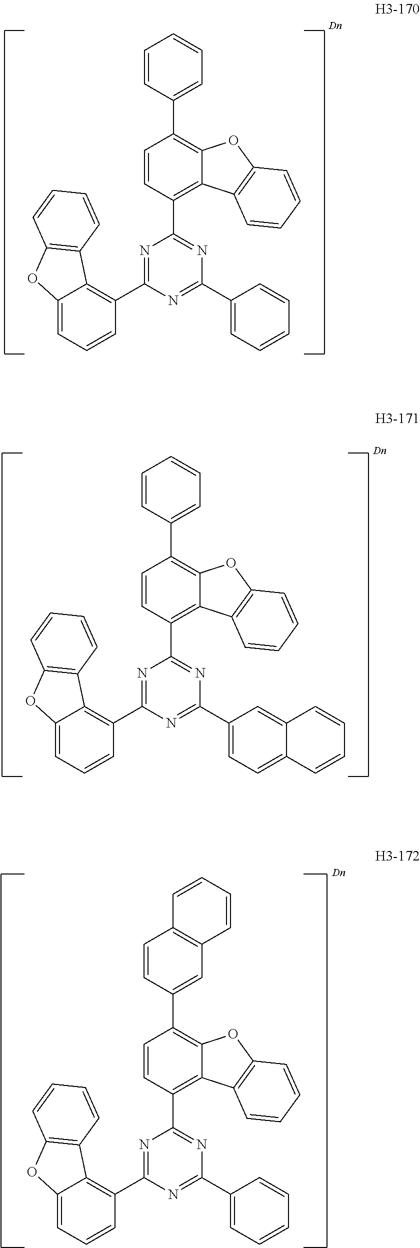 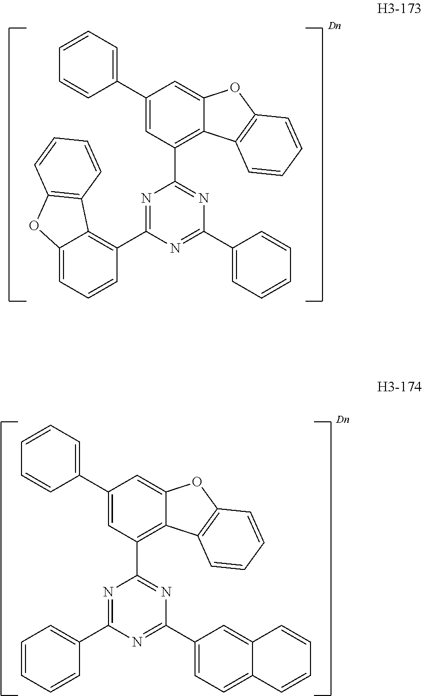 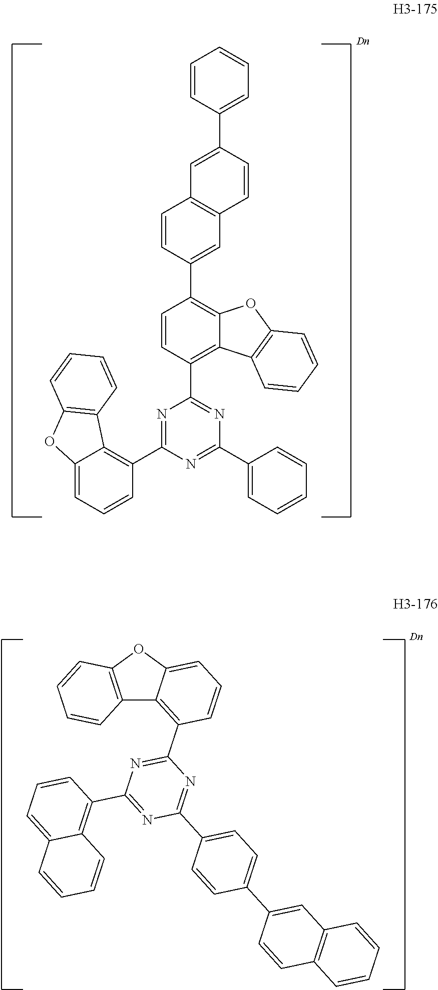 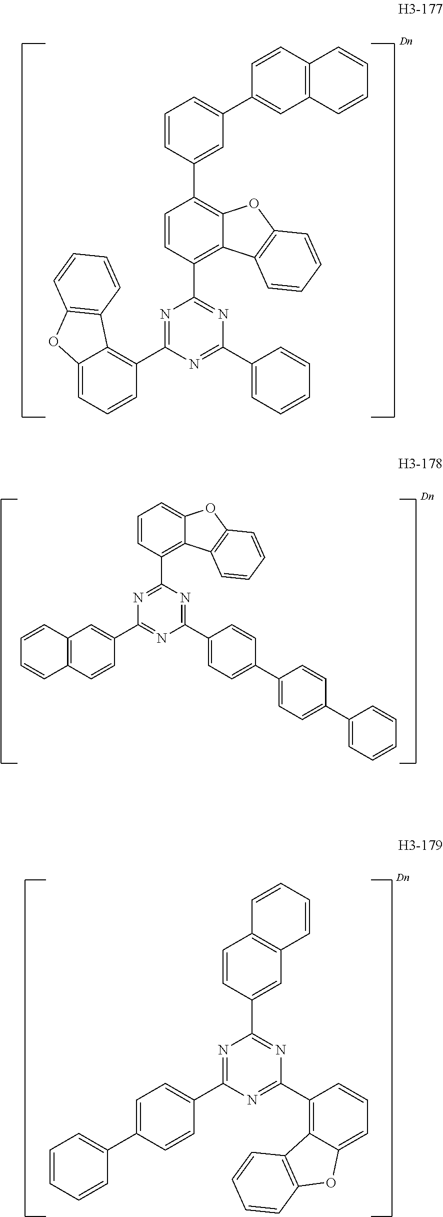 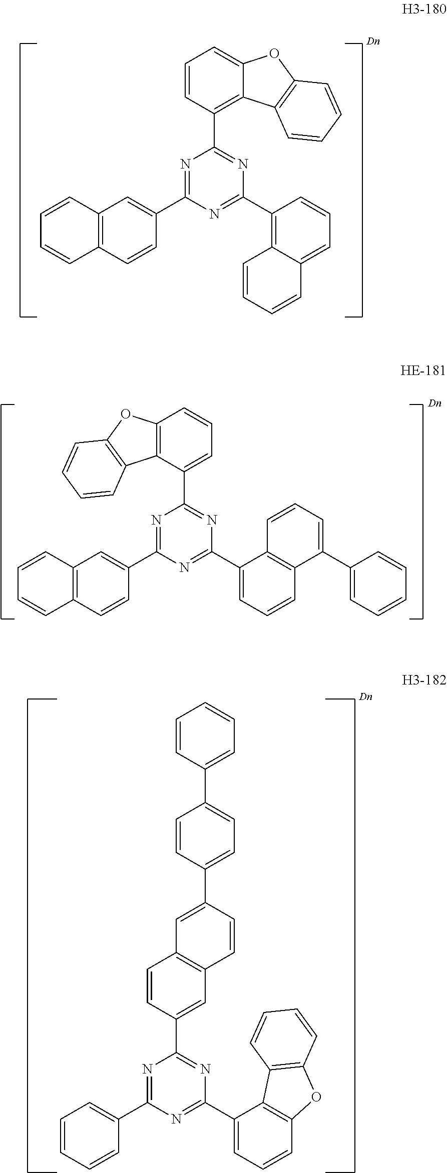 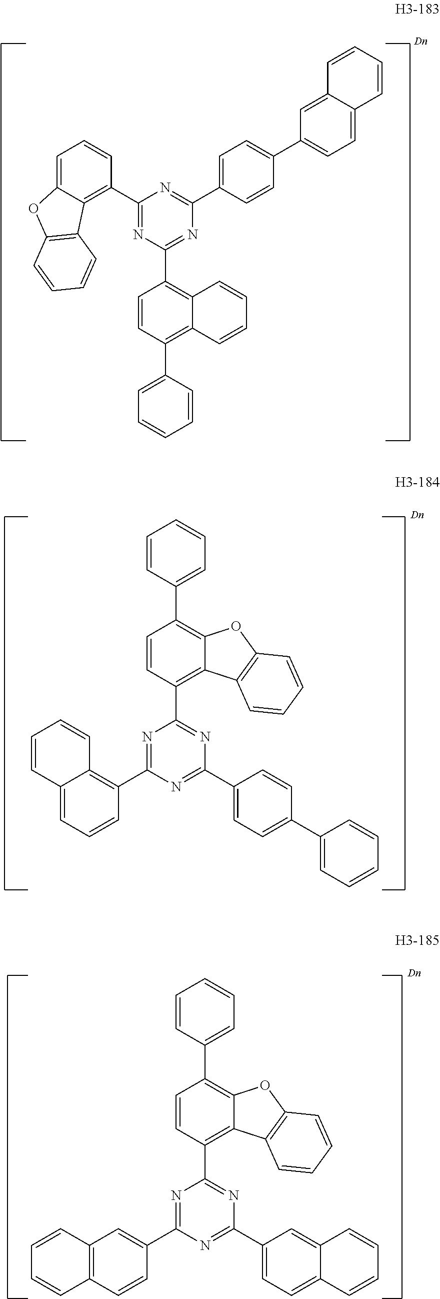 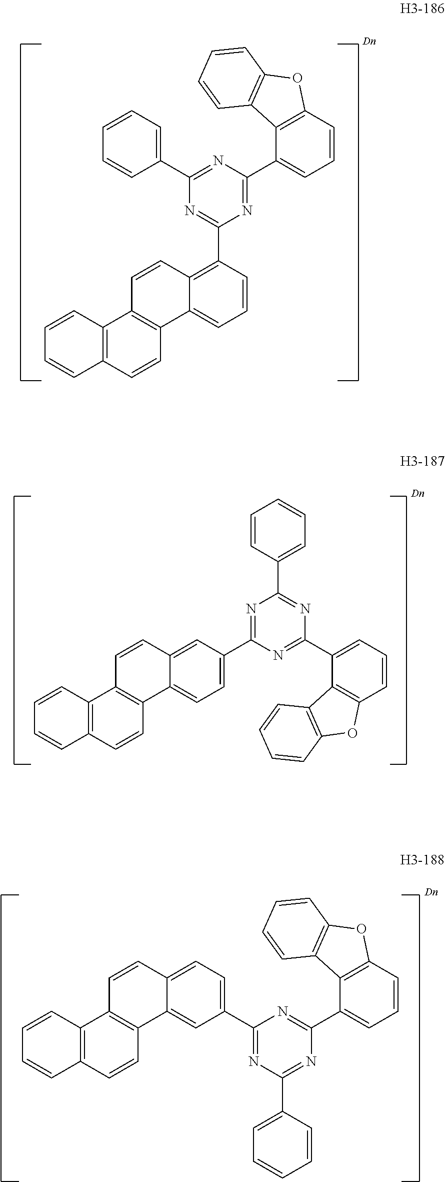 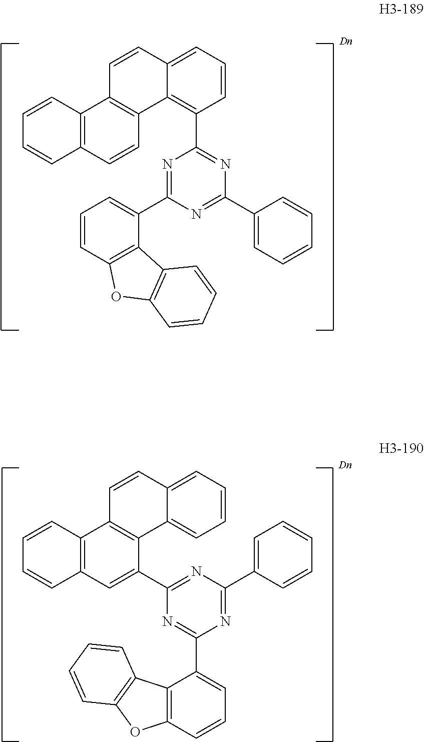 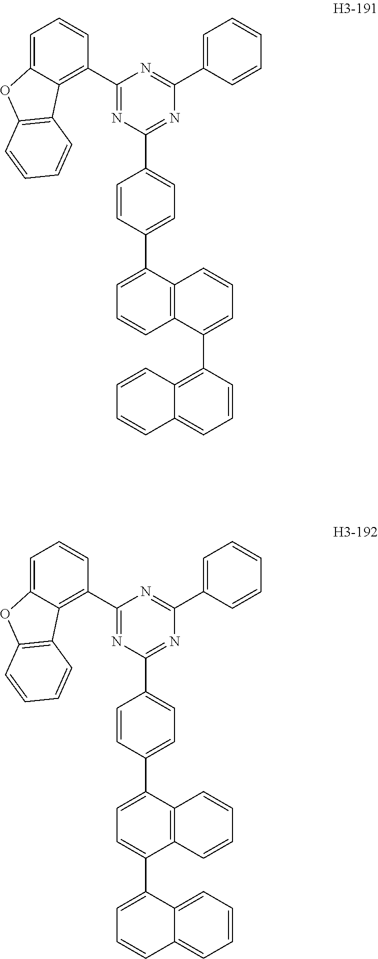 [SMILES: c1ccc(-c2nc(-c3ccc(-c4cccc5c(-c6cccc7ccccc67)cccc45)cc3)nc(-c3cccc4oc5ccccc5c34)n2)cc1 ; c1ccc(-c2nc(-c3ccc(-c4ccc(-c5cccc6ccccc56)c5ccccc45)cc3)nc(-c3cccc4oc5ccccc5c34)n2)cc1] 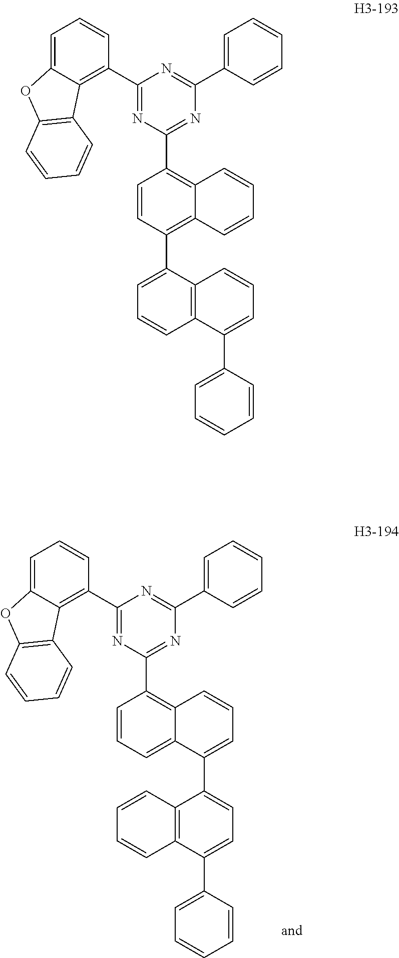 [SMILES: c1ccc(-c2nc(-c3ccc(-c4cccc5c(-c6ccccc6)cccc45)c4ccccc34)nc(-c3cccc4oc5ccccc5c34)n2)cc1 ; c1ccc(-c2nc(-c3cccc4c(-c5ccc(-c6ccccc6)c6ccccc56)cccc34)nc(-c3cccc4oc5ccccc5c34)n2)cc1] 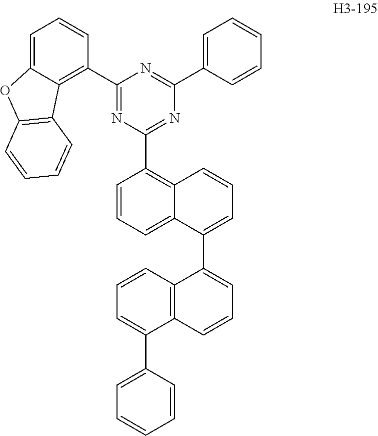 [SMILES: c1ccc(-c2nc(-c3cccc4c(-c5cccc6c(-c7ccccc7)cccc56)cccc34)nc(-c3cccc4oc5ccccc5c34)n2)cc1]
wherein in the compounds above, Dₙ means that n number of hydrogens are replaced with deuterium, and n represents an integer from 1 to the maximum number of hydrogens in the compound.

14. The plurality of host materials according to claim 1, wherein the compound represented by Formula 2 is selected from the following compounds: 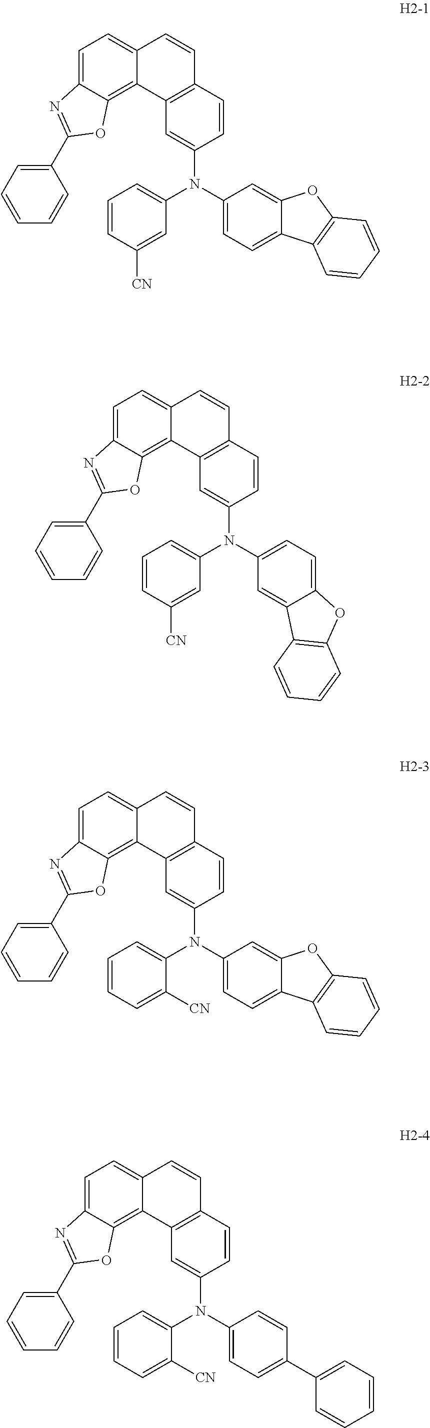 [SMILES: N#Cc1cccc(N(c2ccc3c(c2)oc2ccccc23)c2ccc3ccc4ccc5nc(-c6ccccc6)oc5c4c3c2)c1 ; N#Cc1cccc(N(c2ccc3oc4ccccc4c3c2)c2ccc3ccc4ccc5nc(-c6ccccc6)oc5c4c3c2)c1 ; N#Cc1ccccc1N(c1ccc2c(c1)oc1ccccc12)c1ccc2ccc3ccc4nc(-c5ccccc5)oc4c3c2c1 ; N#Cc1ccccc1N(c1ccc(-c2ccccc2)cc1)c1ccc2ccc3ccc4nc(-c5ccccc5)oc4c3c2c1] 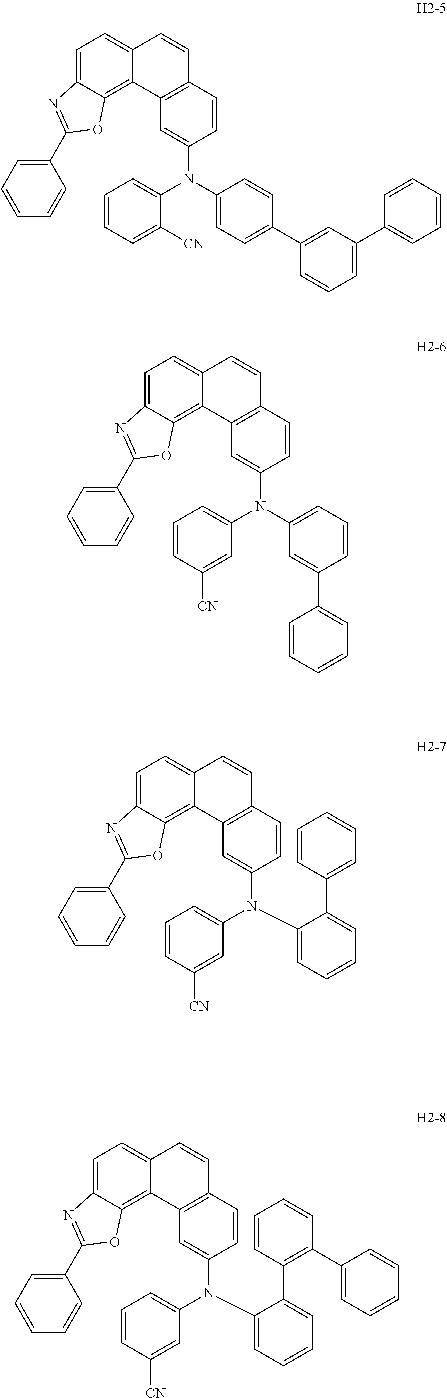 [SMILES: N#Cc1ccccc1N(c1ccc(-c2cccc(-c3ccccc3)c2)cc1)c1ccc2ccc3ccc4nc(-c5ccccc5)oc4c3c2c1 ; N#Cc1cccc(N(c2cccc(-c3ccccc3)c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2ccccc2-c2ccccc2)c1 ; N#Cc1cccc(N(c2ccc3ccc4ccc5nc(-c6ccccc6)oc5c4c3c2)c2ccccc2-c2ccccc2-c2ccccc2)c1] 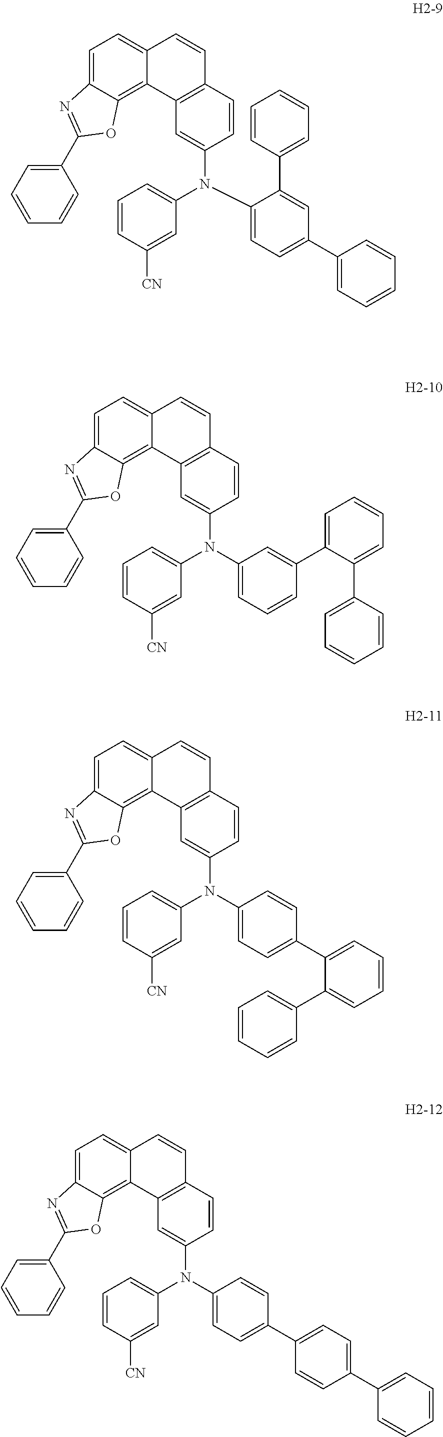 [SMILES: N#Cc1cccc(N(c2ccc3ccc4ccc5nc(-c6ccccc6)oc5c4c3c2)c2ccc(-c3ccccc3)cc2-c2ccccc2)c1 ; N#Cc1cccc(N(c2cccc(-c3ccccc3-c3ccccc3)c2)c2ccc3ccc4ccc5nc(-c6ccccc6)oc5c4c3c2)c1 ; N#Cc1cccc(N(c2ccc(-c3ccccc3-c3ccccc3)cc2)c2ccc3ccc4ccc5nc(-c6ccccc6)oc5c4c3c2)c1 ; N#Cc1cccc(N(c2ccc(-c3ccc(-c4ccccc4)cc3)cc2)c2ccc3ccc4ccc5nc(-c6ccccc6)oc5c4c3c2)c1] 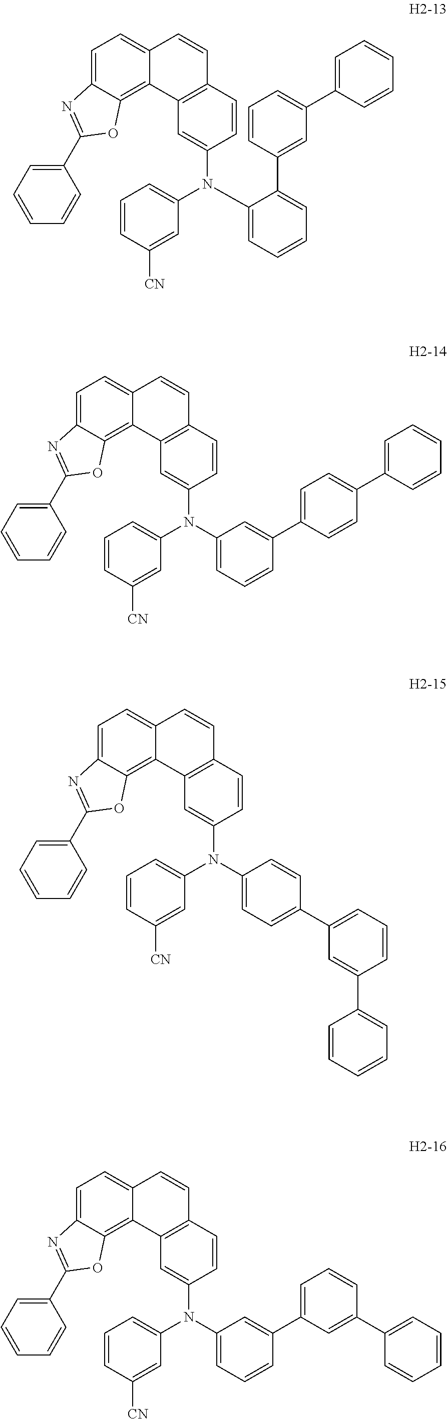 [SMILES: N#Cc1cccc(N(c2ccc3ccc4ccc5nc(-c6ccccc6)oc5c4c3c2)c2ccccc2-c2cccc(-c3ccccc3)c2)c1 ; N#Cc1cccc(N(c2cccc(-c3ccc(-c4ccccc4)cc3)c2)c2ccc3ccc4ccc5nc(-c6ccccc6)oc5c4c3c2)c1 ; N#Cc1cccc(N(c2ccc(-c3cccc(-c4ccccc4)c3)cc2)c2ccc3ccc4ccc5nc(-c6ccccc6)oc5c4c3c2)c1 ; N#Cc1cccc(N(c2cccc(-c3cccc(-c4ccccc4)c3)c2)c2ccc3ccc4ccc5nc(-c6ccccc6)oc5c4c3c2)c1] 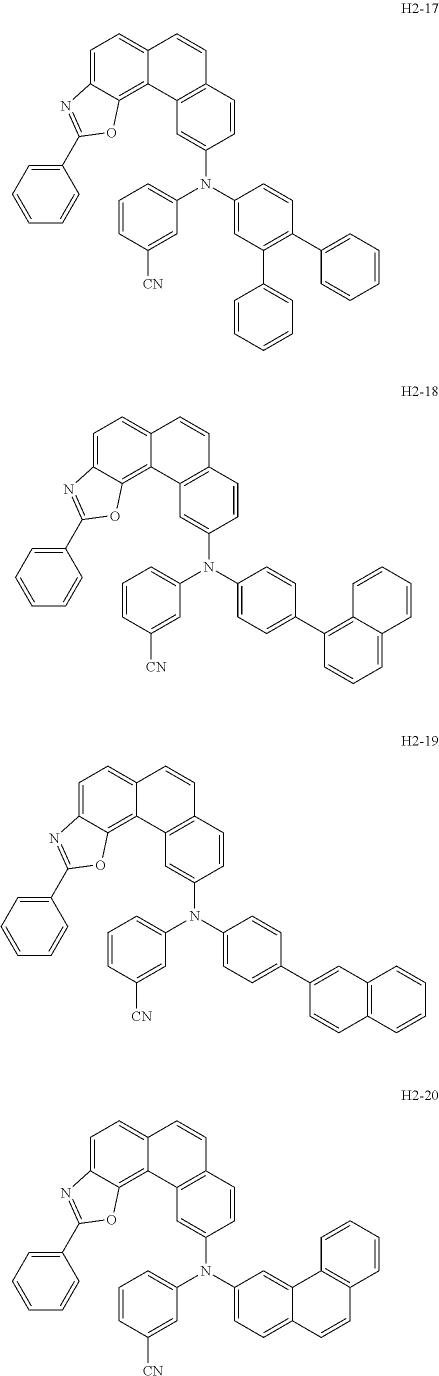 [SMILES: N#Cc1cccc(N(c2ccc(-c3ccccc3)c(-c3ccccc3)c2)c2ccc3ccc4ccc5nc(-c6ccccc6)oc5c4c3c2)c1 ; N#Cc1cccc(N(c2ccc(-c3cccc4ccccc34)cc2)c2ccc3ccc4ccc5nc(-c6ccccc6)oc5c4c3c2)c1 ; N#Cc1cccc(N(c2ccc(-c3ccc4ccccc4c3)cc2)c2ccc3ccc4ccc5nc(-c6ccccc6)oc5c4c3c2)c1 ; N#Cc1cccc(N(c2ccc3ccc4ccccc4c3c2)c2ccc3ccc4ccc5nc(-c6ccccc6)oc5c4c3c2)c1] 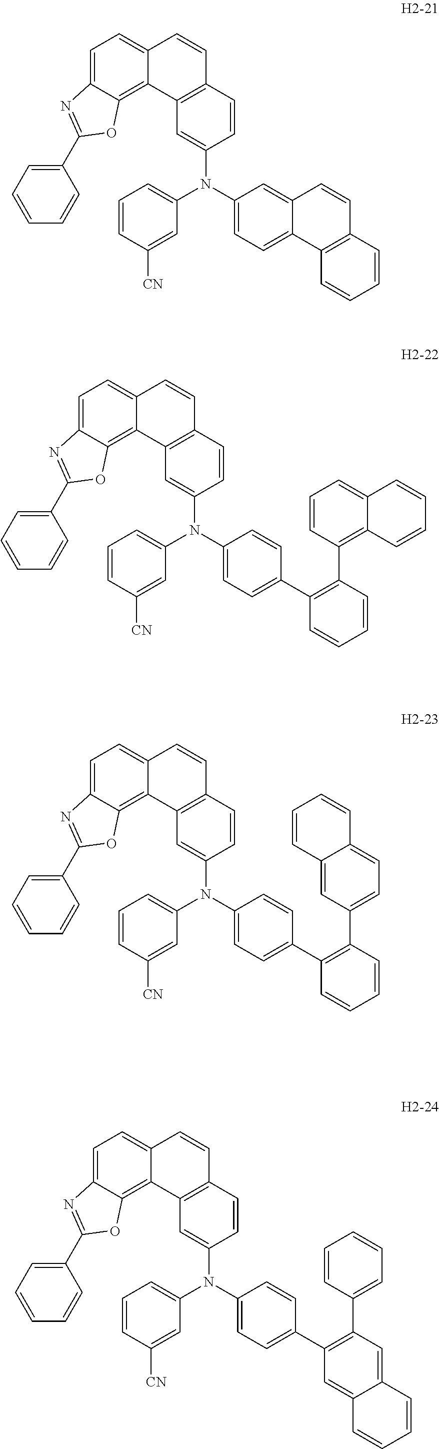 [SMILES: N#Cc1cccc(N(c2ccc3c(ccc4ccccc43)c2)c2ccc3ccc4ccc5nc(-c6ccccc6)oc5c4c3c2)c1 ; N#Cc1cccc(N(c2ccc(-c3ccccc3-c3cccc4ccccc34)cc2)c2ccc3ccc4ccc5nc(-c6ccccc6)oc5c4c3c2)c1 ; N#Cc1cccc(N(c2ccc(-c3ccccc3-c3ccc4ccccc4c3)cc2)c2ccc3ccc4ccc5nc(-c6ccccc6)oc5c4c3c2)c1 ; N#Cc1cccc(N(c2ccc(-c3cc4ccccc4cc3-c3ccccc3)cc2)c2ccc3ccc4ccc5nc(-c6ccccc6)oc5c4c3c2)c1] 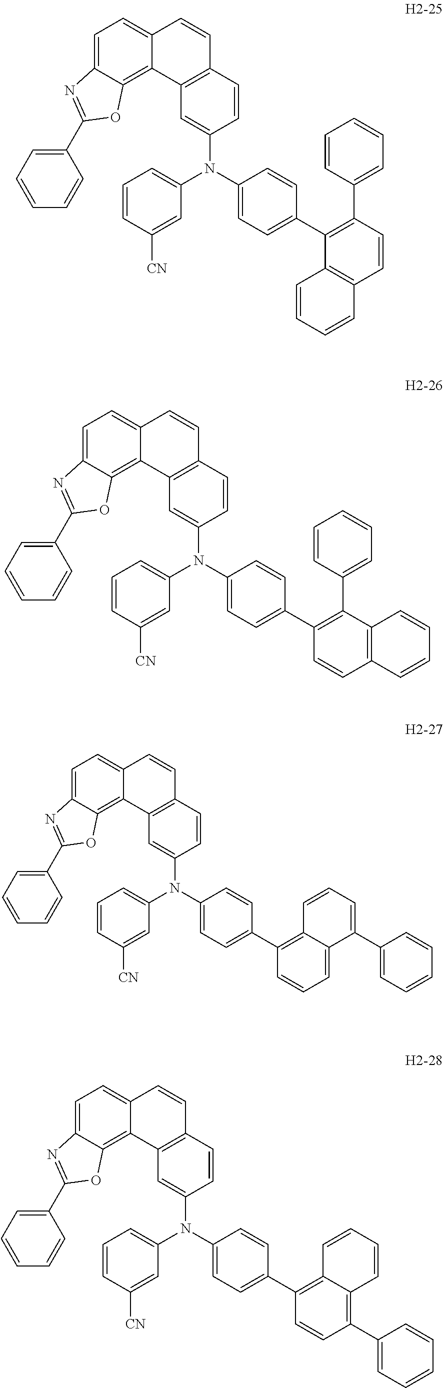 [SMILES: N#Cc1cccc(N(c2ccc(-c3c(-c4ccccc4)ccc4ccccc34)cc2)c2ccc3ccc4ccc5nc(-c6ccccc6)oc5c4c3c2)c1 ; N#Cc1cccc(N(c2ccc(-c3ccc4ccccc4c3-c3ccccc3)cc2)c2ccc3ccc4ccc5nc(-c6ccccc6)oc5c4c3c2)c1 ; N#Cc1cccc(N(c2ccc(-c3cccc4c(-c5ccccc5)cccc34)cc2)c2ccc3ccc4ccc5nc(-c6ccccc6)oc5c4c3c2)c1 ; N#Cc1cccc(N(c2ccc(-c3ccc(-c4ccccc4)c4ccccc34)cc2)c2ccc3ccc4ccc5nc(-c6ccccc6)oc5c4c3c2)c1] 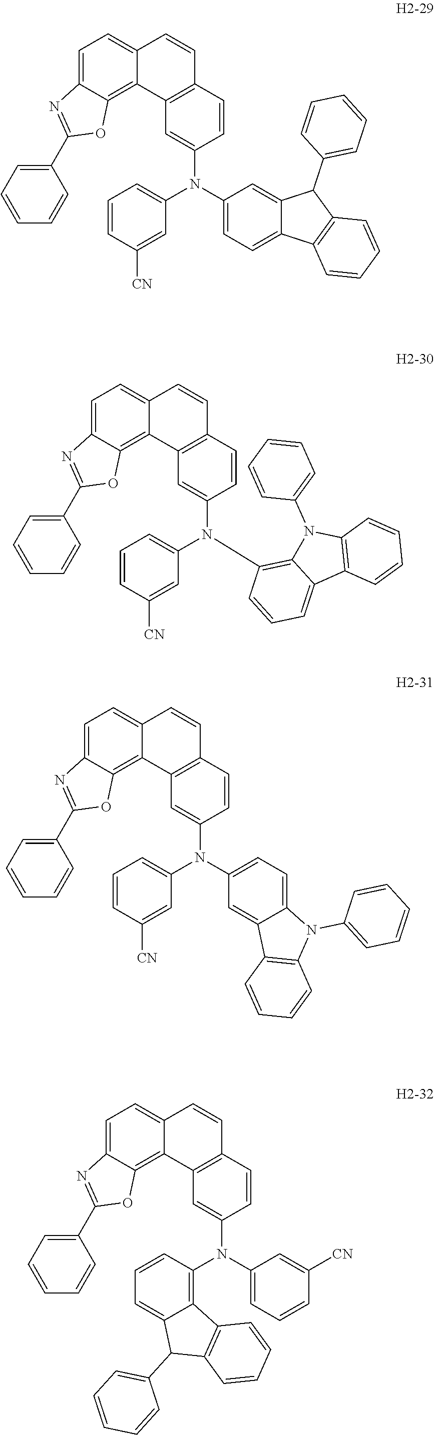 [SMILES: N#Cc1cccc(N(c2ccc3c(c2)C(c2ccccc2)c2ccccc2-3)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c4ccccc4n(-c4ccccc4)c23)c1 ; N#Cc1cccc(N(c2ccc3ccc4ccc5nc(-c6ccccc6)oc5c4c3c2)c2ccc3c(c2)c2ccccc2n3-c2ccccc2)c1 ; N#Cc1cccc(N(c2ccc3ccc4ccc5nc(-c6ccccc6)oc5c4c3c2)c2cccc3c2-c2ccccc2C3c2ccccc2)c1] 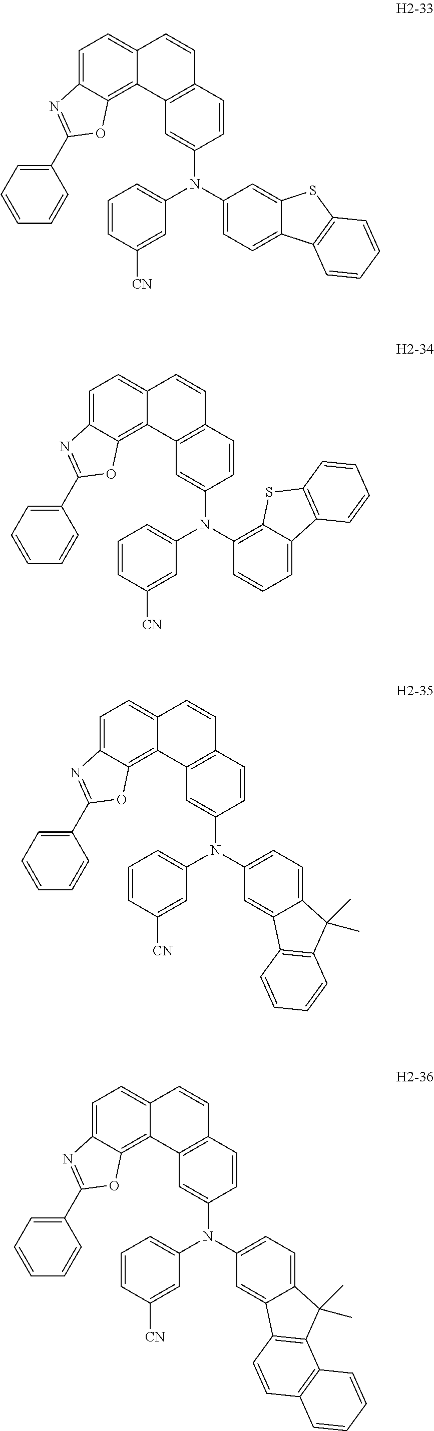 [SMILES: N#Cc1cccc(N(c2ccc3c(c2)sc2ccccc23)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c2sc2ccccc23)c1 ; CC1(C)c2ccccc2-c2cc(N(c3cccc(C#N)c3)c3ccc4ccc5ccc6nc(-c7ccccc7)oc6c5c4c3)ccc21 ; CC1(C)c2ccc(N(c3cccc(C#N)c3)c3ccc4ccc5ccc6nc(-c7ccccc7)oc6c5c4c3)cc2-c2ccc3ccccc3c21] 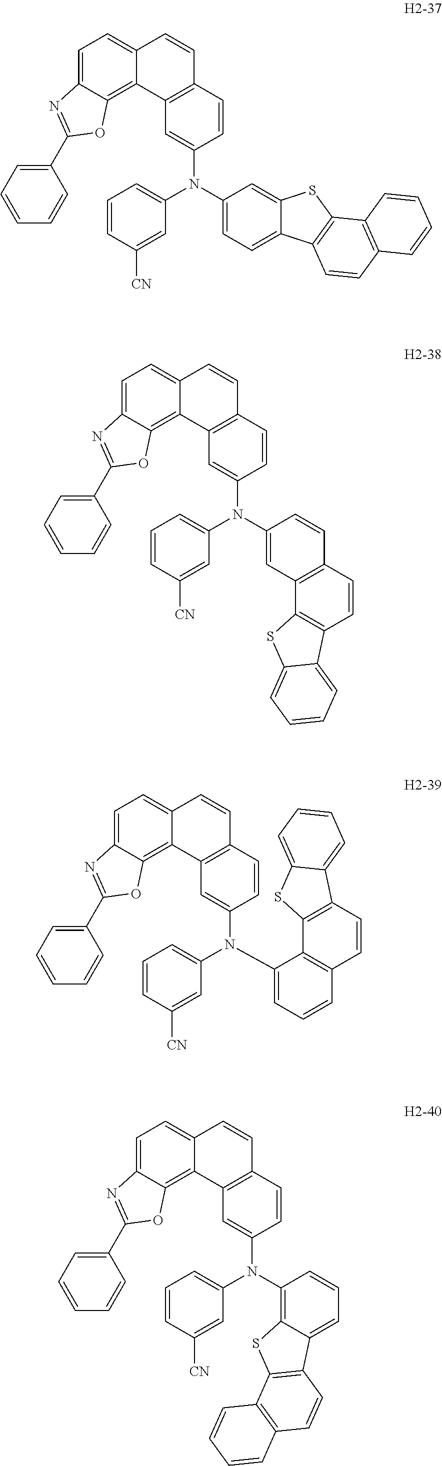 [SMILES: N#Cc1cccc(N(c2ccc3c(c2)sc2c4ccccc4ccc32)c2ccc3ccc4ccc5nc(-c6ccccc6)oc5c4c3c2)c1 ; N#Cc1cccc(N(c2ccc3ccc4c5ccccc5sc4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3ccc4c5ccccc5sc4c23)c1 ; N#Cc1cccc(N(c2ccc3ccc4ccc5nc(-c6ccccc6)oc5c4c3c2)c2cccc3c2sc2c4ccccc4ccc32)c1] 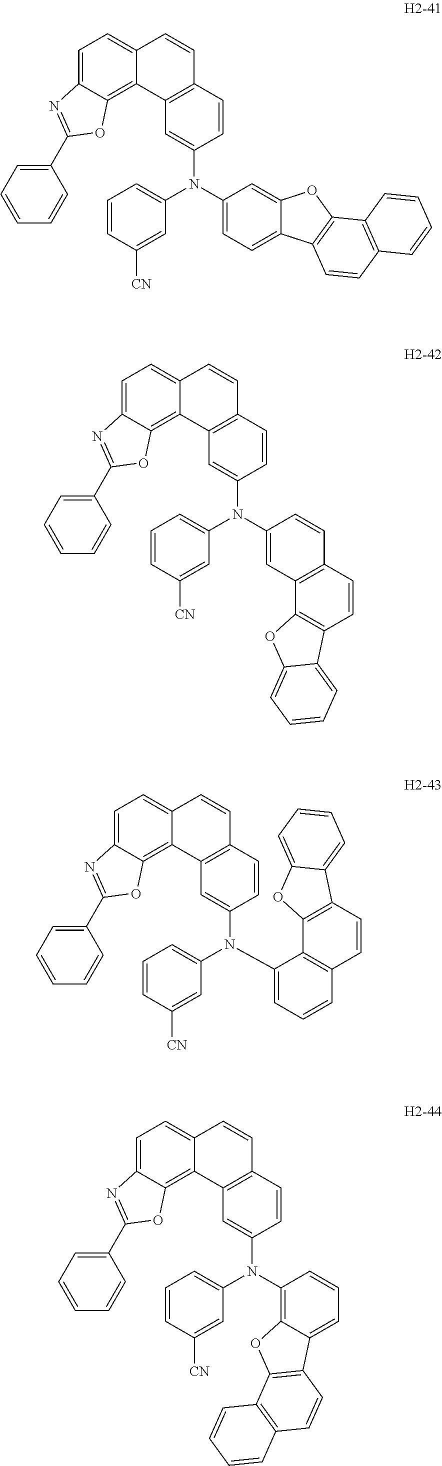 [SMILES: N#Cc1cccc(N(c2ccc3c(c2)oc2c4ccccc4ccc32)c2ccc3ccc4ccc5nc(-c6ccccc6)oc5c4c3c2)c1 ; N#Cc1cccc(N(c2ccc3ccc4c5ccccc5oc4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3ccc4c5ccccc5oc4c23)c1 ; N#Cc1cccc(N(c2ccc3ccc4ccc5nc(-c6ccccc6)oc5c4c3c2)c2cccc3c2oc2c4ccccc4ccc32)c1] 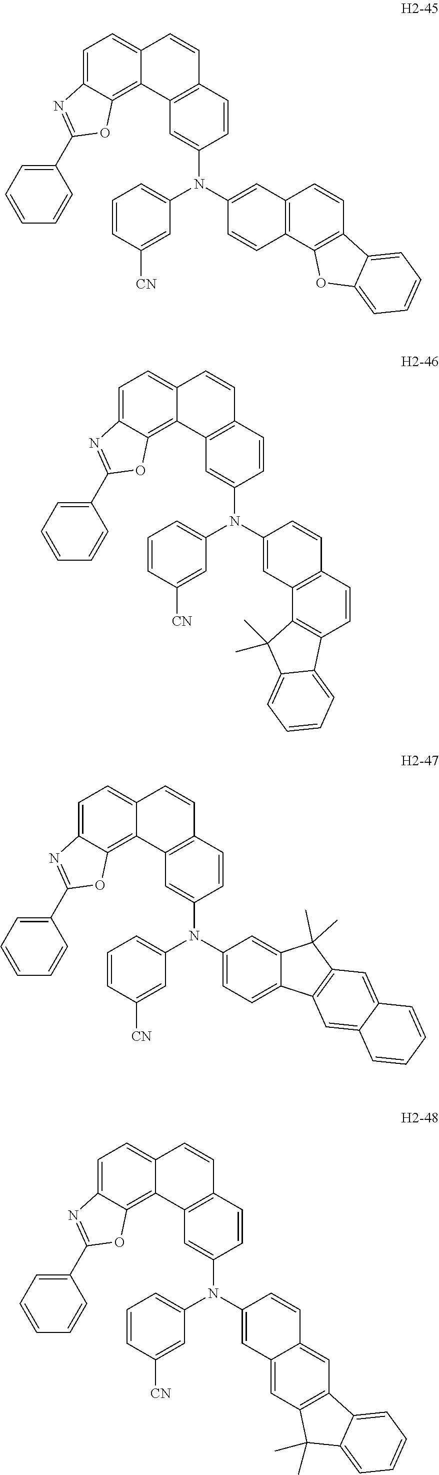 [SMILES: N#Cc1cccc(N(c2ccc3c(ccc4c5ccccc5oc34)c2)c2ccc3ccc4ccc5nc(-c6ccccc6)oc5c4c3c2)c1 ; CC1(C)c2ccccc2-c2ccc3ccc(N(c4cccc(C#N)c4)c4ccc5ccc6ccc7nc(-c8ccccc8)oc7c6c5c4)cc3c21 ; CC1(C)c2cc(N(c3cccc(C#N)c3)c3ccc4ccc5ccc6nc(-c7ccccc7)oc6c5c4c3)ccc2-c2cc3ccccc3cc21 ; CC1(C)c2ccccc2-c2cc3ccc(N(c4cccc(C#N)c4)c4ccc5ccc6ccc7nc(-c8ccccc8)oc7c6c5c4)cc3cc21] 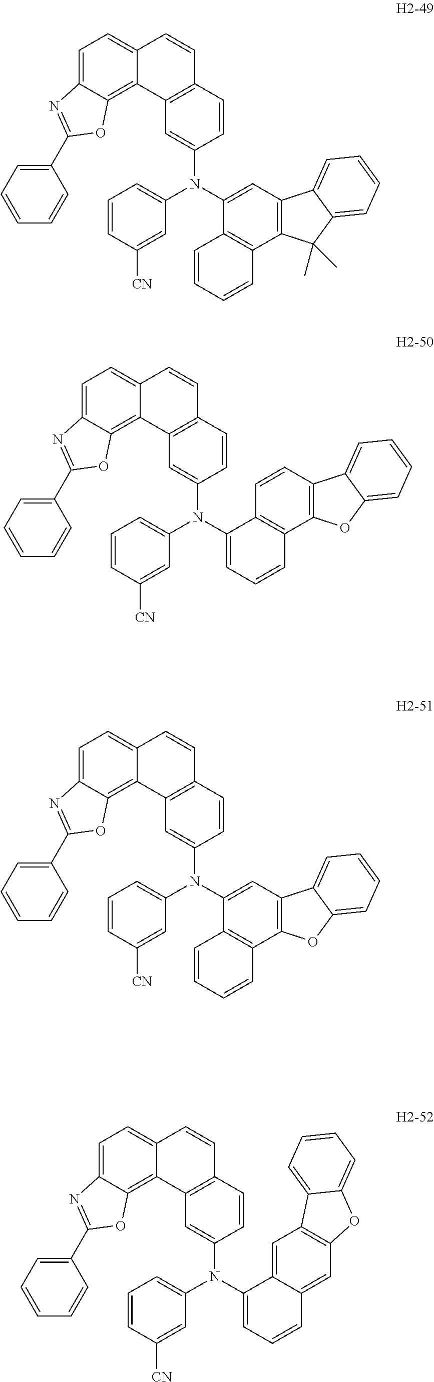 [SMILES: CC1(C)c2ccccc2-c2cc(N(c3cccc(C#N)c3)c3ccc4ccc5ccc6nc(-c7ccccc7)oc6c5c4c3)c3ccccc3c21 ; N#Cc1cccc(N(c2ccc3ccc4ccc5nc(-c6ccccc6)oc5c4c3c2)c2cccc3c2ccc2c4ccccc4oc32)c1 ; N#Cc1cccc(N(c2ccc3ccc4ccc5nc(-c6ccccc6)oc5c4c3c2)c2cc3c4ccccc4oc3c3ccccc23)c1 ; N#Cc1cccc(N(c2ccc3ccc4ccc5nc(-c6ccccc6)oc5c4c3c2)c2cccc3cc4oc5ccccc5c4cc23)c1] 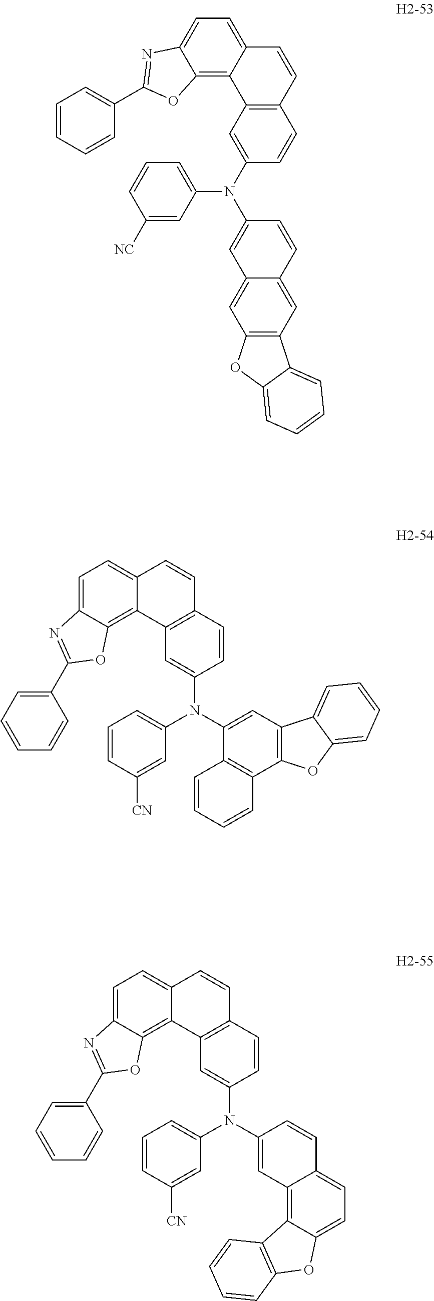 [SMILES: N#Cc1cccc(N(c2ccc3cc4c(cc3c2)oc2ccccc24)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cc3c4ccccc4oc3c3ccccc23)c1 ; N#Cc1cccc(N(c2ccc3ccc4oc5ccccc5c4c3c2)c2ccc3ccc4ccc5nc(-c6ccccc6)oc5c4c3c2)c1] 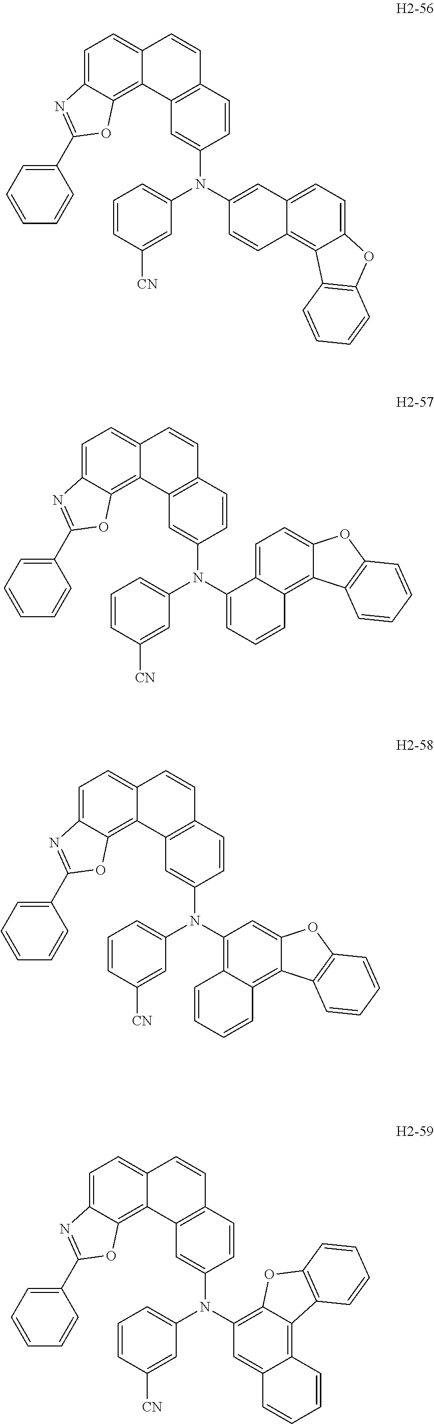 [SMILES: N#Cc1cccc(N(c2ccc3c(ccc4oc5ccccc5c43)c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cccc3c2ccc2oc4ccccc4c23)c1 ; N#Cc1cccc(N(c2ccc3ccc4ccc5nc(-c6ccccc6)oc5c4c3c2)c2cc3oc4ccccc4c3c3ccccc23)c1 ; N#Cc1cccc(N(c2ccc3ccc4ccc5nc(-c6ccccc6)oc5c4c3c2)c2cc3ccccc3c3c2oc2ccccc23)c1] 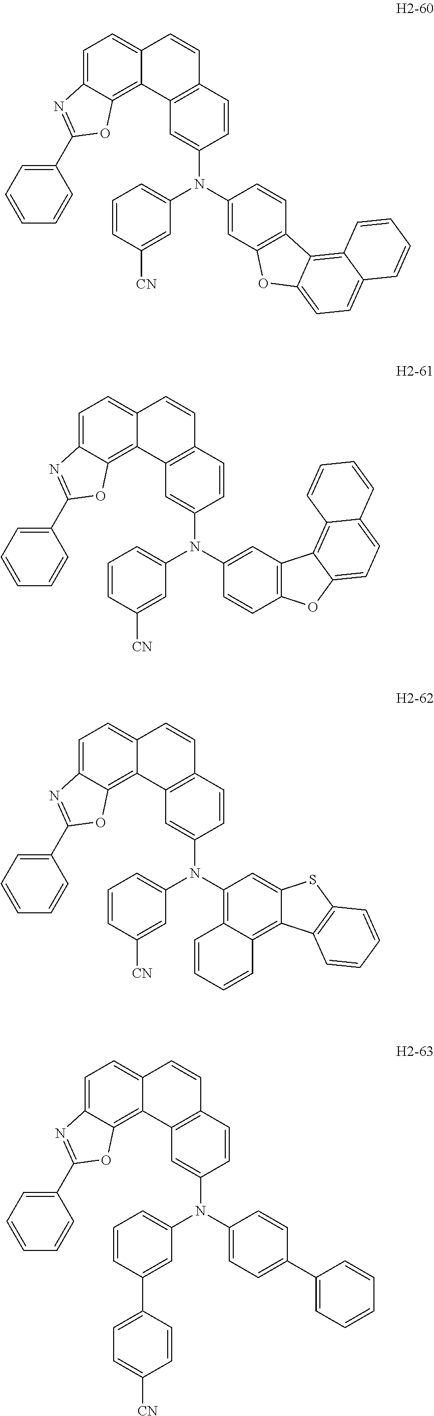 [SMILES: N#Cc1cccc(N(c2ccc3c(c2)oc2ccc4ccccc4c23)c2ccc3ccc4ccc5nc(-c6ccccc6)oc5c4c3c2)c1 ; N#Cc1cccc(N(c2ccc3oc4ccc5ccccc5c4c3c2)c2ccc3ccc4ccc5nc(-c6ccccc6)oc5c4c3c2)c1 ; N#Cc1cccc(N(c2ccc3ccc4ccc5nc(-c6ccccc6)oc5c4c3c2)c2cc3sc4ccccc4c3c3ccccc23)c1 ; N#Cc1ccc(-c2cccc(N(c3ccc(-c4ccccc4)cc3)c3ccc4ccc5ccc6nc(-c7ccccc7)oc6c5c4c3)c2)cc1] 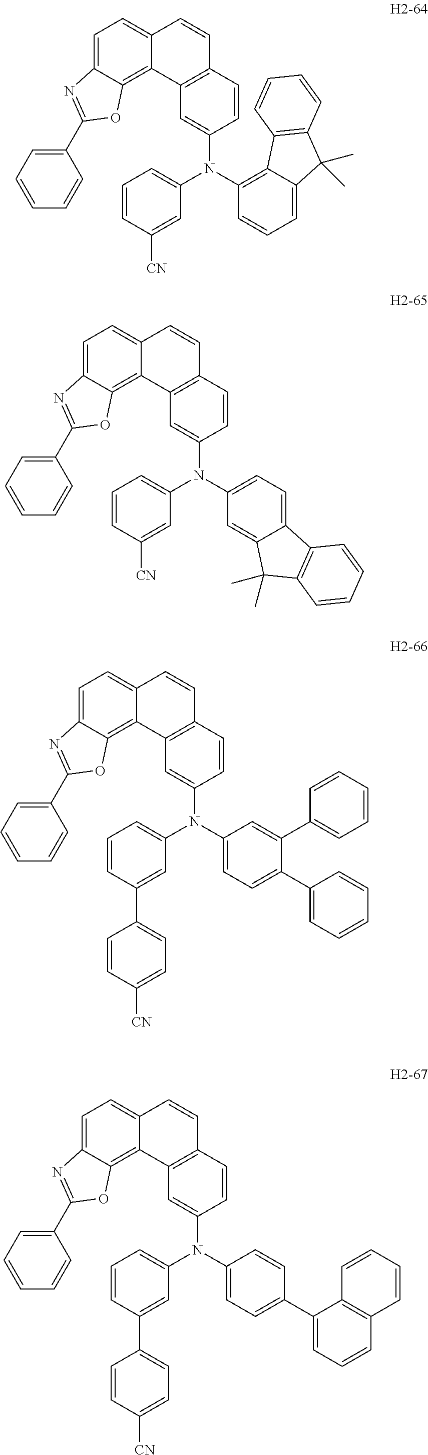 [SMILES: CC1(C)c2ccccc2-c2c(N(c3cccc(C#N)c3)c3ccc4ccc5ccc6nc(-c7ccccc7)oc6c5c4c3)cccc21 ; CC1(C)c2ccccc2-c2ccc(N(c3cccc(C#N)c3)c3ccc4ccc5ccc6nc(-c7ccccc7)oc6c5c4c3)cc21 ; N#Cc1ccc(-c2cccc(N(c3ccc(-c4ccccc4)c(-c4ccccc4)c3)c3ccc4ccc5ccc6nc(-c7ccccc7)oc6c5c4c3)c2)cc1 ; N#Cc1ccc(-c2cccc(N(c3ccc(-c4cccc5ccccc45)cc3)c3ccc4ccc5ccc6nc(-c7ccccc7)oc6c5c4c3)c2)cc1] 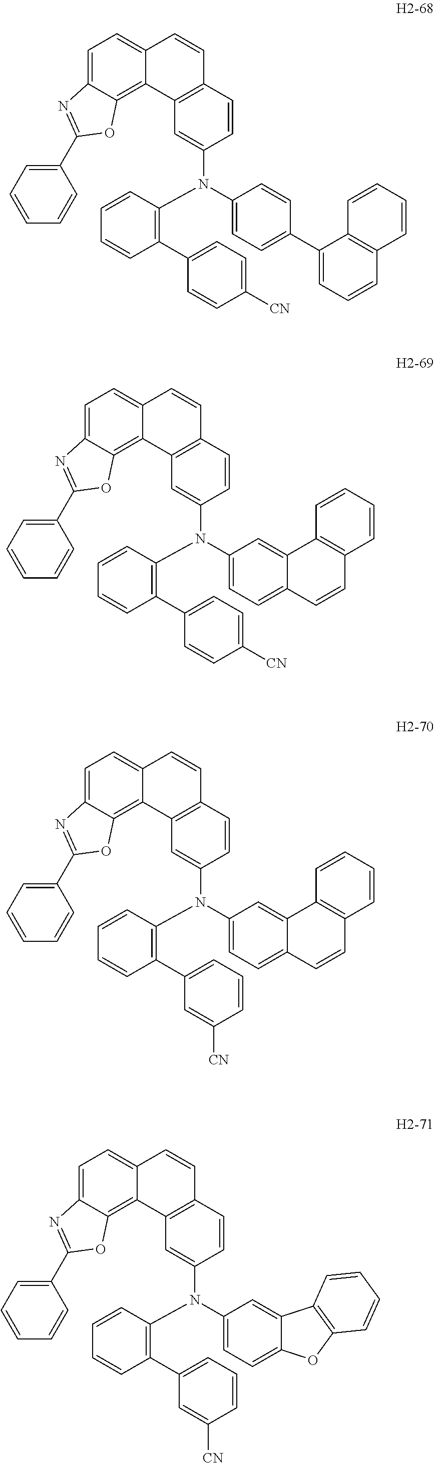 [SMILES: N#Cc1ccc(-c2ccccc2N(c2ccc(-c3cccc4ccccc34)cc2)c2ccc3ccc4ccc5nc(-c6ccccc6)oc5c4c3c2)cc1 ; N#Cc1ccc(-c2ccccc2N(c2ccc3ccc4ccccc4c3c2)c2ccc3ccc4ccc5nc(-c6ccccc6)oc5c4c3c2)cc1 ; N#Cc1cccc(-c2ccccc2N(c2ccc3ccc4ccccc4c3c2)c2ccc3ccc4ccc5nc(-c6ccccc6)oc5c4c3c2)c1 ; N#Cc1cccc(-c2ccccc2N(c2ccc3oc4ccccc4c3c2)c2ccc3ccc4ccc5nc(-c6ccccc6)oc5c4c3c2)c1] 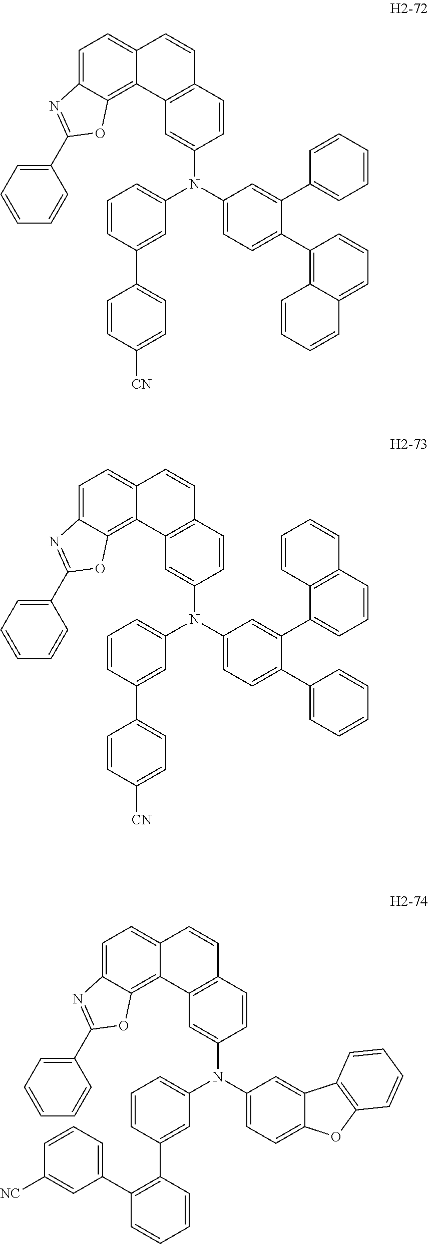 [SMILES: N#Cc1ccc(-c2cccc(N(c3ccc(-c4cccc5ccccc45)c(-c4ccccc4)c3)c3ccc4ccc5ccc6nc(-c7ccccc7)oc6c5c4c3)c2)cc1 ; N#Cc1ccc(-c2cccc(N(c3ccc(-c4ccccc4)c(-c4cccc5ccccc45)c3)c3ccc4ccc5ccc6nc(-c7ccccc7)oc6c5c4c3)c2)cc1 ; N#Cc1cccc(-c2ccccc2-c2cccc(N(c3ccc4oc5ccccc5c4c3)c3ccc4ccc5ccc6nc(-c7ccccc7)oc6c5c4c3)c2)c1] 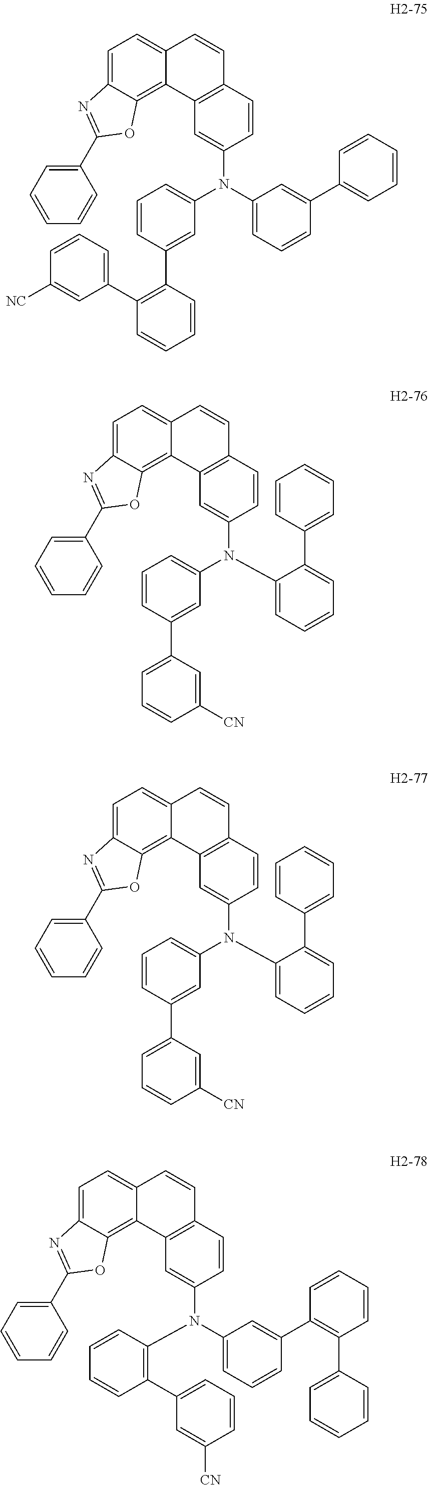 [SMILES: N#Cc1cccc(-c2ccccc2-c2cccc(N(c3cccc(-c4ccccc4)c3)c3ccc4ccc5ccc6nc(-c7ccccc7)oc6c5c4c3)c2)c1 ; N#Cc1cccc(-c2cccc(N(c3ccc4ccc5ccc6nc(-c7ccccc7)oc6c5c4c3)c3ccccc3-c3ccccc3)c2)c1 ; N#Cc1cccc(-c2cccc(N(c3ccc4ccc5ccc6nc(-c7ccccc7)oc6c5c4c3)c3ccccc3-c3ccccc3)c2)c1 ; N#Cc1cccc(-c2ccccc2N(c2cccc(-c3ccccc3-c3ccccc3)c2)c2ccc3ccc4ccc5nc(-c6ccccc6)oc5c4c3c2)c1] 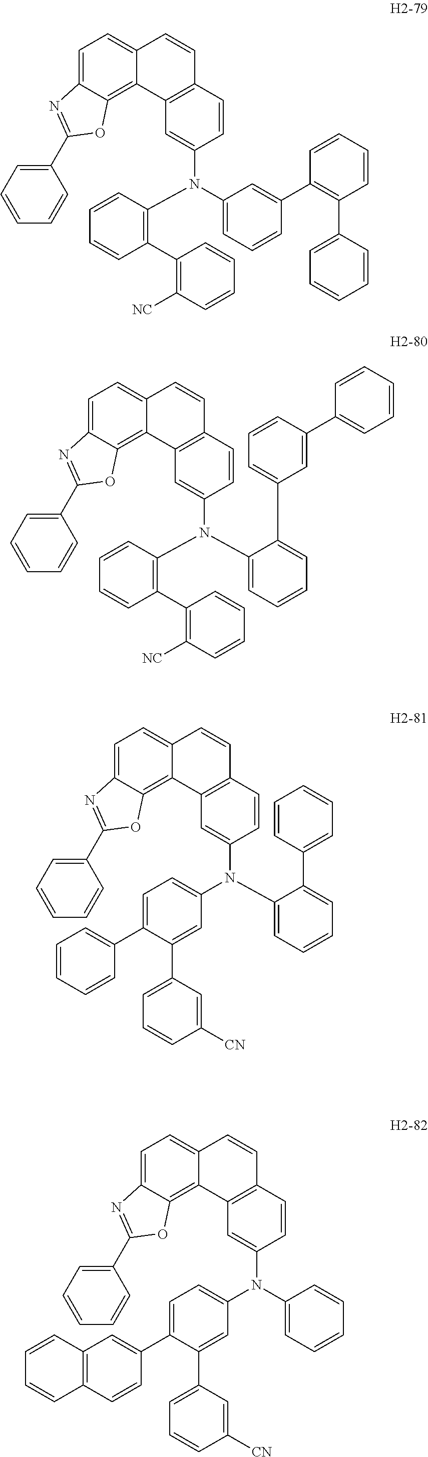 [SMILES: N#Cc1ccccc1-c1ccccc1N(c1cccc(-c2ccccc2-c2ccccc2)c1)c1ccc2ccc3ccc4nc(-c5ccccc5)oc4c3c2c1 ; N#Cc1ccccc1-c1ccccc1N(c1ccc2ccc3ccc4nc(-c5ccccc5)oc4c3c2c1)c1ccccc1-c1cccc(-c2ccccc2)c1 ; N#Cc1cccc(-c2cc(N(c3ccc4ccc5ccc6nc(-c7ccccc7)oc6c5c4c3)c3ccccc3-c3ccccc3)ccc2-c2ccccc2)c1 ; N#Cc1cccc(-c2cc(N(c3ccccc3)c3ccc4ccc5ccc6nc(-c7ccccc7)oc6c5c4c3)ccc2-c2ccc3ccccc3c2)c1] 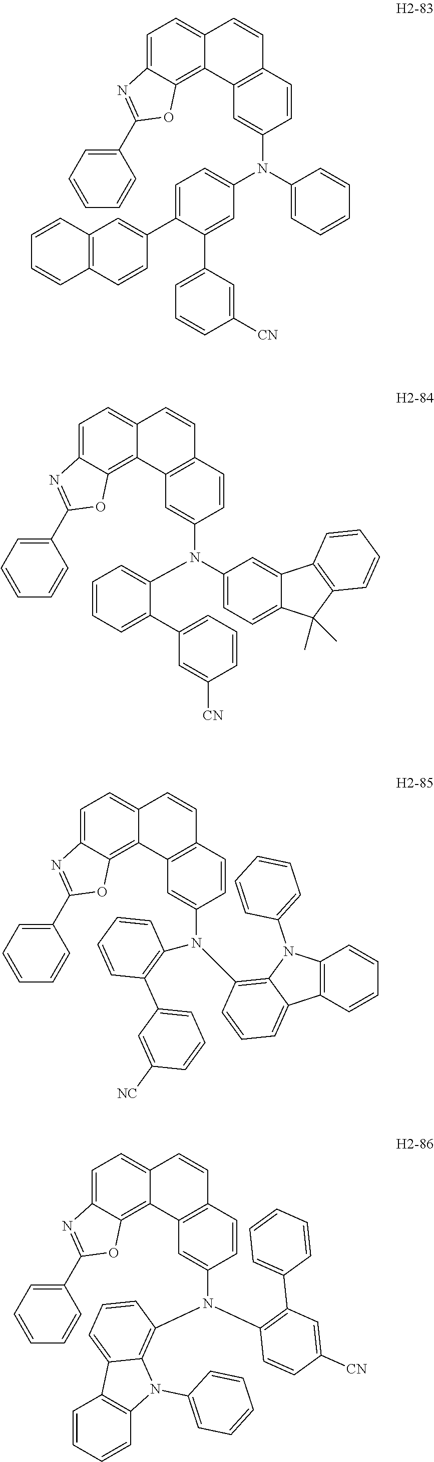 [SMILES: N#Cc1cccc(-c2cc(N(c3ccccc3)c3ccc4ccc5ccc6nc(-c7ccccc7)oc6c5c4c3)ccc2-c2ccc3ccccc3c2)c1 ; CC1(C)c2ccccc2-c2cc(N(c3ccc4ccc5ccc6nc(-c7ccccc7)oc6c5c4c3)c3ccccc3-c3cccc(C#N)c3)ccc21 ; N#Cc1cccc(-c2ccccc2N(c2ccc3ccc4ccc5nc(-c6ccccc6)oc5c4c3c2)c2cccc3c4ccccc4n(-c4ccccc4)c23)c1 ; N#Cc1ccc(N(c2ccc3ccc4ccc5nc(-c6ccccc6)oc5c4c3c2)c2cccc3c4ccccc4n(-c4ccccc4)c23)c(-c2ccccc2)c1] 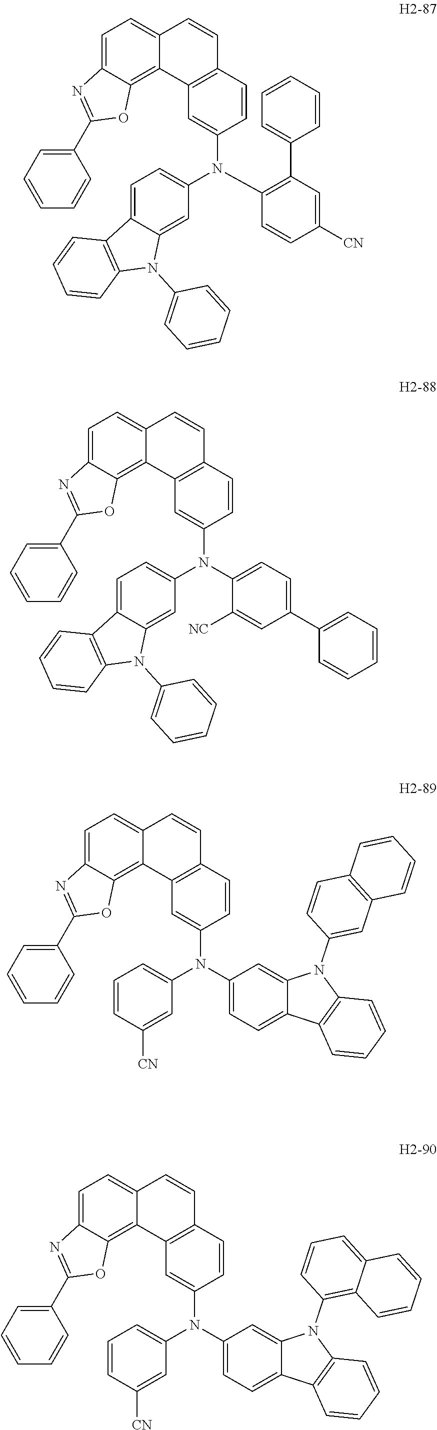 [SMILES: N#Cc1ccc(N(c2ccc3ccc4ccc5nc(-c6ccccc6)oc5c4c3c2)c2ccc3c4ccccc4n(-c4ccccc4)c3c2)c(-c2ccccc2)c1 ; N#Cc1cc(-c2ccccc2)ccc1N(c1ccc2ccc3ccc4nc(-c5ccccc5)oc4c3c2c1)c1ccc2c3ccccc3n(-c3ccccc3)c2c1 ; N#Cc1cccc(N(c2ccc3ccc4ccc5nc(-c6ccccc6)oc5c4c3c2)c2ccc3c4ccccc4n(-c4ccc5ccccc5c4)c3c2)c1 ; N#Cc1cccc(N(c2ccc3ccc4ccc5nc(-c6ccccc6)oc5c4c3c2)c2ccc3c4ccccc4n(-c4cccc5ccccc45)c3c2)c1] 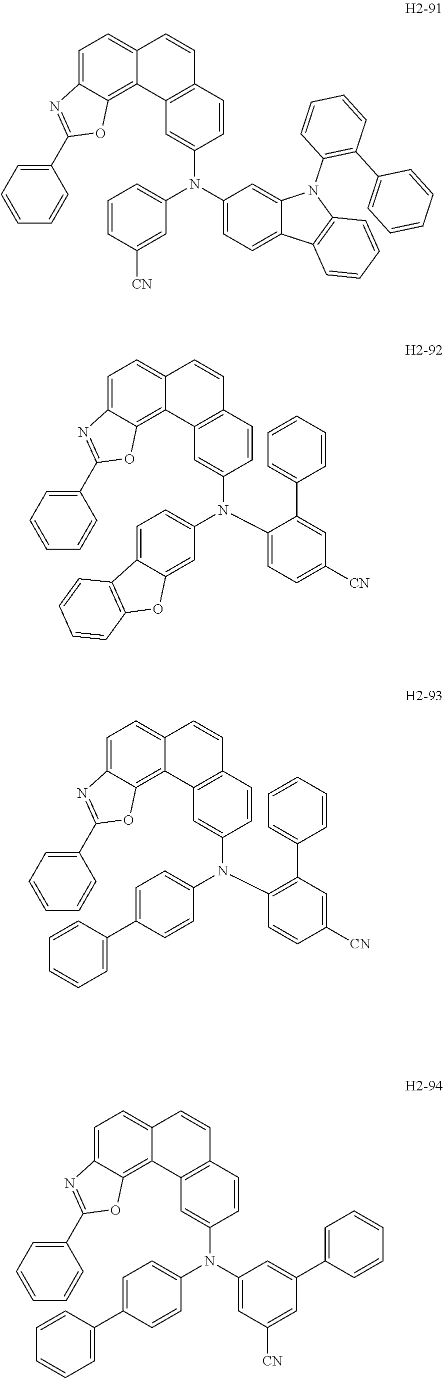 [SMILES: N#Cc1cccc(N(c2ccc3ccc4ccc5nc(-c6ccccc6)oc5c4c3c2)c2ccc3c4ccccc4n(-c4ccccc4-c4ccccc4)c3c2)c1 ; N#Cc1ccc(N(c2ccc3c(c2)oc2ccccc23)c2ccc3ccc4ccc5nc(-c6ccccc6)oc5c4c3c2)c(-c2ccccc2)c1 ; N#Cc1ccc(N(c2ccc(-c3ccccc3)cc2)c2ccc3ccc4ccc5nc(-c6ccccc6)oc5c4c3c2)c(-c2ccccc2)c1 ; N#Cc1cc(-c2ccccc2)cc(N(c2ccc(-c3ccccc3)cc2)c2ccc3ccc4ccc5nc(-c6ccccc6)oc5c4c3c2)c1] 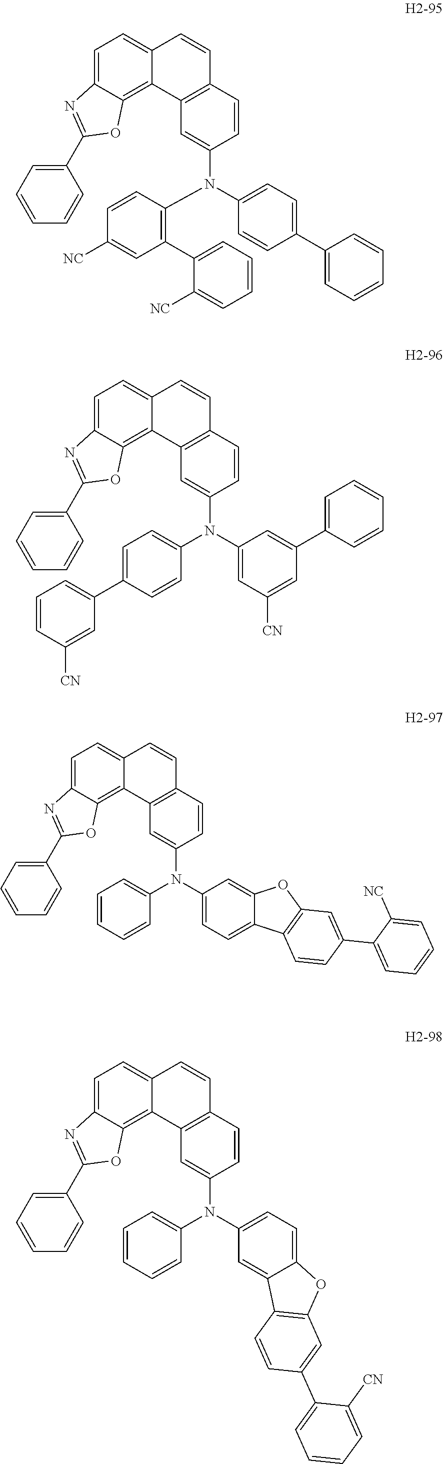 [SMILES: N#Cc1ccc(N(c2ccc(-c3ccccc3)cc2)c2ccc3ccc4ccc5nc(-c6ccccc6)oc5c4c3c2)c(-c2ccccc2C#N)c1 ; N#Cc1cccc(-c2ccc(N(c3cc(C#N)cc(-c4ccccc4)c3)c3ccc4ccc5ccc6nc(-c7ccccc7)oc6c5c4c3)cc2)c1 ; N#Cc1ccccc1-c1ccc2c(c1)oc1cc(N(c3ccccc3)c3ccc4ccc5ccc6nc(-c7ccccc7)oc6c5c4c3)ccc12 ; N#Cc1ccccc1-c1ccc2c(c1)oc1ccc(N(c3ccccc3)c3ccc4ccc5ccc6nc(-c7ccccc7)oc6c5c4c3)cc12] 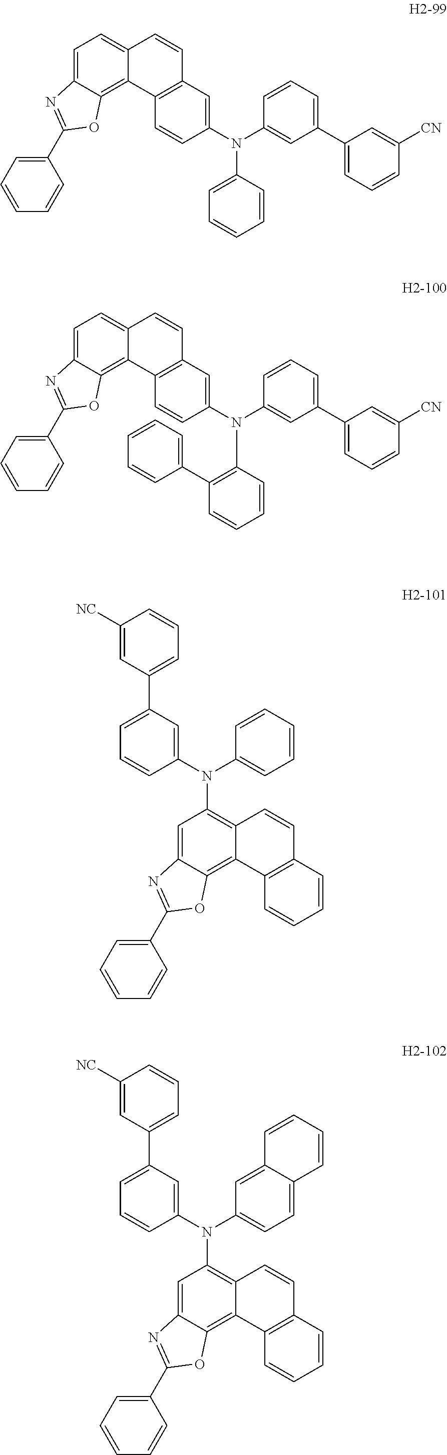 [SMILES: N#Cc1cccc(-c2cccc(N(c3ccccc3)c3ccc4c(ccc5ccc6nc(-c7ccccc7)oc6c54)c3)c2)c1 ; N#Cc1cccc(-c2cccc(N(c3ccc4c(ccc5ccc6nc(-c7ccccc7)oc6c54)c3)c3ccccc3-c3ccccc3)c2)c1 ; N#Cc1cccc(-c2cccc(N(c3ccccc3)c3cc4nc(-c5ccccc5)oc4c4c3ccc3ccccc34)c2)c1 ; N#Cc1cccc(-c2cccc(N(c3ccc4ccccc4c3)c3cc4nc(-c5ccccc5)oc4c4c3ccc3ccccc34)c2)c1] 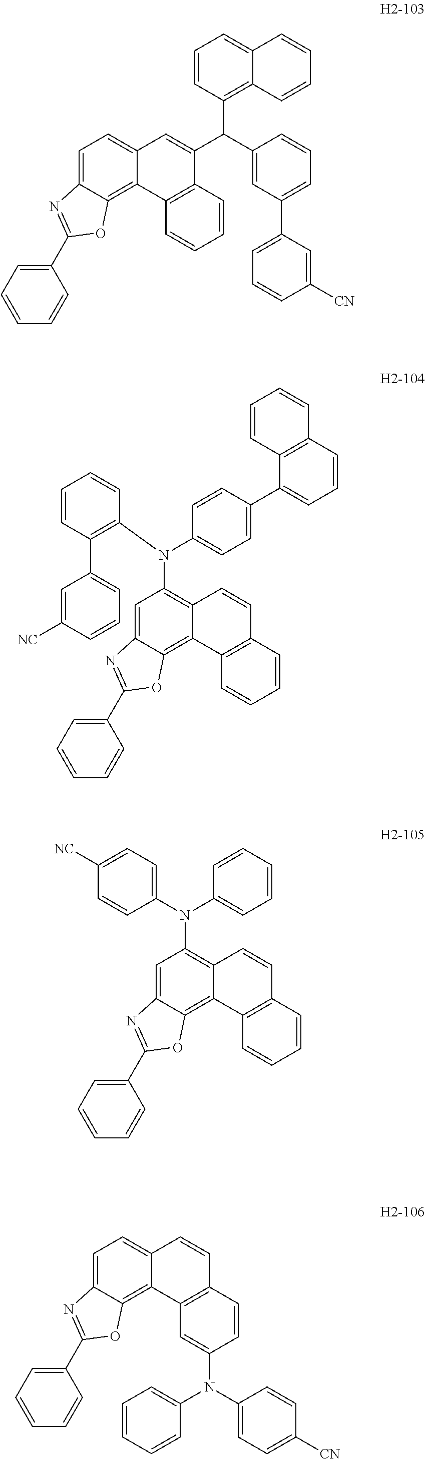 [SMILES: N#Cc1cccc(-c2cccc(C(c3cccc4ccccc34)c3cc4ccc5nc(-c6ccccc6)oc5c4c4ccccc34)c2)c1 ; N#Cc1cccc(-c2ccccc2N(c2ccc(-c3cccc4ccccc34)cc2)c2cc3nc(-c4ccccc4)oc3c3c2ccc2ccccc23)c1 ; N#Cc1ccc(N(c2ccccc2)c2cc3nc(-c4ccccc4)oc3c3c2ccc2ccccc23)cc1 ; N#Cc1ccc(N(c2ccccc2)c2ccc3ccc4ccc5nc(-c6ccccc6)oc5c4c3c2)cc1] 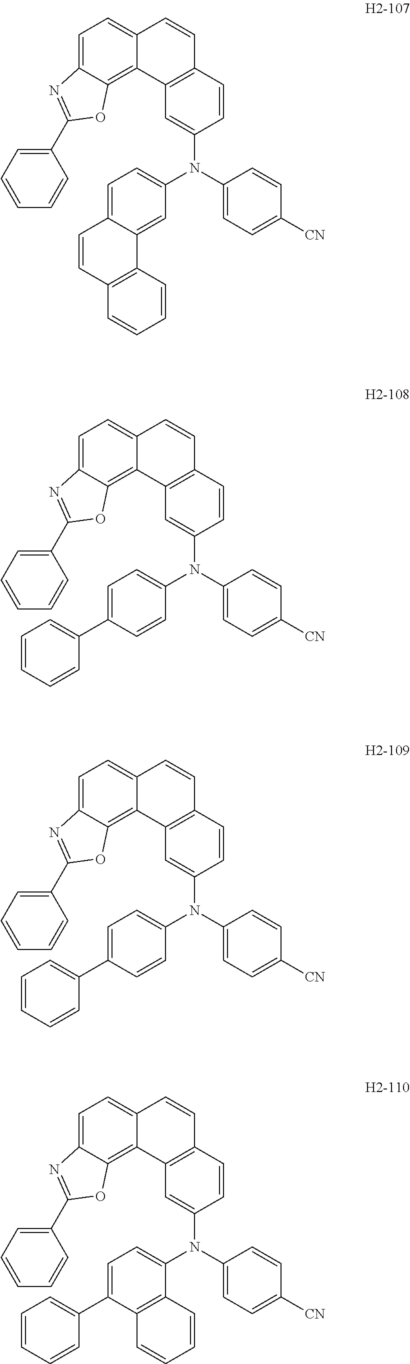 [SMILES: N#Cc1ccc(N(c2ccc3ccc4ccccc4c3c2)c2ccc3ccc4ccc5nc(-c6ccccc6)oc5c4c3c2)cc1 ; N#Cc1ccc(N(c2ccc(-c3ccccc3)cc2)c2ccc3ccc4ccc5nc(-c6ccccc6)oc5c4c3c2)cc1 ; N#Cc1ccc(N(c2ccc(-c3ccccc3)cc2)c2ccc3ccc4ccc5nc(-c6ccccc6)oc5c4c3c2)cc1 ; N#Cc1ccc(N(c2ccc3ccc4ccc5nc(-c6ccccc6)oc5c4c3c2)c2ccc(-c3ccccc3)c3ccccc23)cc1] 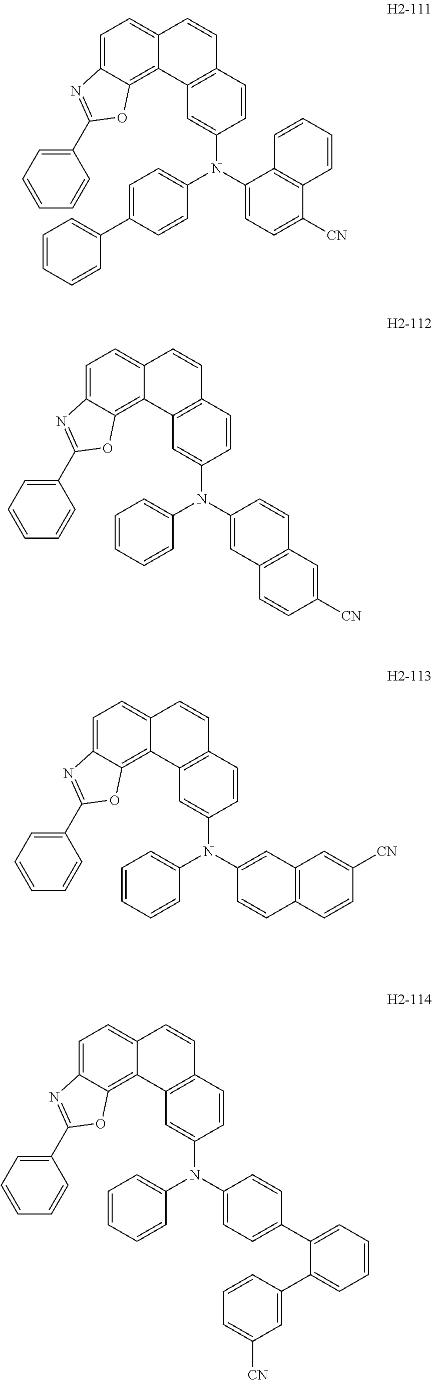 [SMILES: N#Cc1ccc(N(c2ccc(-c3ccccc3)cc2)c2ccc3ccc4ccc5nc(-c6ccccc6)oc5c4c3c2)c2ccccc12 ; N#Cc1ccc2cc(N(c3ccccc3)c3ccc4ccc5ccc6nc(-c7ccccc7)oc6c5c4c3)ccc2c1 ; N#Cc1ccc2ccc(N(c3ccccc3)c3ccc4ccc5ccc6nc(-c7ccccc7)oc6c5c4c3)cc2c1 ; N#Cc1cccc(-c2ccccc2-c2ccc(N(c3ccccc3)c3ccc4ccc5ccc6nc(-c7ccccc7)oc6c5c4c3)cc2)c1] 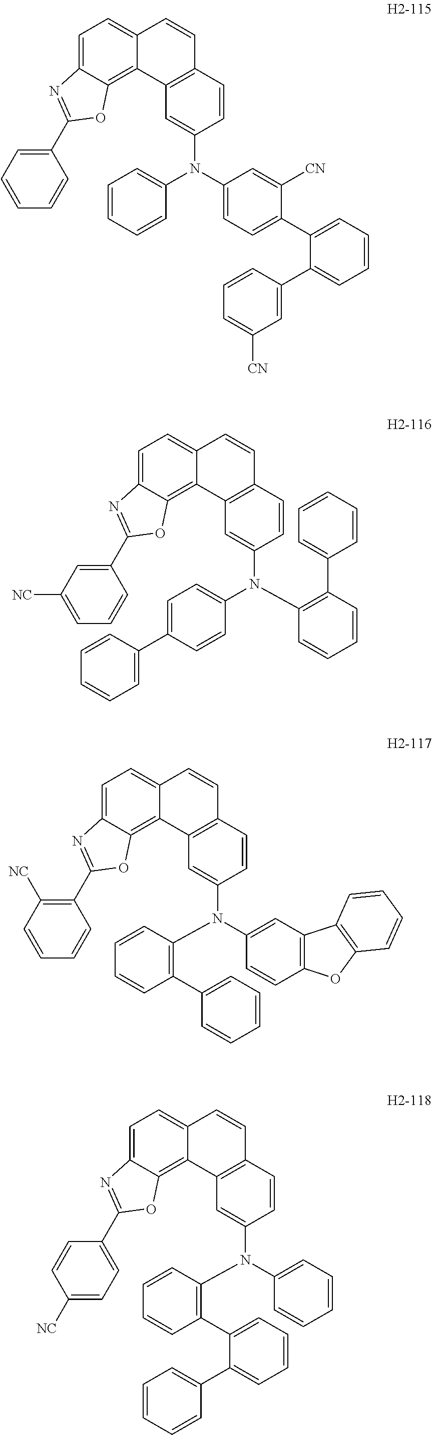 [SMILES: N#Cc1cccc(-c2ccccc2-c2ccc(N(c3ccccc3)c3ccc4ccc5ccc6nc(-c7ccccc7)oc6c5c4c3)cc2C#N)c1 ; N#Cc1cccc(-c2nc3ccc4ccc5ccc(N(c6ccc(-c7ccccc7)cc6)c6ccccc6-c6ccccc6)cc5c4c3o2)c1 ; N#Cc1ccccc1-c1nc2ccc3ccc4ccc(N(c5ccc6oc7ccccc7c6c5)c5ccccc5-c5ccccc5)cc4c3c2o1 ; N#Cc1ccc(-c2nc3ccc4ccc5ccc(N(c6ccccc6)c6ccccc6-c6ccccc6-c6ccccc6)cc5c4c3o2)cc1] 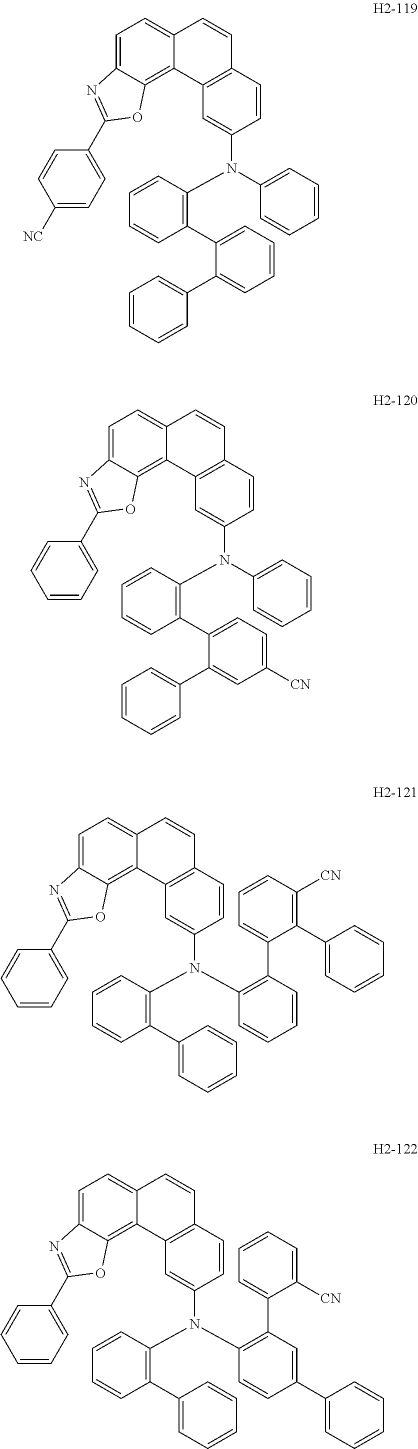 [SMILES: N#Cc1ccc(-c2nc3ccc4ccc5ccc(N(c6ccccc6)c6ccccc6-c6ccccc6-c6ccccc6)cc5c4c3o2)cc1 ; N#Cc1ccc(-c2ccccc2N(c2ccccc2)c2ccc3ccc4ccc5nc(-c6ccccc6)oc5c4c3c2)c(-c2ccccc2)c1 ; N#Cc1cccc(-c2ccccc2N(c2ccc3ccc4ccc5nc(-c6ccccc6)oc5c4c3c2)c2ccccc2-c2ccccc2)c1-c1ccccc1 ; N#Cc1ccccc1-c1cc(-c2ccccc2)ccc1N(c1ccc2ccc3ccc4nc(-c5ccccc5)oc4c3c2c1)c1ccccc1-c1ccccc1] 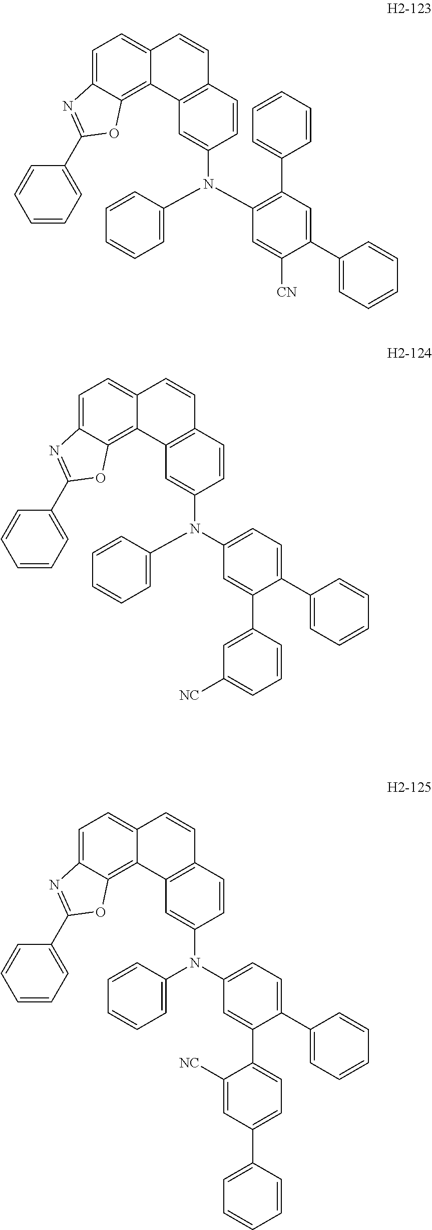 [SMILES: N#Cc1cc(N(c2ccccc2)c2ccc3ccc4ccc5nc(-c6ccccc6)oc5c4c3c2)c(-c2ccccc2)cc1-c1ccccc1 ; N#Cc1cccc(-c2cc(N(c3ccccc3)c3ccc4ccc5ccc6nc(-c7ccccc7)oc6c5c4c3)ccc2-c2ccccc2)c1 ; N#Cc1cc(-c2ccccc2)ccc1-c1cc(N(c2ccccc2)c2ccc3ccc4ccc5nc(-c6ccccc6)oc5c4c3c2)ccc1-c1ccccc1] 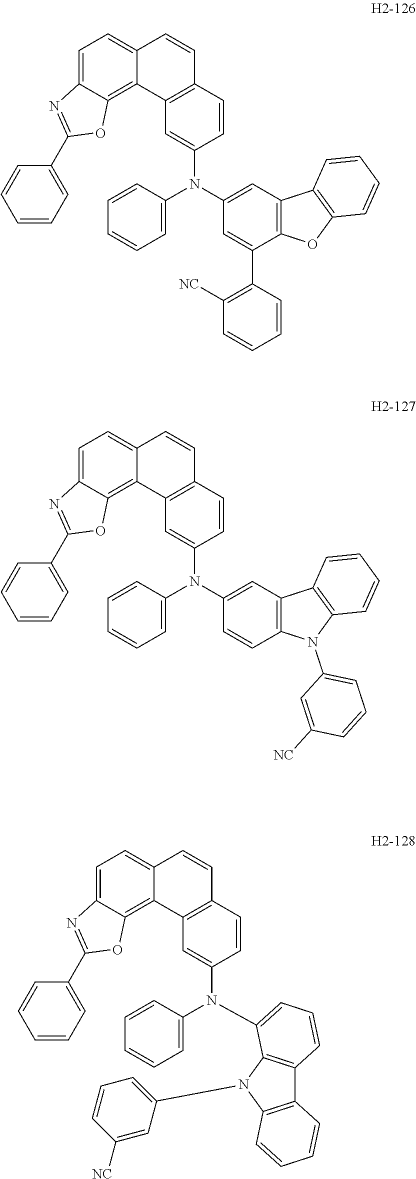 [SMILES: N#Cc1ccccc1-c1cc(N(c2ccccc2)c2ccc3ccc4ccc5nc(-c6ccccc6)oc5c4c3c2)cc2c1oc1ccccc12 ; N#Cc1cccc(-n2c3ccccc3c3cc(N(c4ccccc4)c4ccc5ccc6ccc7nc(-c8ccccc8)oc7c6c5c4)ccc32)c1 ; N#Cc1cccc(-n2c3ccccc3c3cccc(N(c4ccccc4)c4ccc5ccc6ccc7nc(-c8ccccc8)oc7c6c5c4)c32)c1] 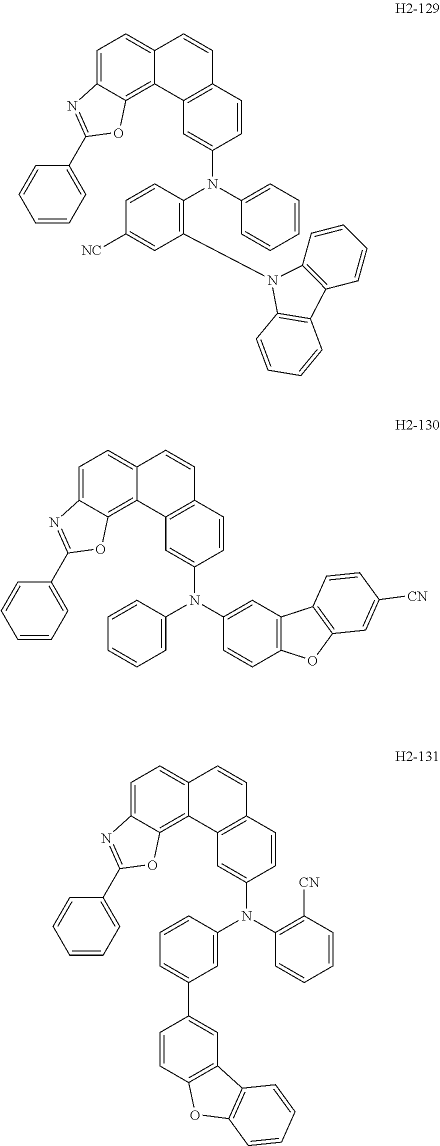 [SMILES: N#Cc1ccc(N(c2ccccc2)c2ccc3ccc4ccc5nc(-c6ccccc6)oc5c4c3c2)c(-n2c3ccccc3c3ccccc32)c1 ; N#Cc1ccc2c(c1)oc1ccc(N(c3ccccc3)c3ccc4ccc5ccc6nc(-c7ccccc7)oc6c5c4c3)cc12 ; N#Cc1ccccc1N(c1cccc(-c2ccc3oc4ccccc4c3c2)c1)c1ccc2ccc3ccc4nc(-c5ccccc5)oc4c3c2c1] 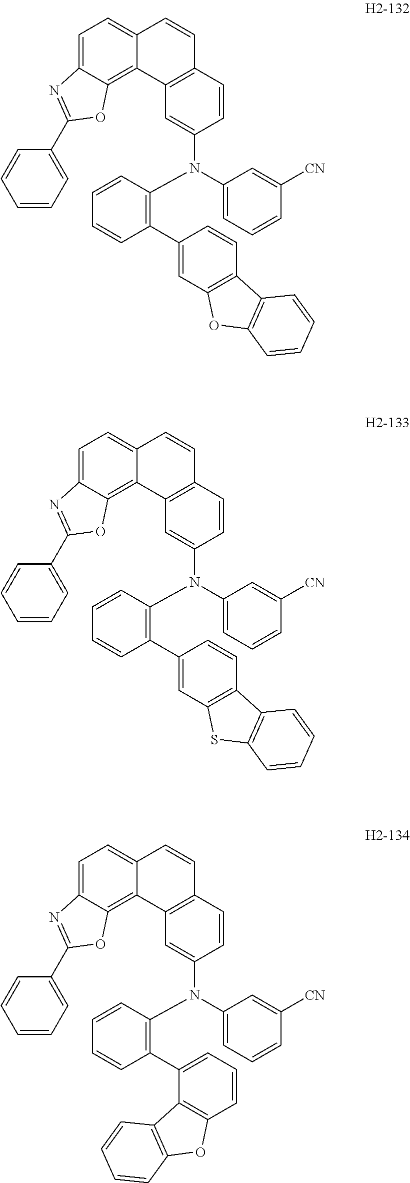 [SMILES: N#Cc1cccc(N(c2ccc3ccc4ccc5nc(-c6ccccc6)oc5c4c3c2)c2ccccc2-c2ccc3c(c2)oc2ccccc23)c1 ; N#Cc1cccc(N(c2ccc3ccc4ccc5nc(-c6ccccc6)oc5c4c3c2)c2ccccc2-c2ccc3c(c2)sc2ccccc23)c1 ; N#Cc1cccc(N(c2ccc3ccc4ccc5nc(-c6ccccc6)oc5c4c3c2)c2ccccc2-c2cccc3oc4ccccc4c23)c1] 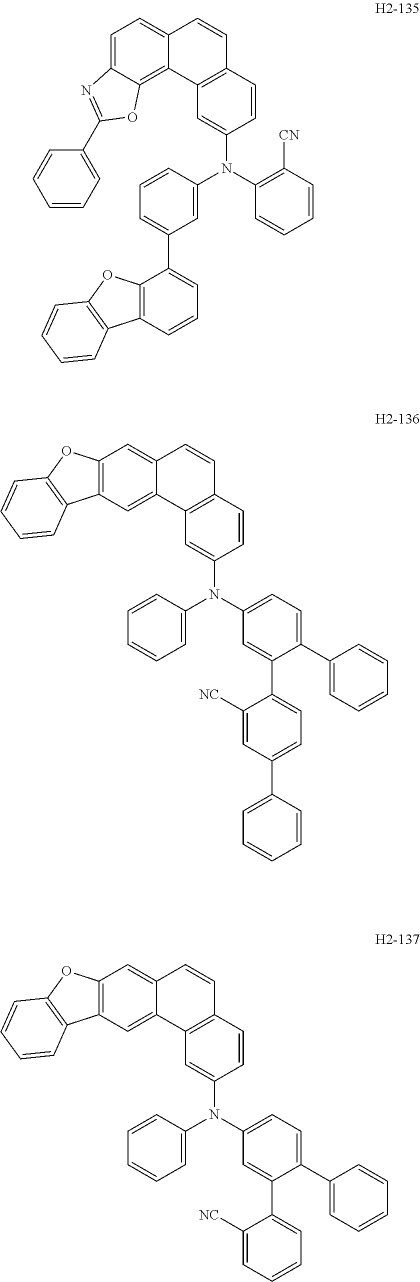 [SMILES: N#Cc1ccccc1N(c1cccc(-c2cccc3c2oc2ccccc23)c1)c1ccc2ccc3ccc4nc(-c5ccccc5)oc4c3c2c1 ; N#Cc1cc(-c2ccccc2)ccc1-c1cc(N(c2ccccc2)c2ccc3ccc4cc5oc6ccccc6c5cc4c3c2)ccc1-c1ccccc1 ; N#Cc1ccccc1-c1cc(N(c2ccccc2)c2ccc3ccc4cc5oc6ccccc6c5cc4c3c2)ccc1-c1ccccc1] 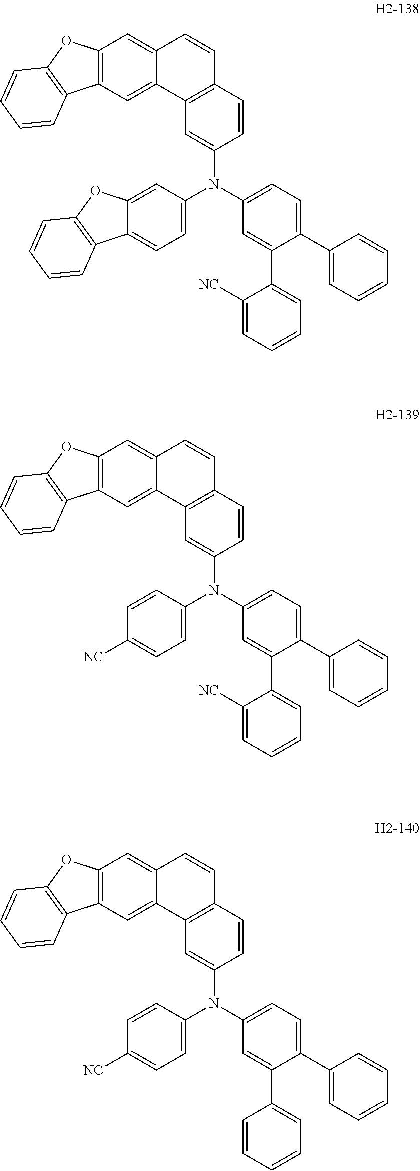 [SMILES: N#Cc1ccccc1-c1cc(N(c2ccc3c(c2)oc2ccccc23)c2ccc3ccc4cc5oc6ccccc6c5cc4c3c2)ccc1-c1ccccc1 ; N#Cc1ccc(N(c2ccc(-c3ccccc3)c(-c3ccccc3C#N)c2)c2ccc3ccc4cc5oc6ccccc6c5cc4c3c2)cc1 ; N#Cc1ccc(N(c2ccc(-c3ccccc3)c(-c3ccccc3)c2)c2ccc3ccc4cc5oc6ccccc6c5cc4c3c2)cc1] 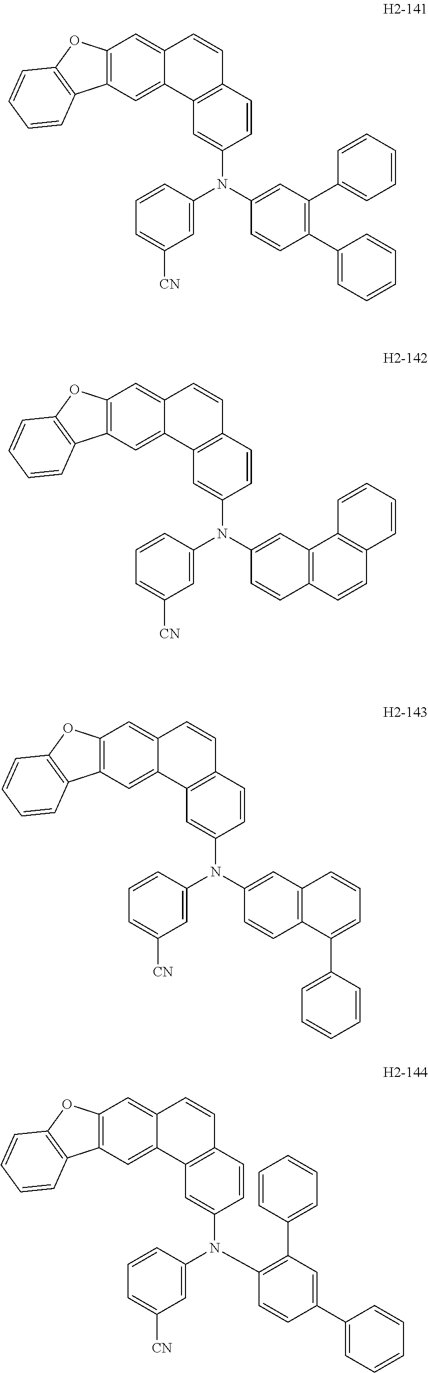 [SMILES: N#Cc1cccc(N(c2ccc(-c3ccccc3)c(-c3ccccc3)c2)c2ccc3ccc4cc5oc6ccccc6c5cc4c3c2)c1 ; N#Cc1cccc(N(c2ccc3ccc4ccccc4c3c2)c2ccc3ccc4cc5oc6ccccc6c5cc4c3c2)c1 ; N#Cc1cccc(N(c2ccc3c(-c4ccccc4)cccc3c2)c2ccc3ccc4cc5oc6ccccc6c5cc4c3c2)c1 ; N#Cc1cccc(N(c2ccc3ccc4cc5oc6ccccc6c5cc4c3c2)c2ccc(-c3ccccc3)cc2-c2ccccc2)c1] 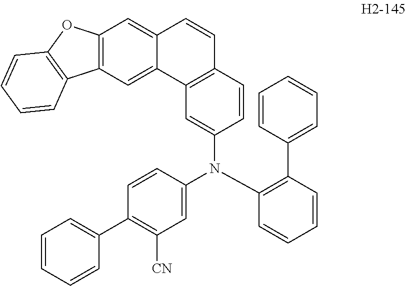 [SMILES: N#Cc1cc(N(c2ccc3ccc4cc5oc6ccccc6c5cc4c3c2)c2ccccc2-c2ccccc2)ccc1-c1ccccc1] 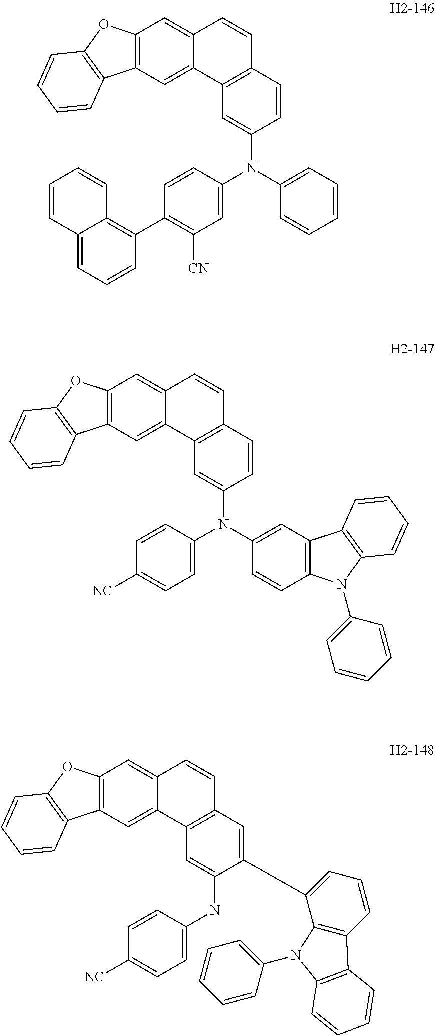 [SMILES: N#Cc1cc(N(c2ccccc2)c2ccc3ccc4cc5oc6ccccc6c5cc4c3c2)ccc1-c1cccc2ccccc12 ; N#Cc1ccc(N(c2ccc3ccc4cc5oc6ccccc6c5cc4c3c2)c2ccc3c(c2)c2ccccc2n3-c2ccccc2)cc1 ; N#Cc1ccc(Nc2cc3c(ccc4cc5oc6ccccc6c5cc43)cc2-c2cccc3c4ccccc4n(-c4ccccc4)c23)cc1] 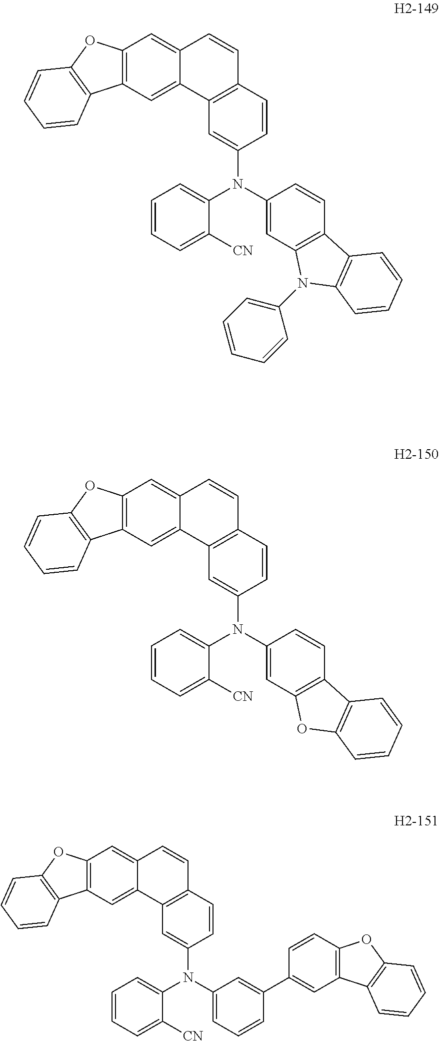 [SMILES: N#Cc1ccccc1N(c1ccc2ccc3cc4oc5ccccc5c4cc3c2c1)c1ccc2c3ccccc3n(-c3ccccc3)c2c1 ; N#Cc1ccccc1N(c1ccc2c(c1)oc1ccccc12)c1ccc2ccc3cc4oc5ccccc5c4cc3c2c1 ; N#Cc1ccccc1N(c1cccc(-c2ccc3oc4ccccc4c3c2)c1)c1ccc2ccc3cc4oc5ccccc5c4cc3c2c1] 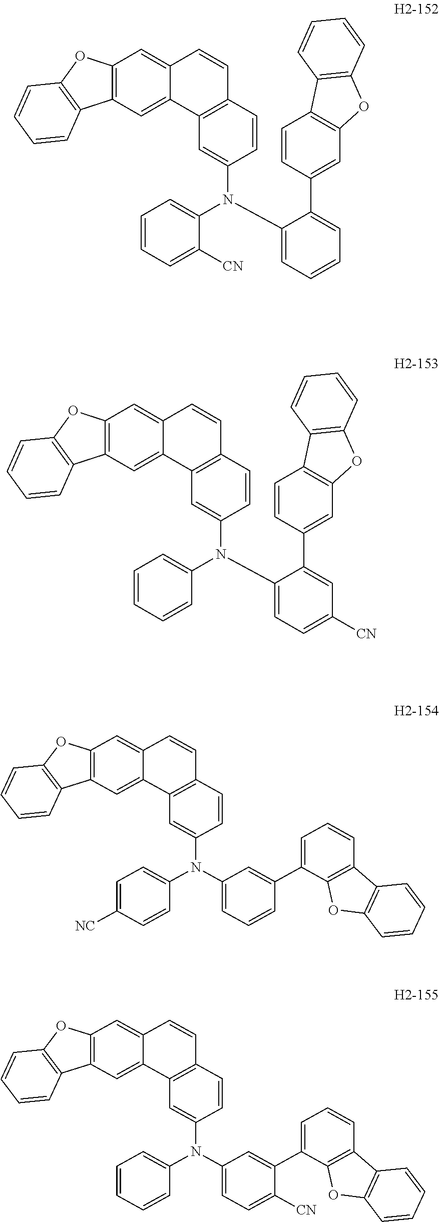 [SMILES: N#Cc1ccccc1N(c1ccc2ccc3cc4oc5ccccc5c4cc3c2c1)c1ccccc1-c1ccc2c(c1)oc1ccccc12 ; N#Cc1ccc(N(c2ccccc2)c2ccc3ccc4cc5oc6ccccc6c5cc4c3c2)c(-c2ccc3c(c2)oc2ccccc23)c1 ; N#Cc1ccc(N(c2cccc(-c3cccc4c3oc3ccccc34)c2)c2ccc3ccc4cc5oc6ccccc6c5cc4c3c2)cc1 ; N#Cc1ccc(N(c2ccccc2)c2ccc3ccc4cc5oc6ccccc6c5cc4c3c2)cc1-c1cccc2c1oc1ccccc12] 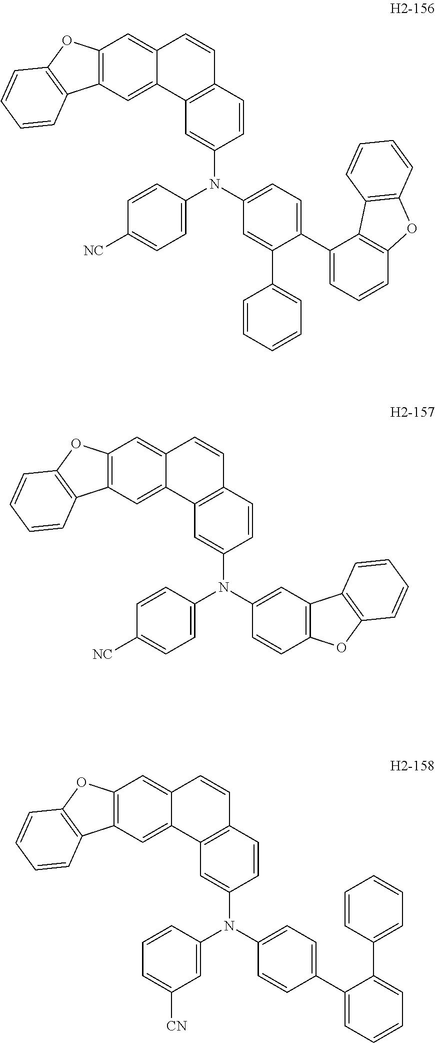 [SMILES: N#Cc1ccc(N(c2ccc(-c3cccc4oc5ccccc5c34)c(-c3ccccc3)c2)c2ccc3ccc4cc5oc6ccccc6c5cc4c3c2)cc1 ; N#Cc1ccc(N(c2ccc3ccc4cc5oc6ccccc6c5cc4c3c2)c2ccc3oc4ccccc4c3c2)cc1 ; N#Cc1cccc(N(c2ccc(-c3ccccc3-c3ccccc3)cc2)c2ccc3ccc4cc5oc6ccccc6c5cc4c3c2)c1] 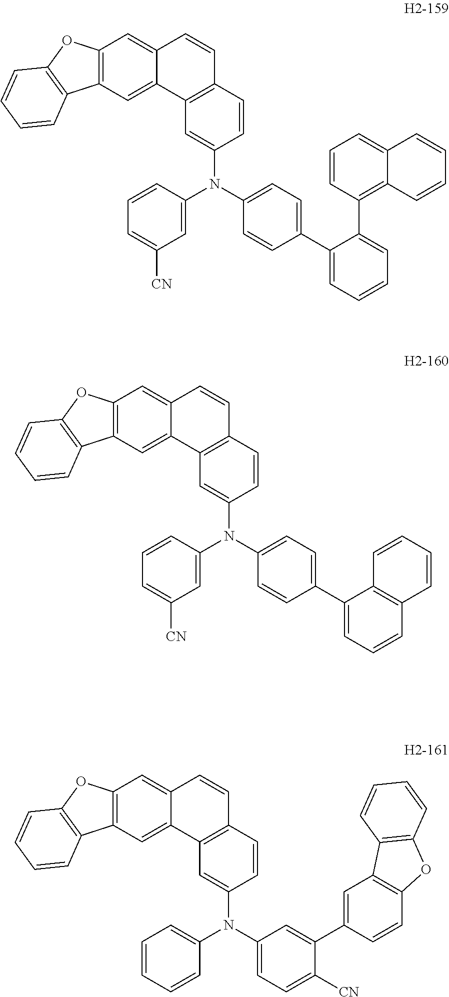 [SMILES: N#Cc1cccc(N(c2ccc(-c3ccccc3-c3cccc4ccccc34)cc2)c2ccc3ccc4cc5oc6ccccc6c5cc4c3c2)c1 ; N#Cc1cccc(N(c2ccc(-c3cccc4ccccc34)cc2)c2ccc3ccc4cc5oc6ccccc6c5cc4c3c2)c1 ; N#Cc1ccc(N(c2ccccc2)c2ccc3ccc4cc5oc6ccccc6c5cc4c3c2)cc1-c1ccc2oc3ccccc3c2c1] 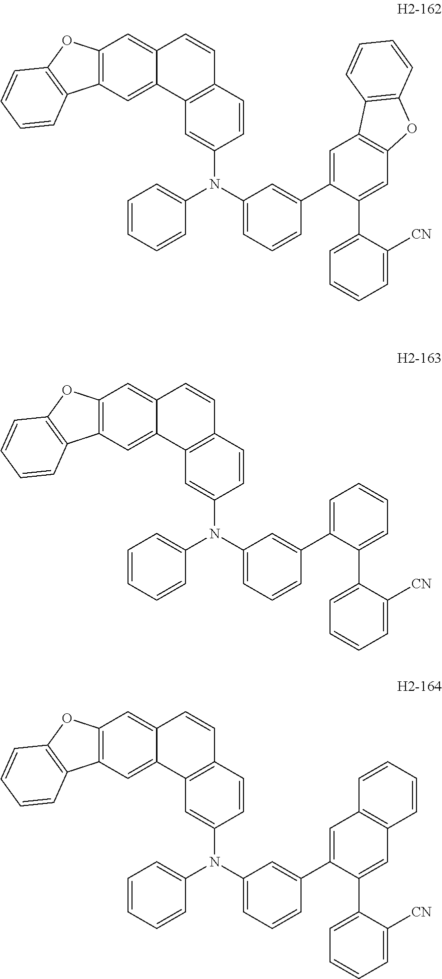 [SMILES: N#Cc1ccccc1-c1cc2oc3ccccc3c2cc1-c1cccc(N(c2ccccc2)c2ccc3ccc4cc5oc6ccccc6c5cc4c3c2)c1 ; N#Cc1ccccc1-c1ccccc1-c1cccc(N(c2ccccc2)c2ccc3ccc4cc5oc6ccccc6c5cc4c3c2)c1 ; N#Cc1ccccc1-c1cc2ccccc2cc1-c1cccc(N(c2ccccc2)c2ccc3ccc4cc5oc6ccccc6c5cc4c3c2)c1] 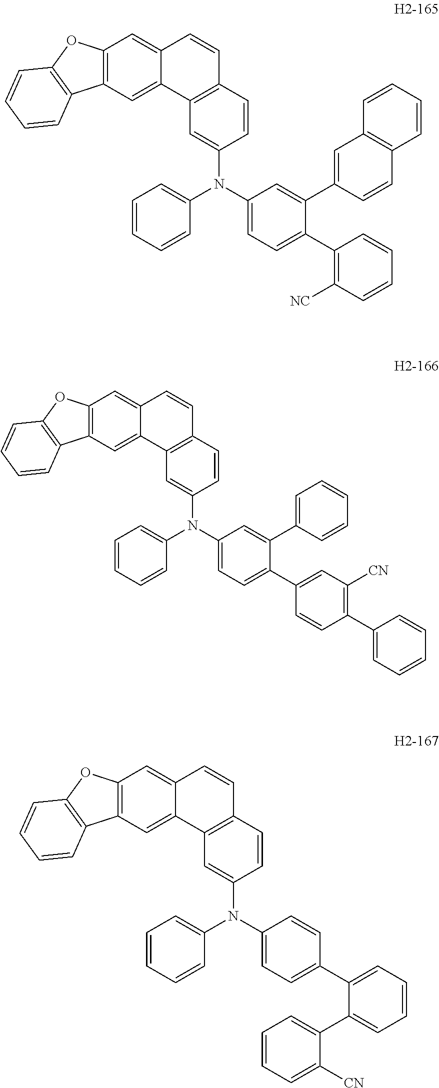 [SMILES: N#Cc1ccccc1-c1ccc(N(c2ccccc2)c2ccc3ccc4cc5oc6ccccc6c5cc4c3c2)cc1-c1ccc2ccccc2c1 ; N#Cc1cc(-c2ccc(N(c3ccccc3)c3ccc4ccc5cc6oc7ccccc7c6cc5c4c3)cc2-c2ccccc2)ccc1-c1ccccc1 ; N#Cc1ccccc1-c1ccccc1-c1ccc(N(c2ccccc2)c2ccc3ccc4cc5oc6ccccc6c5cc4c3c2)cc1] 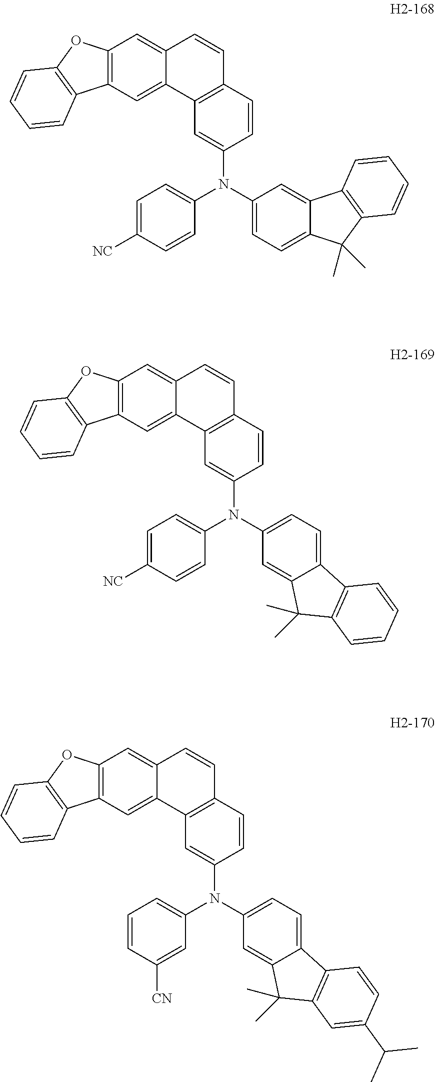 [SMILES: CC1(C)c2ccccc2-c2cc(N(c3ccc(C#N)cc3)c3ccc4ccc5cc6oc7ccccc7c6cc5c4c3)ccc21 ; CC1(C)c2ccccc2-c2ccc(N(c3ccc(C#N)cc3)c3ccc4ccc5cc6oc7ccccc7c6cc5c4c3)cc21 ; CC(C)c1ccc2c(c1)C(C)(C)c1cc(N(c3cccc(C#N)c3)c3ccc4ccc5cc6oc7ccccc7c6cc5c4c3)ccc1-2] 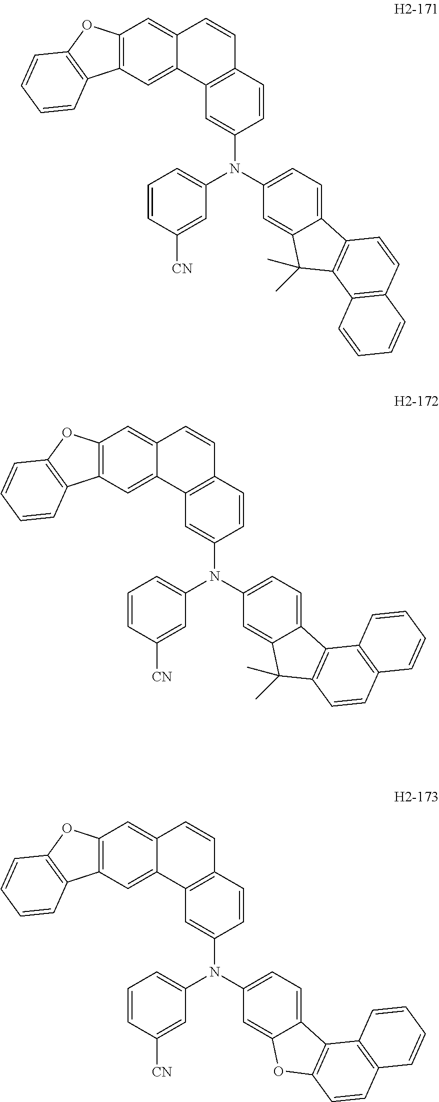 [SMILES: CC1(C)c2cc(N(c3cccc(C#N)c3)c3ccc4ccc5cc6oc7ccccc7c6cc5c4c3)ccc2-c2ccc3ccccc3c21 ; CC1(C)c2cc(N(c3cccc(C#N)c3)c3ccc4ccc5cc6oc7ccccc7c6cc5c4c3)ccc2-c2c1ccc1ccccc21 ; N#Cc1cccc(N(c2ccc3c(c2)oc2ccc4ccccc4c23)c2ccc3ccc4cc5oc6ccccc6c5cc4c3c2)c1] 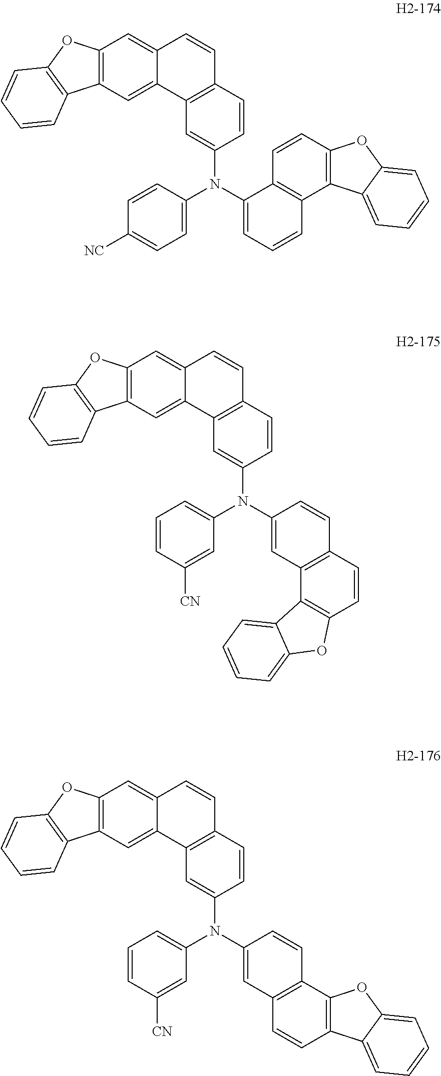 [SMILES: N#Cc1ccc(N(c2ccc3ccc4cc5oc6ccccc6c5cc4c3c2)c2cccc3c2ccc2oc4ccccc4c23)cc1 ; N#Cc1cccc(N(c2ccc3ccc4cc5oc6ccccc6c5cc4c3c2)c2ccc3ccc4oc5ccccc5c4c3c2)c1 ; N#Cc1cccc(N(c2ccc3c(ccc4c5ccccc5oc34)c2)c2ccc3ccc4cc5oc6ccccc6c5cc4c3c2)c1] 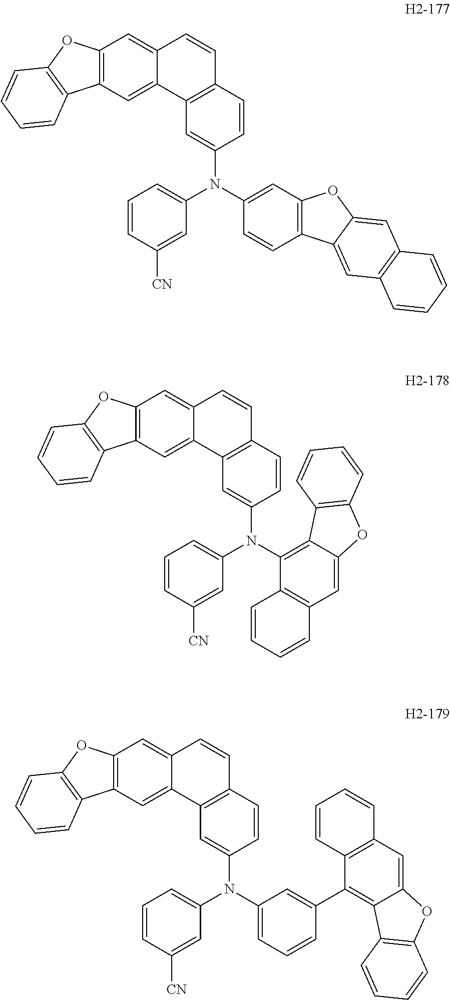 [SMILES: N#Cc1cccc(N(c2ccc3c(c2)oc2cc4ccccc4cc23)c2ccc3ccc4cc5oc6ccccc6c5cc4c3c2)c1 ; N#Cc1cccc(N(c2ccc3ccc4cc5oc6ccccc6c5cc4c3c2)c2c3ccccc3cc3oc4ccccc4c23)c1 ; N#Cc1cccc(N(c2cccc(-c3c4ccccc4cc4oc5ccccc5c34)c2)c2ccc3ccc4cc5oc6ccccc6c5cc4c3c2)c1] 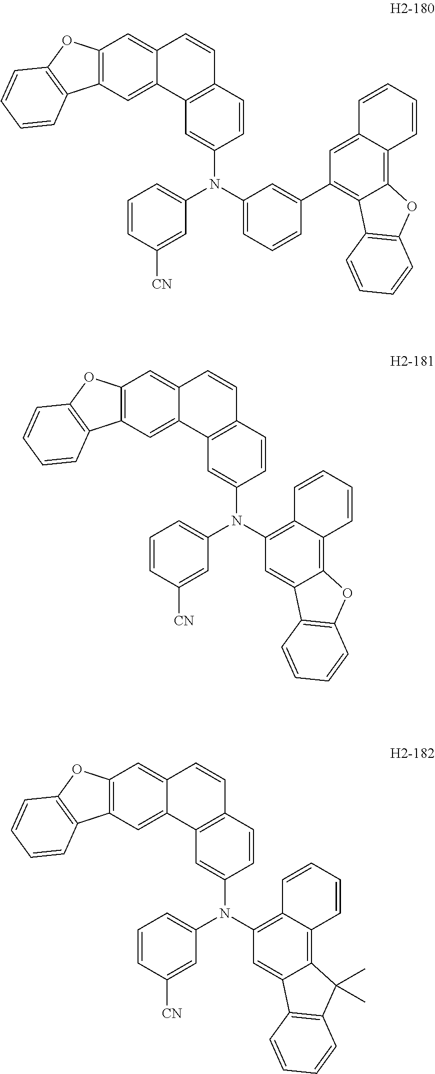 [SMILES: N#Cc1cccc(N(c2cccc(-c3cc4ccccc4c4oc5ccccc5c34)c2)c2ccc3ccc4cc5oc6ccccc6c5cc4c3c2)c1 ; N#Cc1cccc(N(c2ccc3ccc4cc5oc6ccccc6c5cc4c3c2)c2cc3c4ccccc4oc3c3ccccc23)c1 ; CC1(C)c2ccccc2-c2cc(N(c3cccc(C#N)c3)c3ccc4ccc5cc6oc7ccccc7c6cc5c4c3)c3ccccc3c21] 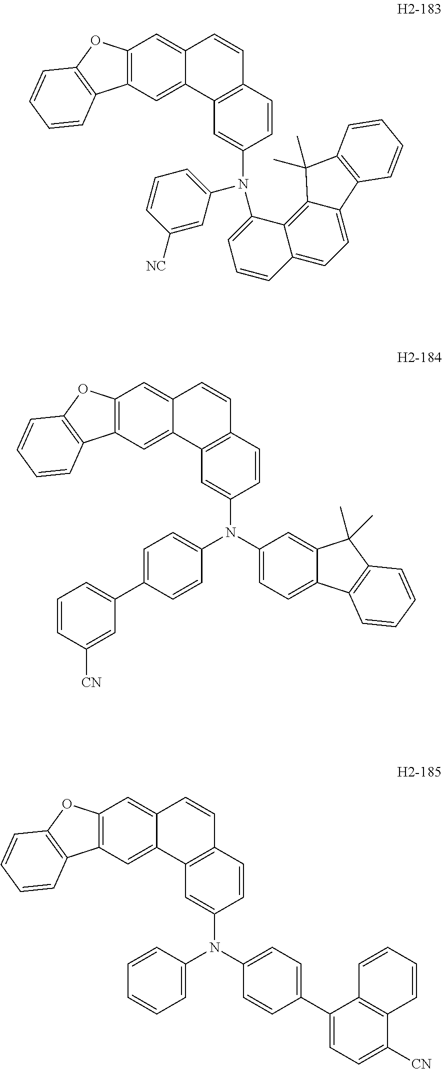 [SMILES: CC1(C)c2ccccc2-c2ccc3cccc(N(c4cccc(C#N)c4)c4ccc5ccc6cc7oc8ccccc8c7cc6c5c4)c3c21 ; CC1(C)c2ccccc2-c2ccc(N(c3ccc(-c4cccc(C#N)c4)cc3)c3ccc4ccc5cc6oc7ccccc7c6cc5c4c3)cc21 ; N#Cc1ccc(-c2ccc(N(c3ccccc3)c3ccc4ccc5cc6oc7ccccc7c6cc5c4c3)cc2)c2ccccc12] 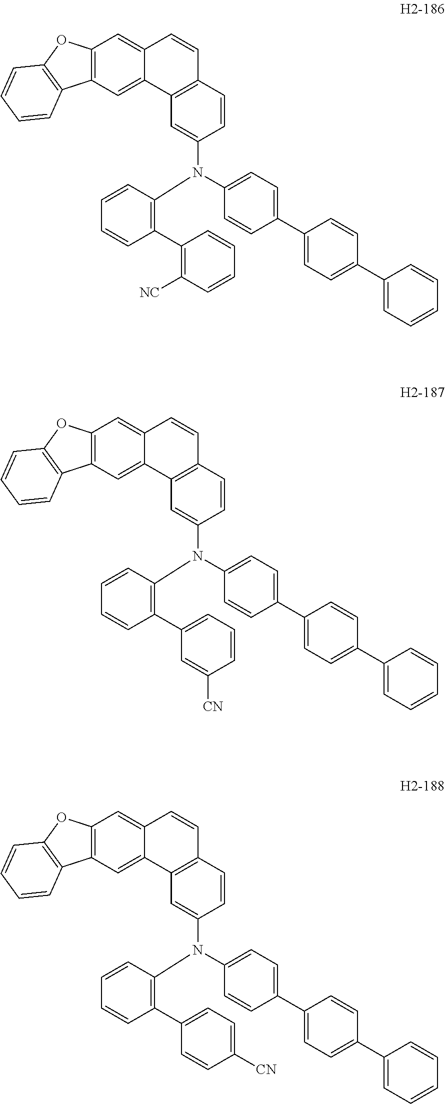 [SMILES: N#Cc1ccccc1-c1ccccc1N(c1ccc(-c2ccc(-c3ccccc3)cc2)cc1)c1ccc2ccc3cc4oc5ccccc5c4cc3c2c1 ; N#Cc1cccc(-c2ccccc2N(c2ccc(-c3ccc(-c4ccccc4)cc3)cc2)c2ccc3ccc4cc5oc6ccccc6c5cc4c3c2)c1 ; N#Cc1ccc(-c2ccccc2N(c2ccc(-c3ccc(-c4ccccc4)cc3)cc2)c2ccc3ccc4cc5oc6ccccc6c5cc4c3c2)cc1] 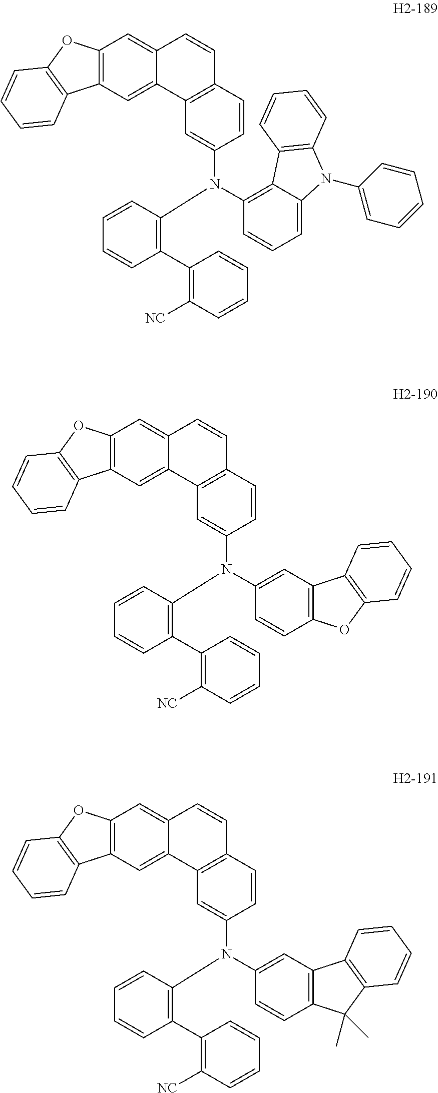 [SMILES: N#Cc1ccccc1-c1ccccc1N(c1ccc2ccc3cc4oc5ccccc5c4cc3c2c1)c1cccc2c1c1ccccc1n2-c1ccccc1 ; N#Cc1ccccc1-c1ccccc1N(c1ccc2ccc3cc4oc5ccccc5c4cc3c2c1)c1ccc2oc3ccccc3c2c1 ; CC1(C)c2ccccc2-c2cc(N(c3ccc4ccc5cc6oc7ccccc7c6cc5c4c3)c3ccccc3-c3ccccc3C#N)ccc21] 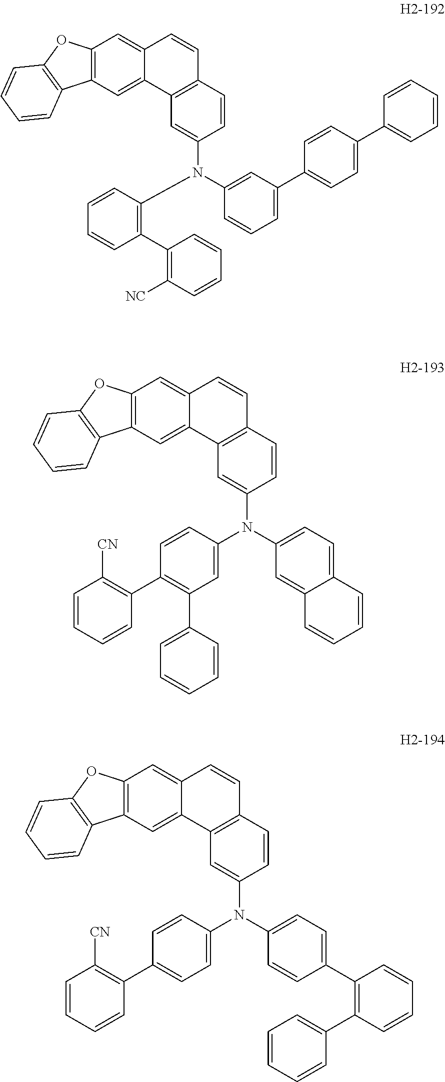 [SMILES: N#Cc1ccccc1-c1ccccc1N(c1cccc(-c2ccc(-c3ccccc3)cc2)c1)c1ccc2ccc3cc4oc5ccccc5c4cc3c2c1 ; N#Cc1ccccc1-c1ccc(N(c2ccc3ccccc3c2)c2ccc3ccc4cc5oc6ccccc6c5cc4c3c2)cc1-c1ccccc1 ; N#Cc1ccccc1-c1ccc(N(c2ccc(-c3ccccc3-c3ccccc3)cc2)c2ccc3ccc4cc5oc6ccccc6c5cc4c3c2)cc1] 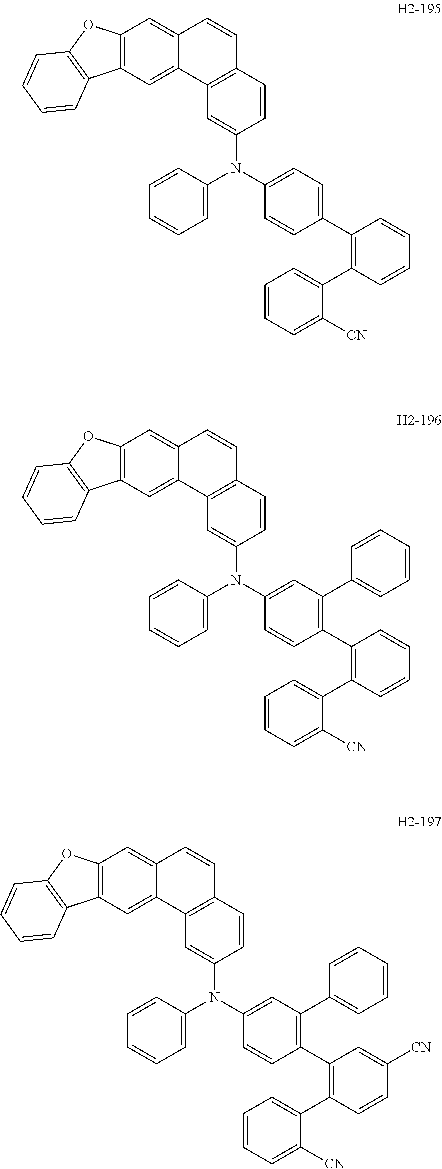 [SMILES: N#Cc1ccccc1-c1ccccc1-c1ccc(N(c2ccccc2)c2ccc3ccc4cc5oc6ccccc6c5cc4c3c2)cc1 ; N#Cc1ccccc1-c1ccccc1-c1ccc(N(c2ccccc2)c2ccc3ccc4cc5oc6ccccc6c5cc4c3c2)cc1-c1ccccc1 ; N#Cc1ccc(-c2ccccc2C#N)c(-c2ccc(N(c3ccccc3)c3ccc4ccc5cc6oc7ccccc7c6cc5c4c3)cc2-c2ccccc2)c1] 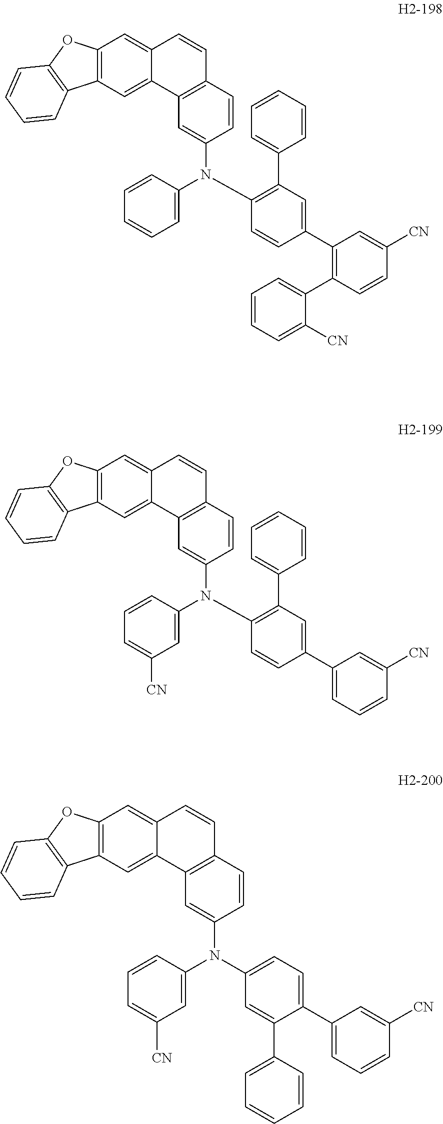 [SMILES: N#Cc1ccc(-c2ccccc2C#N)c(-c2ccc(N(c3ccccc3)c3ccc4ccc5cc6oc7ccccc7c6cc5c4c3)c(-c3ccccc3)c2)c1 ; N#Cc1cccc(-c2ccc(N(c3cccc(C#N)c3)c3ccc4ccc5cc6oc7ccccc7c6cc5c4c3)c(-c3ccccc3)c2)c1 ; N#Cc1cccc(-c2ccc(N(c3cccc(C#N)c3)c3ccc4ccc5cc6oc7ccccc7c6cc5c4c3)cc2-c2ccccc2)c1] 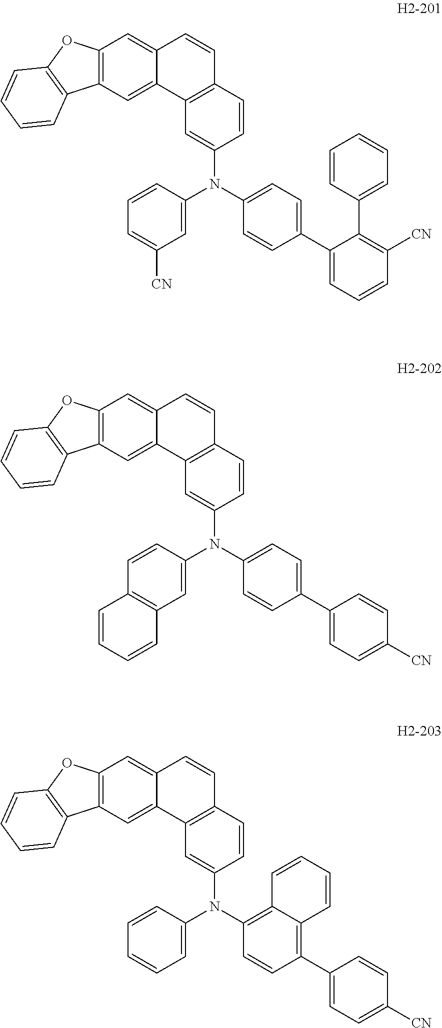 [SMILES: N#Cc1cccc(N(c2ccc(-c3cccc(C#N)c3-c3ccccc3)cc2)c2ccc3ccc4cc5oc6ccccc6c5cc4c3c2)c1 ; N#Cc1ccc(-c2ccc(N(c3ccc4ccccc4c3)c3ccc4ccc5cc6oc7ccccc7c6cc5c4c3)cc2)cc1 ; N#Cc1ccc(-c2ccc(N(c3ccccc3)c3ccc4ccc5cc6oc7ccccc7c6cc5c4c3)c3ccccc23)cc1] 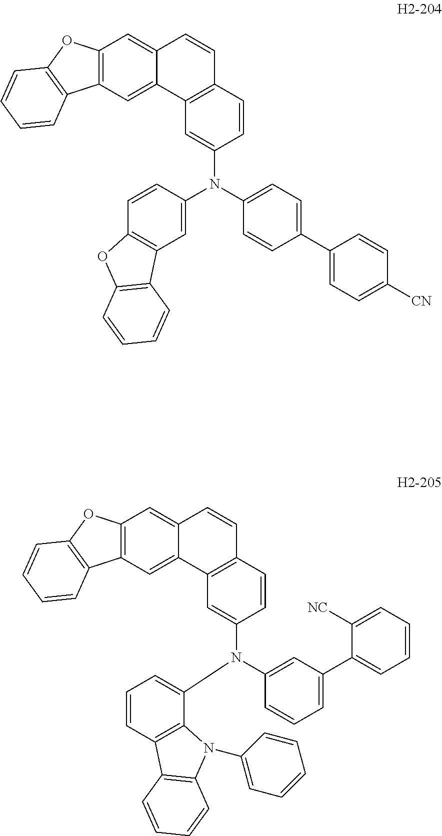 [SMILES: N#Cc1ccc(-c2ccc(N(c3ccc4ccc5cc6oc7ccccc7c6cc5c4c3)c3ccc4oc5ccccc5c4c3)cc2)cc1 ; N#Cc1ccccc1-c1cccc(N(c2ccc3ccc4cc5oc6ccccc6c5cc4c3c2)c2cccc3c4ccccc4n(-c4ccccc4)c23)c1] 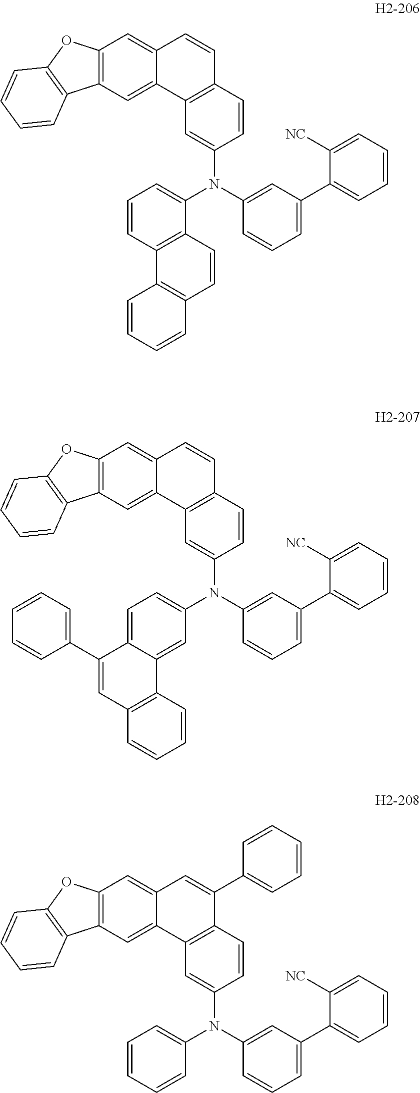 [SMILES: N#Cc1ccccc1-c1cccc(N(c2ccc3ccc4cc5oc6ccccc6c5cc4c3c2)c2cccc3c2ccc2ccccc23)c1 ; N#Cc1ccccc1-c1cccc(N(c2ccc3ccc4cc5oc6ccccc6c5cc4c3c2)c2ccc3c(-c4ccccc4)cc4ccccc4c3c2)c1 ; N#Cc1ccccc1-c1cccc(N(c2ccccc2)c2ccc3c(-c4ccccc4)cc4cc5oc6ccccc6c5cc4c3c2)c1] 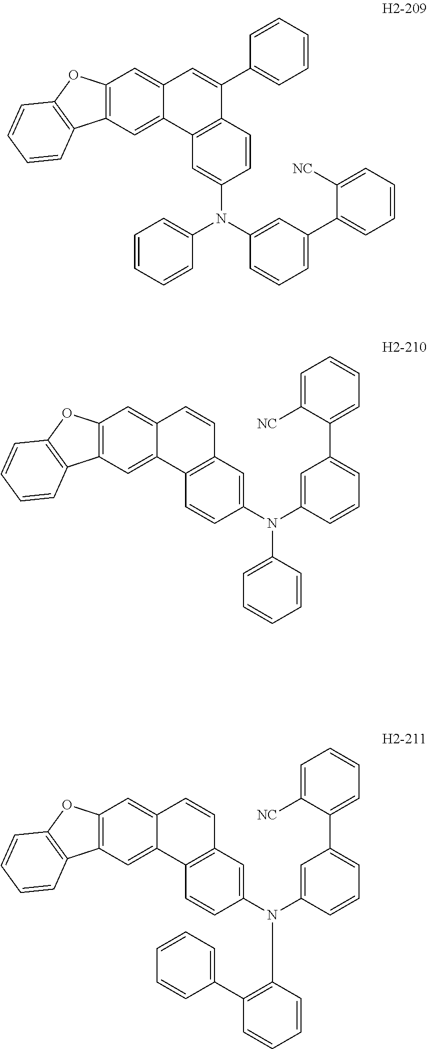 [SMILES: N#Cc1ccccc1-c1cccc(N(c2ccccc2)c2ccc3c(-c4ccccc4)cc4cc5oc6ccccc6c5cc4c3c2)c1 ; N#Cc1ccccc1-c1cccc(N(c2ccccc2)c2ccc3c(ccc4cc5oc6ccccc6c5cc43)c2)c1 ; N#Cc1ccccc1-c1cccc(N(c2ccc3c(ccc4cc5oc6ccccc6c5cc43)c2)c2ccccc2-c2ccccc2)c1] 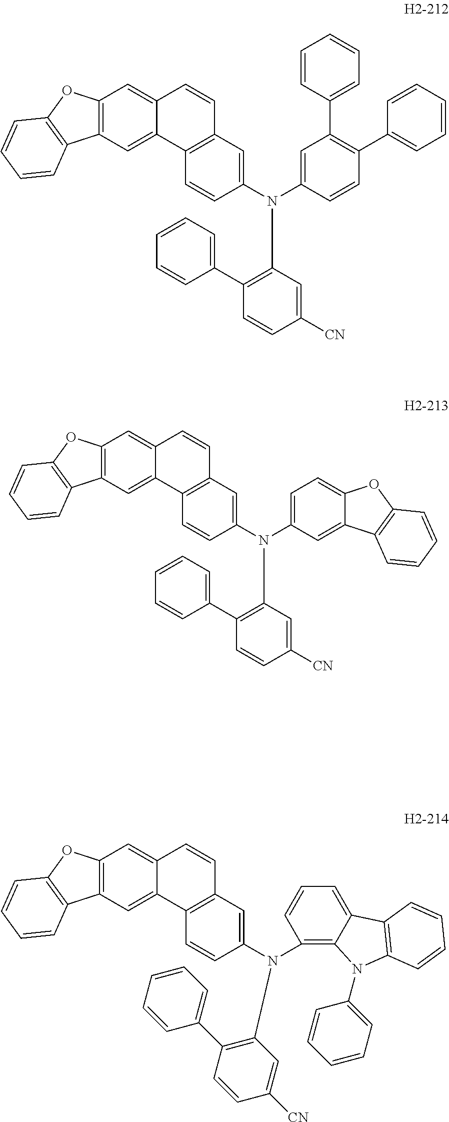 [SMILES: N#Cc1ccc(-c2ccccc2)c(N(c2ccc(-c3ccccc3)c(-c3ccccc3)c2)c2ccc3c(ccc4cc5oc6ccccc6c5cc43)c2)c1 ; N#Cc1ccc(-c2ccccc2)c(N(c2ccc3c(ccc4cc5oc6ccccc6c5cc43)c2)c2ccc3oc4ccccc4c3c2)c1 ; N#Cc1ccc(-c2ccccc2)c(N(c2ccc3c(ccc4cc5oc6ccccc6c5cc43)c2)c2cccc3c4ccccc4n(-c4ccccc4)c23)c1] 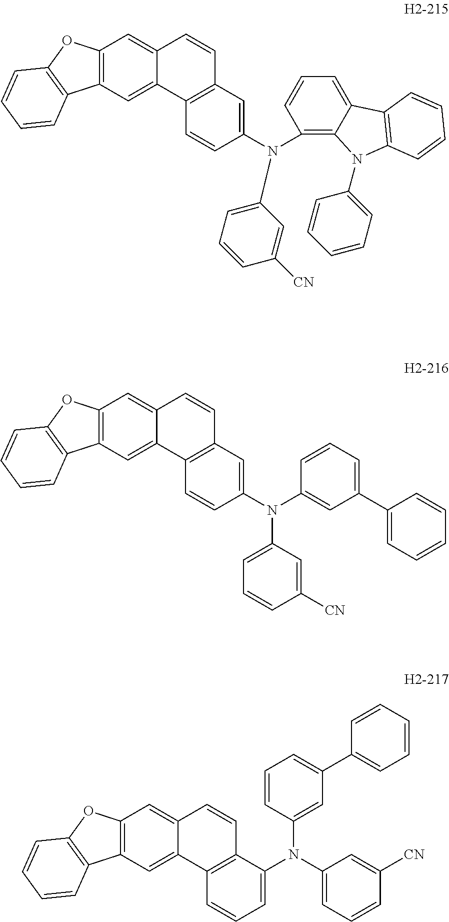 [SMILES: N#Cc1cccc(N(c2ccc3c(ccc4cc5oc6ccccc6c5cc43)c2)c2cccc3c4ccccc4n(-c4ccccc4)c23)c1 ; N#Cc1cccc(N(c2cccc(-c3ccccc3)c2)c2ccc3c(ccc4cc5oc6ccccc6c5cc43)c2)c1 ; N#Cc1cccc(N(c2cccc(-c3ccccc3)c2)c2cccc3c2ccc2cc4oc5ccccc5c4cc23)c1] 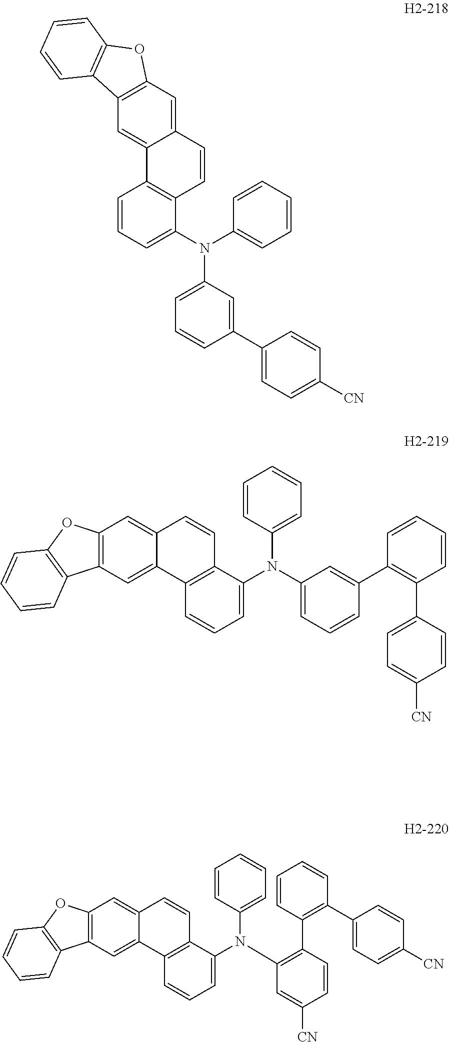 [SMILES: N#Cc1ccc(-c2cccc(N(c3ccccc3)c3cccc4c3ccc3cc5oc6ccccc6c5cc34)c2)cc1 ; N#Cc1ccc(-c2ccccc2-c2cccc(N(c3ccccc3)c3cccc4c3ccc3cc5oc6ccccc6c5cc34)c2)cc1 ; N#Cc1ccc(-c2ccccc2-c2ccc(C#N)cc2N(c2ccccc2)c2cccc3c2ccc2cc4oc5ccccc5c4cc23)cc1] 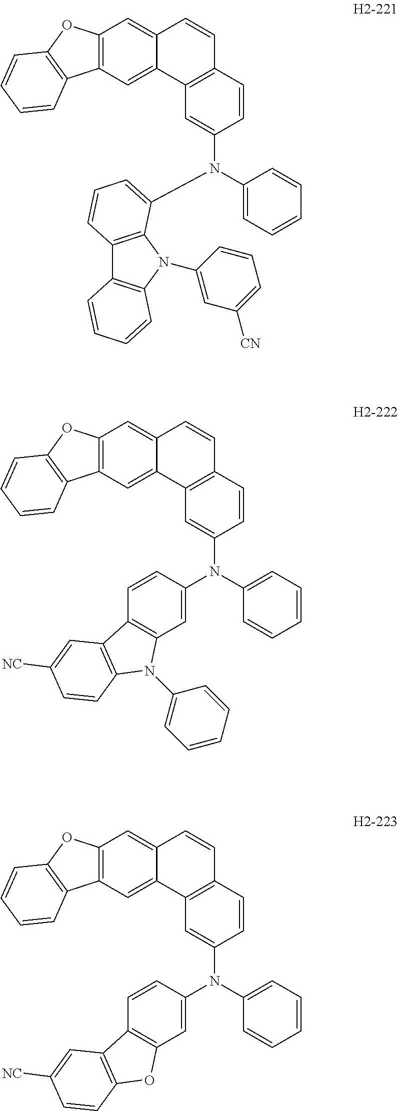 [SMILES: N#Cc1cccc(-n2c3ccccc3c3cccc(N(c4ccccc4)c4ccc5ccc6cc7oc8ccccc8c7cc6c5c4)c32)c1 ; N#Cc1ccc2c(c1)c1ccc(N(c3ccccc3)c3ccc4ccc5cc6oc7ccccc7c6cc5c4c3)cc1n2-c1ccccc1 ; N#Cc1ccc2oc3cc(N(c4ccccc4)c4ccc5ccc6cc7oc8ccccc8c7cc6c5c4)ccc3c2c1] 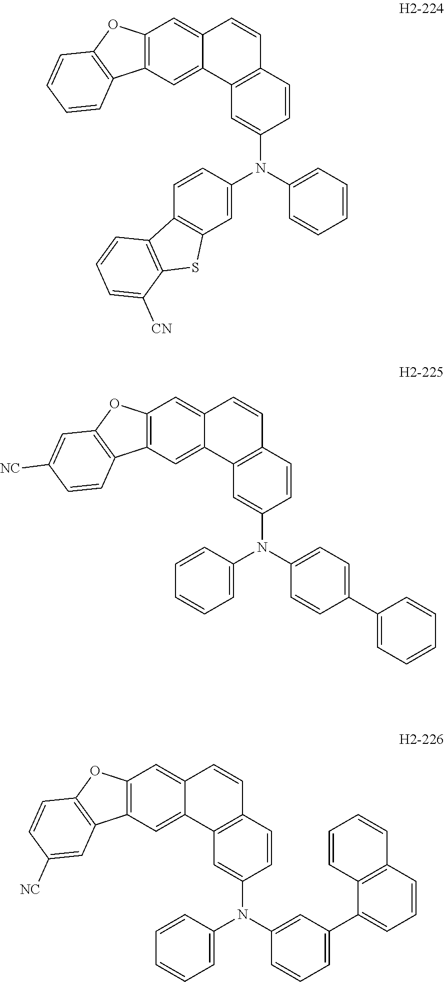 [SMILES: N#Cc1cccc2c1sc1cc(N(c3ccccc3)c3ccc4ccc5cc6oc7ccccc7c6cc5c4c3)ccc12 ; N#Cc1ccc2c(c1)oc1cc3ccc4ccc(N(c5ccccc5)c5ccc(-c6ccccc6)cc5)cc4c3cc12 ; N#Cc1ccc2oc3cc4ccc5ccc(N(c6ccccc6)c6cccc(-c7cccc8ccccc78)c6)cc5c4cc3c2c1] 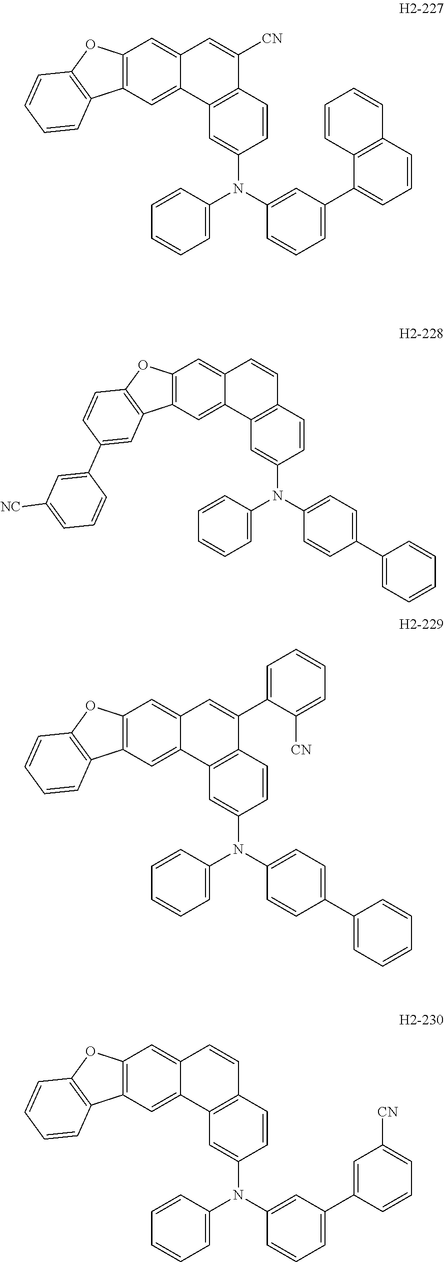 [SMILES: N#Cc1cc2cc3oc4ccccc4c3cc2c2cc(N(c3ccccc3)c3cccc(-c4cccc5ccccc45)c3)ccc12 ; N#Cc1cccc(-c2ccc3oc4cc5ccc6ccc(N(c7ccccc7)c7ccc(-c8ccccc8)cc7)cc6c5cc4c3c2)c1 ; N#Cc1ccccc1-c1cc2cc3oc4ccccc4c3cc2c2cc(N(c3ccccc3)c3ccc(-c4ccccc4)cc3)ccc12 ; N#Cc1cccc(-c2cccc(N(c3ccccc3)c3ccc4ccc5cc6oc7ccccc7c6cc5c4c3)c2)c1] 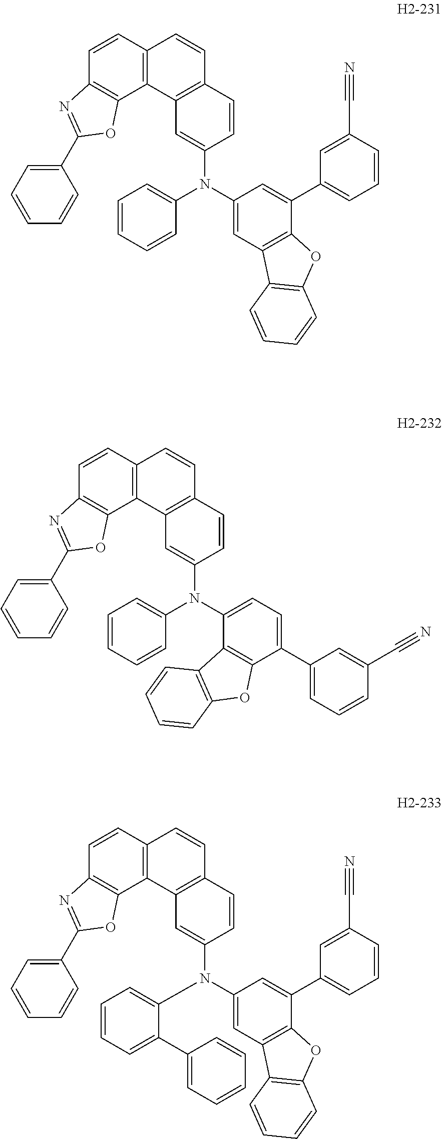 [SMILES: N#Cc1cccc(-c2cc(N(c3ccccc3)c3ccc4ccc5ccc6nc(-c7ccccc7)oc6c5c4c3)cc3c2oc2ccccc23)c1 ; N#Cc1cccc(-c2ccc(N(c3ccccc3)c3ccc4ccc5ccc6nc(-c7ccccc7)oc6c5c4c3)c3c2oc2ccccc23)c1 ; N#Cc1cccc(-c2cc(N(c3ccc4ccc5ccc6nc(-c7ccccc7)oc6c5c4c3)c3ccccc3-c3ccccc3)cc3c2oc2ccccc23)c1] 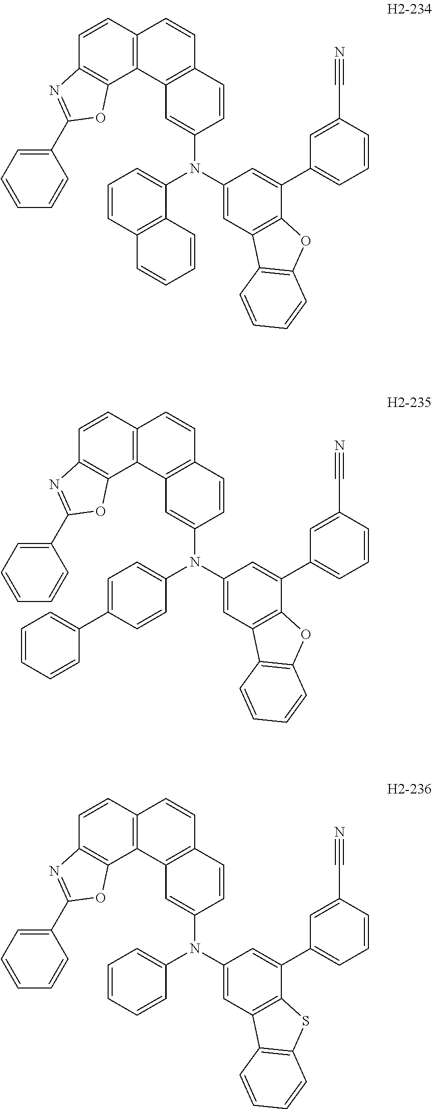 [SMILES: N#Cc1cccc(-c2cc(N(c3ccc4ccc5ccc6nc(-c7ccccc7)oc6c5c4c3)c3cccc4ccccc34)cc3c2oc2ccccc23)c1 ; N#Cc1cccc(-c2cc(N(c3ccc(-c4ccccc4)cc3)c3ccc4ccc5ccc6nc(-c7ccccc7)oc6c5c4c3)cc3c2oc2ccccc23)c1 ; N#Cc1cccc(-c2cc(N(c3ccccc3)c3ccc4ccc5ccc6nc(-c7ccccc7)oc6c5c4c3)cc3c2sc2ccccc23)c1] 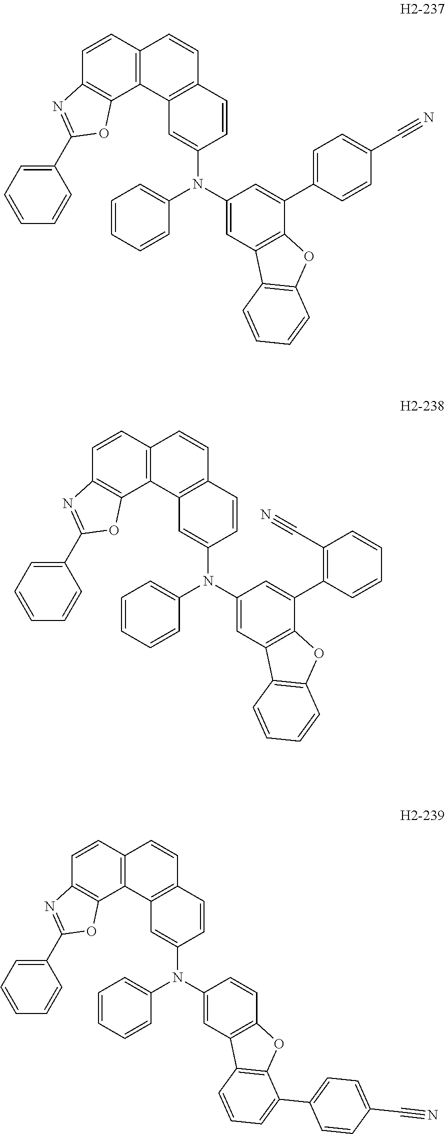 [SMILES: N#Cc1ccc(-c2cc(N(c3ccccc3)c3ccc4ccc5ccc6nc(-c7ccccc7)oc6c5c4c3)cc3c2oc2ccccc23)cc1 ; N#Cc1ccccc1-c1cc(N(c2ccccc2)c2ccc3ccc4ccc5nc(-c6ccccc6)oc5c4c3c2)cc2c1oc1ccccc12 ; N#Cc1ccc(-c2cccc3c2oc2ccc(N(c4ccccc4)c4ccc5ccc6ccc7nc(-c8ccccc8)oc7c6c5c4)cc23)cc1] 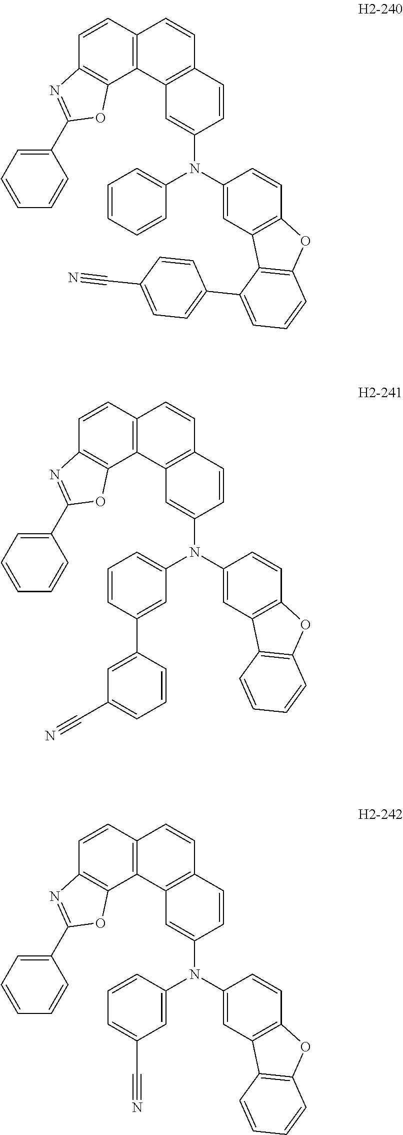 [SMILES: N#Cc1ccc(-c2cccc3oc4ccc(N(c5ccccc5)c5ccc6ccc7ccc8nc(-c9ccccc9)oc8c7c6c5)cc4c23)cc1 ; N#Cc1cccc(-c2cccc(N(c3ccc4oc5ccccc5c4c3)c3ccc4ccc5ccc6nc(-c7ccccc7)oc6c5c4c3)c2)c1 ; N#Cc1cccc(N(c2ccc3oc4ccccc4c3c2)c2ccc3ccc4ccc5nc(-c6ccccc6)oc5c4c3c2)c1] 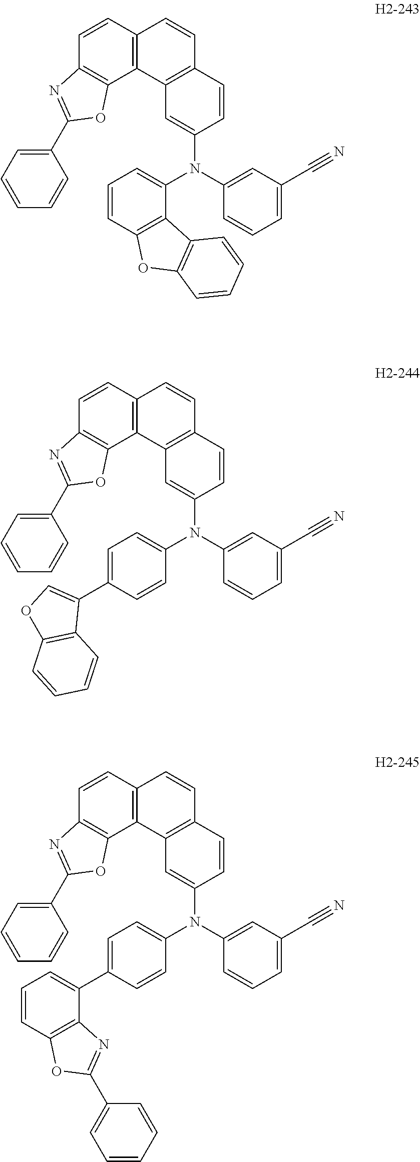 [SMILES: N#Cc1cccc(N(c2ccc3ccc4ccc5nc(-c6ccccc6)oc5c4c3c2)c2cccc3oc4ccccc4c23)c1 ; N#Cc1cccc(N(c2ccc(-c3coc4ccccc34)cc2)c2ccc3ccc4ccc5nc(-c6ccccc6)oc5c4c3c2)c1 ; N#Cc1cccc(N(c2ccc(-c3cccc4oc(-c5ccccc5)nc34)cc2)c2ccc3ccc4ccc5nc(-c6ccccc6)oc5c4c3c2)c1] 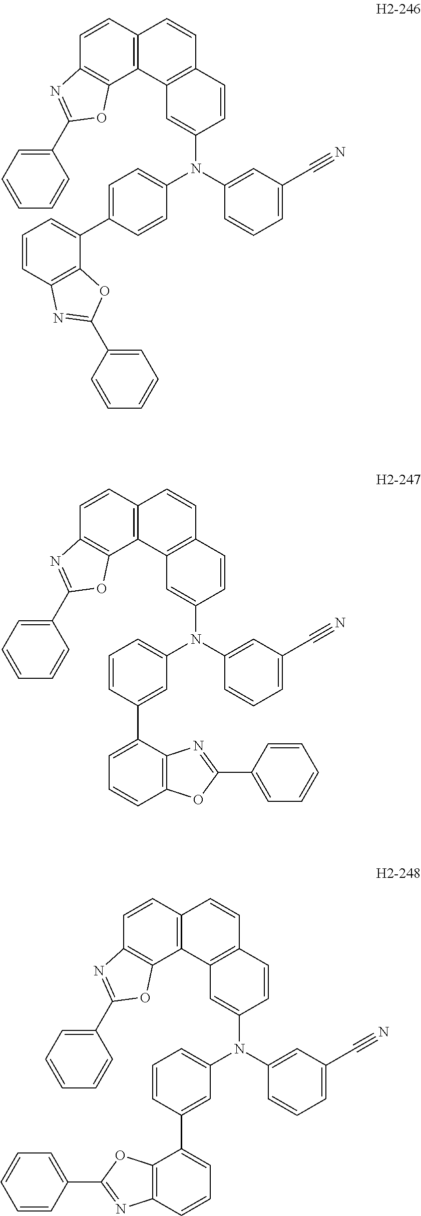 [SMILES: N#Cc1cccc(N(c2ccc(-c3cccc4nc(-c5ccccc5)oc34)cc2)c2ccc3ccc4ccc5nc(-c6ccccc6)oc5c4c3c2)c1 ; N#Cc1cccc(N(c2cccc(-c3cccc4oc(-c5ccccc5)nc34)c2)c2ccc3ccc4ccc5nc(-c6ccccc6)oc5c4c3c2)c1 ; N#Cc1cccc(N(c2cccc(-c3cccc4nc(-c5ccccc5)oc34)c2)c2ccc3ccc4ccc5nc(-c6ccccc6)oc5c4c3c2)c1] 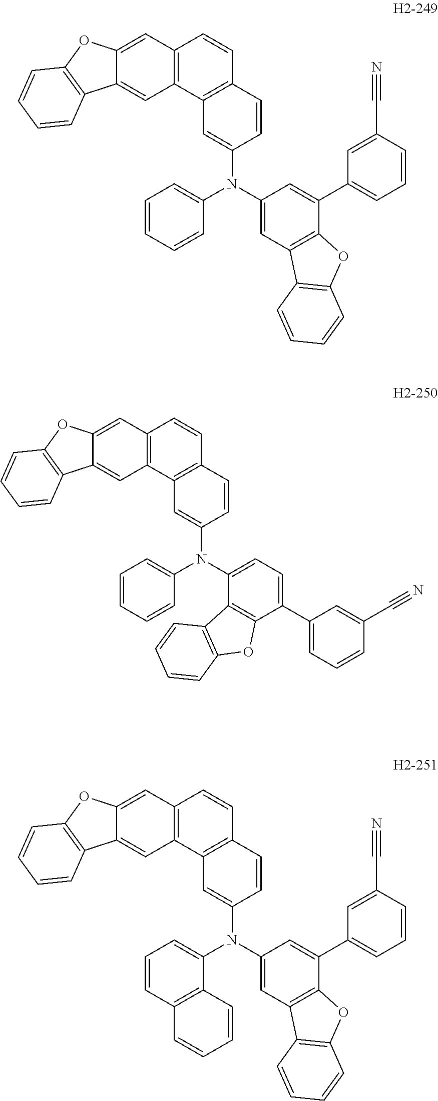 [SMILES: N#Cc1cccc(-c2cc(N(c3ccccc3)c3ccc4ccc5cc6oc7ccccc7c6cc5c4c3)cc3c2oc2ccccc23)c1 ; N#Cc1cccc(-c2ccc(N(c3ccccc3)c3ccc4ccc5cc6oc7ccccc7c6cc5c4c3)c3c2oc2ccccc23)c1 ; N#Cc1cccc(-c2cc(N(c3ccc4ccc5cc6oc7ccccc7c6cc5c4c3)c3cccc4ccccc34)cc3c2oc2ccccc23)c1] 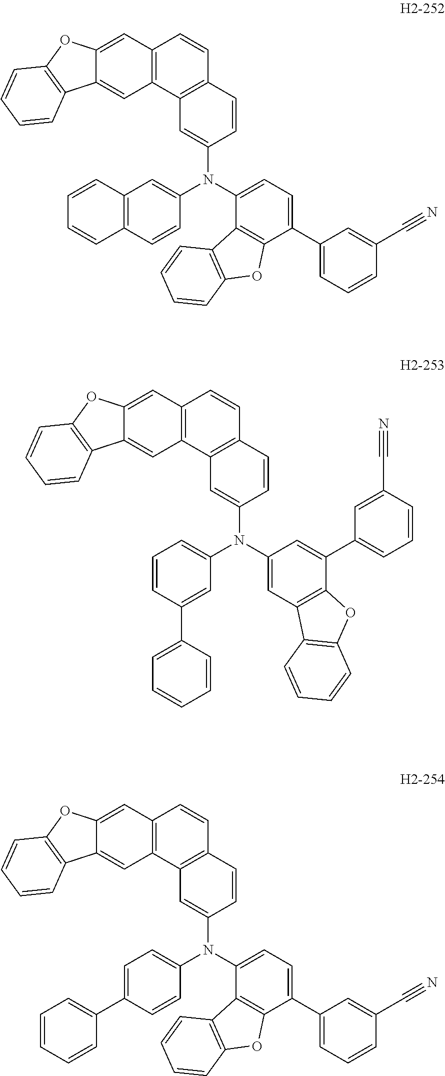 [SMILES: N#Cc1cccc(-c2ccc(N(c3ccc4ccccc4c3)c3ccc4ccc5cc6oc7ccccc7c6cc5c4c3)c3c2oc2ccccc23)c1 ; N#Cc1cccc(-c2cc(N(c3cccc(-c4ccccc4)c3)c3ccc4ccc5cc6oc7ccccc7c6cc5c4c3)cc3c2oc2ccccc23)c1 ; N#Cc1cccc(-c2ccc(N(c3ccc(-c4ccccc4)cc3)c3ccc4ccc5cc6oc7ccccc7c6cc5c4c3)c3c2oc2ccccc23)c1] 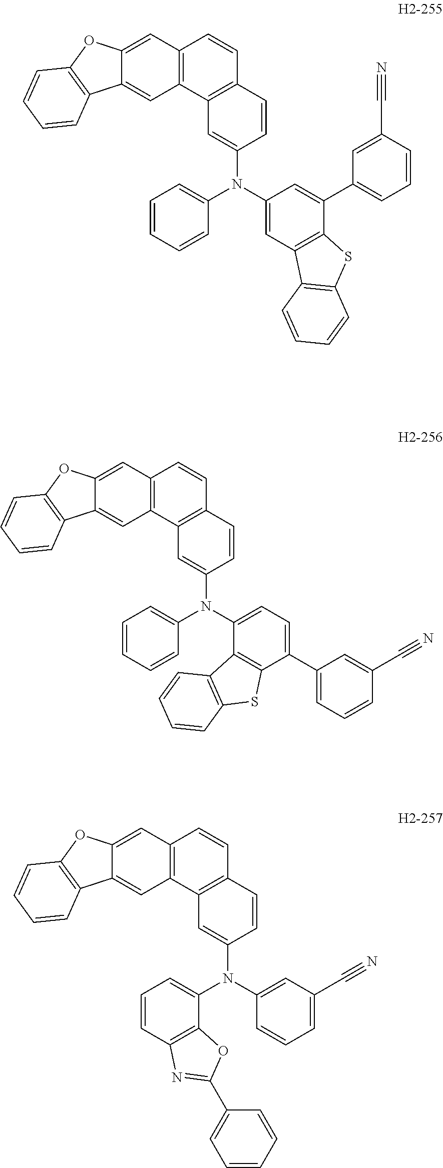 [SMILES: N#Cc1cccc(-c2cc(N(c3ccccc3)c3ccc4ccc5cc6oc7ccccc7c6cc5c4c3)cc3c2sc2ccccc23)c1 ; N#Cc1cccc(-c2ccc(N(c3ccccc3)c3ccc4ccc5cc6oc7ccccc7c6cc5c4c3)c3c2sc2ccccc23)c1 ; N#Cc1cccc(N(c2ccc3ccc4cc5oc6ccccc6c5cc4c3c2)c2cccc3nc(-c4ccccc4)oc23)c1] 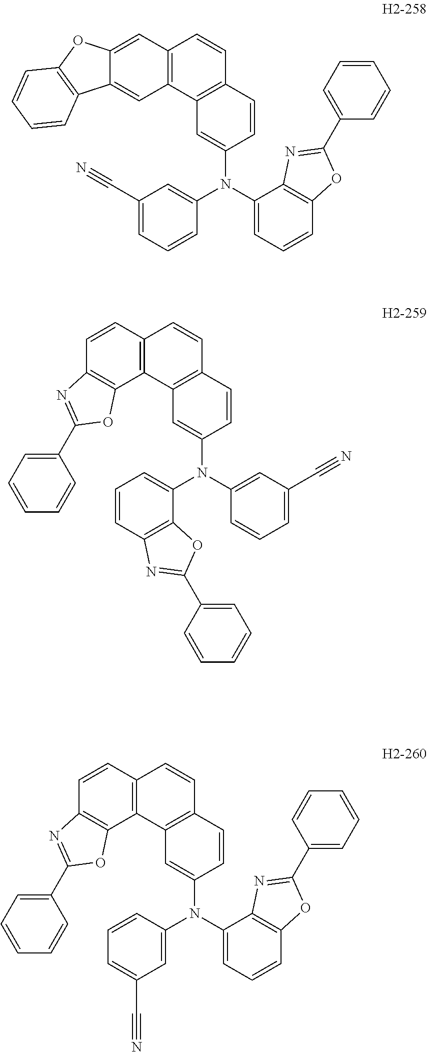 [SMILES: N#Cc1cccc(N(c2ccc3ccc4cc5oc6ccccc6c5cc4c3c2)c2cccc3oc(-c4ccccc4)nc23)c1 ; N#Cc1cccc(N(c2ccc3ccc4ccc5nc(-c6ccccc6)oc5c4c3c2)c2cccc3nc(-c4ccccc4)oc23)c1 ; N#Cc1cccc(N(c2ccc3ccc4ccc5nc(-c6ccccc6)oc5c4c3c2)c2cccc3oc(-c4ccccc4)nc23)c1] 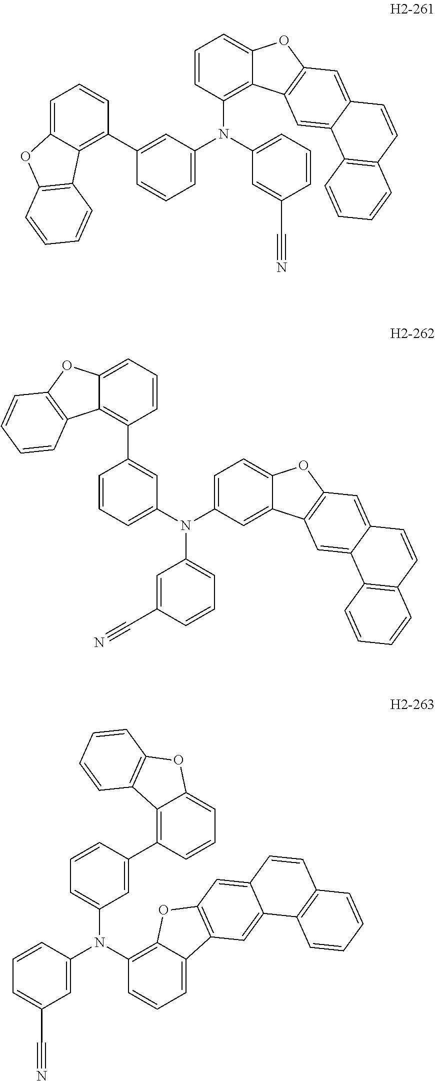 [SMILES: N#Cc1cccc(N(c2cccc(-c3cccc4oc5ccccc5c34)c2)c2cccc3oc4cc5ccc6ccccc6c5cc4c23)c1 ; N#Cc1cccc(N(c2cccc(-c3cccc4oc5ccccc5c34)c2)c2ccc3oc4cc5ccc6ccccc6c5cc4c3c2)c1 ; N#Cc1cccc(N(c2cccc(-c3cccc4oc5ccccc5c34)c2)c2cccc3c2oc2cc4ccc5ccccc5c4cc23)c1] 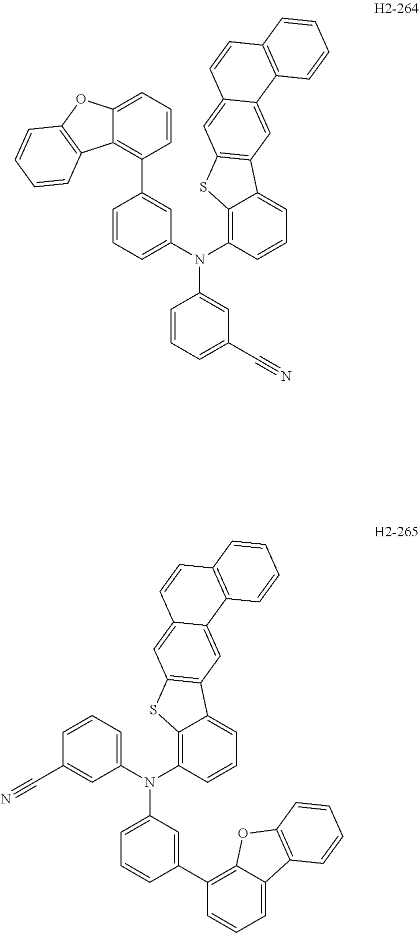 [SMILES: N#Cc1cccc(N(c2cccc(-c3cccc4oc5ccccc5c34)c2)c2cccc3c2sc2cc4ccc5ccccc5c4cc23)c1 ; N#Cc1cccc(N(c2cccc(-c3cccc4c3oc3ccccc34)c2)c2cccc3c2sc2cc4ccc5ccccc5c4cc23)c1] 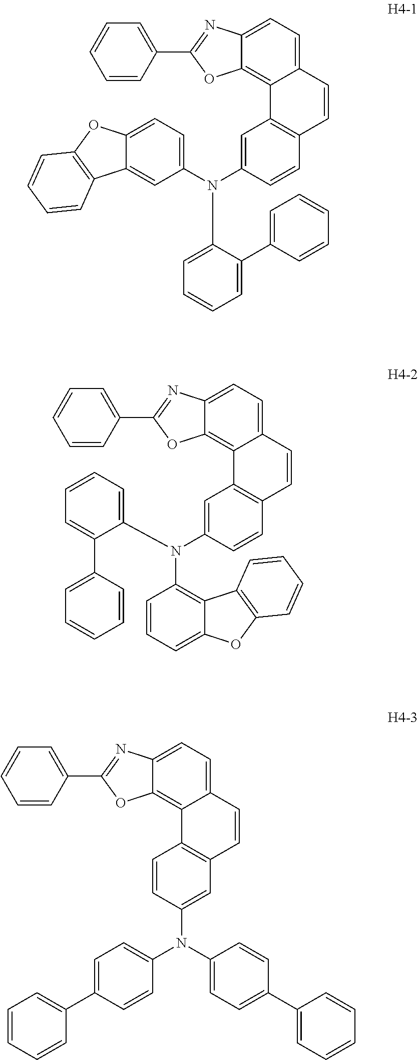 [SMILES: c1ccc(-c2nc3ccc4ccc5ccc(N(c6ccc7oc8ccccc8c7c6)c6ccccc6-c6ccccc6)cc5c4c3o2)cc1 ; c1ccc(-c2nc3ccc4ccc5ccc(N(c6ccccc6-c6ccccc6)c6cccc7oc8ccccc8c67)cc5c4c3o2)cc1 ; c1ccc(-c2ccc(N(c3ccc(-c4ccccc4)cc3)c3ccc4c(ccc5ccc6nc(-c7ccccc7)oc6c54)c3)cc2)cc1] 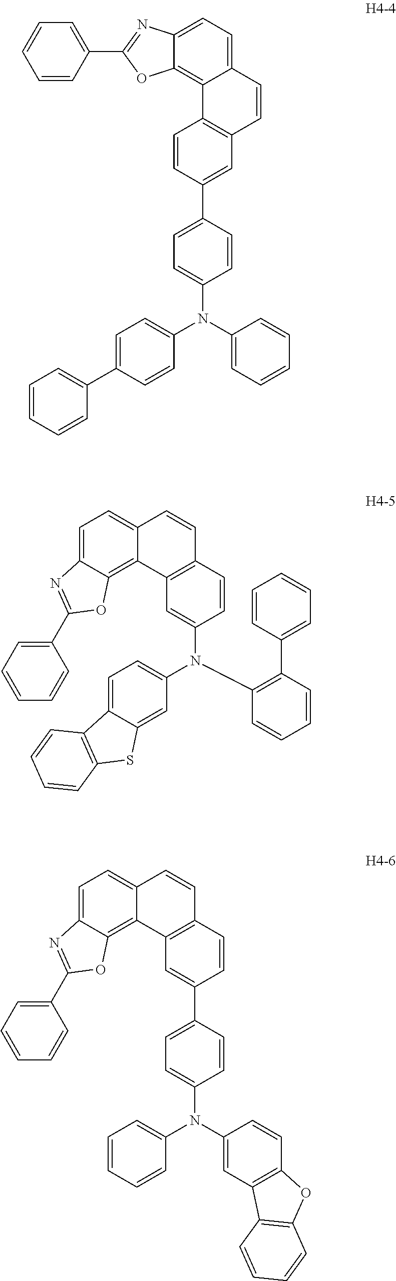 [SMILES: c1ccc(-c2ccc(N(c3ccccc3)c3ccc(-c4ccc5c(ccc6ccc7nc(-c8ccccc8)oc7c65)c4)cc3)cc2)cc1 ; c1ccc(-c2nc3ccc4ccc5ccc(N(c6ccc7c(c6)sc6ccccc67)c6ccccc6-c6ccccc6)cc5c4c3o2)cc1 ; c1ccc(-c2nc3ccc4ccc5ccc(-c6ccc(N(c7ccccc7)c7ccc8oc9ccccc9c8c7)cc6)cc5c4c3o2)cc1] 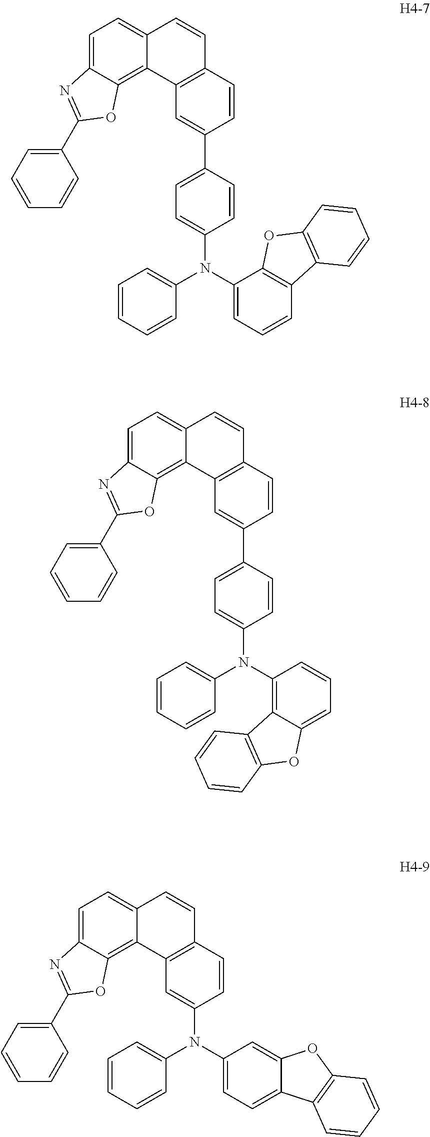 [SMILES: c1ccc(-c2nc3ccc4ccc5ccc(-c6ccc(N(c7ccccc7)c7cccc8c7oc7ccccc78)cc6)cc5c4c3o2)cc1 ; c1ccc(-c2nc3ccc4ccc5ccc(-c6ccc(N(c7ccccc7)c7cccc8oc9ccccc9c78)cc6)cc5c4c3o2)cc1 ; c1ccc(-c2nc3ccc4ccc5ccc(N(c6ccccc6)c6ccc7c(c6)oc6ccccc67)cc5c4c3o2)cc1] 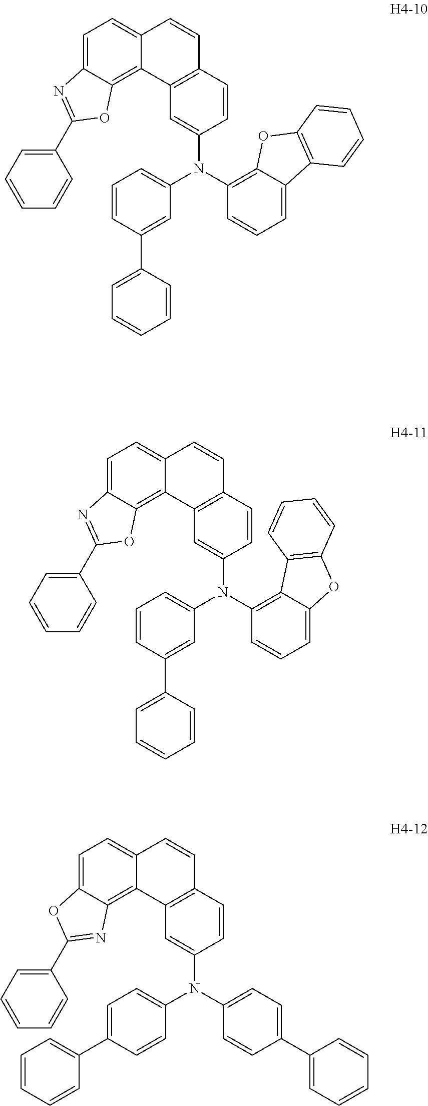 [SMILES: c1ccc(-c2cccc(N(c3ccc4ccc5ccc6nc(-c7ccccc7)oc6c5c4c3)c3cccc4c3oc3ccccc34)c2)cc1 ; c1ccc(-c2cccc(N(c3ccc4ccc5ccc6nc(-c7ccccc7)oc6c5c4c3)c3cccc4oc5ccccc5c34)c2)cc1 ; c1ccc(-c2ccc(N(c3ccc(-c4ccccc4)cc3)c3ccc4ccc5ccc6oc(-c7ccccc7)nc6c5c4c3)cc2)cc1] 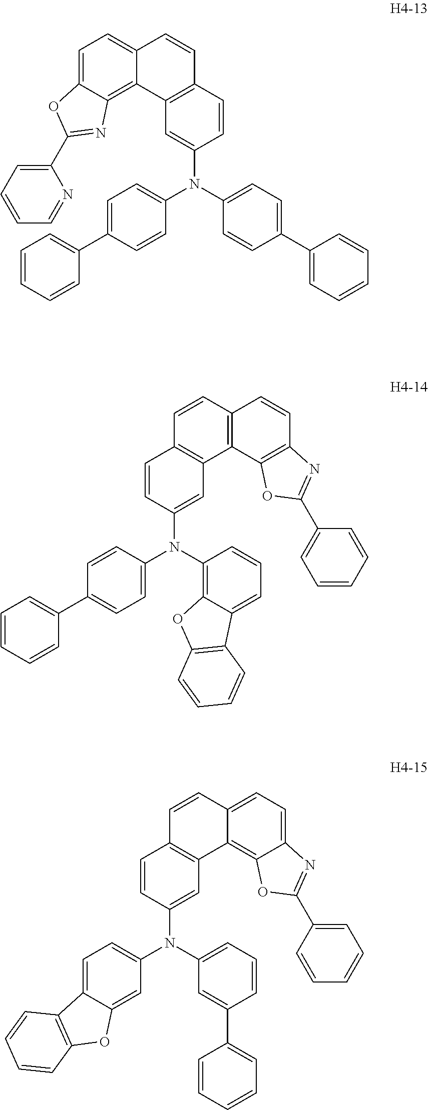 [SMILES: c1ccc(-c2ccc(N(c3ccc(-c4ccccc4)cc3)c3ccc4ccc5ccc6oc(-c7ccccn7)nc6c5c4c3)cc2)cc1 ; c1ccc(-c2ccc(N(c3ccc4ccc5ccc6nc(-c7ccccc7)oc6c5c4c3)c3cccc4c3oc3ccccc34)cc2)cc1 ; c1ccc(-c2cccc(N(c3ccc4c(c3)oc3ccccc34)c3ccc4ccc5ccc6nc(-c7ccccc7)oc6c5c4c3)c2)cc1] 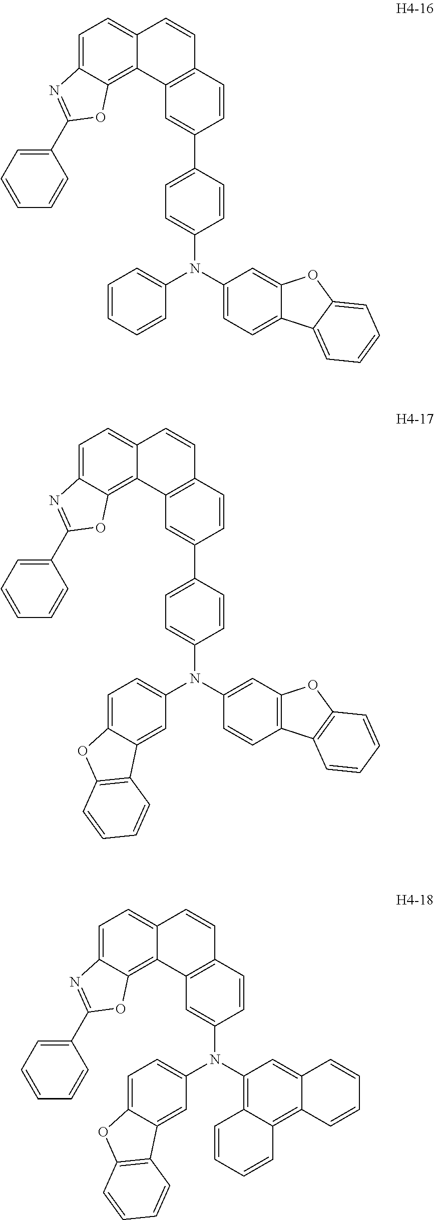 [SMILES: c1ccc(-c2nc3ccc4ccc5ccc(-c6ccc(N(c7ccccc7)c7ccc8c(c7)oc7ccccc78)cc6)cc5c4c3o2)cc1 ; c1ccc(-c2nc3ccc4ccc5ccc(-c6ccc(N(c7ccc8c(c7)oc7ccccc78)c7ccc8oc9ccccc9c8c7)cc6)cc5c4c3o2)cc1 ; c1ccc(-c2nc3ccc4ccc5ccc(N(c6ccc7oc8ccccc8c7c6)c6cc7ccccc7c7ccccc67)cc5c4c3o2)cc1] 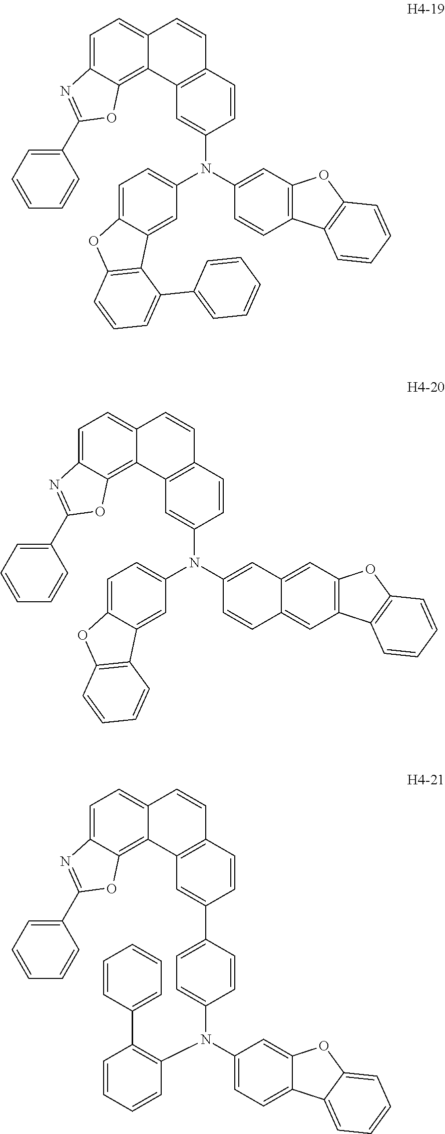 [SMILES: c1ccc(-c2nc3ccc4ccc5ccc(N(c6ccc7c(c6)oc6ccccc67)c6ccc7oc8cccc(-c9ccccc9)c8c7c6)cc5c4c3o2)cc1 ; c1ccc(-c2nc3ccc4ccc5ccc(N(c6ccc7cc8c(cc7c6)oc6ccccc68)c6ccc7oc8ccccc8c7c6)cc5c4c3o2)cc1 ; c1ccc(-c2nc3ccc4ccc5ccc(-c6ccc(N(c7ccc8c(c7)oc7ccccc78)c7ccccc7-c7ccccc7)cc6)cc5c4c3o2)cc1] 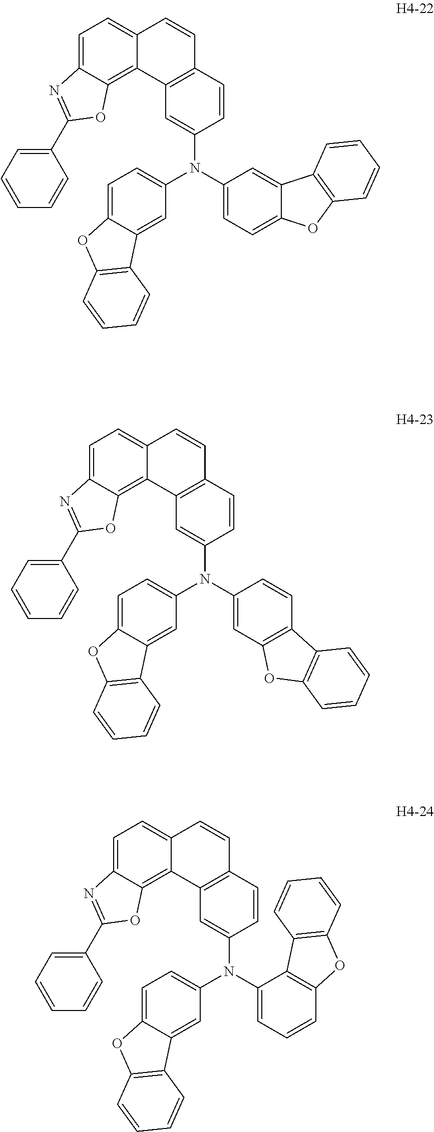 [SMILES: c1ccc(-c2nc3ccc4ccc5ccc(N(c6ccc7oc8ccccc8c7c6)c6ccc7oc8ccccc8c7c6)cc5c4c3o2)cc1 ; c1ccc(-c2nc3ccc4ccc5ccc(N(c6ccc7c(c6)oc6ccccc67)c6ccc7oc8ccccc8c7c6)cc5c4c3o2)cc1 ; c1ccc(-c2nc3ccc4ccc5ccc(N(c6ccc7oc8ccccc8c7c6)c6cccc7oc8ccccc8c67)cc5c4c3o2)cc1] 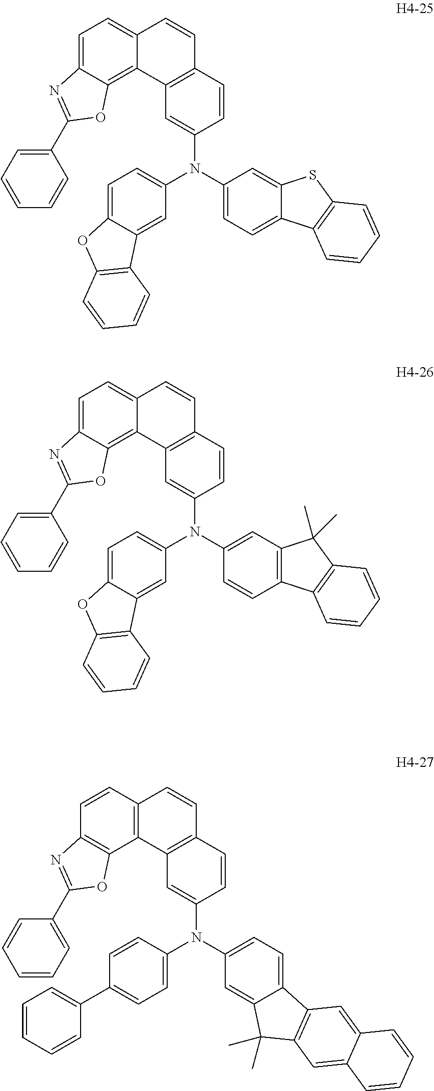 [SMILES: c1ccc(-c2nc3ccc4ccc5ccc(N(c6ccc7c(c6)sc6ccccc67)c6ccc7oc8ccccc8c7c6)cc5c4c3o2)cc1 ; CC1(C)c2ccccc2-c2ccc(N(c3ccc4oc5ccccc5c4c3)c3ccc4ccc5ccc6nc(-c7ccccc7)oc6c5c4c3)cc21 ; CC1(C)c2cc(N(c3ccc(-c4ccccc4)cc3)c3ccc4ccc5ccc6nc(-c7ccccc7)oc6c5c4c3)ccc2-c2cc3ccccc3cc21] 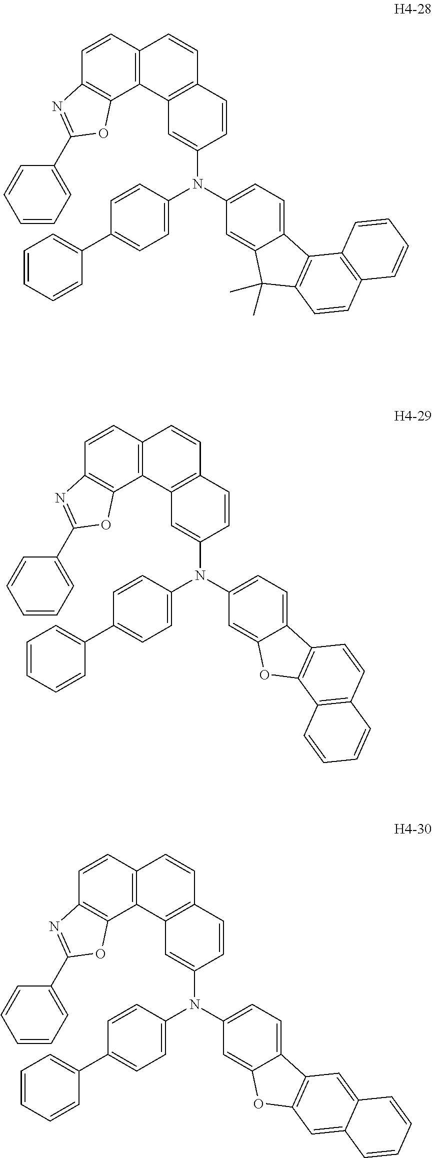 [SMILES: CC1(C)c2cc(N(c3ccc(-c4ccccc4)cc3)c3ccc4ccc5ccc6nc(-c7ccccc7)oc6c5c4c3)ccc2-c2c1ccc1ccccc21 ; c1ccc(-c2ccc(N(c3ccc4c(c3)oc3c5ccccc5ccc43)c3ccc4ccc5ccc6nc(-c7ccccc7)oc6c5c4c3)cc2)cc1 ; c1ccc(-c2ccc(N(c3ccc4c(c3)oc3cc5ccccc5cc34)c3ccc4ccc5ccc6nc(-c7ccccc7)oc6c5c4c3)cc2)cc1] 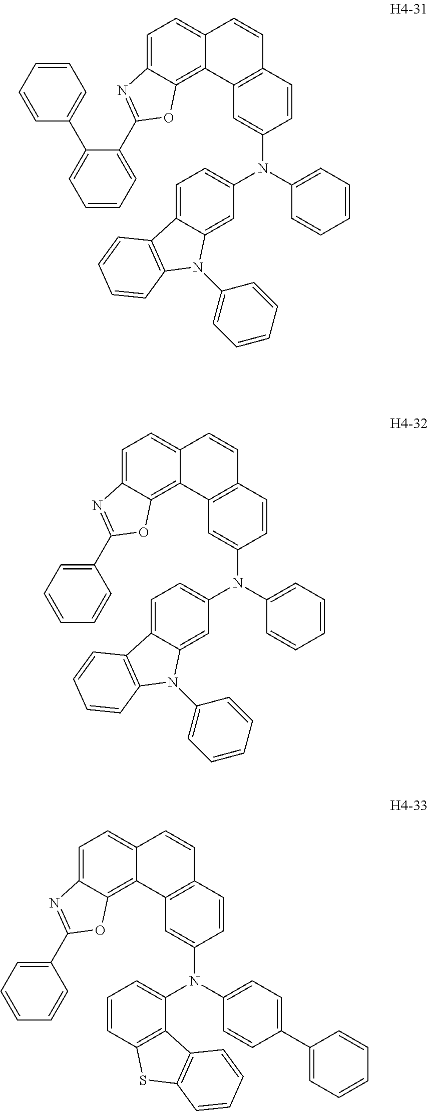 [SMILES: c1ccc(-c2ccccc2-c2nc3ccc4ccc5ccc(N(c6ccccc6)c6ccc7c8ccccc8n(-c8ccccc8)c7c6)cc5c4c3o2)cc1 ; c1ccc(-c2nc3ccc4ccc5ccc(N(c6ccccc6)c6ccc7c8ccccc8n(-c8ccccc8)c7c6)cc5c4c3o2)cc1 ; c1ccc(-c2ccc(N(c3ccc4ccc5ccc6nc(-c7ccccc7)oc6c5c4c3)c3cccc4sc5ccccc5c34)cc2)cc1] 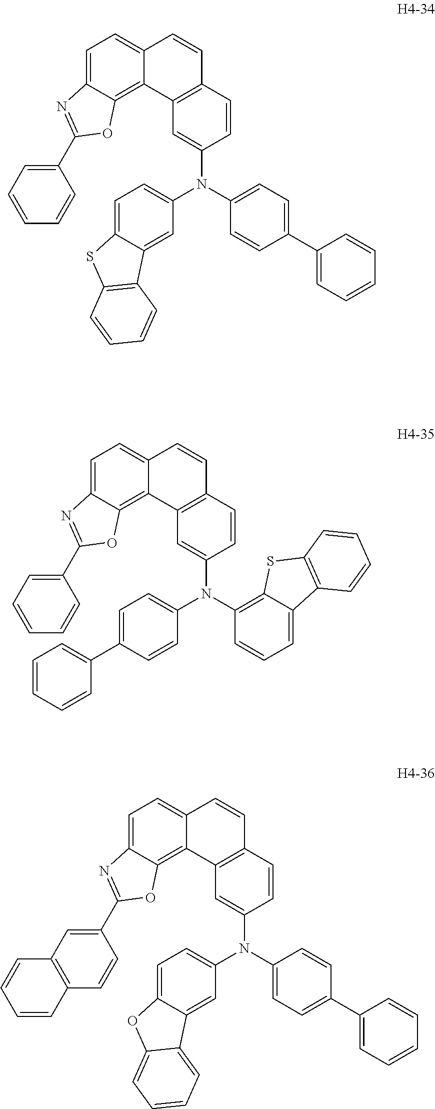 [SMILES: c1ccc(-c2ccc(N(c3ccc4sc5ccccc5c4c3)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4c3sc3ccccc34)cc2)cc1 ; c1ccc(-c2ccc(N(c3ccc4oc5ccccc5c4c3)c3ccc4ccc5ccc6nc(-c7ccc8ccccc8c7)oc6c5c4c3)cc2)cc1] 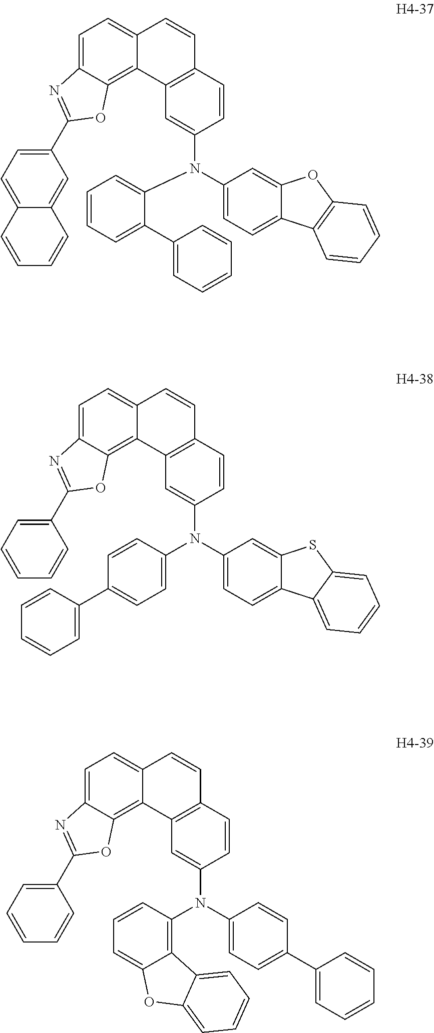 [SMILES: c1ccc(-c2ccccc2N(c2ccc3c(c2)oc2ccccc23)c2ccc3ccc4ccc5nc(-c6ccc7ccccc7c6)oc5c4c3c2)cc1 ; c1ccc(-c2ccc(N(c3ccc4c(c3)sc3ccccc34)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4oc5ccccc5c34)cc2)cc1] 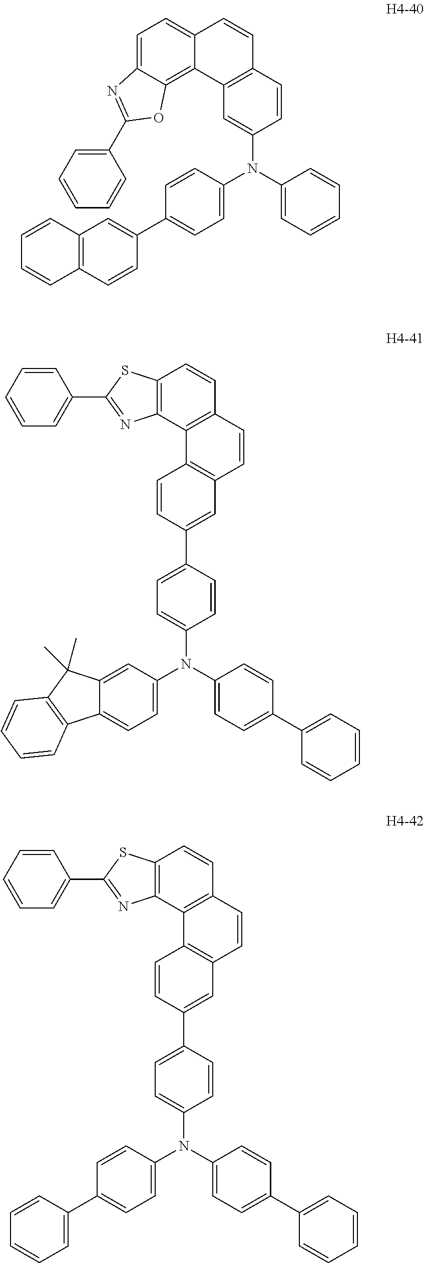 [SMILES: c1ccc(-c2nc3ccc4ccc5ccc(N(c6ccccc6)c6ccc(-c7ccc8ccccc8c7)cc6)cc5c4c3o2)cc1 ; CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21 ; c1ccc(-c2ccc(N(c3ccc(-c4ccccc4)cc3)c3ccc(-c4ccc5c(ccc6ccc7sc(-c8ccccc8)nc7c65)c4)cc3)cc2)cc1] 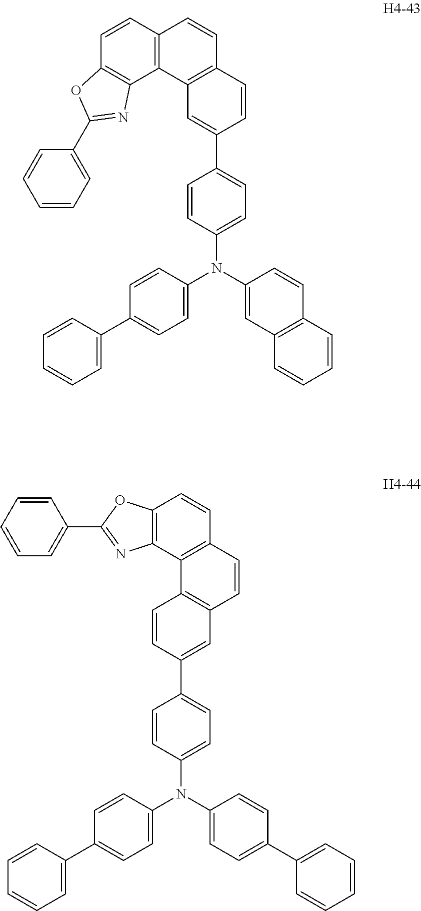 [SMILES: c1ccc(-c2ccc(N(c3ccc(-c4ccc5ccc6ccc7oc(-c8ccccc8)nc7c6c5c4)cc3)c3ccc4ccccc4c3)cc2)cc1 ; c1ccc(-c2ccc(N(c3ccc(-c4ccccc4)cc3)c3ccc(-c4ccc5c(ccc6ccc7oc(-c8ccccc8)nc7c65)c4)cc3)cc2)cc1] 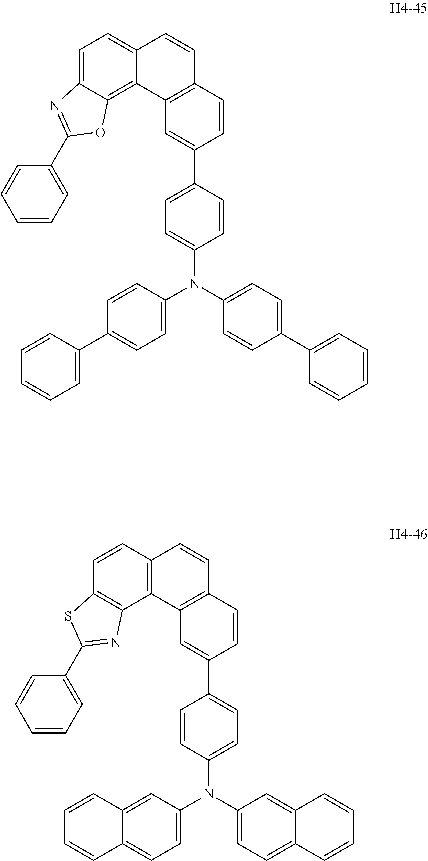 [SMILES: c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2nc3c(ccc4ccc5ccc(-c6ccc(N(c7ccc8ccccc8c7)c7ccc8ccccc8c7)cc6)cc5c43)s2)cc1] 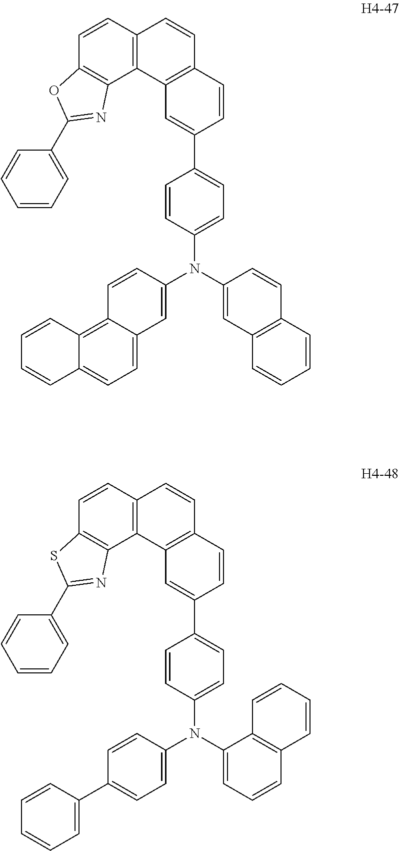 [SMILES: c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2ccc(N(c3ccc(-c4ccc5ccc6ccc7sc(-c8ccccc8)nc7c6c5c4)cc3)c3cccc4ccccc34)cc2)cc1] 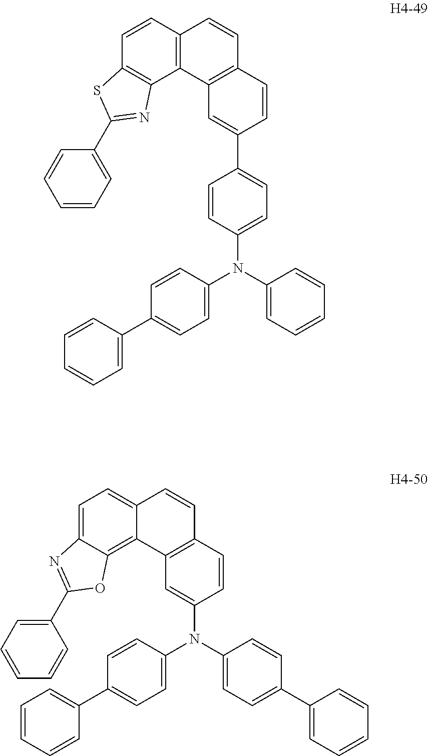 [SMILES: c1ccc(-c2ccc(N(c3ccccc3)c3ccc(-c4ccc5ccc6ccc7sc(-c8ccccc8)nc7c6c5c4)cc3)cc2)cc1 ; c1ccc(-c2ccc(N(c3ccc(-c4ccccc4)cc3)c3ccc4ccc5ccc6nc(-c7ccccc7)oc6c5c4c3)cc2)cc1] 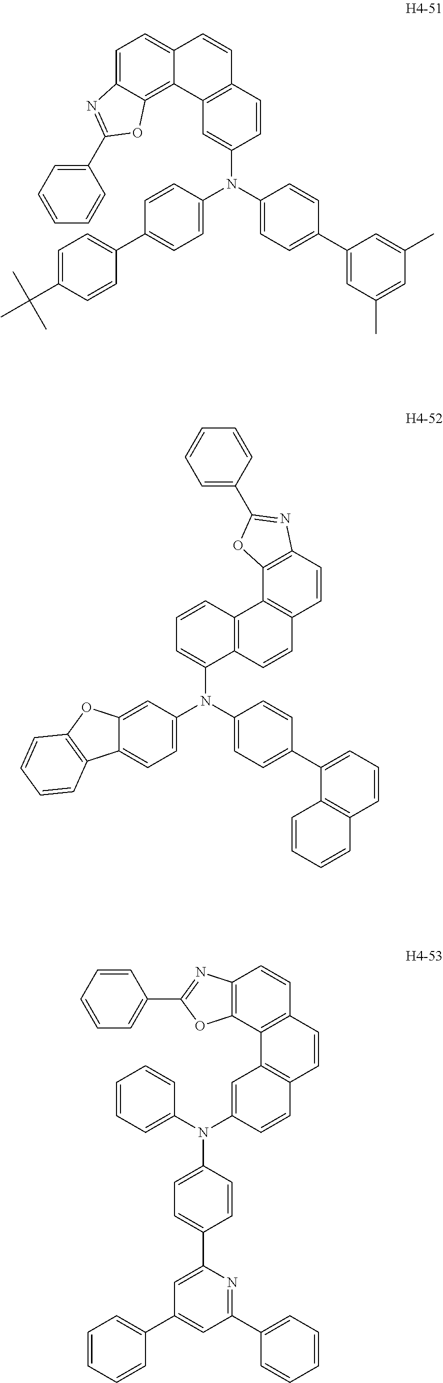 [SMILES: Cc1cc(C)cc(-c2ccc(N(c3ccc(-c4ccc(C(C)(C)C)cc4)cc3)c3ccc4ccc5ccc6nc(-c7ccccc7)oc6c5c4c3)cc2)c1 ; c1ccc(-c2nc3ccc4ccc5c(N(c6ccc(-c7cccc8ccccc78)cc6)c6ccc7c(c6)oc6ccccc67)cccc5c4c3o2)cc1 ; c1ccc(-c2cc(-c3ccccc3)nc(-c3ccc(N(c4ccccc4)c4ccc5ccc6ccc7nc(-c8ccccc8)oc7c6c5c4)cc3)c2)cc1] 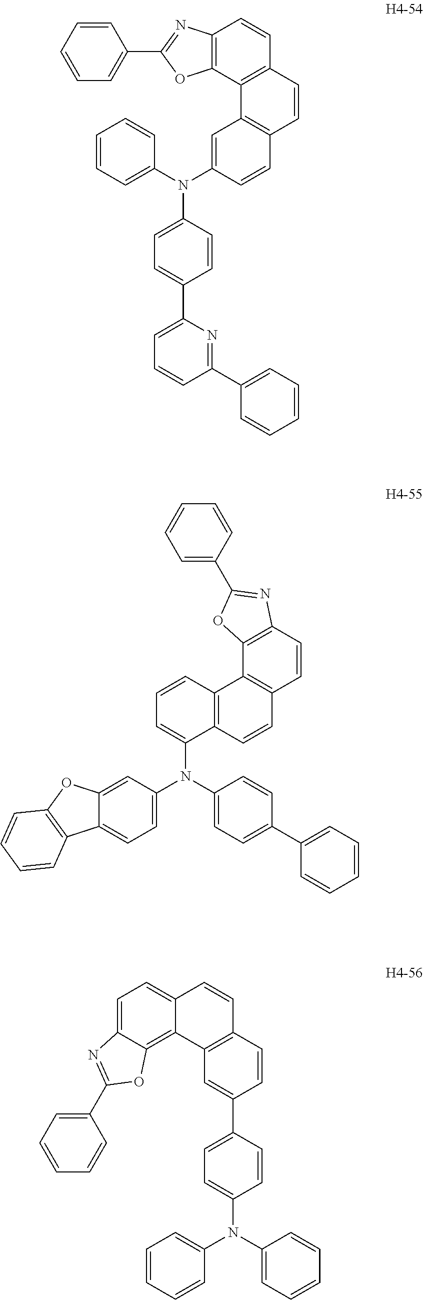 [SMILES: c1ccc(-c2cccc(-c3ccc(N(c4ccccc4)c4ccc5ccc6ccc7nc(-c8ccccc8)oc7c6c5c4)cc3)n2)cc1 ; c1ccc(-c2ccc(N(c3ccc4c(c3)oc3ccccc34)c3cccc4c3ccc3ccc5nc(-c6ccccc6)oc5c34)cc2)cc1 ; c1ccc(-c2nc3ccc4ccc5ccc(-c6ccc(N(c7ccccc7)c7ccccc7)cc6)cc5c4c3o2)cc1] 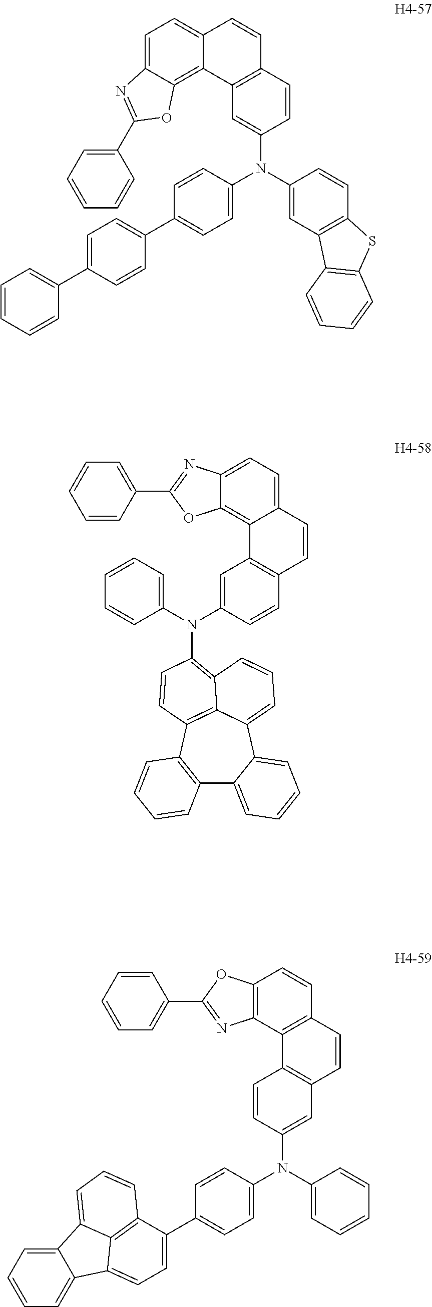 [SMILES: c1ccc(-c2ccc(-c3ccc(N(c4ccc5sc6ccccc6c5c4)c4ccc5ccc6ccc7nc(-c8ccccc8)oc7c6c5c4)cc3)cc2)cc1 ; c1ccc(-c2nc3ccc4ccc5ccc(N(c6ccccc6)c6ccc7c8c(cccc68)-c6ccccc6-c6ccccc6-7)cc5c4c3o2)cc1 ; c1ccc(-c2nc3c(ccc4ccc5cc(N(c6ccccc6)c6ccc(-c7ccc8c9c(cccc79)-c7ccccc7-8)cc6)ccc5c43)o2)cc1] 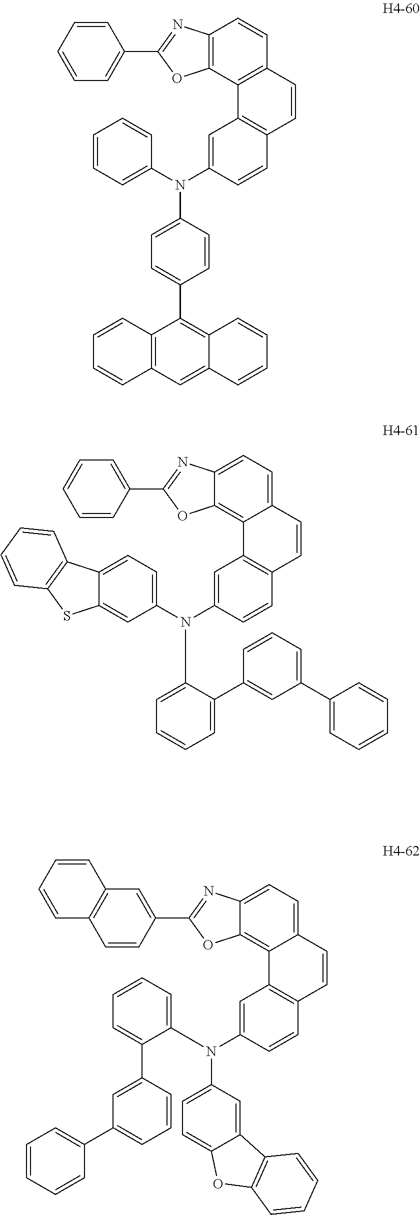 [SMILES: c1ccc(-c2nc3ccc4ccc5ccc(N(c6ccccc6)c6ccc(-c7c8ccccc8cc8ccccc78)cc6)cc5c4c3o2)cc1 ; c1ccc(-c2cccc(-c3ccccc3N(c3ccc4c(c3)sc3ccccc34)c3ccc4ccc5ccc6nc(-c7ccccc7)oc6c5c4c3)c2)cc1 ; c1ccc(-c2cccc(-c3ccccc3N(c3ccc4oc5ccccc5c4c3)c3ccc4ccc5ccc6nc(-c7ccc8ccccc8c7)oc6c5c4c3)c2)cc1] 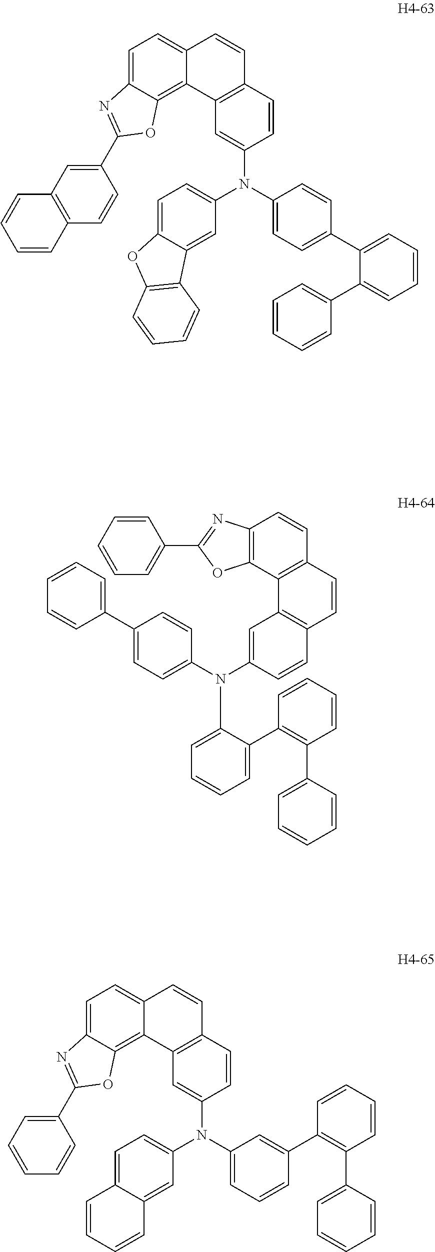 [SMILES: c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccc(N(c3ccc4ccc5ccc6nc(-c7ccccc7)oc6c5c4c3)c3ccccc3-c3ccccc3-c3ccccc3)cc2)cc1 ; c1ccc(-c2nc3ccc4ccc5ccc(N(c6cccc(-c7ccccc7-c7ccccc7)c6)c6ccc7ccccc7c6)cc5c4c3o2)cc1] 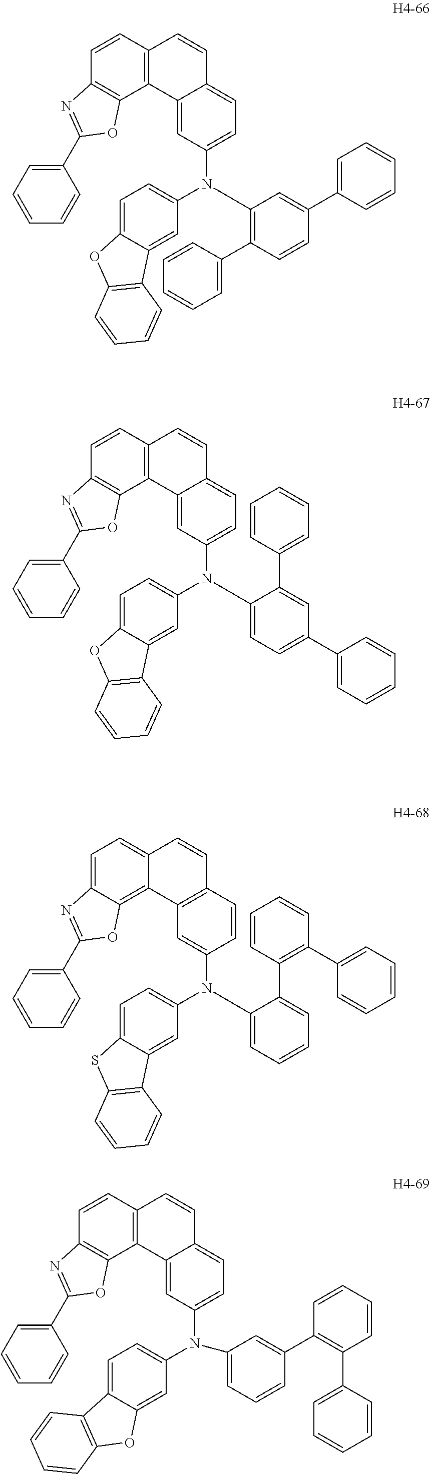 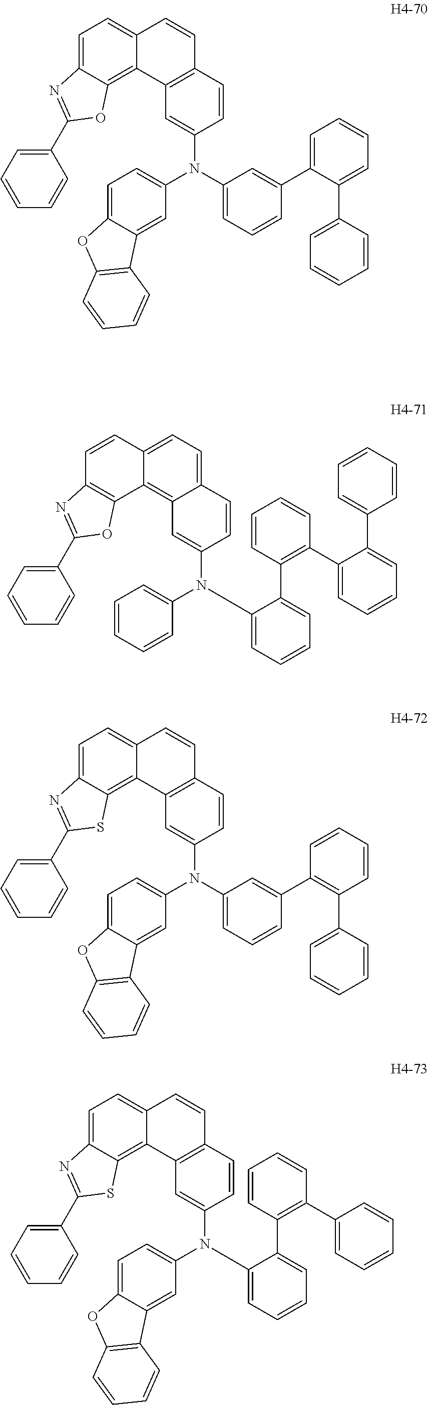 [SMILES: c1ccc(-c2nc3ccc4ccc5ccc(N(c6cccc(-c7ccccc7-c7ccccc7)c6)c6ccc7oc8ccccc8c7c6)cc5c4c3o2)cc1 ; c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6cccc(-c7ccccc7-c7ccccc7)c6)c6ccc7oc8ccccc8c7c6)cc5c4c3s2)cc1 ; c1ccc(-c2nc3ccc4ccc5ccc(N(c6ccc7oc8ccccc8c7c6)c6ccccc6-c6ccccc6-c6ccccc6)cc5c4c3s2)cc1] 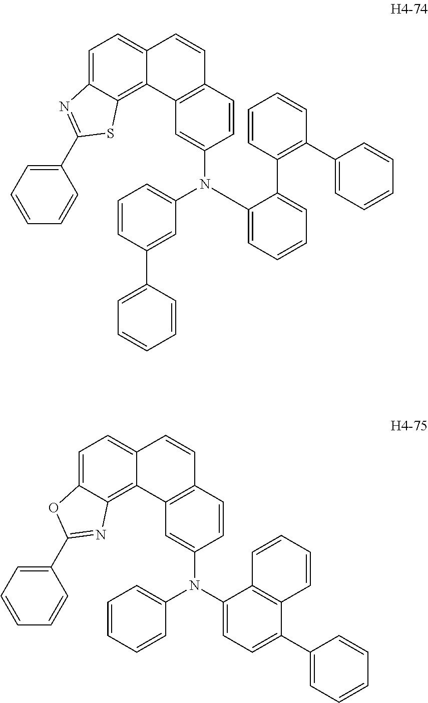 [SMILES: c1ccc(-c2cccc(N(c3ccc4ccc5ccc6nc(-c7ccccc7)sc6c5c4c3)c3ccccc3-c3ccccc3-c3ccccc3)c2)cc1 ; c1ccc(-c2nc3c(ccc4ccc5ccc(N(c6ccccc6)c6ccc(-c7ccccc7)c7ccccc67)cc5c43)o2)cc1] 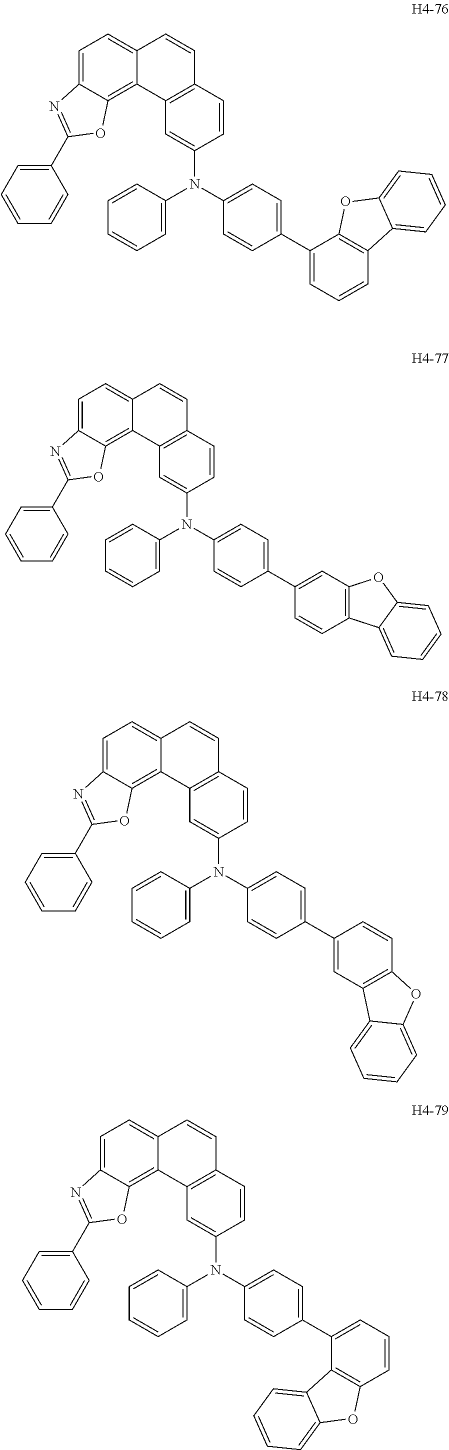 [SMILES: c1ccc(-c2nc3ccc4ccc5ccc(N(c6ccccc6)c6ccc(-c7cccc8c7oc7ccccc78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3o2)cc1 ; c1ccc(-c2nc3ccc4ccc5ccc(N(c6ccccc6)c6ccc(-c7ccc8oc9ccccc9c8c7)cc6)cc5c4c3o2)cc1 ; c1ccc(-c2nc3ccc4ccc5ccc(N(c6ccccc6)c6ccc(-c7cccc8oc9ccccc9c78)cc6)cc5c4c3o2)cc1] 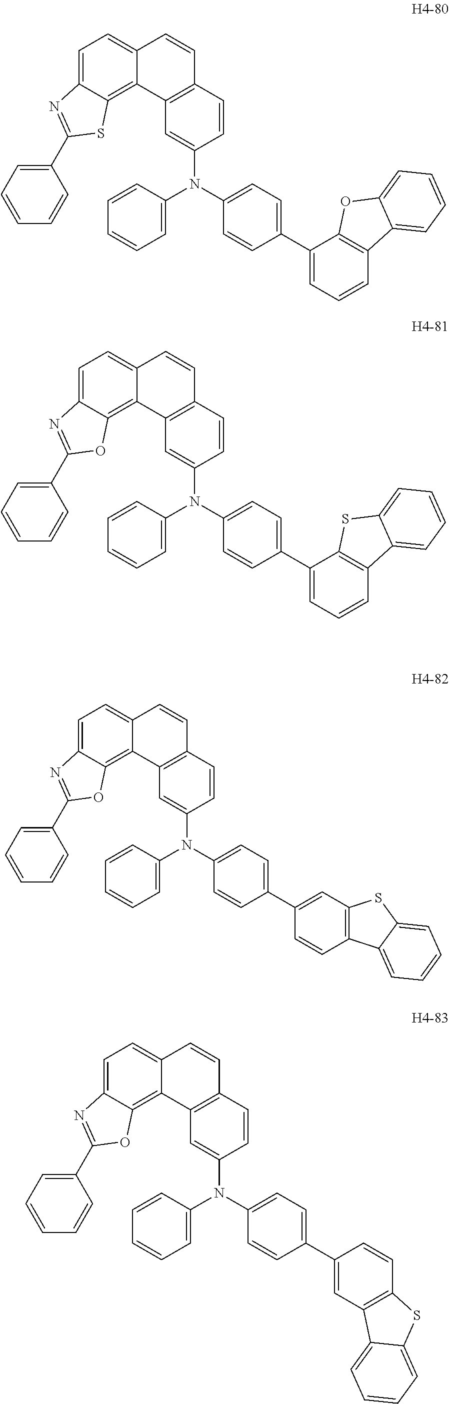 [SMILES: c1ccc(-c2nc3ccc4ccc5ccc(N(c6ccccc6)c6ccc(-c7cccc8c7oc7ccccc78)cc6)cc5c4c3s2)cc1 ; c1ccc(-c2nc3ccc4ccc5ccc(N(c6ccccc6)c6ccc(-c7cccc8c7sc7ccccc78)cc6)cc5c4c3o2)cc1 ; c1ccc(-c2nc3ccc4ccc5ccc(N(c6ccccc6)c6ccc(-c7ccc8c(c7)sc7ccccc78)cc6)cc5c4c3o2)cc1 ; c1ccc(-c2nc3ccc4ccc5ccc(N(c6ccccc6)c6ccc(-c7ccc8sc9ccccc9c8c7)cc6)cc5c4c3o2)cc1] 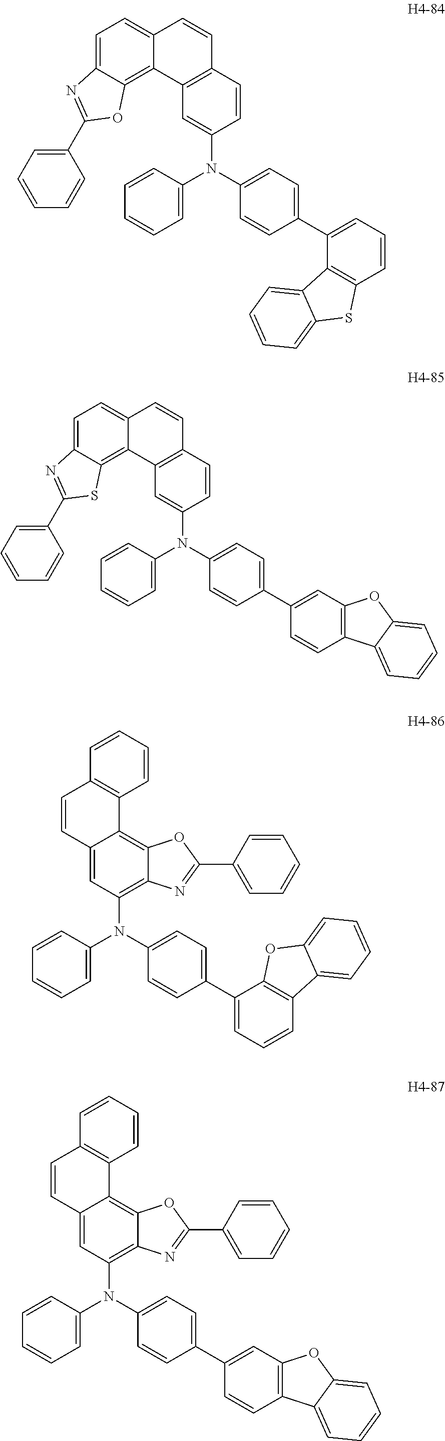 [SMILES: c1ccc(-c2nc3ccc4ccc5ccc(N(c6ccccc6)c6ccc(-c7cccc8sc9ccccc9c78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3s2)cc1 ; c1ccc(-c2nc3c(N(c4ccccc4)c4ccc(-c5cccc6c5oc5ccccc56)cc4)cc4ccc5ccccc5c4c3o2)cc1 ; c1ccc(-c2nc3c(N(c4ccccc4)c4ccc(-c5ccc6c(c5)oc5ccccc56)cc4)cc4ccc5ccccc5c4c3o2)cc1] 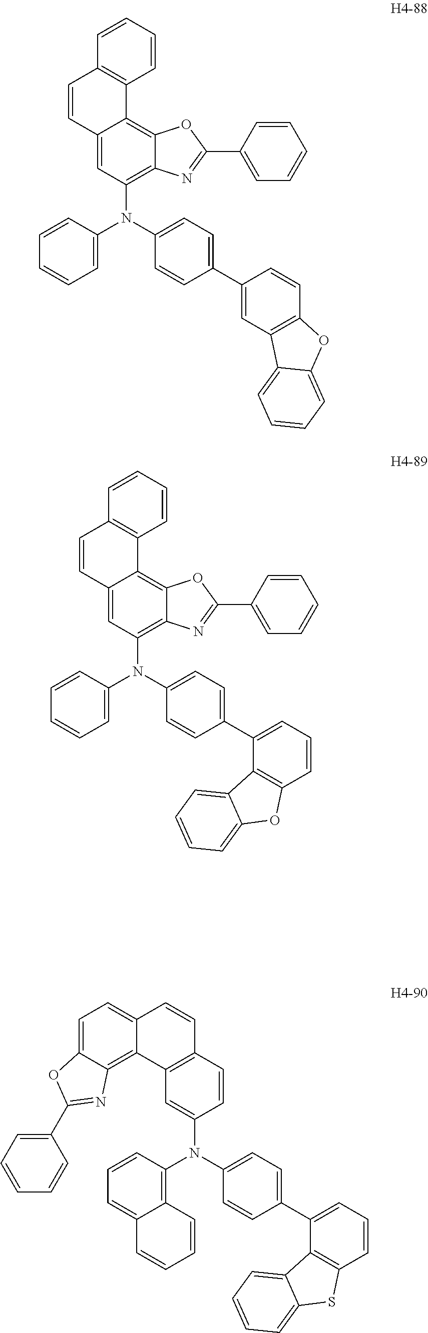 [SMILES: c1ccc(-c2nc3c(N(c4ccccc4)c4ccc(-c5ccc6oc7ccccc7c6c5)cc4)cc4ccc5ccccc5c4c3o2)cc1 ; c1ccc(-c2nc3c(N(c4ccccc4)c4ccc(-c5cccc6oc7ccccc7c56)cc4)cc4ccc5ccccc5c4c3o2)cc1 ; c1ccc(-c2nc3c(ccc4ccc5ccc(N(c6ccc(-c7cccc8sc9ccccc9c78)cc6)c6cccc7ccccc67)cc5c43)o2)cc1] 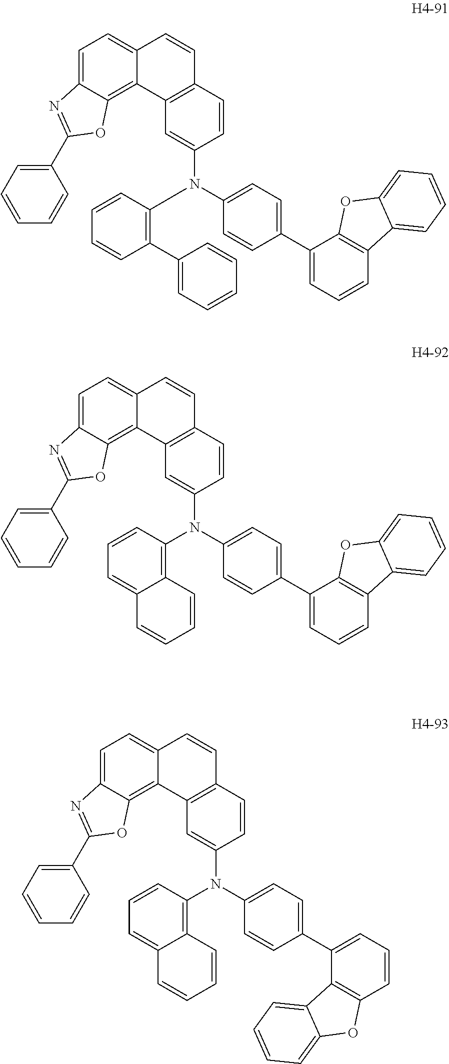 [SMILES: c1ccc(-c2nc3ccc4ccc5ccc(N(c6ccc(-c7cccc8c7oc7ccccc78)cc6)c6ccccc6-c6ccccc6)cc5c4c3o2)cc1 ; c1ccc(-c2nc3ccc4ccc5ccc(N(c6ccc(-c7cccc8c7oc7ccccc78)cc6)c6cccc7ccccc67)cc5c4c3o2)cc1 ; c1ccc(-c2nc3ccc4ccc5ccc(N(c6ccc(-c7cccc8oc9ccccc9c78)cc6)c6cccc7ccccc67)cc5c4c3o2)cc1] 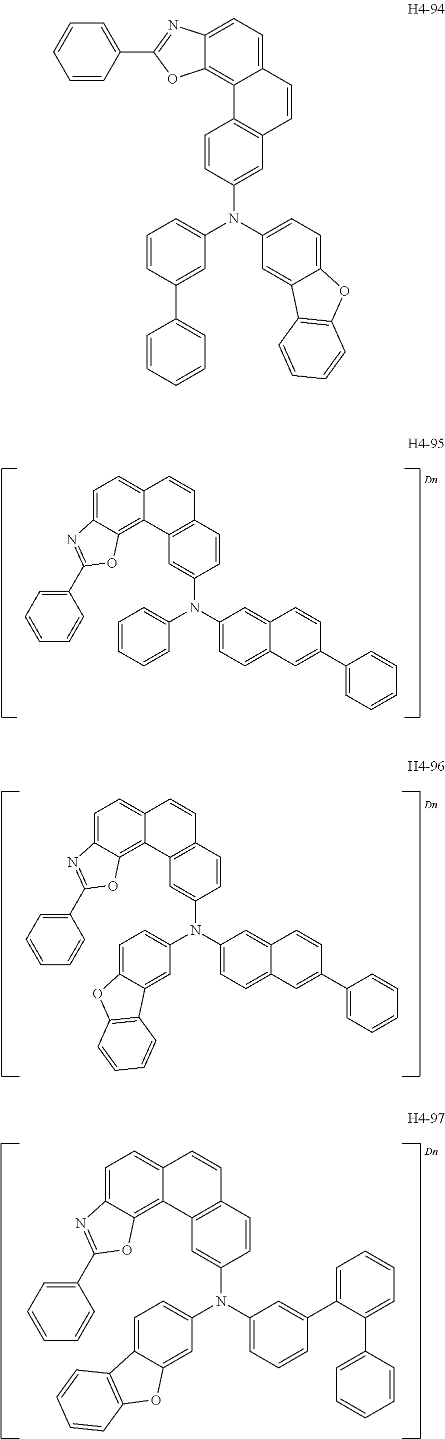 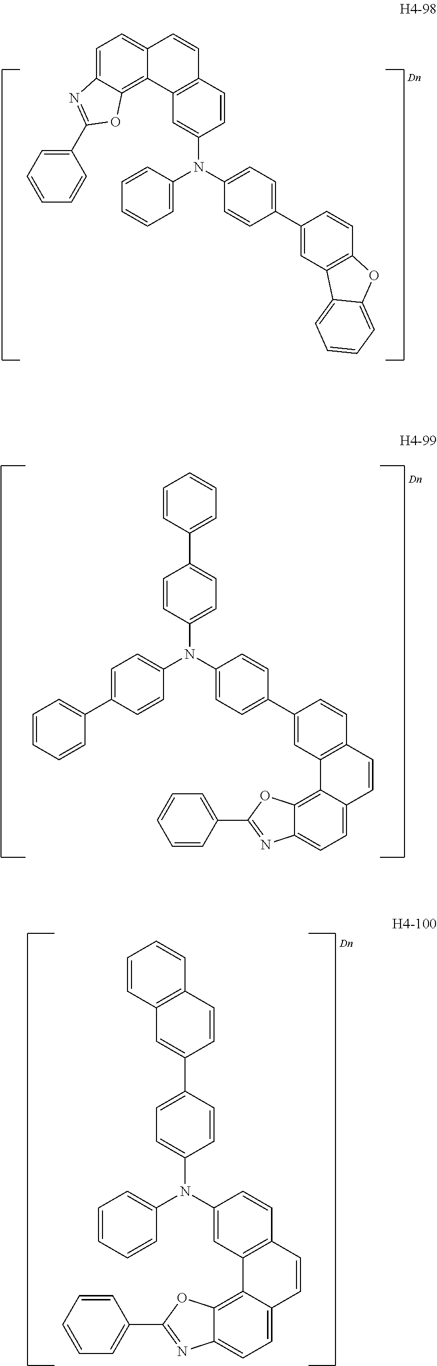 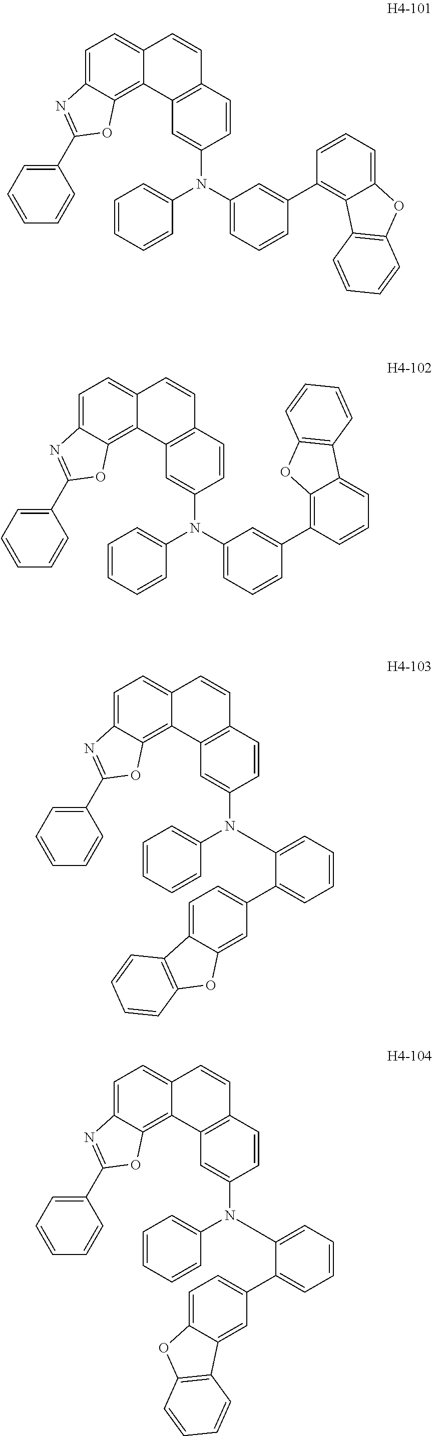 [SMILES: c1ccc(-c2nc3ccc4ccc5ccc(N(c6ccccc6)c6cccc(-c7cccc8oc9ccccc9c78)c6)cc5c4c3o2)cc1 ; c1ccc(-c2nc3ccc4ccc5ccc(N(c6ccccc6)c6cccc(-c7cccc8c7oc7ccccc78)c6)cc5c4c3o2)cc1 ; c1ccc(-c2nc3ccc4ccc5ccc(N(c6ccccc6)c6ccccc6-c6ccc7c(c6)oc6ccccc67)cc5c4c3o2)cc1 ; c1ccc(-c2nc3ccc4ccc5ccc(N(c6ccccc6)c6ccccc6-c6ccc7oc8ccccc8c7c6)cc5c4c3o2)cc1] 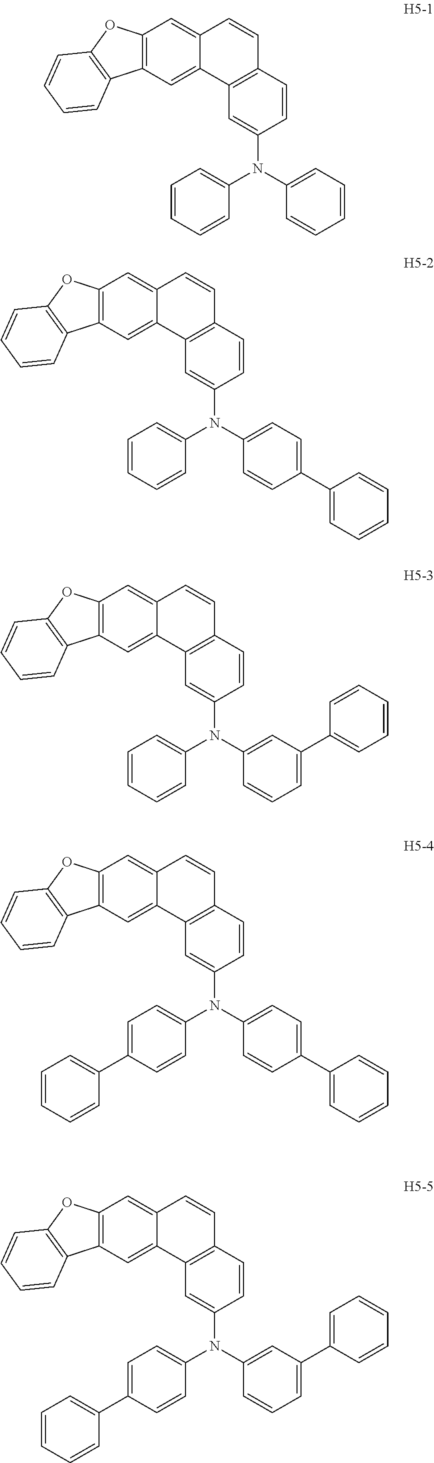 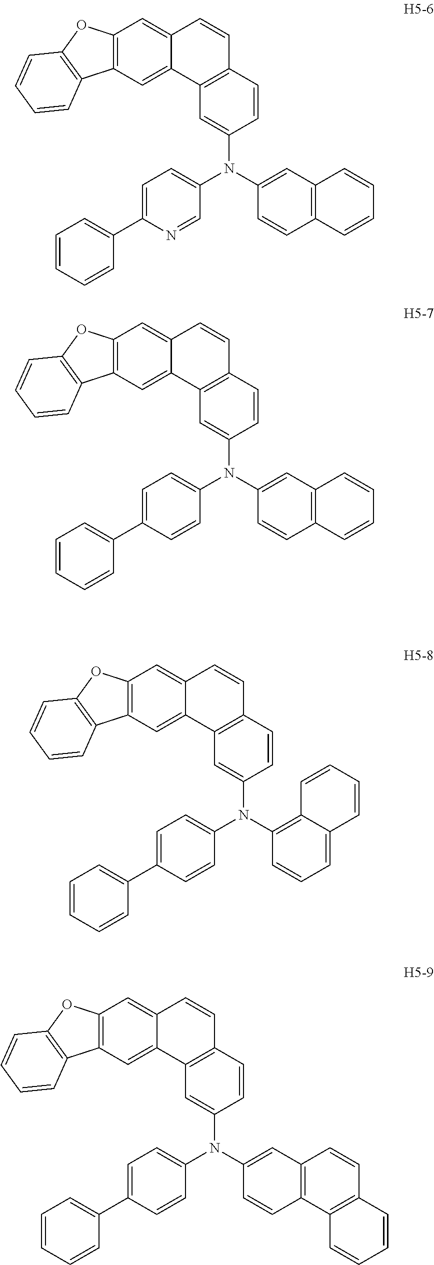 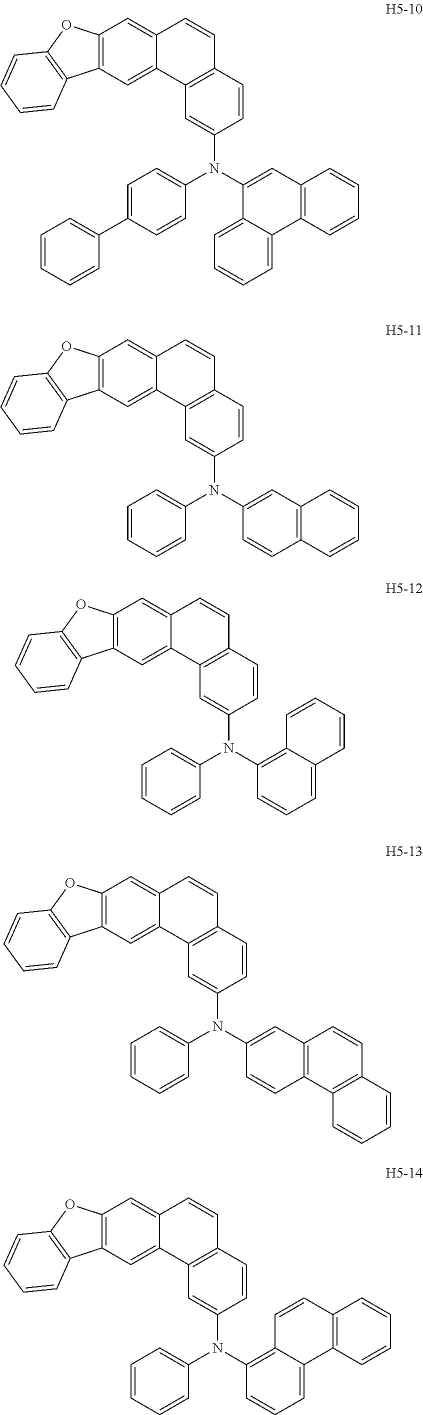 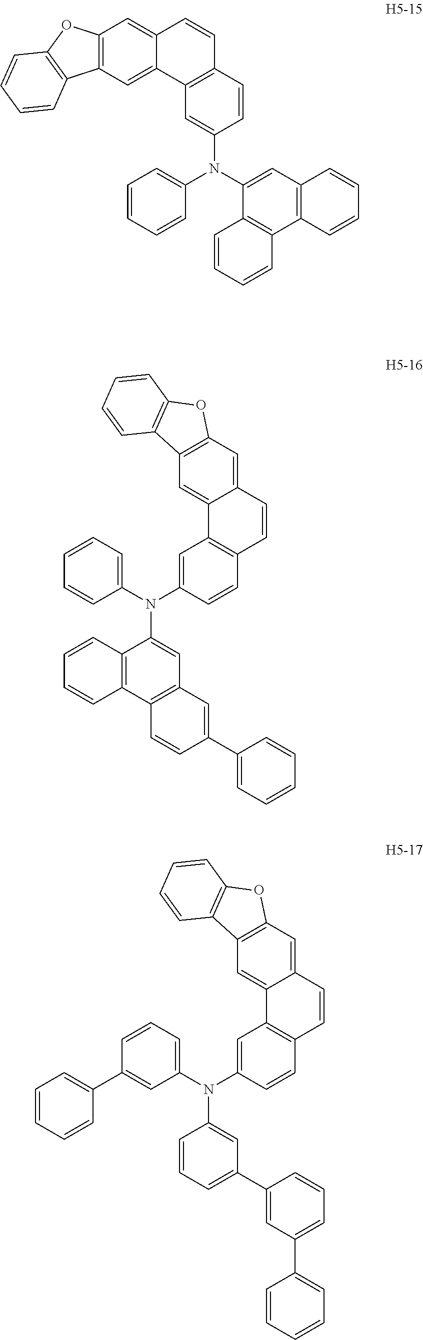 [SMILES: c1ccc(N(c2ccc3ccc4cc5oc6ccccc6c5cc4c3c2)c2cc3ccccc3c3ccccc23)cc1 ; c1ccc(-c2ccc3c(c2)cc(N(c2ccccc2)c2ccc4ccc5cc6oc7ccccc7c6cc5c4c2)c2ccccc23)cc1 ; c1ccc(-c2cccc(-c3cccc(N(c4cccc(-c5ccccc5)c4)c4ccc5ccc6cc7oc8ccccc8c7cc6c5c4)c3)c2)cc1] 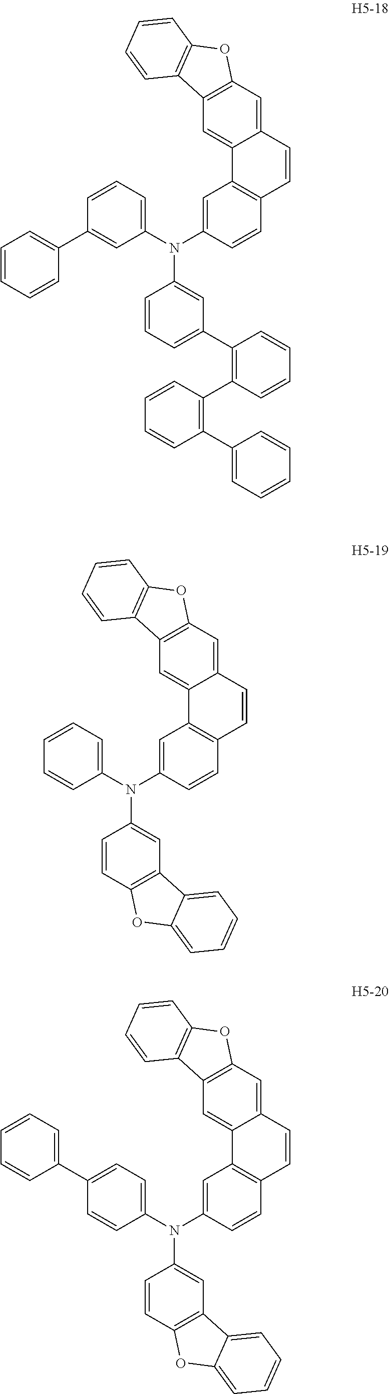 [SMILES: c1ccc(-c2cccc(N(c3cccc(-c4ccccc4-c4ccccc4-c4ccccc4)c3)c3ccc4ccc5cc6oc7ccccc7c6cc5c4c3)c2)cc1 ; c1ccc(N(c2ccc3ccc4cc5oc6ccccc6c5cc4c3c2)c2ccc3oc4ccccc4c3c2)cc1 ; c1ccc(-c2ccc(N(c3ccc4ccc5cc6oc7ccccc7c6cc5c4c3)c3ccc4oc5ccccc5c4c3)cc2)cc1] 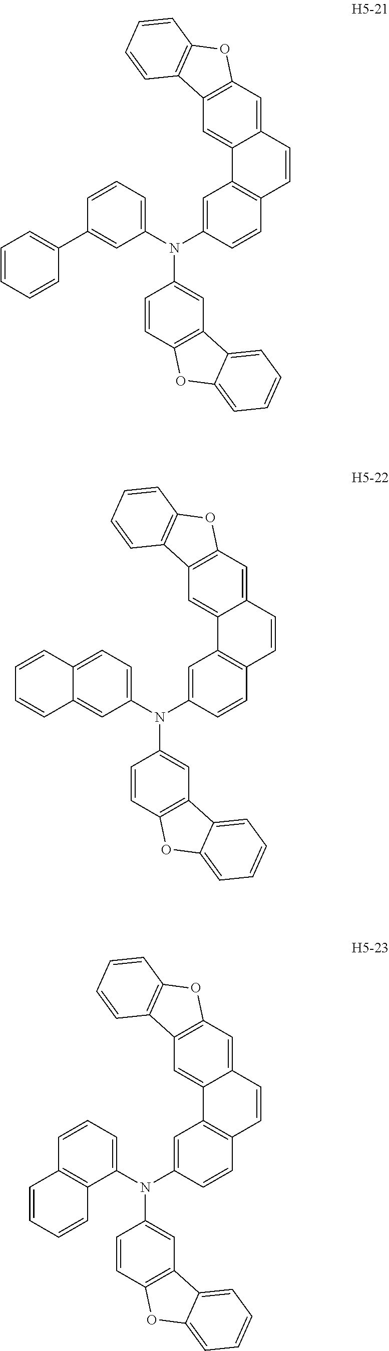 [SMILES: c1ccc(-c2cccc(N(c3ccc4ccc5cc6oc7ccccc7c6cc5c4c3)c3ccc4oc5ccccc5c4c3)c2)cc1 ; c1ccc2cc(N(c3ccc4ccc5cc6oc7ccccc7c6cc5c4c3)c3ccc4oc5ccccc5c4c3)ccc2c1 ; c1ccc2c(N(c3ccc4ccc5cc6oc7ccccc7c6cc5c4c3)c3ccc4oc5ccccc5c4c3)cccc2c1] 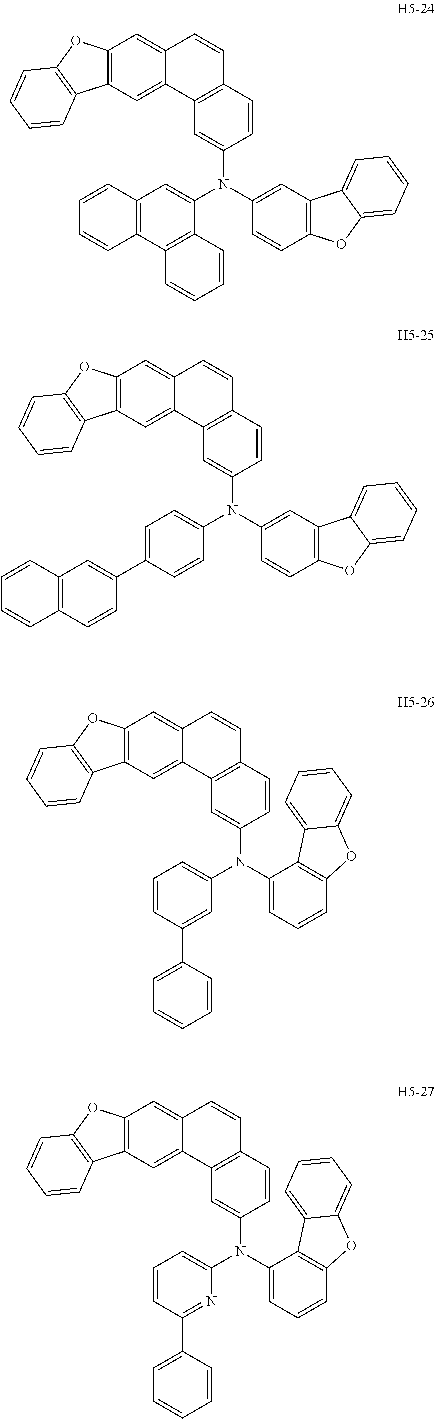 [SMILES: c1ccc2c(c1)cc(N(c1ccc3ccc4cc5oc6ccccc6c5cc4c3c1)c1ccc3oc4ccccc4c3c1)c1ccccc12 ; c1ccc2cc(-c3ccc(N(c4ccc5ccc6cc7oc8ccccc8c7cc6c5c4)c4ccc5oc6ccccc6c5c4)cc3)ccc2c1 ; c1ccc(-c2cccc(N(c3ccc4ccc5cc6oc7ccccc7c6cc5c4c3)c3cccc4oc5ccccc5c34)c2)cc1 ; c1ccc(-c2cccc(N(c3ccc4ccc5cc6oc7ccccc7c6cc5c4c3)c3cccc4oc5ccccc5c34)n2)cc1] 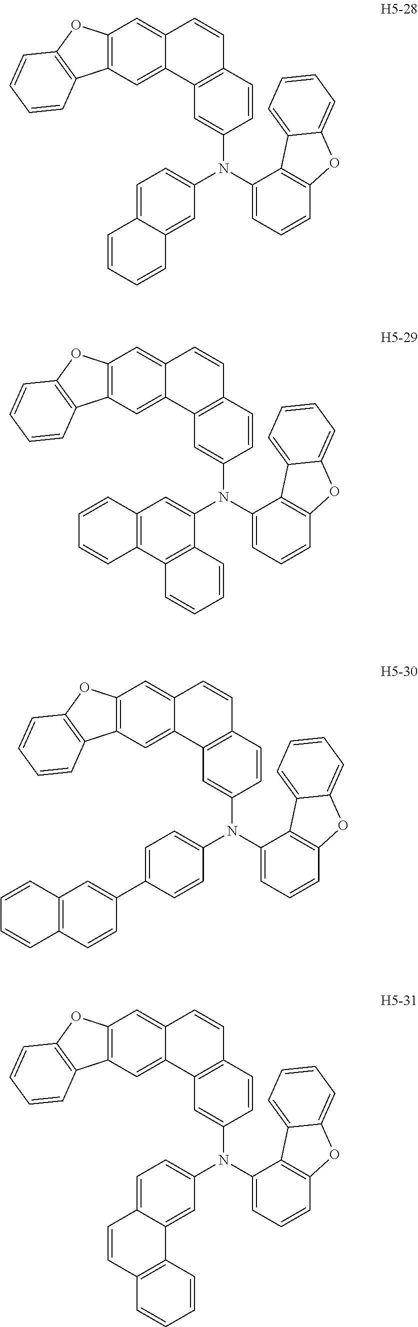 [SMILES: c1ccc2cc(N(c3ccc4ccc5cc6oc7ccccc7c6cc5c4c3)c3cccc4oc5ccccc5c34)ccc2c1 ; c1ccc2c(c1)cc(N(c1ccc3ccc4cc5oc6ccccc6c5cc4c3c1)c1cccc3oc4ccccc4c13)c1ccccc12 ; c1ccc2cc(-c3ccc(N(c4ccc5ccc6cc7oc8ccccc8c7cc6c5c4)c4cccc5oc6ccccc6c45)cc3)ccc2c1 ; c1ccc2c(c1)ccc1ccc(N(c3ccc4ccc5cc6oc7ccccc7c6cc5c4c3)c3cccc4oc5ccccc5c34)cc12] 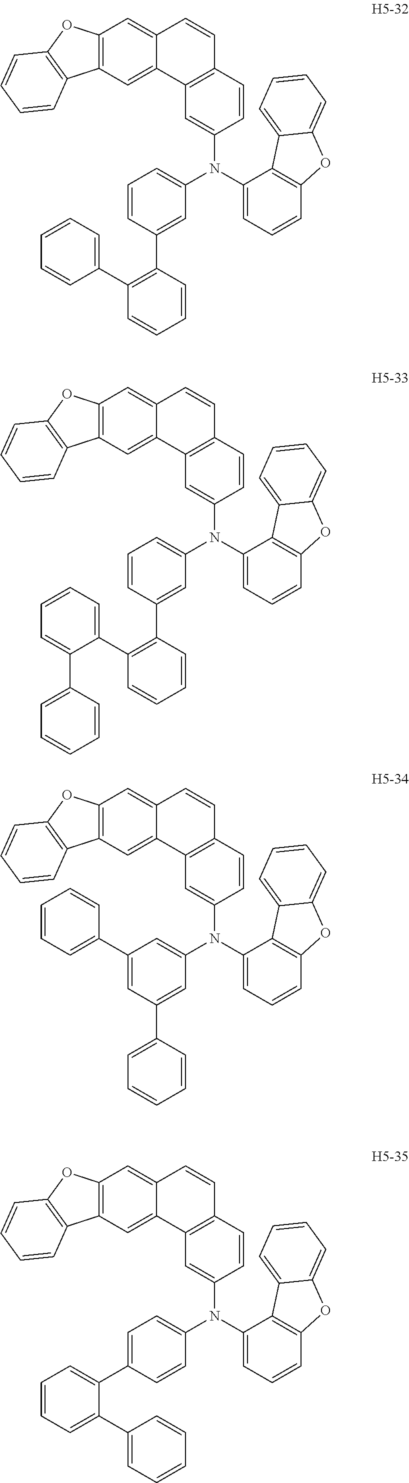 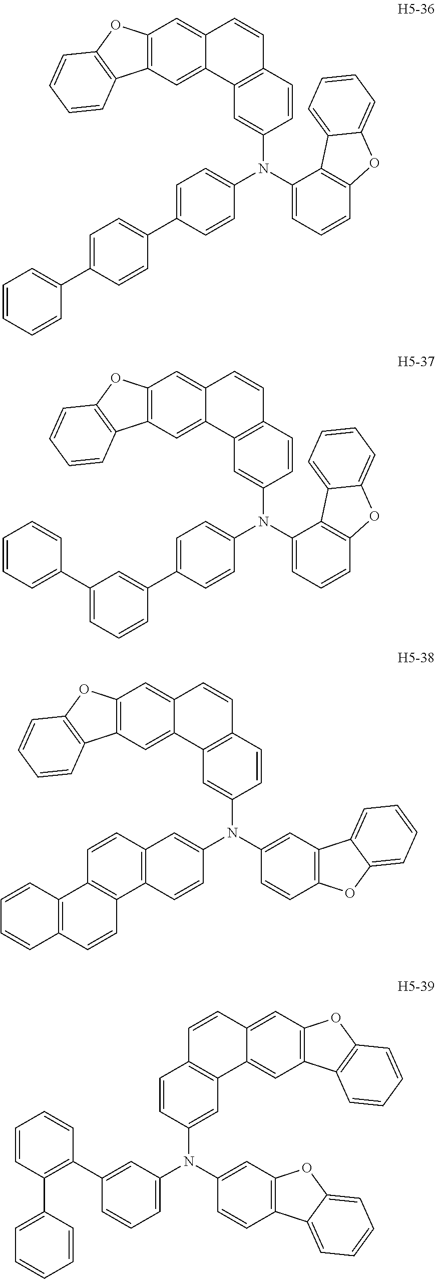 [SMILES: c1ccc(-c2ccc(-c3ccc(N(c4ccc5ccc6cc7oc8ccccc8c7cc6c5c4)c4cccc5oc6ccccc6c45)cc3)cc2)cc1 ; c1ccc(-c2cccc(-c3ccc(N(c4ccc5ccc6cc7oc8ccccc8c7cc6c5c4)c4cccc5oc6ccccc6c45)cc3)c2)cc1 ; c1ccc2c(c1)ccc1c3ccc(N(c4ccc5ccc6cc7oc8ccccc8c7cc6c5c4)c4ccc5oc6ccccc6c5c4)cc3ccc21 ; c1ccc(-c2ccccc2-c2cccc(N(c3ccc4c(c3)oc3ccccc34)c3ccc4ccc5cc6oc7ccccc7c6cc5c4c3)c2)cc1] 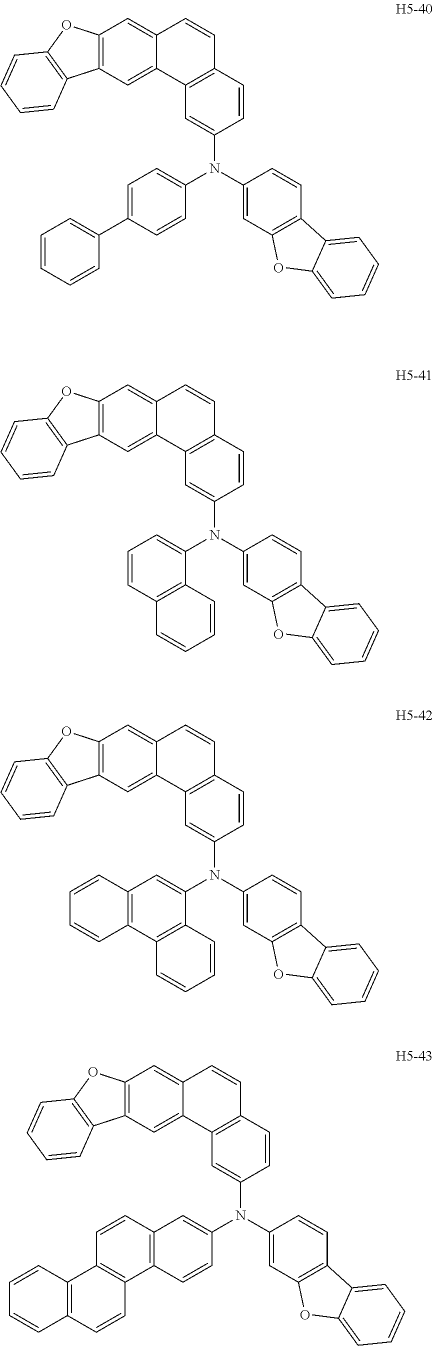 [SMILES: c1ccc(-c2ccc(N(c3ccc4c(c3)oc3ccccc34)c3ccc4ccc5cc6oc7ccccc7c6cc5c4c3)cc2)cc1 ; c1ccc2c(N(c3ccc4c(c3)oc3ccccc34)c3ccc4ccc5cc6oc7ccccc7c6cc5c4c3)cccc2c1 ; c1ccc2c(c1)cc(N(c1ccc3c(c1)oc1ccccc13)c1ccc3ccc4cc5oc6ccccc6c5cc4c3c1)c1ccccc12 ; c1ccc2c(c1)ccc1c3ccc(N(c4ccc5c(c4)oc4ccccc45)c4ccc5ccc6cc7oc8ccccc8c7cc6c5c4)cc3ccc21] 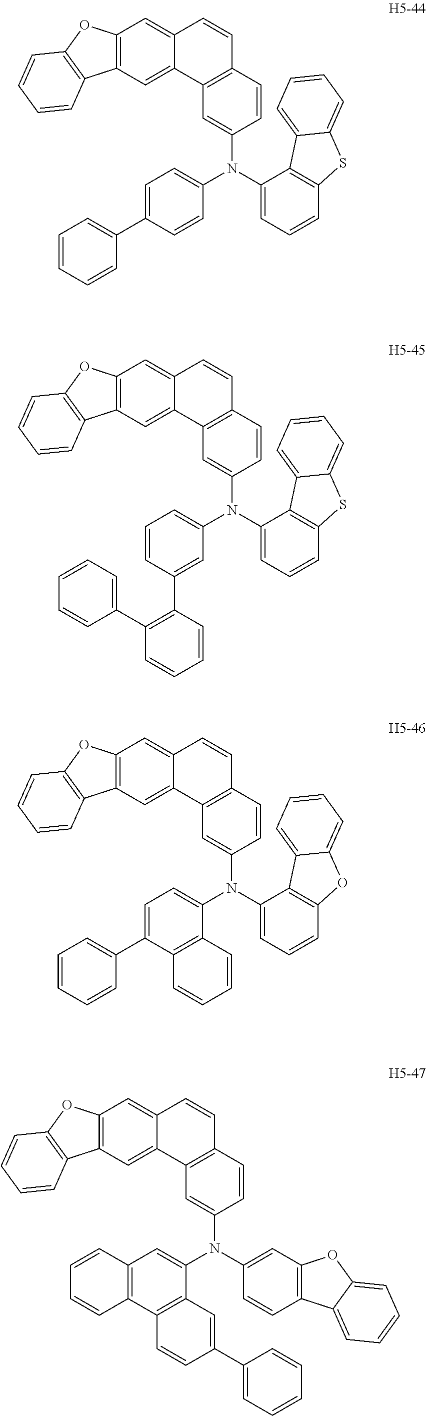 [SMILES: c1ccc(-c2ccc(N(c3ccc4ccc5cc6oc7ccccc7c6cc5c4c3)c3cccc4sc5ccccc5c34)cc2)cc1 ; c1ccc(-c2ccccc2-c2cccc(N(c3ccc4ccc5cc6oc7ccccc7c6cc5c4c3)c3cccc4sc5ccccc5c34)c2)cc1 ; c1ccc(-c2ccc(N(c3ccc4ccc5cc6oc7ccccc7c6cc5c4c3)c3cccc4oc5ccccc5c34)c3ccccc23)cc1 ; c1ccc(-c2ccc3c(c2)c(N(c2ccc4c(c2)oc2ccccc24)c2ccc4ccc5cc6oc7ccccc7c6cc5c4c2)cc2ccccc23)cc1] 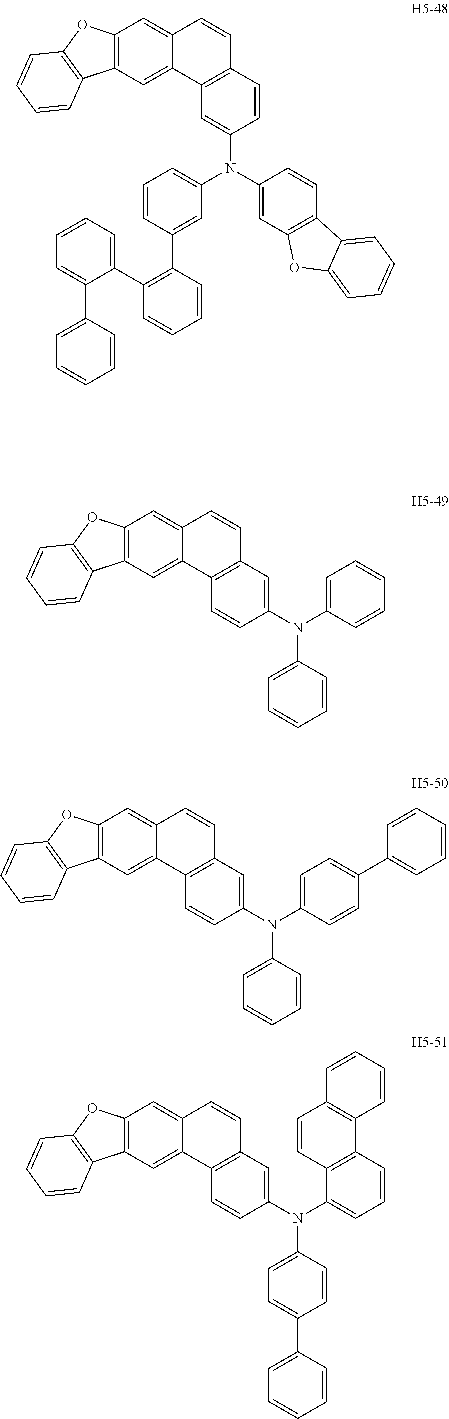 [SMILES: c1ccc(-c2ccccc2-c2ccccc2-c2cccc(N(c3ccc4c(c3)oc3ccccc34)c3ccc4ccc5cc6oc7ccccc7c6cc5c4c3)c2)cc1 ; c1ccc(N(c2ccccc2)c2ccc3c(ccc4cc5oc6ccccc6c5cc43)c2)cc1 ; c1ccc(-c2ccc(N(c3ccccc3)c3ccc4c(ccc5cc6oc7ccccc7c6cc54)c3)cc2)cc1 ; c1ccc(-c2ccc(N(c3ccc4c(ccc5cc6oc7ccccc7c6cc54)c3)c3cccc4c3ccc3ccccc34)cc2)cc1] 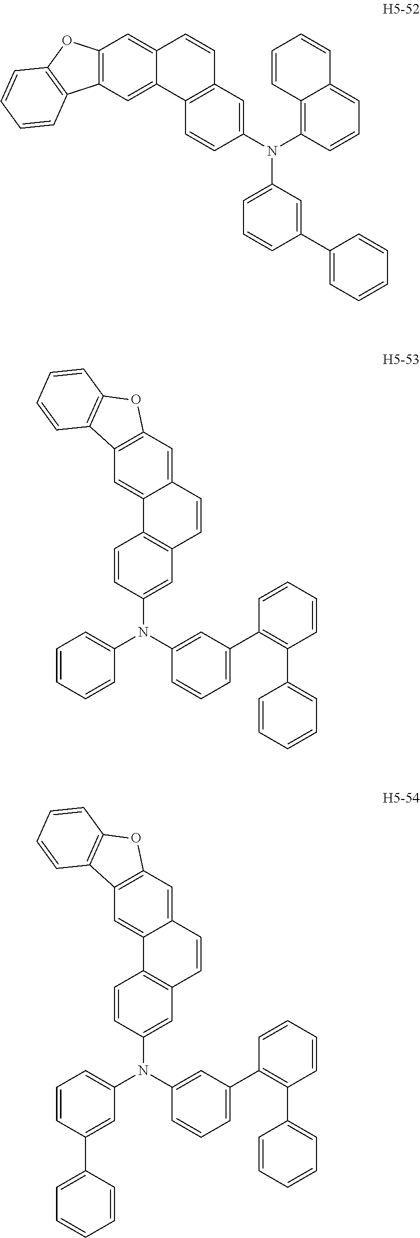 [SMILES: c1ccc(-c2cccc(N(c3ccc4c(ccc5cc6oc7ccccc7c6cc54)c3)c3cccc4ccccc34)c2)cc1 ; c1ccc(-c2ccccc2-c2cccc(N(c3ccccc3)c3ccc4c(ccc5cc6oc7ccccc7c6cc54)c3)c2)cc1 ; c1ccc(-c2cccc(N(c3cccc(-c4ccccc4-c4ccccc4)c3)c3ccc4c(ccc5cc6oc7ccccc7c6cc54)c3)c2)cc1] 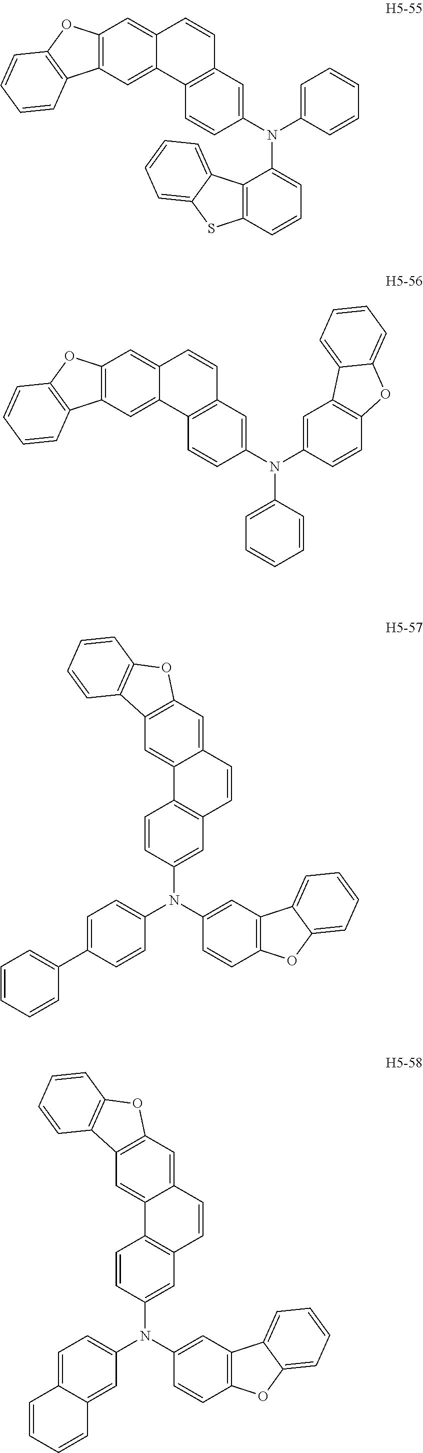 [SMILES: c1ccc(N(c2ccc3c(ccc4cc5oc6ccccc6c5cc43)c2)c2cccc3sc4ccccc4c23)cc1 ; c1ccc(N(c2ccc3c(ccc4cc5oc6ccccc6c5cc43)c2)c2ccc3oc4ccccc4c3c2)cc1 ; c1ccc(-c2ccc(N(c3ccc4c(ccc5cc6oc7ccccc7c6cc54)c3)c3ccc4oc5ccccc5c4c3)cc2)cc1 ; c1ccc2cc(N(c3ccc4c(ccc5cc6oc7ccccc7c6cc54)c3)c3ccc4oc5ccccc5c4c3)ccc2c1] 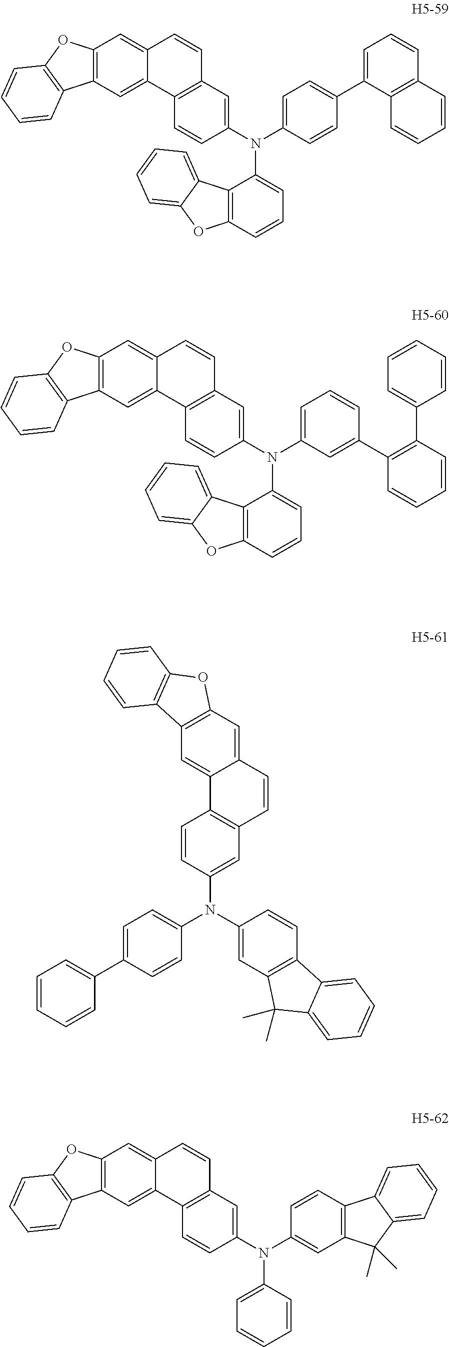 [SMILES: c1ccc2c(-c3ccc(N(c4ccc5c(ccc6cc7oc8ccccc8c7cc65)c4)c4cccc5oc6ccccc6c45)cc3)cccc2c1 ; c1ccc(-c2ccccc2-c2cccc(N(c3ccc4c(ccc5cc6oc7ccccc7c6cc54)c3)c3cccc4oc5ccccc5c34)c2)cc1 ; CC1(C)c2ccccc2-c2ccc(N(c3ccc(-c4ccccc4)cc3)c3ccc4c(ccc5cc6oc7ccccc7c6cc54)c3)cc21 ; CC1(C)c2ccccc2-c2ccc(N(c3ccccc3)c3ccc4c(ccc5cc6oc7ccccc7c6cc54)c3)cc21] 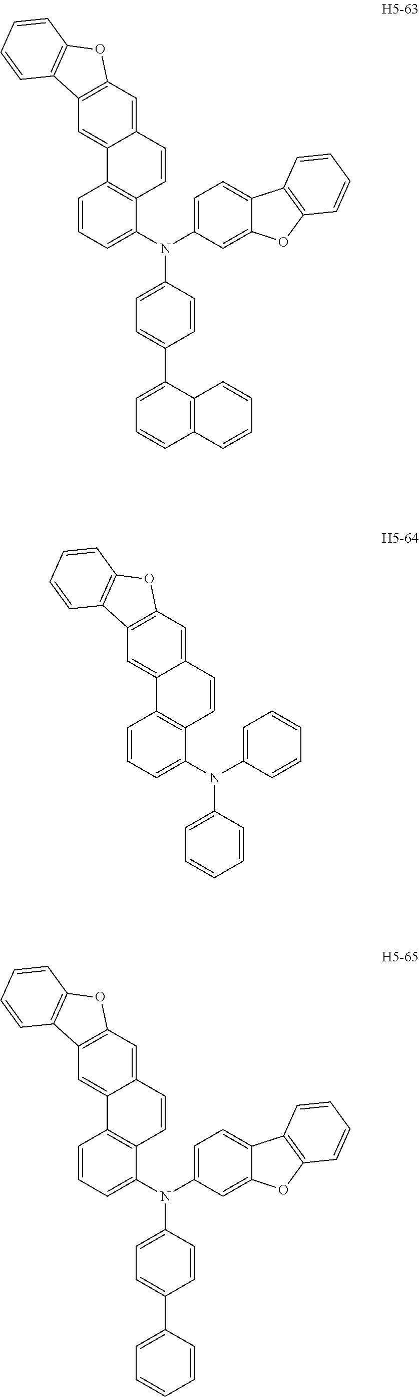 [SMILES: c1ccc2c(-c3ccc(N(c4ccc5c(c4)oc4ccccc45)c4cccc5c4ccc4cc6oc7ccccc7c6cc45)cc3)cccc2c1 ; c1ccc(N(c2ccccc2)c2cccc3c2ccc2cc4oc5ccccc5c4cc23)cc1 ; c1ccc(-c2ccc(N(c3ccc4c(c3)oc3ccccc34)c3cccc4c3ccc3cc5oc6ccccc6c5cc34)cc2)cc1] 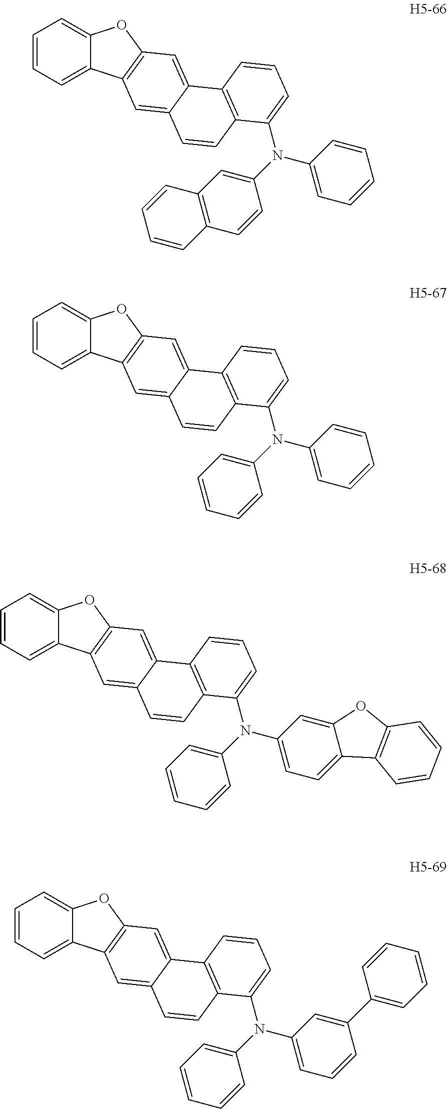 [SMILES: c1ccc(N(c2ccc3ccccc3c2)c2cccc3c2ccc2cc4c(cc23)oc2ccccc24)cc1 ; c1ccc(N(c2ccccc2)c2cccc3c2ccc2cc4c(cc23)oc2ccccc24)cc1 ; c1ccc(N(c2ccc3c(c2)oc2ccccc23)c2cccc3c2ccc2cc4c(cc23)oc2ccccc24)cc1 ; c1ccc(-c2cccc(N(c3ccccc3)c3cccc4c3ccc3cc5c(cc34)oc3ccccc35)c2)cc1] 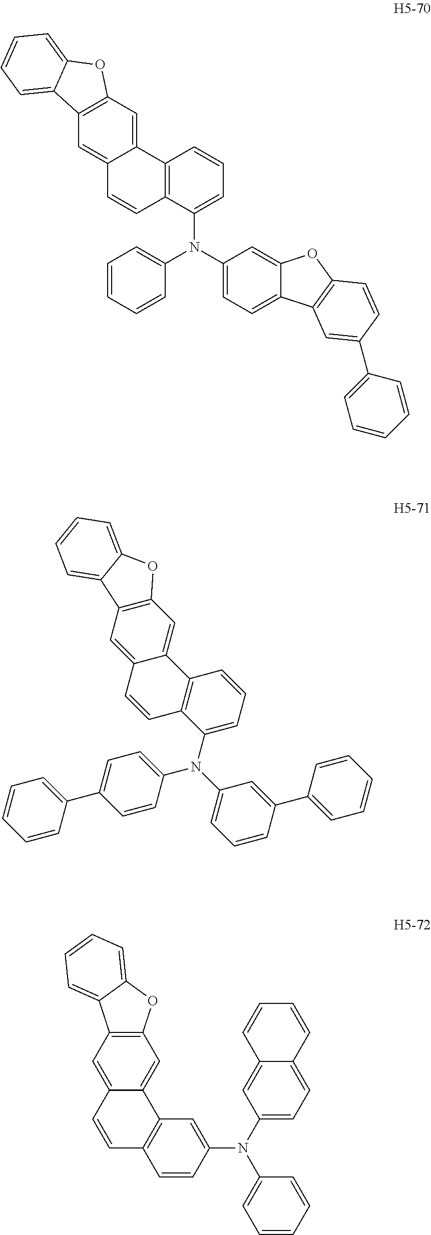 [SMILES: c1ccc(-c2ccc3oc4cc(N(c5ccccc5)c5cccc6c5ccc5cc7c(cc56)oc5ccccc57)ccc4c3c2)cc1 ; c1ccc(-c2ccc(N(c3cccc(-c4ccccc4)c3)c3cccc4c3ccc3cc5c(cc34)oc3ccccc35)cc2)cc1 ; c1ccc(N(c2ccc3ccccc3c2)c2ccc3ccc4cc5c(cc4c3c2)oc2ccccc25)cc1] 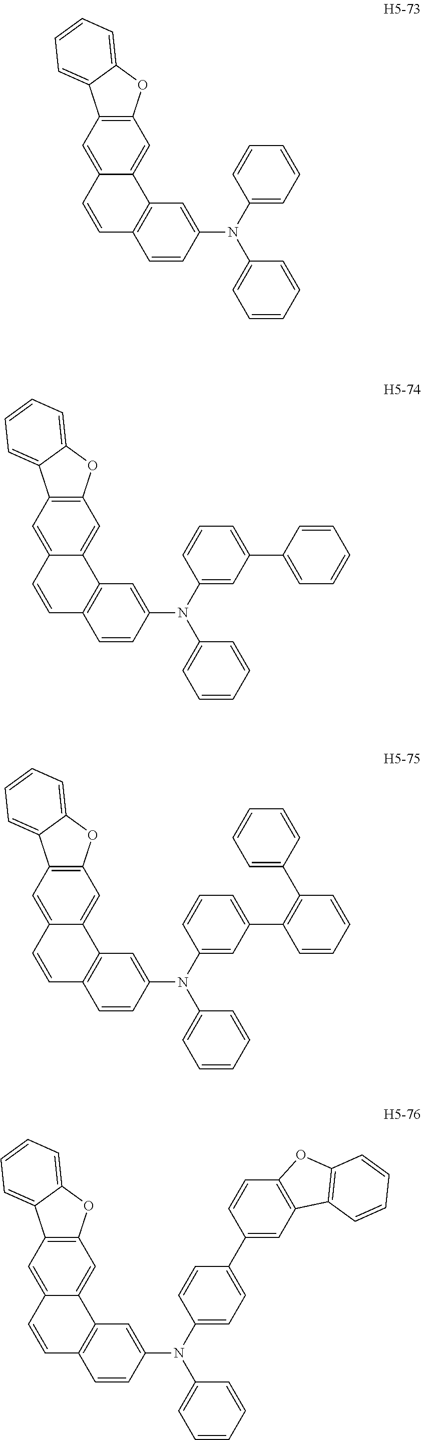 [SMILES: c1ccc(N(c2ccccc2)c2ccc3ccc4cc5c(cc4c3c2)oc2ccccc25)cc1 ; c1ccc(-c2cccc(N(c3ccccc3)c3ccc4ccc5cc6c(cc5c4c3)oc3ccccc36)c2)cc1 ; c1ccc(-c2ccccc2-c2cccc(N(c3ccccc3)c3ccc4ccc5cc6c(cc5c4c3)oc3ccccc36)c2)cc1 ; c1ccc(N(c2ccc(-c3ccc4oc5ccccc5c4c3)cc2)c2ccc3ccc4cc5c(cc4c3c2)oc2ccccc25)cc1] 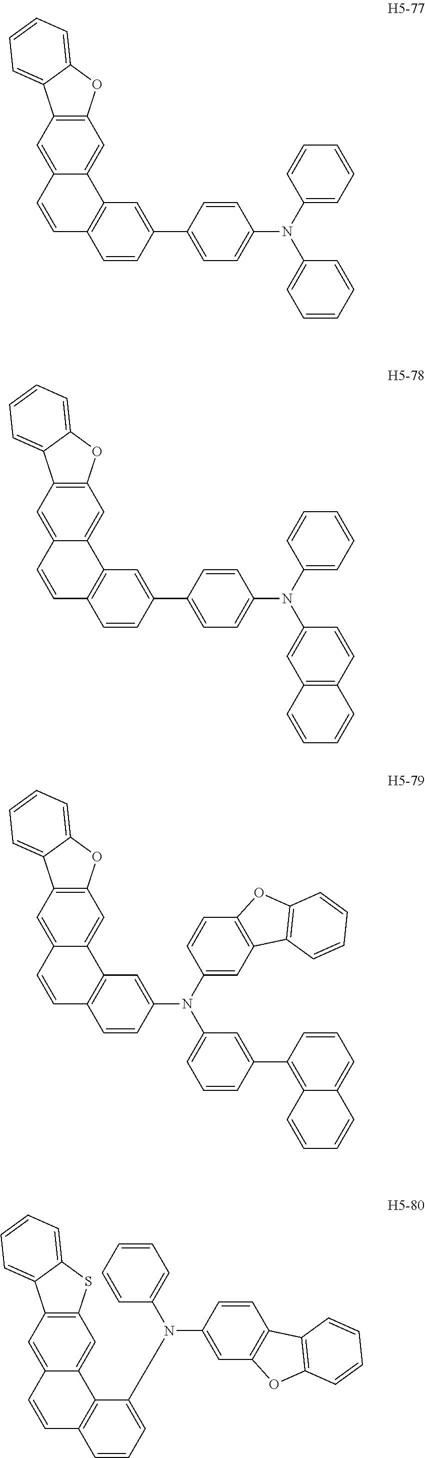 [SMILES: c1ccc(N(c2ccccc2)c2ccc(-c3ccc4ccc5cc6c(cc5c4c3)oc3ccccc36)cc2)cc1 ; c1ccc(N(c2ccc(-c3ccc4ccc5cc6c(cc5c4c3)oc3ccccc36)cc2)c2ccc3ccccc3c2)cc1 ; c1cc(-c2cccc3ccccc23)cc(N(c2ccc3ccc4cc5c(cc4c3c2)oc2ccccc25)c2ccc3oc4ccccc4c3c2)c1 ; c1ccc(N(c2ccc3c(c2)oc2ccccc23)c2cccc3ccc4cc5c(cc4c23)sc2ccccc25)cc1] 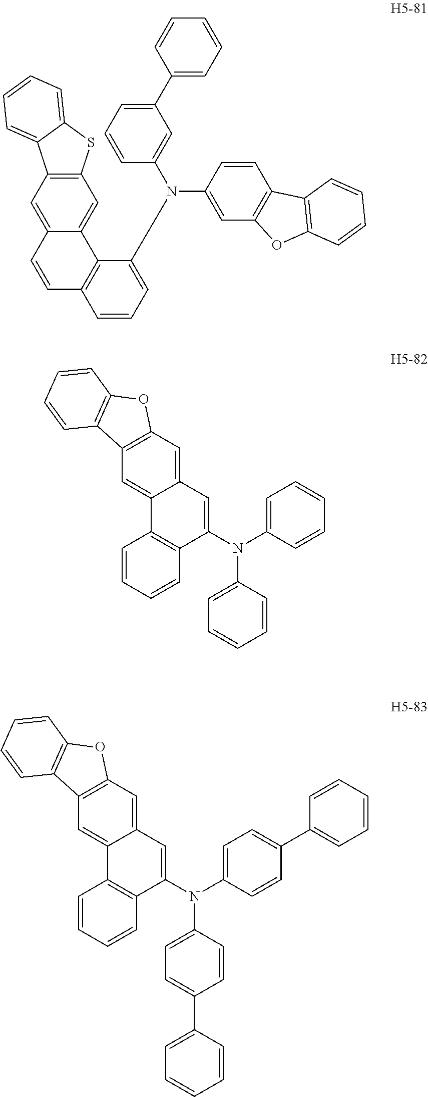 [SMILES: c1ccc(-c2cccc(N(c3ccc4c(c3)oc3ccccc34)c3cccc4ccc5cc6c(cc5c34)sc3ccccc36)c2)cc1 ; c1ccc(N(c2ccccc2)c2cc3cc4oc5ccccc5c4cc3c3ccccc23)cc1 ; c1ccc(-c2ccc(N(c3ccc(-c4ccccc4)cc3)c3cc4cc5oc6ccccc6c5cc4c4ccccc34)cc2)cc1] 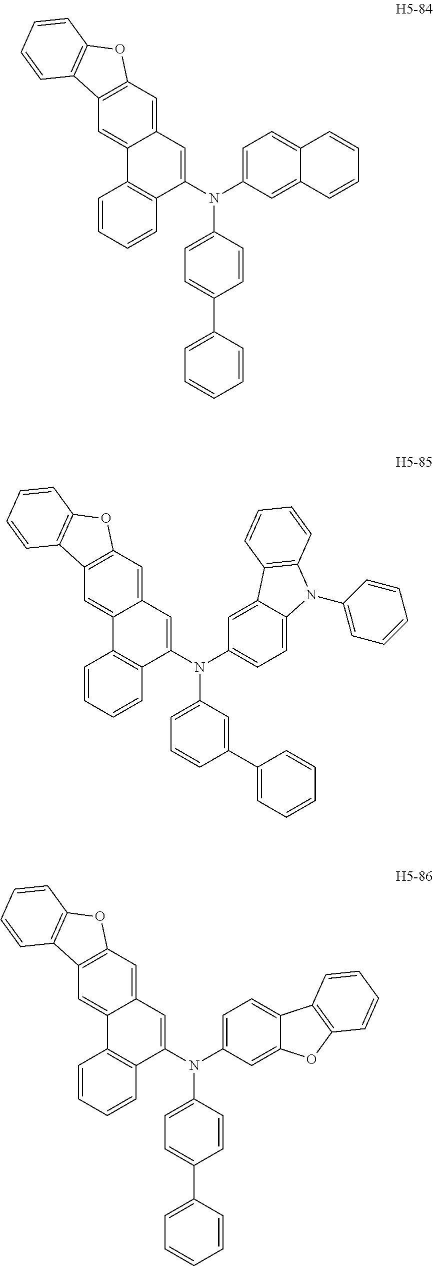 [SMILES: c1ccc(-c2ccc(N(c3ccc4ccccc4c3)c3cc4cc5oc6ccccc6c5cc4c4ccccc34)cc2)cc1 ; c1ccc(-c2cccc(N(c3ccc4c(c3)c3ccccc3n4-c3ccccc3)c3cc4cc5oc6ccccc6c5cc4c4ccccc34)c2)cc1 ; c1ccc(-c2ccc(N(c3ccc4c(c3)oc3ccccc34)c3cc4cc5oc6ccccc6c5cc4c4ccccc34)cc2)cc1] 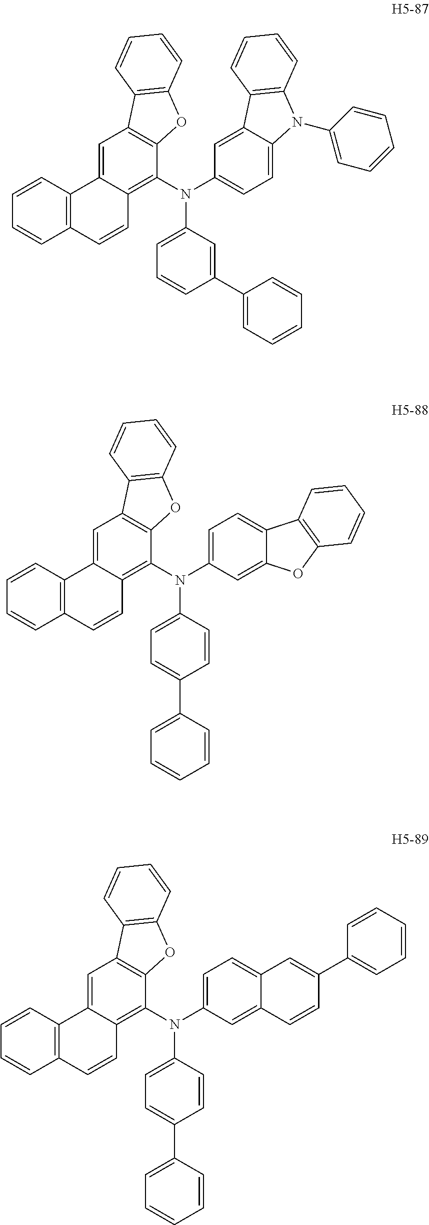 [SMILES: c1ccc(-c2cccc(N(c3ccc4c(c3)c3ccccc3n4-c3ccccc3)c3c4ccc5ccccc5c4cc4c3oc3ccccc34)c2)cc1 ; c1ccc(-c2ccc(N(c3ccc4c(c3)oc3ccccc34)c3c4ccc5ccccc5c4cc4c3oc3ccccc34)cc2)cc1 ; c1ccc(-c2ccc(N(c3ccc4cc(-c5ccccc5)ccc4c3)c3c4ccc5ccccc5c4cc4c3oc3ccccc34)cc2)cc1] 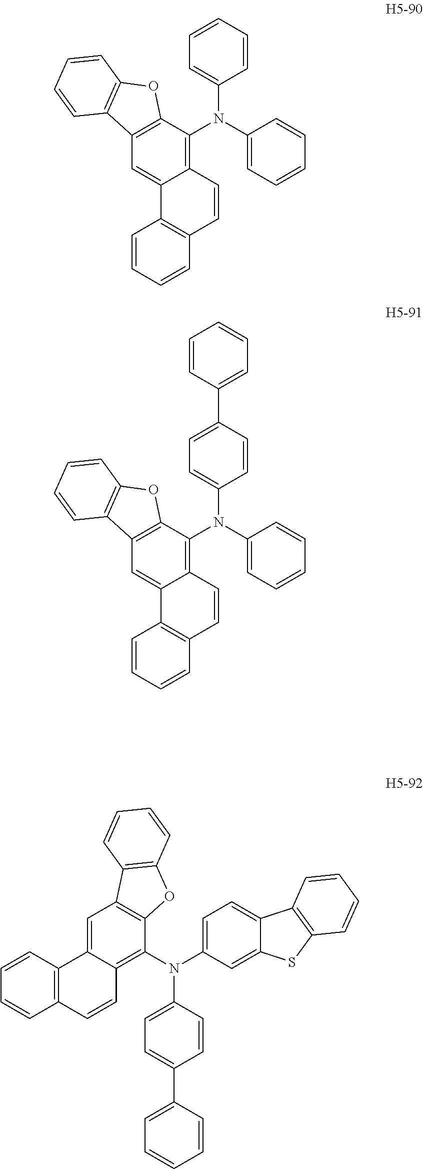 [SMILES: c1ccc(N(c2ccccc2)c2c3ccc4ccccc4c3cc3c2oc2ccccc23)cc1 ; c1ccc(-c2ccc(N(c3ccccc3)c3c4ccc5ccccc5c4cc4c3oc3ccccc34)cc2)cc1 ; c1ccc(-c2ccc(N(c3ccc4c(c3)sc3ccccc34)c3c4ccc5ccccc5c4cc4c3oc3ccccc34)cc2)cc1] 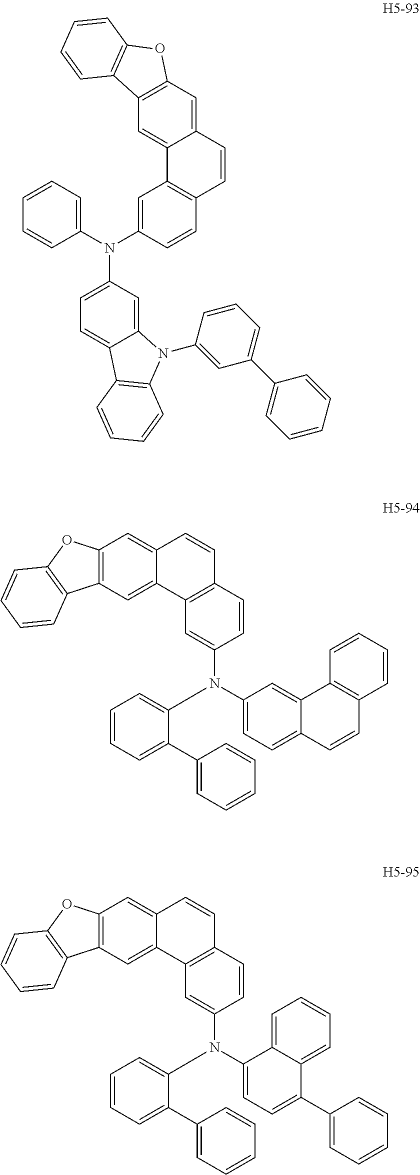 [SMILES: c1ccc(-c2cccc(-n3c4ccccc4c4ccc(N(c5ccccc5)c5ccc6ccc7cc8oc9ccccc9c8cc7c6c5)cc43)c2)cc1 ; c1ccc(-c2ccccc2N(c2ccc3ccc4ccccc4c3c2)c2ccc3ccc4cc5oc6ccccc6c5cc4c3c2)cc1 ; c1ccc(-c2ccccc2N(c2ccc3ccc4cc5oc6ccccc6c5cc4c3c2)c2ccc(-c3ccccc3)c3ccccc23)cc1] 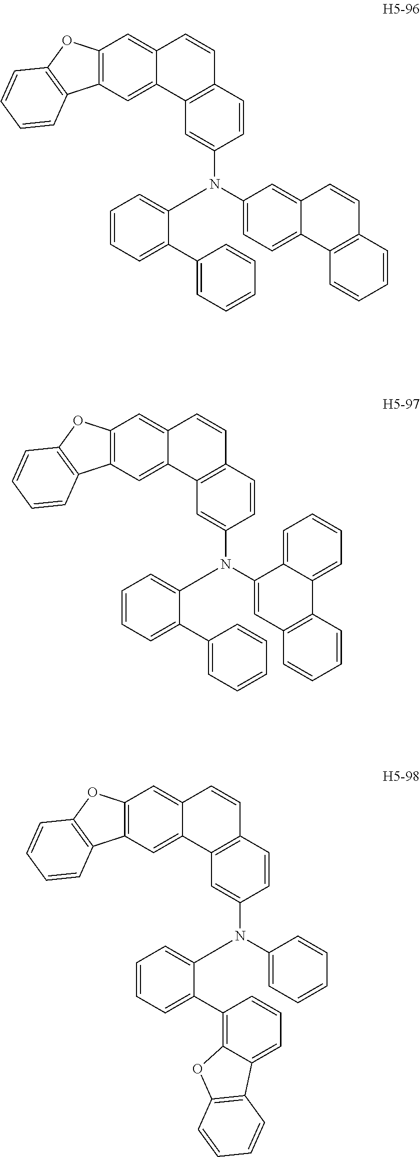 [SMILES: c1ccc(-c2ccccc2N(c2ccc3c(ccc4ccccc43)c2)c2ccc3ccc4cc5oc6ccccc6c5cc4c3c2)cc1 ; c1ccc(-c2ccccc2N(c2ccc3ccc4cc5oc6ccccc6c5cc4c3c2)c2cc3ccccc3c3ccccc23)cc1 ; c1ccc(N(c2ccc3ccc4cc5oc6ccccc6c5cc4c3c2)c2ccccc2-c2cccc3c2oc2ccccc23)cc1] 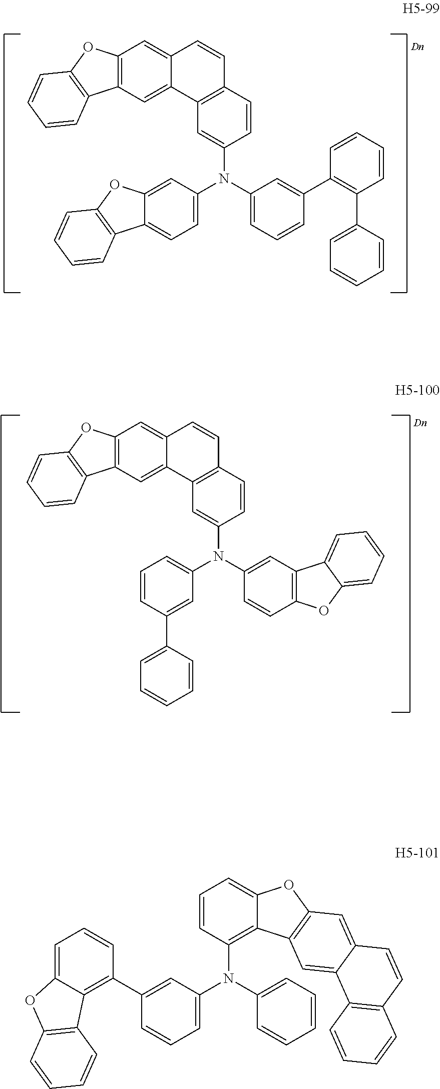 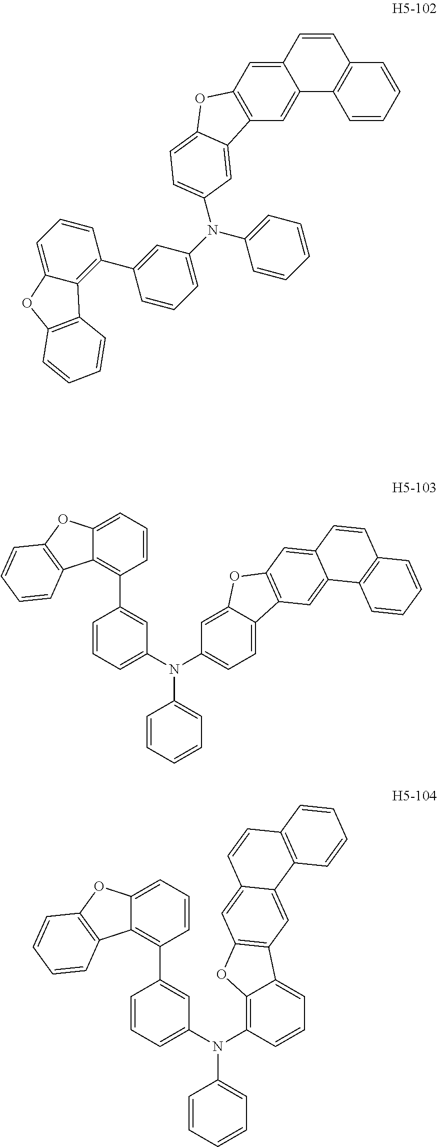 [SMILES: c1ccc(N(c2cccc(-c3cccc4oc5ccccc5c34)c2)c2ccc3oc4cc5ccc6ccccc6c5cc4c3c2)cc1 ; c1ccc(N(c2cccc(-c3cccc4oc5ccccc5c34)c2)c2ccc3c(c2)oc2cc4ccc5ccccc5c4cc23)cc1 ; c1ccc(N(c2cccc(-c3cccc4oc5ccccc5c34)c2)c2cccc3c2oc2cc4ccc5ccccc5c4cc23)cc1] 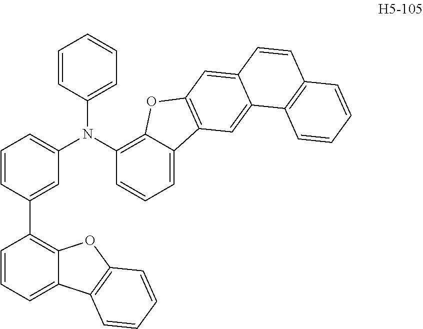 [SMILES: c1ccc(N(c2cccc(-c3cccc4c3oc3ccccc34)c2)c2cccc3c2oc2cc4ccc5ccccc5c4cc23)cc1] 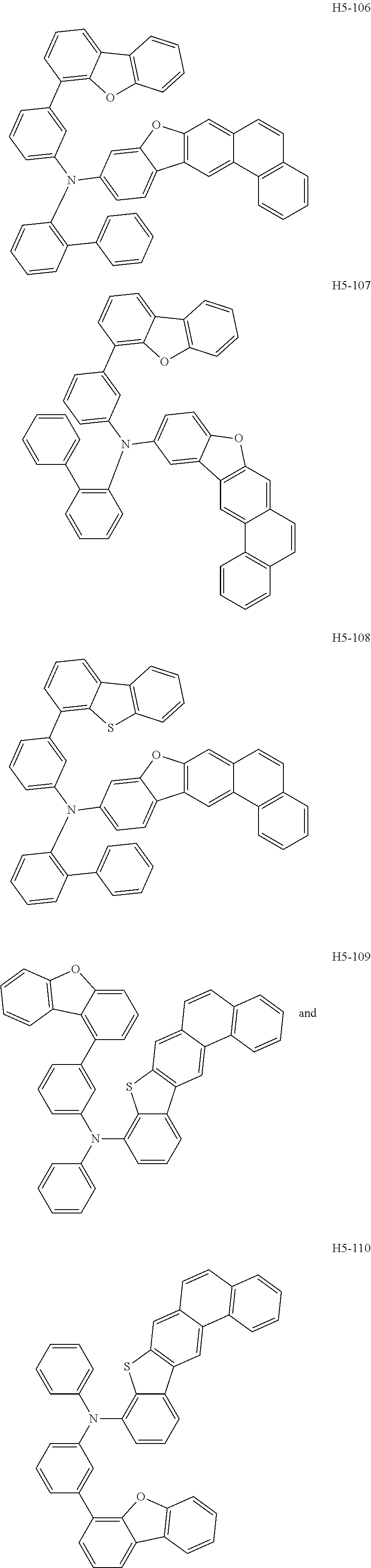
wherein in the compounds above, Dₙ means that n number of hydrogens are replaced with deuterium, and n represents an integer from 1 to the maximum number of hydrogens in the compound.

15. An organic electroluminescent device comprising a first electrode; a second electrode; and at least one light-emitting layer disposed between the first electrode and the second electrode, wherein the at least one light-emitting layer comprises the plurality of host materials according to claim 1.

16. The plurality of host materials according to claim 1, wherein the plurality of host materials further comprises a third host material.

17. The plurality of host materials according to claim 16, wherein the third host material comprises a compound with electronic properties by comprising a substituent that is relatively rich in electrons in a parent nucleus.

18. The plurality of host materials according to claim 16, wherein the third host material comprises a compound with hole properties by comprising a substituent that is relatively deficient in electrons on a parent nucleus.

19. An organic electroluminescent device comprising a first electrode; a second electrode; and at least one light-emitting layer disposed between the first electrode and the second electrode, wherein the at least one light-emitting layer comprises the plurality of host materials according to claim 16.

20. An organic electroluminescent compound represented by the following Formula 3: 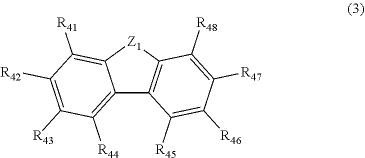
wherein in Formula 3,
Z₁ represents O, S, Se, NR_{b}, or CR_{c}R_{d}; and
R₄₁ to R₄₈ and R_{b} to R_{d} each independently represent the following Formula 3-a, or hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl;
with the proviso that at least one of R₄₁ to R₄₈ and R_{b} to R_{d} is represented by the following Formula 3-a: 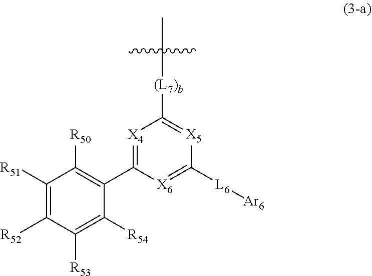
wherein in Formula 3-a,
X₄ to X₆ each independently represent N or CRₑ; with the proviso that at least one of X₄ to X₆ is N;
L₆ and L₇ each independently represent a single bond, a substituted or unsubstituted (C₆-C₃₀)arylene, a substituted or unsubstituted (3- to 30-membered)heteroarylene, or a substituted or unsubstituted (C₃-C₃₀)cycloalkylene;
b represents an integer of 1 or 2, where if b is an integer of 2, each L₇ may be the same as or different from each other;
R₅₀ to R₅₄ and Rₑ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring group of a (C₃-C₃₀)aliphatic ring(s) and a (C₆-C₃₀)aromatic ring(s); with the proviso that at least one of R₅₀ to R₅₄ is cyano; and
Ar₆ represents a substituted or unsubstituted phenyl, a substituted or unsubstituted biphenyl, a substituted or unsubstituted terphenyl, a substituted or unsubstituted naphthyl, a substituted or unsubstituted binaphthyl, a substituted or unsubstituted phenylnaphthyl, a substituted or unsubstituted naphthylphenyl, a substituted or unsubstituted phenanthrenyl, a substituted or unsubstituted anthracenyl, a substituted or unsubstituted chrysenyl, a substituted or unsubstituted dibenzofuranyl, a substituted or unsubstituted dibenzothiophenyl, a substituted or unsubstituted naphthobenzothiophenyl, a substituted or unsubstituted carbazolyl, or a substituted or unsubstituted benzocarbazolyl.

21. The organic electroluminescent compound according to claim 20, wherein at least one of R₅₀ to R₅₄ in Formula 3-a is a cyano, and one of the remainder is a substituted or unsubstituted (C₆-C₃₀)aryl.

22. The organic electroluminescent compound according to claim 20, wherein at least one of R₅₀ to R₅₄ in Formula 3-a is a cyano, and the rest are hydrogen or deuterium.

23. The organic electroluminescent compound according to claim 20, wherein at least one of R₄₁ to R₄₈ in Formula 3 is a substituted or unsubstituted phenyl, a substituted or unsubstituted biphenyl, a substituted or unsubstituted naphthyl, a substituted or unsubstituted phenylnaphthyl, or a substituted or unsubstituted naphthylphenyl.

24. The organic electroluminescent compound according to claim 20, wherein the compound represented by Formula 3 is selected from the following compounds: 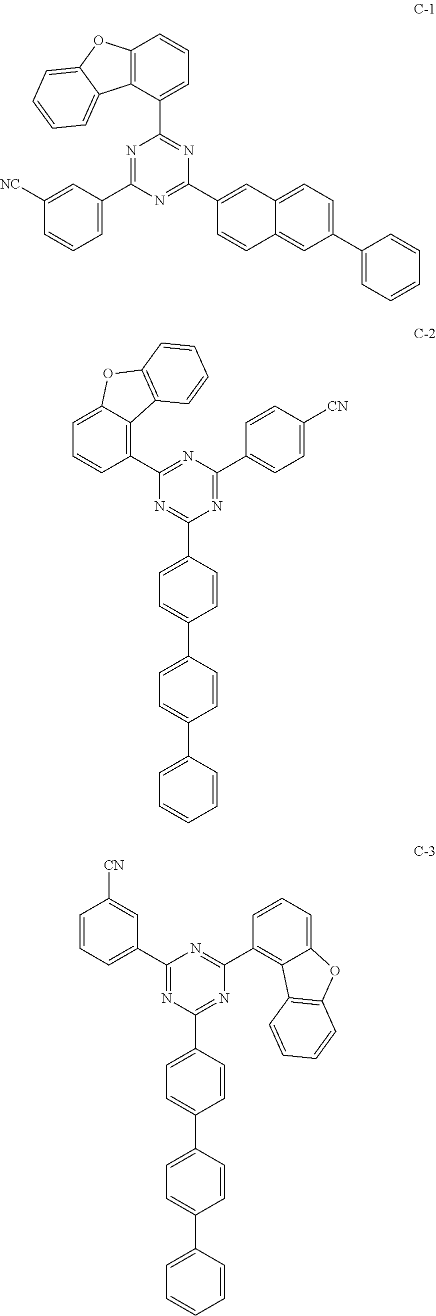 [SMILES: N#Cc1cccc(-c2nc(-c3ccc4cc(-c5ccccc5)ccc4c3)nc(-c3cccc4oc5ccccc5c34)n2)c1 ; N#Cc1ccc(-c2nc(-c3ccc(-c4ccc(-c5ccccc5)cc4)cc3)nc(-c3cccc4oc5ccccc5c34)n2)cc1 ; N#Cc1cccc(-c2nc(-c3ccc(-c4ccc(-c5ccccc5)cc4)cc3)nc(-c3cccc4oc5ccccc5c34)n2)c1] 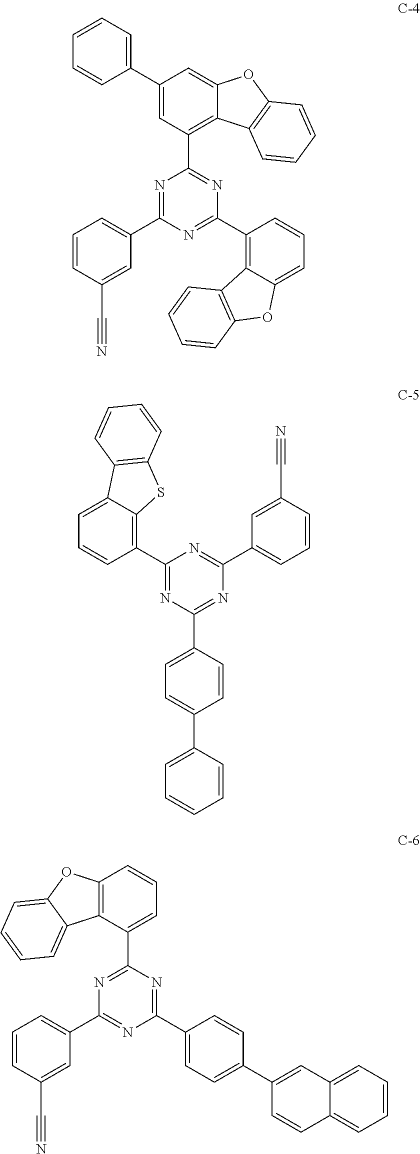 [SMILES: N#Cc1cccc(-c2nc(-c3cccc4oc5ccccc5c34)nc(-c3cc(-c4ccccc4)cc4oc5ccccc5c34)n2)c1 ; N#Cc1cccc(-c2nc(-c3ccc(-c4ccccc4)cc3)nc(-c3cccc4c3sc3ccccc34)n2)c1 ; N#Cc1cccc(-c2nc(-c3ccc(-c4ccc5ccccc5c4)cc3)nc(-c3cccc4oc5ccccc5c34)n2)c1] 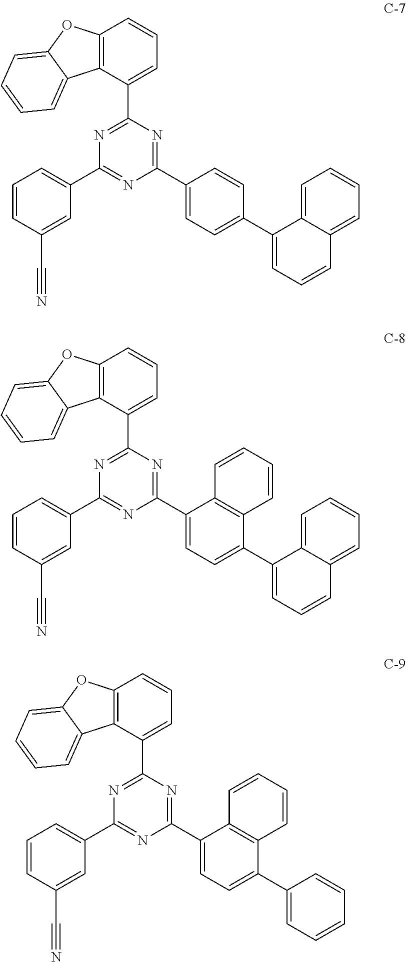 [SMILES: N#Cc1cccc(-c2nc(-c3ccc(-c4cccc5ccccc45)cc3)nc(-c3cccc4oc5ccccc5c34)n2)c1 ; N#Cc1cccc(-c2nc(-c3ccc(-c4cccc5ccccc45)c4ccccc34)nc(-c3cccc4oc5ccccc5c34)n2)c1 ; N#Cc1cccc(-c2nc(-c3ccc(-c4ccccc4)c4ccccc34)nc(-c3cccc4oc5ccccc5c34)n2)c1] 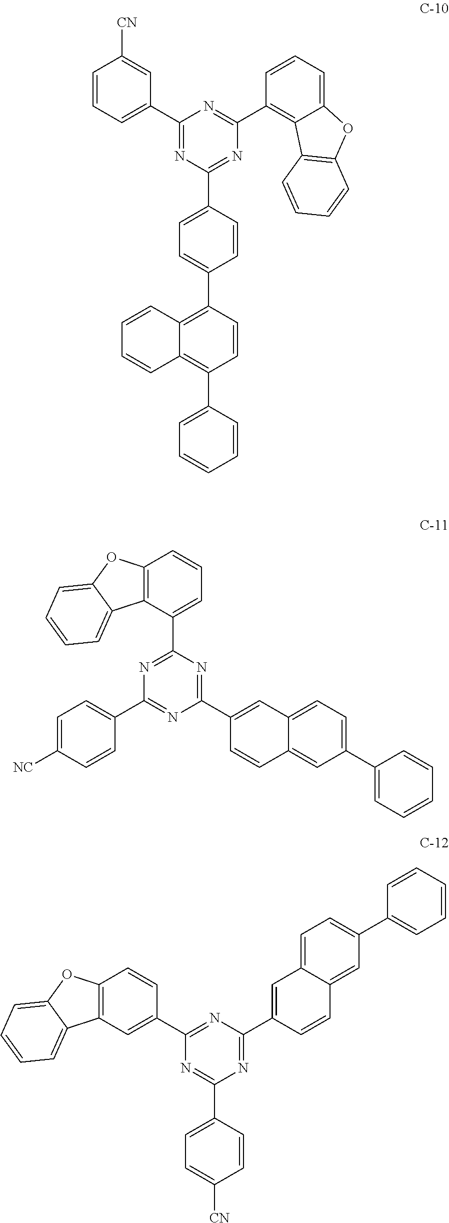 [SMILES: N#Cc1cccc(-c2nc(-c3ccc(-c4ccc(-c5ccccc5)c5ccccc45)cc3)nc(-c3cccc4oc5ccccc5c34)n2)c1 ; N#Cc1ccc(-c2nc(-c3ccc4cc(-c5ccccc5)ccc4c3)nc(-c3cccc4oc5ccccc5c34)n2)cc1 ; N#Cc1ccc(-c2nc(-c3ccc4cc(-c5ccccc5)ccc4c3)nc(-c3ccc4oc5ccccc5c4c3)n2)cc1] 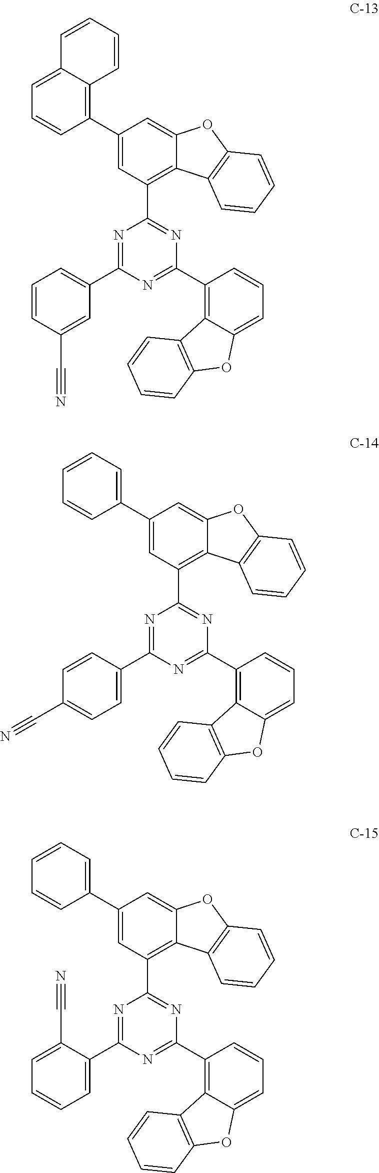 [SMILES: N#Cc1cccc(-c2nc(-c3cccc4oc5ccccc5c34)nc(-c3cc(-c4cccc5ccccc45)cc4oc5ccccc5c34)n2)c1 ; N#Cc1ccc(-c2nc(-c3cccc4oc5ccccc5c34)nc(-c3cc(-c4ccccc4)cc4oc5ccccc5c34)n2)cc1 ; N#Cc1ccccc1-c1nc(-c2cccc3oc4ccccc4c23)nc(-c2cc(-c3ccccc3)cc3oc4ccccc4c23)n1] 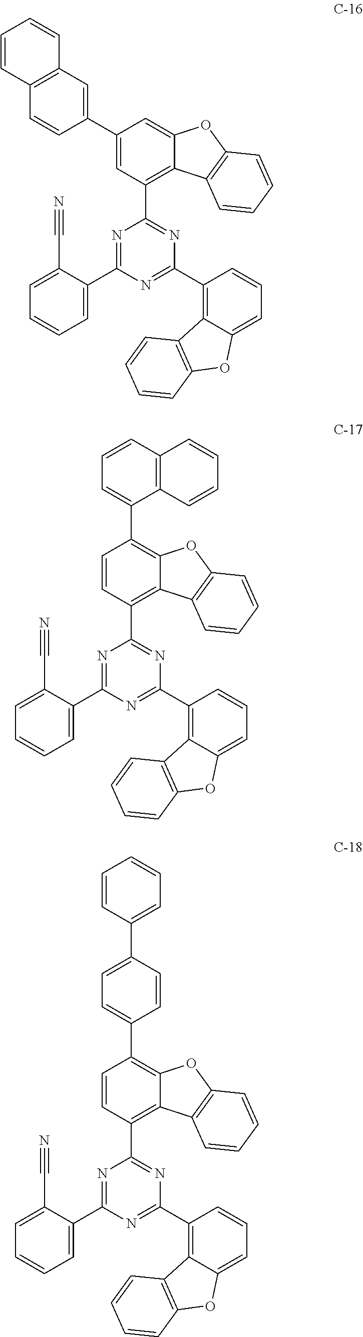 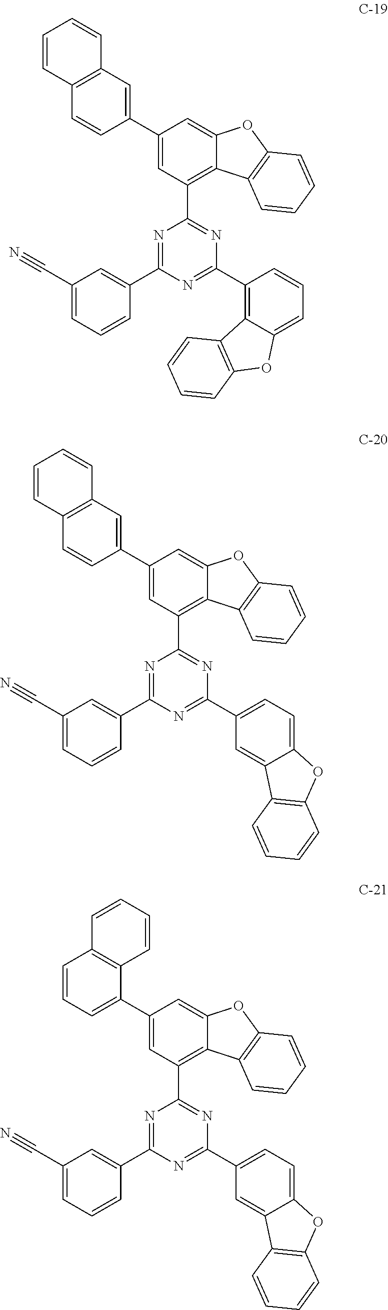 [SMILES: N#Cc1cccc(-c2nc(-c3cccc4oc5ccccc5c34)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4ccc5ccccc5c4)cc4oc5ccccc5c34)n2)c1 ; N#Cc1cccc(-c2nc(-c3ccc4oc5ccccc5c4c3)nc(-c3cc(-c4cccc5ccccc45)cc4oc5ccccc5c34)n2)c1] 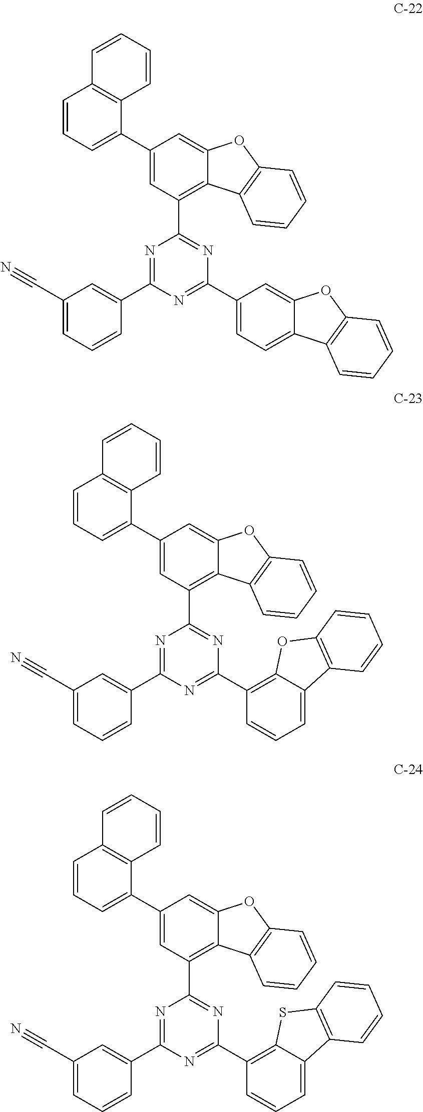 [SMILES: N#Cc1cccc(-c2nc(-c3ccc4c(c3)oc3ccccc34)nc(-c3cc(-c4cccc5ccccc45)cc4oc5ccccc5c34)n2)c1 ; N#Cc1cccc(-c2nc(-c3cccc4c3oc3ccccc34)nc(-c3cc(-c4cccc5ccccc45)cc4oc5ccccc5c34)n2)c1 ; N#Cc1cccc(-c2nc(-c3cccc4c3sc3ccccc34)nc(-c3cc(-c4cccc5ccccc45)cc4oc5ccccc5c34)n2)c1] 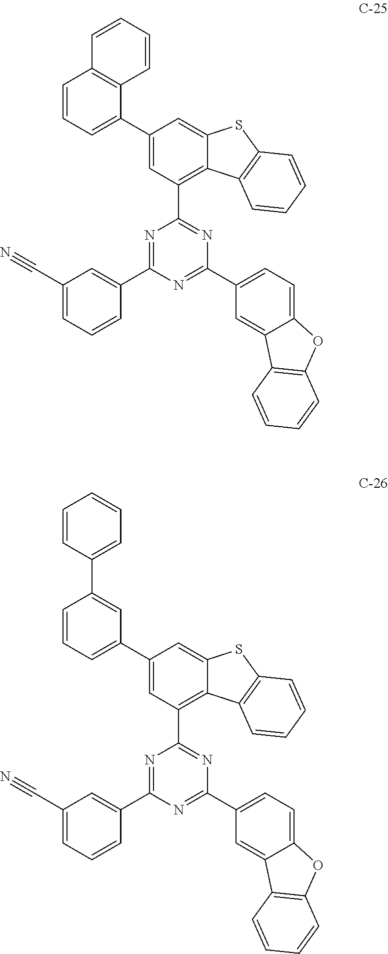 [SMILES: N#Cc1cccc(-c2nc(-c3ccc4oc5ccccc5c4c3)nc(-c3cc(-c4cccc5ccccc45)cc4sc5ccccc5c34)n2)c1 ; N#Cc1cccc(-c2nc(-c3ccc4oc5ccccc5c4c3)nc(-c3cc(-c4cccc(-c5ccccc5)c4)cc4sc5ccccc5c34)n2)c1] 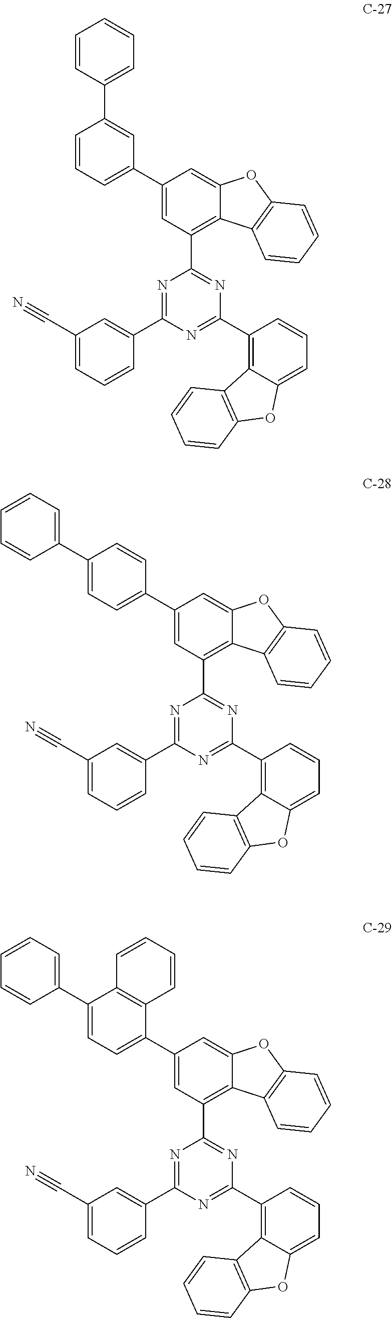 [SMILES: N#Cc1cccc(-c2nc(-c3cccc4oc5ccccc5c34)nc(-c3cc(-c4cccc(-c5ccccc5)c4)cc4oc5ccccc5c34)n2)c1 ; N#Cc1cccc(-c2nc(-c3cccc4oc5ccccc5c34)nc(-c3cc(-c4ccc(-c5ccccc5)cc4)cc4oc5ccccc5c34)n2)c1 ; N#Cc1cccc(-c2nc(-c3cccc4oc5ccccc5c34)nc(-c3cc(-c4ccc(-c5ccccc5)c5ccccc45)cc4oc5ccccc5c34)n2)c1] 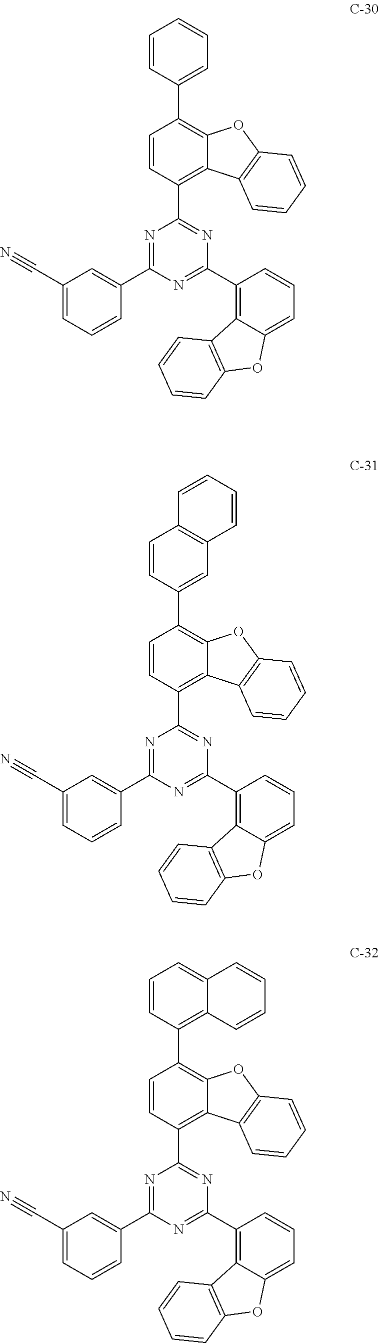 [SMILES: N#Cc1cccc(-c2nc(-c3cccc4oc5ccccc5c34)nc(-c3ccc(-c4ccccc4)c4oc5ccccc5c34)n2)c1 ; N#Cc1cccc(-c2nc(-c3cccc4oc5ccccc5c34)nc(-c3ccc(-c4ccc5ccccc5c4)c4oc5ccccc5c34)n2)c1 ; N#Cc1cccc(-c2nc(-c3cccc4oc5ccccc5c34)nc(-c3ccc(-c4cccc5ccccc45)c4oc5ccccc5c34)n2)c1] 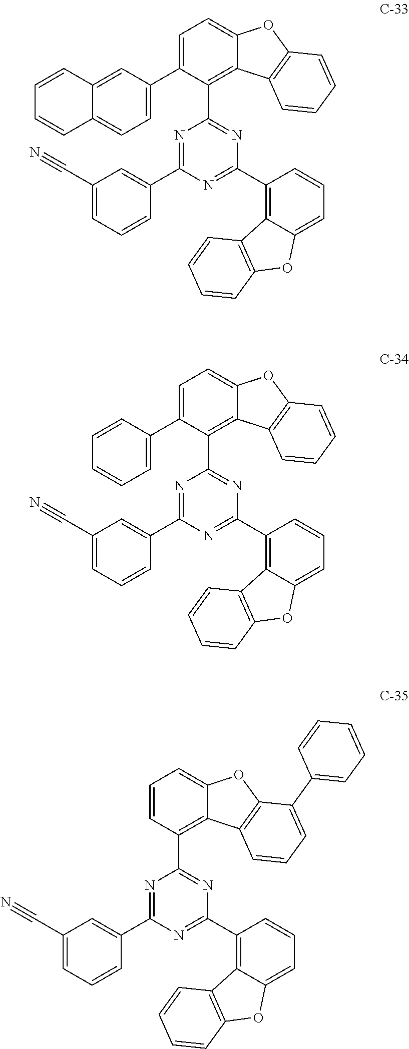 [SMILES: N#Cc1cccc(-c2nc(-c3cccc4oc5ccccc5c34)nc(-c3c(-c4ccc5ccccc5c4)ccc4oc5ccccc5c34)n2)c1 ; N#Cc1cccc(-c2nc(-c3cccc4oc5ccccc5c34)nc(-c3c(-c4ccccc4)ccc4oc5ccccc5c34)n2)c1 ; N#Cc1cccc(-c2nc(-c3cccc4oc5ccccc5c34)nc(-c3cccc4oc5c(-c6ccccc6)cccc5c34)n2)c1] 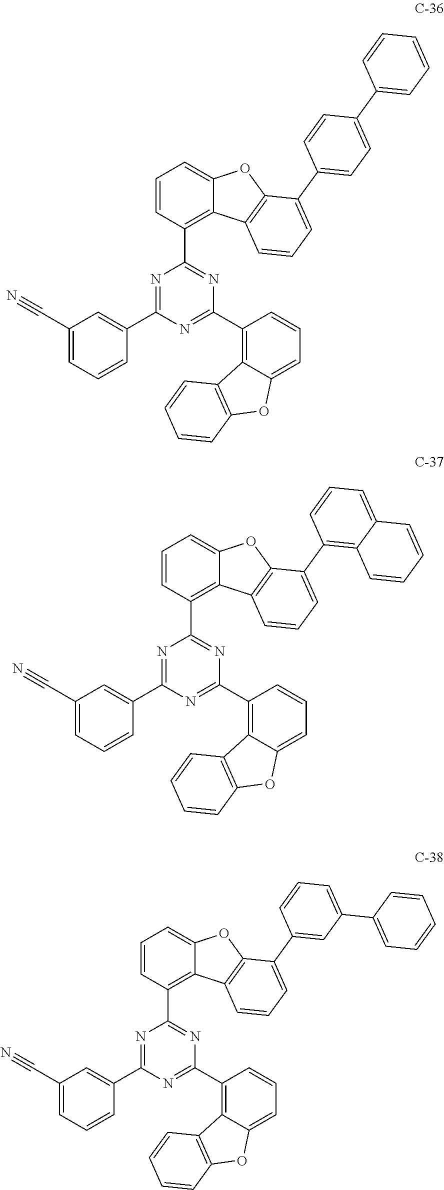 [SMILES: N#Cc1cccc(-c2nc(-c3cccc4oc5ccccc5c34)nc(-c3cccc4oc5c(-c6ccc(-c7ccccc7)cc6)cccc5c34)n2)c1 ; N#Cc1cccc(-c2nc(-c3cccc4oc5ccccc5c34)nc(-c3cccc4oc5c(-c6cccc7ccccc67)cccc5c34)n2)c1 ; N#Cc1cccc(-c2nc(-c3cccc4oc5ccccc5c34)nc(-c3cccc4oc5c(-c6cccc(-c7ccccc7)c6)cccc5c34)n2)c1] 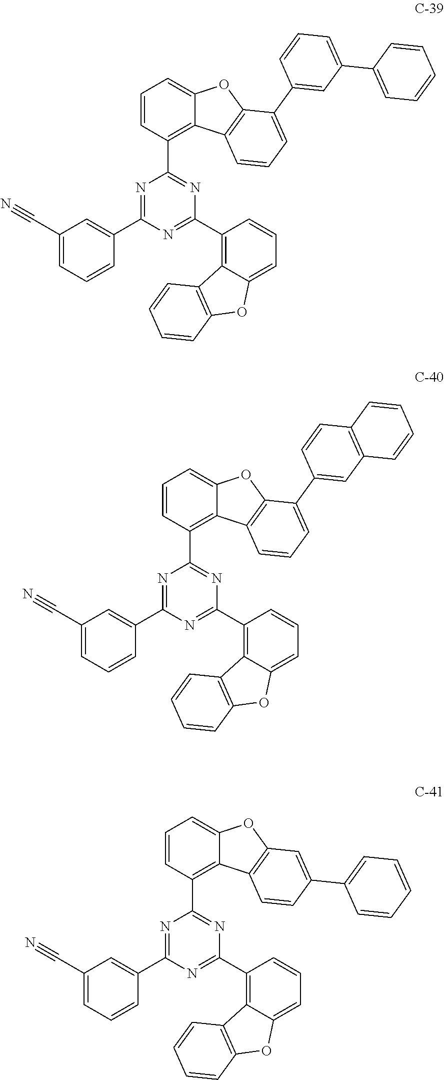 [SMILES: N#Cc1cccc(-c2nc(-c3cccc4oc5ccccc5c34)nc(-c3cccc4oc5c(-c6cccc(-c7ccccc7)c6)cccc5c34)n2)c1 ; N#Cc1cccc(-c2nc(-c3cccc4oc5ccccc5c34)nc(-c3cccc4oc5c(-c6ccc7ccccc7c6)cccc5c34)n2)c1 ; N#Cc1cccc(-c2nc(-c3cccc4oc5ccccc5c34)nc(-c3cccc4oc5cc(-c6ccccc6)ccc5c34)n2)c1] 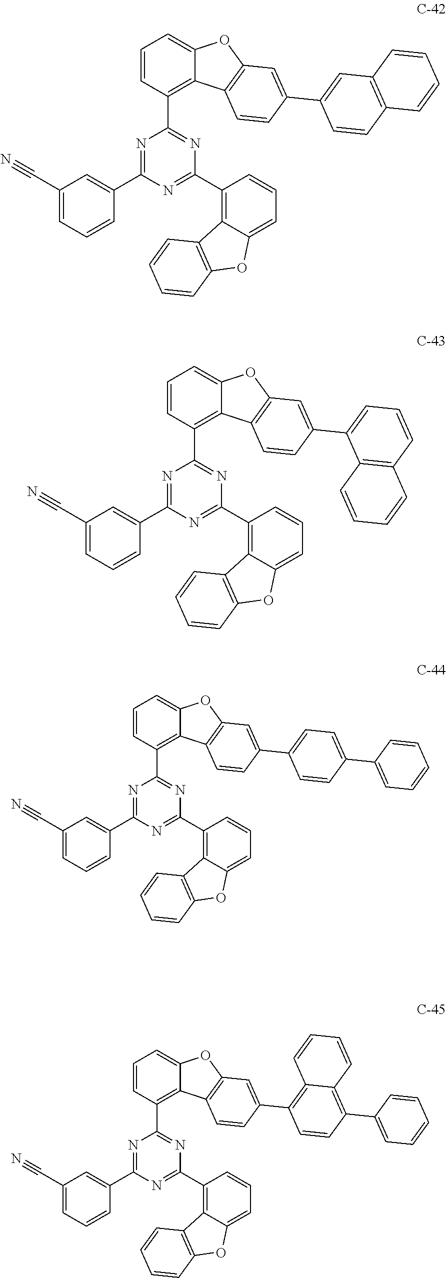 [SMILES: N#Cc1cccc(-c2nc(-c3cccc4oc5ccccc5c34)nc(-c3cccc4oc5cc(-c6ccc7ccccc7c6)ccc5c34)n2)c1 ; N#Cc1cccc(-c2nc(-c3cccc4oc5ccccc5c34)nc(-c3cccc4oc5cc(-c6cccc7ccccc67)ccc5c34)n2)c1 ; N#Cc1cccc(-c2nc(-c3cccc4oc5ccccc5c34)nc(-c3cccc4oc5cc(-c6ccc(-c7ccccc7)cc6)ccc5c34)n2)c1 ; N#Cc1cccc(-c2nc(-c3cccc4oc5ccccc5c34)nc(-c3cccc4oc5cc(-c6ccc(-c7ccccc7)c7ccccc67)ccc5c34)n2)c1] 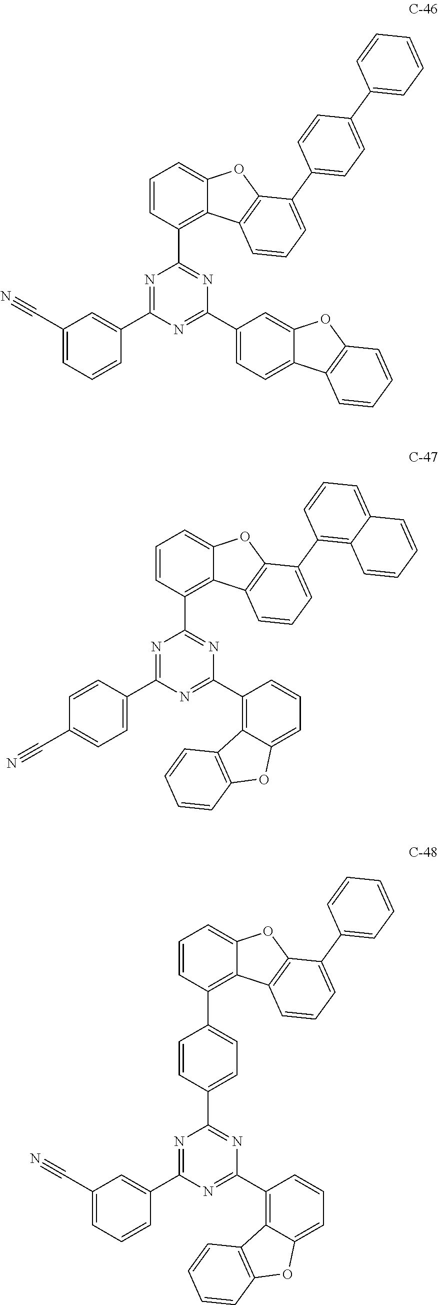 [SMILES: N#Cc1cccc(-c2nc(-c3ccc4c(c3)oc3ccccc34)nc(-c3cccc4oc5c(-c6ccc(-c7ccccc7)cc6)cccc5c34)n2)c1 ; N#Cc1ccc(-c2nc(-c3cccc4oc5ccccc5c34)nc(-c3cccc4oc5c(-c6cccc7ccccc67)cccc5c34)n2)cc1 ; N#Cc1cccc(-c2nc(-c3ccc(-c4cccc5oc6c(-c7ccccc7)cccc6c45)cc3)nc(-c3cccc4oc5ccccc5c34)n2)c1] 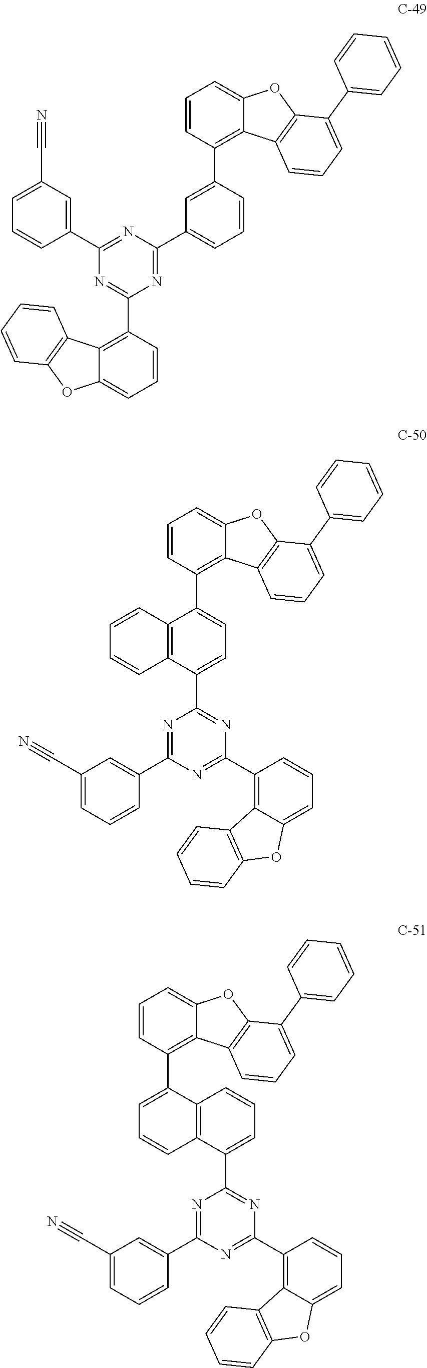 [SMILES: N#Cc1cccc(-c2nc(-c3cccc(-c4cccc5oc6c(-c7ccccc7)cccc6c45)c3)nc(-c3cccc4oc5ccccc5c34)n2)c1 ; N#Cc1cccc(-c2nc(-c3ccc(-c4cccc5oc6c(-c7ccccc7)cccc6c45)c4ccccc34)nc(-c3cccc4oc5ccccc5c34)n2)c1 ; N#Cc1cccc(-c2nc(-c3cccc4c(-c5cccc6oc7c(-c8ccccc8)cccc7c56)cccc34)nc(-c3cccc4oc5ccccc5c34)n2)c1] 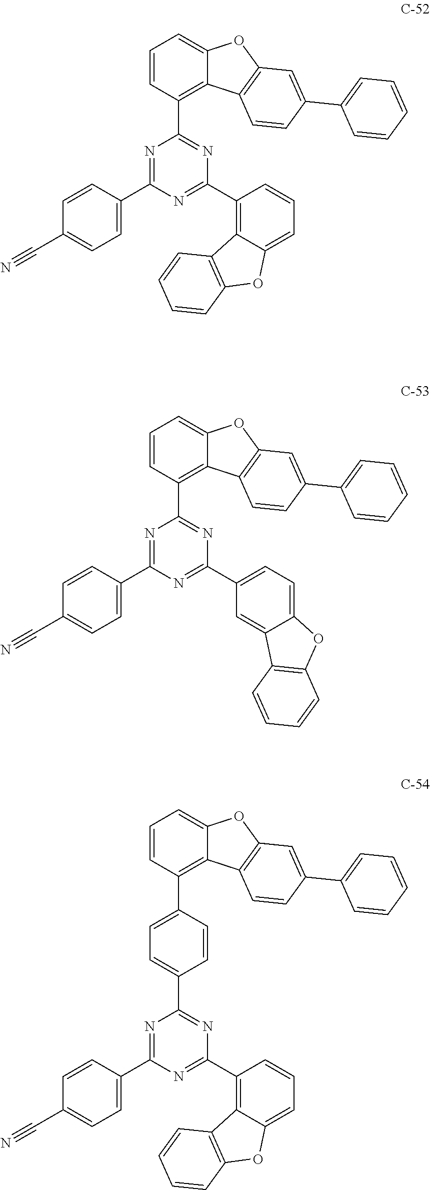 [SMILES: N#Cc1ccc(-c2nc(-c3cccc4oc5ccccc5c34)nc(-c3cccc4oc5cc(-c6ccccc6)ccc5c34)n2)cc1 ; N#Cc1ccc(-c2nc(-c3ccc4oc5ccccc5c4c3)nc(-c3cccc4oc5cc(-c6ccccc6)ccc5c34)n2)cc1 ; N#Cc1ccc(-c2nc(-c3ccc(-c4cccc5oc6cc(-c7ccccc7)ccc6c45)cc3)nc(-c3cccc4oc5ccccc5c34)n2)cc1] 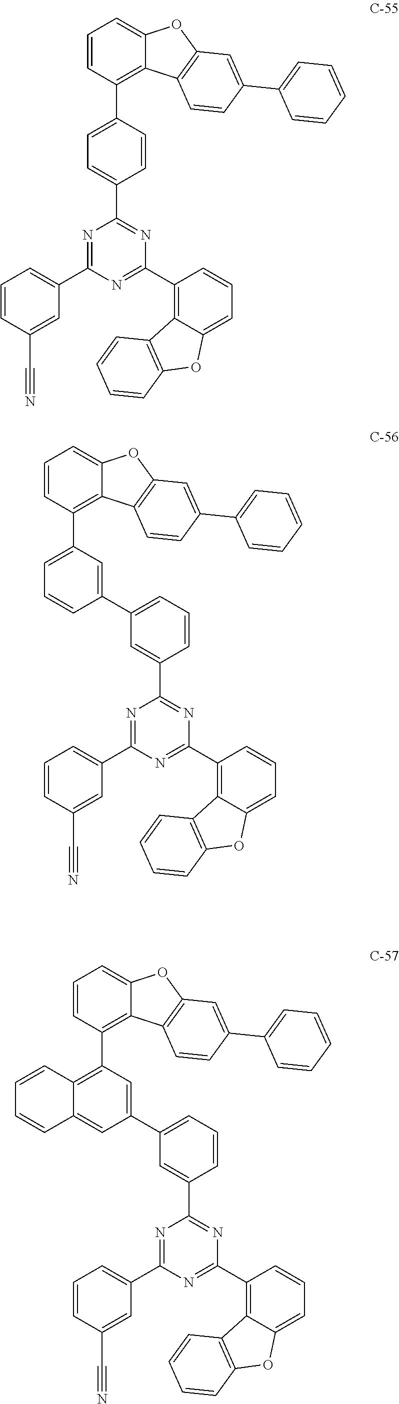 [SMILES: N#Cc1cccc(-c2nc(-c3ccc(-c4cccc5oc6cc(-c7ccccc7)ccc6c45)cc3)nc(-c3cccc4oc5ccccc5c34)n2)c1 ; N#Cc1cccc(-c2nc(-c3cccc(-c4cccc(-c5cccc6oc7cc(-c8ccccc8)ccc7c56)c4)c3)nc(-c3cccc4oc5ccccc5c34)n2)c1 ; N#Cc1cccc(-c2nc(-c3cccc(-c4cc(-c5cccc6oc7cc(-c8ccccc8)ccc7c56)c5ccccc5c4)c3)nc(-c3cccc4oc5ccccc5c34)n2)c1] 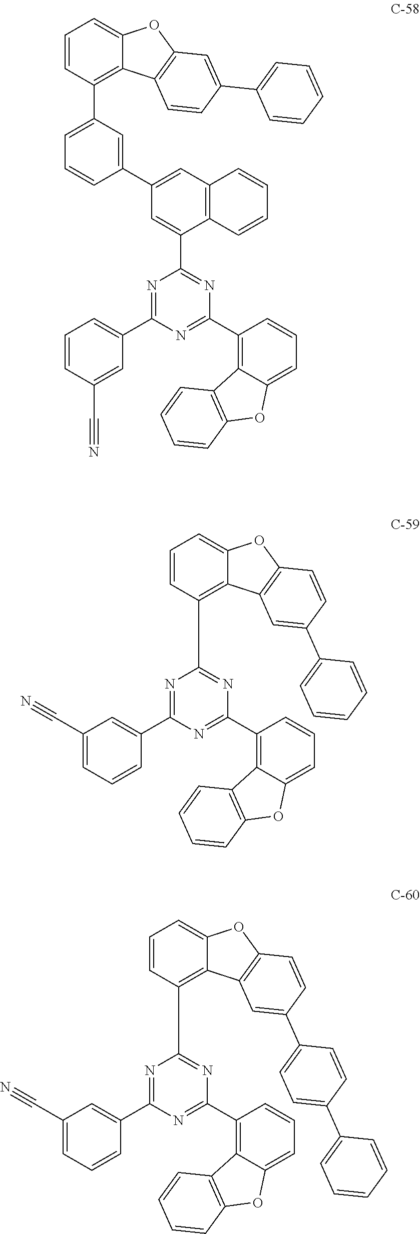 [SMILES: N#Cc1cccc(-c2nc(-c3cc(-c4cccc(-c5cccc6oc7cc(-c8ccccc8)ccc7c56)c4)cc4ccccc34)nc(-c3cccc4oc5ccccc5c34)n2)c1 ; N#Cc1cccc(-c2nc(Cc3cccc4oc5ccc(-c6ccccc6)cc5c34)nc(-c3cccc4oc5ccccc5c34)n2)c1 ; N#Cc1cccc(-c2nc(Cc3cccc4oc5ccc(-c6ccc(-c7ccccc7)cc6)cc5c34)nc(-c3cccc4oc5ccccc5c34)n2)c1] 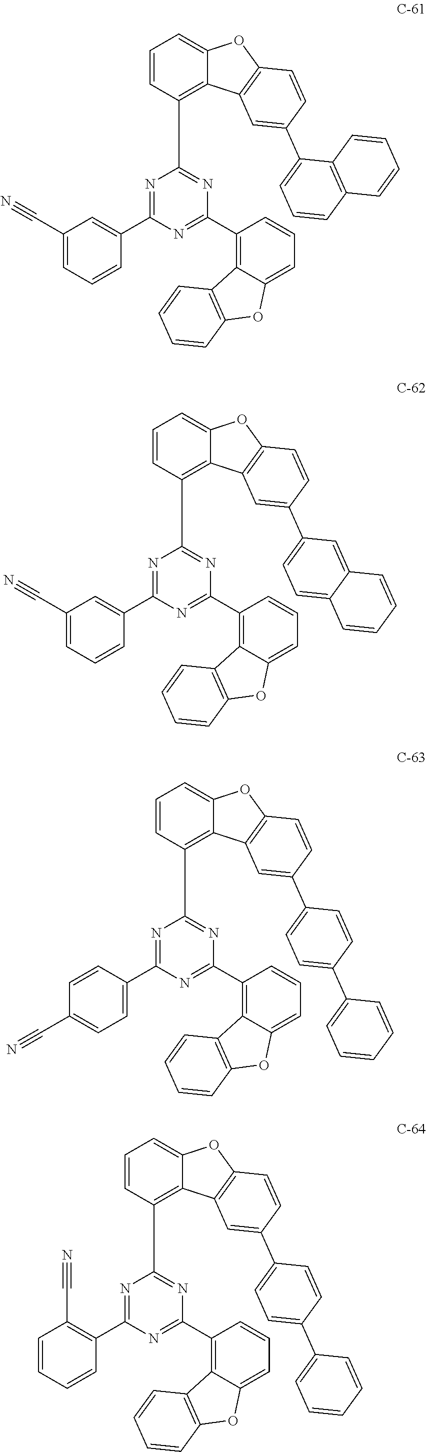 [SMILES: N#Cc1cccc(-c2nc(Cc3cccc4oc5ccc(-c6cccc7ccccc67)cc5c34)nc(-c3cccc4oc5ccccc5c34)n2)c1 ; N#Cc1cccc(-c2nc(Cc3cccc4oc5ccc(-c6ccc7ccccc7c6)cc5c34)nc(-c3cccc4oc5ccccc5c34)n2)c1 ; N#Cc1ccc(-c2nc(Cc3cccc4oc5ccc(-c6ccc(-c7ccccc7)cc6)cc5c34)nc(-c3cccc4oc5ccccc5c34)n2)cc1 ; N#Cc1ccccc1-c1nc(Cc2cccc3oc4ccc(-c5ccc(-c6ccccc6)cc5)cc4c23)nc(-c2cccc3oc4ccccc4c23)n1] 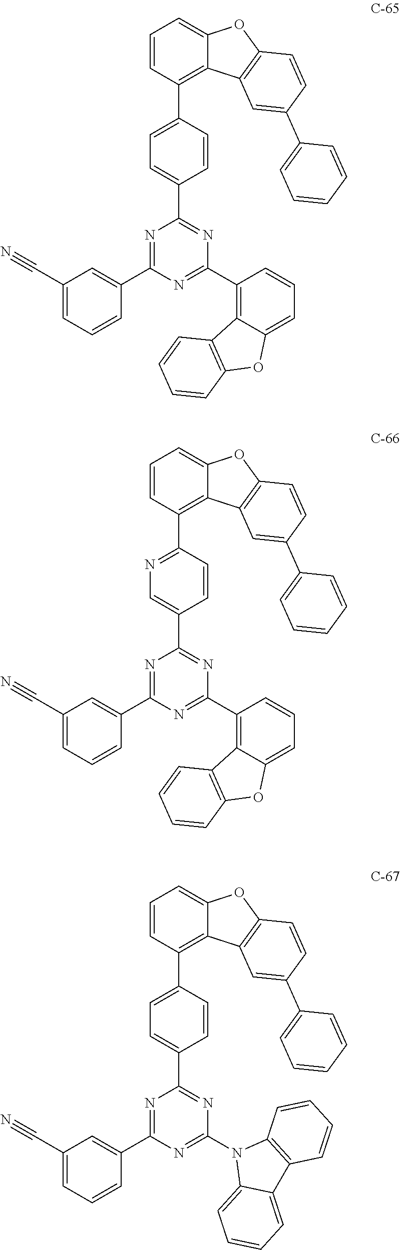 [SMILES: N#Cc1cccc(-c2nc(-c3ccc(-c4cccc5oc6ccc(-c7ccccc7)cc6c45)cc3)nc(-c3cccc4oc5ccccc5c34)n2)c1 ; N#Cc1cccc(-c2nc(-c3ccc(-c4cccc5oc6ccc(-c7ccccc7)cc6c45)nc3)nc(-c3cccc4oc5ccccc5c34)n2)c1 ; N#Cc1cccc(-c2nc(-c3ccc(-c4cccc5oc6ccc(-c7ccccc7)cc6c45)cc3)nc(-n3c4ccccc4c4ccccc43)n2)c1] 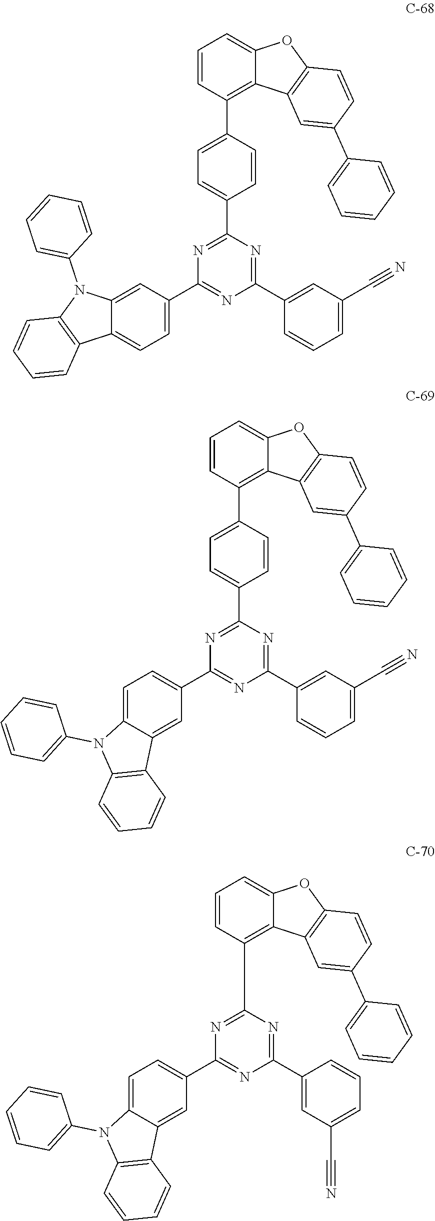 [SMILES: N#Cc1cccc(-c2nc(-c3ccc(-c4cccc5oc6ccc(-c7ccccc7)cc6c45)cc3)nc(-c3ccc4c5ccccc5n(-c5ccccc5)c4c3)n2)c1 ; N#Cc1cccc(-c2nc(-c3ccc(-c4cccc5oc6ccc(-c7ccccc7)cc6c45)cc3)nc(-c3ccc4c(c3)c3ccccc3n4-c3ccccc3)n2)c1 ; N#Cc1cccc(-c2nc(Cc3cccc4oc5ccc(-c6ccccc6)cc5c34)nc(-c3ccc4c(c3)c3ccccc3n4-c3ccccc3)n2)c1] 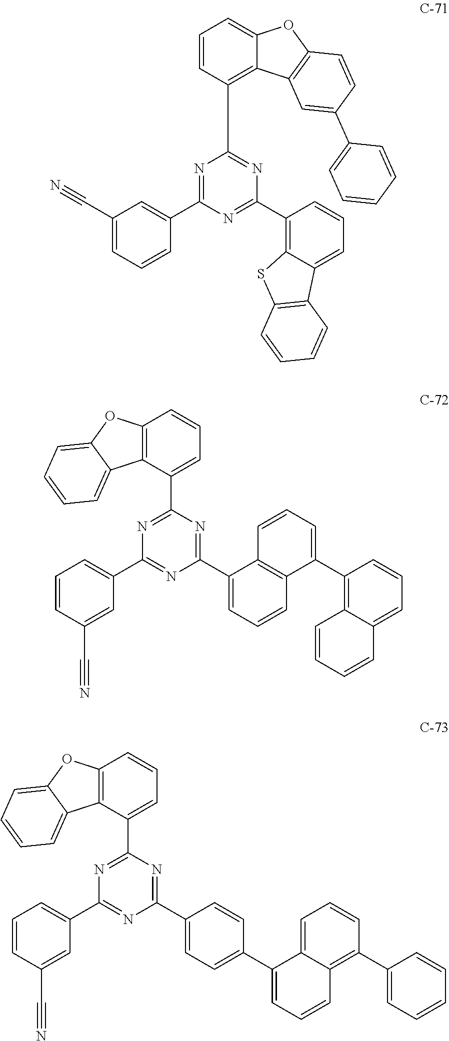 [SMILES: N#Cc1cccc(-c2nc(Cc3cccc4oc5ccc(-c6ccccc6)cc5c34)nc(-c3cccc4c3sc3ccccc34)n2)c1 ; N#Cc1cccc(-c2nc(-c3cccc4c(-c5cccc6ccccc56)cccc34)nc(-c3cccc4oc5ccccc5c34)n2)c1 ; N#Cc1cccc(-c2nc(-c3ccc(-c4cccc5c(-c6ccccc6)cccc45)cc3)nc(-c3cccc4oc5ccccc5c34)n2)c1] 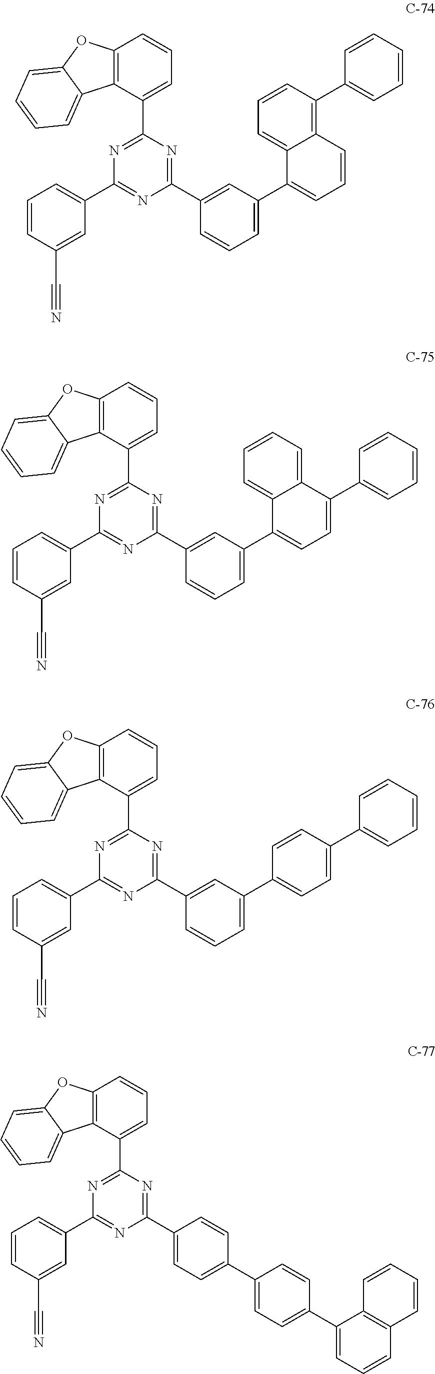 [SMILES: N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1 ; N#Cc1cccc(-c2nc(-c3cccc(-c4ccc(-c5ccccc5)cc4)c3)nc(-c3cccc4oc5ccccc5c34)n2)c1 ; N#Cc1cccc(-c2nc(-c3ccc(-c4ccc(-c5cccc6ccccc56)cc4)cc3)nc(-c3cccc4oc5ccccc5c34)n2)c1] 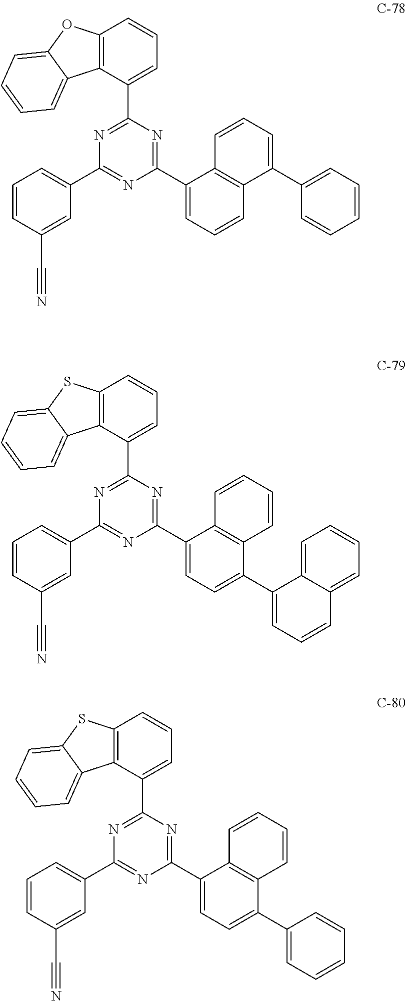 [SMILES: N#Cc1cccc(-c2nc(-c3cccc4c(-c5ccccc5)cccc34)nc(-c3cccc4oc5ccccc5c34)n2)c1 ; N#Cc1cccc(-c2nc(-c3ccc(-c4cccc5ccccc45)c4ccccc34)nc(-c3cccc4sc5ccccc5c34)n2)c1 ; N#Cc1cccc(-c2nc(-c3ccc(-c4ccccc4)c4ccccc34)nc(-c3cccc4sc5ccccc5c34)n2)c1] 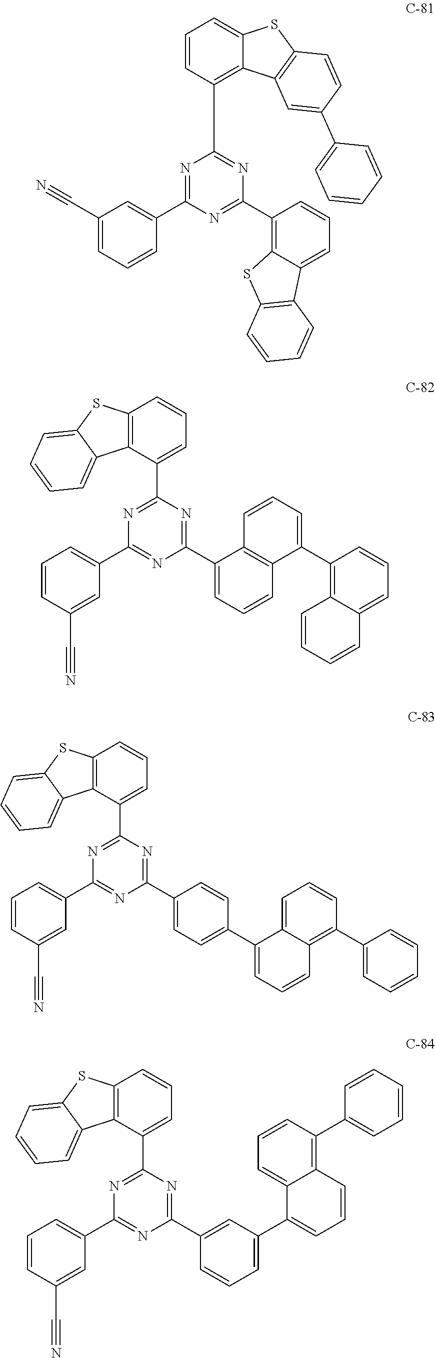 [SMILES: N#Cc1cccc(-c2nc(Cc3cccc4sc5ccc(-c6ccccc6)cc5c34)nc(-c3cccc4c3sc3ccccc34)n2)c1 ; N#Cc1cccc(-c2nc(-c3cccc4c(-c5cccc6ccccc56)cccc34)nc(-c3cccc4sc5ccccc5c34)n2)c1 ; N#Cc1cccc(-c2nc(-c3ccc(-c4cccc5c(-c6ccccc6)cccc45)cc3)nc(-c3cccc4sc5ccccc5c34)n2)c1 ; N#Cc1cccc(-c2nc(-c3cccc(-c4cccc5c(-c6ccccc6)cccc45)c3)nc(-c3cccc4sc5ccccc5c34)n2)c1] 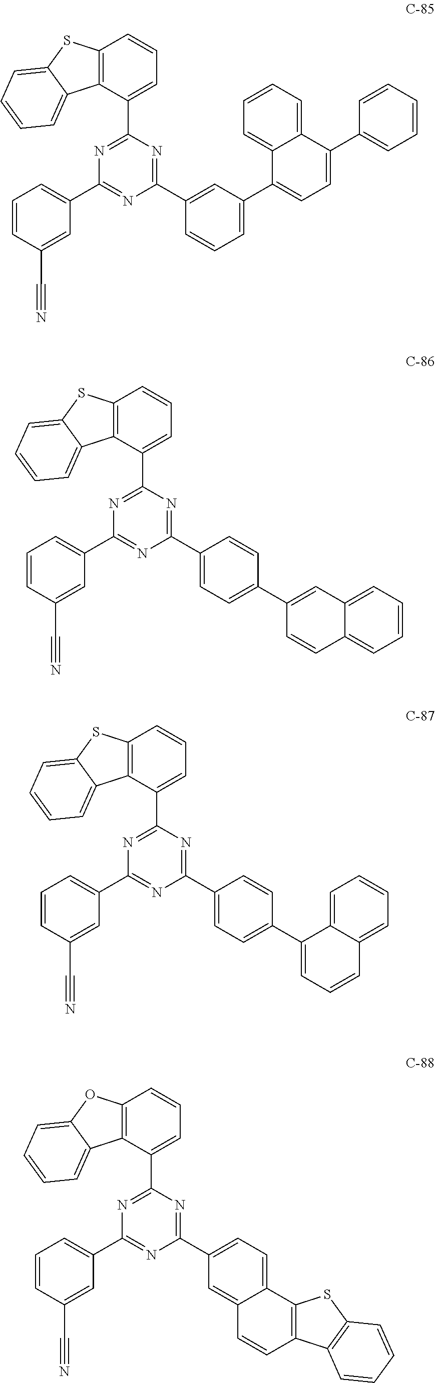 [SMILES: N#Cc1cccc(-c2nc(-c3cccc(-c4ccc(-c5ccccc5)c5ccccc45)c3)nc(-c3cccc4sc5ccccc5c34)n2)c1 ; N#Cc1cccc(-c2nc(-c3ccc(-c4ccc5ccccc5c4)cc3)nc(-c3cccc4sc5ccccc5c34)n2)c1 ; N#Cc1cccc(-c2nc(-c3ccc(-c4cccc5ccccc45)cc3)nc(-c3cccc4sc5ccccc5c34)n2)c1 ; N#Cc1cccc(-c2nc(-c3ccc4c(ccc5c6ccccc6sc45)c3)nc(-c3cccc4oc5ccccc5c34)n2)c1] 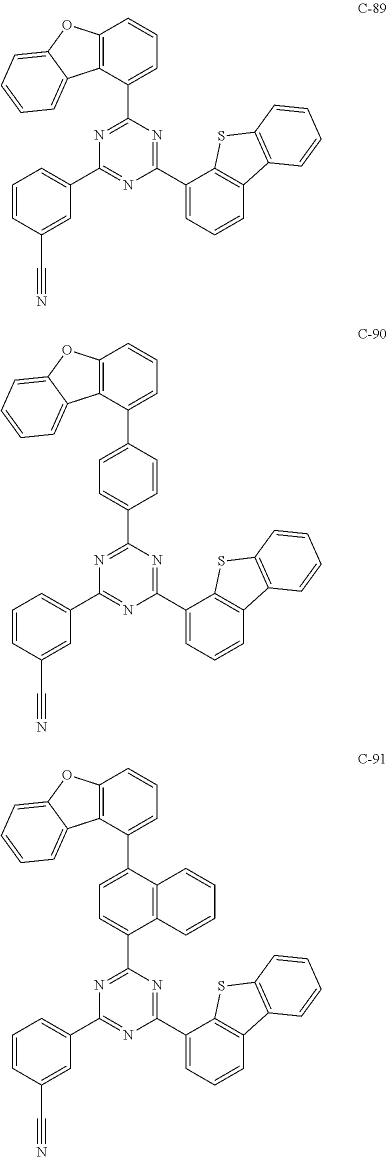 [SMILES: N#Cc1cccc(-c2nc(-c3cccc4c3sc3ccccc34)nc(-c3cccc4oc5ccccc5c34)n2)c1 ; N#Cc1cccc(-c2nc(-c3ccc(-c4cccc5oc6ccccc6c45)cc3)nc(-c3cccc4c3sc3ccccc34)n2)c1 ; N#Cc1cccc(-c2nc(-c3ccc(-c4cccc5oc6ccccc6c45)c4ccccc34)nc(-c3cccc4c3sc3ccccc34)n2)c1] 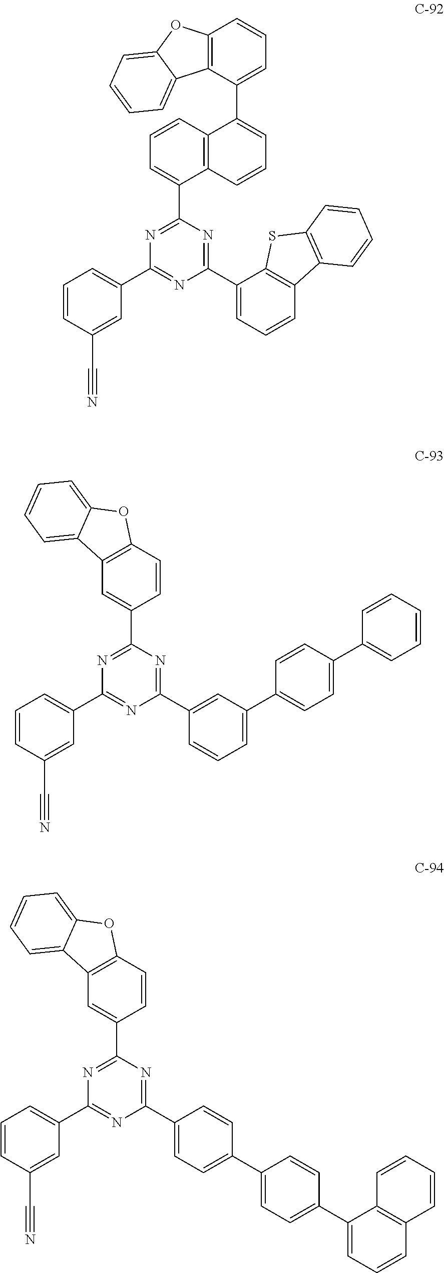 [SMILES: N#Cc1cccc(-c2nc(-c3cccc4c(-c5cccc6oc7ccccc7c56)cccc34)nc(-c3cccc4c3sc3ccccc34)n2)c1 ; N#Cc1cccc(-c2nc(-c3cccc(-c4ccc(-c5ccccc5)cc4)c3)nc(-c3ccc4oc5ccccc5c4c3)n2)c1 ; N#Cc1cccc(-c2nc(-c3ccc(-c4ccc(-c5cccc6ccccc56)cc4)cc3)nc(-c3ccc4oc5ccccc5c4c3)n2)c1] 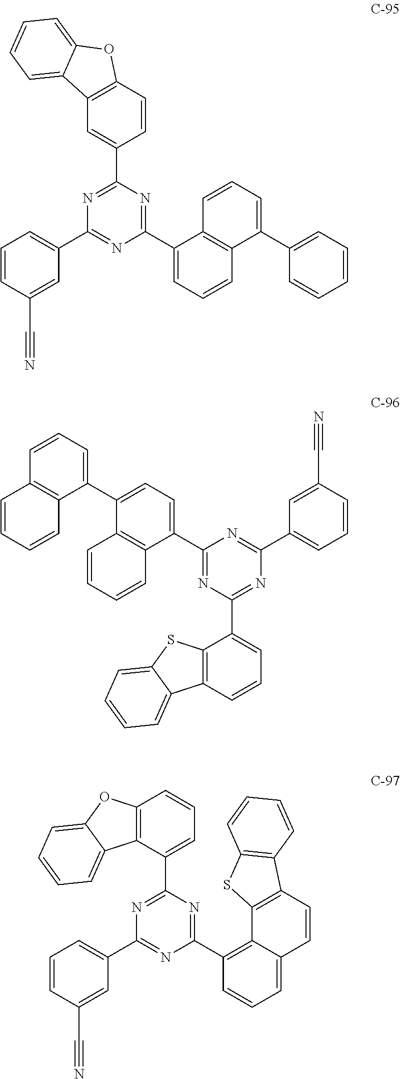 [SMILES: N#Cc1cccc(-c2nc(-c3ccc4oc5ccccc5c4c3)nc(-c3cccc4c(-c5ccccc5)cccc34)n2)c1 ; N#Cc1cccc(-c2nc(-c3ccc(-c4cccc5ccccc45)c4ccccc34)nc(-c3cccc4c3sc3ccccc34)n2)c1 ; N#Cc1cccc(-c2nc(-c3cccc4oc5ccccc5c34)nc(-c3cccc4ccc5c6ccccc6sc5c34)n2)c1] 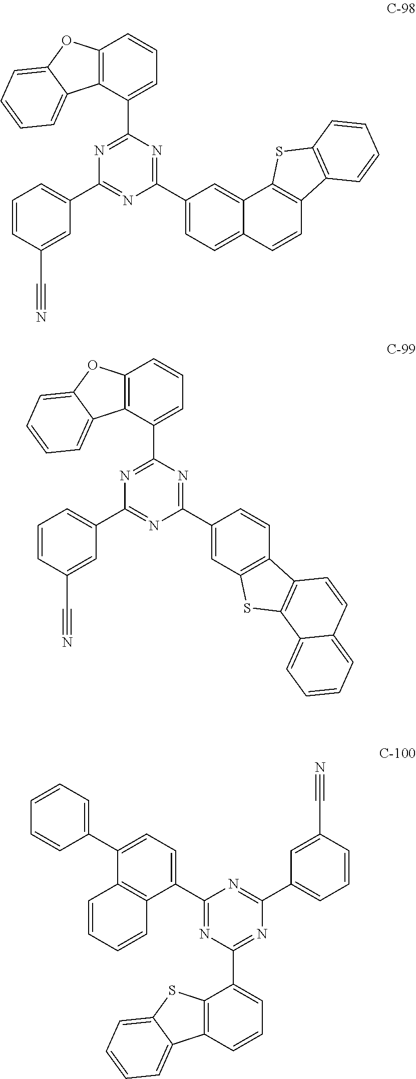 [SMILES: N#Cc1cccc(-c2nc(-c3ccc4ccc5c6ccccc6sc5c4c3)nc(-c3cccc4oc5ccccc5c34)n2)c1 ; N#Cc1cccc(-c2nc(-c3ccc4c(c3)sc3c5ccccc5ccc43)nc(-c3cccc4oc5ccccc5c34)n2)c1 ; N#Cc1cccc(-c2nc(-c3ccc(-c4ccccc4)c4ccccc34)nc(-c3cccc4c3sc3ccccc34)n2)c1] 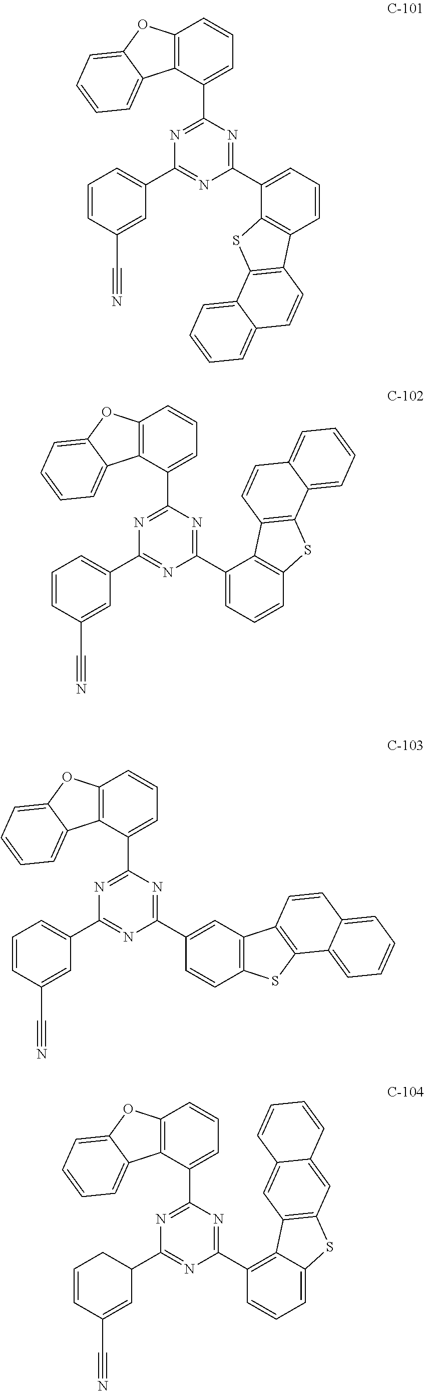 [SMILES: N#Cc1cccc(-c2nc(-c3cccc4c3sc3c5ccccc5ccc43)nc(-c3cccc4oc5ccccc5c34)n2)c1 ; N#Cc1cccc(-c2nc(-c3cccc4oc5ccccc5c34)nc(-c3cccc4sc5c6ccccc6ccc5c34)n2)c1 ; N#Cc1cccc(-c2nc(-c3ccc4sc5c6ccccc6ccc5c4c3)nc(-c3cccc4oc5ccccc5c34)n2)c1 ; N#CC1=CC(c2nc(-c3cccc4oc5ccccc5c34)nc(-c3cccc4sc5cc6ccccc6cc5c34)n2)CC=C1] 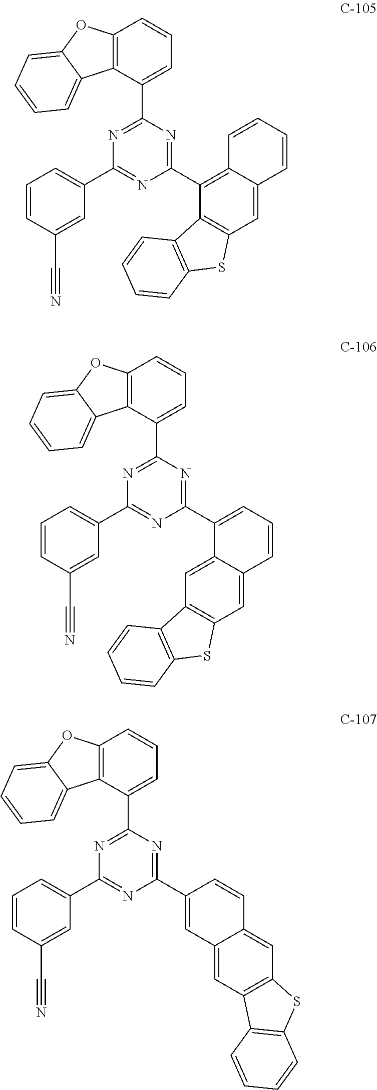 [SMILES: N#Cc1cccc(-c2nc(-c3cccc4oc5ccccc5c34)nc(-c3c4ccccc4cc4sc5ccccc5c34)n2)c1 ; N#Cc1cccc(-c2nc(-c3cccc4cc5sc6ccccc6c5cc34)nc(-c3cccc4oc5ccccc5c34)n2)c1 ; N#Cc1cccc(-c2nc(-c3ccc4cc5sc6ccccc6c5cc4c3)nc(-c3cccc4oc5ccccc5c34)n2)c1] 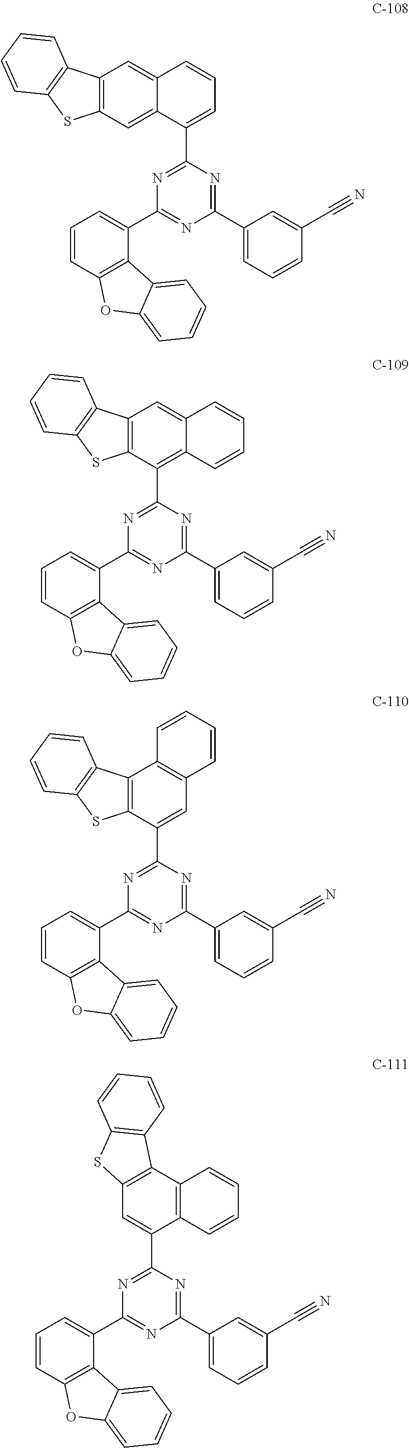 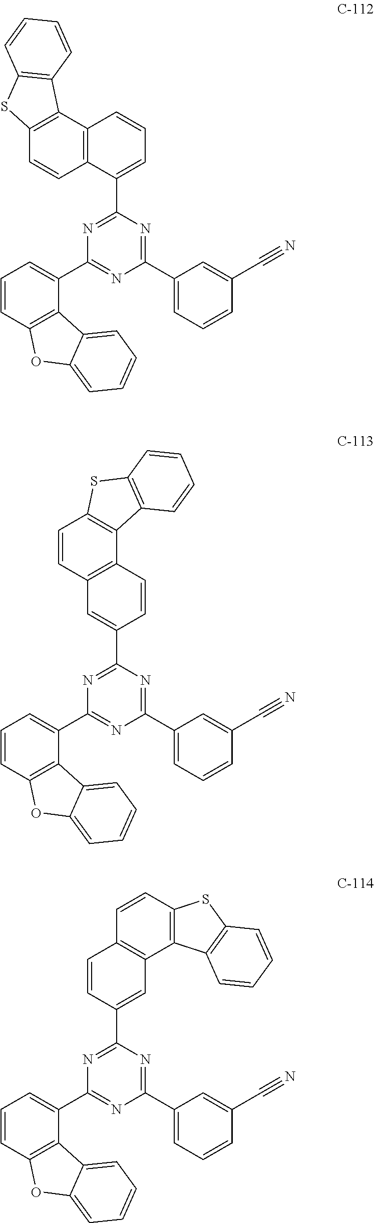 [SMILES: N#Cc1cccc(-c2nc(-c3cccc4c3ccc3sc5ccccc5c34)nc(-c3cccc4oc5ccccc5c34)n2)c1 ; N#Cc1cccc(-c2nc(-c3ccc4c(ccc5sc6ccccc6c54)c3)nc(-c3cccc4oc5ccccc5c34)n2)c1 ; N#Cc1cccc(-c2nc(-c3ccc4ccc5sc6ccccc6c5c4c3)nc(-c3cccc4oc5ccccc5c34)n2)c1] 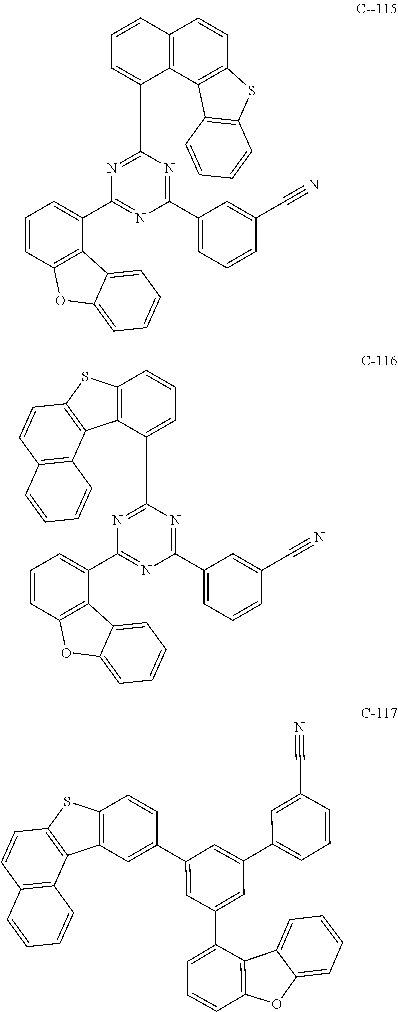 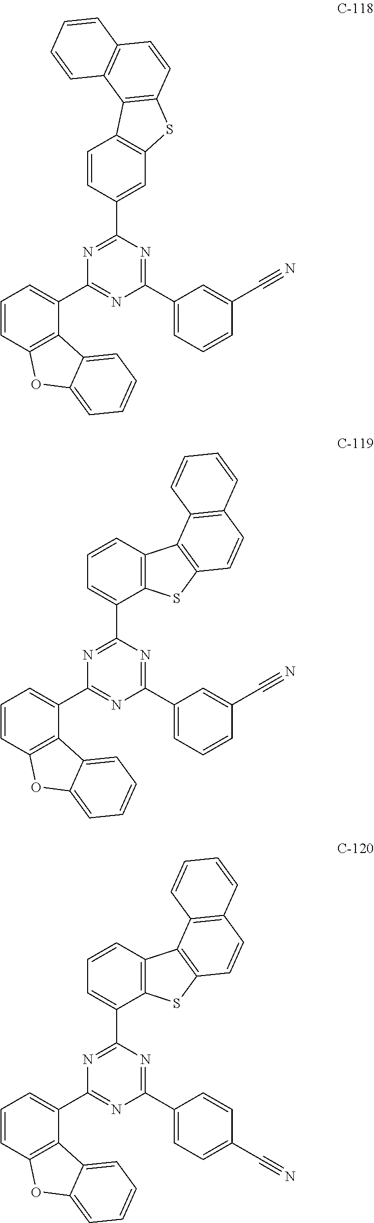 [SMILES: N#Cc1cccc(-c2nc(-c3ccc4c(c3)sc3ccc5ccccc5c34)nc(-c3cccc4oc5ccccc5c34)n2)c1 ; N#Cc1cccc(-c2nc(-c3cccc4c3sc3ccc5ccccc5c34)nc(-c3cccc4oc5ccccc5c34)n2)c1 ; N#Cc1ccc(-c2nc(-c3cccc4c3sc3ccc5ccccc5c34)nc(-c3cccc4oc5ccccc5c34)n2)cc1] 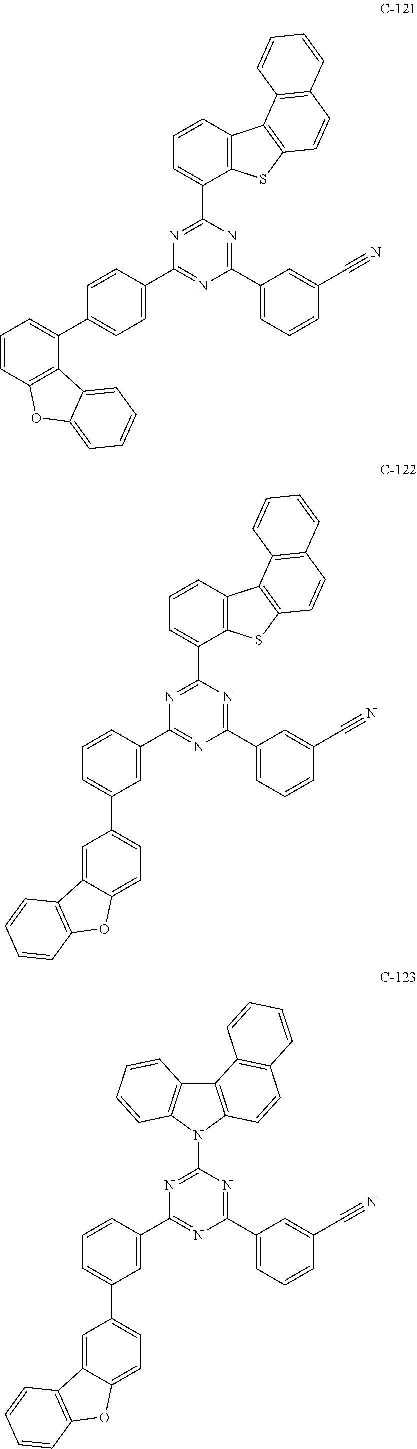 [SMILES: N#Cc1cccc(-c2nc(-c3ccc(-c4cccc5oc6ccccc6c45)cc3)nc(-c3cccc4c3sc3ccc5ccccc5c34)n2)c1 ; N#Cc1cccc(-c2nc(-c3cccc(-c4ccc5oc6ccccc6c5c4)c3)nc(-c3cccc4c3sc3ccc5ccccc5c34)n2)c1 ; N#Cc1cccc(-c2nc(-c3cccc(-c4ccc5oc6ccccc6c5c4)c3)nc(-n3c4ccccc4c4c5ccccc5ccc43)n2)c1] 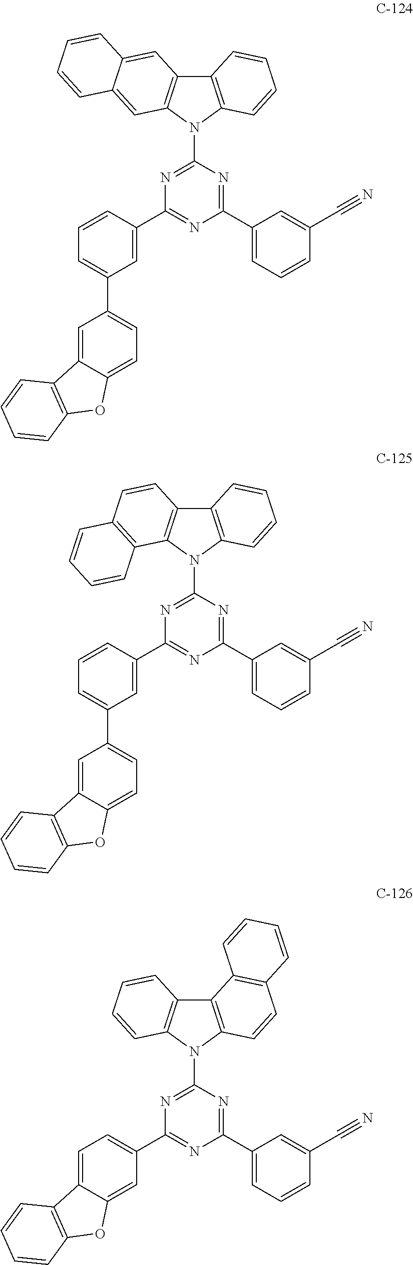 [SMILES: N#Cc1cccc(-c2nc(-c3cccc(-c4ccc5oc6ccccc6c5c4)c3)nc(-n3c4ccccc4c4cc5ccccc5cc43)n2)c1 ; N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4c(c3)oc3ccccc34)nc(-n3c4ccccc4c4c5ccccc5ccc43)n2)c1] 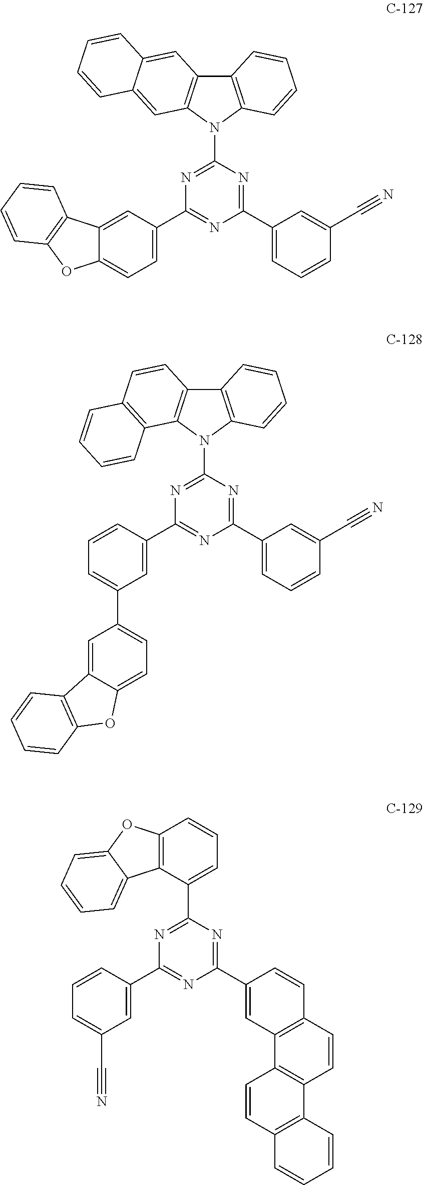 [SMILES: N#Cc1cccc(-c2nc(-c3ccc4oc5ccccc5c4c3)nc(-n3c4ccccc4c4cc5ccccc5cc43)n2)c1 ; N#Cc1cccc(-c2nc(-c3cccc(-c4ccc5oc6ccccc6c5c4)c3)nc(-n3c4ccccc4c4ccc5ccccc5c43)n2)c1 ; N#Cc1cccc(-c2nc(-c3ccc4ccc5c6ccccc6ccc5c4c3)nc(-c3cccc4oc5ccccc5c34)n2)c1] 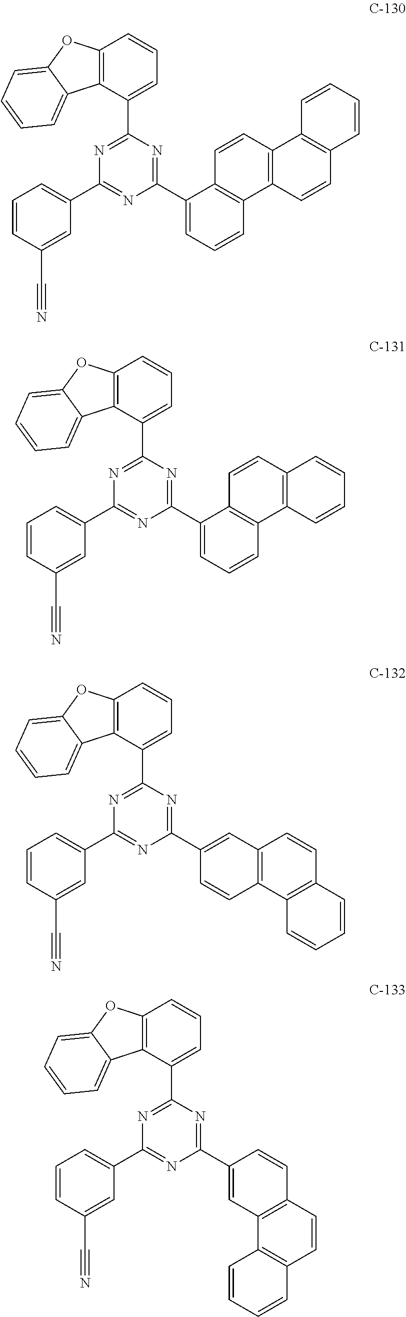 [SMILES: N#Cc1cccc(-c2nc(-c3cccc4c3ccc3c5ccccc5ccc43)nc(-c3cccc4oc5ccccc5c34)n2)c1 ; N#Cc1cccc(-c2nc(-c3cccc4c3ccc3ccccc34)nc(-c3cccc4oc5ccccc5c34)n2)c1 ; N#Cc1cccc(-c2nc(-c3ccc4c(ccc5ccccc54)c3)nc(-c3cccc4oc5ccccc5c34)n2)c1 ; N#Cc1cccc(-c2nc(-c3ccc4ccc5ccccc5c4c3)nc(-c3cccc4oc5ccccc5c34)n2)c1] 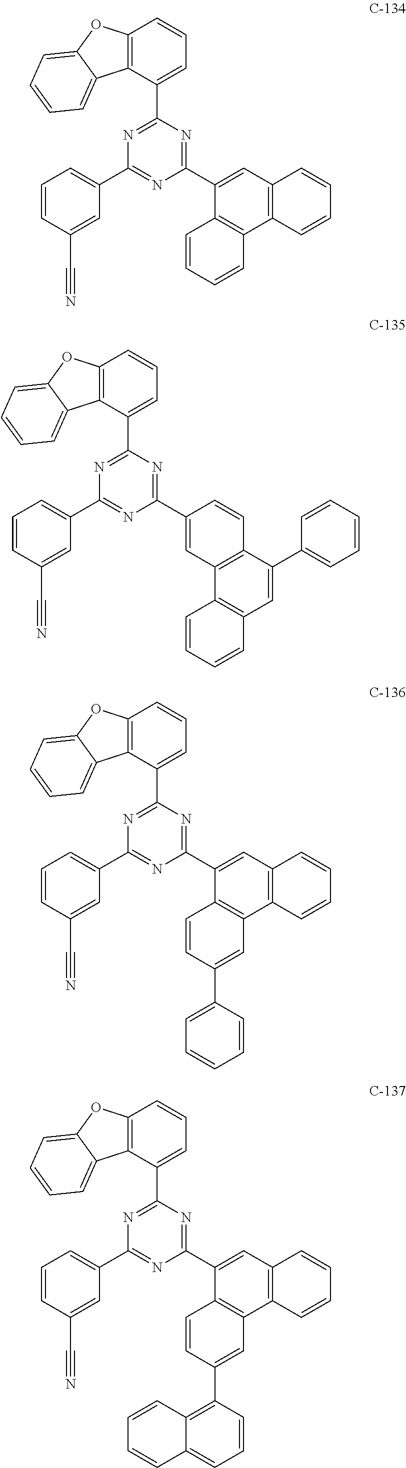 [SMILES: N#Cc1cccc(-c2nc(-c3cc4ccccc4c4ccccc34)nc(-c3cccc4oc5ccccc5c34)n2)c1 ; N#Cc1cccc(-c2nc(-c3ccc4c(-c5ccccc5)cc5ccccc5c4c3)nc(-c3cccc4oc5ccccc5c34)n2)c1 ; N#Cc1cccc(-c2nc(-c3cc4ccccc4c4cc(-c5ccccc5)ccc34)nc(-c3cccc4oc5ccccc5c34)n2)c1 ; N#Cc1cccc(-c2nc(-c3cc4ccccc4c4cc(-c5cccc6ccccc56)ccc34)nc(-c3cccc4oc5ccccc5c34)n2)c1] 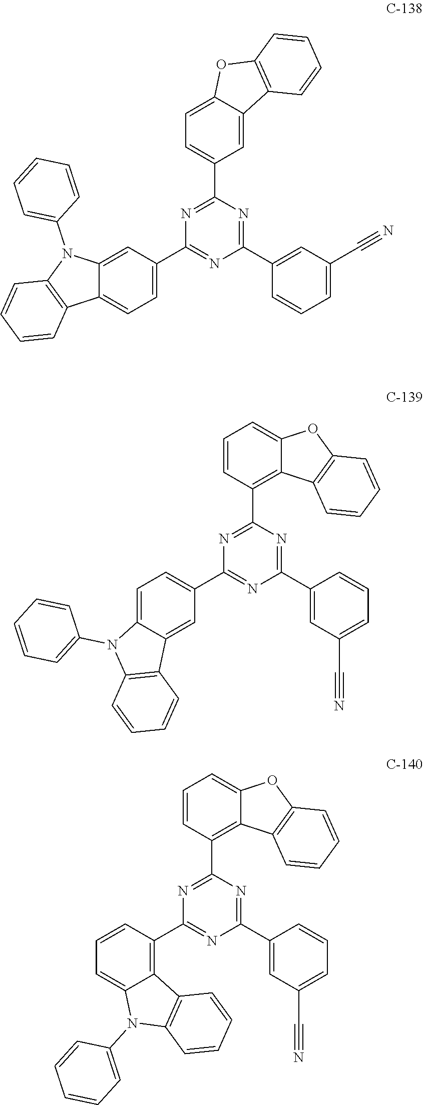 [SMILES: N#Cc1cccc(-c2nc(-c3ccc4oc5ccccc5c4c3)nc(-c3ccc4c5ccccc5n(-c5ccccc5)c4c3)n2)c1 ; N#Cc1cccc(-c2nc(-c3ccc4c(c3)c3ccccc3n4-c3ccccc3)nc(-c3cccc4oc5ccccc5c34)n2)c1 ; N#Cc1cccc(-c2nc(-c3cccc4oc5ccccc5c34)nc(-c3cccc4c3c3ccccc3n4-c3ccccc3)n2)c1] 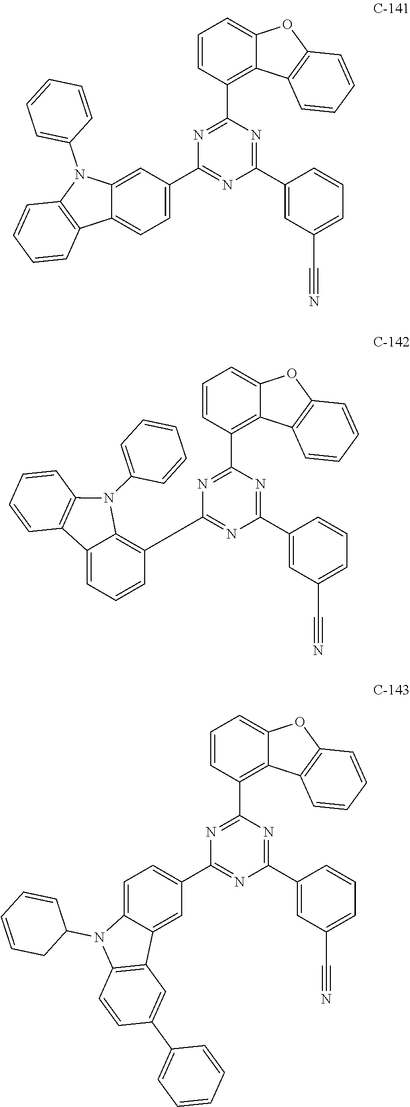 [SMILES: N#Cc1cccc(-c2nc(-c3ccc4c5ccccc5n(-c5ccccc5)c4c3)nc(-c3cccc4oc5ccccc5c34)n2)c1 ; N#Cc1cccc(-c2nc(Cc3cccc4c5ccccc5n(-c5ccccc5)c34)nc(-c3cccc4oc5ccccc5c34)n2)c1 ; N#Cc1cccc(-c2nc(-c3ccc4c(c3)c3cc(-c5ccccc5)ccc3n4C3C=CC=CC3)nc(-c3cccc4oc5ccccc5c34)n2)c1] 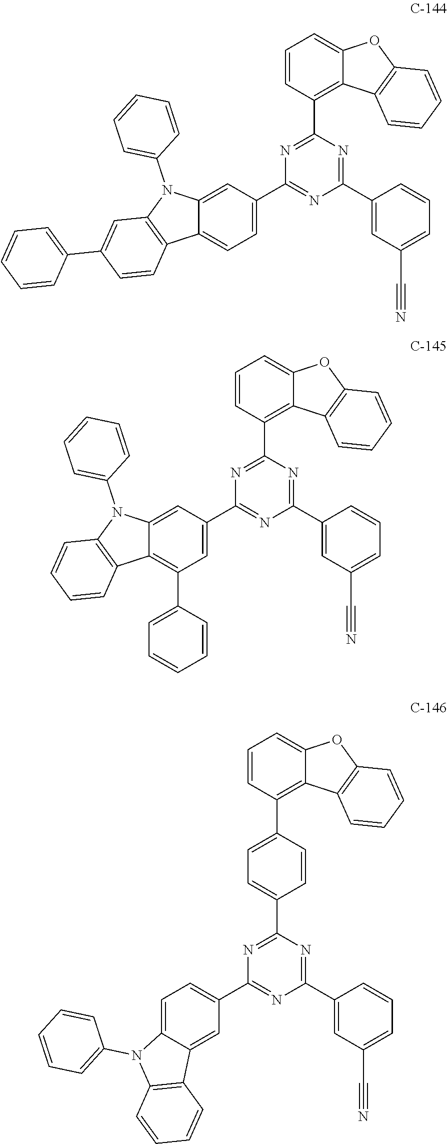 [SMILES: N#Cc1cccc(-c2nc(-c3ccc4c5ccc(-c6ccccc6)cc5n(-c5ccccc5)c4c3)nc(-c3cccc4oc5ccccc5c34)n2)c1 ; N#Cc1cccc(-c2nc(-c3cc(-c4ccccc4)c4c5ccccc5n(-c5ccccc5)c4c3)nc(-c3cccc4oc5ccccc5c34)n2)c1 ; N#Cc1cccc(-c2nc(-c3ccc(-c4cccc5oc6ccccc6c45)cc3)nc(-c3ccc4c(c3)c3ccccc3n4-c3ccccc3)n2)c1] 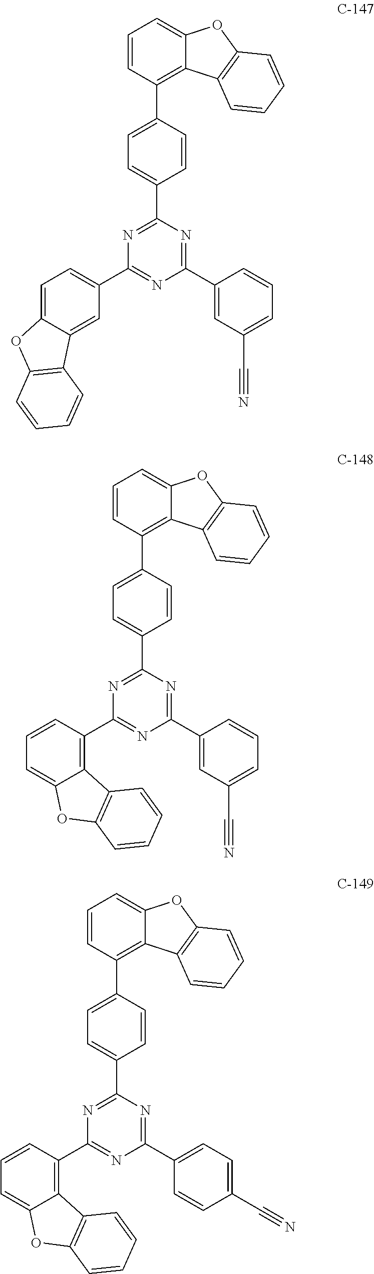 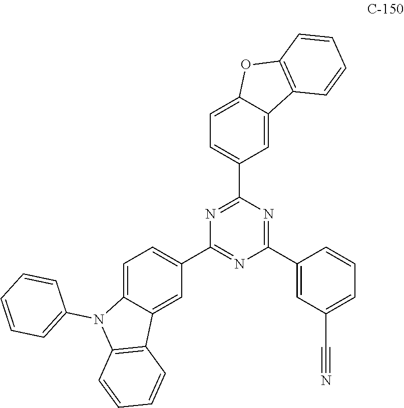 [SMILES: N#Cc1cccc(-c2nc(-c3ccc4oc5ccccc5c4c3)nc(-c3ccc4c(c3)c3ccccc3n4-c3ccccc3)n2)c1] 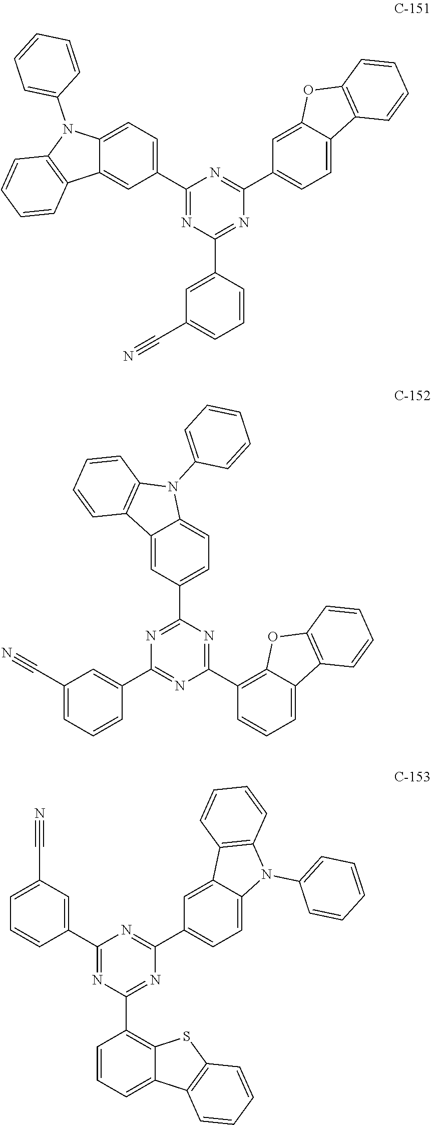 [SMILES: N#Cc1cccc(-c2nc(-c3ccc4c(c3)oc3ccccc34)nc(-c3ccc4c(c3)c3ccccc3n4-c3ccccc3)n2)c1 ; N#Cc1cccc(-c2nc(-c3ccc4c(c3)c3ccccc3n4-c3ccccc3)nc(-c3cccc4c3oc3ccccc34)n2)c1 ; N#Cc1cccc(-c2nc(-c3ccc4c(c3)c3ccccc3n4-c3ccccc3)nc(-c3cccc4c3sc3ccccc34)n2)c1] 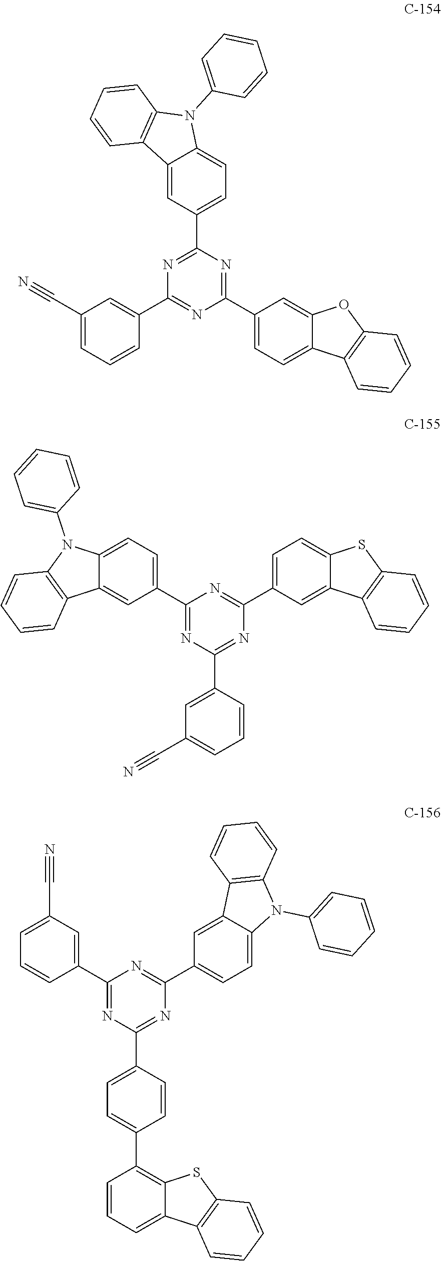 [SMILES: N#Cc1cccc(-c2nc(-c3ccc4c(c3)oc3ccccc34)nc(-c3ccc4c(c3)c3ccccc3n4-c3ccccc3)n2)c1 ; N#Cc1cccc(-c2nc(-c3ccc4sc5ccccc5c4c3)nc(-c3ccc4c(c3)c3ccccc3n4-c3ccccc3)n2)c1 ; N#Cc1cccc(-c2nc(-c3ccc(-c4cccc5c4sc4ccccc45)cc3)nc(-c3ccc4c(c3)c3ccccc3n4-c3ccccc3)n2)c1] 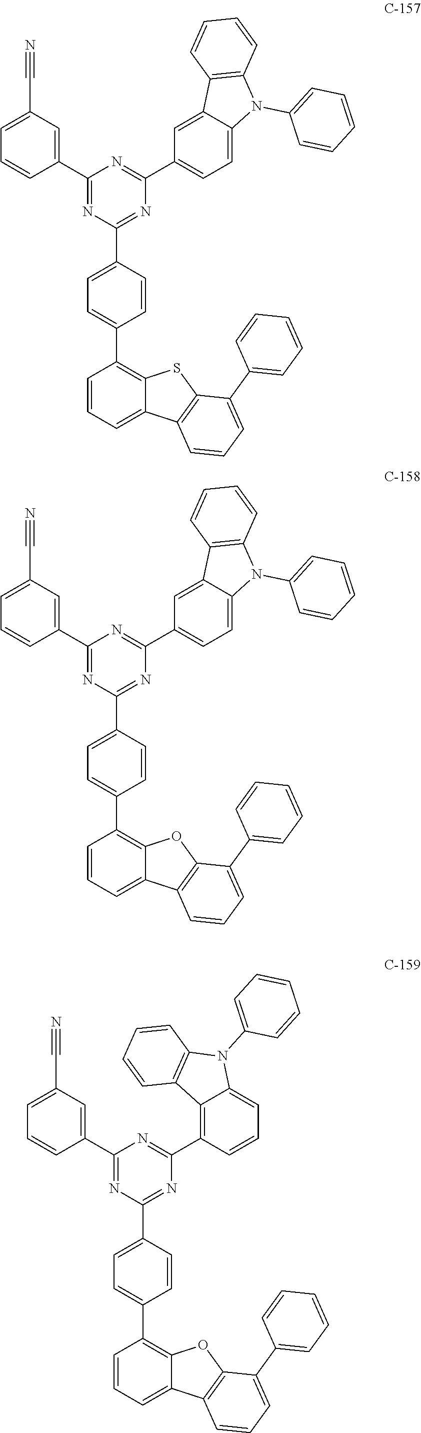 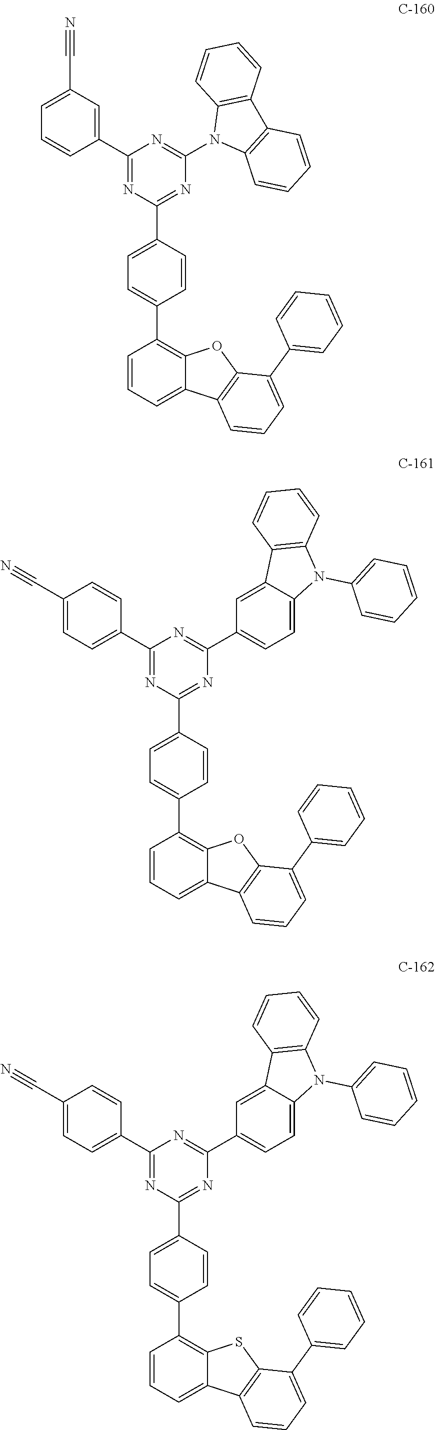 [SMILES: N#Cc1cccc(-c2nc(-c3ccc(-c4cccc5c4oc4c(-c6ccccc6)cccc45)cc3)nc(-n3c4ccccc4c4ccccc43)n2)c1 ; N#Cc1ccc(-c2nc(-c3ccc(-c4cccc5c4oc4c(-c6ccccc6)cccc45)cc3)nc(-c3ccc4c(c3)c3ccccc3n4-c3ccccc3)n2)cc1 ; N#Cc1ccc(-c2nc(-c3ccc(-c4cccc5c4sc4c(-c6ccccc6)cccc45)cc3)nc(-c3ccc4c(c3)c3ccccc3n4-c3ccccc3)n2)cc1] 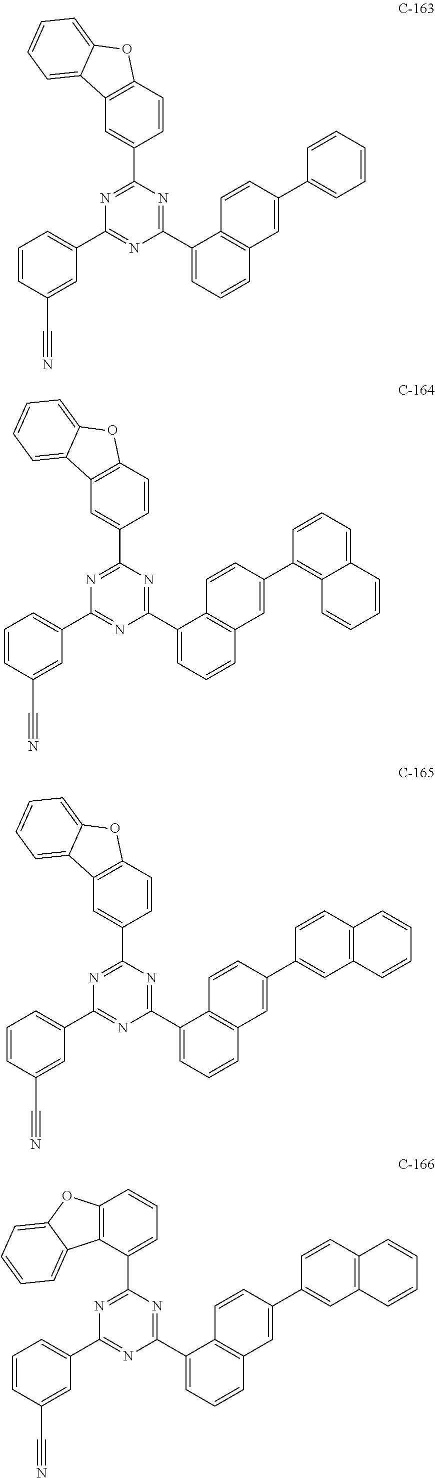 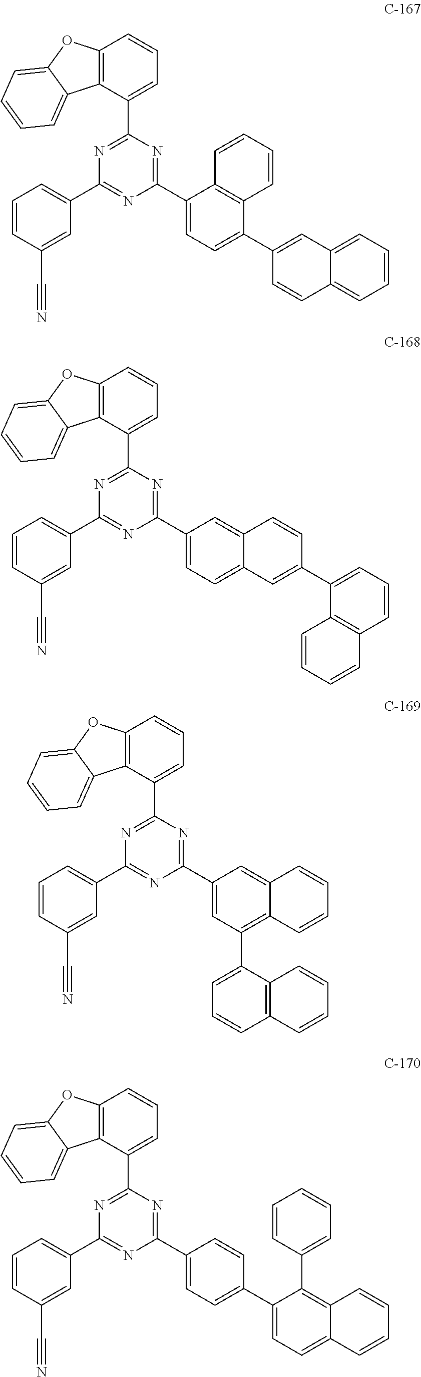 [SMILES: N#Cc1cccc(-c2nc(-c3ccc(-c4ccc5ccccc5c4)c4ccccc34)nc(-c3cccc4oc5ccccc5c34)n2)c1 ; N#Cc1cccc(-c2nc(-c3ccc4cc(-c5cccc6ccccc56)ccc4c3)nc(-c3cccc4oc5ccccc5c34)n2)c1 ; N#Cc1cccc(-c2nc(-c3cc(-c4cccc5ccccc45)c4ccccc4c3)nc(-c3cccc4oc5ccccc5c34)n2)c1 ; N#Cc1cccc(-c2nc(-c3ccc(-c4ccc5ccccc5c4-c4ccccc4)cc3)nc(-c3cccc4oc5ccccc5c34)n2)c1] 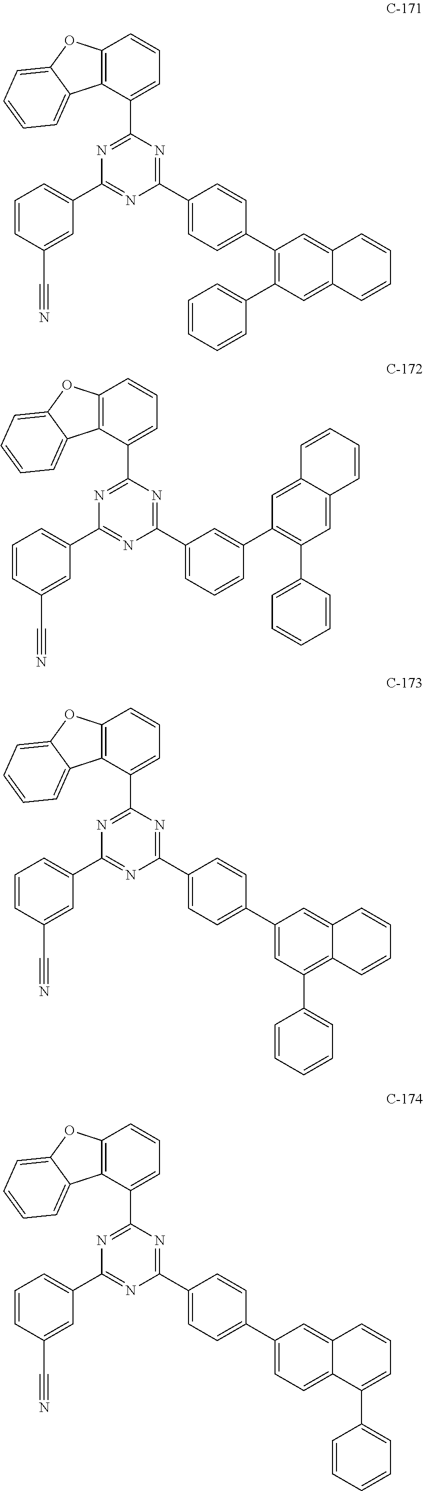 [SMILES: N#Cc1cccc(-c2nc(-c3ccc(-c4cc5ccccc5cc4-c4ccccc4)cc3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3ccc(-c4cc(-c5ccccc5)c5ccccc5c4)cc3)nc(-c3cccc4oc5ccccc5c34)n2)c1 ; N#Cc1cccc(-c2nc(-c3ccc(-c4ccc5c(-c6ccccc6)cccc5c4)cc3)nc(-c3cccc4oc5ccccc5c34)n2)c1] 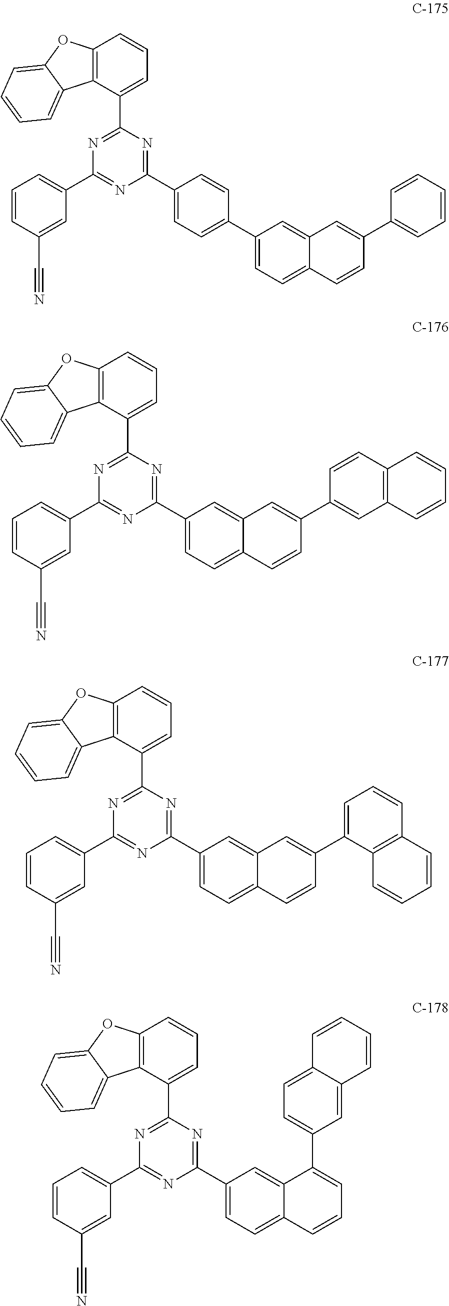 [SMILES: N#Cc1cccc(-c2nc(-c3ccc(-c4ccc5ccc(-c6ccccc6)cc5c4)cc3)nc(-c3cccc4oc5ccccc5c34)n2)c1 ; N#Cc1cccc(-c2nc(-c3ccc4ccc(-c5ccc6ccccc6c5)cc4c3)nc(-c3cccc4oc5ccccc5c34)n2)c1 ; N#Cc1cccc(-c2nc(-c3ccc4ccc(-c5cccc6ccccc56)cc4c3)nc(-c3cccc4oc5ccccc5c34)n2)c1 ; N#Cc1cccc(-c2nc(-c3ccc4cccc(-c5ccc6ccccc6c5)c4c3)nc(-c3cccc4oc5ccccc5c34)n2)c1] 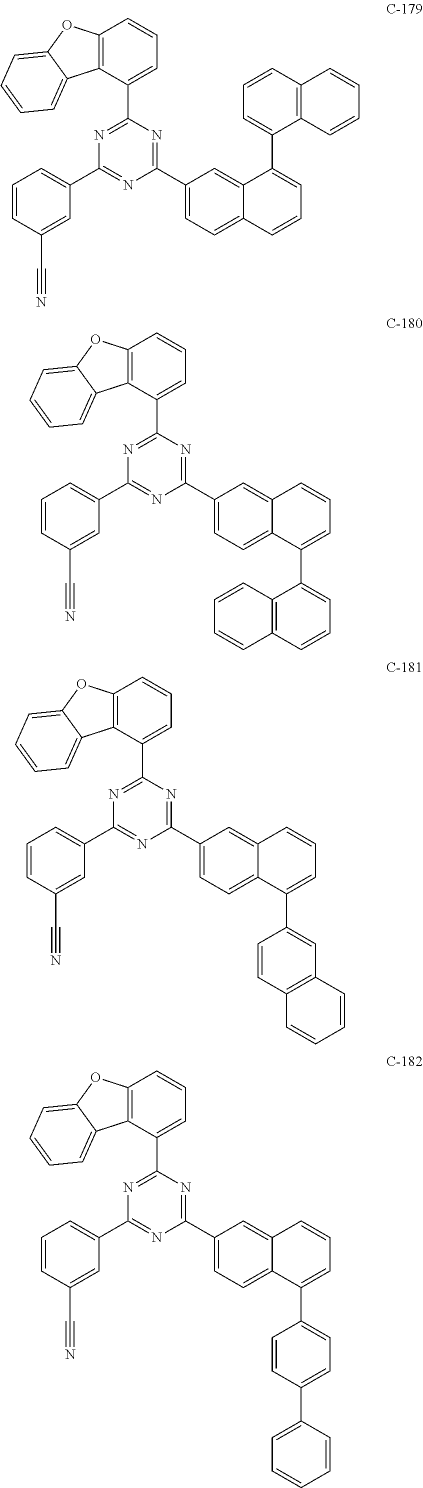 [SMILES: N#Cc1cccc(-c2nc(-c3ccc4cccc(-c5cccc6ccccc56)c4c3)nc(-c3cccc4oc5ccccc5c34)n2)c1 ; N#Cc1cccc(-c2nc(-c3ccc4c(-c5cccc6ccccc56)cccc4c3)nc(-c3cccc4oc5ccccc5c34)n2)c1 ; N#Cc1cccc(-c2nc(-c3ccc4c(-c5ccc6ccccc6c5)cccc4c3)nc(-c3cccc4oc5ccccc5c34)n2)c1 ; N#Cc1cccc(-c2nc(-c3ccc4c(-c5ccc(-c6ccccc6)cc5)cccc4c3)nc(-c3cccc4oc5ccccc5c34)n2)c1] 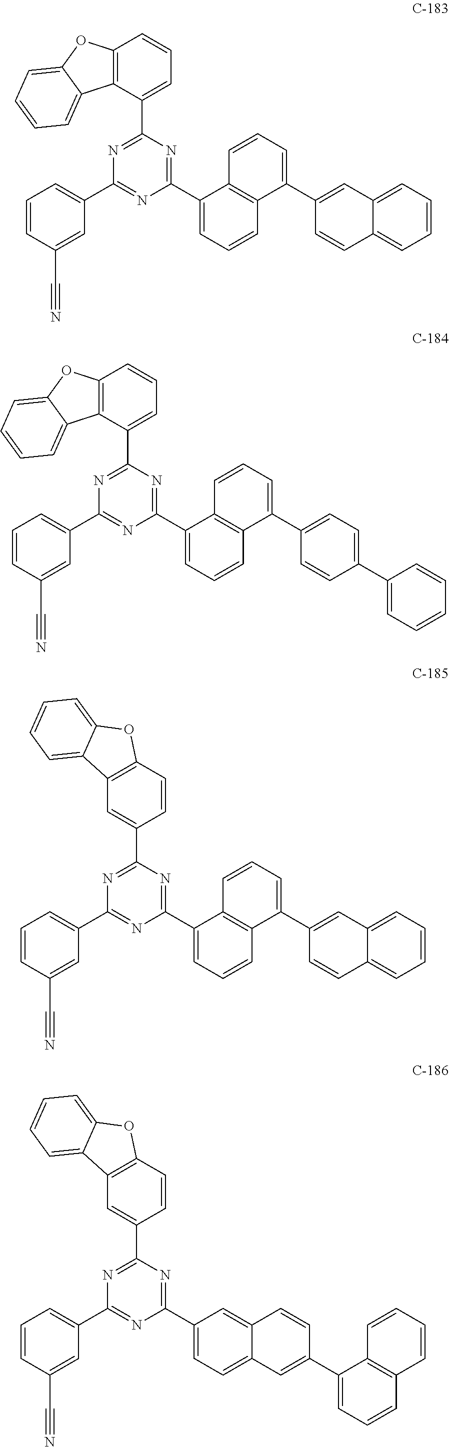 [SMILES: N#Cc1cccc(-c2nc(-c3cccc4c(-c5ccc6ccccc6c5)cccc34)nc(-c3cccc4oc5ccccc5c34)n2)c1 ; N#Cc1cccc(-c2nc(-c3cccc4c(-c5ccc(-c6ccccc6)cc5)cccc34)nc(-c3cccc4oc5ccccc5c34)n2)c1 ; N#Cc1cccc(-c2nc(-c3ccc4oc5ccccc5c4c3)nc(-c3cccc4c(-c5ccc6ccccc6c5)cccc34)n2)c1 ; N#Cc1cccc(-c2nc(-c3ccc4cc(-c5cccc6ccccc56)ccc4c3)nc(-c3ccc4oc5ccccc5c4c3)n2)c1] 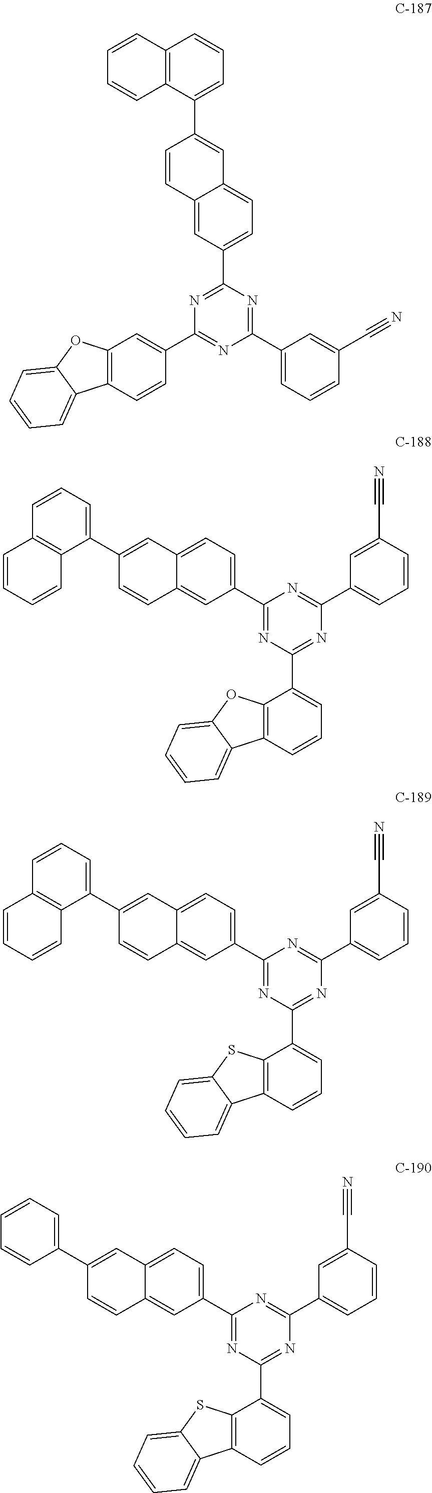 [SMILES: N#Cc1cccc(-c2nc(-c3ccc4cc(-c5cccc6ccccc56)ccc4c3)nc(-c3ccc4c(c3)oc3ccccc34)n2)c1 ; N#Cc1cccc(-c2nc(-c3ccc4cc(-c5cccc6ccccc56)ccc4c3)nc(-c3cccc4c3oc3ccccc34)n2)c1 ; N#Cc1cccc(-c2nc(-c3ccc4cc(-c5cccc6ccccc56)ccc4c3)nc(-c3cccc4c3sc3ccccc34)n2)c1 ; N#Cc1cccc(-c2nc(-c3ccc4cc(-c5ccccc5)ccc4c3)nc(-c3cccc4c3sc3ccccc34)n2)c1] 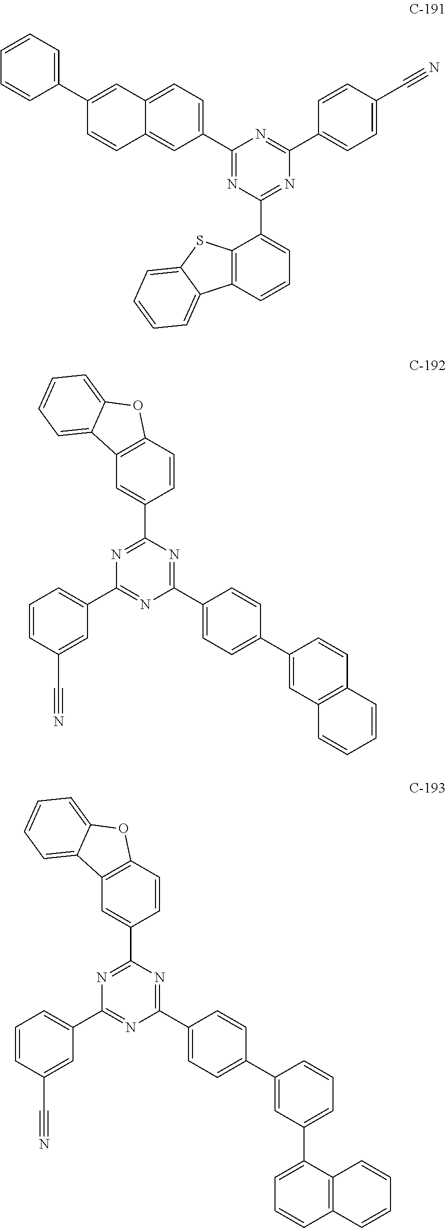 [SMILES: N#Cc1ccc(-c2nc(-c3ccc4cc(-c5ccccc5)ccc4c3)nc(-c3cccc4c3sc3ccccc34)n2)cc1 ; N#Cc1cccc(-c2nc(-c3ccc(-c4ccc5ccccc5c4)cc3)nc(-c3ccc4oc5ccccc5c4c3)n2)c1 ; N#Cc1cccc(-c2nc(-c3ccc(-c4cccc(-c5cccc6ccccc56)c4)cc3)nc(-c3ccc4oc5ccccc5c4c3)n2)c1] 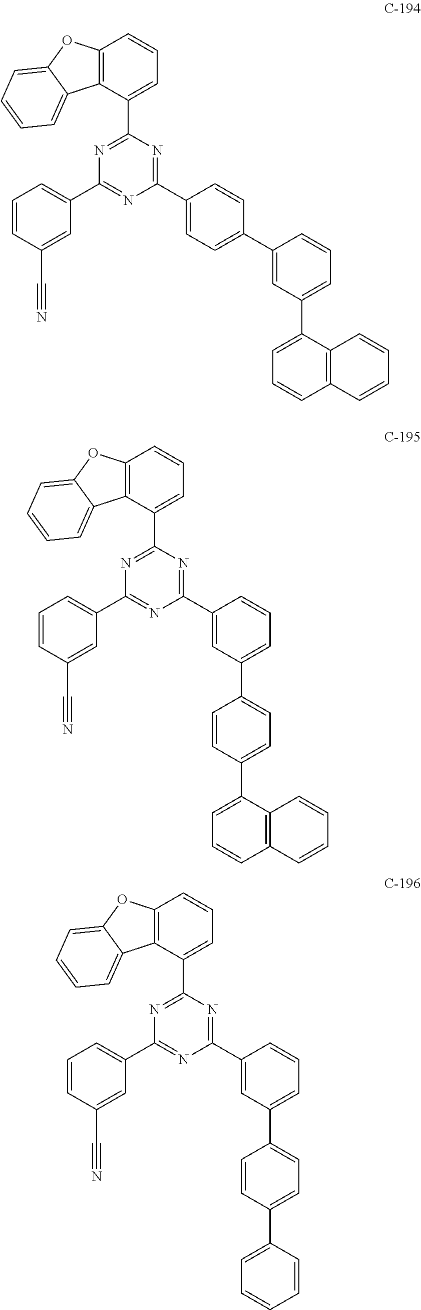 [SMILES: N#Cc1cccc(-c2nc(-c3ccc(-c4cccc(-c5cccc6ccccc56)c4)cc3)nc(-c3cccc4oc5ccccc5c34)n2)c1 ; N#Cc1cccc(-c2nc(-c3cccc(-c4ccc(-c5cccc6ccccc56)cc4)c3)nc(-c3cccc4oc5ccccc5c34)n2)c1 ; N#Cc1cccc(-c2nc(-c3cccc(-c4ccc(-c5ccccc5)cc4)c3)nc(-c3cccc4oc5ccccc5c34)n2)c1] 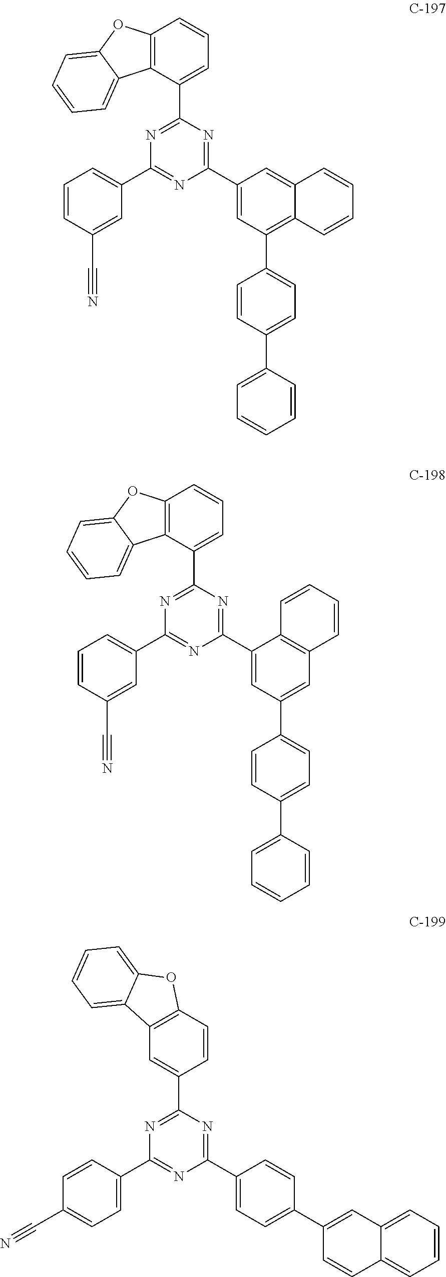 [SMILES: N#Cc1cccc(-c2nc(-c3cc(-c4ccc(-c5ccccc5)cc4)c4ccccc4c3)nc(-c3cccc4oc5ccccc5c34)n2)c1 ; N#Cc1cccc(-c2nc(-c3cc(-c4ccc(-c5ccccc5)cc4)cc4ccccc34)nc(-c3cccc4oc5ccccc5c34)n2)c1 ; N#Cc1ccc(-c2nc(-c3ccc(-c4ccc5ccccc5c4)cc3)nc(-c3ccc4oc5ccccc5c4c3)n2)cc1] 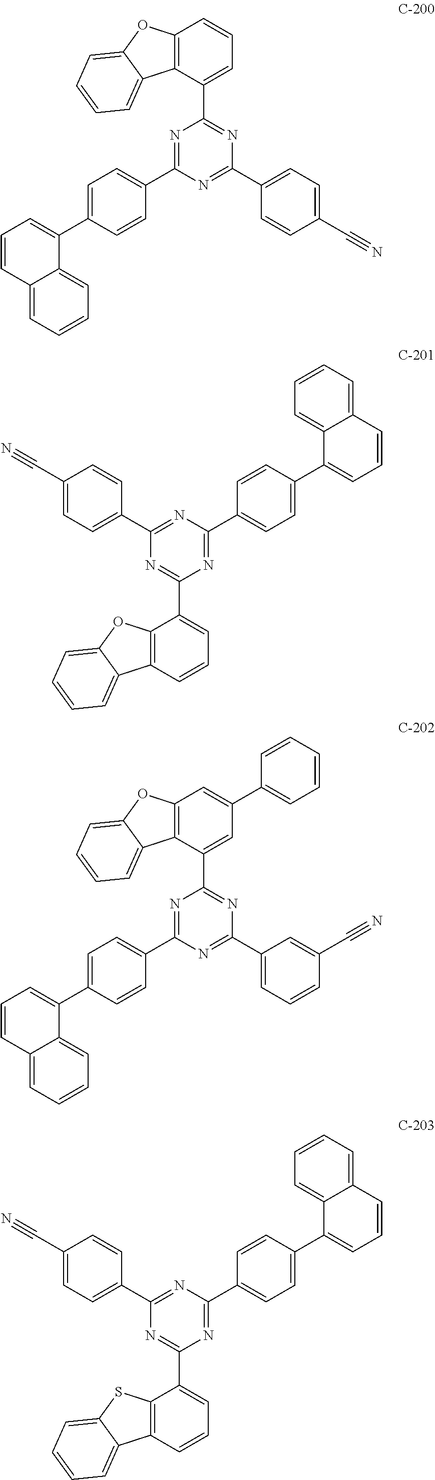 [SMILES: N#Cc1ccc(-c2nc(-c3ccc(-c4cccc5ccccc45)cc3)nc(-c3cccc4oc5ccccc5c34)n2)cc1 ; N#Cc1ccc(-c2nc(-c3ccc(-c4cccc5ccccc45)cc3)nc(-c3cccc4c3oc3ccccc34)n2)cc1 ; N#Cc1cccc(-c2nc(-c3ccc(-c4cccc5ccccc45)cc3)nc(-c3cc(-c4ccccc4)cc4oc5ccccc5c34)n2)c1 ; N#Cc1ccc(-c2nc(-c3ccc(-c4cccc5ccccc45)cc3)nc(-c3cccc4c3sc3ccccc34)n2)cc1] 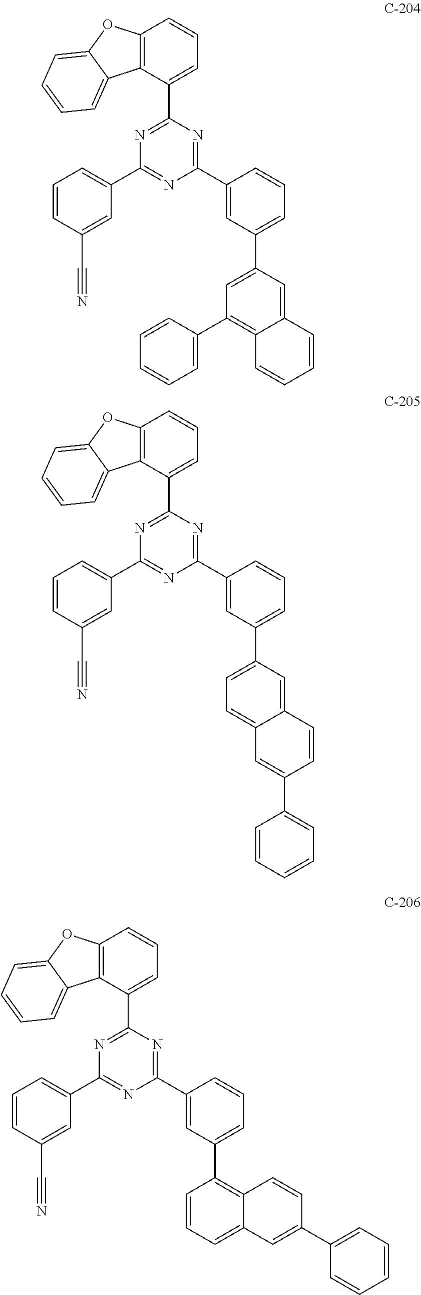 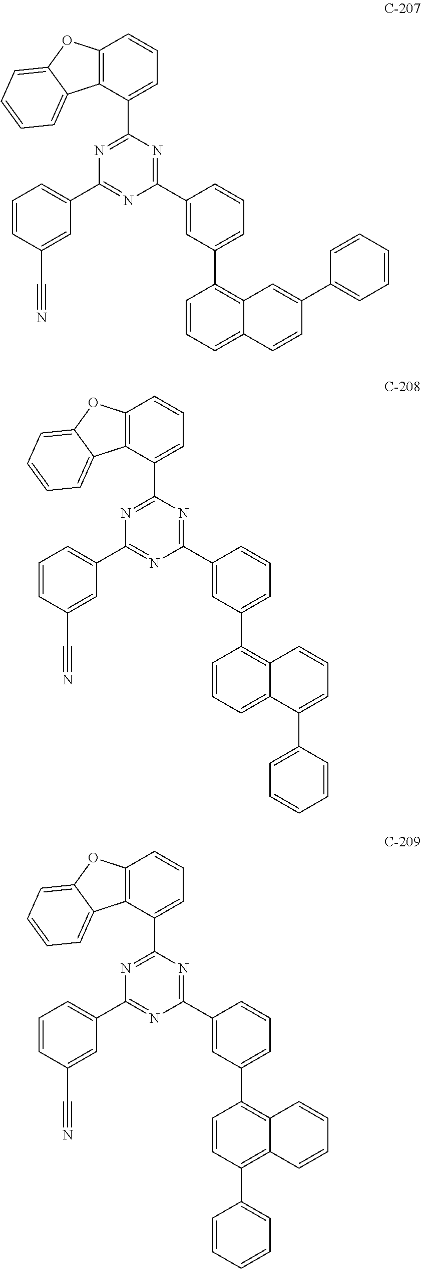 [SMILES: N#Cc1cccc(-c2nc(-c3cccc(-c4cccc5ccc(-c6ccccc6)cc45)c3)nc(-c3cccc4oc5ccccc5c34)n2)c1 ; N#Cc1cccc(-c2nc(-c3cccc(-c4cccc5c(-c6ccccc6)cccc45)c3)nc(-c3cccc4oc5ccccc5c34)n2)c1 ; N#Cc1cccc(-c2nc(-c3cccc(-c4ccc(-c5ccccc5)c5ccccc45)c3)nc(-c3cccc4oc5ccccc5c34)n2)c1] 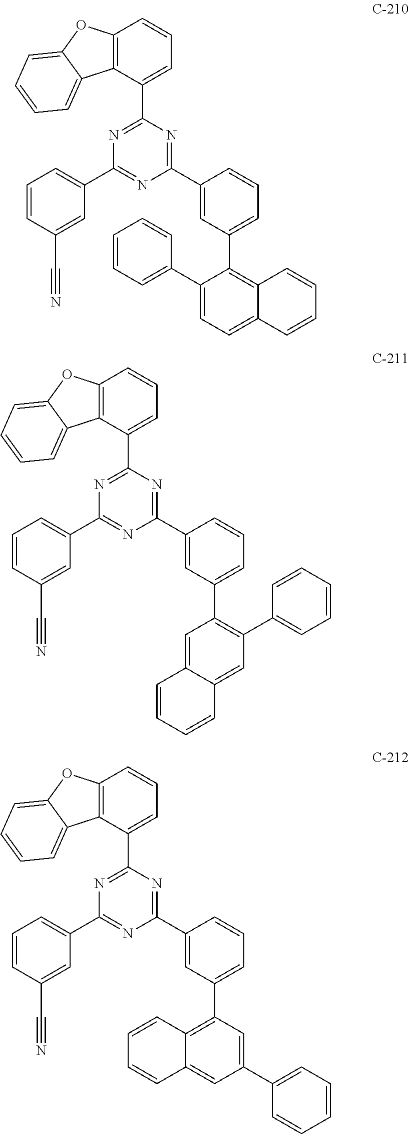 [SMILES: N#Cc1cccc(-c2nc(-c3cccc(-c4c(-c5ccccc5)ccc5ccccc45)c3)nc(-c3cccc4oc5ccccc5c34)n2)c1 ; N#Cc1cccc(-c2nc(-c3cccc(-c4cc5ccccc5cc4-c4ccccc4)c3)nc(-c3cccc4oc5ccccc5c34)n2)c1 ; N#Cc1cccc(-c2nc(-c3cccc(-c4cc(-c5ccccc5)cc5ccccc45)c3)nc(-c3cccc4oc5ccccc5c34)n2)c1] 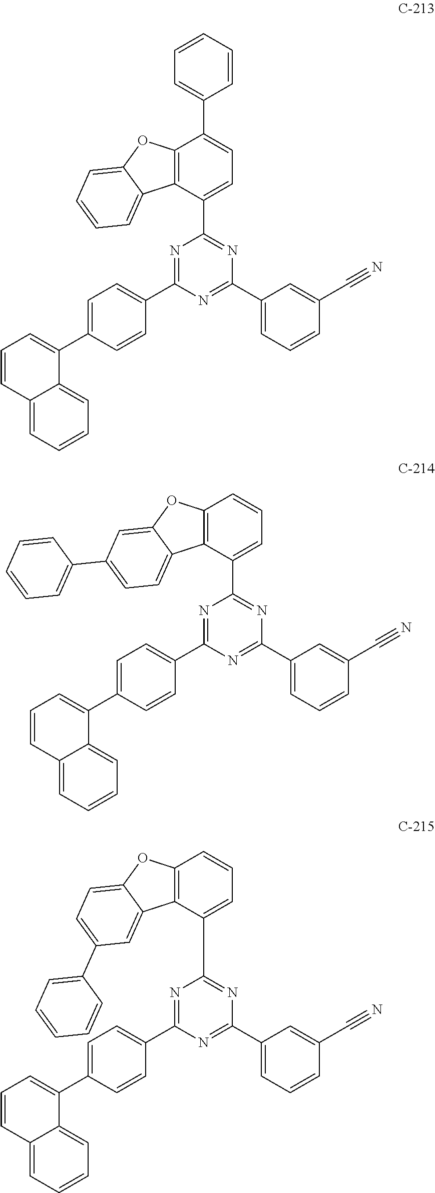 [SMILES: N#Cc1cccc(-c2nc(-c3ccc(-c4cccc5ccccc45)cc3)nc(-c3ccc(-c4ccccc4)c4oc5ccccc5c34)n2)c1 ; N#Cc1cccc(-c2nc(-c3ccc(-c4cccc5ccccc45)cc3)nc(-c3cccc4oc5cc(-c6ccccc6)ccc5c34)n2)c1 ; N#Cc1cccc(-c2nc(-c3ccc(-c4cccc5ccccc45)cc3)nc(-c3cccc4oc5ccc(-c6ccccc6)cc5c34)n2)c1] 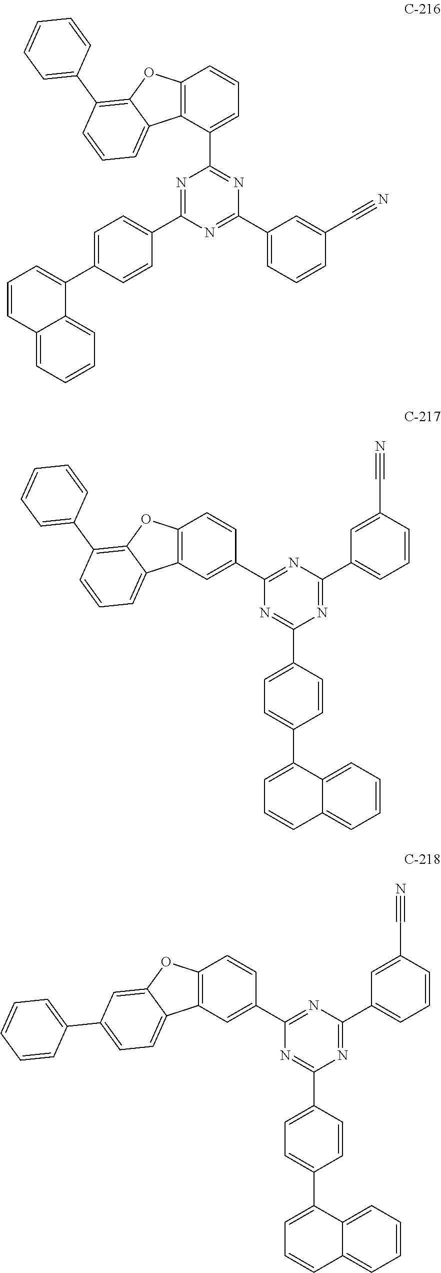 [SMILES: N#Cc1cccc(-c2nc(-c3ccc(-c4cccc5ccccc45)cc3)nc(-c3cccc4oc5c(-c6ccccc6)cccc5c34)n2)c1 ; N#Cc1cccc(-c2nc(-c3ccc(-c4cccc5ccccc45)cc3)nc(-c3ccc4oc5c(-c6ccccc6)cccc5c4c3)n2)c1 ; N#Cc1cccc(-c2nc(-c3ccc(-c4cccc5ccccc45)cc3)nc(-c3ccc4oc5cc(-c6ccccc6)ccc5c4c3)n2)c1] 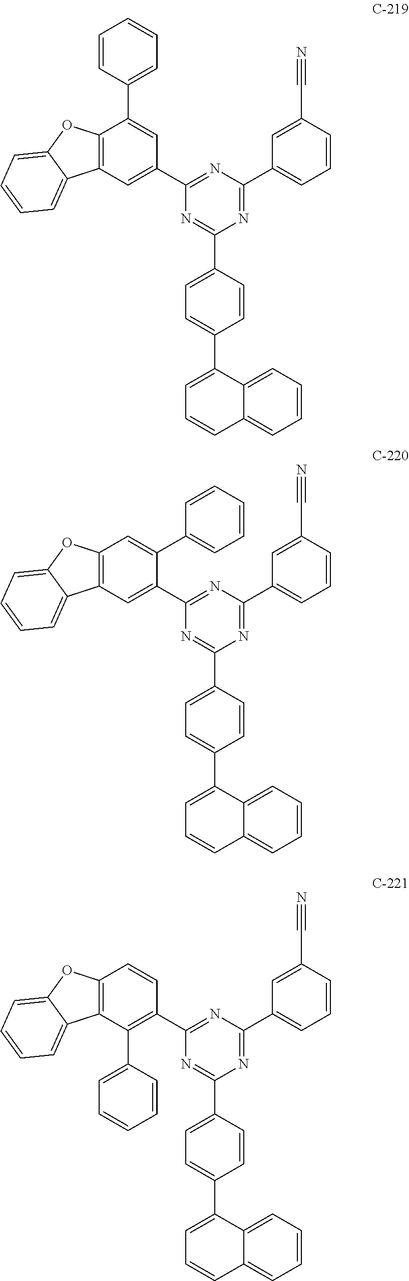 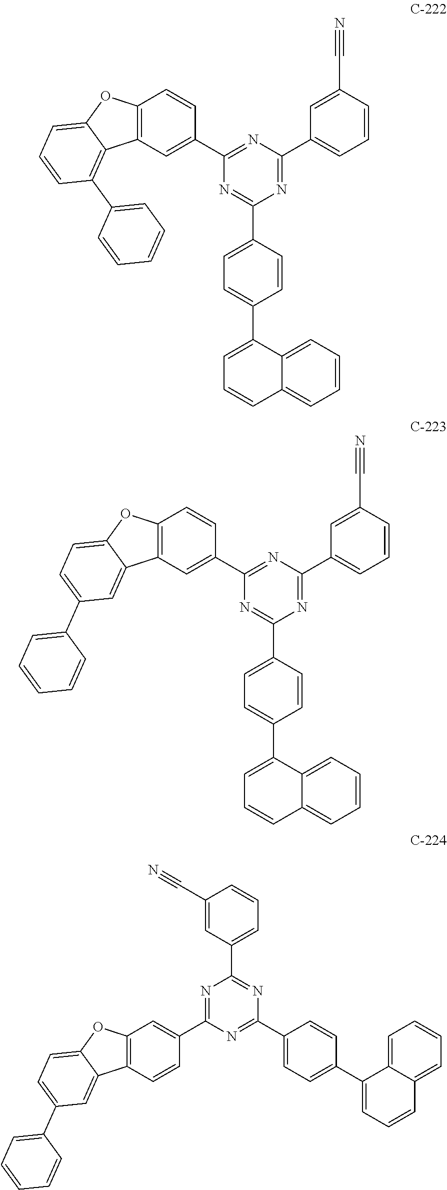 [SMILES: N#Cc1cccc(-c2nc(-c3ccc(-c4cccc5ccccc45)cc3)nc(-c3ccc4oc5cccc(-c6ccccc6)c5c4c3)n2)c1 ; N#Cc1cccc(-c2nc(-c3ccc(-c4cccc5ccccc45)cc3)nc(-c3ccc4oc5ccc(-c6ccccc6)cc5c4c3)n2)c1 ; N#Cc1cccc(-c2nc(-c3ccc(-c4cccc5ccccc45)cc3)nc(-c3ccc4c(c3)oc3ccc(-c5ccccc5)cc34)n2)c1] 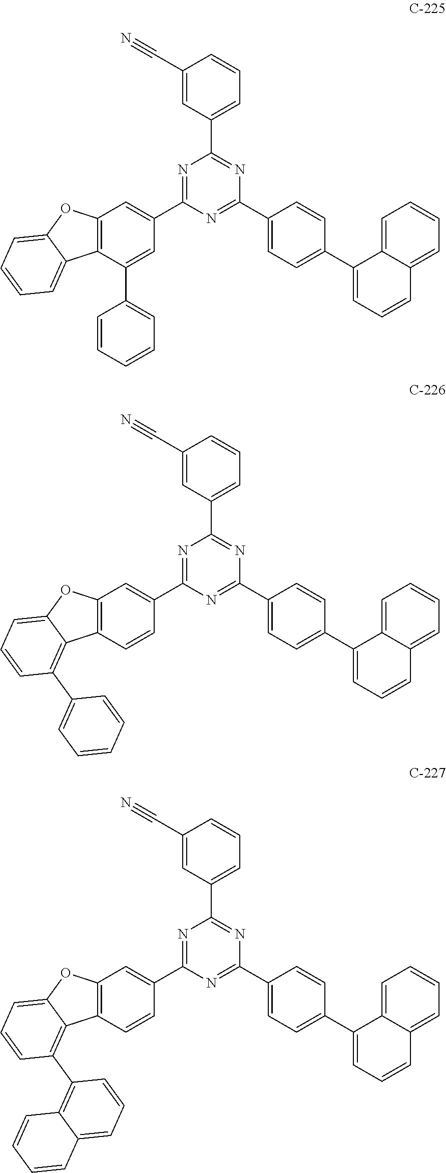 [SMILES: N#Cc1cccc(-c2nc(-c3ccc(-c4cccc5ccccc45)cc3)nc(-c3cc(-c4ccccc4)c4c(c3)oc3ccccc34)n2)c1 ; N#Cc1cccc(-c2nc(-c3ccc(-c4cccc5ccccc45)cc3)nc(-c3ccc4c(c3)oc3cccc(-c5ccccc5)c34)n2)c1 ; N#Cc1cccc(-c2nc(-c3ccc(-c4cccc5ccccc45)cc3)nc(-c3ccc4c(c3)oc3cccc(-c5cccc6ccccc56)c34)n2)c1] 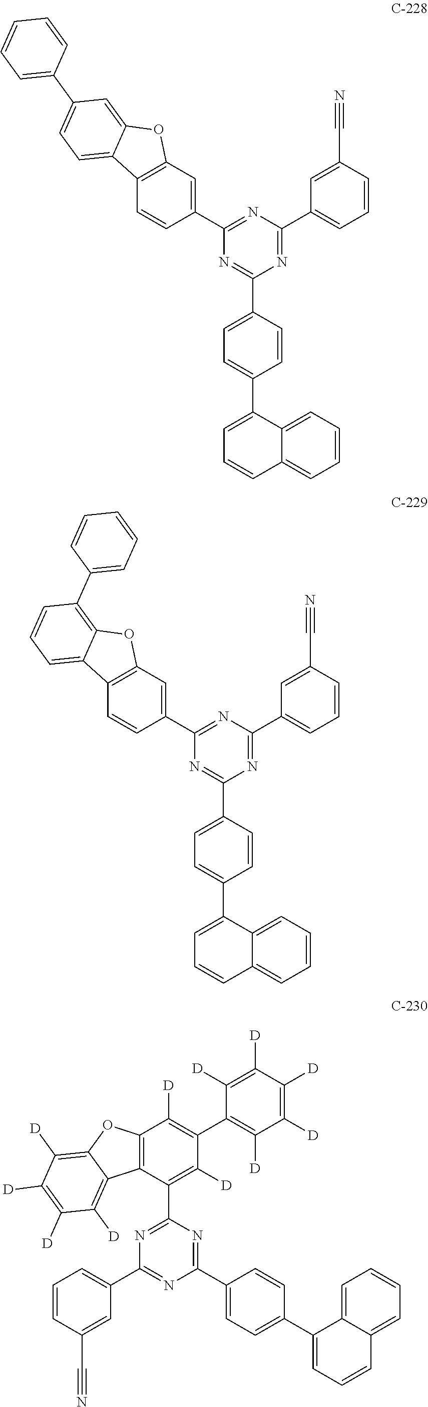 [SMILES: N#Cc1cccc(-c2nc(-c3ccc(-c4cccc5ccccc45)cc3)nc(-c3ccc4c(c3)oc3cc(-c5ccccc5)ccc34)n2)c1 ; N#Cc1cccc(-c2nc(-c3ccc(-c4cccc5ccccc45)cc3)nc(-c3ccc4c(c3)oc3c(-c5ccccc5)cccc34)n2)c1 ; [2H]c1c([2H])c([2H])c(-c2c([2H])c(-c3nc(-c4ccc(-c5cccc6ccccc56)cc4)nc(-c4cccc(C#N)c4)n3)c3c(oc4c([2H])c([2H])c([2H])c([2H])c43)c2[2H])c([2H])c1[2H]] 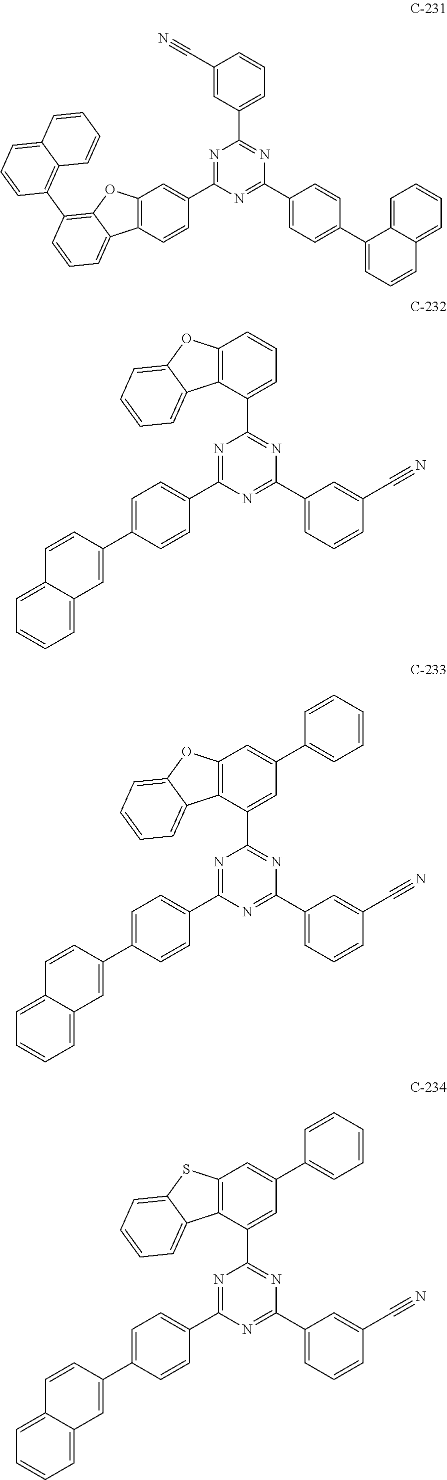 [SMILES: N#Cc1cccc(-c2nc(-c3ccc(-c4cccc5ccccc45)cc3)nc(-c3ccc4c(c3)oc3c(-c5cccc6ccccc56)cccc34)n2)c1 ; N#Cc1cccc(-c2nc(-c3ccc(-c4ccc5ccccc5c4)cc3)nc(-c3cccc4oc5ccccc5c34)n2)c1 ; N#Cc1cccc(-c2nc(-c3ccc(-c4ccc5ccccc5c4)cc3)nc(-c3cc(-c4ccccc4)cc4oc5ccccc5c34)n2)c1 ; N#Cc1cccc(-c2nc(-c3ccc(-c4ccc5ccccc5c4)cc3)nc(-c3cc(-c4ccccc4)cc4sc5ccccc5c34)n2)c1] 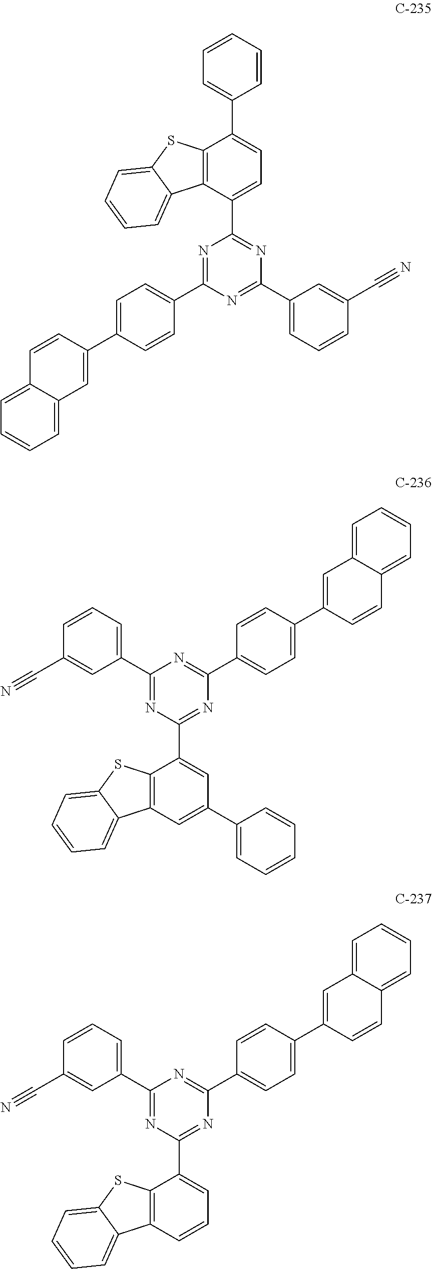 [SMILES: N#Cc1cccc(-c2nc(-c3ccc(-c4ccc5ccccc5c4)cc3)nc(-c3ccc(-c4ccccc4)c4sc5ccccc5c34)n2)c1 ; N#Cc1cccc(-c2nc(-c3ccc(-c4ccc5ccccc5c4)cc3)nc(-c3cc(-c4ccccc4)cc4c3sc3ccccc34)n2)c1 ; N#Cc1cccc(-c2nc(-c3ccc(-c4ccc5ccccc5c4)cc3)nc(-c3cccc4c3sc3ccccc34)n2)c1] 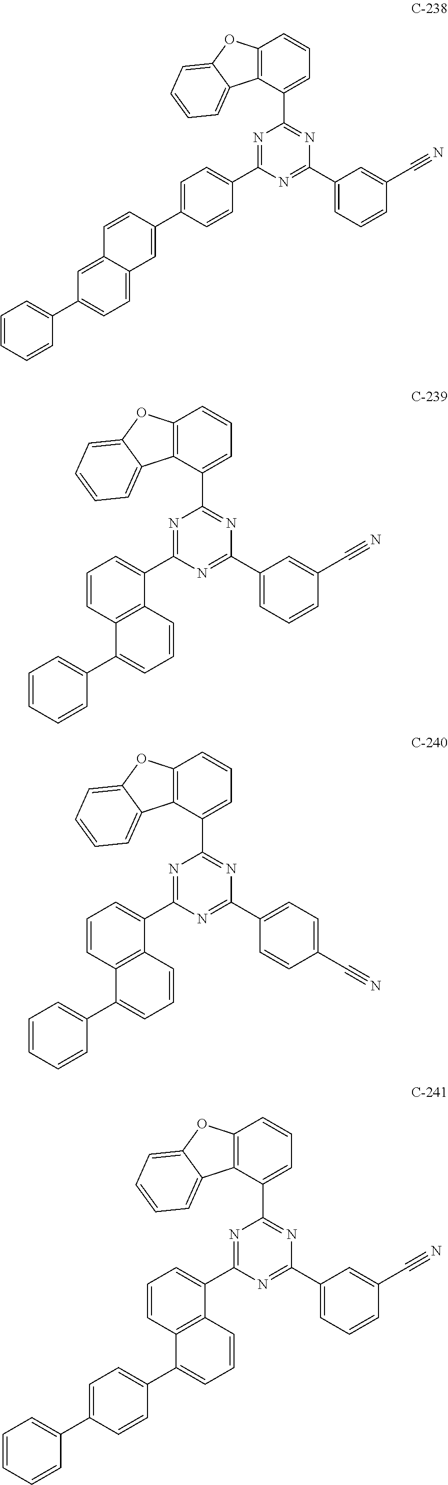 [SMILES: N#Cc1cccc(-c2nc(-c3ccc(-c4ccc5cc(-c6ccccc6)ccc5c4)cc3)nc(-c3cccc4oc5ccccc5c34)n2)c1 ; N#Cc1cccc(-c2nc(-c3cccc4c(-c5ccccc5)cccc34)nc(-c3cccc4oc5ccccc5c34)n2)c1 ; N#Cc1ccc(-c2nc(-c3cccc4c(-c5ccccc5)cccc34)nc(-c3cccc4oc5ccccc5c34)n2)cc1 ; N#Cc1cccc(-c2nc(-c3cccc4c(-c5ccc(-c6ccccc6)cc5)cccc34)nc(-c3cccc4oc5ccccc5c34)n2)c1] 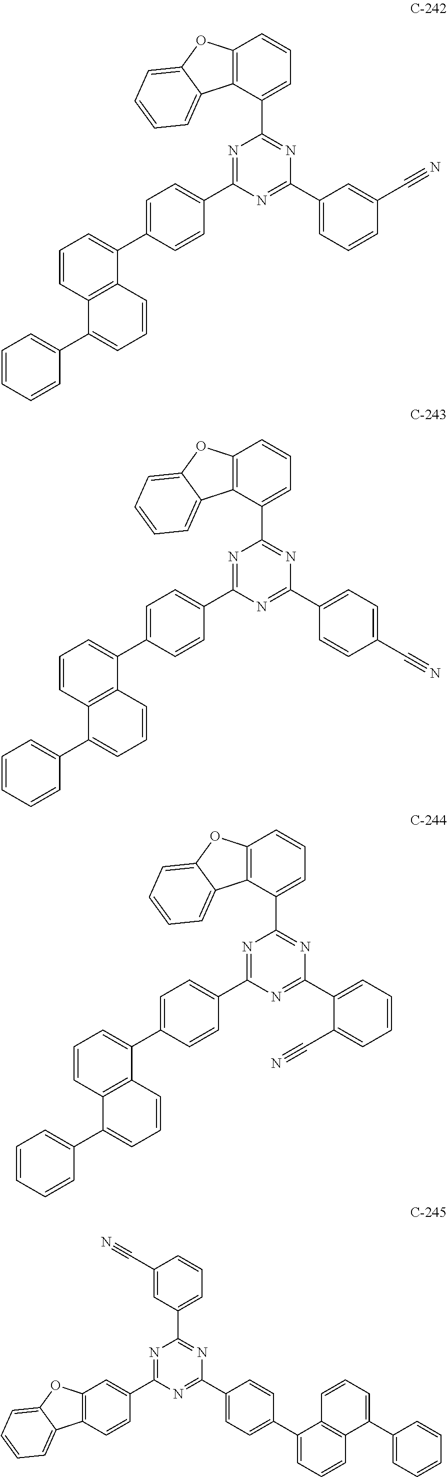 [SMILES: N#Cc1cccc(-c2nc(-c3ccc(-c4cccc5c(-c6ccccc6)cccc45)cc3)nc(-c3cccc4oc5ccccc5c34)n2)c1 ; N#Cc1ccc(-c2nc(-c3ccc(-c4cccc5c(-c6ccccc6)cccc45)cc3)nc(-c3cccc4oc5ccccc5c34)n2)cc1 ; N#Cc1ccccc1-c1nc(-c2ccc(-c3cccc4c(-c5ccccc5)cccc34)cc2)nc(-c2cccc3oc4ccccc4c23)n1 ; N#Cc1cccc(-c2nc(-c3ccc(-c4cccc5c(-c6ccccc6)cccc45)cc3)nc(-c3ccc4c(c3)oc3ccccc34)n2)c1] 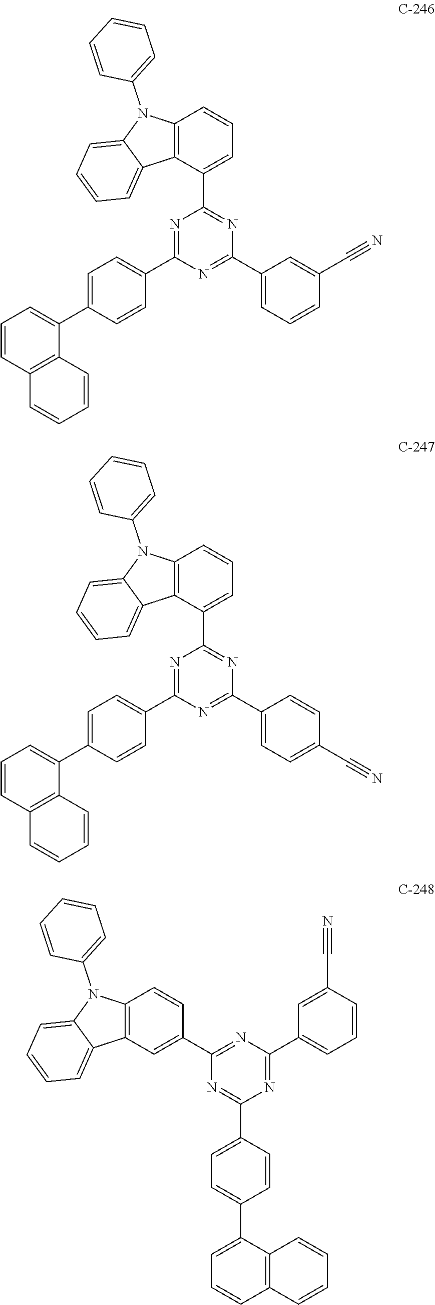 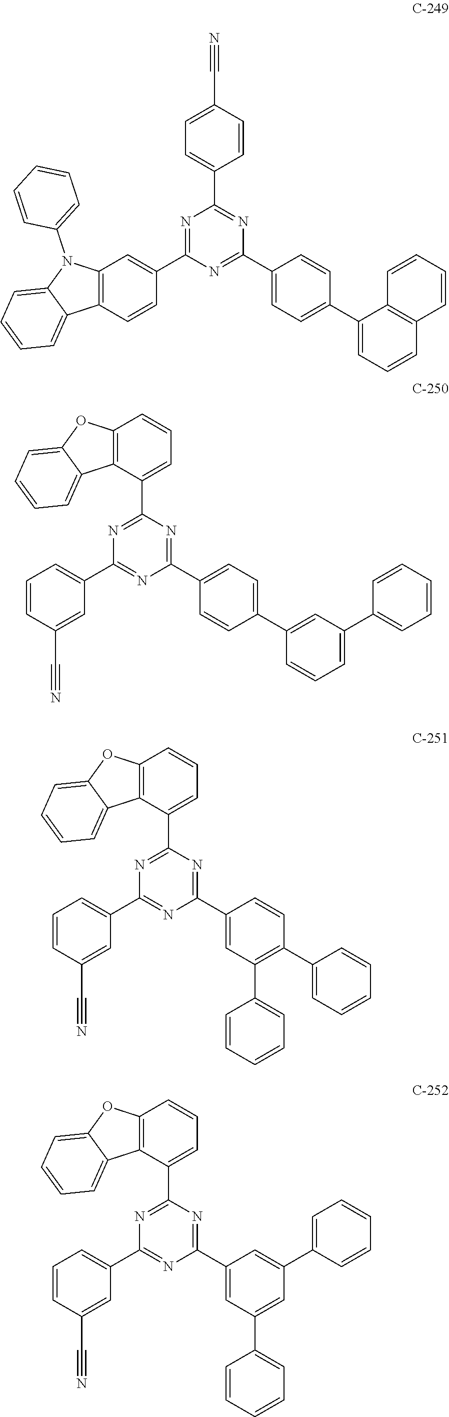 [SMILES: N#Cc1ccc(-c2nc(-c3ccc(-c4cccc5ccccc45)cc3)nc(-c3ccc4c5ccccc5n(-c5ccccc5)c4c3)n2)cc1 ; N#Cc1cccc(-c2nc(-c3ccc(-c4cccc(-c5ccccc5)c4)cc3)nc(-c3cccc4oc5ccccc5c34)n2)c1 ; N#Cc1cccc(-c2nc(-c3ccc(-c4ccccc4)c(-c4ccccc4)c3)nc(-c3cccc4oc5ccccc5c34)n2)c1 ; N#Cc1cccc(-c2nc(-c3cc(-c4ccccc4)cc(-c4ccccc4)c3)nc(-c3cccc4oc5ccccc5c34)n2)c1] 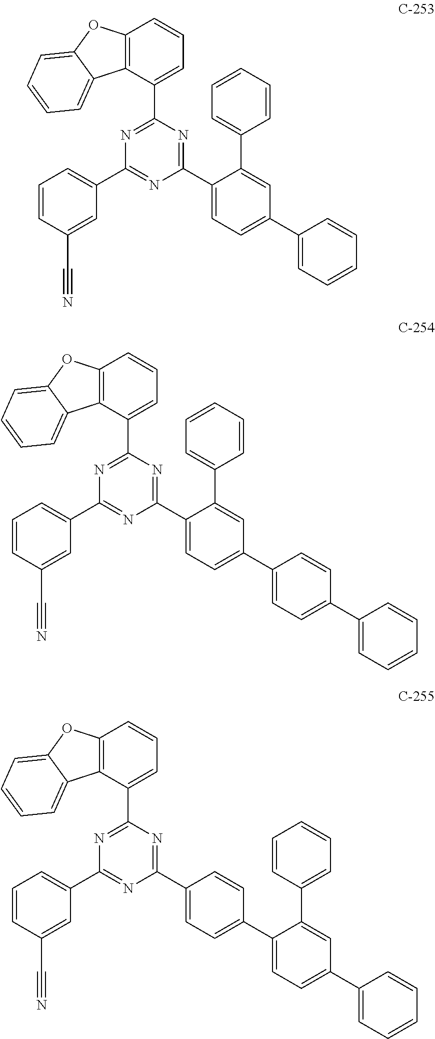 [SMILES: N#Cc1cccc(-c2nc(-c3ccc(-c4ccccc4)cc3-c3ccccc3)nc(-c3cccc4oc5ccccc5c34)n2)c1 ; N#Cc1cccc(-c2nc(-c3ccc(-c4ccc(-c5ccccc5)cc4)cc3-c3ccccc3)nc(-c3cccc4oc5ccccc5c34)n2)c1 ; N#Cc1cccc(-c2nc(-c3ccc(-c4ccc(-c5ccccc5)cc4-c4ccccc4)cc3)nc(-c3cccc4oc5ccccc5c34)n2)c1] 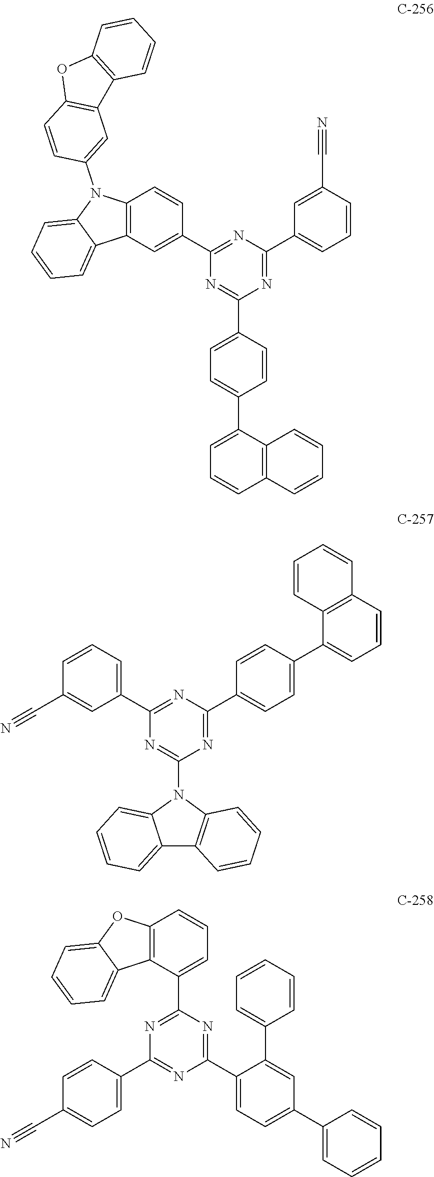 [SMILES: N#Cc1cccc(-c2nc(-c3ccc(-c4cccc5ccccc45)cc3)nc(-c3ccc4c(c3)c3ccccc3n4-c3ccc4oc5ccccc5c4c3)n2)c1 ; N#Cc1cccc(-c2nc(-c3ccc(-c4cccc5ccccc45)cc3)nc(-n3c4ccccc4c4ccccc43)n2)c1 ; N#Cc1ccc(-c2nc(-c3ccc(-c4ccccc4)cc3-c3ccccc3)nc(-c3cccc4oc5ccccc5c34)n2)cc1] 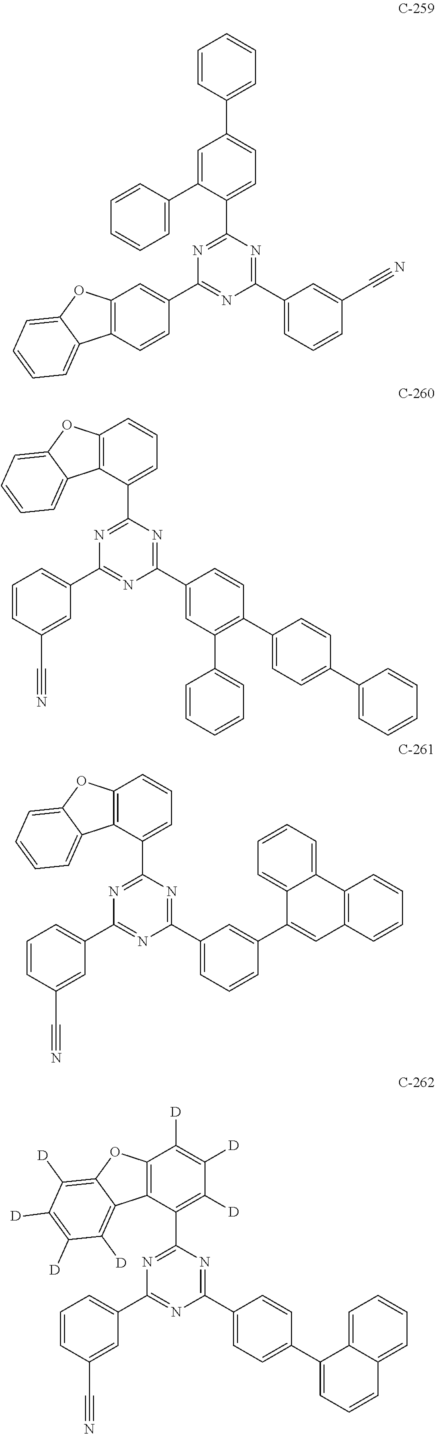 [SMILES: N#Cc1cccc(-c2nc(-c3ccc4c(c3)oc3ccccc34)nc(-c3ccc(-c4ccccc4)cc3-c3ccccc3)n2)c1 ; N#Cc1cccc(-c2nc(-c3ccc(-c4ccc(-c5ccccc5)cc4)c(-c4ccccc4)c3)nc(-c3cccc4oc5ccccc5c34)n2)c1 ; N#Cc1cccc(-c2nc(-c3cccc(-c4cc5ccccc5c5ccccc45)c3)nc(-c3cccc4oc5ccccc5c34)n2)c1 ; [2H]c1c([2H])c([2H])c2c(oc3c([2H])c([2H])c([2H])c(-c4nc(-c5ccc(-c6cccc7ccccc67)cc5)nc(-c5cccc(C#N)c5)n4)c32)c1[2H]] 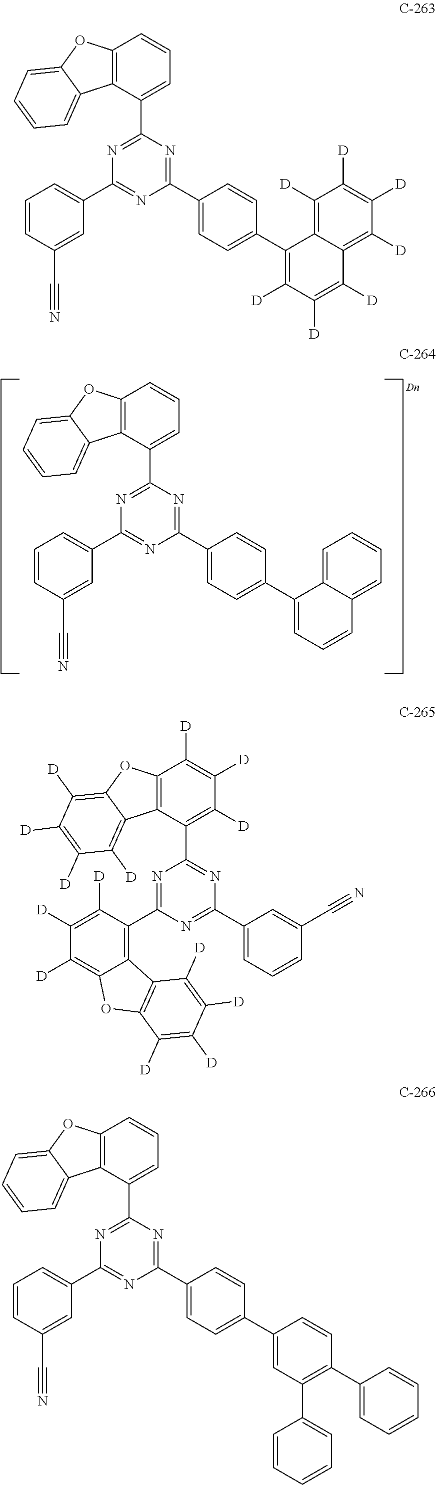 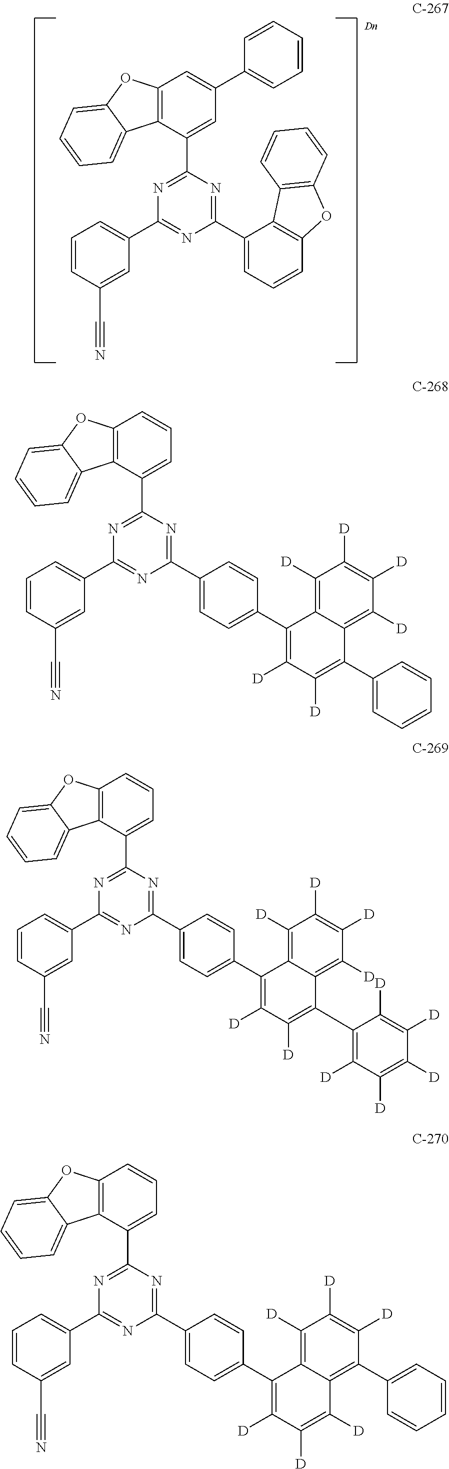 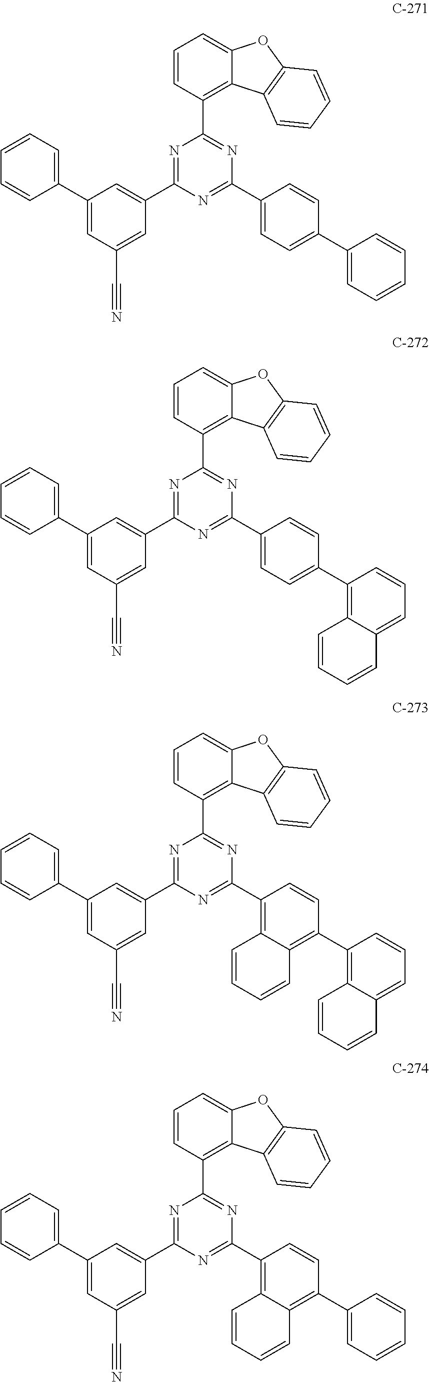 [SMILES: N#Cc1cc(-c2ccccc2)cc(-c2nc(-c3ccc(-c4ccccc4)cc3)nc(-c3cccc4oc5ccccc5c34)n2)c1 ; N#Cc1cc(-c2ccccc2)cc(-c2nc(-c3ccc(-c4cccc5ccccc45)cc3)nc(-c3cccc4oc5ccccc5c34)n2)c1 ; N#Cc1cc(-c2ccccc2)cc(-c2nc(-c3ccc(-c4cccc5ccccc45)c4ccccc34)nc(-c3cccc4oc5ccccc5c34)n2)c1 ; N#Cc1cc(-c2ccccc2)cc(-c2nc(-c3ccc(-c4ccccc4)c4ccccc34)nc(-c3cccc4oc5ccccc5c34)n2)c1] 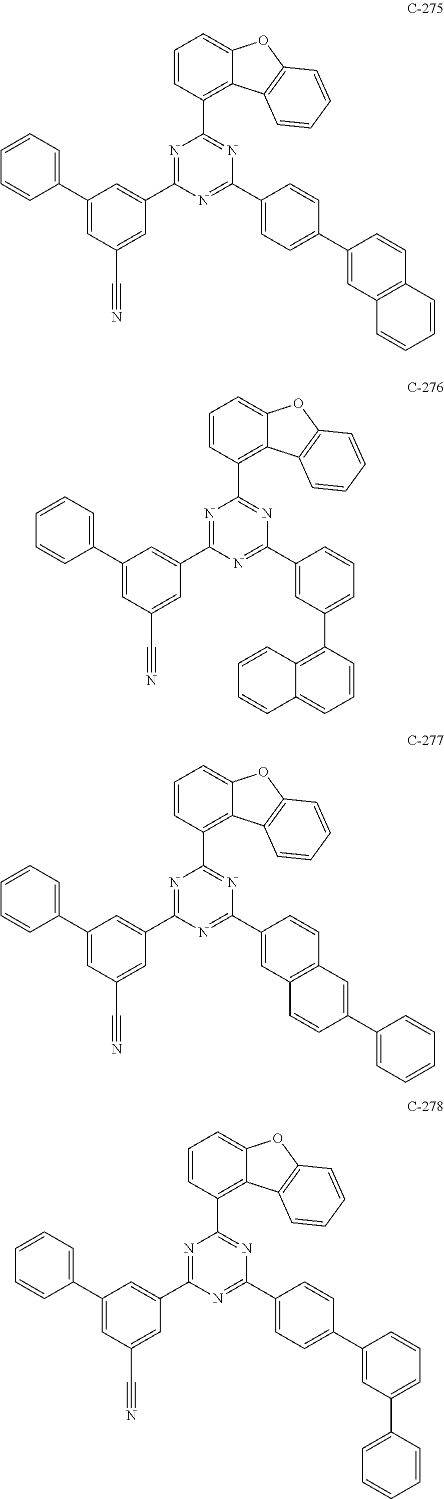 [SMILES: N#Cc1cc(-c2ccccc2)cc(-c2nc(-c3ccc(-c4ccc5ccccc5c4)cc3)nc(-c3cccc4oc5ccccc5c34)n2)c1 ; N#Cc1cc(-c2ccccc2)cc(-c2nc(-c3cccc(-c4cccc5ccccc45)c3)nc(-c3cccc4oc5ccccc5c34)n2)c1 ; N#Cc1cc(-c2ccccc2)cc(-c2nc(-c3ccc4cc(-c5ccccc5)ccc4c3)nc(-c3cccc4oc5ccccc5c34)n2)c1 ; N#Cc1cc(-c2ccccc2)cc(-c2nc(-c3ccc(-c4cccc(-c5ccccc5)c4)cc3)nc(-c3cccc4oc5ccccc5c34)n2)c1] 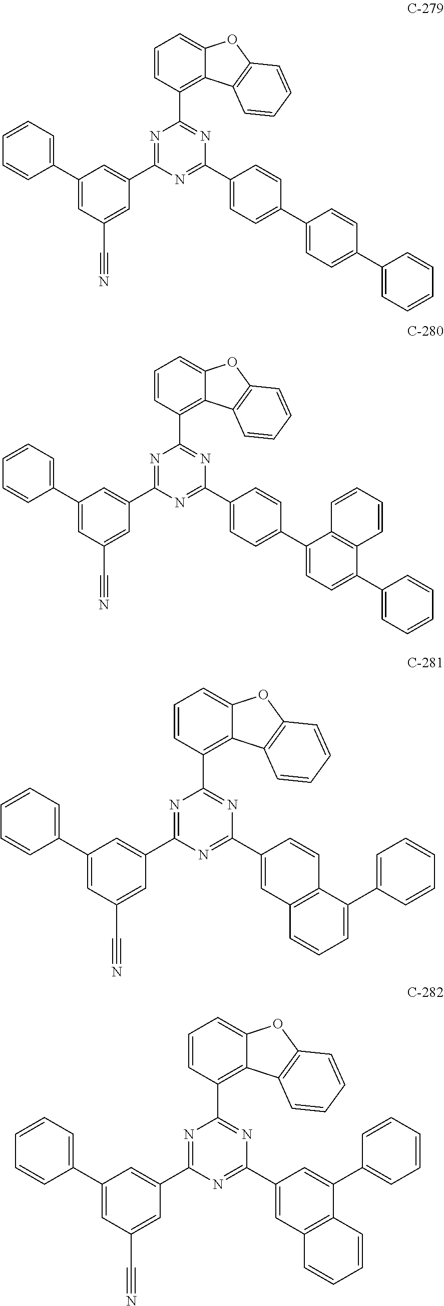 [SMILES: N#Cc1cc(-c2ccccc2)cc(-c2nc(-c3ccc(-c4ccc(-c5ccccc5)cc4)cc3)nc(-c3cccc4oc5ccccc5c34)n2)c1 ; N#Cc1cc(-c2ccccc2)cc(-c2nc(-c3ccc(-c4ccc(-c5ccccc5)c5ccccc45)cc3)nc(-c3cccc4oc5ccccc5c34)n2)c1 ; N#Cc1cc(-c2ccccc2)cc(-c2nc(-c3ccc4c(-c5ccccc5)cccc4c3)nc(-c3cccc4oc5ccccc5c34)n2)c1 ; N#Cc1cc(-c2ccccc2)cc(-c2nc(-c3cc(-c4ccccc4)c4ccccc4c3)nc(-c3cccc4oc5ccccc5c34)n2)c1] 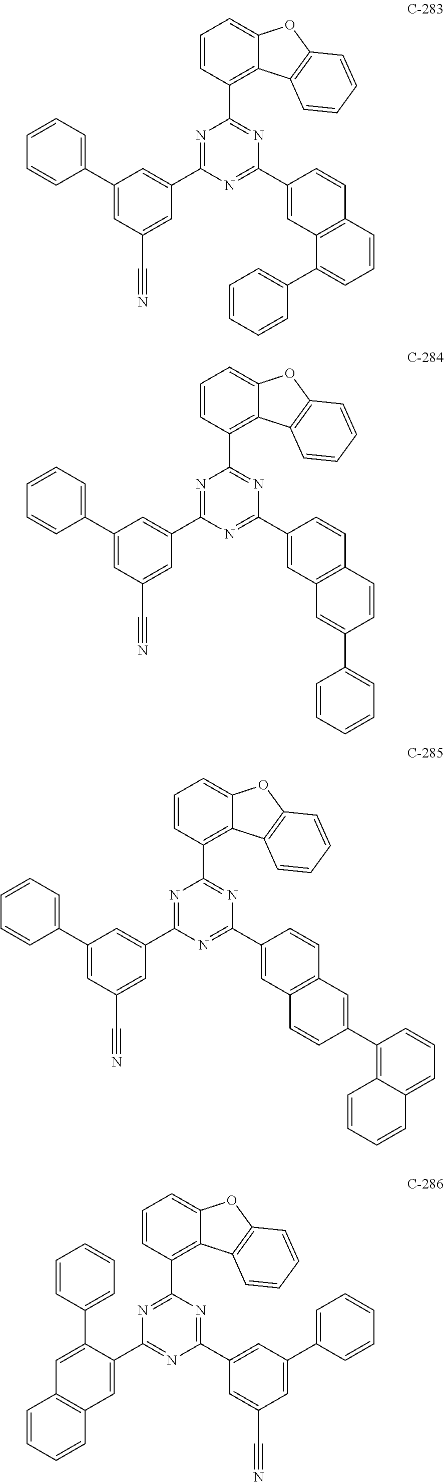 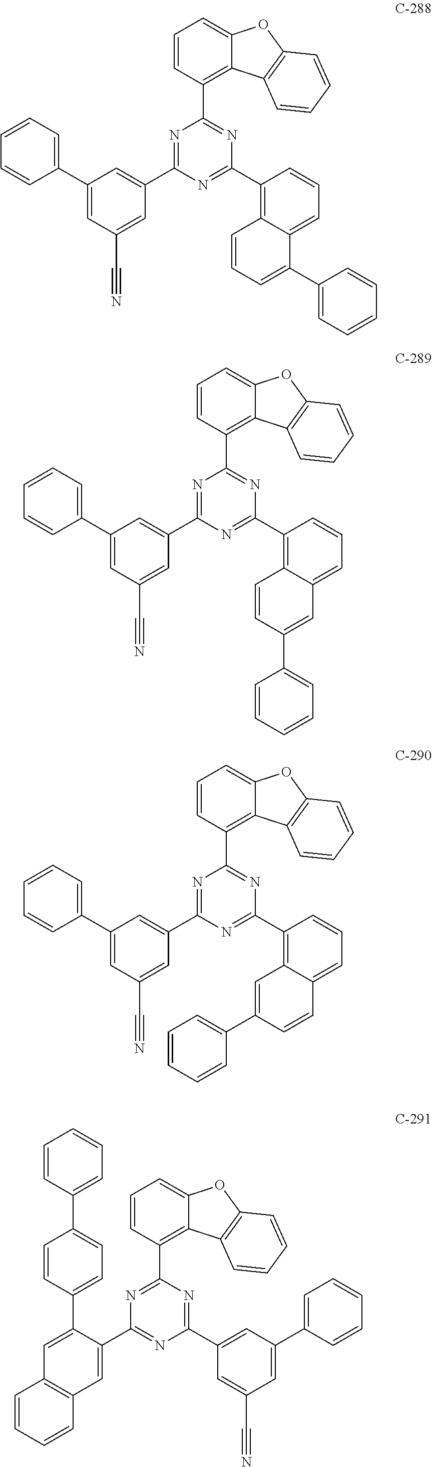 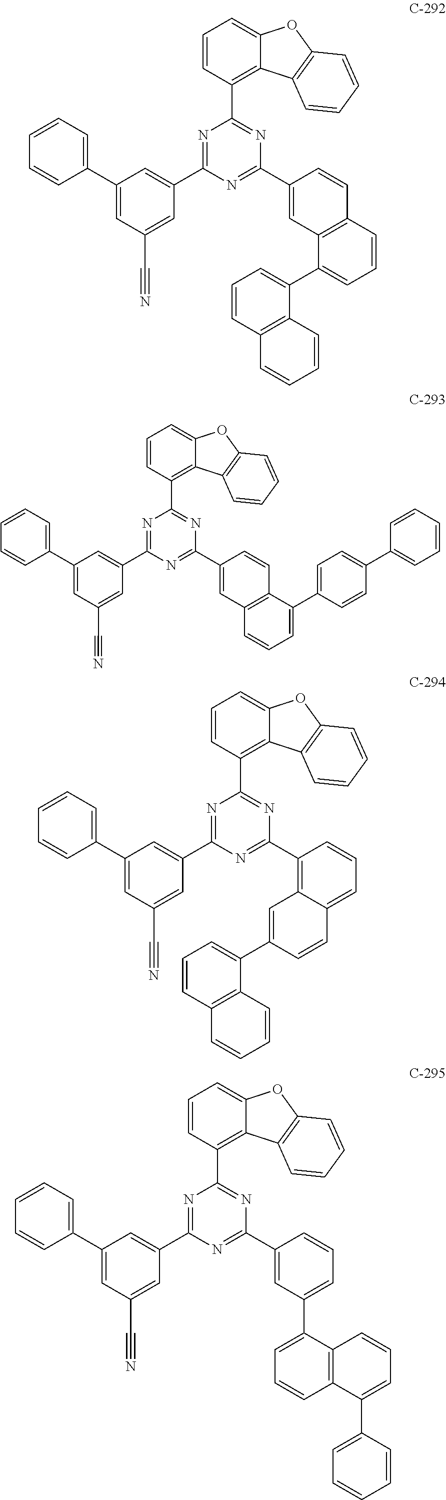 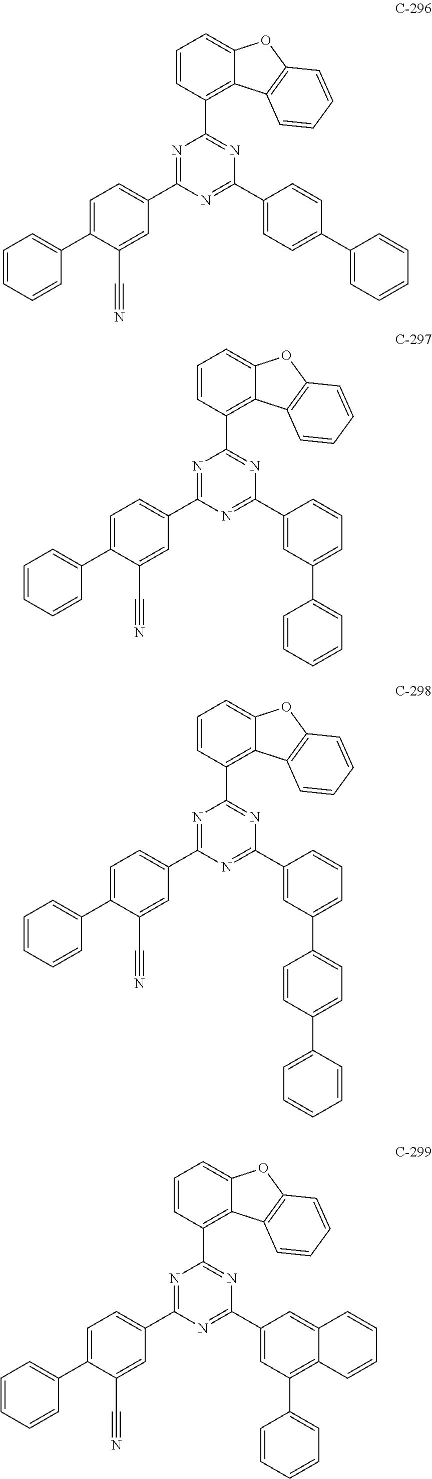 [SMILES: N#Cc1cc(-c2nc(-c3ccc(-c4ccccc4)cc3)nc(-c3cccc4oc5ccccc5c34)n2)ccc1-c1ccccc1 ; N#Cc1cc(-c2nc(-c3cccc(-c4ccccc4)c3)nc(-c3cccc4oc5ccccc5c34)n2)ccc1-c1ccccc1 ; N#Cc1cc(-c2nc(-c3cccc(-c4ccc(-c5ccccc5)cc4)c3)nc(-c3cccc4oc5ccccc5c34)n2)ccc1-c1ccccc1 ; N#Cc1cc(-c2nc(-c3cc(-c4ccccc4)c4ccccc4c3)nc(-c3cccc4oc5ccccc5c34)n2)ccc1-c1ccccc1] 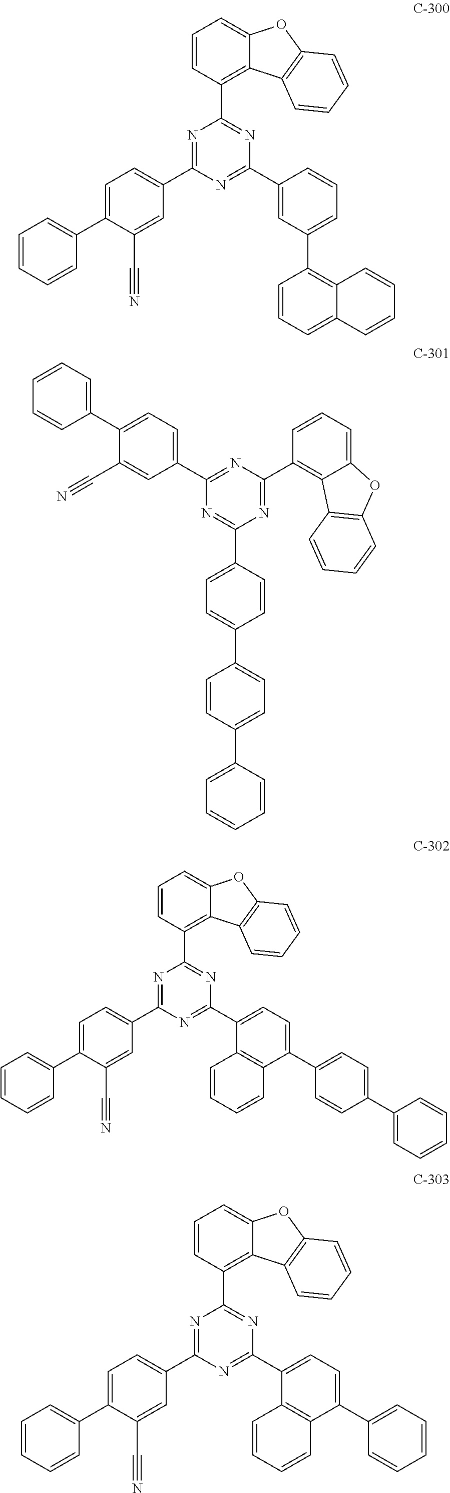 [SMILES: N#Cc1cc(-c2nc(-c3cccc(-c4cccc5ccccc45)c3)nc(-c3cccc4oc5ccccc5c34)n2)ccc1-c1ccccc1 ; N#Cc1cc(-c2nc(-c3ccc(-c4ccc(-c5ccccc5)cc4)cc3)nc(-c3cccc4oc5ccccc5c34)n2)ccc1-c1ccccc1 ; N#Cc1cc(-c2nc(-c3ccc(-c4ccc(-c5ccccc5)cc4)c4ccccc34)nc(-c3cccc4oc5ccccc5c34)n2)ccc1-c1ccccc1 ; N#Cc1cc(-c2nc(-c3ccc(-c4ccccc4)c4ccccc34)nc(-c3cccc4oc5ccccc5c34)n2)ccc1-c1ccccc1] 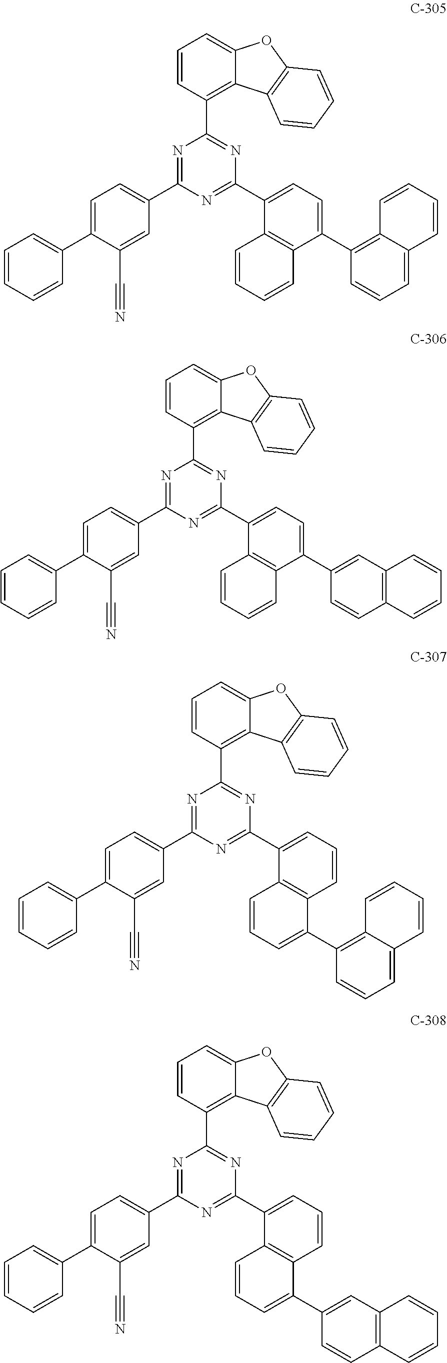 [SMILES: N#Cc1cc(-c2nc(-c3ccc(-c4cccc5ccccc45)c4ccccc34)nc(-c3cccc4oc5ccccc5c34)n2)ccc1-c1ccccc1 ; N#Cc1cc(-c2nc(-c3ccc(-c4ccc5ccccc5c4)c4ccccc34)nc(-c3cccc4oc5ccccc5c34)n2)ccc1-c1ccccc1 ; N#Cc1cc(-c2nc(-c3cccc4c(-c5cccc6ccccc56)cccc34)nc(-c3cccc4oc5ccccc5c34)n2)ccc1-c1ccccc1 ; N#Cc1cc(-c2nc(-c3cccc4c(-c5ccc6ccccc6c5)cccc34)nc(-c3cccc4oc5ccccc5c34)n2)ccc1-c1ccccc1] 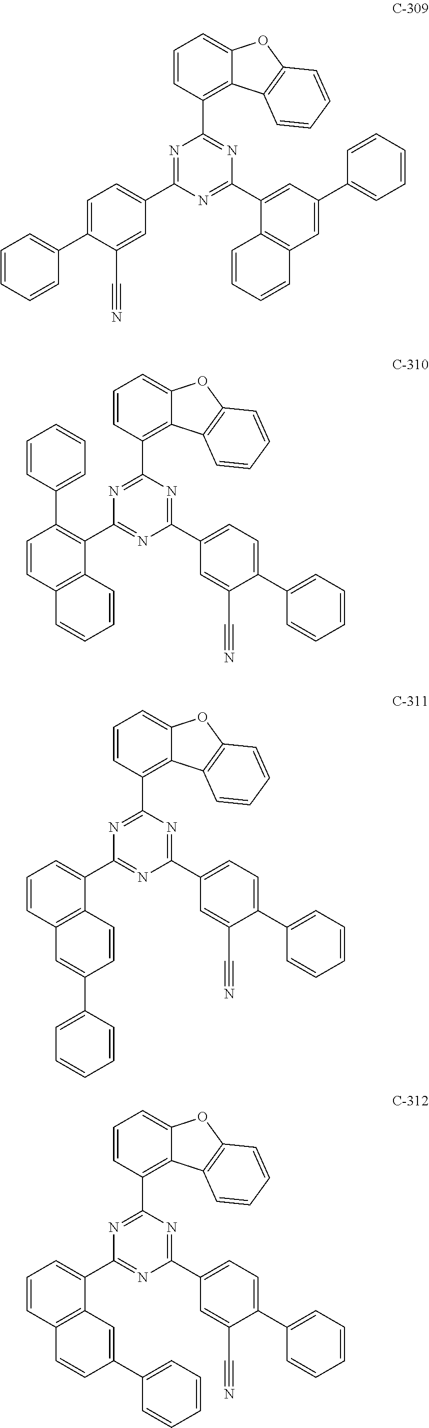 [SMILES: N#Cc1cc(-c2nc(-c3cc(-c4ccccc4)cc4ccccc34)nc(-c3cccc4oc5ccccc5c34)n2)ccc1-c1ccccc1 ; N#Cc1cc(-c2nc(-c3c(-c4ccccc4)ccc4ccccc34)nc(-c3cccc4oc5ccccc5c34)n2)ccc1-c1ccccc1 ; N#Cc1cc(-c2nc(-c3cccc4cc(-c5ccccc5)ccc34)nc(-c3cccc4oc5ccccc5c34)n2)ccc1-c1ccccc1 ; N#Cc1cc(-c2nc(-c3cccc4ccc(-c5ccccc5)cc34)nc(-c3cccc4oc5ccccc5c34)n2)ccc1-c1ccccc1] 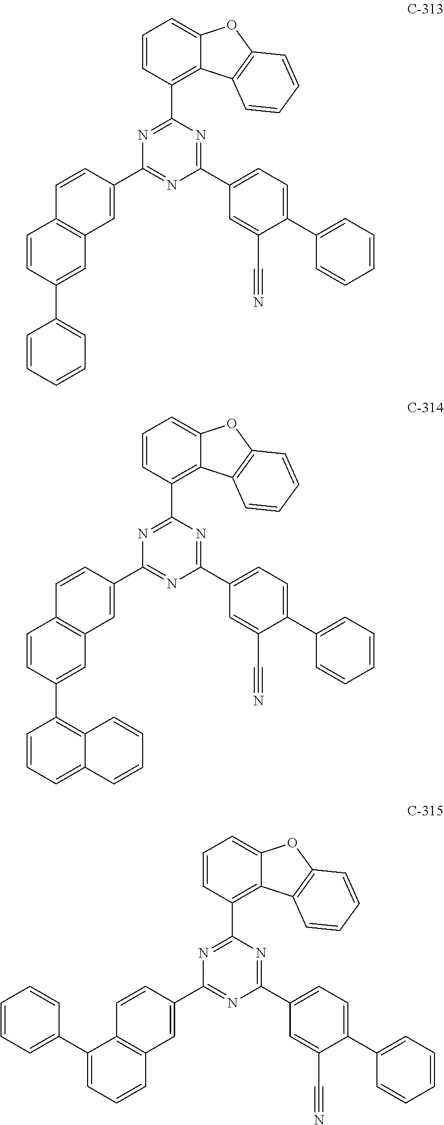 [SMILES: N#Cc1cc(-c2nc(-c3ccc4ccc(-c5ccccc5)cc4c3)nc(-c3cccc4oc5ccccc5c34)n2)ccc1-c1ccccc1 ; N#Cc1cc(-c2nc(-c3ccc4ccc(-c5cccc6ccccc56)cc4c3)nc(-c3cccc4oc5ccccc5c34)n2)ccc1-c1ccccc1 ; N#Cc1cc(-c2nc(-c3ccc4c(-c5ccccc5)cccc4c3)nc(-c3cccc4oc5ccccc5c34)n2)ccc1-c1ccccc1] 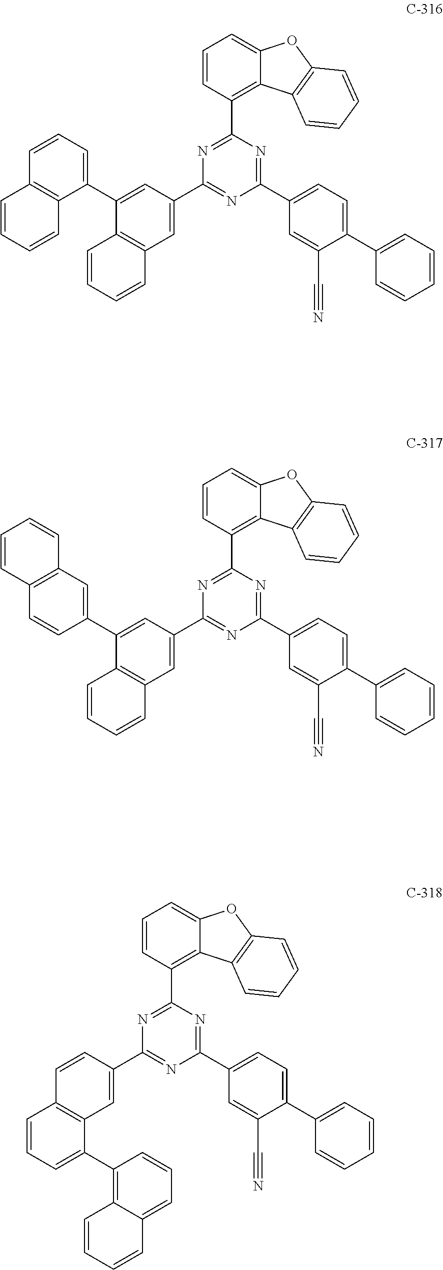 [SMILES: N#Cc1cc(-c2nc(-c3cc(-c4cccc5ccccc45)c4ccccc4c3)nc(-c3cccc4oc5ccccc5c34)n2)ccc1-c1ccccc1 ; N#Cc1cc(-c2nc(-c3cc(-c4ccc5ccccc5c4)c4ccccc4c3)nc(-c3cccc4oc5ccccc5c34)n2)ccc1-c1ccccc1 ; N#Cc1cc(-c2nc(-c3ccc4cccc(-c5cccc6ccccc56)c4c3)nc(-c3cccc4oc5ccccc5c34)n2)ccc1-c1ccccc1] 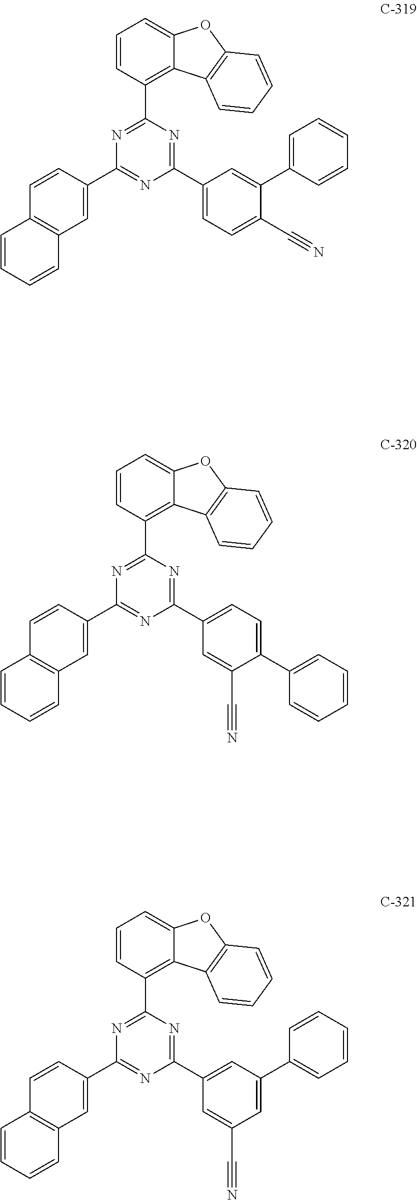 [SMILES: N#Cc1ccc(-c2nc(-c3ccc4ccccc4c3)nc(-c3cccc4oc5ccccc5c34)n2)cc1-c1ccccc1 ; N#Cc1cc(-c2nc(-c3ccc4ccccc4c3)nc(-c3cccc4oc5ccccc5c34)n2)ccc1-c1ccccc1 ; N#Cc1cc(-c2ccccc2)cc(-c2nc(-c3ccc4ccccc4c3)nc(-c3cccc4oc5ccccc5c34)n2)c1] 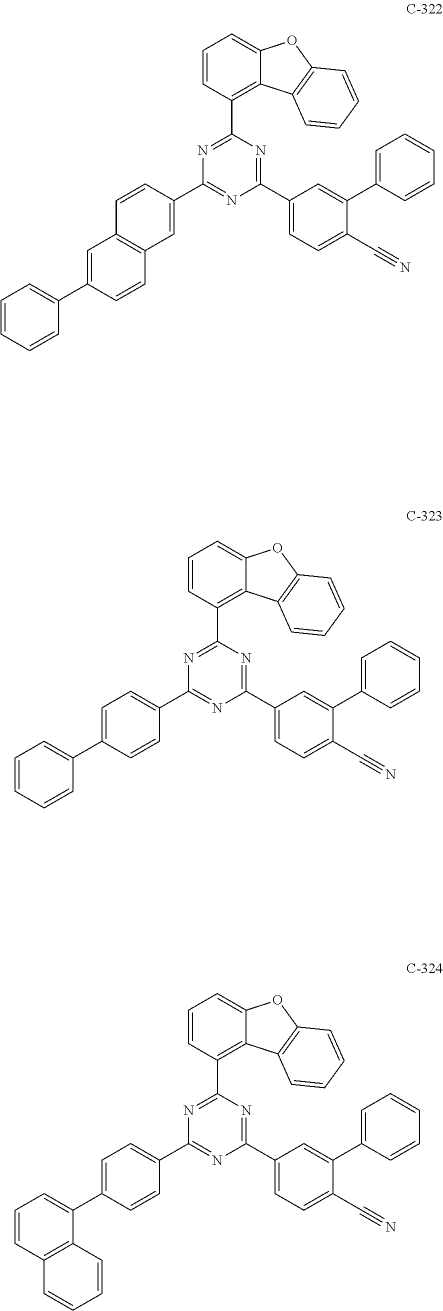 [SMILES: N#Cc1ccc(-c2nc(-c3ccc4cc(-c5ccccc5)ccc4c3)nc(-c3cccc4oc5ccccc5c34)n2)cc1-c1ccccc1 ; N#Cc1ccc(-c2nc(-c3ccc(-c4ccccc4)cc3)nc(-c3cccc4oc5ccccc5c34)n2)cc1-c1ccccc1 ; N#Cc1ccc(-c2nc(-c3ccc(-c4cccc5ccccc45)cc3)nc(-c3cccc4oc5ccccc5c34)n2)cc1-c1ccccc1] 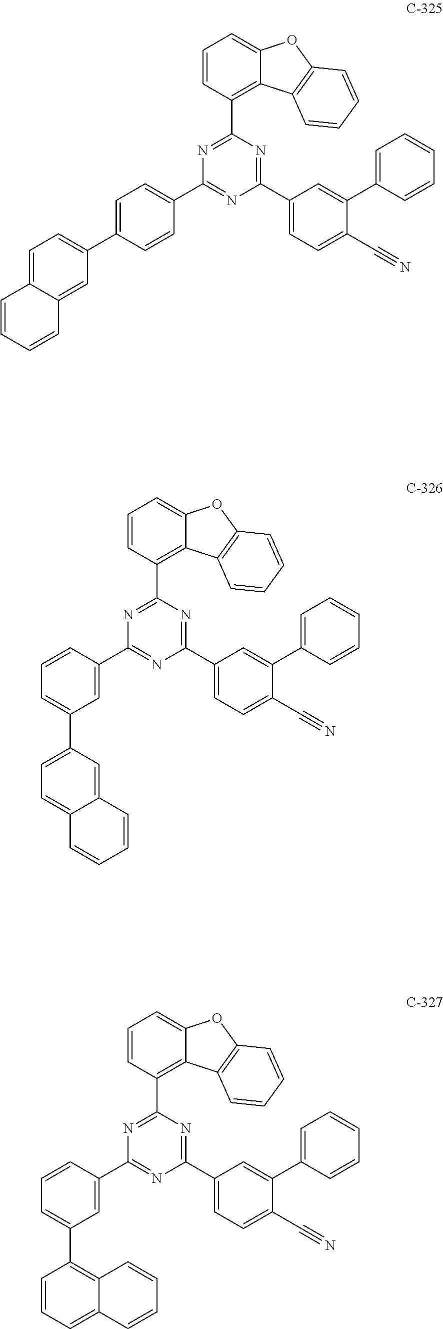 [SMILES: N#Cc1ccc(-c2nc(-c3ccc(-c4ccc5ccccc5c4)cc3)nc(-c3cccc4oc5ccccc5c34)n2)cc1-c1ccccc1 ; N#Cc1ccc(-c2nc(-c3cccc(-c4ccc5ccccc5c4)c3)nc(-c3cccc4oc5ccccc5c34)n2)cc1-c1ccccc1 ; N#Cc1ccc(-c2nc(-c3cccc(-c4cccc5ccccc45)c3)nc(-c3cccc4oc5ccccc5c34)n2)cc1-c1ccccc1] 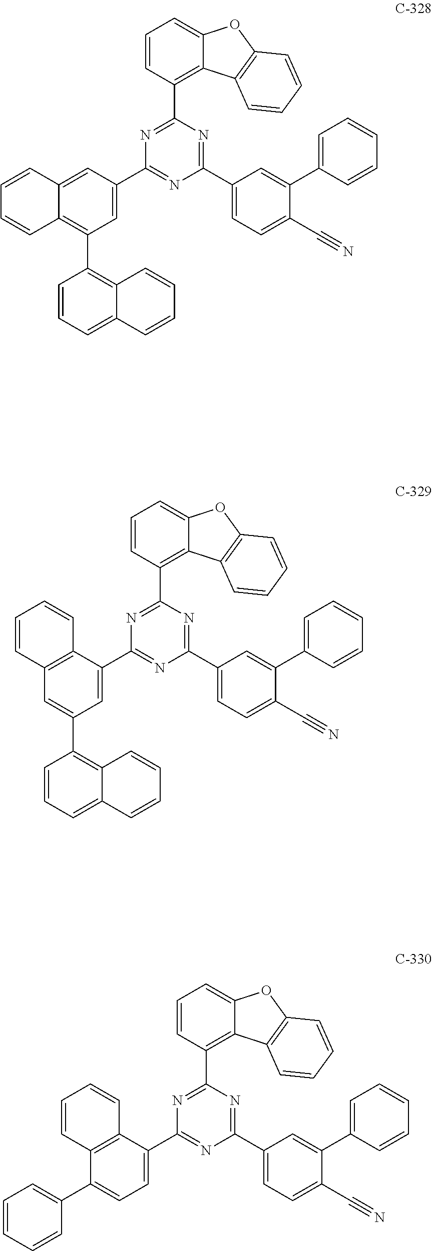 [SMILES: N#Cc1ccc(-c2nc(-c3cc(-c4cccc5ccccc45)c4ccccc4c3)nc(-c3cccc4oc5ccccc5c34)n2)cc1-c1ccccc1 ; N#Cc1ccc(-c2nc(-c3cc(-c4cccc5ccccc45)cc4ccccc34)nc(-c3cccc4oc5ccccc5c34)n2)cc1-c1ccccc1 ; N#Cc1ccc(-c2nc(-c3ccc(-c4ccccc4)c4ccccc34)nc(-c3cccc4oc5ccccc5c34)n2)cc1-c1ccccc1] 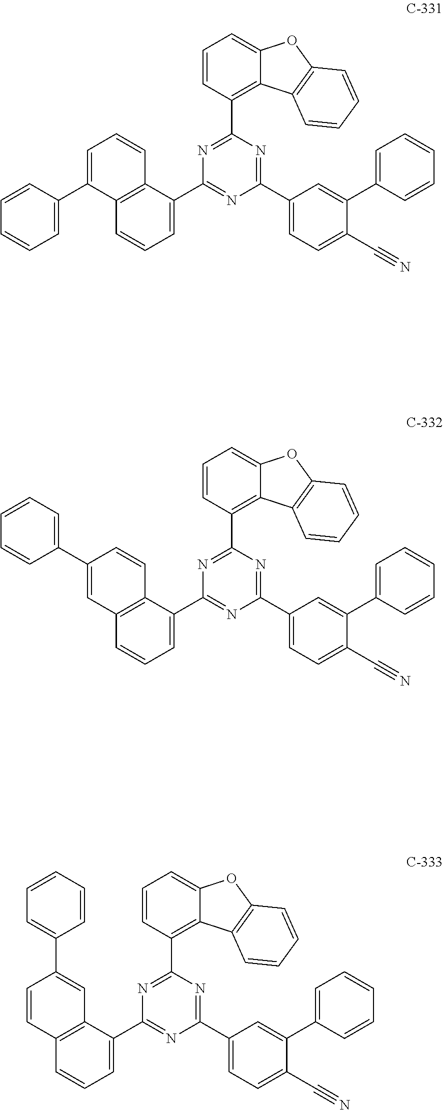 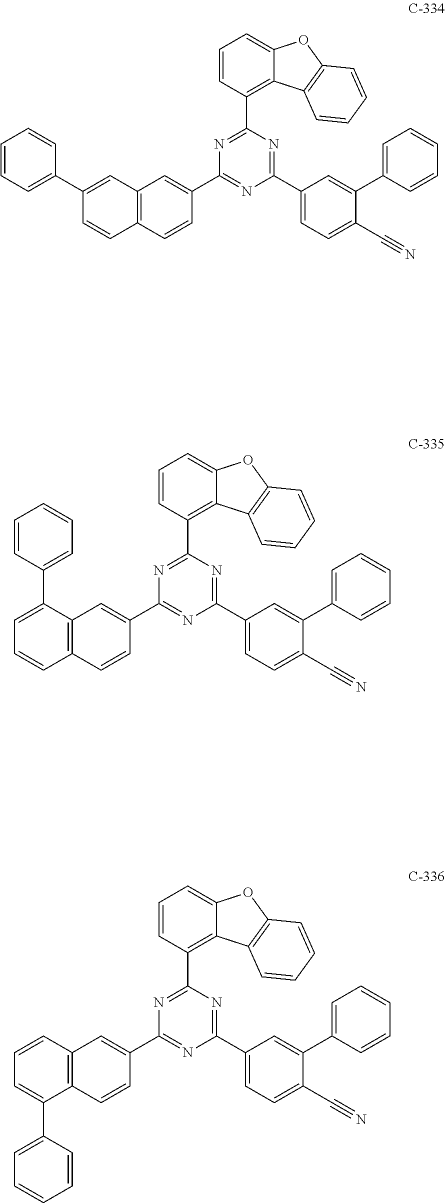 [SMILES: N#Cc1ccc(-c2nc(-c3ccc4ccc(-c5ccccc5)cc4c3)nc(-c3cccc4oc5ccccc5c34)n2)cc1-c1ccccc1 ; N#Cc1ccc(-c2nc(-c3ccc4cccc(-c5ccccc5)c4c3)nc(-c3cccc4oc5ccccc5c34)n2)cc1-c1ccccc1 ; N#Cc1ccc(-c2nc(-c3ccc4c(-c5ccccc5)cccc4c3)nc(-c3cccc4oc5ccccc5c34)n2)cc1-c1ccccc1] 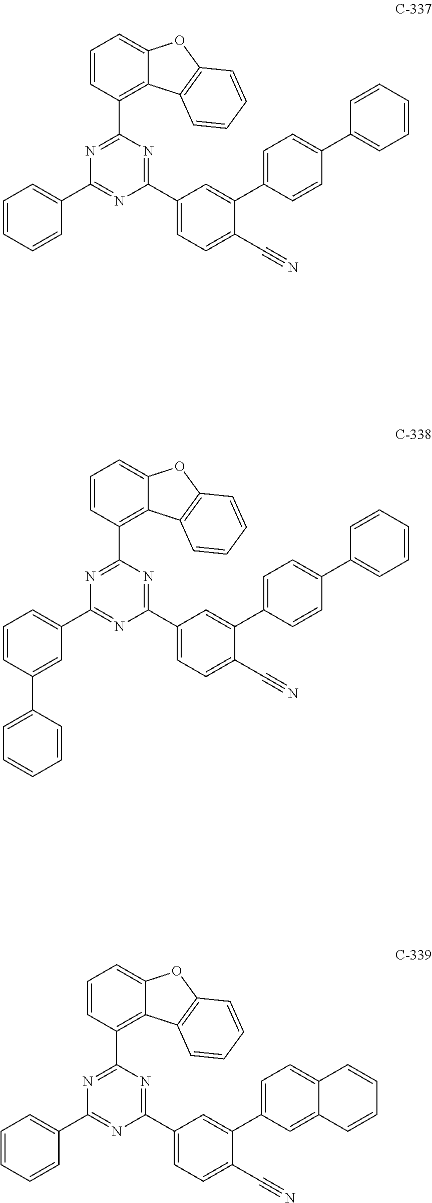 [SMILES: N#Cc1ccc(-c2nc(-c3ccccc3)nc(-c3cccc4oc5ccccc5c34)n2)cc1-c1ccc(-c2ccccc2)cc1 ; N#Cc1ccc(-c2nc(-c3cccc(-c4ccccc4)c3)nc(-c3cccc4oc5ccccc5c34)n2)cc1-c1ccc(-c2ccccc2)cc1 ; N#Cc1ccc(-c2nc(-c3ccccc3)nc(-c3cccc4oc5ccccc5c34)n2)cc1-c1ccc2ccccc2c1] 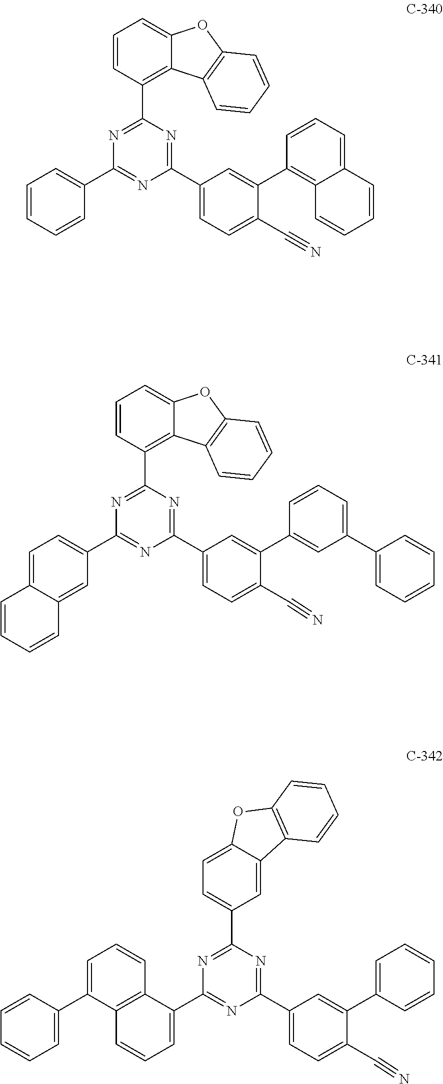 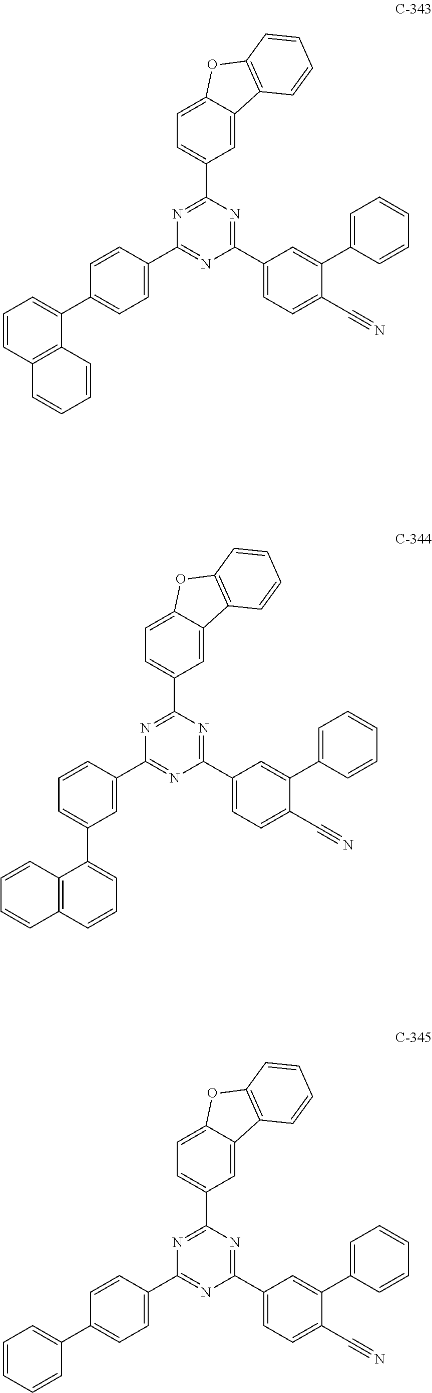 [SMILES: N#Cc1ccc(-c2nc(-c3ccc(-c4cccc5ccccc45)cc3)nc(-c3ccc4oc5ccccc5c4c3)n2)cc1-c1ccccc1 ; N#Cc1ccc(-c2nc(-c3cccc(-c4cccc5ccccc45)c3)nc(-c3ccc4oc5ccccc5c4c3)n2)cc1-c1ccccc1 ; N#Cc1ccc(-c2nc(-c3ccc(-c4ccccc4)cc3)nc(-c3ccc4oc5ccccc5c4c3)n2)cc1-c1ccccc1] 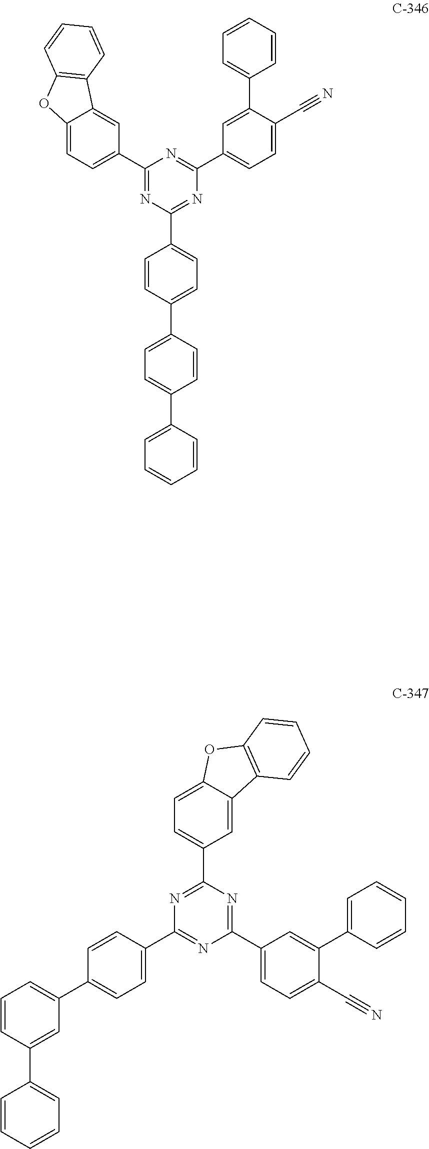 [SMILES: N#Cc1ccc(-c2nc(-c3ccc(-c4ccc(-c5ccccc5)cc4)cc3)nc(-c3ccc4oc5ccccc5c4c3)n2)cc1-c1ccccc1 ; N#Cc1ccc(-c2nc(-c3ccc(-c4cccc(-c5ccccc5)c4)cc3)nc(-c3ccc4oc5ccccc5c4c3)n2)cc1-c1ccccc1] 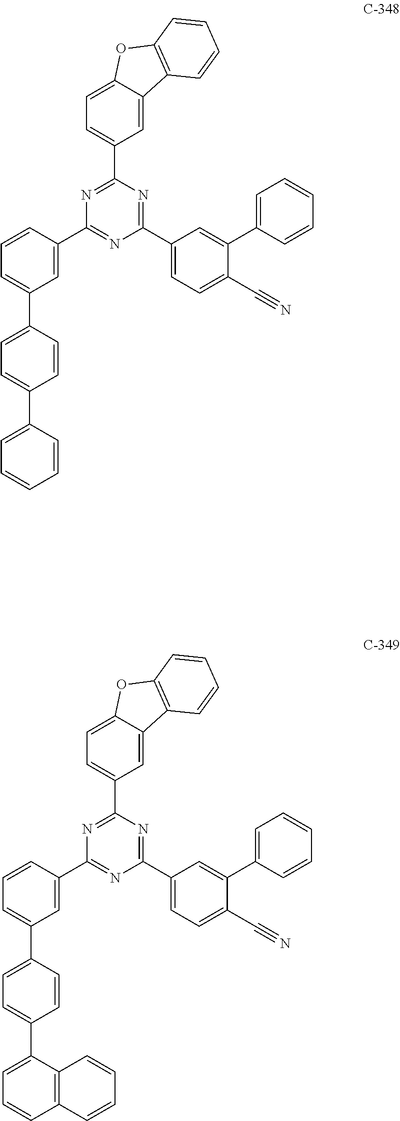 [SMILES: N#Cc1ccc(-c2nc(-c3cccc(-c4ccc(-c5ccccc5)cc4)c3)nc(-c3ccc4oc5ccccc5c4c3)n2)cc1-c1ccccc1 ; N#Cc1ccc(-c2nc(-c3cccc(-c4ccc(-c5cccc6ccccc56)cc4)c3)nc(-c3ccc4oc5ccccc5c4c3)n2)cc1-c1ccccc1] 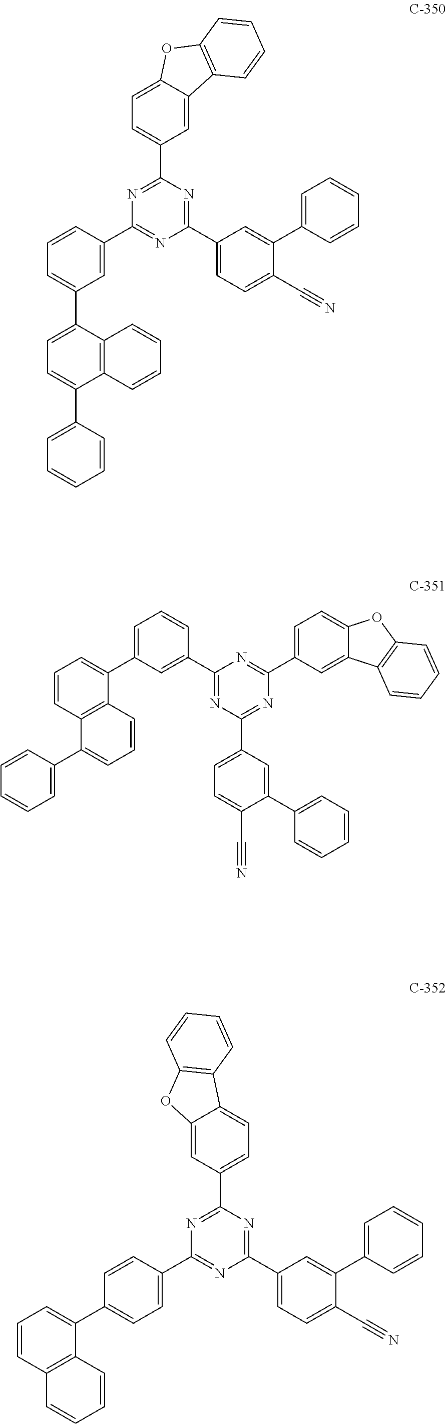 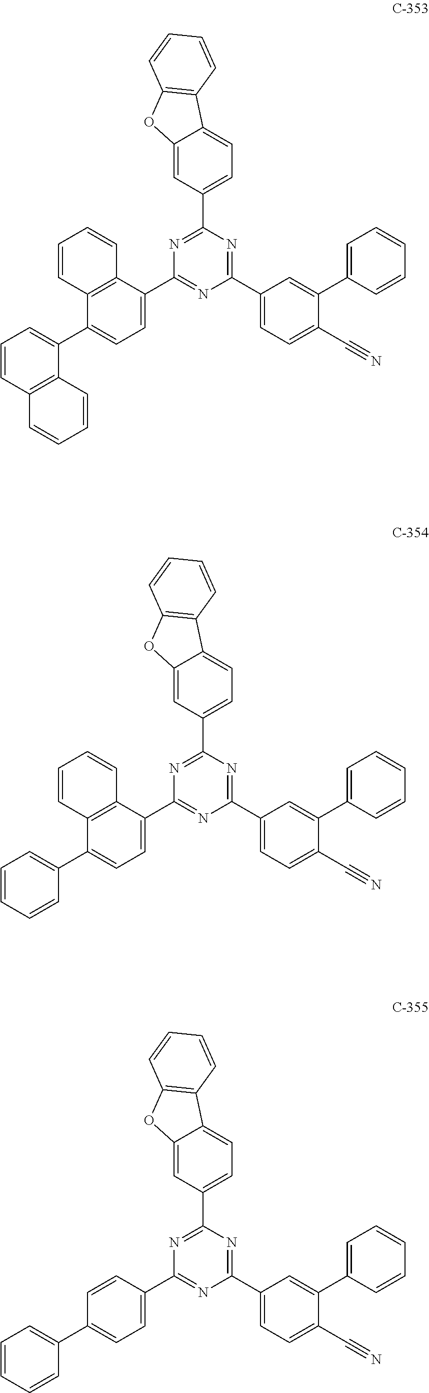 [SMILES: N#Cc1ccc(-c2nc(-c3ccc4c(c3)oc3ccccc34)nc(-c3ccc(-c4cccc5ccccc45)c4ccccc34)n2)cc1-c1ccccc1 ; N#Cc1ccc(-c2nc(-c3ccc4c(c3)oc3ccccc34)nc(-c3ccc(-c4ccccc4)c4ccccc34)n2)cc1-c1ccccc1 ; N#Cc1ccc(-c2nc(-c3ccc(-c4ccccc4)cc3)nc(-c3ccc4c(c3)oc3ccccc34)n2)cc1-c1ccccc1] 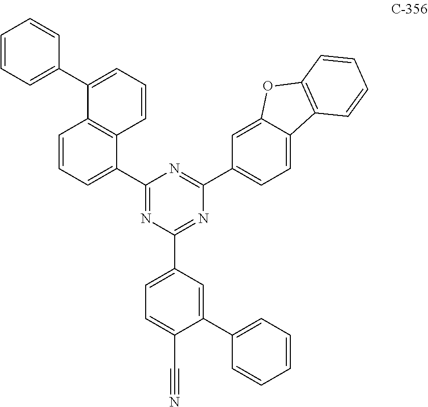 [SMILES: N#Cc1ccc(-c2nc(-c3ccc4c(c3)oc3ccccc34)nc(-c3cccc4c(-c5ccccc5)cccc34)n2)cc1-c1ccccc1] 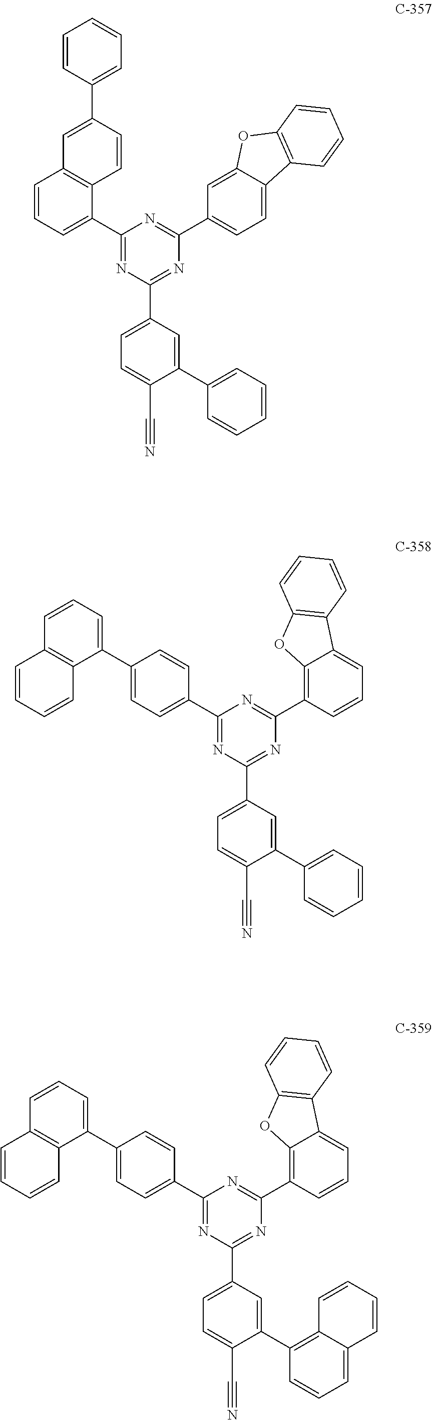 [SMILES: N#Cc1ccc(-c2nc(-c3ccc4c(c3)oc3ccccc34)nc(-c3cccc4cc(-c5ccccc5)ccc34)n2)cc1-c1ccccc1 ; N#Cc1ccc(-c2nc(-c3ccc(-c4cccc5ccccc45)cc3)nc(-c3cccc4c3oc3ccccc34)n2)cc1-c1ccccc1 ; N#Cc1ccc(-c2nc(-c3ccc(-c4cccc5ccccc45)cc3)nc(-c3cccc4c3oc3ccccc34)n2)cc1-c1cccc2ccccc12] 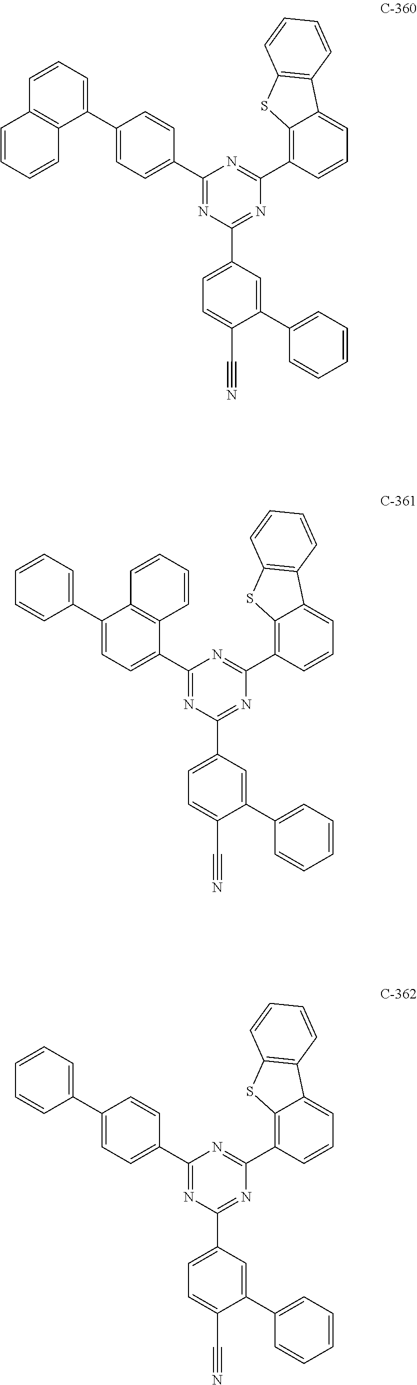 [SMILES: N#Cc1ccc(-c2nc(-c3ccc(-c4cccc5ccccc45)cc3)nc(-c3cccc4c3sc3ccccc34)n2)cc1-c1ccccc1 ; N#Cc1ccc(-c2nc(-c3ccc(-c4ccccc4)c4ccccc34)nc(-c3cccc4c3sc3ccccc34)n2)cc1-c1ccccc1 ; N#Cc1ccc(-c2nc(-c3ccc(-c4ccccc4)cc3)nc(-c3cccc4c3sc3ccccc34)n2)cc1-c1ccccc1] 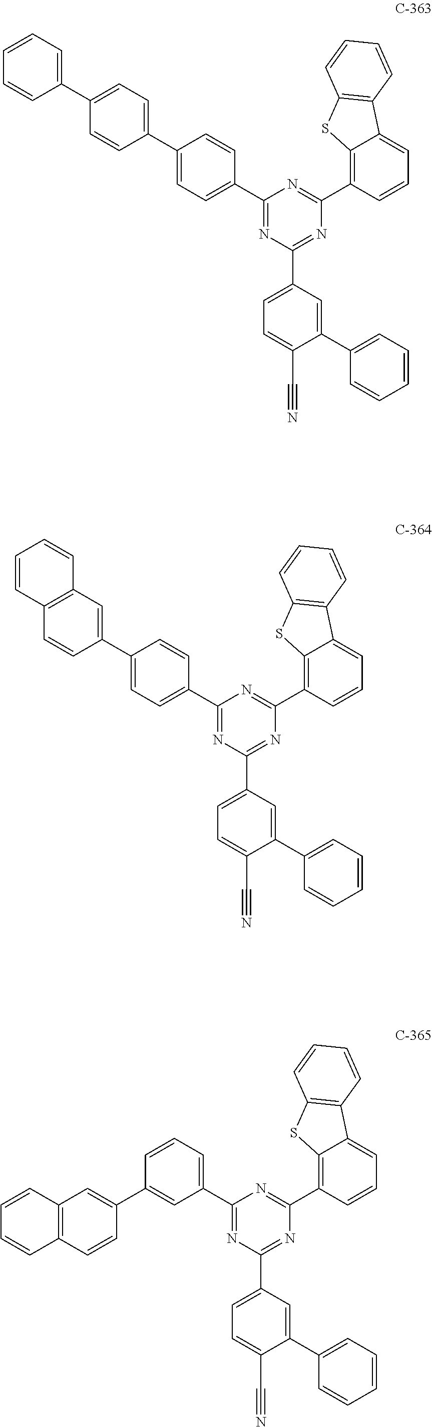 [SMILES: N#Cc1ccc(-c2nc(-c3ccc(-c4ccc(-c5ccccc5)cc4)cc3)nc(-c3cccc4c3sc3ccccc34)n2)cc1-c1ccccc1 ; N#Cc1ccc(-c2nc(-c3ccc(-c4ccc5ccccc5c4)cc3)nc(-c3cccc4c3sc3ccccc34)n2)cc1-c1ccccc1 ; N#Cc1ccc(-c2nc(-c3cccc(-c4ccc5ccccc5c4)c3)nc(-c3cccc4c3sc3ccccc34)n2)cc1-c1ccccc1] 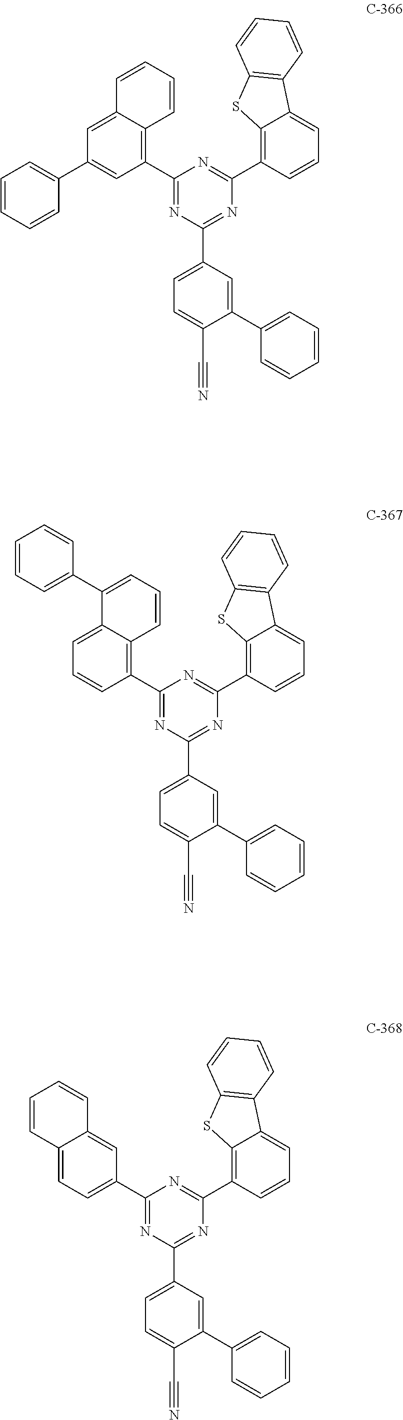 [SMILES: N#Cc1ccc(-c2nc(-c3cc(-c4ccccc4)cc4ccccc34)nc(-c3cccc4c3sc3ccccc34)n2)cc1-c1ccccc1 ; N#Cc1ccc(-c2nc(-c3cccc4c(-c5ccccc5)cccc34)nc(-c3cccc4c3sc3ccccc34)n2)cc1-c1ccccc1 ; N#Cc1ccc(-c2nc(-c3ccc4ccccc4c3)nc(-c3cccc4c3sc3ccccc34)n2)cc1-c1ccccc1] 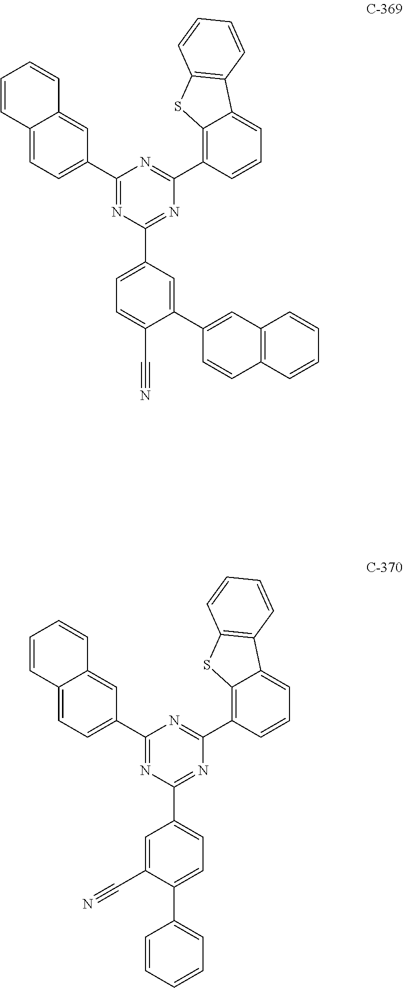 [SMILES: N#Cc1ccc(-c2nc(-c3ccc4ccccc4c3)nc(-c3cccc4c3sc3ccccc34)n2)cc1-c1ccc2ccccc2c1 ; N#Cc1cc(-c2nc(-c3ccc4ccccc4c3)nc(-c3cccc4c3sc3ccccc34)n2)ccc1-c1ccccc1] 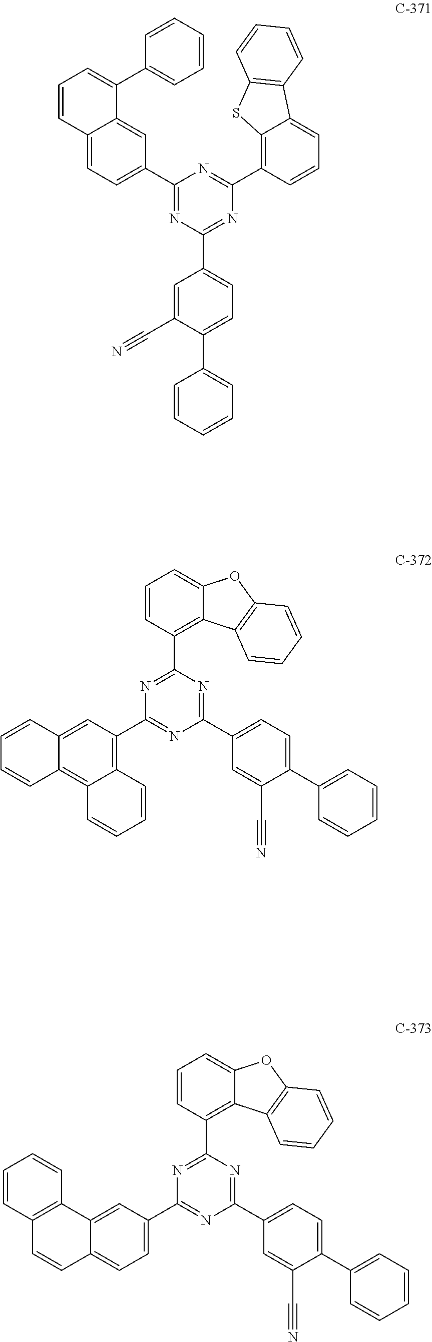 [SMILES: N#Cc1cc(-c2nc(-c3ccc4cccc(-c5ccccc5)c4c3)nc(-c3cccc4c3sc3ccccc34)n2)ccc1-c1ccccc1 ; N#Cc1cc(-c2nc(-c3cc4ccccc4c4ccccc34)nc(-c3cccc4oc5ccccc5c34)n2)ccc1-c1ccccc1 ; N#Cc1cc(-c2nc(-c3ccc4ccc5ccccc5c4c3)nc(-c3cccc4oc5ccccc5c34)n2)ccc1-c1ccccc1] 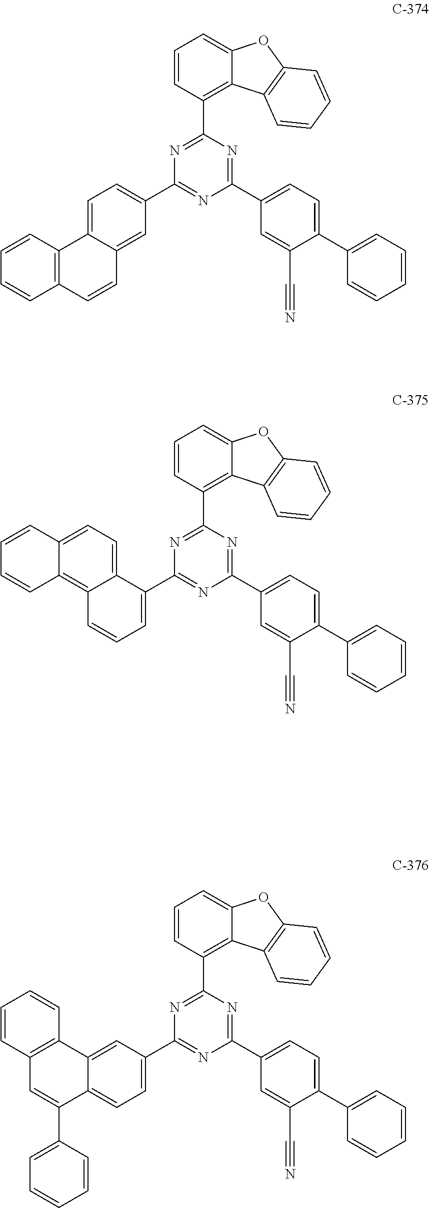 [SMILES: N#Cc1cc(-c2nc(-c3ccc4c(ccc5ccccc54)c3)nc(-c3cccc4oc5ccccc5c34)n2)ccc1-c1ccccc1 ; N#Cc1cc(-c2nc(-c3cccc4c3ccc3ccccc34)nc(-c3cccc4oc5ccccc5c34)n2)ccc1-c1ccccc1 ; N#Cc1cc(-c2nc(-c3ccc4c(-c5ccccc5)cc5ccccc5c4c3)nc(-c3cccc4oc5ccccc5c34)n2)ccc1-c1ccccc1] 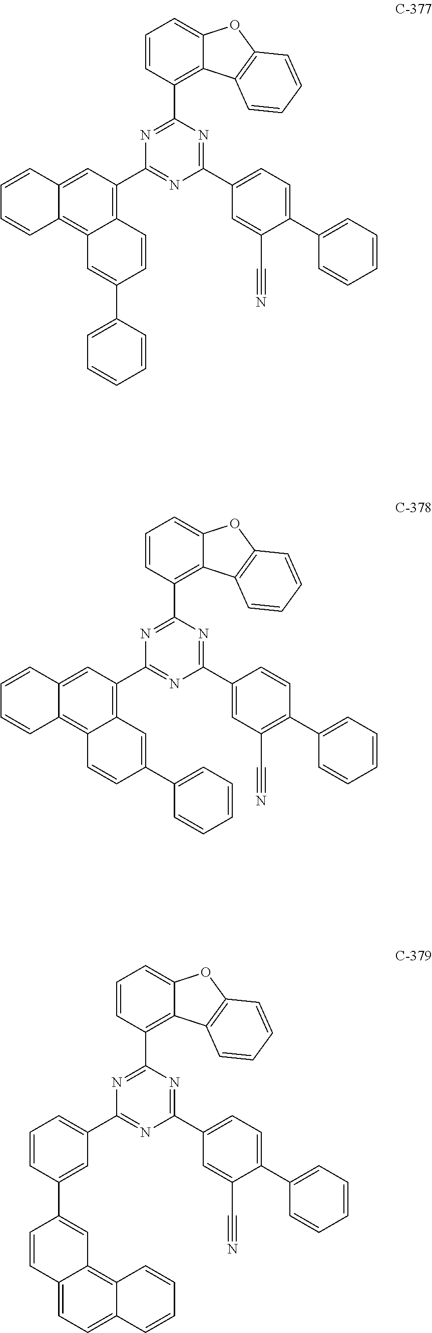 [SMILES: N#Cc1cc(-c2nc(-c3cc4ccccc4c4cc(-c5ccccc5)ccc34)nc(-c3cccc4oc5ccccc5c34)n2)ccc1-c1ccccc1 ; N#Cc1cc(-c2nc(-c3cc4ccccc4c4ccc(-c5ccccc5)cc34)nc(-c3cccc4oc5ccccc5c34)n2)ccc1-c1ccccc1 ; N#Cc1cc(-c2nc(-c3cccc(-c4ccc5ccc6ccccc6c5c4)c3)nc(-c3cccc4oc5ccccc5c34)n2)ccc1-c1ccccc1] 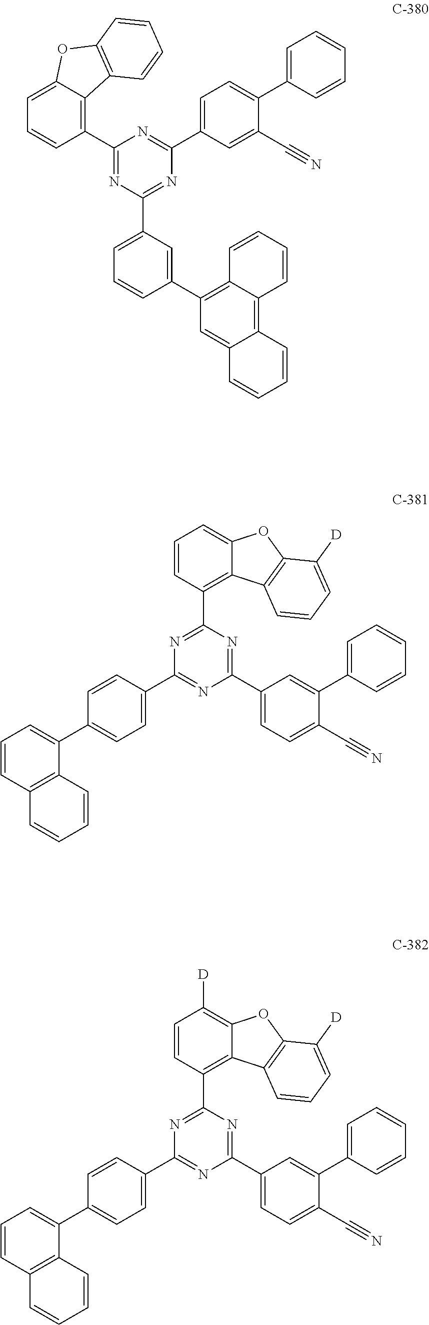 [SMILES: N#Cc1cc(-c2nc(-c3cccc(-c4cc5ccccc5c5ccccc45)c3)nc(-c3cccc4oc5ccccc5c34)n2)ccc1-c1ccccc1 ; [2H]c1cccc2c1oc1cccc(-c3nc(-c4ccc(-c5cccc6ccccc56)cc4)nc(-c4ccc(C#N)c(-c5ccccc5)c4)n3)c12 ; [2H]c1cccc2c1oc1c([2H])ccc(-c3nc(-c4ccc(-c5cccc6ccccc56)cc4)nc(-c4ccc(C#N)c(-c5ccccc5)c4)n3)c12] 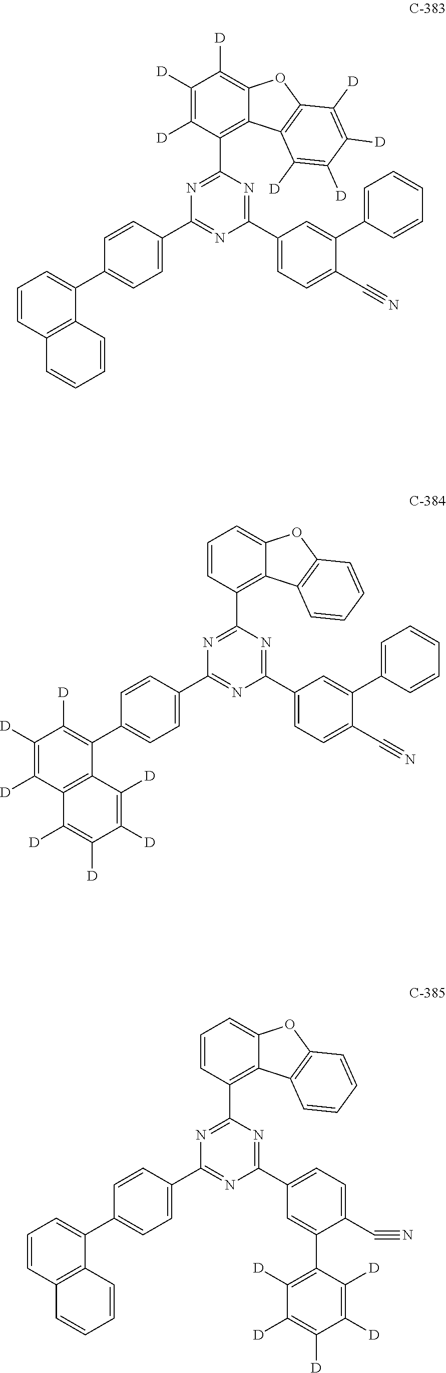 [SMILES: [2H]c1c([2H])c([2H])c2c(oc3c([2H])c([2H])c([2H])c(-c4nc(-c5ccc(-c6cccc7ccccc67)cc5)nc(-c5ccc(C#N)c(-c6ccccc6)c5)n4)c32)c1[2H] ; [2H]c1c([2H])c([2H])c2c(-c3ccc(-c4nc(-c5ccc(C#N)c(-c6ccccc6)c5)nc(-c5cccc6oc7ccccc7c56)n4)cc3)c([2H])c([2H])c([2H])c2c1[2H] ; [2H]c1c([2H])c([2H])c(-c2cc(-c3nc(-c4ccc(-c5cccc6ccccc56)cc4)nc(-c4cccc5oc6ccccc6c45)n3)ccc2C#N)c([2H])c1[2H]] 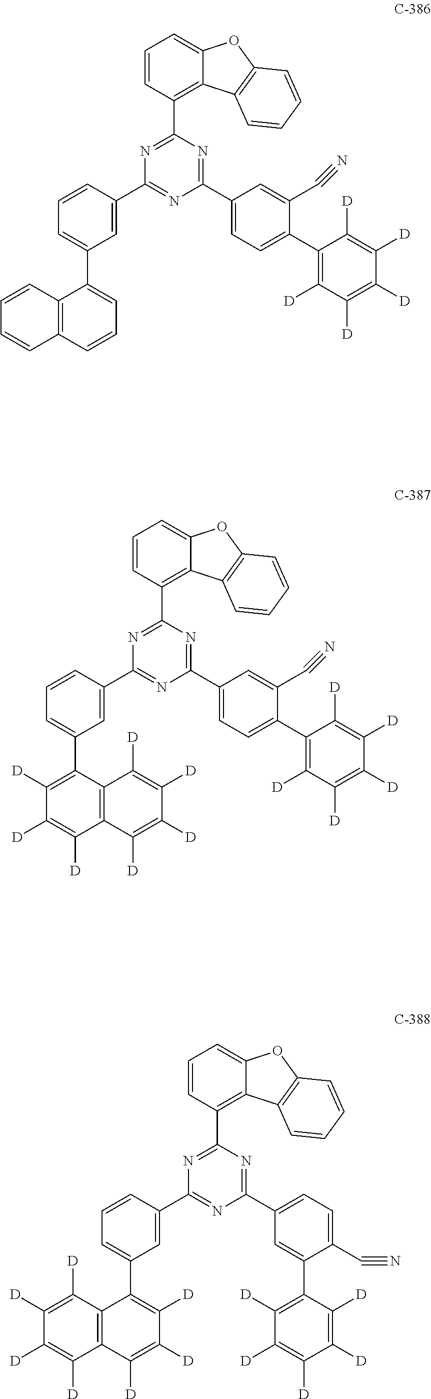 [SMILES: [2H]c1c([2H])c([2H])c(-c2ccc(-c3nc(-c4cccc(-c5cccc6ccccc56)c4)nc(-c4cccc5oc6ccccc6c45)n3)cc2C#N)c([2H])c1[2H] ; [2H]c1c([2H])c([2H])c(-c2ccc(-c3nc(-c4cccc(-c5c([2H])c([2H])c([2H])c6c([2H])c([2H])c([2H])c([2H])c56)c4)nc(-c4cccc5oc6ccccc6c45)n3)cc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccccc6c45)n3)ccc2C#N)c([2H])c1[2H]] 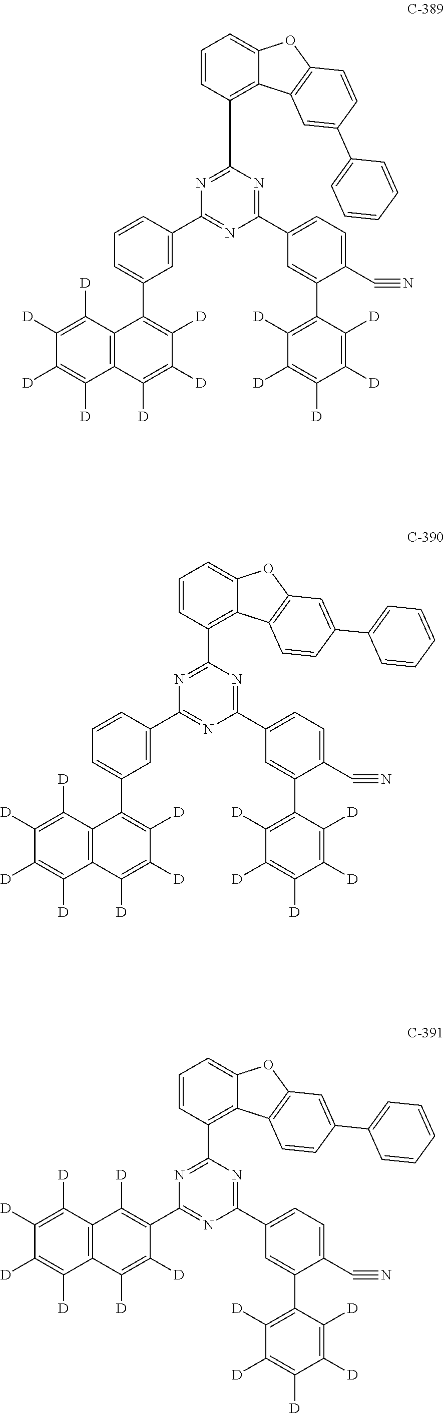 [SMILES: [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6ccc(-c7ccccc7)cc6c45)n3)ccc2C#N)c([2H])c1[2H] ; [2H]c1c([2H])c([2H])c(-c2cc(-c3nc(-c4cccc(-c5c([2H])c([2H])c([2H])c6c([2H])c([2H])c([2H])c([2H])c56)c4)nc(-c4cccc5oc6cc(-c7ccccc7)ccc6c45)n3)ccc2C#N)c([2H])c1[2H] ; [2H]c1c([2H])c([2H])c(-c2cc(-c3nc(-c4c([2H])c([2H])c5c([2H])c([2H])c([2H])c([2H])c5c4[2H])nc(-c4cccc5oc6cc(-c7ccccc7)ccc6c45)n3)ccc2C#N)c([2H])c1[2H]] 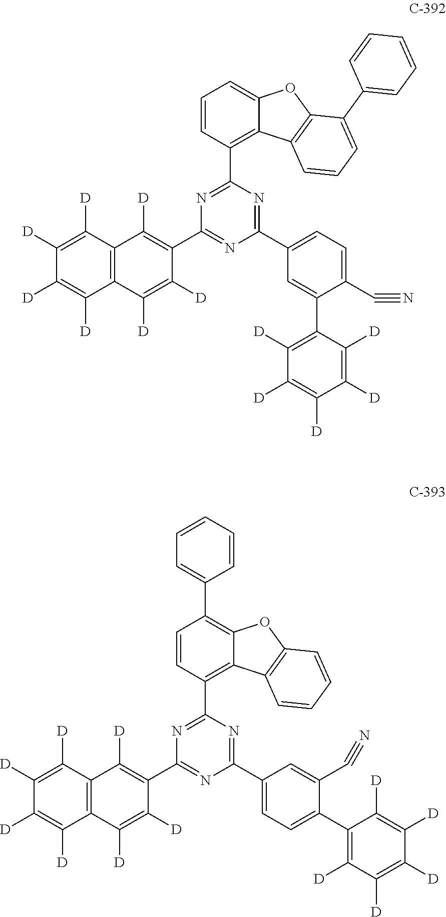 [SMILES: [2H]c1c([2H])c([2H])c(-c2cc(-c3nc(-c4c([2H])c([2H])c5c([2H])c([2H])c([2H])c([2H])c5c4[2H])nc(-c4cccc5oc6c(-c7ccccc7)cccc6c45)n3)ccc2C#N)c([2H])c1[2H] ; [2H]c1c([2H])c([2H])c(-c2ccc(-c3nc(-c4c([2H])c([2H])c5c([2H])c([2H])c([2H])c([2H])c5c4[2H])nc(-c4ccc(-c5ccccc5)c5oc6ccccc6c45)n3)cc2C#N)c([2H])c1[2H]] 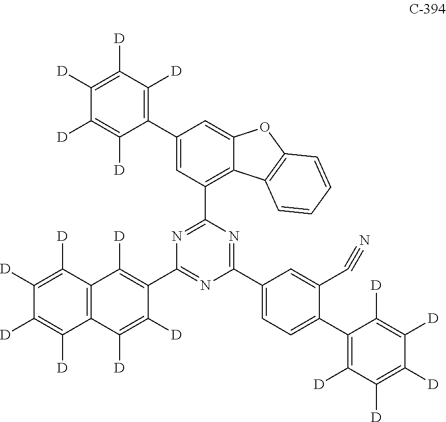 [SMILES: [2H]c1c([2H])c([2H])c(-c2cc(-c3nc(-c4ccc(-c5c([2H])c([2H])c([2H])c([2H])c5[2H])c(C#N)c4)nc(-c4c([2H])c([2H])c5c([2H])c([2H])c([2H])c([2H])c5c4[2H])n3)c3c(c2)oc2ccccc23)c([2H])c1[2H]] 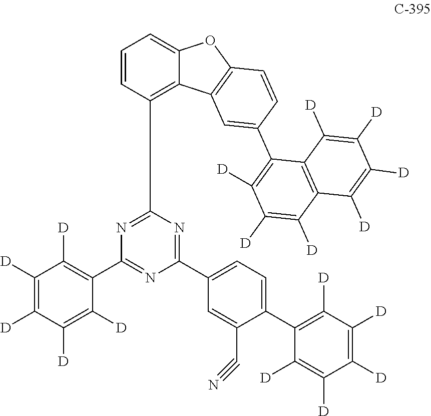 [SMILES: [2H]c1c([2H])c([2H])c(-c2nc(-c3ccc(-c4c([2H])c([2H])c([2H])c([2H])c4[2H])c(C#N)c3)nc(-c3cccc4oc5ccc(-c6c([2H])c([2H])c([2H])c7c([2H])c([2H])c([2H])c([2H])c67)cc5c34)n2)c([2H])c1[2H]] 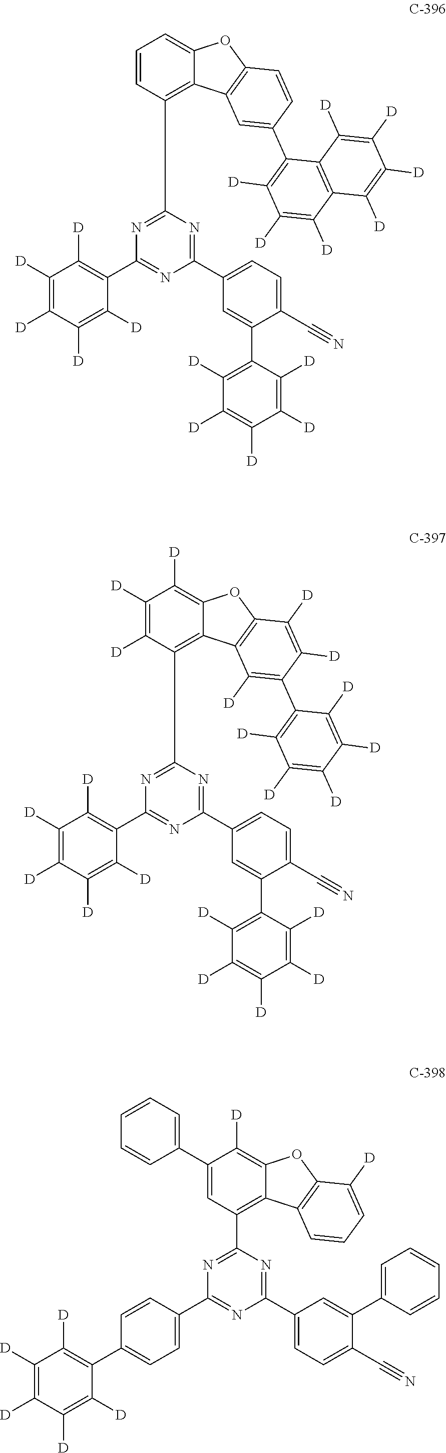 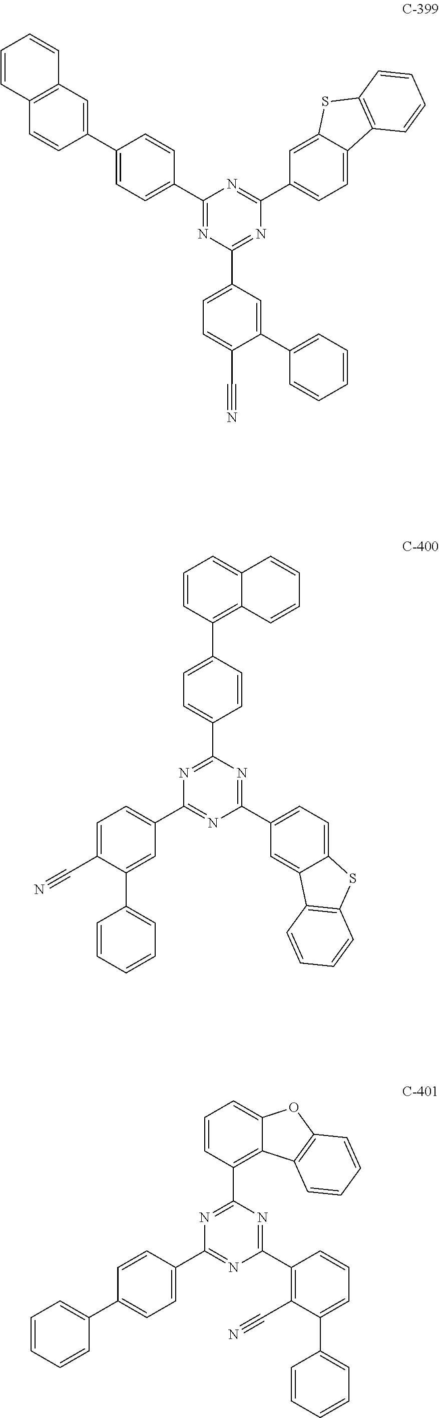 [SMILES: N#Cc1ccc(-c2nc(-c3ccc(-c4ccc5ccccc5c4)cc3)nc(-c3ccc4c(c3)sc3ccccc34)n2)cc1-c1ccccc1 ; N#Cc1ccc(-c2nc(-c3ccc(-c4cccc5ccccc45)cc3)nc(-c3ccc4sc5ccccc5c4c3)n2)cc1-c1ccccc1 ; N#Cc1c(-c2ccccc2)cccc1-c1nc(-c2ccc(-c3ccccc3)cc2)nc(-c2cccc3oc4ccccc4c23)n1] 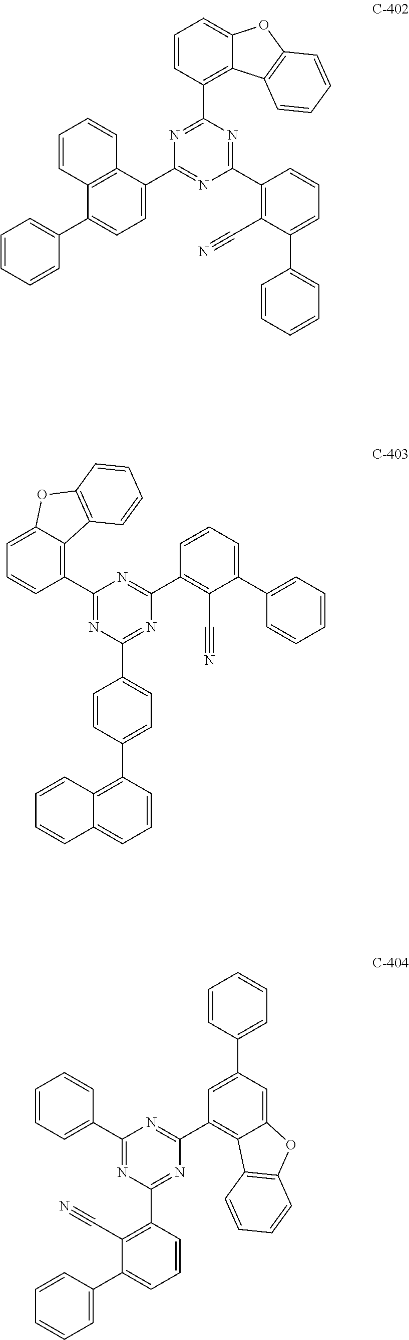 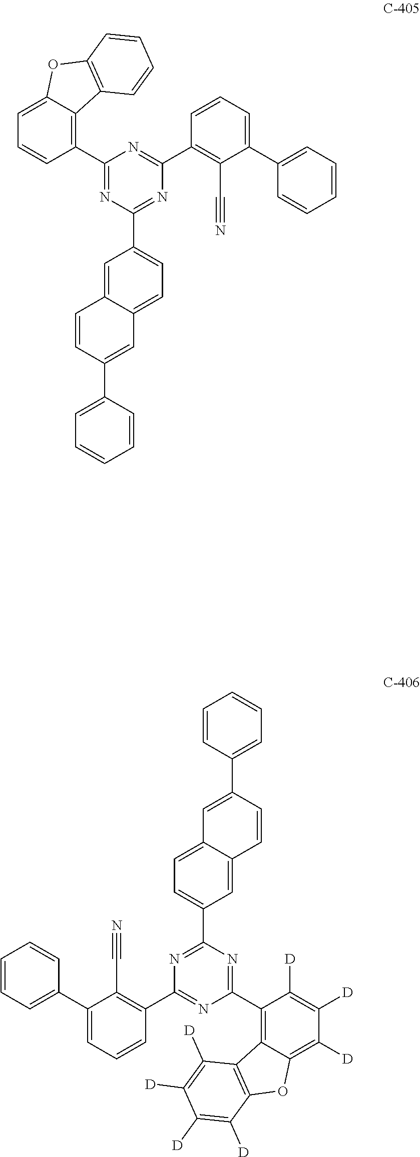 [SMILES: N#Cc1c(-c2ccccc2)cccc1-c1nc(-c2ccc3cc(-c4ccccc4)ccc3c2)nc(-c2cccc3oc4ccccc4c23)n1 ; [2H]c1c([2H])c([2H])c2c(oc3c([2H])c([2H])c([2H])c(-c4nc(-c5ccc6cc(-c7ccccc7)ccc6c5)nc(-c5cccc(-c6ccccc6)c5C#N)n4)c32)c1[2H]] 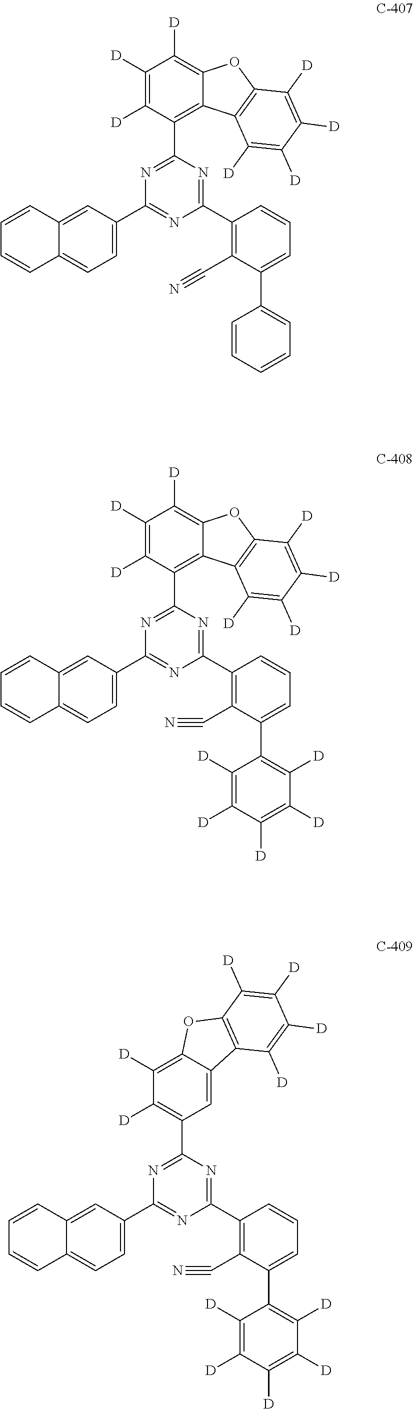 [SMILES: [2H]c1c([2H])c([2H])c2c(oc3c([2H])c([2H])c([2H])c(-c4nc(-c5ccc6ccccc6c5)nc(-c5cccc(-c6ccccc6)c5C#N)n4)c32)c1[2H] ; [2H]c1c([2H])c([2H])c(-c2cccc(-c3nc(-c4ccc5ccccc5c4)nc(-c4c([2H])c([2H])c([2H])c5oc6c([2H])c([2H])c([2H])c([2H])c6c45)n3)c2C#N)c([2H])c1[2H] ; [2H]c1c([2H])c([2H])c(-c2cccc(-c3nc(-c4ccc5ccccc5c4)nc(-c4cc5c(oc6c([2H])c([2H])c([2H])c([2H])c65)c([2H])c4[2H])n3)c2C#N)c([2H])c1[2H]] 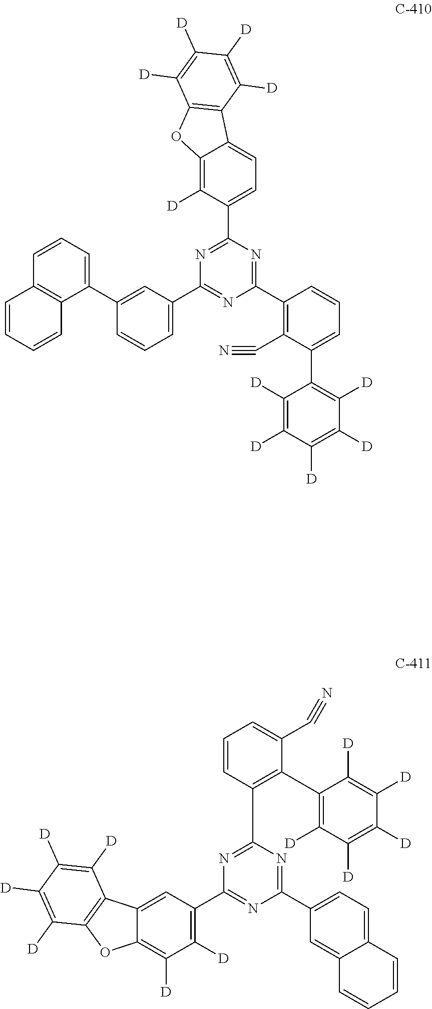 [SMILES: [2H]c1c([2H])c([2H])c(-c2cccc(-c3nc(-c4cccc(-c5cccc6ccccc56)c4)nc(-c4ccc5c(oc6c([2H])c([2H])c([2H])c([2H])c65)c4[2H])n3)c2C#N)c([2H])c1[2H] ; [2H]c1c([2H])c([2H])c(-c2c(C#N)cccc2-c2nc(-c3ccc4ccccc4c3)nc(-c3cc4c(oc5c([2H])c([2H])c([2H])c([2H])c54)c([2H])c3[2H])n2)c([2H])c1[2H]] 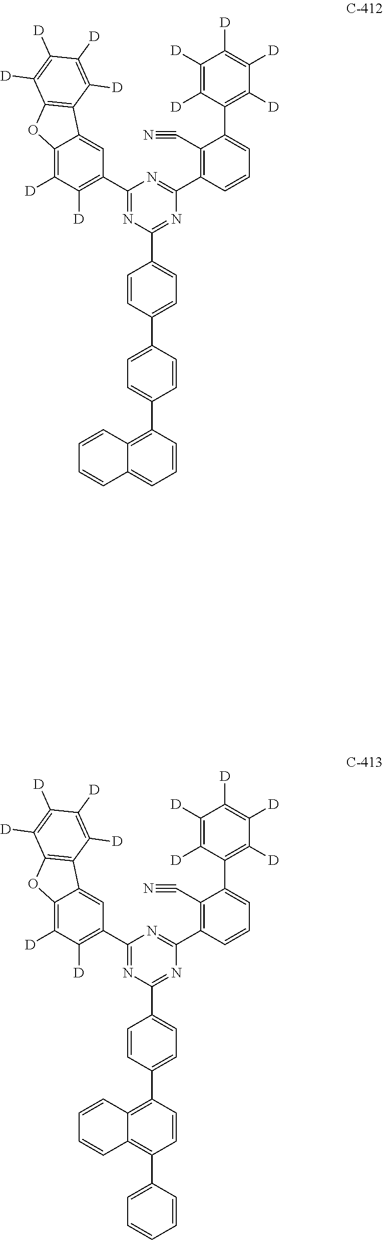 [SMILES: [2H]c1c([2H])c([2H])c(-c2cccc(-c3nc(-c4ccc(-c5ccc(-c6cccc7ccccc67)cc5)cc4)nc(-c4cc5c(oc6c([2H])c([2H])c([2H])c([2H])c65)c([2H])c4[2H])n3)c2C#N)c([2H])c1[2H] ; [2H]c1c([2H])c([2H])c(-c2cccc(-c3nc(-c4ccc(-c5ccc(-c6ccccc6)c6ccccc56)cc4)nc(-c4cc5c(oc6c([2H])c([2H])c([2H])c([2H])c65)c([2H])c4[2H])n3)c2C#N)c([2H])c1[2H]] 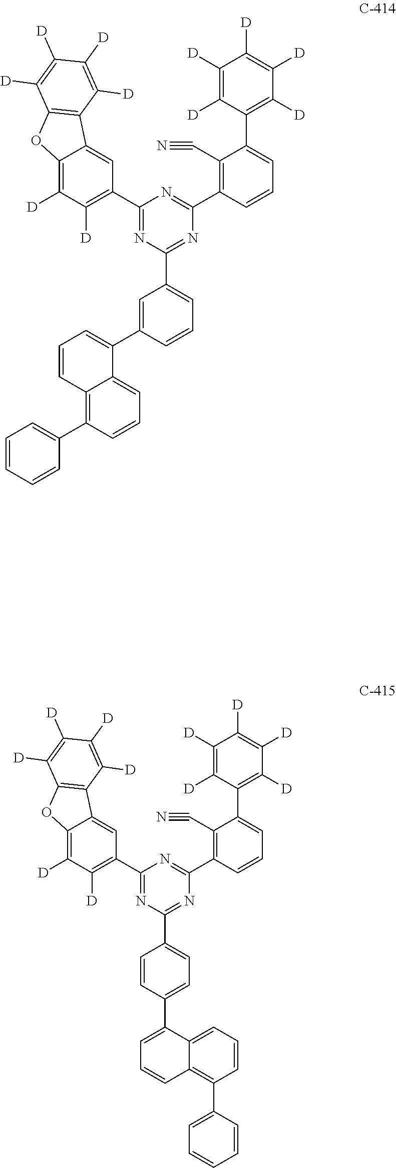 [SMILES: [2H]c1c([2H])c([2H])c(-c2cccc(-c3nc(-c4cccc(-c5cccc6c(-c7ccccc7)cccc56)c4)nc(-c4cc5c(oc6c([2H])c([2H])c([2H])c([2H])c65)c([2H])c4[2H])n3)c2C#N)c([2H])c1[2H] ; [2H]c1c([2H])c([2H])c(-c2cccc(-c3nc(-c4ccc(-c5cccc6c(-c7ccccc7)cccc56)cc4)nc(-c4cc5c(oc6c([2H])c([2H])c([2H])c([2H])c65)c([2H])c4[2H])n3)c2C#N)c([2H])c1[2H]] 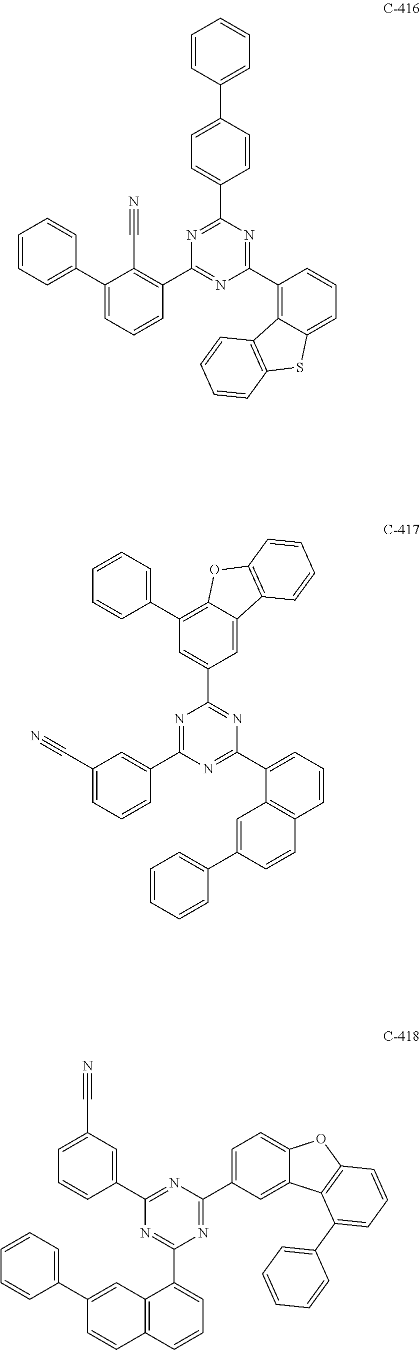 [SMILES: N#Cc1c(-c2ccccc2)cccc1-c1nc(-c2ccc(-c3ccccc3)cc2)nc(-c2cccc3sc4ccccc4c23)n1 ; N#Cc1cccc(-c2nc(-c3cc(-c4ccccc4)c4oc5ccccc5c4c3)nc(-c3cccc4ccc(-c5ccccc5)cc34)n2)c1 ; N#Cc1cccc(-c2nc(-c3ccc4oc5cccc(-c6ccccc6)c5c4c3)nc(-c3cccc4ccc(-c5ccccc5)cc34)n2)c1] 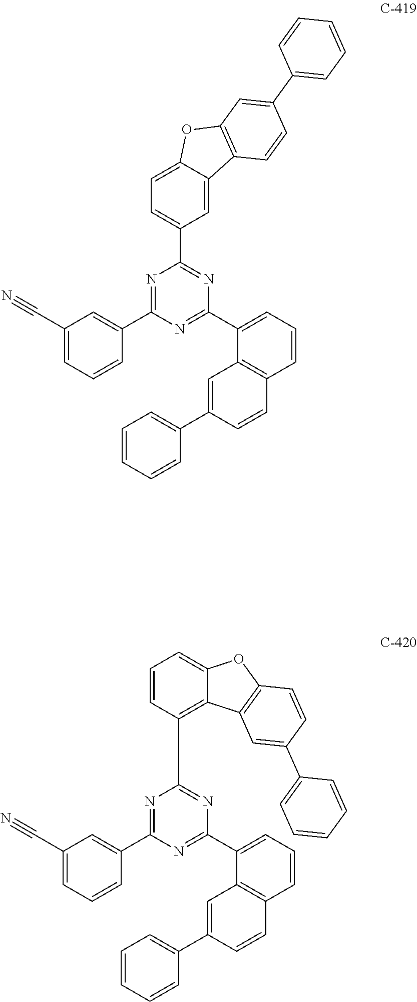 [SMILES: N#Cc1cccc(-c2nc(-c3ccc4oc5cc(-c6ccccc6)ccc5c4c3)nc(-c3cccc4ccc(-c5ccccc5)cc34)n2)c1 ; N#Cc1cccc(-c2nc(-c3cccc4ccc(-c5ccccc5)cc34)nc(-c3cccc4oc5ccc(-c6ccccc6)cc5c34)n2)c1] 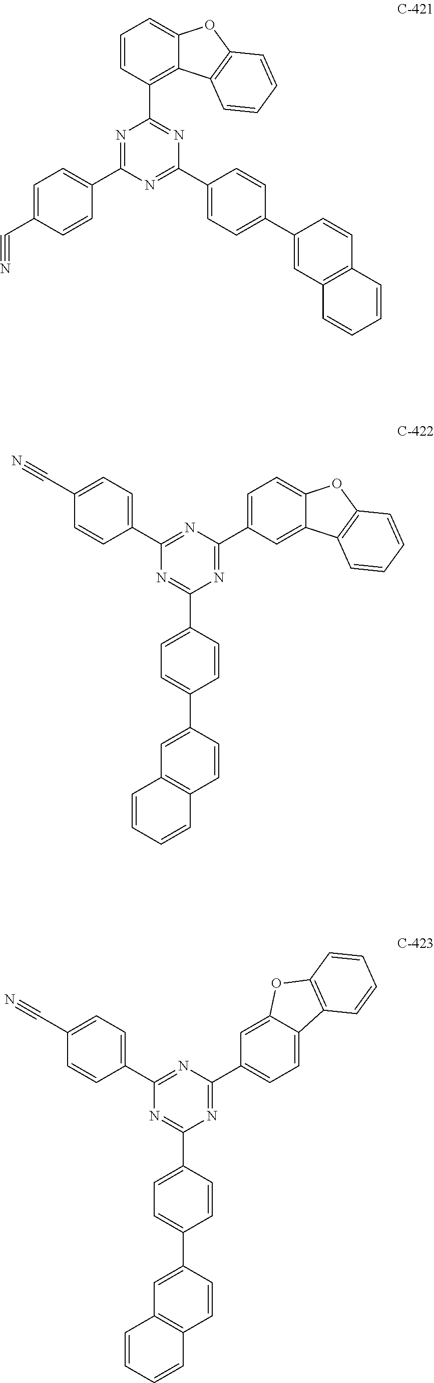 [SMILES: N#Cc1ccc(-c2nc(-c3ccc(-c4ccc5ccccc5c4)cc3)nc(-c3cccc4oc5ccccc5c34)n2)cc1 ; N#Cc1ccc(-c2nc(-c3ccc(-c4ccc5ccccc5c4)cc3)nc(-c3ccc4oc5ccccc5c4c3)n2)cc1 ; N#Cc1ccc(-c2nc(-c3ccc(-c4ccc5ccccc5c4)cc3)nc(-c3ccc4c(c3)oc3ccccc34)n2)cc1] 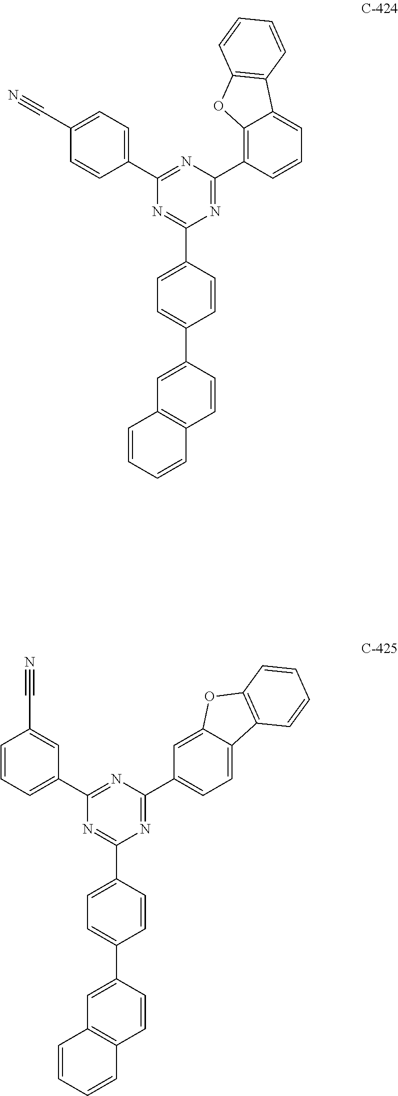 [SMILES: N#Cc1ccc(-c2nc(-c3ccc(-c4ccc5ccccc5c4)cc3)nc(-c3cccc4c3oc3ccccc34)n2)cc1 ; N#Cc1cccc(-c2nc(-c3ccc(-c4ccc5ccccc5c4)cc3)nc(-c3ccc4c(c3)oc3ccccc34)n2)c1] 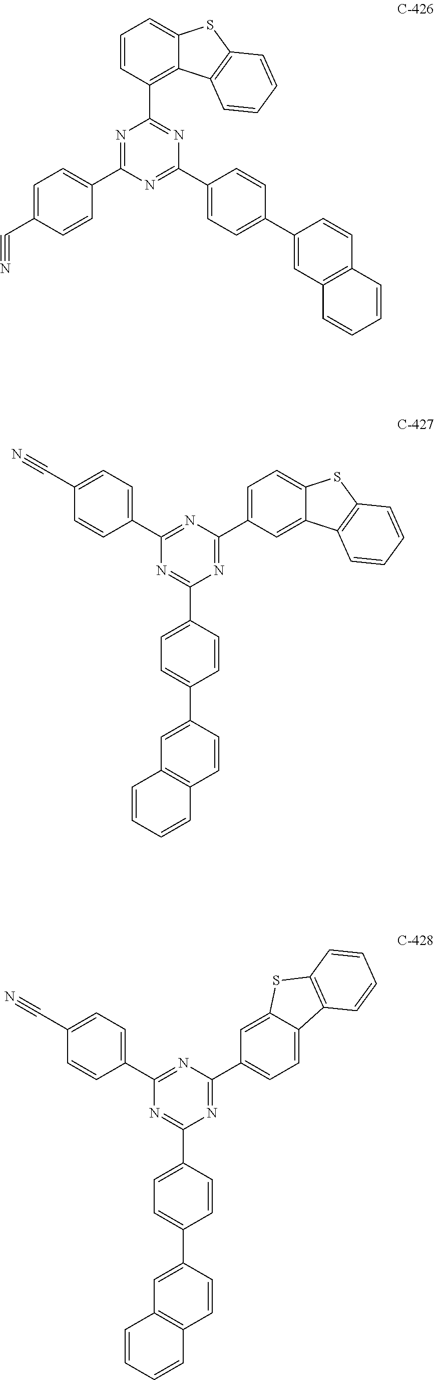 [SMILES: N#Cc1ccc(-c2nc(-c3ccc(-c4ccc5ccccc5c4)cc3)nc(-c3cccc4sc5ccccc5c34)n2)cc1 ; N#Cc1ccc(-c2nc(-c3ccc(-c4ccc5ccccc5c4)cc3)nc(-c3ccc4sc5ccccc5c4c3)n2)cc1 ; N#Cc1ccc(-c2nc(-c3ccc(-c4ccc5ccccc5c4)cc3)nc(-c3ccc4c(c3)sc3ccccc34)n2)cc1] 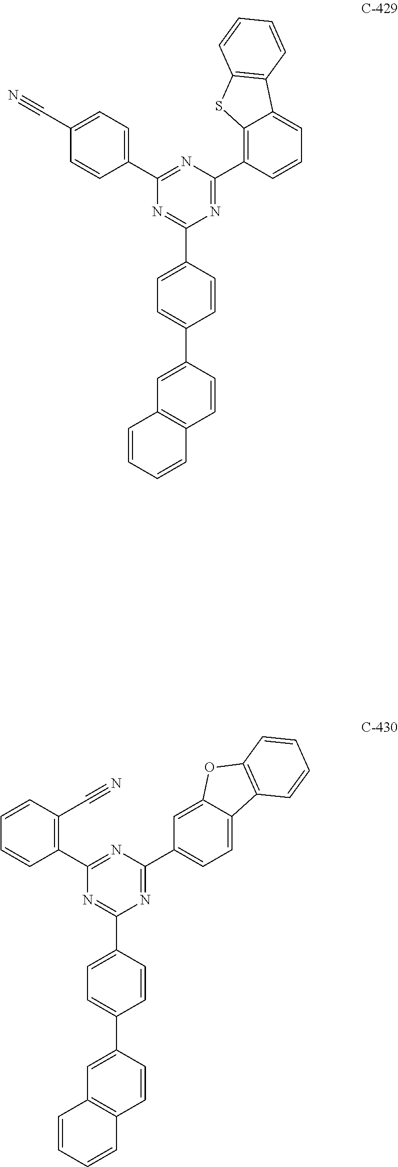 [SMILES: N#Cc1ccc(-c2nc(-c3ccc(-c4ccc5ccccc5c4)cc3)nc(-c3cccc4c3sc3ccccc34)n2)cc1 ; N#Cc1ccccc1-c1nc(-c2ccc(-c3ccc4ccccc4c3)cc2)nc(-c2ccc3c(c2)oc2ccccc23)n1] 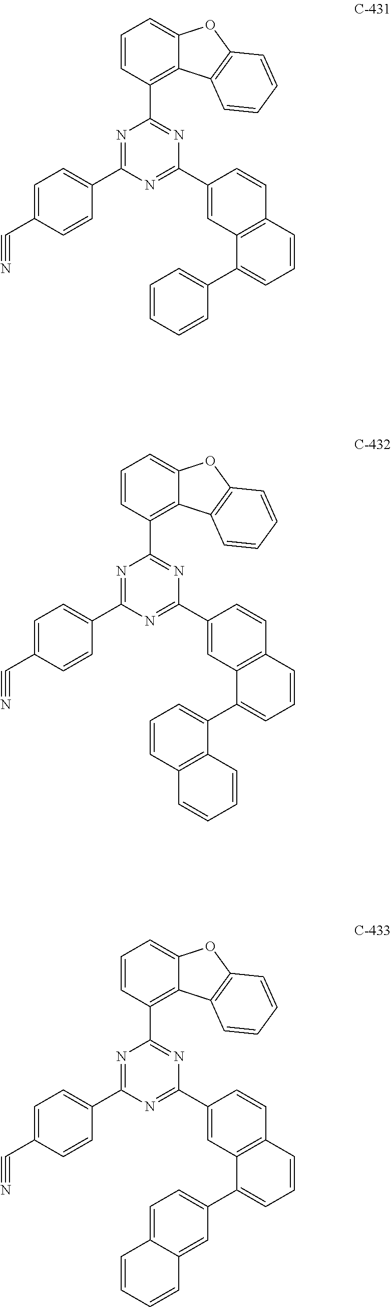 [SMILES: N#Cc1ccc(-c2nc(-c3ccc4cccc(-c5ccccc5)c4c3)nc(-c3cccc4oc5ccccc5c34)n2)cc1 ; N#Cc1ccc(-c2nc(-c3ccc4cccc(-c5cccc6ccccc56)c4c3)nc(-c3cccc4oc5ccccc5c34)n2)cc1 ; N#Cc1ccc(-c2nc(-c3ccc4cccc(-c5ccc6ccccc6c5)c4c3)nc(-c3cccc4oc5ccccc5c34)n2)cc1] 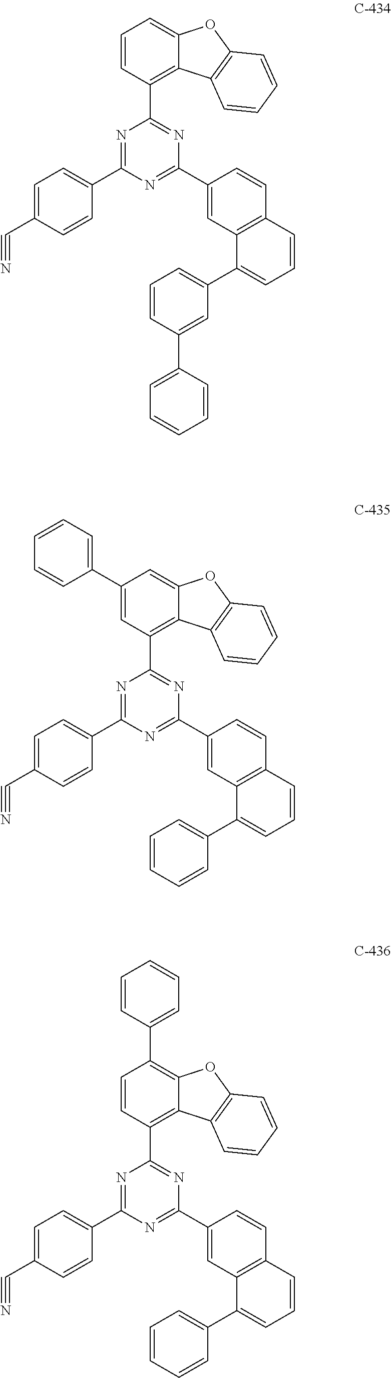 [SMILES: N#Cc1ccc(-c2nc(-c3ccc4cccc(-c5cccc(-c6ccccc6)c5)c4c3)nc(-c3cccc4oc5ccccc5c34)n2)cc1 ; N#Cc1ccc(-c2nc(-c3ccc4cccc(-c5ccccc5)c4c3)nc(-c3cc(-c4ccccc4)cc4oc5ccccc5c34)n2)cc1 ; N#Cc1ccc(-c2nc(-c3ccc4cccc(-c5ccccc5)c4c3)nc(-c3ccc(-c4ccccc4)c4oc5ccccc5c34)n2)cc1] 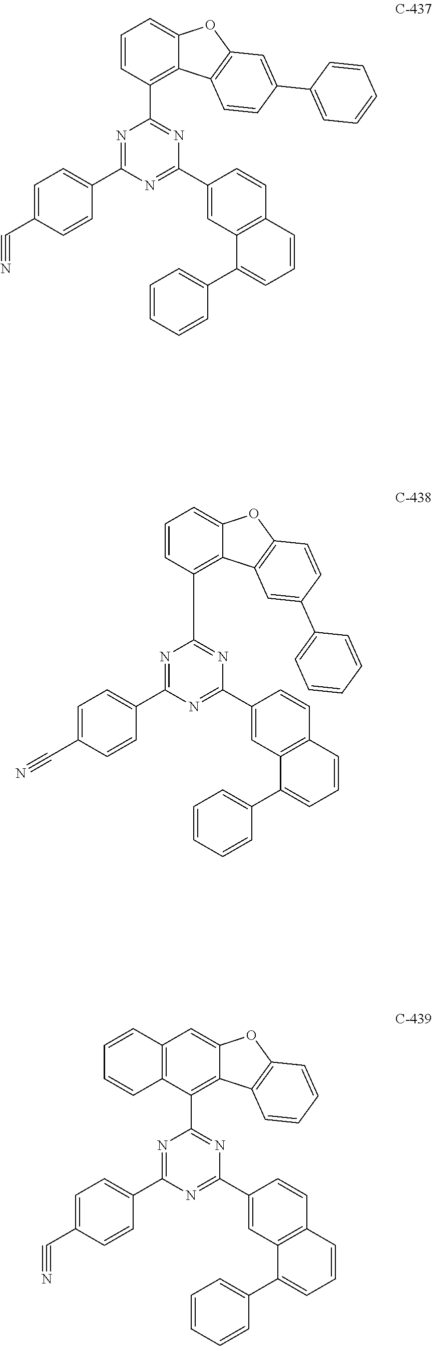 [SMILES: N#Cc1ccc(-c2nc(-c3ccc4cccc(-c5ccccc5)c4c3)nc(-c3cccc4oc5cc(-c6ccccc6)ccc5c34)n2)cc1 ; N#Cc1ccc(-c2nc(-c3ccc4cccc(-c5ccccc5)c4c3)nc(-c3cccc4oc5ccc(-c6ccccc6)cc5c34)n2)cc1 ; N#Cc1ccc(-c2nc(-c3ccc4cccc(-c5ccccc5)c4c3)nc(-c3c4ccccc4cc4oc5ccccc5c34)n2)cc1] 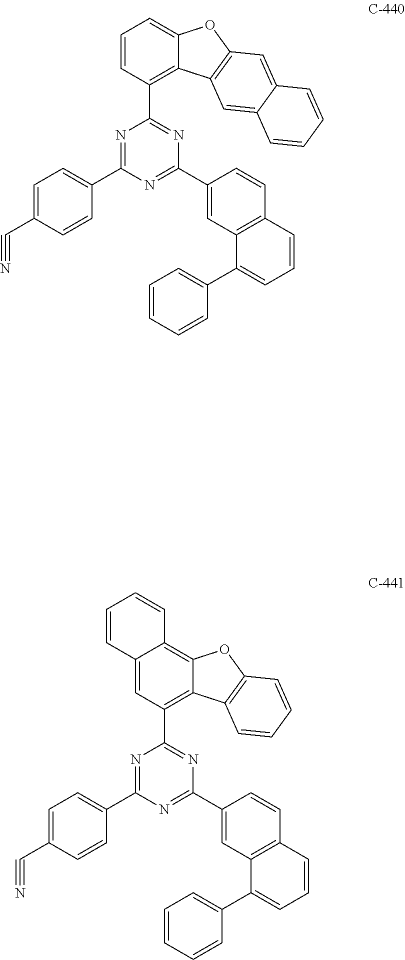 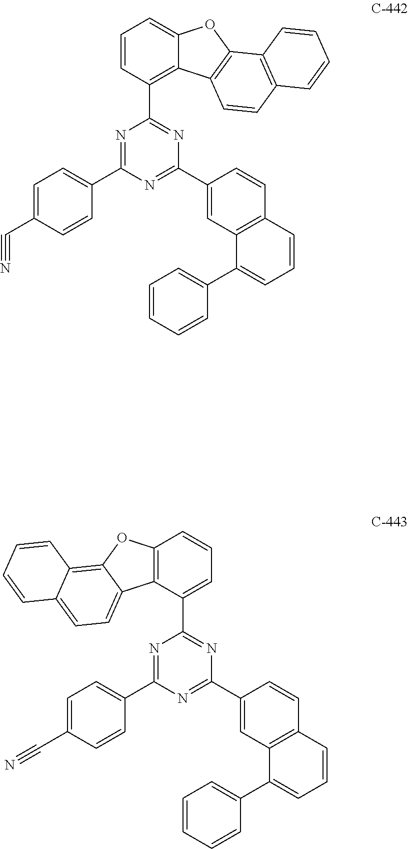 [SMILES: N#Cc1ccc(-c2nc(-c3ccc4cccc(-c5ccccc5)c4c3)nc(-c3cccc4oc5c6ccccc6ccc5c34)n2)cc1 ; N#Cc1ccc(-c2nc(-c3ccc4cccc(-c5ccccc5)c4c3)nc(-c3cccc4oc5c6ccccc6ccc5c34)n2)cc1] 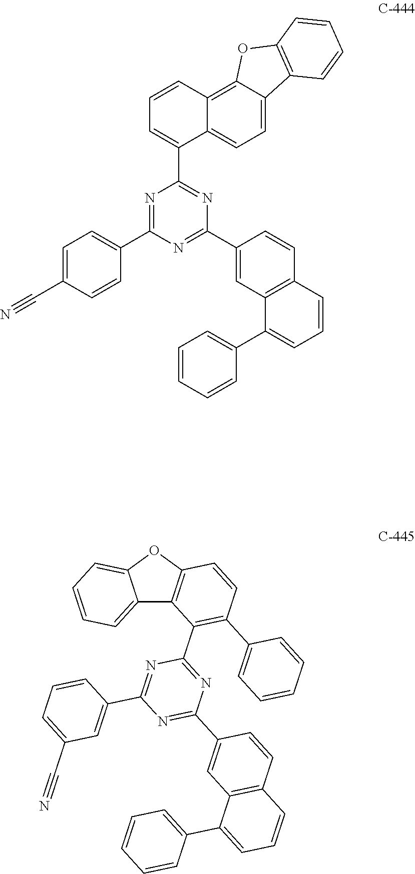 [SMILES: N#Cc1ccc(-c2nc(-c3ccc4cccc(-c5ccccc5)c4c3)nc(-c3cccc4c3ccc3c5ccccc5oc43)n2)cc1 ; N#Cc1cccc(-c2nc(-c3ccc4cccc(-c5ccccc5)c4c3)nc(-c3c(-c4ccccc4)ccc4oc5ccccc5c34)n2)c1] 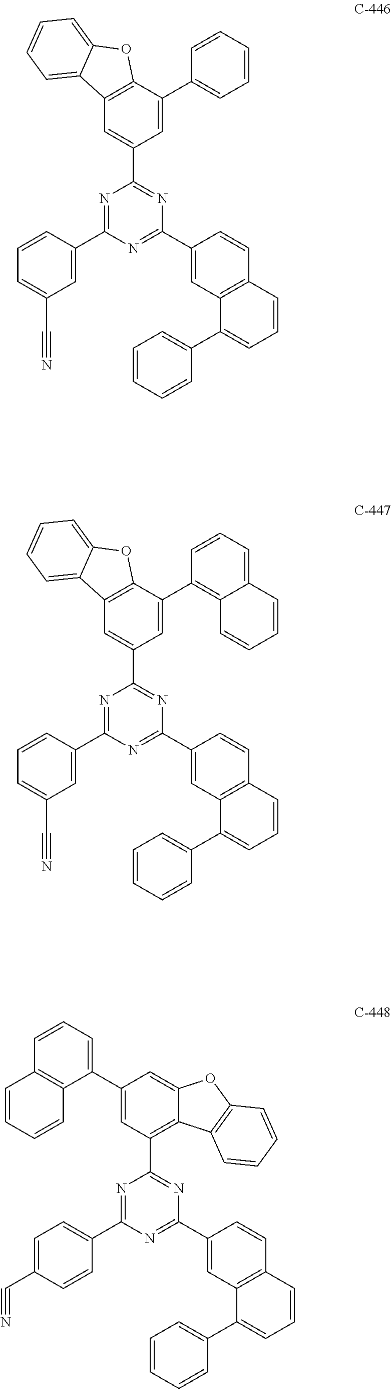 [SMILES: N#Cc1cccc(-c2nc(-c3ccc4cccc(-c5ccccc5)c4c3)nc(-c3cc(-c4ccccc4)c4oc5ccccc5c4c3)n2)c1 ; N#Cc1cccc(-c2nc(-c3ccc4cccc(-c5ccccc5)c4c3)nc(-c3cc(-c4cccc5ccccc45)c4oc5ccccc5c4c3)n2)c1 ; N#Cc1ccc(-c2nc(-c3ccc4cccc(-c5ccccc5)c4c3)nc(-c3cc(-c4cccc5ccccc45)cc4oc5ccccc5c34)n2)cc1] 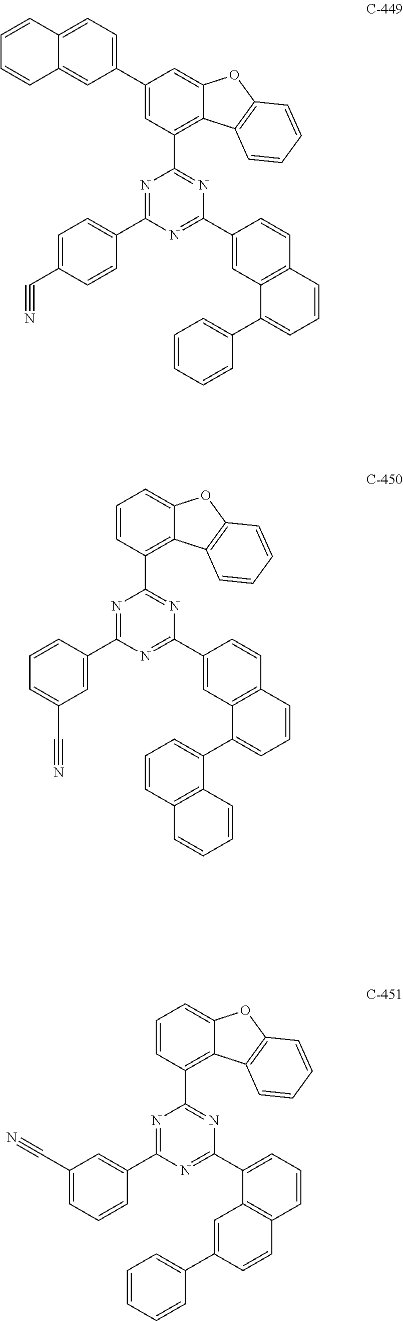 [SMILES: N#Cc1ccc(-c2nc(-c3ccc4cccc(-c5ccccc5)c4c3)nc(-c3cc(-c4ccc5ccccc5c4)cc4oc5ccccc5c34)n2)cc1 ; N#Cc1cccc(-c2nc(-c3ccc4cccc(-c5cccc6ccccc56)c4c3)nc(-c3cccc4oc5ccccc5c34)n2)c1 ; N#Cc1cccc(-c2nc(-c3cccc4ccc(-c5ccccc5)cc34)nc(-c3cccc4oc5ccccc5c34)n2)c1] 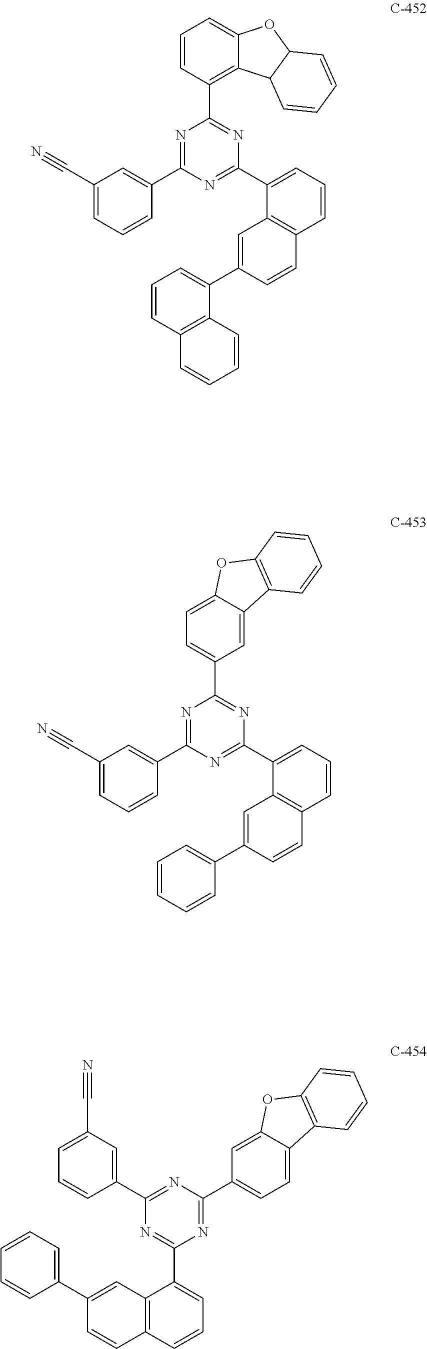 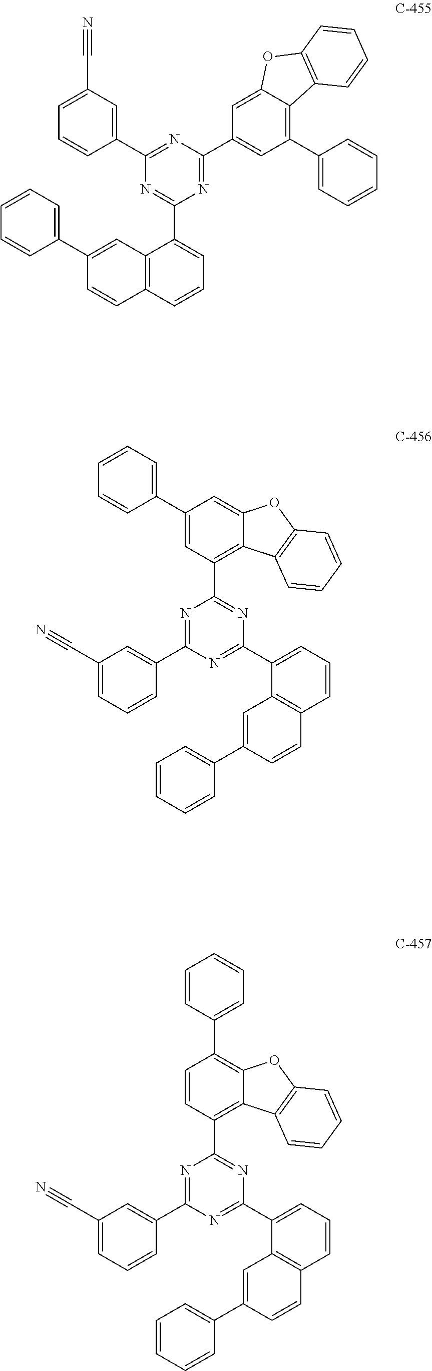 [SMILES: N#Cc1cccc(-c2nc(-c3cc(-c4ccccc4)c4c(c3)oc3ccccc34)nc(-c3cccc4ccc(-c5ccccc5)cc34)n2)c1 ; N#Cc1cccc(-c2nc(-c3cccc4ccc(-c5ccccc5)cc34)nc(-c3cc(-c4ccccc4)cc4oc5ccccc5c34)n2)c1 ; N#Cc1cccc(-c2nc(-c3cccc4ccc(-c5ccccc5)cc34)nc(-c3ccc(-c4ccccc4)c4oc5ccccc5c34)n2)c1] 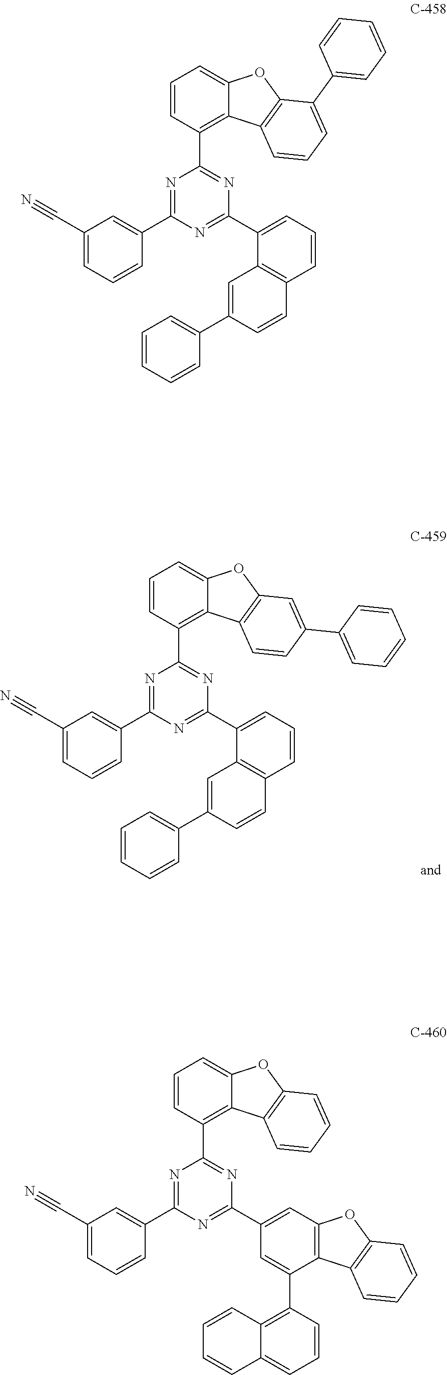 [SMILES: N#Cc1cccc(-c2nc(-c3cccc4ccc(-c5ccccc5)cc34)nc(-c3cccc4oc5c(-c6ccccc6)cccc5c34)n2)c1 ; N#Cc1cccc(-c2nc(-c3cccc4ccc(-c5ccccc5)cc34)nc(-c3cccc4oc5cc(-c6ccccc6)ccc5c34)n2)c1 ; N#Cc1cccc(-c2nc(-c3cc(-c4cccc5ccccc45)c4c(c3)oc3ccccc34)nc(-c3cccc4oc5ccccc5c34)n2)c1]
wherein in the compounds above, Dₙ means that n number of hydrogens are replaced with deuterium, and n represents an integer from 1 to the maximum number of hydrogens in the compound.

25. An organic electroluminescent material comprising the organic electroluminescent compound according to claim 20.

26. An organic electroluminescent device comprising the organic electroluminescent compound according to claim 20.
